(19) United States
(12) Patent Application Publication
(10) Pub. No.: US 2026/0231598 A1
(43) Pub. Date: Aug. 6, 2026

(54) ORGANIC ELECTROLUMINESCENT ELEMENT AND ELECTRONIC DEVICE

(71) Applicant: IDEMITSU KOSAN CO.,LTD., Tokyo (JP)

(72) Inventors: Shintaro BAN, Chiyoda-ku, Tokyo (JP); Kei YOSHIDA, Chiyoda-ku, Tokyo (JP); Masato MITANI, Chiyoda-ku, Tokyo (JP); Kazuki TERADA, Chiyoda-ku, Tokyo (JP); Hiroaki ITOI, Chiyoda-ku, Tokyo (JP); Yu KUDO, Chiyoda-ku, Tokyo (JP)

(73) Assignee: IDEMITSU KOSAN CO.,LTD., Tokyo (JP)

(21) Appl. No.: 19/152,247

(22) PCT Filed: Jan. 15, 2024
(86) PCT No.: PCT/JP2024/000831

§ 371 Date: Jul. 30, 2025

(30) Foreign Application Priority Data
Feb. 6, 2023 (JP) 2023-015904

(51) Int. Cl. H10K 50/12; C09K 11/06; H10K 85/60; H10K 101/00; H10K 101/10; H10K 102/00

(52) U.S. Cl. CPC H10K 50/12; C09K 11/06; H10K 85/622; H10K 85/623; H10K 85/624; H10K 85/626; H10K 85/633; H10K 85/636; H10K 85/654; H10K 85/6572; H10K 85/6574; H10K 85/6576; H10K 85/658; C09K 2211/1088; H10K 2101/10; H10K 2101/90; H10K 2102/351

(57) ABSTRACT

An organic electroluminescent element comprising a negative electrode, a positive electrode, and light emitting layers disposed between the negative electrode and the positive electrode, wherein the light emitting layers include a first light emitting layer and a second light emitting layer, and the first light emitting layer contains at least one compound selected from the group consisting of compounds represented by formulae (1)-(4).

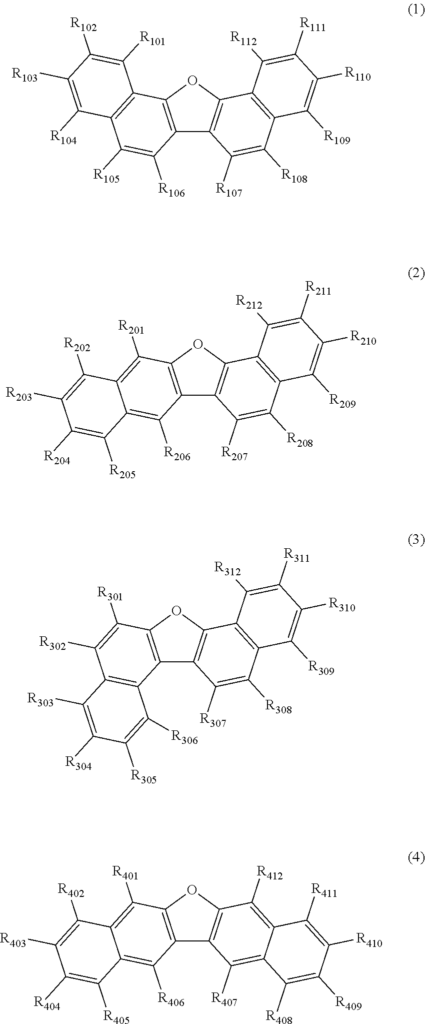

### TECHNICAL FIELD

The present invention relates to an organic electroluminescence device and an electronic apparatus.

### BACKGROUND ART

When a voltage is applied to an organic electroluminescence device (hereinafter, also referred to as “organic EL device”), holes are injected from an anode and electrons are injected from a cathode into an emitting layer. The injected holes and electrons are recombined in the emitting layer to form excitons.

Conventional organic EL devices have not yet achieved sufficient device performance. In order to enhance device performance, improvement of a material used for an organic EL device has been gradually advanced, but further improvement in performance is required.

Patent Document 1 describes that a phenomenon (hereinafter, referred to as Triplet-Triplet Fusion=TTF phenomenon in some cases) in which singlet excitons are generated by collision fusion of two triplet excitons is used to improve performance of an organic EL device.

### RELATED ART DOCUMENTS

### Patent Documents

[Patent Document 1] WO 2021/210582 A1

### SUMMARY OF INVENTION

An object of the present invention is to provide a high-performance organic EL device.

As a result of intensive studies by the present inventors, it has been found that performance of a device can be improved by using a dinaphthofuran derivative having the specific structure for one layer of stacked emitting layers, and the present invention has been completed.

According to the present invention, the following organic EL device and the like are provided.

1. An organic electroluminescence device comprising
a cathode,
an anode, and
an emitting layer disposed between the cathode and the anode,
wherein the emitting layer comprises a first emitting layer and a second emitting layer, and
the first emitting layer contains one or more compounds selected from the group consisting of a compound represented by each of the following formulas (1) to (4):

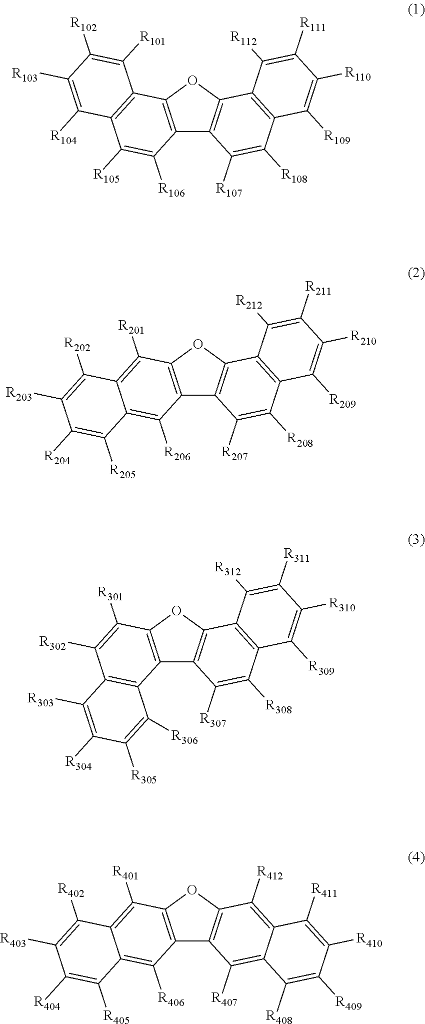

wherein in the formulas (1) to (4),
at least one of R₁₀₁ to R₁₁₂, at least one of R₂₀₁ to R₂₁₂, at least one of R₃₀₁ to R₃₁₂, and at least one of R₄₀₁ to R₄₁₂ are a single bond bonded to a group represented by the following formula (A1):

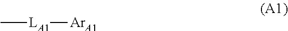

in the formula (A1),
L_{A1} is
a single bond,
a substituted or unsubstituted arylene group having 6 to 20 ring carbon atoms, or
a substituted or unsubstituted divalent heterocyclic group having 5 to 19 ring atoms, Ar_{A1} is
a substituted or unsubstituted aryl group having 6 to 30 ring carbon atoms, or
a substituted or unsubstituted monovalent heterocyclic group having 5 to 30 ring atoms, R₁₀₁ to R₁₁₂, R₂₀₁ to R₂₁₂, R₃₀₁ to R₃₁₂, and R₄₀₁ to R₄₁₂ which are not a single bond bonded to the group represented by the formula (A1) are independently
a hydrogen atom,
a substituted or unsubstituted aryl group having 6 to 20 ring carbon atoms, or
a substituted or unsubstituted monovalent heterocyclic group having 5 to 19 ring atoms, and
when two or more groups represented by the formula (A1) are present, the two or more groups represented by the formula (A1) may be the same as or different from each other.
   2. An electronic apparatus comprising the organic electroluminescence device according to 1.

According to the present invention, a high-performance organic EL device can be provided.

### BRIEF DESCRIPTION OF DRAWING

FIG. 1 is a view illustrating a schematic configuration of an organic EL device according to an aspect of the present invention.

### DESCRIPTION OF EMBODIMENTS

### Definition

In this specification, a hydrogen atom includes its isotopes different in the number of neutrons, namely, a protium, a deuterium and a tritium.

In this specification, at a bondable position in a chemical formula where a symbol such as “R”, or “D” representing a deuterium atom is not indicated, a hydrogen atom, that is, a protium atom, a deuterium atom or a tritium atom is bonded.

In this specification, the number of ring carbon atoms represents the number of carbon atoms forming a subject ring itself among the carbon atoms of a compound having a structure in which atoms are bonded in a ring form (for example, a monocyclic compound, a fused ring compound, a cross-linked compound, a carbocyclic compound, or a heterocyclic compound). When the subject ring is substituted by a substituent, the carbon contained in the substituent is not included in the number of ring carbon atoms. The same shall apply to “the number of ring carbon atoms” described below, unless otherwise specified. For example, a benzene ring has 6 ring carbon atoms, a naphthalene ring includes 10 ring carbon atoms, a pyridine ring includes 5 ring carbon atoms, and a furan ring includes 4 ring carbon atoms. Further, for example, a 9,9-diphenylfluorenyl group includes 13 ring carbon atoms, and a 9,9′-spirobifluorenyl group includes 25 ring carbon atoms.

When a benzene ring is substituted by, for example, an alkyl group as a substituent, the number of carbon atoms of the alkyl group is not included in the number of ring carbon atoms of the benzene ring. Therefore, the number of ring carbon atoms of the benzene ring substituted by the alkyl group is 6. When a naphthalene ring is substituted by, for example, an alkyl group as a substituent, the number of carbon atoms of the alkyl group is not included in the number of ring carbon atoms of the naphthalene ring. Therefore, the number of ring carbon atoms of the naphthalene ring substituted by the alkyl group is 10.

In this specification, the number of ring atoms represents the number of atoms forming a subject ring itself among the atoms of a compound having a structure in which atoms are bonded in a ring form (for example, the structure includes a monocyclic ring, a fused ring and a ring assembly) (for example, a monocyclic compound, a fused ring compound, a cross-linked compound, a carbocyclic compound and a heterocyclic compound). The number of ring atoms does not include atoms which do not form the ring (for example, a hydrogen atom which terminates a bond of the atoms forming the ring), or atoms contained in a substituent when the ring is substituted by the substituent. The same shall apply to “the number of ring atoms” described below, unless otherwise specified. For example, the number of atoms of a pyridine ring is 6, the number of atoms of a quinazoline ring is 10, and the number of a furan ring is 5. For example, hydrogen atoms bonded to a pyridine ring and atoms constituting a substituent substituted on the pyridine ring are not included in the number of ring atoms of the pyridine ring. Therefore, the number of ring atoms of a pyridine ring with which a hydrogen atom or a substituent is bonded is 6. For example, hydrogen atoms and atoms constituting a substituent which are bonded with a quinazoline ring is not included in the number of ring atoms of the quinazoline ring. Therefore, the number of ring atoms of a quinazoline ring with which a hydrogen atom or a substituent is bonded is 10.

In this specification, “XX to YY carbon atoms” in the expression “a substituted or unsubstituted ZZ group including XX to YY carbon atoms” represents the number of carbon atoms in the case where the ZZ group is unsubstituted by a substituent, and does not include the number of carbon atoms of a substituent in the case where the ZZ group is substituted by the substituent. Here, “YY” is larger than “XX”, and “XX means an integer of 1 or more and “YY” means an integer of 2 or more.

In this specification, “XX to YY atoms” in the expression “a substituted or unsubstituted ZZ group including XX to YY atoms” represents the number of atoms in the case where the ZZ group is unsubstituted by a substituent, and does not include the number of atoms of a substituent in the case where the ZZ group is substituted by the substituent. Here, “YY” is larger than XX”, and “XX” means an integer of 1 or more and “YY” means an integer of 2 or more.

In this specification, the unsubstituted ZZ group represents the case where the “substituted or unsubstituted ZZ group” is a “ZZ group unsubstituted by a substituent”, and the substituted ZZ group represents the case where the “substituted or unsubstituted ZZ group“is a” ZZ group substituted by a substituent”.

In this specification, a term “unsubstituted” in the case of “a substituted or unsubstituted ZZ group” means that hydrogen atoms in the ZZ group are not substituted by a substituent. Hydrogen atoms in a term “unsubstituted ZZ group” are a protium atom, a deuterium atom, or a tritium atom.

In this specification, a term “substituted” in the case of “a substituted or unsubstituted ZZ group” means that one or more hydrogen atoms in the ZZ group are substituted by a substituent. Similarly, a term “substituted” in the case of “a BB group substituted by an AA group” means that one or more hydrogen atoms in the BB group are substituted by the AA group.

“Substituent as Described in this Specification”

Hereinafter, the substituent described in this specification will be explained.

The number of ring carbon atoms of the “unsubstituted aryl group” described in this specification is 6 to 50, preferably 6 to 30, and more preferably 6 to 18, unless otherwise specified.

The number of ring atoms of the “unsubstituted heterocyclic group” described in this specification is 5 to 50, preferably 5 to 30, and more preferably 5 to 18, unless otherwise specified.

The number of carbon atoms of the “unsubstituted alkyl group” described in this specification is 1 to 50, preferably 1 to 20, and more preferably 1 to 6, unless otherwise specified.

The number of carbon atoms of the “unsubstituted alkenyl group” described in this specification is 2 to 50, preferably 2 to 20, and more preferably 2 to 6, unless otherwise specified.

The number of carbon atoms of the “unsubstituted alkynyl group” described in this specification is 2 to 50, preferably 2 to 20, and more preferably 2 to 6, unless otherwise specified.

The number of ring carbon atoms of the “unsubstituted cycloalkyl group” described in this specification is 3 to 50, preferably 3 to 20, and more preferably 3 to 6, unless otherwise specified.

The number of ring carbon atoms of the “unsubstituted arylene group” described in this specification is 6 to 50, preferably 6 to 30, and more preferably 6 to 18, unless otherwise specified.

The number of ring atoms of the “unsubstituted divalent heterocyclic group” described in this specification is 5 to 50, preferably 5 to 30, and more preferably 5 to 18, unless otherwise specified.

The number of carbon atoms of the “unsubstituted alkylene group” described in this specification is 1 to 50, preferably 1 to 20, and more preferably 1 to 6, unless otherwise specified.

### “Substituted or Unsubstituted Aryl Group”

Specific examples of the “substituted or unsubstituted aryl group” described in this specification (specific example group G1) include the following unsubstituted aryl groups (specific example group G1A), substituted aryl groups (specific example group G1B), and the like. (Here, the unsubstituted aryl group refers to the case where the “substituted or unsubstituted aryl group” is an “aryl group unsubstituted by a substituent”, and the substituted aryl group refers to the case where the “substituted or unsubstituted aryl group“is an” aryl group substituted by a substituent”.). In this specification, in the case where simply referred as an “aryl group”, it includes both a “unsubstituted aryl group” and a “substituted aryl group.”

The “substituted aryl group” means a group in which one or more hydrogen atoms of the “unsubstituted aryl group” are substituted by a substituent. Specific examples of the “substituted aryl group” include, for example, groups in which one or more hydrogen atoms of the “unsubstituted aryl group” of the following specific example group G1A are substituted by a substituent, the substituted aryl groups of the following specific example group G1B, and the like. It should be noted that the examples of the “unsubstituted aryl group” and the examples of the “substituted aryl group” enumerated in this specification are mere examples, and the “substituted aryl group” described in this specification also includes a group in which a hydrogen atom bonded with a carbon atom of the aryl group itself in the “substituted aryl group” of the following specific group G1B is further substituted by a substituent, and a group in which a hydrogen atom of a substituent in the “substituted aryl group” of the following specific group G1B is further substituted by a substituent.

### Unsubstituted Aryl Group (Specific Example Group G1A):

a phenyl group,
a p-biphenyl group,
a m-biphenyl group,
an o-biphenyl group,
a p-terphenyl-4-yl group,
a p-terphenyl-3-yl group,
a p-terphenyl-2-yl group,
a m-terphenyl-4-yl group,
a m-terphenyl-3-yl group,
a m-terphenyl-2-yl group,
an o-terphenyl-4-yl group,
an o-terphenyl-3-yl group,
an o-terphenyl-2-yl group,
a 1-naphthyl group,
a 2-naphthyl group,
an anthryl group,
a benzanthryl group,
a phenanthryl group,
a benzophenanthryl group,
a phenalenyl group,
a pyrenyl group,
a chrysenyl group,
a benzochrysenyl group,
a triphenylenyl group,
a benzotriphenylenyl group,
a tetracenyl group,
a pentacenyl group,
a fluorenyl group,
a 9,9′-spirobifluorenyl group,
a benzofluorenyl group,
a dibenzofluorenyl group,
a fluoranthenyl group,
a benzofluoranthenyl group,
a perylenyl group, and
a monovalent aryl group derived by removing one hydrogen atom from the ring structures represented by each of the following general formulas (TEMP-1) to (TEMP-15).

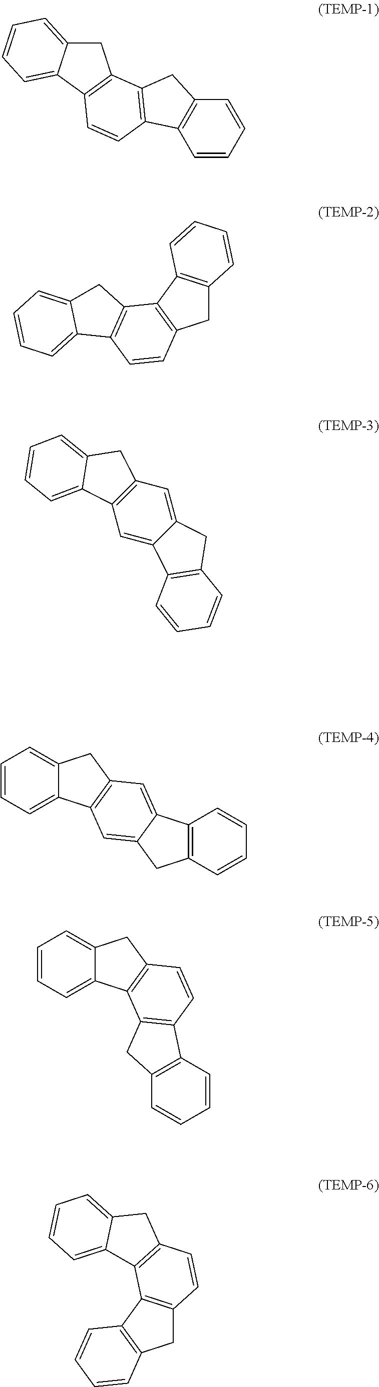

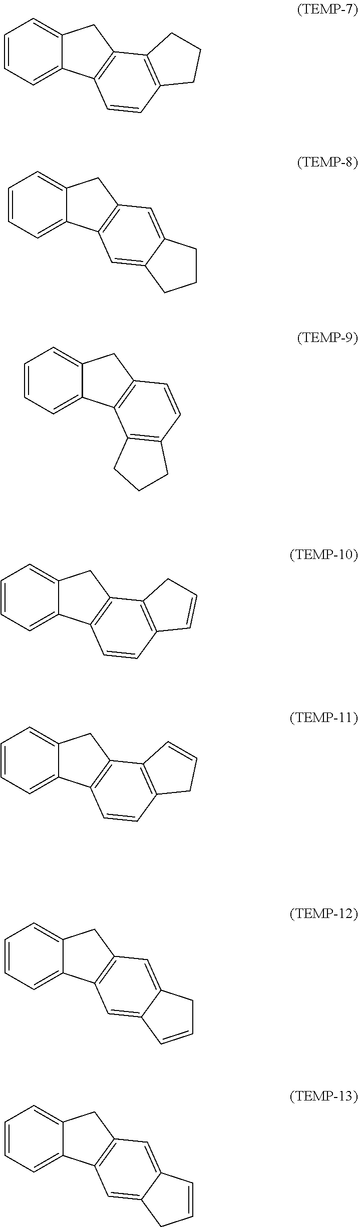

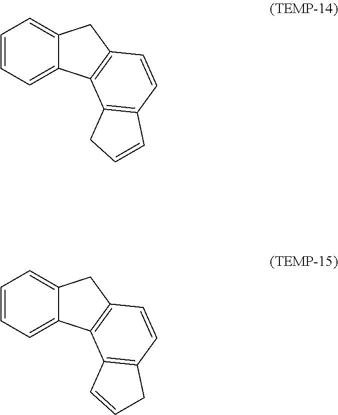

### Substituted Aryl Group (Specific Example Group G1B):

an o-tolyl group,
a m-tolyl group,
a p-tolyl group,
a p-xylyl group,
a m-xylyl group,
an o-xylyl group,
a p-isopropylphenyl group,
a m-isopropylphenyl group,
an o-isopropylphenyl group,
a p-t-butylphenyl group,
a m-t-butylphenyl group,
an o-t-butylphenyl group,
a 3,4,5-trimethylphenyl group,
a 9,9-dimethylfluorenyl group,
a 9,9-diphenylfluorenyl group,
a 9,9-bis(4-methylphenyl)fluorenyl group,
a 9,9-bis(4-isopropylphenyl)fluorenyl group,
a 9,9-bis(4-t-butylphenyl)fluorenyl group,
a cyanophenyl group,
a triphenylsilylphenyl group,
a trimethylsilylphenyl group,
a phenylnaphthyl group,
a naphthylphenyl group, and
a group in which one or more hydrogen atoms of a monovalent group derived from the ring structures represented by each of the general formulas (TEMP-1) to (TEMP-15) are substituted by a substituent.

### “Substituted or Unsubstituted Heterocyclic Group”

The “heterocyclic group” described in this specification is a ring group having at least one hetero atom in the ring atom. Specific examples of the hetero atom include a nitrogen atom, an oxygen atom, a sulfur atom, a silicon atom, a phosphorus atom, and a boron atom.

The “heterocyclic group” in this specification is a monocyclic group or a fused ring group.

The “heterocyclic group” in this specification is an aromatic heterocyclic group or a non-aromatic heterocyclic group.

Specific examples of the “substituted or unsubstituted heterocyclic group” (specific example group G2) described in this specification include the following unsubstituted heterocyclic group (specific example group G2A), the following substituted heterocyclic group (specific example group G2B), and the like. (Here, the unsubstituted heterocyclic group refers to the case where the “substituted or unsubstituted heterocyclic group“is a” heterocyclic group unsubstituted by a substituent”, and the substituted heterocyclic group refers to the case where the “substituted or unsubstituted heterocyclic group“is a” heterocyclic group substituted by a substituent”.). In this specification, in the case where simply referred as a “heterocyclic group”, it includes both the “unsubstituted heterocyclic group” and the “substituted heterocyclic group.”

The “substituted heterocyclic group” means a group in which one or more hydrogen atom of the “unsubstituted heterocyclic group” are substituted by a substituent. Specific examples of the “substituted heterocyclic group” include a group in which a hydrogen atom of “unsubstituted heterocyclic group” of the following specific example group G2A is substituted by a substituent, the substituted heterocyclic groups of the following specific example group G2B, and the like. It should be noted that the examples of the “unsubstituted heterocyclic group” and the examples of the “substituted heterocyclic group” enumerated in this specification are mere examples, and the “substituted heterocyclic group” described in this specification includes groups in which hydrogen atom bonded with a ring atom of the heterocyclic group itself in the “substituted heterocyclic group” of the specific example group G2B is further substituted by a substituent, and a group in which hydrogen atom of a substituent in the “substituted heterocyclic group” of the specific example group G2B is further substituted by a substituent.

Specific example group G2A includes, for example, the following unsubstituted heterocyclic group containing a nitrogen atom (specific example group G2A1), the following unsubstituted heterocyclic group containing an oxygen atom (specific example group G2A2), the following unsubstituted heterocyclic group containing a sulfur atom (specific example group G2A3), and the monovalent heterocyclic group derived by removing one hydrogen atom from the ring structures represented by each of the following general formulas (TEMP-16) to (TEMP-33) (specific example group G2A4).

Specific example group G2B includes, for example, the following substituted heterocyclic group containing a nitrogen atom (specific example group G2B1), the following substituted heterocyclic group containing an oxygen atom (specific example group G2B2), the following substituted heterocyclic group containing a sulfur atom (specific example group G2B3), and the following group in which one or more hydrogen atoms of the monovalent heterocyclic group derived from the ring structures represented by each of the following general formulas (TEMP-16) to (TEMP-33) are substituted by a substituent (specific example group G2B4).

### Unsubstituted Heterocyclic Group Containing a Nitrogen Atom (Specific Example Group G2A1):

a pyrrolyl group,
an imidazolyl group,
a pyrazolyl group,
a triazolyl group,
a tetrazolyl group,
an oxazolyl group,
an isoxazolyl group,
an oxadiazolyl group,
a thiazolyl group,
an isothiazolyl group,
a thiadiazolyl group,
a pyridyl group,
a pyridazinyl group,
a pyrimidinyl group,
a pyrazinyl group,
a triazinyl group,
an indolyl group,
an isoindolyl group,
an indolizinyl group,
a quinolizinyl group,
a quinolyl group,
an isoquinolyl group,
a cinnolyl group,
a phthalazinyl group,
a quinazolinyl group,
a quinoxalinyl group,
a benzimidazolyl group,
an indazolyl group,
a phenanthrolinyl group,
a phenanthridinyl group,
an acridinyl group,
a phenazinyl group,
a carbazolyl group,
a benzocarbazolyl group,
a morpholino group,
a phenoxazinyl group,
a phenothiazinyl group,
an azacarbazolyl group, and
a diazacarbazolyl group.

### Unsubstituted Heterocyclic Group Containing an Oxygen Atom (Specific Example Group G2A2):

a furyl group,
an oxazolyl group,
an isoxazolyl group,
an oxadiazolyl group,
a xanthenyl group,
a benzofuranyl group,
an isobenzofuranyl group,
a dibenzofuranyl group,
a naphthobenzofuranyl group,
a benzoxazolyl group,
a benzisoxazolyl group,
a phenoxazinyl group,
a morpholino group,
a dinaphthofuranyl group,
an azadibenzofuranyl group,
a diazadibenzofuranyl group,
an azanaphthobenzofuranyl group, and
a diazanaphthobenzofuranyl group.

### Unsubstituted Heterocyclic Group Containing a Sulfur Atom (Specific Example Group G2A3):

a thienyl group,
a thiazolyl group,
an isothiazolyl group,
a thiadiazolyl group,
a benzothiophenyl group (benzothienyl group),
an isobenzothiophenyl group (isobenzothienyl group),
a dibenzothiophenyl group (dibenzothienyl group),
a naphthobenzothiophenyl group (naphthobenzothienyl group),
a benzothiazolyl group,
a benzisothiazolyl group,
a phenothiazinyl group,
a dinaphthothiophenyl group (dinaphthothienyl group),
an azadibenzothiophenyl group (azadibenzothienyl group),
a diazadibenzothiophenyl group (diazadibenzothienyl group),
an azanaphthobenzothiophenyl group (azanaphthobenzothienyl group), and
a diazanaphthobenzothiophenyl group (diazanaphthobenzothienyl group).
   Monovalent Heterocyclic Group Derived by Removing One Hydrogen Atom from the Ring Structures Represented by Each of the Following General Formulas (TEMP-16) to (TEMP-33) (Specific Example Group G2A4):

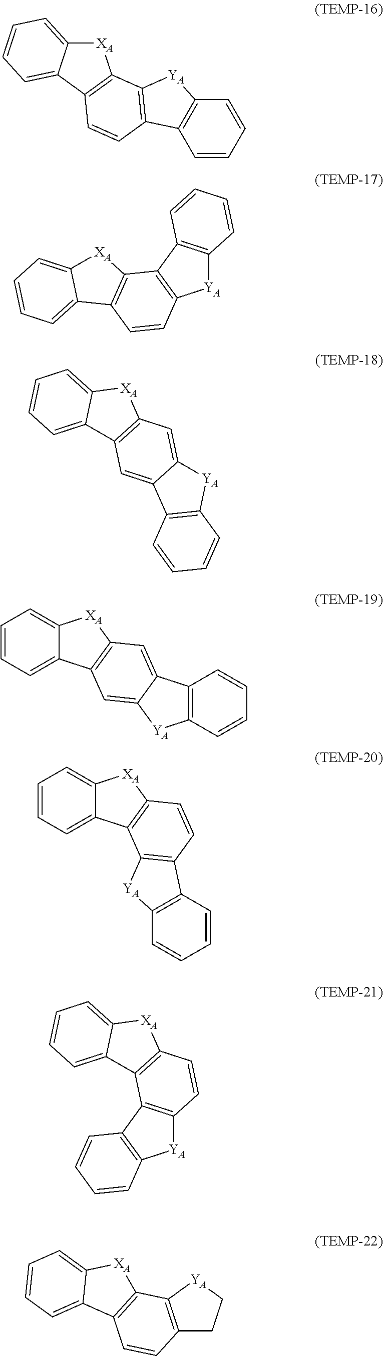

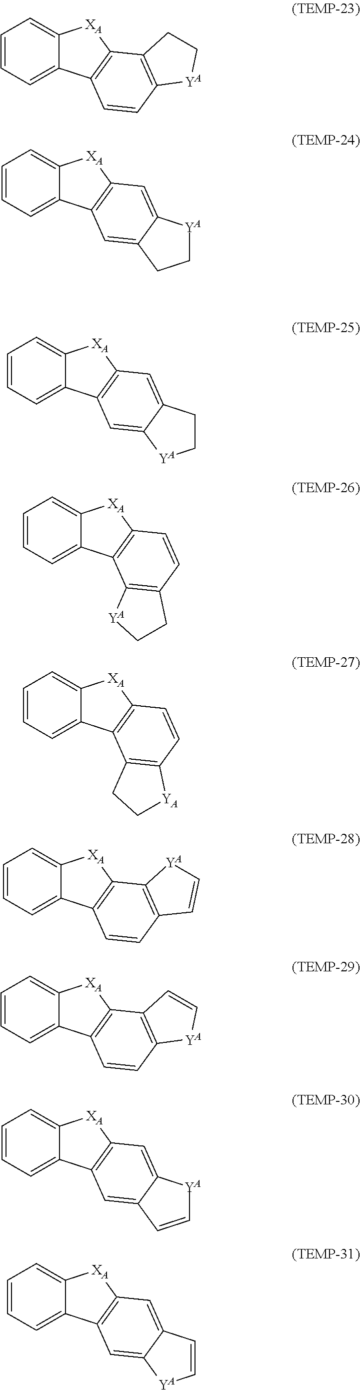

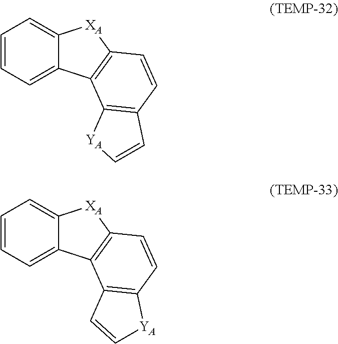

In the general formulas (TEMP-16) to (TEMP-33), X_{A} and Y_{A} are independently an oxygen atom, a sulfur atom, NH, or CH₂. Provided that at least one of X_{A} and Y_{A} is an oxygen atom, a sulfur atom, or NH.

In the general formulas (TEMP-16) to (TEMP-33), when at least one of X_{A} and Y_{A} is NH or CH₂, the monovalent heterocyclic group derived from the ring structures represented by each of the general formulas (TEMP-16) to (TEMP-33) includes a monovalent group derived by removing one hydrogen atom from these NH or CH₂.

### Substituted Heterocyclic Group Containing a Nitrogen Atom (Specific Example Group G2B1):

a (9-phenyl)carbazolyl group,
a (9-biphenylyl)carbazolyl group,
a (9-phenyl)phenylcarbazolyl group,
a (9-naphthyl)carbazolyl group,
a diphenylcarbazol-9-yl group,
a phenylcarbazol-9-yl group,
a methylbenzimidazolyl group,
an ethylbenzimidazolyl group,
a phenyltriazinyl group,
a biphenylyltriazinyl group,
a diphenyltriazinyl group,
a phenylquinazolinyl group, and
a biphenylylquinazolinyl group.

### Substituted Heterocyclic Group Containing an Oxygen Atom (Specific Example Group G2B2):

a phenyldibenzofuranyl group,
a methyldibenzofuranyl group,
a t-butyldibenzofuranyl group, and
a monovalent residue of spiro[9H-xanthene-9,9′-[9H]fluorene].

### Substituted Heterocyclic Group Containing a Sulfur Atom (Specific Example Group G2B3):

a phenyldibenzothiophenyl group,
a methyldibenzothiophenyl group,
a t-butyldibenzothiophenyl group, and
a monovalent residue of spiro[9H-thioxanthene-9,9′-[9H]fluorene].
   Group in which One or More Hydrogen Atoms of the Monovalent Heterocyclic Group Derived from the Ring Structures Represented by Each of the Following General Formulas (TEMP-16) to (TEMP-33) are Substituted by a Substituent (Specific Example Group G2B4):

The “one or more hydrogen atoms of the monovalent heterocyclic group” means one or more hydrogen atoms selected from hydrogen atoms bonded with ring carbon atoms of the monovalent heterocyclic group, a hydrogen atom bonded with a nitrogen atom when at least one of X_{A} and Y_{A} is NH, and hydrogen atoms of a methylene group when one of X_{A} and Y_{A} is CH₂.

### “Substituted or Unsubstituted Alkyl Group”

Specific examples of the “substituted or unsubstituted alkyl group” (specific example group G3) described in this specification include the following unsubstituted alkyl groups (specific example group G3A) and the following substituted alkyl groups (specific example group G3B). (Here, the unsubstituted alkyl group refers to the case where the “substituted or unsubstituted alkyl group” is an “alkyl group unsubstituted by a substituent”, and the substituted alkyl group refers to the case where the “substituted or unsubstituted alkyl group“is an” alkyl group substituted by a substituent”.). In this specification, in the case where simply referred as an “alkyl group” includes both the “unsubstituted alkyl group” and the “substituted alkyl group.”

The “substituted alkyl group” means a group in which one or more hydrogen atoms in the “unsubstituted alkyl group” are substituted by a substituent. Specific examples of the “substituted alkyl group” include groups in which one or more hydrogen atoms in the following “unsubstituted alkyl group” (specific example group G3A) are substituted by a substituent, the following substituted alkyl group (specific example group G3B), and the like. In this specification, the alkyl group in the “unsubstituted alkyl group” means a linear alkyl group. Thus, the “unsubstituted alkyl group” includes a straight-chain “unsubstituted alkyl group” and a branched-chain “unsubstituted alkyl group”. It should be noted that the examples of the “unsubstituted alkyl group” and the examples of the “substituted alkyl group” enumerated in this specification are mere examples, and the “substituted alkyl group” described in this specification includes a group in which hydrogen atom of the alkyl group itself in the “substituted alkyl group” of the specific example group G3B is further substituted by a substituent, and a group in which hydrogen atom of a substituent in the “substituted alkyl group” of the specific example group G3B is further substituted by a substituent.

### Unsubstituted Alkyl Group (Specific Example Group G3A):

a methyl group,
an ethyl group,
a n-propyl group,
an isopropyl group,
a n-butyl group,
an isobutyl group,
a s-butyl group, and
a t-butyl group.

### Substituted Alkyl Group (Specific Example Group G3B):

a heptafluoropropyl group (including isomers),
a pentafluoroethyl group,
a 2,2,2-trifluoroethyl group, and
a trifluoromethyl group.

### “Substituted or Unsubstituted Alkenyl Group”

Specific examples of the “substituted or unsubstituted alkenyl group” described in this specification (specific example group G4) include the following unsubstituted alkenyl group (specific example group G4A), the following substituted alkenyl group (specific example group G4B), and the like. (Here, the unsubstituted alkenyl group refers to the case where the “substituted or unsubstituted alkenyl group“is a” alkenyl group unsubstituted by a substituent”, and the “substituted alkenyl group” refers to the case where the “substituted or unsubstituted alkenyl group” is a “alkenyl group substituted by a substituent.”). In this specification, in the case where simply referred as an “alkenyl group” includes both the “unsubstituted alkenyl group” and the “substituted alkenyl group.”

The “substituted alkenyl group” means a group in which one or more hydrogen atoms in the “unsubstituted alkenyl group” are substituted by a substituent. Specific examples of the “substituted alkenyl group” include a group in which the following “unsubstituted alkenyl group” (specific example group G4A) has a substituent, the following substituted alkenyl group (specific example group G4B), and the like. It should be noted that the examples of the “unsubstituted alkenyl group” and the examples of the “substituted alkenyl group” enumerated in this specification are mere examples, and the “substituted alkenyl group” described in this specification includes a group in which a hydrogen atom of the alkenyl group itself in the “substituted alkenyl group” of the specific example group G4B is further substituted by a substituent, and a group in which a hydrogen atom of a substituent in the “substituted alkenyl group” of the specific example group G4B is further substituted by a substituent.

### Unsubstituted Alkenyl Group (Specific Example Group G4A):

a vinyl group,
an allyl group,
a 1-butenyl group,
a 2-butenyl group, and
a 3-butenyl group.

### Substituted Alkenyl Group (Specific Example Group G4B):

a 1,3-butanedienyl group,
a 1-methylvinyl group,
a 1-methylallyl group,
a 1,1-dimethylallyl group,
a 2-methylally group, and
a 1,2-dimethylallyl group.

### “Substituted or Unsubstituted Alkynyl Group”

Specific examples of the “substituted or unsubstituted alkynyl group” described in this specification (specific example group G5) include the following unsubstituted alkynyl group (specific example group G5A) and the like. (Here, the unsubstituted alkynyl group refers to the case where the “substituted or unsubstituted alkynyl group” is an “alkynyl group unsubstituted by a substituent”.). In this specification, in the case where simply referred as an “alkynyl group” includes both the “unsubstituted alkynyl group” and the “substituted alkynyl group.”

The “substituted alkynyl group” means a group in which one or more hydrogen atoms in the “unsubstituted alkynyl group” are substituted by a substituent. Specific examples of the “substituted alkynyl group” include a group in which one or more hydrogen atoms in the following “unsubstituted alkynyl group” (specific example group G5A) are substituted by a substituent, and the like.

### Unsubstituted Alkynyl Group (Specific Example Group G5A):

an ethynyl group.

### “Substituted or Unsubstituted Cycloalkyl Group”

Specific examples of the “substituted or unsubstituted cycloalkyl group” described in this specification (specific example group G6) include the following unsubstituted cycloalkyl group (specific example group G6A), the following substituted cycloalkyl group (specific example group G6B), and the like. (Here, the unsubstituted cycloalkyl group refers to the case where the “substituted or unsubstituted cycloalkyl group“is a” cycloalkyl group unsubstituted by a substituent”, and the substituted cycloalkyl group refers to the case where the “substituted or unsubstituted cycloalkyl group” is a “cycloalkyl group substituted by a substituent”.). In this specification, in the case where simply referred as a “cycloalkyl group” includes both the “unsubstituted cycloalkyl group” and the “substituted cycloalkyl group.”

The “substituted cycloalkyl group” means a group in which one or more hydrogen atoms in the “unsubstituted cycloalkyl group” are substituted by a substituent. Specific examples of the “substituted cycloalkyl group” include a group in which one or more hydrogen atoms in the following “unsubstituted cycloalkyl group” (specific example group G6A) are substituted by a substituent, and examples of the following substituted cycloalkyl group (specific example group G6B), and the like. It should be noted that the examples of the “unsubstituted cycloalkyl group” and the examples of the “substituted cycloalkyl group” enumerated in this specification are mere examples, and the “substituted cycloalkyl group” in this specification includes a group in which one or more hydrogen atoms bonded with the carbon atom of the cycloalkyl group itself in the “substituted cycloalkyl group” of the specific example group G6B are substituted by a substituent, and a group in which a hydrogen atom of a substituent in the “substituted cycloalkyl group” of specific example group G6B is further substituted by a substituent.

### Unsubstituted Cycloalkyl Group (Specific Example Group G6A):

a cyclopropyl group,
a cyclobutyl group,
a cyclopentyl group,
a cyclohexyl group,
a 1-adamantyl group,
a 2-adamantyl group,
a 1-norbornyl group, and
a 2-norbornyl group.

### Substituted Cycloalkyl Group (Specific Example Group G6B):

a 4-methylcyclohexyl group.
   “Group Represented by —Si (R₉₀₁)(R₉₀₂)(R₉₀₃)”

Specific examples of the group represented by —Si(R₉₀₁)(R₉₀₂)(R₉₀₃) described in this specification (specific example group G7) include:
—Si(G1)(G1)(G1),
—Si(G1)(G2)(G2),
—Si(G1)(G1)(G2),
—Si(G2)(G2)(G2),
—Si(G3)(G3)(G3), and
—Si(G6)(G6)(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

Plural G1's in —Si(G1)(G1)(G1) are the same or different.

Plural G2's in —Si(G1)(G2)(G2) are the same or different.

Plural G1's in —Si(G1)(G1)(G2) are the same or different.

Plural G2's in —Si(G2)(G2)(G2) are be the same or different.

Plural G3's in —Si(G3)(G3)(G3) are the same or different.

Plural G6's in —Si(G6)(G6)(G6) are be the same or different.

### “Group Represented by —O—(R₉₀₄)”

Specific examples of the group represented by —O—(R₉₀₄) in this specification (specific example group G8) include:

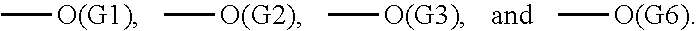

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

### “Group Represented by —S—(R₉₀₅)”

Specific examples of the group represented by —S—(R₉₀₅) in this specification (specific example group G9) include:

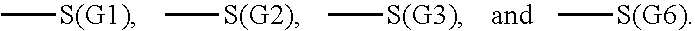

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

“Group Represented by —N(R₉₀₆)(R₉₀₇)”

Specific examples of the group represented by —N(R₉₀₆)(R₉₀₇) in this specification (specific example group G10) include:

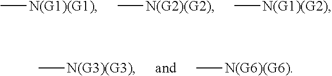

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

Plural G1's in —N(G1)(G1) are the same or different.

Plural G2's in —N(G2)(G2) are the same or different.

Plural G3's in —N(G3)(G3) are the same or different.

Plural G6's in —N(G6)(G6) are the same or different.

### “Halogen Atom”

Specific examples of the “halogen atom” described in this specification (specific example group G11) include a fluorine atom, a chlorine atom, a bromine atom, an iodine atom, and the like.

### “Substituted or Unsubstituted Fluoroalkyl Group”

The “substituted or unsubstituted fluoroalkyl group” described in this specification is a group in which at least one hydrogen atom bonded with a carbon atom constituting the alkyl group in the “substituted or unsubstituted alkyl group” is substituted by a fluorine atom, and includes a group in which all hydrogen atoms bonded with a carbon atom constituting the alkyl group in the “substituted or unsubstituted alkyl group” are substituted by a fluorine atom (a perfluoro group). The number of carbon atoms of the “unsubstituted fluoroalkyl group” is 1 to 50, preferably 1 to 30, more preferably 1 to 18, unless otherwise specified in this specification. The “substituted fluoroalkyl group” means a group in which one or more hydrogen atoms of the “fluoroalkyl group” are substituted by a substituent. The “substituted fluoroalkyl group” described in this specification also includes a group in which one or more hydrogen atoms bonded with a carbon atom of the alkyl chains in the “substituted fluoroalkyl group” are further substituted by a substituent, and a group in which one or more hydrogen atom of a substituent in the “substituted fluoroalkyl group” are further substituted by a substituent. Specific examples of the “unsubstituted fluoroalkyl group” include a group in which one or more hydrogen atoms in the “alkyl group” (specific group G3) are substituted by a fluorine atom, and the like.

### “Substituted or Unsubstituted Haloalkyl Group”

The “substituted or unsubstituted haloalkyl group” described in this specification is a group in which at least one hydrogen atom bonded with a carbon atom constituting the alkyl group in the “substituted or unsubstituted alkyl group” is substituted by a halogen atom, and also includes a group in which all hydrogen atoms bonded with a carbon atom constituting the alkyl group in the “substituted or unsubstituted alkyl group” are substituted by a halogen atom. The number of carbon atoms of the “unsubstituted haloalkyl group” is 1 to 50, preferably 1 to 30, more preferably 1 to 18, unless otherwise specified in this specification. The “substituted haloalkyl group” means a group in which one or more hydrogen atoms of the “haloalkyl group” are substituted by a substituent. The “substituted haloalkyl group” described in this specification also includes a group in which one or more hydrogen atoms bonded with a carbon atom of the alkyl chain in the “substituted haloalkyl group” are further substituted by a substituent, and a group in which one or more hydrogen atoms of a substituent in the “substituted haloalkyl group” are further substituted by a substituent. Specific examples of the “unsubstituted haloalkyl group” include a group in which one or more hydrogen atoms in the “alkyl group” (specific example group G3) are substituted by a halogen atom, and the like. A haloalkyl group is sometimes referred to as an alkyl halide group.

### “Substituted or Unsubstituted Alkoxy Group”

Specific examples of the “substituted or unsubstituted alkoxy group” described in this specification include a group represented by —O(G3), wherein G3 is the “substituted or unsubstituted alkyl group” described in the specific example group G3. The number of carbon atoms of the “unsubstituted alkoxy group” is 1 to 50, preferably 1 to 30, more preferably 1 to 18, unless otherwise specified in this specification.

### “Substituted or Unsubstituted Alkylthio Group”

Specific examples of the “substituted or unsubstituted alkylthio group” described in this specification include a group represented by —S(G3), wherein G3 is the “substituted or unsubstituted alkyl group” described in the specific example group G3. The number of carbon atoms of the “unsubstituted alkylthio group” is 1 to 50, preferably 1 to 30, more preferably 1 to 18, unless otherwise specified in this specification.

### “Substituted or Unsubstituted Aryloxy Group”

Specific examples of the “substituted or unsubstituted aryloxy group” described in this specification include a group represented by —O(G1), wherein G1 is the “substituted or unsubstituted aryl group” described in the specific example group G1. The number of ring carbon atoms of the “unsubstituted aryloxy group” is 6 to 50, preferably 6 to 30, more preferably 6 to 18, unless otherwise specified in this specification.

### “Substituted or Unsubstituted Arylthio Group”

Specific examples of the “substituted or unsubstituted arylthio group” described in this specification include a group represented by —S(G1), wherein G1 is a “substituted or unsubstituted aryl group” described in the specific example group G1. The number of ring carbon atoms of the “unsubstituted arylthio group” is 6 to 50, preferably 6 to 30, more preferably 6 to 18, unless otherwise specified in this specification.

### “Substituted or Unsubstituted Trialkylsilyl Group”

Specific examples of the “trialkylsilyl group” described in this specification include a group represented by —Si(G3)(G3)(G3), where G3 is the “substituted or unsubstituted alkyl group” described in the specific example group G3. Plural G3's in —Si(G3)(G3)(G3) are the same or different. The number of carbon atoms in each alkyl group of the “trialkylsilyl group” is 1 to 50, preferably 1 to 20, more preferably 1 to 6, unless otherwise specified in this specification.

### “Substituted or Unsubstituted Aralkyl Group”

Specific examples of the “substituted or unsubstituted aralkyl group” described in this specification is a group represented by -(G3)-(G1), wherein G3 is the “substituted or unsubstituted alkyl group” described in the specific example group G3, and G1 is the “substituted or unsubstituted aryl group” described in the specific example group G1. Therefore, the “aralkyl group” is a group in which a hydrogen atom of the “alkyl group” is substituted by an “aryl group” as a substituent, and is one form of the “substituted alkyl group.” The “unsubstituted aralkyl group” is the “unsubstituted alkyl group” substituted by the “unsubstituted aryl group”, and the number of carbon atoms of the “unsubstituted aralkyl group” is 7 to 50, preferably 7 to 30, more preferably 7 to 18, unless otherwise specified in this specification.

Specific examples of the “substituted or unsubstituted aralkyl group” include a benzyl group, a 1-phenylethyl group, a 2-phenylethyl group, a 1-phenylisopropyl group, a 2-phenylisopropyl group, a phenyl-t-butyl group, an a-naphthylmethyl group, a 1-α-naphthylethyl group, a 2-α-naphthylethyl group, a 1-α-naphthylisopropyl group, a 2-α-naphthylisopropyl group, a β-naphthylmethyl group, a 1-β-naphthylethyl group, a 2-β-naphthylethyl group, a 1-β-naphthylisopropyl group, a 2-β-naphthylisopropyl group, and the like.

Unless otherwise specified in this specification, examples of the substituted or unsubstituted aryl group described in this specification preferably include a phenyl group, a p-biphenyl group, a m-biphenyl group, an o-biphenyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-terphenyl-4-yl group, an o-terphenyl-3-yl group, an o-terphenyl-2-yl group, a 1-naphthyl group, a 2-naphthyl group, an anthryl group, a phenanthryl group, a pyrenyl group, a chrysenyl group, a triphenylenyl group, a fluorenyl group, a 9,9′-spirobifluorenyl group, 9,9-dimethylfluorenyl group, 9,9-diphenylfluorenyl group, and the like.

Unless otherwise specified in this specification, examples of the substituted or unsubstituted heterocyclic groups described in this specification preferably include a pyridyl group, a pyrimidinyl group, a triazinyl group, a quinolyl group, an isoquinolyl group, a quinazolinyl group, a benzimidazolyl group, a phenanthrolinyl group, a carbazolyl group (a 1-carbazolyl group, a 2-carbazolyl group, a 3-carbazolyl group, a 4-carbazolyl group, or a 9-carbazolyl group), a benzocarbazolyl group, an azacarbazolyl group, a diazacarbazolyl group, a dibenzofuranyl group, a naphthobenzofuranyl group, an azadibenzofuranyl group, a diazadibenzofuranyl group, a dibenzothiophenyl group, a naphthobenzothiophenyl group, an azadibenzothiophenyl group, a diazadibenzothiophenyl group, a (9-phenyl)carbazolyl group (a (9-phenyl)carbazol-1-yl group, a (9-phenyl)carbazol-2-yl group, a (9-phenyl)carbazol-3-yl group, or a (9-phenyl)carbazol-4-yl group), a (9-biphenylyl)carbazolyl group, a (9-phenyl)phenylcarbazolyl group, a diphenylcarbazol-9-yl group, a phenylcarbazol-9-yl group, a phenyltriazinyl group, a biphenylyltriazinyl group, a diphenyltriazinyl group, a phenyldibenzofuranyl group, a phenyldibenzothiophenyl group, and the like.

In this specification, the carbazolyl group is specifically each of the following groups, unless otherwise specified in this specification.

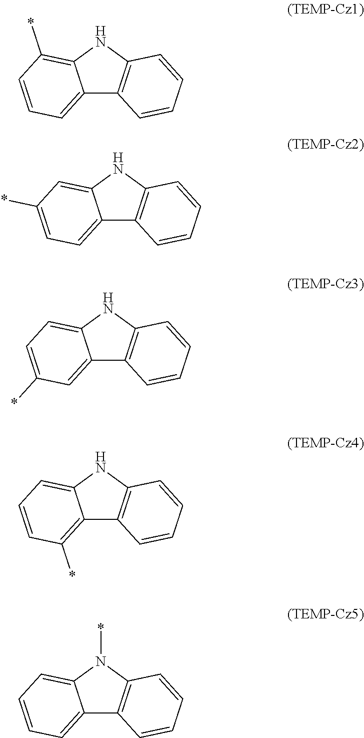 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

In this specification, the (9-phenyl)carbazolyl group is specifically any of the following groups, unless otherwise specified in this specification.

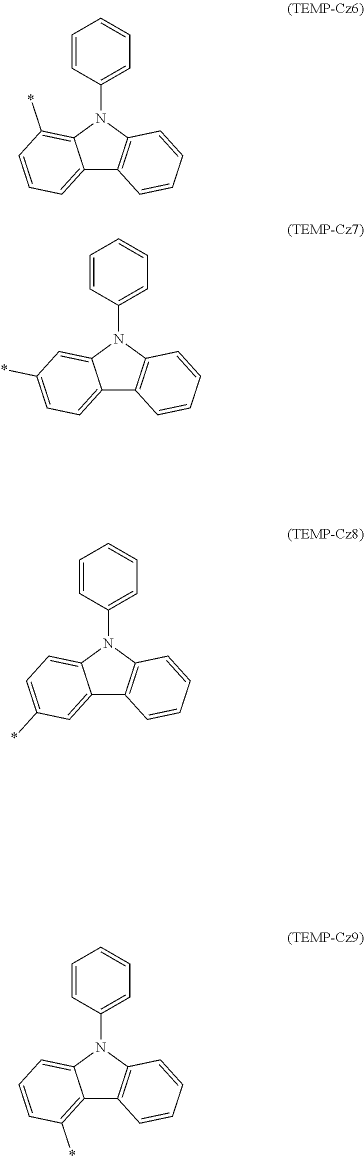 [SMILES: *c1cccc2c3ccccc3n(-c3ccccc3)c12 ; *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1]

In the general formulas (TEMP-Cz1) to (TEMP-Cz9), * represents a bonding site.

In this specification, the dibenzofuranyl group and the dibenzothiophenyl group are specifically any of the following groups, unless otherwise specified in this specification.

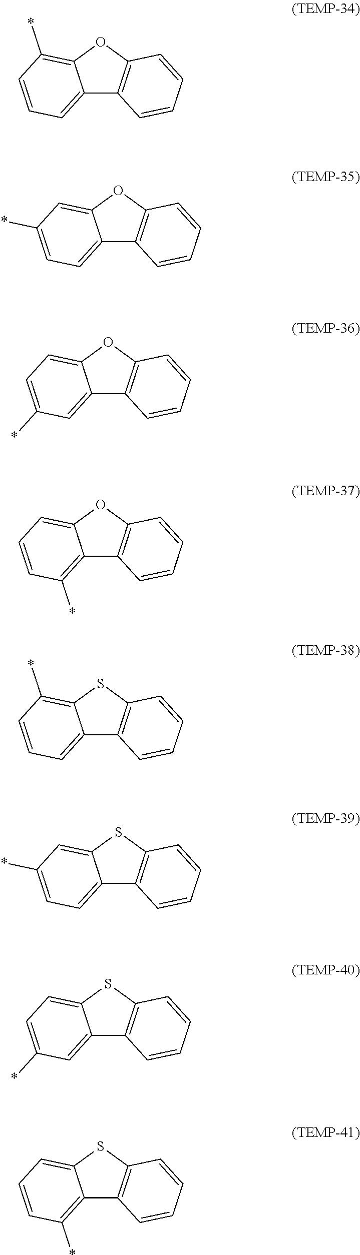

In the general formulas (TEMP-34) to (TEMP-41), * represents a bonding site.

The substituted or unsubstituted alkyl group described in this specification is preferably a methyl group, an ethyl group, a propyl group, an isopropyl group, a n-butyl group, an isobutyl group, a t-butyl group, or the like, unless otherwise specified in this specification.

### “Substituted or Unsubstituted Arylene Group”

The “substituted or unsubstituted arylene group” described in this specification is a divalent group derived by removing one hydrogen atom on the aryl ring of the “substituted or unsubstituted aryl group”, unless otherwise specified. Specific examples of the “substituted or unsubstituted arylene group” (specific example group G12) include a divalent group derived by removing one hydrogen atom on the aryl ring of the “substituted or unsubstituted aryl group” described in the specific example group G1, and the like.

### “Substituted or Unsubstituted Divalent Heterocyclic Group”

The “substituted or unsubstituted divalent heterocyclic group” described in this specification is a divalent group derived by removing one hydrogen atom on the heterocycle of the “substituted or unsubstituted heterocyclic group”, unless otherwise specified. Specific examples of the “substituted or unsubstituted divalent heterocyclic group” (specific example group G13) include a divalent group derived by removing one hydrogen atom on the heterocycle of the “substituted or unsubstituted heterocyclic group” described in the specific example group G2, and the like.

### “Substituted or Unsubstituted Alkylene Group”

The “substituted or unsubstituted alkylene group” described in this specification is a divalent group derived by removing one hydrogen atom on the alkyl chain of the “substituted or unsubstituted alkyl group”, unless otherwise specified. Specific examples of the “substituted or unsubstituted alkylene group” (specific example group G14) include a divalent group derived by removing one hydrogen atom on the alkyl chain of the “substituted or unsubstituted alkyl group” described in the specific example group G3, and the like.

The substituted or unsubstituted arylene group described in this specification is preferably any group of the following general formulas (TEMP-42) to (TEMP-68), unless otherwise specified in this specification.

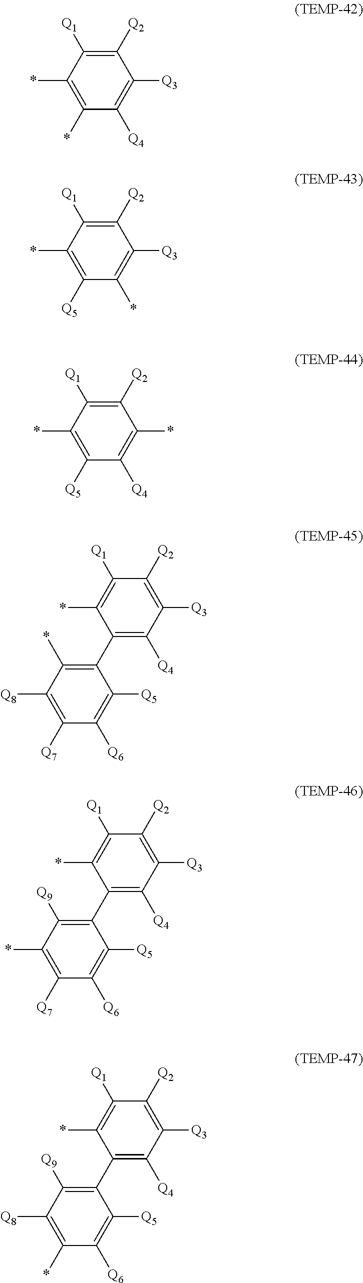

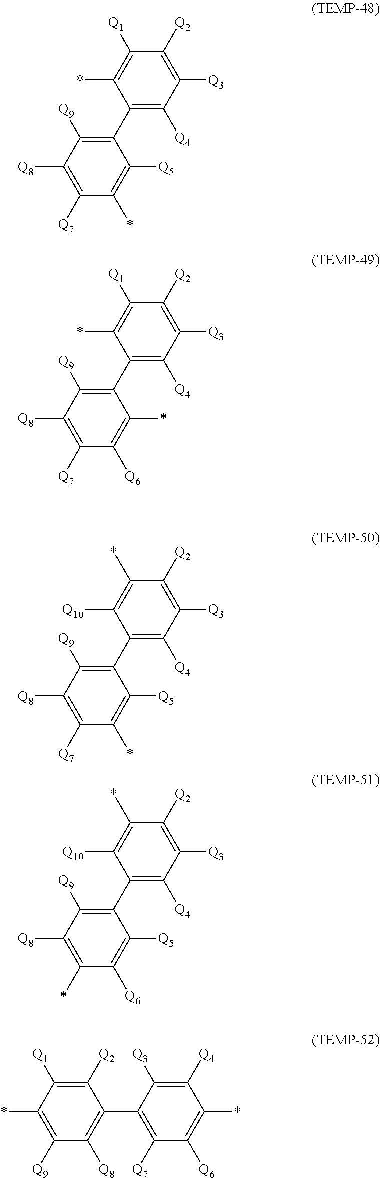

In the general formulas (TEMP-42) to (TEMP-52), Q₁ to Q₁₀ are independently a hydrogen atom or a substituent.

In the general formulas (TEMP-42) to (TEMP-52), * represents a bonding site.

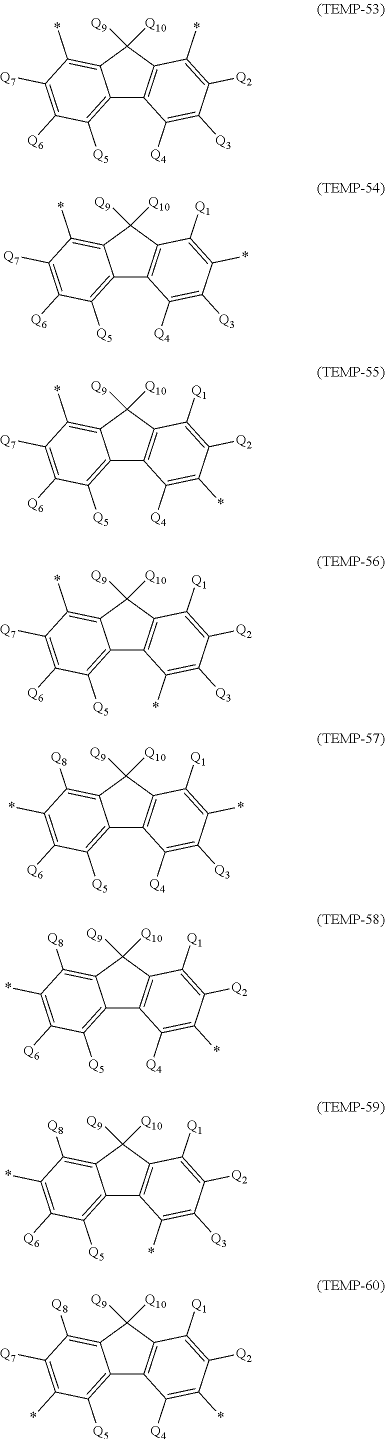

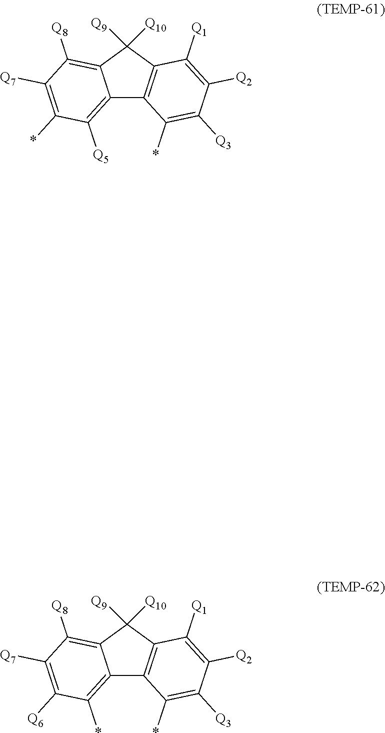

In the general formulas (TEMP-53) to (TEMP-62), Q₁ to Q₁₀ are independently a hydrogen atom or a substituent.

Q₉ and Q₁₀ may be bonded with each other via a single bond to form a ring.

In the general formulas (TEMP-53) to (TEMP-62), * represents a bonding site.

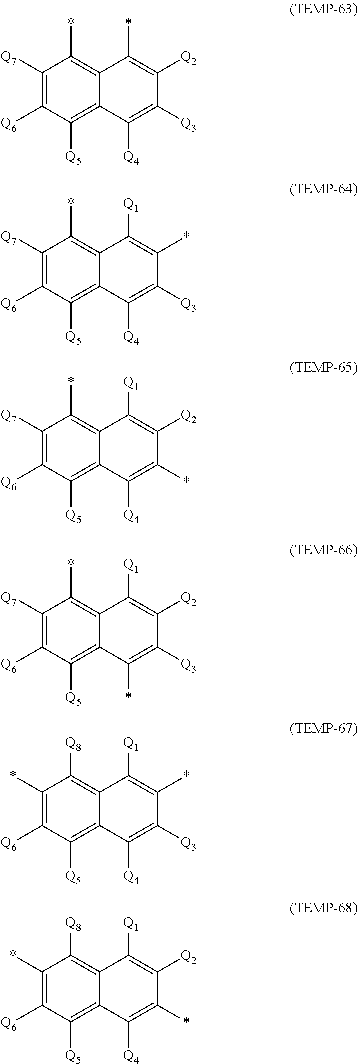

In the general formulas (TEMP-63) to (TEMP-68), Q₁ to Q₈ are independently a hydrogen atom or a substituent.

In the general formulas (TEMP-63) to (TEMP-68), * represents a bonding site.

The substituted or unsubstituted divalent heterocyclic group described in this specification is preferably any group of the following general formulas (TEMP-69) to (TEMP-102), unless otherwise specified in this specification.

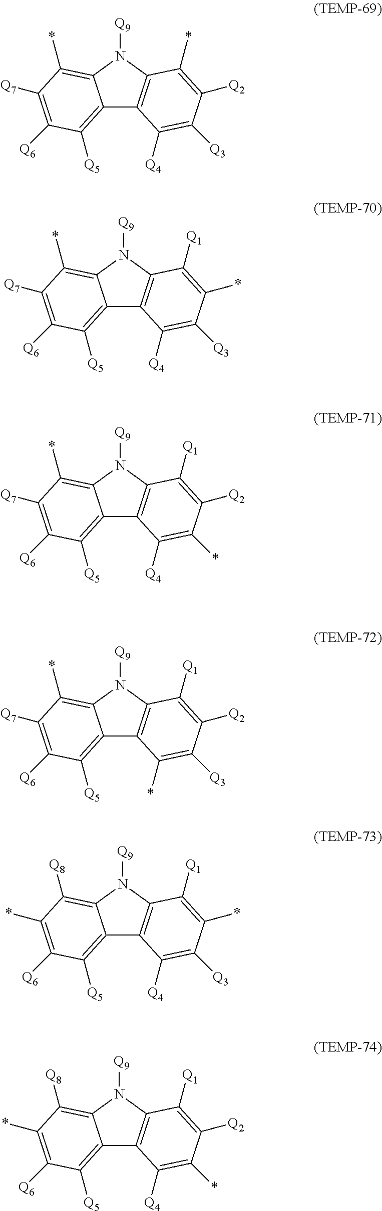

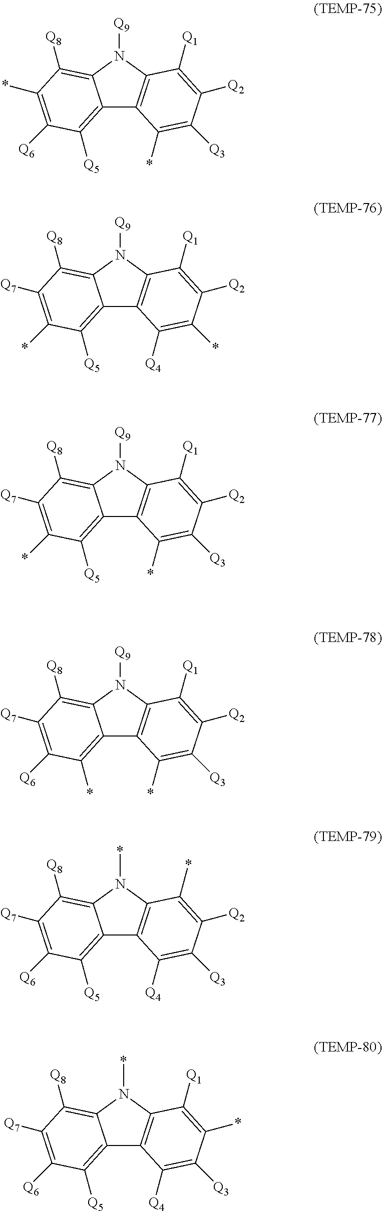

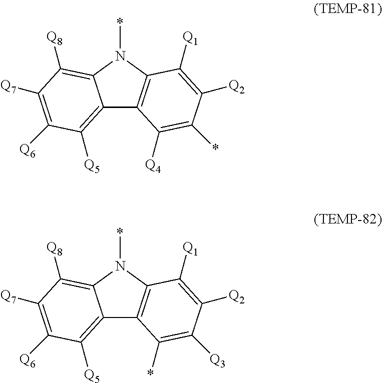

In the general formulas (TEMP-69) to (TEMP-82), Q₁ to Q₉ are independently a hydrogen atom or a substituent.

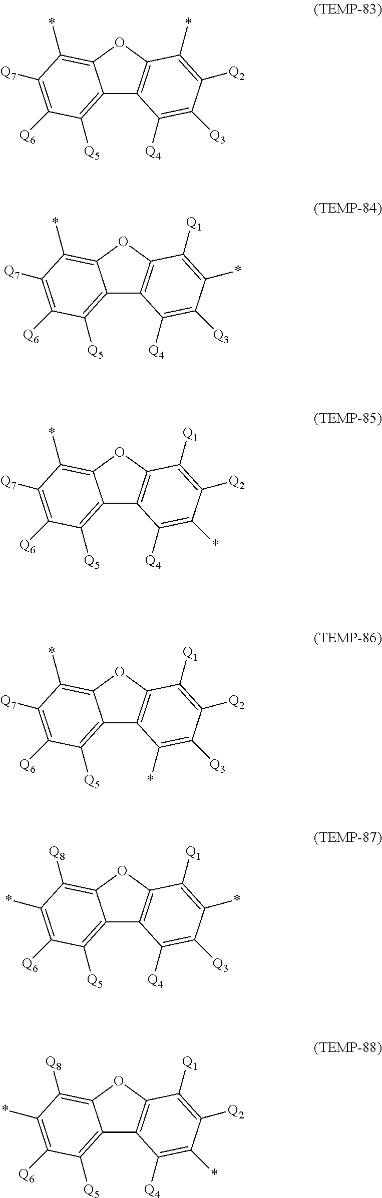

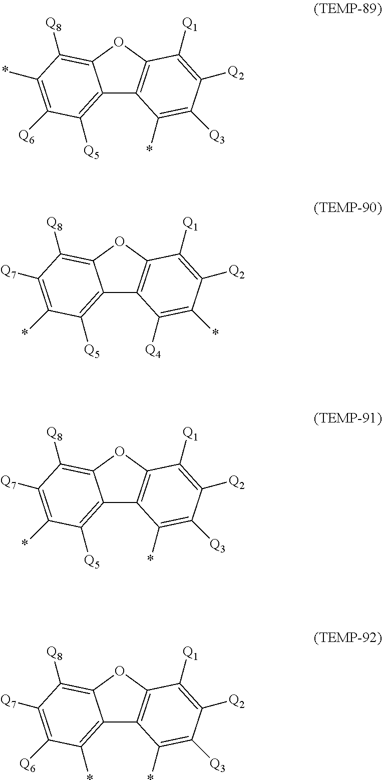

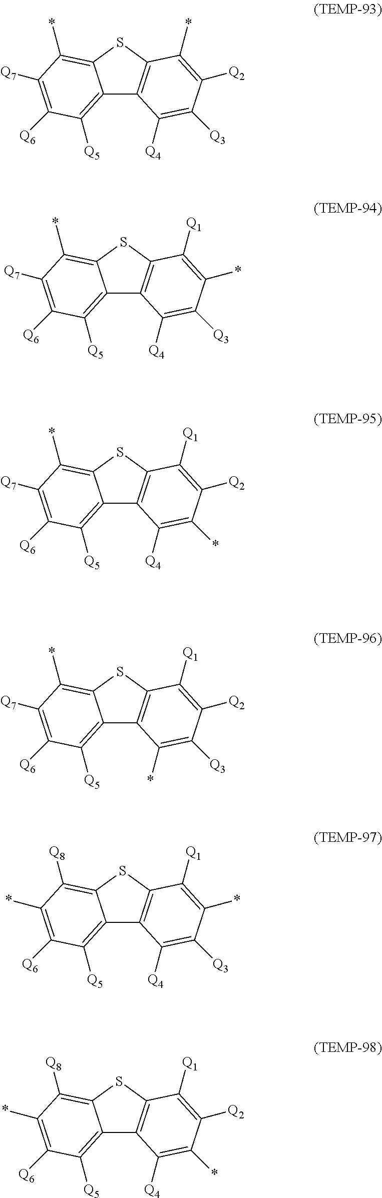

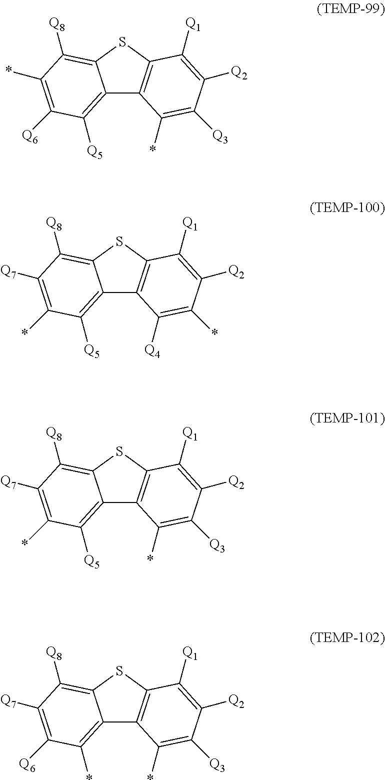

In the general formulas (TEMP-83) to (TEMP-102), Q₁ to Q₈ are independently a hydrogen atom or a substituent.

The above is the explanation of the “Substituent described in this specification.”

“the Case where Bonded with Each Other to Form a Ring”

In this specification, the case where “one or more sets of adjacent two or more form a substituted or unsubstituted monocycle by bonding with each other, form a substituted or unsubstituted fused ring by bonding with each other, or do not bond with each other” means the case where “one or more sets of adjacent two or more form a substituted or unsubstituted monocycle by bonding with each other”; the case where “one or more sets of adjacent two or more form a substituted or unsubstituted fused ring by bonding with each other”; and the case where “one or more sets of adjacent two or more do not bond with each other.”

The case where “one or more sets of adjacent two or more form a substituted or unsubstituted monocycle by bonding with each other” and the case where “one or more sets of adjacent two or more form a substituted or unsubstituted fused ring by bonding with each other” in this specification (these cases may be collectively referred to as “the case where forming a ring by bonding with each other”) will be described below. The case of an anthracene compound represented by the following general formula (TEMP-103) in which the mother skeleton is an anthracene ring will be described as an example.

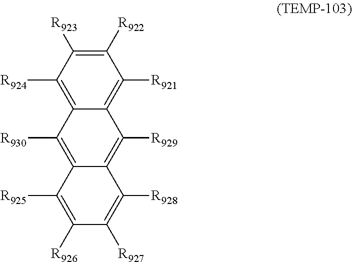

For example, in the case where “one or more sets of adjacent two or more among R₉₂₁ to R₉₃₀ form a ring by bonding with each other”, the one set of adjacent two includes a pair of R₉₂₁ and R₉₂₂, a pair of R₉₂₂ and R₉₂₃, a pair of R₉₂₃ and R₉₂₄, a pair of R₉₂₄ and R₉₃₀, a pair of R₉₃₀ and R₉₂₅, a pair of R₉₂₅ and R₉₂₆, a pair of R₉₂₆ and R₉₂₇, a pair of R₉₂₇ and R₉₂₈, a pair of R₉₂₈ and R₉₂₉, and a pair of R₉₂₉ and R₉₂₁.

The “one or more sets” means that two or more sets of the adjacent two or more sets may form a ring at the same time. For example, R₉₂₁ and R₉₂₂ form a ring Q_{A} by bonding with each other, and at the same, time R₉₂₅ and R₉₂₆ form a ring Q_{B} by bonding with each other, the anthracene compound represented by the general formula (TEMP-103) is represented by the following general formula (TEMP-104).

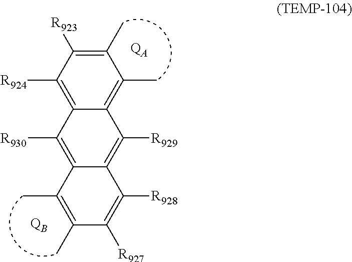

The case where the “set of adjacent two or more” form a ring includes not only the case where the set (pair) of adjacent “two” is bonded with as in the above-mentioned examples, but also the case where the set of adjacent “three or more” are bonded with each other. For example, it means the case where R₉₂₁ and R₉₂₂ form a ring Q_{A} by bonding with each other, and R₉₂₂ and R₉₂₃ form a ring Q_{C} by bonding with each other, and adjacent three (R₉₂₁, R₉₂₂ and R₉₂₃) form rings by bonding with each other and together fused to the anthracene mother skeleton. In this case, the anthracene compound represented by the general formula (TEMP-103) is represented by the following general formula (TEMP-105). In the following general formula (TEMP-105), the ring Q_{A} and the ring Q_{C} share R₉₂₂.

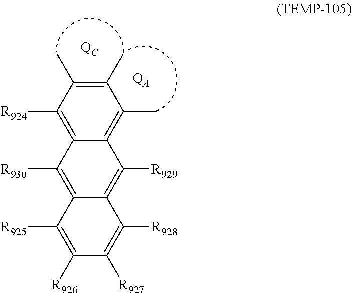

The “monocycle” or “fused ring” formed may be a saturated ring or an unsaturated ring, as a structure of the formed ring alone. Even when the “one pair of adjacent two” forms a “monocycle” or a “fused ring”, the “monocycle” or the “fused ring” may form a saturated ring or an unsaturated ring. For example, the ring Q_{A} and the ring Q_{B} formed in the general formula (TEMP-104) are independently a “monocycle” or a “fused ring.” The ring Q_{A} and the ring Q_{C} formed in the general formula (TEMP-105) are “fused ring.” The ring Q_{A} and ring Q_{C} of the general formula (TEMP-105) are fused ring by fusing the ring Q_{A} and the ring Q_{C} together. When the ring Q_{A} of the general formula (TMEP-104) is a benzene ring, the ring Q_{A} is a monocycle. When the ring Q_{A} of the general formula (TMEP-104) is a naphthalene ring, the ring Q_{A} is a fused ring.

The “unsaturated ring” includes, in addition to an aromatic hydrocarbon ring and an aromatic heterocycle, an aliphatic hydrocarbon ring with an unsaturated bond, i.e., double and/or triple bonds in the ring structure (e.g., cyclohexene, cyclohexadiene, etc.), and a non-aromatic heterocycle with an unsaturated bond (e.g., dihydropyran, imidazoline, pyrazoline, quinolizine, indoline, isoindoline, etc.). The “saturated ring” includes an aliphatic hydrocarbon ring without an unsaturated bond and a non-aromatic heterocycle without ab unsaturated bond.

Specific examples of the aromatic hydrocarbon ring include a structure in which the group listed as a specific example in the specific example group G1 is terminated by a hydrogen atom.

Specific examples of the aromatic heterocycle include a structure in which the aromatic heterocyclic group listed as a specific example in the example group G2 is terminated by a hydrogen atom.

Specific examples of the aliphatic hydrocarbon ring include a structure in which the group listed as a specific example in the specific example group G6 is terminated by a hydrogen atom.

The term “to form a ring” means forming a ring only with plural atoms of the mother skeleton, or with plural atoms of the mother skeleton and one or more arbitrary atoms in addition. For example, the ring Q_{A} shown in the general formula (TEMP-104), which is formed by bonding R₉₂₁ and R₉₂₂ with each other, is a ring formed from the carbon atom of the anthracene skeleton with which R₉₂₁ is bonded, the carbon atom of the anthracene skeleton with which R₉₂₂ is bonded, and one or more arbitrary atoms. For example, in the case where the ring Q_{A} is formed with R₉₂₁ and R₉₂₂, when a monocyclic unsaturated ring is formed with the carbon atom of the anthracene skeleton with which R₉₂₁ is bonded, the carbon atom of the anthracene skeleton with which R₉₂₂ is bonded, and four carbon atoms, the ring formed with R₉₂₁ and R₉₂₂ is a benzene ring.

Here, the “arbitrary atom” is preferably at least one atom selected from the group consisting of a carbon atom, a nitrogen atom, an oxygen atom, and a sulfur atom, unless otherwise specified in this specification. In the arbitrary atom (for example, a carbon atom or a nitrogen atom), a bond which does not form a ring may be terminated with a hydrogen atom or the like, or may be substituted with “arbitrary substituent” described below. When an arbitrary atom other than a carbon atom is contained, the ring formed is a heterocycle.

The number of “one or more arbitrary atom(s)” constituting a monocycle or a fused ring is preferably 2 or more and 15 or less, more preferably 3 or more and 12 or less, and still more preferably 3 or more and 5 or less, unless otherwise specified in this specification.

The “monocycle” is preferable among the “monocycle” and the “fused ring”, unless otherwise specified in this specification.

The “unsaturated ring” is preferable among the “saturated ring” and the “unsaturated ring”, unless otherwise specified in this specification.

Unless otherwise specified in this specification, the “monocycle” is preferably a benzene ring.

Unless otherwise specified in this specification, the “unsaturated ring” is preferably a benzene ring.

Unless otherwise specified in this specification, when “one or more sets of adjacent two or more” are “bonded with each other to form a substituted or unsubstituted monocycle” or “bonded with each other to form a substituted or unsubstituted fused ring”, this specification, one or more sets of adjacent two or more are preferably bonded with each other to form a substituted or unsubstituted “unsaturated ring” from plural atoms of the mother skeleton and one or more and 15 or less atoms which is at least one kind selected from a carbon atom, a nitrogen atom, an oxygen atom, and a sulfur atom.

The substituent in the case where the above-mentioned “monocycle” or “fused ring” has a substituent is, for example, an “arbitrary substituent” described below. Specific examples of the substituent which the above-mentioned “monocycle” or “fused ring” has include the substituent described above in the “Substituent described in this specification” section.

The substituent in the case where the above-mentioned “saturated ring” or “unsaturated ring” has a substituent is, for example, an “arbitrary substituent” described below. Specific examples of the substituent which the above-mentioned “monocycle” or “fused ring” has include the substituent described above in the “Substituent described in this specification” section.

The foregoing describes the case where “one or more sets of adjacent two or more form a substituted or unsubstituted monocycle by bonding with each other” and the case where “one or more sets of adjacent two or more form a substituted or unsubstituted fused ring by bonding with each other” (the case where “forming a ring by bonding with each other”).

### Substituent in the Case of “Substituted or Unsubstituted”

In one embodiment in this specification, the substituent (in this specification, sometimes referred to as an “arbitrary substituent”) in the case of “substituted or unsubstituted” is, for example, a group selected from the group consisting of:
an unsubstituted alkyl group including 1 to 50 carbon atoms,
an unsubstituted alkenyl group including 2 to 50 carbon atoms,
an unsubstituted alkynyl group including 2 to 50 carbon atoms,
an unsubstituted cycloalkyl group including 3 to 50 ring carbon atoms,

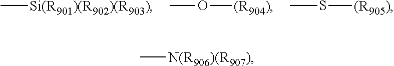

a halogen atom, a cyano group, a nitro group,
an unsubstituted aryl group including 6 to 50 ring carbon atoms, and
an unsubstituted heterocyclic group including 5 to 50 ring atoms,
wherein, R₉₀₁ to R₉₀₇ are independently
a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted heterocyclic group including 5 to 50 ring atoms.

When two or more R₉₀₁'s are present, the two or more R₉₀₁'s may be the same or different.

When two or more R₉₀₂'s are present, the two or more R₉₀₂'s may be the same or different.

When two or more R₉₀₃'s are present, the two or more R₉₀₃'s may be the same or different.

When two or more R₉₀₄'s are present, the two or more R₉₀₄'s may be the same or different.

When two or more R₉₀₅'s are present, the two or more R₉₀₅'s may be the same or different.

When two or more R₉₀₆'s are present, the two or more R₉₀₆'s may be the same or different.

When two or more R₉₀₇'s are present, the two or more R₉₀₇'s may be the same or different.

In one embodiment, the substituent in the case of “substituted or unsubstituted” is a group selected from the group consisting of:
an alkyl group including 1 to 50 carbon atoms,
an aryl group including 6 to 50 ring carbon atoms, and
a heterocyclic group including 5 to 50 ring atoms.

In one embodiment, the substituent in the case of “substituted or unsubstituted” is a group selected from the group consisting of:
an alkyl group including 1 to 18 carbon atoms,
an aryl group including 6 to 18 ring carbon atoms, and
a heterocyclic group including 5 to 18 ring atoms.

Specific examples of each of the arbitrary substituents include specific examples of substituent described in the section “Substituent described in this specification” above.

Unless otherwise specified in this specification, adjacent arbitrary substituents may form a “saturated ring” or an “unsaturated ring”, preferably form a substituted or unsubstituted saturated 5-membered ring, a substituted or unsubstituted saturated 6-membered ring, a substituted or unsubstituted unsaturated 5-membered ring, or a substituted or unsubstituted unsaturated 6-membered ring, more preferably form a benzene ring.

Unless otherwise specified in this specification, the arbitrary substituent may further have a substituent. The substituent which the arbitrary substituent further has is the same as that of the above-mentioned arbitrary substituent.

In this specification, the numerical range represented by “AA to BB” means the range including the numerical value AA described on the front side of “AA to BB” as the lower limit and the numerical value BB described on the rear side of “AA to BB” as the upper limit.

### [Organic EL Device]

An organic EL device according to an aspect of the present invention includes a cathode, an anode, and an emitting layer disposed between the cathode and the anode. The emitting layer includes a first emitting layer and a second emitting layer, and the first emitting layer contains one or more compounds selected from the group consisting of a compound represented by each of the formulas (1) to (4) described later.

The organic EL device of an aspect of the present invention can improve performance by having the above configuration. In particular, by using a predetermined compound for the first emitting layer, a recombination region can be localized more in the first emitting layer than in the related art, so that the efficiency of the device can be improved and the device lifetime can be improved.

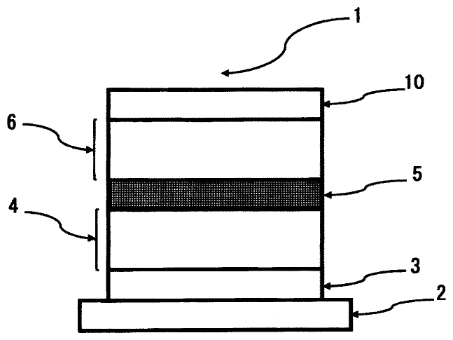

The schematic configuration of the organic EL device of an aspect of the present invention will be described with reference to FIG. 1.

The organic EL device 1 according to an aspect of the present invention includes a substrate 2, an anode 3, an emitting layer 5, a cathode 10, a hole-transporting zone 4 between the anode 3 and the emitting layer 5, and an electron-transporting zone 6 between the emitting layer 5 and the cathode 10.

The emitting layer 5 has a stacked structure, and it includes at least a first emitting layer and a second emitting layer.

A typical device configuration of the organic EL device of the present invention includes structures such as
(1) Anode/emitting layer/cathode,
(2) Anode/hole-injecting layer/emitting layer/cathode,
(3) Anode/emitting layer/electron-injecting/transporting layer/cathode,
(4) Anode/hole-injecting layer/emitting layer/electron-injecting/transporting layer/cathode,
(5) Anode/organic semiconductor layer/emitting layer/cathode,
(6) Anode/organic semiconductor layer/electron-blocking layer/emitting layer/cathode,
(7) Anode/organic semiconductor layer/emitting layer/adhesion-improving layer/cathode,
(8) Anode/hole-injecting/transporting layer/emitting layer/electron-injecting/transporting layer/cathode,
(9) Anode/insulating layer/emitting layer/insulating layer/cathode,
(10) Anode/inorganic semiconductor layer/insulating layer/emitting layer/insulating layer/cathode,
(11) Anode/organic semiconductor layer/insulating layer/emitting layer/insulating layer/cathode,
(12) Anode/insulating layer/hole-injecting/transporting layer/emitting layer/insulating layer/cathode, and
(13) Anode/insulating layer/hole-injecting/transporting layer/emitting layer/electron-injecting/transporting layer/cathode.

Among the above, the configuration of (8) is preferably used, but the present invention is not limited thereto.

In the emitting layer, formation positions of the first emitting layer and the second emitting layer are not limited. In one embodiment, the emitting layer includes the first emitting layer and the second emitting layer in this order from the anode side.

In one embodiment, the first emitting layer and the second emitting layer are directly adjacent to each other.

In the present specification, the “hole-injecting/transporting layer” means “at least one of a hole-injecting layer and a hole-transporting layer”, and the “electron-injecting/transporting layer” means “at least one of an electron-injecting layer and an electron-transporting layer”.

In one embodiment, the organic EL device according to an aspect of the present invention includes a hole-transporting layer between the anode and the emitting layer.

In one embodiment, the organic EL device according to an aspect of the present invention includes an electron-transporting layer between the cathode and the emitting layer.

Hereinafter, members that can be used in the organic EL device according to an aspect of the present invention, materials constituting each layer, and the like will be described.

### (First Emitting Layer)

The first emitting layer contains one or more compounds selected from the group consisting of a compound represented by each of the formulas (1) to (4) described later.

In the present specification, the phrase “the group consisting of a compound represented by each of the formulas (1) to (4)” means “the group consisting of a compound represented by the formula (1), a compound represented by the formula (2), a compound represented by the formula (3), and a compound represented by the formula (4)”.

### [Compound Represented by Formula (1)]

The compound represented by the formula (1) is as follows:

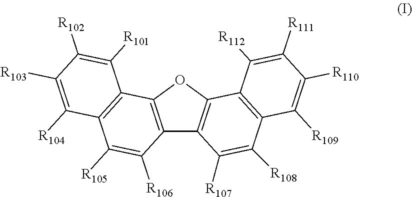

wherein in the formula (1),
at least one of R₁₀₁ to R₁₁₂ is a single bond bonded to a group represented by the following formula (A1):

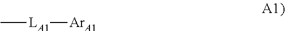

in the formula (A1),
L_{A1} is
a single bond,
a substituted or unsubstituted arylene group having 6 to 20 ring carbon atoms, or
a substituted or unsubstituted divalent heterocyclic group having 5 to 19 ring atoms, Ar_{A1} is
a substituted or unsubstituted aryl group having 6 to 30 ring carbon atoms, or
a substituted or unsubstituted monovalent heterocyclic group having 5 to 30 ring atoms,
R₁₀₁ to R₁₁₂ which are not a single bond bonded to the group represented by the formula (A1) are independently
a hydrogen atom,
a substituted or unsubstituted aryl group having 6 to 20 ring carbon atoms, or
a substituted or unsubstituted monovalent heterocyclic group having 5 to 19 ring atoms, and
when two or more groups represented by the formula (A1) are present, the two or more groups represented by the formula (A1) may be the same as or different from each other.

In the formula (1), when L_{A1} of the formula (A1) is a single bond, Ar_{A1} is directly bonded to the dinaphthofuran skeleton.

In one embodiment, Ar_{A1} is a substituted or unsubstituted aryl group having 6 to 30 ring carbon atoms.

In one embodiment, Ar_{A1} is
a substituted or unsubstituted phenyl group,
a substituted or unsubstituted naphthyl group, or
a substituted or unsubstituted pyrenyl group.

In one embodiment, Ar_{A1} is a substituted or unsubstituted monovalent heterocyclic group having 5 to 30 ring atoms.

In one embodiment, Ar_{A1} is
a substituted or unsubstituted pyrenyl group,
a substituted or unsubstituted benzanthryl group, or
a substituted or unsubstituted benzoxanthenyl group.

In one embodiment, L_{A1} is
a single bond, or
a substituted or unsubstituted arylene group having 6 to 20 ring carbon atoms.

In one embodiment, the compound represented by the formula (1) is a compound represented by the following formula (11):

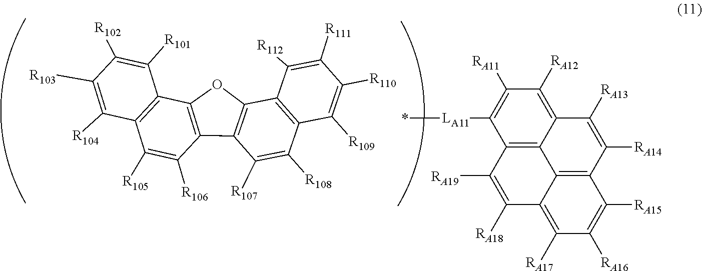

wherein in the formula (11),
at least one of R₁₀₁ to R₁₁₂ is a single bond bonded to L_{A11},
R₁₀₁ to R₁₁₂ which are not a single bond bonded to L_{A11} are independently
a hydrogen atom,
a substituted or unsubstituted aryl group having 6 to 20 ring carbon atoms, or
a substituted or unsubstituted monovalent heterocyclic group having 5 to 19 ring atoms, L_{A11} is
a single bond, or
a substituted or unsubstituted arylene group having 6 to 20 ring carbon atoms,
R_{A11} to R_{A19} are independently a hydrogen atom or a substituent R,
the substituent R is selected from the group consisting of
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,

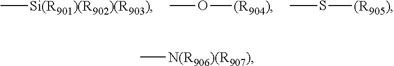

a halogen atom, a cyano group, a nitro group,
a substituted or unsubstituted aryl group having 6 to 50 ring carbon atoms, and
a substituted or unsubstituted monovalent heterocyclic group having 5 to 50 ring atoms,
when two or more substituents R are present, the two or more substituents R may be the same as or different from each other,
R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms, and
when two or more of each of R₉₀₁ to R₉₀₇ are present, the two or more of each of R₉₀₁ to R₉₀₇ may be the same as or different from each other.

In the formula (11), when L_{A11} is a single bond, the pyrene skeleton is directly bonded to the dinaphthofuran skeleton.

In one embodiment, R_{A11} to R_{A19} are a hydrogen atom.

In one embodiment, at least one of R_{A11} to R_{A19} which are a hydrogen atom is a deuterium atom.

In one embodiment, the compound represented by the formula (1) is a compound represented by the following formula (12):

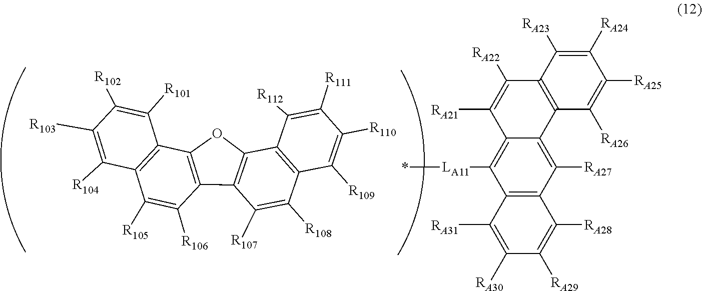

wherein in the formula (12),
at least one of R₁₁ to R₁₁₂ is a single bond bonded to L_{A11},
R₁₁ to R₁₁₂ which are not a single bond bonded to L_{A11} are independently
a hydrogen atom,
a substituted or unsubstituted aryl group having 6 to 20 ring carbon atoms, or
a substituted or unsubstituted monovalent heterocyclic group having 5 to 19 ring atoms, L_{A11} is
a single bond, or
a substituted or unsubstituted arylene group having 6 to 20 ring carbon atoms,
R_{A21} to R_{A31} are independently a hydrogen atom or a substituent R,
the substituent R is selected from the group consisting of
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,

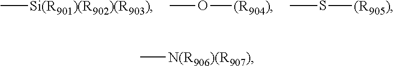

a halogen atom, a cyano group, a nitro group,
a substituted or unsubstituted aryl group having 6 to 50 ring carbon atoms, and
a substituted or unsubstituted monovalent heterocyclic group having 5 to 50 ring atoms,
when two or more substituents R are present, the two or more substituents R may be the same as or different from each other,
R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms, and
when two or more of each of R₉₀₁ to R₉₀₇ are present, the two or more of each of R₉₀₁ to R₉₀₇ may be the same as or different from each other.

In one embodiment, the compound represented by the formula (12) is a compound represented by the following formula (121) or (122):

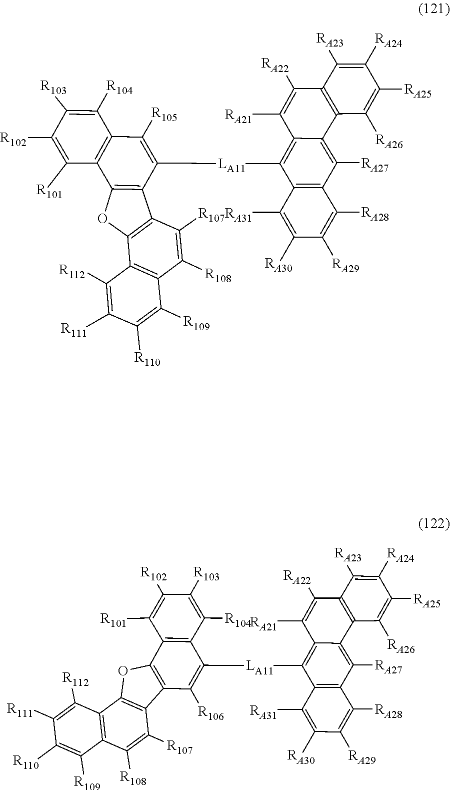

wherein in the formulas (121) and (122),
L_{A11}, R_{A21} to R_{A31}, and R₁₀₁ to R₁₁₂ are as defined in the above formula (12).

In one embodiment, R_{A21} to R_{A31} are a hydrogen atom.

In one embodiment, at least one of R_{A21} to R_{A31} which are a hydrogen atom is a deuterium atom.

In the present specification, the phrase a hydrogen atom is “a deuterium atom” means that in the hydrogen atom, the ratio of deuterium atoms to the total of light hydrogen atoms and deuterium atoms is larger than the natural abundance ratio. It can be confirmed by a nuclear magnetic resonance apparatus that the ratio of deuterium atoms to the total of light hydrogen atoms and deuterium atoms is higher than the natural abundance ratio.

In one embodiment, R₁₀₁ to R₁₁₂ which are not a single bond bonded to L_{A11} are a hydrogen atom.

In one embodiment, a substituent in the case of “substituted or unsubstituted” in the above formula (1) is selected from the group consisting of
an alkyl group having 1 to 50 carbon atoms,
a haloalkyl group having 1 to 50 carbon atoms,
an alkenyl group having 2 to 50 carbon atoms,
an alkynyl group having 2 to 50 carbon atoms,
a cycloalkyl group having 3 to 50 ring carbon atoms,
an alkoxy group having 1 to 50 carbon atoms,
an alkylthio group having 1 to 50 carbon atoms,
an aryloxy group having 6 to 50 ring carbon atoms,
an arylthio group having 6 to 50 ring carbon atoms,
an aralkyl group having 7 to 50 carbon atoms,

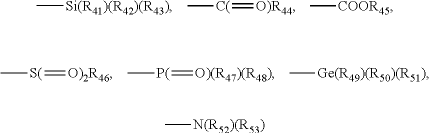

(wherein R₄₁ to R₅₃ are independently a hydrogen atom, an alkyl group having 1 to 50 carbon atoms, an aryl group having 6 to 50 ring carbon atoms, or a monovalent heterocyclic group having 5 to 50 ring atoms; when two or more of each of R₄₁ to R₅₃ are present, the two or more of each of R₄₁ to R₅₃ may be the same as or different from each other),
a hydroxy group,
a halogen atom,
a cyano group,
a nitro group,
an aryl group having 6 to 50 ring carbon atoms, and
a monovalent heterocyclic group having 5 to 50 ring atoms.

In one embodiment, a substituent in the case of “substituted or unsubstituted” in the above formula (1) is selected from the group consisting of
an alkyl group having 1 to 50 carbon atoms,
an aryl group having 6 to 50 ring carbon atoms, and
a monovalent heterocyclic group having 5 to 50 ring atoms.

In one embodiment, a substituent in the case of “substituted or unsubstituted” in the above formula (1) is
an unsubstituted aryl group having 6 to 20 ring carbon atoms, or
an unsubstituted monovalent heterocyclic group having 5 to 19 ring atoms.

The compound represented by the formula (1) can be synthesized by following Examples and using a known alternative reaction or raw material suited for an intended product.

Specific examples of the compound represented by the formula (1) will be described below, but these are merely examples, and the compound represented by the formula (1) is not limited to the following specific examples.

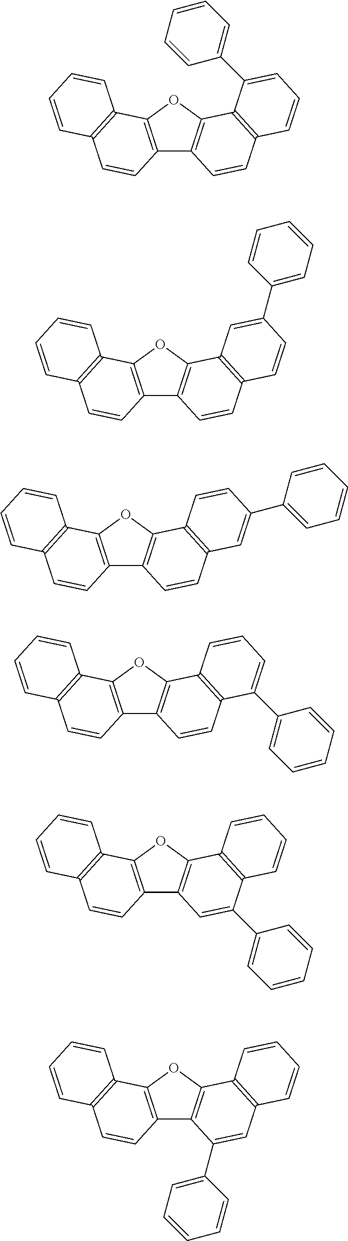 [SMILES: c1ccc(-c2cccc3ccc4c5ccc6ccccc6c5oc4c23)cc1 ; c1ccc(-c2ccc3ccc4c5ccc6ccccc6c5oc4c3c2)cc1 ; c1ccc(-c2ccc3c(ccc4c5ccc6ccccc6c5oc34)c2)cc1 ; c1ccc(-c2cccc3c2ccc2c4ccc5ccccc5c4oc32)cc1 ; c1ccc(-c2cc3c4ccc5ccccc5c4oc3c3ccccc23)cc1 ; c1ccc(-c2cc3ccccc3c3oc4c5ccccc5ccc4c23)cc1]

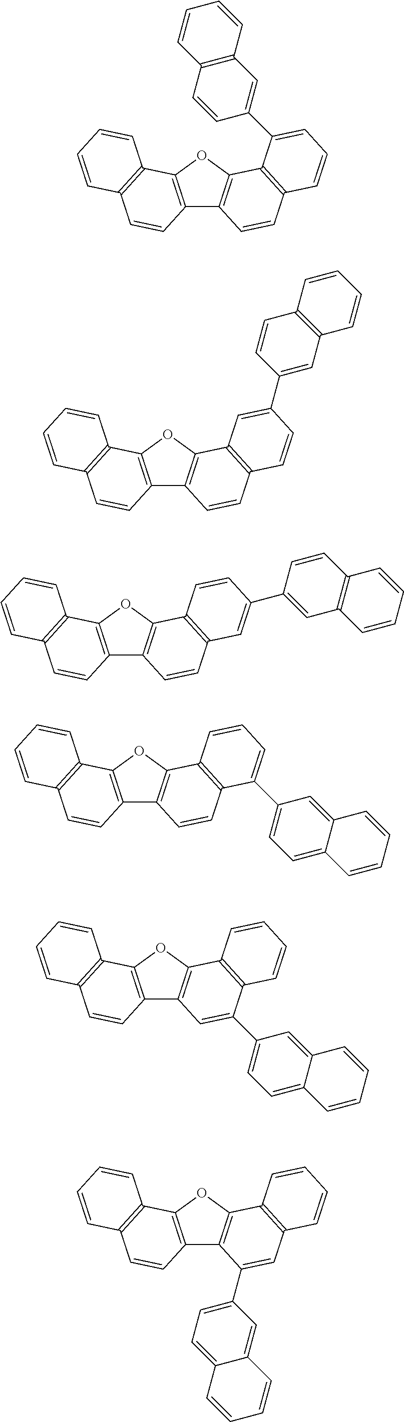 [SMILES: c1ccc2cc(-c3cccc4ccc5c6ccc7ccccc7c6oc5c34)ccc2c1 ; c1ccc2cc(-c3ccc4ccc5c6ccc7ccccc7c6oc5c4c3)ccc2c1 ; c1ccc2cc(-c3ccc4c(ccc5c6ccc7ccccc7c6oc45)c3)ccc2c1 ; c1ccc2cc(-c3cccc4c3ccc3c5ccc6ccccc6c5oc43)ccc2c1 ; c1ccc2cc(-c3cc4c5ccc6ccccc6c5oc4c4ccccc34)ccc2c1 ; c1ccc2cc(-c3cc4ccccc4c4oc5c6ccccc6ccc5c34)ccc2c1]

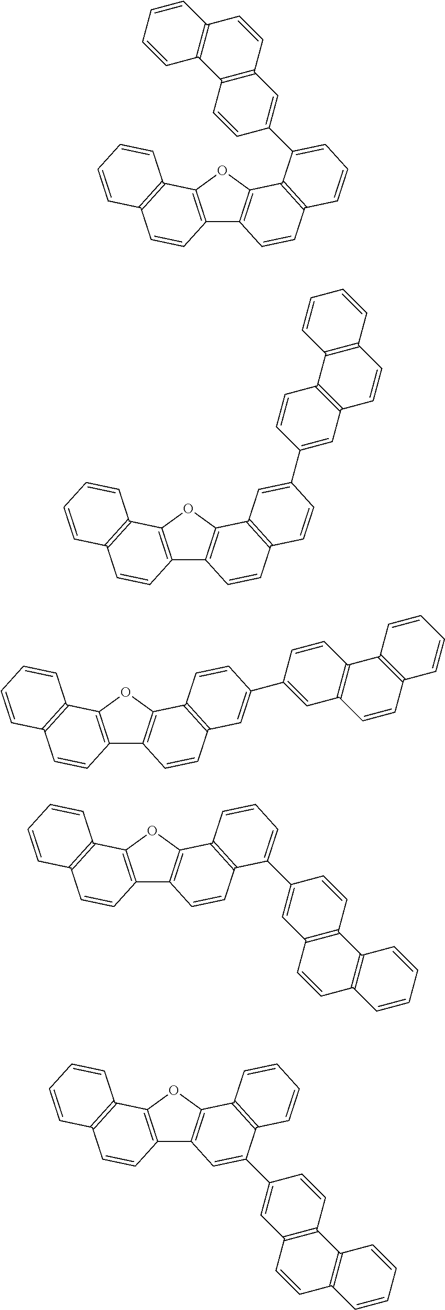

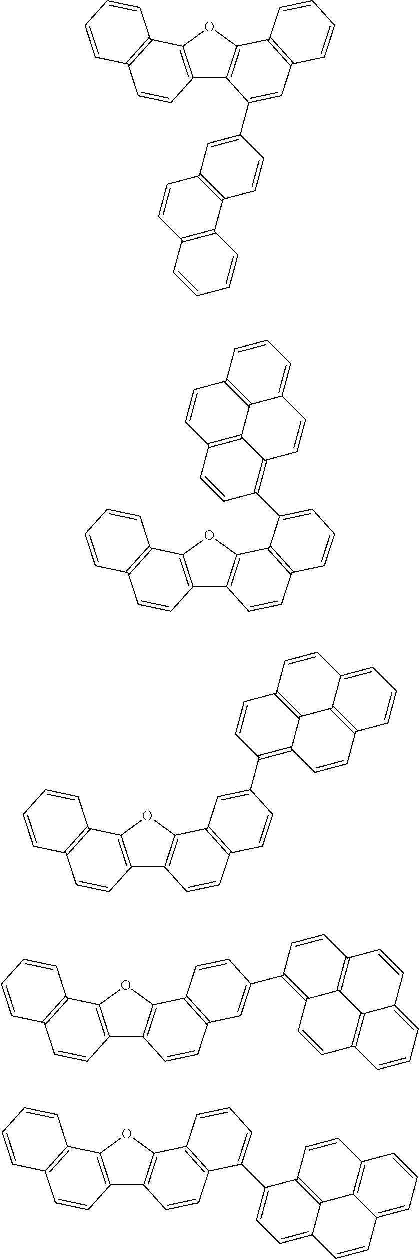 [SMILES: c1ccc2c(c1)ccc1cc(-c3cc4ccccc4c4oc5c6ccccc6ccc5c34)ccc12 ; c1ccc2c(c1)ccc1c3ccc4cccc(-c5ccc6ccc7cccc8ccc5c6c78)c4c3oc21 ; c1ccc2c(c1)ccc1c3ccc4ccc(-c5ccc6ccc7cccc8ccc5c6c78)cc4c3oc21 ; c1ccc2c(c1)ccc1c3ccc4cc(-c5ccc6ccc7cccc8ccc5c6c78)ccc4c3oc21 ; c1ccc2c(c1)ccc1c3ccc4c(-c5ccc6ccc7cccc8ccc5c6c78)cccc4c3oc21]

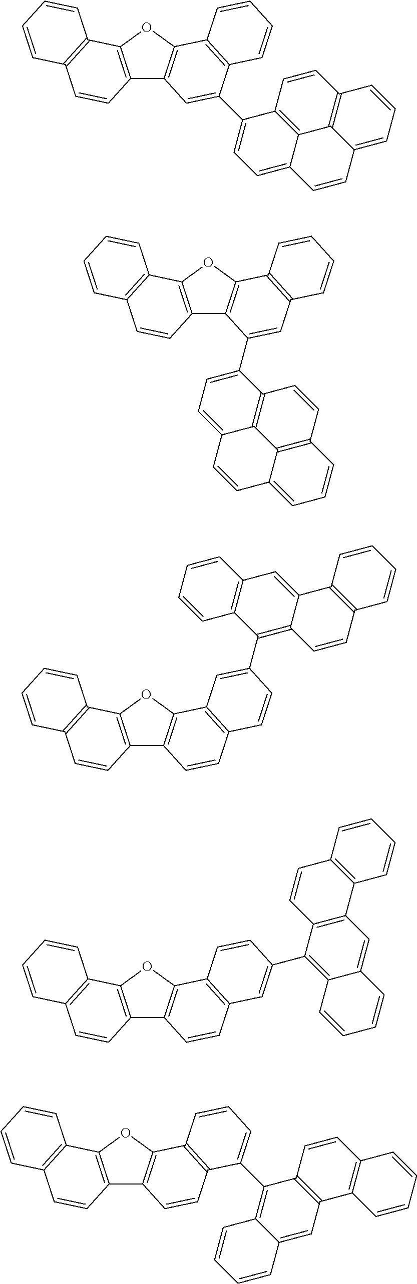

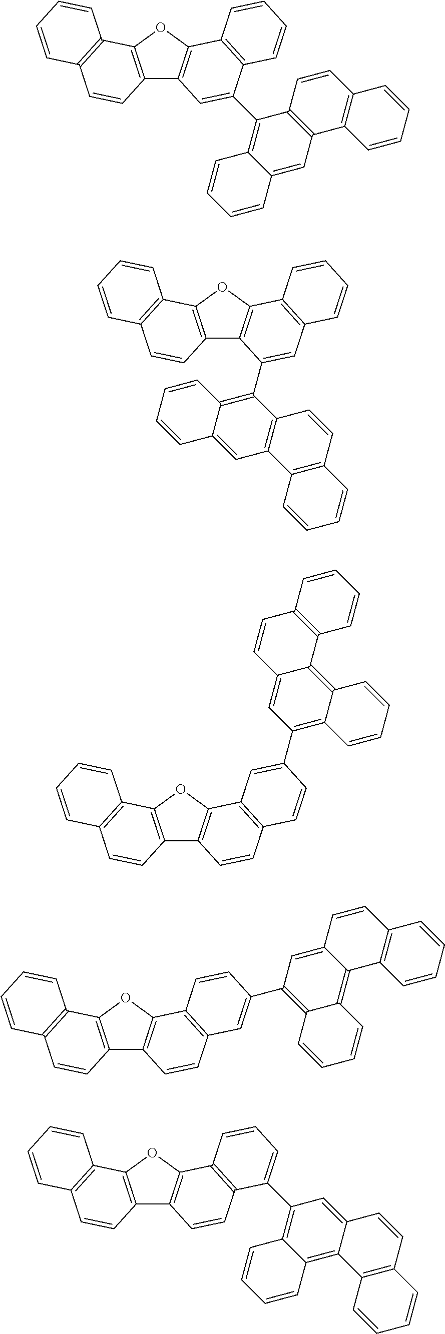 [SMILES: c1ccc2c(-c3cc4c5ccc6ccccc6c5oc4c4ccccc34)c3ccc4ccccc4c3cc2c1 ; c1ccc2c(-c3cc4ccccc4c4oc5c6ccccc6ccc5c34)c3ccc4ccccc4c3cc2c1 ; c1ccc2c(c1)ccc1c3ccc4ccc(-c5cc6ccc7ccccc7c6c6ccccc56)cc4c3oc21 ; c1ccc2c(c1)ccc1c3ccc4cc(-c5cc6ccc7ccccc7c6c6ccccc56)ccc4c3oc21 ; c1ccc2c(c1)ccc1c3ccc4c(-c5cc6ccc7ccccc7c6c6ccccc56)cccc4c3oc21]

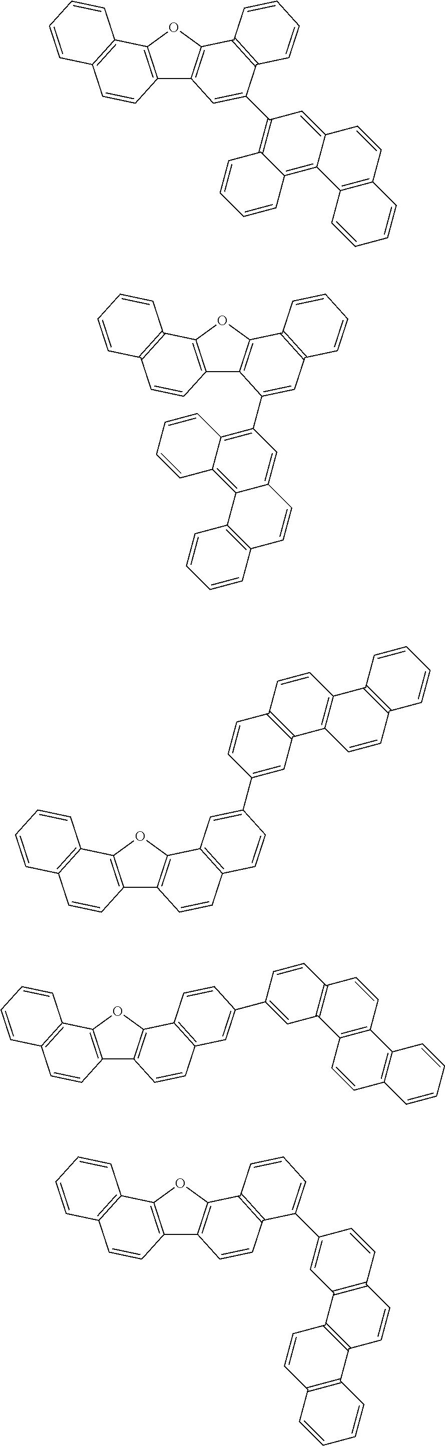 [SMILES: c1ccc2c(c1)ccc1c3cc(-c4cc5ccc6ccccc6c5c5ccccc45)c4ccccc4c3oc21 ; c1ccc2c(c1)ccc1c2oc2c3ccccc3cc(-c3cc4ccc5ccccc5c4c4ccccc34)c12 ; c1ccc2c(c1)ccc1c3cc(-c4ccc5ccc6c7ccc8ccccc8c7oc6c5c4)ccc3ccc21 ; c1ccc2c(c1)ccc1c3cc(-c4ccc5c(ccc6c7ccc8ccccc8c7oc56)c4)ccc3ccc21 ; c1ccc2c(c1)ccc1c3cc(-c4cccc5c4ccc4c6ccc7ccccc7c6oc54)ccc3ccc21]

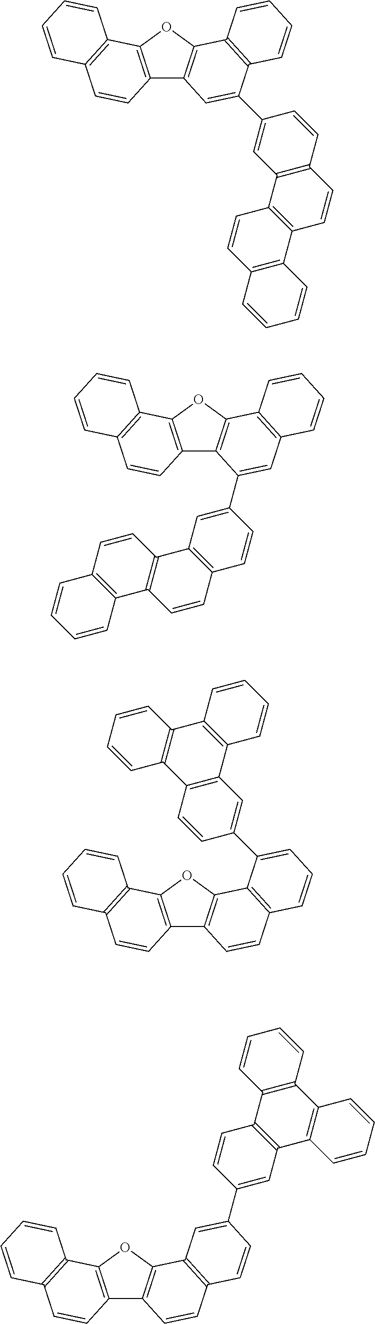 [SMILES: c1ccc2c(c1)ccc1c3cc(-c4cc5c6ccc7ccccc7c6oc5c5ccccc45)ccc3ccc21 ; c1ccc2c(c1)ccc1c3cc(-c4cc5ccccc5c5oc6c7ccccc7ccc6c45)ccc3ccc21 ; c1ccc2c(c1)ccc1c3ccc4cccc(-c5ccc6c7ccccc7c7ccccc7c6c5)c4c3oc21 ; c1ccc2c(c1)ccc1c3ccc4ccc(-c5ccc6c7ccccc7c7ccccc7c6c5)cc4c3oc21]

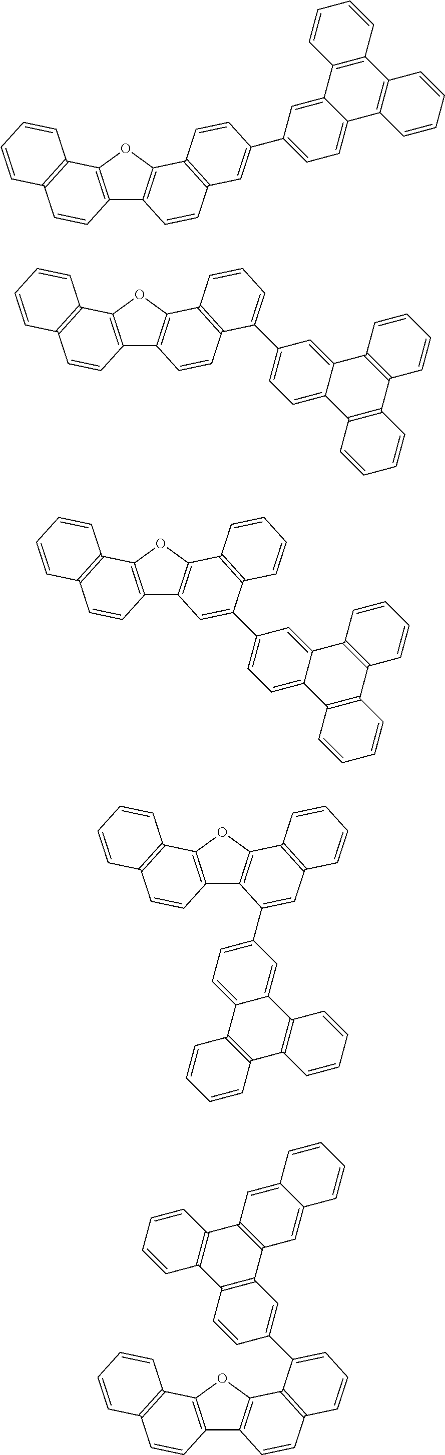 [SMILES: c1ccc2c(c1)ccc1c3ccc4cc(-c5ccc6c7ccccc7c7ccccc7c6c5)ccc4c3oc21 ; c1ccc2c(c1)ccc1c3ccc4c(-c5ccc6c7ccccc7c7ccccc7c6c5)cccc4c3oc21 ; c1ccc2c(c1)ccc1c3cc(-c4ccc5c6ccccc6c6ccccc6c5c4)c4ccccc4c3oc21 ; c1ccc2c(c1)ccc1c2oc2c3ccccc3cc(-c3ccc4c5ccccc5c5ccccc5c4c3)c12 ; c1ccc2cc3c4cc(-c5cccc6ccc7c8ccc9ccccc9c8oc7c56)ccc4c4ccccc4c3cc2c1]

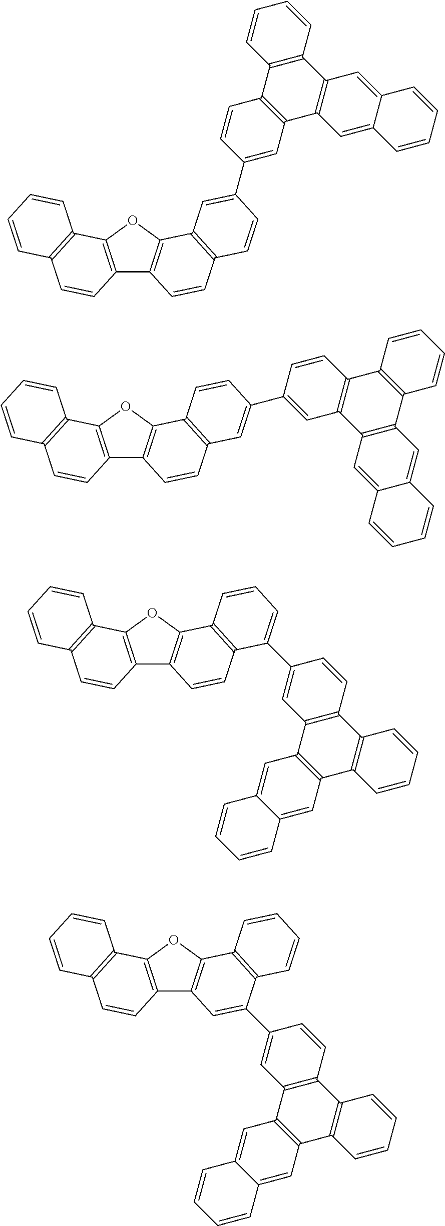 [SMILES: c1ccc2cc3c4cc(-c5ccc6ccc7c8ccc9ccccc9c8oc7c6c5)ccc4c4ccccc4c3cc2c1 ; c1ccc2cc3c4cc(-c5ccc6c(ccc7c8ccc9ccccc9c8oc67)c5)ccc4c4ccccc4c3cc2c1 ; c1ccc2cc3c4cc(-c5cccc6c5ccc5c7ccc8ccccc8c7oc65)ccc4c4ccccc4c3cc2c1 ; c1ccc2cc3c4cc(-c5cc6c7ccc8ccccc8c7oc6c6ccccc56)ccc4c4ccccc4c3cc2c1]

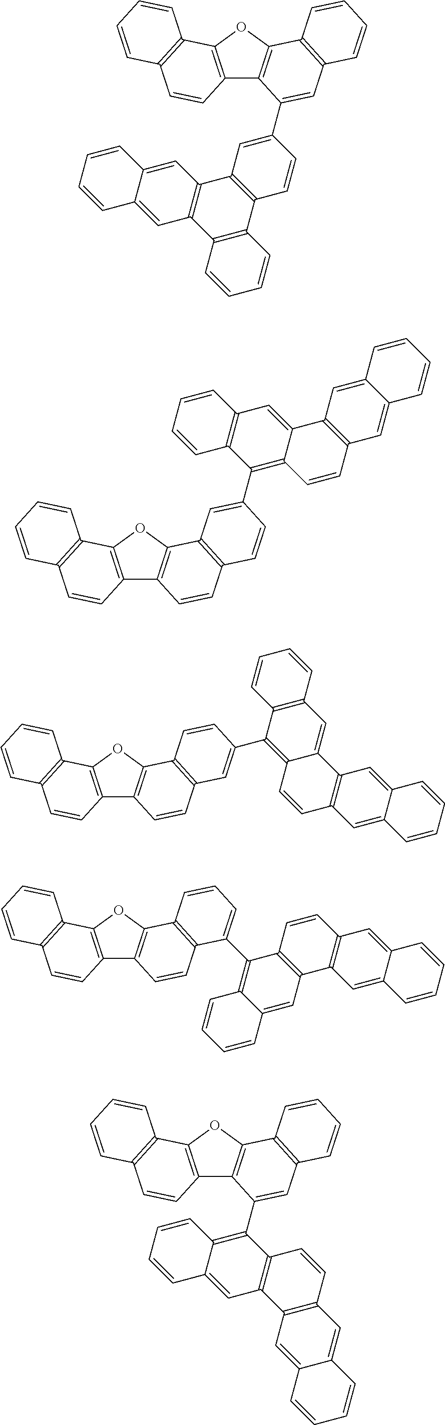 [SMILES: c1ccc2cc3c4cc(-c5cc6ccccc6c6oc7c8ccccc8ccc7c56)ccc4c4ccccc4c3cc2c1 ; c1ccc2cc3c(ccc4c(-c5ccc6ccc7c8ccc9ccccc9c8oc7c6c5)c5ccccc5cc43)cc2c1 ; c1ccc2cc3c(ccc4c(-c5ccc6c(ccc7c8ccc9ccccc9c8oc67)c5)c5ccccc5cc43)cc2c1 ; c1ccc2cc3c(ccc4c(-c5cccc6c5ccc5c7ccc8ccccc8c7oc65)c5ccccc5cc43)cc2c1 ; c1ccc2cc3c(ccc4c(-c5cc6ccccc6c6oc7c8ccccc8ccc7c56)c5ccccc5cc43)cc2c1]

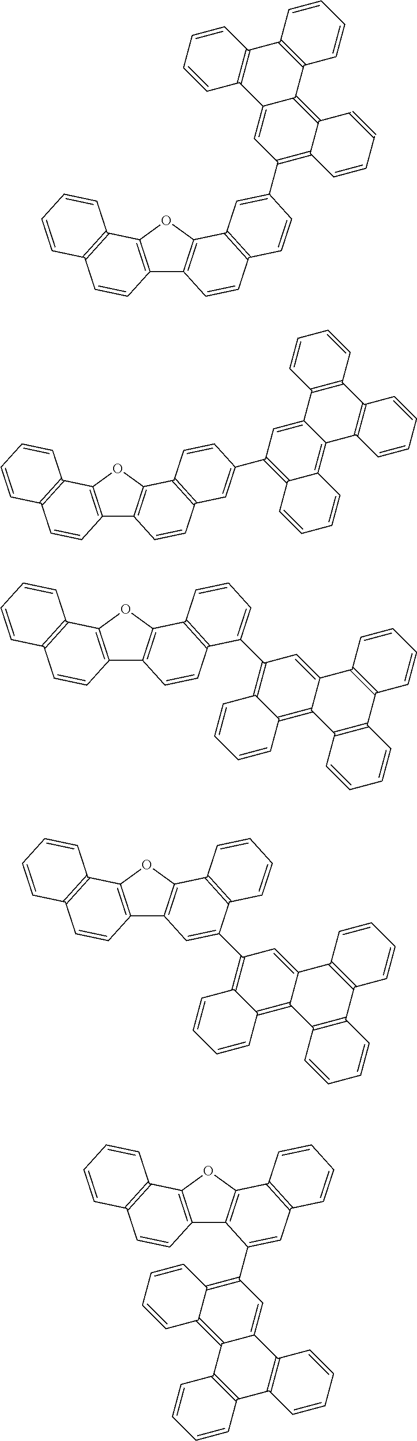 [SMILES: c1ccc2c(c1)ccc1c3ccc4ccc(-c5cc6c7ccccc7c7ccccc7c6c6ccccc56)cc4c3oc21 ; c1ccc2c(c1)ccc1c3ccc4cc(-c5cc6c7ccccc7c7ccccc7c6c6ccccc56)ccc4c3oc21 ; c1ccc2c(c1)ccc1c3ccc4c(-c5cc6c7ccccc7c7ccccc7c6c6ccccc56)cccc4c3oc21 ; c1ccc2c(c1)ccc1c3cc(-c4cc5c6ccccc6c6ccccc6c5c5ccccc45)c4ccccc4c3oc21 ; c1ccc2c(c1)ccc1c2oc2c3ccccc3cc(-c3cc4c5ccccc5c5ccccc5c4c4ccccc34)c12]

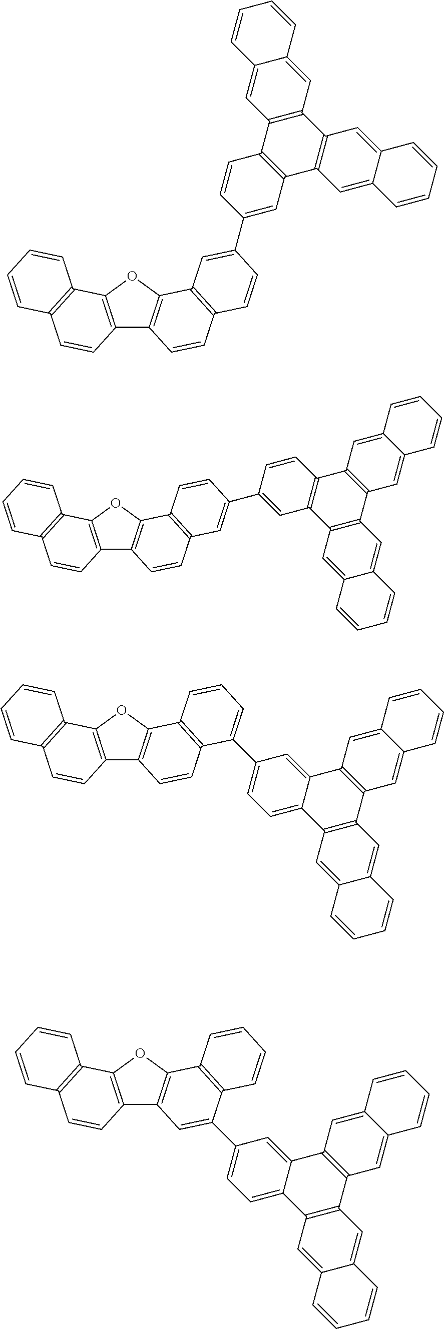 [SMILES: c1ccc2cc3c(cc2c1)c1ccc(-c2ccc4ccc5c6ccc7ccccc7c6oc5c4c2)cc1c1cc2ccccc2cc13 ; c1ccc2cc3c(cc2c1)c1ccc(-c2ccc4c(ccc5c6ccc7ccccc7c6oc45)c2)cc1c1cc2ccccc2cc13 ; c1ccc2cc3c(cc2c1)c1ccc(-c2cccc4c2ccc2c5ccc6ccccc6c5oc42)cc1c1cc2ccccc2cc13 ; c1ccc2cc3c(cc2c1)c1ccc(-c2cc4c5ccc6ccccc6c5oc4c4ccccc24)cc1c1cc2ccccc2cc13]

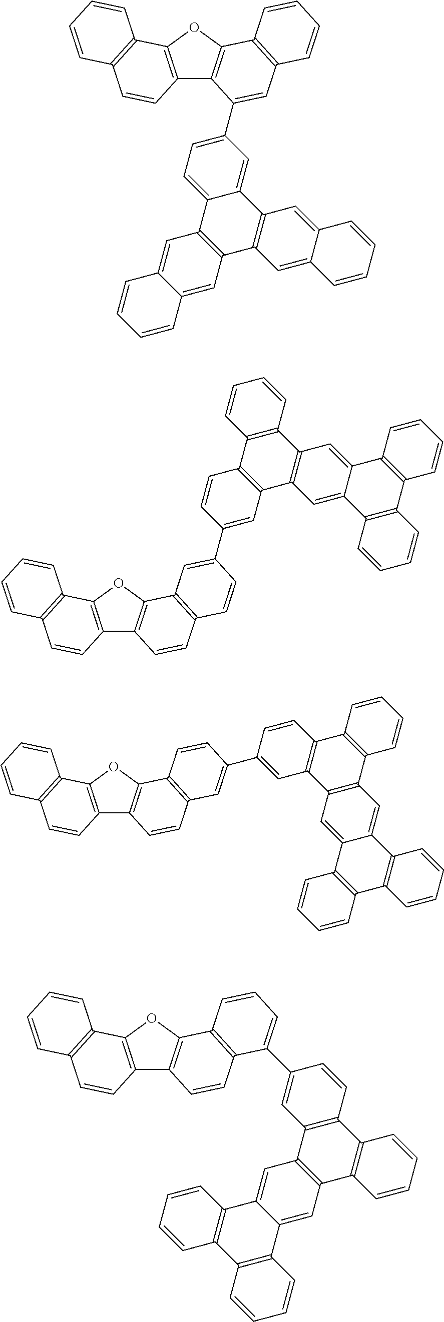 [SMILES: c1ccc2cc3c(cc2c1)c1ccc(-c2cc4ccccc4c4oc5c6ccccc6ccc5c24)cc1c1cc2ccccc2cc13 ; c1ccc2c(c1)ccc1c3ccc4ccc(-c5ccc6c7ccccc7c7cc8c9ccccc9c9ccccc9c8cc7c6c5)cc4c3oc21 ; c1ccc2c(c1)ccc1c3ccc4cc(-c5ccc6c7ccccc7c7cc8c9ccccc9c9ccccc9c8cc7c6c5)ccc4c3oc21 ; c1ccc2c(c1)ccc1c3ccc4c(-c5ccc6c7ccccc7c7cc8c9ccccc9c9ccccc9c8cc7c6c5)cccc4c3oc21]

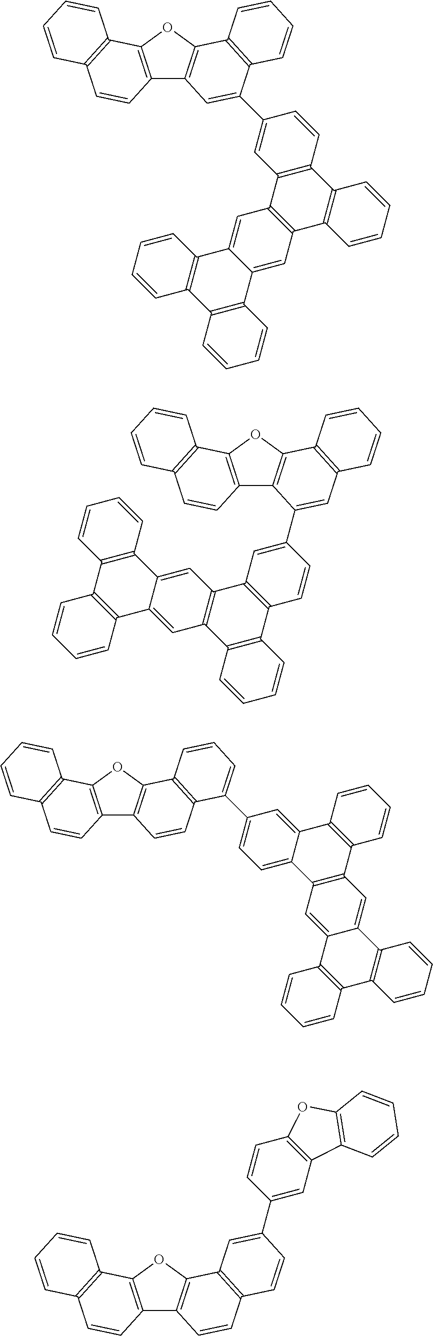 [SMILES: c1ccc2c(c1)ccc1c3cc(-c4ccc5c6ccccc6c6cc7c8ccccc8c8ccccc8c7cc6c5c4)c4ccccc4c3oc21 ; c1ccc2c(c1)ccc1c2oc2c3ccccc3cc(-c3ccc4c5ccccc5c5cc6c7ccccc7c7ccccc7c6cc5c4c3)c12 ; c1ccc2c(c1)ccc1c3ccc4c(-c5ccc6c(c5)c5ccccc5c5cc7c8ccccc8c8ccccc8c7cc65)cccc4c3oc21 ; c1ccc2c(c1)ccc1c3ccc4ccc(-c5ccc6oc7ccccc7c6c5)cc4c3oc21]

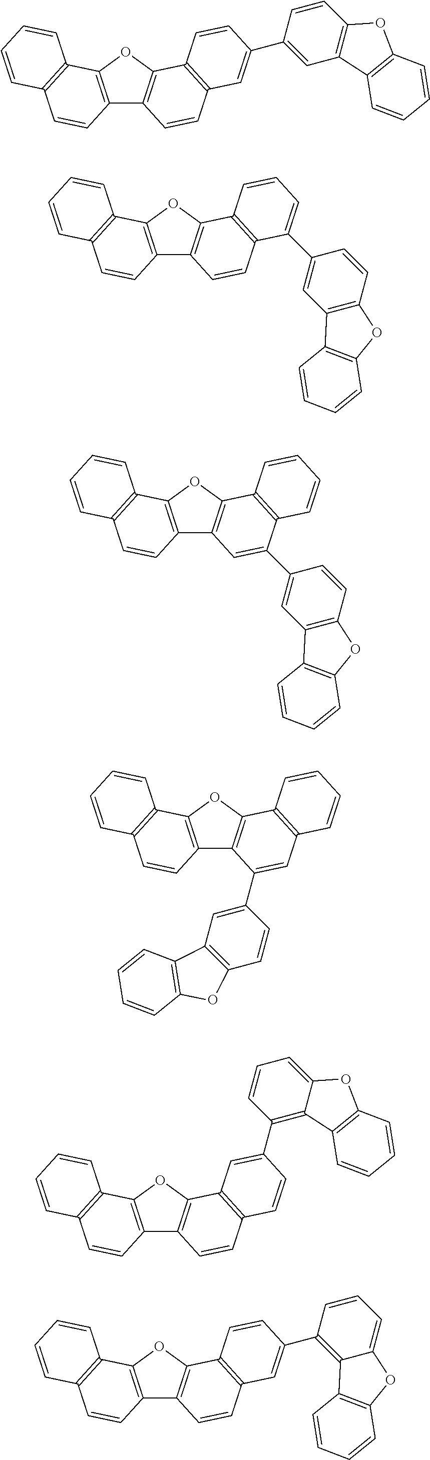

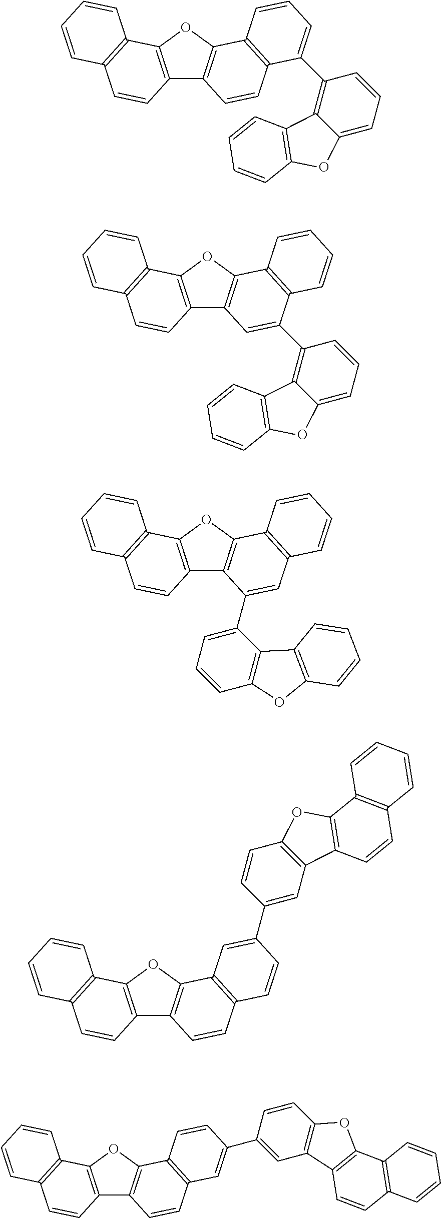 [SMILES: c1ccc2c(c1)ccc1c3ccc4c(-c5cccc6oc7ccccc7c56)cccc4c3oc21 ; c1ccc2c(c1)ccc1c3cc(-c4cccc5oc6ccccc6c45)c4ccccc4c3oc21 ; c1ccc2c(c1)ccc1c2oc2c3ccccc3cc(-c3cccc4oc5ccccc5c34)c12 ; c1ccc2c(c1)ccc1c3cc(-c4ccc5ccc6c7ccc8ccccc8c7oc6c5c4)ccc3oc21 ; c1ccc2c(c1)ccc1c3cc(-c4ccc5c(ccc6c7ccc8ccccc8c7oc56)c4)ccc3oc21]

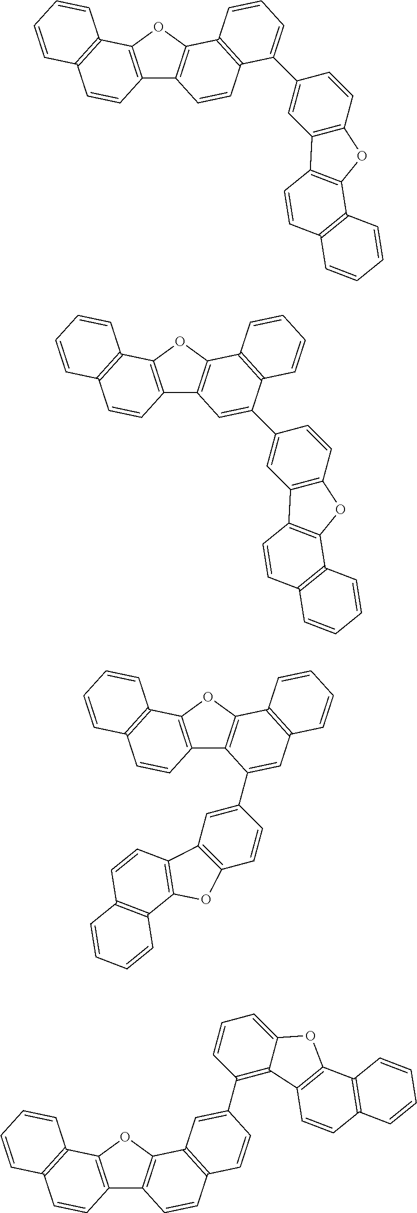

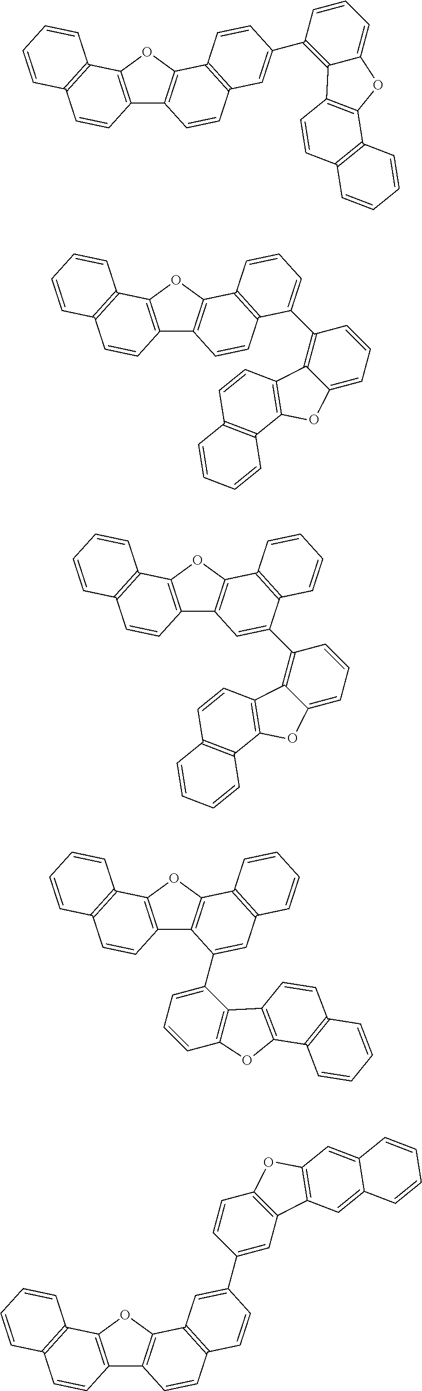 [SMILES: c1ccc2c(c1)ccc1c3ccc4cc(-c5cccc6oc7c8ccccc8ccc7c56)ccc4c3oc21 ; c1ccc2c(c1)ccc1c3ccc4c(-c5cccc6oc7c8ccccc8ccc7c56)cccc4c3oc21 ; c1ccc2c(c1)ccc1c3cc(-c4cccc5oc6c7ccccc7ccc6c45)c4ccccc4c3oc21 ; c1ccc2c(c1)ccc1c2oc2cccc(-c3cc4ccccc4c4oc5c6ccccc6ccc5c34)c21 ; c1ccc2cc3c(cc2c1)oc1ccc(-c2ccc4ccc5c6ccc7ccccc7c6oc5c4c2)cc13]

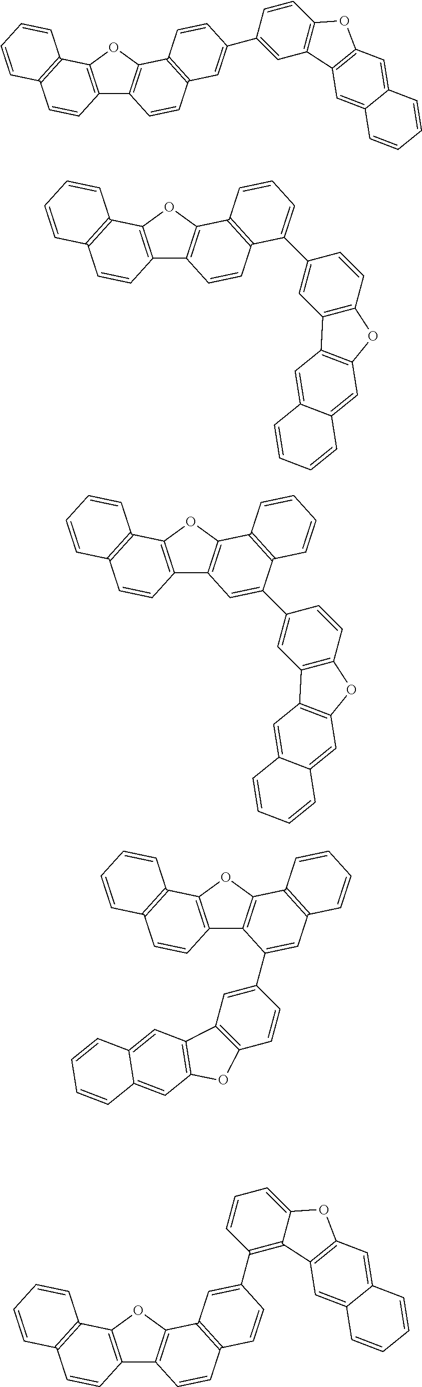

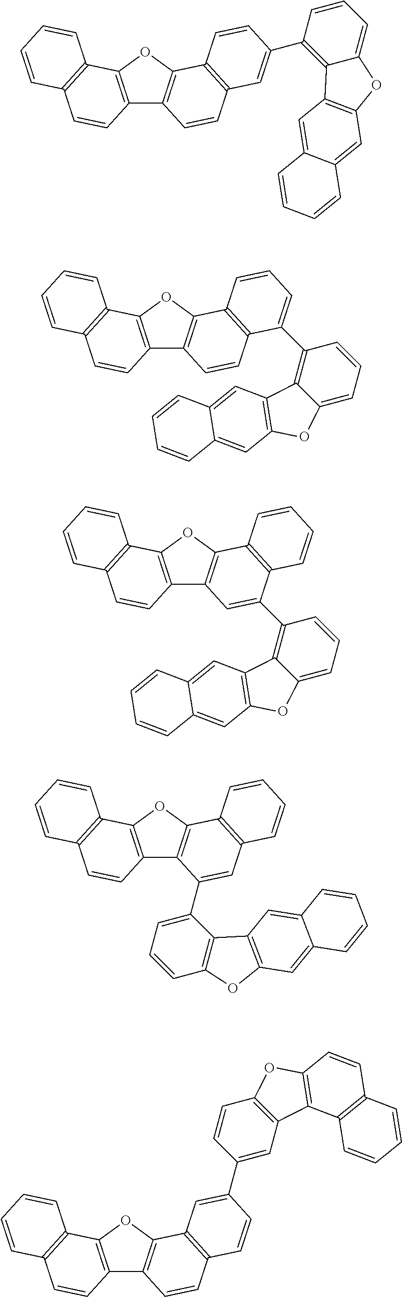 [SMILES: c1ccc2cc3c(cc2c1)oc1cccc(-c2ccc4c(ccc5c6ccc7ccccc7c6oc45)c2)c13 ; c1ccc2cc3c(cc2c1)oc1cccc(-c2cccc4c2ccc2c5ccc6ccccc6c5oc42)c13 ; c1ccc2cc3c(cc2c1)oc1cccc(-c2cc4c5ccc6ccccc6c5oc4c4ccccc24)c13 ; c1ccc2cc3c(cc2c1)oc1cccc(-c2cc4ccccc4c4oc5c6ccccc6ccc5c24)c13 ; c1ccc2c(c1)ccc1c3ccc4ccc(-c5ccc6oc7ccc8ccccc8c7c6c5)cc4c3oc21]

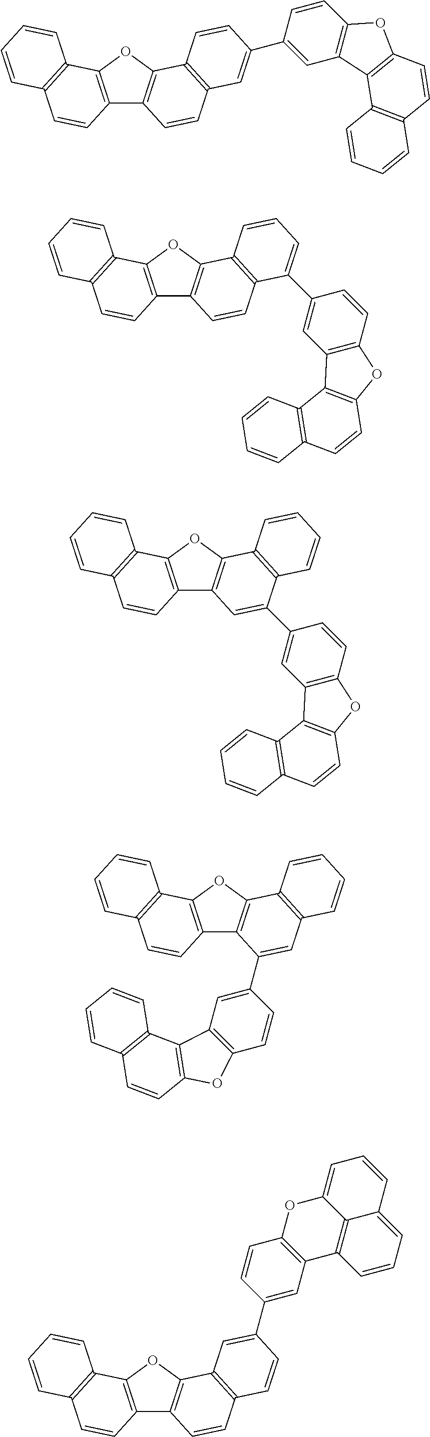 [SMILES: c1ccc2c(c1)ccc1c3ccc4cc(-c5ccc6oc7ccc8ccccc8c7c6c5)ccc4c3oc21 ; c1ccc2c(c1)ccc1c3ccc4c(-c5ccc6oc7ccc8ccccc8c7c6c5)cccc4c3oc21 ; c1ccc2c(c1)ccc1c3cc(-c4ccc5oc6ccc7ccccc7c6c5c4)c4ccccc4c3oc21 ; c1ccc2c(c1)ccc1c2oc2c3ccccc3cc(-c3ccc4oc5ccc6ccccc6c5c4c3)c12 ; c1cc2c3c(cccc3c1)-c1cc(-c3ccc4ccc5c6ccc7ccccc7c6oc5c4c3)ccc1O2]

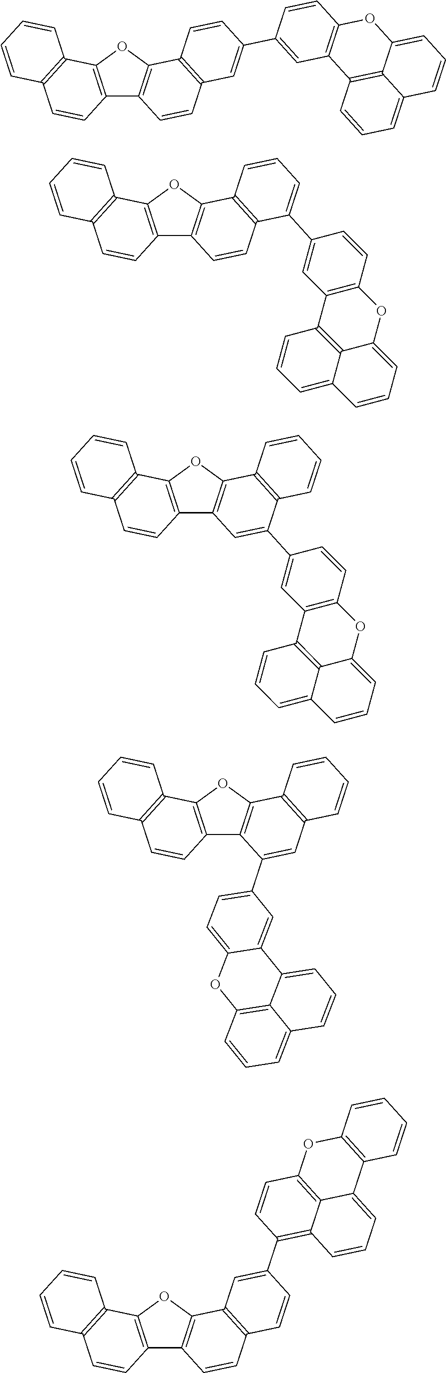

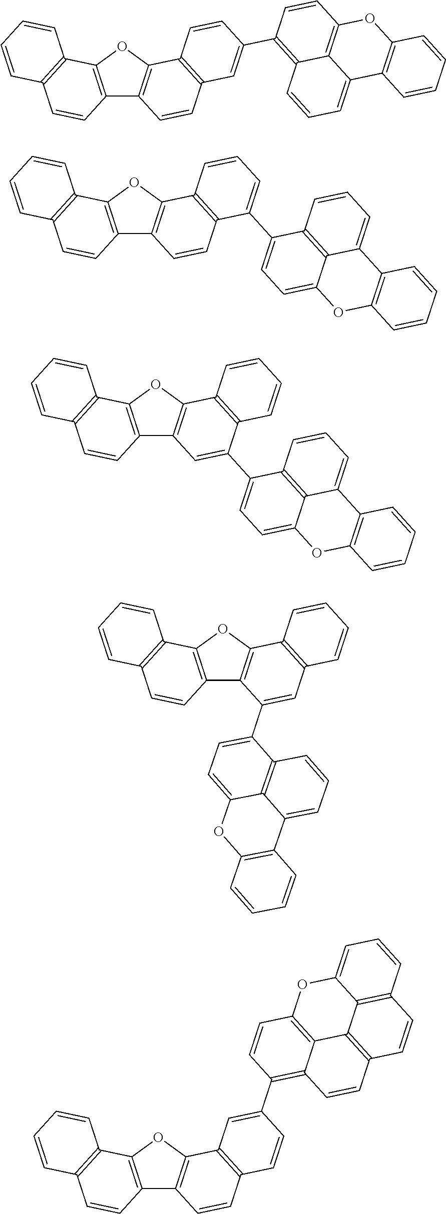 [SMILES: c1ccc2c(c1)Oc1ccc(-c3ccc4c(ccc5c6ccc7ccccc7c6oc45)c3)c3cccc-2c13 ; c1ccc2c(c1)Oc1ccc(-c3cccc4c3ccc3c5ccc6ccccc6c5oc43)c3cccc-2c13 ; c1ccc2c(c1)Oc1ccc(-c3cc4c5ccc6ccccc6c5oc4c4ccccc34)c3cccc-2c13 ; c1ccc2c(c1)Oc1ccc(-c3cc4ccccc4c4oc5c6ccccc6ccc5c34)c3cccc-2c13 ; c1ccc2c(c1)ccc1c3ccc4ccc(-c5ccc6c7c5ccc5ccc8cccc(c8c57)O6)cc4c3oc21]

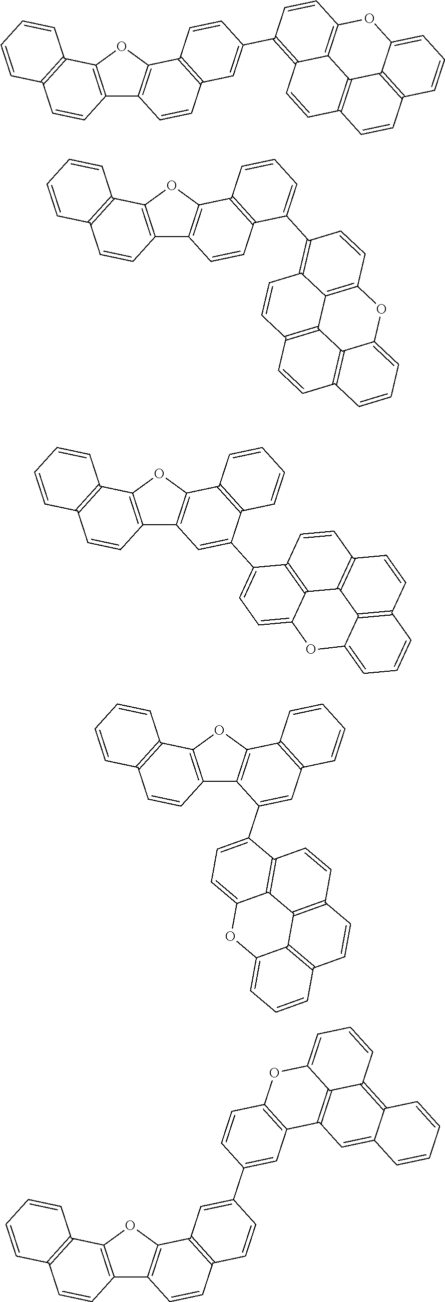

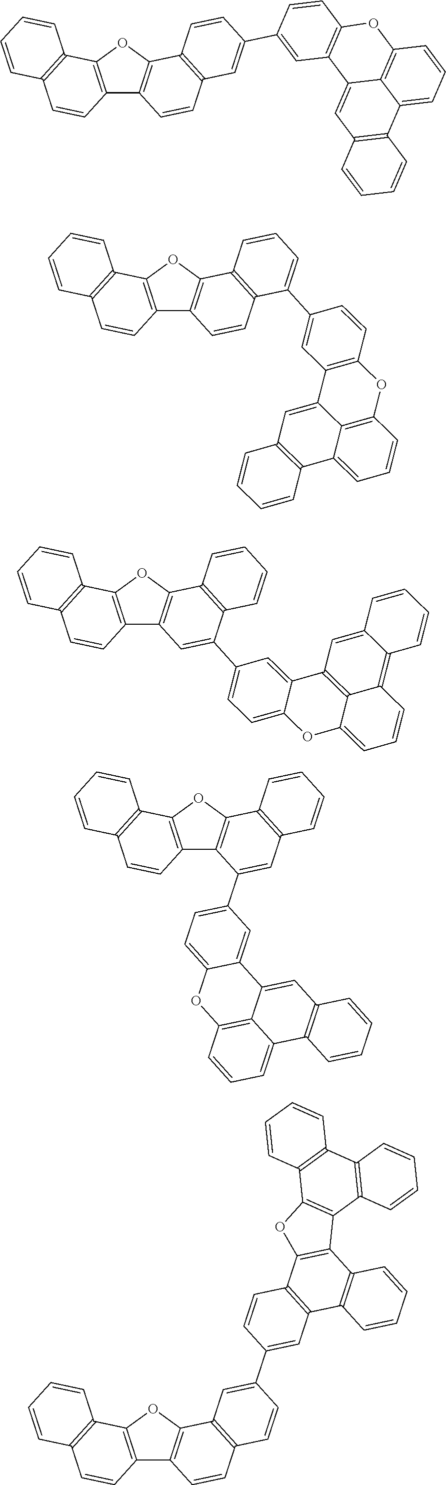

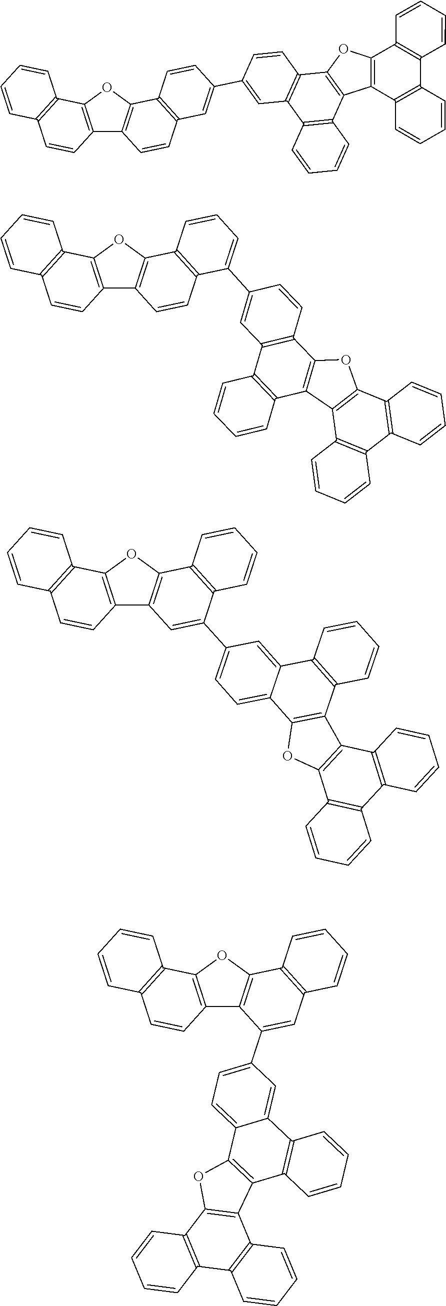 [SMILES: c1ccc2c(c1)ccc1c3ccc4cc(-c5ccc6c(c5)c5ccccc5c5c6oc6c7ccccc7c7ccccc7c65)ccc4c3oc21 ; c1ccc2c(c1)ccc1c3ccc4c(-c5ccc6c(c5)c5ccccc5c5c6oc6c7ccccc7c7ccccc7c65)cccc4c3oc21 ; c1ccc2c(c1)ccc1c3cc(-c4ccc5c(c4)c4ccccc4c4c5oc5c6ccccc6c6ccccc6c54)c4ccccc4c3oc21 ; c1ccc2c(c1)ccc1c2oc2c3ccccc3cc(-c3ccc4c(c3)c3ccccc3c3c4oc4c5ccccc5c5ccccc5c43)c12]

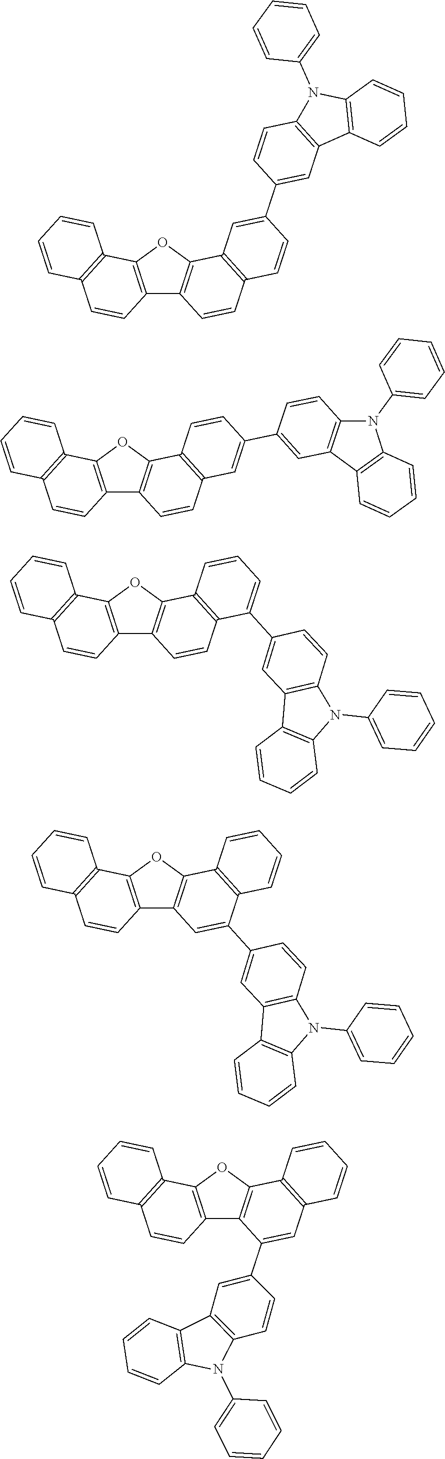 [SMILES: c1ccc(-n2c3ccccc3c3cc(-c4ccc5ccc6c7ccc8ccccc8c7oc6c5c4)ccc32)cc1 ; c1ccc(-n2c3ccccc3c3cc(-c4ccc5c(ccc6c7ccc8ccccc8c7oc56)c4)ccc32)cc1 ; c1ccc(-n2c3ccccc3c3cc(-c4cccc5c4ccc4c6ccc7ccccc7c6oc54)ccc32)cc1 ; c1ccc(-n2c3ccccc3c3cc(-c4cc5c6ccc7ccccc7c6oc5c5ccccc45)ccc32)cc1 ; c1ccc(-n2c3ccccc3c3cc(-c4cc5ccccc5c5oc6c7ccccc7ccc6c45)ccc32)cc1]

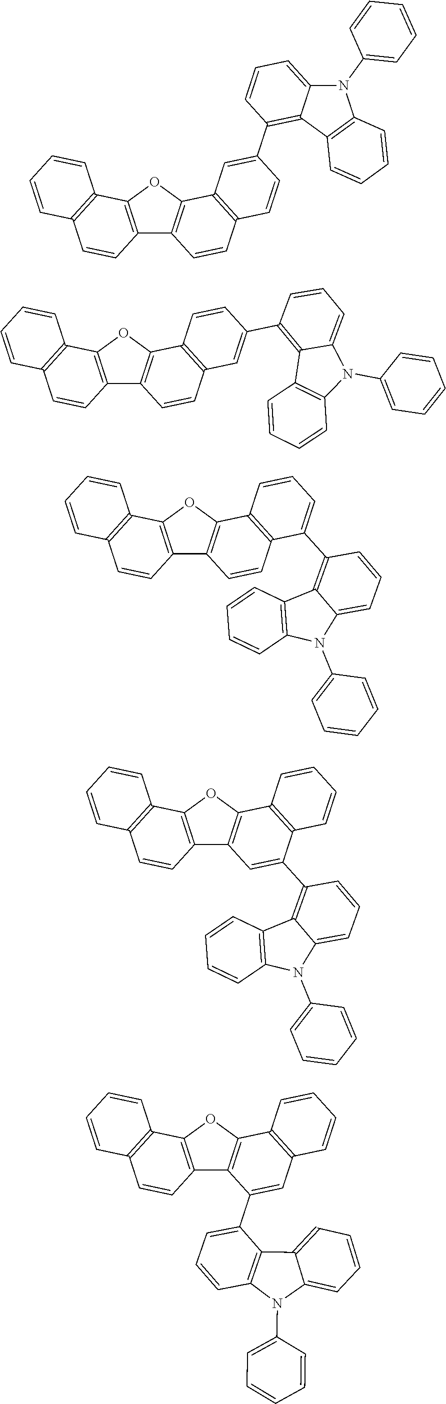

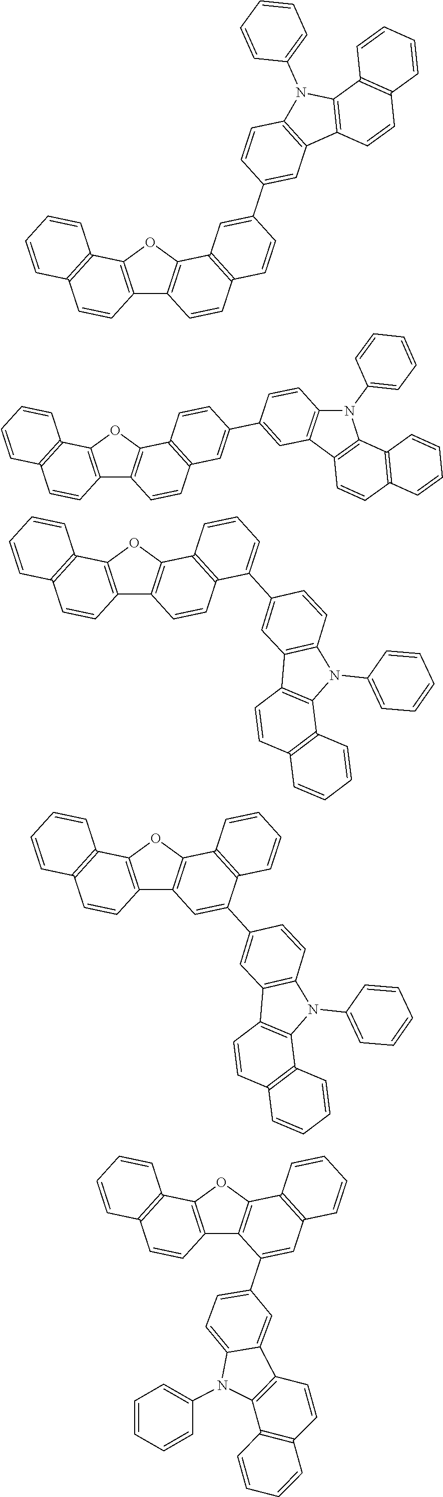

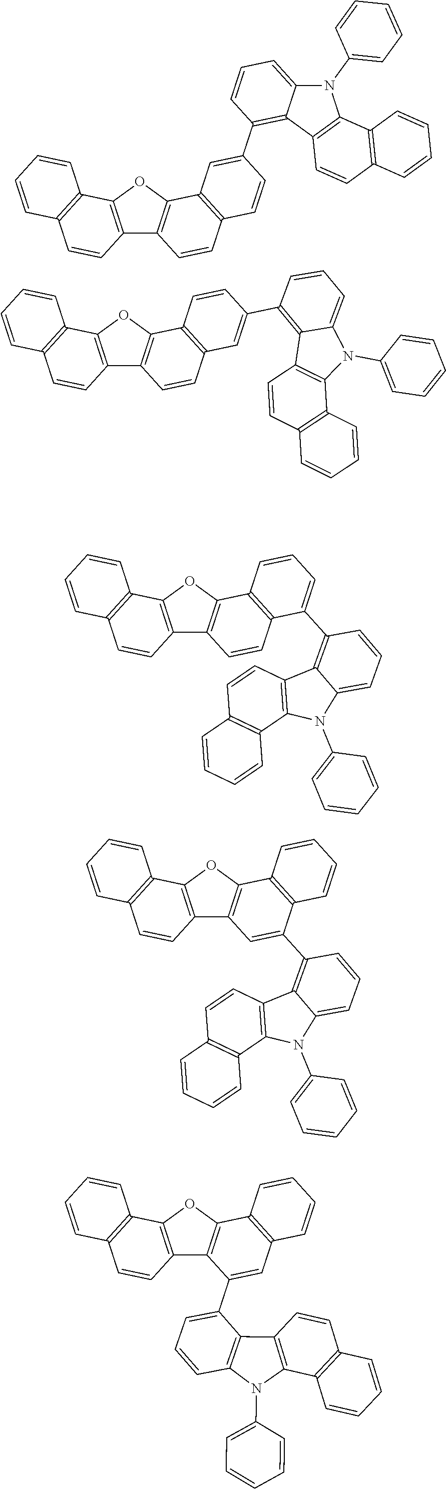

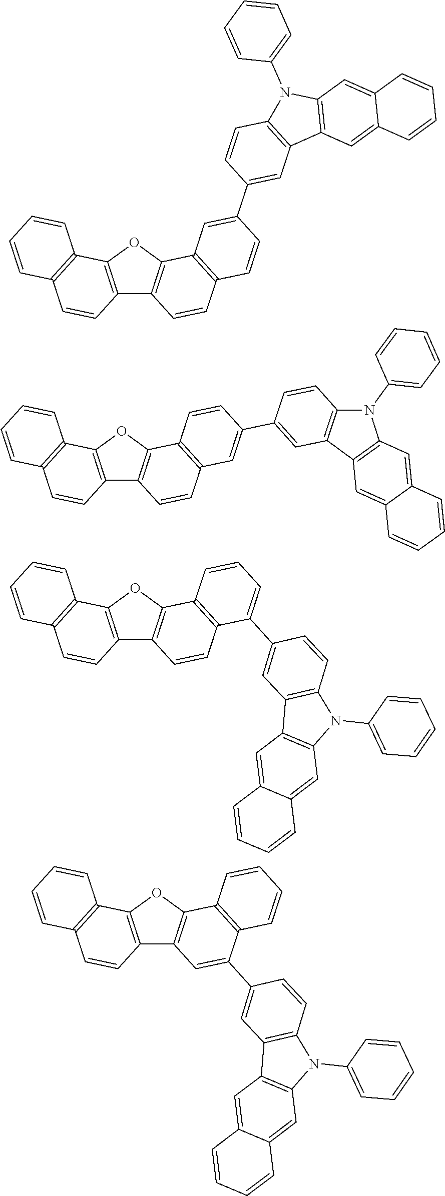

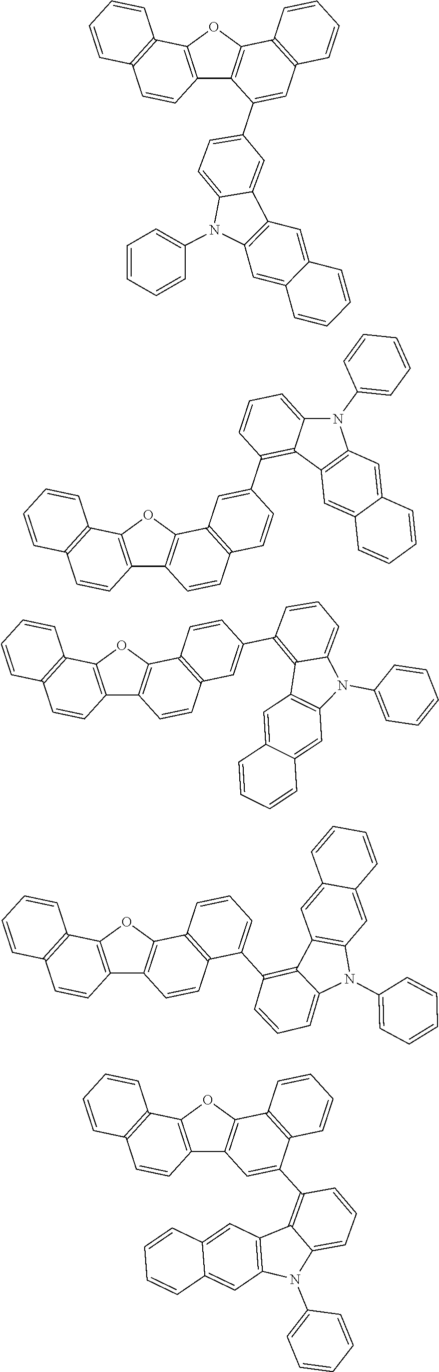

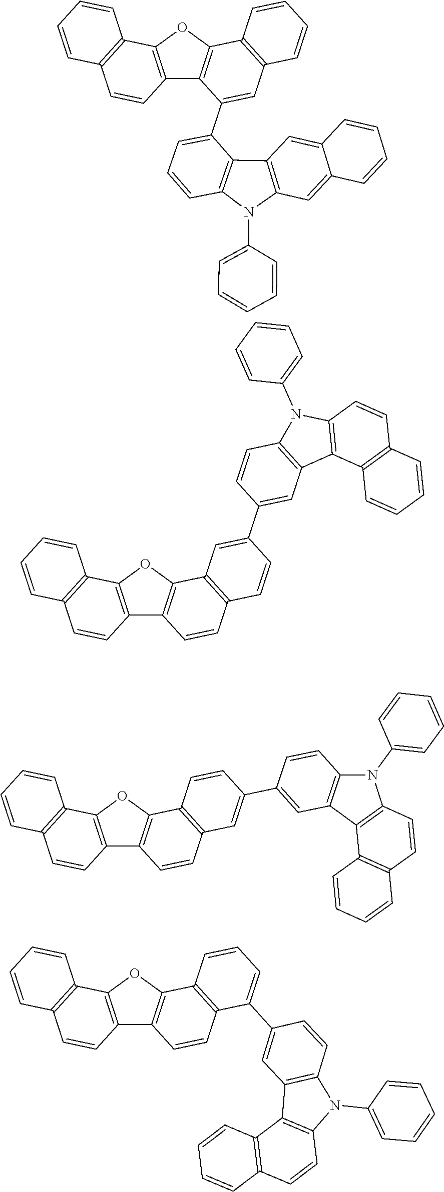

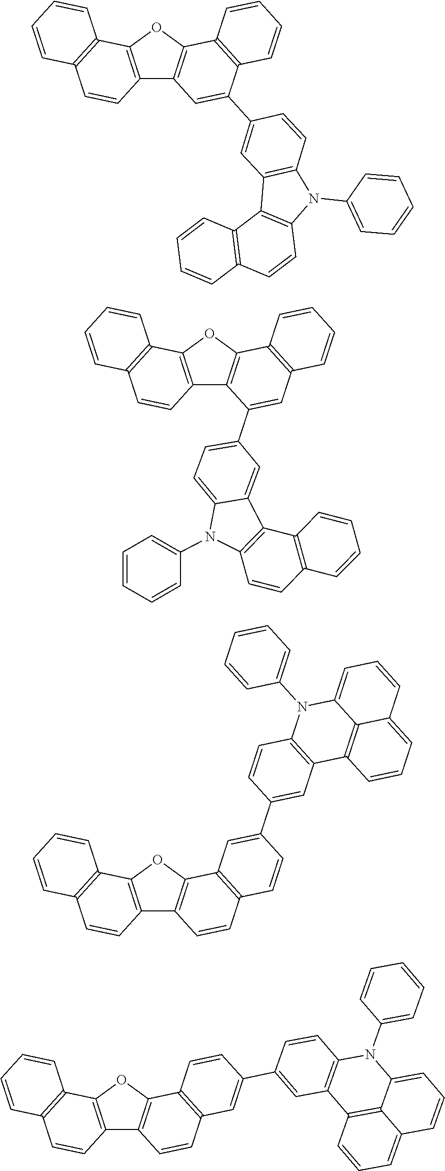

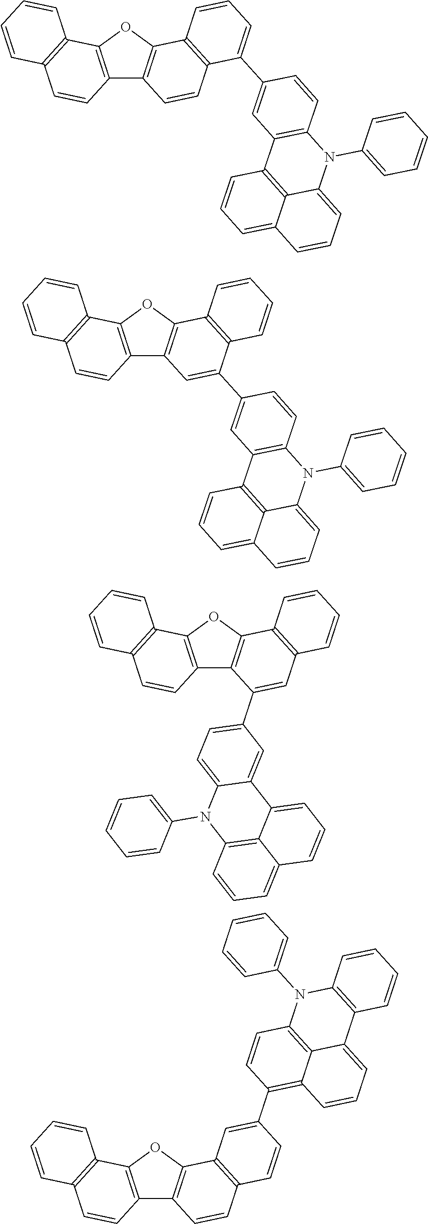

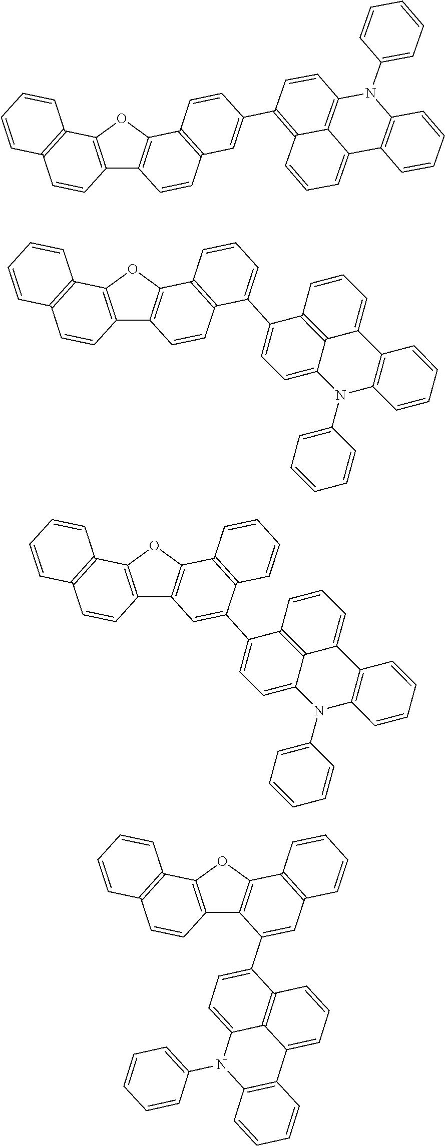

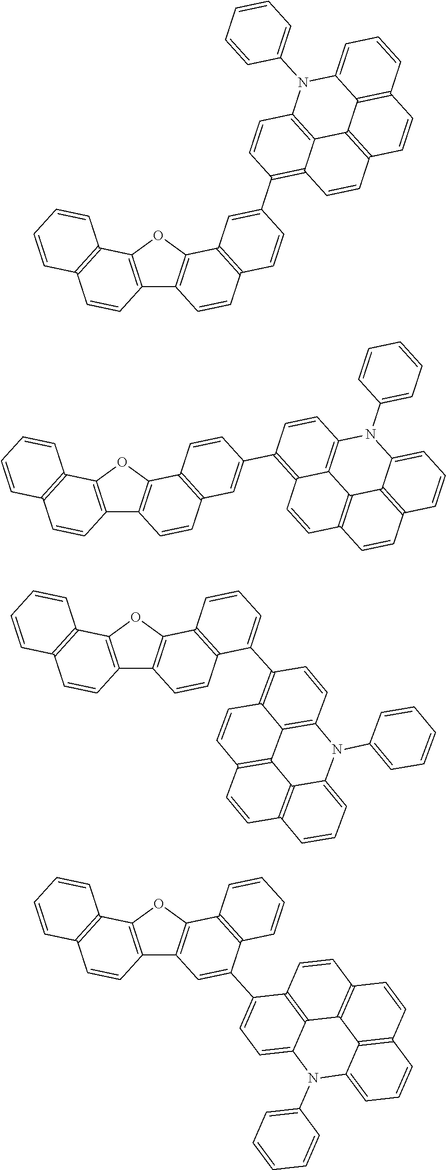 [SMILES: c1ccc(N2c3cccc4ccc5ccc6c(-c7ccc8ccc9c%10ccc%11ccccc%11c%10oc9c8c7)ccc2c6c5c34)cc1 ; c1ccc(N2c3cccc4ccc5ccc6c(-c7ccc8c(ccc9c%10ccc%11ccccc%11c%10oc89)c7)ccc2c6c5c34)cc1 ; c1ccc(N2c3cccc4ccc5ccc6c(-c7cccc8c7ccc7c9ccc%10ccccc%10c9oc87)ccc2c6c5c34)cc1 ; c1ccc(N2c3cccc4ccc5ccc6c(-c7cc8c9ccc%10ccccc%10c9oc8c8ccccc78)ccc2c6c5c34)cc1]

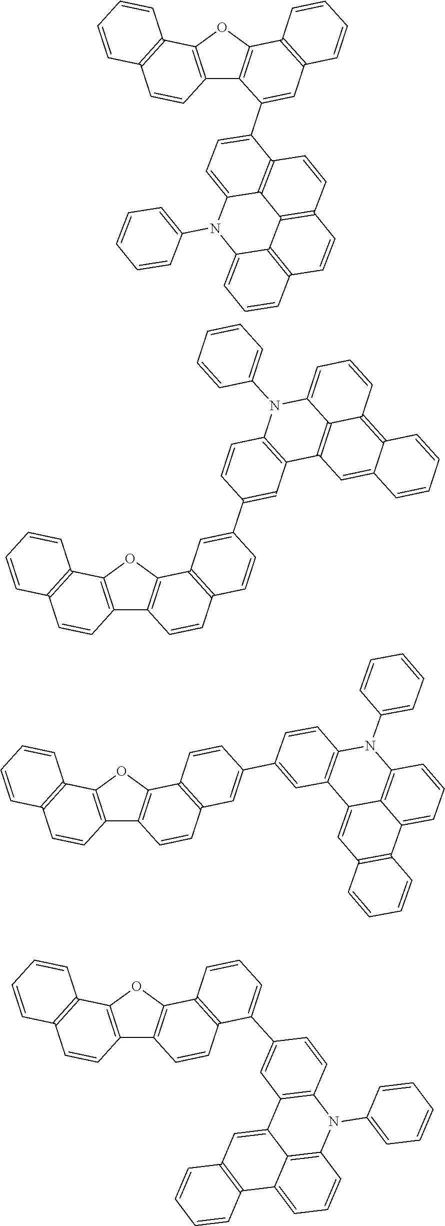

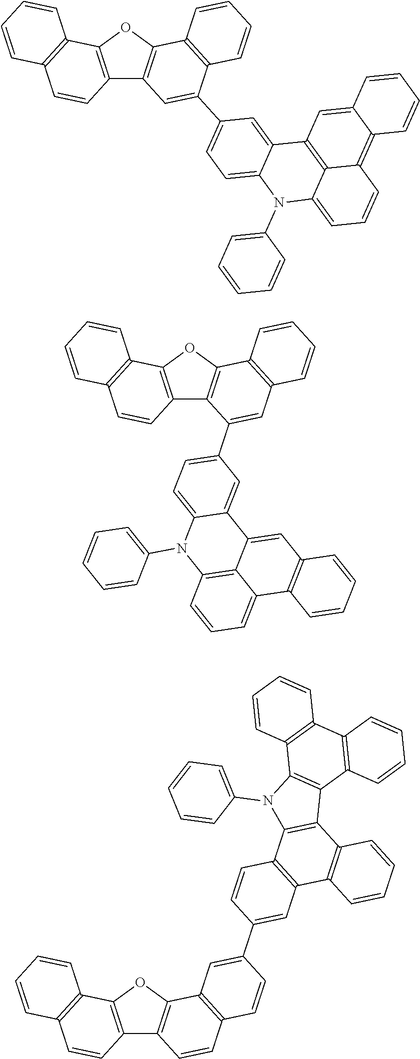

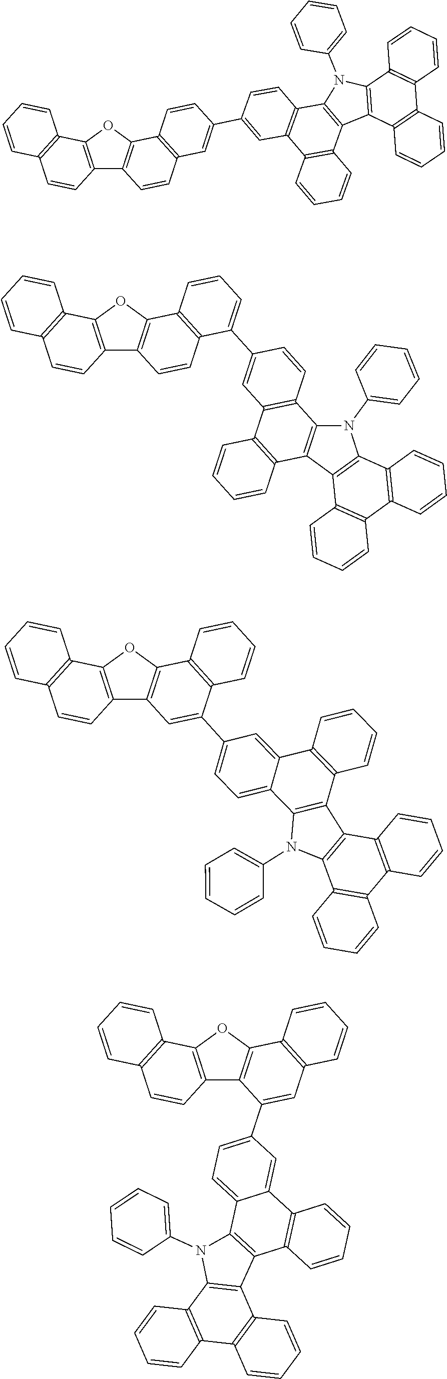 [SMILES: c1ccc(-n2c3c4ccccc4c4ccccc4c3c3c4ccccc4c4cc(-c5ccc6c(ccc7c8ccc9ccccc9c8oc67)c5)ccc4c32)cc1 ; c1ccc(-n2c3c4ccccc4c4ccccc4c3c3c4ccccc4c4cc(-c5cccc6c5ccc5c7ccc8ccccc8c7oc65)ccc4c32)cc1 ; c1ccc(-n2c3c4ccccc4c4ccccc4c3c3c4ccccc4c4cc(-c5cc6c7ccc8ccccc8c7oc6c6ccccc56)ccc4c32)cc1 ; c1ccc(-n2c3c4ccccc4c4ccccc4c3c3c4ccccc4c4cc(-c5cc6ccccc6c6oc7c8ccccc8ccc7c56)ccc4c32)cc1]

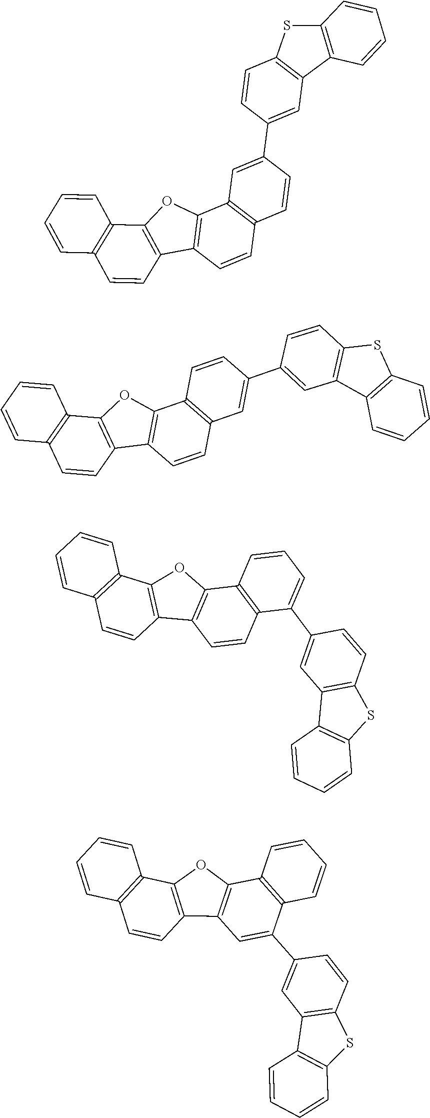 [SMILES: c1ccc2c(c1)ccc1c3ccc4ccc(-c5ccc6sc7ccccc7c6c5)cc4c3oc21 ; c1ccc2c(c1)ccc1c3ccc4cc(-c5ccc6sc7ccccc7c6c5)ccc4c3oc21 ; c1ccc2c(c1)ccc1c3ccc4c(-c5ccc6sc7ccccc7c6c5)cccc4c3oc21 ; c1ccc2c(c1)ccc1c3cc(-c4ccc5sc6ccccc6c5c4)c4ccccc4c3oc21]

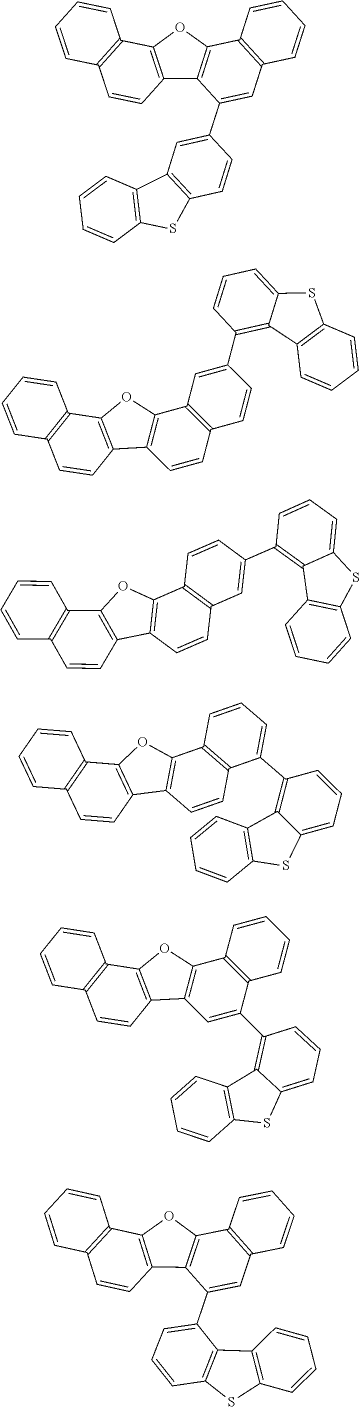

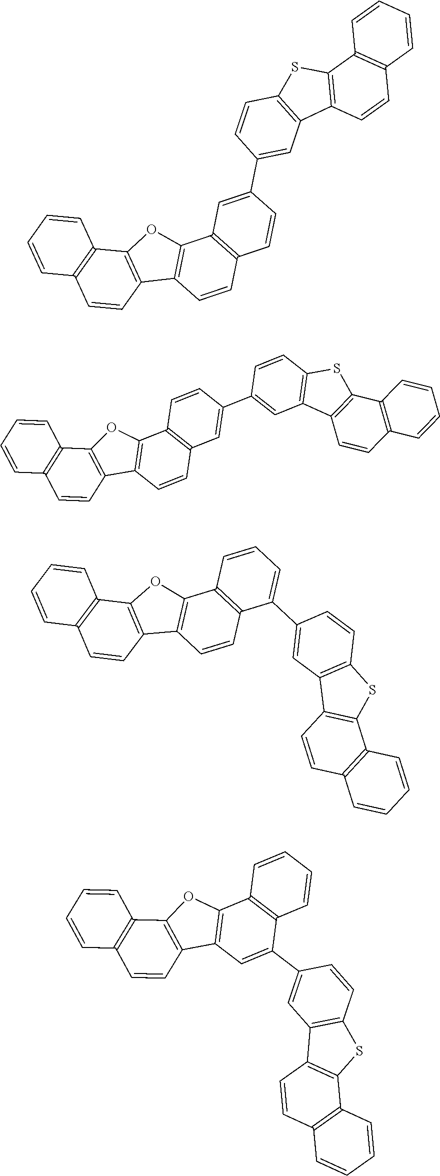 [SMILES: c1ccc2c(c1)ccc1c3ccc4ccc(-c5ccc6sc7c8ccccc8ccc7c6c5)cc4c3oc21 ; c1ccc2c(c1)ccc1c3ccc4cc(-c5ccc6sc7c8ccccc8ccc7c6c5)ccc4c3oc21 ; c1ccc2c(c1)ccc1c3ccc4c(-c5ccc6sc7c8ccccc8ccc7c6c5)cccc4c3oc21 ; c1ccc2c(c1)ccc1c3cc(-c4ccc5sc6c7ccccc7ccc6c5c4)c4ccccc4c3oc21]

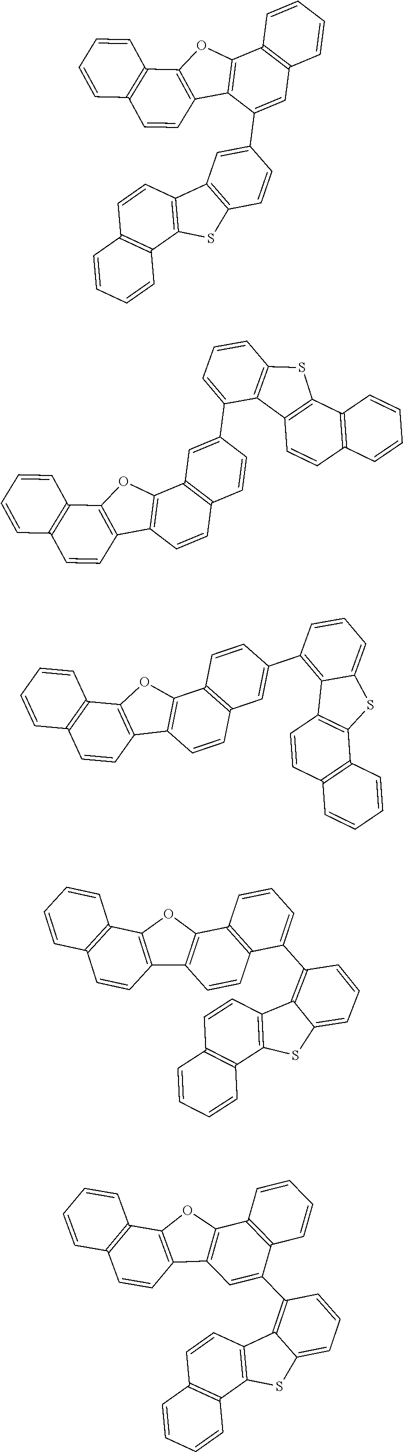 [SMILES: c1ccc2c(c1)ccc1c2oc2c3ccccc3cc(-c3ccc4sc5c6ccccc6ccc5c4c3)c12 ; c1ccc2c(c1)ccc1c3ccc4ccc(-c5cccc6sc7c8ccccc8ccc7c56)cc4c3oc21 ; c1ccc2c(c1)ccc1c3ccc4cc(-c5cccc6sc7c8ccccc8ccc7c56)ccc4c3oc21 ; c1ccc2c(c1)ccc1c3ccc4c(-c5cccc6sc7c8ccccc8ccc7c56)cccc4c3oc21 ; c1ccc2c(c1)ccc1c3cc(-c4cccc5sc6c7ccccc7ccc6c45)c4ccccc4c3oc21]

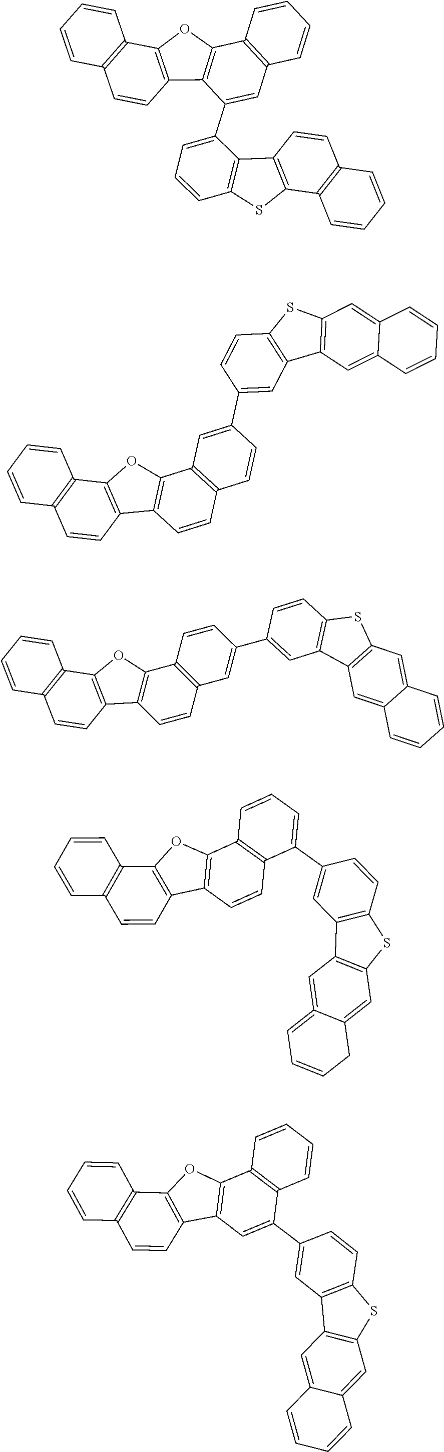

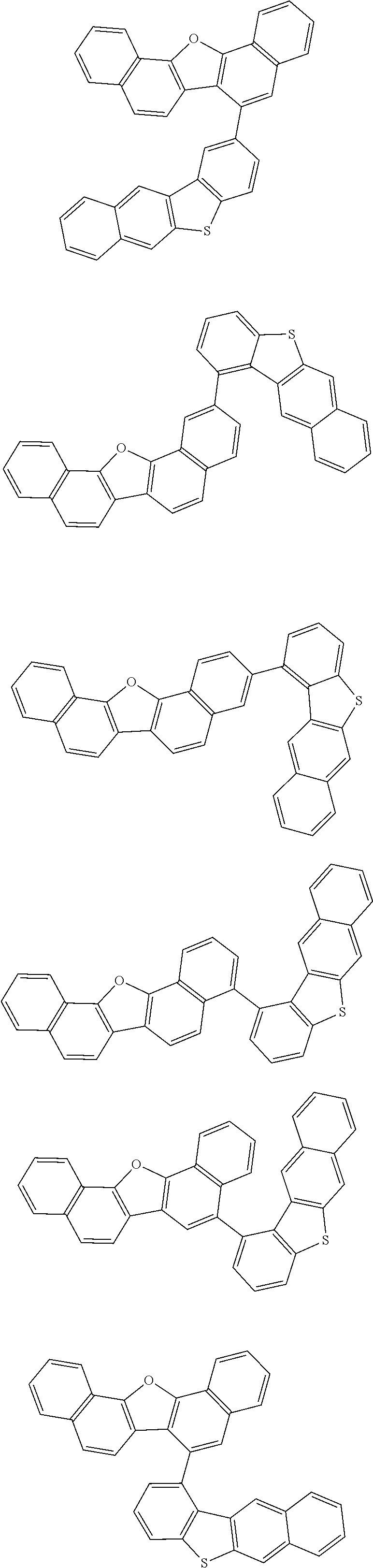

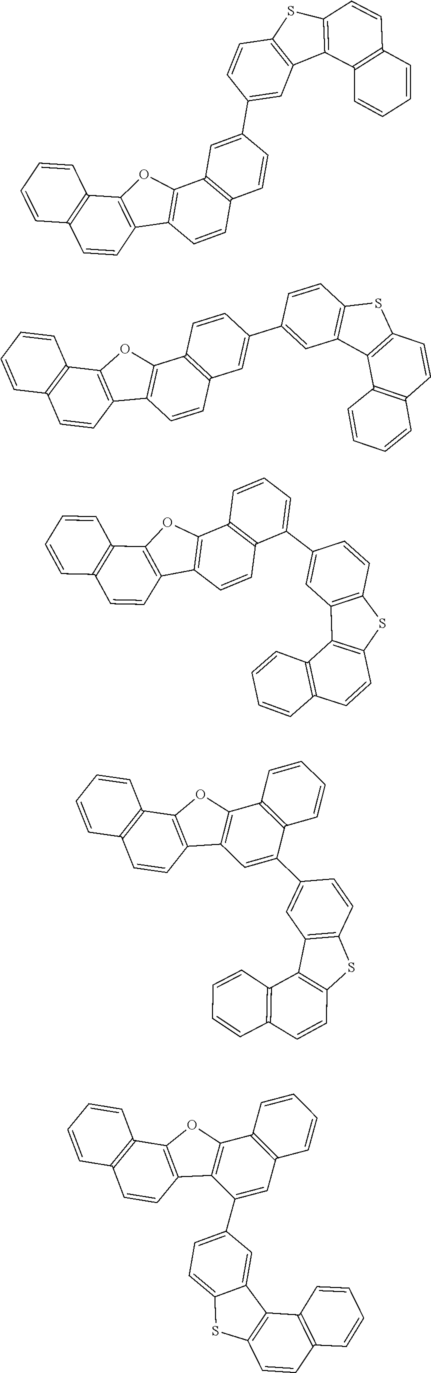

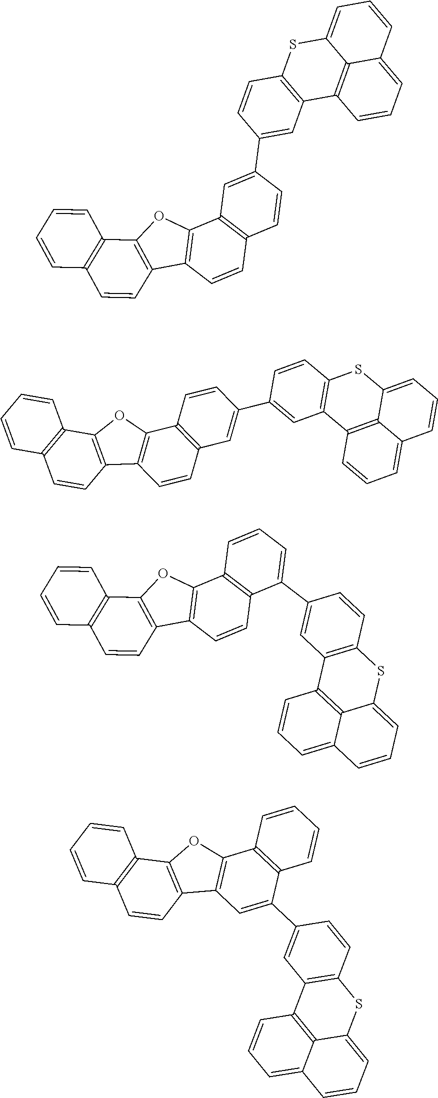 [SMILES: c1cc2c3c(cccc3c1)-c1cc(-c3ccc4ccc5c6ccc7ccccc7c6oc5c4c3)ccc1S2 ; c1cc2c3c(cccc3c1)-c1cc(-c3ccc4c(ccc5c6ccc7ccccc7c6oc45)c3)ccc1S2 ; c1cc2c3c(cccc3c1)-c1cc(-c3cccc4c3ccc3c5ccc6ccccc6c5oc43)ccc1S2 ; c1cc2c3c(cccc3c1)-c1cc(-c3cc4c5ccc6ccccc6c5oc4c4ccccc34)ccc1S2]

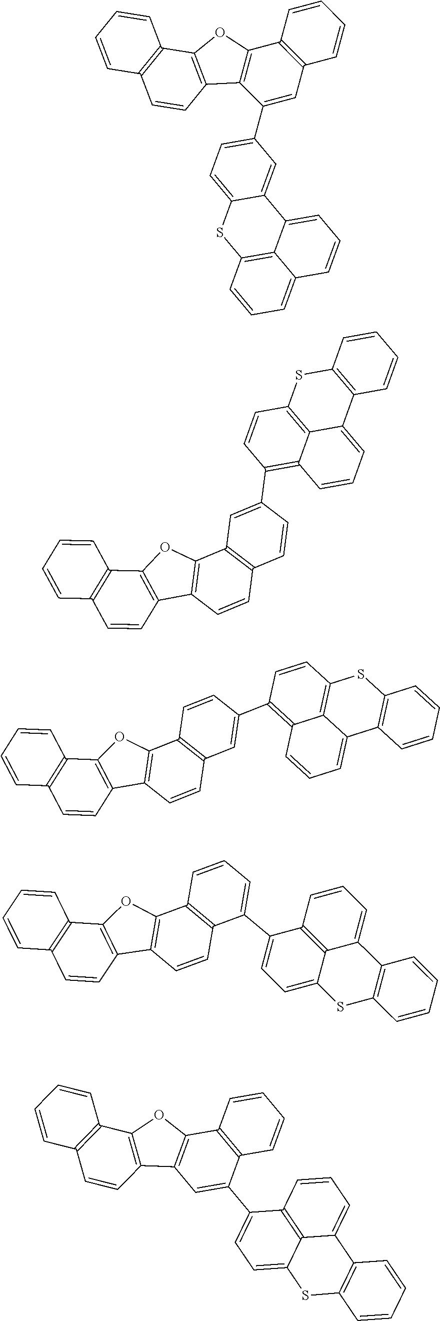 [SMILES: c1cc2c3c(cccc3c1)-c1cc(-c3cc4ccccc4c4oc5c6ccccc6ccc5c34)ccc1S2 ; c1ccc2c(c1)Sc1ccc(-c3ccc4ccc5c6ccc7ccccc7c6oc5c4c3)c3cccc-2c13 ; c1ccc2c(c1)Sc1ccc(-c3ccc4c(ccc5c6ccc7ccccc7c6oc45)c3)c3cccc-2c13 ; c1ccc2c(c1)Sc1ccc(-c3cccc4c3ccc3c5ccc6ccccc6c5oc43)c3cccc-2c13 ; c1ccc2c(c1)Sc1ccc(-c3cc4c5ccc6ccccc6c5oc4c4ccccc34)c3cccc-2c13]

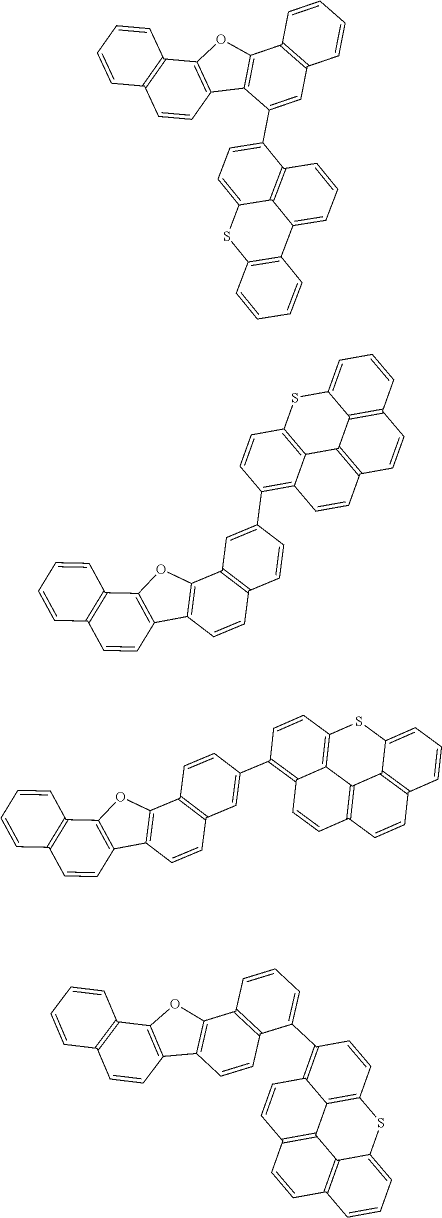 [SMILES: c1ccc2c(c1)Sc1ccc(-c3cc4ccccc4c4oc5c6ccccc6ccc5c34)c3cccc-2c13 ; c1ccc2c(c1)ccc1c3ccc4ccc(-c5ccc6c7c5ccc5ccc8cccc(c8c57)S6)cc4c3oc21 ; c1ccc2c(c1)ccc1c3ccc4cc(-c5ccc6c7c5ccc5ccc8cccc(c8c57)S6)ccc4c3oc21 ; c1ccc2c(c1)ccc1c3ccc4c(-c5ccc6c7c5ccc5ccc8cccc(c8c57)S6)cccc4c3oc21]

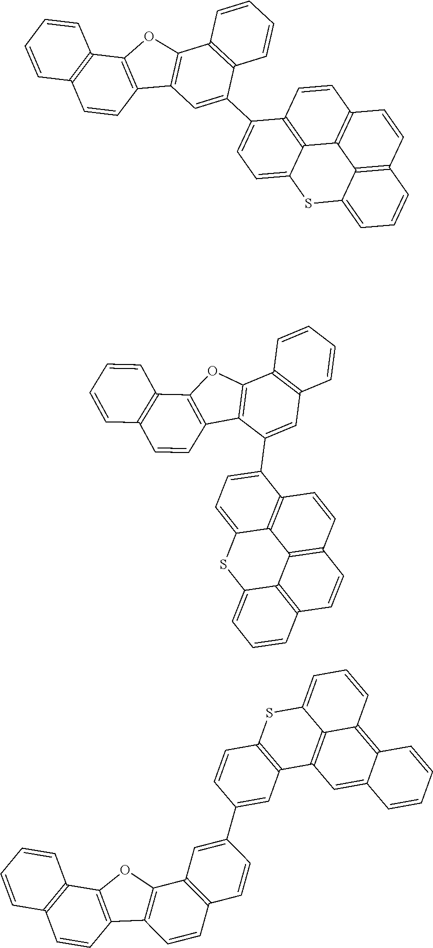

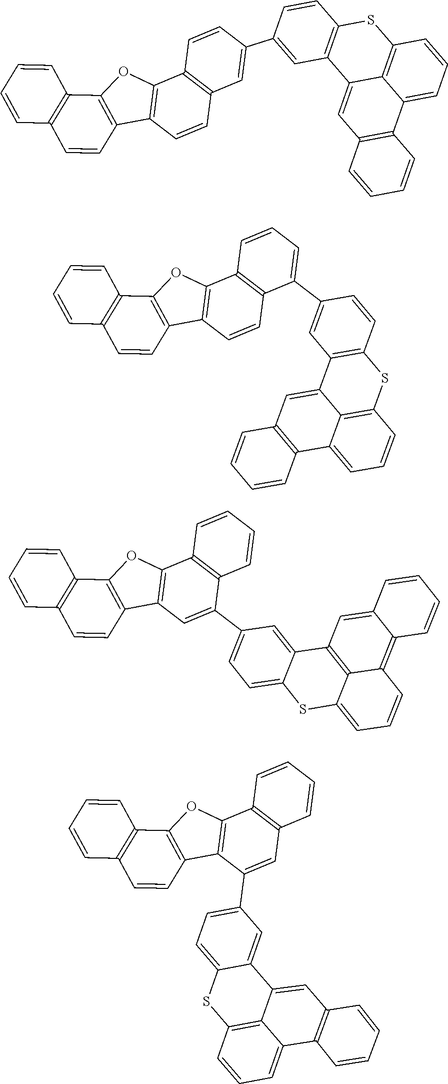

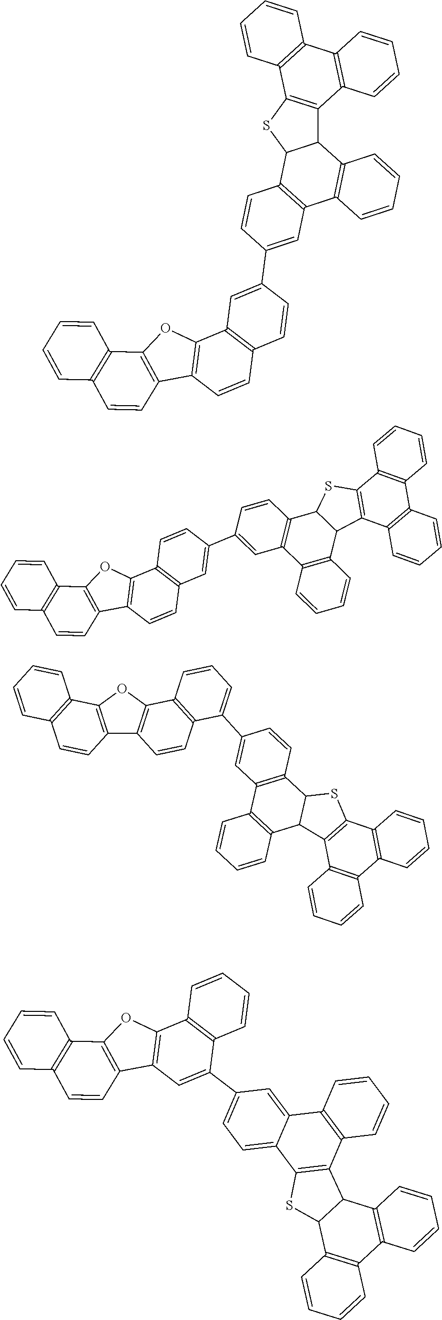

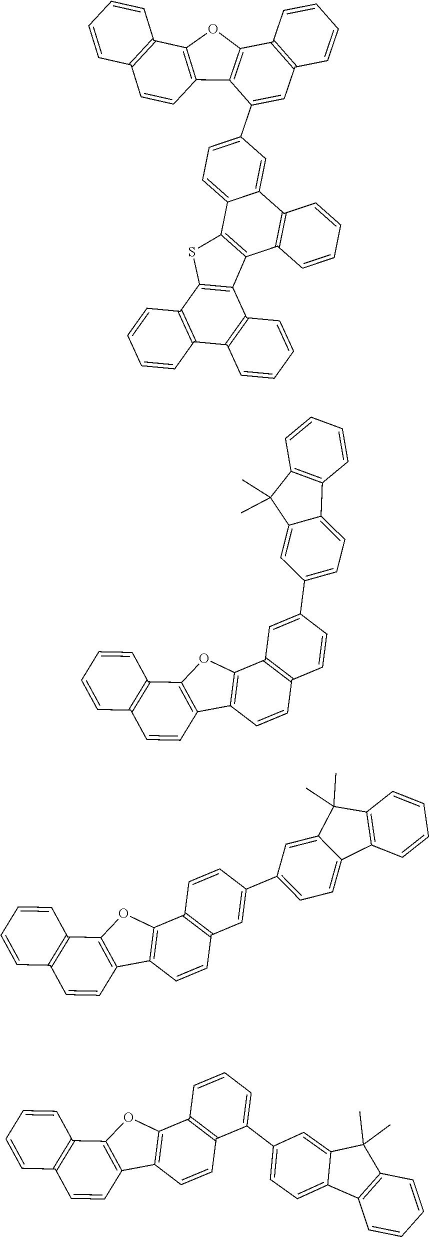 [SMILES: c1ccc2c(c1)ccc1c2oc2c3ccccc3cc(-c3ccc4c(c3)c3ccccc3c3c4sc4c5ccccc5c5ccccc5c43)c12 ; CC1(C)c2ccccc2-c2ccc(-c3ccc4ccc5c6ccc7ccccc7c6oc5c4c3)cc21 ; CC1(C)c2ccccc2-c2ccc(-c3ccc4c(ccc5c6ccc7ccccc7c6oc45)c3)cc21 ; CC1(C)c2ccccc2-c2ccc(-c3cccc4c3ccc3c5ccc6ccccc6c5oc43)cc21]

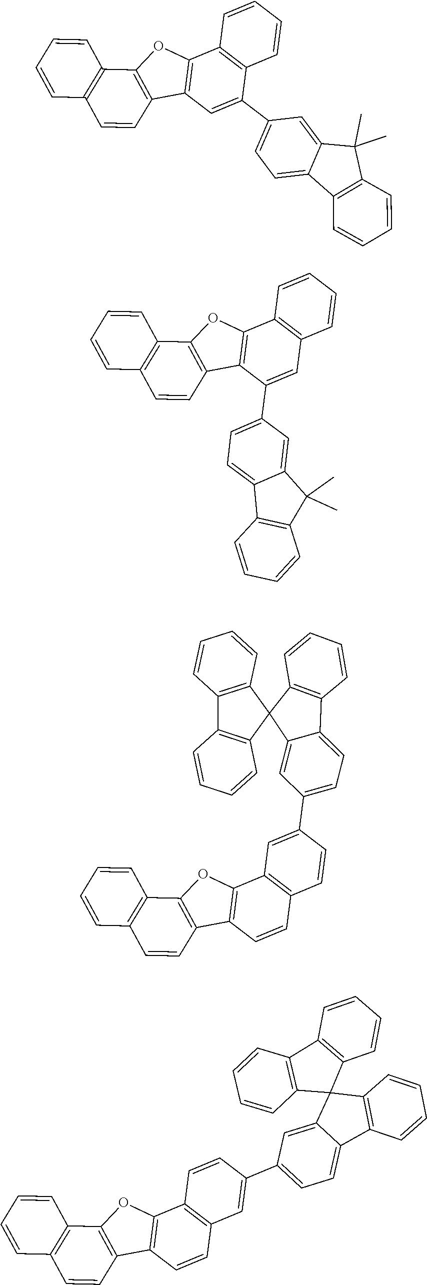 [SMILES: CC1(C)c2ccccc2-c2ccc(-c3cc4c5ccc6ccccc6c5oc4c4ccccc34)cc21 ; CC1(C)c2ccccc2-c2ccc(-c3cc4ccccc4c4oc5c6ccccc6ccc5c34)cc21 ; c1ccc2c(c1)-c1ccccc1C21c2ccccc2-c2ccc(-c3ccc4ccc5c6ccc7ccccc7c6oc5c4c3)cc21 ; c1ccc2c(c1)-c1ccccc1C21c2ccccc2-c2ccc(-c3ccc4c(ccc5c6ccc7ccccc7c6oc45)c3)cc21]

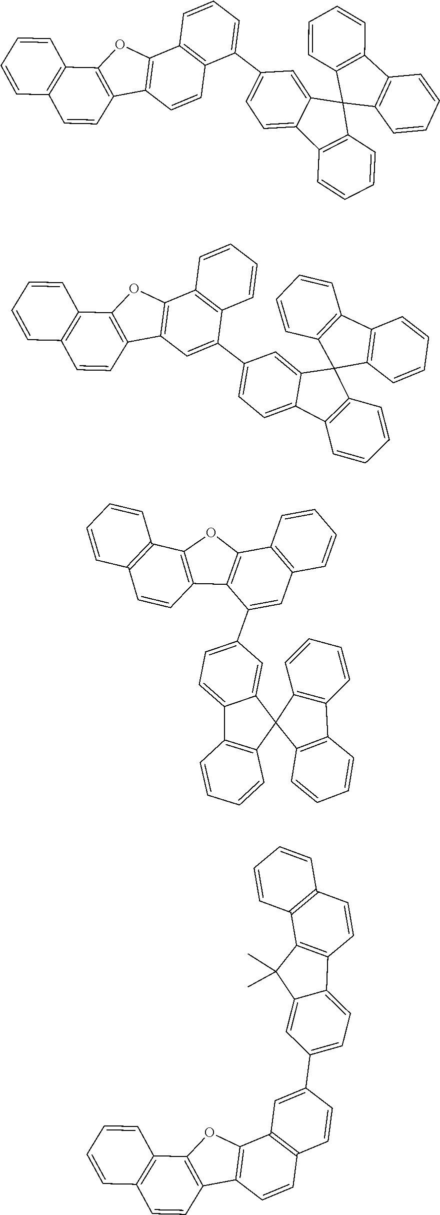 [SMILES: c1ccc2c(c1)-c1ccccc1C21c2ccccc2-c2ccc(-c3cccc4c3ccc3c5ccc6ccccc6c5oc43)cc21 ; c1ccc2c(c1)-c1ccccc1C21c2ccccc2-c2ccc(-c3cc4c5ccc6ccccc6c5oc4c4ccccc34)cc21 ; c1ccc2c(c1)-c1ccccc1C21c2ccccc2-c2ccc(-c3cc4ccccc4c4oc5c6ccccc6ccc5c34)cc21 ; CC1(C)c2cc(-c3ccc4ccc5c6ccc7ccccc7c6oc5c4c3)ccc2-c2ccc3ccccc3c21]

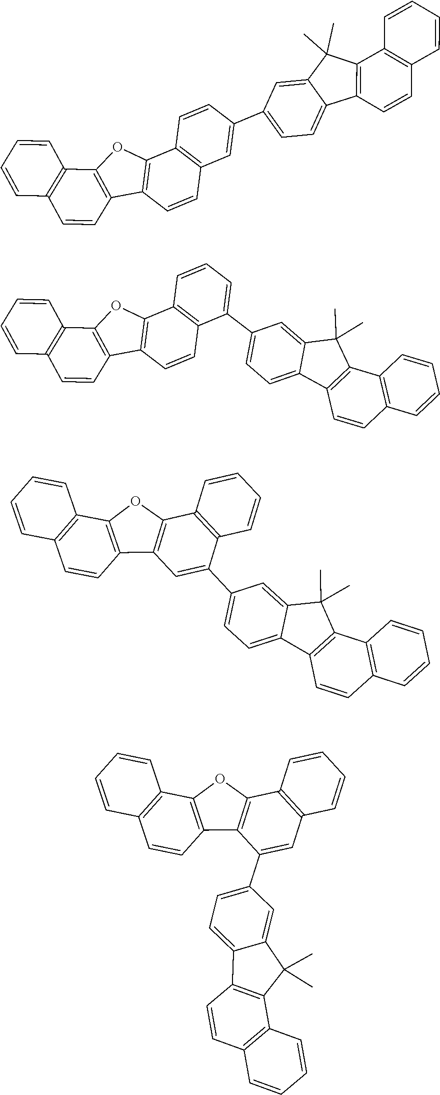 [SMILES: CC1(C)c2cc(-c3ccc4c(ccc5c6ccc7ccccc7c6oc45)c3)ccc2-c2ccc3ccccc3c21 ; CC1(C)c2cc(-c3cccc4c3ccc3c5ccc6ccccc6c5oc43)ccc2-c2ccc3ccccc3c21 ; CC1(C)c2cc(-c3cc4c5ccc6ccccc6c5oc4c4ccccc34)ccc2-c2ccc3ccccc3c21 ; CC1(C)c2cc(-c3cc4ccccc4c4oc5c6ccccc6ccc5c34)ccc2-c2ccc3ccccc3c21]

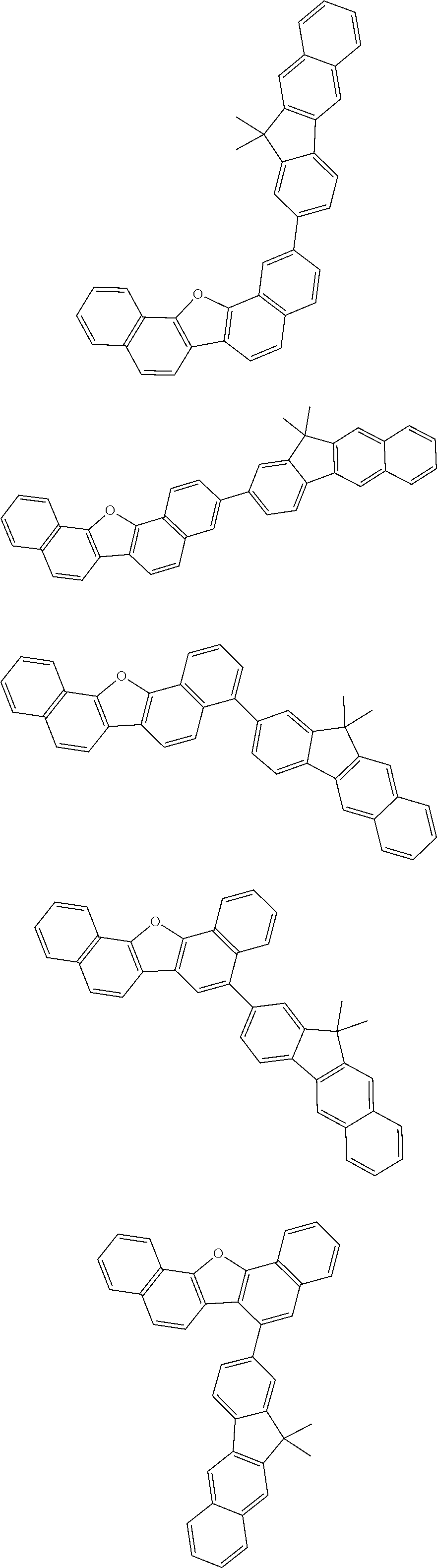 [SMILES: CC1(C)c2cc(-c3ccc4ccc5c6ccc7ccccc7c6oc5c4c3)ccc2-c2cc3ccccc3cc21 ; CC1(C)c2cc(-c3ccc4c(ccc5c6ccc7ccccc7c6oc45)c3)ccc2-c2cc3ccccc3cc21 ; CC1(C)c2cc(-c3cccc4c3ccc3c5ccc6ccccc6c5oc43)ccc2-c2cc3ccccc3cc21 ; CC1(C)c2cc(-c3cc4c5ccc6ccccc6c5oc4c4ccccc34)ccc2-c2cc3ccccc3cc21 ; CC1(C)c2cc(-c3cc4ccccc4c4oc5c6ccccc6ccc5c34)ccc2-c2cc3ccccc3cc21]

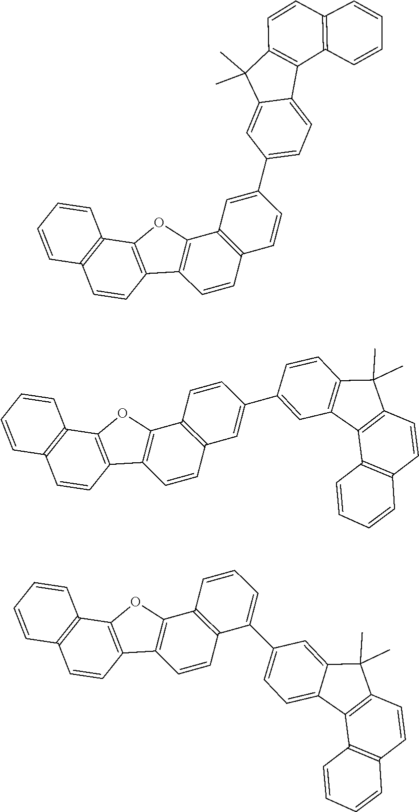 [SMILES: CC1(C)c2cc(-c3ccc4ccc5c6ccc7ccccc7c6oc5c4c3)ccc2-c2c1ccc1ccccc21 ; CC1(C)c2ccc(-c3ccc4c(ccc5c6ccc7ccccc7c6oc45)c3)cc2-c2c1ccc1ccccc21 ; CC1(C)c2cc(-c3cccc4c3ccc3c5ccc6ccccc6c5oc43)ccc2-c2c1ccc1ccccc21]

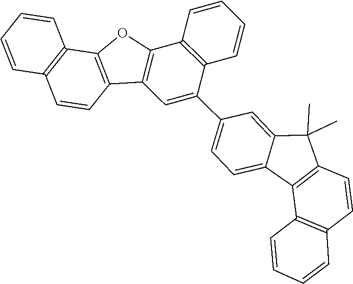 [SMILES: CC1(C)c2cc(-c3cc4c5ccc6ccccc6c5oc4c4ccccc34)ccc2-c2c1ccc1ccccc21]

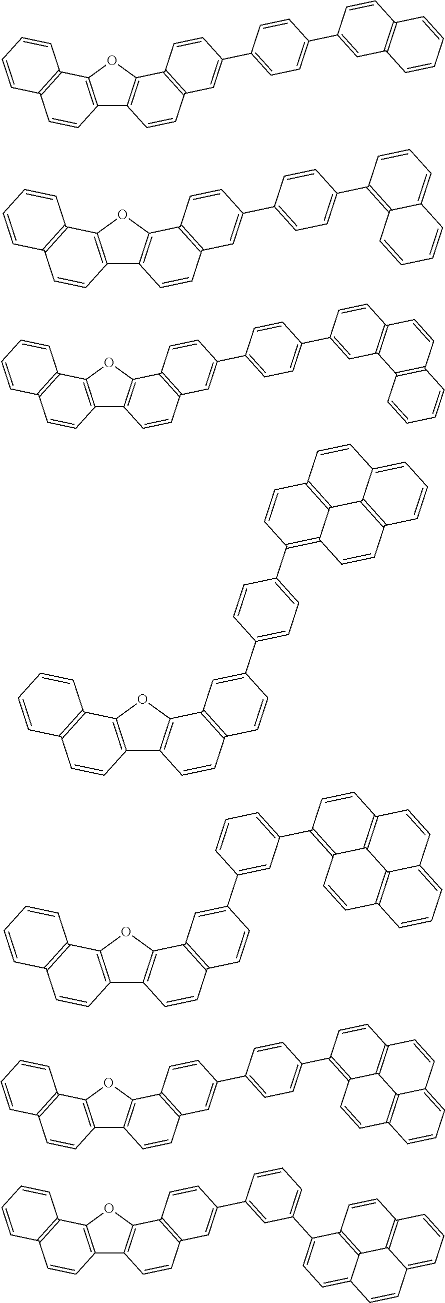

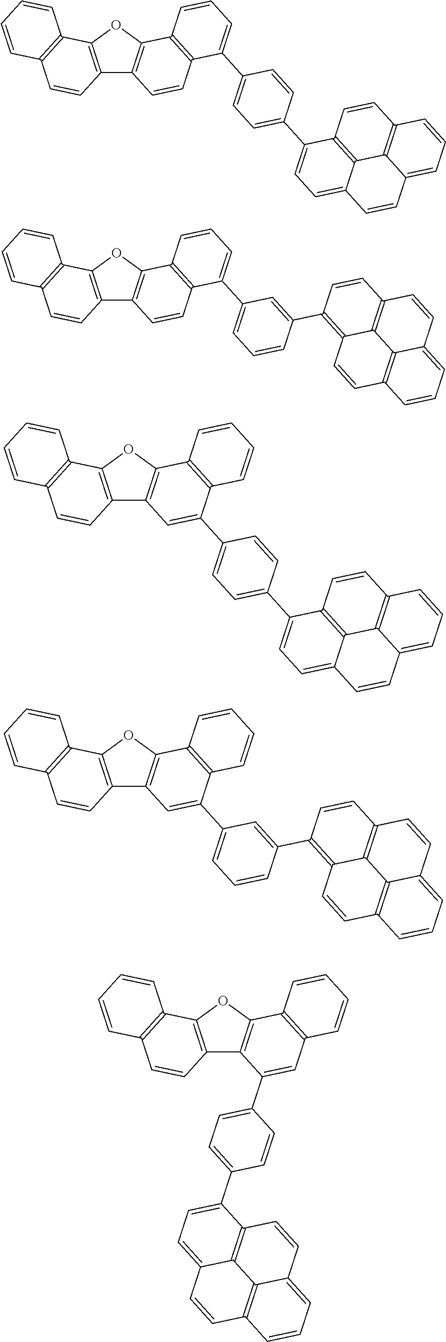 [SMILES: c1ccc2c(c1)ccc1c3ccc4c(-c5ccc(-c6ccc7ccc8cccc9ccc6c7c89)cc5)cccc4c3oc21 ; c1cc(-c2cccc3c2ccc2c4ccc5ccccc5c4oc32)cc(-c2ccc3ccc4cccc5ccc2c3c45)c1 ; c1ccc2c(c1)ccc1c3cc(-c4ccc(-c5ccc6ccc7cccc8ccc5c6c78)cc4)c4ccccc4c3oc21 ; c1cc(-c2cc3c4ccc5ccccc5c4oc3c3ccccc23)cc(-c2ccc3ccc4cccc5ccc2c3c45)c1 ; c1ccc2c(c1)ccc1c2oc2c3ccccc3cc(-c3ccc(-c4ccc5ccc6cccc7ccc4c5c67)cc3)c12]

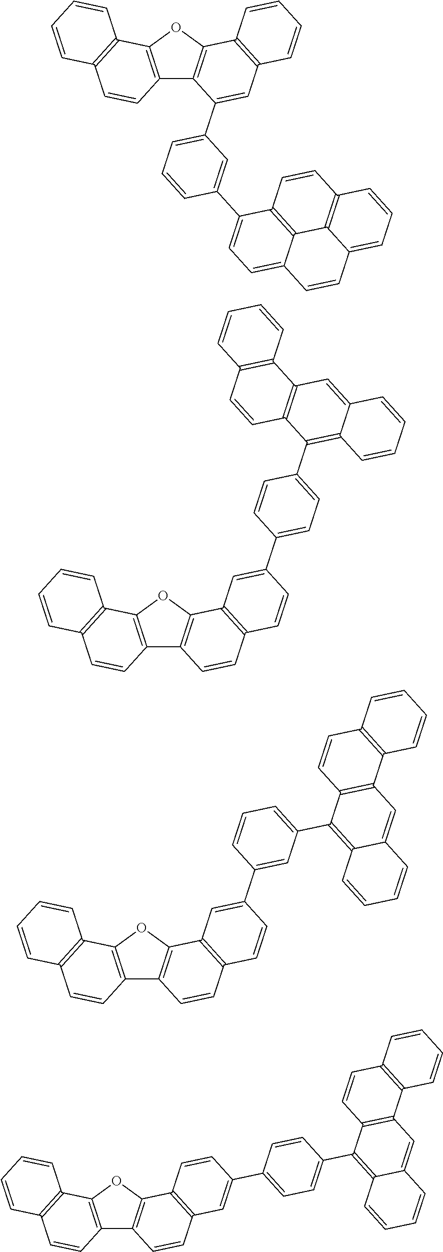

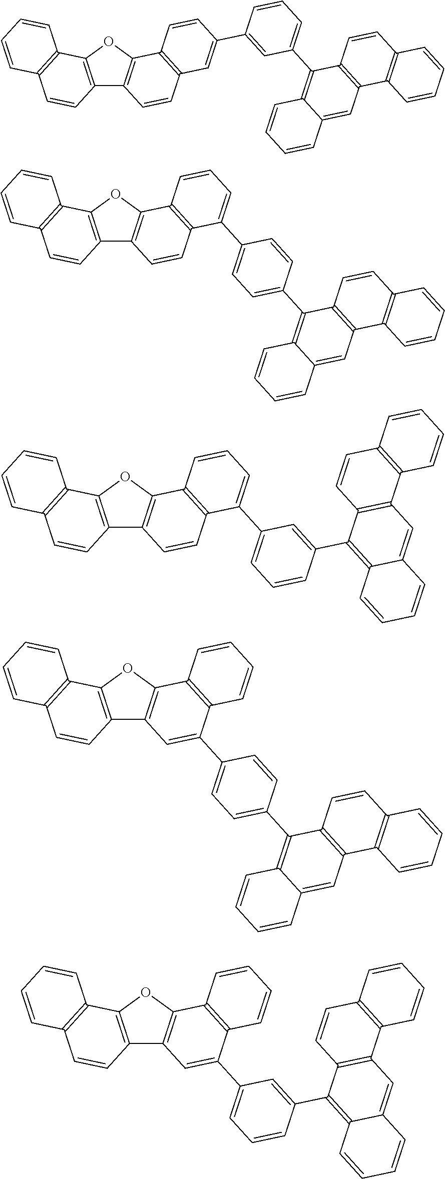

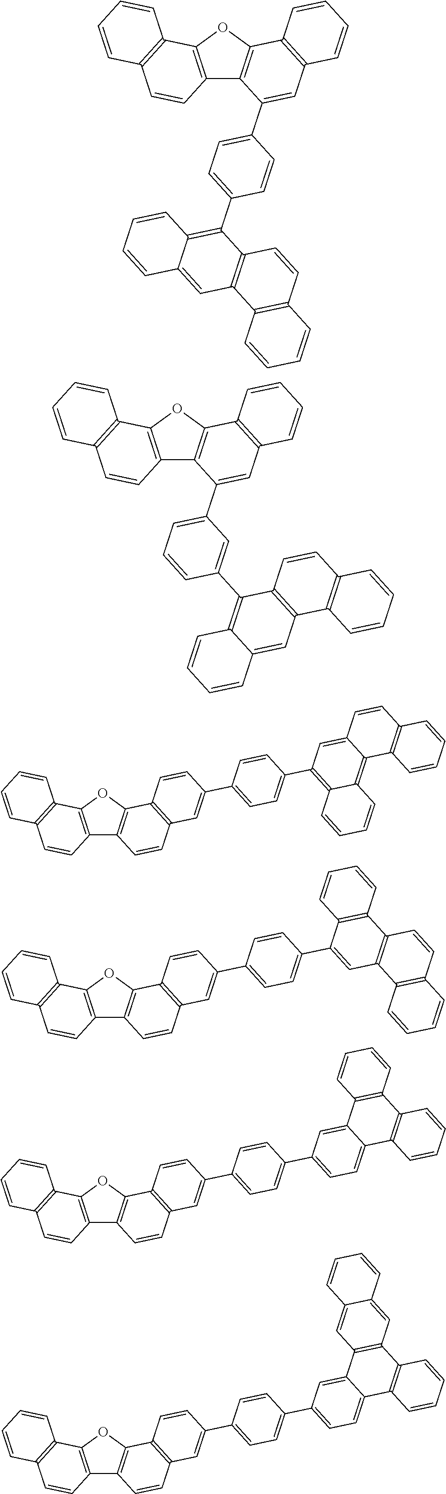

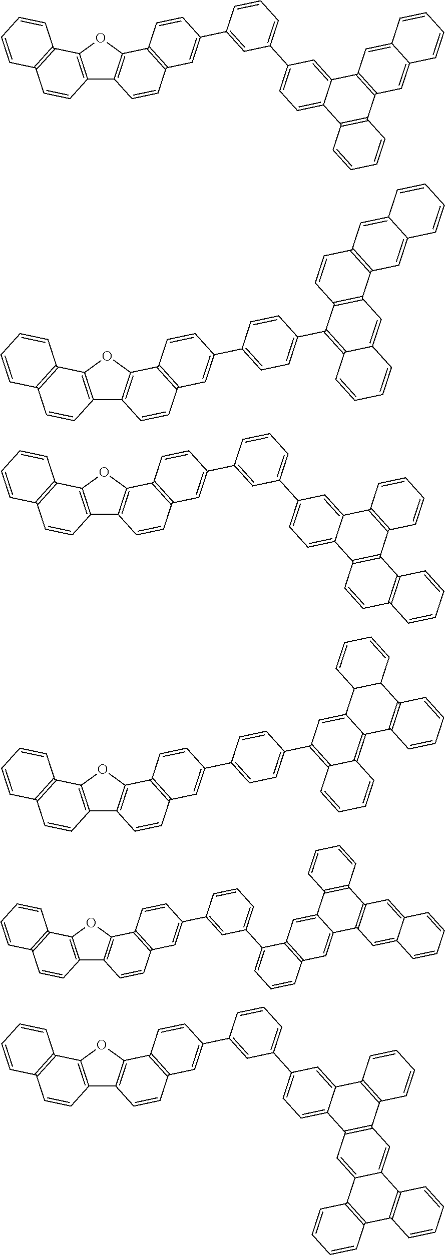

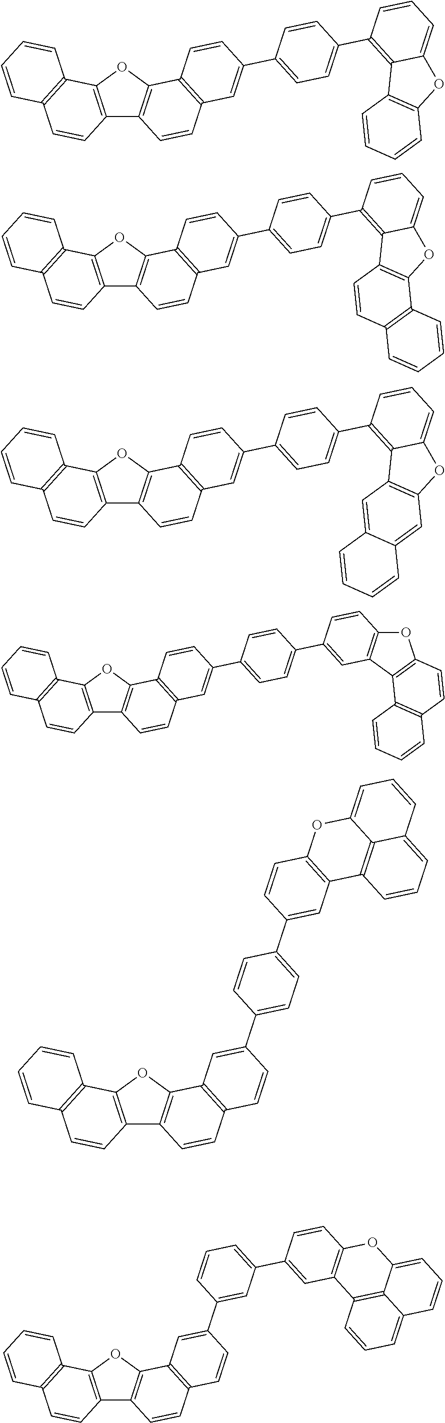

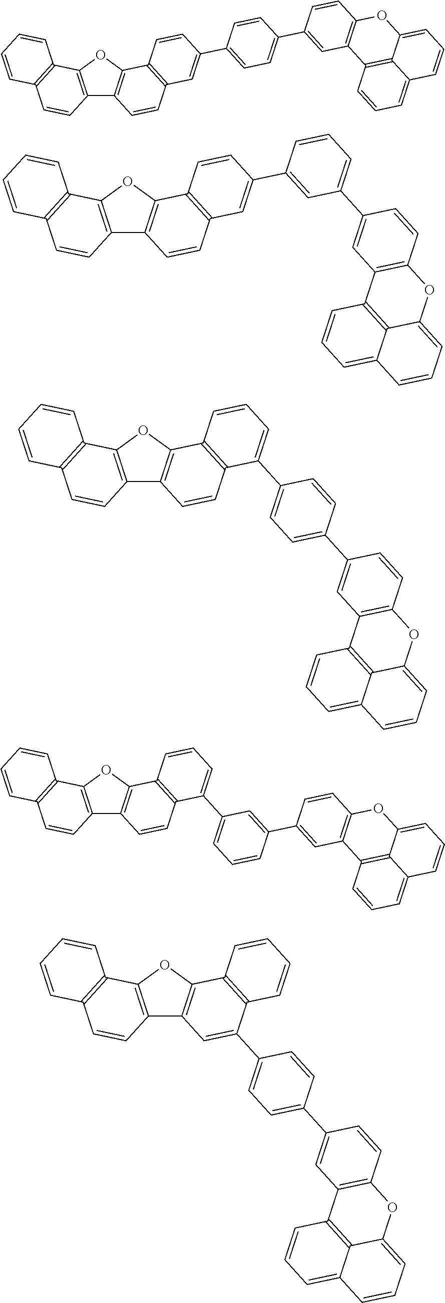 [SMILES: c1cc2c3c(cccc3c1)-c1cc(-c3ccc(-c4ccc5c(ccc6c7ccc8ccccc8c7oc56)c4)cc3)ccc1O2 ; c1cc(-c2ccc3c(c2)-c2cccc4cccc(c24)O3)cc(-c2ccc3c(ccc4c5ccc6ccccc6c5oc34)c2)c1 ; c1cc2c3c(cccc3c1)-c1cc(-c3ccc(-c4cccc5c4ccc4c6ccc7ccccc7c6oc54)cc3)ccc1O2 ; c1cc(-c2ccc3c(c2)-c2cccc4cccc(c24)O3)cc(-c2cccc3c2ccc2c4ccc5ccccc5c4oc32)c1 ; c1cc2c3c(cccc3c1)-c1cc(-c3ccc(-c4cc5c6ccc7ccccc7c6oc5c5ccccc45)cc3)ccc1O2]

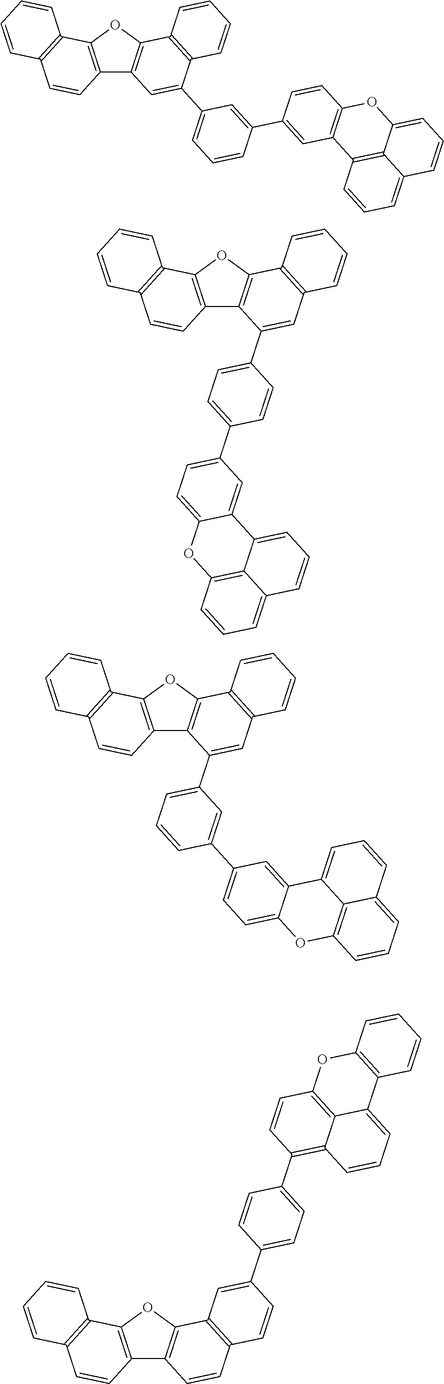

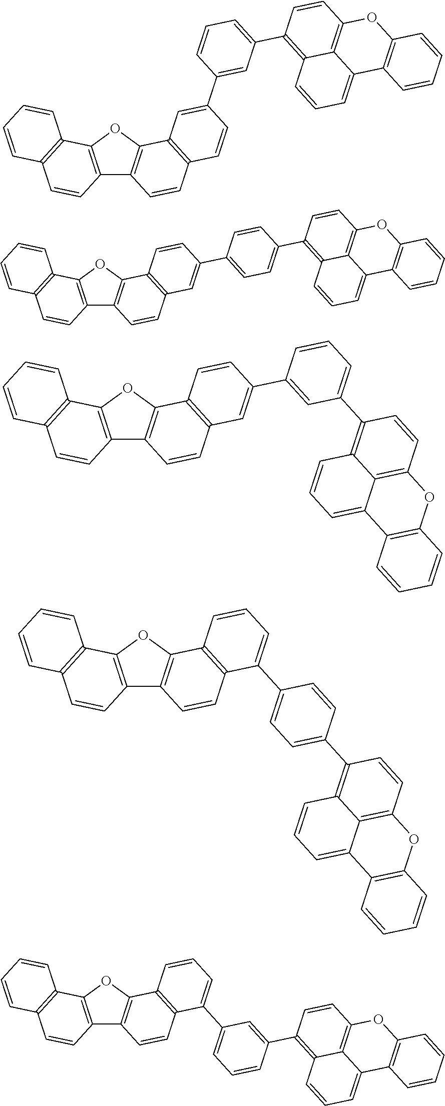

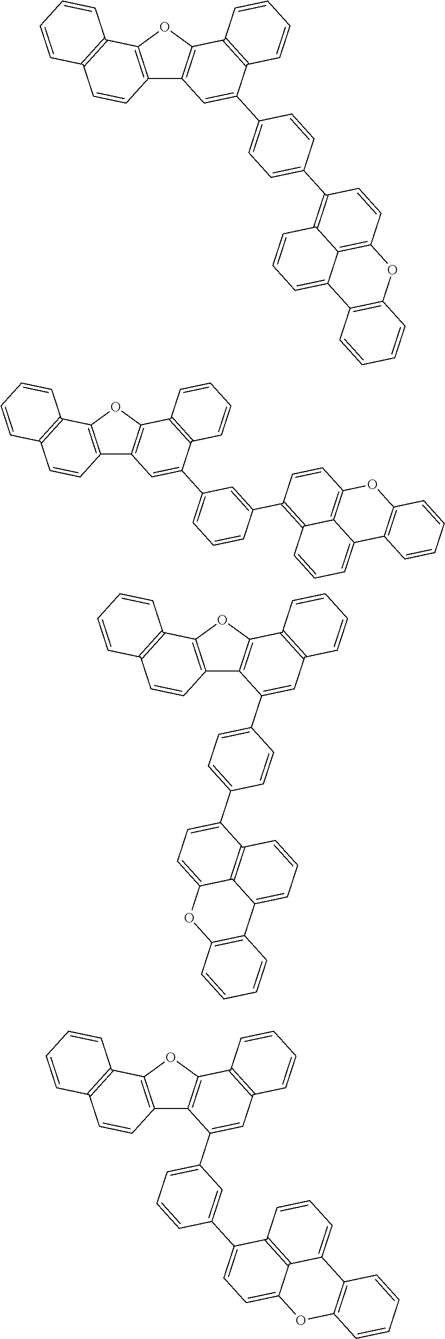

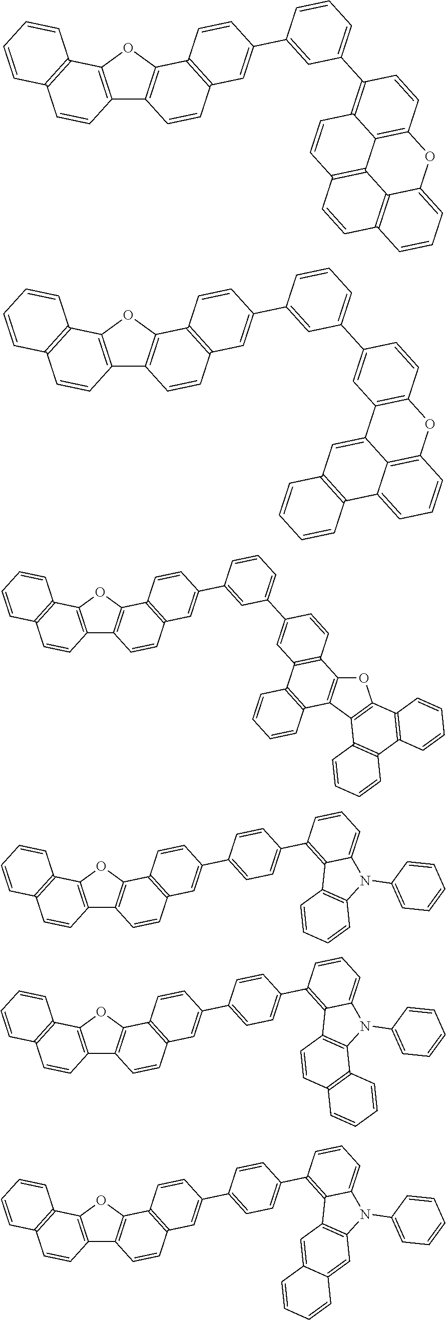

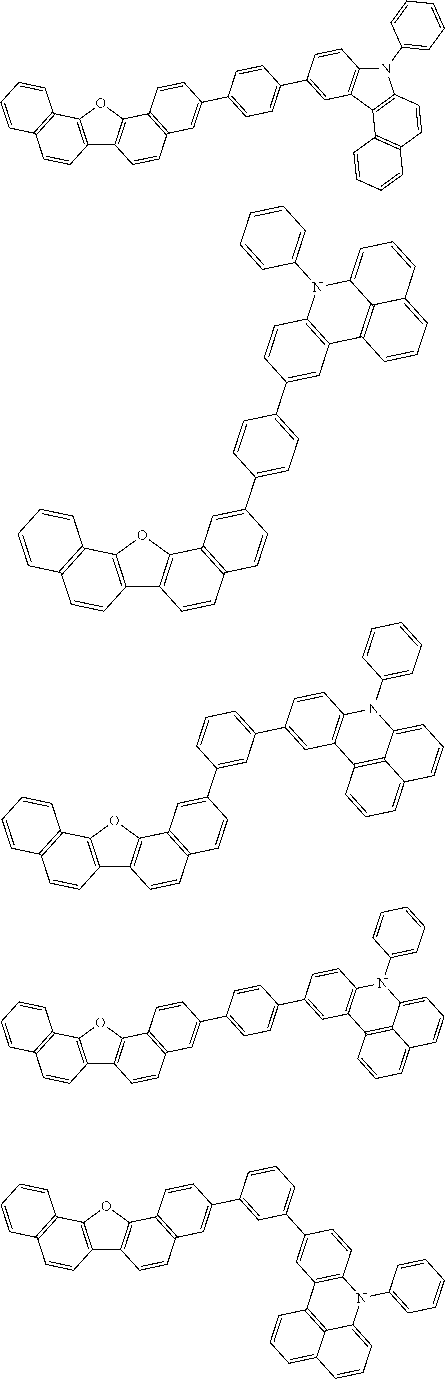 [SMILES: c1ccc(-n2c3ccc(-c4ccc(-c5ccc6c(ccc7c8ccc9ccccc9c8oc67)c5)cc4)cc3c3c4ccccc4ccc32)cc1 ; c1ccc(N2c3ccc(-c4ccc(-c5ccc6ccc7c8ccc9ccccc9c8oc7c6c5)cc4)cc3-c3cccc4cccc2c34)cc1 ; c1ccc(N2c3ccc(-c4cccc(-c5ccc6ccc7c8ccc9ccccc9c8oc7c6c5)c4)cc3-c3cccc4cccc2c34)cc1 ; c1ccc(N2c3ccc(-c4ccc(-c5ccc6c(ccc7c8ccc9ccccc9c8oc67)c5)cc4)cc3-c3cccc4cccc2c34)cc1 ; c1ccc(N2c3ccc(-c4cccc(-c5ccc6c(ccc7c8ccc9ccccc9c8oc67)c5)c4)cc3-c3cccc4cccc2c34)cc1]

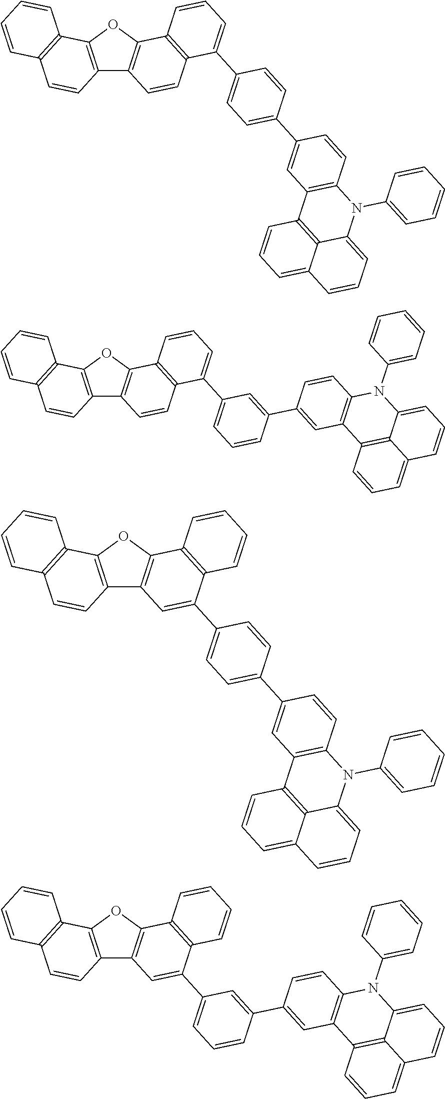

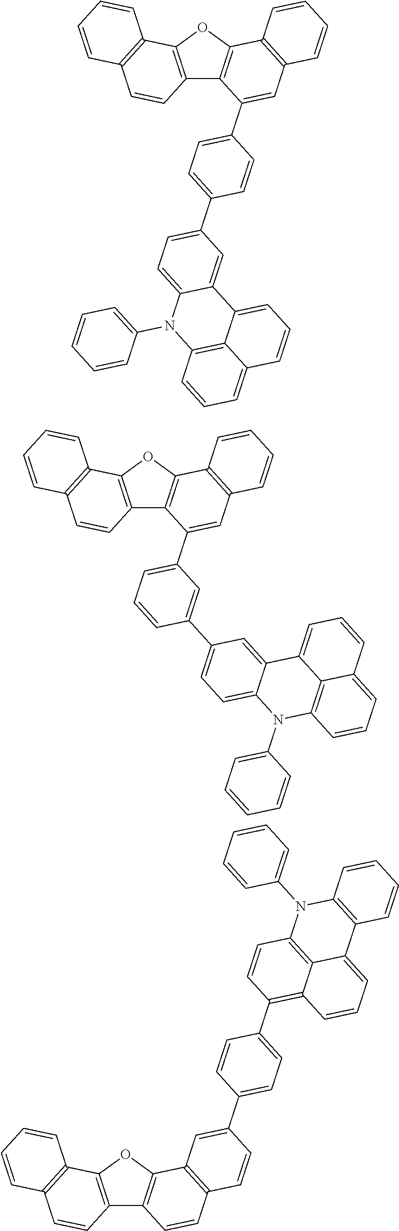

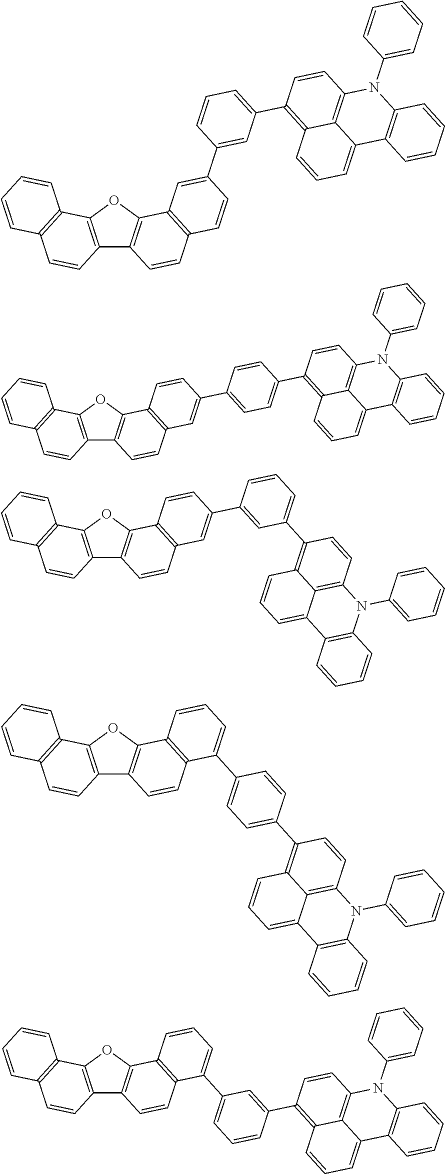

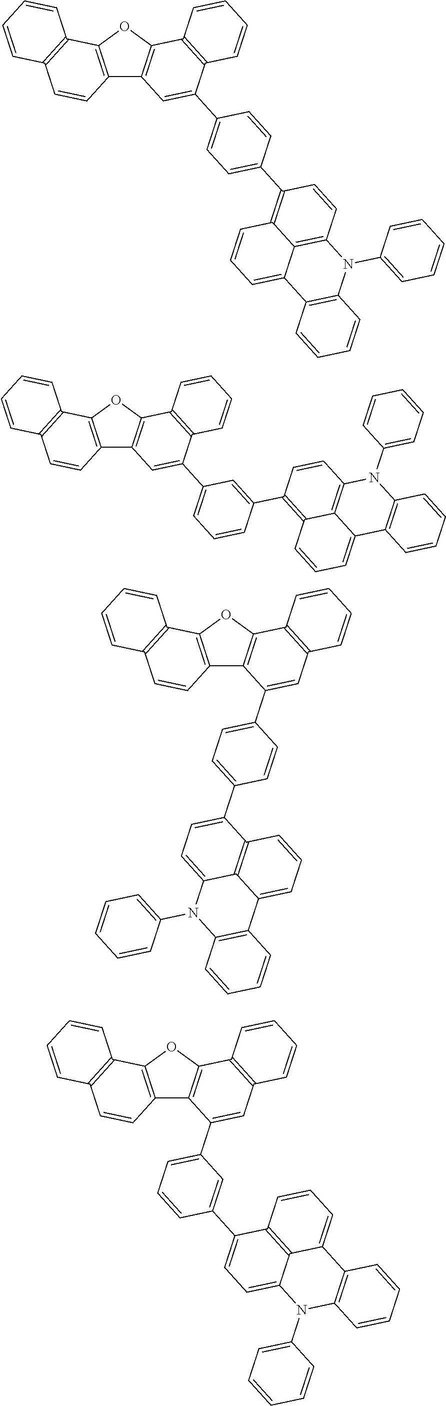

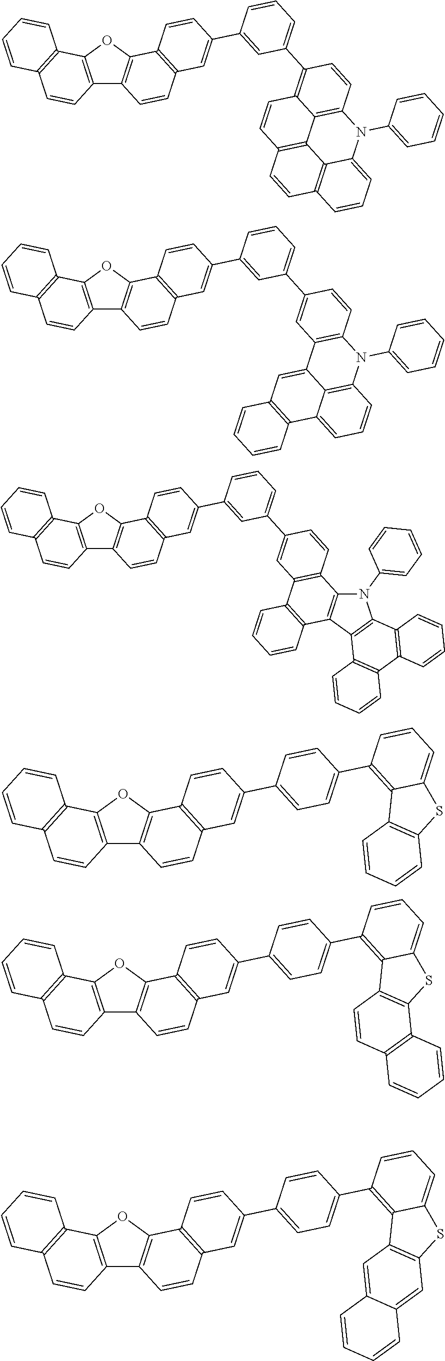

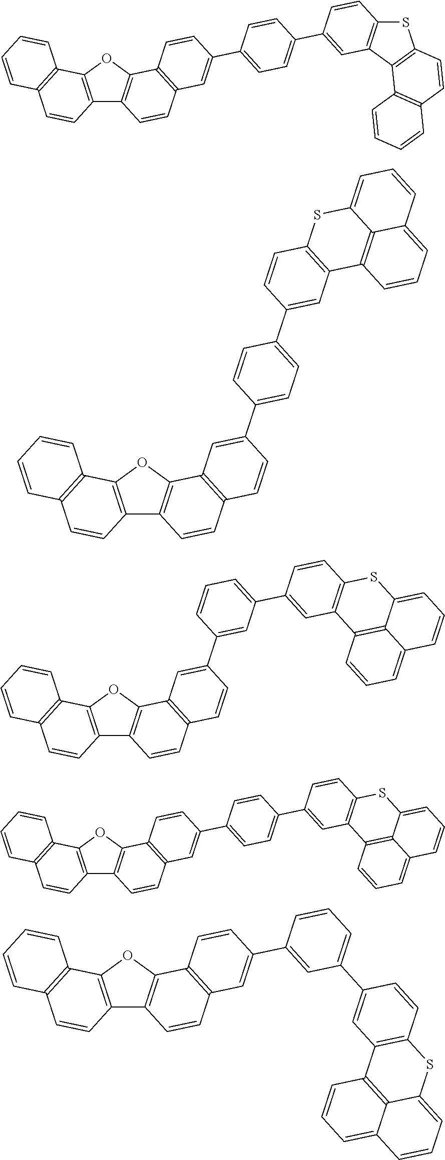

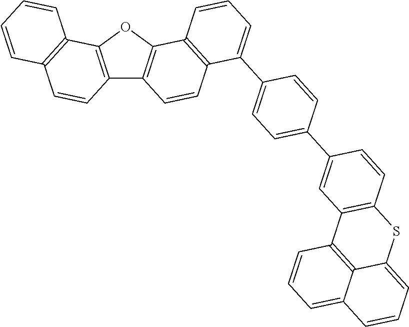 [SMILES: c1cc2c3c(cccc3c1)-c1cc(-c3ccc(-c4cccc5c4ccc4c6ccc7ccccc7c6oc54)cc3)ccc1S2]

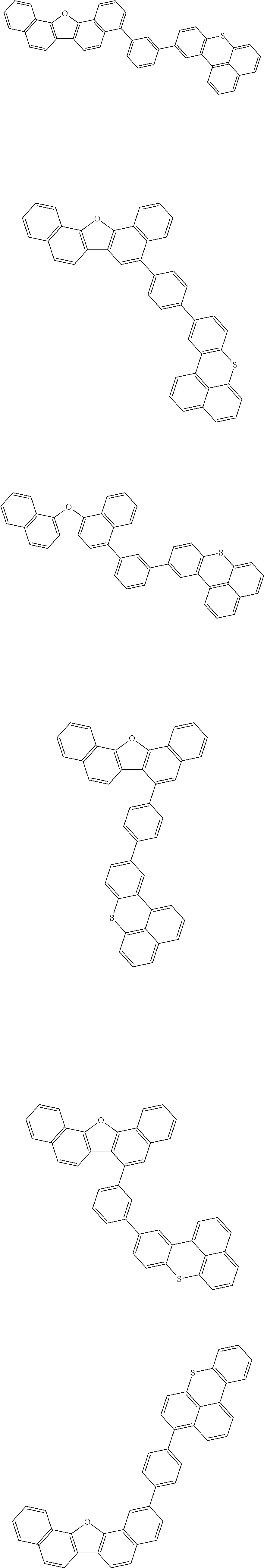 [SMILES: c1cc(-c2ccc3c(c2)-c2cccc4cccc(c24)S3)cc(-c2cccc3c2ccc2c4ccc5ccccc5c4oc32)c1 ; c1cc2c3c(cccc3c1)-c1cc(-c3ccc(-c4cc5c6ccc7ccccc7c6oc5c5ccccc45)cc3)ccc1S2 ; c1cc(-c2ccc3c(c2)-c2cccc4cccc(c24)S3)cc(-c2cc3c4ccc5ccccc5c4oc3c3ccccc23)c1 ; c1cc2c3c(cccc3c1)-c1cc(-c3ccc(-c4cc5ccccc5c5oc6c7ccccc7ccc6c45)cc3)ccc1S2 ; c1cc(-c2ccc3c(c2)-c2cccc4cccc(c24)S3)cc(-c2cc3ccccc3c3oc4c5ccccc5ccc4c23)c1 ; c1ccc2c(c1)Sc1ccc(-c3ccc(-c4ccc5ccc6c7ccc8ccccc8c7oc6c5c4)cc3)c3cccc-2c13]

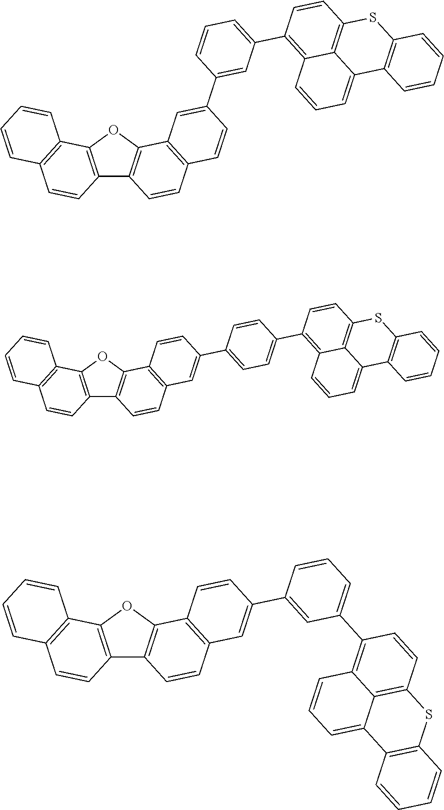 [SMILES: c1cc(-c2ccc3ccc4c5ccc6ccccc6c5oc4c3c2)cc(-c2ccc3c4c(cccc24)-c2ccccc2S3)c1 ; c1ccc2c(c1)Sc1ccc(-c3ccc(-c4ccc5c(ccc6c7ccc8ccccc8c7oc56)c4)cc3)c3cccc-2c13 ; c1cc(-c2ccc3c(ccc4c5ccc6ccccc6c5oc34)c2)cc(-c2ccc3c4c(cccc24)-c2ccccc2S3)c1]

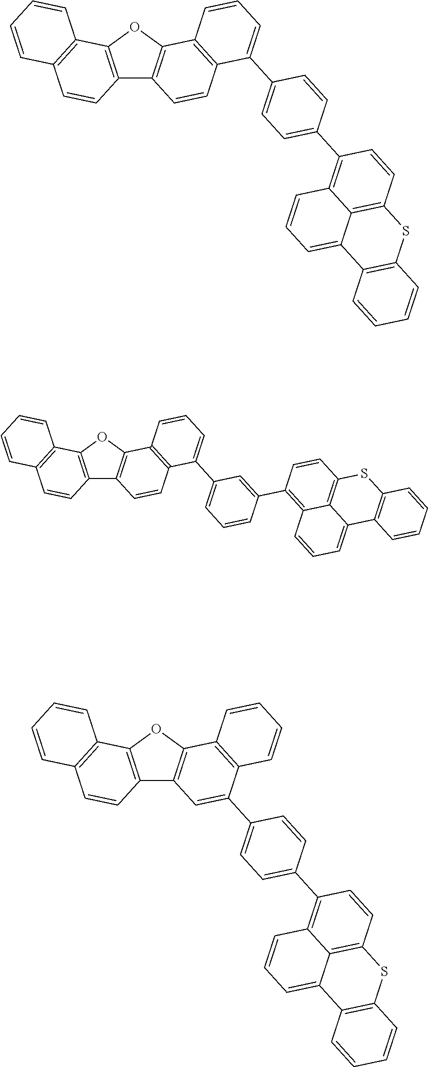 [SMILES: c1ccc2c(c1)Sc1ccc(-c3ccc(-c4cccc5c4ccc4c6ccc7ccccc7c6oc54)cc3)c3cccc-2c13 ; c1cc(-c2ccc3c4c(cccc24)-c2ccccc2S3)cc(-c2cccc3c2ccc2c4ccc5ccccc5c4oc32)c1 ; c1ccc2c(c1)Sc1ccc(-c3ccc(-c4cc5c6ccc7ccccc7c6oc5c5ccccc45)cc3)c3cccc-2c13]

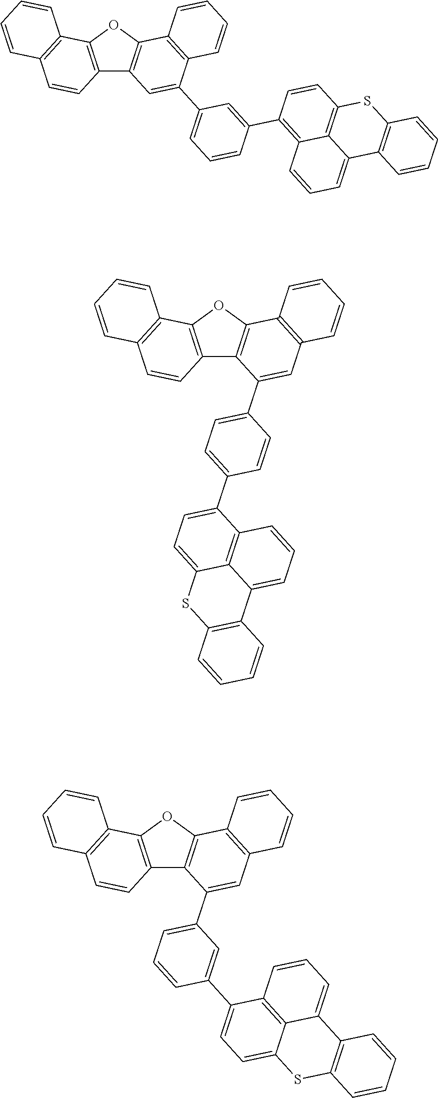 [SMILES: c1cc(-c2ccc3c4c(cccc24)-c2ccccc2S3)cc(-c2cc3c4ccc5ccccc5c4oc3c3ccccc23)c1 ; c1ccc2c(c1)Sc1ccc(-c3ccc(-c4cc5ccccc5c5oc6c7ccccc7ccc6c45)cc3)c3cccc-2c13 ; c1cc(-c2ccc3c4c(cccc24)-c2ccccc2S3)cc(-c2cc3ccccc3c3oc4c5ccccc5ccc4c23)c1]

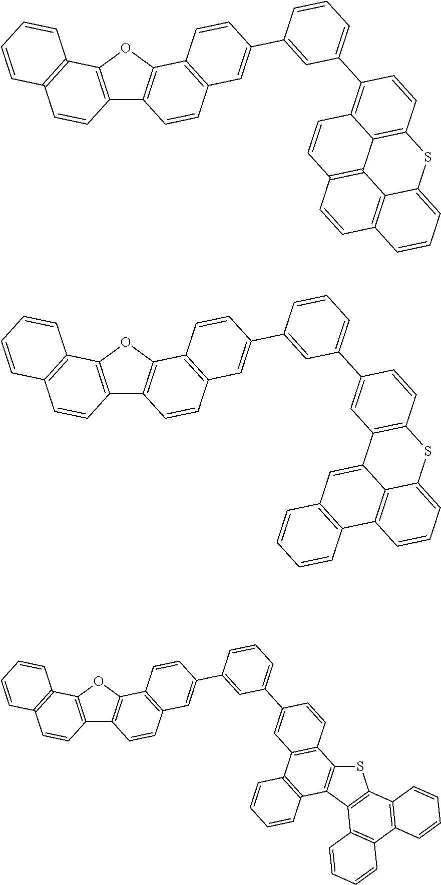 [SMILES: c1cc(-c2ccc3c(ccc4c5ccc6ccccc6c5oc34)c2)cc(-c2ccc3c4c2ccc2ccc5cccc(c5c24)S3)c1 ; c1cc(-c2ccc3c(c2)-c2cc4ccccc4c4cccc(c24)S3)cc(-c2ccc3c(ccc4c5ccc6ccccc6c5oc34)c2)c1 ; c1cc(-c2ccc3c(ccc4c5ccc6ccccc6c5oc34)c2)cc(-c2ccc3c(c2)c2ccccc2c2c3sc3c4ccccc4c4ccccc4c32)c1]

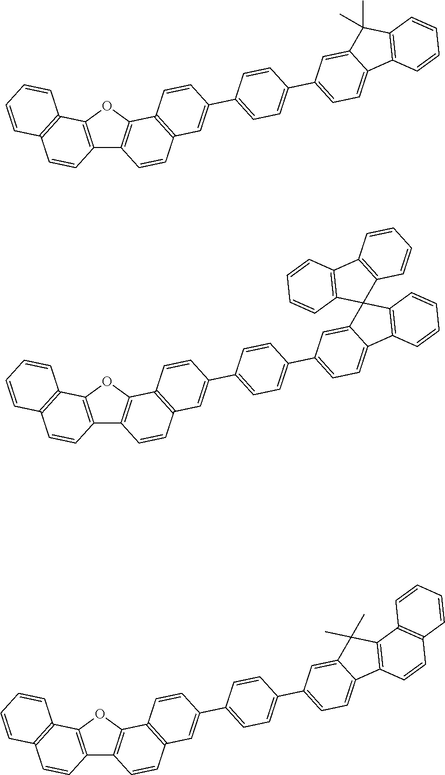 [SMILES: CC1(C)c2ccccc2-c2ccc(-c3ccc(-c4ccc5c(ccc6c7ccc8ccccc8c7oc56)c4)cc3)cc21 ; c1ccc2c(c1)-c1ccccc1C21c2ccccc2-c2ccc(-c3ccc(-c4ccc5c(ccc6c7ccc8ccccc8c7oc56)c4)cc3)cc21 ; CC1(C)c2cc(-c3ccc(-c4ccc5c(ccc6c7ccc8ccccc8c7oc56)c4)cc3)ccc2-c2ccc3ccccc3c21]

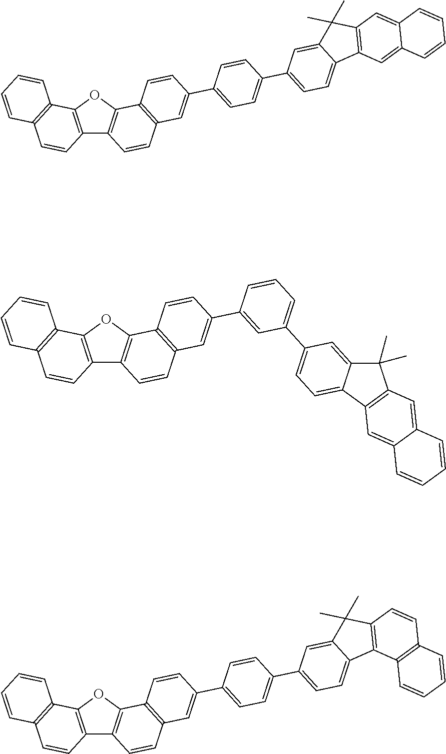 [SMILES: CC1(C)c2cc(-c3ccc(-c4ccc5c(ccc6c7ccc8ccccc8c7oc56)c4)cc3)ccc2-c2cc3ccccc3cc21 ; CC1(C)c2cc(-c3cccc(-c4ccc5c(ccc6c7ccc8ccccc8c7oc56)c4)c3)ccc2-c2cc3ccccc3cc21 ; CC1(C)c2cc(-c3ccc(-c4ccc5c(ccc6c7ccc8ccccc8c7oc56)c4)cc3)ccc2-c2c1ccc1ccccc21]

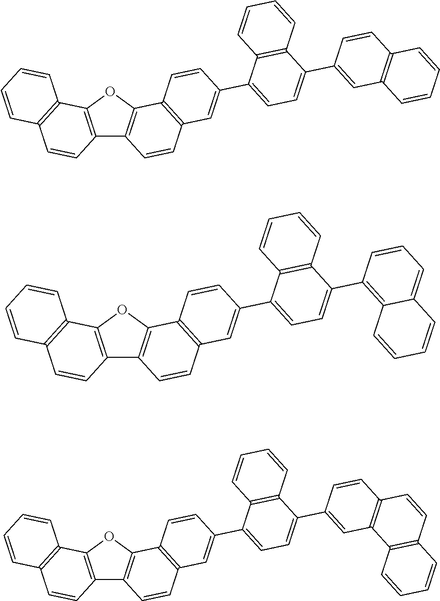 [SMILES: c1ccc2cc(-c3ccc(-c4ccc5c(ccc6c7ccc8ccccc8c7oc56)c4)c4ccccc34)ccc2c1 ; c1ccc2c(-c3ccc(-c4ccc5c(ccc6c7ccc8ccccc8c7oc56)c4)c4ccccc34)cccc2c1 ; c1ccc2c(c1)ccc1ccc(-c3ccc(-c4ccc5c(ccc6c7ccc8ccccc8c7oc56)c4)c4ccccc34)cc12]

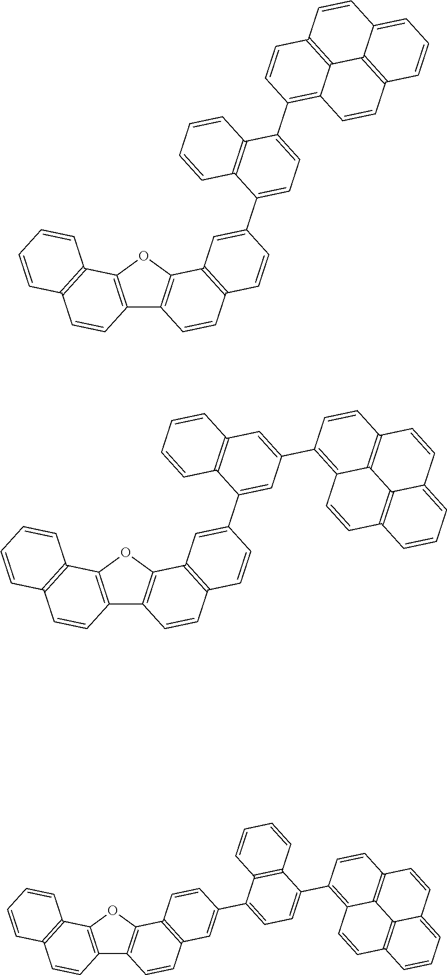 [SMILES: c1ccc2c(c1)ccc1c3ccc4ccc(-c5ccc(-c6ccc7ccc8cccc9ccc6c7c89)c6ccccc56)cc4c3oc21 ; c1ccc2c(-c3ccc4ccc5c6ccc7ccccc7c6oc5c4c3)cc(-c3ccc4ccc5cccc6ccc3c4c56)cc2c1 ; c1ccc2c(c1)ccc1c3ccc4cc(-c5ccc(-c6ccc7ccc8cccc9ccc6c7c89)c6ccccc56)ccc4c3oc21]

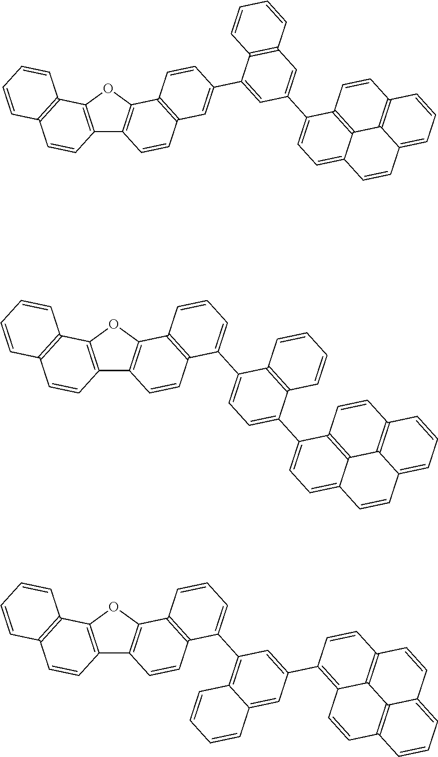 [SMILES: c1ccc2c(-c3ccc4c(ccc5c6ccc7ccccc7c6oc45)c3)cc(-c3ccc4ccc5cccc6ccc3c4c56)cc2c1 ; c1ccc2c(c1)ccc1c3ccc4c(-c5ccc(-c6ccc7ccc8cccc9ccc6c7c89)c6ccccc56)cccc4c3oc21 ; c1ccc2c(-c3cccc4c3ccc3c5ccc6ccccc6c5oc43)cc(-c3ccc4ccc5cccc6ccc3c4c56)cc2c1]

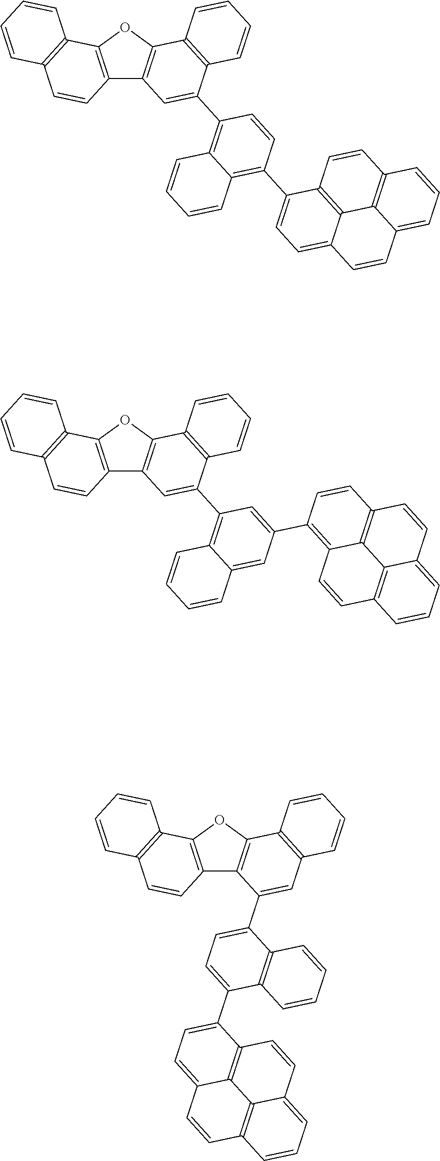 [SMILES: c1ccc2c(c1)ccc1c3cc(-c4ccc(-c5ccc6ccc7cccc8ccc5c6c78)c5ccccc45)c4ccccc4c3oc21 ; c1ccc2c(-c3cc4c5ccc6ccccc6c5oc4c4ccccc34)cc(-c3ccc4ccc5cccc6ccc3c4c56)cc2c1 ; c1ccc2c(c1)ccc1c2oc2c3ccccc3cc(-c3ccc(-c4ccc5ccc6cccc7ccc4c5c67)c4ccccc34)c12]

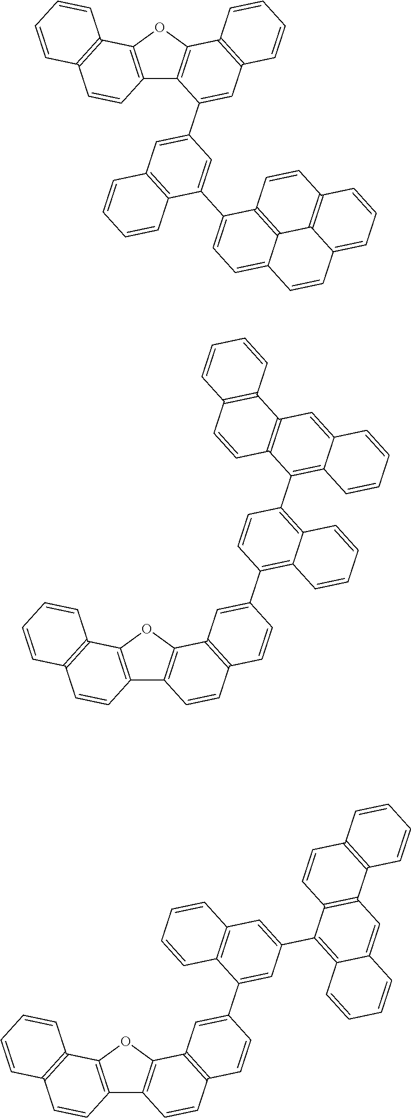 [SMILES: c1ccc2c(-c3ccc4ccc5cccc6ccc3c4c56)cc(-c3cc4ccccc4c4oc5c6ccccc6ccc5c34)cc2c1 ; c1ccc2c(-c3ccc(-c4ccc5ccc6c7ccc8ccccc8c7oc6c5c4)c4ccccc34)c3ccc4ccccc4c3cc2c1 ; c1ccc2c(-c3ccc4ccc5c6ccc7ccccc7c6oc5c4c3)cc(-c3c4ccccc4cc4c3ccc3ccccc34)cc2c1]

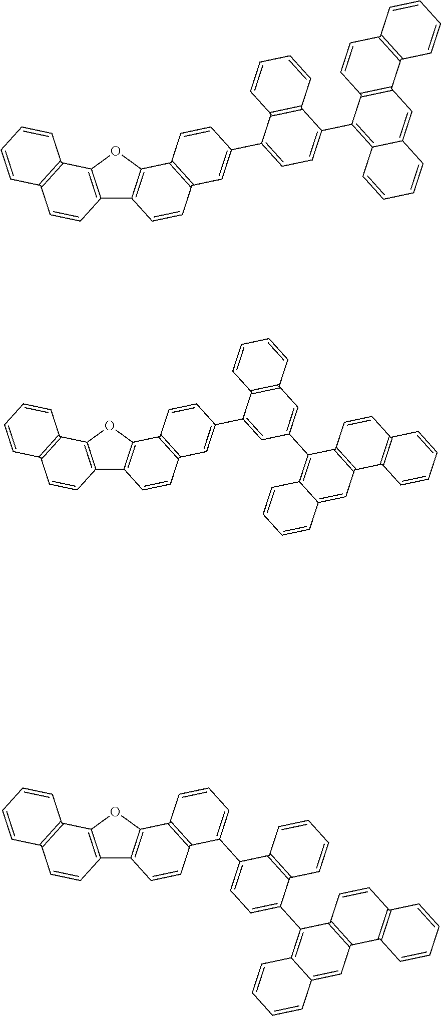 [SMILES: c1ccc2c(-c3ccc(-c4ccc5c(ccc6c7ccc8ccccc8c7oc56)c4)c4ccccc34)c3ccc4ccccc4c3cc2c1 ; c1ccc2c(-c3ccc4c(ccc5c6ccc7ccccc7c6oc45)c3)cc(-c3c4ccccc4cc4c3ccc3ccccc34)cc2c1 ; c1ccc2c(-c3ccc(-c4cccc5c4ccc4c6ccc7ccccc7c6oc54)c4ccccc34)c3ccc4ccccc4c3cc2c1]

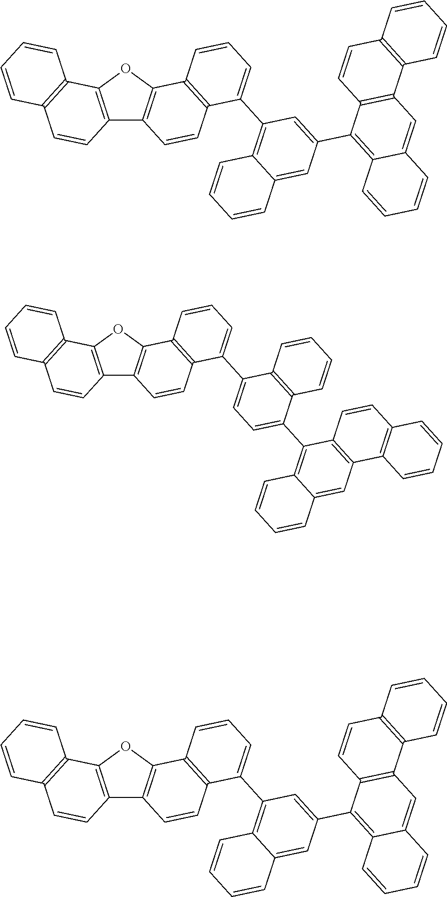 [SMILES: c1ccc2c(-c3cccc4c3ccc3c5ccc6ccccc6c5oc43)cc(-c3c4ccccc4cc4c3ccc3ccccc34)cc2c1 ; c1ccc2c(-c3ccc(-c4cccc5c4ccc4c6ccc7ccccc7c6oc54)c4ccccc34)c3ccc4ccccc4c3cc2c1 ; c1ccc2c(-c3cccc4c3ccc3c5ccc6ccccc6c5oc43)cc(-c3c4ccccc4cc4c3ccc3ccccc34)cc2c1]

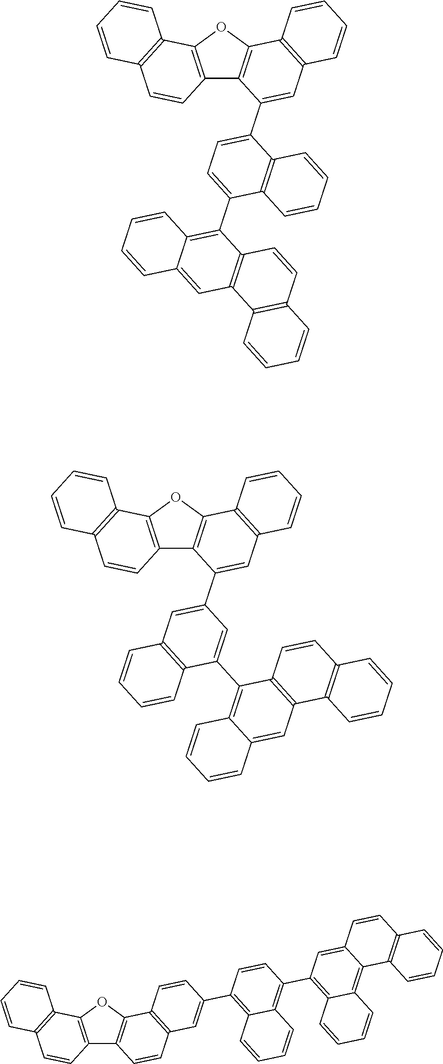 [SMILES: c1ccc2c(-c3ccc(-c4cc5ccccc5c5oc6c7ccccc7ccc6c45)c4ccccc34)c3ccc4ccccc4c3cc2c1 ; c1ccc2c(-c3c4ccccc4cc4c3ccc3ccccc34)cc(-c3cc4ccccc4c4oc5c6ccccc6ccc5c34)cc2c1 ; c1ccc2c(c1)ccc1c3ccc4cc(-c5ccc(-c6cc7ccc8ccccc8c7c7ccccc67)c6ccccc56)ccc4c3oc21]

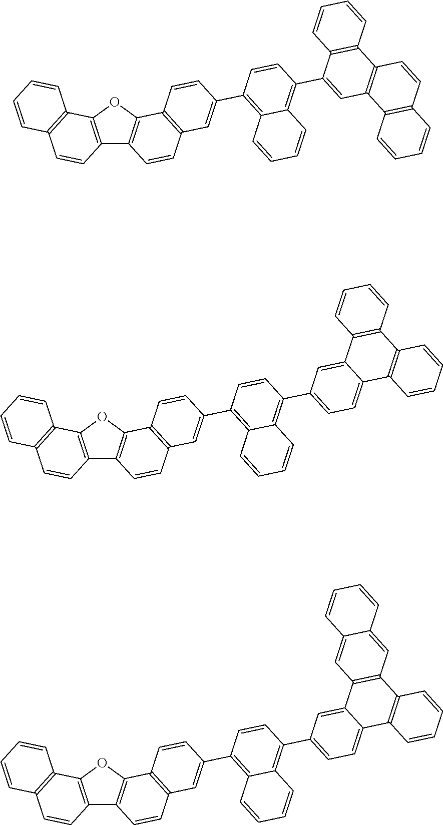 [SMILES: c1ccc2c(c1)ccc1c3ccccc3c(-c3ccc(-c4ccc5c(ccc6c7ccc8ccccc8c7oc56)c4)c4ccccc34)cc21 ; c1ccc2c(c1)ccc1c3ccc4cc(-c5ccc(-c6ccc7c8ccccc8c8ccccc8c7c6)c6ccccc56)ccc4c3oc21 ; c1ccc2cc3c4cc(-c5ccc(-c6ccc7c(ccc8c9ccc%10ccccc%10c9oc78)c6)c6ccccc56)ccc4c4ccccc4c3cc2c1]

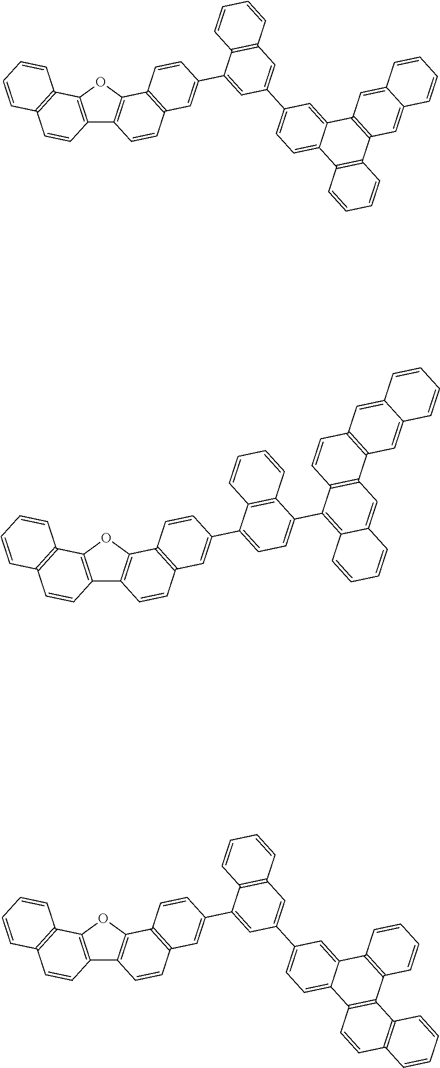 [SMILES: c1ccc2cc3c4cc(-c5cc(-c6ccc7c(ccc8c9ccc%10ccccc%10c9oc78)c6)c6ccccc6c5)ccc4c4ccccc4c3cc2c1 ; c1ccc2cc3c(ccc4c(-c5ccc(-c6ccc7c(ccc8c9ccc%10ccccc%10c9oc78)c6)c6ccccc56)c5ccccc5cc43)cc2c1 ; c1ccc2c(-c3ccc4c(ccc5c6ccc7ccccc7c6oc45)c3)cc(-c3ccc4c(c3)c3ccccc3c3c5ccccc5ccc43)cc2c1]

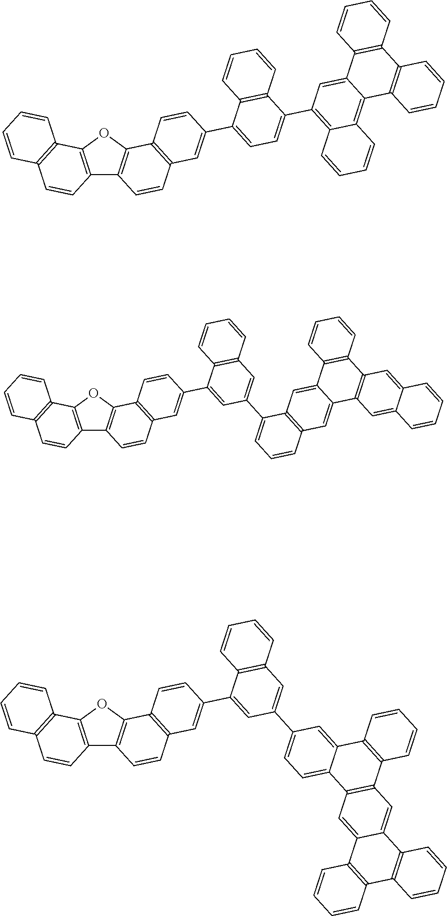 [SMILES: c1ccc2c(c1)ccc1c3ccc4cc(-c5ccc(-c6cc7c8ccccc8c8ccccc8c7c7ccccc67)c6ccccc56)ccc4c3oc21 ; c1ccc2cc3c(cc2c1)c1ccccc1c1cc2c(-c4cc(-c5ccc6c(ccc7c8ccc9ccccc9c8oc67)c5)c5ccccc5c4)cccc2cc31 ; c1ccc2c(-c3ccc4c(ccc5c6ccc7ccccc7c6oc45)c3)cc(-c3ccc4c(c3)c3ccccc3c3cc5c6ccccc6c6ccccc6c5cc43)cc2c1]

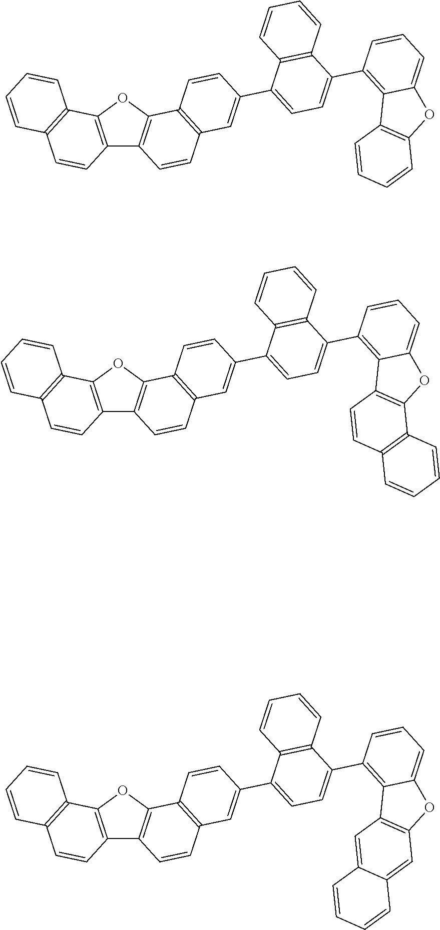 [SMILES: c1ccc2c(c1)ccc1c3ccc4cc(-c5ccc(-c6cccc7oc8ccccc8c67)c6ccccc56)ccc4c3oc21 ; c1ccc2c(c1)ccc1c3ccc4cc(-c5ccc(-c6cccc7oc8c9ccccc9ccc8c67)c6ccccc56)ccc4c3oc21 ; c1ccc2cc3c(cc2c1)oc1cccc(-c2ccc(-c4ccc5c(ccc6c7ccc8ccccc8c7oc56)c4)c4ccccc24)c13]

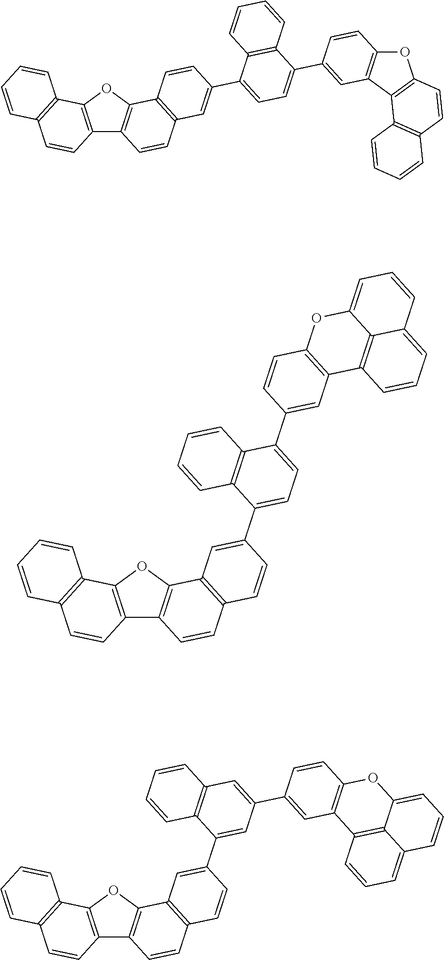 [SMILES: c1ccc2c(c1)ccc1c3ccc4cc(-c5ccc(-c6ccc7oc8ccc9ccccc9c8c7c6)c6ccccc56)ccc4c3oc21 ; c1cc2c3c(cccc3c1)-c1cc(-c3ccc(-c4ccc5ccc6c7ccc8ccccc8c7oc6c5c4)c4ccccc34)ccc1O2 ; c1ccc2c(-c3ccc4ccc5c6ccc7ccccc7c6oc5c4c3)cc(-c3ccc4c(c3)-c3cccc5cccc(c35)O4)cc2c1]

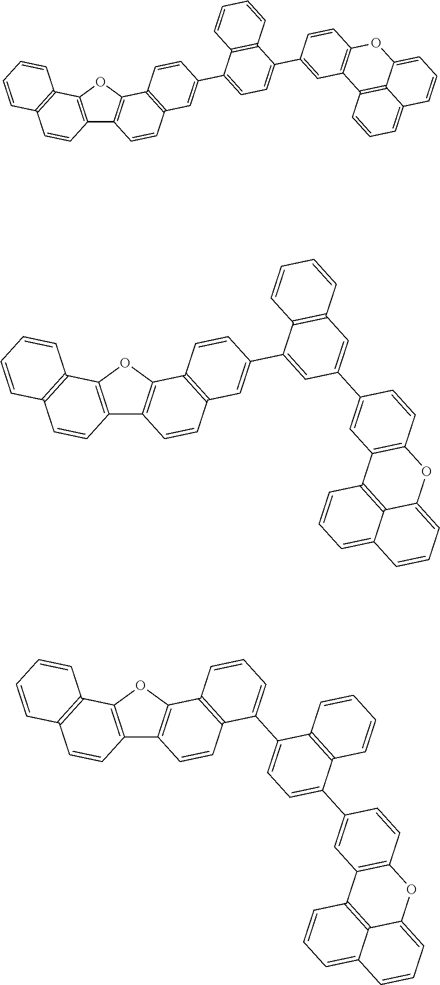 [SMILES: c1cc2c3c(cccc3c1)-c1cc(-c3ccc(-c4ccc5c(ccc6c7ccc8ccccc8c7oc56)c4)c4ccccc34)ccc1O2 ; c1ccc2c(-c3ccc4c(ccc5c6ccc7ccccc7c6oc45)c3)cc(-c3ccc4c(c3)-c3cccc5cccc(c35)O4)cc2c1 ; c1cc2c3c(cccc3c1)-c1cc(-c3ccc(-c4cccc5c4ccc4c6ccc7ccccc7c6oc54)c4ccccc34)ccc1O2]

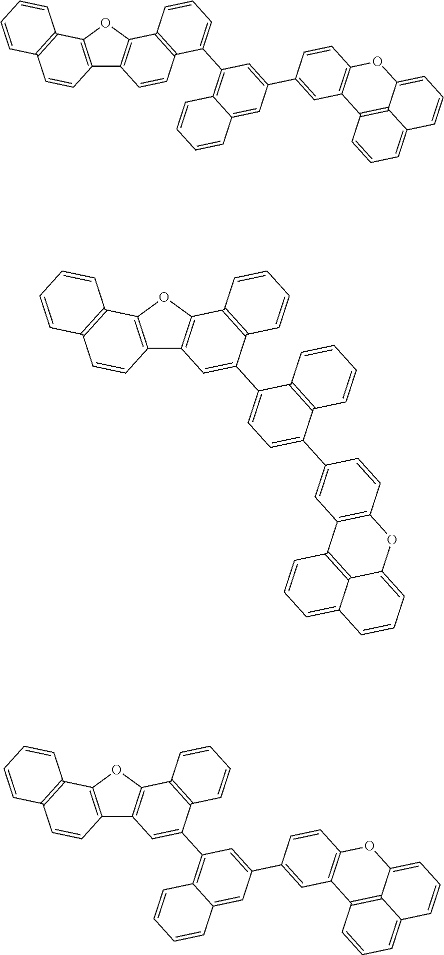 [SMILES: c1ccc2c(-c3cccc4c3ccc3c5ccc6ccccc6c5oc43)cc(-c3ccc4c(c3)-c3cccc5cccc(c35)O4)cc2c1 ; c1cc2c3c(cccc3c1)-c1cc(-c3ccc(-c4cc5c6ccc7ccccc7c6oc5c5ccccc45)c4ccccc34)ccc1O2 ; c1ccc2c(-c3cc4c5ccc6ccccc6c5oc4c4ccccc34)cc(-c3ccc4c(c3)-c3cccc5cccc(c35)O4)cc2c1]

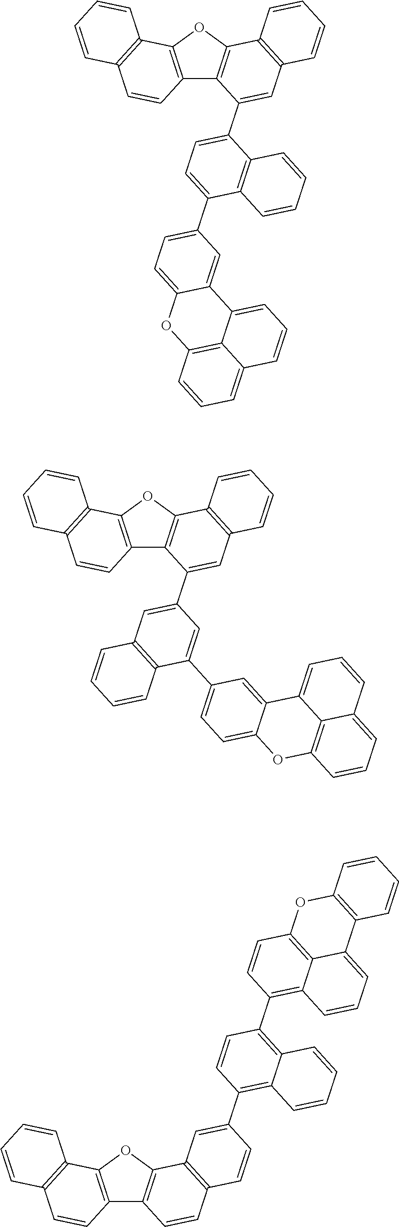 [SMILES: c1cc2c3c(cccc3c1)-c1cc(-c3ccc(-c4cc5ccccc5c5oc6c7ccccc7ccc6c45)c4ccccc34)ccc1O2 ; c1ccc2c(-c3ccc4c(c3)-c3cccc5cccc(c35)O4)cc(-c3cc4ccccc4c4oc5c6ccccc6ccc5c34)cc2c1 ; c1ccc2c(c1)Oc1ccc(-c3ccc(-c4ccc5ccc6c7ccc8ccccc8c7oc6c5c4)c4ccccc34)c3cccc-2c13]

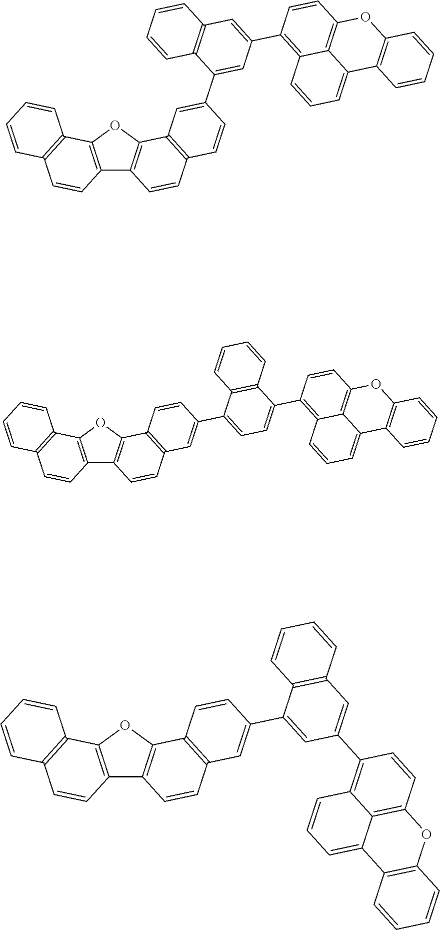 [SMILES: c1ccc2c(c1)Oc1ccc(-c3cc(-c4ccc5ccc6c7ccc8ccccc8c7oc6c5c4)c4ccccc4c3)c3cccc-2c13 ; c1ccc2c(c1)Oc1ccc(-c3ccc(-c4ccc5c(ccc6c7ccc8ccccc8c7oc56)c4)c4ccccc34)c3cccc-2c13 ; c1ccc2c(c1)Oc1ccc(-c3cc(-c4ccc5c(ccc6c7ccc8ccccc8c7oc56)c4)c4ccccc4c3)c3cccc-2c13]

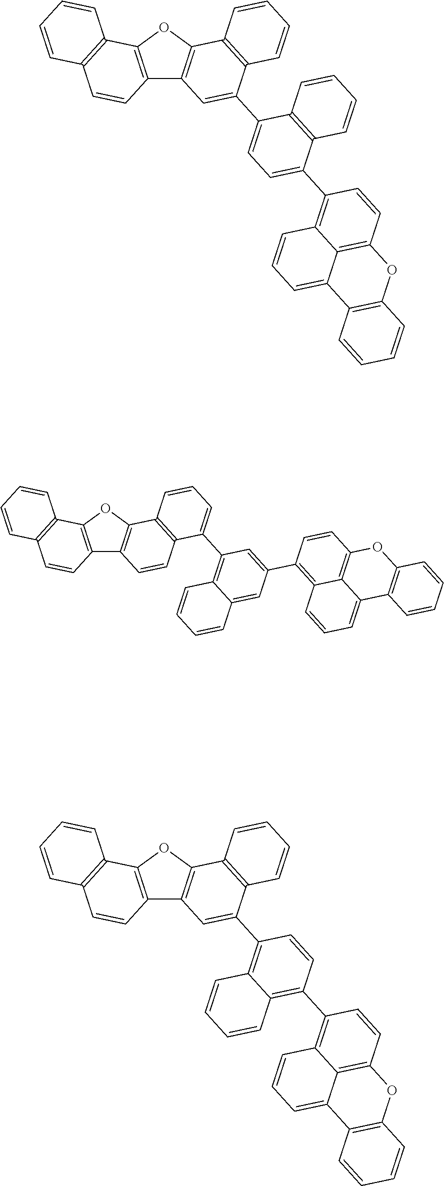 [SMILES: c1ccc2c(c1)Oc1ccc(-c3ccc(-c4cc5c6ccc7ccccc7c6oc5c5ccccc45)c4ccccc34)c3cccc-2c13 ; c1ccc2c(c1)Oc1ccc(-c3cc(-c4cccc5c4ccc4c6ccc7ccccc7c6oc54)c4ccccc4c3)c3cccc-2c13 ; c1ccc2c(c1)Oc1ccc(-c3ccc(-c4cc5c6ccc7ccccc7c6oc5c5ccccc45)c4ccccc34)c3cccc-2c13]

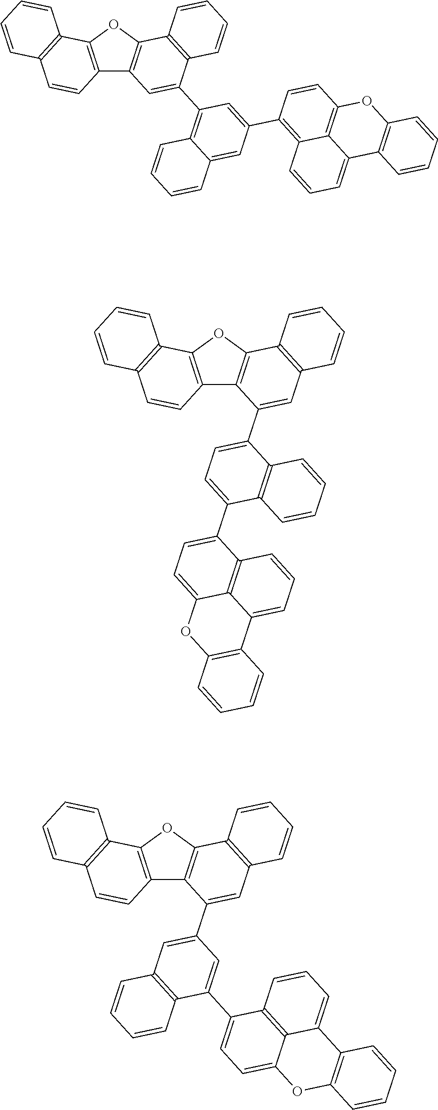 [SMILES: c1ccc2c(c1)Oc1ccc(-c3cc(-c4cc5c6ccc7ccccc7c6oc5c5ccccc45)c4ccccc4c3)c3cccc-2c13 ; c1ccc2c(c1)Oc1ccc(-c3ccc(-c4cc5ccccc5c5oc6c7ccccc7ccc6c45)c4ccccc34)c3cccc-2c13 ; c1ccc2c(c1)Oc1ccc(-c3cc(-c4cc5ccccc5c5oc6c7ccccc7ccc6c45)cc4ccccc34)c3cccc-2c13]

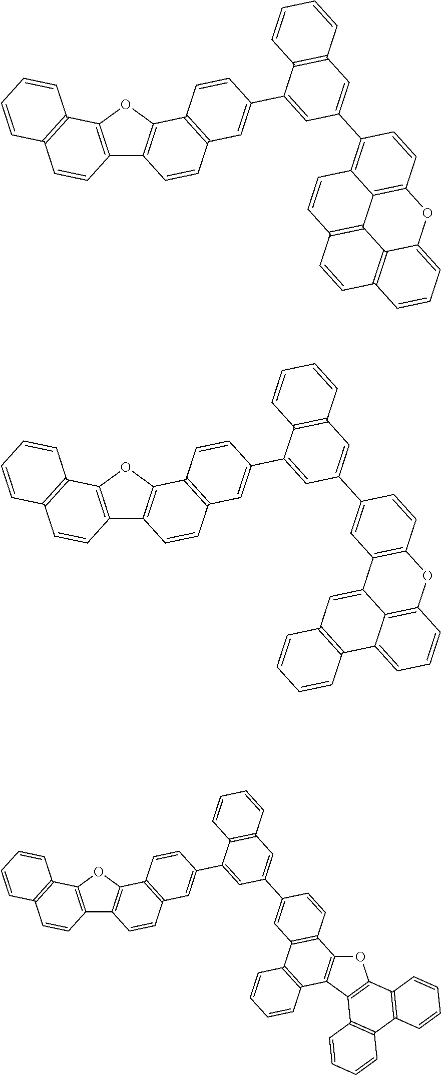 [SMILES: c1ccc2c(-c3ccc4c(ccc5c6ccc7ccccc7c6oc45)c3)cc(-c3ccc4c5c3ccc3ccc6cccc(c6c35)O4)cc2c1 ; c1ccc2c(-c3ccc4c(ccc5c6ccc7ccccc7c6oc45)c3)cc(-c3ccc4c(c3)-c3cc5ccccc5c5cccc(c35)O4)cc2c1 ; c1ccc2c(-c3ccc4c(ccc5c6ccc7ccccc7c6oc45)c3)cc(-c3ccc4c(c3)c3ccccc3c3c4oc4c5ccccc5c5ccccc5c43)cc2c1]

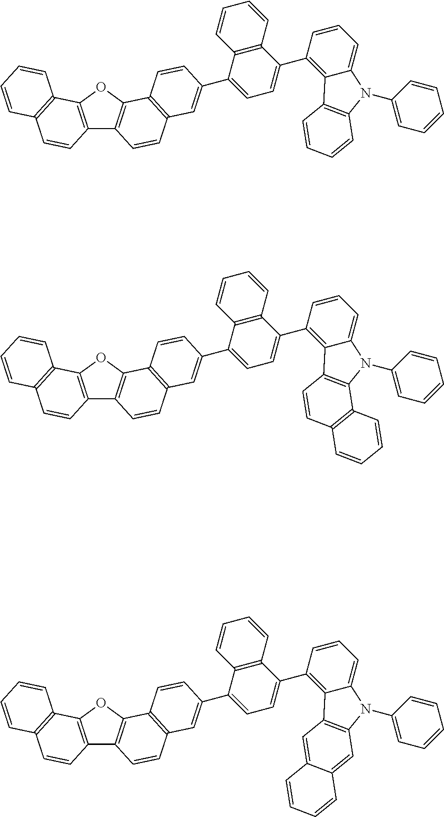 [SMILES: c1ccc(-n2c3ccccc3c3c(-c4ccc(-c5ccc6c(ccc7c8ccc9ccccc9c8oc67)c5)c5ccccc45)cccc32)cc1 ; c1ccc(-n2c3cccc(-c4ccc(-c5ccc6c(ccc7c8ccc9ccccc9c8oc67)c5)c5ccccc45)c3c3ccc4ccccc4c32)cc1 ; c1ccc(-n2c3cc4ccccc4cc3c3c(-c4ccc(-c5ccc6c(ccc7c8ccc9ccccc9c8oc67)c5)c5ccccc45)cccc32)cc1]

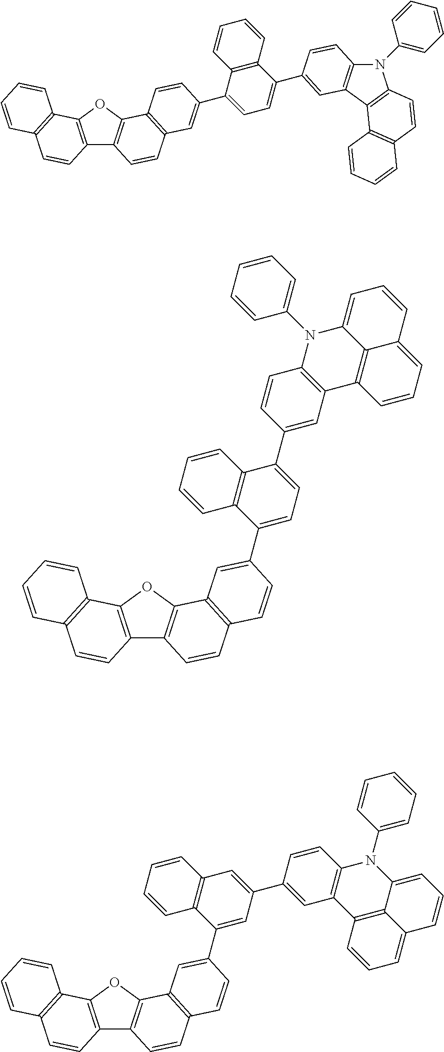 [SMILES: c1ccc(-n2c3ccc(-c4ccc(-c5ccc6c(ccc7c8ccc9ccccc9c8oc67)c5)c5ccccc45)cc3c3c4ccccc4ccc32)cc1 ; c1ccc(N2c3ccc(-c4ccc(-c5ccc6ccc7c8ccc9ccccc9c8oc7c6c5)c5ccccc45)cc3-c3cccc4cccc2c34)cc1 ; c1ccc(N2c3ccc(-c4cc(-c5ccc6ccc7c8ccc9ccccc9c8oc7c6c5)c5ccccc5c4)cc3-c3cccc4cccc2c34)cc1]

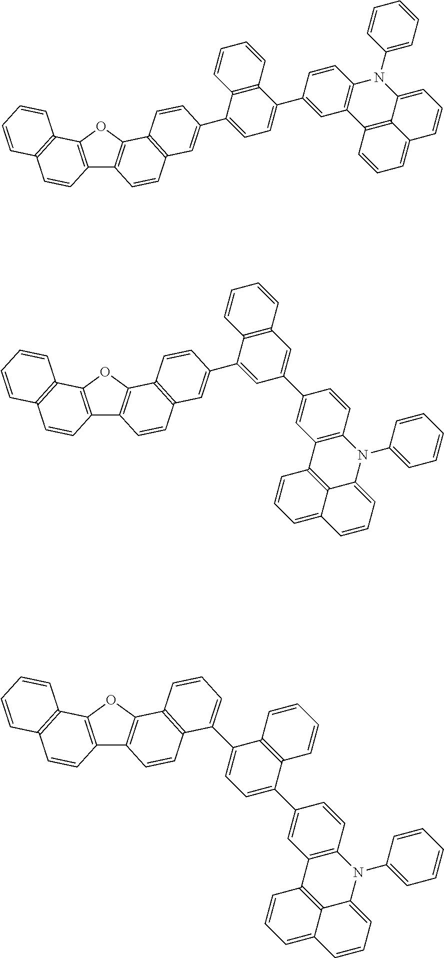 [SMILES: c1ccc(N2c3ccc(-c4ccc(-c5ccc6c(ccc7c8ccc9ccccc9c8oc67)c5)c5ccccc45)cc3-c3cccc4cccc2c34)cc1 ; c1ccc(N2c3ccc(-c4cc(-c5ccc6c(ccc7c8ccc9ccccc9c8oc67)c5)c5ccccc5c4)cc3-c3cccc4cccc2c34)cc1 ; c1ccc(N2c3ccc(-c4ccc(-c5cccc6c5ccc5c7ccc8ccccc8c7oc65)c5ccccc45)cc3-c3cccc4cccc2c34)cc1]

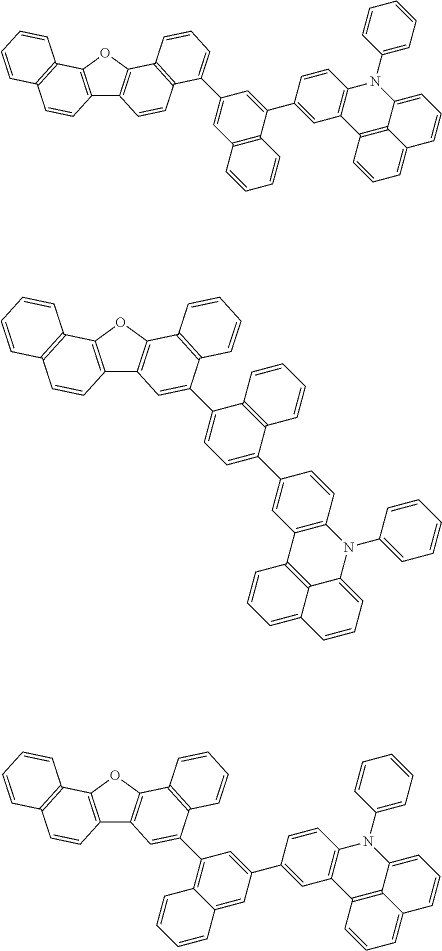 [SMILES: c1ccc(N2c3ccc(-c4cc(-c5cccc6c5ccc5c7ccc8ccccc8c7oc65)cc5ccccc45)cc3-c3cccc4cccc2c34)cc1 ; c1ccc(N2c3ccc(-c4ccc(-c5cc6c7ccc8ccccc8c7oc6c6ccccc56)c5ccccc45)cc3-c3cccc4cccc2c34)cc1 ; c1ccc(N2c3ccc(-c4cc(-c5cc6c7ccc8ccccc8c7oc6c6ccccc56)c5ccccc5c4)cc3-c3cccc4cccc2c34)cc1]

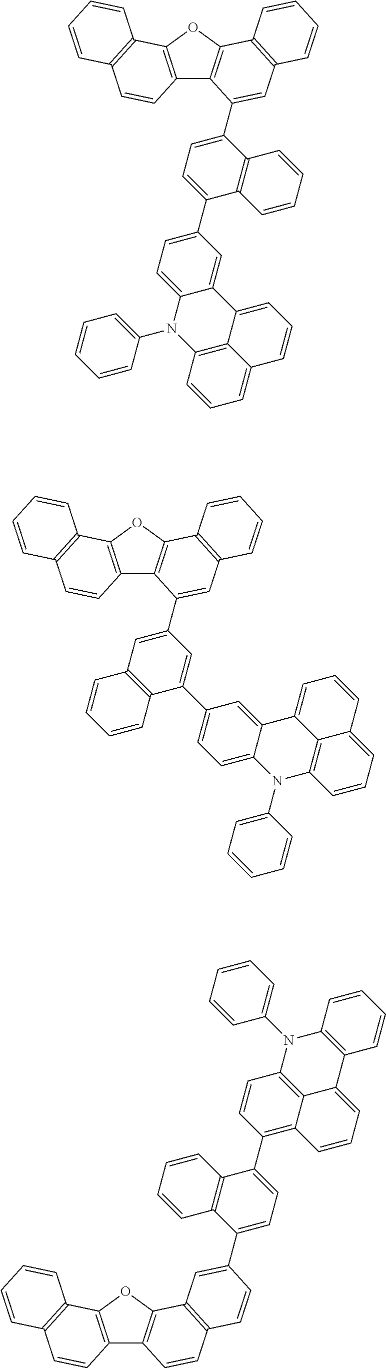 [SMILES: c1ccc(N2c3ccc(-c4ccc(-c5cc6ccccc6c6oc7c8ccccc8ccc7c56)c5ccccc45)cc3-c3cccc4cccc2c34)cc1 ; c1ccc(N2c3ccc(-c4cc(-c5cc6ccccc6c6oc7c8ccccc8ccc7c56)cc5ccccc45)cc3-c3cccc4cccc2c34)cc1 ; c1ccc(N2c3ccccc3-c3cccc4c(-c5ccc(-c6ccc7ccc8c9ccc%10ccccc%10c9oc8c7c6)c6ccccc56)ccc2c34)cc1]

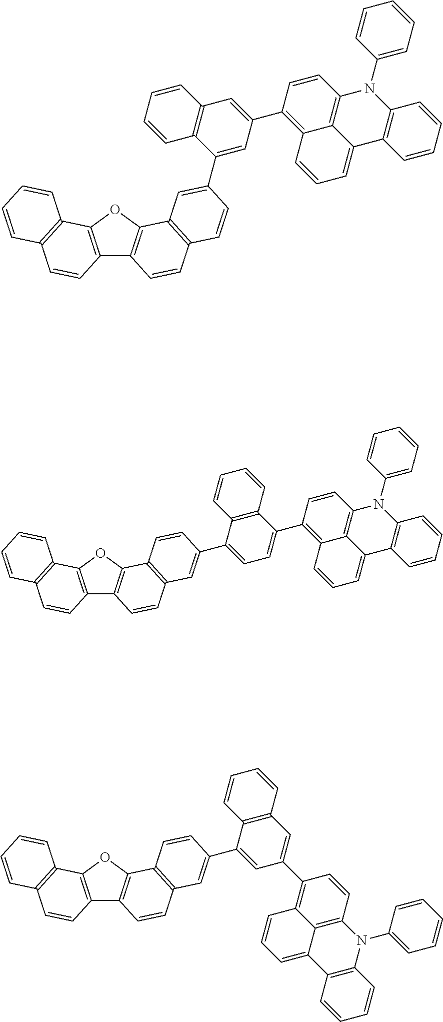 [SMILES: c1ccc(N2c3ccccc3-c3cccc4c(-c5cc(-c6ccc7ccc8c9ccc%10ccccc%10c9oc8c7c6)c6ccccc6c5)ccc2c34)cc1 ; c1ccc(N2c3ccccc3-c3cccc4c(-c5ccc(-c6ccc7c(ccc8c9ccc%10ccccc%10c9oc78)c6)c6ccccc56)ccc2c34)cc1 ; c1ccc(N2c3ccccc3-c3cccc4c(-c5cc(-c6ccc7c(ccc8c9ccc%10ccccc%10c9oc78)c6)c6ccccc6c5)ccc2c34)cc1]

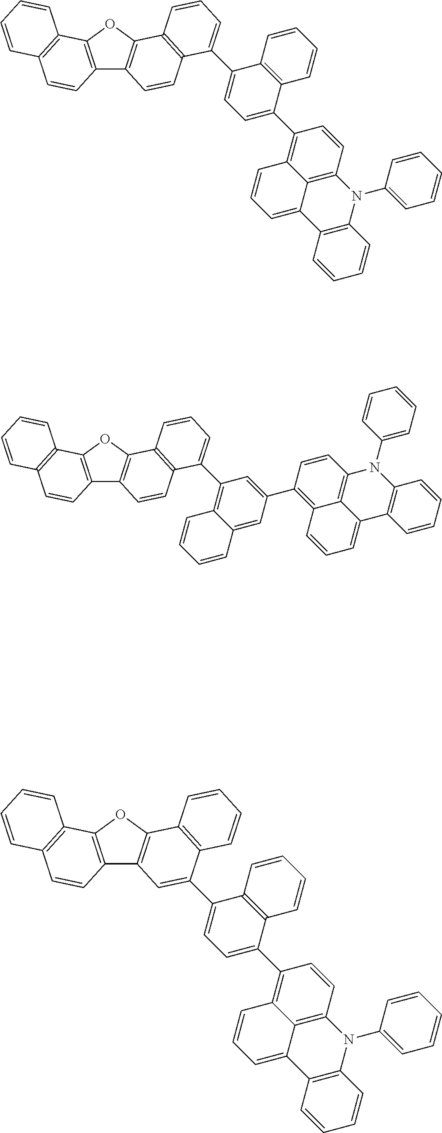 [SMILES: c1ccc(N2c3ccccc3-c3cccc4c(-c5ccc(-c6cccc7c6ccc6c8ccc9ccccc9c8oc76)c6ccccc56)ccc2c34)cc1 ; c1ccc(N2c3ccccc3-c3cccc4c(-c5cc(-c6cccc7c6ccc6c8ccc9ccccc9c8oc76)c6ccccc6c5)ccc2c34)cc1 ; c1ccc(N2c3ccccc3-c3cccc4c(-c5ccc(-c6cc7c8ccc9ccccc9c8oc7c7ccccc67)c6ccccc56)ccc2c34)cc1]

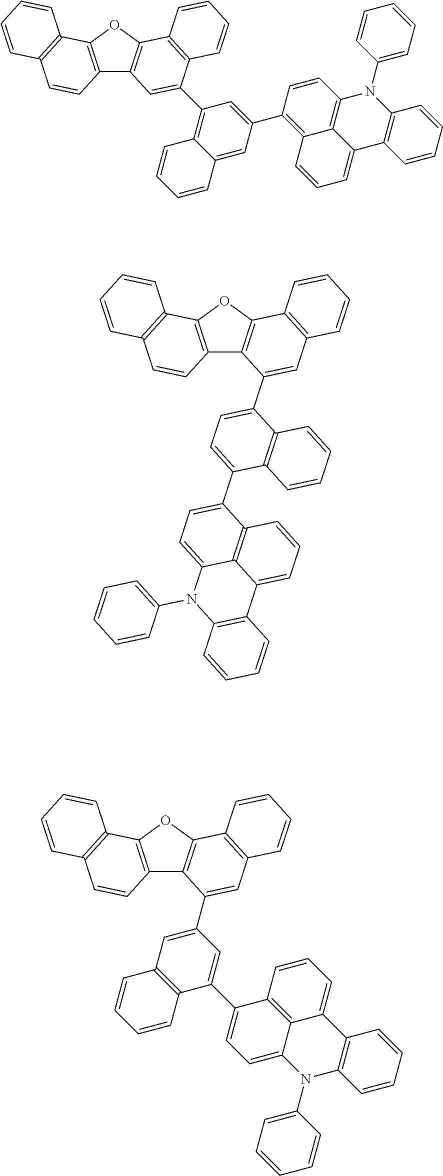 [SMILES: c1ccc(N2c3ccccc3-c3cccc4c(-c5cc(-c6cc7c8ccc9ccccc9c8oc7c7ccccc67)c6ccccc6c5)ccc2c34)cc1 ; c1ccc(N2c3ccccc3-c3cccc4c(-c5ccc(-c6cc7ccccc7c7oc8c9ccccc9ccc8c67)c6ccccc56)ccc2c34)cc1 ; c1ccc(N2c3ccccc3-c3cccc4c(-c5cc(-c6cc7ccccc7c7oc8c9ccccc9ccc8c67)cc6ccccc56)ccc2c34)cc1]

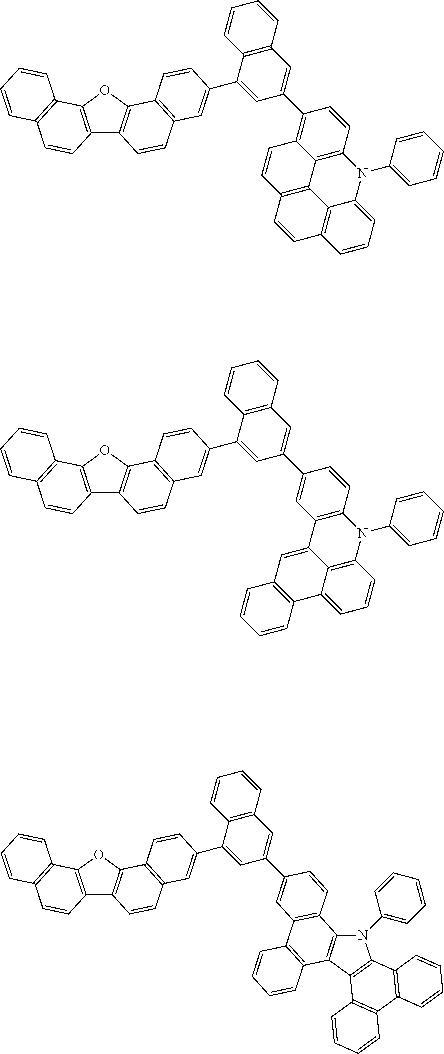

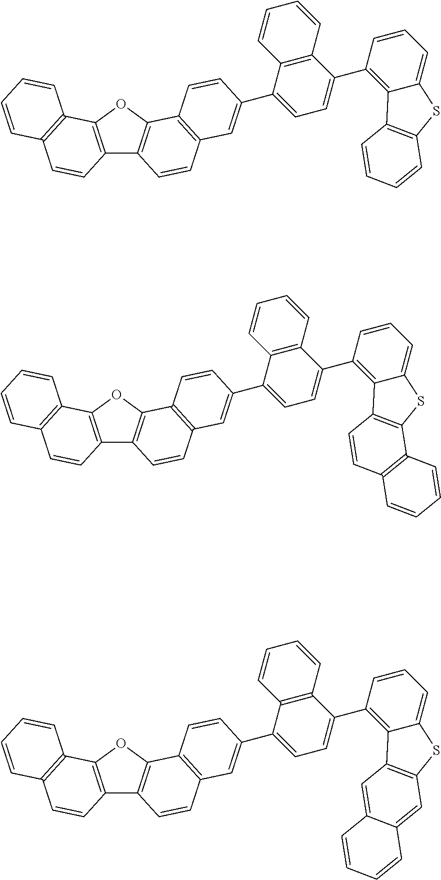 [SMILES: c1ccc2c(c1)ccc1c3ccc4cc(-c5ccc(-c6cccc7sc8ccccc8c67)c6ccccc56)ccc4c3oc21 ; c1ccc2c(c1)ccc1c3ccc4cc(-c5ccc(-c6cccc7sc8c9ccccc9ccc8c67)c6ccccc56)ccc4c3oc21 ; c1ccc2cc3c(cc2c1)sc1cccc(-c2ccc(-c4ccc5c(ccc6c7ccc8ccccc8c7oc56)c4)c4ccccc24)c13]

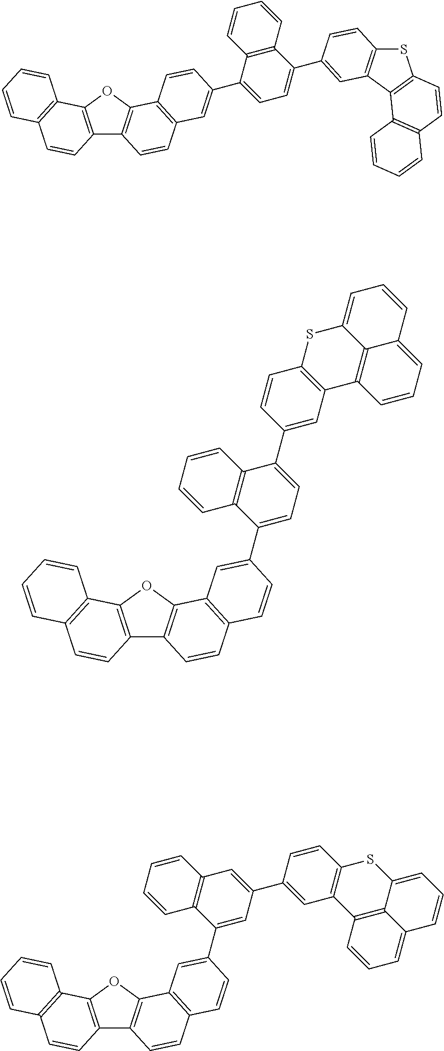 [SMILES: c1ccc2c(c1)ccc1c3ccc4cc(-c5ccc(-c6ccc7sc8ccc9ccccc9c8c7c6)c6ccccc56)ccc4c3oc21 ; c1cc2c3c(cccc3c1)-c1cc(-c3ccc(-c4ccc5ccc6c7ccc8ccccc8c7oc6c5c4)c4ccccc34)ccc1S2 ; c1ccc2c(-c3ccc4ccc5c6ccc7ccccc7c6oc5c4c3)cc(-c3ccc4c(c3)-c3cccc5cccc(c35)S4)cc2c1]

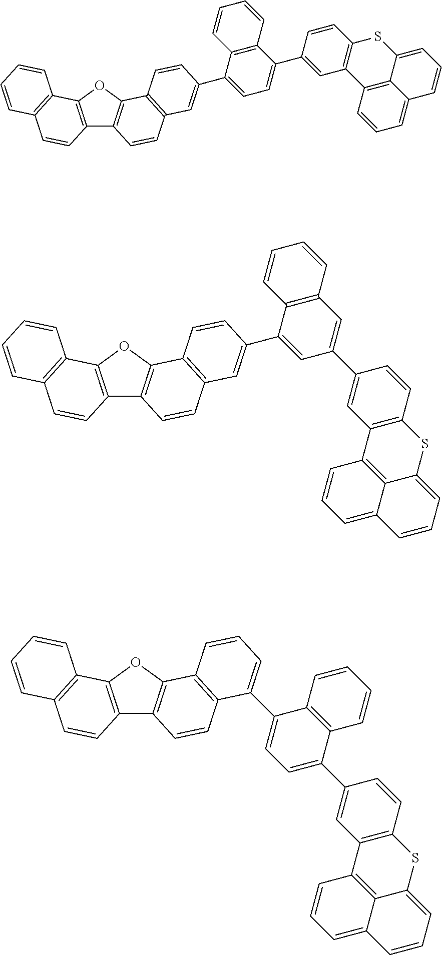 [SMILES: c1cc2c3c(cccc3c1)-c1cc(-c3ccc(-c4ccc5c(ccc6c7ccc8ccccc8c7oc56)c4)c4ccccc34)ccc1S2 ; c1ccc2c(-c3ccc4c(ccc5c6ccc7ccccc7c6oc45)c3)cc(-c3ccc4c(c3)-c3cccc5cccc(c35)S4)cc2c1 ; c1cc2c3c(cccc3c1)-c1cc(-c3ccc(-c4cccc5c4ccc4c6ccc7ccccc7c6oc54)c4ccccc34)ccc1S2]

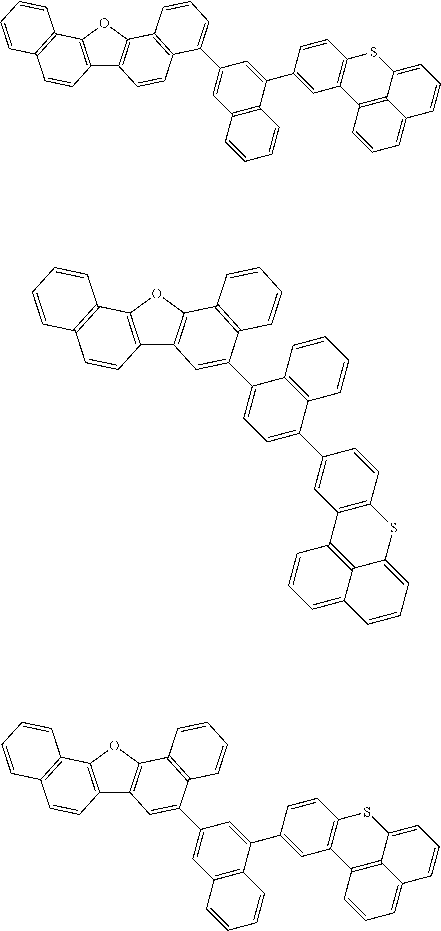 [SMILES: c1ccc2c(-c3ccc4c(c3)-c3cccc5cccc(c35)S4)cc(-c3cccc4c3ccc3c5ccc6ccccc6c5oc43)cc2c1 ; c1cc2c3c(cccc3c1)-c1cc(-c3ccc(-c4cc5c6ccc7ccccc7c6oc5c5ccccc45)c4ccccc34)ccc1S2 ; c1ccc2c(-c3ccc4c(c3)-c3cccc5cccc(c35)S4)cc(-c3cc4c5ccc6ccccc6c5oc4c4ccccc34)cc2c1]

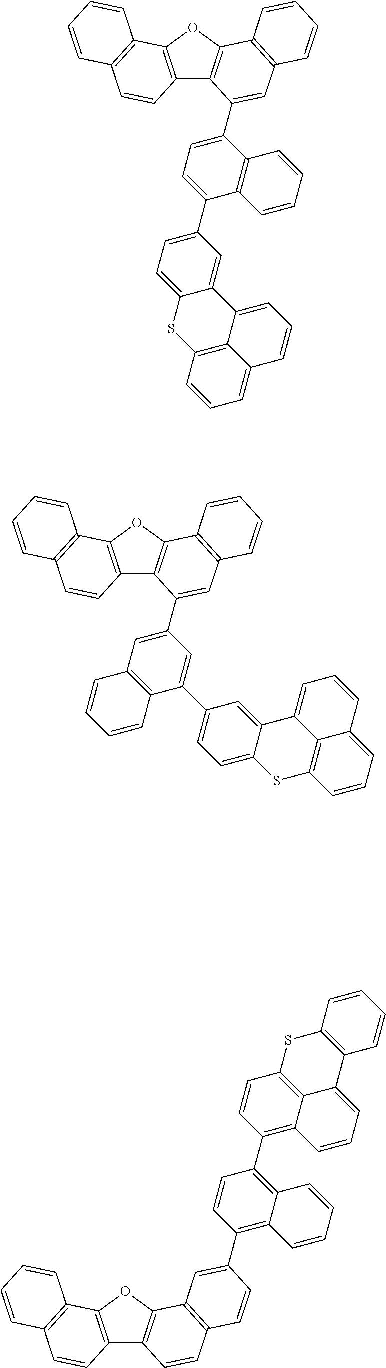 [SMILES: c1cc2c3c(cccc3c1)-c1cc(-c3ccc(-c4cc5ccccc5c5oc6c7ccccc7ccc6c45)c4ccccc34)ccc1S2 ; c1ccc2c(-c3ccc4c(c3)-c3cccc5cccc(c35)S4)cc(-c3cc4ccccc4c4oc5c6ccccc6ccc5c34)cc2c1 ; c1ccc2c(c1)Sc1ccc(-c3ccc(-c4ccc5ccc6c7ccc8ccccc8c7oc6c5c4)c4ccccc34)c3cccc-2c13]

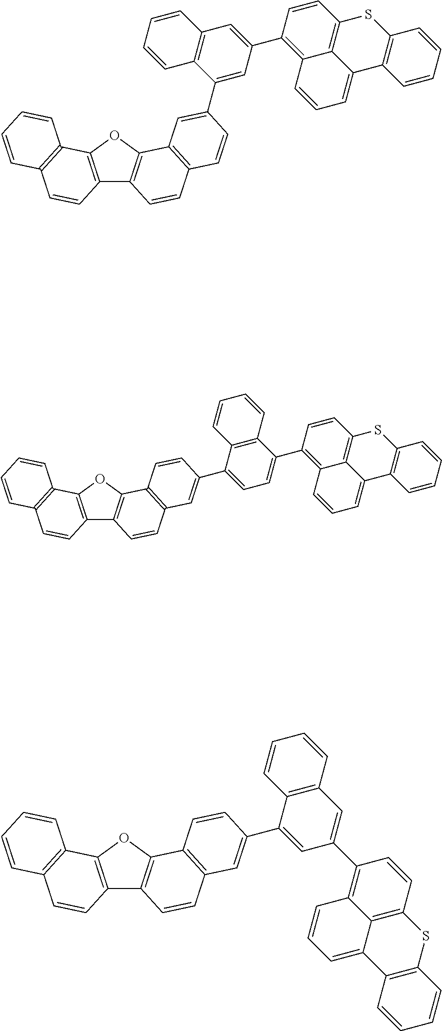 [SMILES: c1ccc2c(c1)Sc1ccc(-c3cc(-c4ccc5ccc6c7ccc8ccccc8c7oc6c5c4)c4ccccc4c3)c3cccc-2c13 ; c1ccc2c(c1)Sc1ccc(-c3ccc(-c4ccc5c(ccc6c7ccc8ccccc8c7oc56)c4)c4ccccc34)c3cccc-2c13 ; c1ccc2c(c1)Sc1ccc(-c3cc(-c4ccc5c(ccc6c7ccc8ccccc8c7oc56)c4)c4ccccc4c3)c3cccc-2c13]

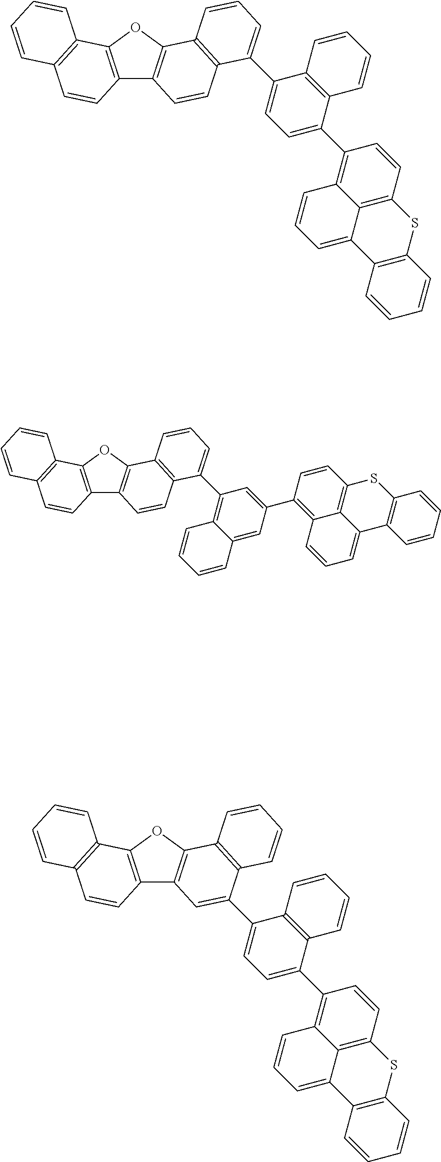 [SMILES: c1ccc2c(c1)Sc1ccc(-c3ccc(-c4cccc5c4ccc4c6ccc7ccccc7c6oc54)c4ccccc34)c3cccc-2c13 ; c1ccc2c(c1)Sc1ccc(-c3cc(-c4cccc5c4ccc4c6ccc7ccccc7c6oc54)c4ccccc4c3)c3cccc-2c13 ; c1ccc2c(c1)Sc1ccc(-c3ccc(-c4cc5c6ccc7ccccc7c6oc5c5ccccc45)c4ccccc34)c3cccc-2c13]

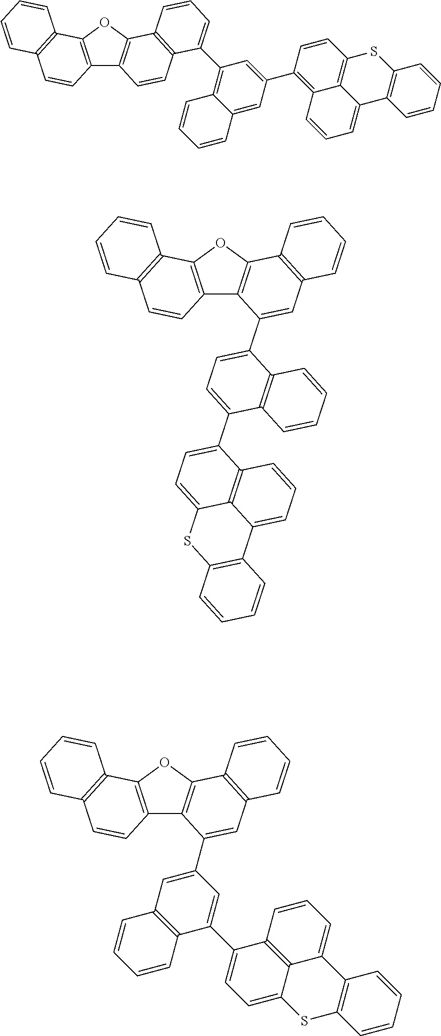 [SMILES: c1ccc2c(c1)Sc1ccc(-c3cc(-c4cccc5c4ccc4c6ccc7ccccc7c6oc54)c4ccccc4c3)c3cccc-2c13 ; c1ccc2c(c1)Sc1ccc(-c3ccc(-c4cc5ccccc5c5oc6c7ccccc7ccc6c45)c4ccccc34)c3cccc-2c13 ; c1ccc2c(c1)Sc1ccc(-c3cc(-c4cc5ccccc5c5oc6c7ccccc7ccc6c45)cc4ccccc34)c3cccc-2c13]

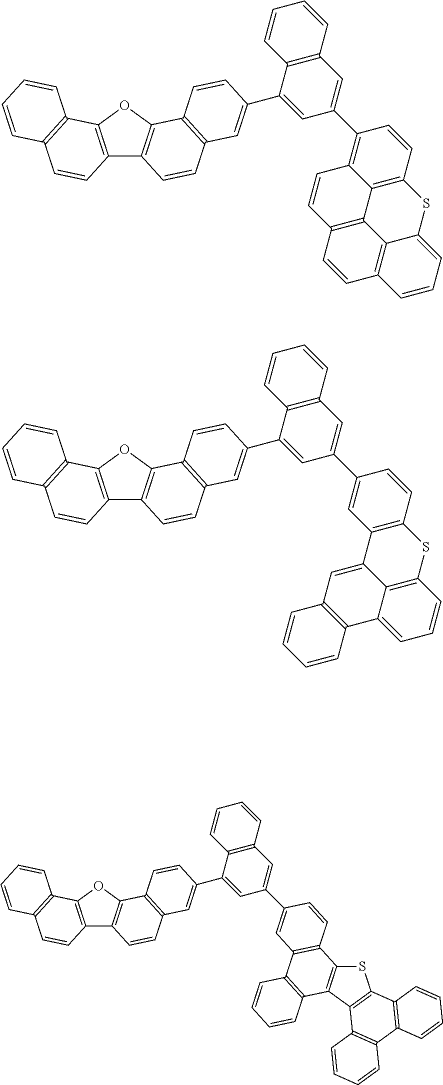

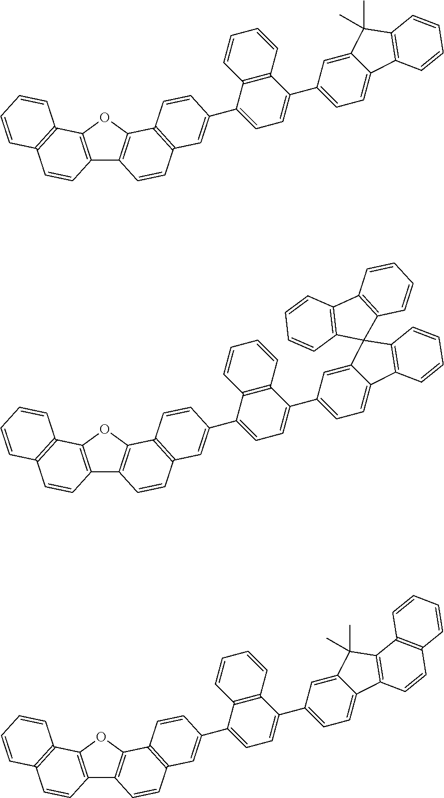 [SMILES: CC1(C)c2ccccc2-c2ccc(-c3ccc(-c4ccc5c(ccc6c7ccc8ccccc8c7oc56)c4)c4ccccc34)cc21 ; c1ccc2c(c1)-c1ccccc1C21c2ccccc2-c2ccc(-c3ccc(-c4ccc5c(ccc6c7ccc8ccccc8c7oc56)c4)c4ccccc34)cc21 ; CC1(C)c2cc(-c3ccc(-c4ccc5c(ccc6c7ccc8ccccc8c7oc56)c4)c4ccccc34)ccc2-c2ccc3ccccc3c21]

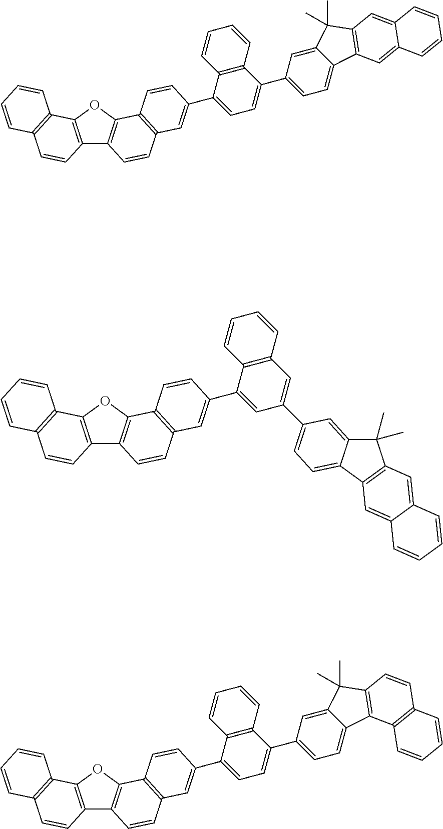 [SMILES: CC1(C)c2cc(-c3ccc(-c4ccc5c(ccc6c7ccc8ccccc8c7oc56)c4)c4ccccc34)ccc2-c2cc3ccccc3cc21 ; CC1(C)c2cc(-c3cc(-c4ccc5c(ccc6c7ccc8ccccc8c7oc56)c4)c4ccccc4c3)ccc2-c2cc3ccccc3cc21 ; CC1(C)c2cc(-c3ccc(-c4ccc5c(ccc6c7ccc8ccccc8c7oc56)c4)c4ccccc34)ccc2-c2c1ccc1ccccc21]

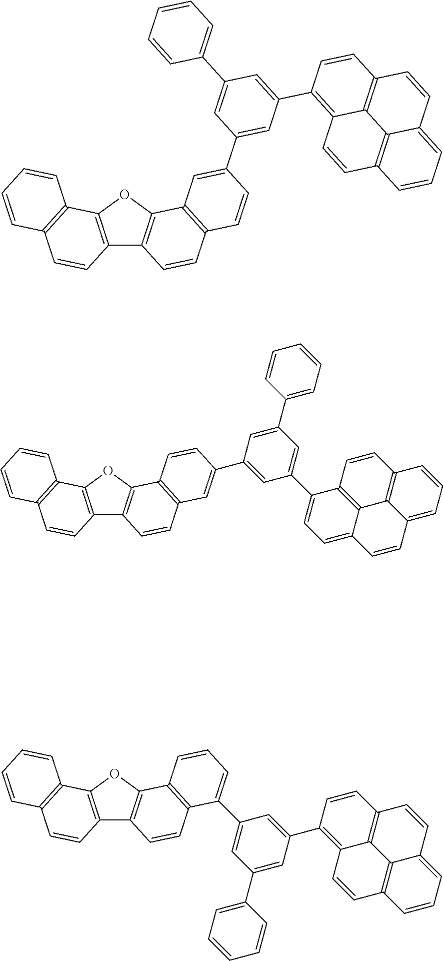 [SMILES: c1ccc(-c2cc(-c3ccc4ccc5c6ccc7ccccc7c6oc5c4c3)cc(-c3ccc4ccc5cccc6ccc3c4c56)c2)cc1 ; c1ccc(-c2cc(-c3ccc4c(ccc5c6ccc7ccccc7c6oc45)c3)cc(-c3ccc4ccc5cccc6ccc3c4c56)c2)cc1 ; c1ccc(-c2cc(-c3cccc4c3ccc3c5ccc6ccccc6c5oc43)cc(-c3ccc4ccc5cccc6ccc3c4c56)c2)cc1]

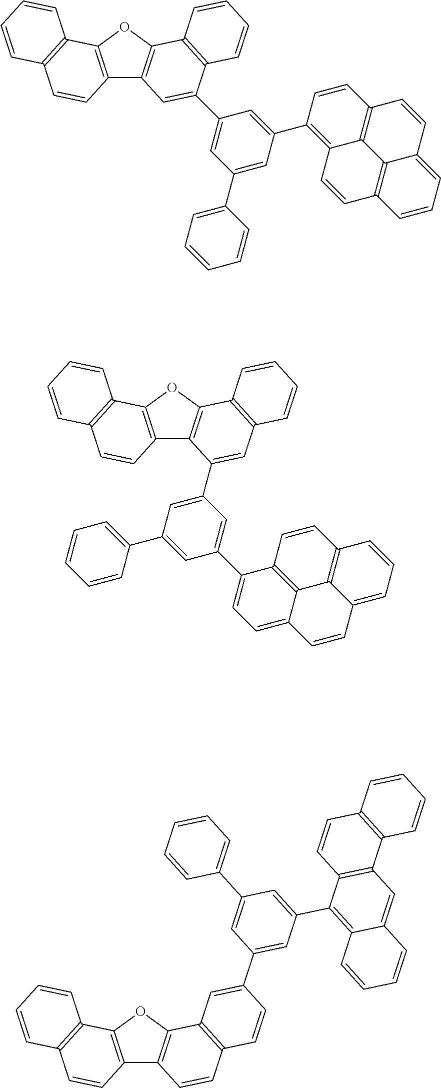 [SMILES: c1ccc(-c2cc(-c3cc4c5ccc6ccccc6c5oc4c4ccccc34)cc(-c3ccc4ccc5cccc6ccc3c4c56)c2)cc1 ; c1ccc(-c2cc(-c3ccc4ccc5cccc6ccc3c4c56)cc(-c3cc4ccccc4c4oc5c6ccccc6ccc5c34)c2)cc1 ; c1ccc(-c2cc(-c3ccc4ccc5c6ccc7ccccc7c6oc5c4c3)cc(-c3c4ccccc4cc4c3ccc3ccccc34)c2)cc1]

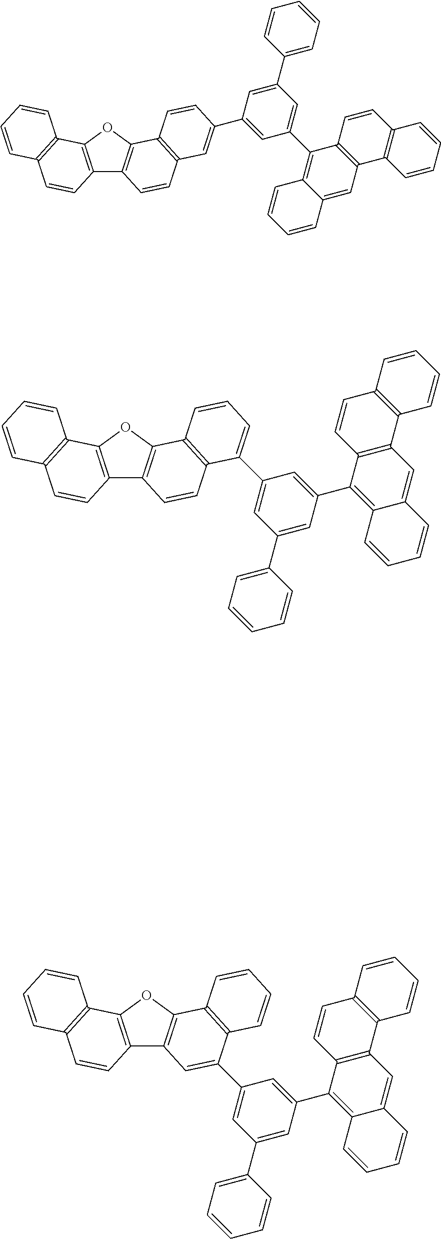 [SMILES: c1ccc(-c2cc(-c3ccc4c(ccc5c6ccc7ccccc7c6oc45)c3)cc(-c3c4ccccc4cc4c3ccc3ccccc34)c2)cc1 ; c1ccc(-c2cc(-c3c4ccccc4cc4c3ccc3ccccc34)cc(-c3cccc4c3ccc3c5ccc6ccccc6c5oc43)c2)cc1 ; c1ccc(-c2cc(-c3c4ccccc4cc4c3ccc3ccccc34)cc(-c3cc4c5ccc6ccccc6c5oc4c4ccccc34)c2)cc1]

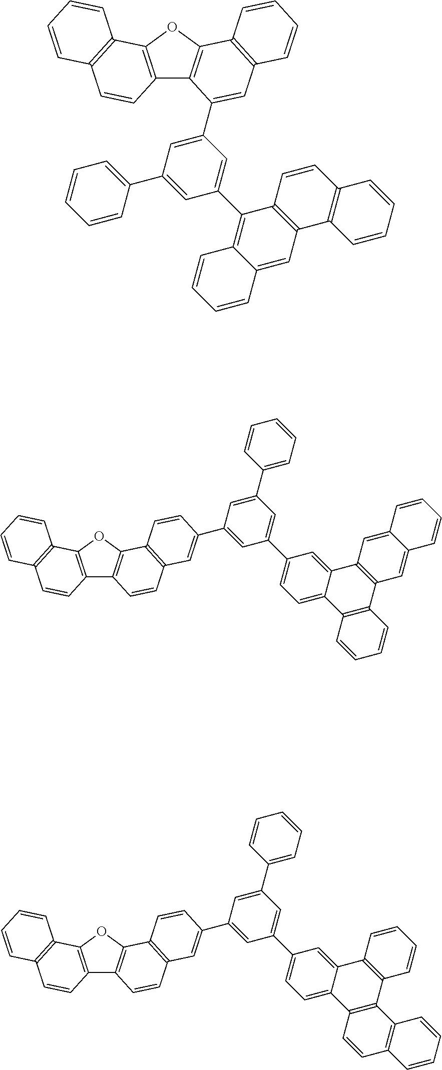 [SMILES: c1ccc(-c2cc(-c3c4ccccc4cc4c3ccc3ccccc34)cc(-c3cc4ccccc4c4oc5c6ccccc6ccc5c34)c2)cc1 ; c1ccc(-c2cc(-c3ccc4c(ccc5c6ccc7ccccc7c6oc45)c3)cc(-c3ccc4c5ccccc5c5cc6ccccc6cc5c4c3)c2)cc1 ; c1ccc(-c2cc(-c3ccc4c(ccc5c6ccc7ccccc7c6oc45)c3)cc(-c3ccc4c(c3)c3ccccc3c3c5ccccc5ccc43)c2)cc1]

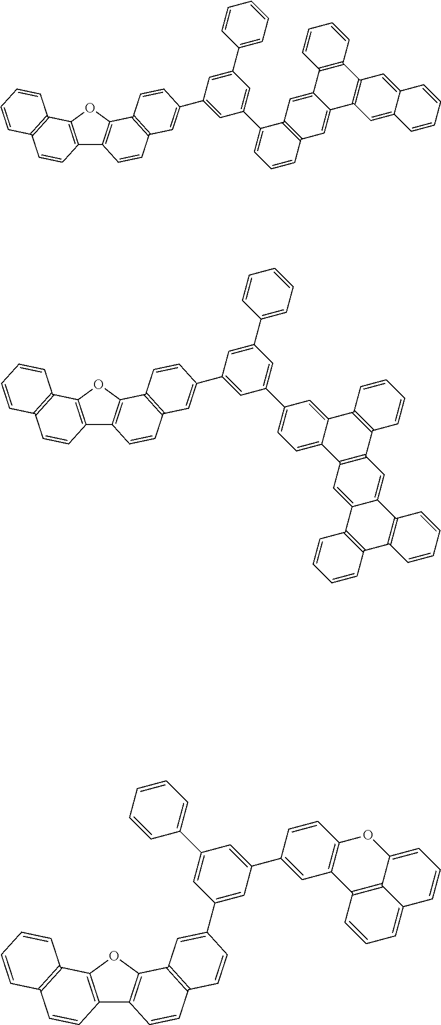 [SMILES: c1ccc(-c2cc(-c3ccc4c(ccc5c6ccc7ccccc7c6oc45)c3)cc(-c3cccc4cc5c6cc7ccccc7cc6c6ccccc6c5cc34)c2)cc1 ; c1ccc(-c2cc(-c3ccc4c(ccc5c6ccc7ccccc7c6oc45)c3)cc(-c3ccc4c(c3)c3ccccc3c3cc5c6ccccc6c6ccccc6c5cc43)c2)cc1 ; c1ccc(-c2cc(-c3ccc4c(c3)-c3cccc5cccc(c35)O4)cc(-c3ccc4ccc5c6ccc7ccccc7c6oc5c4c3)c2)cc1]

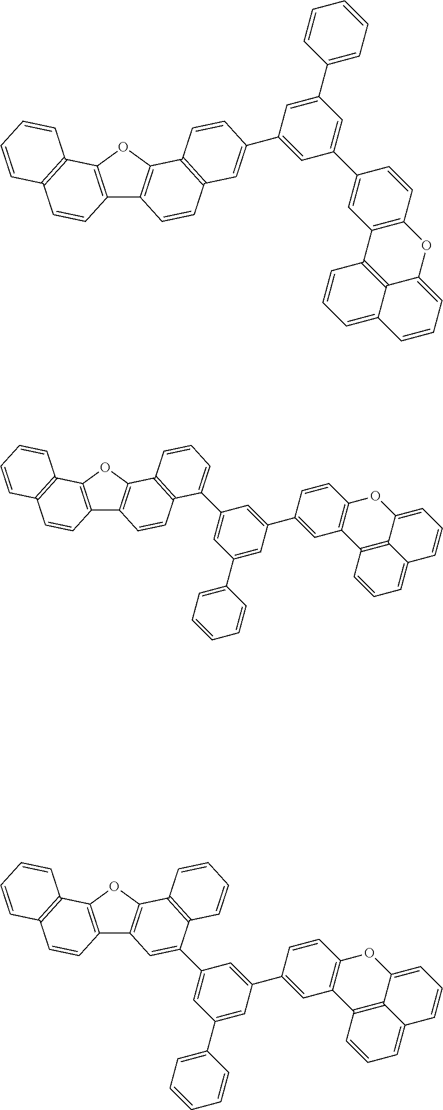 [SMILES: c1ccc(-c2cc(-c3ccc4c(c3)-c3cccc5cccc(c35)O4)cc(-c3ccc4c(ccc5c6ccc7ccccc7c6oc45)c3)c2)cc1 ; c1ccc(-c2cc(-c3ccc4c(c3)-c3cccc5cccc(c35)O4)cc(-c3cccc4c3ccc3c5ccc6ccccc6c5oc43)c2)cc1 ; c1ccc(-c2cc(-c3ccc4c(c3)-c3cccc5cccc(c35)O4)cc(-c3cc4c5ccc6ccccc6c5oc4c4ccccc34)c2)cc1]

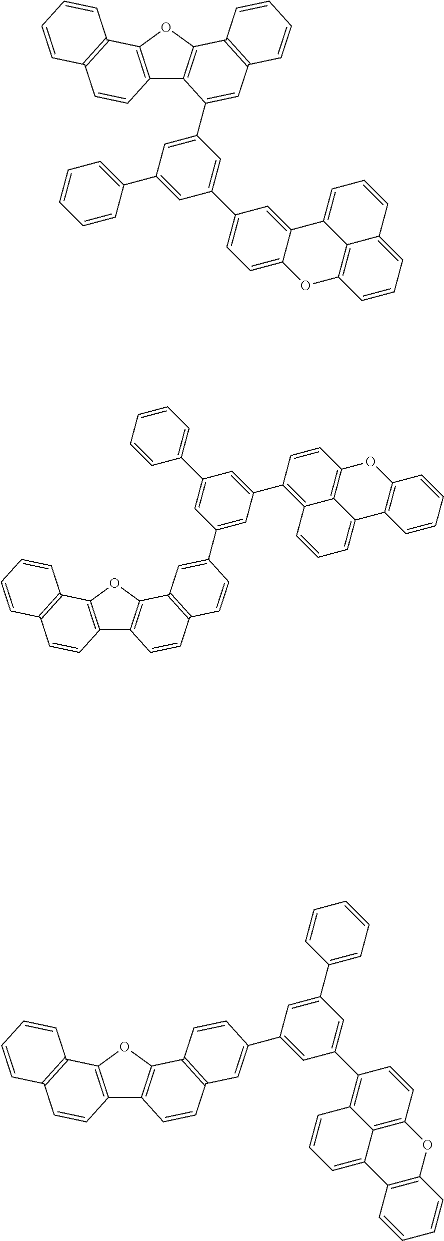 [SMILES: c1ccc(-c2cc(-c3ccc4c(c3)-c3cccc5cccc(c35)O4)cc(-c3cc4ccccc4c4oc5c6ccccc6ccc5c34)c2)cc1 ; c1ccc(-c2cc(-c3ccc4ccc5c6ccc7ccccc7c6oc5c4c3)cc(-c3ccc4c5c(cccc35)-c3ccccc3O4)c2)cc1 ; c1ccc(-c2cc(-c3ccc4c(ccc5c6ccc7ccccc7c6oc45)c3)cc(-c3ccc4c5c(cccc35)-c3ccccc3O4)c2)cc1]

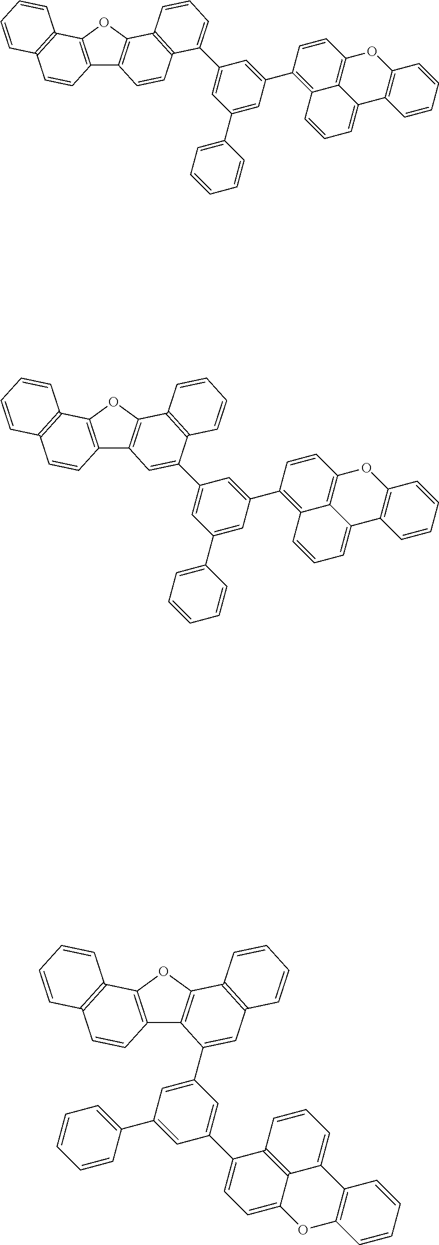 [SMILES: c1ccc(-c2cc(-c3ccc4c5c(cccc35)-c3ccccc3O4)cc(-c3cccc4c3ccc3c5ccc6ccccc6c5oc43)c2)cc1 ; c1ccc(-c2cc(-c3ccc4c5c(cccc35)-c3ccccc3O4)cc(-c3cc4c5ccc6ccccc6c5oc4c4ccccc34)c2)cc1 ; c1ccc(-c2cc(-c3ccc4c5c(cccc35)-c3ccccc3O4)cc(-c3cc4ccccc4c4oc5c6ccccc6ccc5c34)c2)cc1]

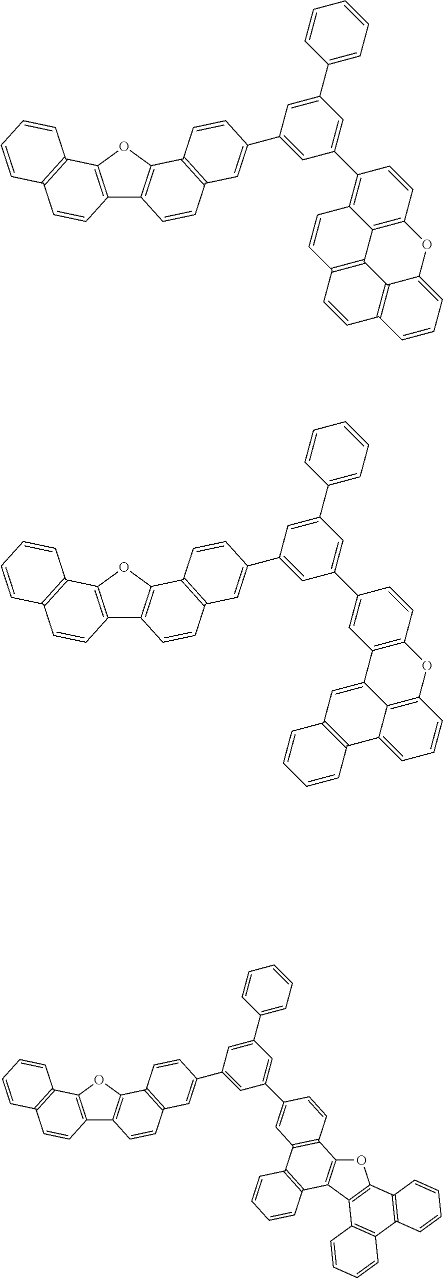 [SMILES: c1ccc(-c2cc(-c3ccc4c(ccc5c6ccc7ccccc7c6oc45)c3)cc(-c3ccc4c5c3ccc3ccc6cccc(c6c35)O4)c2)cc1 ; c1ccc(-c2cc(-c3ccc4c(c3)-c3cc5ccccc5c5cccc(c35)O4)cc(-c3ccc4c(ccc5c6ccc7ccccc7c6oc45)c3)c2)cc1 ; c1ccc(-c2cc(-c3ccc4c(ccc5c6ccc7ccccc7c6oc45)c3)cc(-c3ccc4c(c3)c3ccccc3c3c4oc4c5ccccc5c5ccccc5c43)c2)cc1]

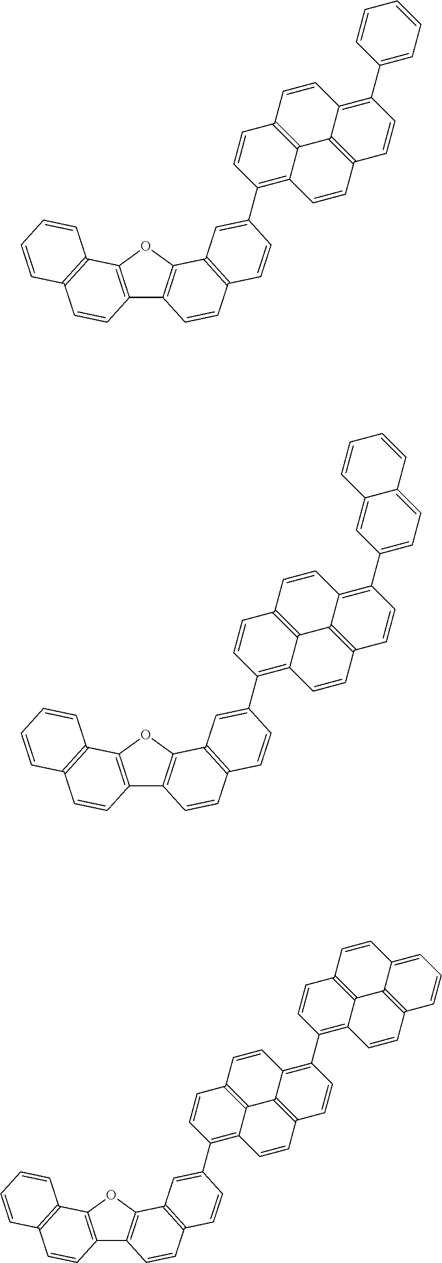 [SMILES: c1ccc(-c2ccc3ccc4c(-c5ccc6ccc7c8ccc9ccccc9c8oc7c6c5)ccc5ccc2c3c54)cc1 ; c1ccc2cc(-c3ccc4ccc5c(-c6ccc7ccc8c9ccc%10ccccc%10c9oc8c7c6)ccc6ccc3c4c65)ccc2c1 ; c1ccc2c(c1)ccc1c3ccc4ccc(-c5ccc6ccc7c(-c8ccc9ccc%10cccc%11ccc8c9c%10%11)ccc8ccc5c6c87)cc4c3oc21]

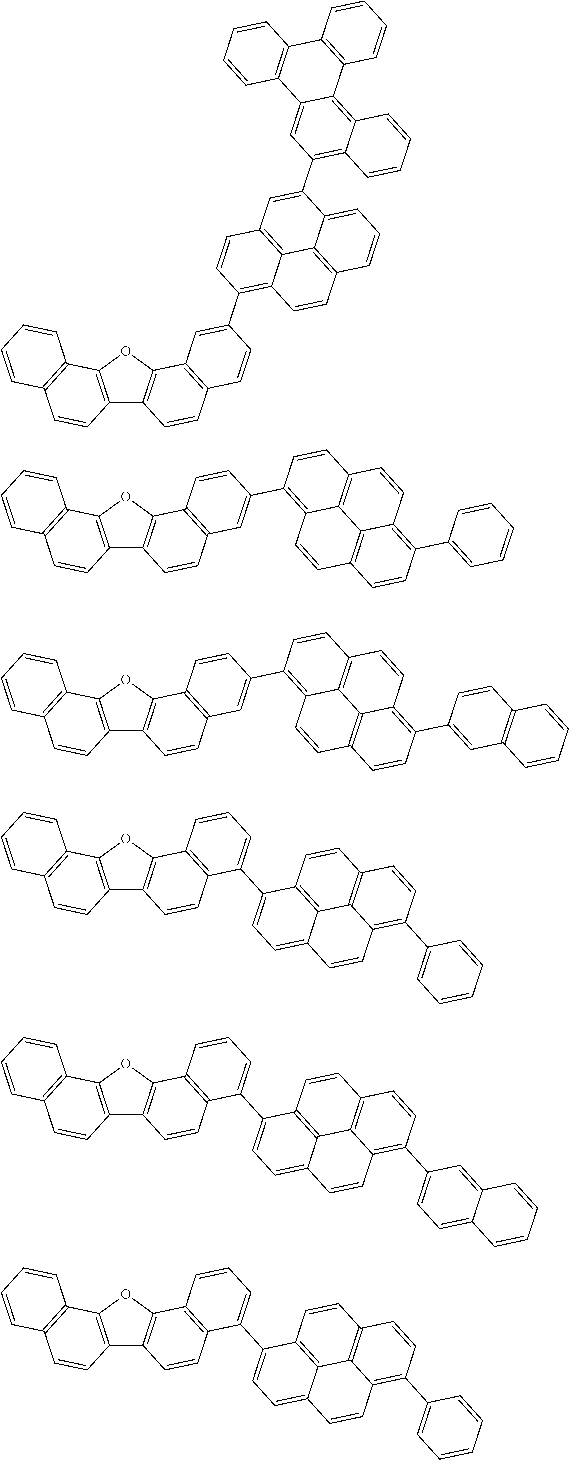 [SMILES: c1ccc2c(c1)ccc1c3ccc4ccc(-c5ccc6cc(-c7cc8c9ccccc9c9ccccc9c8c8ccccc78)c7cccc8ccc5c6c87)cc4c3oc21 ; c1ccc(-c2ccc3ccc4c(-c5ccc6c(ccc7c8ccc9ccccc9c8oc67)c5)ccc5ccc2c3c54)cc1 ; c1ccc2cc(-c3ccc4ccc5c(-c6ccc7c(ccc8c9ccc%10ccccc%10c9oc78)c6)ccc6ccc3c4c65)ccc2c1 ; c1ccc(-c2ccc3ccc4c(-c5cccc6c5ccc5c7ccc8ccccc8c7oc65)ccc5ccc2c3c54)cc1 ; c1ccc2cc(-c3ccc4ccc5c(-c6cccc7c6ccc6c8ccc9ccccc9c8oc76)ccc6ccc3c4c65)ccc2c1 ; c1ccc(-c2ccc3ccc4c(-c5cccc6c5ccc5c7ccc8ccccc8c7oc65)ccc5ccc2c3c54)cc1]

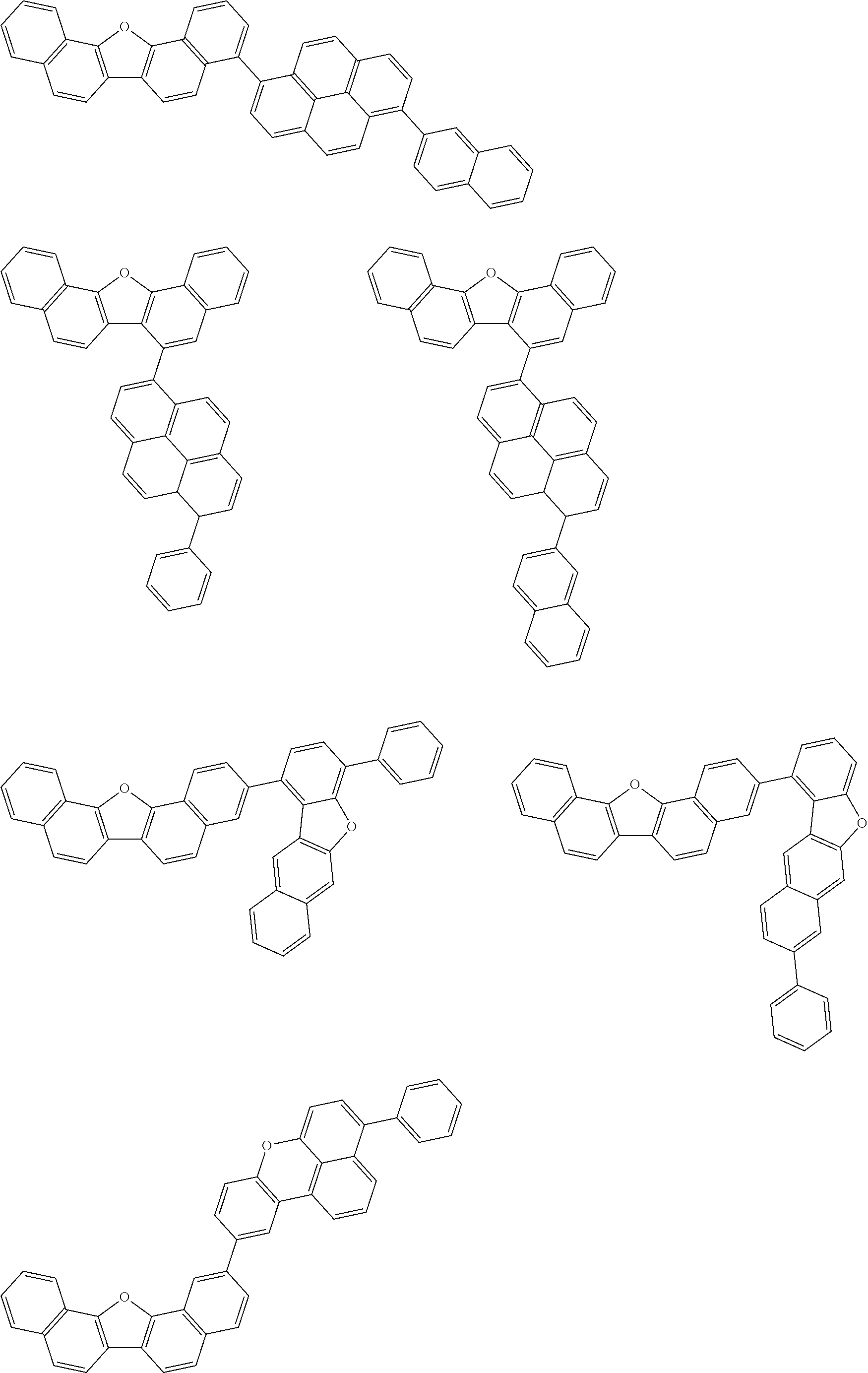 [SMILES: c1ccc2cc(-c3ccc4ccc5c(-c6cccc7c6ccc6c8ccc9ccccc9c8oc76)ccc6ccc3c4c65)ccc2c1 ; C1=CC(c2ccccc2)C2C=Cc3ccc(-c4cc5ccccc5c5oc6c7ccccc7ccc6c45)c4ccc1c2c34 ; C1=CC(c2ccc3ccccc3c2)C2C=Cc3ccc(-c4cc5ccccc5c5oc6c7ccccc7ccc6c45)c4ccc1c2c34 ; c1ccc(-c2ccc(-c3ccc4c(ccc5c6ccc7ccccc7c6oc45)c3)c3c2oc2cc4ccccc4cc23)cc1 ; c1ccc(-c2ccc3cc4c(cc3c2)oc2cccc(-c3ccc5c(ccc6c7ccc8ccccc8c7oc56)c3)c24)cc1 ; c1ccc(-c2ccc3c4c(cccc24)-c2cc(-c4ccc5ccc6c7ccc8ccccc8c7oc6c5c4)ccc2O3)cc1]

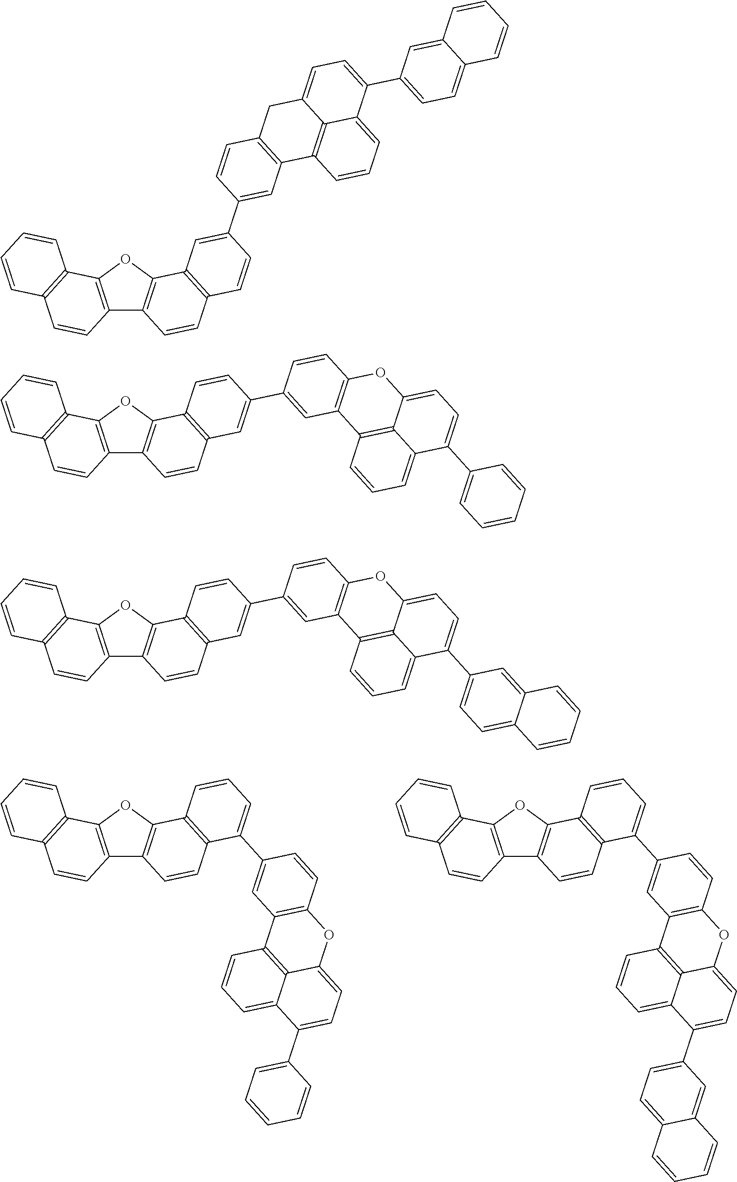 [SMILES: c1ccc2cc(-c3ccc4c5c(cccc35)-c3cc(-c5ccc6ccc7c8ccc9ccccc9c8oc7c6c5)ccc3C4)ccc2c1 ; c1ccc(-c2ccc3c4c(cccc24)-c2cc(-c4ccc5c(ccc6c7ccc8ccccc8c7oc56)c4)ccc2O3)cc1 ; c1ccc2cc(-c3ccc4c5c(cccc35)-c3cc(-c5ccc6c(ccc7c8ccc9ccccc9c8oc67)c5)ccc3O4)ccc2c1 ; c1ccc(-c2ccc3c4c(cccc24)-c2cc(-c4cccc5c4ccc4c6ccc7ccccc7c6oc54)ccc2O3)cc1 ; c1ccc2cc(-c3ccc4c5c(cccc35)-c3cc(-c5cccc6c5ccc5c7ccc8ccccc8c7oc65)ccc3O4)ccc2c1]

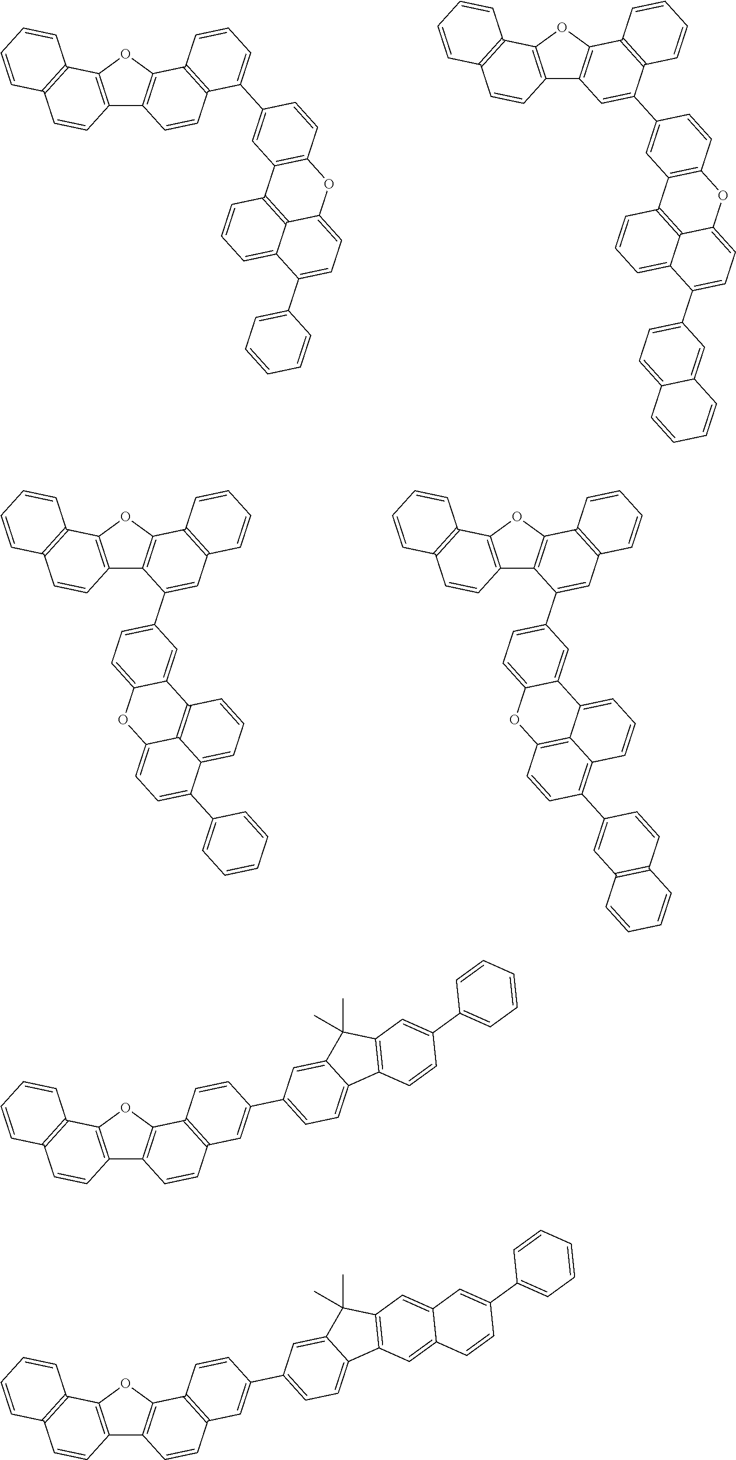 [SMILES: c1ccc(-c2ccc3c4c(cccc24)-c2cc(-c4cccc5c4ccc4c6ccc7ccccc7c6oc54)ccc2O3)cc1 ; c1ccc2cc(-c3ccc4c5c(cccc35)-c3cc(-c5cc6c7ccc8ccccc8c7oc6c6ccccc56)ccc3O4)ccc2c1 ; c1ccc(-c2ccc3c4c(cccc24)-c2cc(-c4cc5ccccc5c5oc6c7ccccc7ccc6c45)ccc2O3)cc1 ; c1ccc2cc(-c3ccc4c5c(cccc35)-c3cc(-c5cc6ccccc6c6oc7c8ccccc8ccc7c56)ccc3O4)ccc2c1 ; CC1(C)c2cc(-c3ccccc3)ccc2-c2ccc(-c3ccc4c(ccc5c6ccc7ccccc7c6oc45)c3)cc21 ; CC1(C)c2cc(-c3ccc4c(ccc5c6ccc7ccccc7c6oc45)c3)ccc2-c2cc3ccc(-c4ccccc4)cc3cc21]

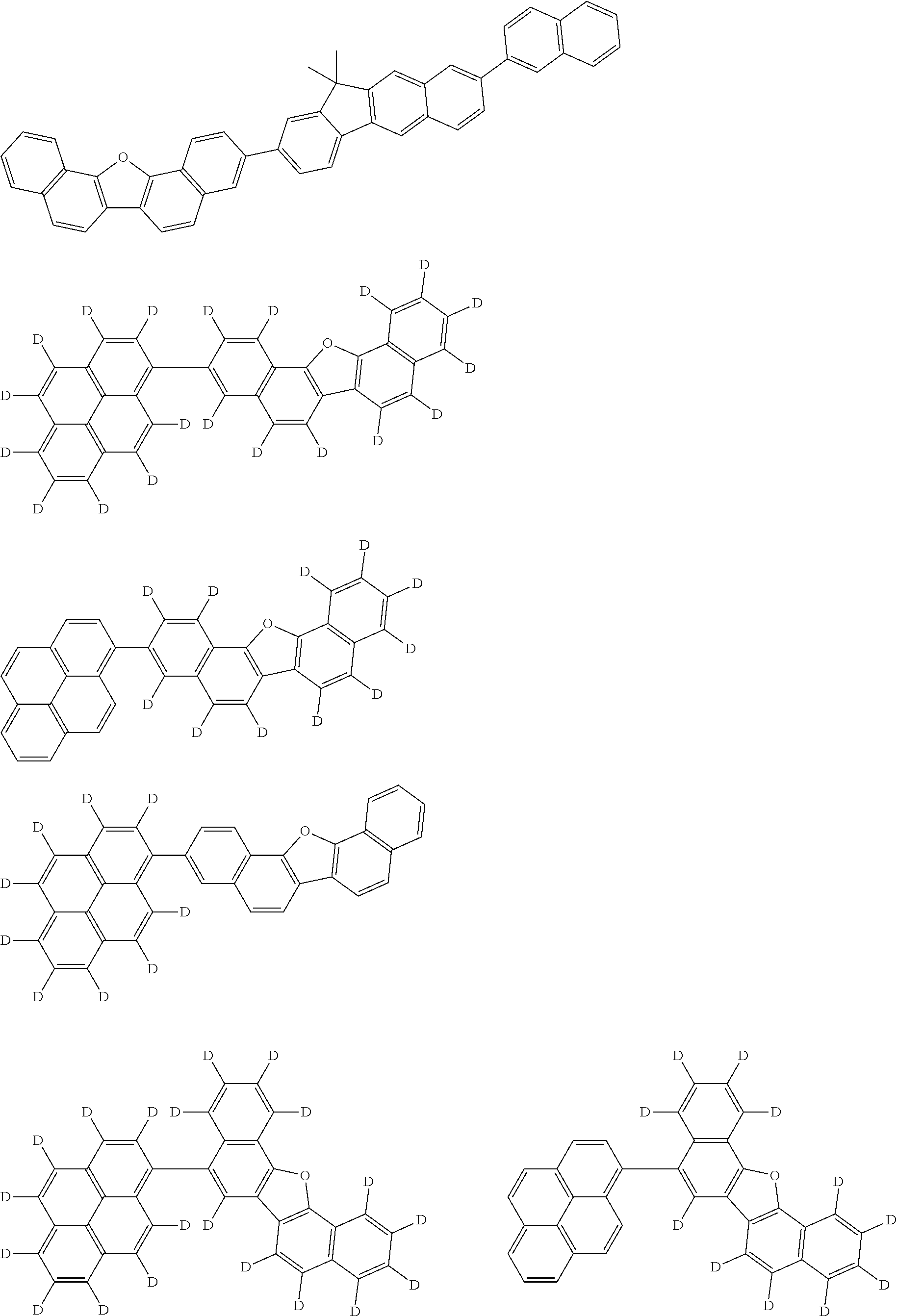

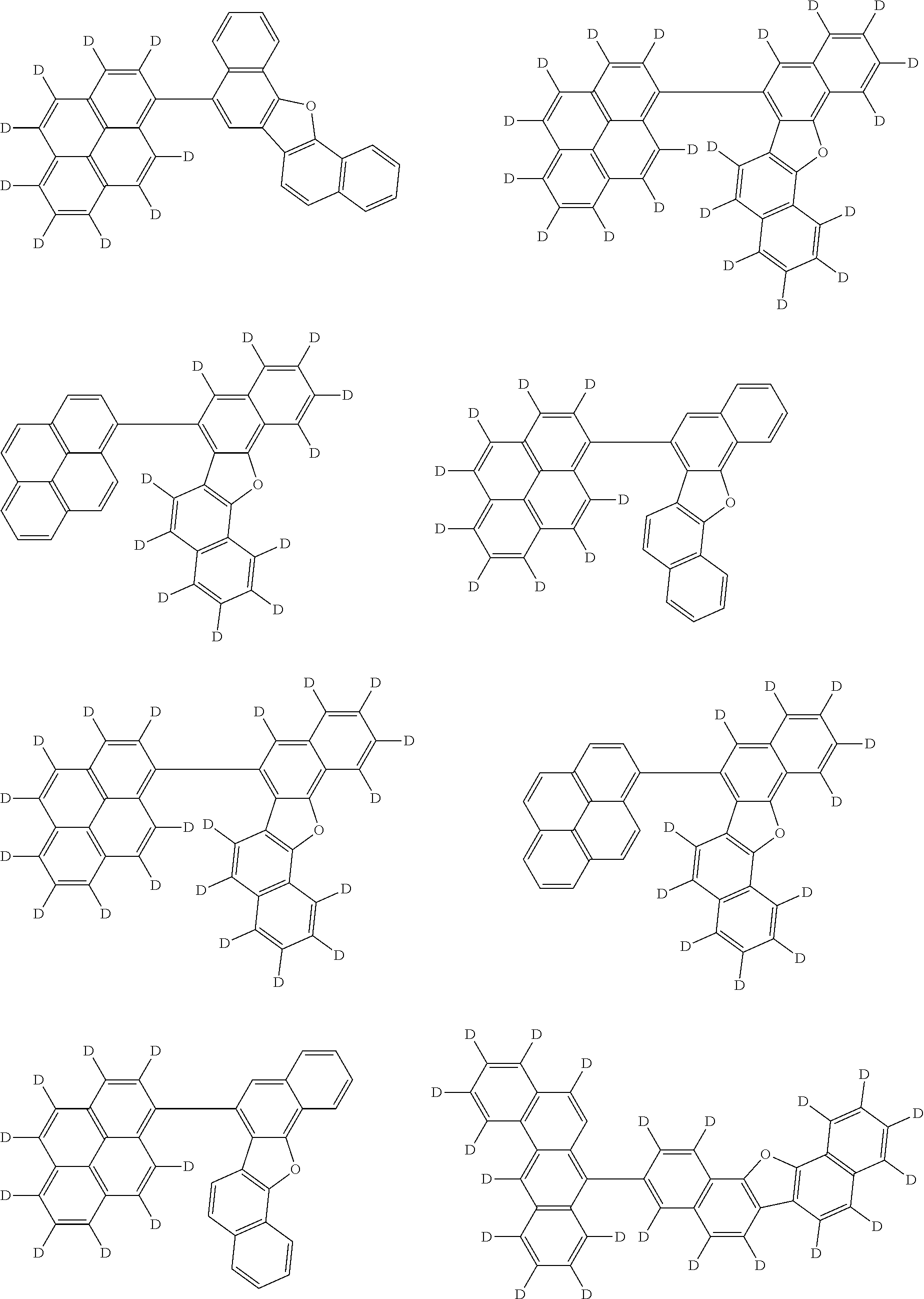

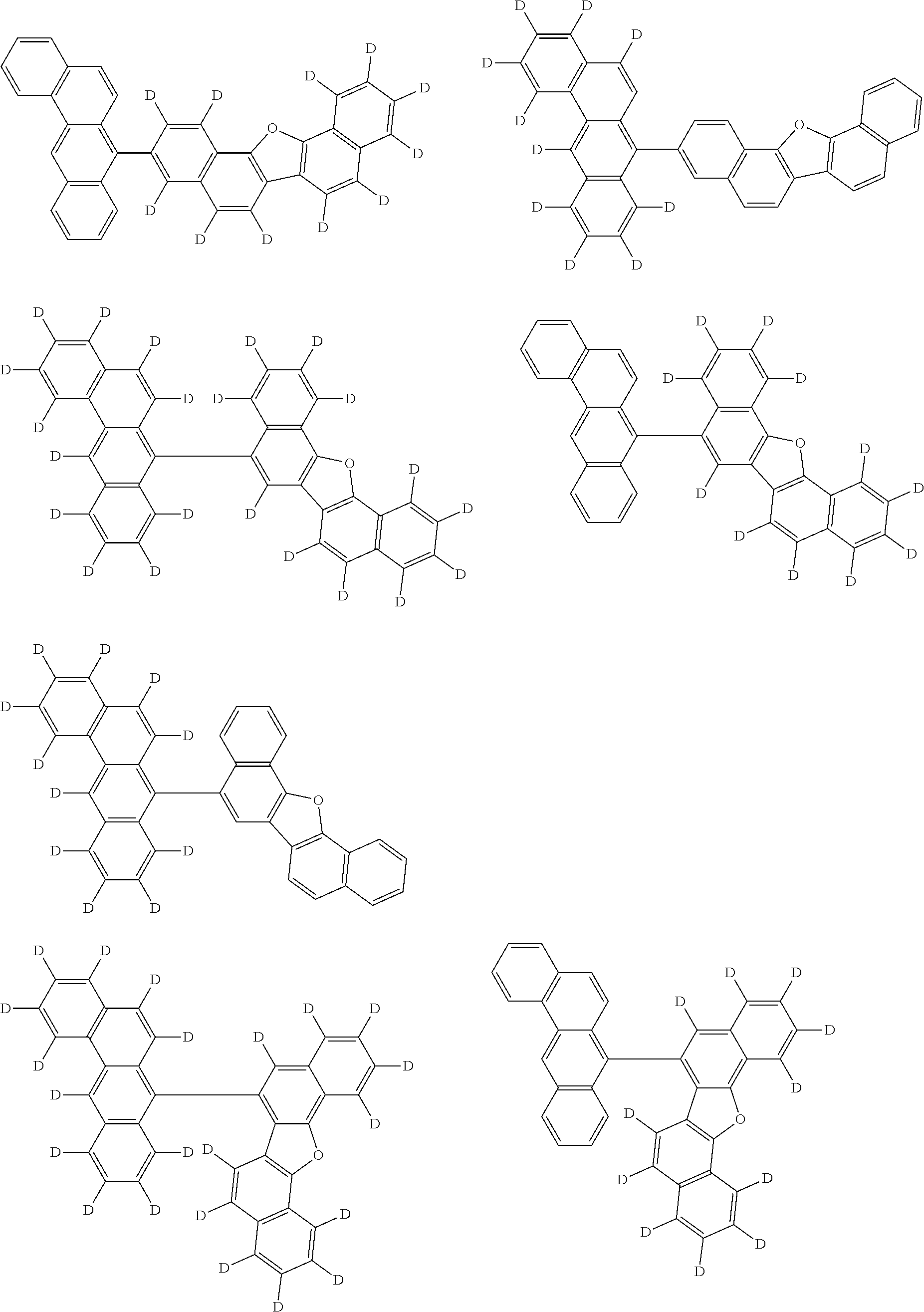

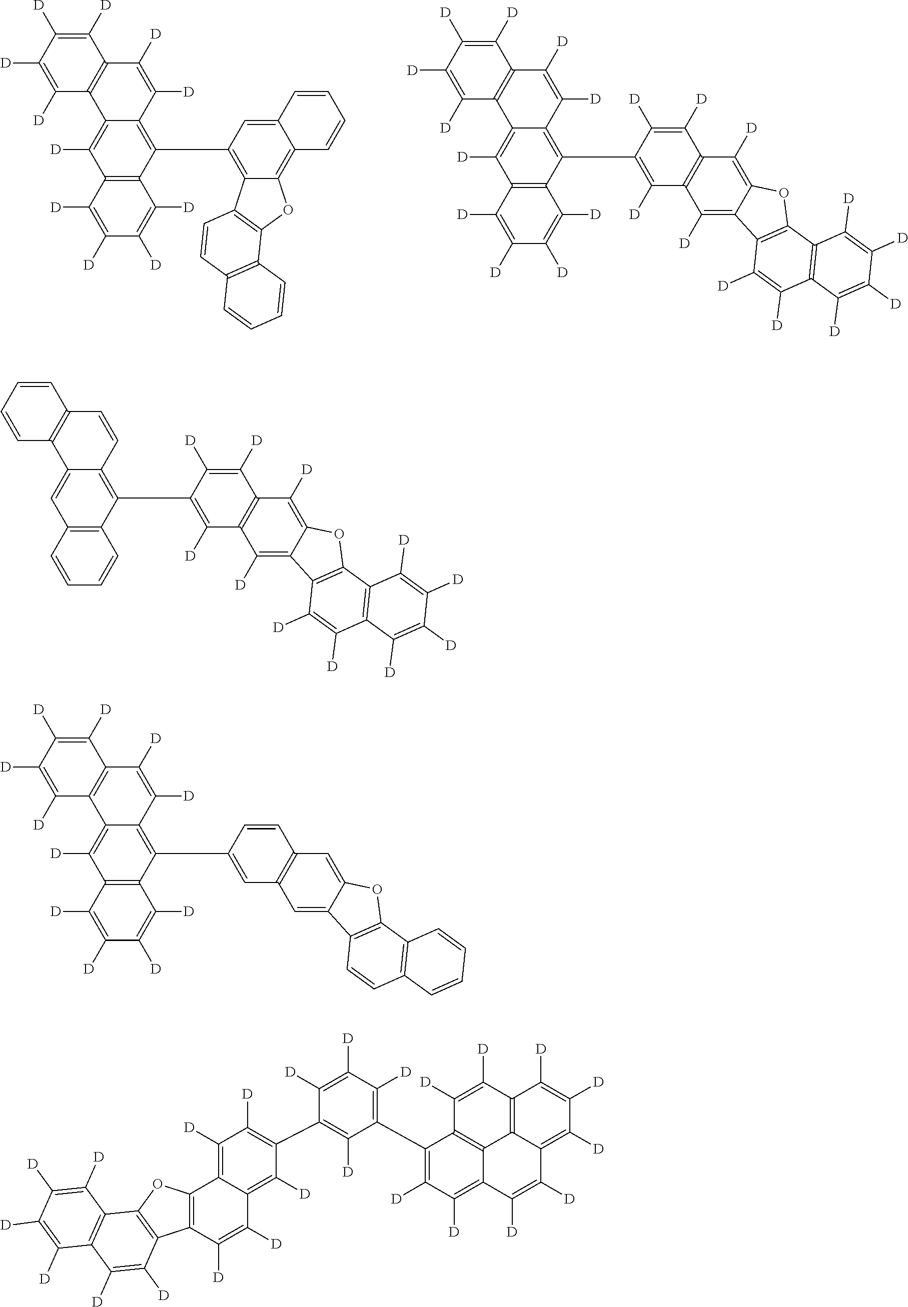

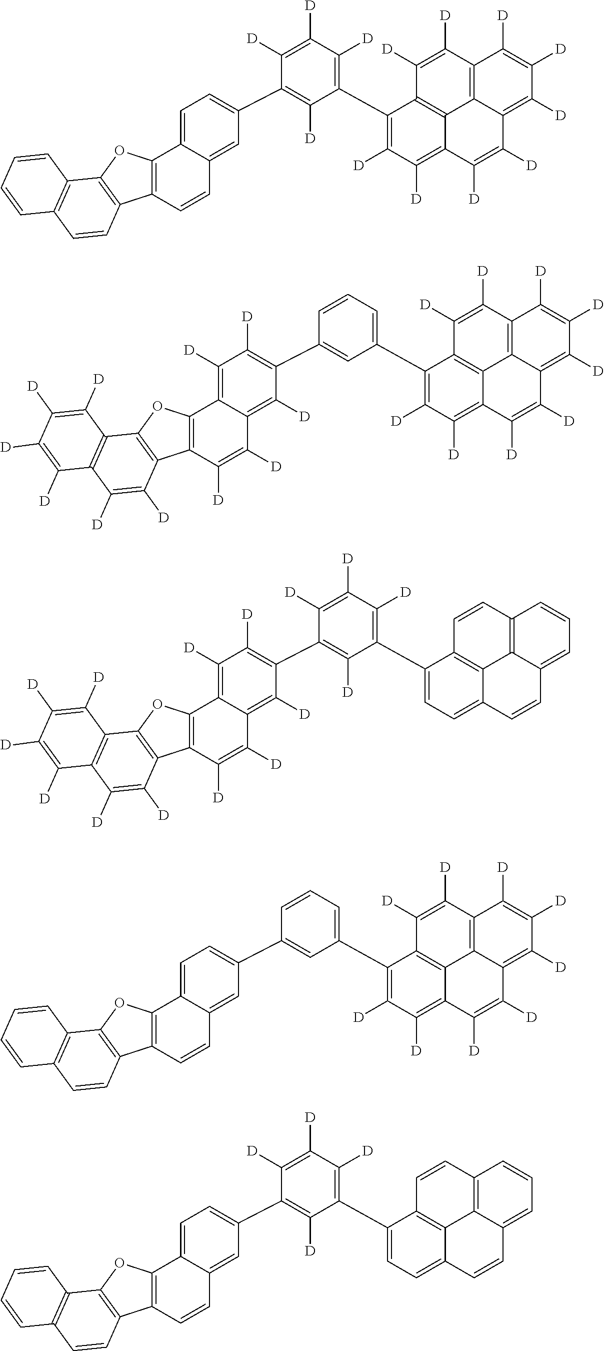

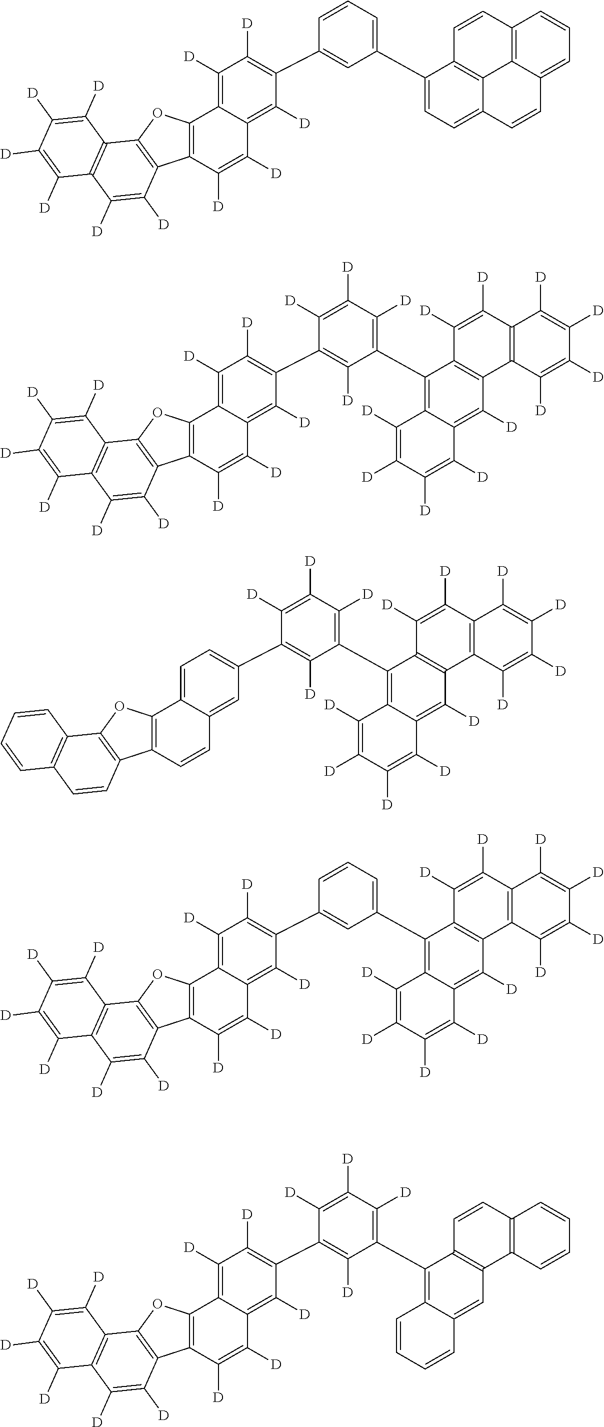

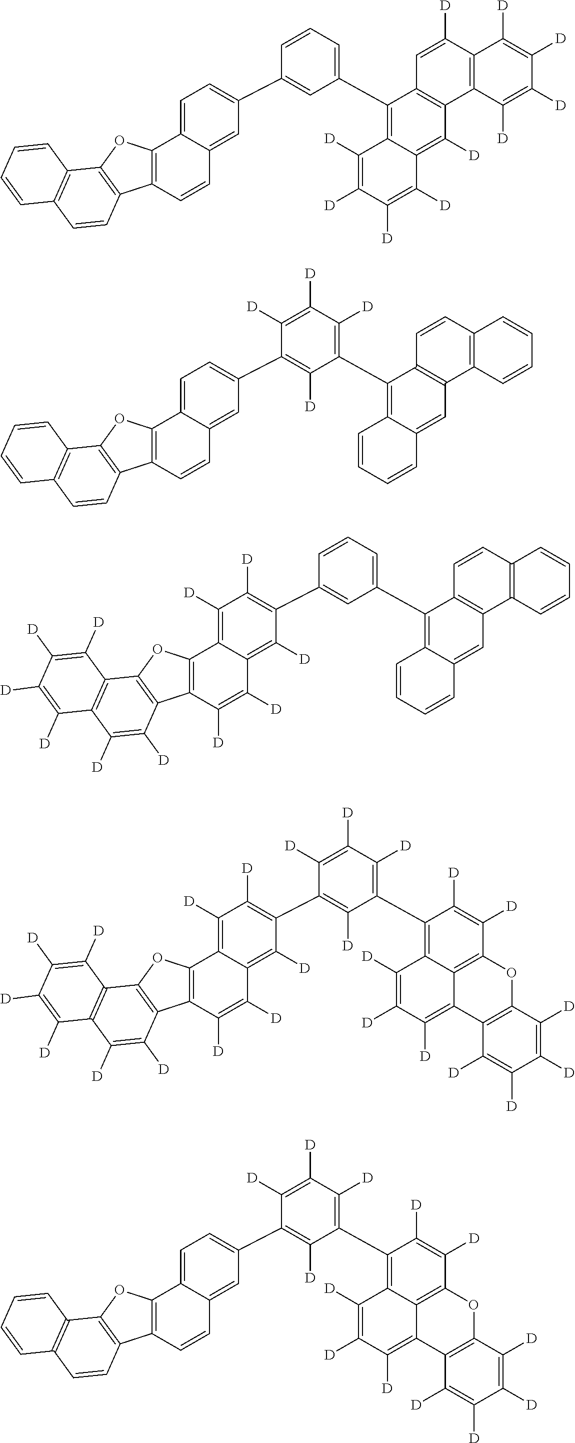

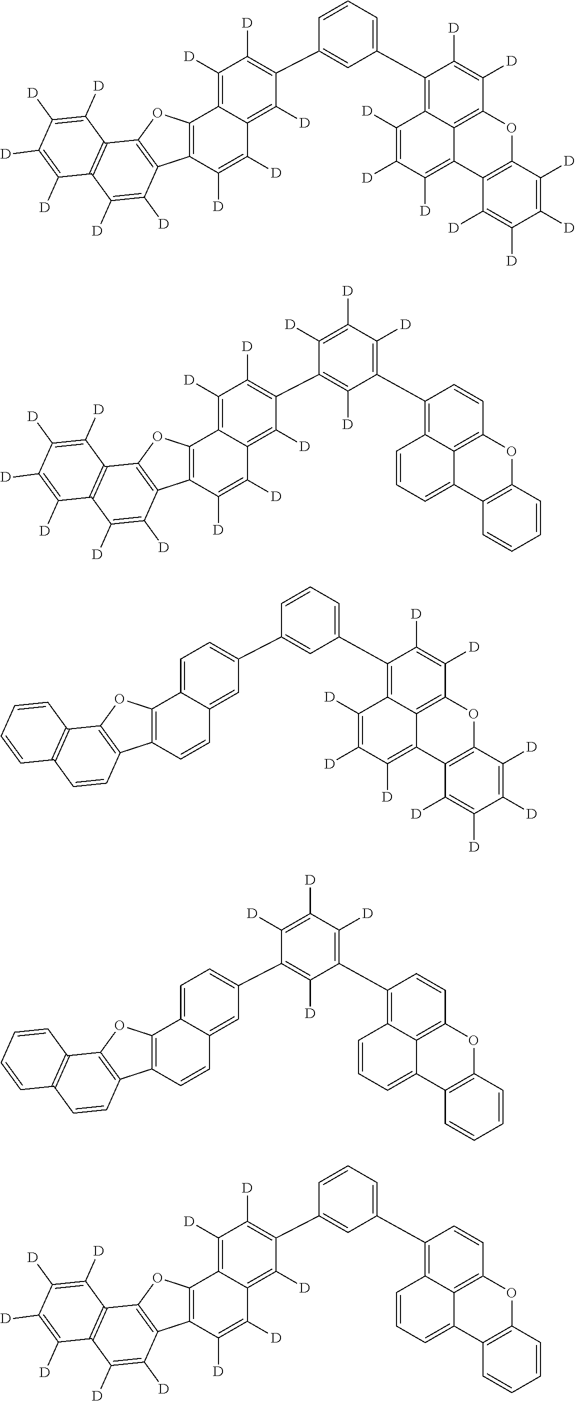

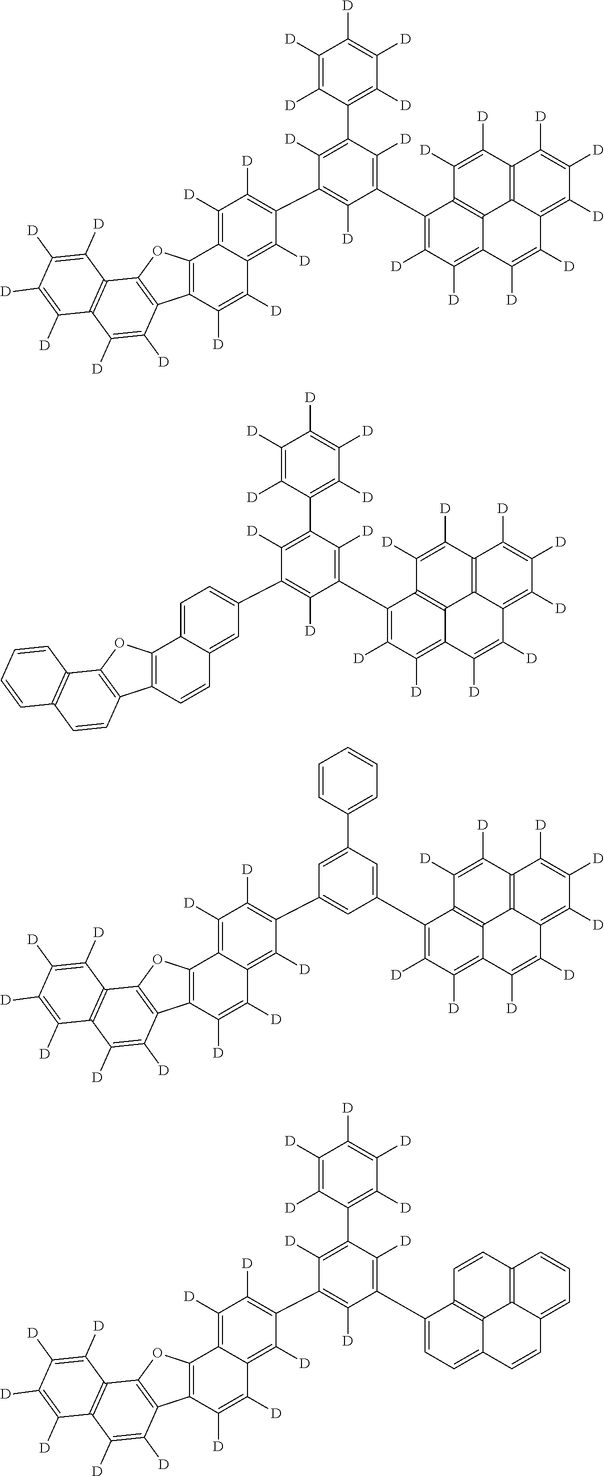

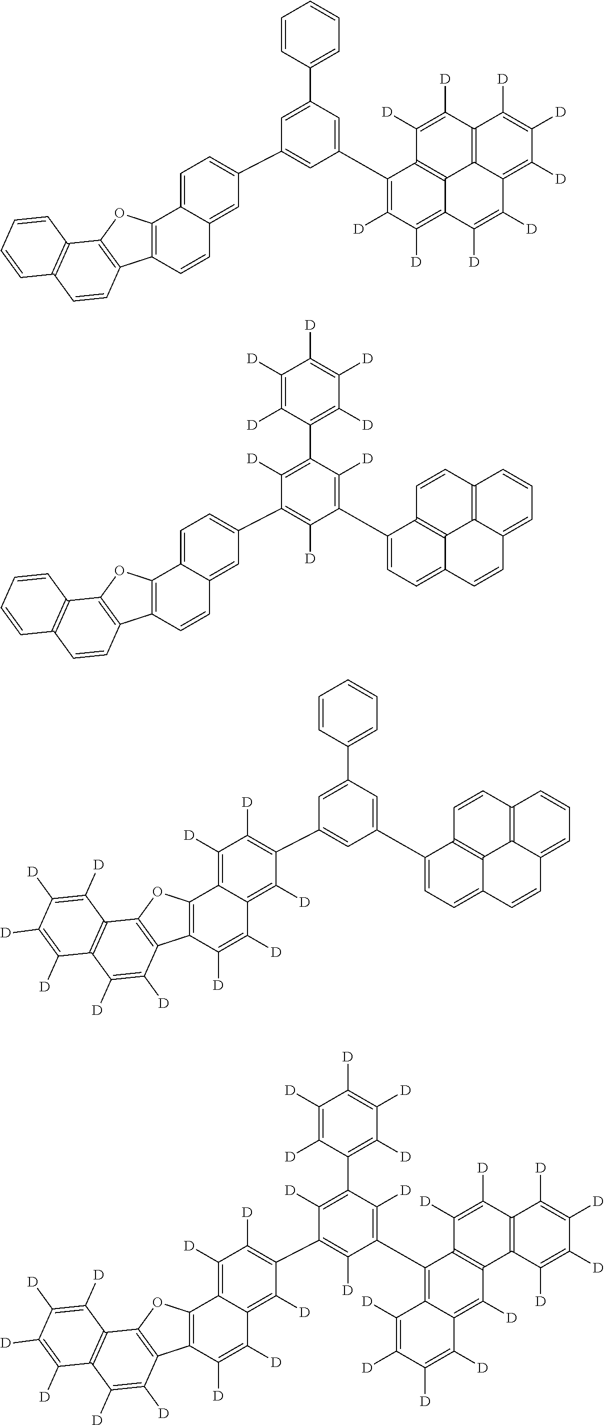

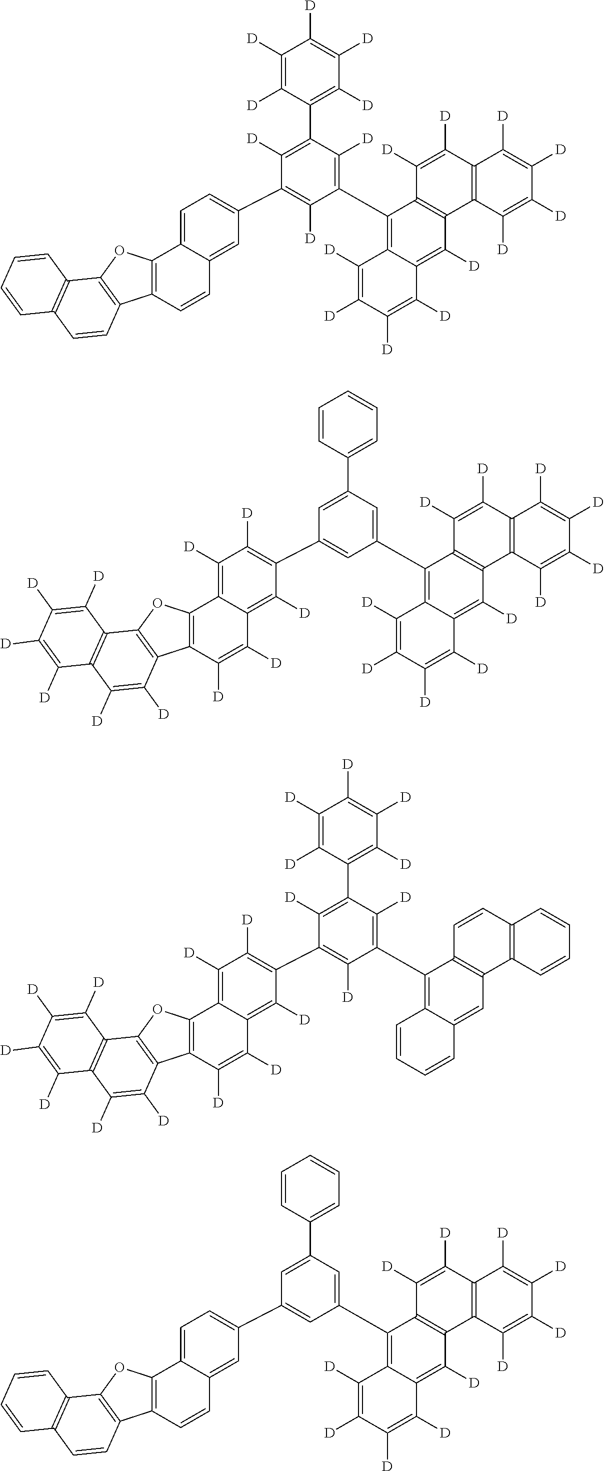

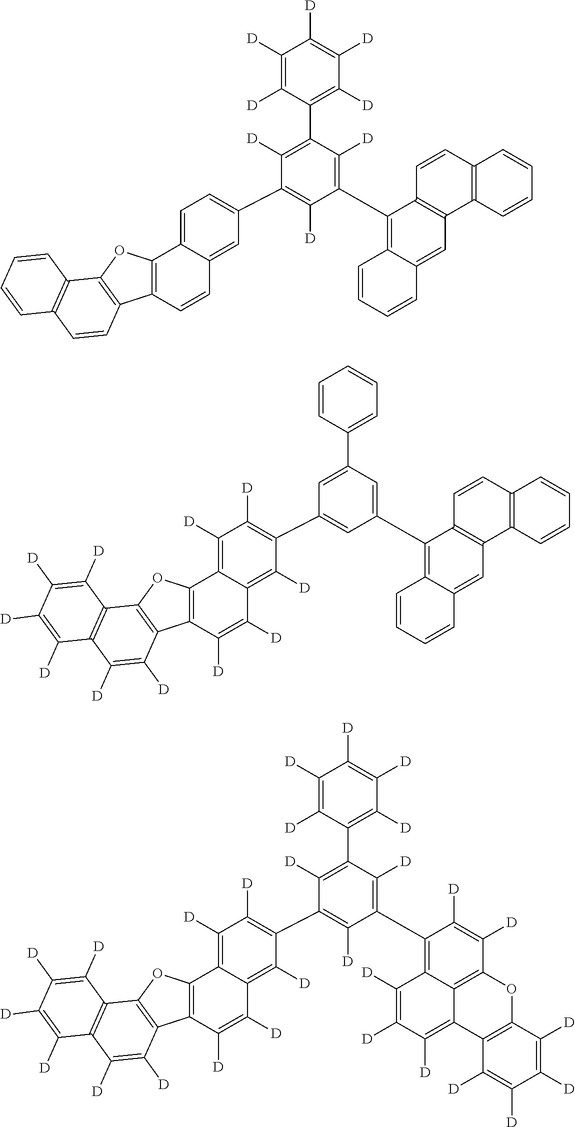

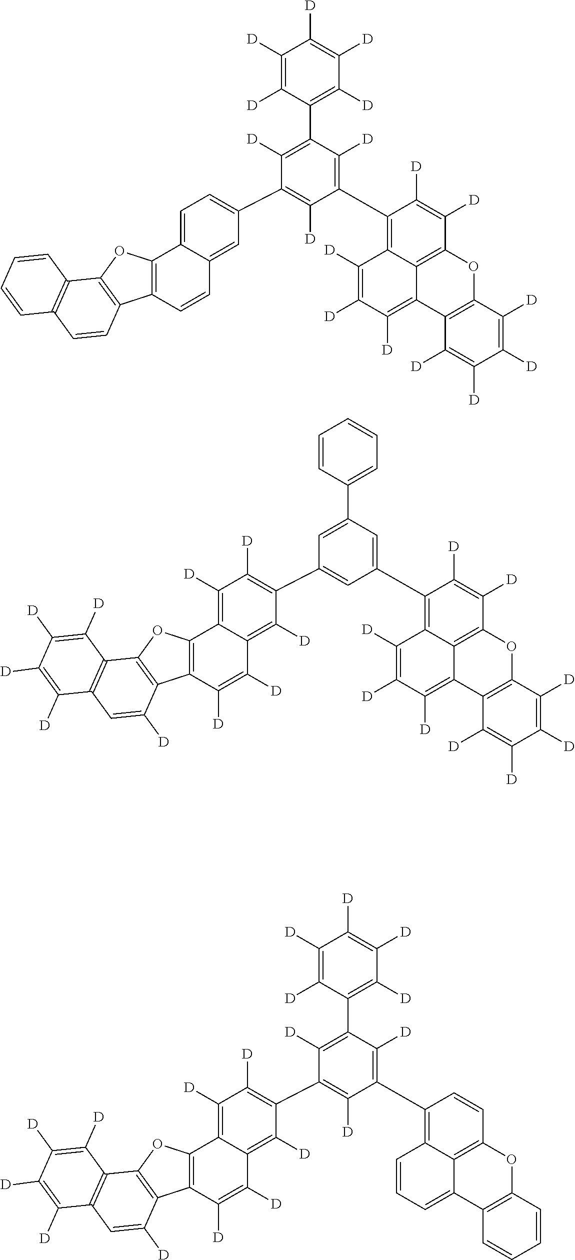

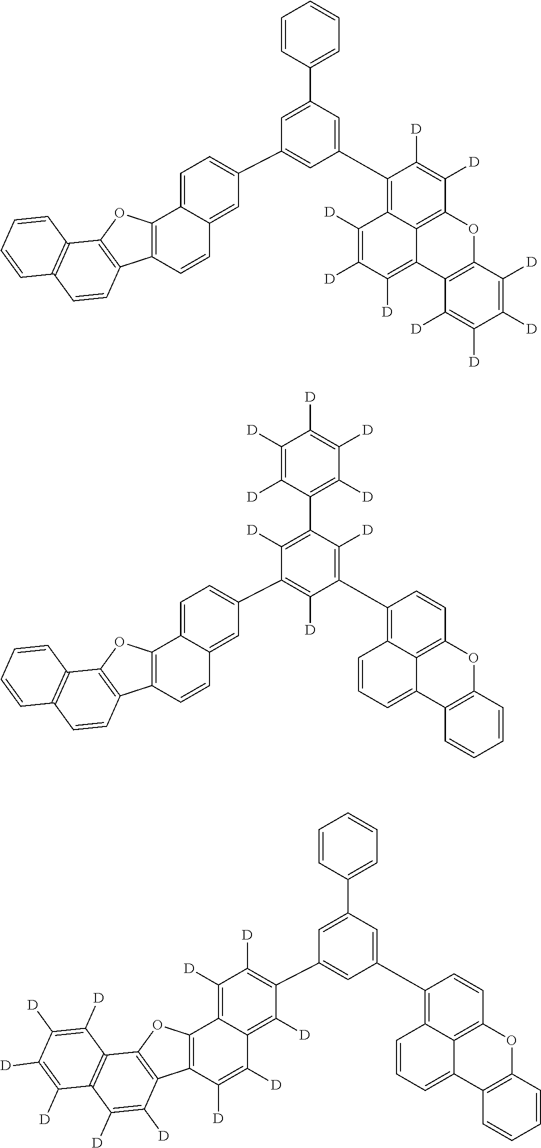 [SMILES: [2H]c1c([2H])c([2H])c2c(c1[2H])Oc1c([2H])c([2H])c(-c3cc(-c4ccccc4)cc(-c4ccc5c(ccc6c7ccc8ccccc8c7oc56)c4)c3)c3c([2H])c([2H])c([2H])c-2c13 ; [2H]c1c([2H])c([2H])c(-c2c([2H])c(-c3ccc4c(ccc5c6ccc7ccccc7c6oc45)c3)c([2H])c(-c3ccc4c5c(cccc35)-c3ccccc3O4)c2[2H])c([2H])c1[2H] ; [2H]c1c([2H])c([2H])c2c(c1[2H])c([2H])c([2H])c1c2oc2c3c([2H])c([2H])c(-c4cc(-c5ccccc5)cc(-c5ccc6c7c(cccc57)-c5ccccc5O6)c4)c([2H])c3c([2H])c([2H])c21]

### [Compound Represented by Formula (2)]

The compound represented by the formula (2) is as follows:

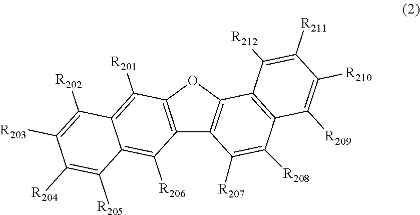

wherein in the formula (2),
at least one of R₂₀₁ to R₂₁₂ is a single bond bonded to a group represented by the following formula (A1):

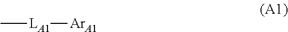

those in the formula (A1) are the same as those defined in the above formula (1), and
R₂₀₁ to R₂₁₂ which are not a single bond bonded to the group represented by the formula (A1) are independently
a hydrogen atom,
a substituted or unsubstituted aryl group having 6 to 20 ring carbon atoms, or
a substituted or unsubstituted monovalent heterocyclic group having 5 to 19 ring atoms.

In the formula (2), when L_{A1} of the formula (A1) is a single bond, Ar_{A1} is directly bonded to the dinaphthofuran skeleton.

The matter described for the formula (A1) in the compound represented by the formula (1) can also be applied to the compound represented by the formula (2).

In one embodiment, the compound represented by the formula (2) is a compound represented by the following formula (21):

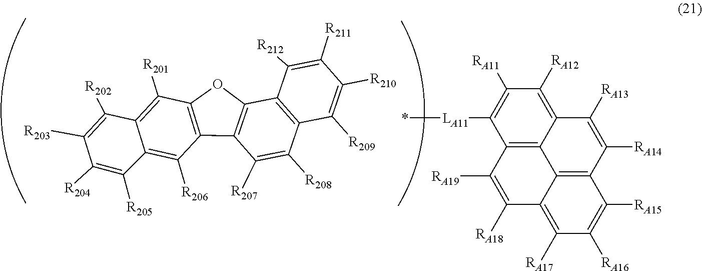

wherein in the formula (21),
at least one of R₂₀₁ to R₂₁₂ is a single bond bonded to L_{A11},
R₂₀₁ to R₂₁₂ which are not a single bond bonded to L_{A11} are independently
a hydrogen atom,
a substituted or unsubstituted aryl group having 6 to 20 ring carbon atoms, or
a substituted or unsubstituted monovalent heterocyclic group having 5 to 19 ring atoms, L_{A11} is
a single bond, or
a substituted or unsubstituted arylene group having 6 to 20 ring carbon atoms, R_{A11} to R_{A19} are independently a hydrogen atom or a substituent R, and
the substituent R is as defined in the above formula (11).

In the formula (21), when L_{A11} is a single bond, the pyrene skeleton is directly bonded to the dinaphthofuran skeleton.

In one embodiment, the compound represented by the formula (21) is a compound represented by the following formula (211):

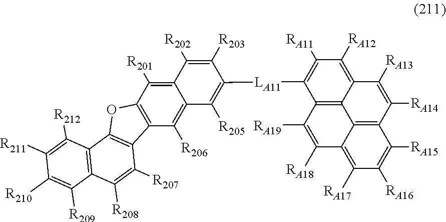

wherein in the formula (211),
L_{A11}, R_{A11} to R_{A19}, R₂₀₁ to R₂₀₃, and R₂₀₅ to R₂₁₂ are as defined in the above formula (21).

In one embodiment, R_{A11} to R_{A19} are a hydrogen atom.

In one embodiment, at least one of R_{A11} to R_{A19} which are a hydrogen atom is a deuterium atom.

In one embodiment, the compound represented by the formula (2) is a compound represented by the following formula (22):

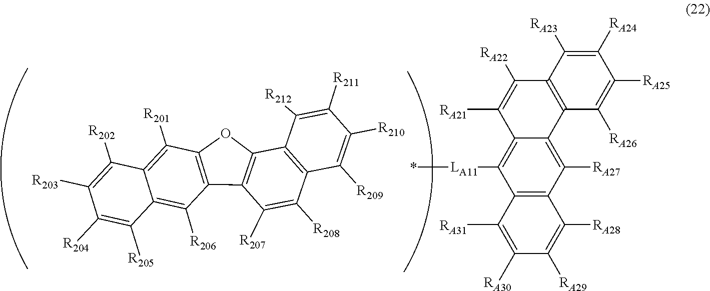

wherein in the formula (22),
at least one of R₂₀₁ to R₂₁₂ is a single bond bonded to L_{A11},
R₂₀₁ to R₂₁₂ which are not a single bond bonded to L_{A11} are independently
a hydrogen atom,
a substituted or unsubstituted aryl group having 6 to 20 ring carbon atoms, or
a substituted or unsubstituted monovalent heterocyclic group having 5 to 19 ring atoms, L_{A11} is
a single bond, or
a substituted or unsubstituted arylene group having 6 to 20 ring carbon atoms, R_{A21} to R_{A31} are independently a hydrogen atom or a substituent R,
the substituent R is selected from the group consisting of
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,

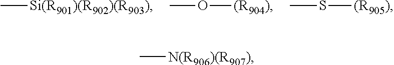

a halogen atom, a cyano group, a nitro group,
a substituted or unsubstituted aryl group having 6 to 50 ring carbon atoms, and
a substituted or unsubstituted monovalent heterocyclic group having 5 to 50 ring atoms,
when two or more substituents R are present, the two or more substituents R may be the same as or different from each other,
R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms, and
when two or more of each of R₉₀₁ to R₉₀₇ are present, the two or more of each of R₉₀₁ to R₉₀₇ may be the same as or different from each other.

In one embodiment, R_{A21} to R_{A31} are a hydrogen atom.

In one embodiment, at least one of R_{A21} to R_{A31} which are a hydrogen atom is a deuterium atom.

In one embodiment, R₂₀₁ to R₂₁₂ which are not a single bond bonded to L_{A11} are a hydrogen atom.

For the deuterium atom, the matter described in the compound represented by the formula (1) can be applied.

In one embodiment, a substituent in the case of “substituted or unsubstituted” in the above formula (2) is selected from the group consisting of
an alkyl group having 1 to 50 carbon atoms,
a haloalkyl group having 1 to 50 carbon atoms,
an alkenyl group having 2 to 50 carbon atoms,
an alkynyl group having 2 to 50 carbon atoms,
a cycloalkyl group having 3 to 50 ring carbon atoms,
an alkoxy group having 1 to 50 carbon atoms,
an alkylthio group having 1 to 50 carbon atoms,
an aryloxy group having 6 to 50 ring carbon atoms,
an arylthio group having 6 to 50 ring carbon atoms,
an aralkyl group having 7 to 50 carbon atoms,

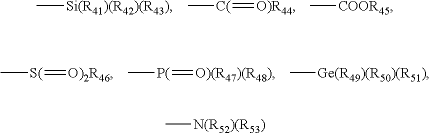

(wherein R₄₁ to R₅₃ are independently a hydrogen atom, an alkyl group having 1 to 50 carbon atoms, an aryl group having 6 to 50 ring carbon atoms, or a monovalent heterocyclic group having 5 to 50 ring atoms; when two or more of each of R₄₁ to R₅₃ are present, the two or more of each of R₄₁ to R₅₃ may be the same as or different from each other),
a hydroxy group,
a halogen atom,
a cyano group,
a nitro group,
an aryl group having 6 to 50 ring carbon atoms, and
a monovalent heterocyclic group having 5 to 50 ring atoms.

In one embodiment, a substituent in the case of “substituted or unsubstituted” in the above formula (2) is selected from the group consisting of
an alkyl group having 1 to 50 carbon atoms,
an aryl group having 6 to 50 ring carbon atoms, and
a monovalent heterocyclic group having 5 to 50 ring atoms.

In one embodiment, a substituent in the case of “substituted or unsubstituted” in the above formula (2) is
an unsubstituted aryl group having 6 to 20 ring carbon atoms, or
an unsubstituted monovalent heterocyclic group having 5 to 19 ring atoms.

The compound represented by the formula (2) can be synthesized by following Examples and using a known alternative reaction or raw material suited for an intended product.

Specific examples of the compound represented by the formula (2) will be described below, but these are merely examples, and the compound represented by the formula (2) is not limited to the following specific examples.

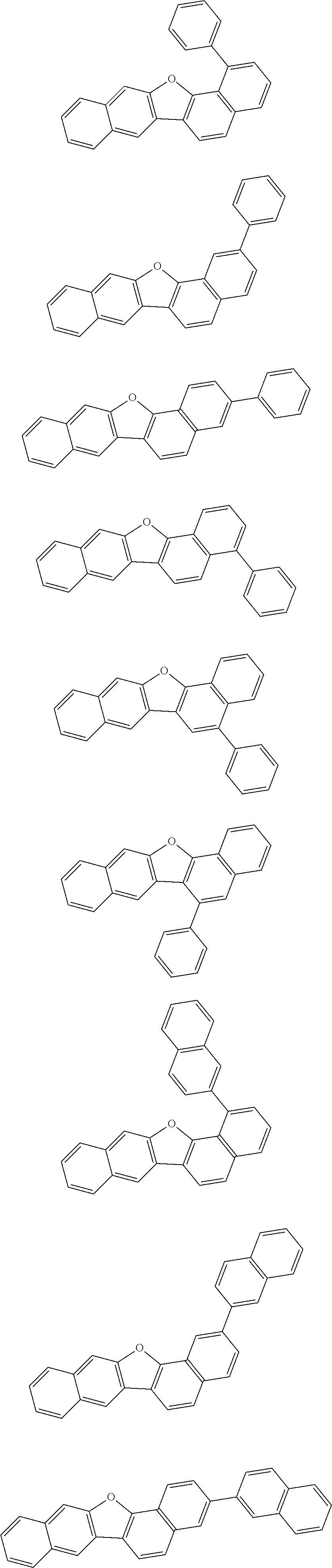

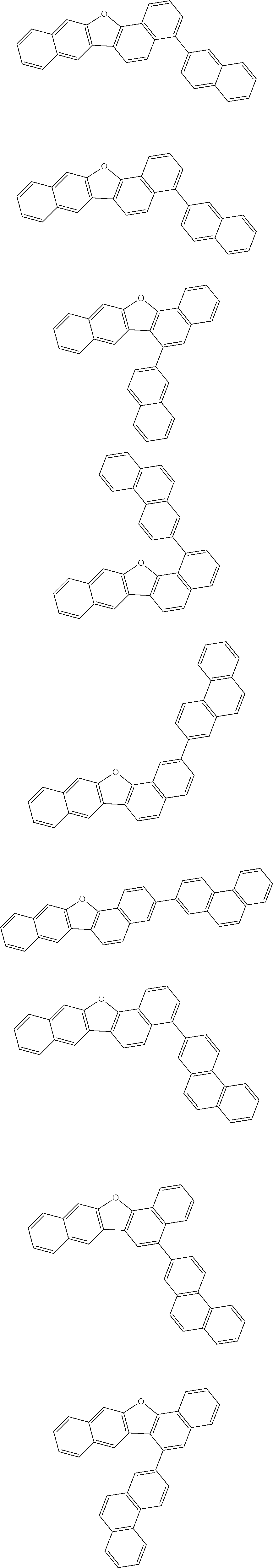

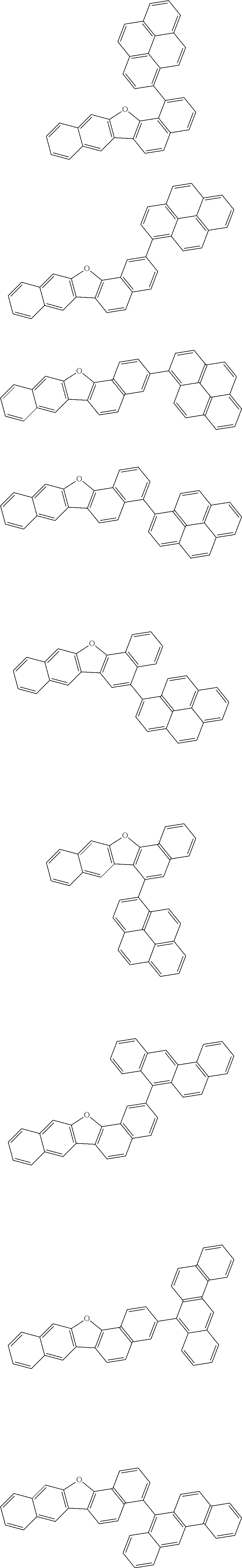

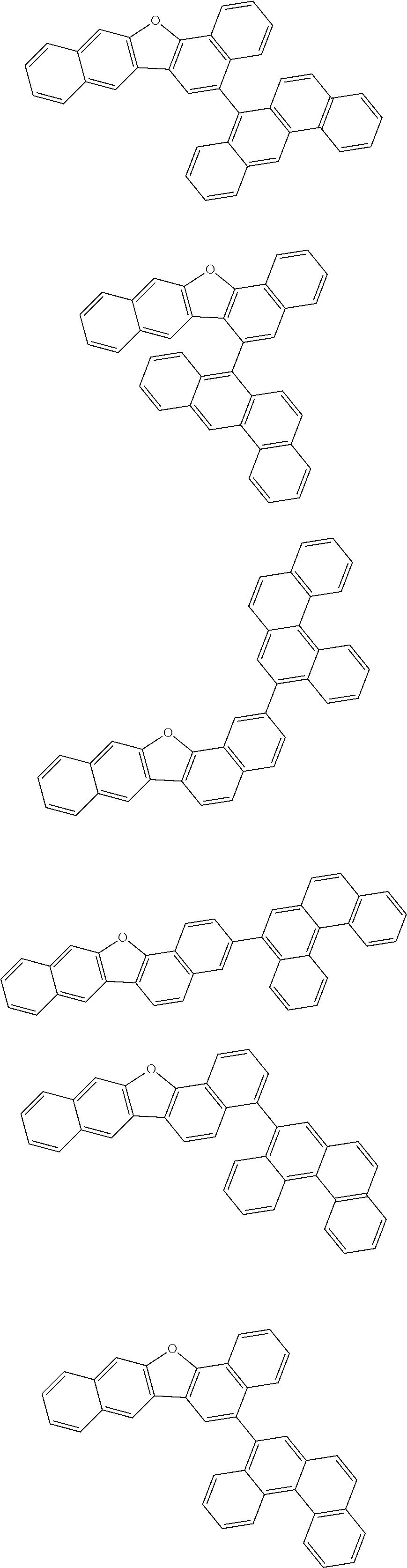 [SMILES: c1ccc2cc3c(cc2c1)oc1c2ccccc2c(-c2c4ccccc4cc4c2ccc2ccccc24)cc31 ; c1ccc2cc3c(cc2c1)oc1c2ccccc2cc(-c2c4ccccc4cc4c2ccc2ccccc24)c31 ; c1ccc2cc3c(cc2c1)oc1c2cc(-c4cc5ccc6ccccc6c5c5ccccc45)ccc2ccc31 ; c1ccc2cc3c(cc2c1)oc1c2ccc(-c4cc5ccc6ccccc6c5c5ccccc45)cc2ccc31 ; c1ccc2cc3c(cc2c1)oc1c2cccc(-c4cc5ccc6ccccc6c5c5ccccc45)c2ccc31 ; c1ccc2cc3c(cc2c1)oc1c2ccccc2c(-c2cc4ccc5ccccc5c4c4ccccc24)cc31]

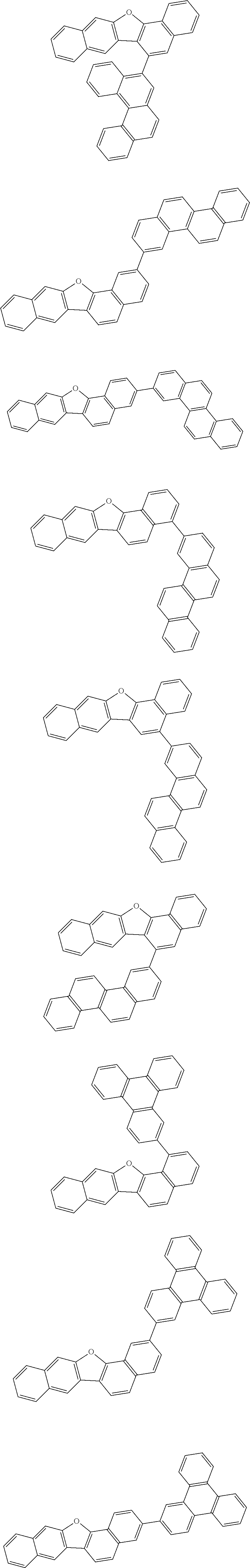

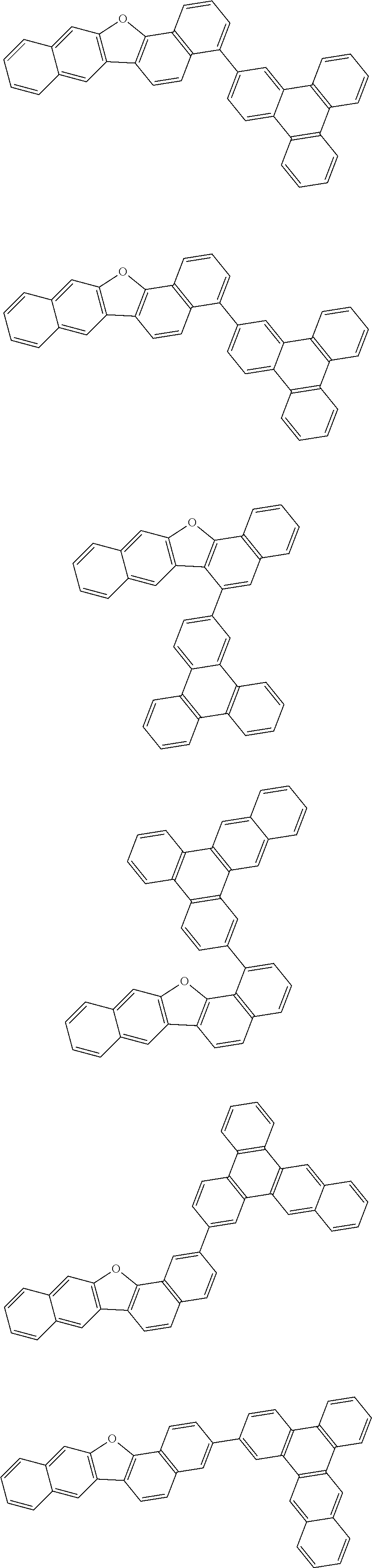 [SMILES: c1ccc2cc3c(cc2c1)oc1c2cccc(-c4ccc5c6ccccc6c6ccccc6c5c4)c2ccc31 ; c1ccc2cc3c(cc2c1)oc1c2cccc(-c4ccc5c6ccccc6c6ccccc6c5c4)c2ccc31 ; c1ccc2cc3c(cc2c1)oc1c2ccccc2cc(-c2ccc4c5ccccc5c5ccccc5c4c2)c31 ; c1ccc2cc3c(cc2c1)oc1c3ccc2cccc(-c3ccc4c5ccccc5c5cc6ccccc6cc5c4c3)c21 ; c1ccc2cc3c(cc2c1)oc1c2cc(-c4ccc5c6ccccc6c6cc7ccccc7cc6c5c4)ccc2ccc31 ; c1ccc2cc3c(cc2c1)oc1c2ccc(-c4ccc5c6ccccc6c6cc7ccccc7cc6c5c4)cc2ccc31]

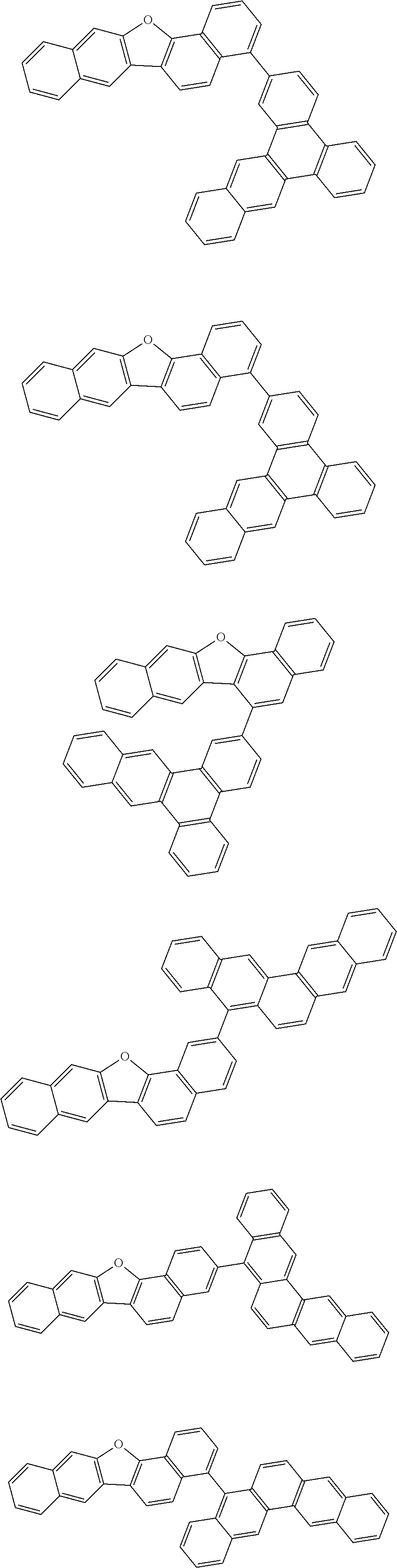 [SMILES: c1ccc2cc3c(cc2c1)oc1c2cccc(-c4ccc5c6ccccc6c6cc7ccccc7cc6c5c4)c2ccc31 ; c1ccc2cc3c(cc2c1)oc1c2cccc(-c4ccc5c6ccccc6c6cc7ccccc7cc6c5c4)c2ccc31 ; c1ccc2cc3c(cc2c1)oc1c2ccccc2cc(-c2ccc4c5ccccc5c5cc6ccccc6cc5c4c2)c31 ; c1ccc2cc3c(ccc4c(-c5ccc6ccc7c8cc9ccccc9cc8oc7c6c5)c5ccccc5cc43)cc2c1 ; c1ccc2cc3c(ccc4c(-c5ccc6c(ccc7c8cc9ccccc9cc8oc67)c5)c5ccccc5cc43)cc2c1 ; c1ccc2cc3c(ccc4c(-c5cccc6c5ccc5c7cc8ccccc8cc7oc65)c5ccccc5cc43)cc2c1]

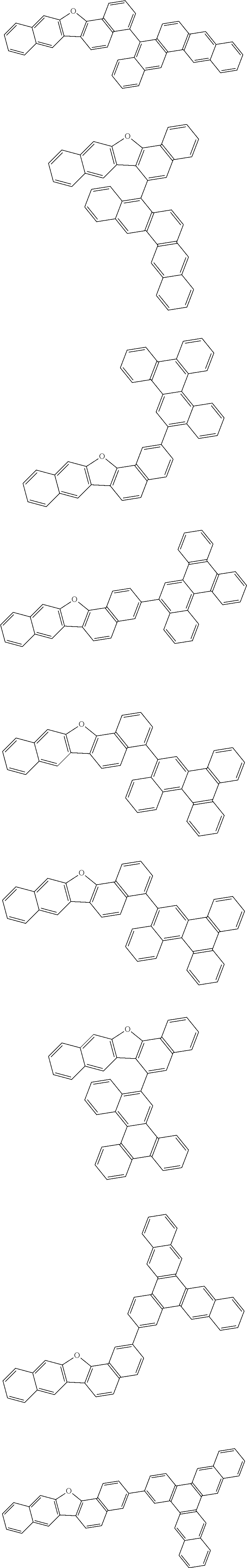

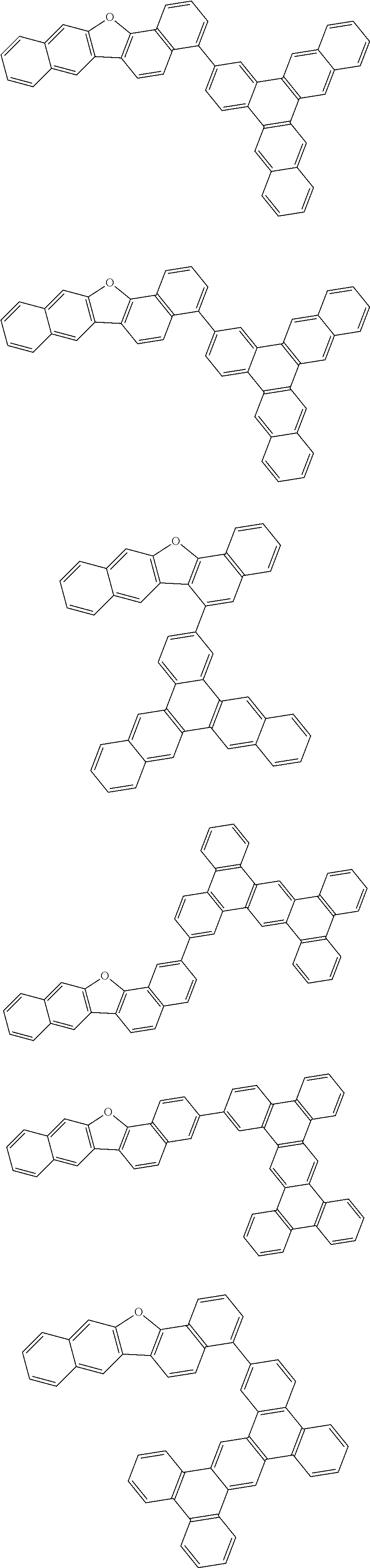 [SMILES: c1ccc2cc3c(cc2c1)oc1c2cccc(-c4ccc5c(c4)c4cc6ccccc6cc4c4cc6ccccc6cc54)c2ccc31 ; c1ccc2cc3c(cc2c1)oc1c2cccc(-c4ccc5c(c4)c4cc6ccccc6cc4c4cc6ccccc6cc54)c2ccc31 ; c1ccc2cc3c(cc2c1)oc1c2ccccc2cc(-c2ccc4c(c2)c2cc5ccccc5cc2c2cc5ccccc5cc42)c31 ; c1ccc2cc3c(cc2c1)oc1c2cc(-c4ccc5c6ccccc6c6cc7c8ccccc8c8ccccc8c7cc6c5c4)ccc2ccc31 ; c1ccc2cc3c(cc2c1)oc1c2ccc(-c4ccc5c6ccccc6c6cc7c8ccccc8c8ccccc8c7cc6c5c4)cc2ccc31 ; c1ccc2cc3c(cc2c1)oc1c2cccc(-c4ccc5c6ccccc6c6cc7c8ccccc8c8ccccc8c7cc6c5c4)c2ccc31]

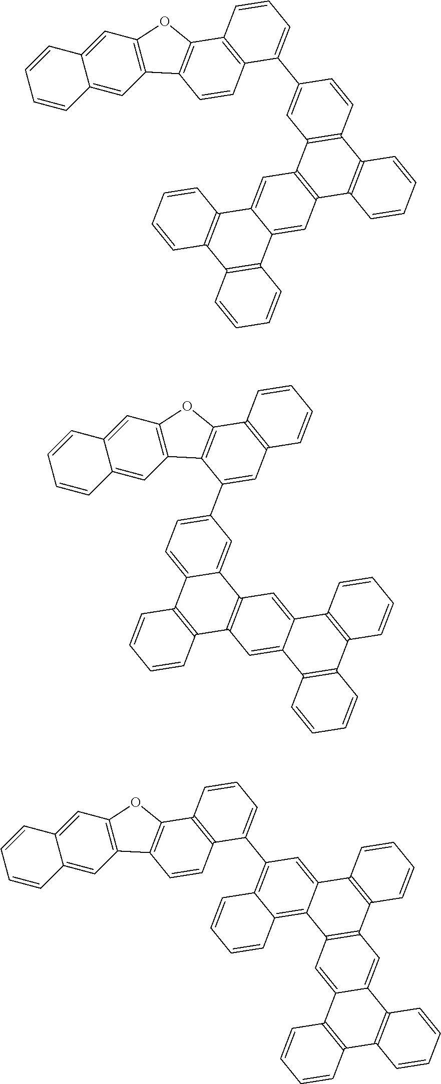 [SMILES: c1ccc2cc3c(cc2c1)oc1c2cccc(-c4ccc5c6ccccc6c6cc7c8ccccc8c8ccccc8c7cc6c5c4)c2ccc31 ; c1ccc2cc3c(cc2c1)oc1c2ccccc2cc(-c2ccc4c5ccccc5c5cc6c7ccccc7c7ccccc7c6cc5c4c2)c31 ; c1ccc2cc3c(cc2c1)oc1c2cccc(-c4cc5c6ccccc6c6cc7c8ccccc8c8ccccc8c7cc6c5c5ccccc45)c2ccc31]

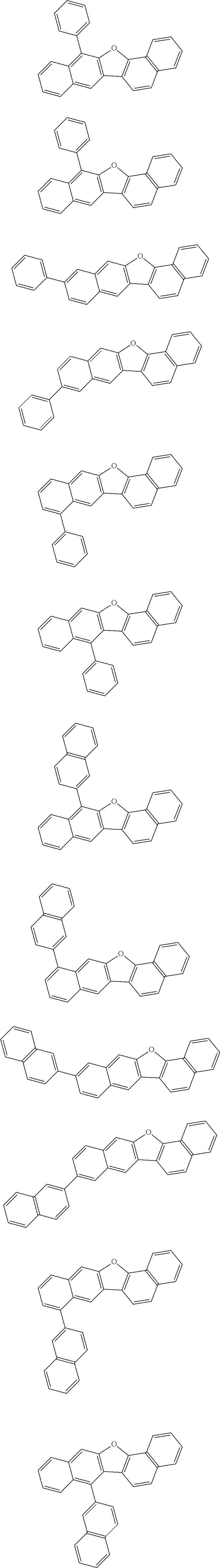

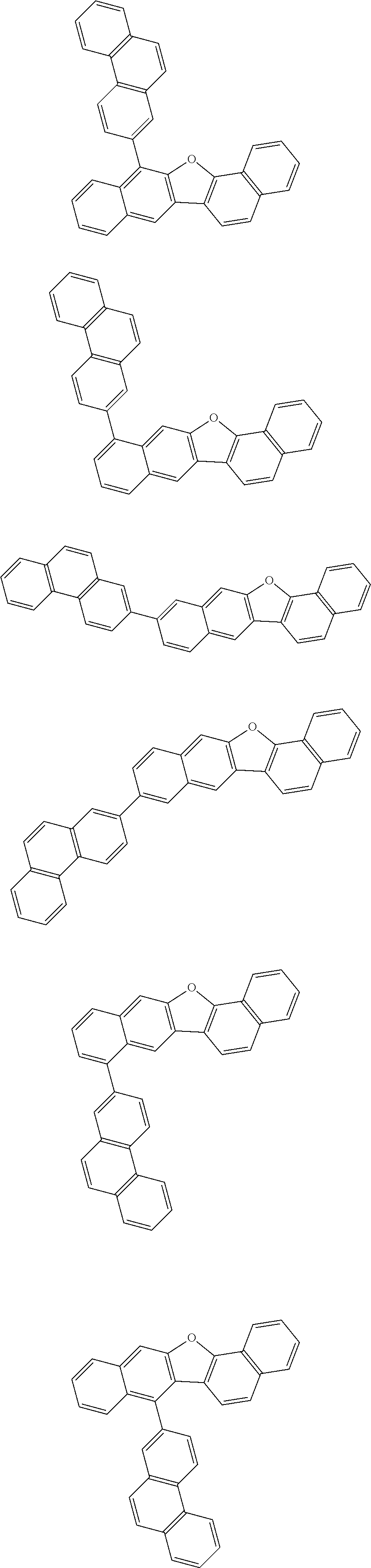 [SMILES: c1ccc2c(-c3ccc4c(ccc5ccccc54)c3)c3oc4c5ccccc5ccc4c3cc2c1 ; c1cc(-c2ccc3c(ccc4ccccc43)c2)c2cc3oc4c5ccccc5ccc4c3cc2c1 ; c1ccc2c(c1)ccc1cc(-c3ccc4cc5c(cc4c3)oc3c4ccccc4ccc53)ccc12 ; c1ccc2c(c1)ccc1cc(-c3ccc4cc5oc6c7ccccc7ccc6c5cc4c3)ccc12 ; c1cc(-c2ccc3c(ccc4ccccc43)c2)c2cc3c(cc2c1)oc1c2ccccc2ccc31 ; c1ccc2c(-c3ccc4c(ccc5ccccc54)c3)c3c(cc2c1)oc1c2ccccc2ccc13]

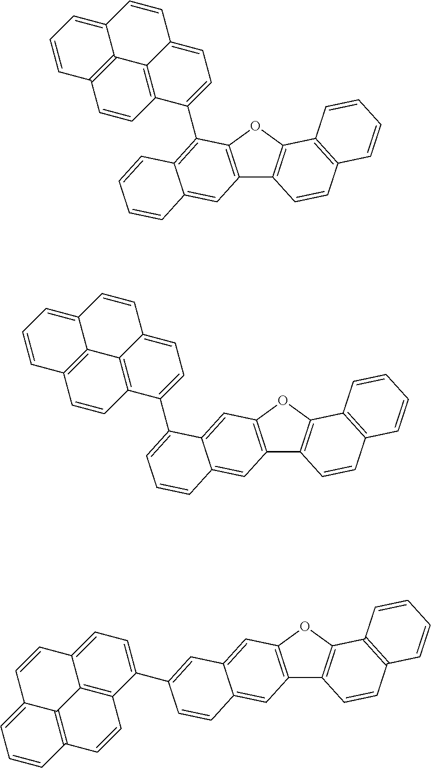 [SMILES: c1ccc2c(-c3ccc4ccc5cccc6ccc3c4c56)c3oc4c5ccccc5ccc4c3cc2c1 ; c1cc(-c2ccc3ccc4cccc5ccc2c3c45)c2cc3oc4c5ccccc5ccc4c3cc2c1 ; c1ccc2c(c1)ccc1c3cc4ccc(-c5ccc6ccc7cccc8ccc5c6c78)cc4cc3oc21]

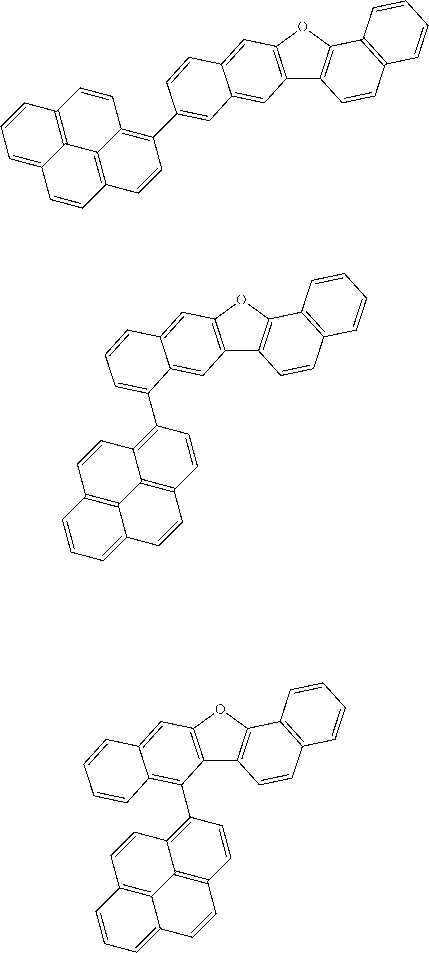 [SMILES: c1ccc2c(c1)ccc1c3cc4cc(-c5ccc6ccc7cccc8ccc5c6c78)ccc4cc3oc21 ; c1cc(-c2ccc3ccc4cccc5ccc2c3c45)c2cc3c(cc2c1)oc1c2ccccc2ccc31 ; c1ccc2c(-c3ccc4ccc5cccc6ccc3c4c56)c3c(cc2c1)oc1c2ccccc2ccc13]

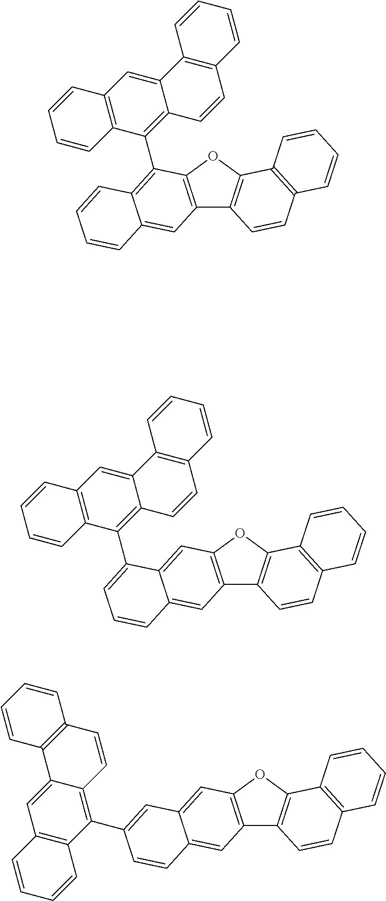 [SMILES: c1ccc2c(-c3c4ccccc4cc4c3oc3c5ccccc5ccc43)c3ccc4ccccc4c3cc2c1 ; c1cc(-c2c3ccccc3cc3c2ccc2ccccc23)c2cc3oc4c5ccccc5ccc4c3cc2c1 ; c1ccc2c(-c3ccc4cc5c(cc4c3)oc3c4ccccc4ccc53)c3ccc4ccccc4c3cc2c1]

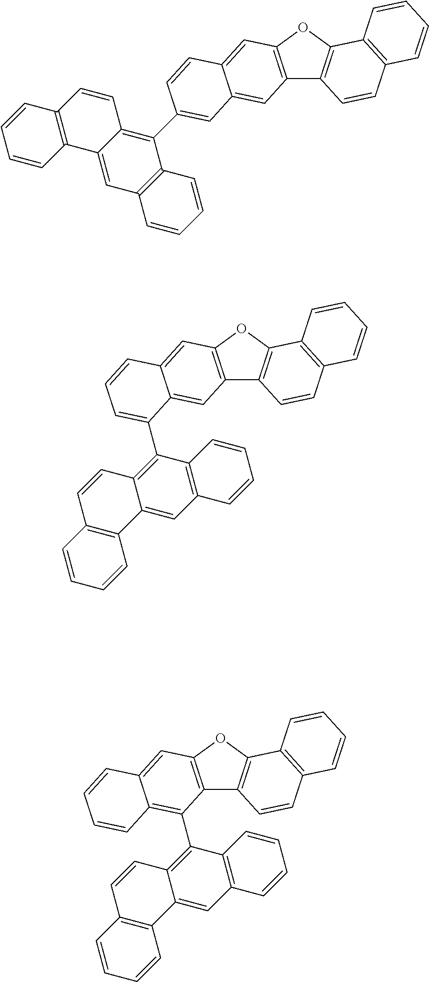 [SMILES: c1ccc2c(-c3ccc4cc5oc6c7ccccc7ccc6c5cc4c3)c3ccc4ccccc4c3cc2c1 ; c1cc(-c2c3ccccc3cc3c2ccc2ccccc23)c2cc3c(cc2c1)oc1c2ccccc2ccc31 ; c1ccc2c(-c3c4ccccc4cc4oc5c6ccccc6ccc5c34)c3ccc4ccccc4c3cc2c1]

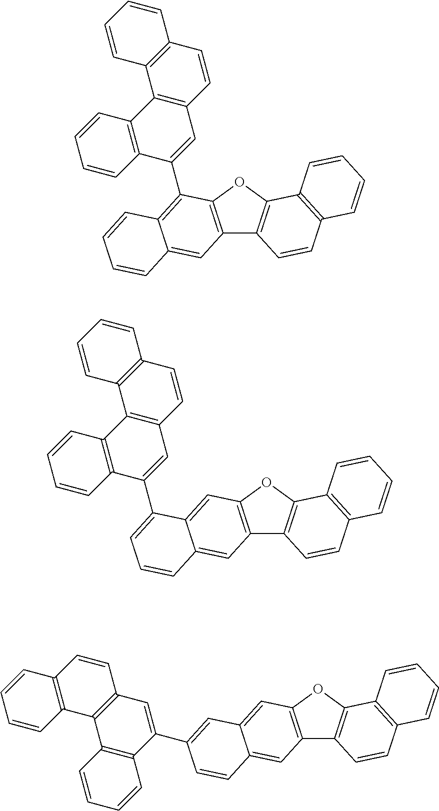 [SMILES: c1ccc2c(-c3cc4ccc5ccccc5c4c4ccccc34)c3oc4c5ccccc5ccc4c3cc2c1 ; c1cc(-c2cc3ccc4ccccc4c3c3ccccc23)c2cc3oc4c5ccccc5ccc4c3cc2c1 ; c1ccc2c(c1)ccc1c3cc4ccc(-c5cc6ccc7ccccc7c6c6ccccc56)cc4cc3oc21]

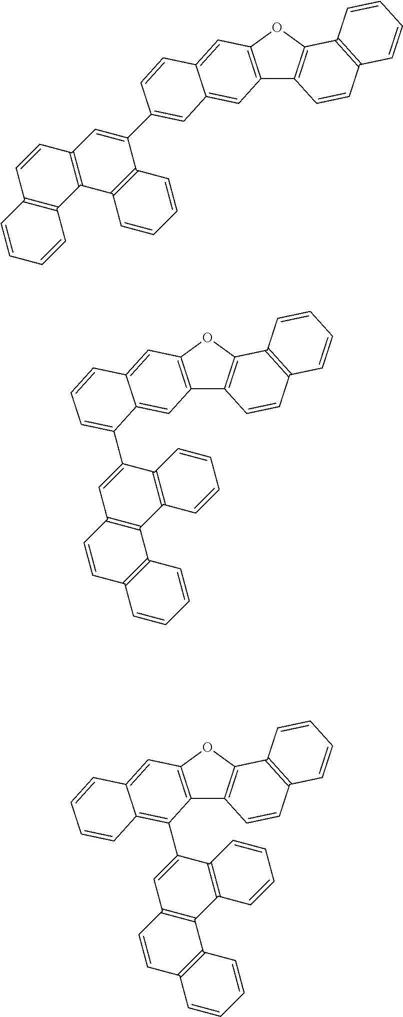 [SMILES: c1ccc2c(c1)ccc1c3cc4cc(-c5cc6ccc7ccccc7c6c6ccccc56)ccc4cc3oc21 ; c1cc(-c2cc3ccc4ccccc4c3c3ccccc23)c2cc3c(cc2c1)oc1c2ccccc2ccc31 ; c1ccc2c(-c3cc4ccc5ccccc5c4c4ccccc34)c3c(cc2c1)oc1c2ccccc2ccc13]

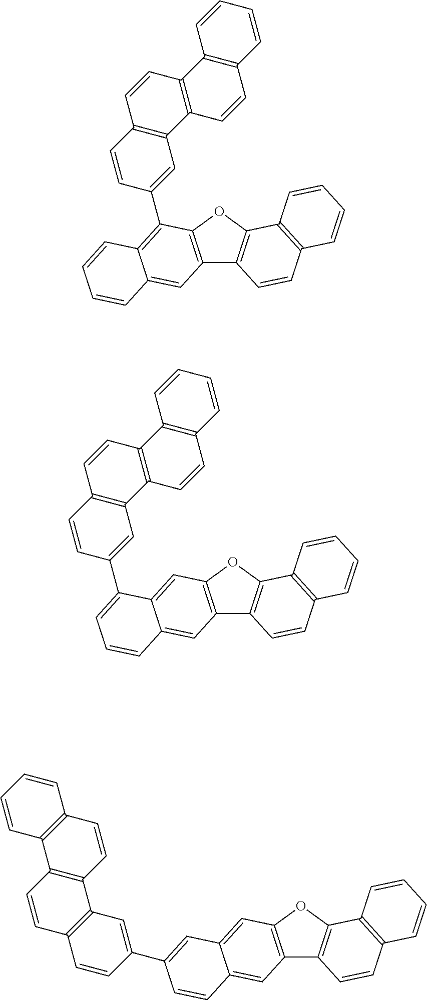 [SMILES: c1ccc2c(-c3ccc4ccc5c6ccccc6ccc5c4c3)c3oc4c5ccccc5ccc4c3cc2c1 ; c1cc(-c2ccc3ccc4c5ccccc5ccc4c3c2)c2cc3oc4c5ccccc5ccc4c3cc2c1 ; c1ccc2c(c1)ccc1c3cc(-c4ccc5cc6c(cc5c4)oc4c5ccccc5ccc64)ccc3ccc21]

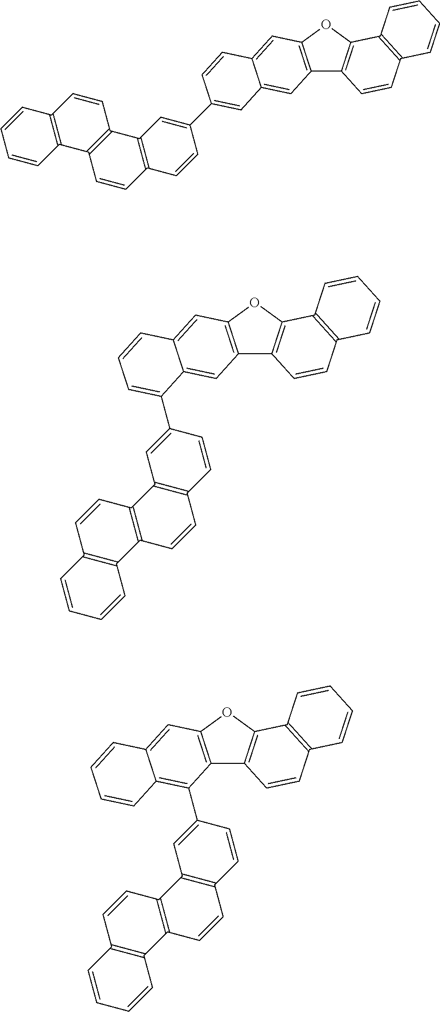 [SMILES: c1ccc2c(c1)ccc1c3cc(-c4ccc5cc6oc7c8ccccc8ccc7c6cc5c4)ccc3ccc21 ; c1cc(-c2ccc3ccc4c5ccccc5ccc4c3c2)c2cc3c(cc2c1)oc1c2ccccc2ccc31 ; c1ccc2c(-c3ccc4ccc5c6ccccc6ccc5c4c3)c3c(cc2c1)oc1c2ccccc2ccc13]

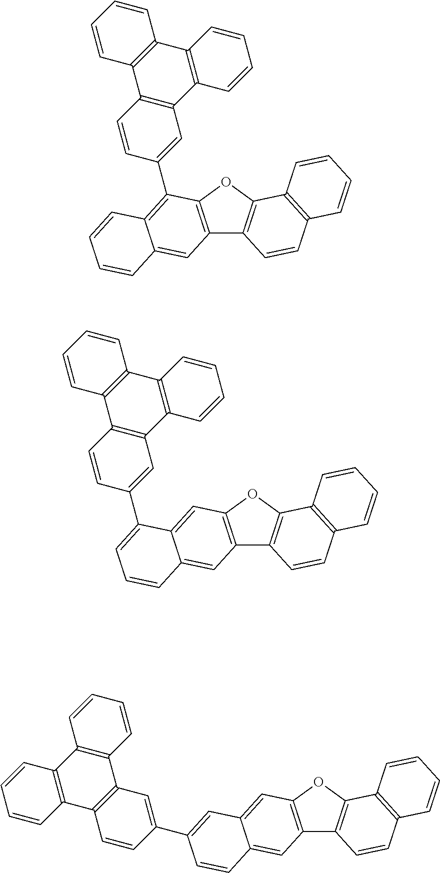 [SMILES: c1ccc2c(-c3ccc4c5ccccc5c5ccccc5c4c3)c3oc4c5ccccc5ccc4c3cc2c1 ; c1cc(-c2ccc3c4ccccc4c4ccccc4c3c2)c2cc3oc4c5ccccc5ccc4c3cc2c1 ; c1ccc2c(c1)ccc1c3cc4ccc(-c5ccc6c7ccccc7c7ccccc7c6c5)cc4cc3oc21]

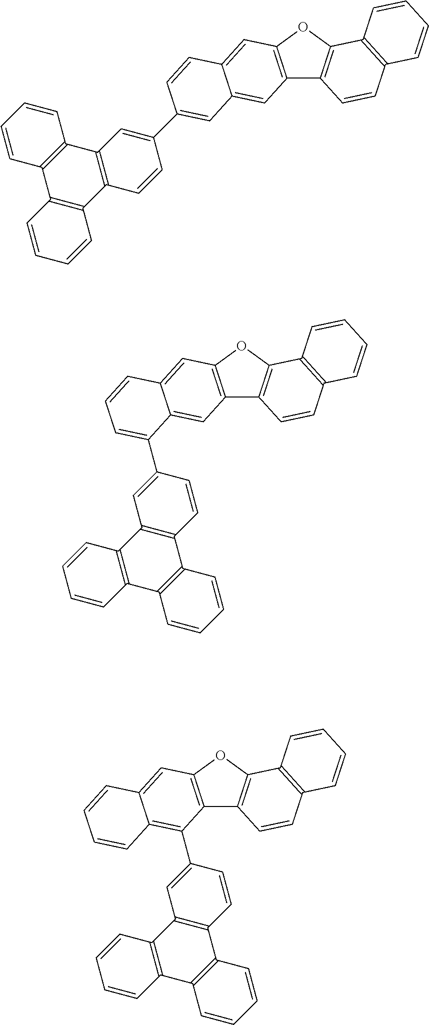 [SMILES: c1ccc2c(c1)ccc1c3cc4cc(-c5ccc6c7ccccc7c7ccccc7c6c5)ccc4cc3oc21 ; c1cc(-c2ccc3c4ccccc4c4ccccc4c3c2)c2cc3c(cc2c1)oc1c2ccccc2ccc31 ; c1ccc2c(-c3ccc4c5ccccc5c5ccccc5c4c3)c3c(cc2c1)oc1c2ccccc2ccc13]

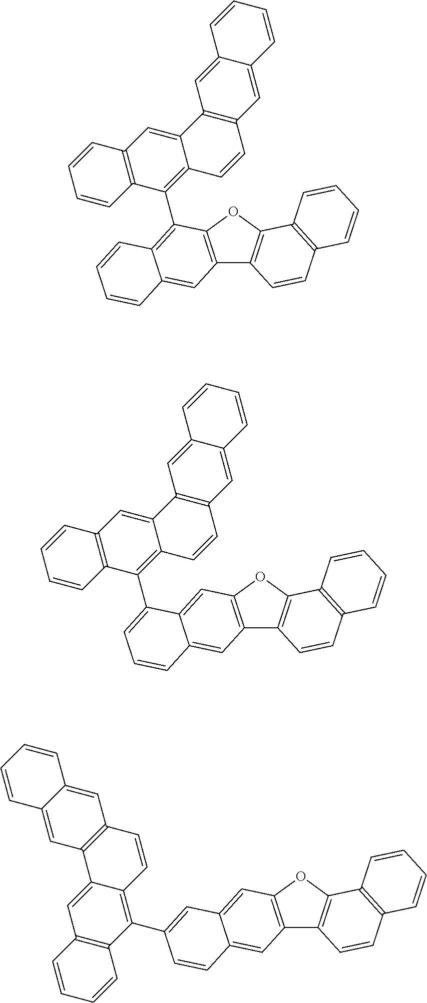 [SMILES: c1ccc2cc3c(ccc4c(-c5c6ccccc6cc6c5oc5c7ccccc7ccc65)c5ccccc5cc43)cc2c1 ; c1ccc2cc3c(ccc4c(-c5cccc6cc7c(cc56)oc5c6ccccc6ccc75)c5ccccc5cc43)cc2c1 ; c1ccc2cc3c(ccc4c(-c5ccc6cc7c(cc6c5)oc5c6ccccc6ccc75)c5ccccc5cc43)cc2c1]

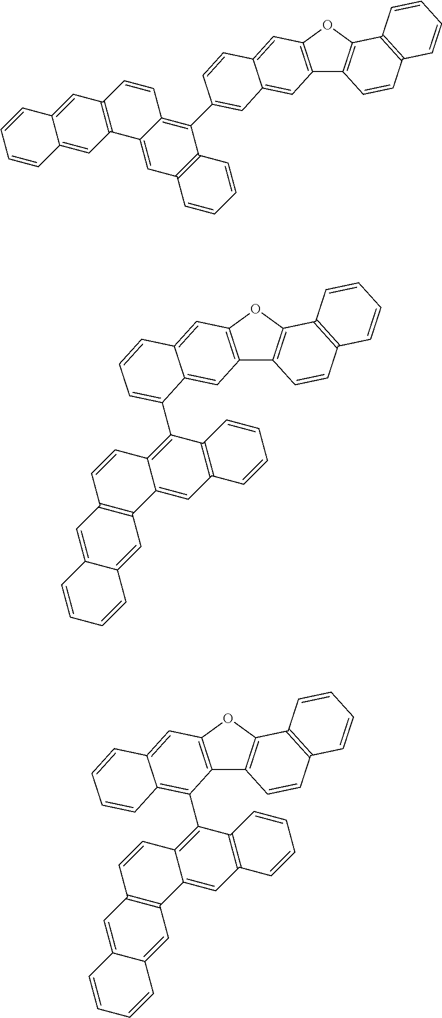 [SMILES: c1ccc2cc3c(ccc4c(-c5ccc6cc7oc8c9ccccc9ccc8c7cc6c5)c5ccccc5cc43)cc2c1 ; c1ccc2cc3c(ccc4c(-c5cccc6cc7oc8c9ccccc9ccc8c7cc56)c5ccccc5cc43)cc2c1 ; c1ccc2cc3c(ccc4c(-c5c6ccccc6cc6oc7c8ccccc8ccc7c56)c5ccccc5cc43)cc2c1]

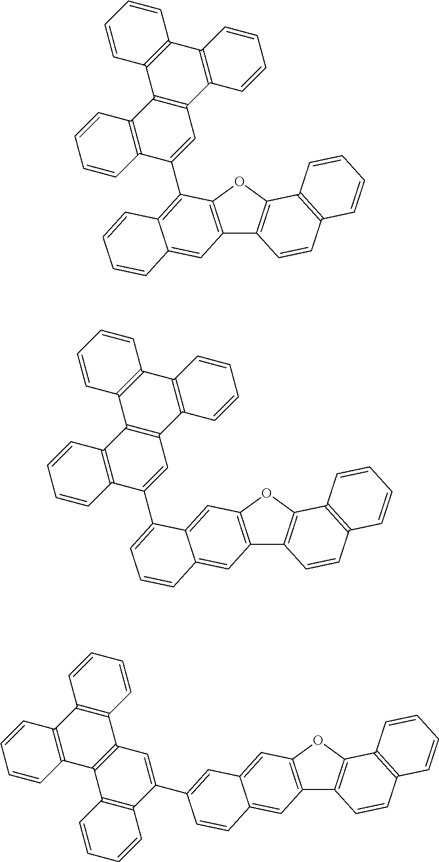 [SMILES: c1ccc2c(-c3cc4c5ccccc5c5ccccc5c4c4ccccc34)c3oc4c5ccccc5ccc4c3cc2c1 ; c1cc(-c2cc3c4ccccc4c4ccccc4c3c3ccccc23)c2cc3oc4c5ccccc5ccc4c3cc2c1 ; c1ccc2c(c1)ccc1c3cc4ccc(-c5cc6c7ccccc7c7ccccc7c6c6ccccc56)cc4cc3oc21]

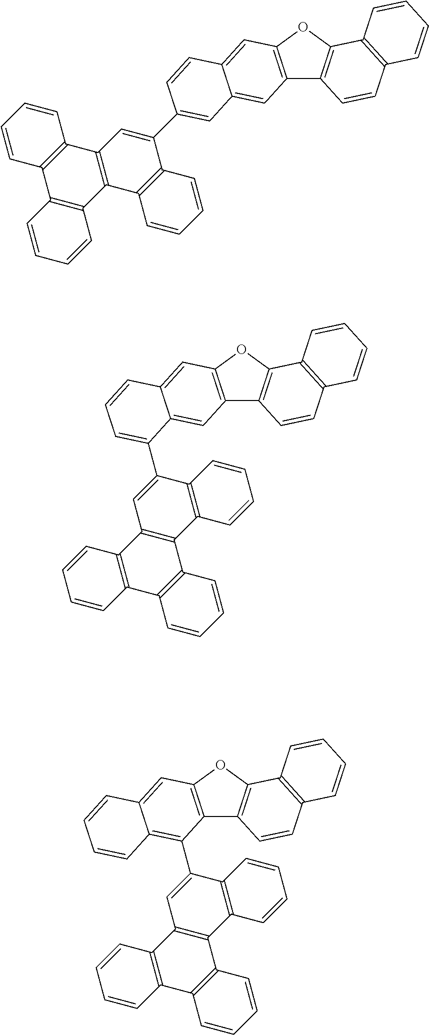 [SMILES: c1ccc2c(c1)ccc1c3cc4cc(-c5cc6c7ccccc7c7ccccc7c6c6ccccc56)ccc4cc3oc21 ; c1cc(-c2cc3c4ccccc4c4ccccc4c3c3ccccc23)c2cc3c(cc2c1)oc1c2ccccc2ccc31 ; c1ccc2c(-c3cc4c5ccccc5c5ccccc5c4c4ccccc34)c3c(cc2c1)oc1c2ccccc2ccc13]

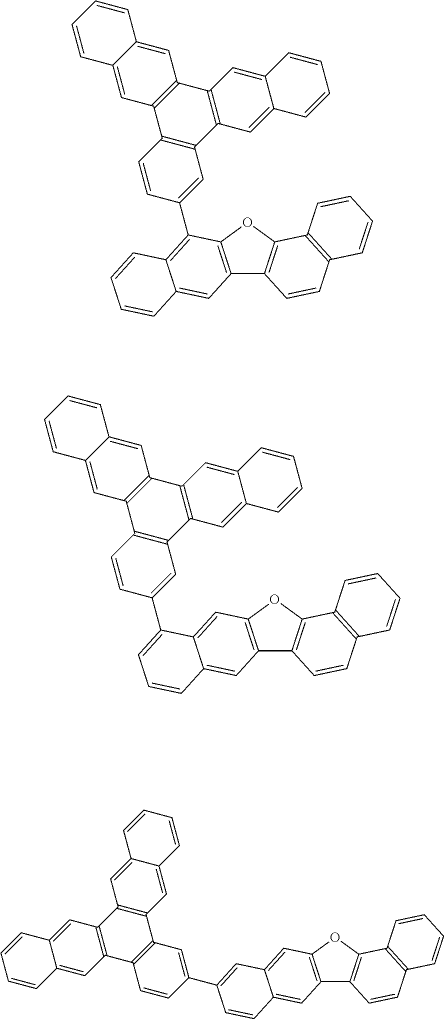 [SMILES: c1ccc2cc3c(cc2c1)c1ccc(-c2c4ccccc4cc4c2oc2c5ccccc5ccc42)cc1c1cc2ccccc2cc13 ; c1ccc2cc3c(cc2c1)c1ccc(-c2cccc4cc5c(cc24)oc2c4ccccc4ccc52)cc1c1cc2ccccc2cc13 ; c1ccc2cc3c(cc2c1)c1ccc(-c2ccc4cc5c(cc4c2)oc2c4ccccc4ccc52)cc1c1cc2ccccc2cc13]

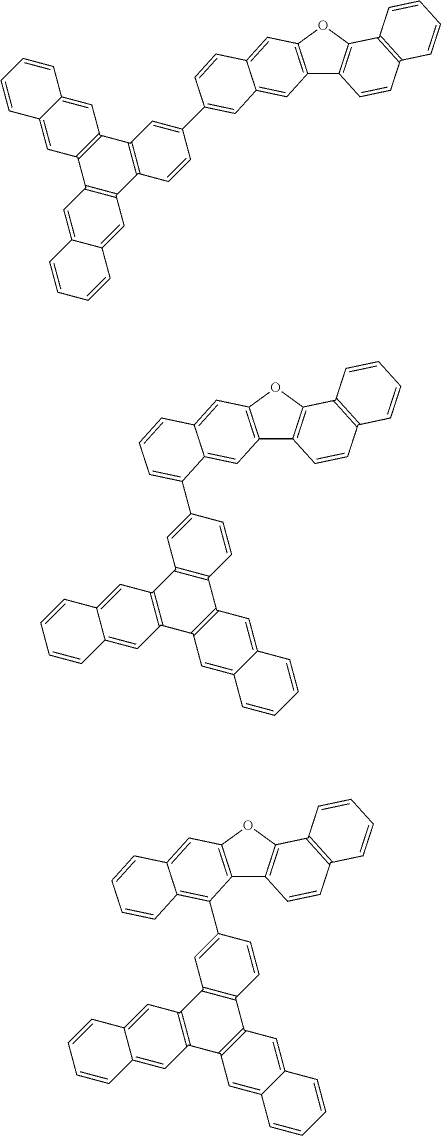 [SMILES: c1ccc2cc3c(cc2c1)c1ccc(-c2ccc4cc5oc6c7ccccc7ccc6c5cc4c2)cc1c1cc2ccccc2cc13 ; c1ccc2cc3c(cc2c1)c1ccc(-c2cccc4cc5oc6c7ccccc7ccc6c5cc24)cc1c1cc2ccccc2cc13 ; c1ccc2cc3c(cc2c1)c1ccc(-c2c4ccccc4cc4oc5c6ccccc6ccc5c24)cc1c1cc2ccccc2cc13]

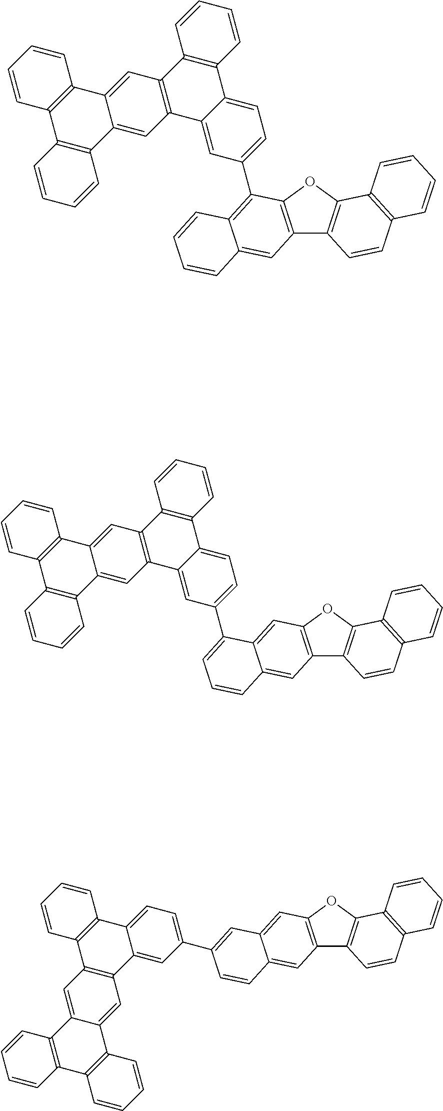 [SMILES: c1ccc2c(-c3ccc4c5ccccc5c5cc6c7ccccc7c7ccccc7c6cc5c4c3)c3oc4c5ccccc5ccc4c3cc2c1 ; c1cc(-c2ccc3c4ccccc4c4cc5c6ccccc6c6ccccc6c5cc4c3c2)c2cc3oc4c5ccccc5ccc4c3cc2c1 ; c1ccc2c(c1)ccc1c3cc4ccc(-c5ccc6c7ccccc7c7cc8c9ccccc9c9ccccc9c8cc7c6c5)cc4cc3oc21]

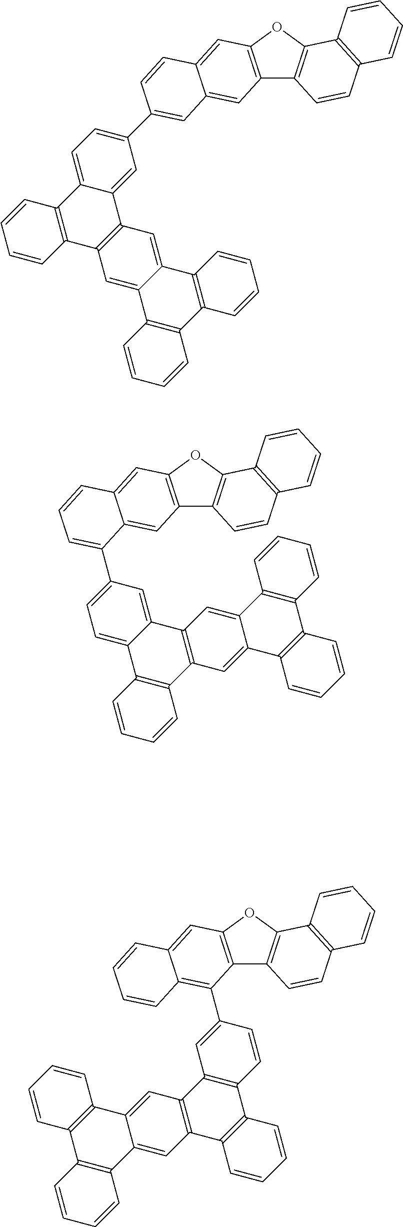 [SMILES: c1ccc2c(c1)ccc1c3cc4cc(-c5ccc6c7ccccc7c7cc8c9ccccc9c9ccccc9c8cc7c6c5)ccc4cc3oc21 ; c1cc(-c2ccc3c4ccccc4c4cc5c6ccccc6c6ccccc6c5cc4c3c2)c2cc3c(cc2c1)oc1c2ccccc2ccc31 ; c1ccc2c(-c3ccc4c5ccccc5c5cc6c7ccccc7c7ccccc7c6cc5c4c3)c3c(cc2c1)oc1c2ccccc2ccc13]

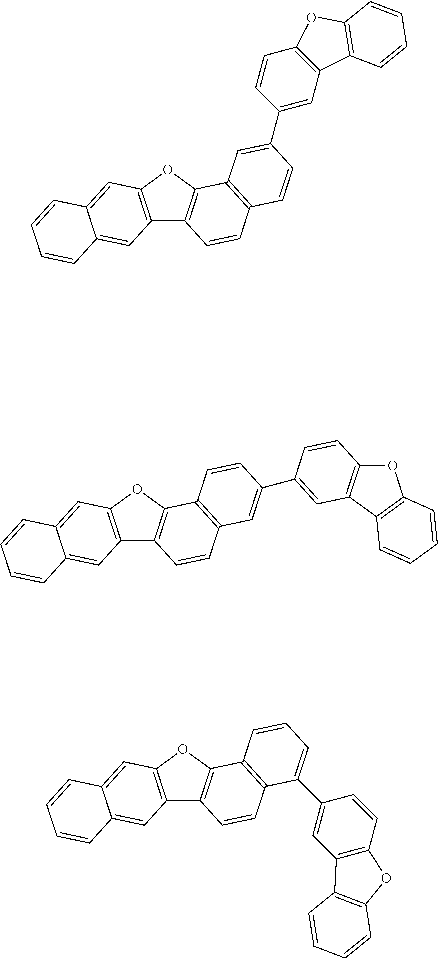 [SMILES: c1ccc2cc3c(cc2c1)oc1c2cc(-c4ccc5oc6ccccc6c5c4)ccc2ccc31 ; c1ccc2cc3c(cc2c1)oc1c2ccc(-c4ccc5oc6ccccc6c5c4)cc2ccc31 ; c1ccc2cc3c(cc2c1)oc1c2cccc(-c4ccc5oc6ccccc6c5c4)c2ccc31]

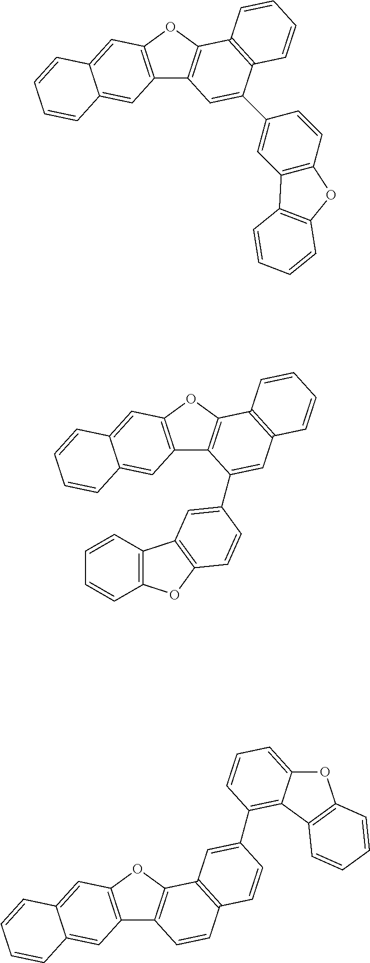 [SMILES: c1ccc2cc3c(cc2c1)oc1c2ccccc2c(-c2ccc4oc5ccccc5c4c2)cc31 ; c1ccc2cc3c(cc2c1)oc1c2ccccc2cc(-c2ccc4oc5ccccc5c4c2)c31 ; c1ccc2cc3c(cc2c1)oc1c2cc(-c4cccc5oc6ccccc6c45)ccc2ccc31]

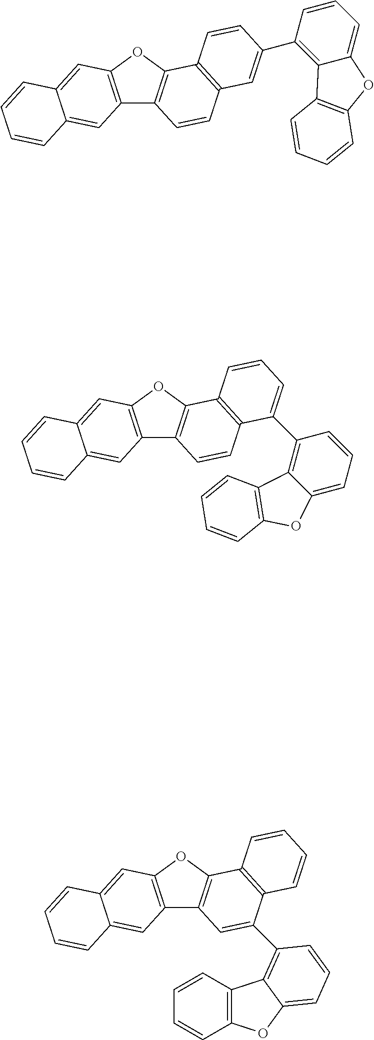 [SMILES: c1ccc2cc3c(cc2c1)oc1c2ccc(-c4cccc5oc6ccccc6c45)cc2ccc31 ; c1ccc2cc3c(cc2c1)oc1c2cccc(-c4cccc5oc6ccccc6c45)c2ccc31 ; c1ccc2cc3c(cc2c1)oc1c2ccccc2c(-c2cccc4oc5ccccc5c24)cc31]

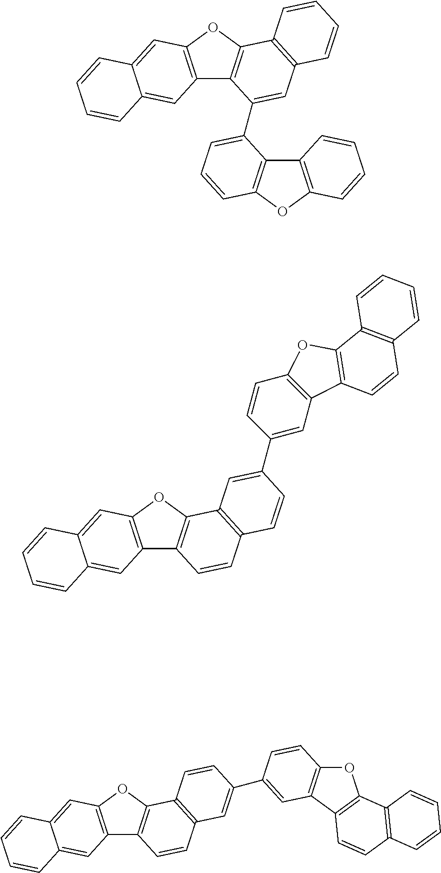 [SMILES: c1ccc2cc3c(cc2c1)oc1c2ccccc2cc(-c2cccc4oc5ccccc5c24)c31 ; c1ccc2cc3c(cc2c1)oc1c2cc(-c4ccc5oc6c7ccccc7ccc6c5c4)ccc2ccc31 ; c1ccc2cc3c(cc2c1)oc1c2ccc(-c4ccc5oc6c7ccccc7ccc6c5c4)cc2ccc31]

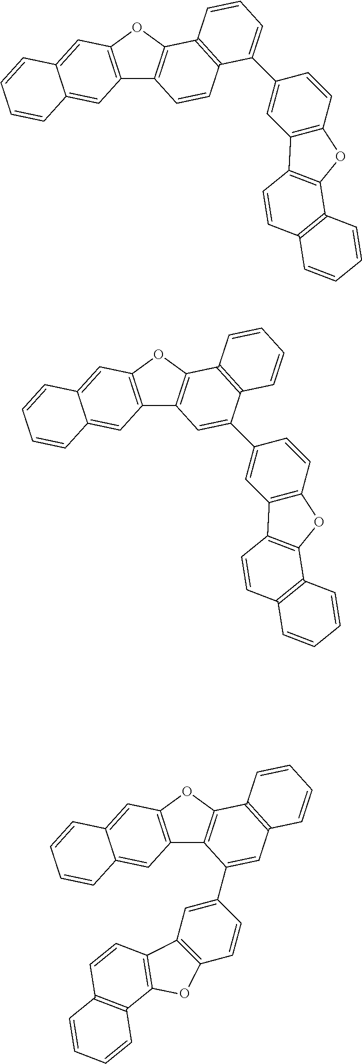 [SMILES: c1ccc2cc3c(cc2c1)oc1c2cccc(-c4ccc5oc6c7ccccc7ccc6c5c4)c2ccc31 ; c1ccc2cc3c(cc2c1)oc1c2ccccc2c(-c2ccc4oc5c6ccccc6ccc5c4c2)cc31 ; c1ccc2cc3c(cc2c1)oc1c2ccccc2cc(-c2ccc4oc5c6ccccc6ccc5c4c2)c31]

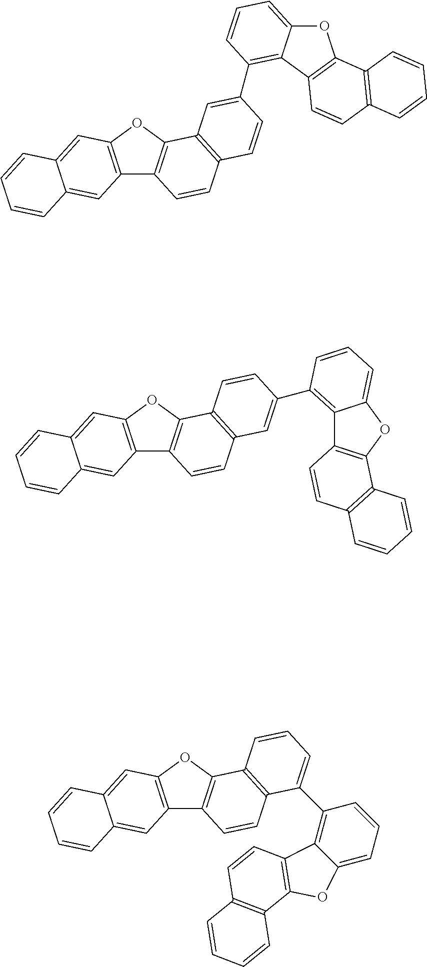 [SMILES: c1ccc2cc3c(cc2c1)oc1c2cc(-c4cccc5oc6c7ccccc7ccc6c45)ccc2ccc31 ; c1ccc2cc3c(cc2c1)oc1c2ccc(-c4cccc5oc6c7ccccc7ccc6c45)cc2ccc31 ; c1ccc2cc3c(cc2c1)oc1c2cccc(-c4cccc5oc6c7ccccc7ccc6c45)c2ccc31]

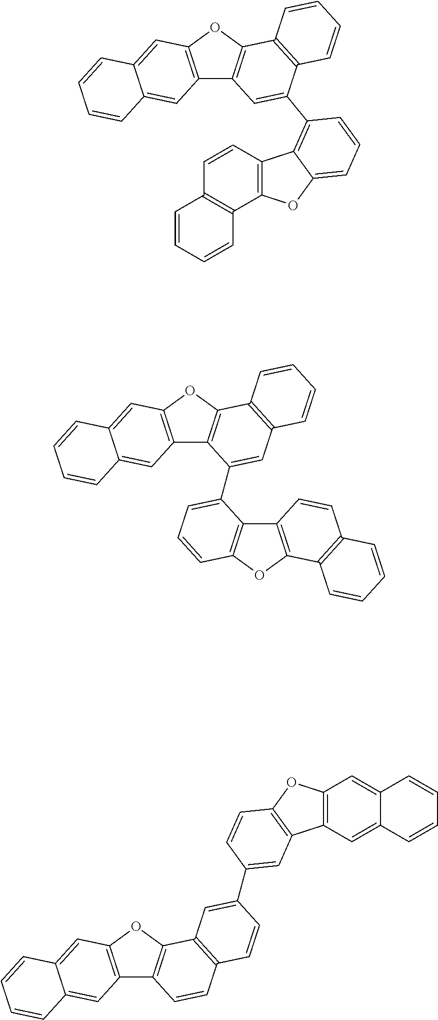 [SMILES: c1ccc2cc3c(cc2c1)oc1c2ccccc2c(-c2cccc4oc5c6ccccc6ccc5c24)cc31 ; c1ccc2cc3c(cc2c1)oc1c2ccccc2cc(-c2cccc4oc5c6ccccc6ccc5c24)c31 ; c1ccc2cc3c(cc2c1)oc1ccc(-c2ccc4ccc5c6cc7ccccc7cc6oc5c4c2)cc13]

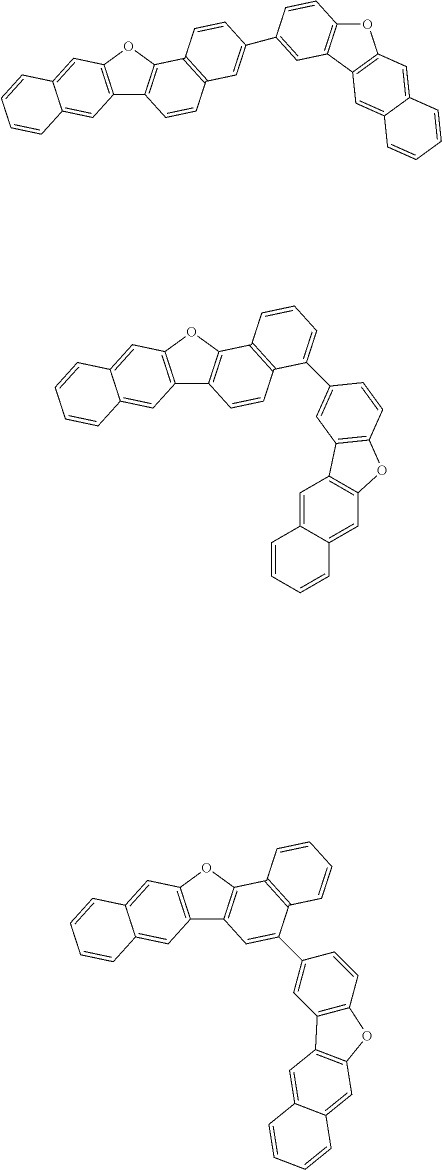 [SMILES: c1ccc2cc3c(cc2c1)oc1ccc(-c2ccc4c(ccc5c6cc7ccccc7cc6oc45)c2)cc13 ; c1ccc2cc3c(cc2c1)oc1ccc(-c2cccc4c2ccc2c5cc6ccccc6cc5oc42)cc13 ; c1ccc2cc3c(cc2c1)oc1ccc(-c2cc4c5cc6ccccc6cc5oc4c4ccccc24)cc13]

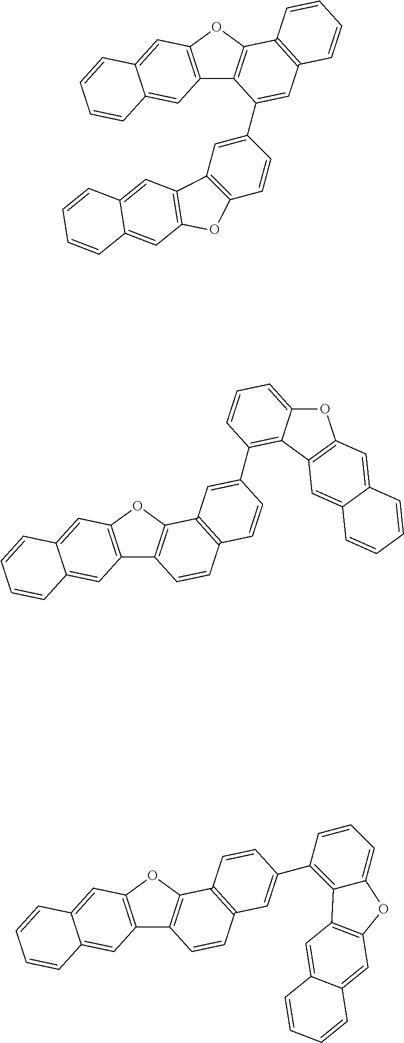 [SMILES: c1ccc2cc3c(cc2c1)oc1ccc(-c2cc4ccccc4c4oc5cc6ccccc6cc5c24)cc13 ; c1ccc2cc3c(cc2c1)oc1c2cc(-c4cccc5oc6cc7ccccc7cc6c45)ccc2ccc31 ; c1ccc2cc3c(cc2c1)oc1c2ccc(-c4cccc5oc6cc7ccccc7cc6c45)cc2ccc31]

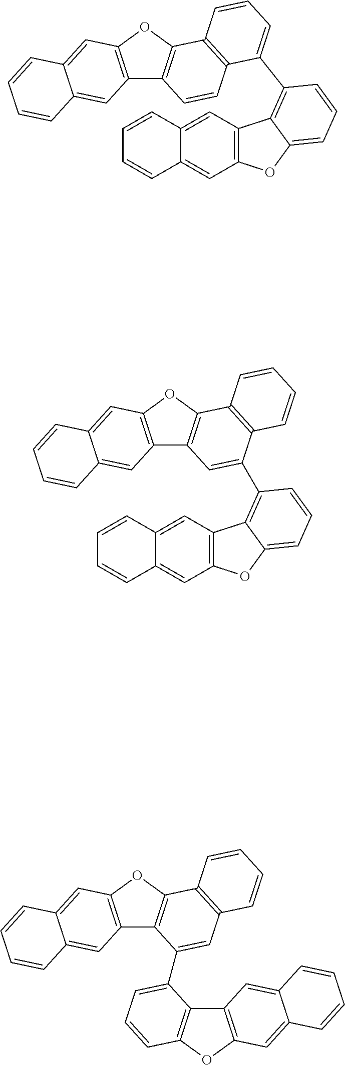 [SMILES: c1ccc2cc3c(cc2c1)oc1c2cccc(-c4cccc5oc6cc7ccccc7cc6c45)c2ccc31 ; c1ccc2cc3c(cc2c1)oc1c2ccccc2c(-c2cccc4oc5cc6ccccc6cc5c24)cc31 ; c1ccc2cc3c(cc2c1)oc1cccc(-c2cc4ccccc4c4oc5cc6ccccc6cc5c24)c13]

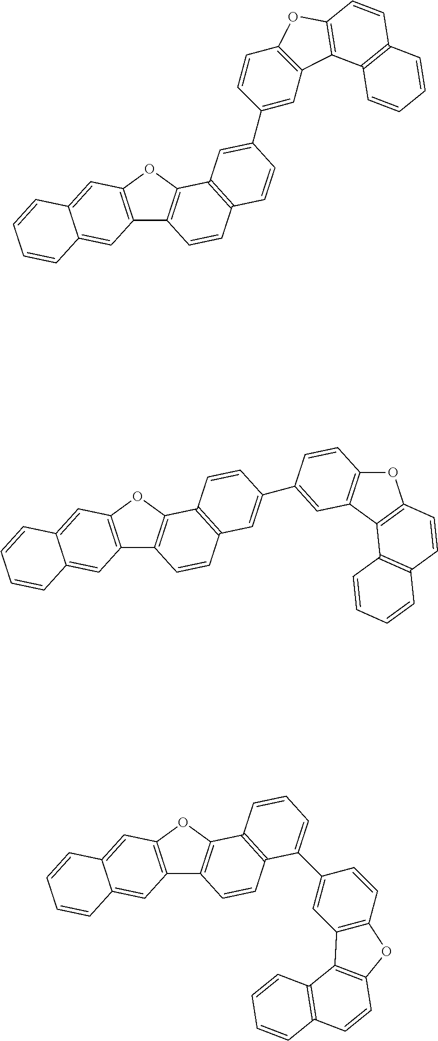 [SMILES: c1ccc2cc3c(cc2c1)oc1c2cc(-c4ccc5oc6ccc7ccccc7c6c5c4)ccc2ccc31 ; c1ccc2cc3c(cc2c1)oc1c2ccc(-c4ccc5oc6ccc7ccccc7c6c5c4)cc2ccc31 ; c1ccc2cc3c(cc2c1)oc1c2cccc(-c4ccc5oc6ccc7ccccc7c6c5c4)c2ccc31]

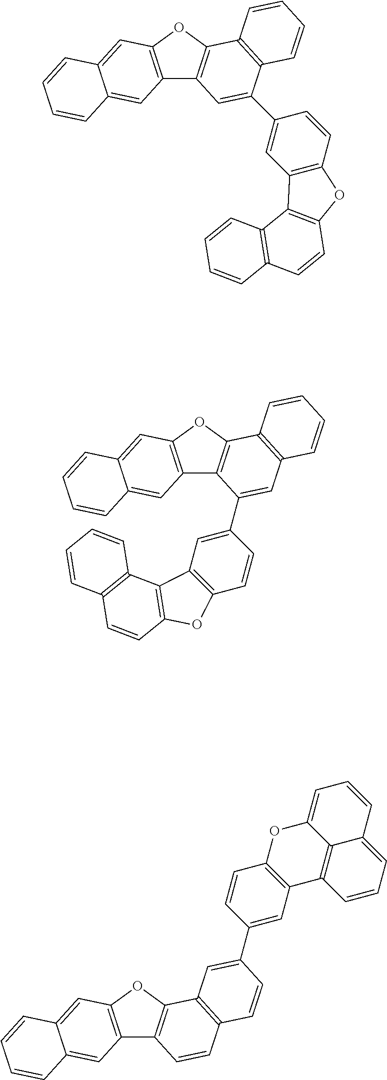 [SMILES: c1ccc2cc3c(cc2c1)oc1c2ccccc2c(-c2ccc4oc5ccc6ccccc6c5c4c2)cc31 ; c1ccc2cc3c(cc2c1)oc1c2ccccc2cc(-c2ccc4oc5ccc6ccccc6c5c4c2)c31 ; c1ccc2cc3c(cc2c1)oc1c2cc(-c4ccc5c(c4)-c4cccc6cccc(c46)O5)ccc2ccc31]

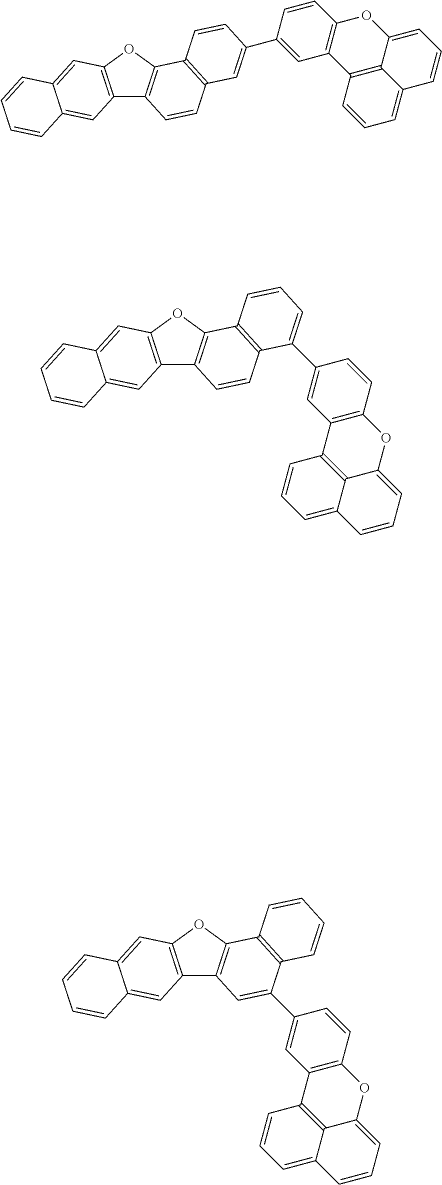 [SMILES: c1ccc2cc3c(cc2c1)oc1c2ccc(-c4ccc5c(c4)-c4cccc6cccc(c46)O5)cc2ccc31 ; c1ccc2cc3c(cc2c1)oc1c2cccc(-c4ccc5c(c4)-c4cccc6cccc(c46)O5)c2ccc31 ; c1ccc2cc3c(cc2c1)oc1c2ccccc2c(-c2ccc4c(c2)-c2cccc5cccc(c25)O4)cc31]

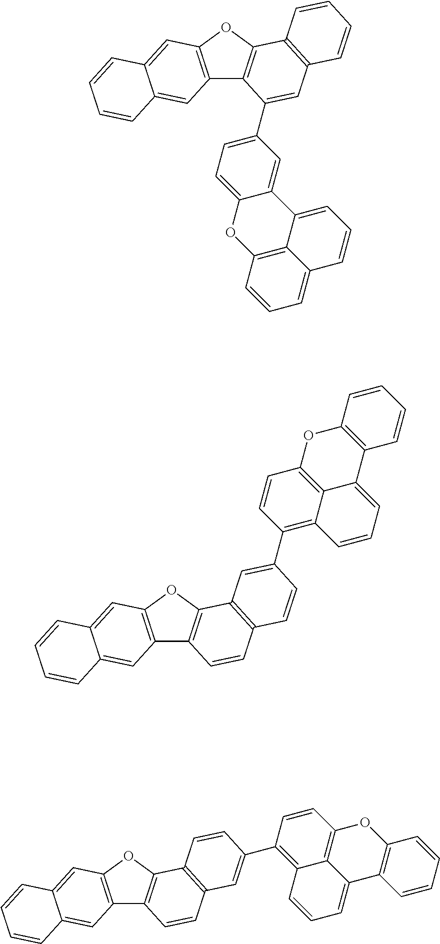 [SMILES: c1ccc2cc3c(cc2c1)oc1c2ccccc2cc(-c2ccc4c(c2)-c2cccc5cccc(c25)O4)c31 ; c1ccc2c(c1)Oc1ccc(-c3ccc4ccc5c6cc7ccccc7cc6oc5c4c3)c3cccc-2c13 ; c1ccc2c(c1)Oc1ccc(-c3ccc4c(ccc5c6cc7ccccc7cc6oc45)c3)c3cccc-2c13]

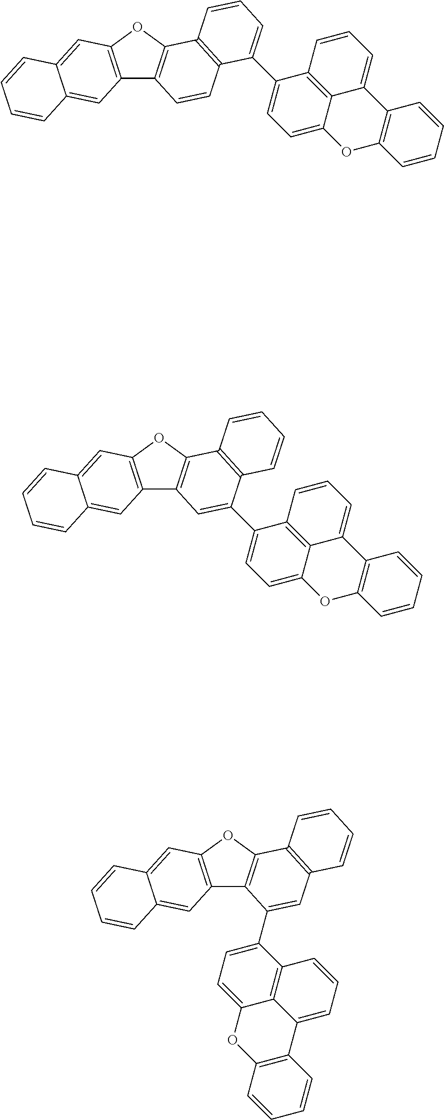 [SMILES: c1ccc2c(c1)Oc1ccc(-c3cccc4c3ccc3c5cc6ccccc6cc5oc43)c3cccc-2c13 ; c1ccc2c(c1)Oc1ccc(-c3cc4c5cc6ccccc6cc5oc4c4ccccc34)c3cccc-2c13 ; c1ccc2c(c1)Oc1ccc(-c3cc4ccccc4c4oc5cc6ccccc6cc5c34)c3cccc-2c13]

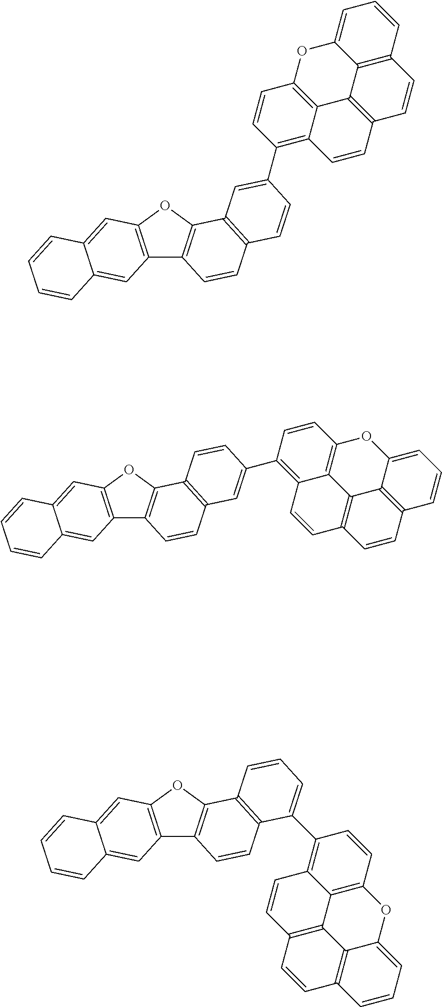 [SMILES: c1ccc2cc3c(cc2c1)oc1c2cc(-c4ccc5c6c4ccc4ccc7cccc(c7c46)O5)ccc2ccc31 ; c1ccc2cc3c(cc2c1)oc1c2ccc(-c4ccc5c6c4ccc4ccc7cccc(c7c46)O5)cc2ccc31 ; c1ccc2cc3c(cc2c1)oc1c2cccc(-c4ccc5c6c4ccc4ccc7cccc(c7c46)O5)c2ccc31]

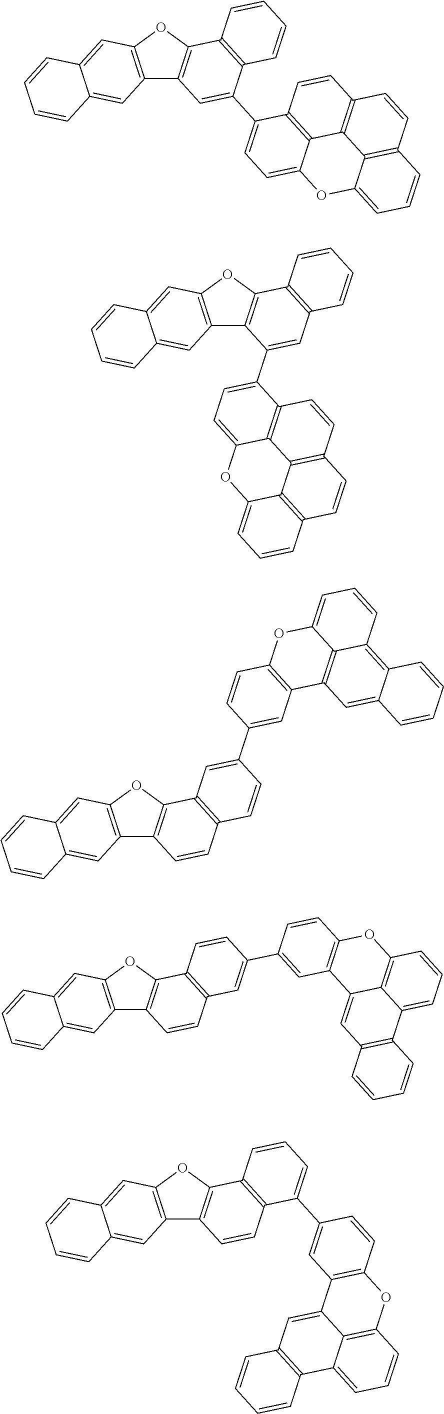 [SMILES: c1ccc2cc3c(cc2c1)oc1c2ccccc2c(-c2ccc4c5c2ccc2ccc6cccc(c6c25)O4)cc31 ; c1ccc2cc3c(cc2c1)oc1c2ccccc2cc(-c2ccc4c5c2ccc2ccc6cccc(c6c25)O4)c31 ; c1ccc2cc3c(cc2c1)oc1c2cc(-c4ccc5c(c4)-c4cc6ccccc6c6cccc(c46)O5)ccc2ccc31 ; c1ccc2cc3c(cc2c1)oc1c2ccc(-c4ccc5c(c4)-c4cc6ccccc6c6cccc(c46)O5)cc2ccc31 ; c1ccc2cc3c(cc2c1)oc1c2cccc(-c4ccc5c(c4)-c4cc6ccccc6c6cccc(c46)O5)c2ccc31]

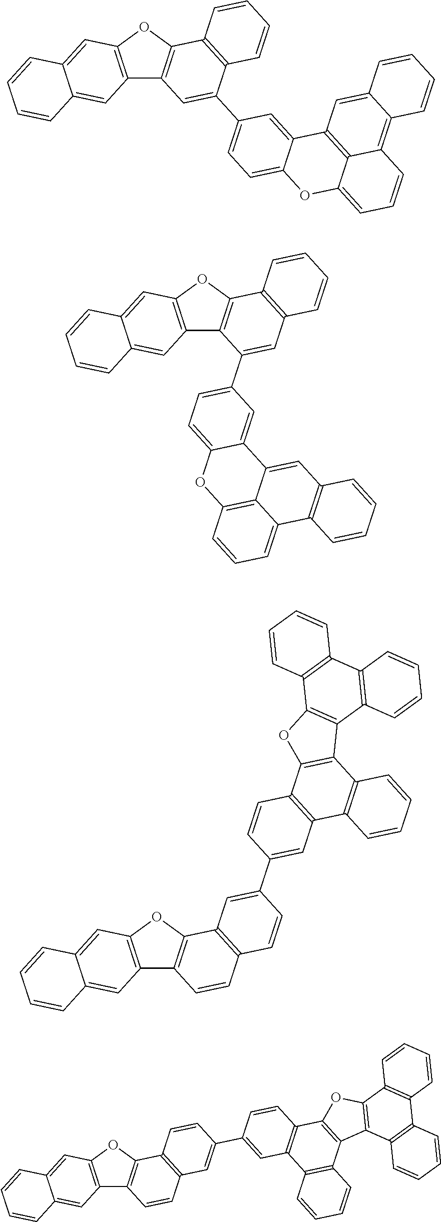 [SMILES: c1ccc2cc3c(cc2c1)oc1c2ccccc2c(-c2ccc4c(c2)-c2cc5ccccc5c5cccc(c25)O4)cc31 ; c1ccc2cc3c(cc2c1)oc1c2ccccc2cc(-c2ccc4c(c2)-c2cc5ccccc5c5cccc(c25)O4)c31 ; c1ccc2cc3c(cc2c1)oc1c2cc(-c4ccc5c(c4)c4ccccc4c4c5oc5c6ccccc6c6ccccc6c54)ccc2ccc31 ; c1ccc2cc3c(cc2c1)oc1c2ccc(-c4ccc5c(c4)c4ccccc4c4c5oc5c6ccccc6c6ccccc6c54)cc2ccc31]

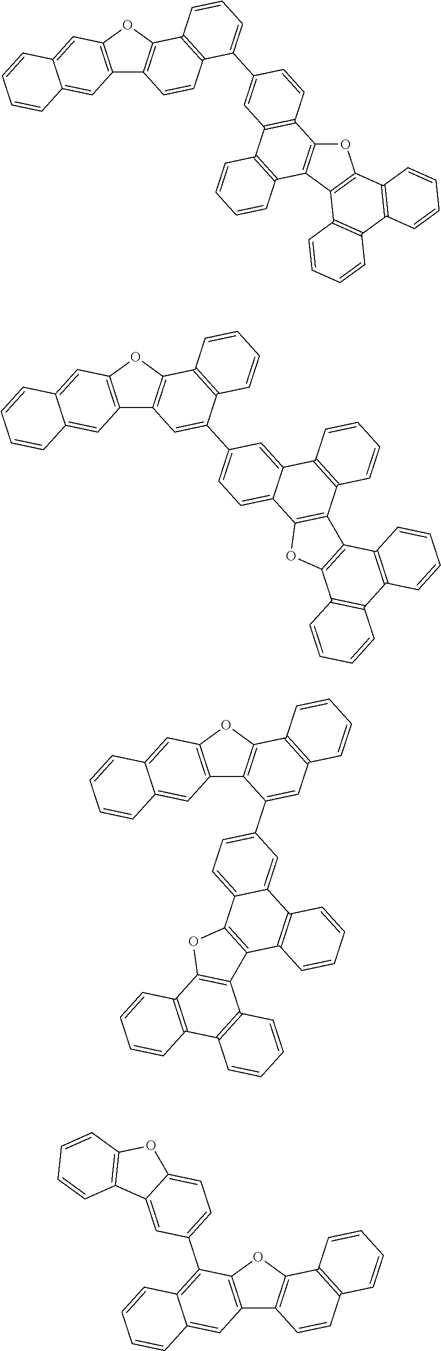

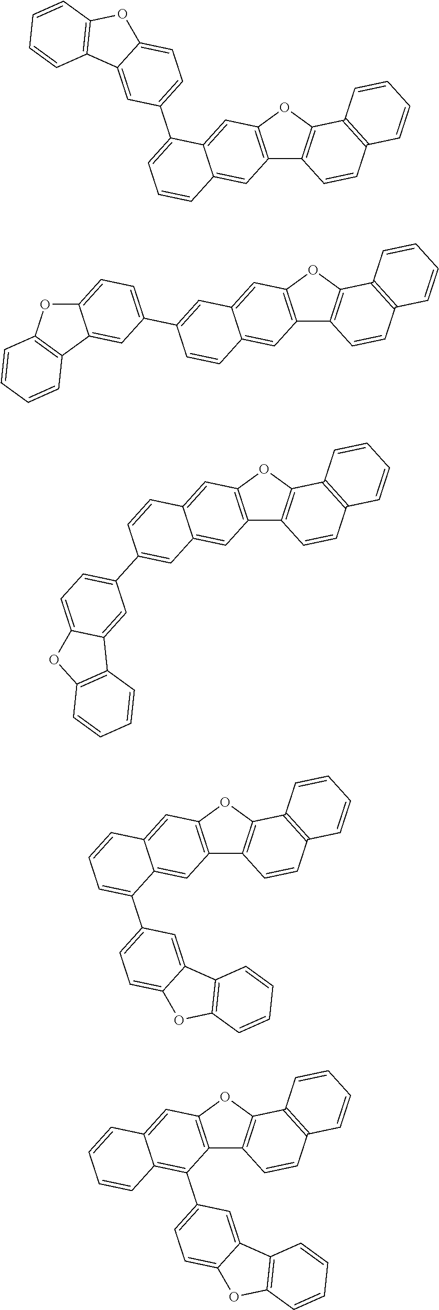 [SMILES: c1cc(-c2ccc3oc4ccccc4c3c2)c2cc3oc4c5ccccc5ccc4c3cc2c1 ; c1ccc2c(c1)ccc1c3cc4ccc(-c5ccc6oc7ccccc7c6c5)cc4cc3oc21 ; c1ccc2c(c1)ccc1c3cc4cc(-c5ccc6oc7ccccc7c6c5)ccc4cc3oc21 ; c1cc(-c2ccc3oc4ccccc4c3c2)c2cc3c(cc2c1)oc1c2ccccc2ccc31 ; c1ccc2c(-c3ccc4oc5ccccc5c4c3)c3c(cc2c1)oc1c2ccccc2ccc13]

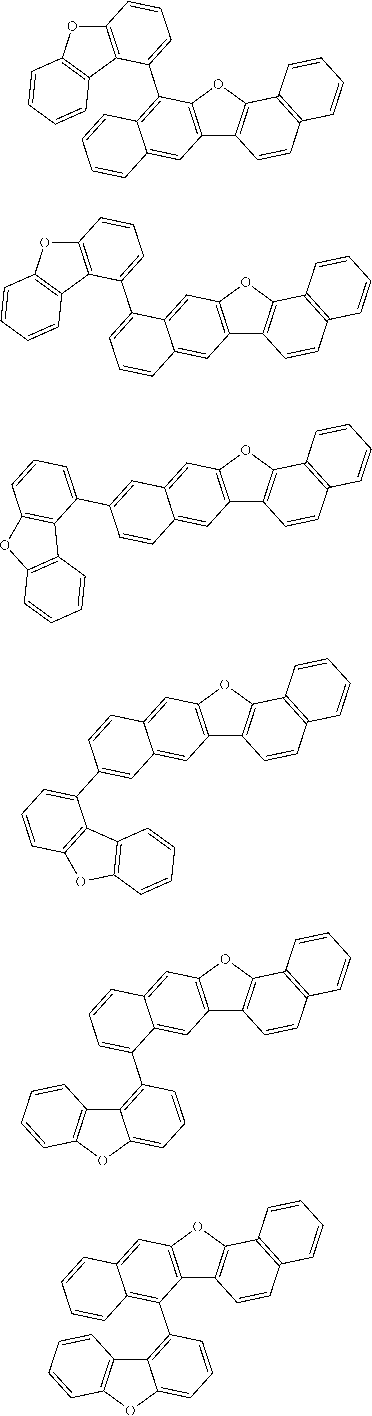

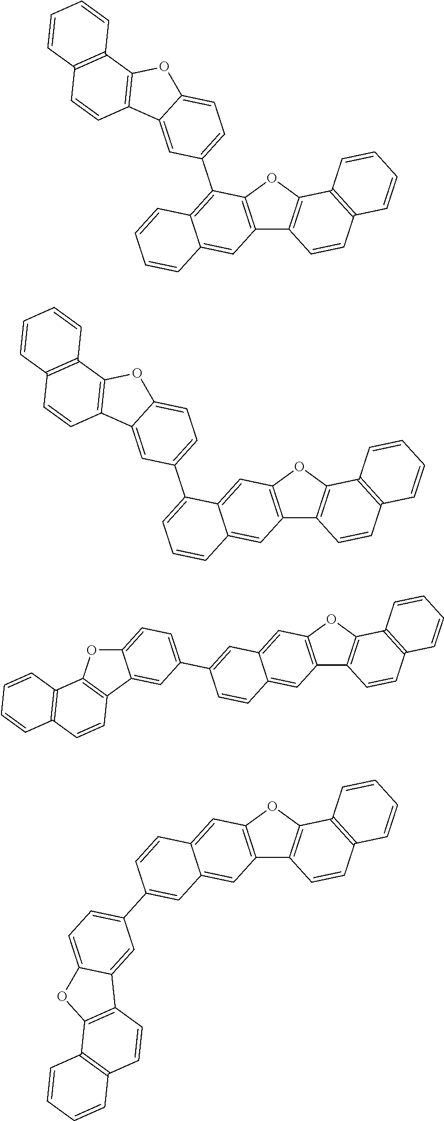 [SMILES: c1ccc2c(-c3ccc4oc5c6ccccc6ccc5c4c3)c3oc4c5ccccc5ccc4c3cc2c1 ; c1cc(-c2ccc3oc4c5ccccc5ccc4c3c2)c2cc3oc4c5ccccc5ccc4c3cc2c1 ; c1ccc2c(c1)ccc1c3cc(-c4ccc5cc6c(cc5c4)oc4c5ccccc5ccc64)ccc3oc21 ; c1ccc2c(c1)ccc1c3cc(-c4ccc5cc6oc7c8ccccc8ccc7c6cc5c4)ccc3oc21]

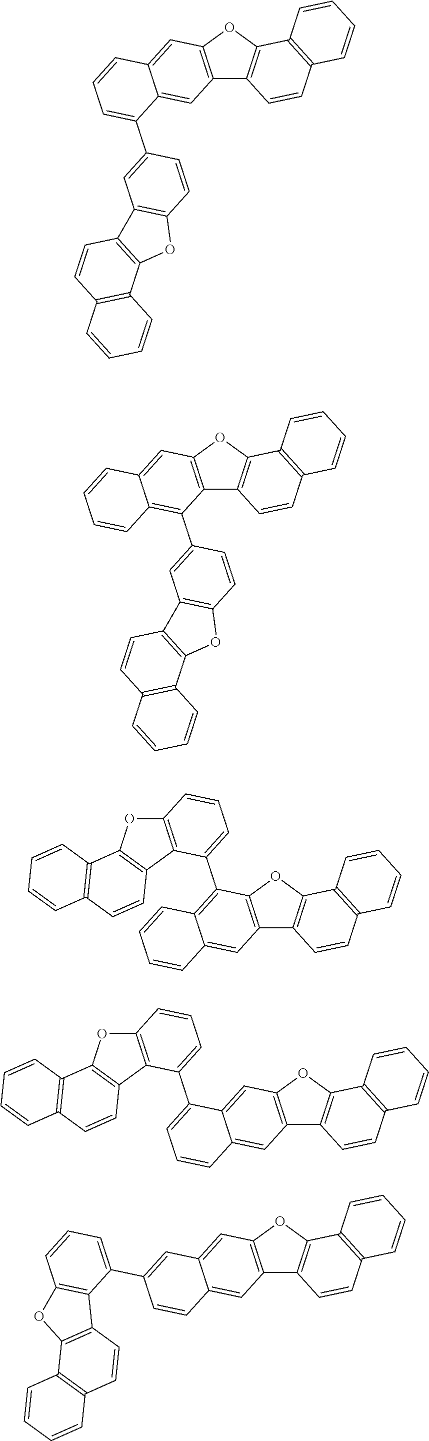

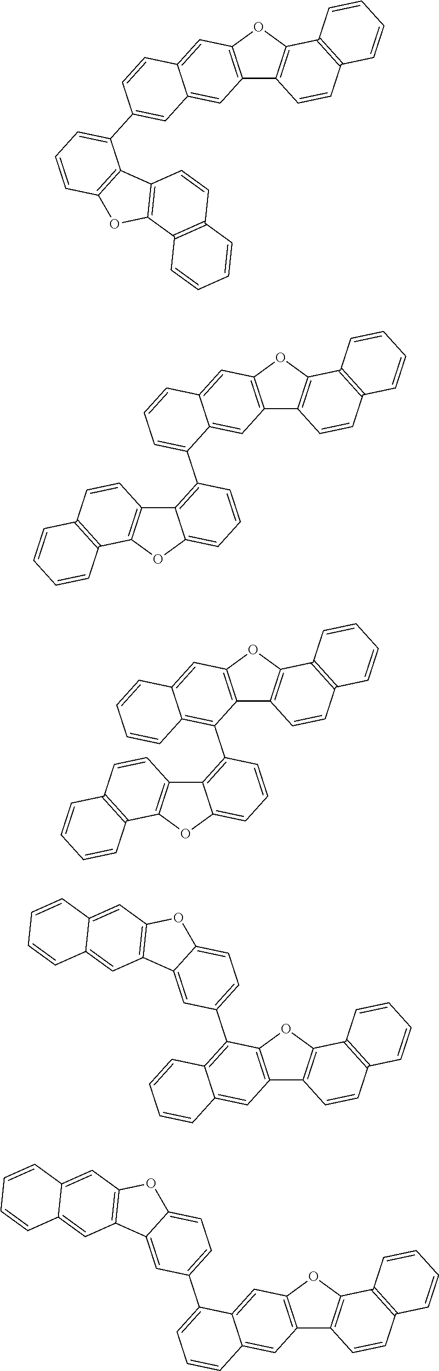

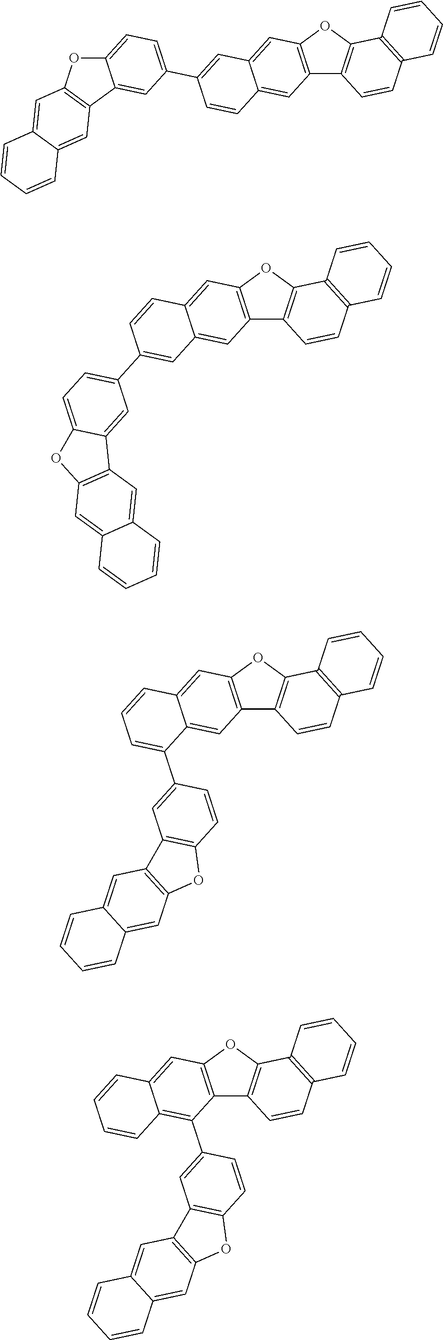 [SMILES: c1ccc2cc3c(cc2c1)oc1ccc(-c2ccc4cc5c(cc4c2)oc2c4ccccc4ccc52)cc13 ; c1ccc2cc3c(cc2c1)oc1ccc(-c2ccc4cc5oc6c7ccccc7ccc6c5cc4c2)cc13 ; c1ccc2cc3c(cc2c1)oc1ccc(-c2cccc4cc5oc6c7ccccc7ccc6c5cc24)cc13 ; c1ccc2cc3c(cc2c1)oc1ccc(-c2c4ccccc4cc4oc5c6ccccc6ccc5c24)cc13]

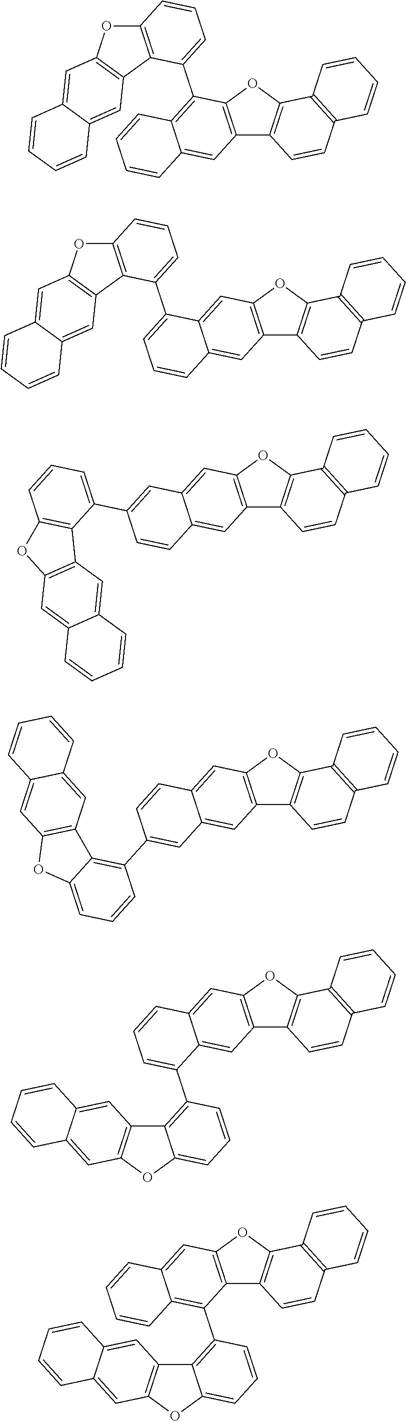 [SMILES: c1ccc2cc3c(cc2c1)oc1cccc(-c2c4ccccc4cc4c2oc2c5ccccc5ccc42)c13 ; c1ccc2cc3c(cc2c1)oc1cccc(-c2cccc4cc5c(cc24)oc2c4ccccc4ccc52)c13 ; c1ccc2cc3c(cc2c1)oc1cccc(-c2ccc4cc5c(cc4c2)oc2c4ccccc4ccc52)c13 ; c1ccc2cc3c(cc2c1)oc1cccc(-c2ccc4cc5oc6c7ccccc7ccc6c5cc4c2)c13 ; c1ccc2cc3c(cc2c1)oc1cccc(-c2cccc4cc5oc6c7ccccc7ccc6c5cc24)c13 ; c1ccc2cc3c(cc2c1)oc1cccc(-c2c4ccccc4cc4oc5c6ccccc6ccc5c24)c13]

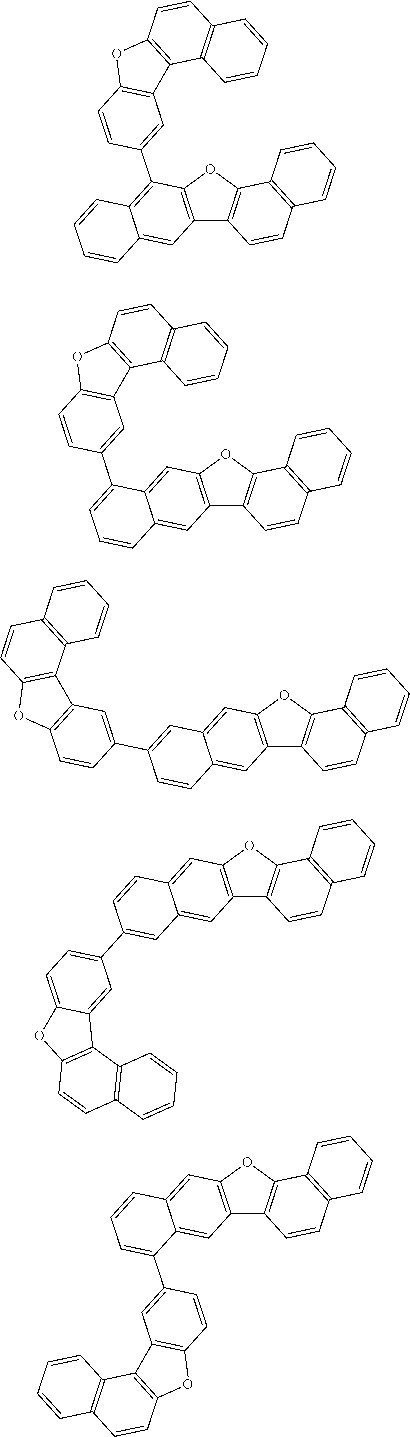

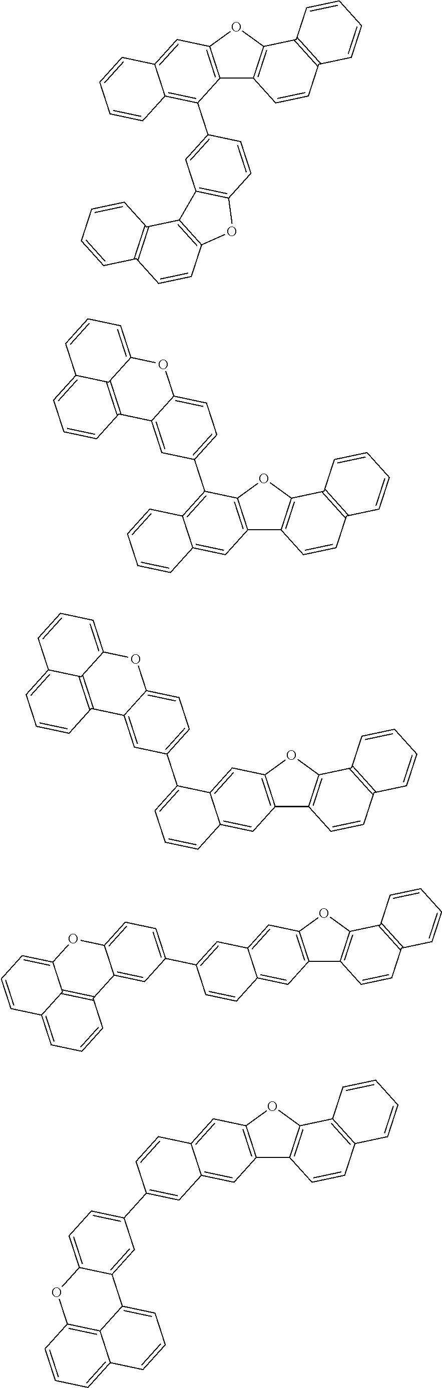 [SMILES: c1ccc2c(-c3ccc4oc5ccc6ccccc6c5c4c3)c3c(cc2c1)oc1c2ccccc2ccc13 ; c1ccc2c(-c3ccc4c(c3)-c3cccc5cccc(c35)O4)c3oc4c5ccccc5ccc4c3cc2c1 ; c1cc(-c2ccc3c(c2)-c2cccc4cccc(c24)O3)c2cc3oc4c5ccccc5ccc4c3cc2c1 ; c1cc2c3c(cccc3c1)-c1cc(-c3ccc4cc5c(cc4c3)oc3c4ccccc4ccc53)ccc1O2 ; c1cc2c3c(cccc3c1)-c1cc(-c3ccc4cc5oc6c7ccccc7ccc6c5cc4c3)ccc1O2]

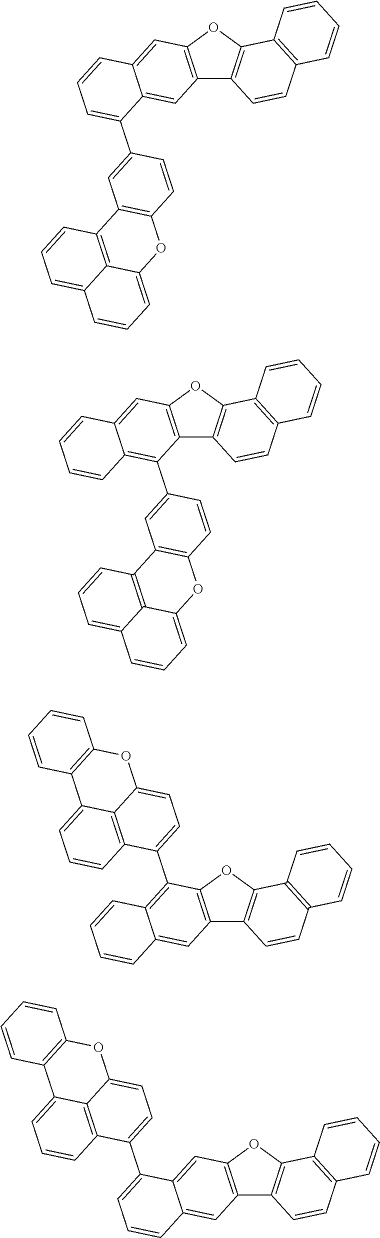 [SMILES: c1cc(-c2ccc3c(c2)-c2cccc4cccc(c24)O3)c2cc3c(cc2c1)oc1c2ccccc2ccc31 ; c1ccc2c(-c3ccc4c(c3)-c3cccc5cccc(c35)O4)c3c(cc2c1)oc1c2ccccc2ccc13 ; c1ccc2c(c1)Oc1ccc(-c3c4ccccc4cc4c3oc3c5ccccc5ccc43)c3cccc-2c13 ; c1ccc2c(c1)Oc1ccc(-c3cccc4cc5c(cc34)oc3c4ccccc4ccc53)c3cccc-2c13]

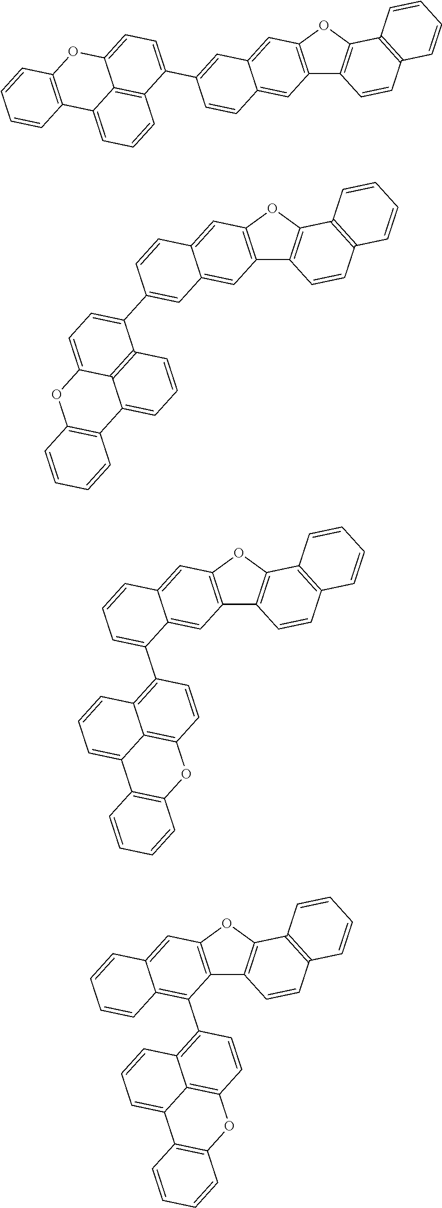 [SMILES: c1ccc2c(c1)Oc1ccc(-c3ccc4cc5c(cc4c3)oc3c4ccccc4ccc53)c3cccc-2c13 ; c1ccc2c(c1)Oc1ccc(-c3ccc4cc5oc6c7ccccc7ccc6c5cc4c3)c3cccc-2c13 ; c1ccc2c(c1)Oc1ccc(-c3cccc4cc5oc6c7ccccc7ccc6c5cc34)c3cccc-2c13 ; c1ccc2c(c1)Oc1ccc(-c3c4ccccc4cc4oc5c6ccccc6ccc5c34)c3cccc-2c13]

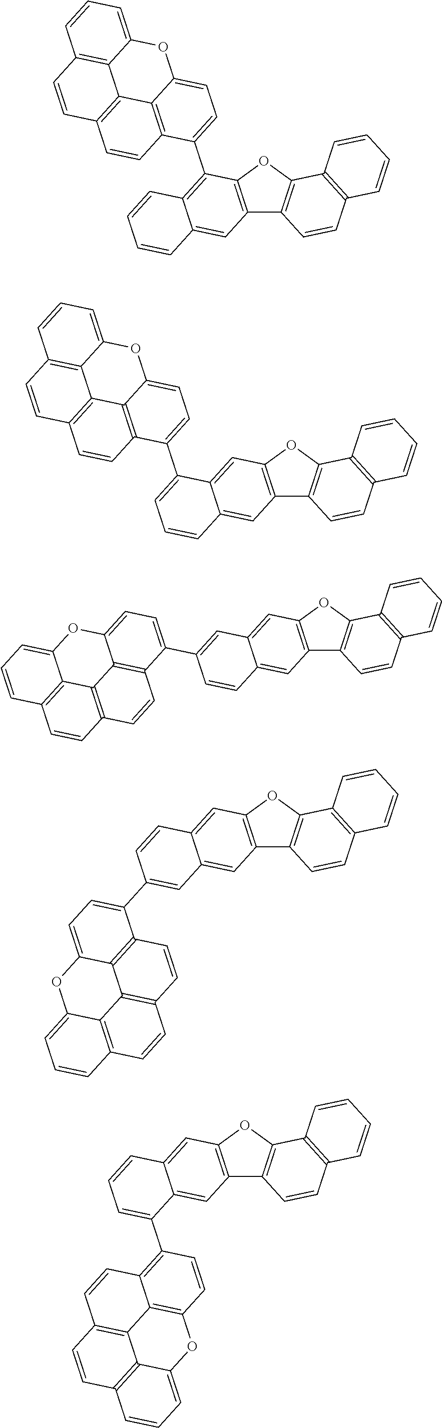 [SMILES: c1ccc2c(-c3ccc4c5c3ccc3ccc6cccc(c6c35)O4)c3oc4c5ccccc5ccc4c3cc2c1 ; c1cc(-c2ccc3c4c2ccc2ccc5cccc(c5c24)O3)c2cc3oc4c5ccccc5ccc4c3cc2c1 ; c1ccc2c(c1)ccc1c3cc4ccc(-c5ccc6c7c5ccc5ccc8cccc(c8c57)O6)cc4cc3oc21 ; c1ccc2c(c1)ccc1c3cc4cc(-c5ccc6c7c5ccc5ccc8cccc(c8c57)O6)ccc4cc3oc21 ; c1cc(-c2ccc3c4c2ccc2ccc5cccc(c5c24)O3)c2cc3c(cc2c1)oc1c2ccccc2ccc31]

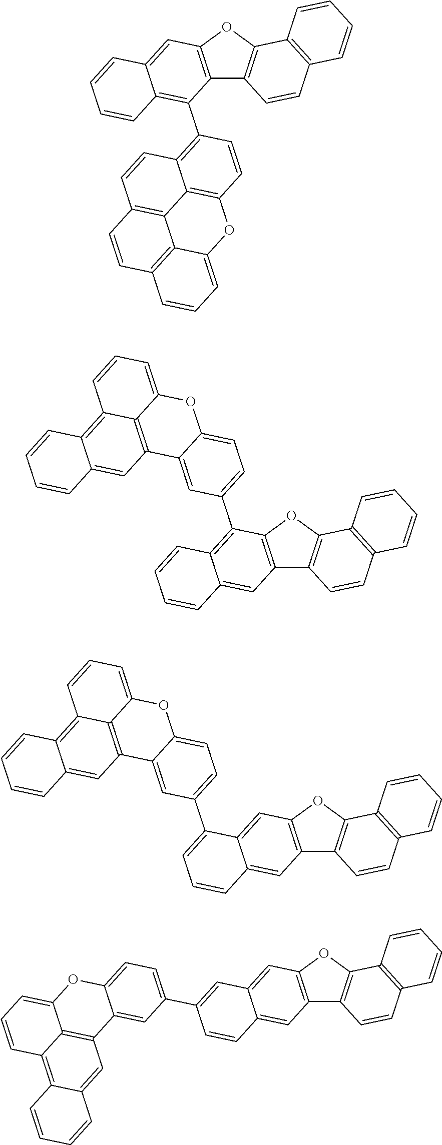 [SMILES: c1ccc2c(-c3ccc4c5c3ccc3ccc6cccc(c6c35)O4)c3c(cc2c1)oc1c2ccccc2ccc13 ; c1ccc2c(-c3ccc4c(c3)-c3cc5ccccc5c5cccc(c35)O4)c3oc4c5ccccc5ccc4c3cc2c1 ; c1cc(-c2ccc3c(c2)-c2cc4ccccc4c4cccc(c24)O3)c2cc3oc4c5ccccc5ccc4c3cc2c1 ; c1ccc2c(c1)cc1c3c(cccc32)Oc2ccc(-c3ccc4cc5c(cc4c3)oc3c4ccccc4ccc53)cc2-1]

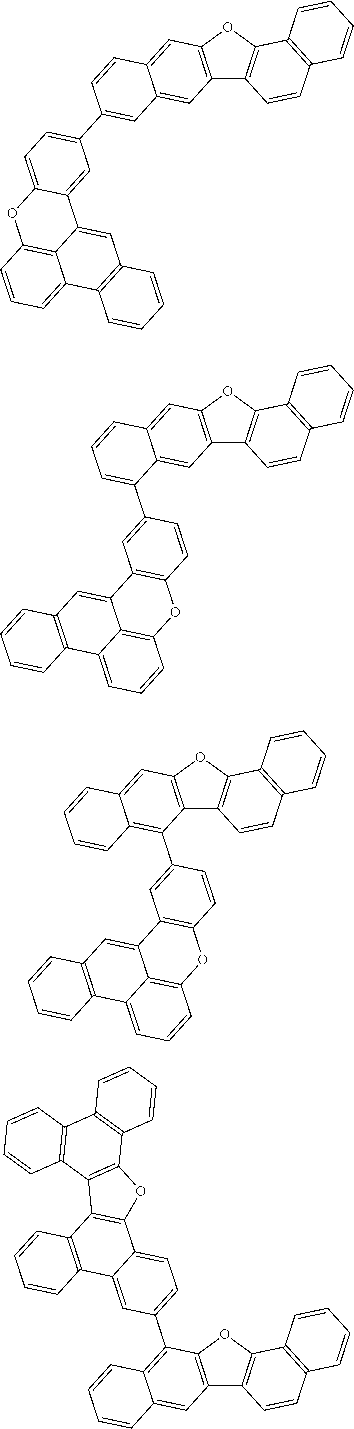

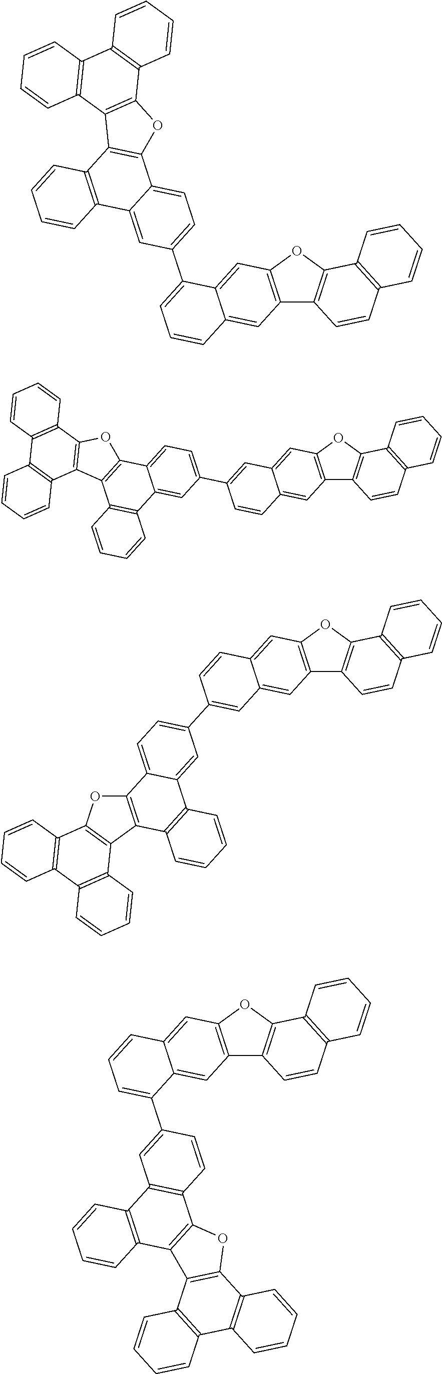 [SMILES: c1cc(-c2ccc3c(c2)c2ccccc2c2c3oc3c4ccccc4c4ccccc4c32)c2cc3oc4c5ccccc5ccc4c3cc2c1 ; c1ccc2c(c1)ccc1c3cc4ccc(-c5ccc6c(c5)c5ccccc5c5c6oc6c7ccccc7c7ccccc7c65)cc4cc3oc21 ; c1ccc2c(c1)ccc1c3cc4cc(-c5ccc6c(c5)c5ccccc5c5c6oc6c7ccccc7c7ccccc7c65)ccc4cc3oc21 ; c1cc(-c2ccc3c(c2)c2ccccc2c2c3oc3c4ccccc4c4ccccc4c32)c2cc3c(cc2c1)oc1c2ccccc2ccc31]

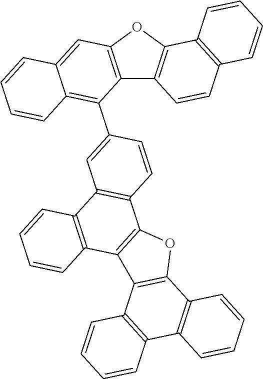 [SMILES: c1ccc2c(-c3ccc4c(c3)c3ccccc3c3c4oc4c5ccccc5c5ccccc5c43)c3c(cc2c1)oc1c2ccccc2ccc13]

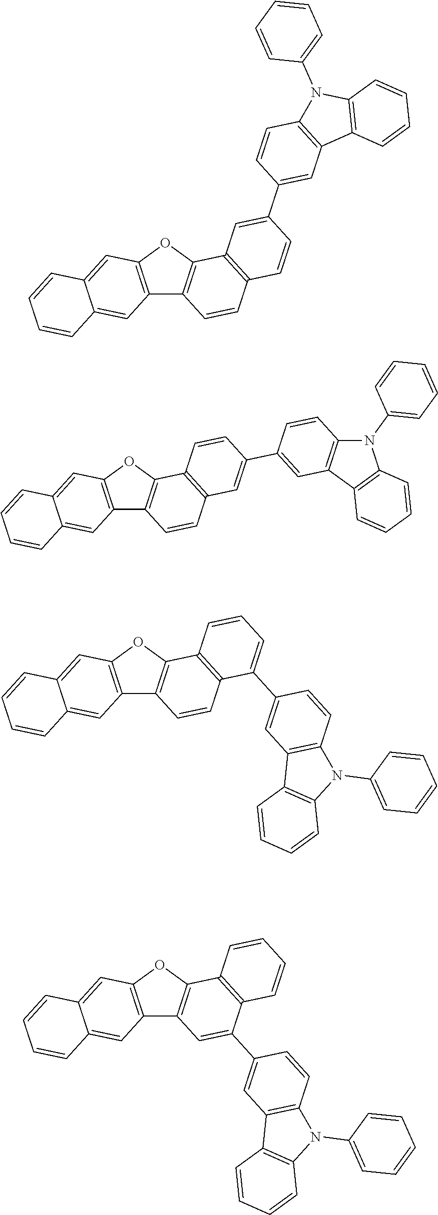 [SMILES: c1ccc(-n2c3ccccc3c3cc(-c4ccc5ccc6c7cc8ccccc8cc7oc6c5c4)ccc32)cc1 ; c1ccc(-n2c3ccccc3c3cc(-c4ccc5c(ccc6c7cc8ccccc8cc7oc56)c4)ccc32)cc1 ; c1ccc(-n2c3ccccc3c3cc(-c4cccc5c4ccc4c6cc7ccccc7cc6oc54)ccc32)cc1 ; c1ccc(-n2c3ccccc3c3cc(-c4cc5c6cc7ccccc7cc6oc5c5ccccc45)ccc32)cc1]

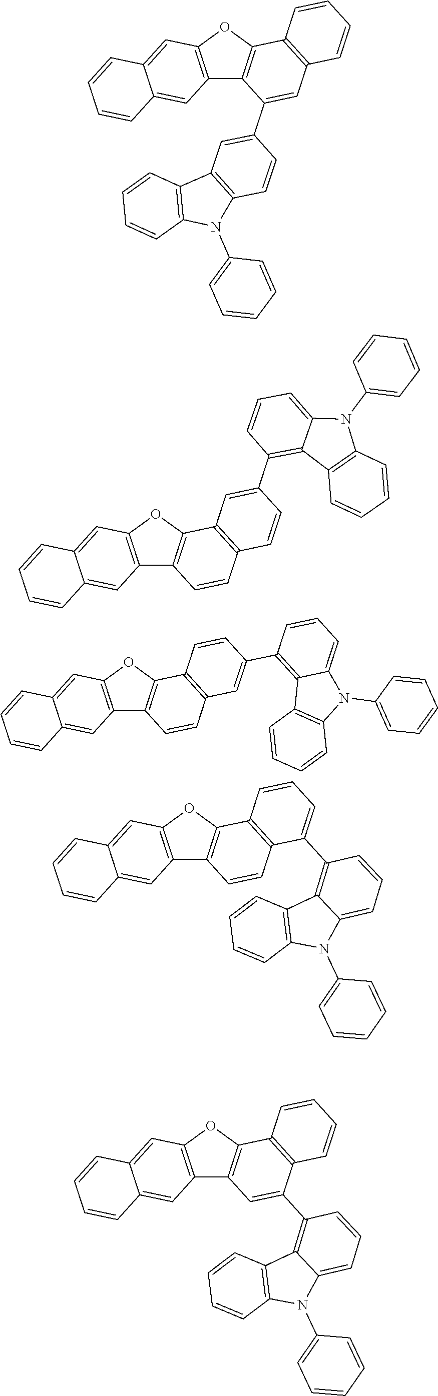

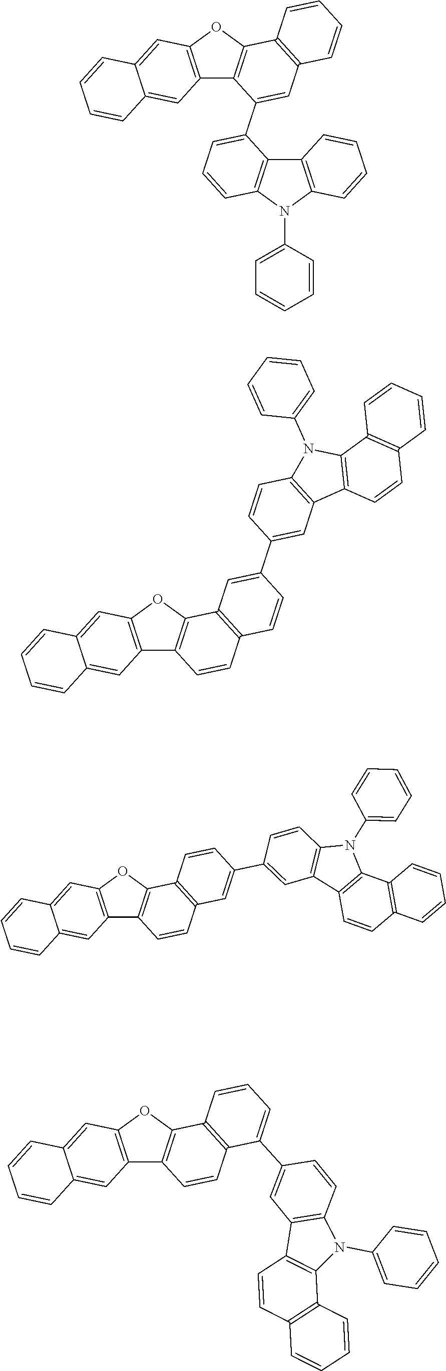 [SMILES: c1ccc(-n2c3ccccc3c3c(-c4cc5ccccc5c5oc6cc7ccccc7cc6c45)cccc32)cc1 ; c1ccc(-n2c3ccc(-c4ccc5ccc6c7cc8ccccc8cc7oc6c5c4)cc3c3ccc4ccccc4c32)cc1 ; c1ccc(-n2c3ccc(-c4ccc5c(ccc6c7cc8ccccc8cc7oc56)c4)cc3c3ccc4ccccc4c32)cc1 ; c1ccc(-n2c3ccc(-c4cccc5c4ccc4c6cc7ccccc7cc6oc54)cc3c3ccc4ccccc4c32)cc1]

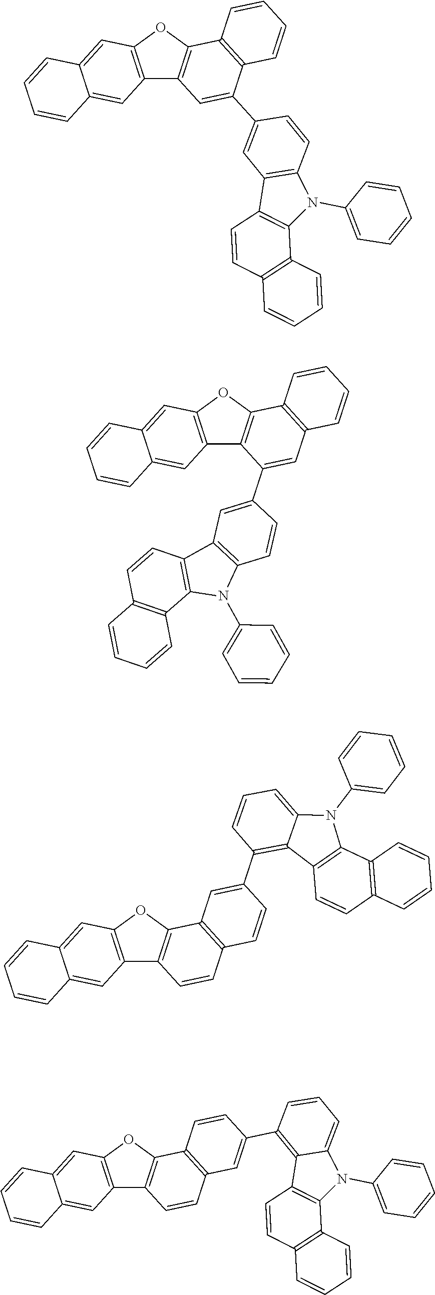 [SMILES: c1ccc(-n2c3ccc(-c4cc5c6cc7ccccc7cc6oc5c5ccccc45)cc3c3ccc4ccccc4c32)cc1 ; c1ccc(-n2c3ccc(-c4cc5ccccc5c5oc6cc7ccccc7cc6c45)cc3c3ccc4ccccc4c32)cc1 ; c1ccc(-n2c3cccc(-c4ccc5ccc6c7cc8ccccc8cc7oc6c5c4)c3c3ccc4ccccc4c32)cc1 ; c1ccc(-n2c3cccc(-c4ccc5c(ccc6c7cc8ccccc8cc7oc56)c4)c3c3ccc4ccccc4c32)cc1]

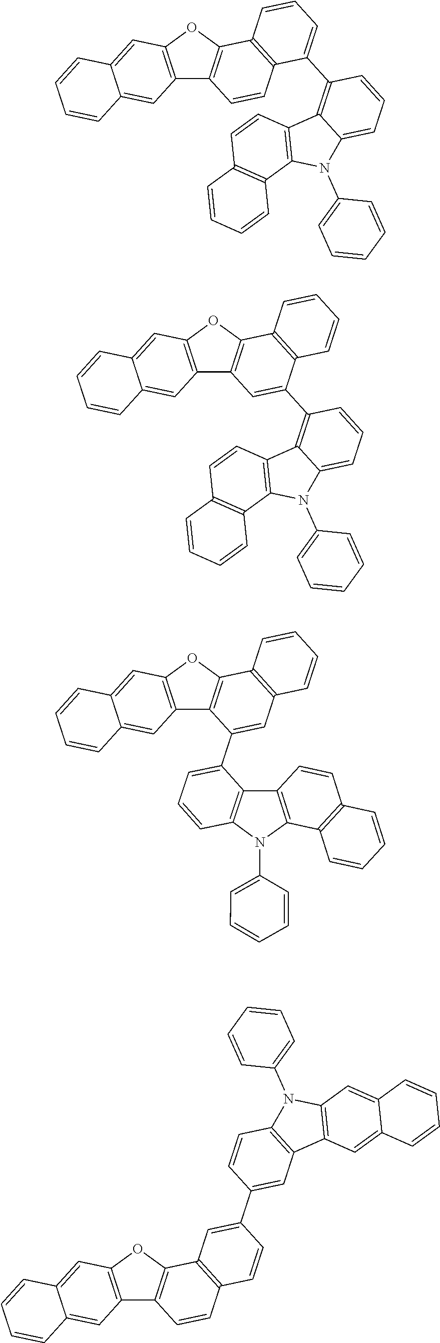

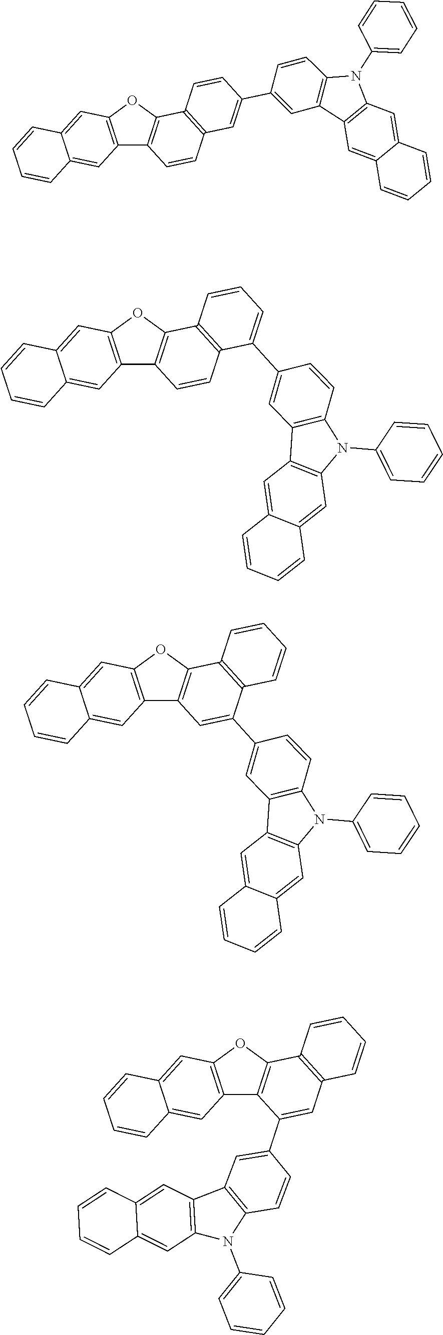

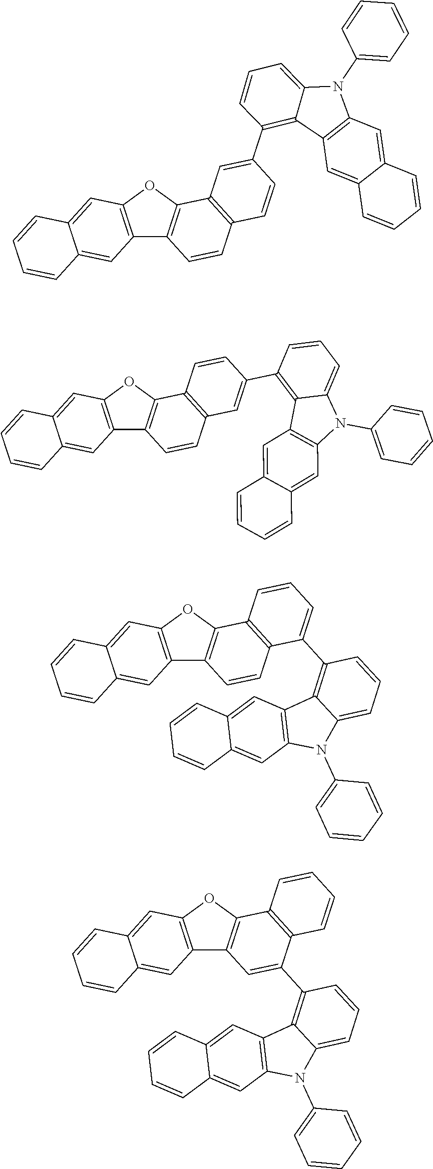

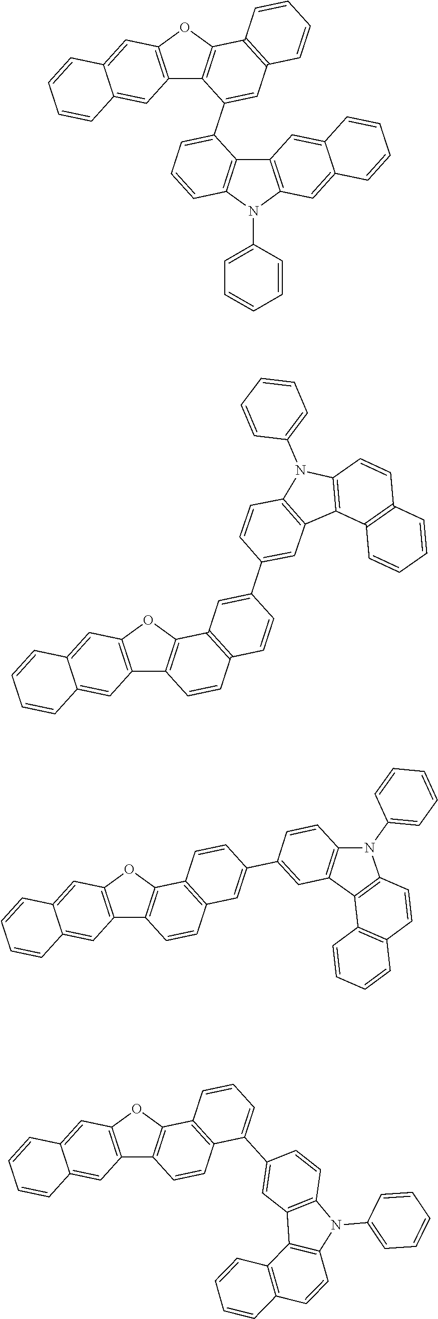 [SMILES: c1ccc(-n2c3cc4ccccc4cc3c3c(-c4cc5ccccc5c5oc6cc7ccccc7cc6c45)cccc32)cc1 ; c1ccc(-n2c3ccc(-c4ccc5ccc6c7cc8ccccc8cc7oc6c5c4)cc3c3c4ccccc4ccc32)cc1 ; c1ccc(-n2c3ccc(-c4ccc5c(ccc6c7cc8ccccc8cc7oc56)c4)cc3c3c4ccccc4ccc32)cc1 ; c1ccc(-n2c3ccc(-c4cccc5c4ccc4c6cc7ccccc7cc6oc54)cc3c3c4ccccc4ccc32)cc1]

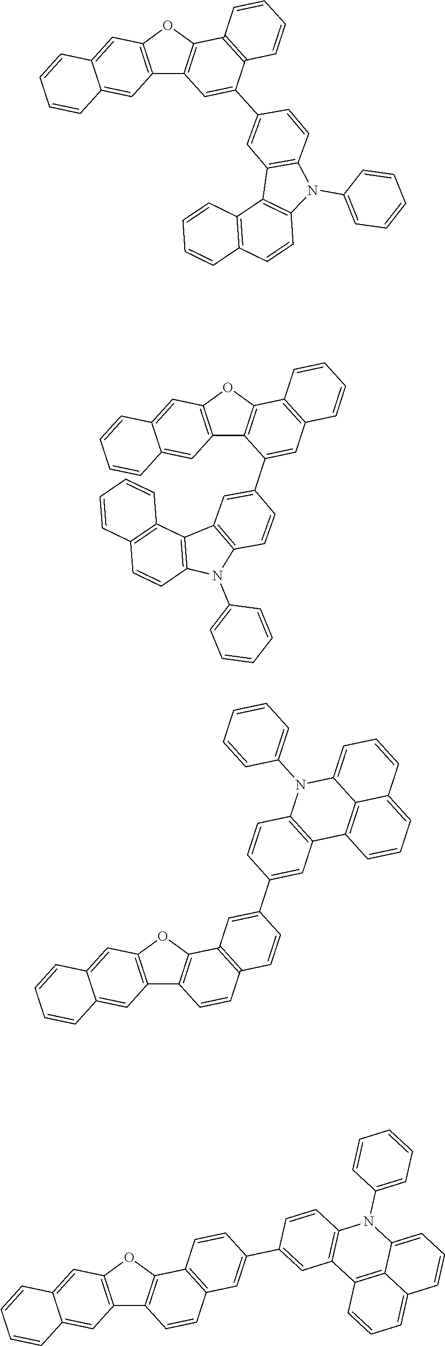

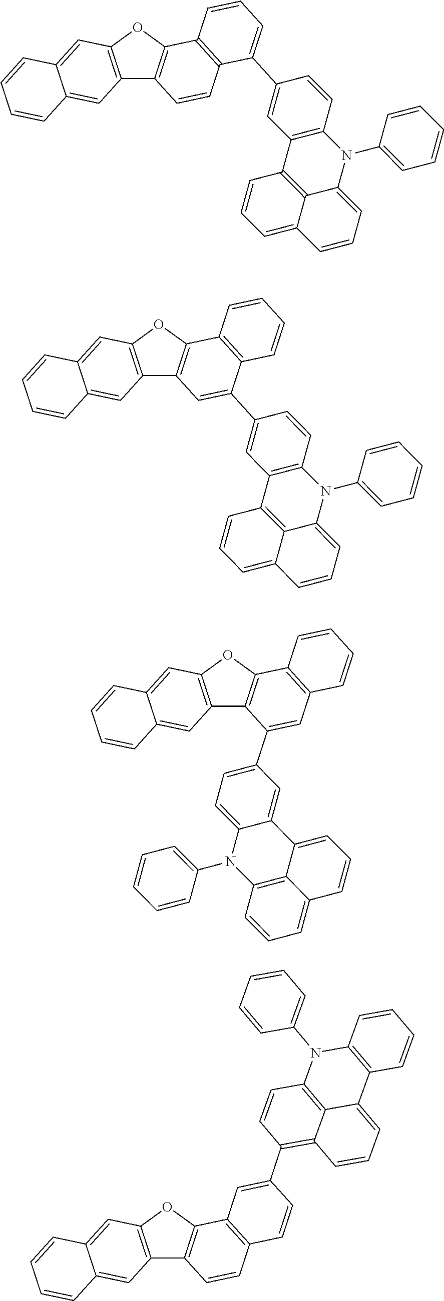

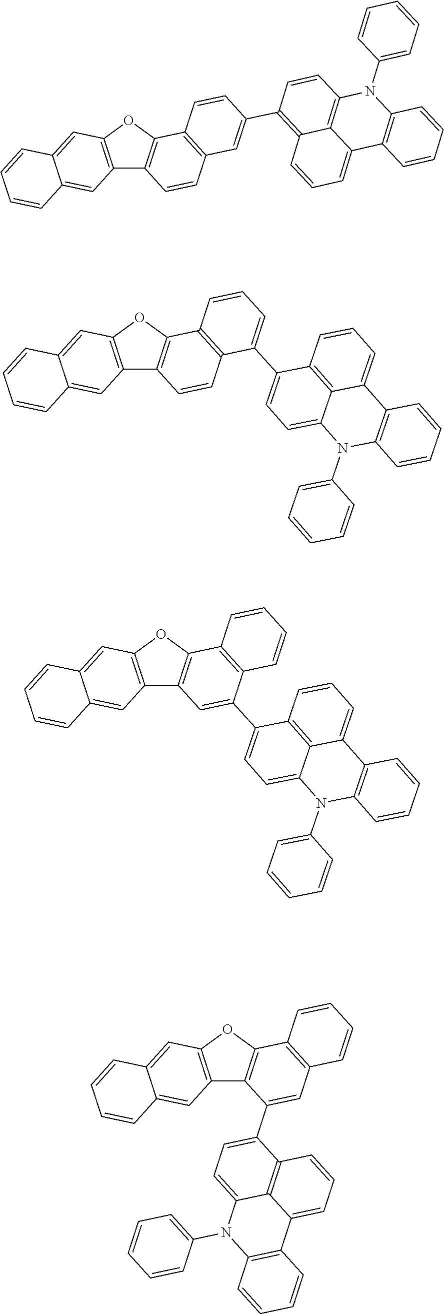 [SMILES: c1ccc(N2c3ccccc3-c3cccc4c(-c5ccc6c(ccc7c8cc9ccccc9cc8oc67)c5)ccc2c34)cc1 ; c1ccc(N2c3ccccc3-c3cccc4c(-c5cccc6c5ccc5c7cc8ccccc8cc7oc65)ccc2c34)cc1 ; c1ccc(N2c3ccccc3-c3cccc4c(-c5cc6c7cc8ccccc8cc7oc6c6ccccc56)ccc2c34)cc1 ; c1ccc(N2c3ccccc3-c3cccc4c(-c5cc6ccccc6c6oc7cc8ccccc8cc7c56)ccc2c34)cc1]

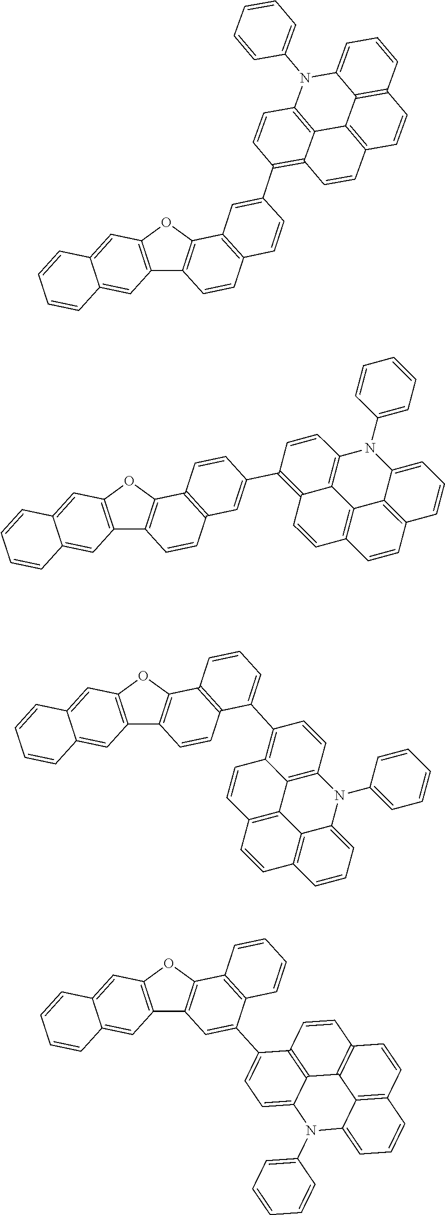 [SMILES: c1ccc(N2c3cccc4ccc5ccc6c(-c7ccc8ccc9c%10cc%11ccccc%11cc%10oc9c8c7)ccc2c6c5c34)cc1 ; c1ccc(N2c3cccc4ccc5ccc6c(-c7ccc8c(ccc9c%10cc%11ccccc%11cc%10oc89)c7)ccc2c6c5c34)cc1 ; c1ccc(N2c3cccc4ccc5ccc6c(-c7cccc8c7ccc7c9cc%10ccccc%10cc9oc87)ccc2c6c5c34)cc1 ; c1ccc(N2c3cccc4ccc5ccc6c(-c7cc8c9cc%10ccccc%10cc9oc8c8ccccc78)ccc2c6c5c34)cc1]

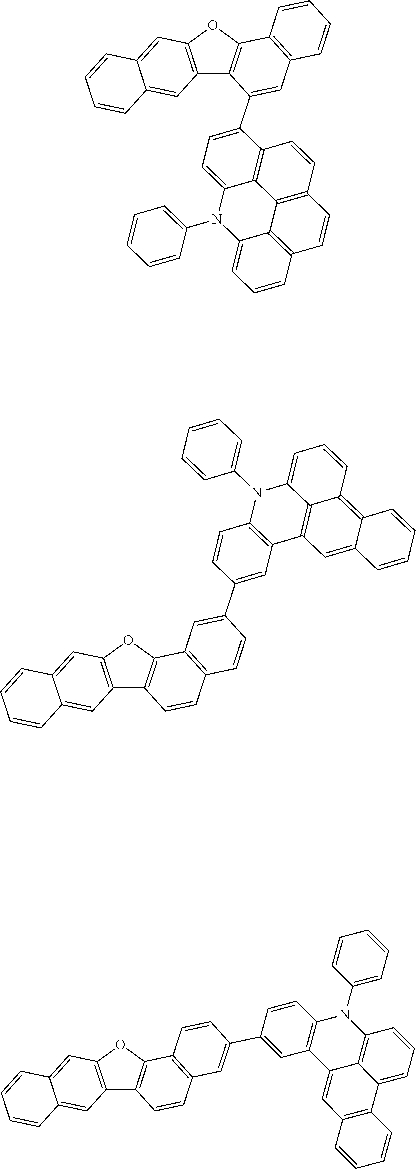 [SMILES: c1ccc(N2c3cccc4ccc5ccc6c(-c7cc8ccccc8c8oc9cc%10ccccc%10cc9c78)ccc2c6c5c34)cc1 ; c1ccc(N2c3ccc(-c4ccc5ccc6c7cc8ccccc8cc7oc6c5c4)cc3-c3cc4ccccc4c4cccc2c34)cc1 ; c1ccc(N2c3ccc(-c4ccc5c(ccc6c7cc8ccccc8cc7oc56)c4)cc3-c3cc4ccccc4c4cccc2c34)cc1]

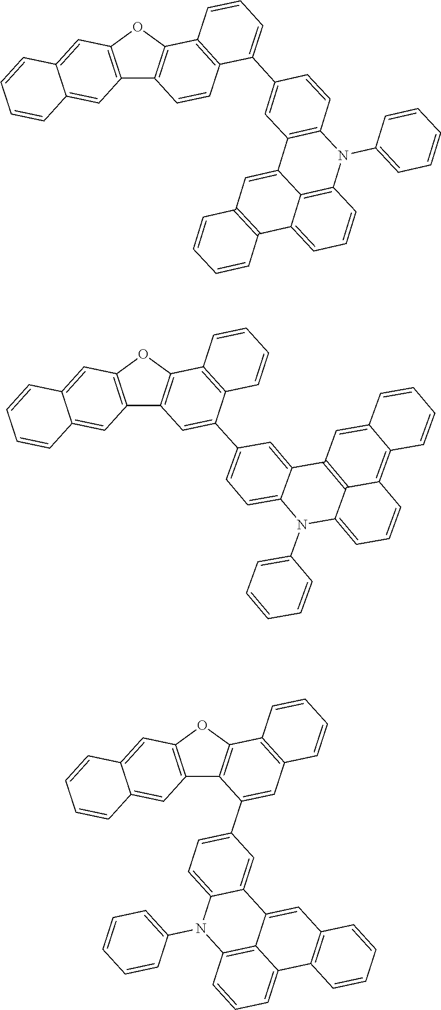 [SMILES: c1ccc(N2c3ccc(-c4cccc5c4ccc4c6cc7ccccc7cc6oc54)cc3-c3cc4ccccc4c4cccc2c34)cc1 ; c1ccc(N2c3ccc(-c4cc5c6cc7ccccc7cc6oc5c5ccccc45)cc3-c3cc4ccccc4c4cccc2c34)cc1 ; c1ccc(N2c3ccc(-c4cc5ccccc5c5oc6cc7ccccc7cc6c45)cc3-c3cc4ccccc4c4cccc2c34)cc1]

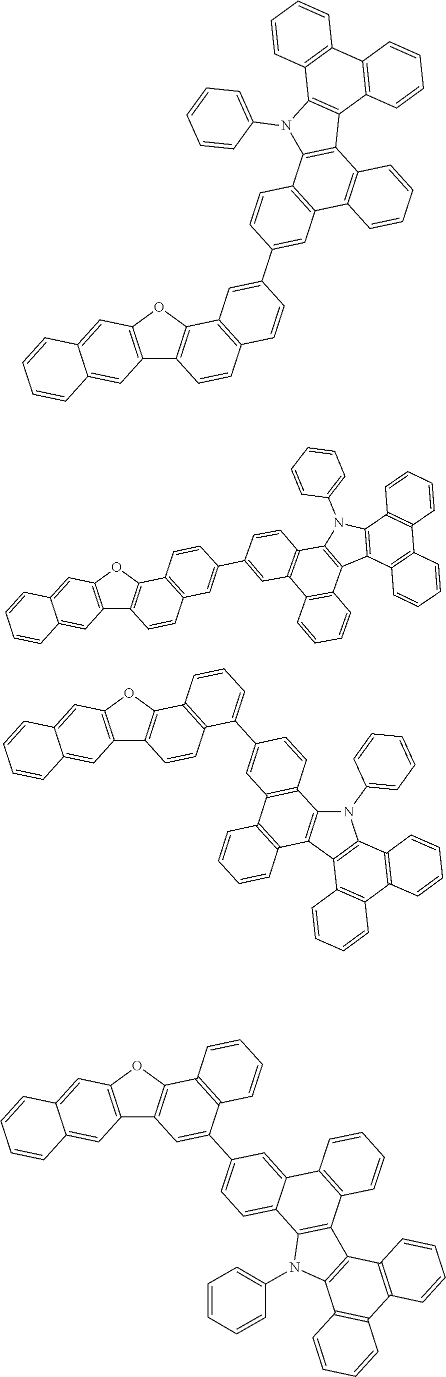 [SMILES: c1ccc(-n2c3c4ccccc4c4ccccc4c3c3c4ccccc4c4cc(-c5ccc6ccc7c8cc9ccccc9cc8oc7c6c5)ccc4c32)cc1 ; c1ccc(-n2c3c4ccccc4c4ccccc4c3c3c4ccccc4c4cc(-c5ccc6c(ccc7c8cc9ccccc9cc8oc67)c5)ccc4c32)cc1 ; c1ccc(-n2c3c4ccccc4c4ccccc4c3c3c4ccccc4c4cc(-c5cccc6c5ccc5c7cc8ccccc8cc7oc65)ccc4c32)cc1 ; c1ccc(-n2c3c4ccccc4c4ccccc4c3c3c4ccccc4c4cc(-c5cc6c7cc8ccccc8cc7oc6c6ccccc56)ccc4c32)cc1]

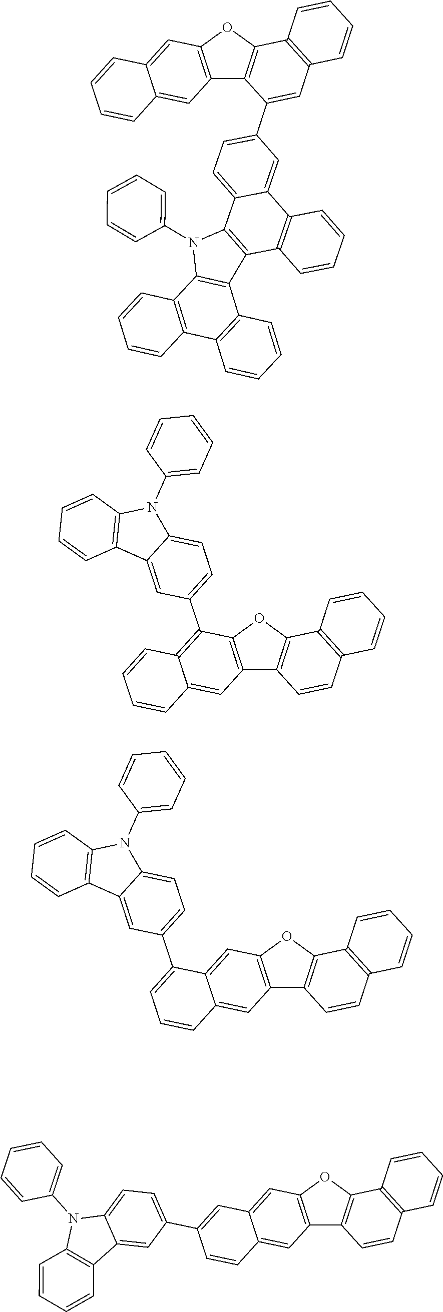

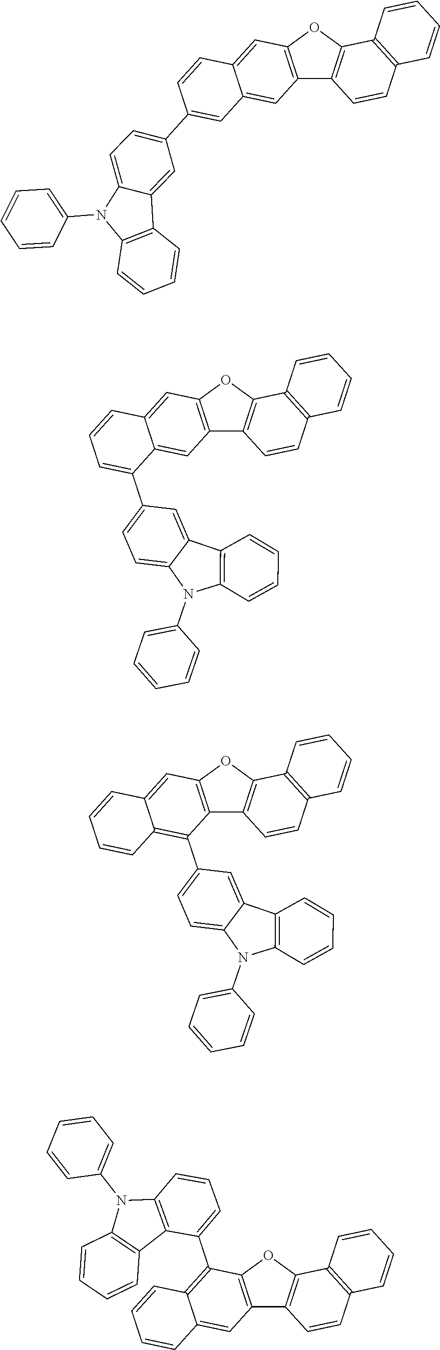 [SMILES: c1ccc(-n2c3ccccc3c3cc(-c4ccc5cc6oc7c8ccccc8ccc7c6cc5c4)ccc32)cc1 ; c1ccc(-n2c3ccccc3c3cc(-c4cccc5cc6oc7c8ccccc8ccc7c6cc45)ccc32)cc1 ; c1ccc(-n2c3ccccc3c3cc(-c4c5ccccc5cc5oc6c7ccccc7ccc6c45)ccc32)cc1 ; c1ccc(-n2c3ccccc3c3c(-c4c5ccccc5cc5c4oc4c6ccccc6ccc54)cccc32)cc1]

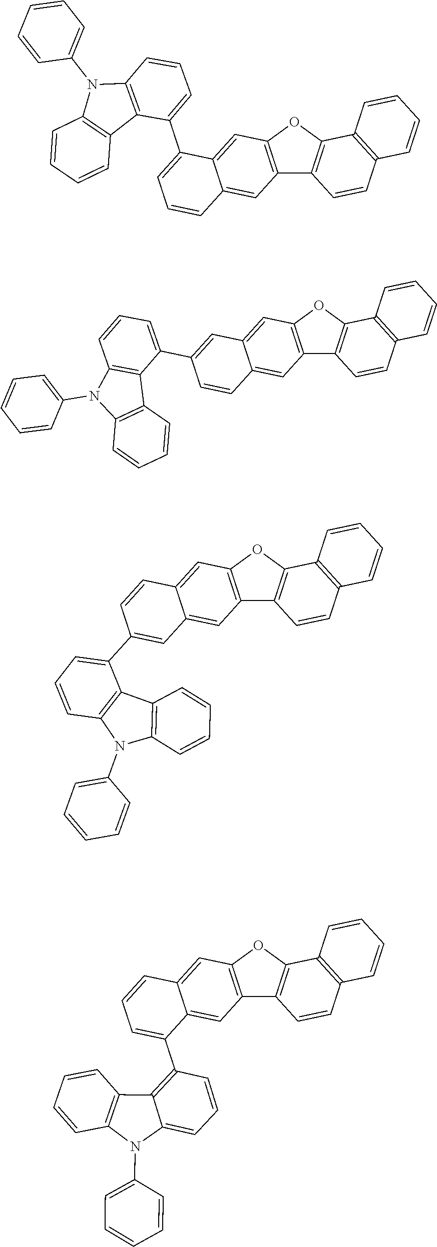 [SMILES: c1ccc(-n2c3ccccc3c3c(-c4cccc5cc6c(cc45)oc4c5ccccc5ccc64)cccc32)cc1 ; c1ccc(-n2c3ccccc3c3c(-c4ccc5cc6c(cc5c4)oc4c5ccccc5ccc64)cccc32)cc1 ; c1ccc(-n2c3ccccc3c3c(-c4ccc5cc6oc7c8ccccc8ccc7c6cc5c4)cccc32)cc1 ; c1ccc(-n2c3ccccc3c3c(-c4cccc5cc6oc7c8ccccc8ccc7c6cc45)cccc32)cc1]

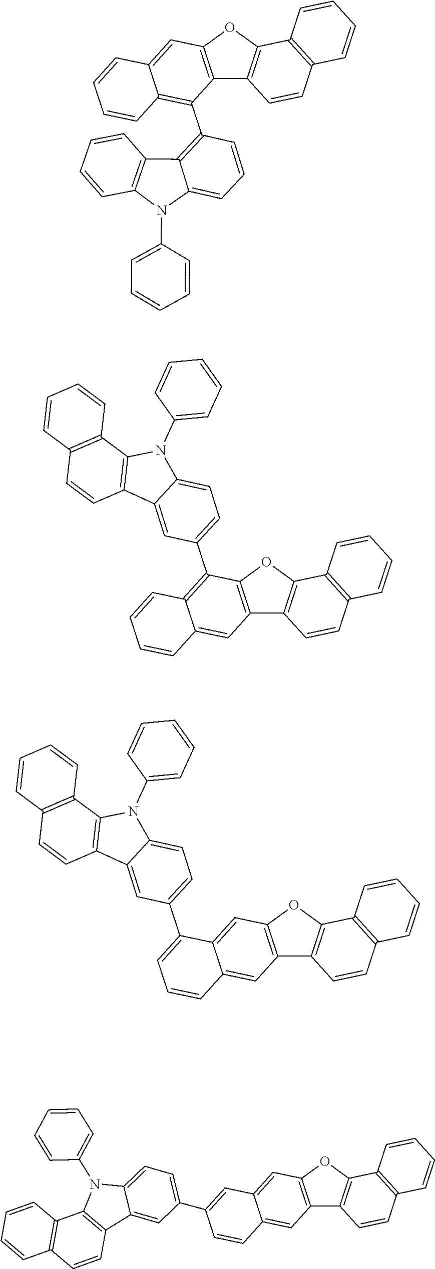 [SMILES: c1ccc(-n2c3ccccc3c3c(-c4c5ccccc5cc5oc6c7ccccc7ccc6c45)cccc32)cc1 ; c1ccc(-n2c3ccc(-c4c5ccccc5cc5c4oc4c6ccccc6ccc54)cc3c3ccc4ccccc4c32)cc1 ; c1ccc(-n2c3ccc(-c4cccc5cc6c(cc45)oc4c5ccccc5ccc64)cc3c3ccc4ccccc4c32)cc1 ; c1ccc(-n2c3ccc(-c4ccc5cc6c(cc5c4)oc4c5ccccc5ccc64)cc3c3ccc4ccccc4c32)cc1]

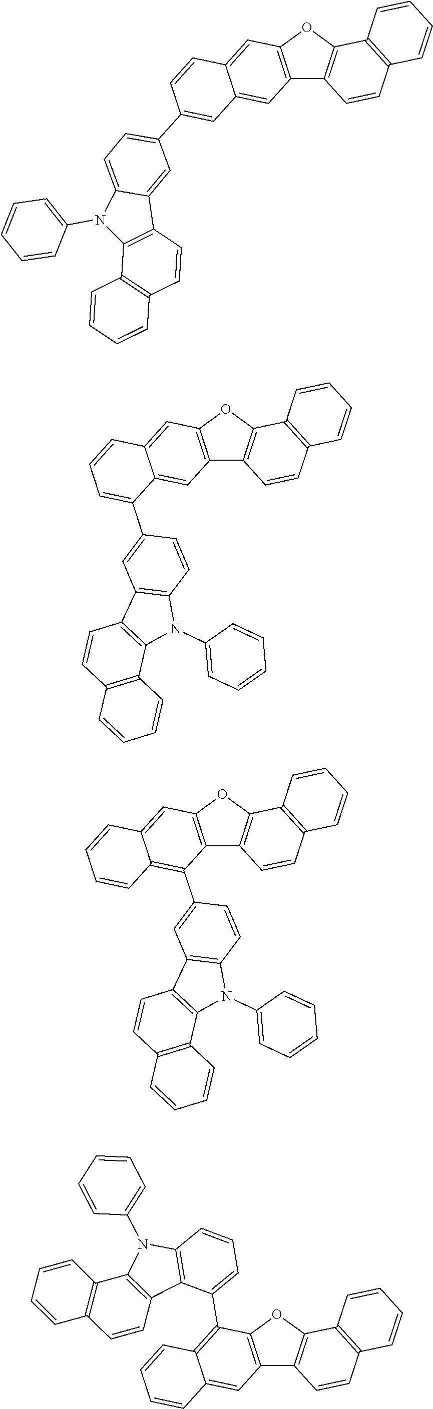 [SMILES: c1ccc(-n2c3ccc(-c4ccc5cc6oc7c8ccccc8ccc7c6cc5c4)cc3c3ccc4ccccc4c32)cc1 ; c1ccc(-n2c3ccc(-c4cccc5cc6oc7c8ccccc8ccc7c6cc45)cc3c3ccc4ccccc4c32)cc1 ; c1ccc(-n2c3ccc(-c4c5ccccc5cc5oc6c7ccccc7ccc6c45)cc3c3ccc4ccccc4c32)cc1 ; c1ccc(-n2c3cccc(-c4c5ccccc5cc5c4oc4c6ccccc6ccc54)c3c3ccc4ccccc4c32)cc1]

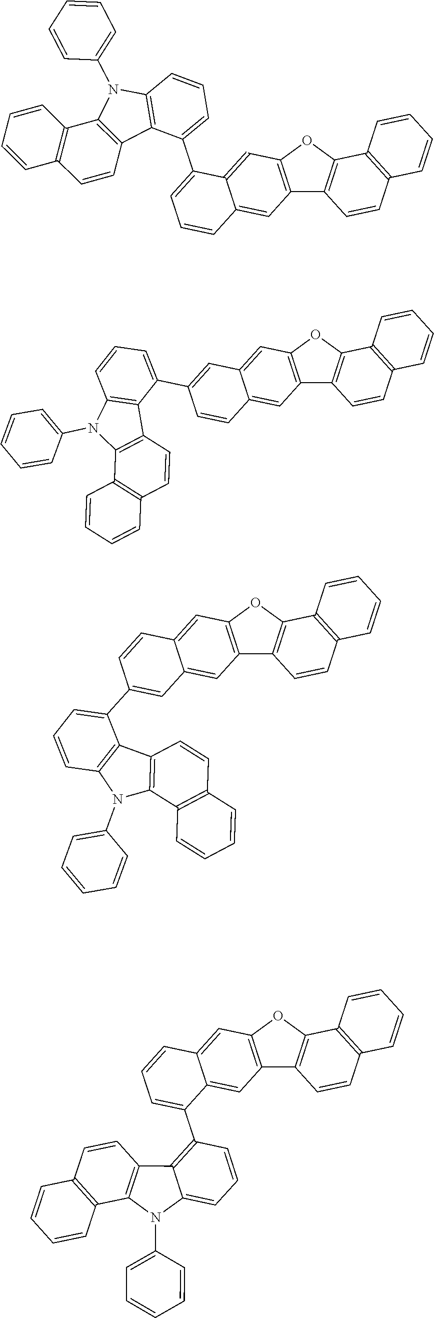 [SMILES: c1ccc(-n2c3cccc(-c4cccc5cc6c(cc45)oc4c5ccccc5ccc64)c3c3ccc4ccccc4c32)cc1 ; c1ccc(-n2c3cccc(-c4ccc5cc6c(cc5c4)oc4c5ccccc5ccc64)c3c3ccc4ccccc4c32)cc1 ; c1ccc(-n2c3cccc(-c4ccc5cc6oc7c8ccccc8ccc7c6cc5c4)c3c3ccc4ccccc4c32)cc1 ; c1ccc(-n2c3cccc(-c4cccc5cc6oc7c8ccccc8ccc7c6cc45)c3c3ccc4ccccc4c32)cc1]

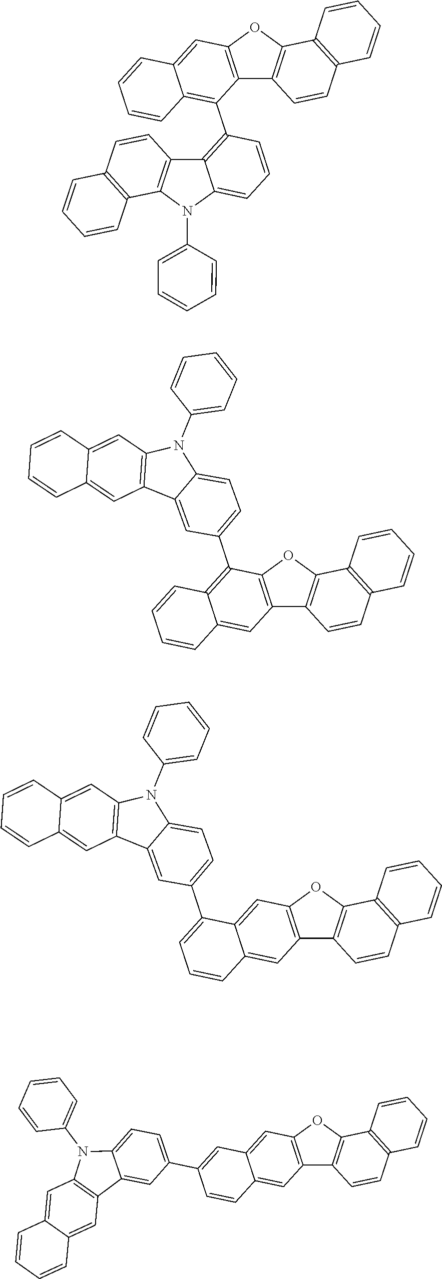 [SMILES: c1ccc(-n2c3cccc(-c4c5ccccc5cc5oc6c7ccccc7ccc6c45)c3c3ccc4ccccc4c32)cc1 ; c1ccc(-n2c3ccc(-c4c5ccccc5cc5c4oc4c6ccccc6ccc54)cc3c3cc4ccccc4cc32)cc1 ; c1ccc(-n2c3ccc(-c4cccc5cc6c(cc45)oc4c5ccccc5ccc64)cc3c3cc4ccccc4cc32)cc1 ; c1ccc(-n2c3ccc(-c4ccc5cc6c(cc5c4)oc4c5ccccc5ccc64)cc3c3cc4ccccc4cc32)cc1]

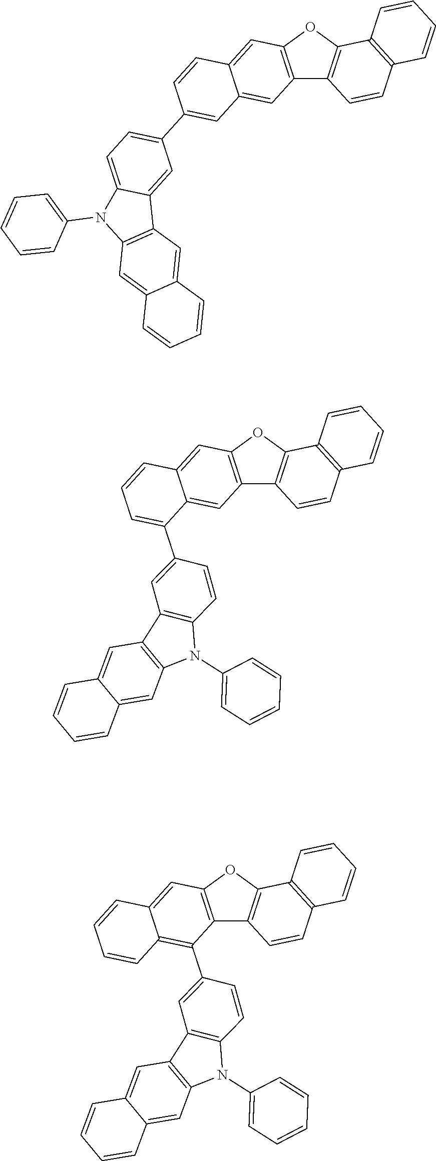 [SMILES: c1ccc(-n2c3ccc(-c4ccc5cc6oc7c8ccccc8ccc7c6cc5c4)cc3c3cc4ccccc4cc32)cc1 ; c1ccc(-n2c3ccc(-c4cccc5cc6oc7c8ccccc8ccc7c6cc45)cc3c3cc4ccccc4cc32)cc1 ; c1ccc(-n2c3ccc(-c4c5ccccc5cc5oc6c7ccccc7ccc6c45)cc3c3cc4ccccc4cc32)cc1]

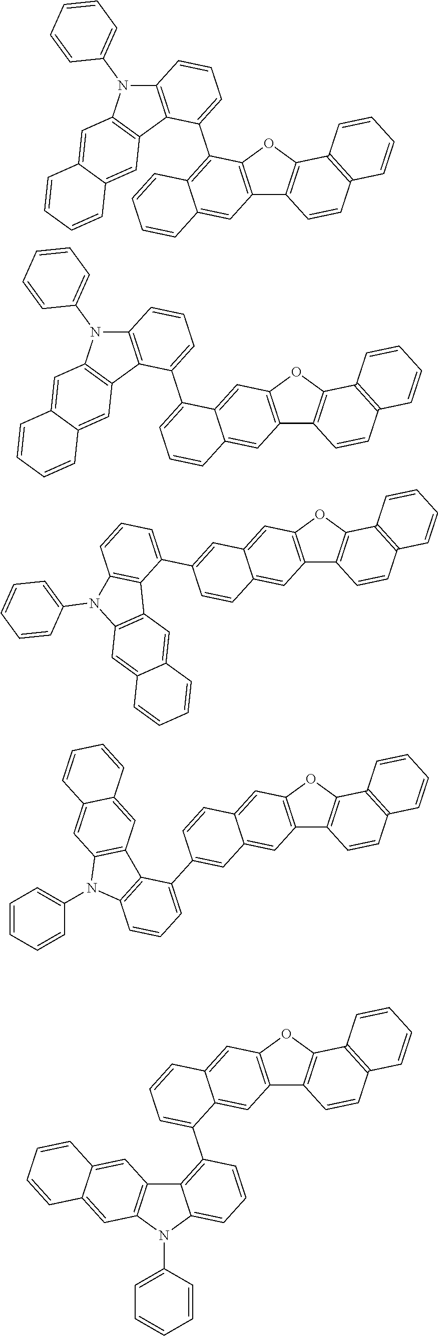

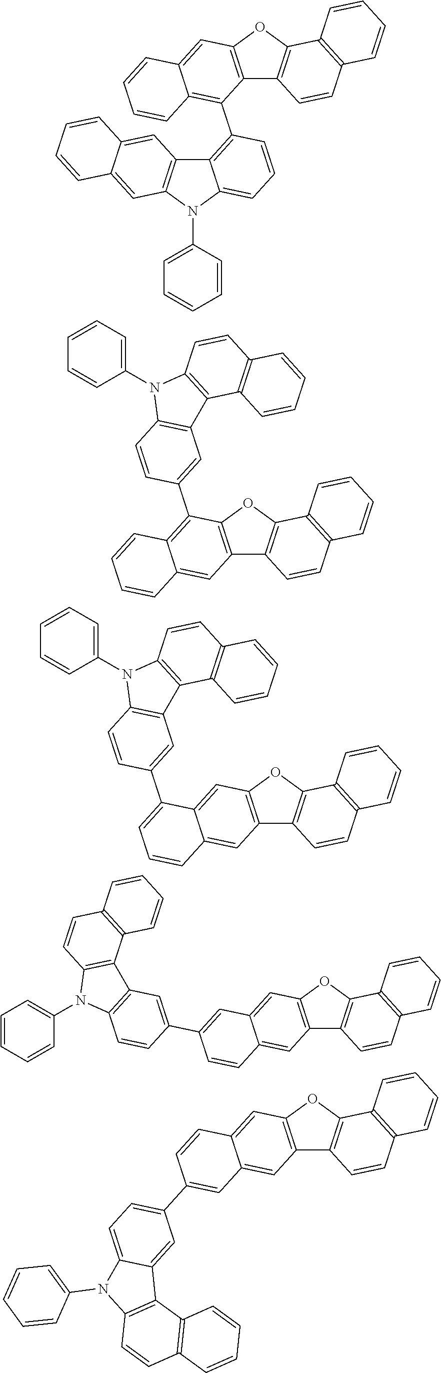

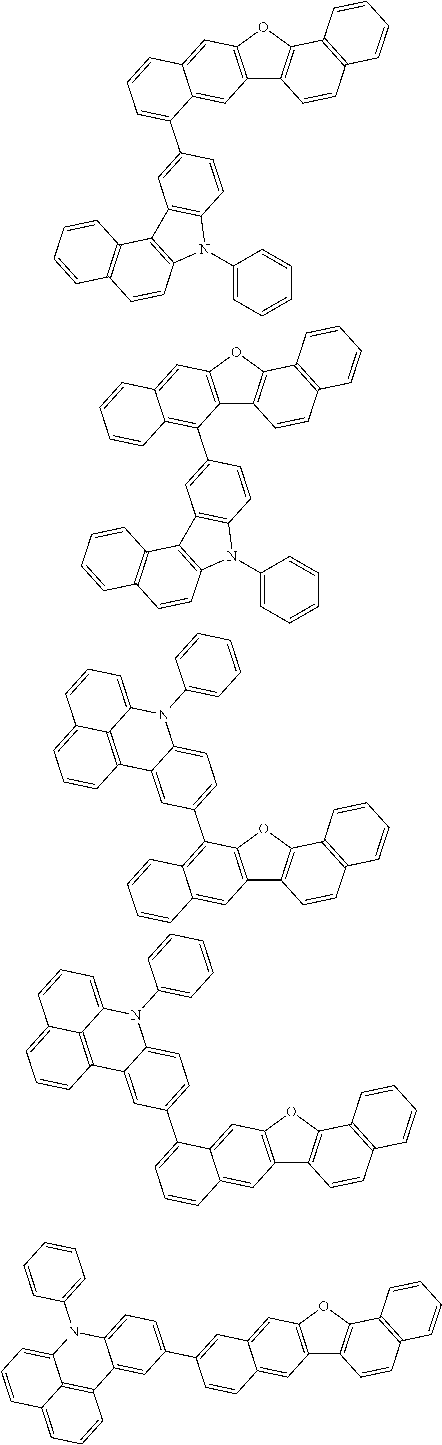

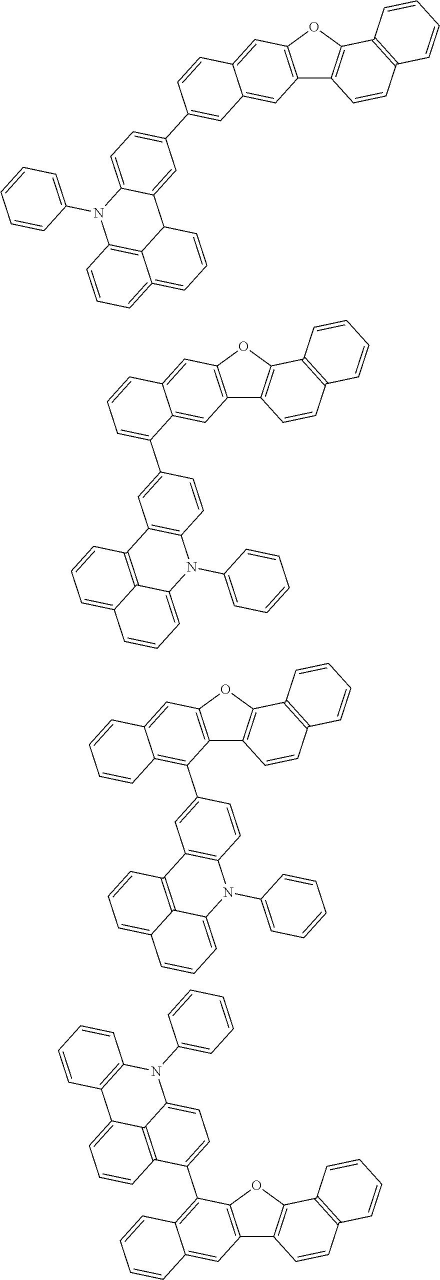

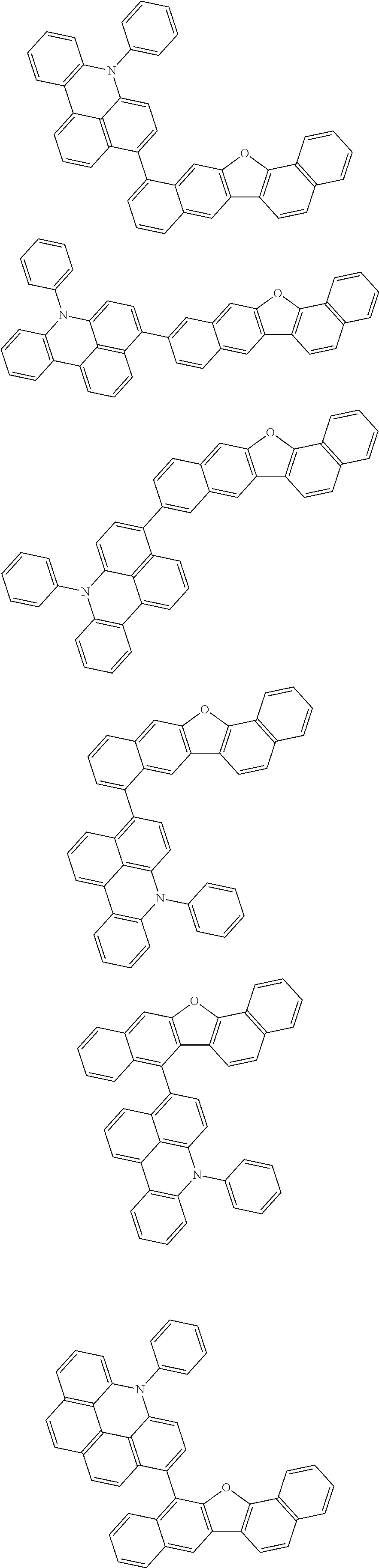 [SMILES: c1ccc(N2c3ccccc3-c3cccc4c(-c5cccc6cc7c(cc56)oc5c6ccccc6ccc75)ccc2c34)cc1 ; c1ccc(N2c3ccccc3-c3cccc4c(-c5ccc6cc7c(cc6c5)oc5c6ccccc6ccc75)ccc2c34)cc1 ; c1ccc(N2c3ccccc3-c3cccc4c(-c5ccc6cc7oc8c9ccccc9ccc8c7cc6c5)ccc2c34)cc1 ; c1ccc(N2c3ccccc3-c3cccc4c(-c5cccc6cc7oc8c9ccccc9ccc8c7cc56)ccc2c34)cc1 ; c1ccc(N2c3ccccc3-c3cccc4c(-c5c6ccccc6cc6oc7c8ccccc8ccc7c56)ccc2c34)cc1 ; c1ccc(N2c3cccc4ccc5ccc6c(-c7c8ccccc8cc8c7oc7c9ccccc9ccc87)ccc2c6c5c34)cc1]

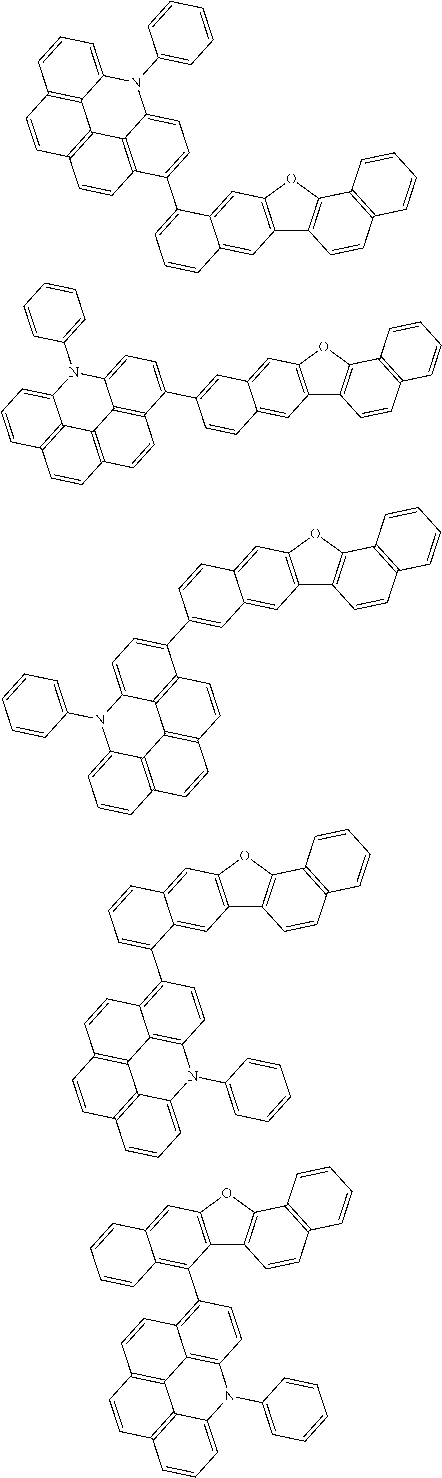 [SMILES: c1ccc(N2c3cccc4ccc5ccc6c(-c7cccc8cc9c(cc78)oc7c8ccccc8ccc97)ccc2c6c5c34)cc1 ; c1ccc(N2c3cccc4ccc5ccc6c(-c7ccc8cc9c(cc8c7)oc7c8ccccc8ccc97)ccc2c6c5c34)cc1 ; c1ccc(N2c3cccc4ccc5ccc6c(-c7ccc8cc9oc%10c%11ccccc%11ccc%10c9cc8c7)ccc2c6c5c34)cc1 ; c1ccc(N2c3cccc4ccc5ccc6c(-c7cccc8cc9oc%10c%11ccccc%11ccc%10c9cc78)ccc2c6c5c34)cc1 ; c1ccc(N2c3cccc4ccc5ccc6c(-c7c8ccccc8cc8oc9c%10ccccc%10ccc9c78)ccc2c6c5c34)cc1]

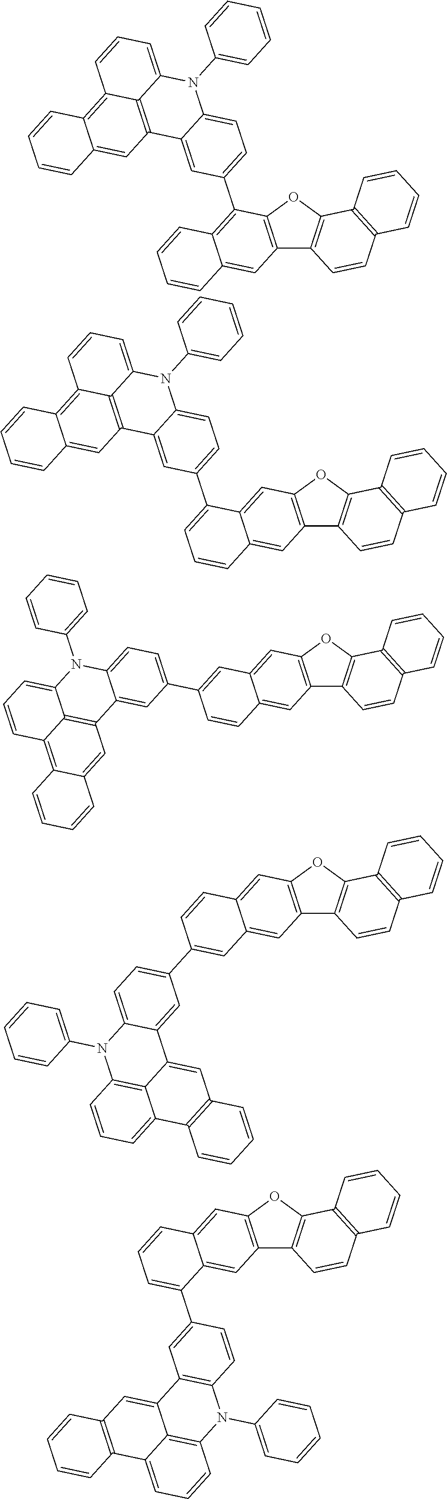

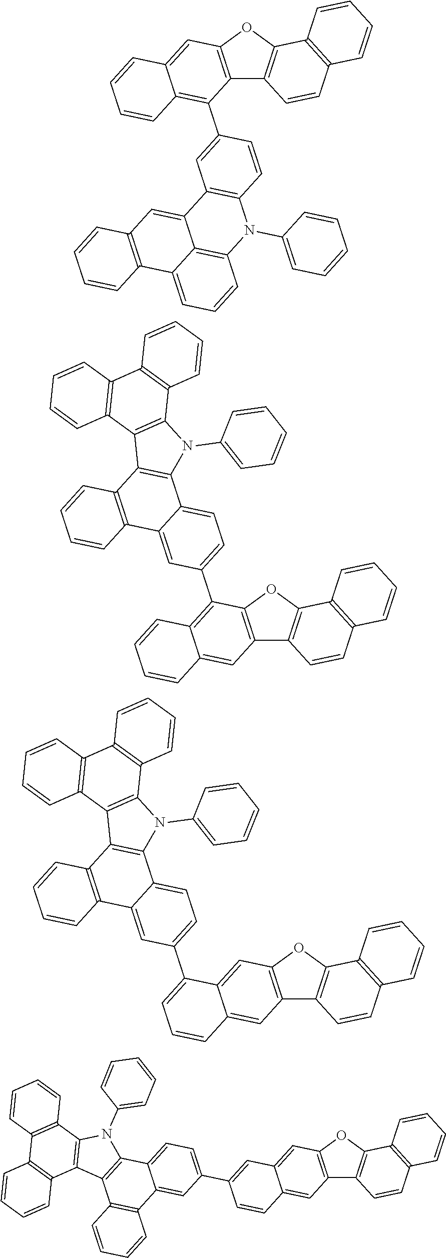

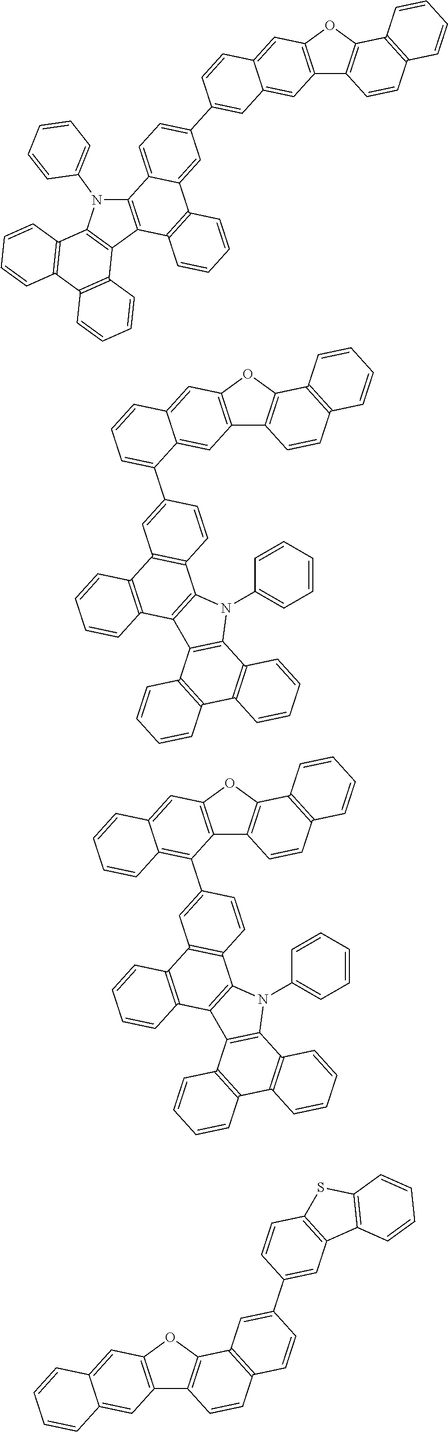 [SMILES: c1ccc(-n2c3c4ccccc4c4ccccc4c3c3c4ccccc4c4cc(-c5ccc6cc7oc8c9ccccc9ccc8c7cc6c5)ccc4c32)cc1 ; c1ccc(-n2c3c4ccccc4c4ccccc4c3c3c4ccccc4c4cc(-c5cccc6cc7oc8c9ccccc9ccc8c7cc56)ccc4c32)cc1 ; c1ccc(-n2c3c4ccccc4c4ccccc4c3c3c4ccccc4c4cc(-c5c6ccccc6cc6oc7c8ccccc8ccc7c56)ccc4c32)cc1 ; c1ccc2cc3c(cc2c1)oc1c2cc(-c4ccc5sc6ccccc6c5c4)ccc2ccc31]

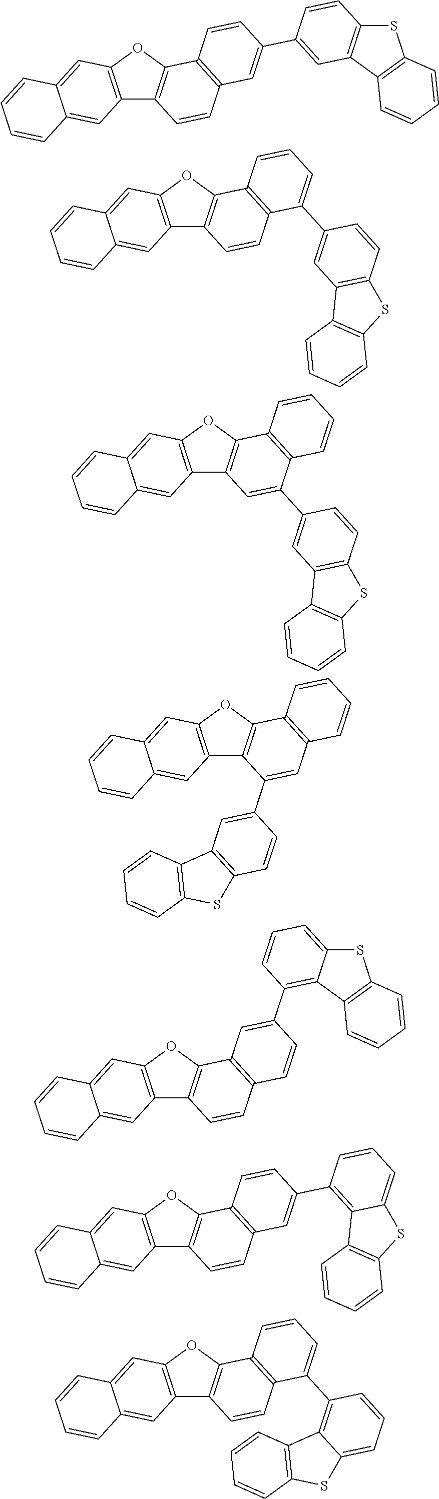

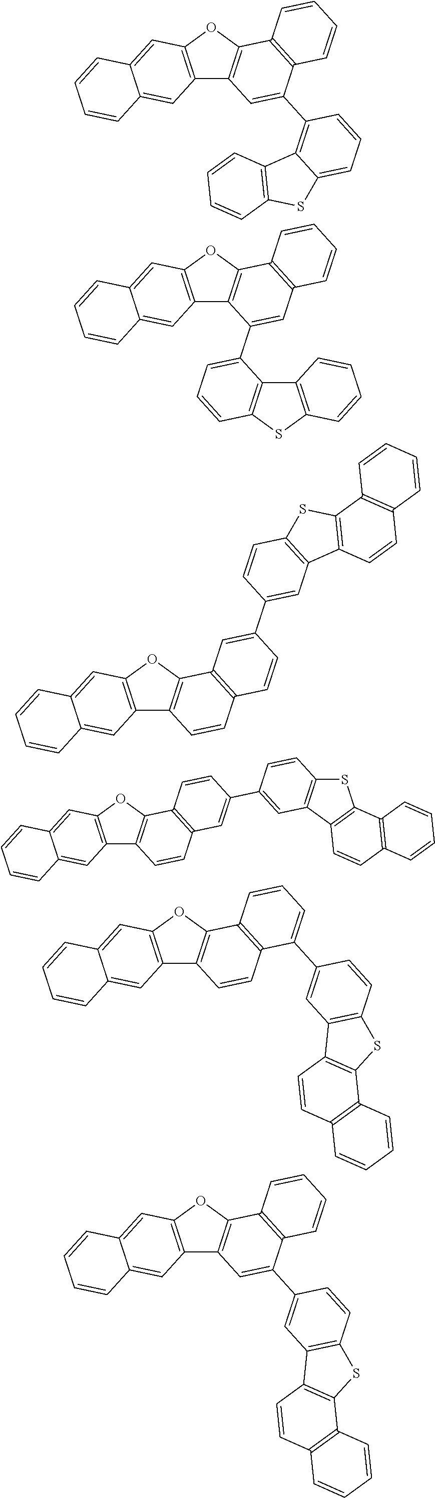

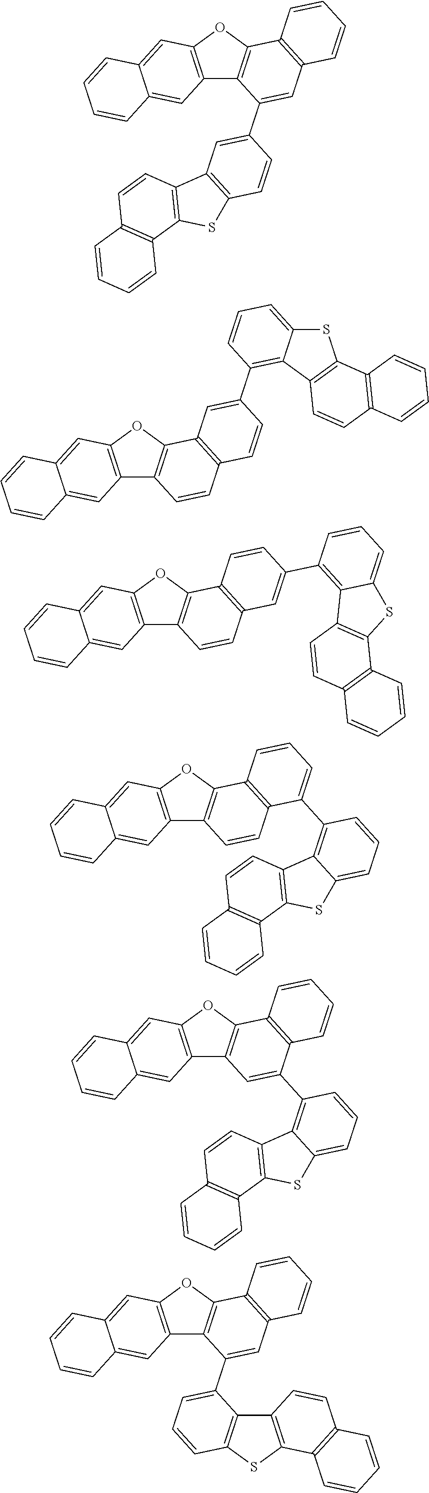

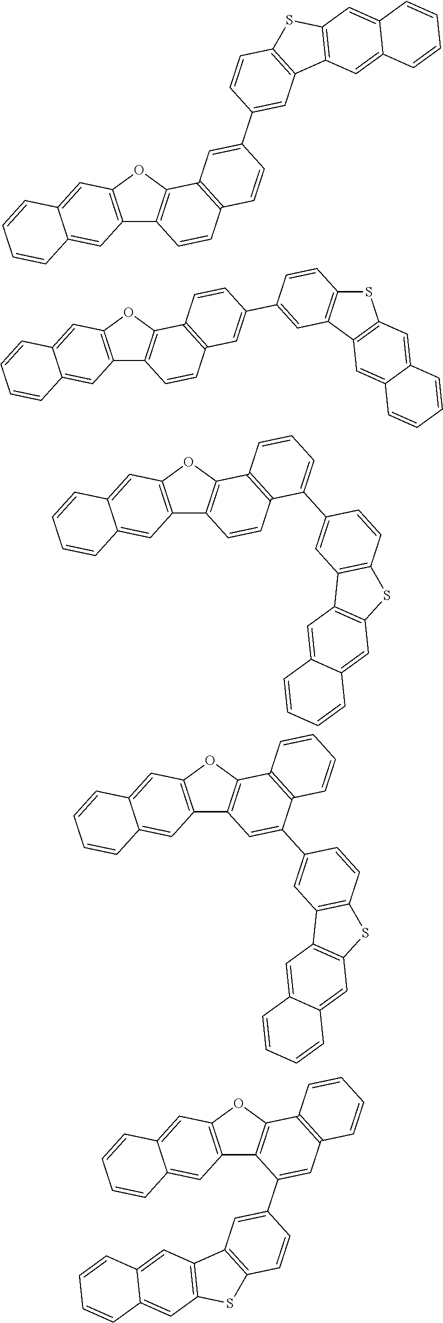

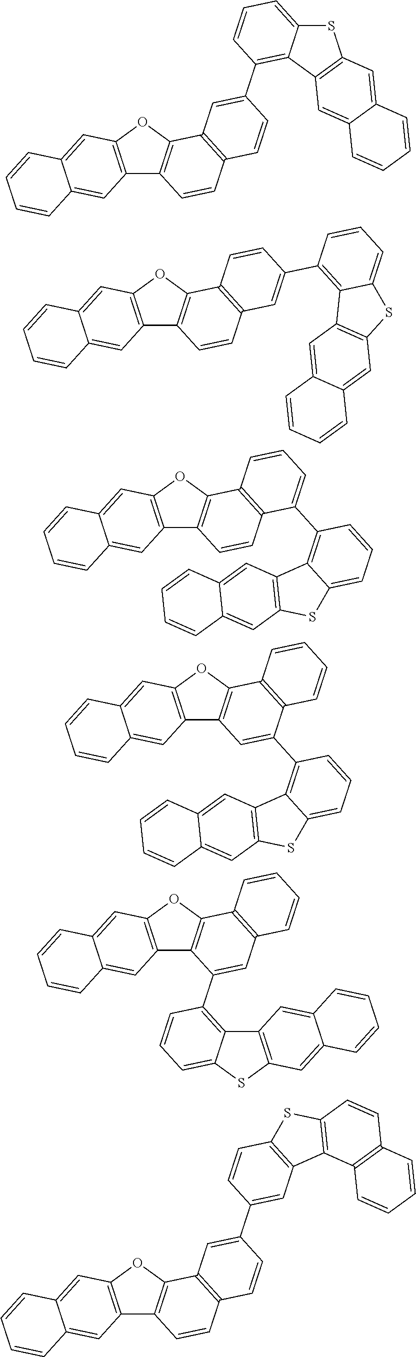

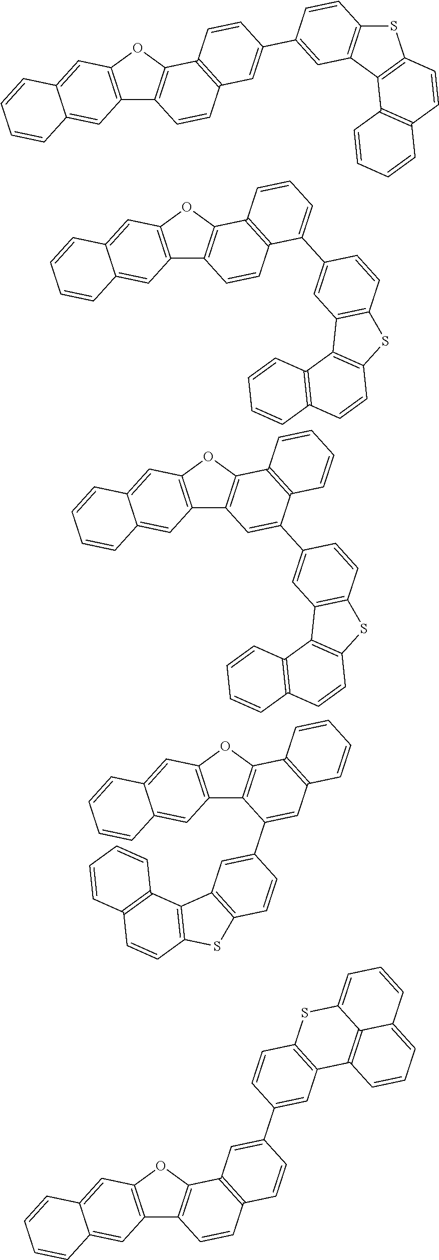

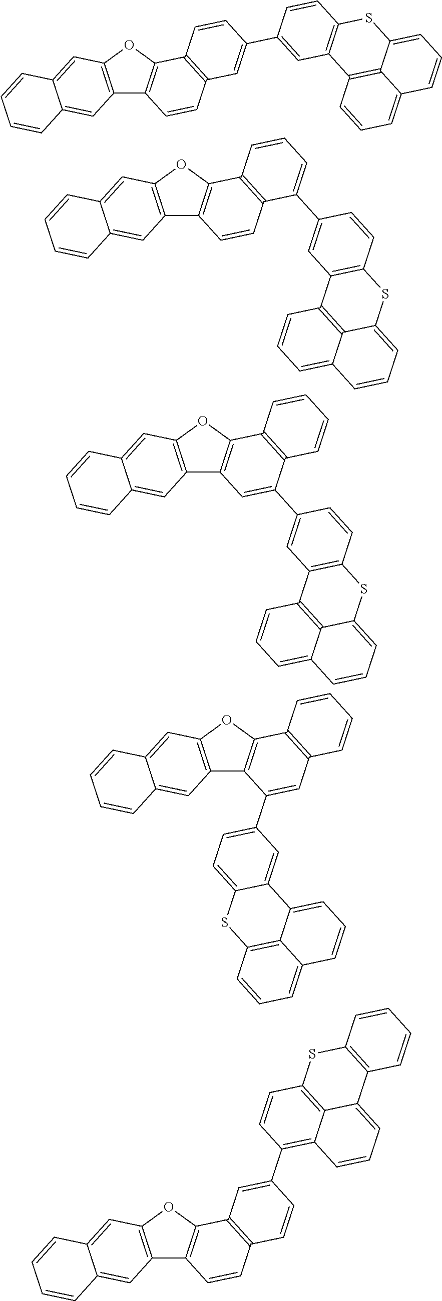

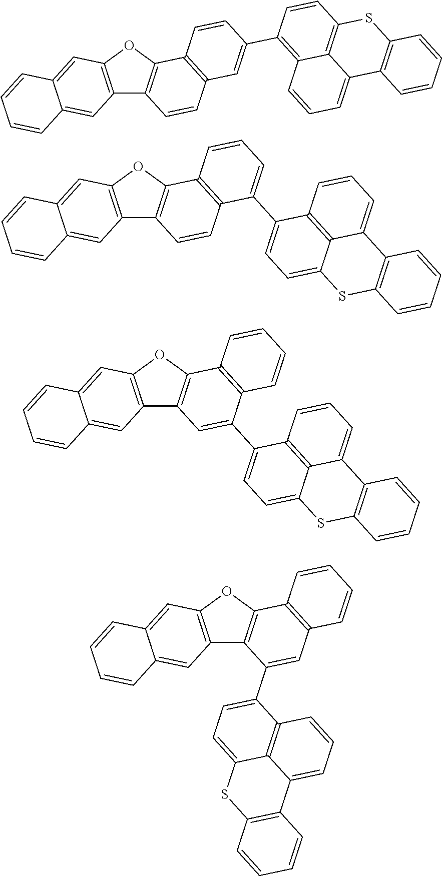

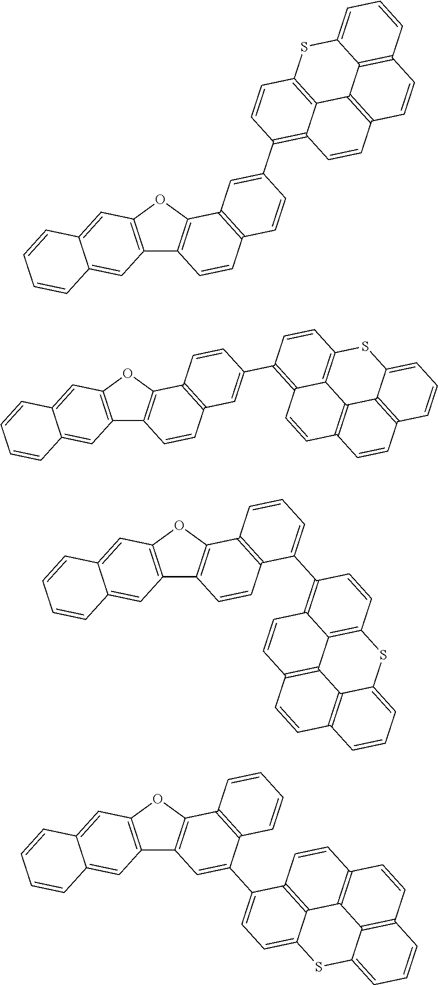 [SMILES: c1ccc2cc3c(cc2c1)oc1c2cc(-c4ccc5c6c4ccc4ccc7cccc(c7c46)S5)ccc2ccc31 ; c1ccc2cc3c(cc2c1)oc1c2ccc(-c4ccc5c6c4ccc4ccc7cccc(c7c46)S5)cc2ccc31 ; c1ccc2cc3c(cc2c1)oc1c2cccc(-c4ccc5c6c4ccc4ccc7cccc(c7c46)S5)c2ccc31 ; c1ccc2cc3c(cc2c1)oc1c2ccccc2c(-c2ccc4c5c2ccc2ccc6cccc(c6c25)S4)cc31]

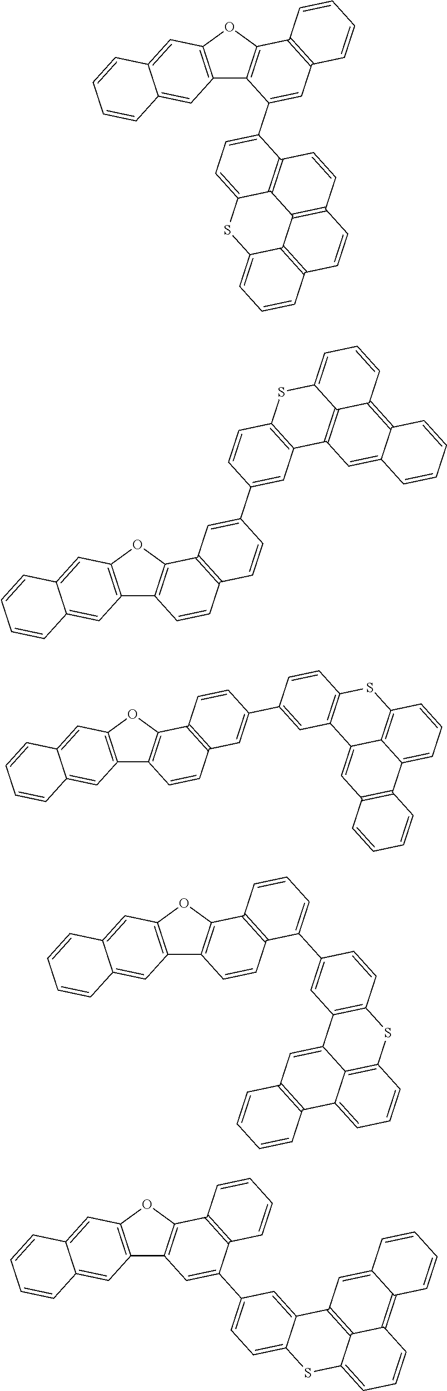

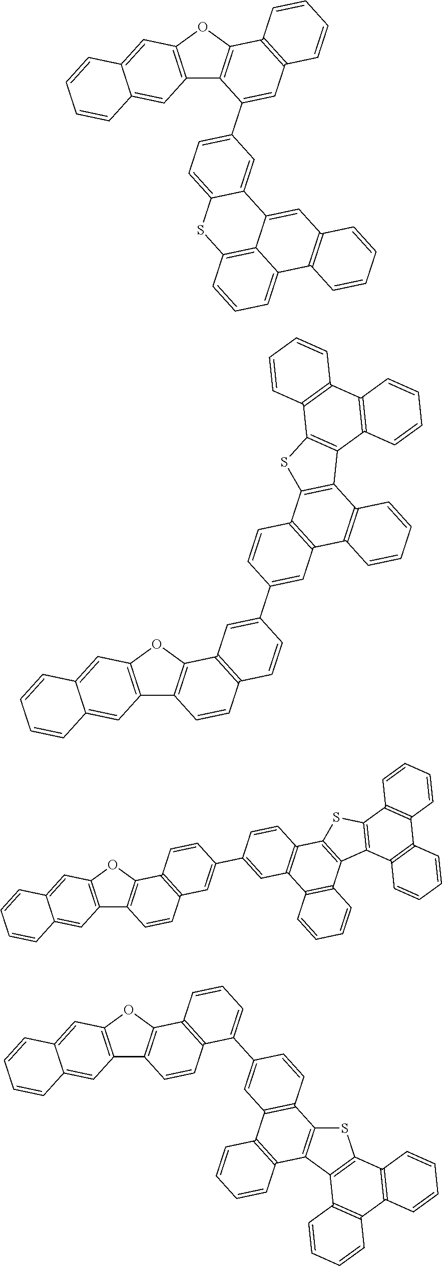 [SMILES: c1ccc2cc3c(cc2c1)oc1c2ccccc2cc(-c2ccc4c(c2)-c2cc5ccccc5c5cccc(c25)S4)c31 ; c1ccc2cc3c(cc2c1)oc1c2cc(-c4ccc5c(c4)c4ccccc4c4c5sc5c6ccccc6c6ccccc6c54)ccc2ccc31 ; c1ccc2cc3c(cc2c1)oc1c2ccc(-c4ccc5c(c4)c4ccccc4c4c5sc5c6ccccc6c6ccccc6c54)cc2ccc31 ; c1ccc2cc3c(cc2c1)oc1c2cccc(-c4ccc5c(c4)c4ccccc4c4c5sc5c6ccccc6c6ccccc6c54)c2ccc31]

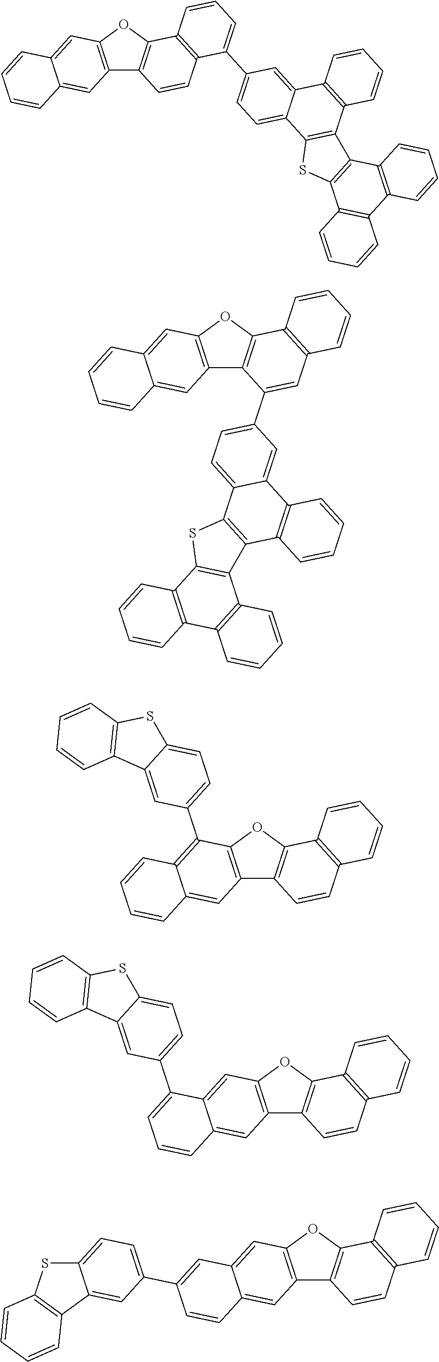

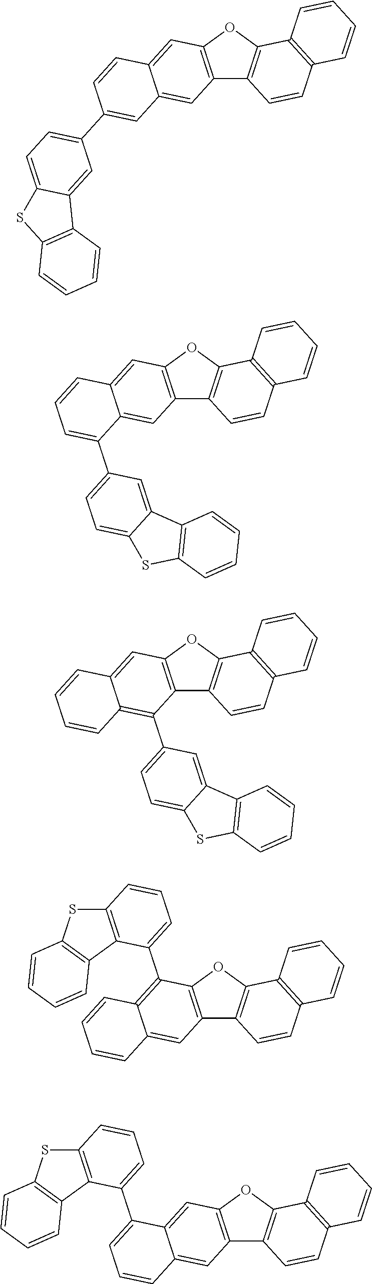 [SMILES: c1ccc2c(c1)ccc1c3cc4cc(-c5ccc6sc7ccccc7c6c5)ccc4cc3oc21 ; c1cc(-c2ccc3sc4ccccc4c3c2)c2cc3c(cc2c1)oc1c2ccccc2ccc31 ; c1ccc2c(-c3ccc4sc5ccccc5c4c3)c3c(cc2c1)oc1c2ccccc2ccc13 ; c1ccc2c(-c3cccc4sc5ccccc5c34)c3oc4c5ccccc5ccc4c3cc2c1 ; c1cc(-c2cccc3sc4ccccc4c23)c2cc3oc4c5ccccc5ccc4c3cc2c1]

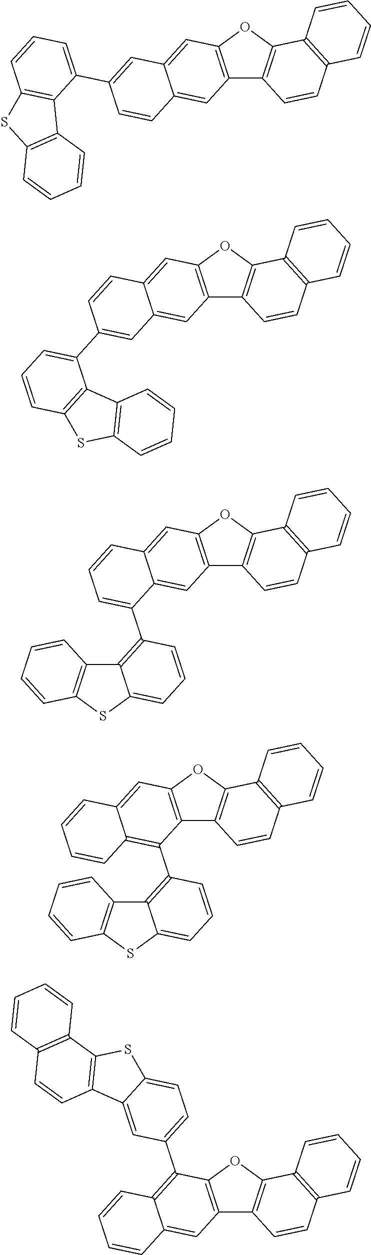 [SMILES: c1ccc2c(c1)ccc1c3cc4ccc(-c5cccc6sc7ccccc7c56)cc4cc3oc21 ; c1ccc2c(c1)ccc1c3cc4cc(-c5cccc6sc7ccccc7c56)ccc4cc3oc21 ; c1cc(-c2cccc3sc4ccccc4c23)c2cc3c(cc2c1)oc1c2ccccc2ccc31 ; c1ccc2c(-c3cccc4sc5ccccc5c34)c3c(cc2c1)oc1c2ccccc2ccc13 ; c1ccc2c(-c3ccc4sc5c6ccccc6ccc5c4c3)c3oc4c5ccccc5ccc4c3cc2c1]

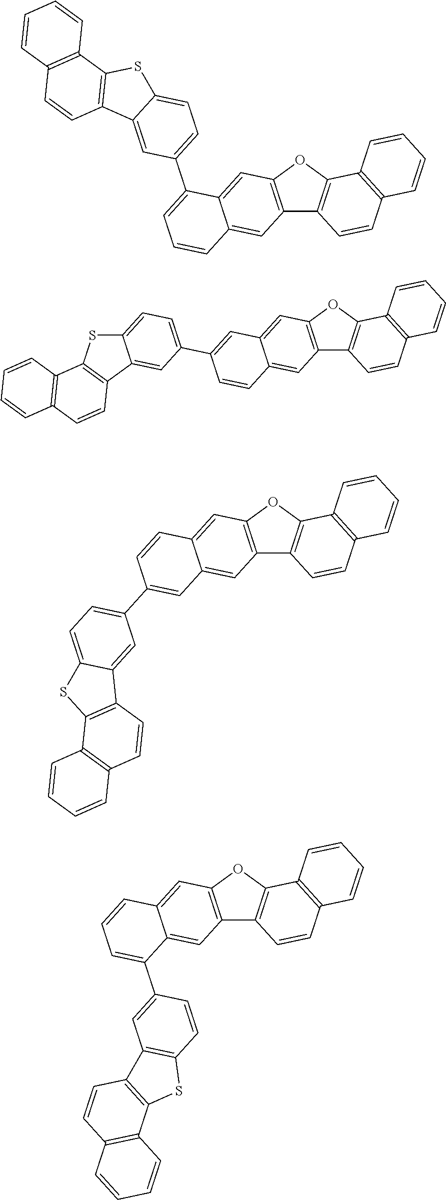 [SMILES: c1cc(-c2ccc3sc4c5ccccc5ccc4c3c2)c2cc3oc4c5ccccc5ccc4c3cc2c1 ; c1ccc2c(c1)ccc1c3cc4ccc(-c5ccc6sc7c8ccccc8ccc7c6c5)cc4cc3oc21 ; c1ccc2c(c1)ccc1c3cc4cc(-c5ccc6sc7c8ccccc8ccc7c6c5)ccc4cc3oc21 ; c1cc(-c2ccc3sc4c5ccccc5ccc4c3c2)c2cc3c(cc2c1)oc1c2ccccc2ccc31]

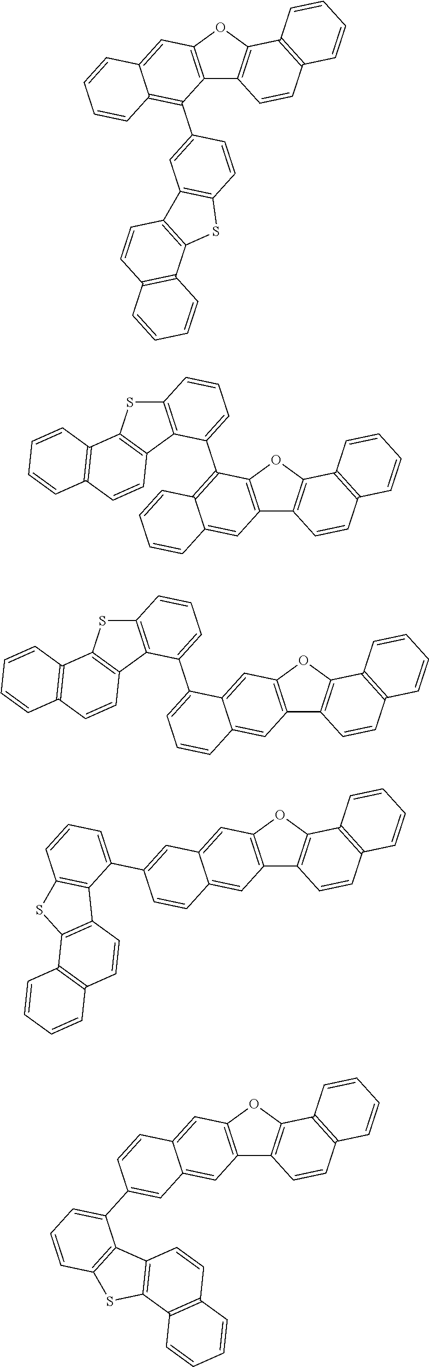

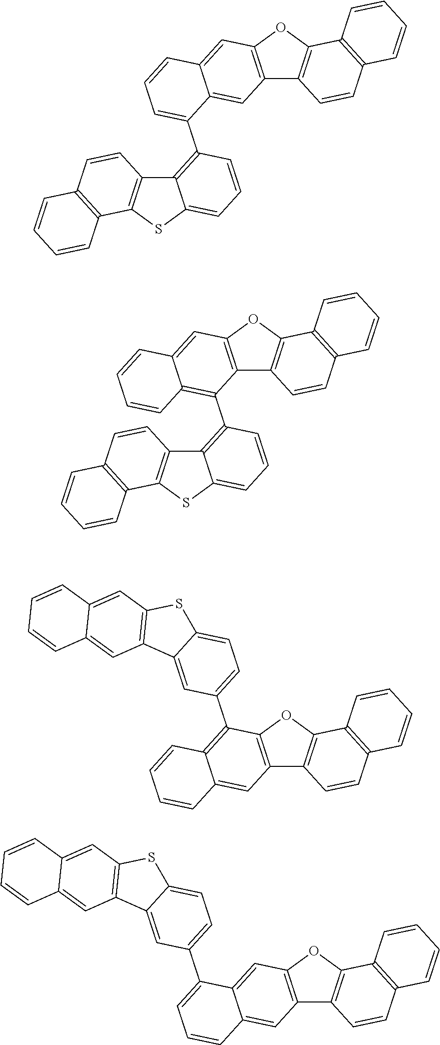 [SMILES: c1cc(-c2cccc3sc4c5ccccc5ccc4c23)c2cc3c(cc2c1)oc1c2ccccc2ccc31 ; c1ccc2c(-c3cccc4sc5c6ccccc6ccc5c34)c3c(cc2c1)oc1c2ccccc2ccc13 ; c1ccc2cc3c(cc2c1)sc1ccc(-c2c4ccccc4cc4c2oc2c5ccccc5ccc42)cc13 ; c1ccc2cc3c(cc2c1)sc1ccc(-c2cccc4cc5c(cc24)oc2c4ccccc4ccc52)cc13]

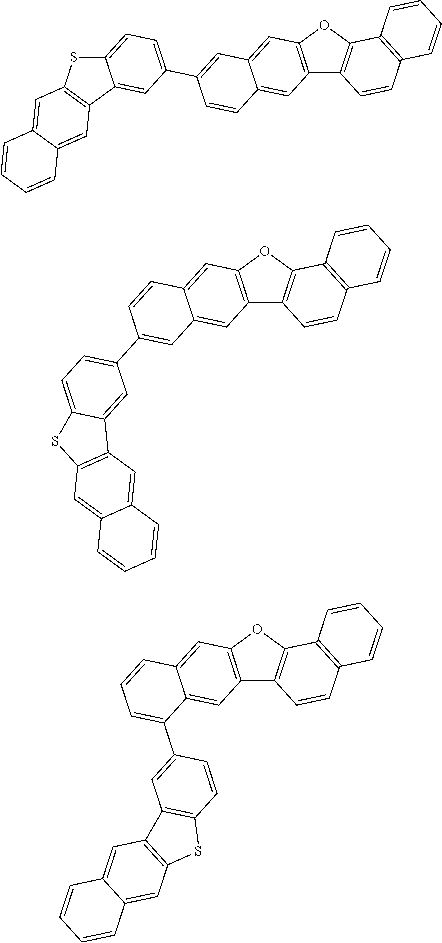 [SMILES: c1ccc2cc3c(cc2c1)sc1ccc(-c2ccc4cc5c(cc4c2)oc2c4ccccc4ccc52)cc13 ; c1ccc2cc3c(cc2c1)sc1ccc(-c2ccc4cc5oc6c7ccccc7ccc6c5cc4c2)cc13 ; c1ccc2cc3c(cc2c1)sc1ccc(-c2cccc4cc5oc6c7ccccc7ccc6c5cc24)cc13]

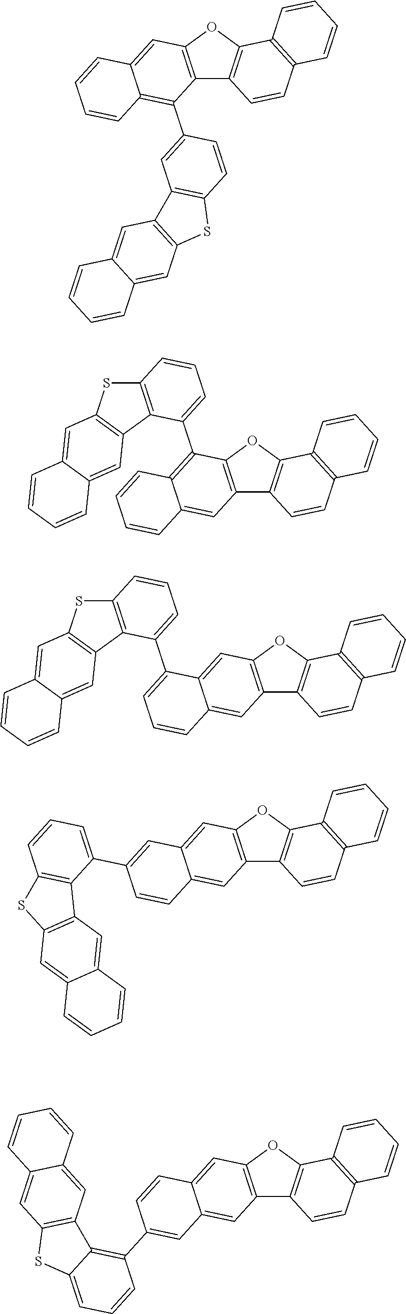 [SMILES: c1ccc2cc3c(cc2c1)sc1ccc(-c2c4ccccc4cc4oc5c6ccccc6ccc5c24)cc13 ; c1ccc2cc3c(cc2c1)sc1cccc(-c2c4ccccc4cc4c2oc2c5ccccc5ccc42)c13 ; c1ccc2cc3c(cc2c1)sc1cccc(-c2cccc4cc5c(cc24)oc2c4ccccc4ccc52)c13 ; c1ccc2cc3c(cc2c1)sc1cccc(-c2ccc4cc5c(cc4c2)oc2c4ccccc4ccc52)c13 ; c1ccc2cc3c(cc2c1)sc1cccc(-c2ccc4cc5oc6c7ccccc7ccc6c5cc4c2)c13]

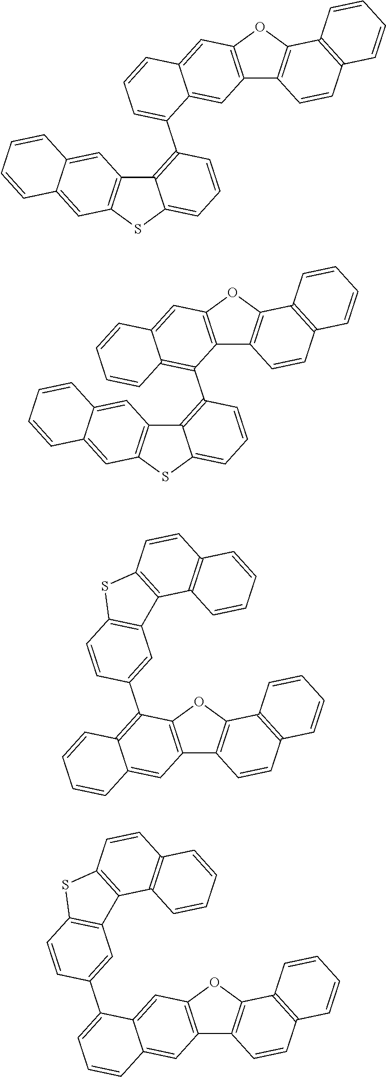

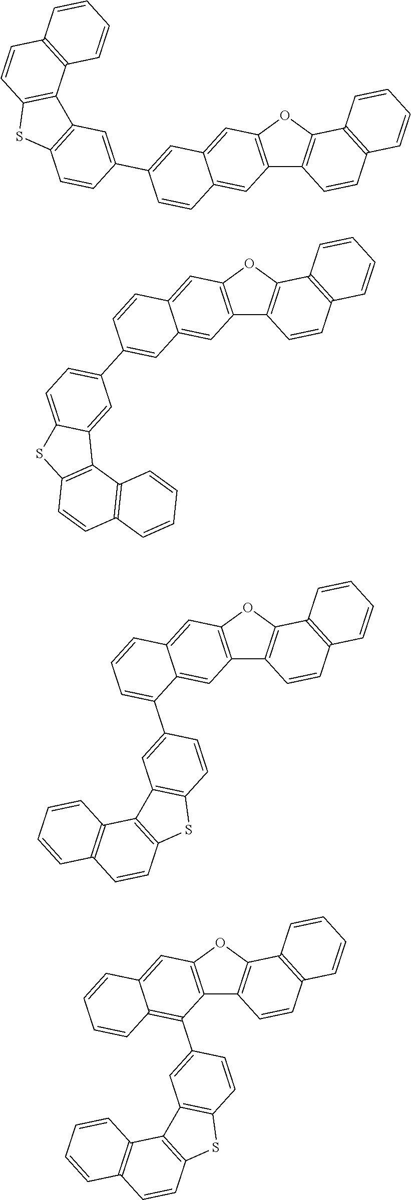 [SMILES: c1ccc2c(c1)ccc1c3cc4ccc(-c5ccc6sc7ccc8ccccc8c7c6c5)cc4cc3oc21 ; c1ccc2c(c1)ccc1c3cc4cc(-c5ccc6sc7ccc8ccccc8c7c6c5)ccc4cc3oc21 ; c1cc(-c2ccc3sc4ccc5ccccc5c4c3c2)c2cc3c(cc2c1)oc1c2ccccc2ccc31 ; c1ccc2c(-c3ccc4sc5ccc6ccccc6c5c4c3)c3c(cc2c1)oc1c2ccccc2ccc13]

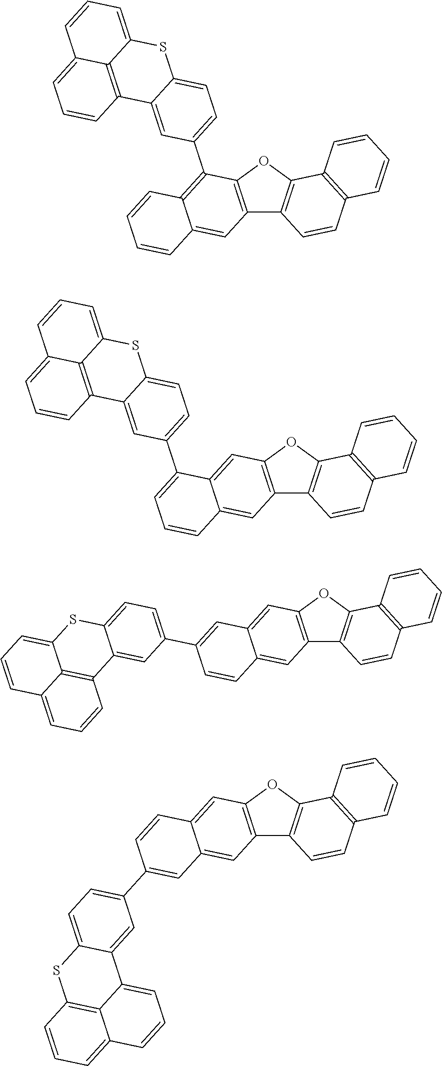 [SMILES: c1ccc2c(-c3ccc4c(c3)-c3cccc5cccc(c35)S4)c3oc4c5ccccc5ccc4c3cc2c1 ; c1cc(-c2ccc3c(c2)-c2cccc4cccc(c24)S3)c2cc3oc4c5ccccc5ccc4c3cc2c1 ; c1cc2c3c(cccc3c1)-c1cc(-c3ccc4cc5c(cc4c3)oc3c4ccccc4ccc53)ccc1S2 ; c1cc2c3c(cccc3c1)-c1cc(-c3ccc4cc5oc6c7ccccc7ccc6c5cc4c3)ccc1S2]

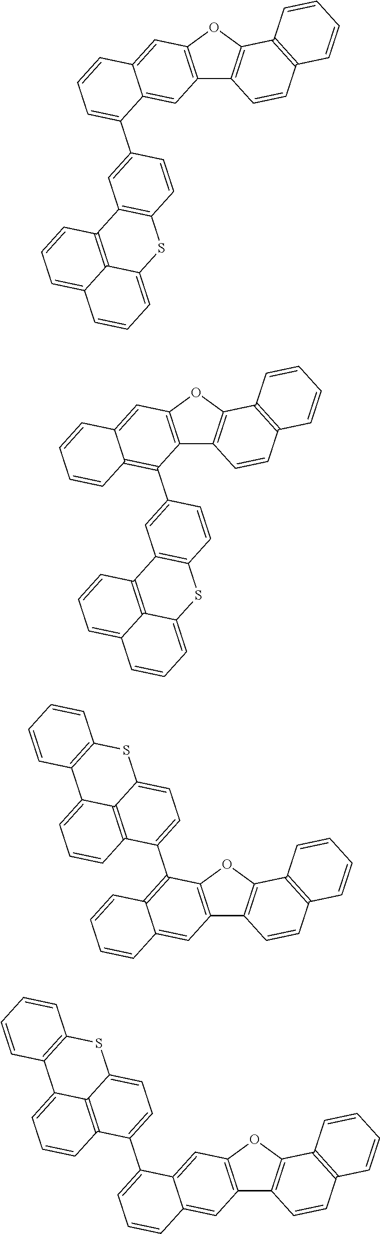 [SMILES: c1cc(-c2ccc3c(c2)-c2cccc4cccc(c24)S3)c2cc3c(cc2c1)oc1c2ccccc2ccc31 ; c1ccc2c(-c3ccc4c(c3)-c3cccc5cccc(c35)S4)c3c(cc2c1)oc1c2ccccc2ccc13 ; c1ccc2c(c1)Sc1ccc(-c3c4ccccc4cc4c3oc3c5ccccc5ccc43)c3cccc-2c13 ; c1ccc2c(c1)Sc1ccc(-c3cccc4cc5c(cc34)oc3c4ccccc4ccc53)c3cccc-2c13]

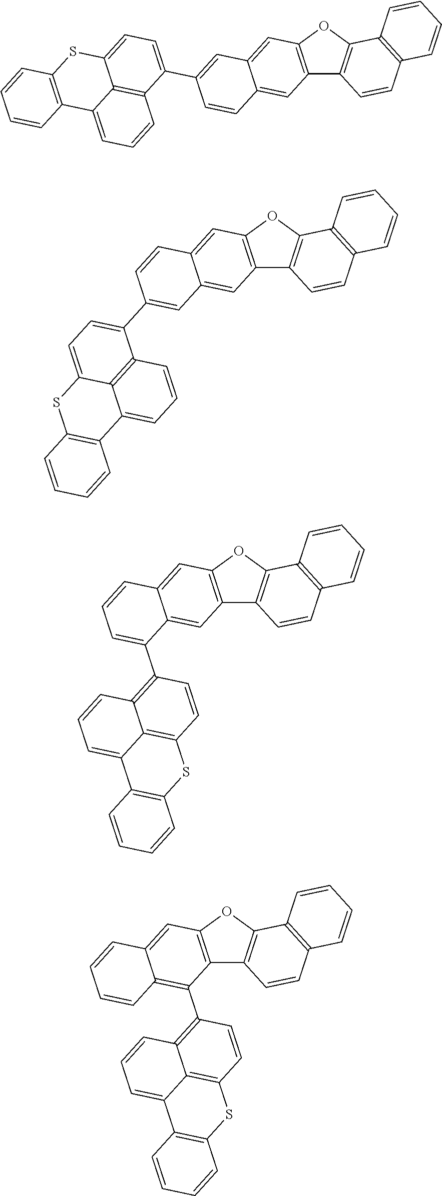 [SMILES: c1ccc2c(c1)Sc1ccc(-c3ccc4cc5c(cc4c3)oc3c4ccccc4ccc53)c3cccc-2c13 ; c1ccc2c(c1)Sc1ccc(-c3ccc4cc5oc6c7ccccc7ccc6c5cc4c3)c3cccc-2c13 ; c1ccc2c(c1)Sc1ccc(-c3cccc4cc5oc6c7ccccc7ccc6c5cc34)c3cccc-2c13 ; c1ccc2c(c1)Sc1ccc(-c3c4ccccc4cc4oc5c6ccccc6ccc5c34)c3cccc-2c13]

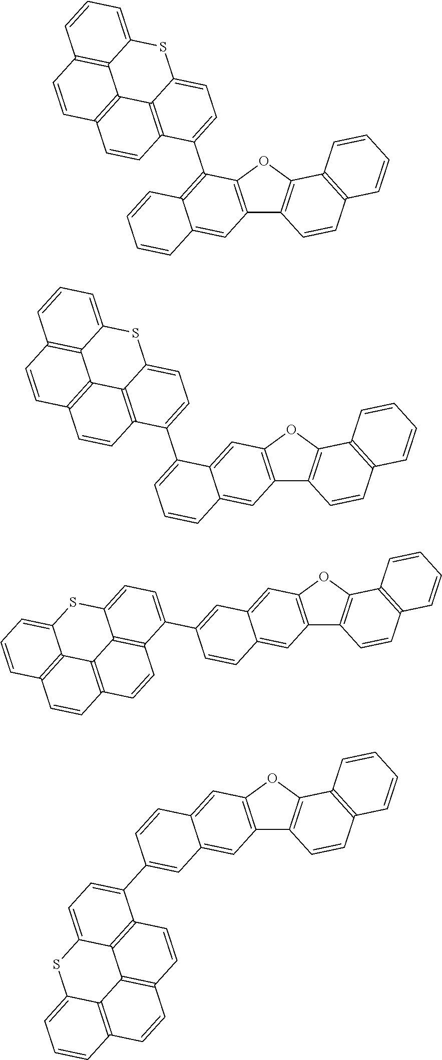 [SMILES: c1ccc2c(-c3ccc4c5c3ccc3ccc6cccc(c6c35)S4)c3oc4c5ccccc5ccc4c3cc2c1 ; c1cc(-c2ccc3c4c2ccc2ccc5cccc(c5c24)S3)c2cc3oc4c5ccccc5ccc4c3cc2c1 ; c1ccc2c(c1)ccc1c3cc4ccc(-c5ccc6c7c5ccc5ccc8cccc(c8c57)S6)cc4cc3oc21 ; c1ccc2c(c1)ccc1c3cc4cc(-c5ccc6c7c5ccc5ccc8cccc(c8c57)S6)ccc4cc3oc21]

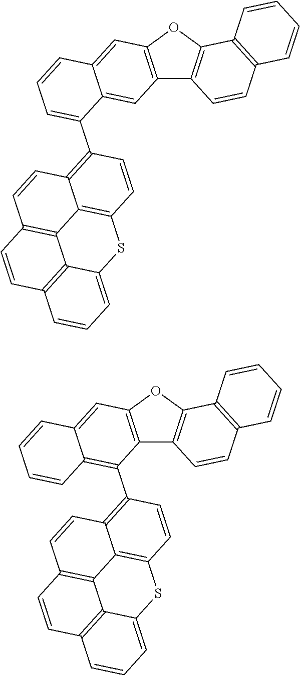 [SMILES: c1cc(-c2ccc3c4c2ccc2ccc5cccc(c5c24)S3)c2cc3c(cc2c1)oc1c2ccccc2ccc31 ; c1ccc2c(-c3ccc4c5c3ccc3ccc6cccc(c6c35)S4)c3c(cc2c1)oc1c2ccccc2ccc13]

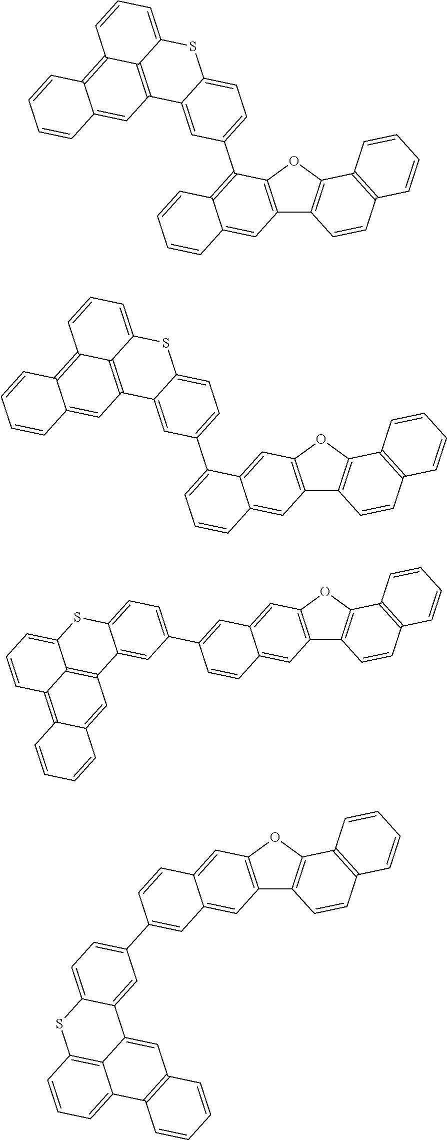 [SMILES: c1ccc2c(-c3ccc4c(c3)-c3cc5ccccc5c5cccc(c35)S4)c3oc4c5ccccc5ccc4c3cc2c1 ; c1cc(-c2ccc3c(c2)-c2cc4ccccc4c4cccc(c24)S3)c2cc3oc4c5ccccc5ccc4c3cc2c1 ; c1ccc2c(c1)cc1c3c(cccc32)Sc2ccc(-c3ccc4cc5c(cc4c3)oc3c4ccccc4ccc53)cc2-1 ; c1ccc2c(c1)cc1c3c(cccc32)Sc2ccc(-c3ccc4cc5oc6c7ccccc7ccc6c5cc4c3)cc2-1]

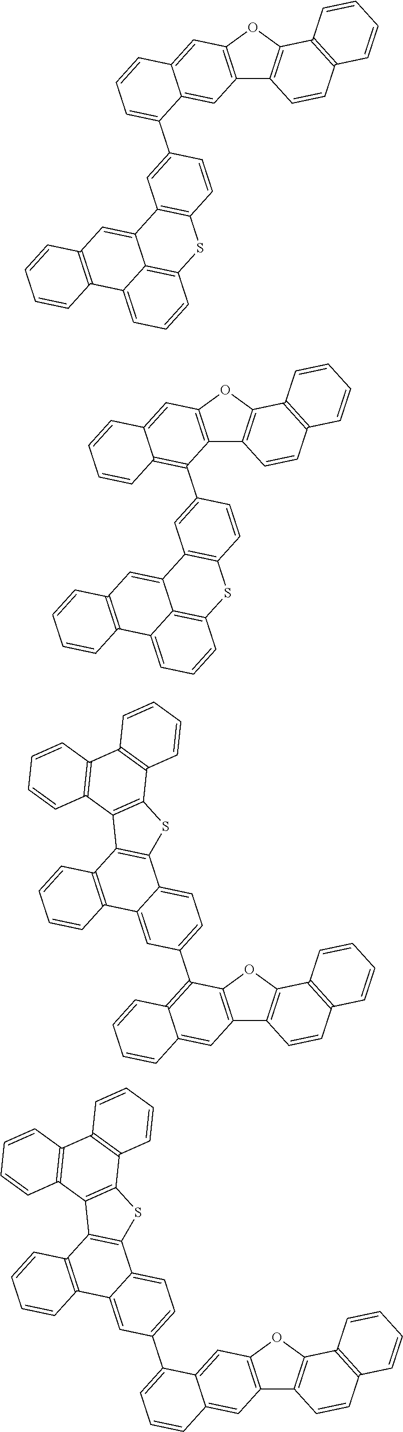

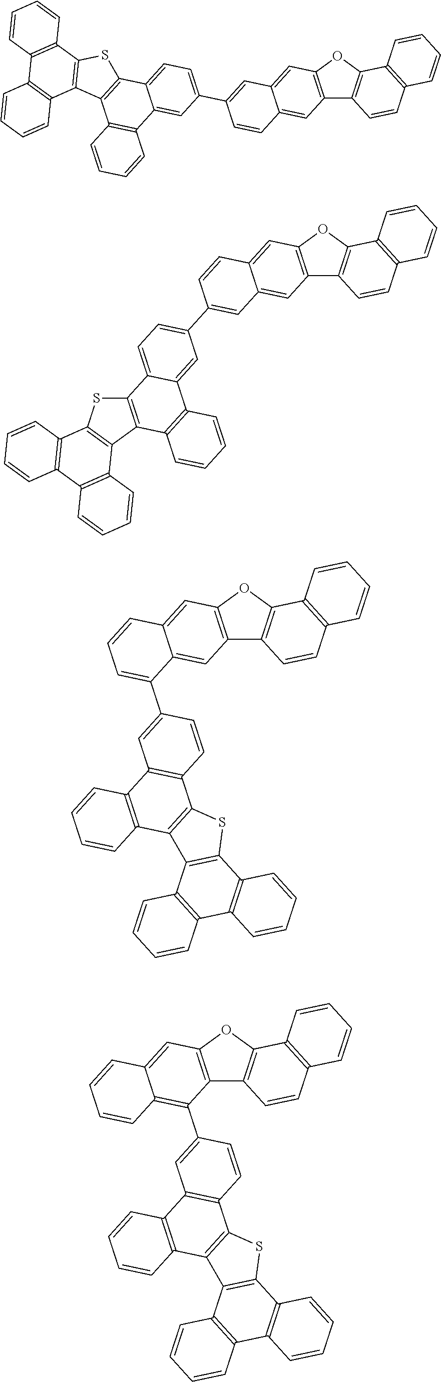 [SMILES: c1ccc2c(c1)ccc1c3cc4ccc(-c5ccc6c(c5)c5ccccc5c5c6sc6c7ccccc7c7ccccc7c65)cc4cc3oc21 ; c1ccc2c(c1)ccc1c3cc4cc(-c5ccc6c(c5)c5ccccc5c5c6sc6c7ccccc7c7ccccc7c65)ccc4cc3oc21 ; c1cc(-c2ccc3c(c2)c2ccccc2c2c3sc3c4ccccc4c4ccccc4c32)c2cc3c(cc2c1)oc1c2ccccc2ccc31 ; c1ccc2c(-c3ccc4c(c3)c3ccccc3c3c4sc4c5ccccc5c5ccccc5c43)c3c(cc2c1)oc1c2ccccc2ccc13]

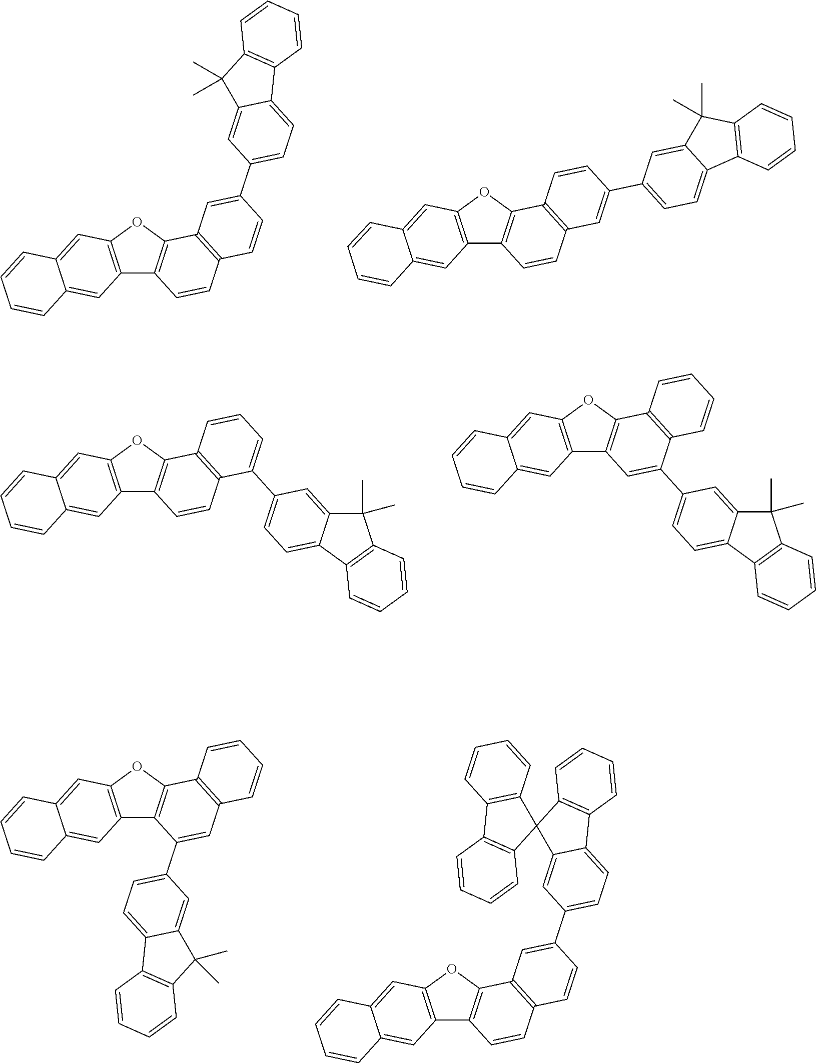 [SMILES: CC1(C)c2ccccc2-c2ccc(-c3ccc4ccc5c6cc7ccccc7cc6oc5c4c3)cc21 ; CC1(C)c2ccccc2-c2ccc(-c3ccc4c(ccc5c6cc7ccccc7cc6oc45)c3)cc21 ; CC1(C)c2ccccc2-c2ccc(-c3cccc4c3ccc3c5cc6ccccc6cc5oc43)cc21 ; CC1(C)c2ccccc2-c2ccc(-c3cc4c5cc6ccccc6cc5oc4c4ccccc34)cc21 ; CC1(C)c2ccccc2-c2ccc(-c3cc4ccccc4c4oc5cc6ccccc6cc5c34)cc21 ; c1ccc2c(c1)-c1ccccc1C21c2ccccc2-c2ccc(-c3ccc4ccc5c6cc7ccccc7cc6oc5c4c3)cc21]

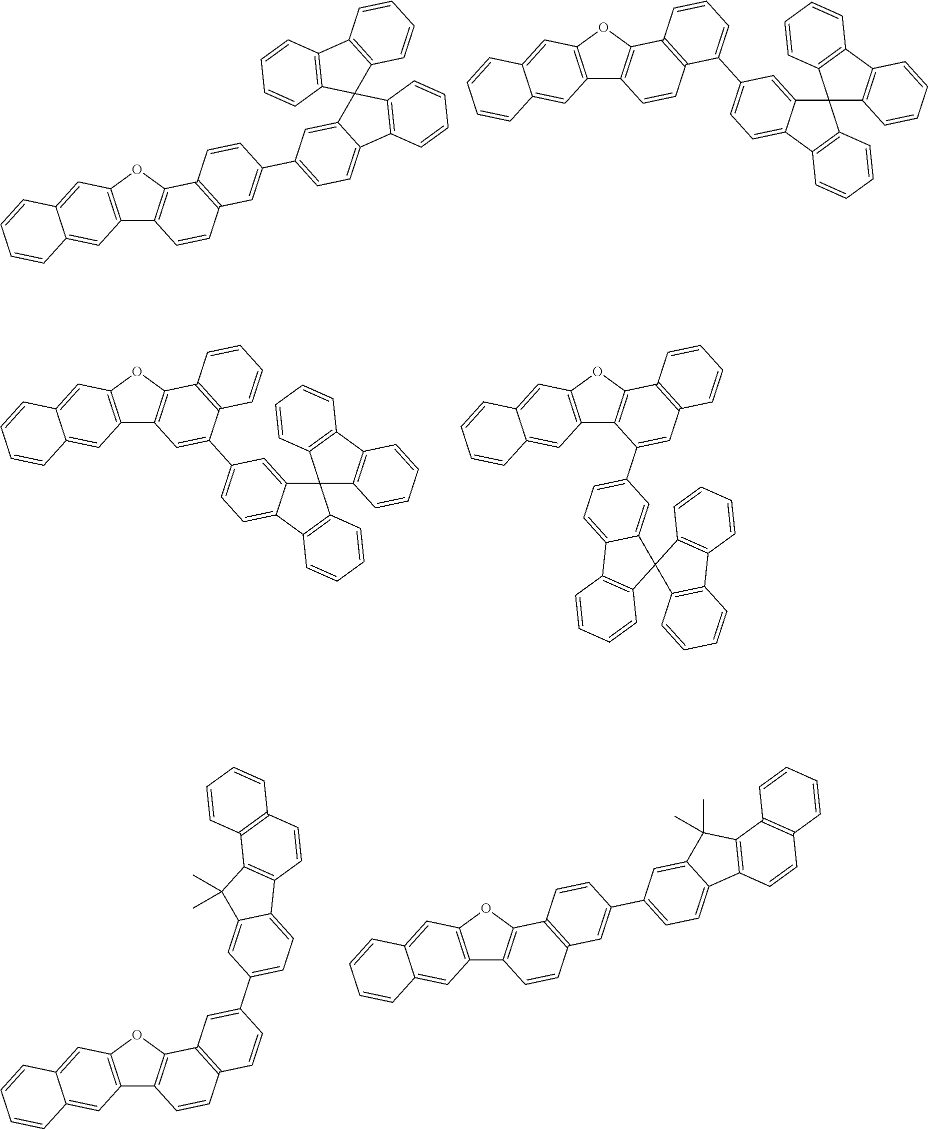

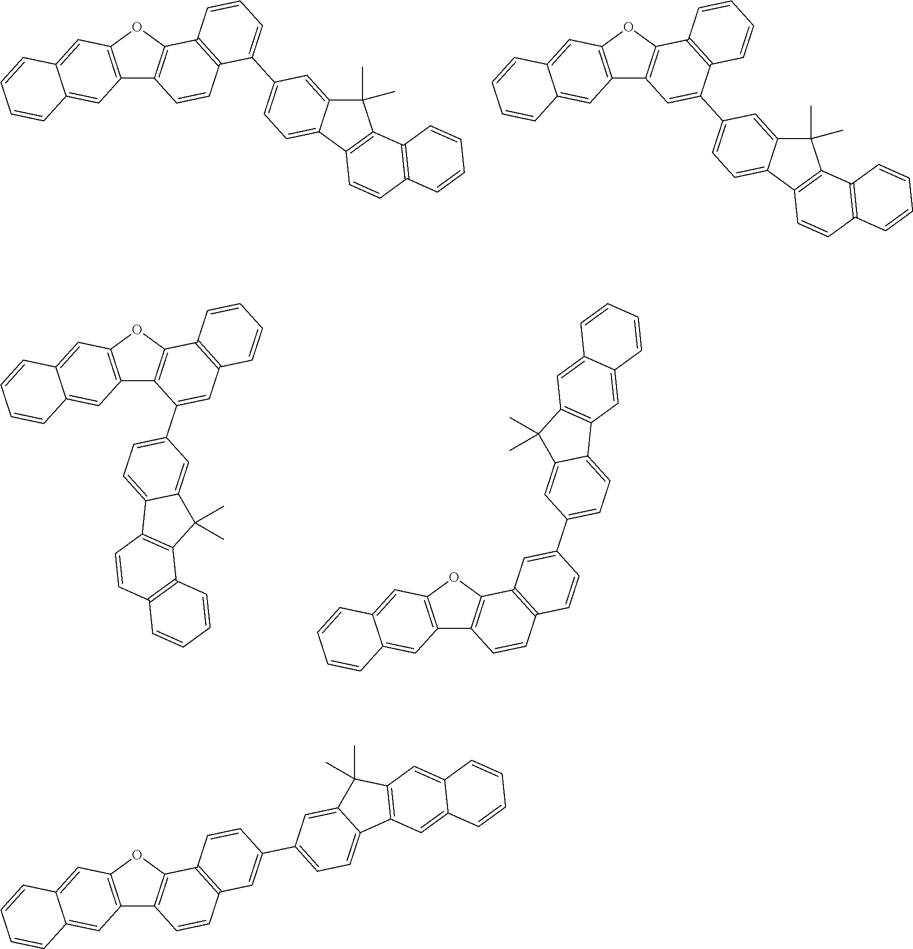 [SMILES: CC1(C)c2cc(-c3cccc4c3ccc3c5cc6ccccc6cc5oc43)ccc2-c2ccc3ccccc3c21 ; CC1(C)c2cc(-c3cc4c5cc6ccccc6cc5oc4c4ccccc34)ccc2-c2ccc3ccccc3c21 ; CC1(C)c2cc(-c3cc4ccccc4c4oc5cc6ccccc6cc5c34)ccc2-c2ccc3ccccc3c21 ; CC1(C)c2cc(-c3ccc4ccc5c6cc7ccccc7cc6oc5c4c3)ccc2-c2cc3ccccc3cc21 ; CC1(C)c2cc(-c3ccc4c(ccc5c6cc7ccccc7cc6oc45)c3)ccc2-c2cc3ccccc3cc21]

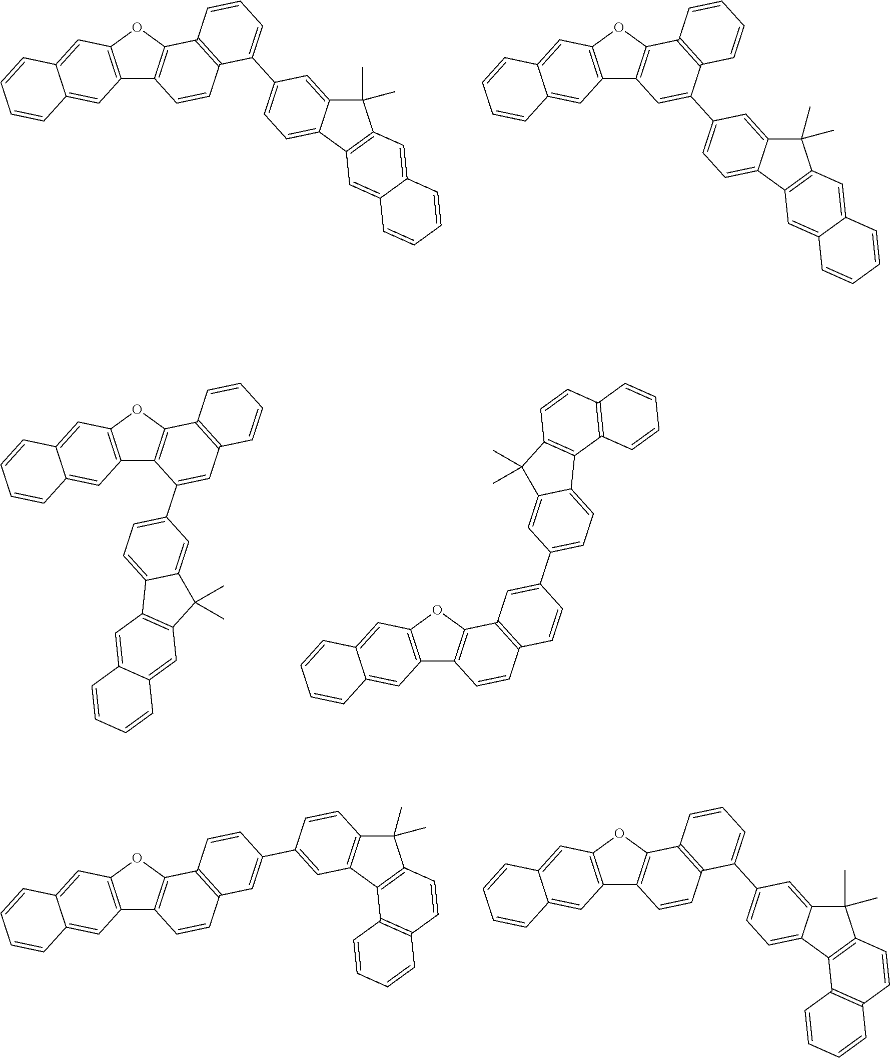 [SMILES: CC1(C)c2cc(-c3cccc4c3ccc3c5cc6ccccc6cc5oc43)ccc2-c2cc3ccccc3cc21 ; CC1(C)c2cc(-c3cc4c5cc6ccccc6cc5oc4c4ccccc34)ccc2-c2cc3ccccc3cc21 ; CC1(C)c2cc(-c3cc4ccccc4c4oc5cc6ccccc6cc5c34)ccc2-c2cc3ccccc3cc21 ; CC1(C)c2cc(-c3ccc4ccc5c6cc7ccccc7cc6oc5c4c3)ccc2-c2c1ccc1ccccc21 ; CC1(C)c2ccc(-c3ccc4c(ccc5c6cc7ccccc7cc6oc45)c3)cc2-c2c1ccc1ccccc21 ; CC1(C)c2cc(-c3cccc4c3ccc3c5cc6ccccc6cc5oc43)ccc2-c2c1ccc1ccccc21]

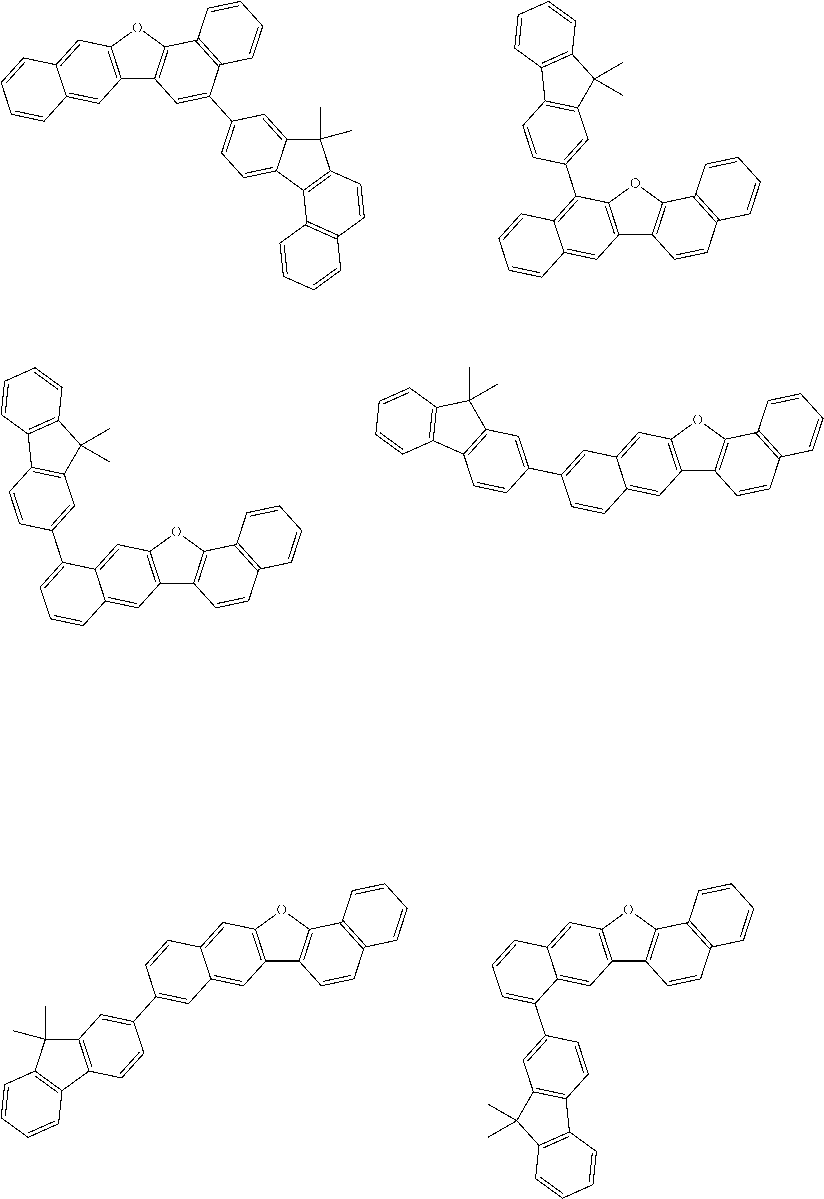 [SMILES: CC1(C)c2cc(-c3cc4c5cc6ccccc6cc5oc4c4ccccc34)ccc2-c2c1ccc1ccccc21 ; CC1(C)c2ccccc2-c2ccc(-c3c4ccccc4cc4c3oc3c5ccccc5ccc43)cc21 ; CC1(C)c2ccccc2-c2ccc(-c3cccc4cc5c(cc34)oc3c4ccccc4ccc53)cc21 ; CC1(C)c2ccccc2-c2ccc(-c3ccc4cc5c(cc4c3)oc3c4ccccc4ccc53)cc21 ; CC1(C)c2ccccc2-c2ccc(-c3ccc4cc5oc6c7ccccc7ccc6c5cc4c3)cc21 ; CC1(C)c2ccccc2-c2ccc(-c3cccc4cc5oc6c7ccccc7ccc6c5cc34)cc21]

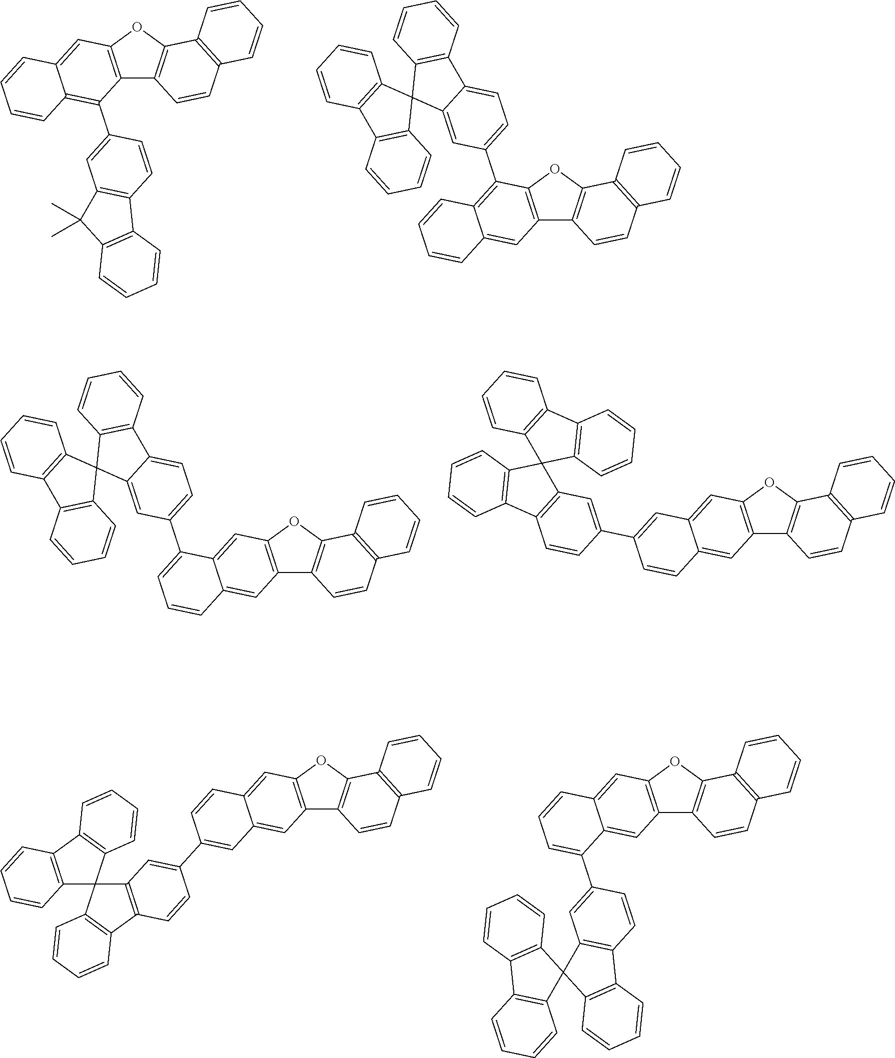

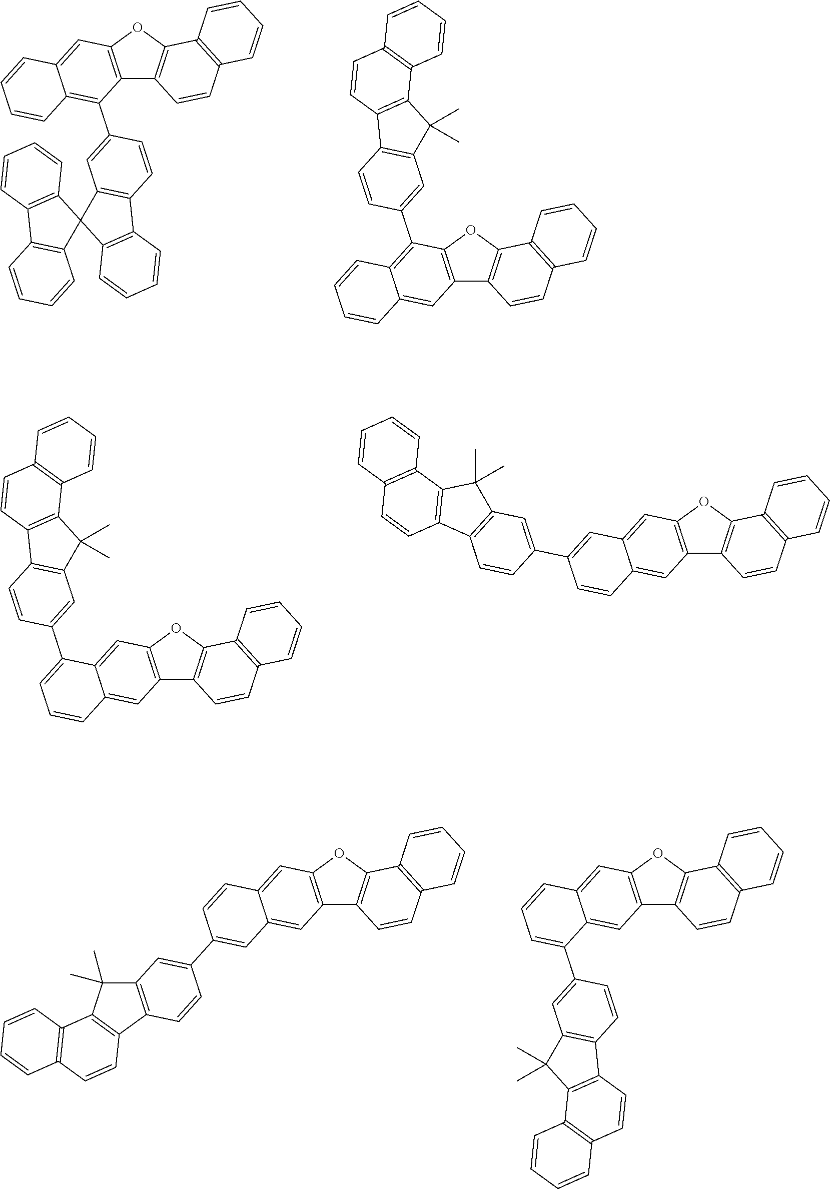 [SMILES: c1ccc2c(c1)-c1ccccc1C21c2ccccc2-c2ccc(-c3c4ccccc4cc4oc5c6ccccc6ccc5c34)cc21 ; CC1(C)c2cc(-c3c4ccccc4cc4c3oc3c5ccccc5ccc43)ccc2-c2ccc3ccccc3c21 ; CC1(C)c2cc(-c3cccc4cc5c(cc34)oc3c4ccccc4ccc53)ccc2-c2ccc3ccccc3c21 ; CC1(C)c2cc(-c3ccc4cc5c(cc4c3)oc3c4ccccc4ccc53)ccc2-c2ccc3ccccc3c21 ; CC1(C)c2cc(-c3ccc4cc5oc6c7ccccc7ccc6c5cc4c3)ccc2-c2ccc3ccccc3c21 ; CC1(C)c2cc(-c3cccc4cc5oc6c7ccccc7ccc6c5cc34)ccc2-c2ccc3ccccc3c21]

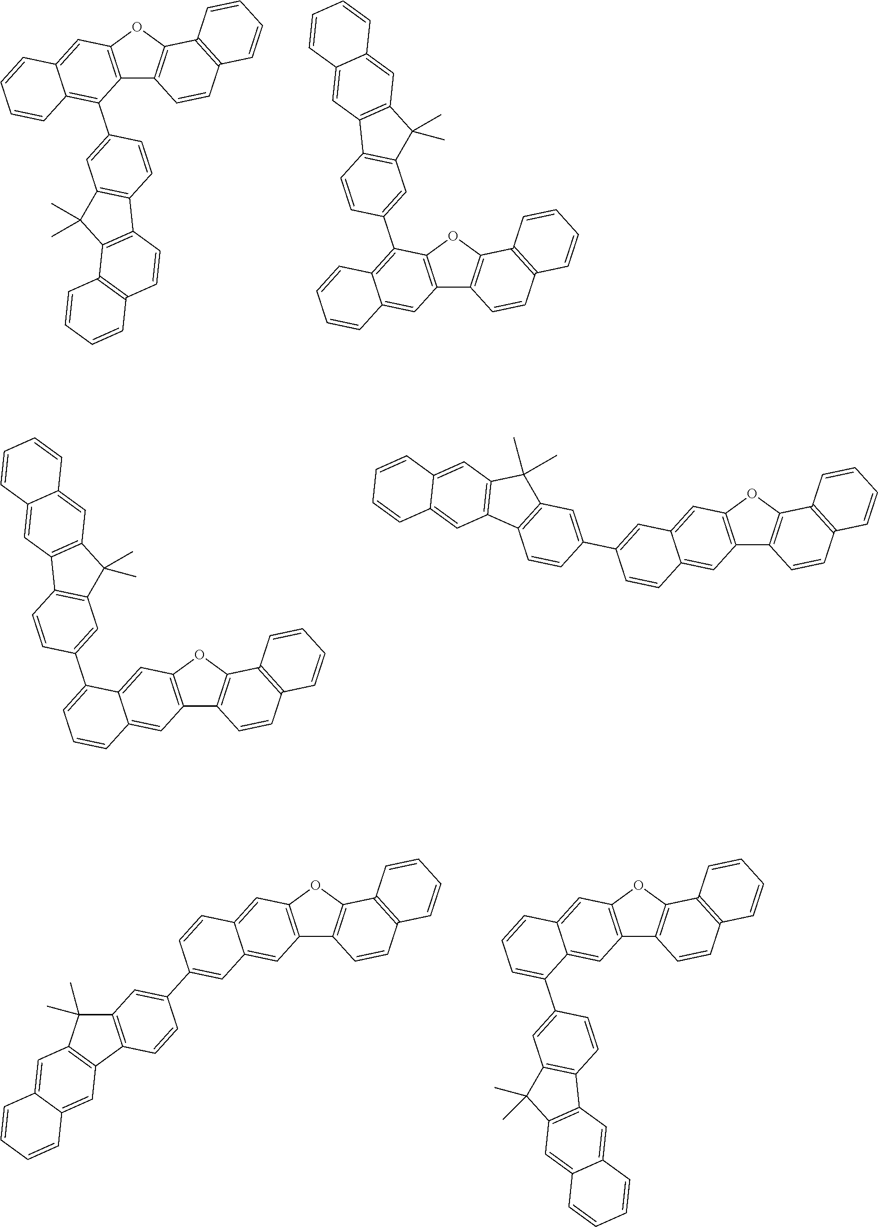 [SMILES: CC1(C)c2cc(-c3c4ccccc4cc4oc5c6ccccc6ccc5c34)ccc2-c2ccc3ccccc3c21 ; CC1(C)c2cc(-c3c4ccccc4cc4c3oc3c5ccccc5ccc43)ccc2-c2cc3ccccc3cc21 ; CC1(C)c2cc(-c3cccc4cc5c(cc34)oc3c4ccccc4ccc53)ccc2-c2cc3ccccc3cc21 ; CC1(C)c2cc(-c3ccc4cc5c(cc4c3)oc3c4ccccc4ccc53)ccc2-c2cc3ccccc3cc21 ; CC1(C)c2cc(-c3ccc4cc5oc6c7ccccc7ccc6c5cc4c3)ccc2-c2cc3ccccc3cc21 ; CC1(C)c2cc(-c3cccc4cc5oc6c7ccccc7ccc6c5cc34)ccc2-c2cc3ccccc3cc21]

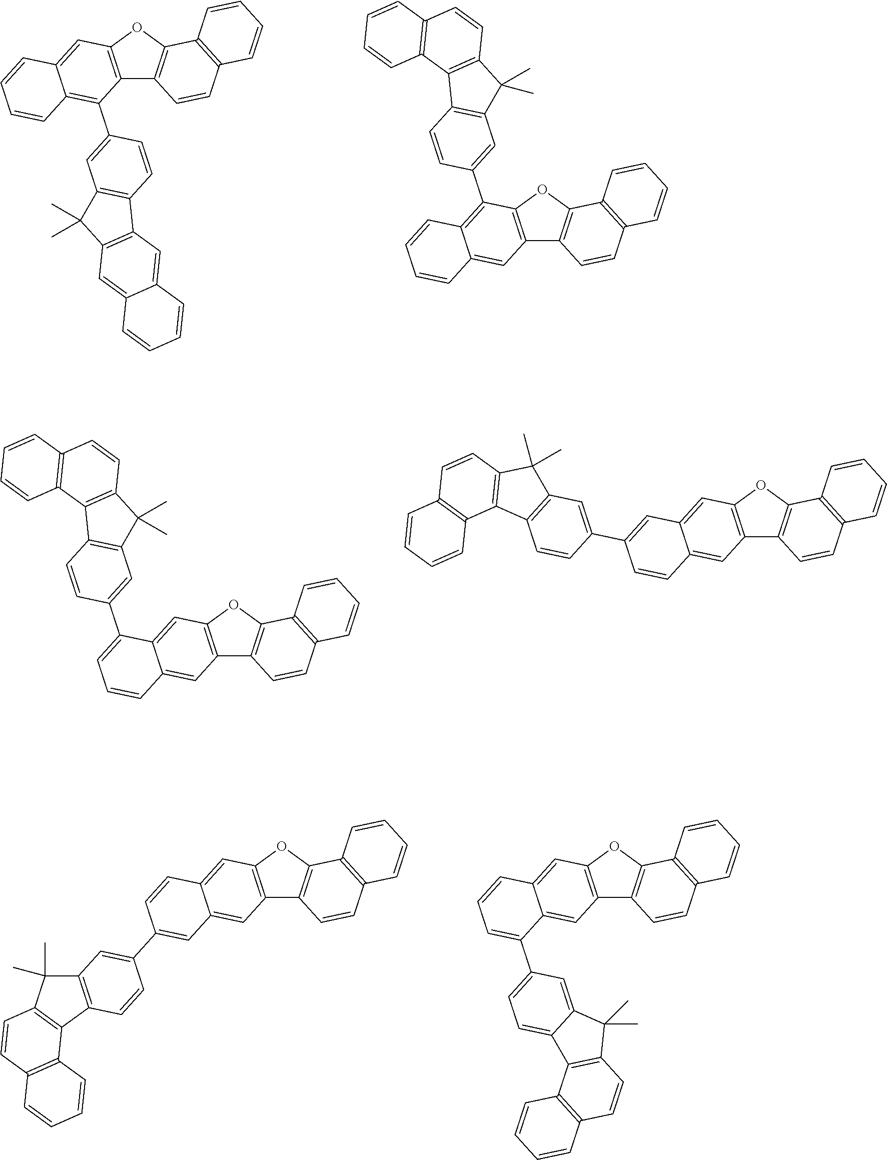 [SMILES: CC1(C)c2cc(-c3c4ccccc4cc4oc5c6ccccc6ccc5c34)ccc2-c2cc3ccccc3cc21 ; CC1(C)c2cc(-c3c4ccccc4cc4c3oc3c5ccccc5ccc43)ccc2-c2c1ccc1ccccc21 ; CC1(C)c2cc(-c3cccc4cc5c(cc34)oc3c4ccccc4ccc53)ccc2-c2c1ccc1ccccc21 ; CC1(C)c2cc(-c3ccc4cc5c(cc4c3)oc3c4ccccc4ccc53)ccc2-c2c1ccc1ccccc21 ; CC1(C)c2cc(-c3ccc4cc5oc6c7ccccc7ccc6c5cc4c3)ccc2-c2c1ccc1ccccc21 ; CC1(C)c2cc(-c3cccc4cc5oc6c7ccccc7ccc6c5cc34)ccc2-c2c1ccc1ccccc21]

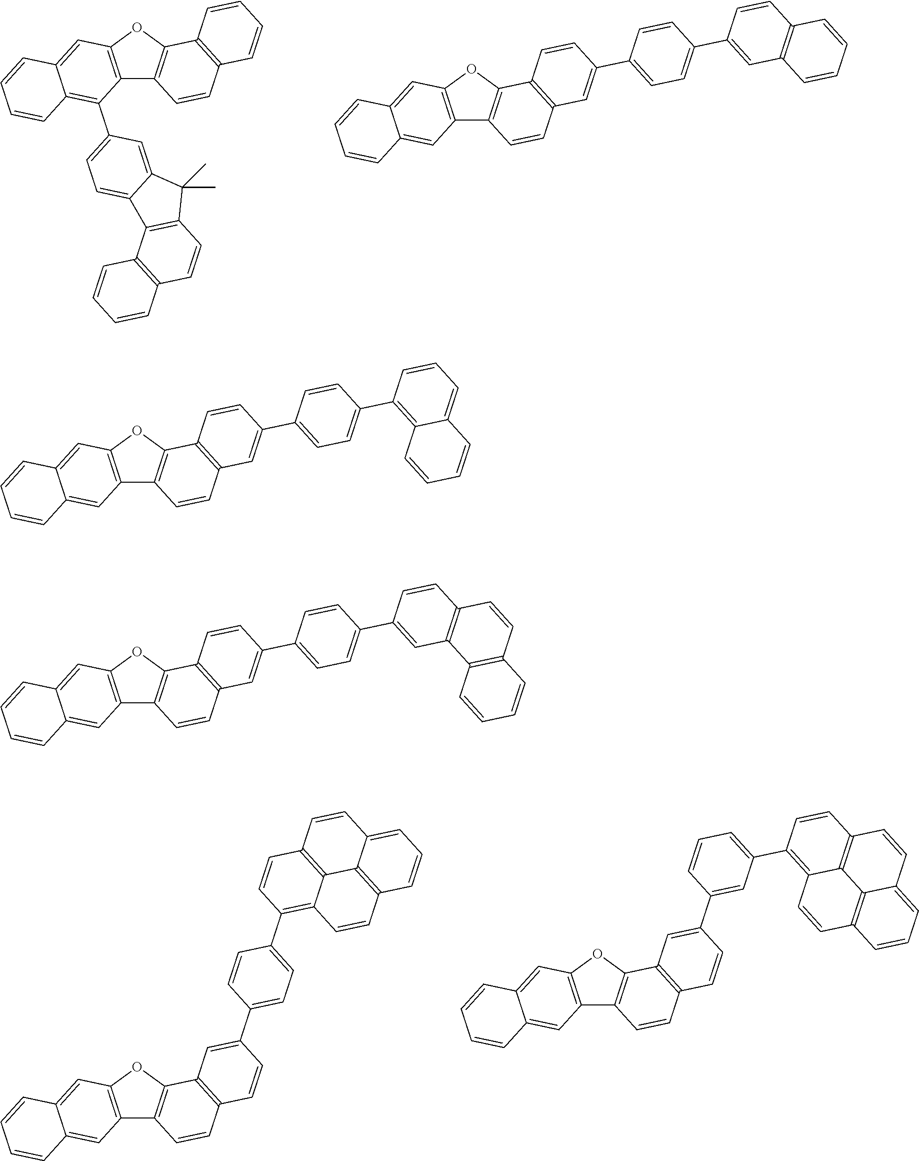 [SMILES: CC1(C)c2cc(-c3c4ccccc4cc4oc5c6ccccc6ccc5c34)ccc2-c2c1ccc1ccccc21 ; c1ccc2cc(-c3ccc(-c4ccc5c(ccc6c7cc8ccccc8cc7oc56)c4)cc3)ccc2c1 ; c1ccc2cc3c(cc2c1)oc1c2ccc(-c4ccc(-c5cccc6ccccc56)cc4)cc2ccc31 ; c1ccc2cc3c(cc2c1)oc1c2ccc(-c4ccc(-c5ccc6ccc7ccccc7c6c5)cc4)cc2ccc31 ; c1ccc2cc3c(cc2c1)oc1c2cc(-c4ccc(-c5ccc6ccc7cccc8ccc5c6c78)cc4)ccc2ccc31 ; c1cc(-c2ccc3ccc4c5cc6ccccc6cc5oc4c3c2)cc(-c2ccc3ccc4cccc5ccc2c3c45)c1]

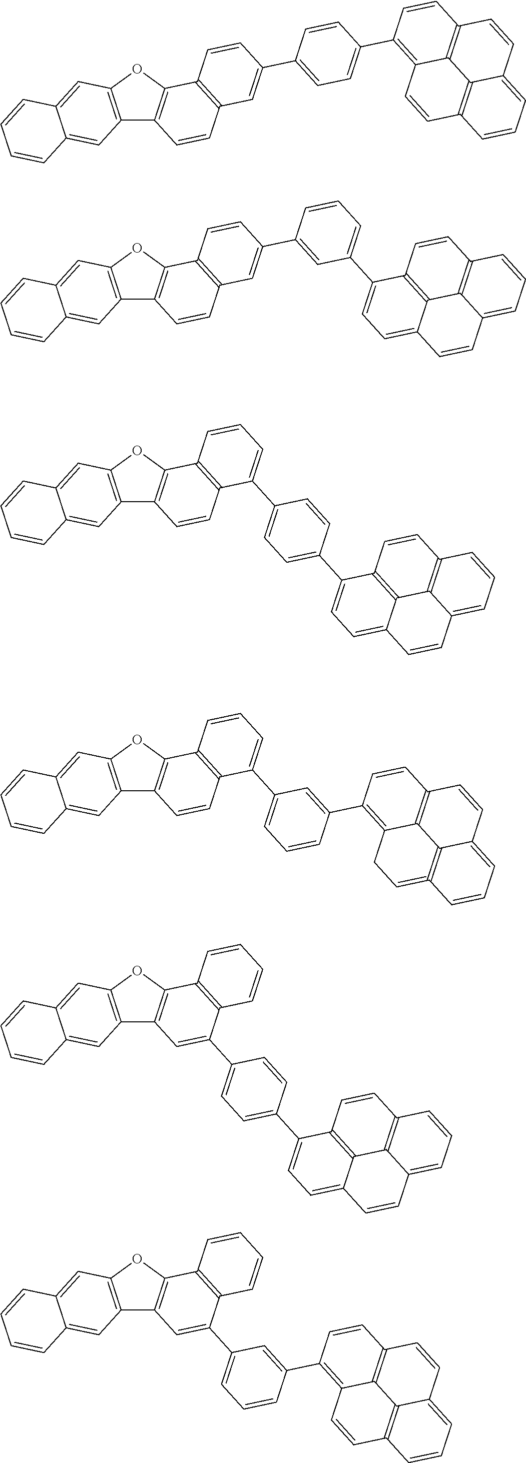

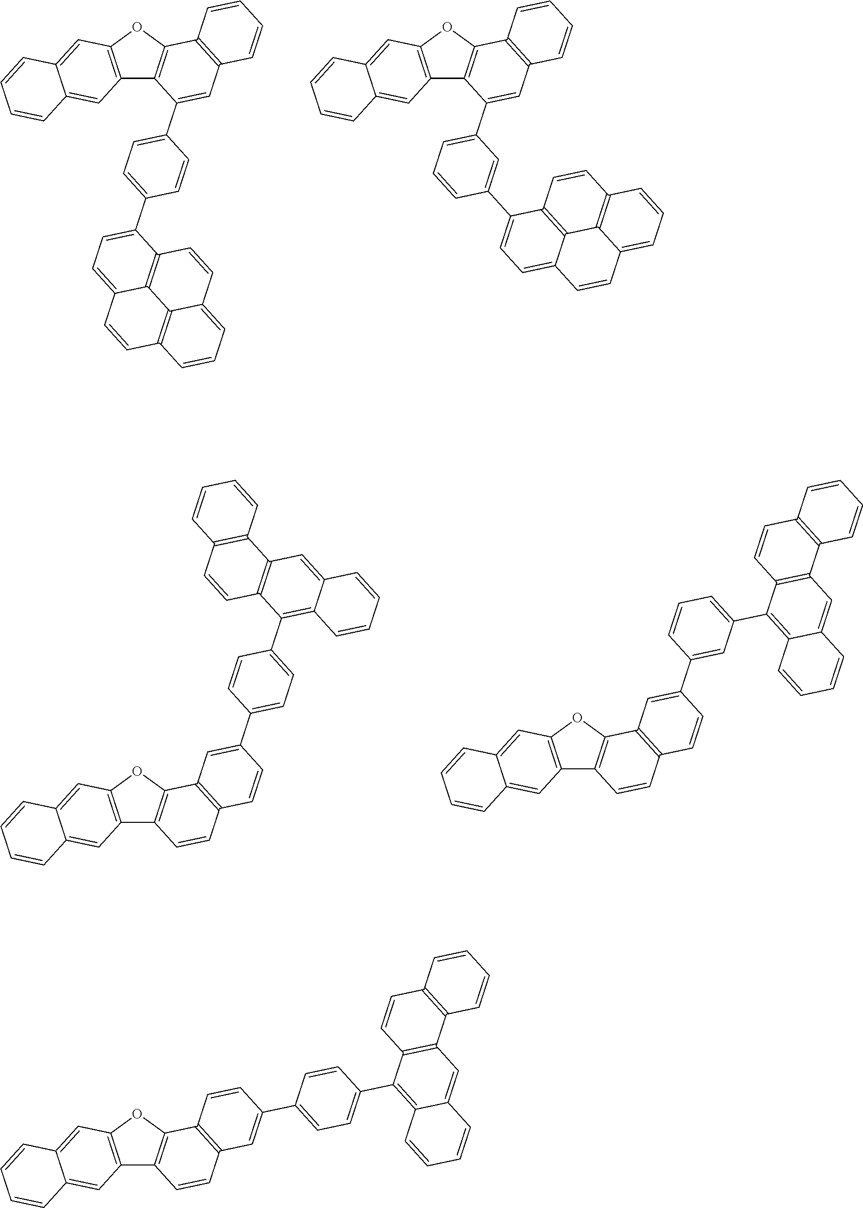 [SMILES: c1ccc2cc3c(cc2c1)oc1c2ccccc2cc(-c2ccc(-c4ccc5ccc6cccc7ccc4c5c67)cc2)c31 ; c1cc(-c2ccc3ccc4cccc5ccc2c3c45)cc(-c2cc3ccccc3c3oc4cc5ccccc5cc4c23)c1 ; c1ccc2cc3c(cc2c1)oc1c2cc(-c4ccc(-c5c6ccccc6cc6c5ccc5ccccc56)cc4)ccc2ccc31 ; c1cc(-c2ccc3ccc4c5cc6ccccc6cc5oc4c3c2)cc(-c2c3ccccc3cc3c2ccc2ccccc23)c1 ; c1ccc2cc3c(cc2c1)oc1c2ccc(-c4ccc(-c5c6ccccc6cc6c5ccc5ccccc56)cc4)cc2ccc31]

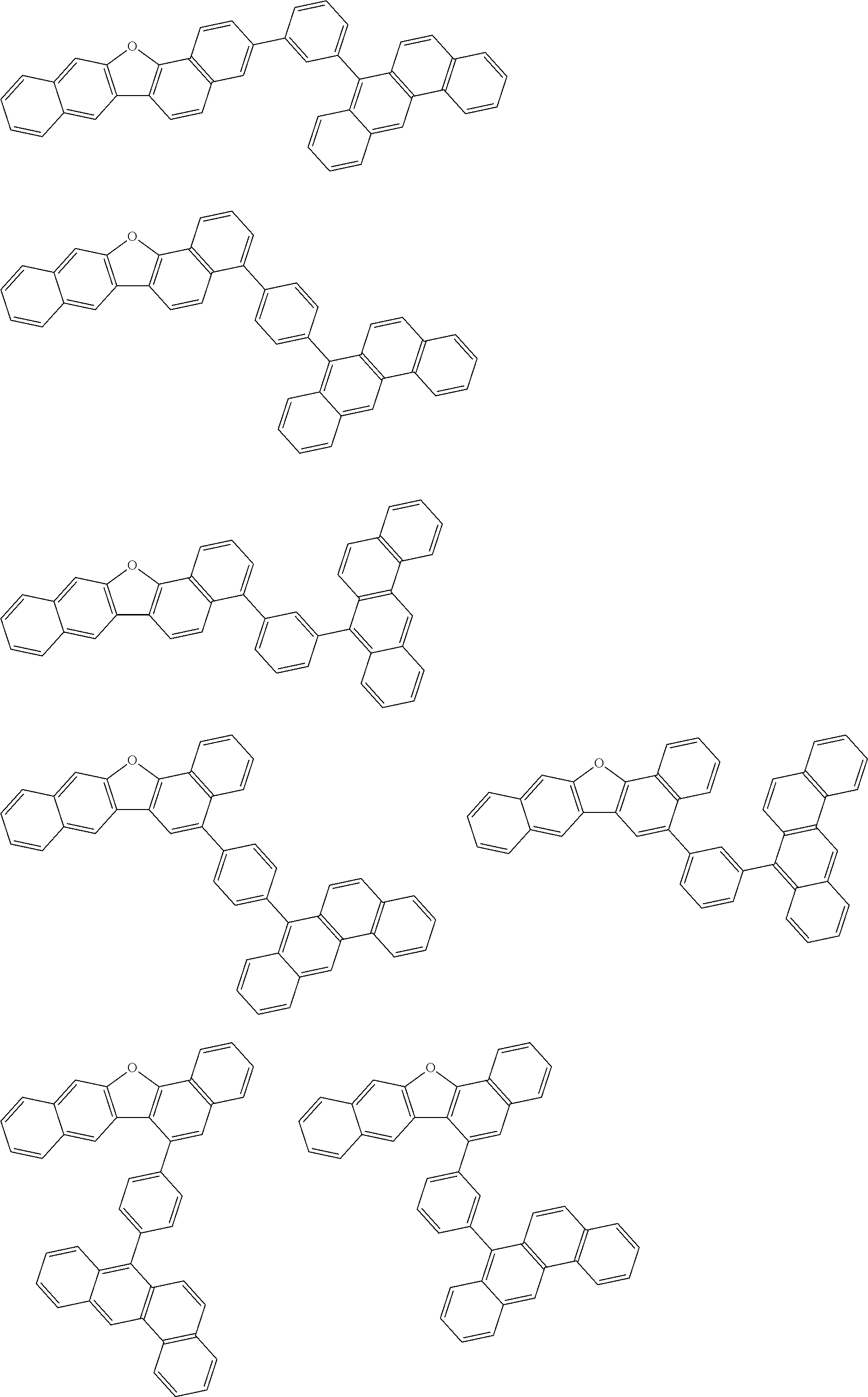

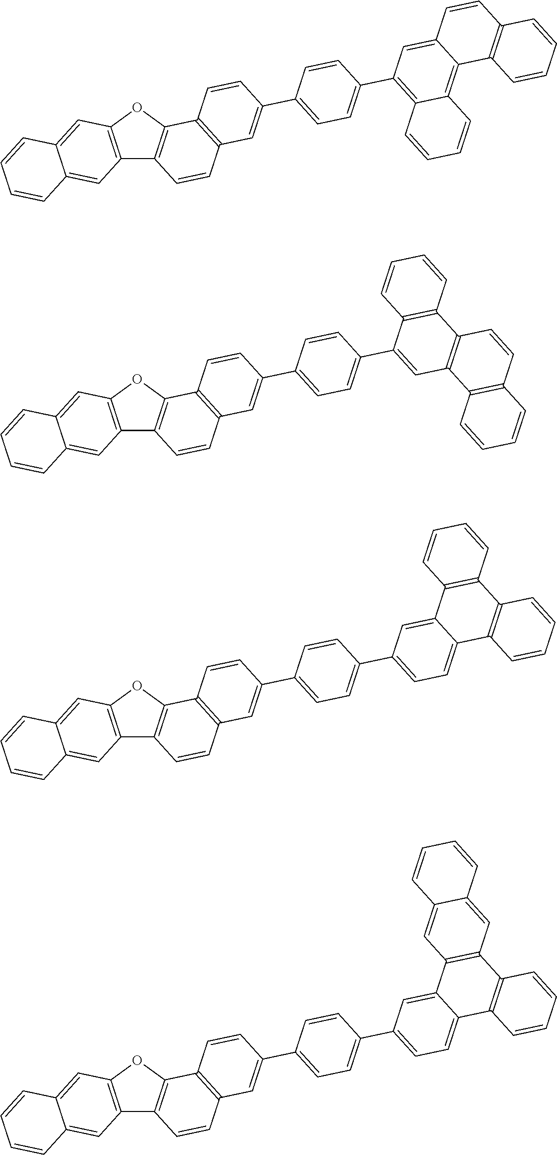 [SMILES: c1ccc2cc3c(cc2c1)oc1c2ccc(-c4ccc(-c5cc6ccc7ccccc7c6c6ccccc56)cc4)cc2ccc31 ; c1ccc2cc3c(cc2c1)oc1c2ccc(-c4ccc(-c5cc6c7ccccc7ccc6c6ccccc56)cc4)cc2ccc31 ; c1ccc2cc3c(cc2c1)oc1c2ccc(-c4ccc(-c5ccc6c7ccccc7c7ccccc7c6c5)cc4)cc2ccc31 ; c1ccc2cc3c(cc2c1)oc1c2ccc(-c4ccc(-c5ccc6c7ccccc7c7cc8ccccc8cc7c6c5)cc4)cc2ccc31]

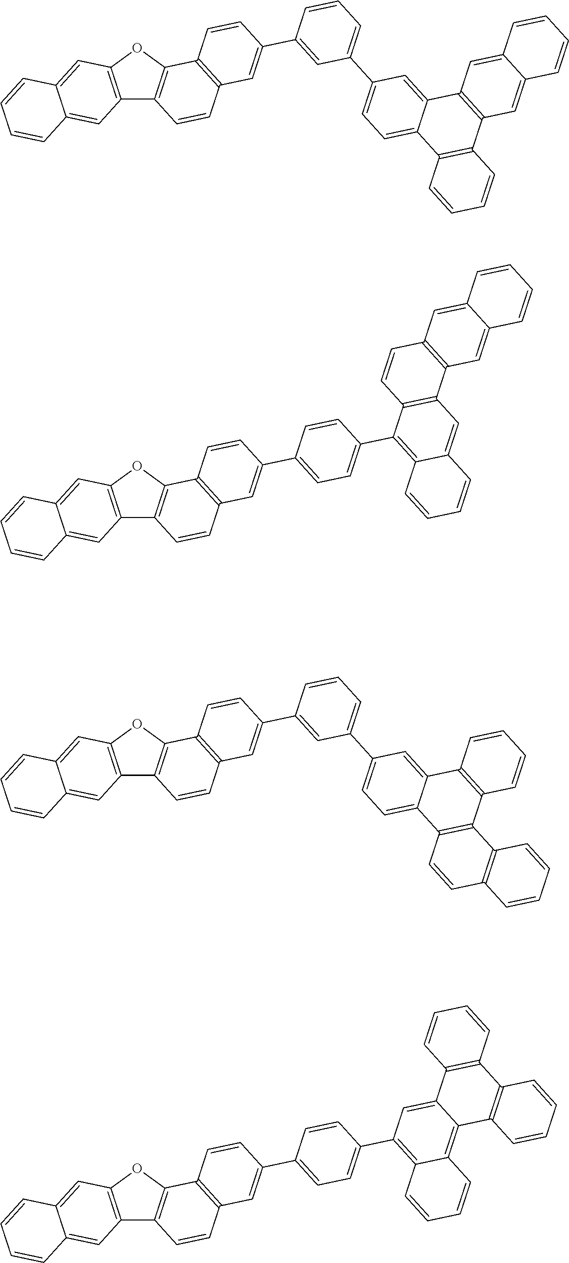 [SMILES: c1cc(-c2ccc3c(ccc4c5cc6ccccc6cc5oc34)c2)cc(-c2ccc3c4ccccc4c4cc5ccccc5cc4c3c2)c1 ; c1ccc2cc3c(ccc4c(-c5ccc(-c6ccc7c(ccc8c9cc%10ccccc%10cc9oc78)c6)cc5)c5ccccc5cc43)cc2c1 ; c1cc(-c2ccc3c(ccc4c5cc6ccccc6cc5oc34)c2)cc(-c2ccc3c(c2)c2ccccc2c2c4ccccc4ccc32)c1 ; c1ccc2cc3c(cc2c1)oc1c2ccc(-c4ccc(-c5cc6c7ccccc7c7ccccc7c6c6ccccc56)cc4)cc2ccc31]

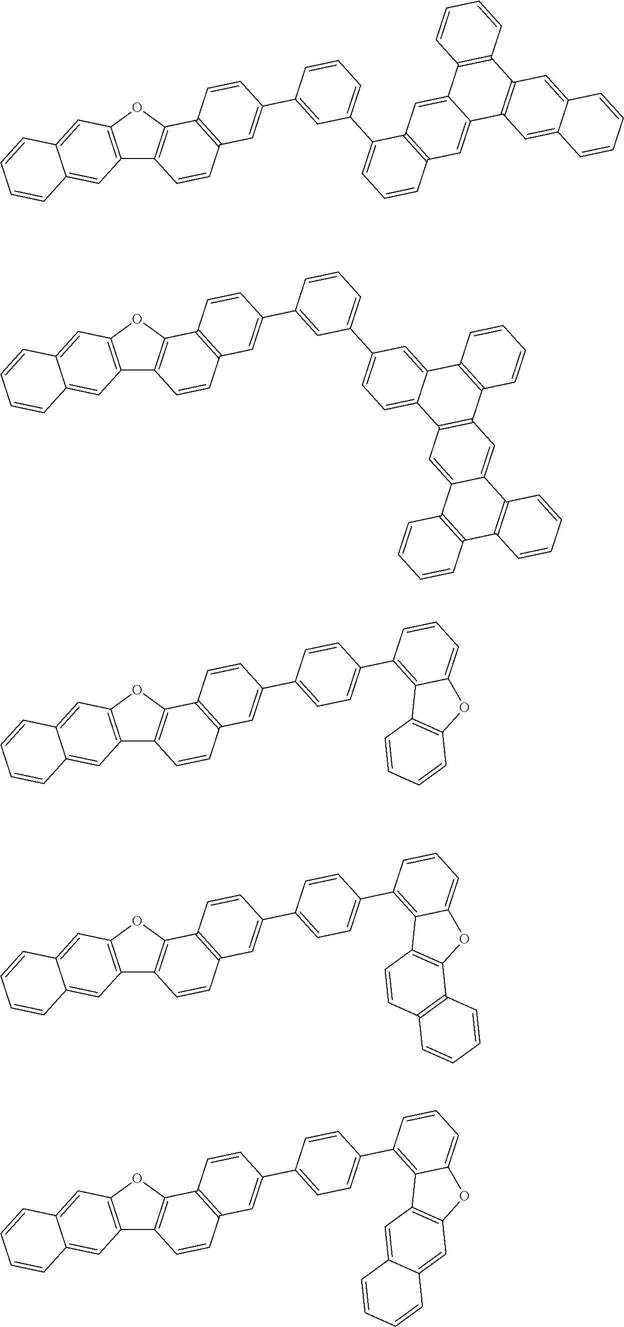

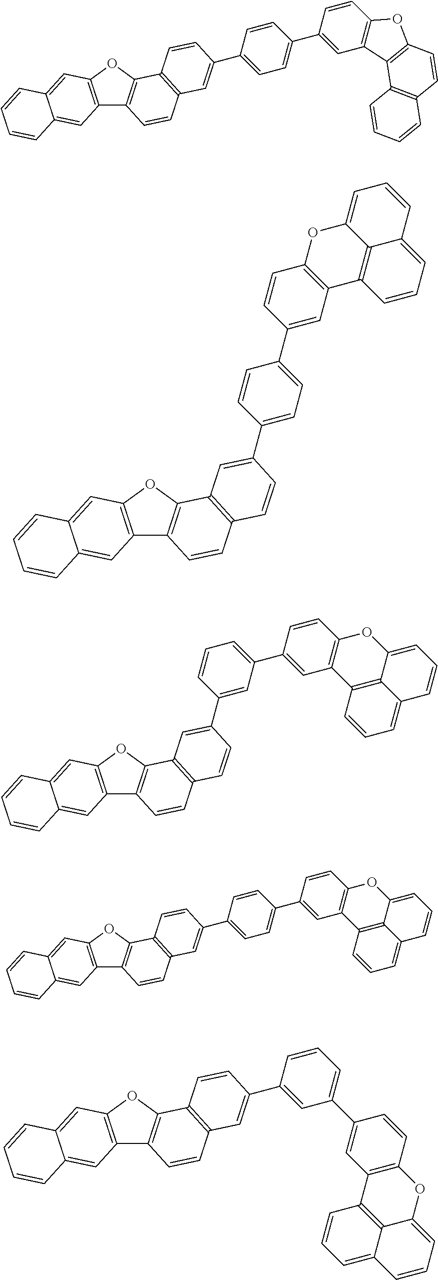 [SMILES: c1ccc2cc3c(cc2c1)oc1c2ccc(-c4ccc(-c5ccc6oc7ccc8ccccc8c7c6c5)cc4)cc2ccc31 ; c1ccc2cc3c(cc2c1)oc1c2cc(-c4ccc(-c5ccc6c(c5)-c5cccc7cccc(c57)O6)cc4)ccc2ccc31 ; c1cc(-c2ccc3c(c2)-c2cccc4cccc(c24)O3)cc(-c2ccc3ccc4c5cc6ccccc6cc5oc4c3c2)c1 ; c1ccc2cc3c(cc2c1)oc1c2ccc(-c4ccc(-c5ccc6c(c5)-c5cccc7cccc(c57)O6)cc4)cc2ccc31 ; c1cc(-c2ccc3c(c2)-c2cccc4cccc(c24)O3)cc(-c2ccc3c(ccc4c5cc6ccccc6cc5oc34)c2)c1]

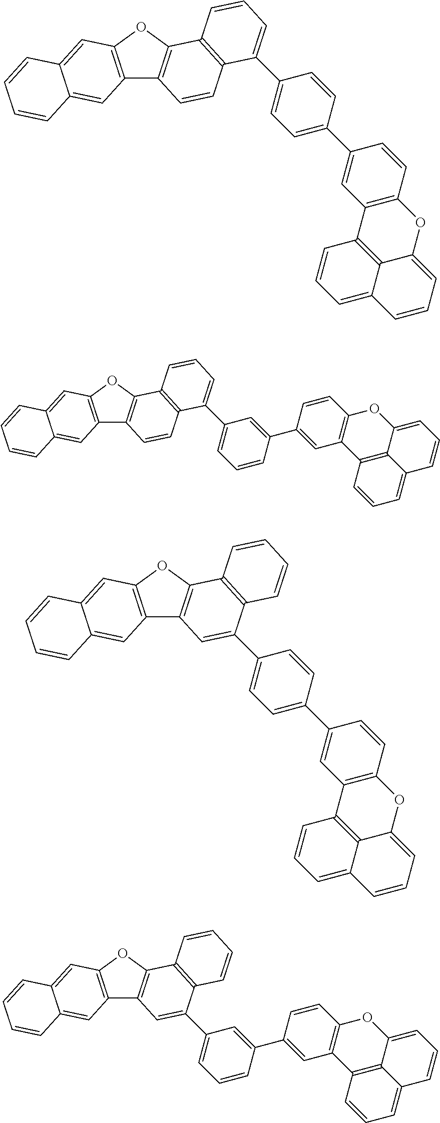 [SMILES: c1ccc2cc3c(cc2c1)oc1c2cccc(-c4ccc(-c5ccc6c(c5)-c5cccc7cccc(c57)O6)cc4)c2ccc31 ; c1cc(-c2ccc3c(c2)-c2cccc4cccc(c24)O3)cc(-c2cccc3c2ccc2c4cc5ccccc5cc4oc32)c1 ; c1ccc2cc3c(cc2c1)oc1c2ccccc2c(-c2ccc(-c4ccc5c(c4)-c4cccc6cccc(c46)O5)cc2)cc31 ; c1cc(-c2ccc3c(c2)-c2cccc4cccc(c24)O3)cc(-c2cc3c4cc5ccccc5cc4oc3c3ccccc23)c1]

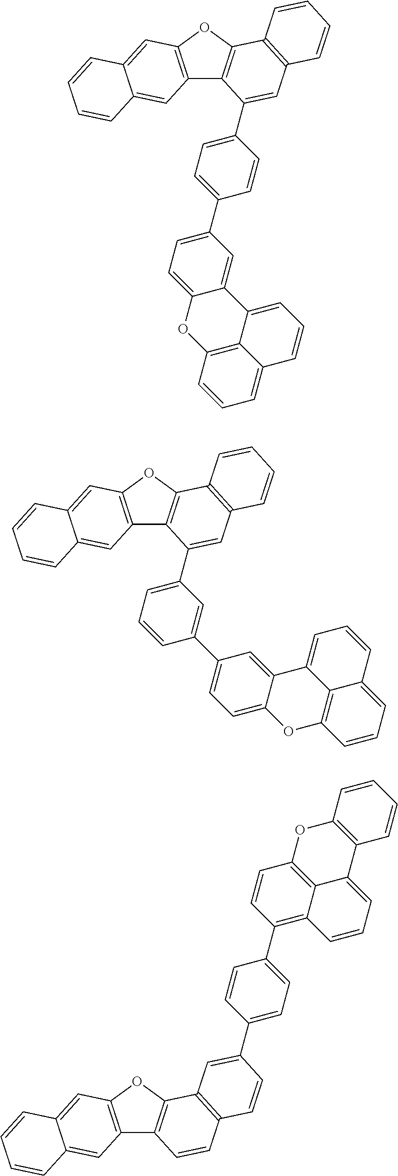

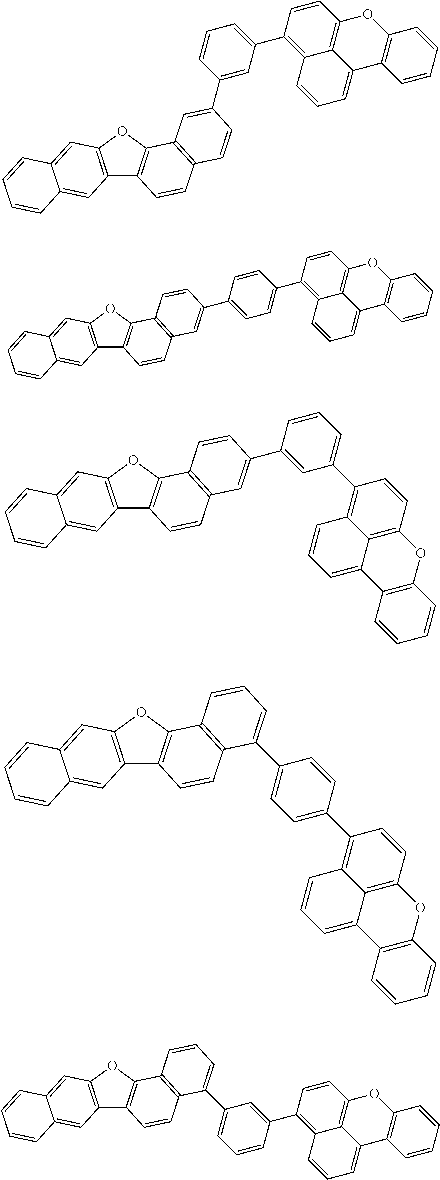 [SMILES: c1cc(-c2ccc3ccc4c5cc6ccccc6cc5oc4c3c2)cc(-c2ccc3c4c(cccc24)-c2ccccc2O3)c1 ; c1ccc2c(c1)Oc1ccc(-c3ccc(-c4ccc5c(ccc6c7cc8ccccc8cc7oc56)c4)cc3)c3cccc-2c13 ; c1cc(-c2ccc3c(ccc4c5cc6ccccc6cc5oc34)c2)cc(-c2ccc3c4c(cccc24)-c2ccccc2O3)c1 ; c1ccc2c(c1)Oc1ccc(-c3ccc(-c4cccc5c4ccc4c6cc7ccccc7cc6oc54)cc3)c3cccc-2c13 ; c1cc(-c2ccc3c4c(cccc24)-c2ccccc2O3)cc(-c2cccc3c2ccc2c4cc5ccccc5cc4oc32)c1]

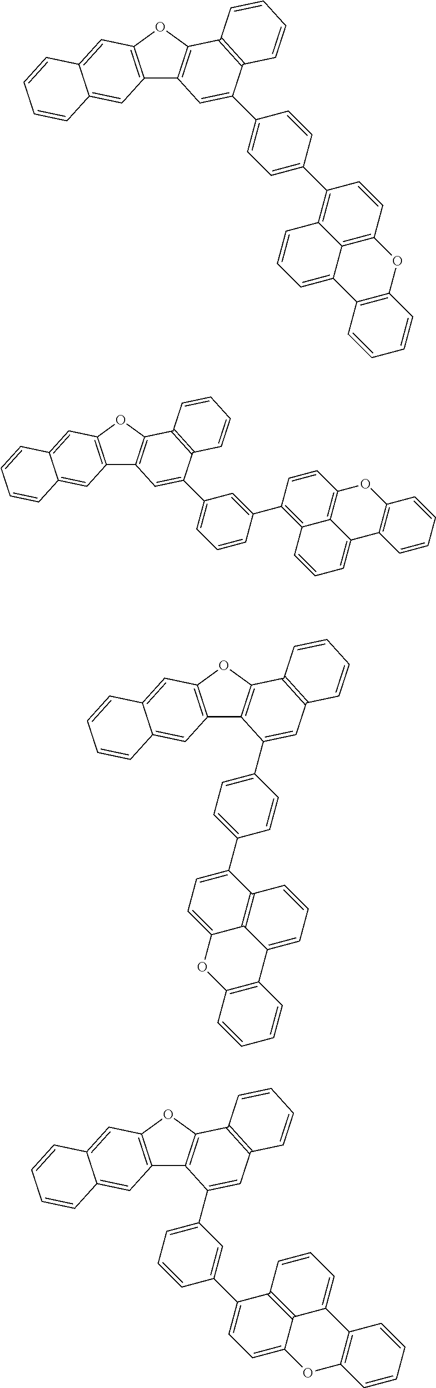 [SMILES: c1ccc2c(c1)Oc1ccc(-c3ccc(-c4cc5c6cc7ccccc7cc6oc5c5ccccc45)cc3)c3cccc-2c13 ; c1cc(-c2ccc3c4c(cccc24)-c2ccccc2O3)cc(-c2cc3c4cc5ccccc5cc4oc3c3ccccc23)c1 ; c1ccc2c(c1)Oc1ccc(-c3ccc(-c4cc5ccccc5c5oc6cc7ccccc7cc6c45)cc3)c3cccc-2c13 ; c1cc(-c2ccc3c4c(cccc24)-c2ccccc2O3)cc(-c2cc3ccccc3c3oc4cc5ccccc5cc4c23)c1]

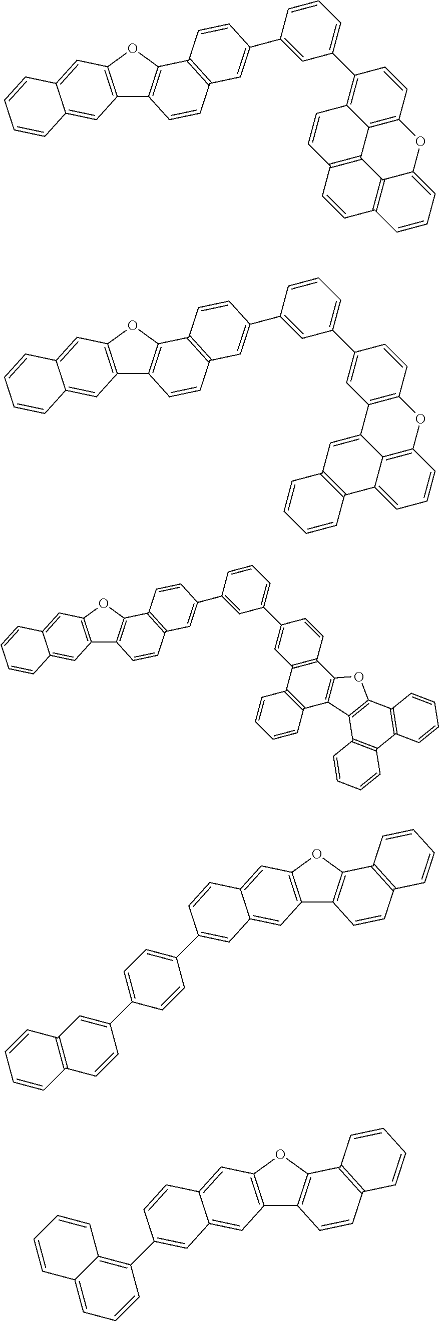 [SMILES: c1cc(-c2ccc3c(ccc4c5cc6ccccc6cc5oc34)c2)cc(-c2ccc3c4c2ccc2ccc5cccc(c5c24)O3)c1 ; c1cc(-c2ccc3c(c2)-c2cc4ccccc4c4cccc(c24)O3)cc(-c2ccc3c(ccc4c5cc6ccccc6cc5oc34)c2)c1 ; c1cc(-c2ccc3c(ccc4c5cc6ccccc6cc5oc34)c2)cc(-c2ccc3c(c2)c2ccccc2c2c3oc3c4ccccc4c4ccccc4c32)c1 ; c1ccc2cc(-c3ccc(-c4ccc5cc6oc7c8ccccc8ccc7c6cc5c4)cc3)ccc2c1 ; c1ccc2c(-c3ccc4cc5oc6c7ccccc7ccc6c5cc4c3)cccc2c1]

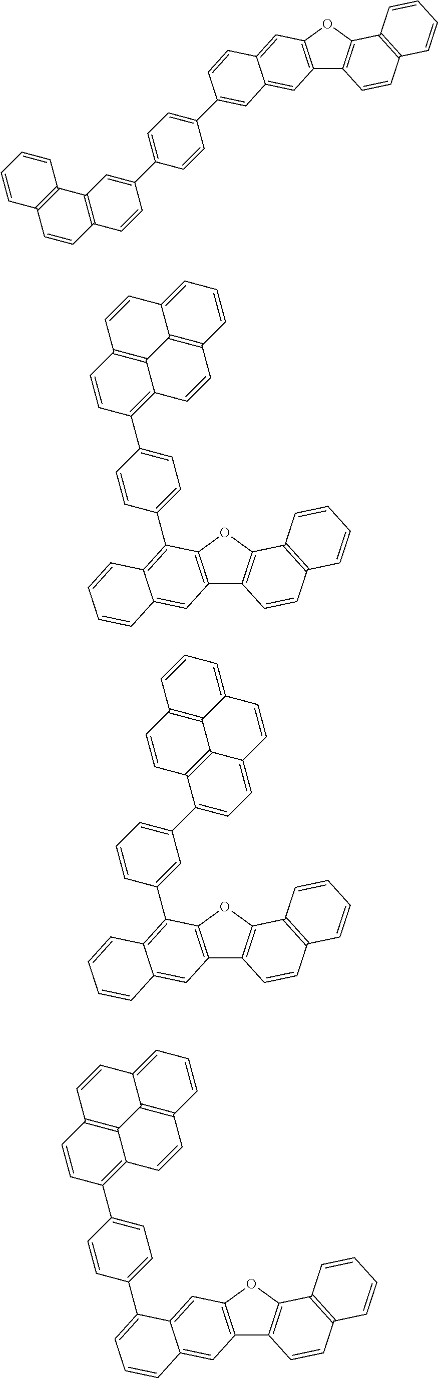 [SMILES: c1ccc2c(c1)ccc1ccc(-c3ccc(-c4ccc5cc6oc7c8ccccc8ccc7c6cc5c4)cc3)cc12 ; c1ccc2c(-c3ccc(-c4ccc5ccc6cccc7ccc4c5c67)cc3)c3oc4c5ccccc5ccc4c3cc2c1 ; c1cc(-c2ccc3ccc4cccc5ccc2c3c45)cc(-c2c3ccccc3cc3c2oc2c4ccccc4ccc32)c1 ; c1cc(-c2ccc(-c3ccc4ccc5cccc6ccc3c4c56)cc2)c2cc3oc4c5ccccc5ccc4c3cc2c1]

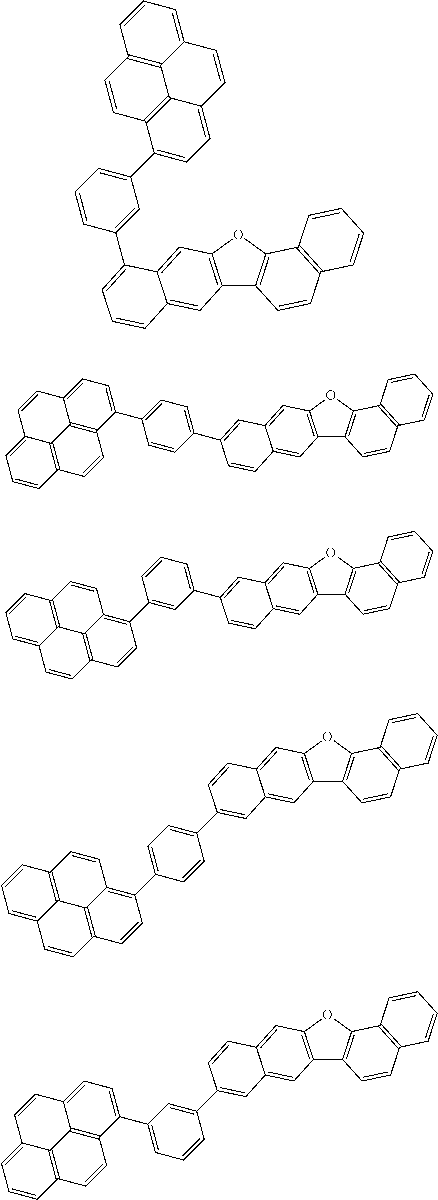 [SMILES: c1cc(-c2cccc3cc4c(cc23)oc2c3ccccc3ccc42)cc(-c2ccc3ccc4cccc5ccc2c3c45)c1 ; c1ccc2c(c1)ccc1c3cc4ccc(-c5ccc(-c6ccc7ccc8cccc9ccc6c7c89)cc5)cc4cc3oc21 ; c1cc(-c2ccc3cc4c(cc3c2)oc2c3ccccc3ccc42)cc(-c2ccc3ccc4cccc5ccc2c3c45)c1 ; c1ccc2c(c1)ccc1c3cc4cc(-c5ccc(-c6ccc7ccc8cccc9ccc6c7c89)cc5)ccc4cc3oc21 ; c1cc(-c2ccc3cc4oc5c6ccccc6ccc5c4cc3c2)cc(-c2ccc3ccc4cccc5ccc2c3c45)c1]

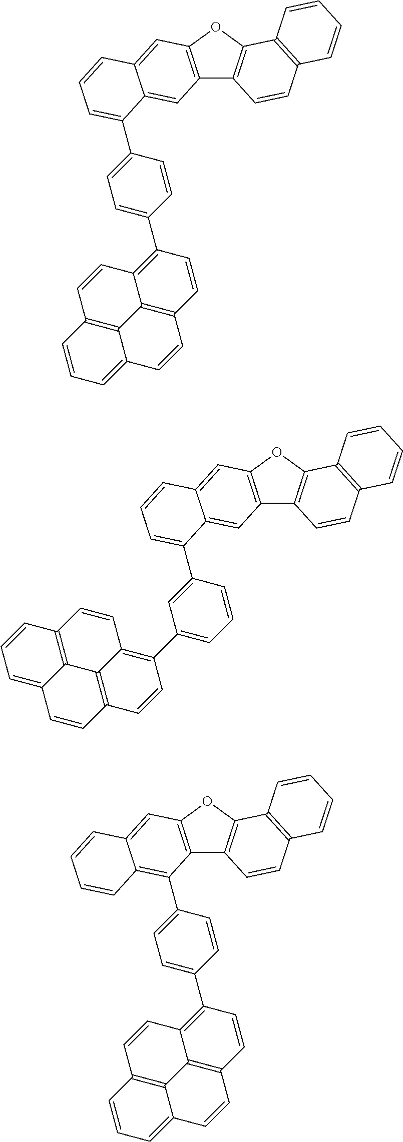 [SMILES: c1cc(-c2ccc(-c3ccc4ccc5cccc6ccc3c4c56)cc2)c2cc3c(cc2c1)oc1c2ccccc2ccc31 ; c1cc(-c2cccc3cc4oc5c6ccccc6ccc5c4cc23)cc(-c2ccc3ccc4cccc5ccc2c3c45)c1 ; c1ccc2c(-c3ccc(-c4ccc5ccc6cccc7ccc4c5c67)cc3)c3c(cc2c1)oc1c2ccccc2ccc13]

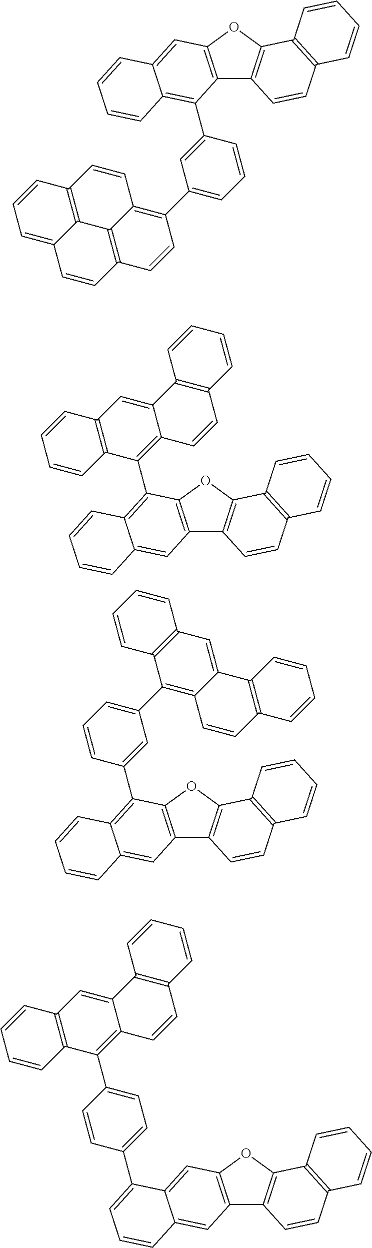

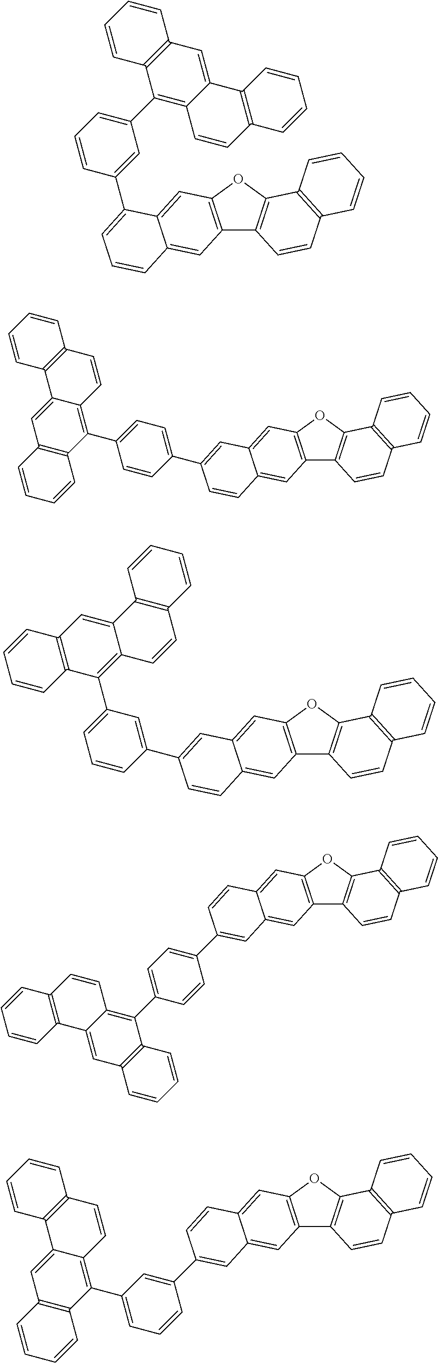 [SMILES: c1cc(-c2cccc3cc4c(cc23)oc2c3ccccc3ccc42)cc(-c2c3ccccc3cc3c2ccc2ccccc23)c1 ; c1ccc2c(-c3ccc(-c4ccc5cc6c(cc5c4)oc4c5ccccc5ccc64)cc3)c3ccc4ccccc4c3cc2c1 ; c1cc(-c2ccc3cc4c(cc3c2)oc2c3ccccc3ccc42)cc(-c2c3ccccc3cc3c2ccc2ccccc23)c1 ; c1ccc2c(-c3ccc(-c4ccc5cc6oc7c8ccccc8ccc7c6cc5c4)cc3)c3ccc4ccccc4c3cc2c1 ; c1cc(-c2ccc3cc4oc5c6ccccc6ccc5c4cc3c2)cc(-c2c3ccccc3cc3c2ccc2ccccc23)c1]

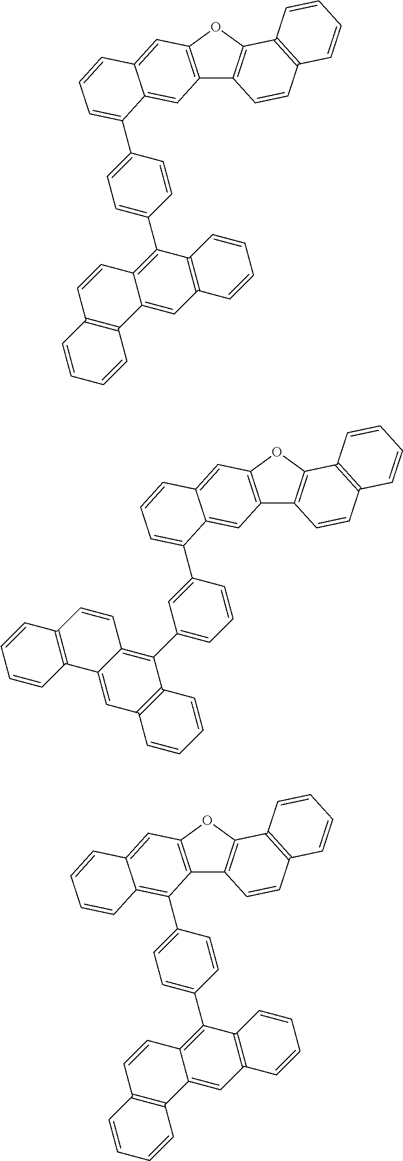 [SMILES: c1cc(-c2ccc(-c3c4ccccc4cc4c3ccc3ccccc34)cc2)c2cc3c(cc2c1)oc1c2ccccc2ccc31 ; c1cc(-c2cccc3cc4oc5c6ccccc6ccc5c4cc23)cc(-c2c3ccccc3cc3c2ccc2ccccc23)c1 ; c1ccc2c(-c3ccc(-c4c5ccccc5cc5oc6c7ccccc7ccc6c45)cc3)c3ccc4ccccc4c3cc2c1]

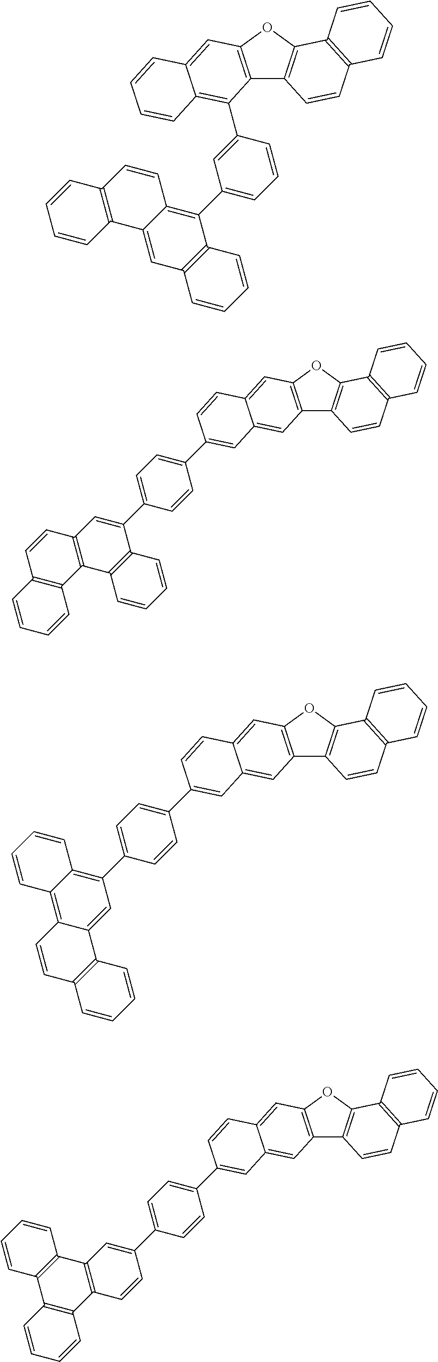 [SMILES: c1cc(-c2c3ccccc3cc3c2ccc2ccccc23)cc(-c2c3ccccc3cc3oc4c5ccccc5ccc4c23)c1 ; c1ccc2c(c1)ccc1c3cc4cc(-c5ccc(-c6cc7ccc8ccccc8c7c7ccccc67)cc5)ccc4cc3oc21 ; c1ccc2c(c1)ccc1c3ccccc3c(-c3ccc(-c4ccc5cc6oc7c8ccccc8ccc7c6cc5c4)cc3)cc21 ; c1ccc2c(c1)ccc1c3cc4cc(-c5ccc(-c6ccc7c8ccccc8c8ccccc8c7c6)cc5)ccc4cc3oc21]

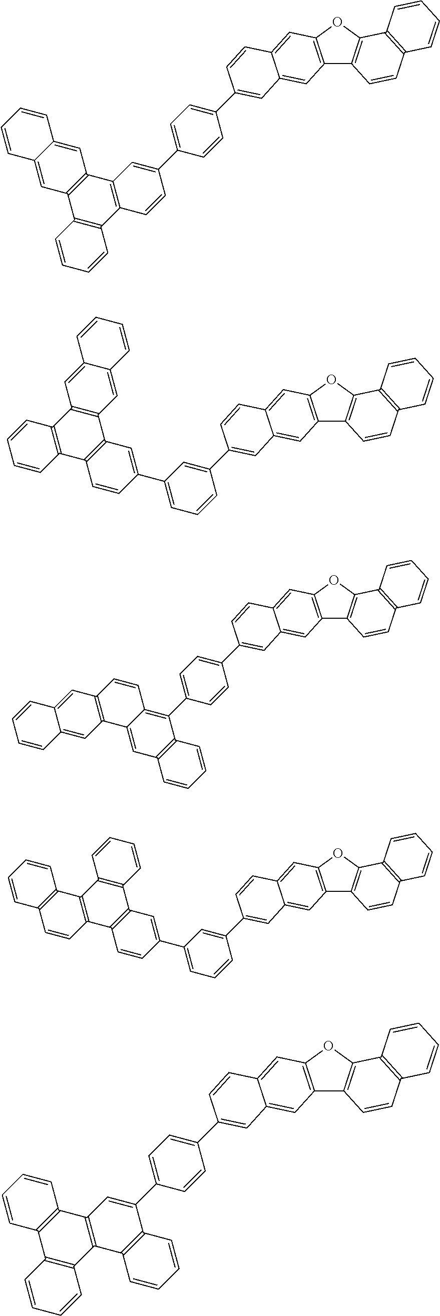 [SMILES: c1ccc2cc3c4cc(-c5ccc(-c6ccc7cc8oc9c%10ccccc%10ccc9c8cc7c6)cc5)ccc4c4ccccc4c3cc2c1 ; c1cc(-c2ccc3cc4oc5c6ccccc6ccc5c4cc3c2)cc(-c2ccc3c4ccccc4c4cc5ccccc5cc4c3c2)c1 ; c1ccc2cc3c(ccc4c(-c5ccc(-c6ccc7cc8oc9c%10ccccc%10ccc9c8cc7c6)cc5)c5ccccc5cc43)cc2c1 ; c1cc(-c2ccc3cc4oc5c6ccccc6ccc5c4cc3c2)cc(-c2ccc3c(c2)c2ccccc2c2c4ccccc4ccc32)c1 ; c1ccc2c(c1)ccc1c3cc4cc(-c5ccc(-c6cc7c8ccccc8c8ccccc8c7c7ccccc67)cc5)ccc4cc3oc21]

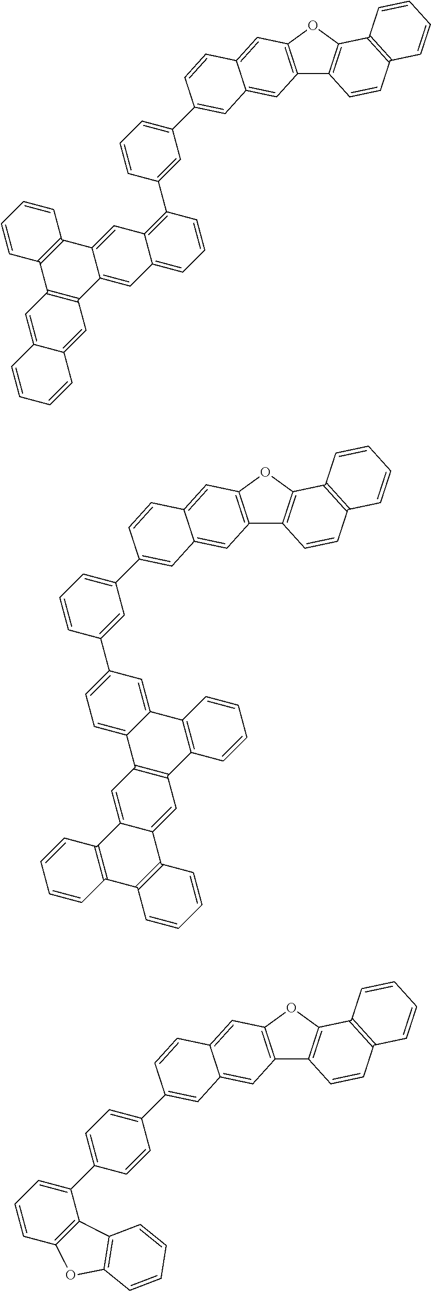 [SMILES: c1cc(-c2ccc3cc4oc5c6ccccc6ccc5c4cc3c2)cc(-c2cccc3cc4c5cc6ccccc6cc5c5ccccc5c4cc23)c1 ; c1cc(-c2ccc3cc4oc5c6ccccc6ccc5c4cc3c2)cc(-c2ccc3c(c2)c2ccccc2c2cc4c5ccccc5c5ccccc5c4cc32)c1 ; c1ccc2c(c1)ccc1c3cc4cc(-c5ccc(-c6cccc7oc8ccccc8c67)cc5)ccc4cc3oc21]

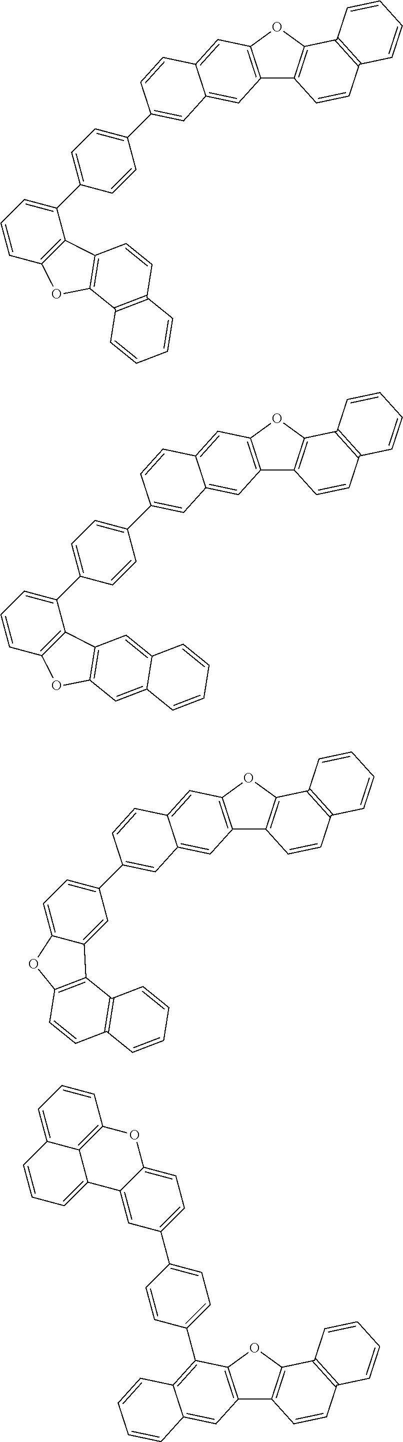

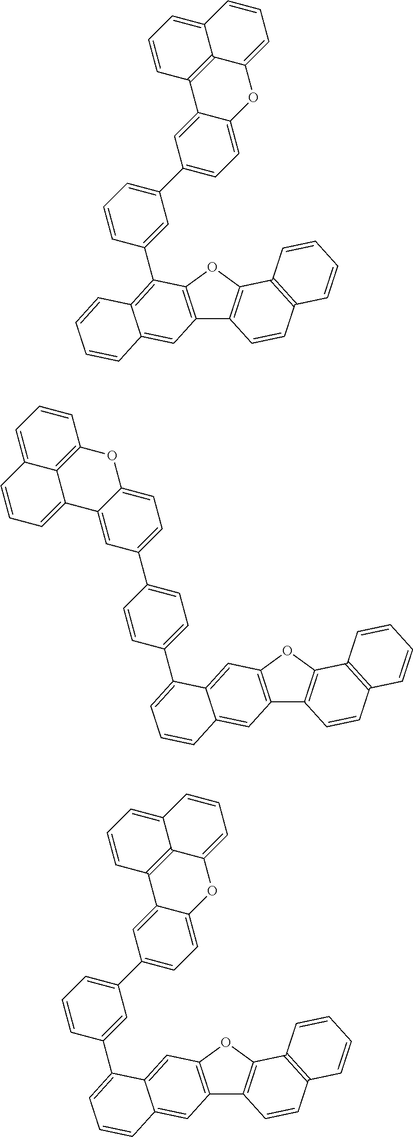 [SMILES: c1cc(-c2ccc3c(c2)-c2cccc4cccc(c24)O3)cc(-c2c3ccccc3cc3c2oc2c4ccccc4ccc32)c1 ; c1cc(-c2ccc(-c3ccc4c(c3)-c3cccc5cccc(c35)O4)cc2)c2cc3oc4c5ccccc5ccc4c3cc2c1 ; c1cc(-c2ccc3c(c2)-c2cccc4cccc(c24)O3)cc(-c2cccc3cc4c(cc23)oc2c3ccccc3ccc42)c1]

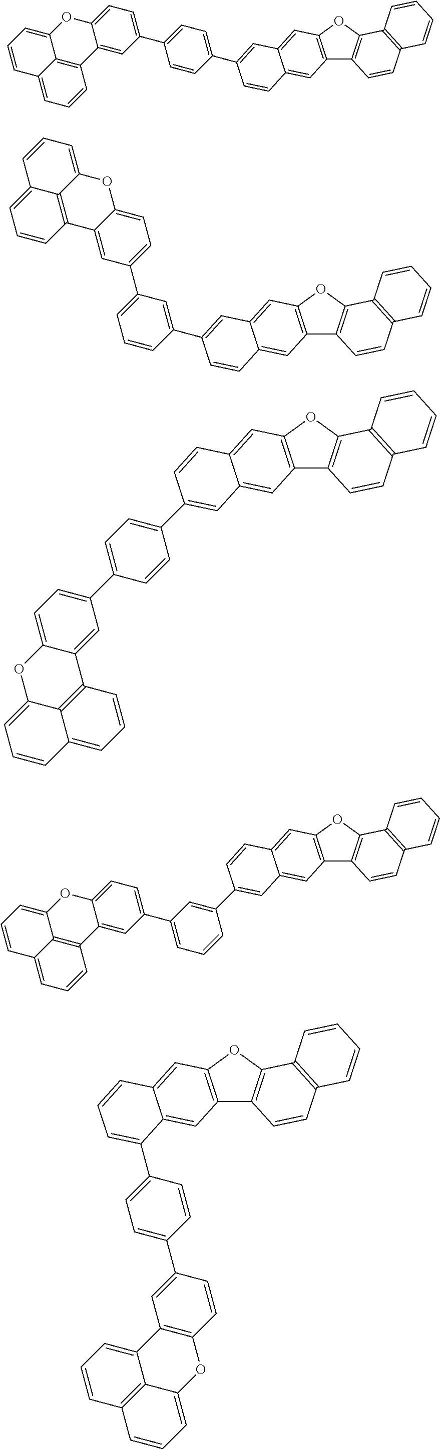

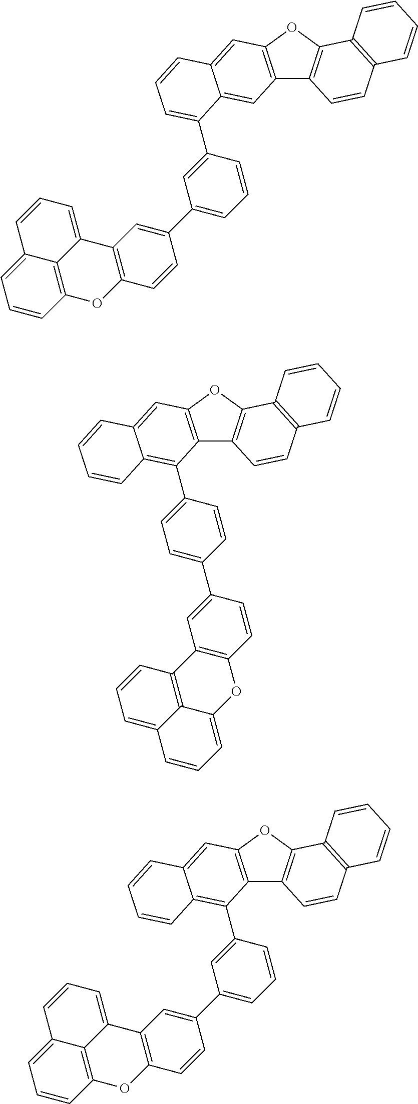 [SMILES: c1cc(-c2ccc3c(c2)-c2cccc4cccc(c24)O3)cc(-c2cccc3cc4oc5c6ccccc6ccc5c4cc23)c1 ; c1ccc2c(-c3ccc(-c4ccc5c(c4)-c4cccc6cccc(c46)O5)cc3)c3c(cc2c1)oc1c2ccccc2ccc13 ; c1cc(-c2ccc3c(c2)-c2cccc4cccc(c24)O3)cc(-c2c3ccccc3cc3oc4c5ccccc5ccc4c23)c1]

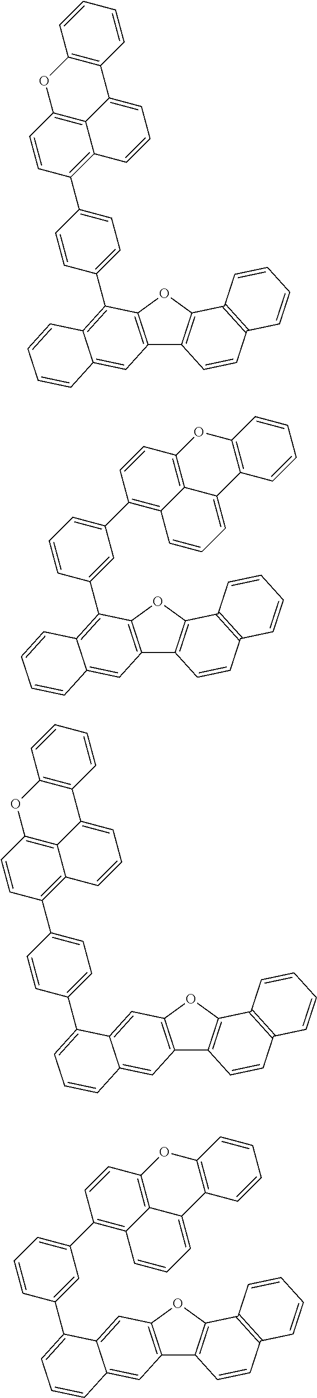

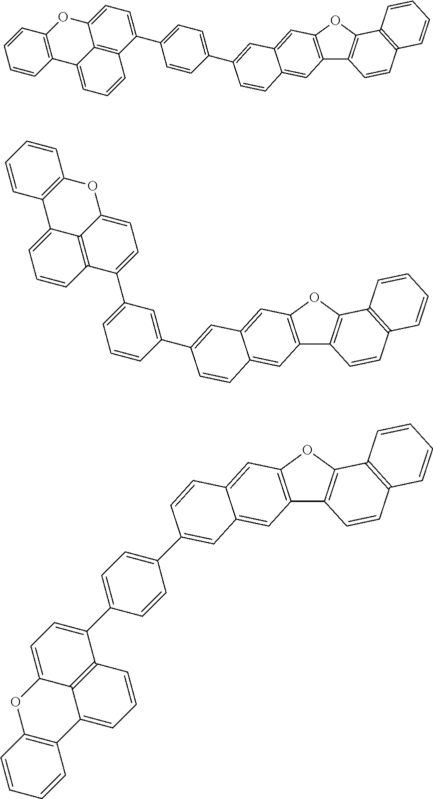 [SMILES: c1ccc2c(c1)Oc1ccc(-c3ccc(-c4ccc5cc6c(cc5c4)oc4c5ccccc5ccc64)cc3)c3cccc-2c13 ; c1cc(-c2ccc3cc4c(cc3c2)oc2c3ccccc3ccc42)cc(-c2ccc3c4c(cccc24)-c2ccccc2O3)c1 ; c1ccc2c(c1)Oc1ccc(-c3ccc(-c4ccc5cc6oc7c8ccccc8ccc7c6cc5c4)cc3)c3cccc-2c13]

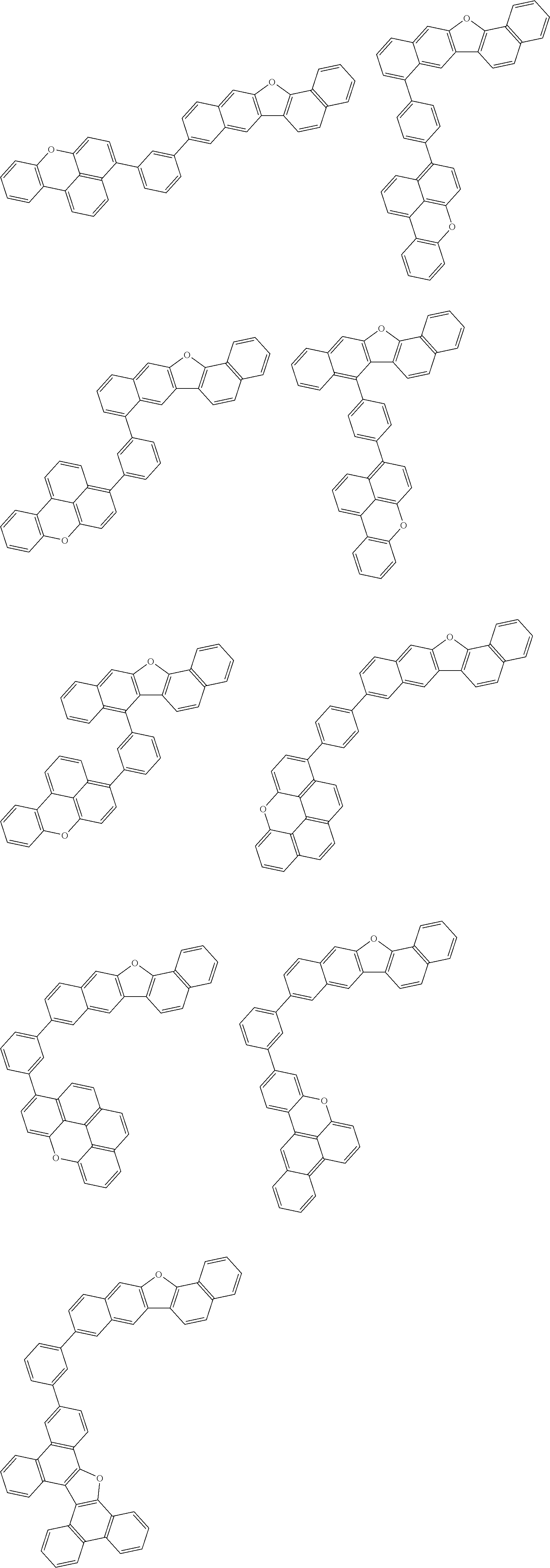

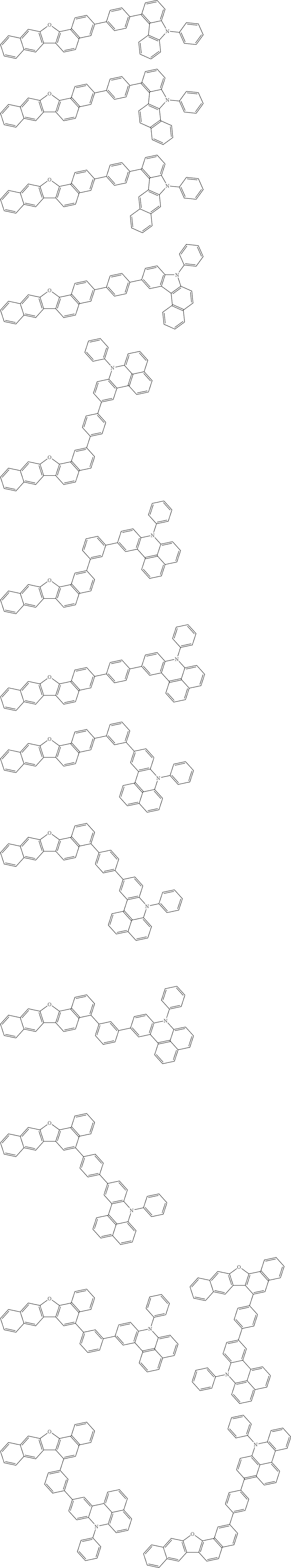

[chemical structure]

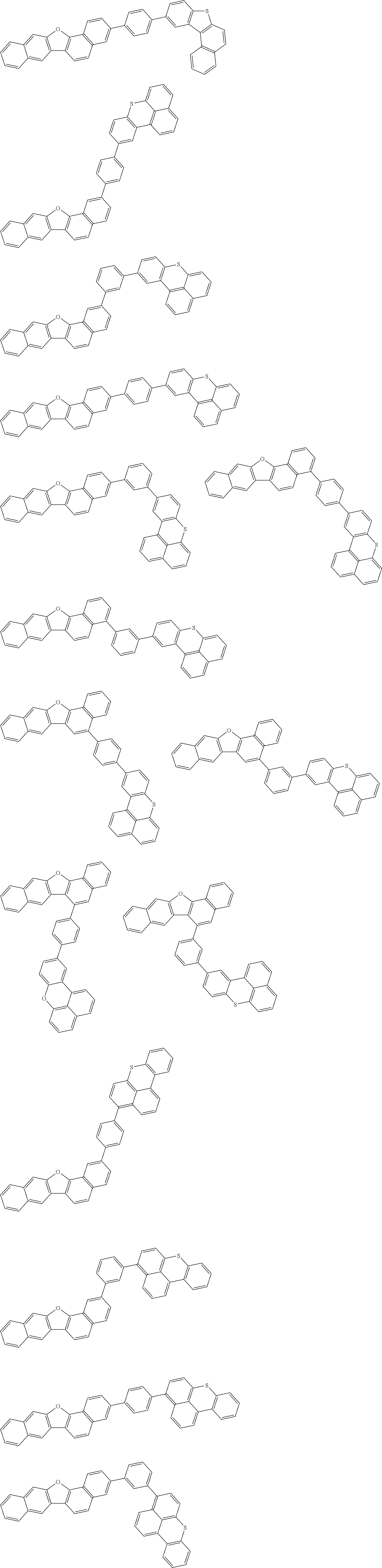

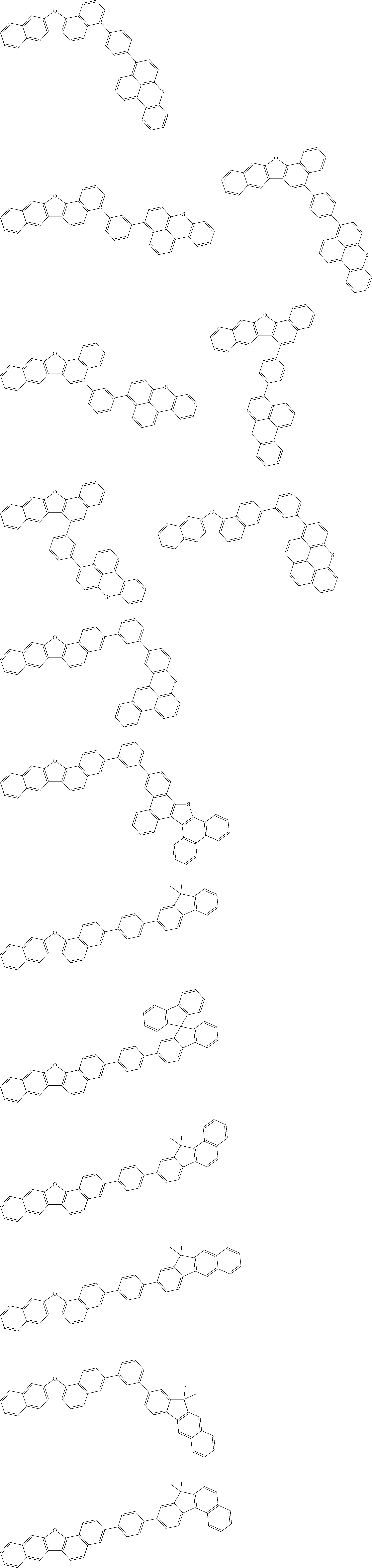

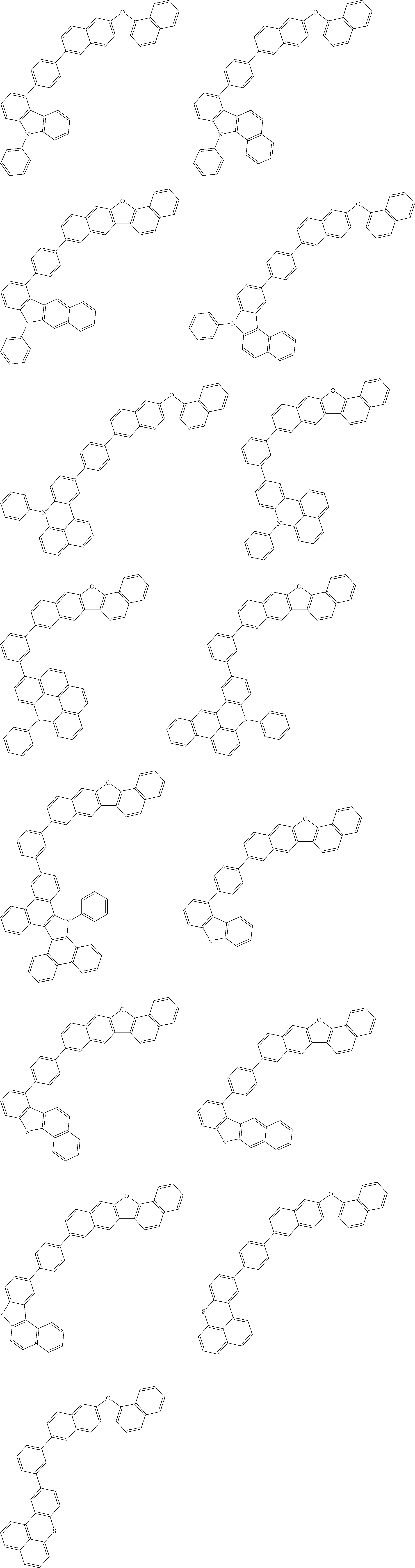

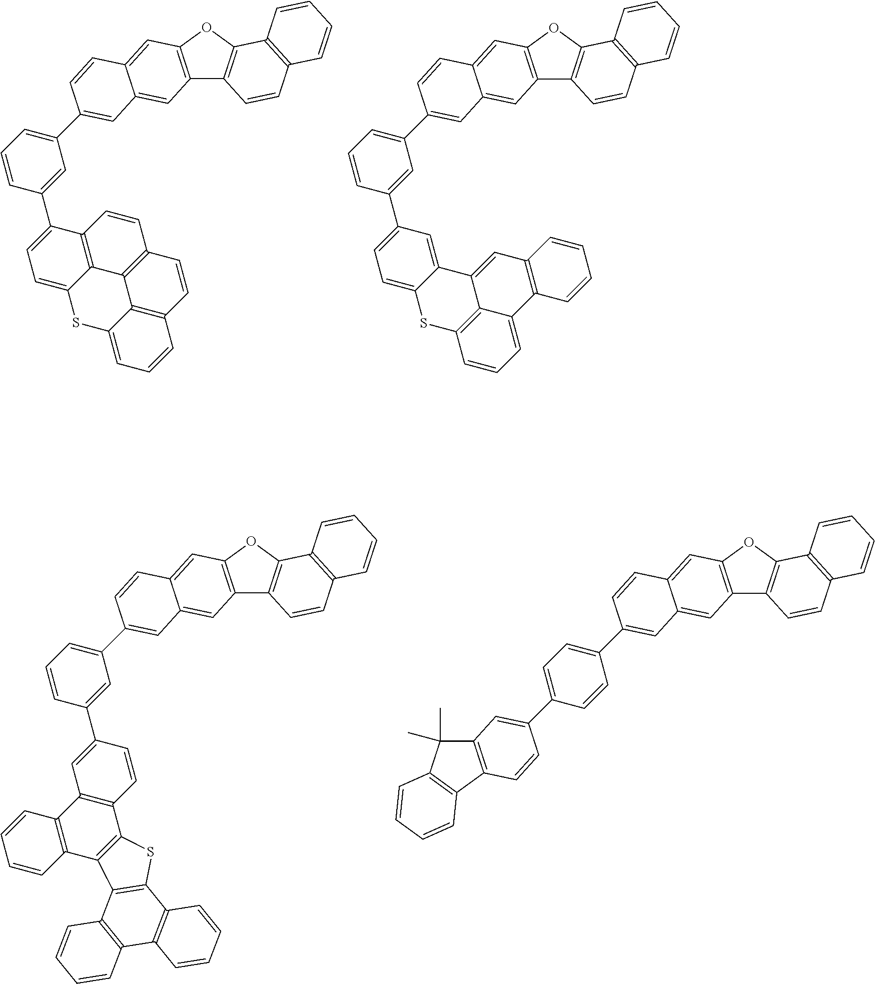 [SMILES: c1cc(-c2ccc3cc4oc5c6ccccc6ccc5c4cc3c2)cc(-c2ccc3c4c2ccc2ccc5cccc(c5c24)S3)c1 ; c1cc(-c2ccc3c(c2)-c2cc4ccccc4c4cccc(c24)S3)cc(-c2ccc3cc4oc5c6ccccc6ccc5c4cc3c2)c1 ; c1cc(-c2ccc3cc4oc5c6ccccc6ccc5c4cc3c2)cc(-c2ccc3c(c2)c2ccccc2c2c3sc3c4ccccc4c4ccccc4c32)c1 ; CC1(C)c2ccccc2-c2ccc(-c3ccc(-c4ccc5cc6oc7c8ccccc8ccc7c6cc5c4)cc3)cc21]

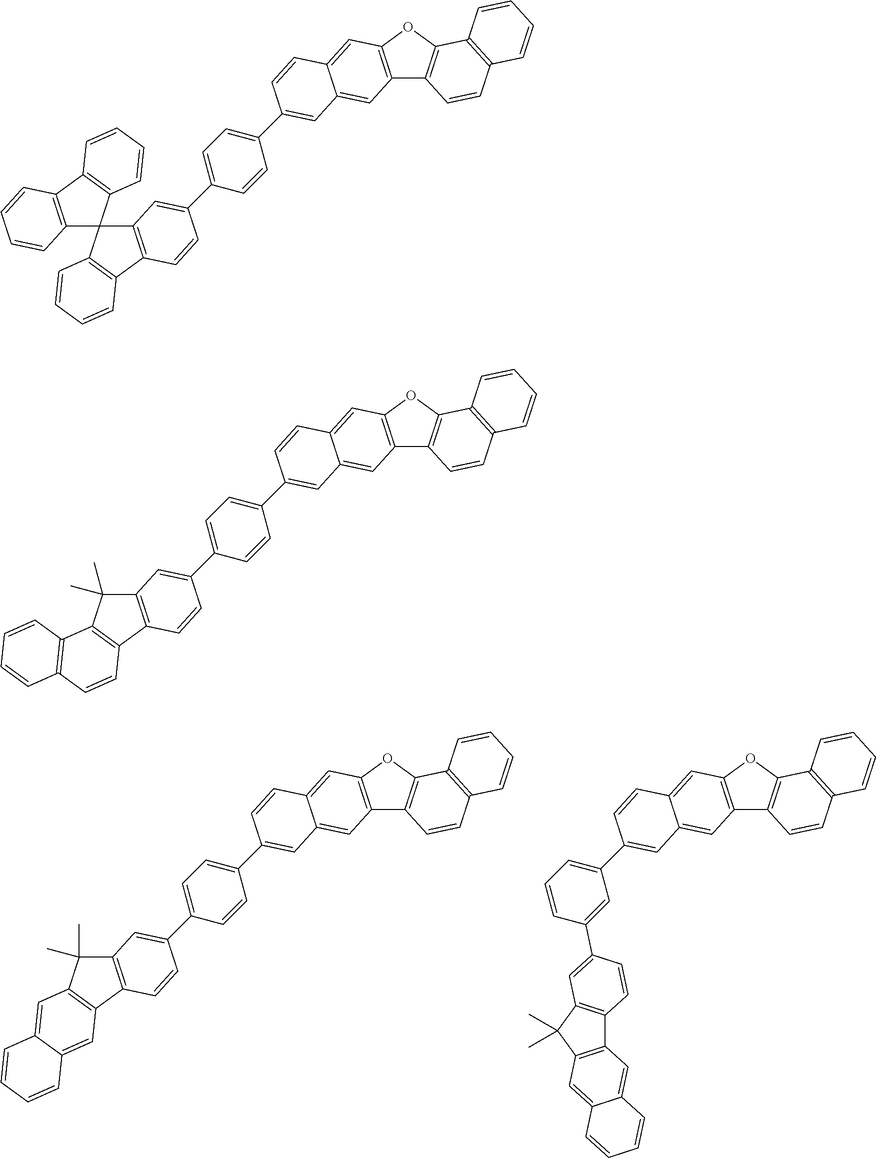 [SMILES: c1ccc2c(c1)-c1ccccc1C21c2ccccc2-c2ccc(-c3ccc(-c4ccc5cc6oc7c8ccccc8ccc7c6cc5c4)cc3)cc21 ; CC1(C)c2cc(-c3ccc(-c4ccc5cc6oc7c8ccccc8ccc7c6cc5c4)cc3)ccc2-c2ccc3ccccc3c21 ; CC1(C)c2cc(-c3ccc(-c4ccc5cc6oc7c8ccccc8ccc7c6cc5c4)cc3)ccc2-c2cc3ccccc3cc21 ; CC1(C)c2cc(-c3cccc(-c4ccc5cc6oc7c8ccccc8ccc7c6cc5c4)c3)ccc2-c2cc3ccccc3cc21]

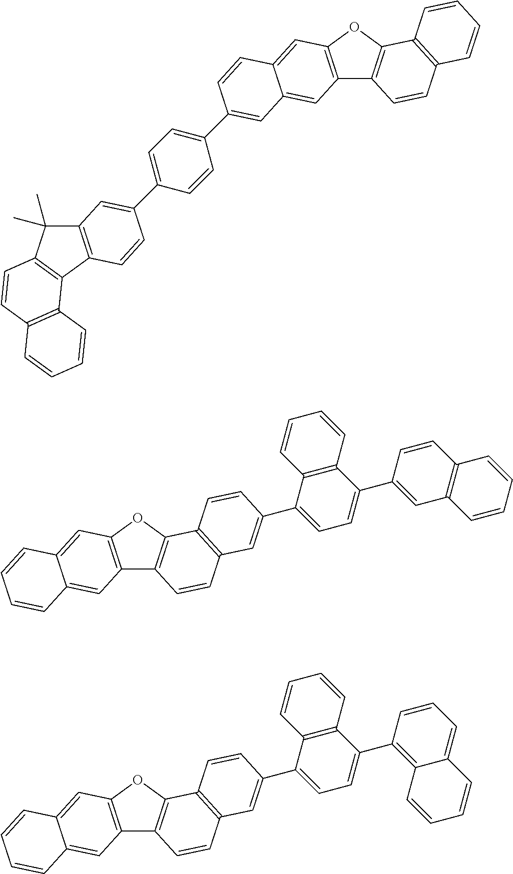 [SMILES: CC1(C)c2cc(-c3ccc(-c4ccc5cc6oc7c8ccccc8ccc7c6cc5c4)cc3)ccc2-c2c1ccc1ccccc21 ; c1ccc2cc(-c3ccc(-c4ccc5c(ccc6c7cc8ccccc8cc7oc56)c4)c4ccccc34)ccc2c1 ; c1ccc2cc3c(cc2c1)oc1c2ccc(-c4ccc(-c5cccc6ccccc56)c5ccccc45)cc2ccc31]

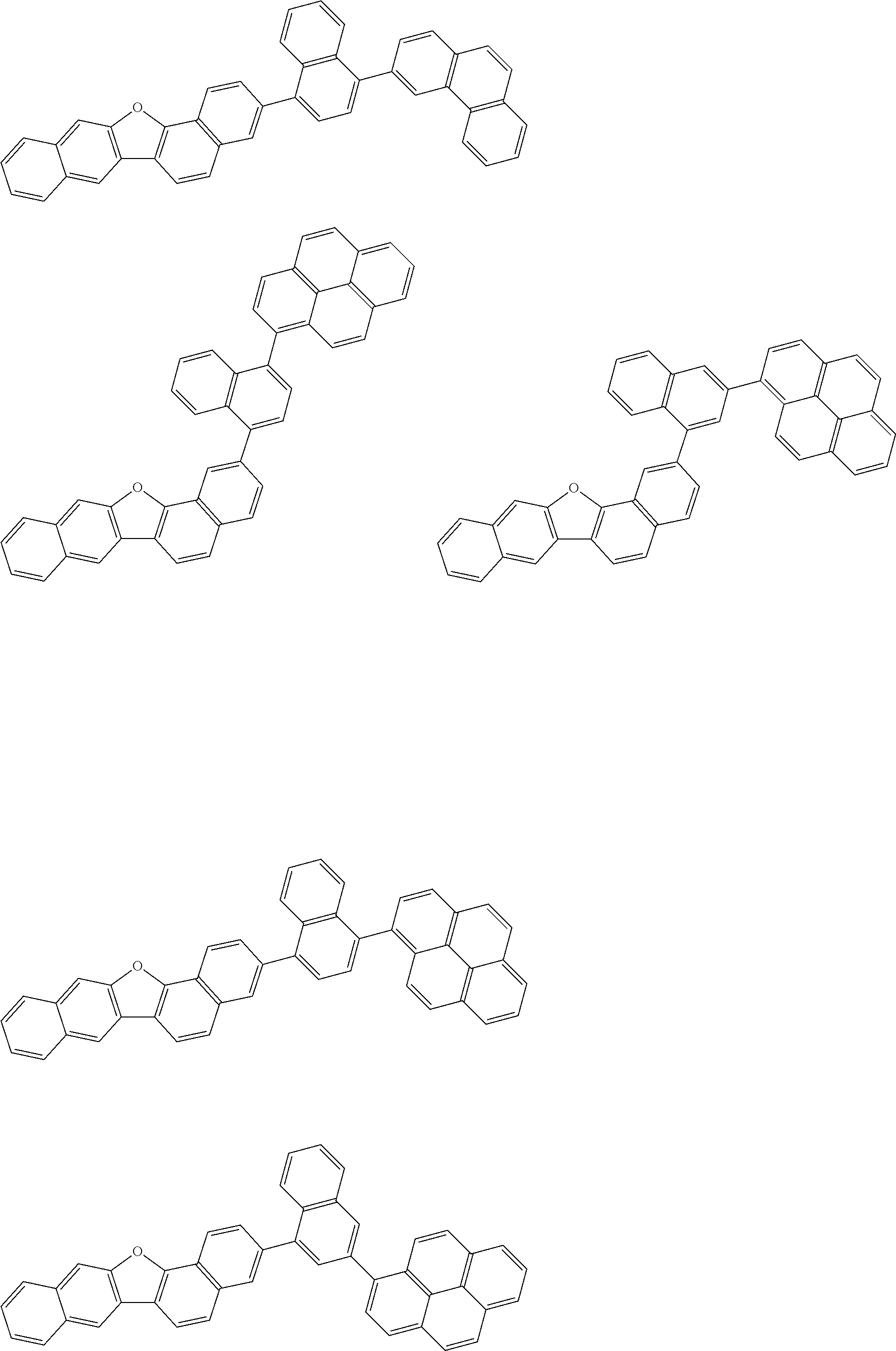 [SMILES: c1ccc2cc3c(cc2c1)oc1c2ccc(-c4ccc(-c5ccc6ccc7ccccc7c6c5)c5ccccc45)cc2ccc31 ; c1ccc2cc3c(cc2c1)oc1c2cc(-c4ccc(-c5ccc6ccc7cccc8ccc5c6c78)c5ccccc45)ccc2ccc31 ; c1ccc2cc3c(cc2c1)oc1c2cc(-c4cc(-c5ccc6ccc7cccc8ccc5c6c78)cc5ccccc45)ccc2ccc31 ; c1ccc2cc3c(cc2c1)oc1c2ccc(-c4ccc(-c5ccc6ccc7cccc8ccc5c6c78)c5ccccc45)cc2ccc31 ; c1ccc2cc3c(cc2c1)oc1c2ccc(-c4cc(-c5ccc6ccc7cccc8ccc5c6c78)cc5ccccc45)cc2ccc31]

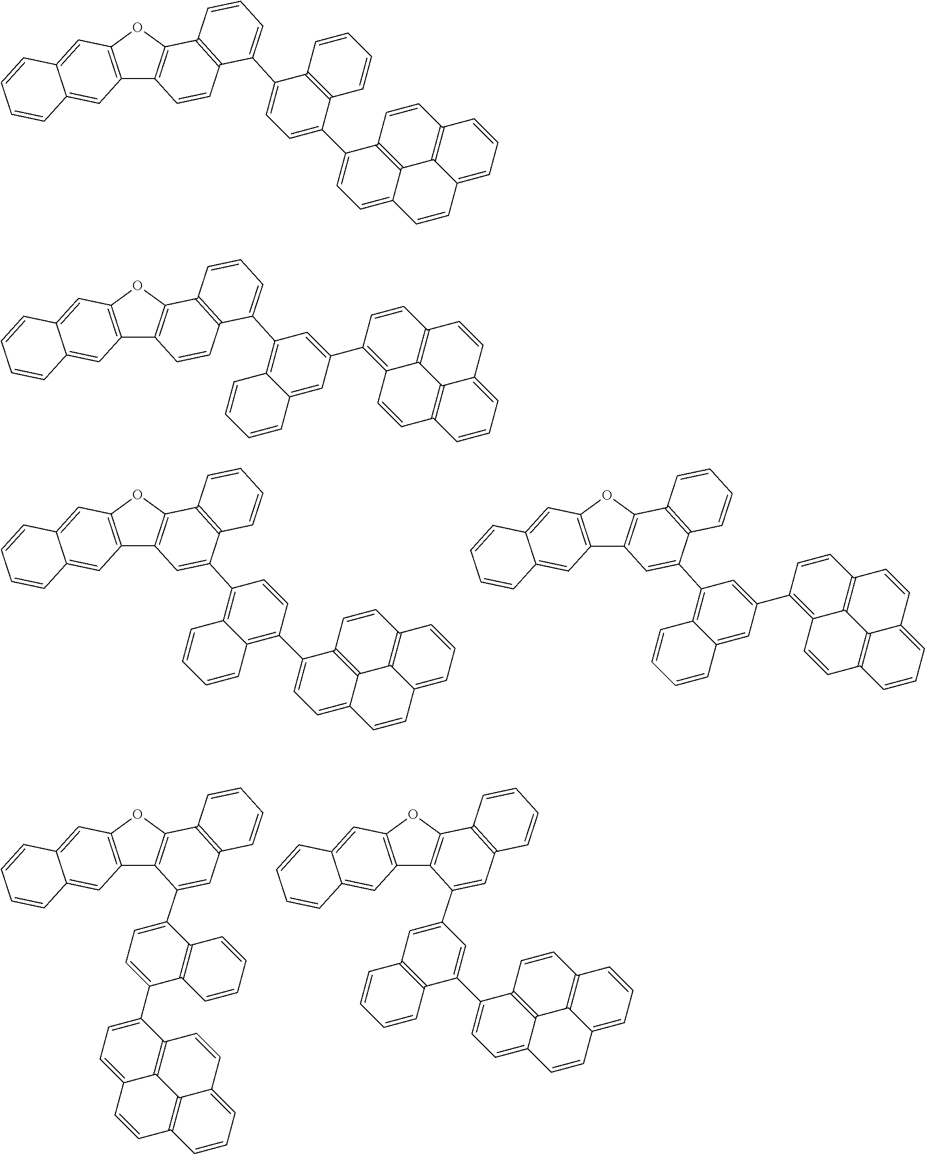

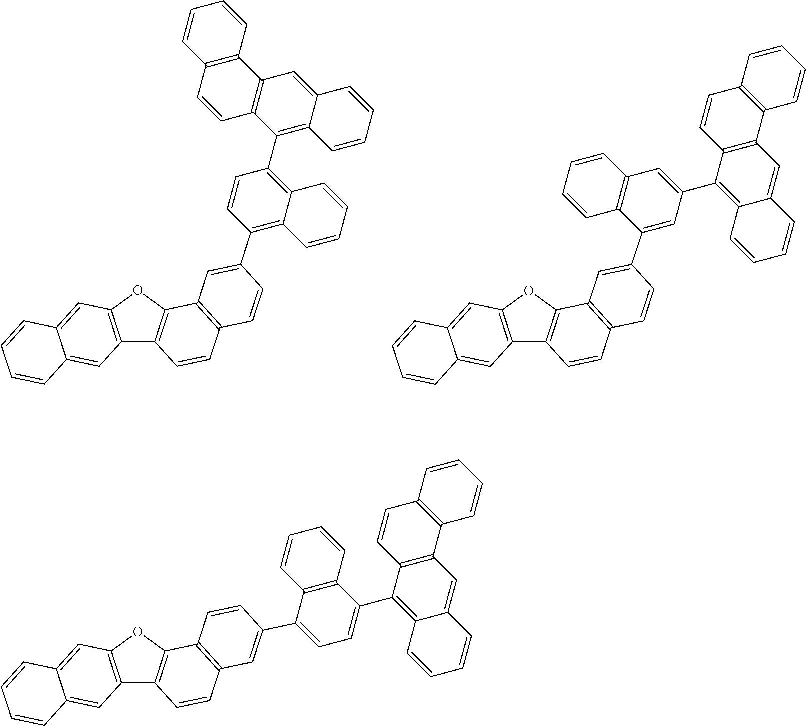 [SMILES: c1ccc2cc3c(cc2c1)oc1c2cc(-c4ccc(-c5c6ccccc6cc6c5ccc5ccccc56)c5ccccc45)ccc2ccc31 ; c1ccc2cc3c(cc2c1)oc1c2cc(-c4cc(-c5c6ccccc6cc6c5ccc5ccccc56)cc5ccccc45)ccc2ccc31 ; c1ccc2cc3c(cc2c1)oc1c2ccc(-c4ccc(-c5c6ccccc6cc6c5ccc5ccccc56)c5ccccc45)cc2ccc31]

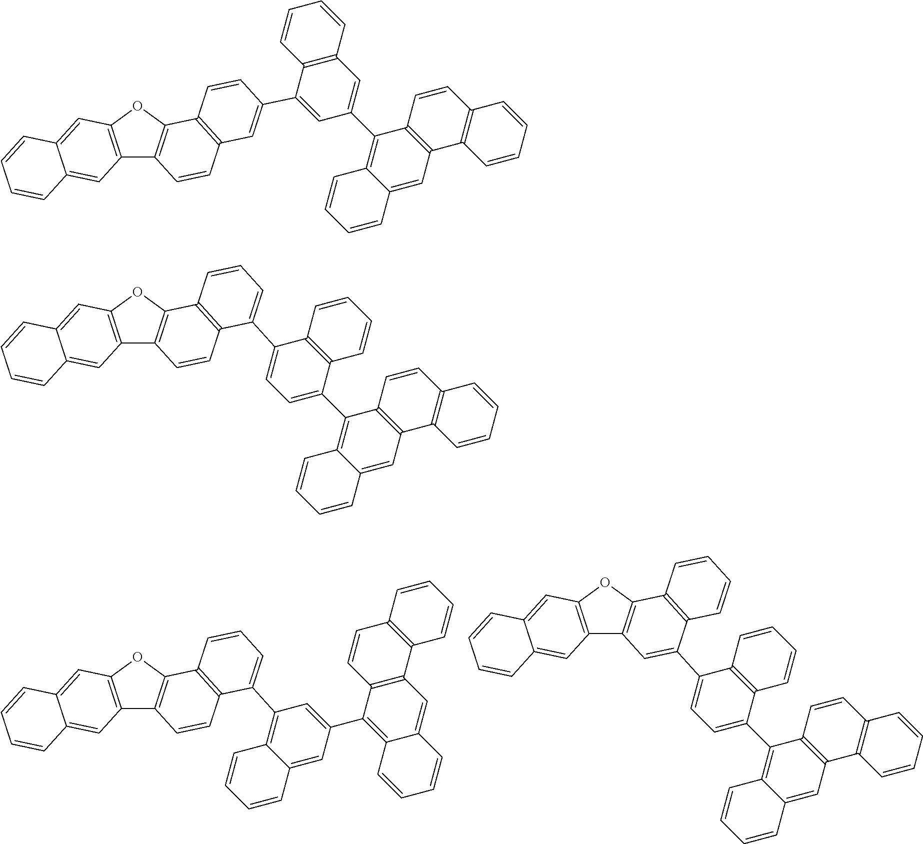

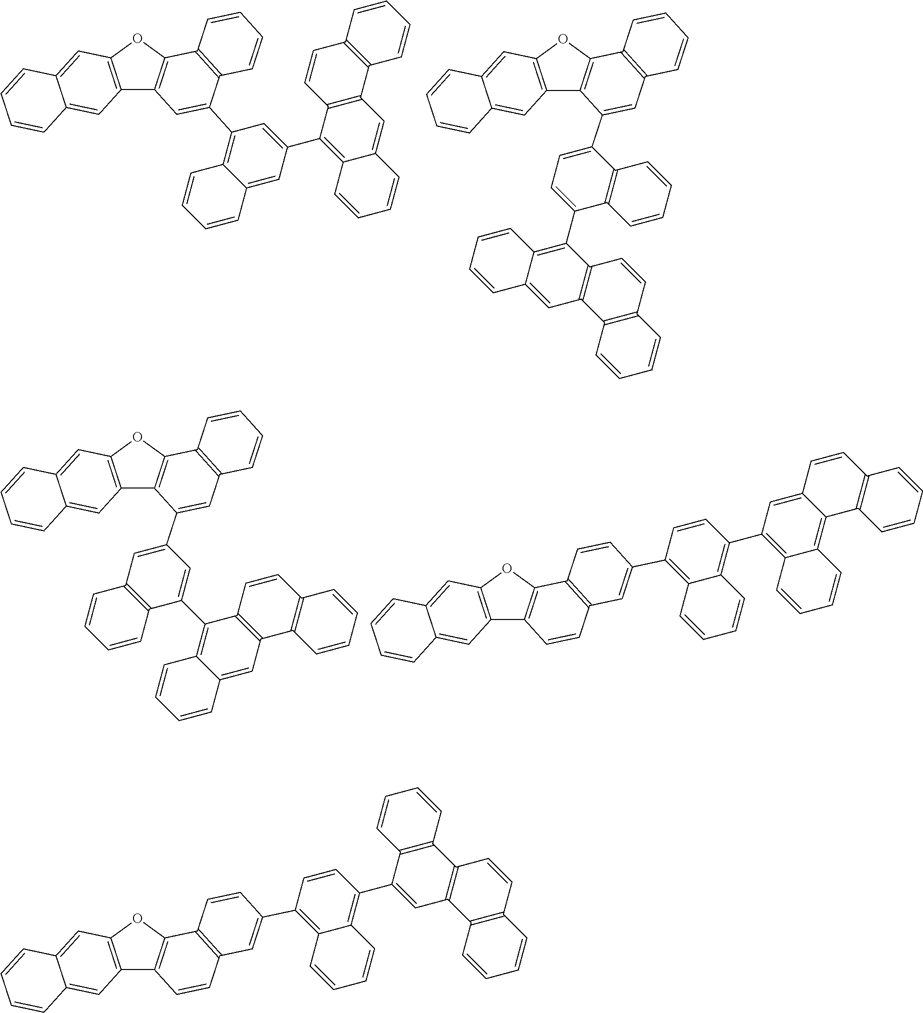

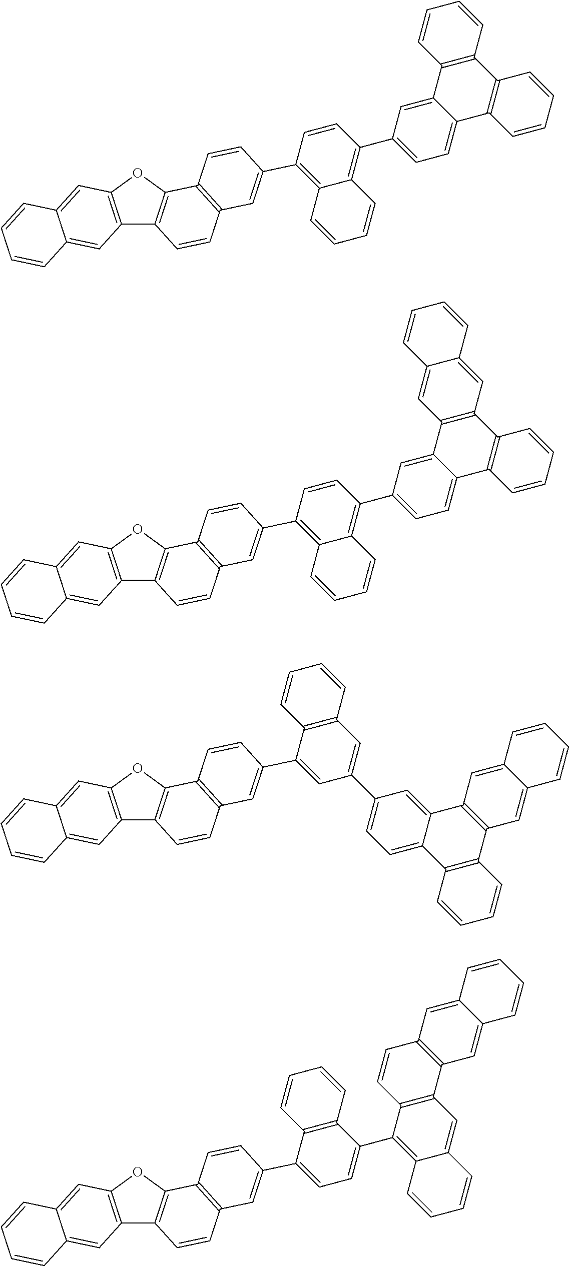

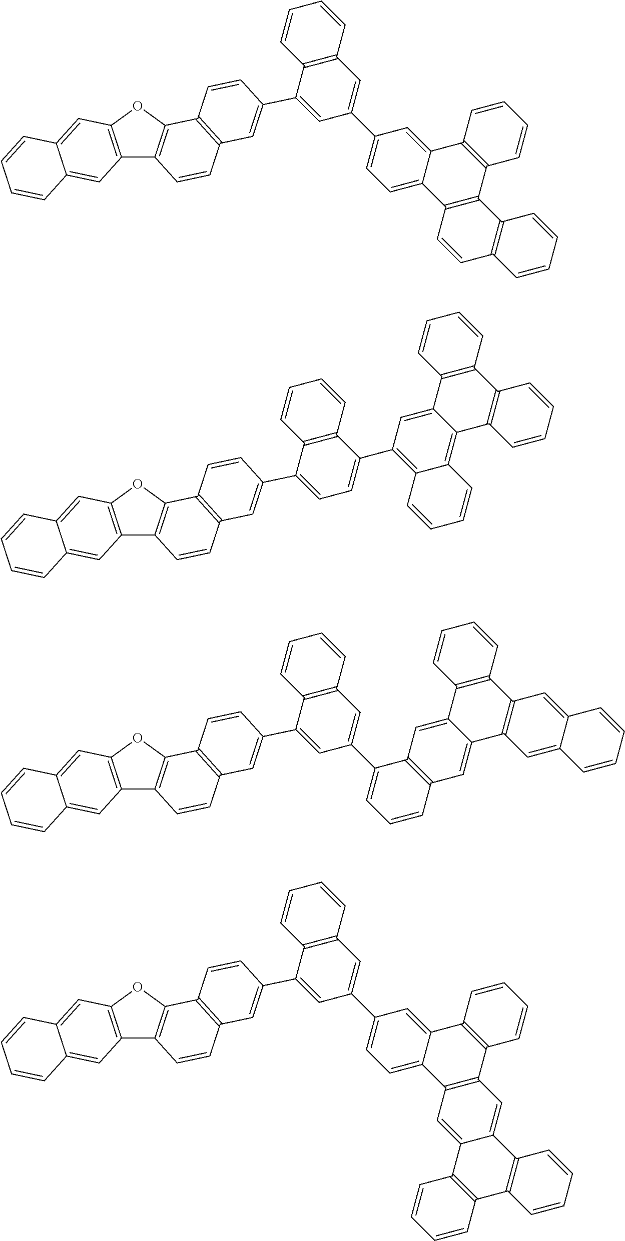 [SMILES: c1ccc2cc3c(cc2c1)oc1c2ccc(-c4cc(-c5ccc6c(c5)c5ccccc5c5c7ccccc7ccc65)cc5ccccc45)cc2ccc31 ; c1ccc2cc3c(cc2c1)oc1c2ccc(-c4ccc(-c5cc6c7ccccc7c7ccccc7c6c6ccccc56)c5ccccc45)cc2ccc31 ; c1ccc2cc3c(cc2c1)oc1c2ccc(-c4cc(-c5cccc6cc7c8cc9ccccc9cc8c8ccccc8c7cc56)cc5ccccc45)cc2ccc31 ; c1ccc2cc3c(cc2c1)oc1c2ccc(-c4cc(-c5ccc6c(c5)c5ccccc5c5cc7c8ccccc8c8ccccc8c7cc65)cc5ccccc45)cc2ccc31]

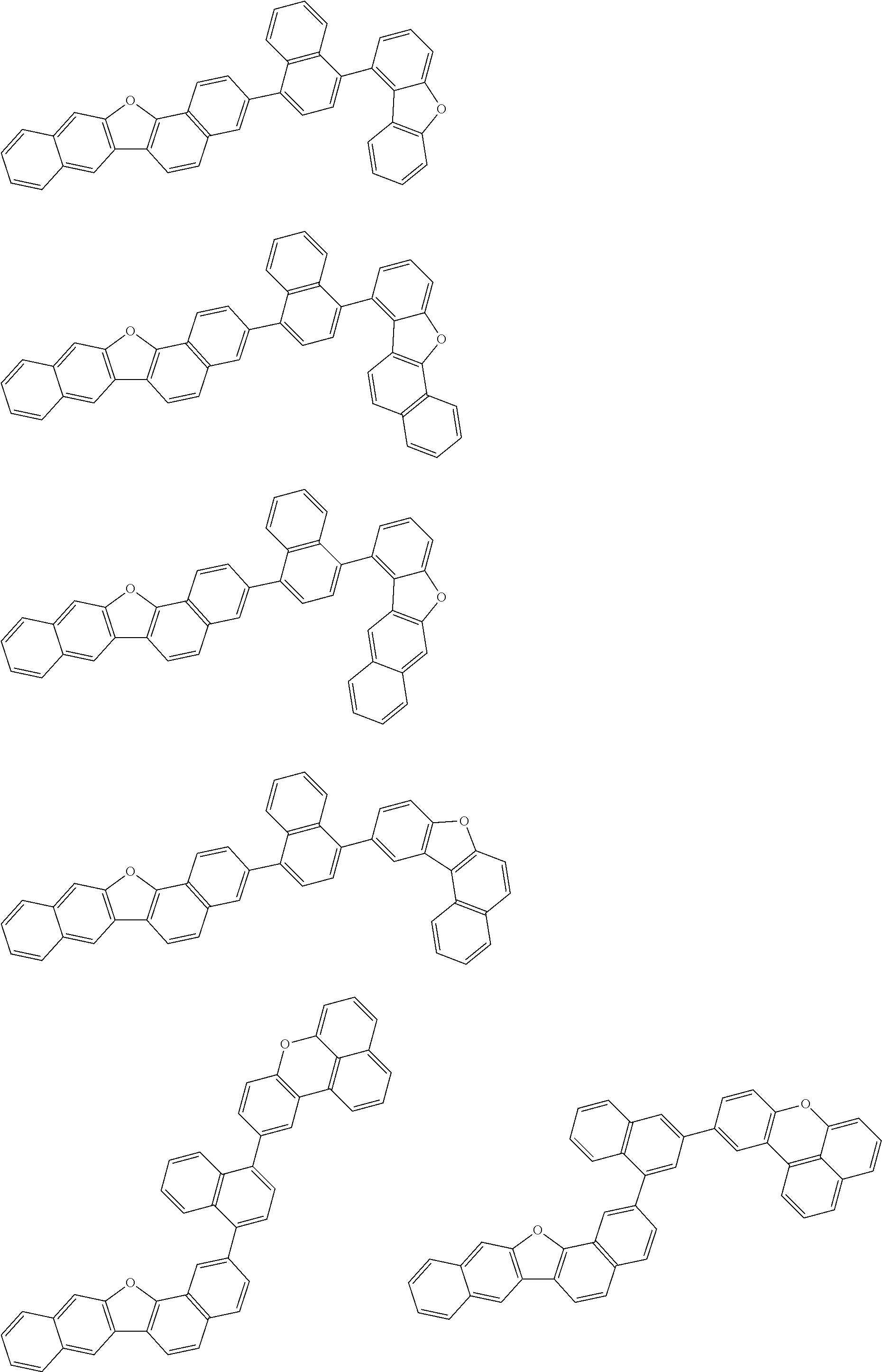 [SMILES: c1ccc2cc3c(cc2c1)oc1c2ccc(-c4ccc(-c5cccc6oc7ccccc7c56)c5ccccc45)cc2ccc31 ; c1ccc2cc3c(cc2c1)oc1c2ccc(-c4ccc(-c5cccc6oc7c8ccccc8ccc7c56)c5ccccc45)cc2ccc31 ; c1ccc2cc3c(cc2c1)oc1c2ccc(-c4ccc(-c5cccc6oc7cc8ccccc8cc7c56)c5ccccc45)cc2ccc31 ; c1ccc2cc3c(cc2c1)oc1c2ccc(-c4ccc(-c5ccc6oc7ccc8ccccc8c7c6c5)c5ccccc45)cc2ccc31 ; c1ccc2cc3c(cc2c1)oc1c2cc(-c4ccc(-c5ccc6c(c5)-c5cccc7cccc(c57)O6)c5ccccc45)ccc2ccc31 ; c1ccc2cc3c(cc2c1)oc1c2cc(-c4cc(-c5ccc6c(c5)-c5cccc7cccc(c57)O6)cc5ccccc45)ccc2ccc31]

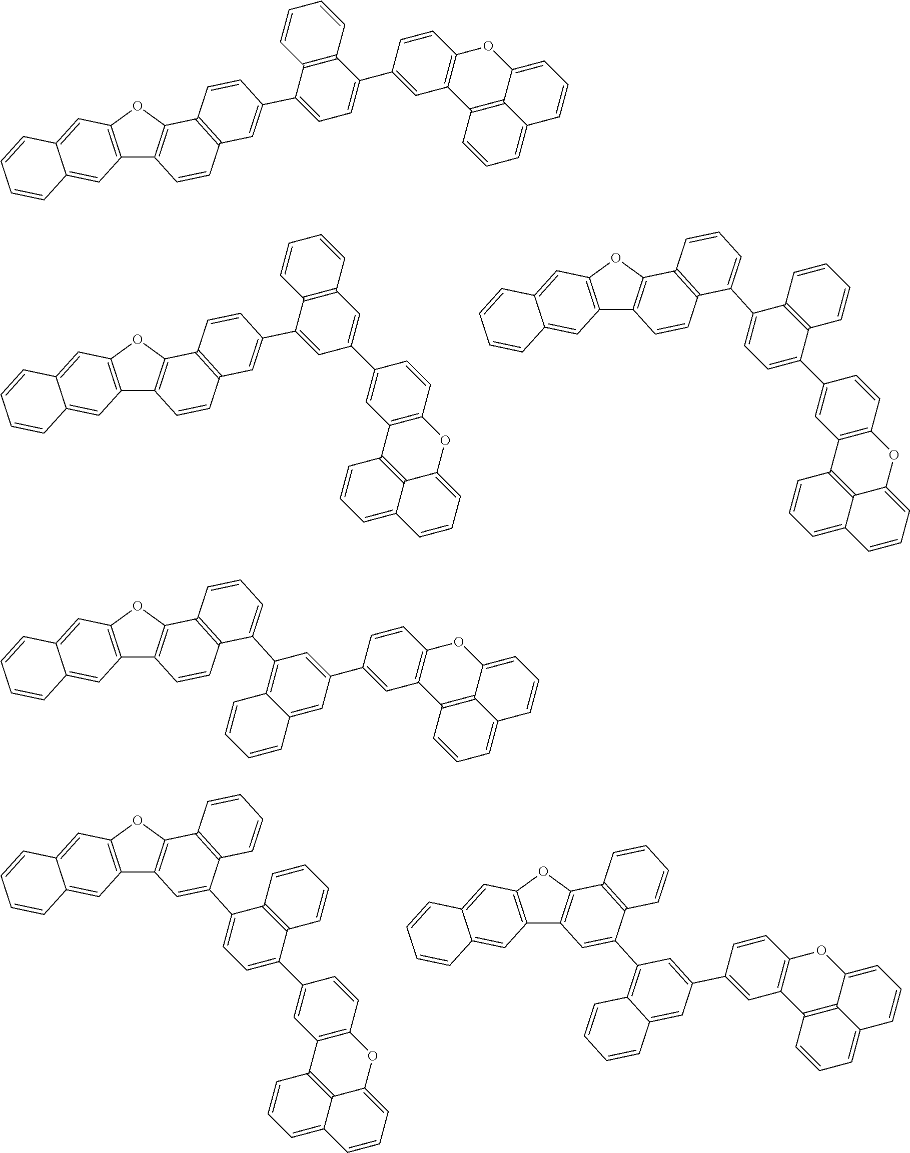

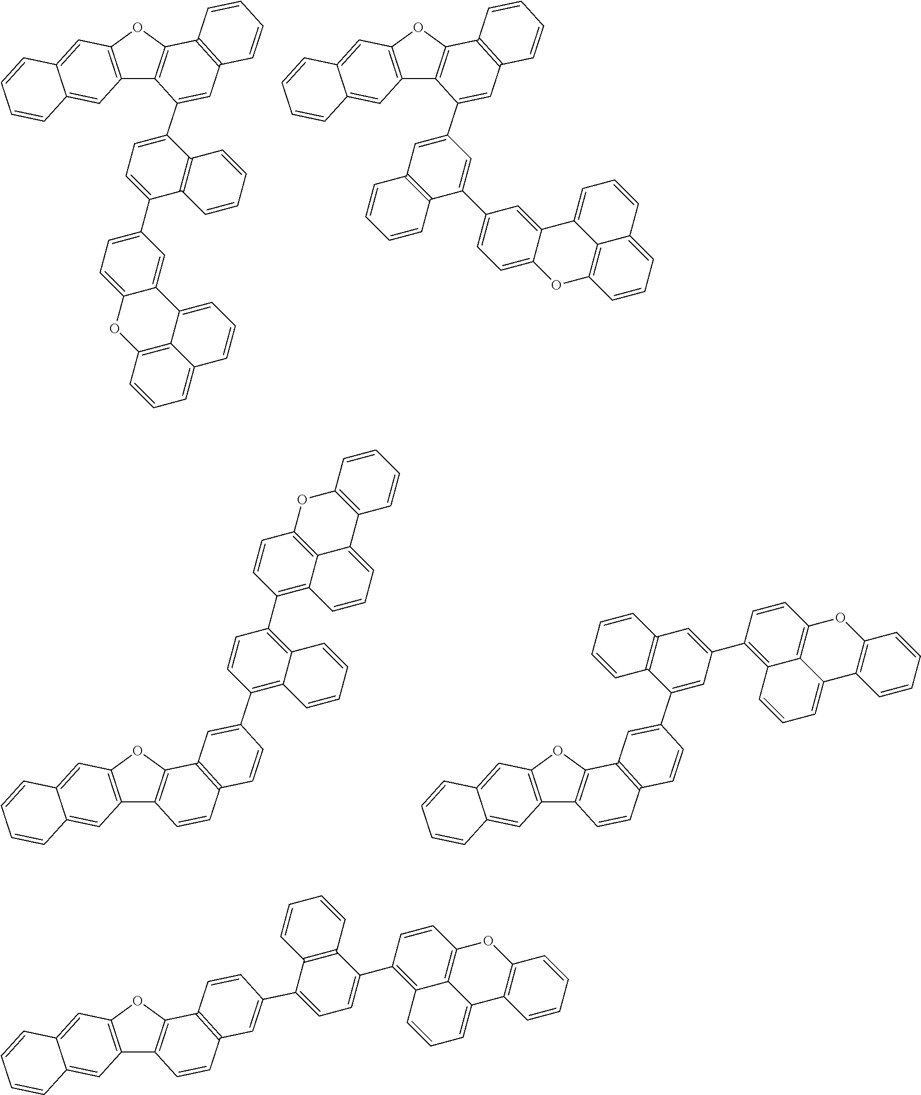

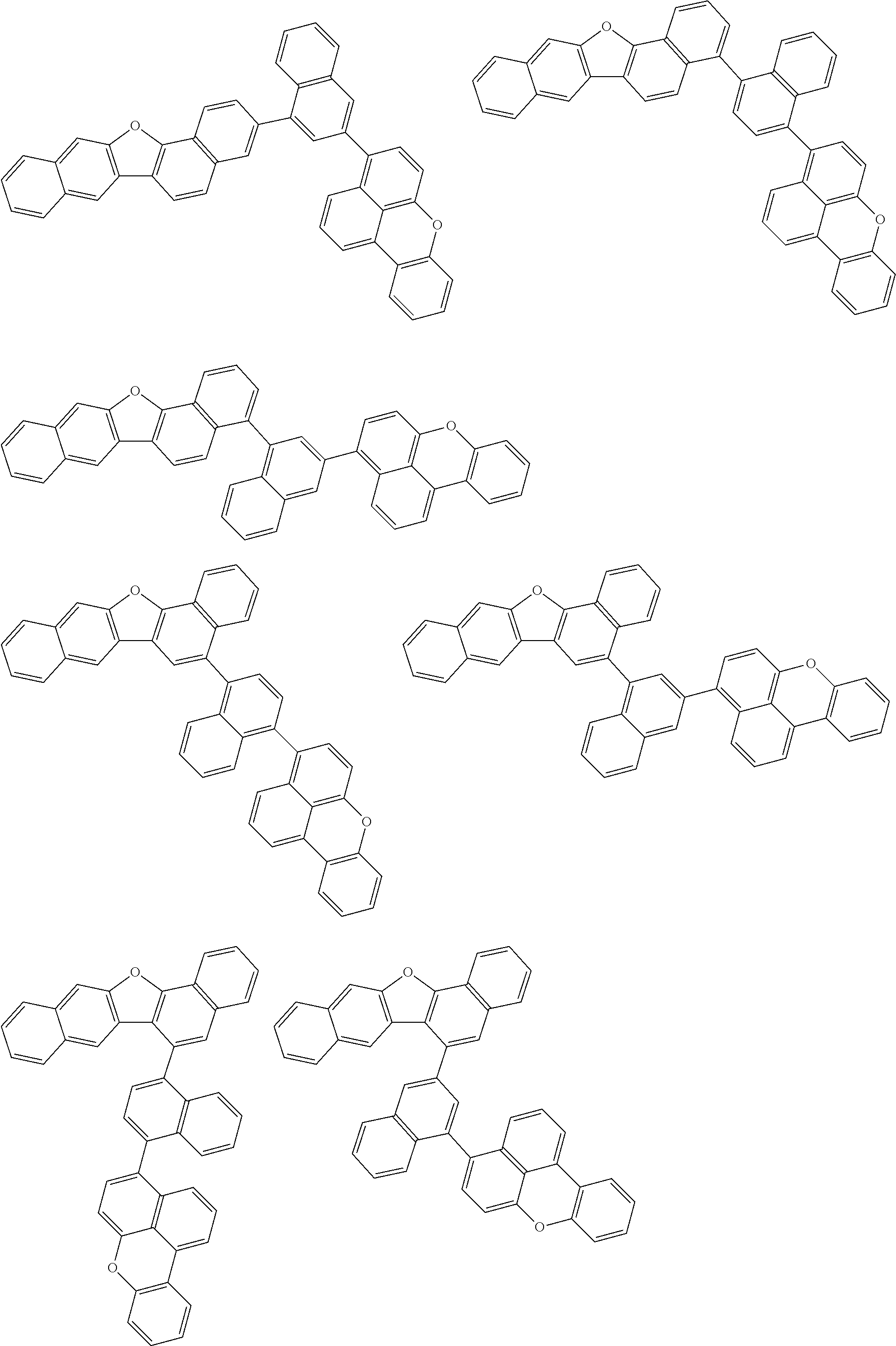

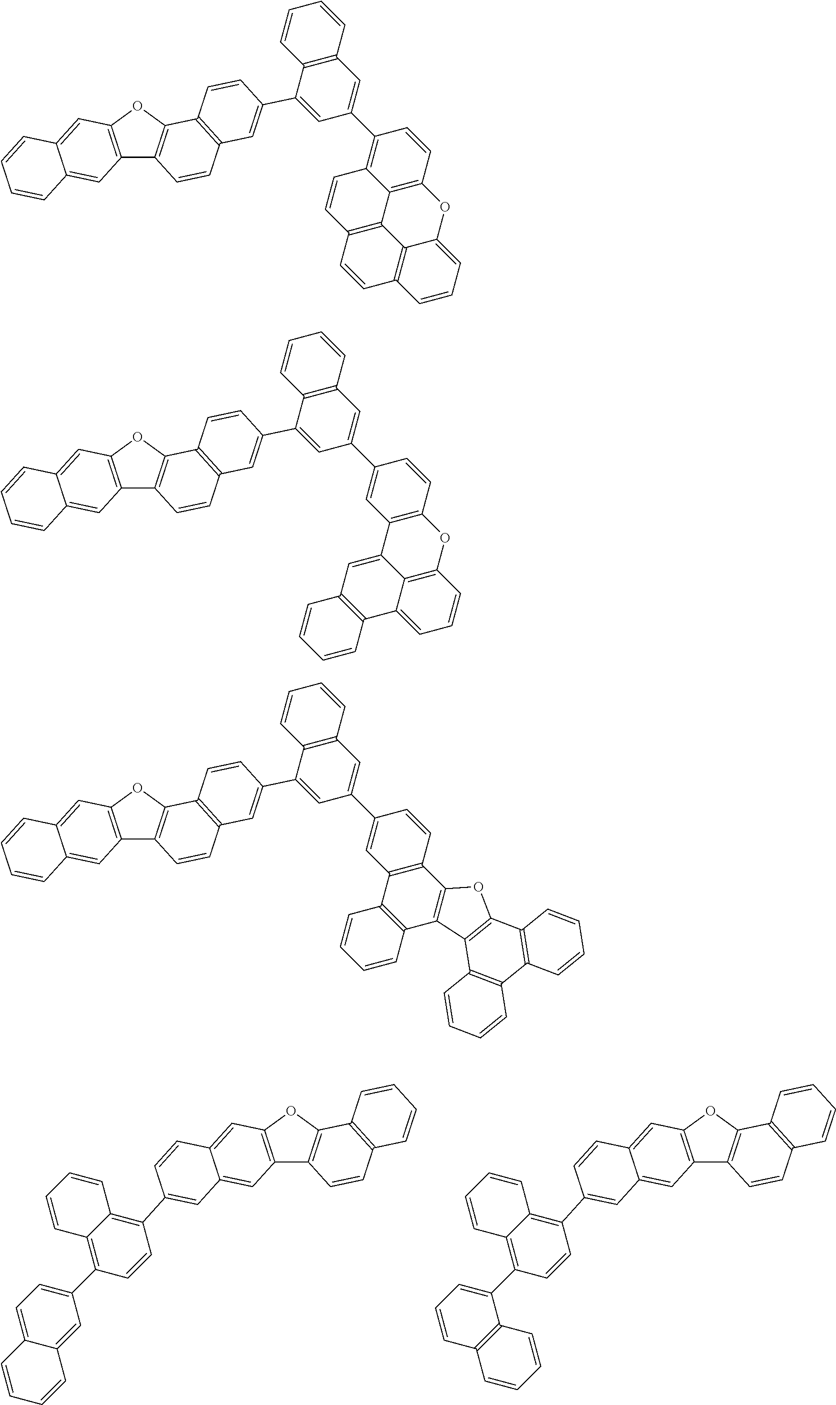

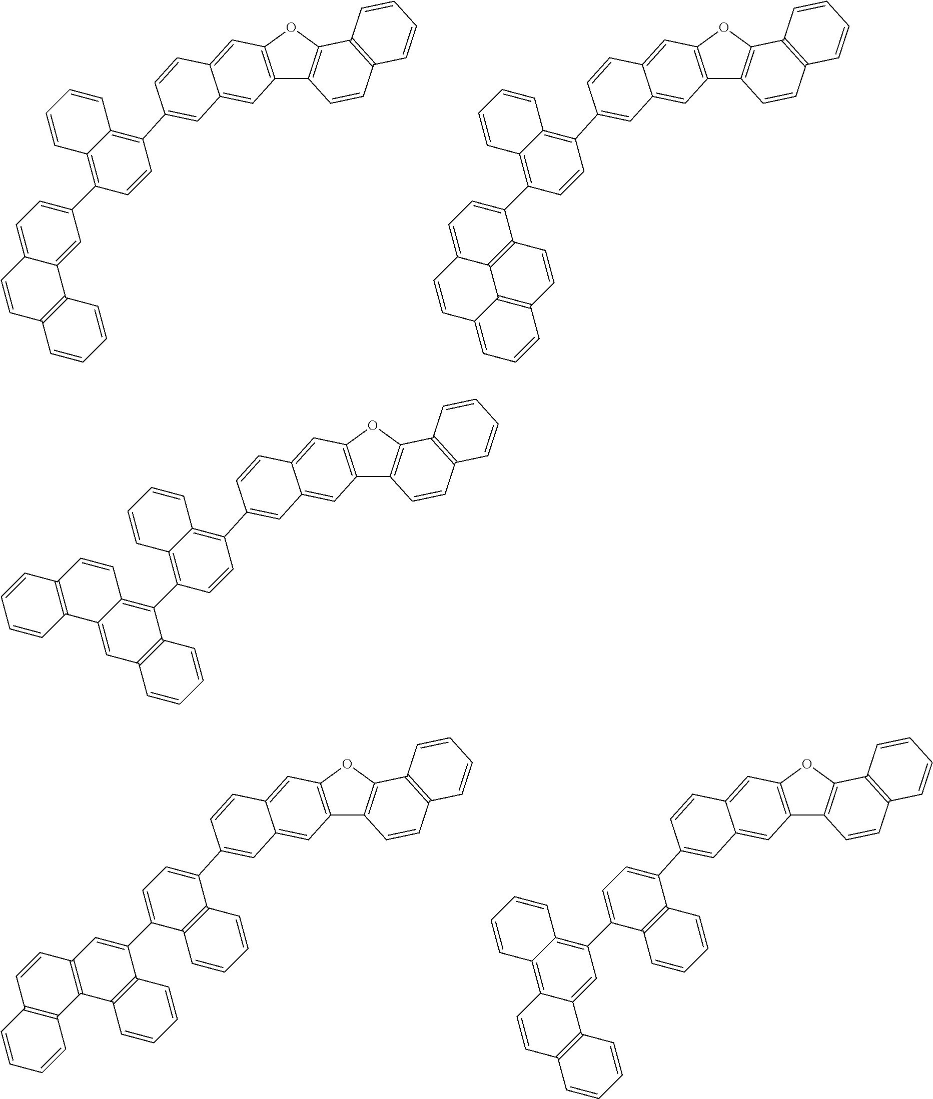

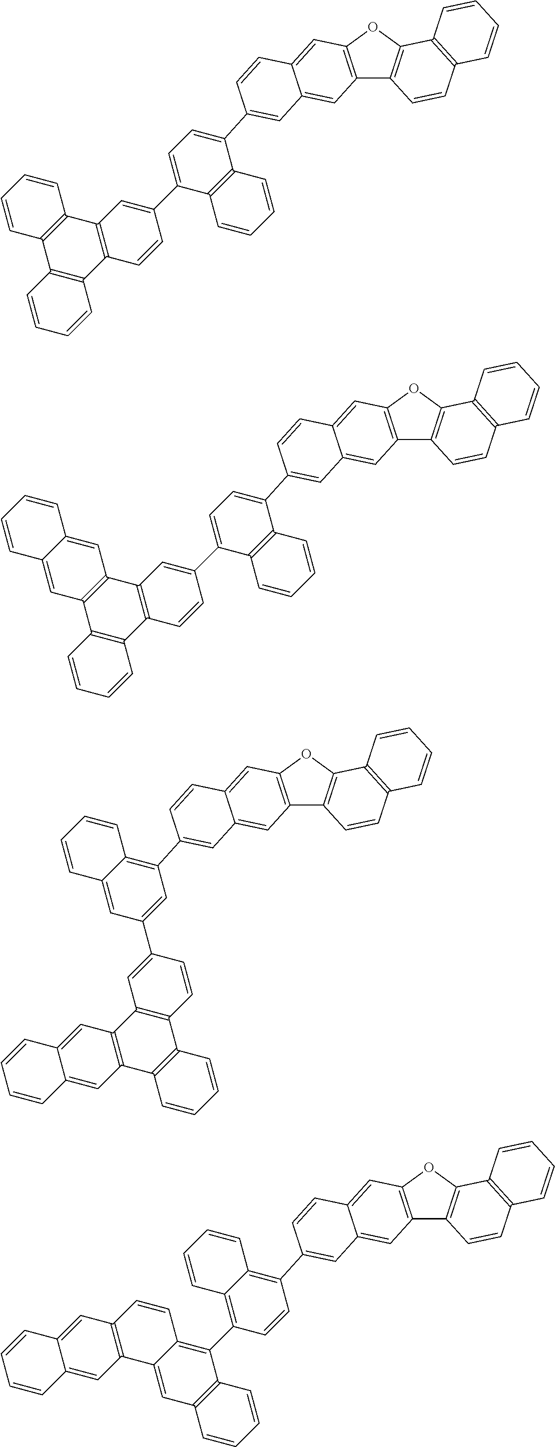 [SMILES: c1ccc2c(c1)ccc1c3cc4cc(-c5ccc(-c6ccc7c8ccccc8c8ccccc8c7c6)c6ccccc56)ccc4cc3oc21 ; c1ccc2cc3c4cc(-c5ccc(-c6ccc7cc8oc9c%10ccccc%10ccc9c8cc7c6)c6ccccc56)ccc4c4ccccc4c3cc2c1 ; c1ccc2cc3c4cc(-c5cc(-c6ccc7cc8oc9c%10ccccc%10ccc9c8cc7c6)c6ccccc6c5)ccc4c4ccccc4c3cc2c1 ; c1ccc2cc3c(ccc4c(-c5ccc(-c6ccc7cc8oc9c%10ccccc%10ccc9c8cc7c6)c6ccccc56)c5ccccc5cc43)cc2c1]

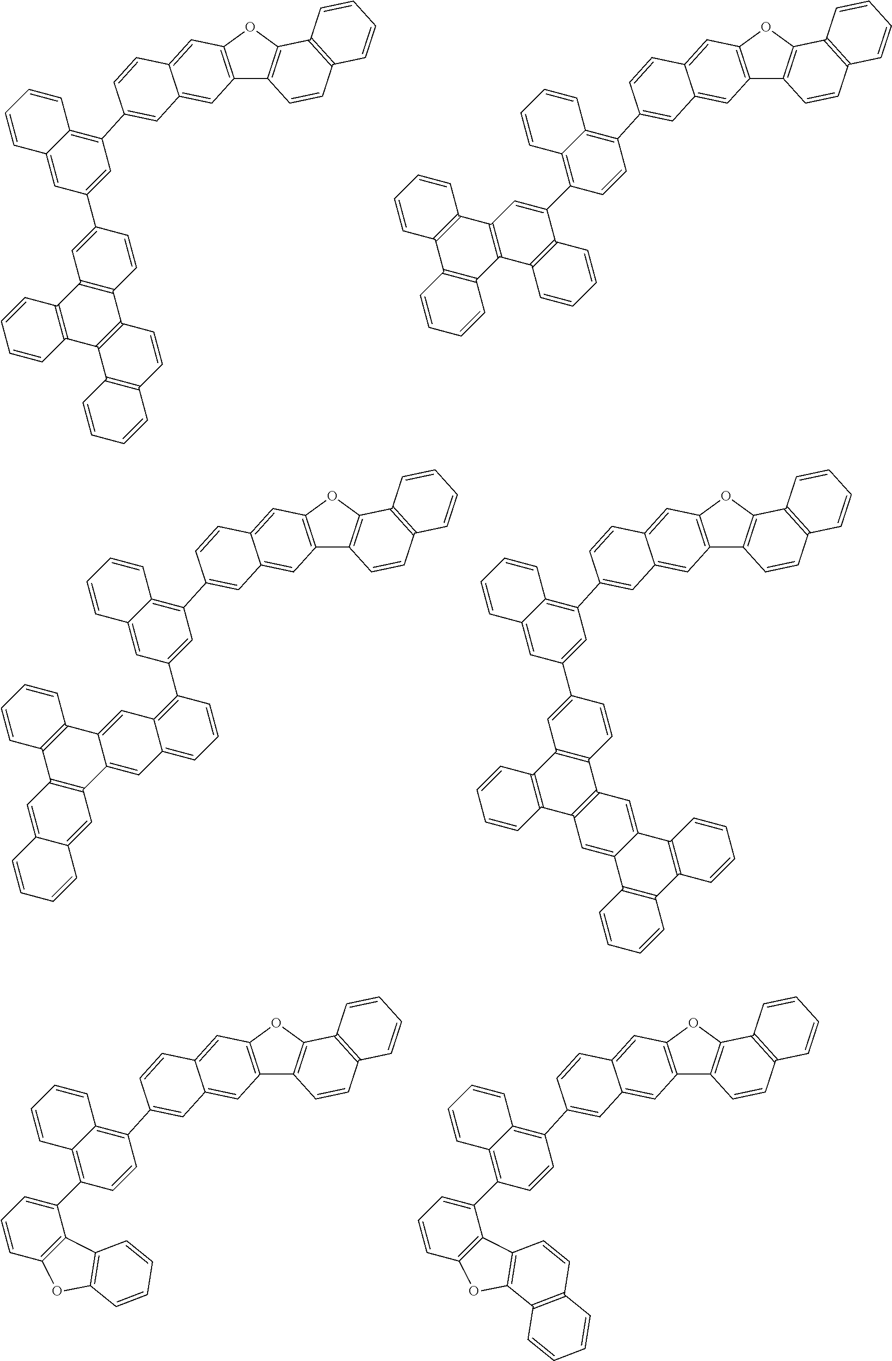

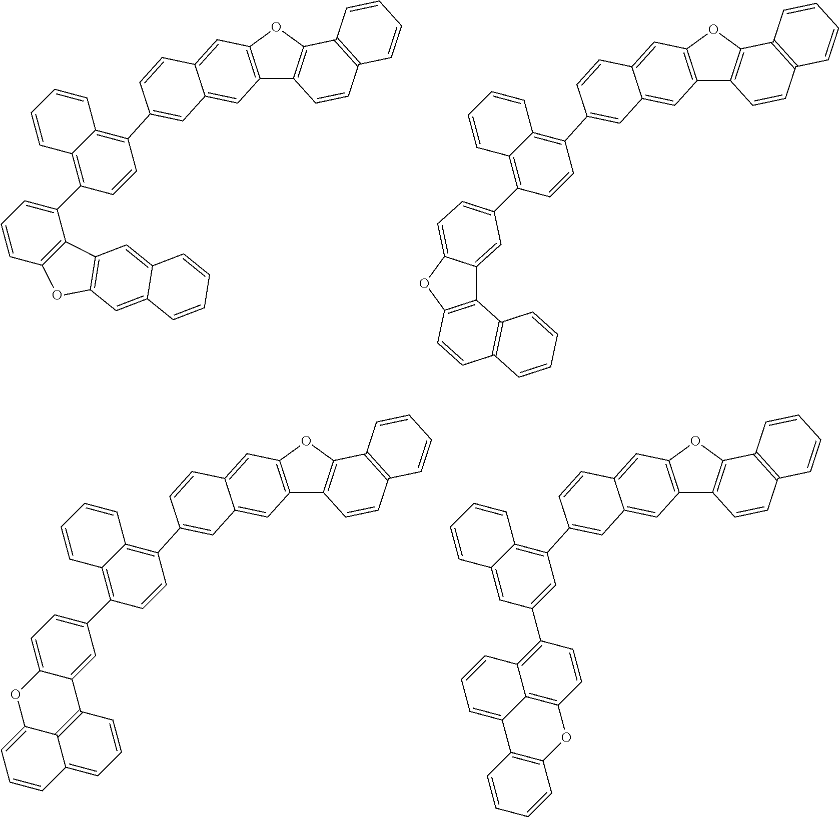 [SMILES: c1ccc2cc3c(cc2c1)oc1cccc(-c2ccc(-c4ccc5cc6oc7c8ccccc8ccc7c6cc5c4)c4ccccc24)c13 ; c1ccc2c(c1)ccc1c3cc4cc(-c5ccc(-c6ccc7oc8ccc9ccccc9c8c7c6)c6ccccc56)ccc4cc3oc21 ; c1cc2c3c(cccc3c1)-c1cc(-c3ccc(-c4ccc5cc6oc7c8ccccc8ccc7c6cc5c4)c4ccccc34)ccc1O2 ; c1ccc2c(c1)Oc1ccc(-c3cc(-c4ccc5cc6oc7c8ccccc8ccc7c6cc5c4)c4ccccc4c3)c3cccc-2c13]

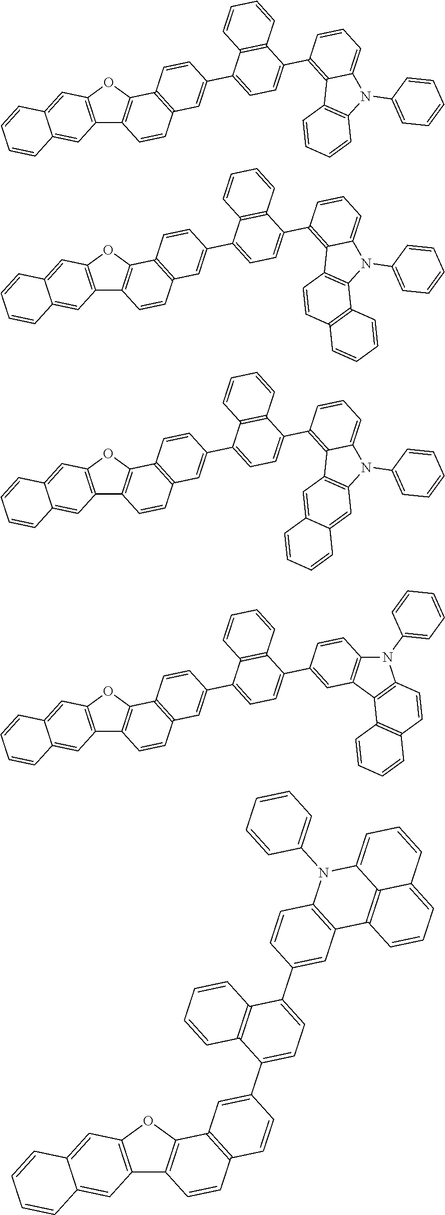 [SMILES: c1ccc(-n2c3ccccc3c3c(-c4ccc(-c5ccc6c(ccc7c8cc9ccccc9cc8oc67)c5)c5ccccc45)cccc32)cc1 ; c1ccc(-n2c3cccc(-c4ccc(-c5ccc6c(ccc7c8cc9ccccc9cc8oc67)c5)c5ccccc45)c3c3ccc4ccccc4c32)cc1 ; c1ccc(-n2c3cc4ccccc4cc3c3c(-c4ccc(-c5ccc6c(ccc7c8cc9ccccc9cc8oc67)c5)c5ccccc45)cccc32)cc1 ; c1ccc(-n2c3ccc(-c4ccc(-c5ccc6c(ccc7c8cc9ccccc9cc8oc67)c5)c5ccccc45)cc3c3c4ccccc4ccc32)cc1 ; c1ccc(N2c3ccc(-c4ccc(-c5ccc6ccc7c8cc9ccccc9cc8oc7c6c5)c5ccccc45)cc3-c3cccc4cccc2c34)cc1]

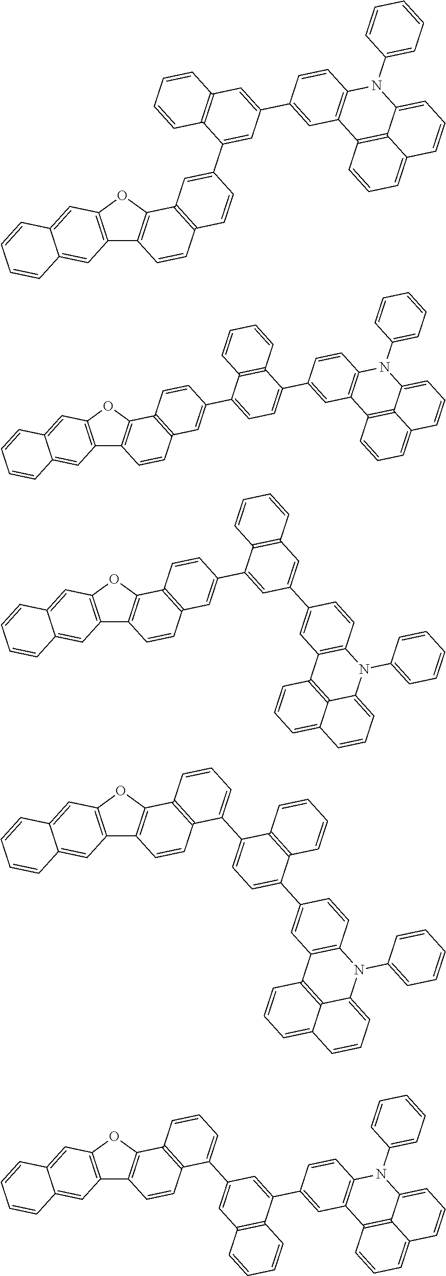 [SMILES: c1ccc(N2c3ccc(-c4cc(-c5ccc6ccc7c8cc9ccccc9cc8oc7c6c5)c5ccccc5c4)cc3-c3cccc4cccc2c34)cc1 ; c1ccc(N2c3ccc(-c4ccc(-c5ccc6c(ccc7c8cc9ccccc9cc8oc67)c5)c5ccccc45)cc3-c3cccc4cccc2c34)cc1 ; c1ccc(N2c3ccc(-c4cc(-c5ccc6c(ccc7c8cc9ccccc9cc8oc67)c5)c5ccccc5c4)cc3-c3cccc4cccc2c34)cc1 ; c1ccc(N2c3ccc(-c4ccc(-c5cccc6c5ccc5c7cc8ccccc8cc7oc65)c5ccccc45)cc3-c3cccc4cccc2c34)cc1 ; c1ccc(N2c3ccc(-c4cc(-c5cccc6c5ccc5c7cc8ccccc8cc7oc65)cc5ccccc45)cc3-c3cccc4cccc2c34)cc1]

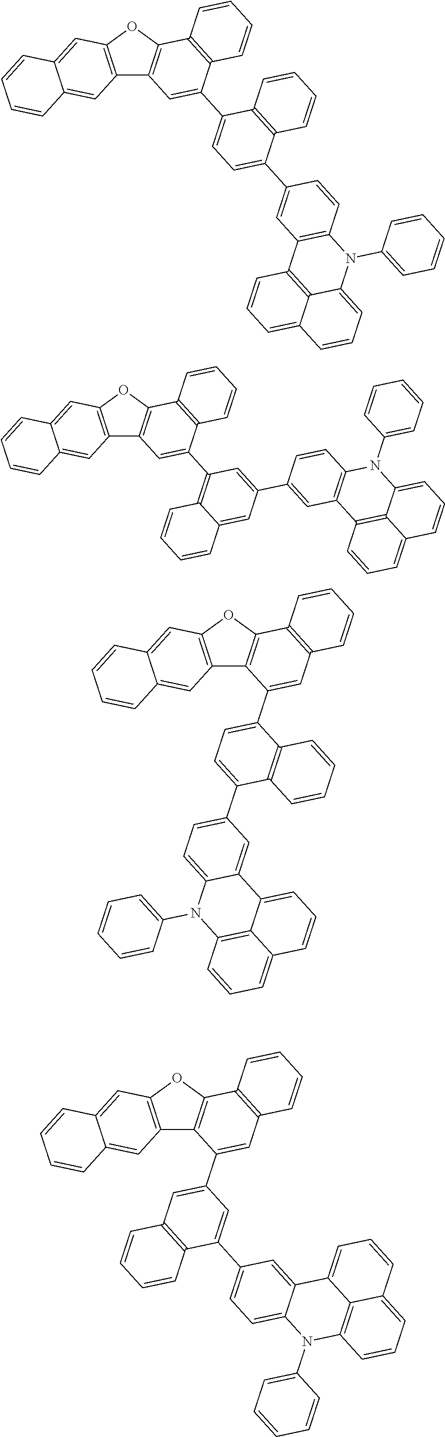

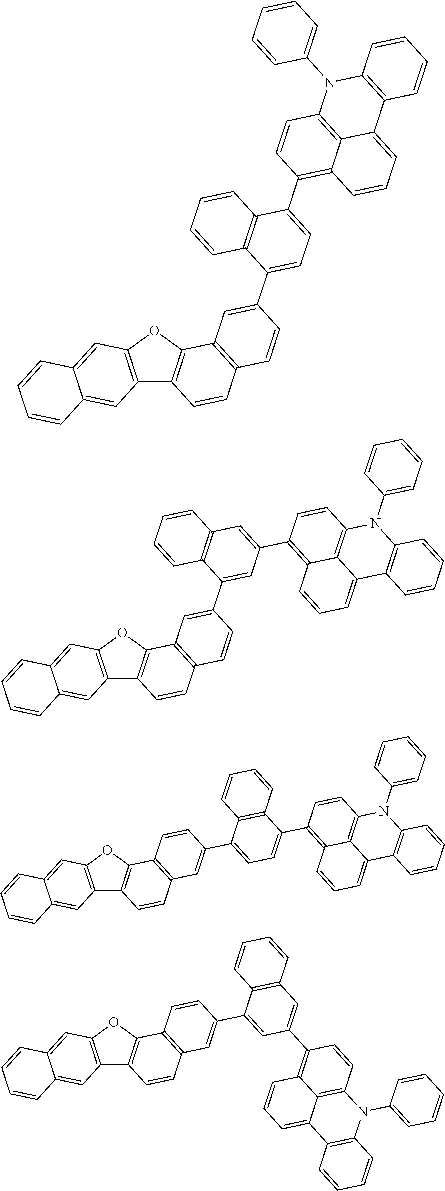 [SMILES: c1ccc(N2c3ccccc3-c3cccc4c(-c5ccc(-c6ccc7ccc8c9cc%10ccccc%10cc9oc8c7c6)c6ccccc56)ccc2c34)cc1 ; c1ccc(N2c3ccccc3-c3cccc4c(-c5cc(-c6ccc7ccc8c9cc%10ccccc%10cc9oc8c7c6)c6ccccc6c5)ccc2c34)cc1 ; c1ccc(N2c3ccccc3-c3cccc4c(-c5ccc(-c6ccc7c(ccc8c9cc%10ccccc%10cc9oc78)c6)c6ccccc56)ccc2c34)cc1 ; c1ccc(N2c3ccccc3-c3cccc4c(-c5cc(-c6ccc7c(ccc8c9cc%10ccccc%10cc9oc78)c6)c6ccccc6c5)ccc2c34)cc1]

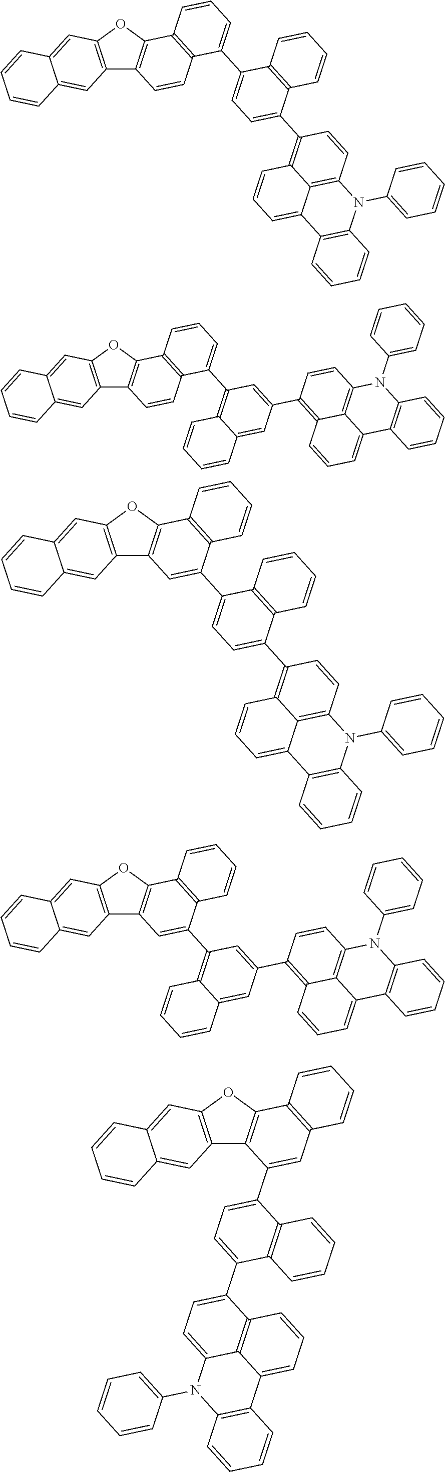

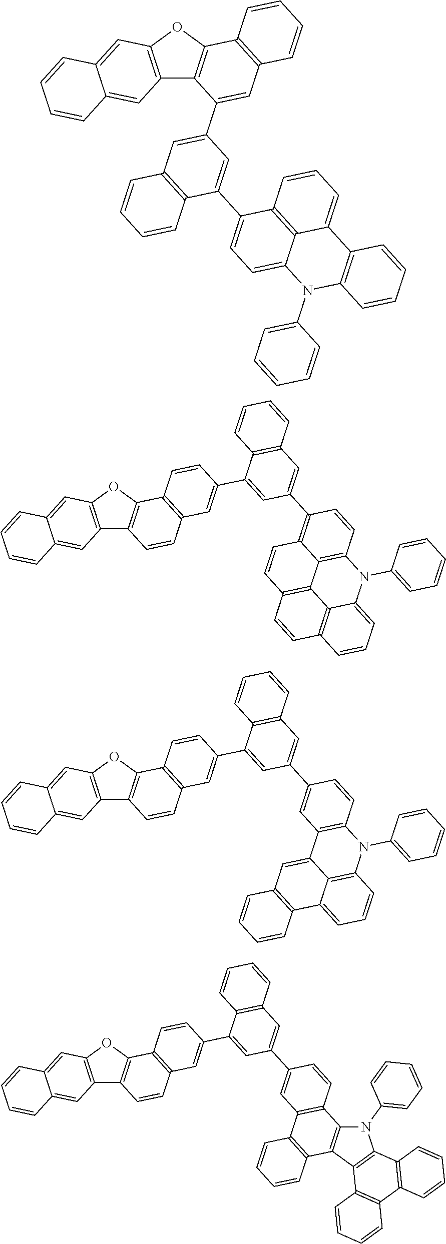

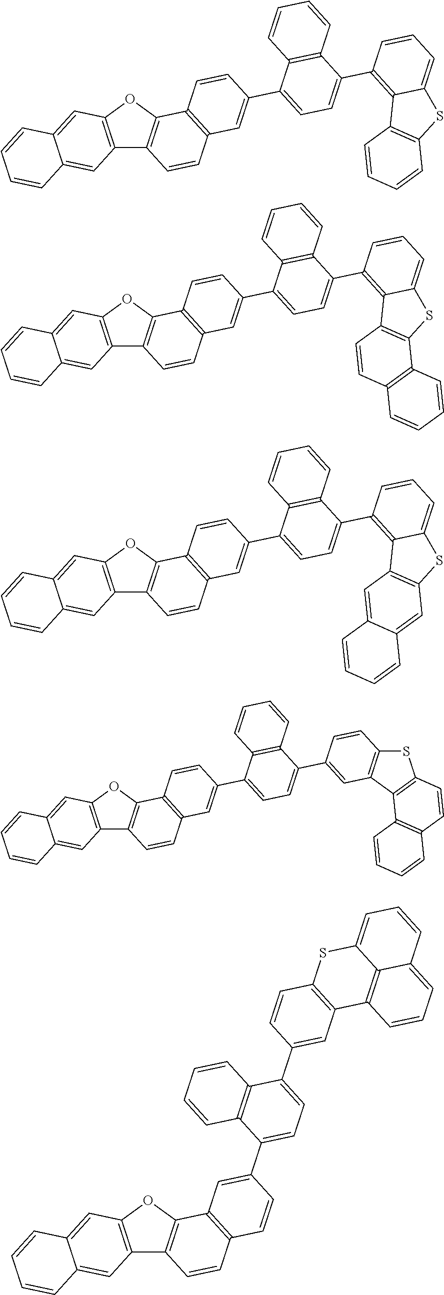

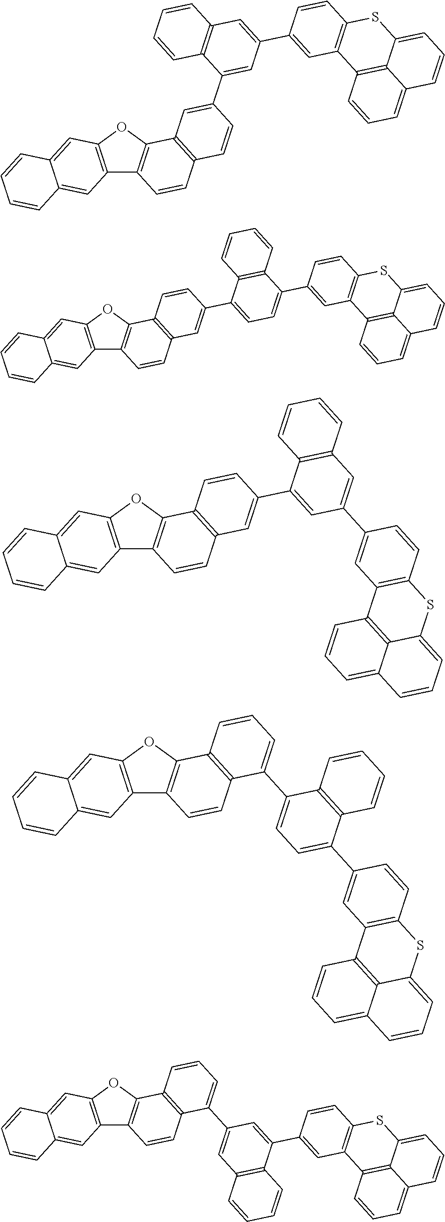 [SMILES: c1ccc2cc3c(cc2c1)oc1c2cc(-c4cc(-c5ccc6c(c5)-c5cccc7cccc(c57)S6)cc5ccccc45)ccc2ccc31 ; c1ccc2cc3c(cc2c1)oc1c2ccc(-c4ccc(-c5ccc6c(c5)-c5cccc7cccc(c57)S6)c5ccccc45)cc2ccc31 ; c1ccc2cc3c(cc2c1)oc1c2ccc(-c4cc(-c5ccc6c(c5)-c5cccc7cccc(c57)S6)cc5ccccc45)cc2ccc31 ; c1ccc2cc3c(cc2c1)oc1c2cccc(-c4ccc(-c5ccc6c(c5)-c5cccc7cccc(c57)S6)c5ccccc45)c2ccc31 ; c1ccc2cc3c(cc2c1)oc1c2cccc(-c4cc(-c5ccc6c(c5)-c5cccc7cccc(c57)S6)c5ccccc5c4)c2ccc31]

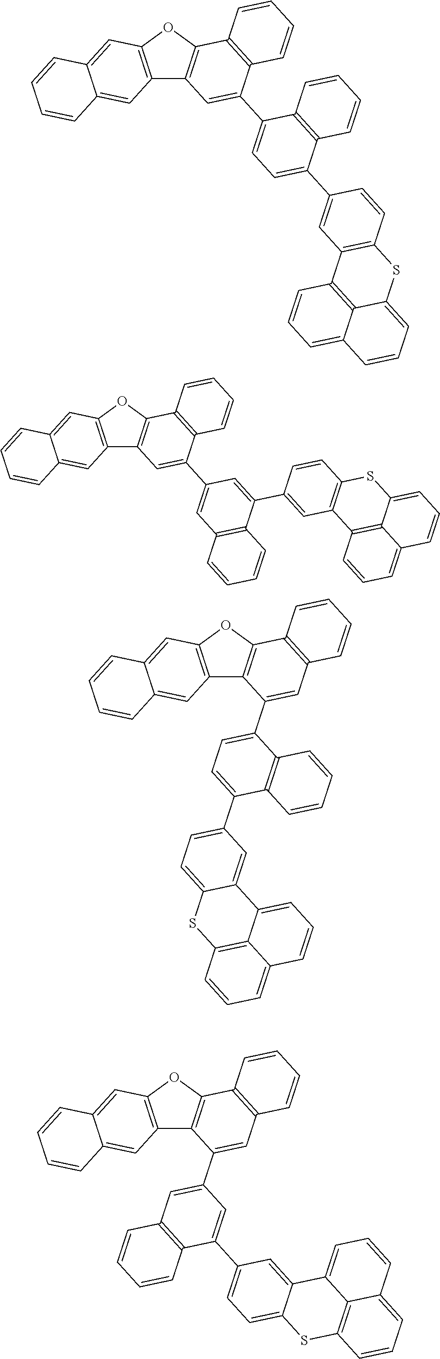

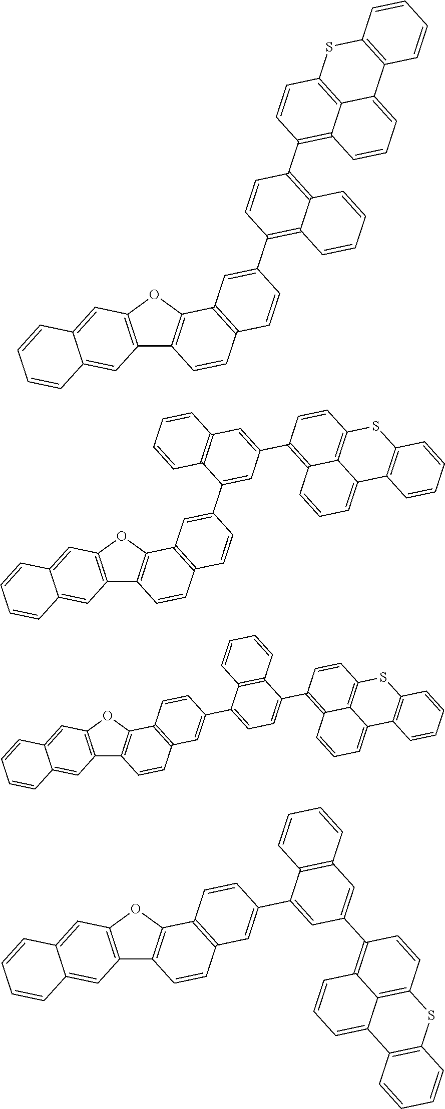

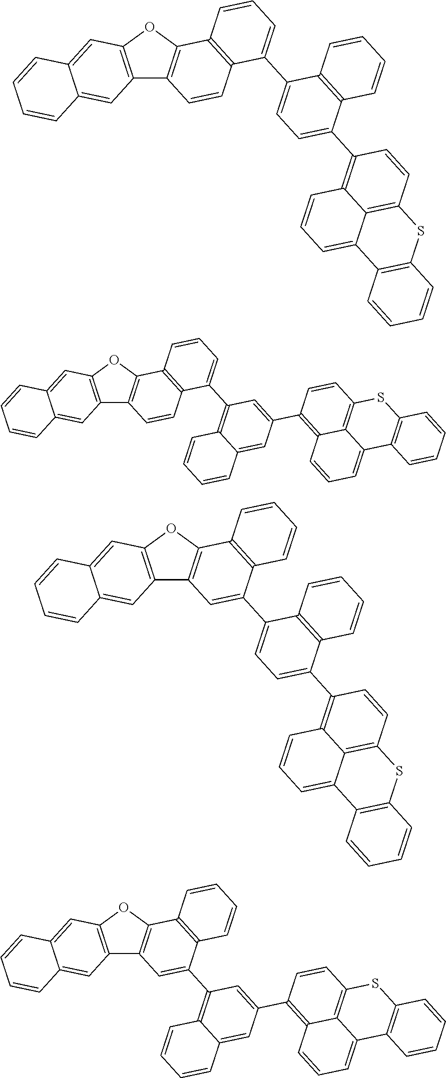

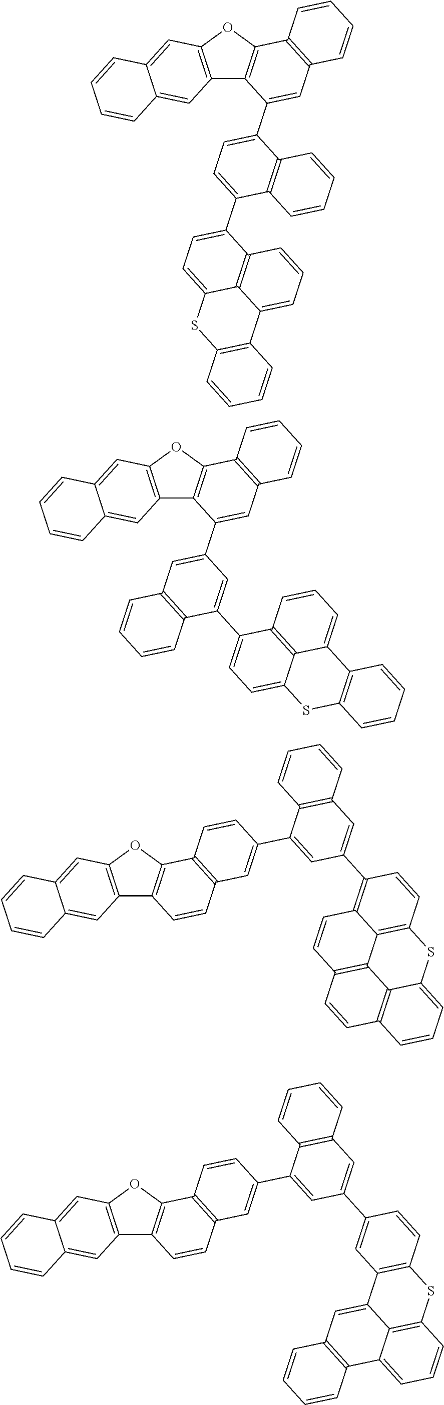

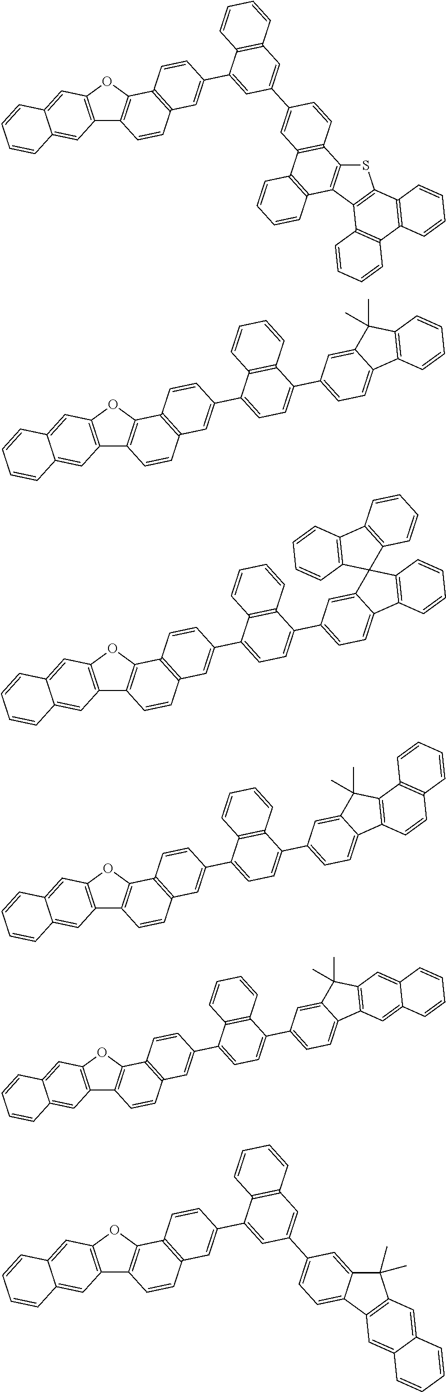

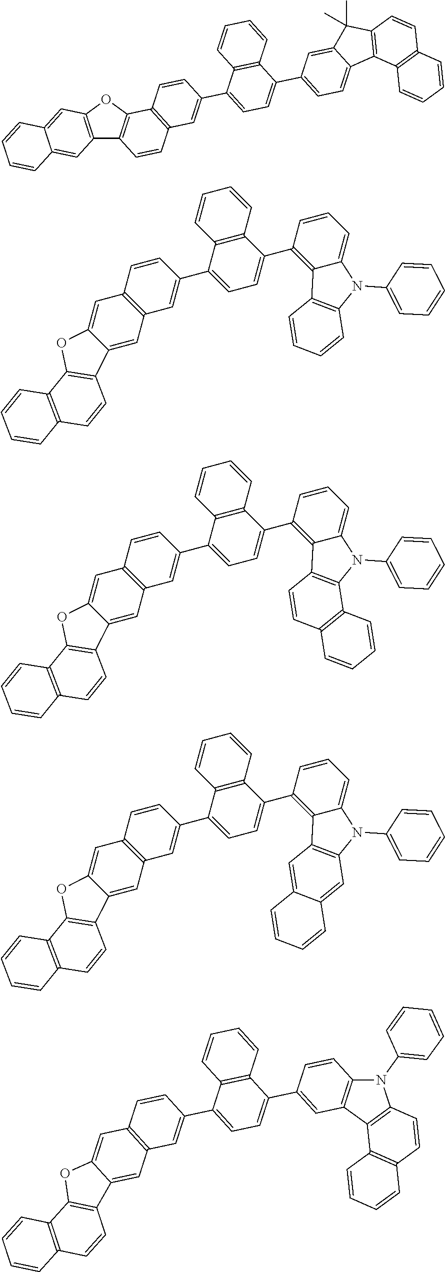 [SMILES: CC1(C)c2cc(-c3ccc(-c4ccc5c(ccc6c7cc8ccccc8cc7oc56)c4)c4ccccc34)ccc2-c2c1ccc1ccccc21 ; c1ccc(-n2c3ccccc3c3c(-c4ccc(-c5ccc6cc7oc8c9ccccc9ccc8c7cc6c5)c5ccccc45)cccc32)cc1 ; c1ccc(-n2c3cccc(-c4ccc(-c5ccc6cc7oc8c9ccccc9ccc8c7cc6c5)c5ccccc45)c3c3ccc4ccccc4c32)cc1 ; c1ccc(-n2c3cc4ccccc4cc3c3c(-c4ccc(-c5ccc6cc7oc8c9ccccc9ccc8c7cc6c5)c5ccccc45)cccc32)cc1 ; c1ccc(-n2c3ccc(-c4ccc(-c5ccc6cc7oc8c9ccccc9ccc8c7cc6c5)c5ccccc45)cc3c3c4ccccc4ccc32)cc1]

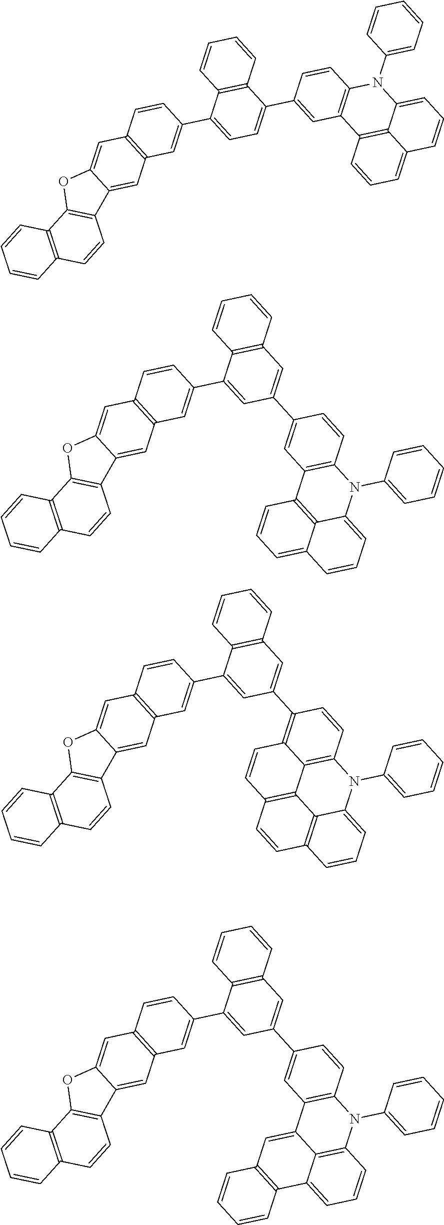

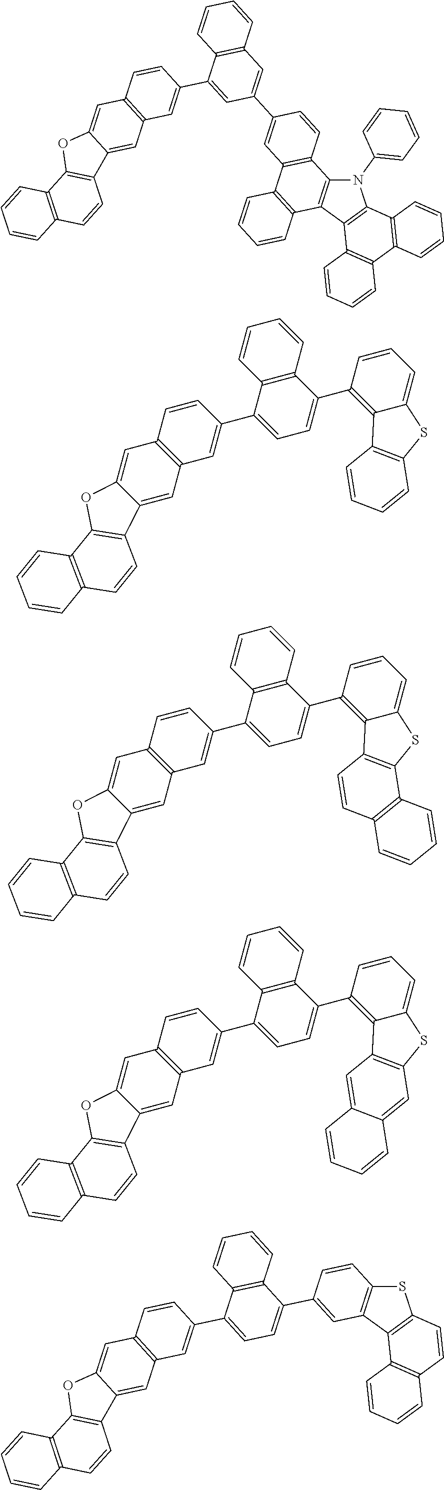 [SMILES: c1ccc(-n2c3c4ccccc4c4ccccc4c3c3c4ccccc4c4cc(-c5cc(-c6ccc7cc8oc9c%10ccccc%10ccc9c8cc7c6)c6ccccc6c5)ccc4c32)cc1 ; c1ccc2c(c1)ccc1c3cc4cc(-c5ccc(-c6cccc7sc8ccccc8c67)c6ccccc56)ccc4cc3oc21 ; c1ccc2c(c1)ccc1c3cc4cc(-c5ccc(-c6cccc7sc8c9ccccc9ccc8c67)c6ccccc56)ccc4cc3oc21 ; c1ccc2cc3c(cc2c1)sc1cccc(-c2ccc(-c4ccc5cc6oc7c8ccccc8ccc7c6cc5c4)c4ccccc24)c13 ; c1ccc2c(c1)ccc1c3cc4cc(-c5ccc(-c6ccc7sc8ccc9ccccc9c8c7c6)c6ccccc56)ccc4cc3oc21]

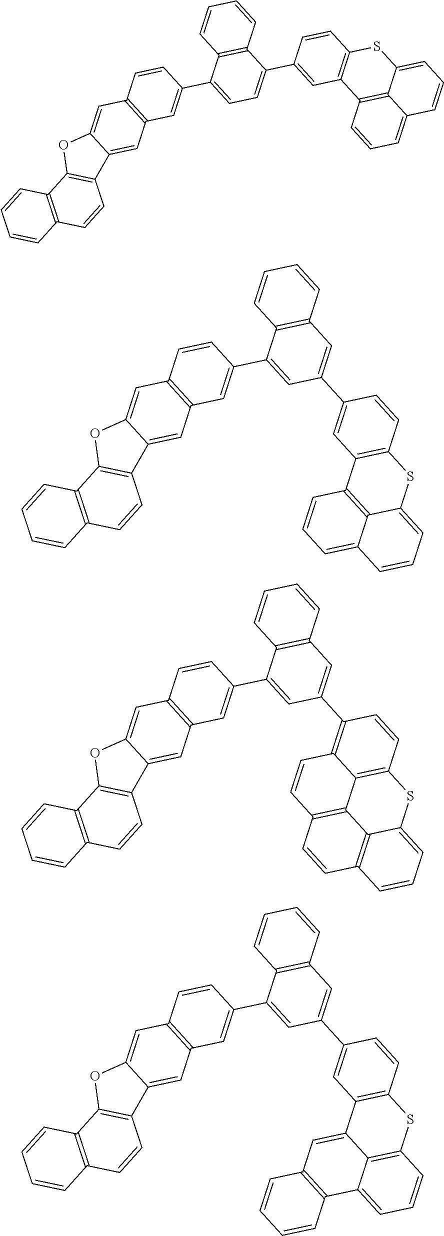

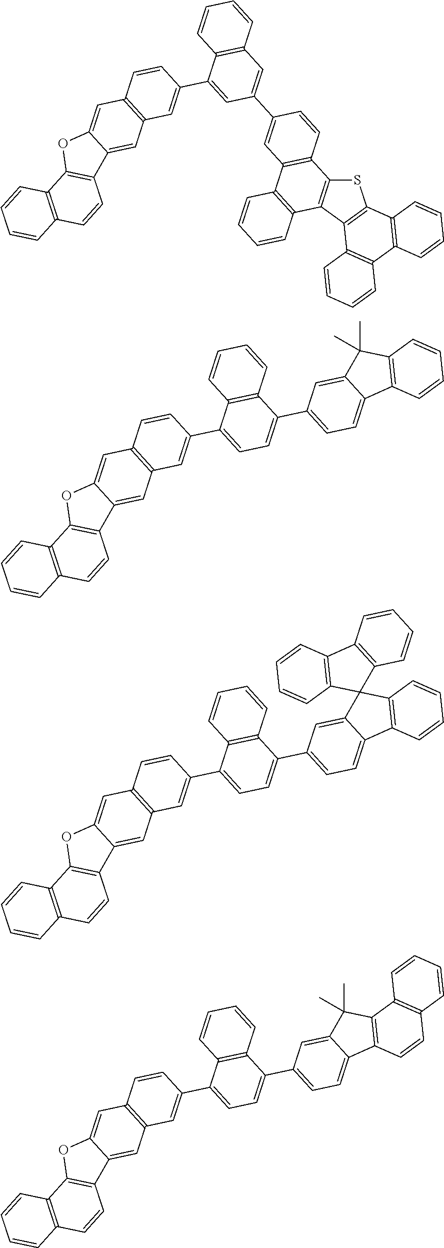

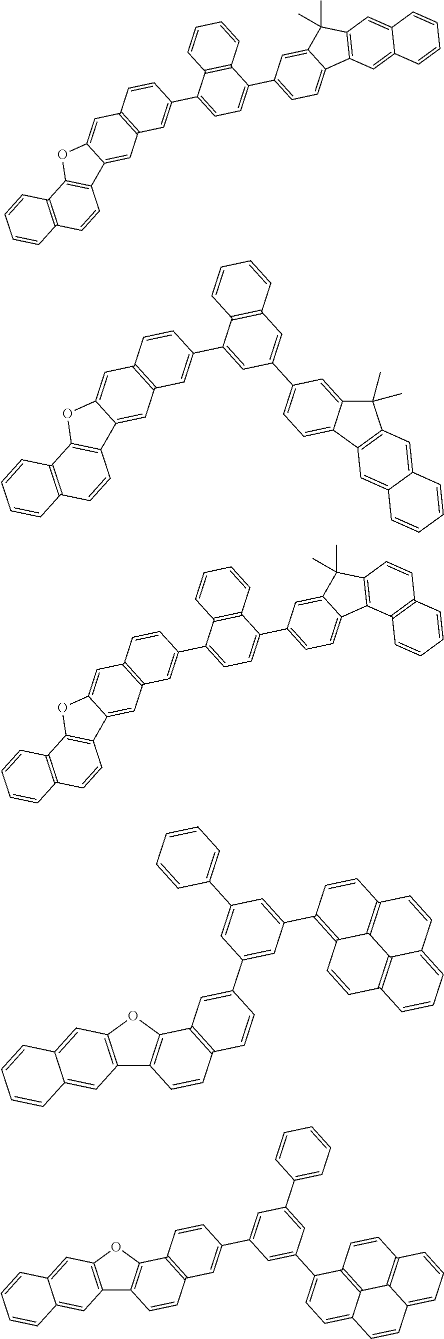 [SMILES: CC1(C)c2cc(-c3ccc(-c4ccc5cc6oc7c8ccccc8ccc7c6cc5c4)c4ccccc34)ccc2-c2cc3ccccc3cc21 ; CC1(C)c2cc(-c3cc(-c4ccc5cc6oc7c8ccccc8ccc7c6cc5c4)c4ccccc4c3)ccc2-c2cc3ccccc3cc21 ; CC1(C)c2cc(-c3ccc(-c4ccc5cc6oc7c8ccccc8ccc7c6cc5c4)c4ccccc34)ccc2-c2c1ccc1ccccc21 ; c1ccc(-c2cc(-c3ccc4ccc5c6cc7ccccc7cc6oc5c4c3)cc(-c3ccc4ccc5cccc6ccc3c4c56)c2)cc1 ; c1ccc(-c2cc(-c3ccc4c(ccc5c6cc7ccccc7cc6oc45)c3)cc(-c3ccc4ccc5cccc6ccc3c4c56)c2)cc1]

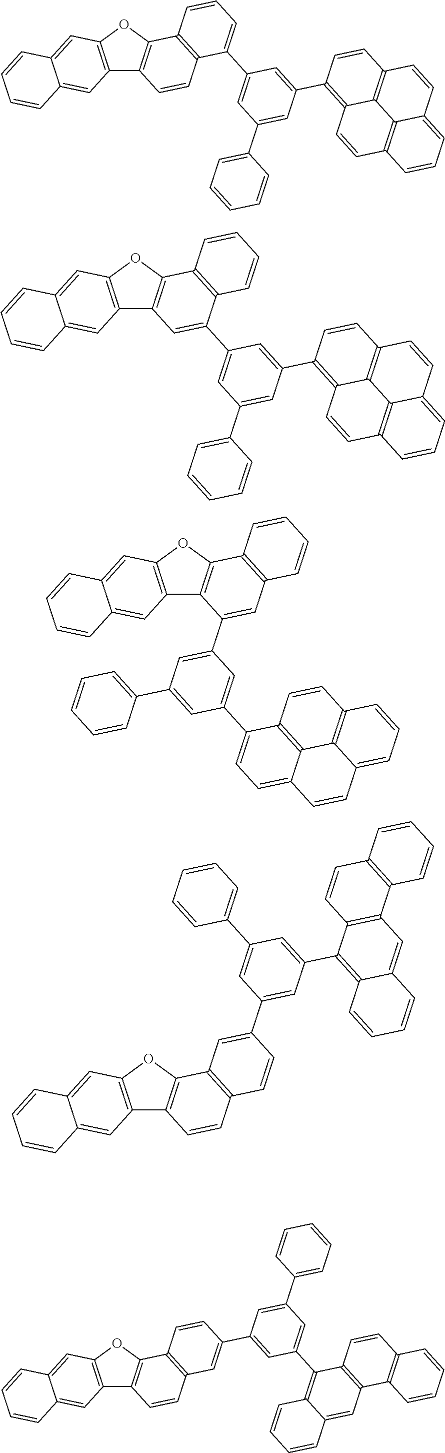

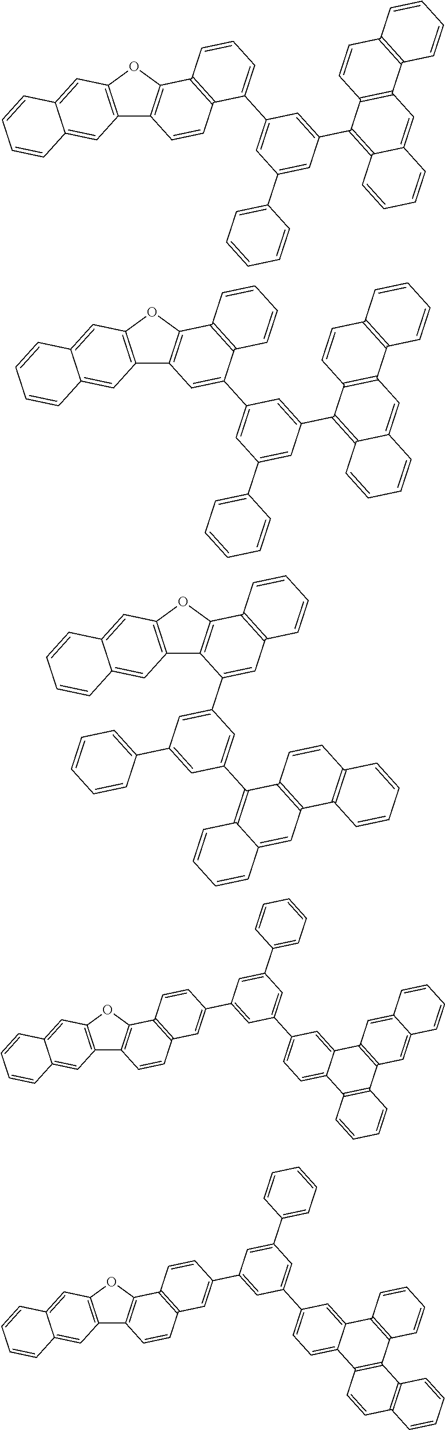

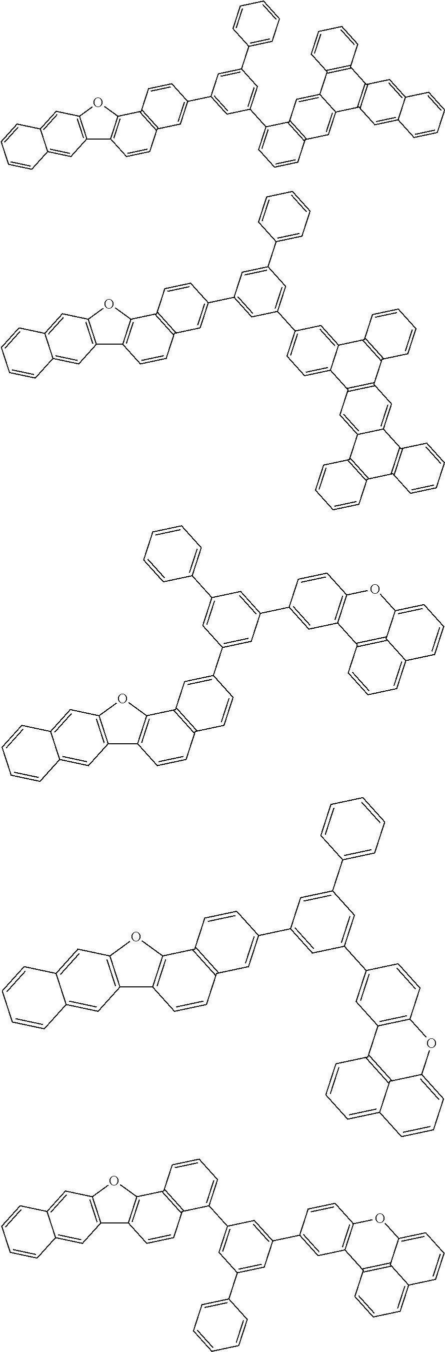

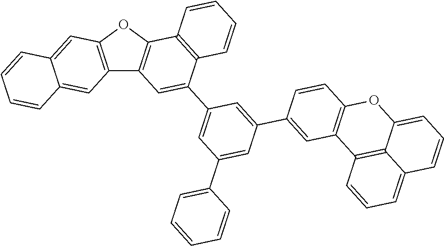 [SMILES: c1ccc(-c2cc(-c3ccc4c(c3)-c3cccc5cccc(c35)O4)cc(-c3cc4c5cc6ccccc6cc5oc4c4ccccc34)c2)cc1]

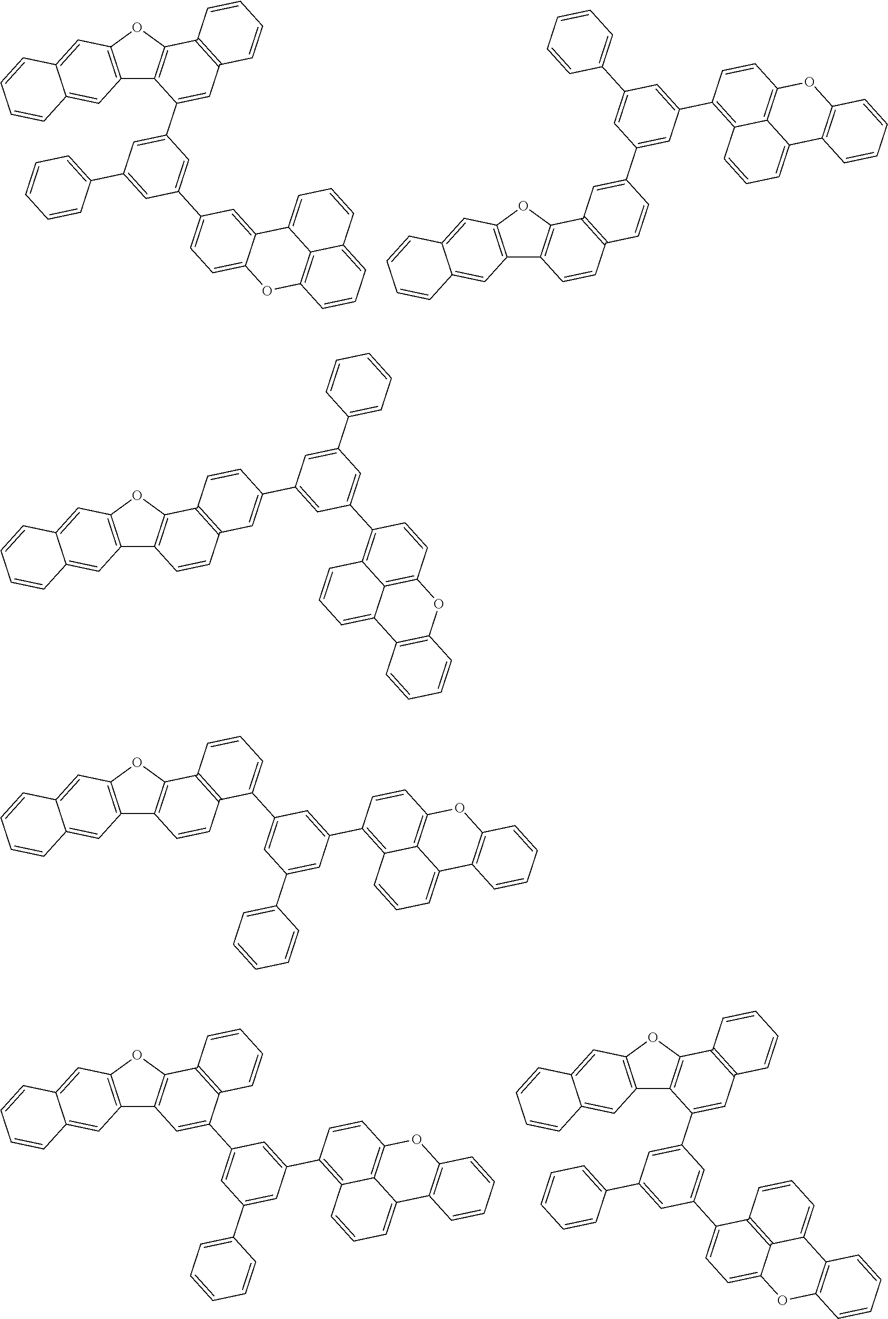

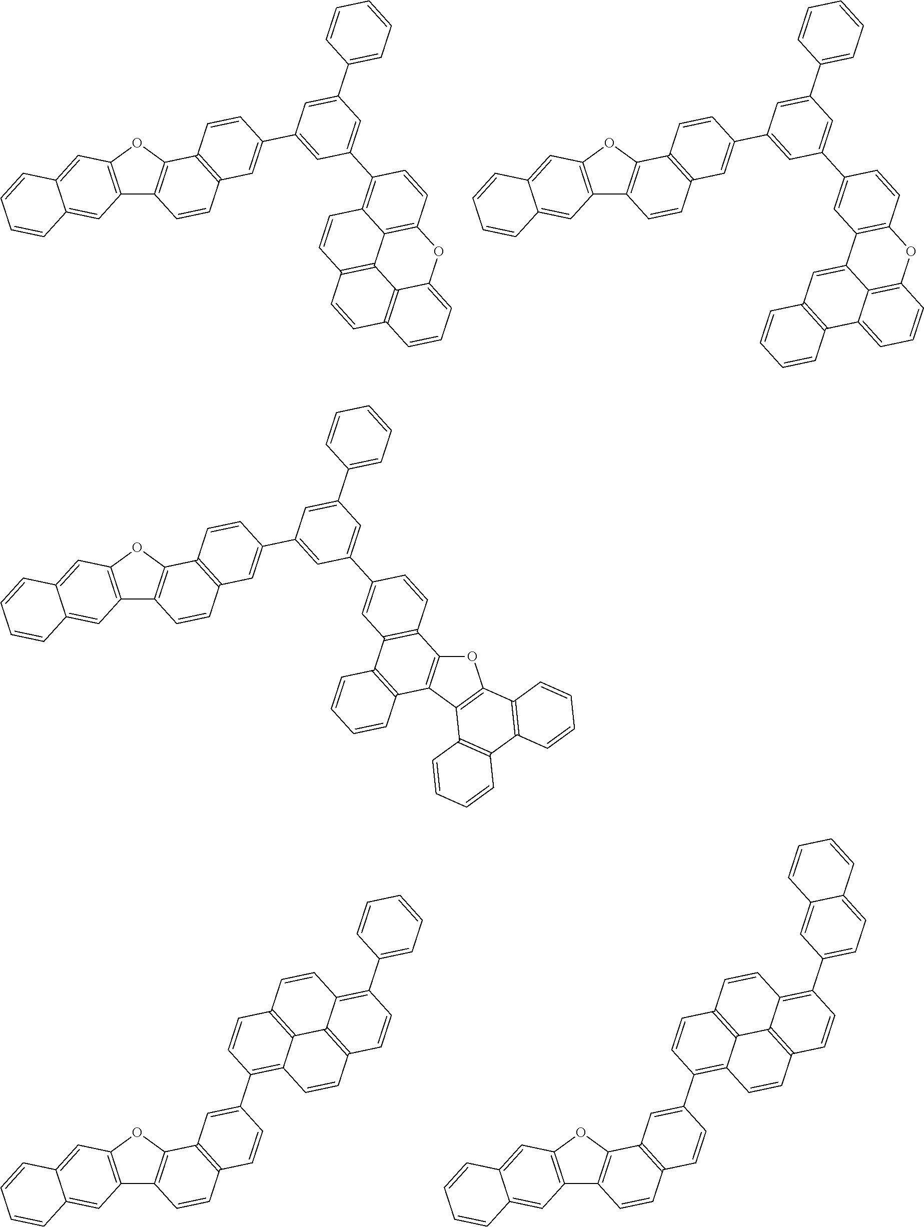

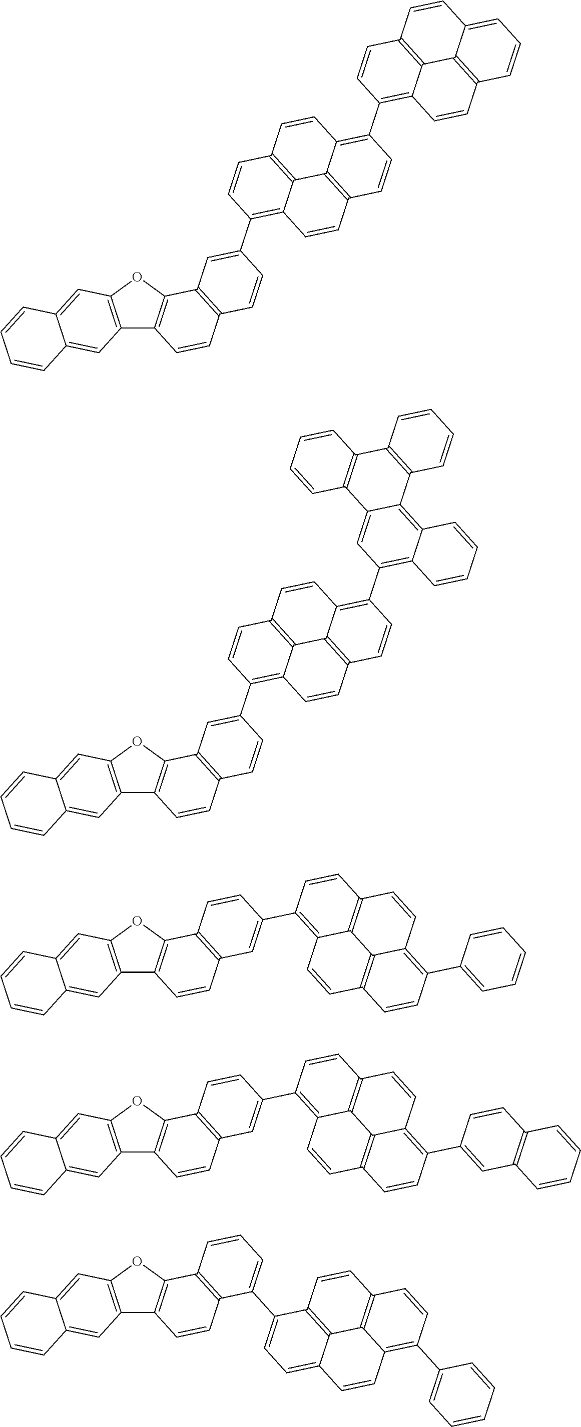 [SMILES: c1ccc2cc3c(cc2c1)oc1c2cc(-c4ccc5ccc6c(-c7ccc8ccc9cccc%10ccc7c8c9%10)ccc7ccc4c5c76)ccc2ccc31 ; c1ccc2cc3c(cc2c1)oc1c2cc(-c4ccc5ccc6c(-c7cc8c9ccccc9c9ccccc9c8c8ccccc78)ccc7ccc4c5c76)ccc2ccc31 ; c1ccc(-c2ccc3ccc4c(-c5ccc6c(ccc7c8cc9ccccc9cc8oc67)c5)ccc5ccc2c3c54)cc1 ; c1ccc2cc(-c3ccc4ccc5c(-c6ccc7c(ccc8c9cc%10ccccc%10cc9oc78)c6)ccc6ccc3c4c65)ccc2c1 ; c1ccc(-c2ccc3ccc4c(-c5cccc6c5ccc5c7cc8ccccc8cc7oc65)ccc5ccc2c3c54)cc1]

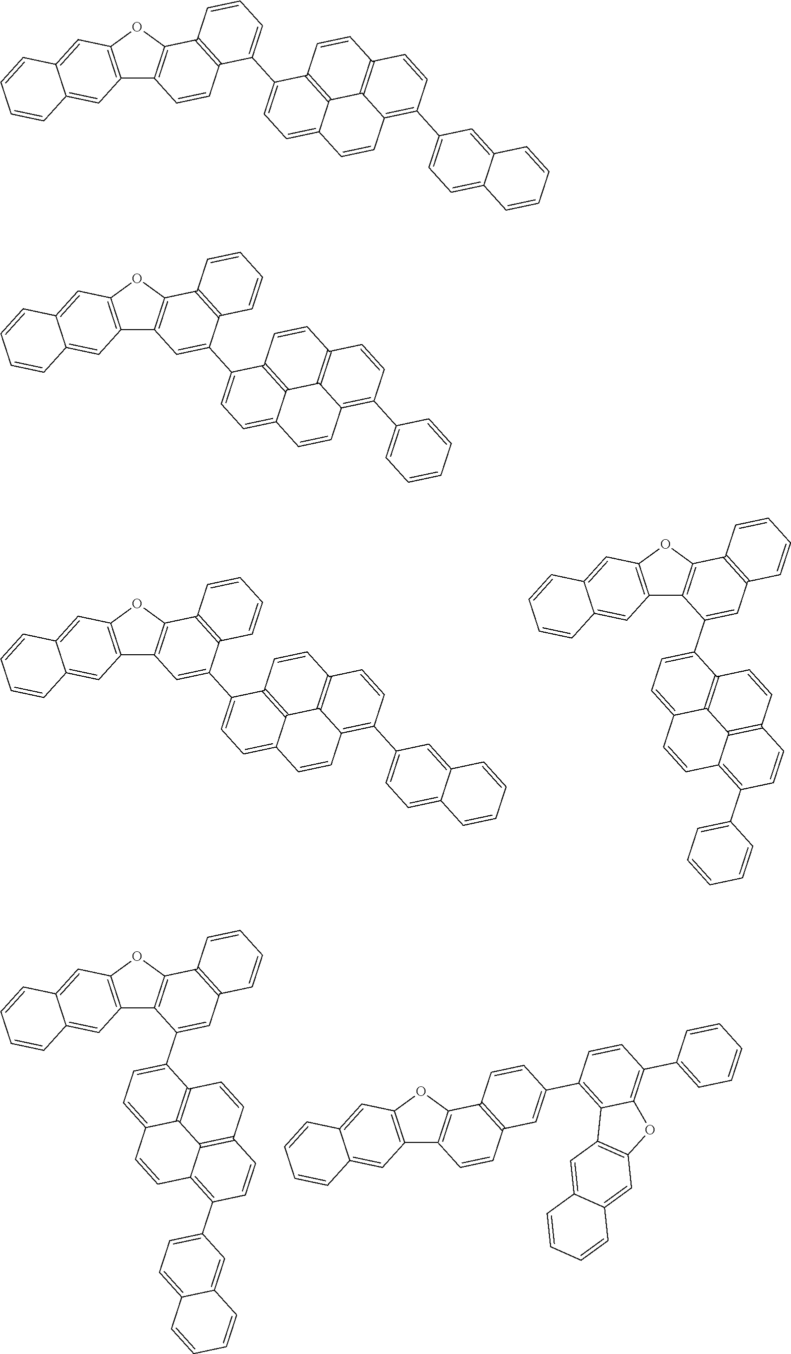

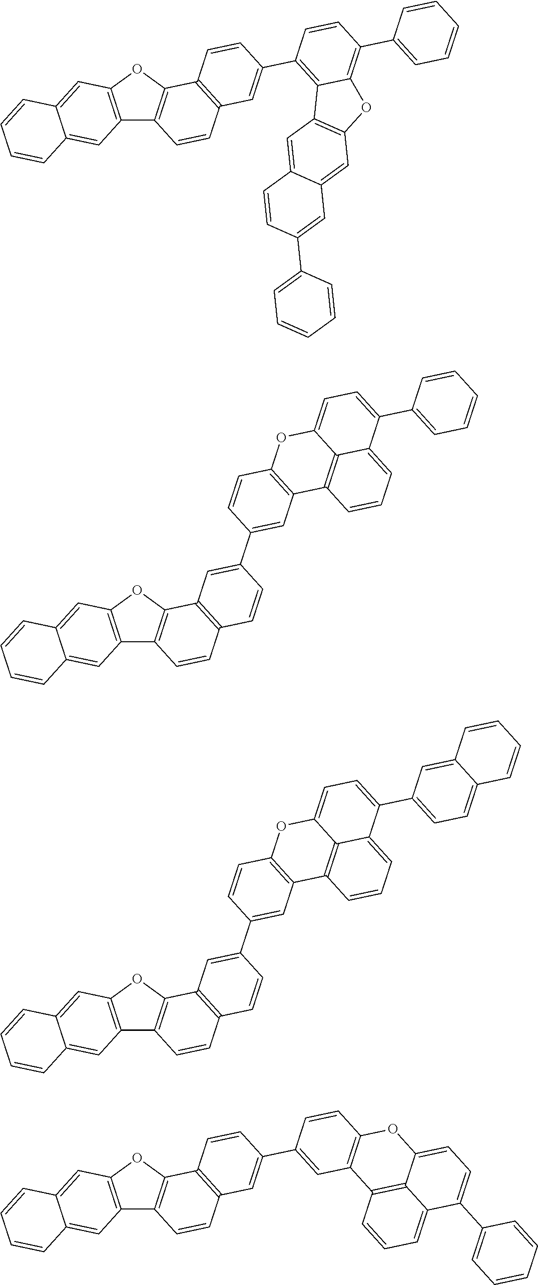 [SMILES: c1ccc(-c2ccc3cc4c(cc3c2)oc2c(-c3ccccc3)ccc(-c3ccc5c(ccc6c7cc8ccccc8cc7oc56)c3)c24)cc1 ; c1ccc(-c2ccc3c4c(cccc24)-c2cc(-c4ccc5ccc6c7cc8ccccc8cc7oc6c5c4)ccc2O3)cc1 ; c1ccc2cc(-c3ccc4c5c(cccc35)-c3cc(-c5ccc6ccc7c8cc9ccccc9cc8oc7c6c5)ccc3O4)ccc2c1 ; c1ccc(-c2ccc3c4c(cccc24)-c2cc(-c4ccc5c(ccc6c7cc8ccccc8cc7oc56)c4)ccc2O3)cc1]

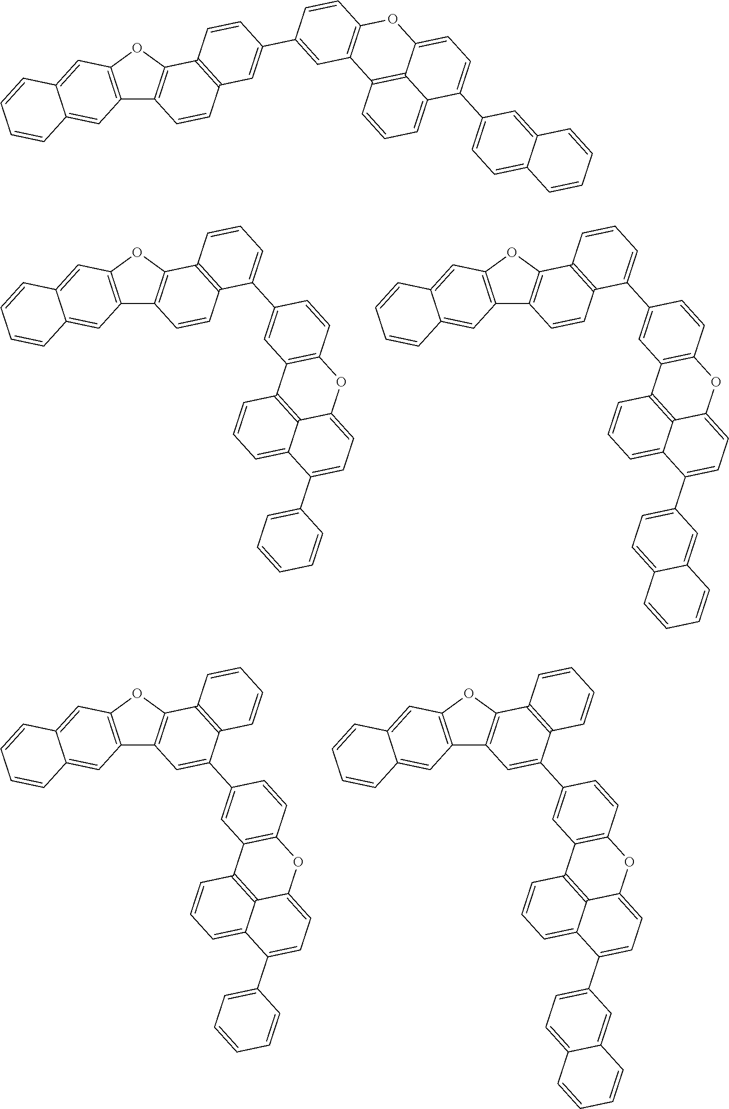 [SMILES: c1ccc2cc(-c3ccc4c5c(cccc35)-c3cc(-c5ccc6c(ccc7c8cc9ccccc9cc8oc67)c5)ccc3O4)ccc2c1 ; c1ccc(-c2ccc3c4c(cccc24)-c2cc(-c4cccc5c4ccc4c6cc7ccccc7cc6oc54)ccc2O3)cc1 ; c1ccc2cc(-c3ccc4c5c(cccc35)-c3cc(-c5cccc6c5ccc5c7cc8ccccc8cc7oc65)ccc3O4)ccc2c1 ; c1ccc(-c2ccc3c4c(cccc24)-c2cc(-c4cc5c6cc7ccccc7cc6oc5c5ccccc45)ccc2O3)cc1 ; c1ccc2cc(-c3ccc4c5c(cccc35)-c3cc(-c5cc6c7cc8ccccc8cc7oc6c6ccccc56)ccc3O4)ccc2c1]

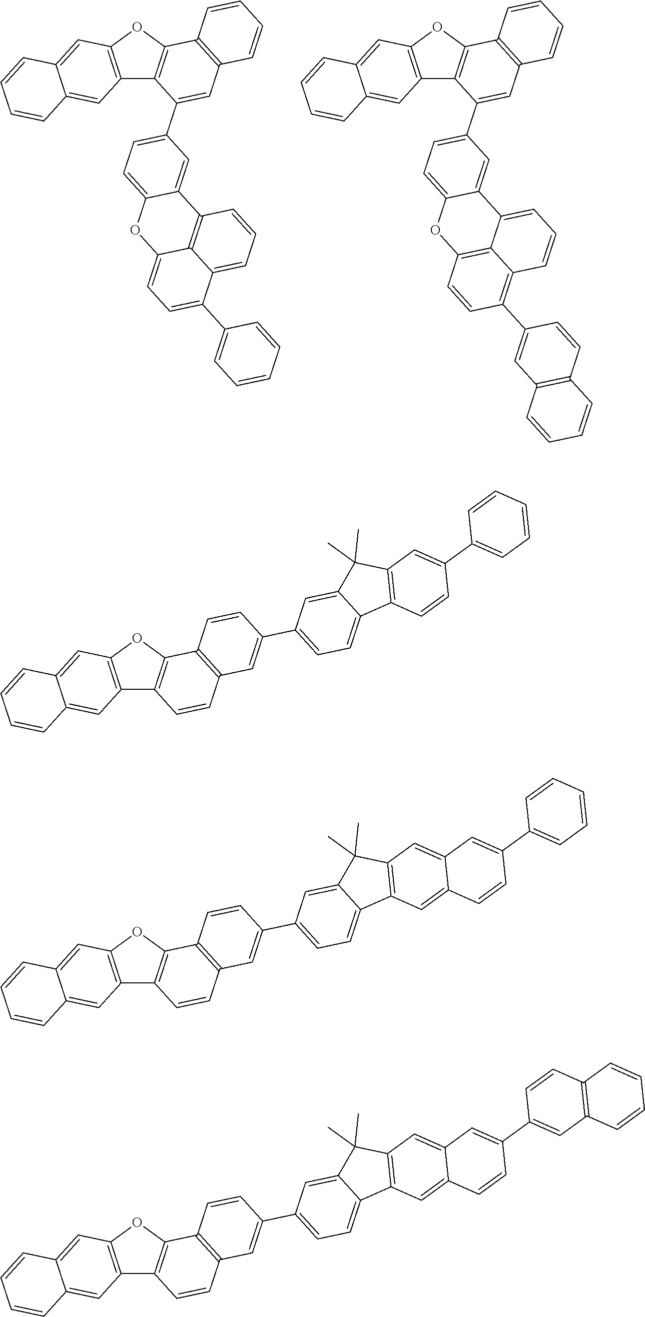 [SMILES: c1ccc(-c2ccc3c4c(cccc24)-c2cc(-c4cc5ccccc5c5oc6cc7ccccc7cc6c45)ccc2O3)cc1 ; c1ccc2cc(-c3ccc4c5c(cccc35)-c3cc(-c5cc6ccccc6c6oc7cc8ccccc8cc7c56)ccc3O4)ccc2c1 ; CC1(C)c2cc(-c3ccccc3)ccc2-c2ccc(-c3ccc4c(ccc5c6cc7ccccc7cc6oc45)c3)cc21 ; CC1(C)c2cc(-c3ccc4c(ccc5c6cc7ccccc7cc6oc45)c3)ccc2-c2cc3ccc(-c4ccccc4)cc3cc21 ; CC1(C)c2cc(-c3ccc4c(ccc5c6cc7ccccc7cc6oc45)c3)ccc2-c2cc3ccc(-c4ccc5ccccc5c4)cc3cc21]

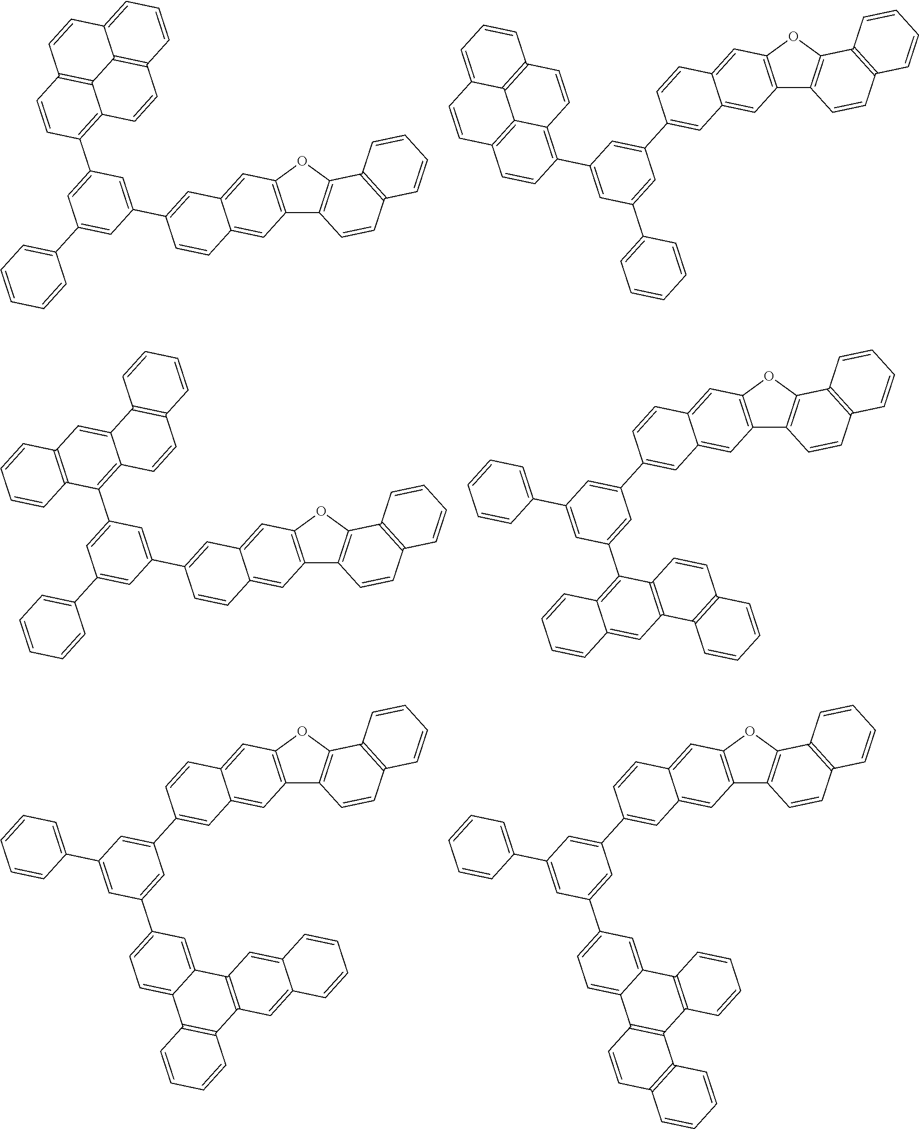

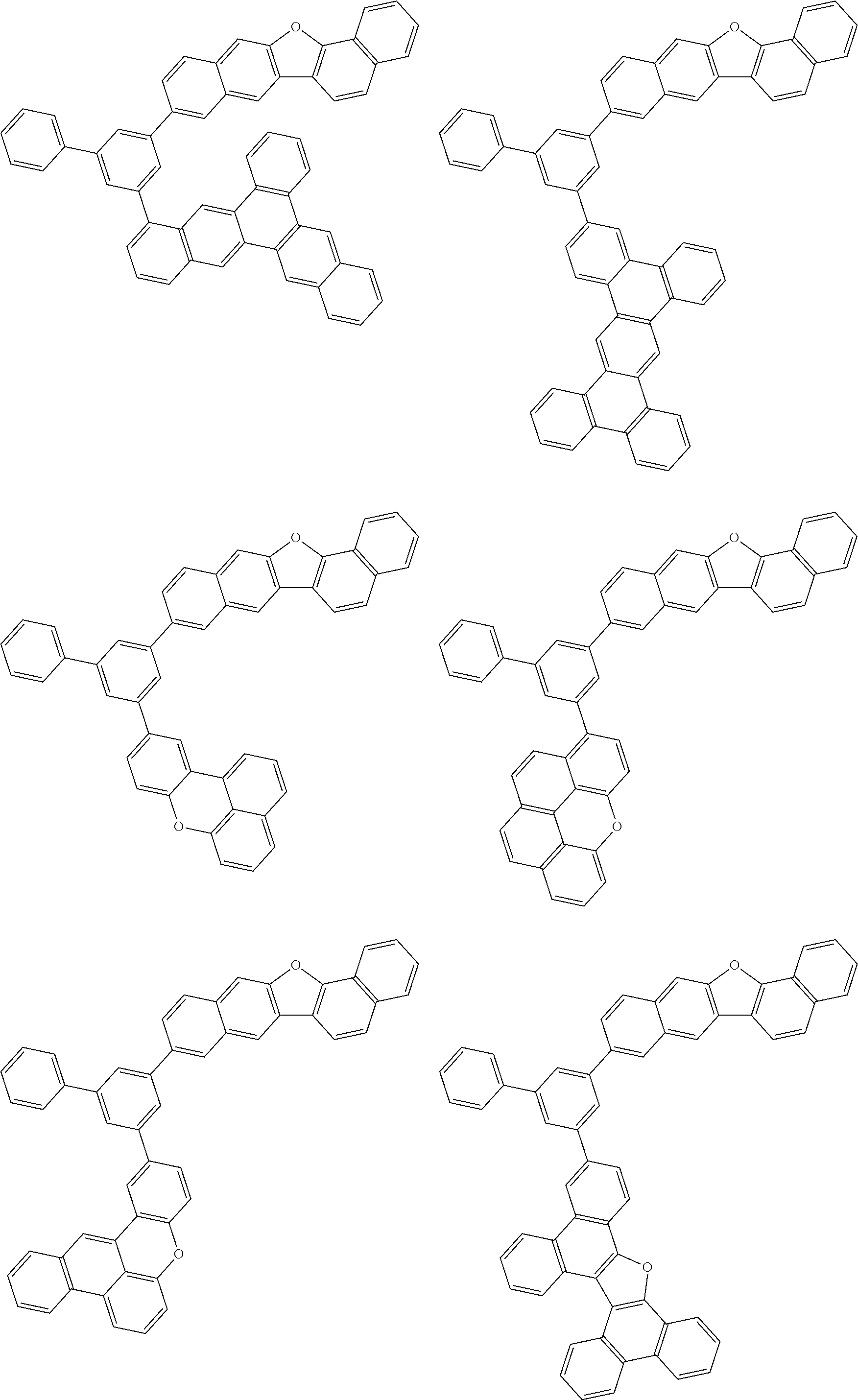

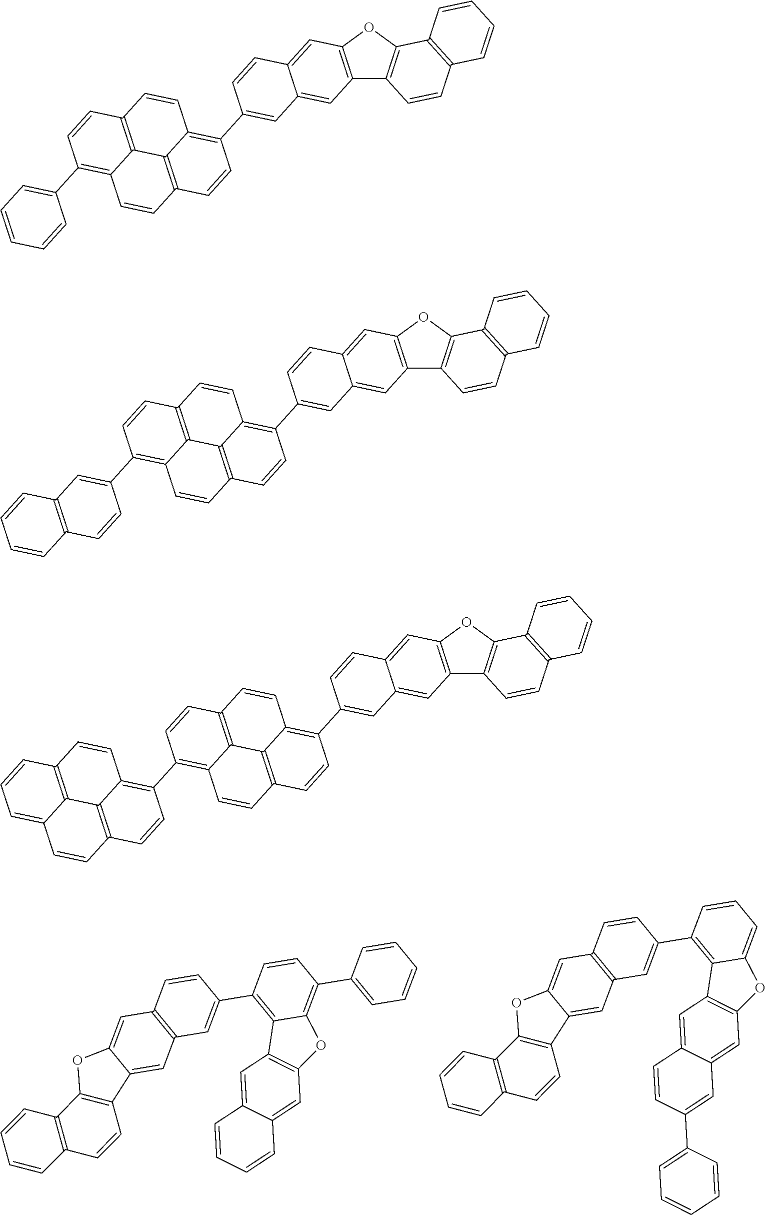 [SMILES: c1ccc(-c2ccc3ccc4c(-c5ccc6cc7oc8c9ccccc9ccc8c7cc6c5)ccc5ccc2c3c54)cc1 ; c1ccc2cc(-c3ccc4ccc5c(-c6ccc7cc8oc9c%10ccccc%10ccc9c8cc7c6)ccc6ccc3c4c65)ccc2c1 ; c1ccc2c(c1)ccc1c3cc4cc(-c5ccc6ccc7c(-c8ccc9ccc%10cccc%11ccc8c9c%10%11)ccc8ccc5c6c87)ccc4cc3oc21 ; c1ccc(-c2ccc(-c3ccc4cc5oc6c7ccccc7ccc6c5cc4c3)c3c2oc2cc4ccccc4cc23)cc1 ; c1ccc(-c2ccc3cc4c(cc3c2)oc2cccc(-c3ccc5cc6oc7c8ccccc8ccc7c6cc5c3)c24)cc1]

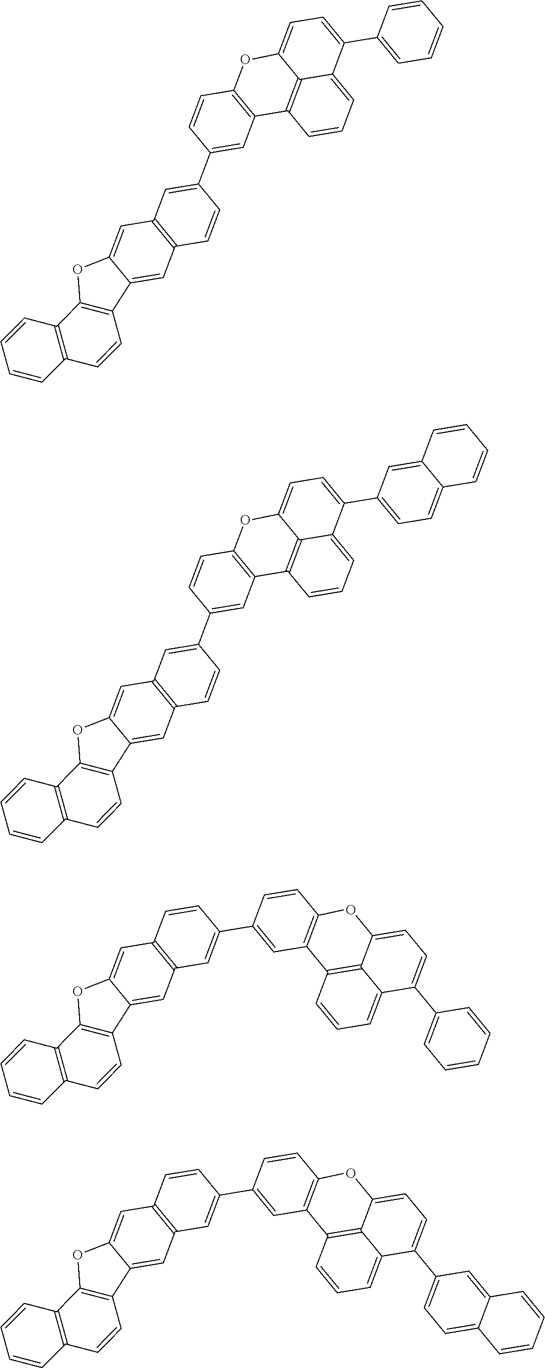 [SMILES: c1ccc(-c2ccc3c4c(cccc24)-c2cc(-c4ccc5cc6c(cc5c4)oc4c5ccccc5ccc64)ccc2O3)cc1 ; c1ccc2cc(-c3ccc4c5c(cccc35)-c3cc(-c5ccc6cc7c(cc6c5)oc5c6ccccc6ccc75)ccc3O4)ccc2c1 ; c1ccc(-c2ccc3c4c(cccc24)-c2cc(-c4ccc5cc6oc7c8ccccc8ccc7c6cc5c4)ccc2O3)cc1 ; c1ccc2cc(-c3ccc4c5c(cccc35)-c3cc(-c5ccc6cc7oc8c9ccccc9ccc8c7cc6c5)ccc3O4)ccc2c1]

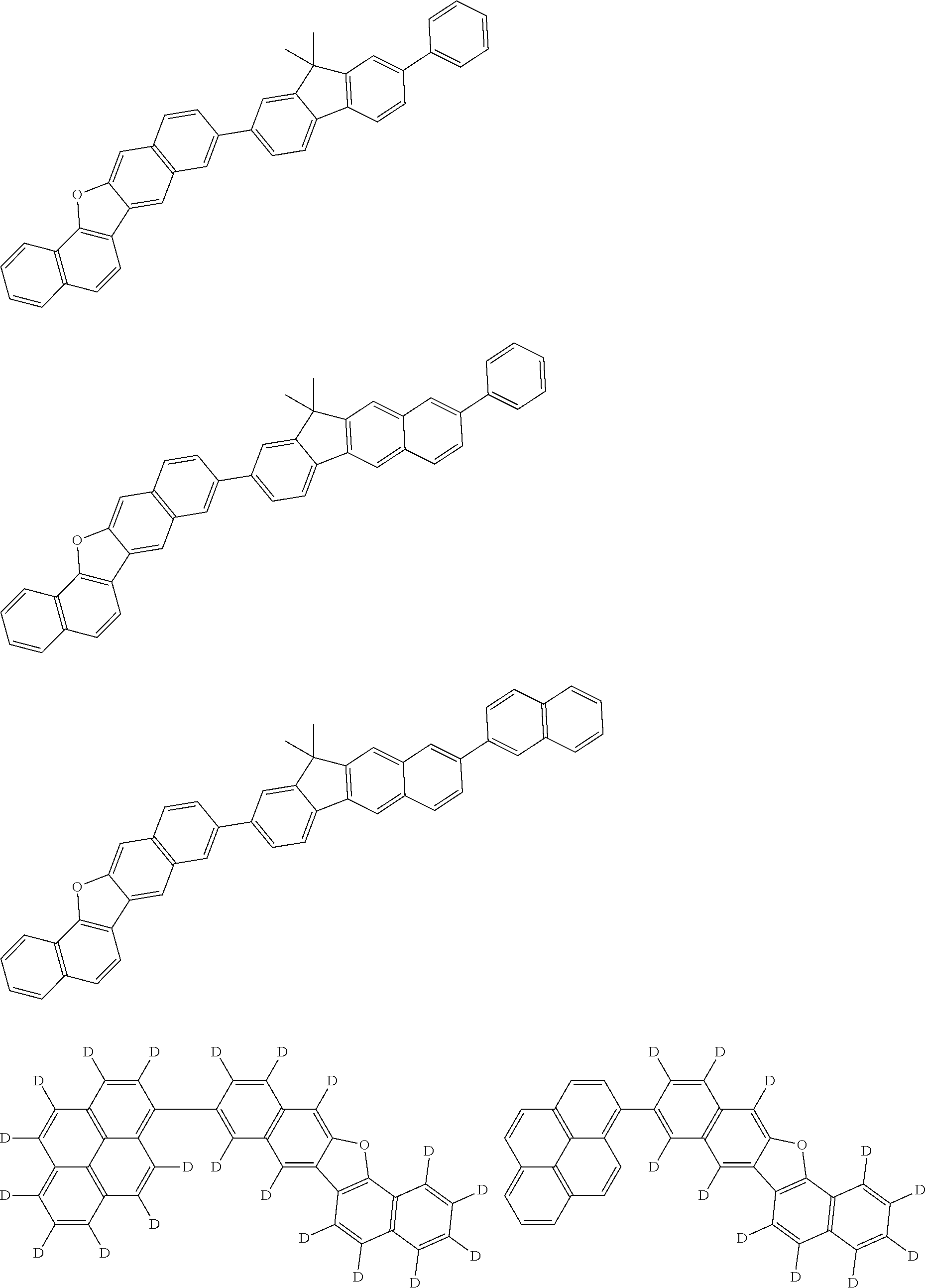

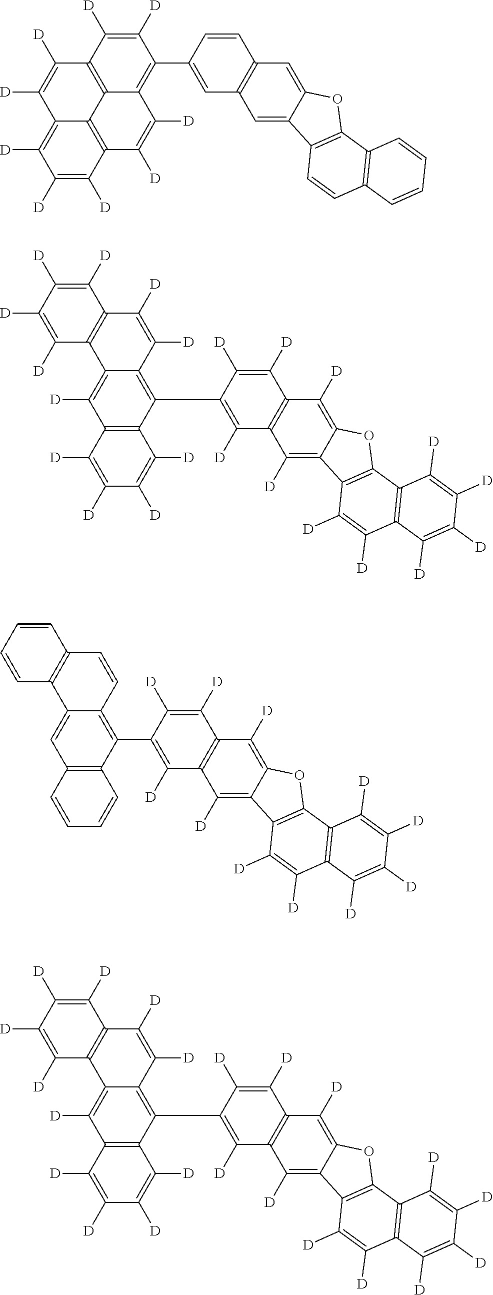

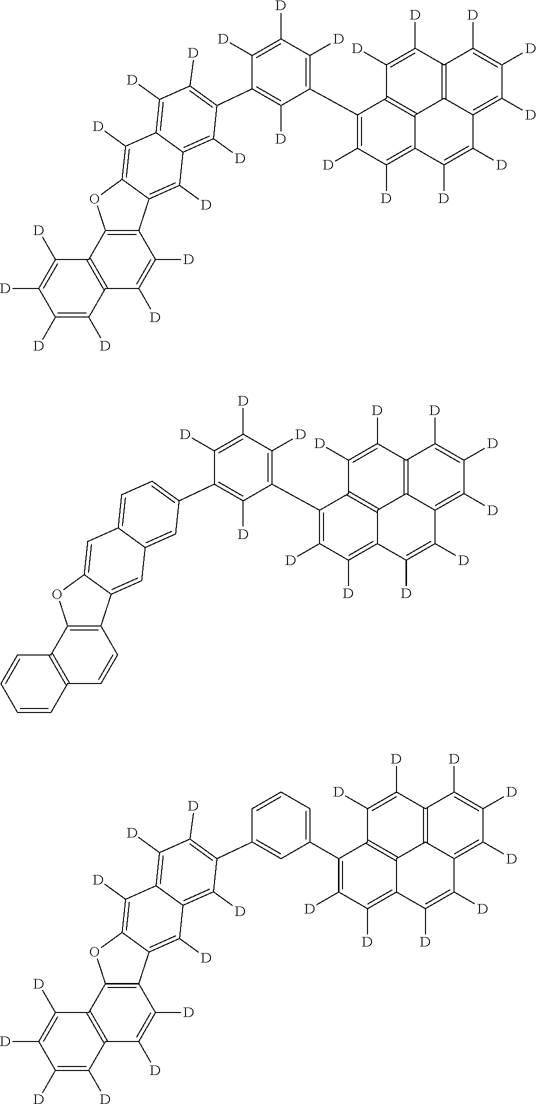

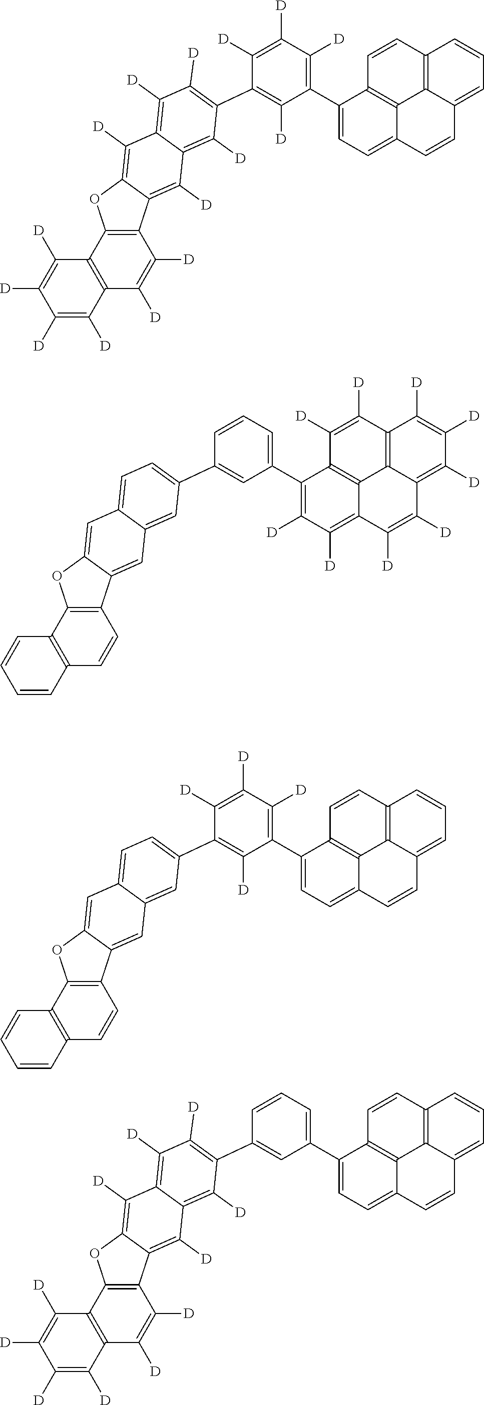

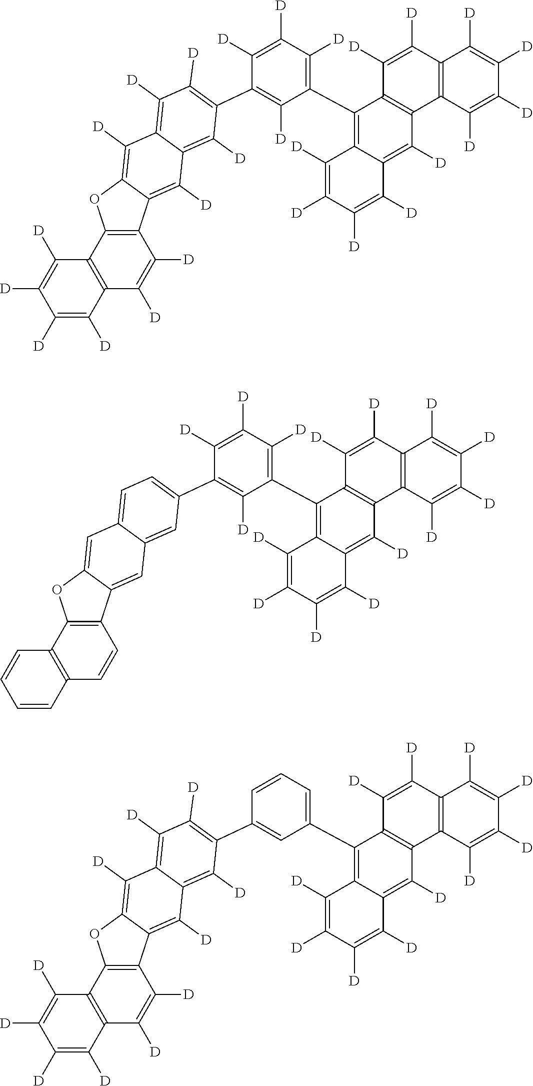

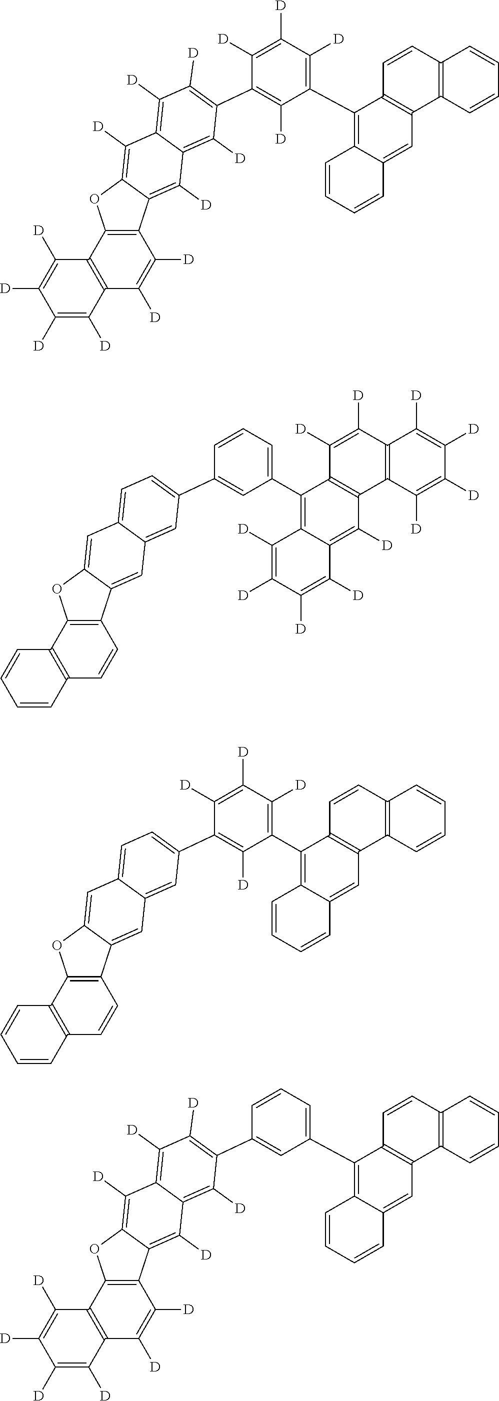

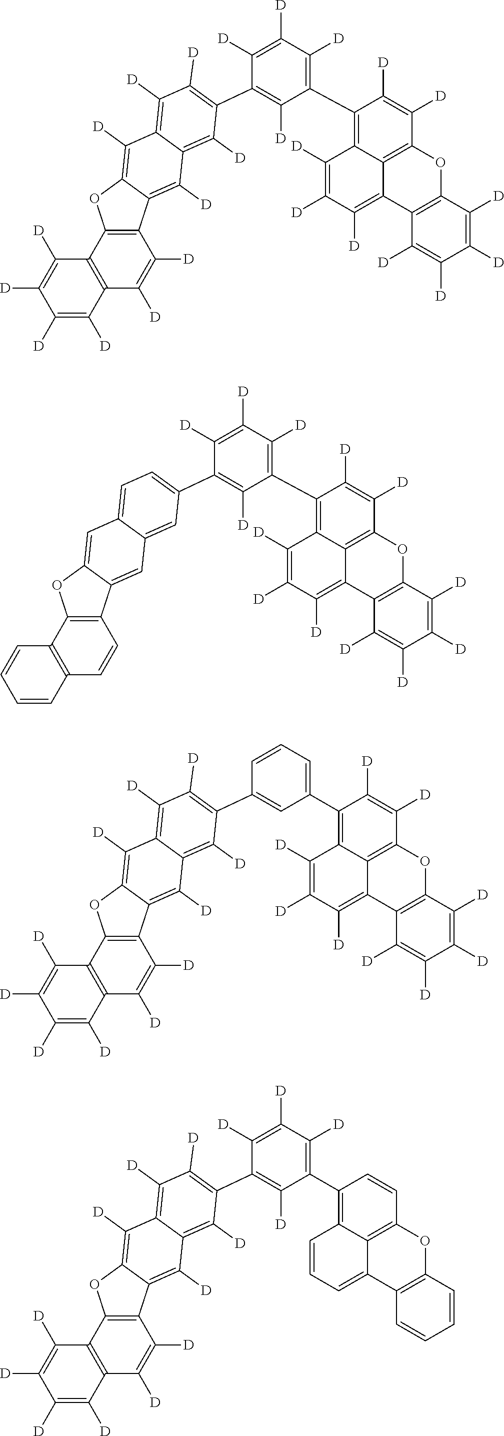

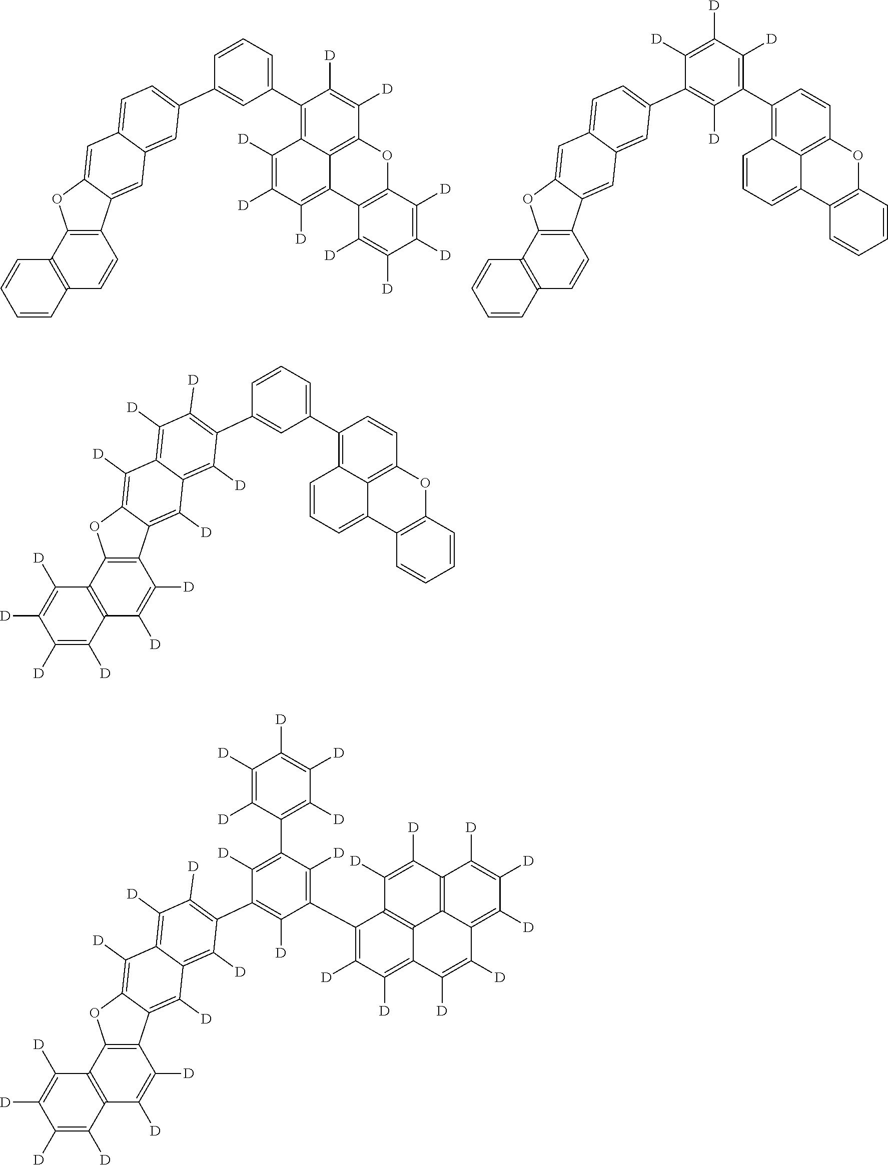

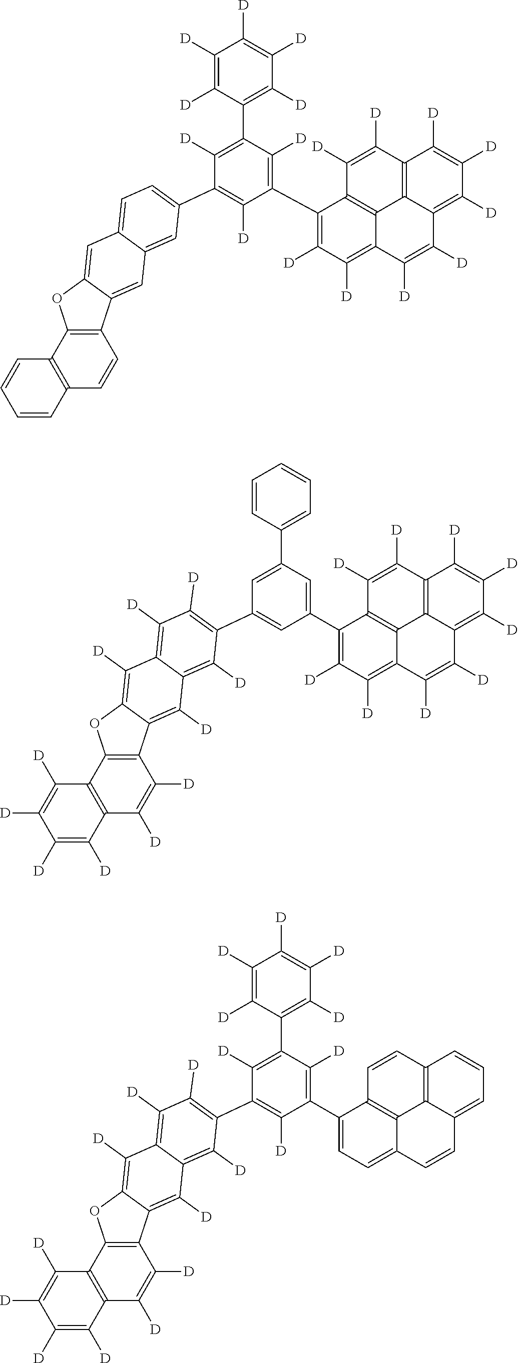

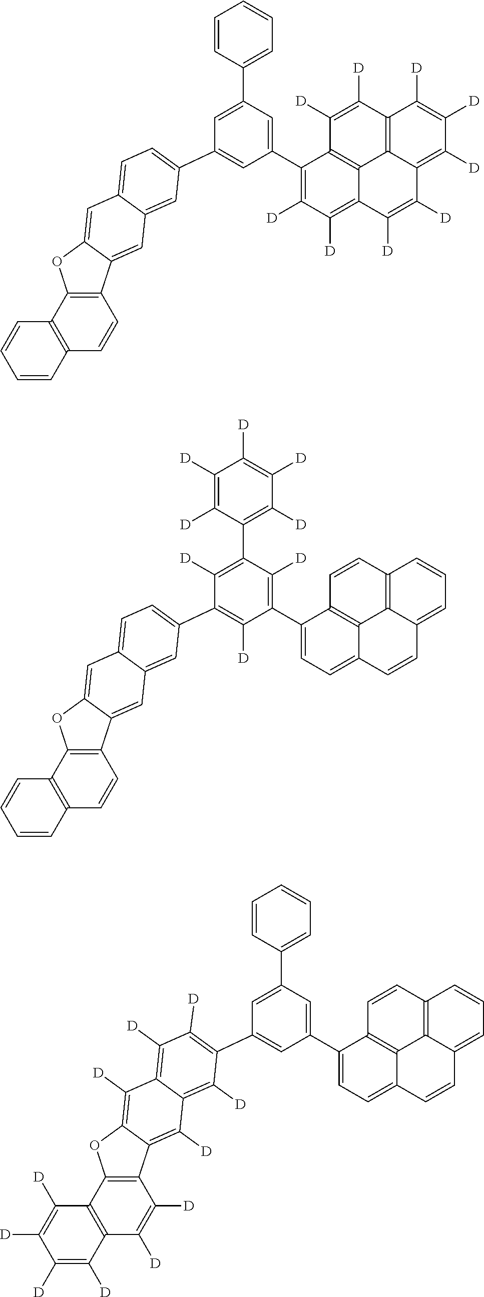 [SMILES: [2H]c1c([2H])c2c([2H])c([2H])c3c([2H])c([2H])c(-c4cc(-c5ccccc5)cc(-c5ccc6cc7oc8c9ccccc9ccc8c7cc6c5)c4)c4c([2H])c([2H])c(c1[2H])c2c34 ; [2H]c1c([2H])c([2H])c(-c2c([2H])c(-c3ccc4cc5oc6c7ccccc7ccc6c5cc4c3)c([2H])c(-c3ccc4ccc5cccc6ccc3c4c56)c2[2H])c([2H])c1[2H] ; [2H]c1c(-c2cc(-c3ccccc3)cc(-c3ccc4ccc5cccc6ccc3c4c56)c2)c([2H])c2c([2H])c3c(oc4c5c([2H])c([2H])c([2H])c([2H])c5c([2H])c([2H])c43)c([2H])c2c1[2H]]

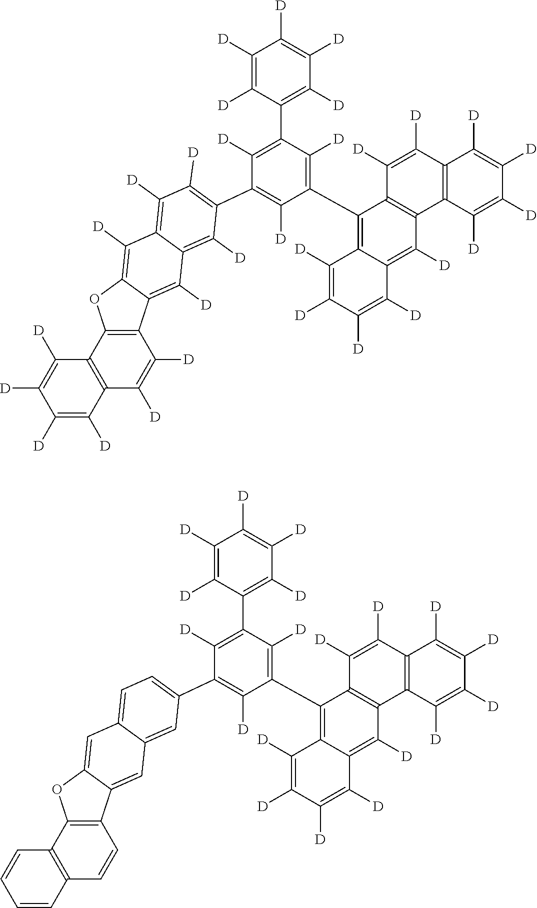 [SMILES: [2H]c1c([2H])c([2H])c(-c2c([2H])c(-c3c([2H])c([2H])c4c([2H])c5oc6c7c([2H])c([2H])c([2H])c([2H])c7c([2H])c([2H])c6c5c([2H])c4c3[2H])c([2H])c(-c3c4c([2H])c([2H])c([2H])c([2H])c4c([2H])c4c3c([2H])c([2H])c3c([2H])c([2H])c([2H])c([2H])c34)c2[2H])c([2H])c1[2H] ; [2H]c1c([2H])c([2H])c(-c2c([2H])c(-c3ccc4cc5oc6c7ccccc7ccc6c5cc4c3)c([2H])c(-c3c4c([2H])c([2H])c([2H])c([2H])c4c([2H])c4c3c([2H])c([2H])c3c([2H])c([2H])c([2H])c([2H])c34)c2[2H])c([2H])c1[2H]]

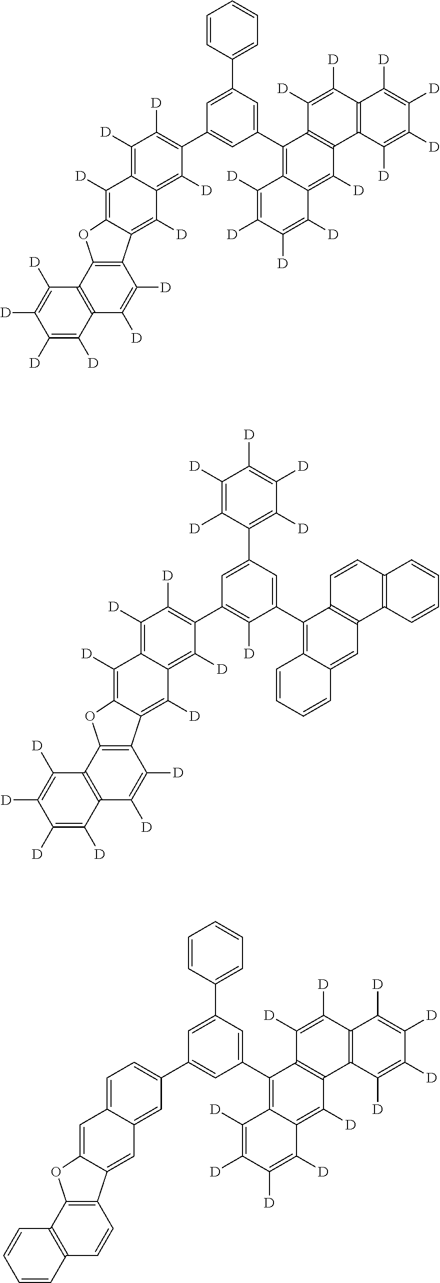

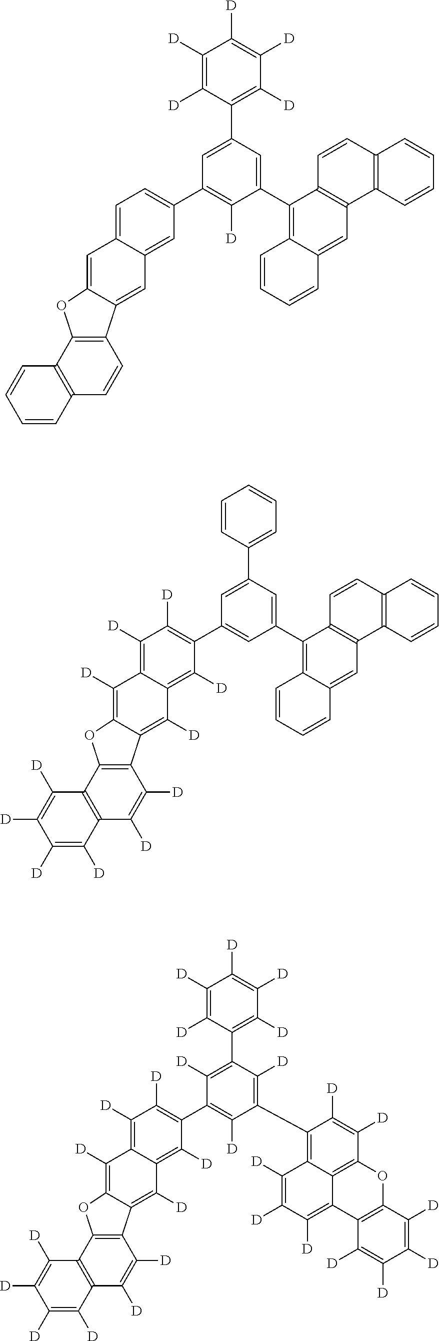

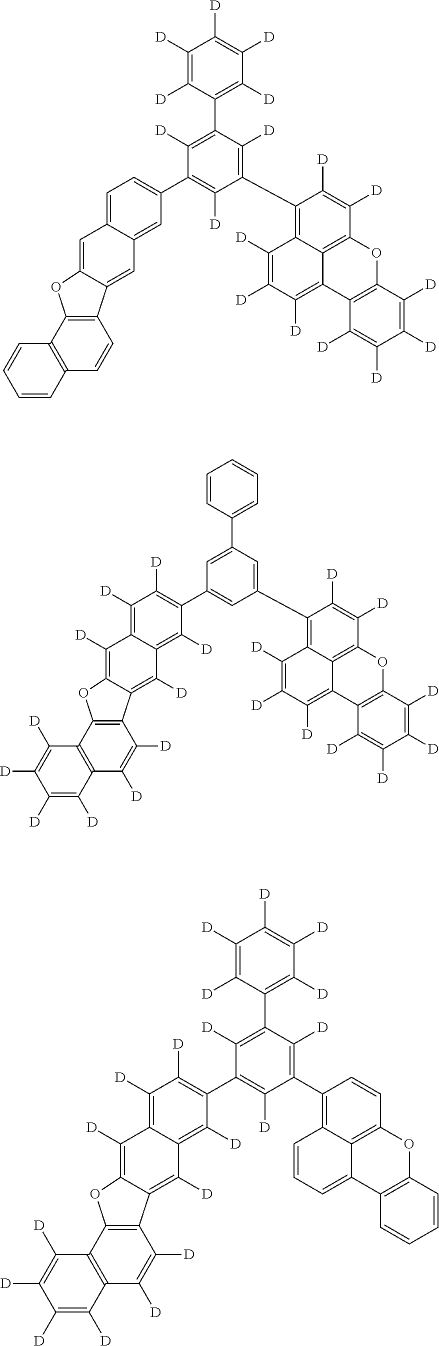

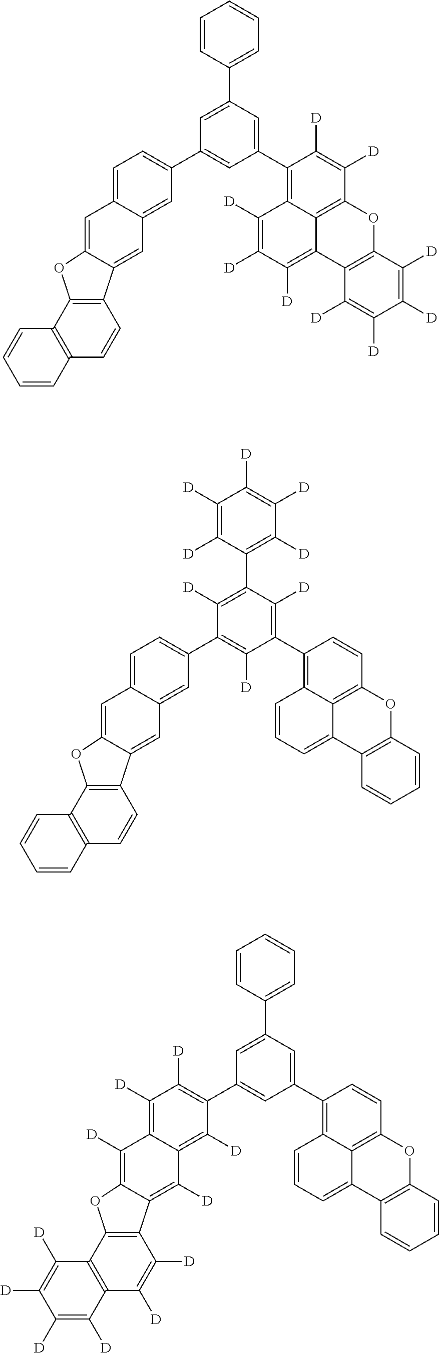 [SMILES: [2H]c1c([2H])c([2H])c2c(c1[2H])Oc1c([2H])c([2H])c(-c3cc(-c4ccccc4)cc(-c4ccc5cc6oc7c8ccccc8ccc7c6cc5c4)c3)c3c([2H])c([2H])c([2H])c-2c13 ; [2H]c1c([2H])c([2H])c(-c2c([2H])c(-c3ccc4cc5oc6c7ccccc7ccc6c5cc4c3)c([2H])c(-c3ccc4c5c(cccc35)-c3ccccc3O4)c2[2H])c([2H])c1[2H] ; [2H]c1c(-c2cc(-c3ccccc3)cc(-c3ccc4c5c(cccc35)-c3ccccc3O4)c2)c([2H])c2c([2H])c3c(oc4c5c([2H])c([2H])c([2H])c([2H])c5c([2H])c([2H])c43)c([2H])c2c1[2H]]

### [Compound Represented by Formula (3)]

The compound represented by the formula (3) is as follows:

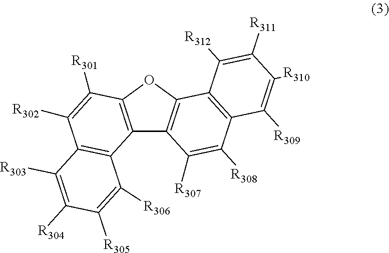

wherein in the formula (3),
at least one of R₃₀₁ to R₃₁₂ is a single bond bonded to a group represented by the following formula (A1):

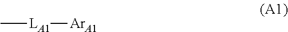

those in the formula (A1) are the same as those defined in the above formula (1), and
R₃₀₁ to R₃₁₂ which are not a single bond bonded to the group represented by the formula (A1) are independently
a hydrogen atom,
a substituted or unsubstituted aryl group having 6 to 20 ring carbon atoms, or
a substituted or unsubstituted monovalent heterocyclic group having 5 to 19 ring atoms.

In the formula (3), when L_{A1} of the formula (A1) is a single bond, Ar_{A1} is directly bonded to the dinaphthofuran skeleton.

The matter described for the formula (A1) in the compound represented by the formula (1) can also be applied to the compound represented by the formula (3).

In one embodiment, the compound represented by the formula (3) is a compound represented by the following formula (31):

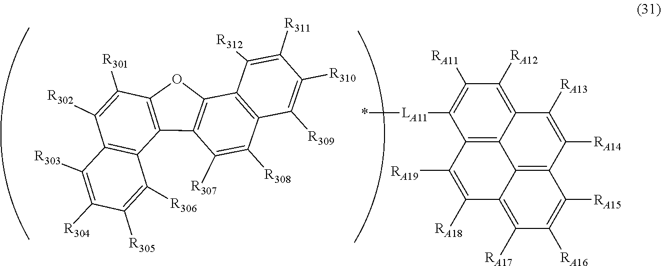

wherein in the formula (31),
at least one of R₃₀₁ to R₃₁₂ is a single bond bonded to L_{A11},
R₃₀₁ to R₃₁₂ which are not a single bond bonded to L_{A11} are independently
a hydrogen atom,
a substituted or unsubstituted aryl group having 6 to 20 ring carbon atoms, or
a substituted or unsubstituted monovalent heterocyclic group having 5 to 19 ring atoms,
L_{A11} is
a single bond, or
a substituted or unsubstituted arylene group having 6 to 20 ring carbon atoms,
R_{A11} to R_{A19} are independently a hydrogen atom or a substituent R, and
the substituent R is as defined in the above formula (11).

In the formula (31), when L_{A11} is a single bond, the pyrene skeleton is directly bonded to the dinaphthofuran skeleton.

In one embodiment, R_{A11} to R_{A19} are a hydrogen atom.

In one embodiment, at least one of R_{A11} to R_{A19} which are a hydrogen atom is a deuterium atom.

In one embodiment, the compound represented by the formula (3) is a compound represented by the following formula (32):

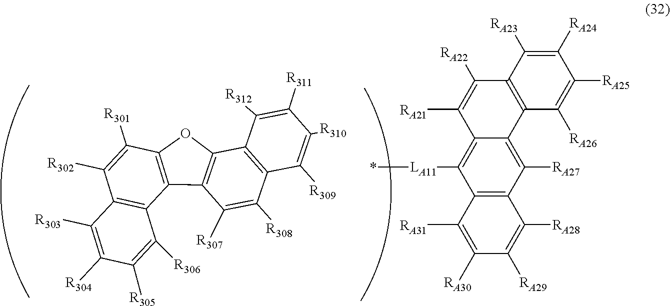

wherein in the formula (32),
at least one of R₃₀₁ to R₃₁₂ is a single bond bonded to L_{A11},
R₃₀₁ to R₃₁₂ which are not a single bond bonded to L_{A11} are independently
a hydrogen atom,
a substituted or unsubstituted aryl group having 6 to 20 ring carbon atoms, or
a substituted or unsubstituted monovalent heterocyclic group having 5 to 19 ring atoms, L_{A11} is
a single bond, or
a substituted or unsubstituted arylene group having 6 to 20 ring carbon atoms,
R_{A21} to R_{A31} are independently a hydrogen atom or a substituent R,
the substituent R is selected from the group consisting of
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,

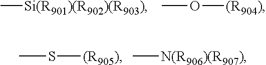

a halogen atom, a cyano group, a nitro group,
a substituted or unsubstituted aryl group having 6 to 50 ring carbon atoms, and
a substituted or unsubstituted monovalent heterocyclic group having 5 to 50 ring atoms,
when two or more substituents R are present, the two or more substituents R may be the same as or different from each other,
R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms, and
when two or more of each of R₉₀₁ to R₉₀₇ are present, the two or more of each of R₉₀₁ to R₉₀₇ may be the same as or different from each other.

In one embodiment, R_{A21} to R_{A31} are a hydrogen atom.

In one embodiment, at least one of R_{A21} to R_{A31} which are a hydrogen atom is a deuterium atom.

In one embodiment, R₃₀₁ to R₃₁₂ which are not a single bond bonded to L_{A11} are a hydrogen atom.

For the deuterium atom, the matter described in the compound represented by the formula (1) can be applied.

In one embodiment, a substituent in the case of “substituted or unsubstituted” in the above formula (3) is selected from the group consisting of
an alkyl group having 1 to 50 carbon atoms,
a haloalkyl group having 1 to 50 carbon atoms,
an alkenyl group having 2 to 50 carbon atoms,
an alkynyl group having 2 to 50 carbon atoms,
a cycloalkyl group having 3 to 50 ring carbon atoms,
an alkoxy group having 1 to 50 carbon atoms,
an alkylthio group having 1 to 50 carbon atoms,
an aryloxy group having 6 to 50 ring carbon atoms,
an arylthio group having 6 to 50 ring carbon atoms,
an aralkyl group having 7 to 50 carbon atoms,

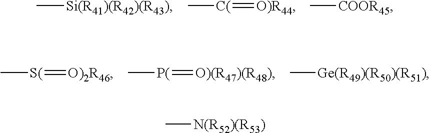

(wherein R₄₁ to R₅₃ are independently a hydrogen atom, an alkyl group having 1 to 50 carbon atoms, an aryl group having 6 to 50 ring carbon atoms, or a monovalent heterocyclic group having 5 to 50 ring atoms; when two or more of each of R₄₁ to R₅₃ are present, the two or more of each of R₄₁ to R₅₃ may be the same as or different from each other),
a hydroxy group,
a halogen atom,
a cyano group,
a nitro group,
an aryl group having 6 to 50 ring carbon atoms, and
a monovalent heterocyclic group having 5 to 50 ring atoms.

In one embodiment, a substituent in the case of “substituted or unsubstituted” in the above formula (3) is selected from the group consisting of
an alkyl group having 1 to 50 carbon atoms,
an aryl group having 6 to 50 ring carbon atoms, and
a monovalent heterocyclic group having 5 to 50 ring atoms.

In one embodiment, a substituent in the case of “substituted or unsubstituted” in the above formula (3) is
an unsubstituted aryl group having 6 to 20 ring carbon atoms, or
an unsubstituted monovalent heterocyclic group having 5 to 19 ring atoms.

The compound represented by the formula (3) can be synthesized by following Examples and using a known alternative reaction or raw material suited for an intended product.

Specific examples of the compound represented by the formula (3) will be described below, but these are merely examples, and the compound represented by the formula (3) is not limited to the following specific examples.

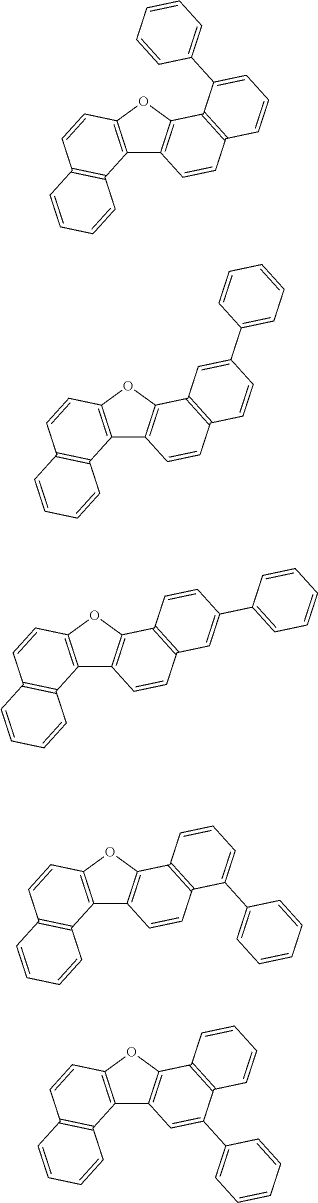 [SMILES: c1ccc(-c2cccc3ccc4c(oc5ccc6ccccc6c54)c23)cc1 ; c1ccc(-c2ccc3ccc4c(oc5ccc6ccccc6c54)c3c2)cc1 ; c1ccc(-c2ccc3c(ccc4c3oc3ccc5ccccc5c34)c2)cc1 ; c1ccc(-c2cccc3c2ccc2c3oc3ccc4ccccc4c32)cc1 ; c1ccc(-c2cc3c(oc4ccc5ccccc5c43)c3ccccc23)cc1]

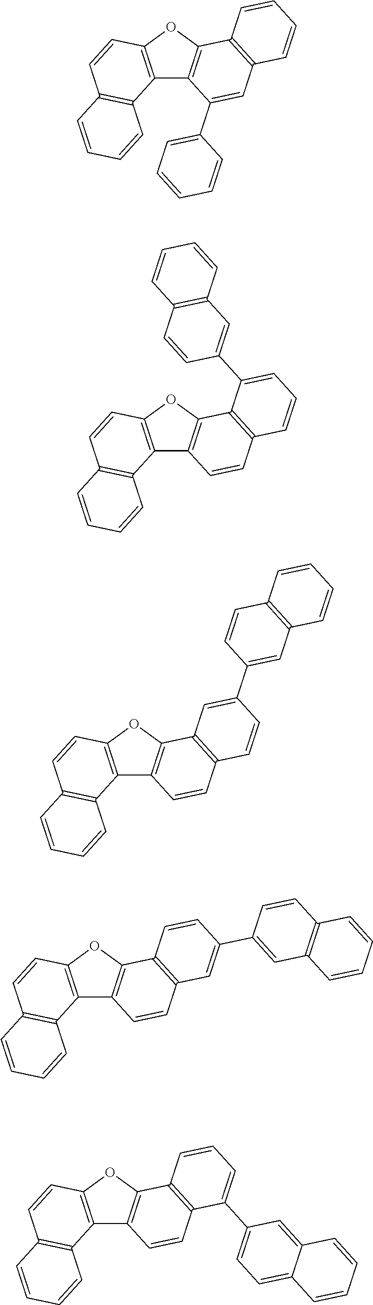 [SMILES: c1ccc(-c2cc3ccccc3c3oc4ccc5ccccc5c4c23)cc1 ; c1ccc2cc(-c3cccc4ccc5c(oc6ccc7ccccc7c65)c34)ccc2c1 ; c1ccc2cc(-c3ccc4ccc5c(oc6ccc7ccccc7c65)c4c3)ccc2c1 ; c1ccc2cc(-c3ccc4c(ccc5c4oc4ccc6ccccc6c45)c3)ccc2c1 ; c1ccc2cc(-c3cccc4c3ccc3c4oc4ccc5ccccc5c43)ccc2c1]

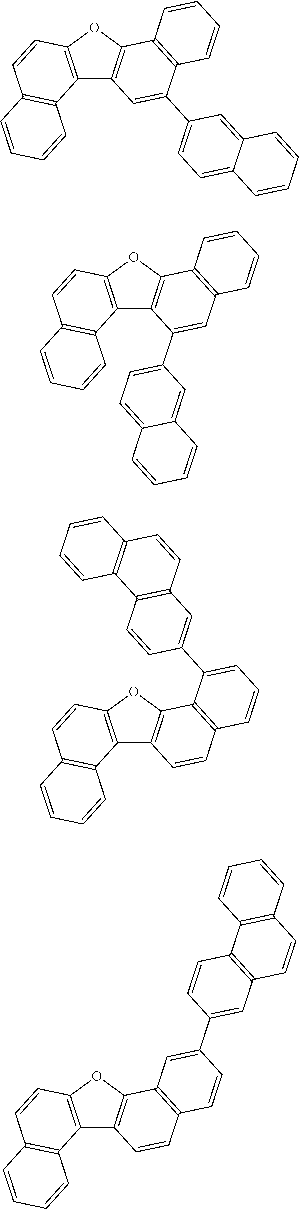

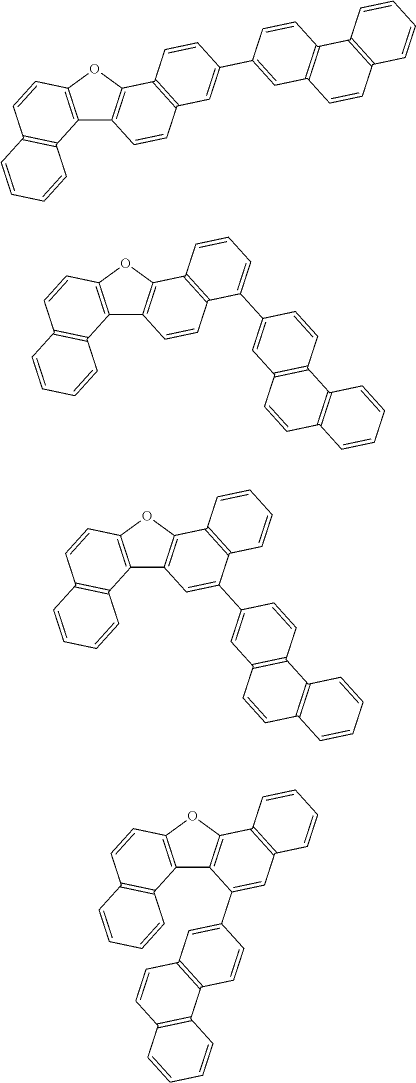 [SMILES: c1ccc2c(c1)ccc1cc(-c3ccc4c(ccc5c4oc4ccc6ccccc6c45)c3)ccc12 ; c1ccc2c(c1)ccc1cc(-c3cccc4c3ccc3c4oc4ccc5ccccc5c43)ccc12 ; c1ccc2c(c1)ccc1cc(-c3cc4c(oc5ccc6ccccc6c54)c4ccccc34)ccc12 ; c1ccc2c(c1)ccc1cc(-c3cc4ccccc4c4oc5ccc6ccccc6c5c34)ccc12]

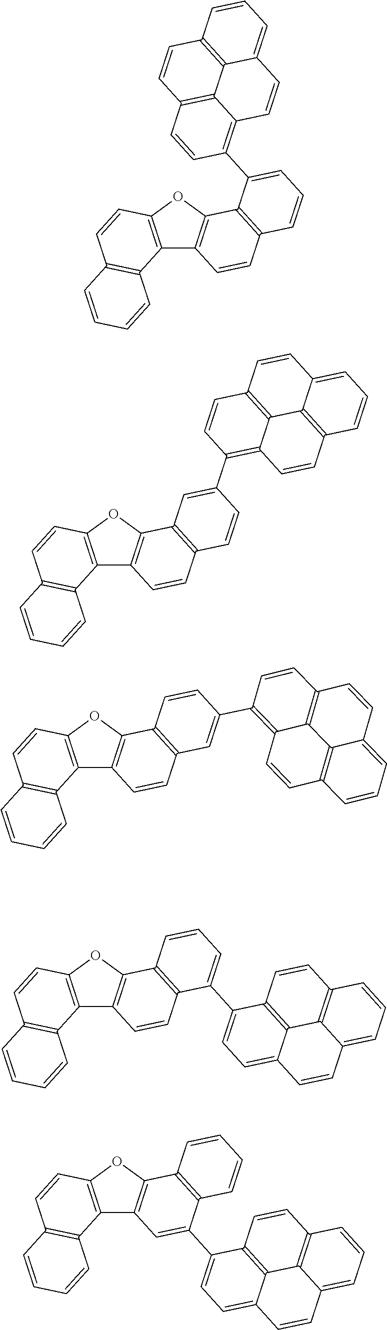 [SMILES: c1ccc2c(c1)ccc1oc3c(ccc4cccc(-c5ccc6ccc7cccc8ccc5c6c78)c43)c12 ; c1ccc2c(c1)ccc1oc3c4cc(-c5ccc6ccc7cccc8ccc5c6c78)ccc4ccc3c12 ; c1ccc2c(c1)ccc1oc3c4ccc(-c5ccc6ccc7cccc8ccc5c6c78)cc4ccc3c12 ; c1ccc2c(c1)ccc1oc3c4cccc(-c5ccc6ccc7cccc8ccc5c6c78)c4ccc3c12 ; c1ccc2c(c1)ccc1oc3c4ccccc4c(-c4ccc5ccc6cccc7ccc4c5c67)cc3c12]

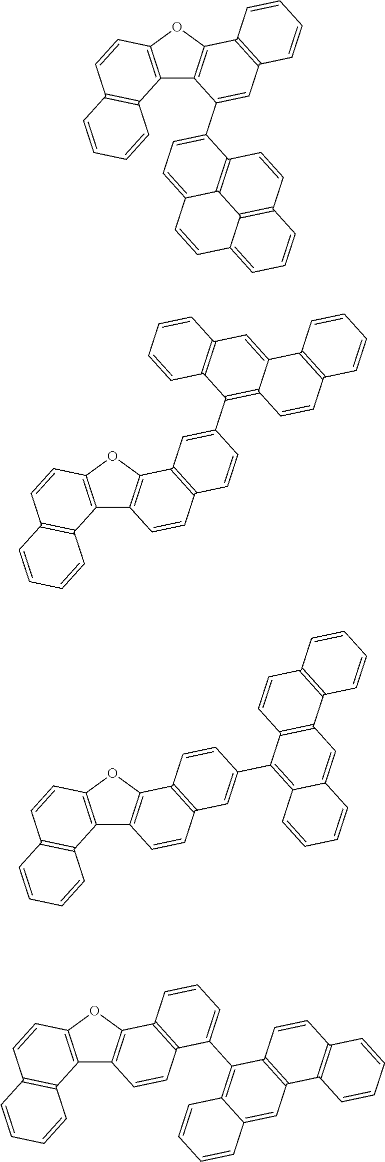 [SMILES: c1ccc2c(c1)cc(-c1ccc3ccc4cccc5ccc1c3c45)c1c2oc2ccc3ccccc3c21 ; c1ccc2c(-c3ccc4ccc5c(oc6ccc7ccccc7c65)c4c3)c3ccc4ccccc4c3cc2c1 ; c1ccc2c(-c3ccc4c(ccc5c4oc4ccc6ccccc6c45)c3)c3ccc4ccccc4c3cc2c1 ; c1ccc2c(-c3cccc4c3ccc3c4oc4ccc5ccccc5c43)c3ccc4ccccc4c3cc2c1]

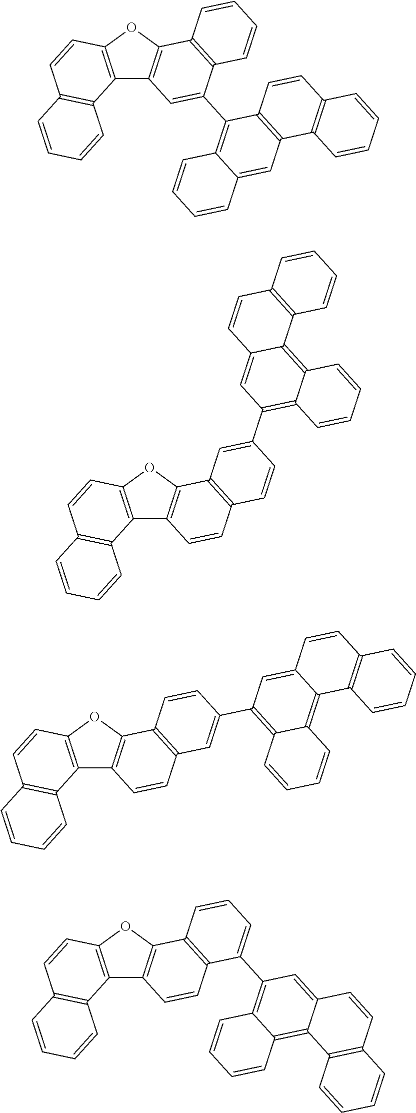 [SMILES: c1ccc2c(-c3cc4c(oc5ccc6ccccc6c54)c4ccccc34)c3ccc4ccccc4c3cc2c1 ; c1ccc2c(c1)ccc1cc(-c3ccc4ccc5c(oc6ccc7ccccc7c65)c4c3)c3ccccc3c12 ; c1ccc2c(c1)ccc1cc(-c3ccc4c(ccc5c4oc4ccc6ccccc6c45)c3)c3ccccc3c12 ; c1ccc2c(c1)ccc1cc(-c3cccc4c3ccc3c4oc4ccc5ccccc5c43)c3ccccc3c12]

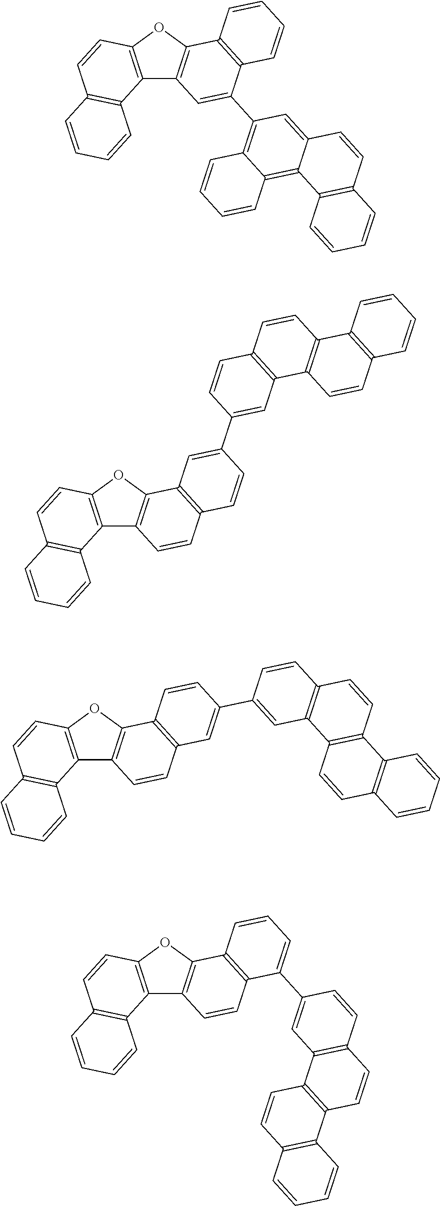 [SMILES: c1ccc2c(c1)ccc1cc(-c3cc4c(oc5ccc6ccccc6c54)c4ccccc34)c3ccccc3c12 ; c1ccc2c(c1)ccc1c3cc(-c4ccc5ccc6c(oc7ccc8ccccc8c76)c5c4)ccc3ccc21 ; c1ccc2c(c1)ccc1c3cc(-c4ccc5c(ccc6c5oc5ccc7ccccc7c56)c4)ccc3ccc21 ; c1ccc2c(c1)ccc1c3cc(-c4cccc5c4ccc4c5oc5ccc6ccccc6c54)ccc3ccc21]

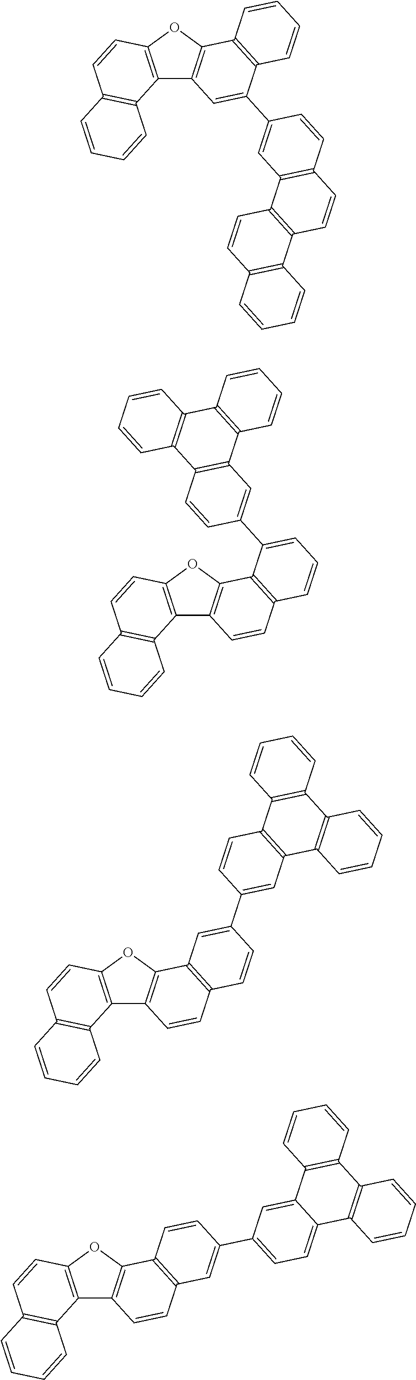

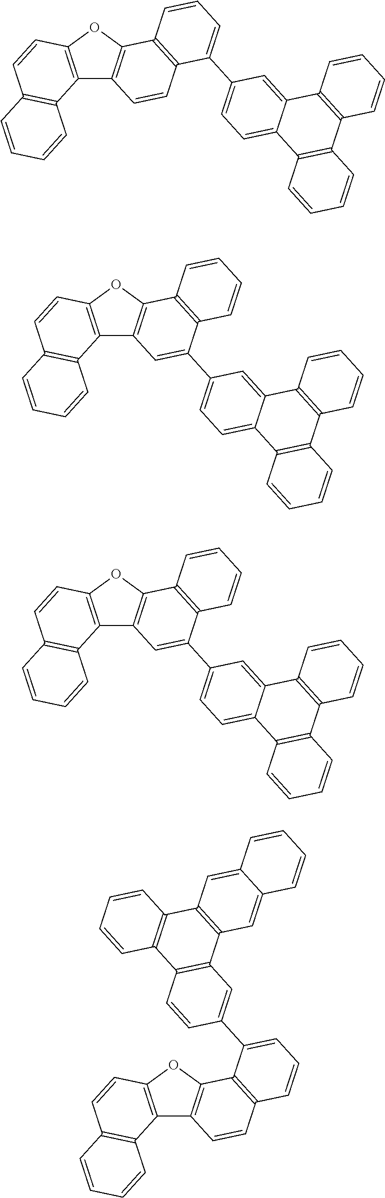

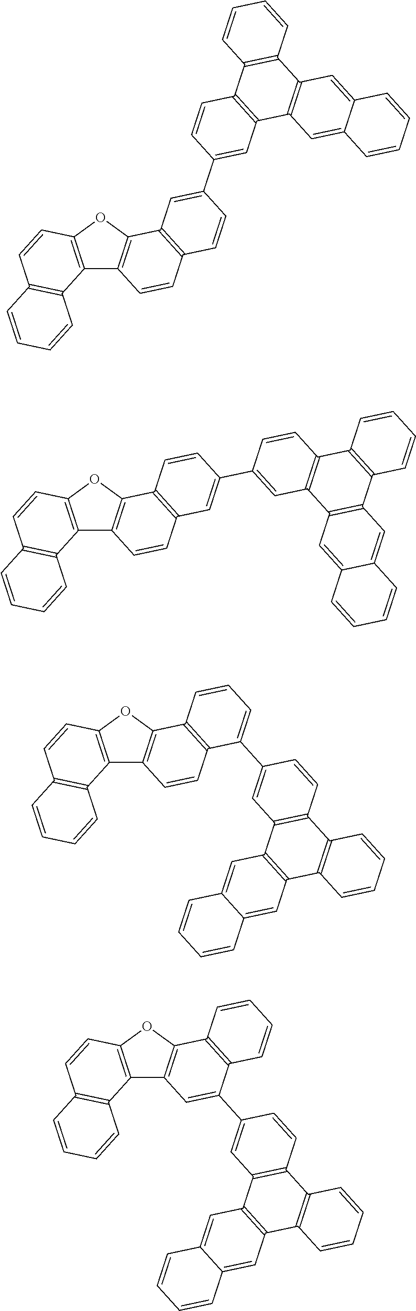 [SMILES: c1ccc2cc3c4cc(-c5ccc6ccc7c(oc8ccc9ccccc9c87)c6c5)ccc4c4ccccc4c3cc2c1 ; c1ccc2cc3c4cc(-c5ccc6c(ccc7c6oc6ccc8ccccc8c67)c5)ccc4c4ccccc4c3cc2c1 ; c1ccc2cc3c4cc(-c5cccc6c5ccc5c6oc6ccc7ccccc7c65)ccc4c4ccccc4c3cc2c1 ; c1ccc2cc3c4cc(-c5cc6c(oc7ccc8ccccc8c76)c6ccccc56)ccc4c4ccccc4c3cc2c1]

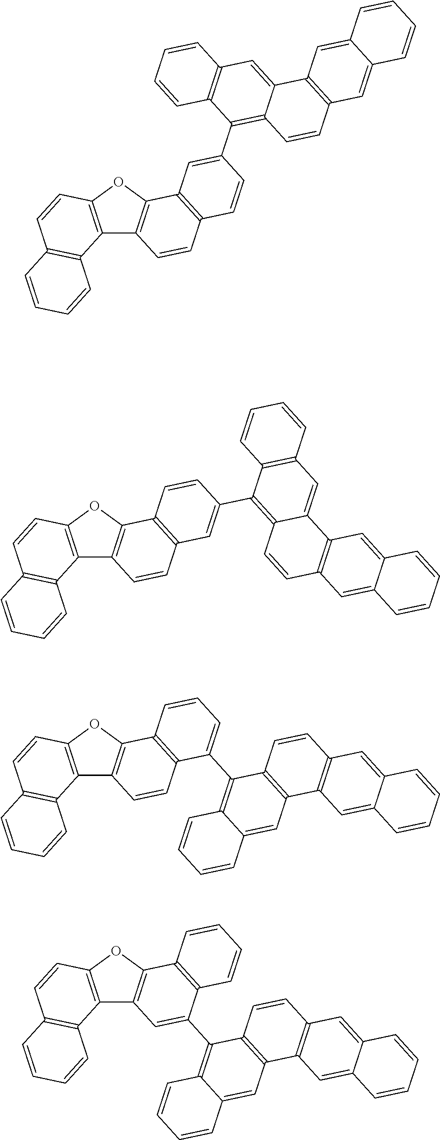 [SMILES: c1ccc2cc3c(ccc4c(-c5ccc6ccc7c(oc8ccc9ccccc9c87)c6c5)c5ccccc5cc43)cc2c1 ; c1ccc2cc3c(ccc4c(-c5ccc6c(ccc7c6oc6ccc8ccccc8c67)c5)c5ccccc5cc43)cc2c1 ; c1ccc2cc3c(ccc4c(-c5cccc6c5ccc5c6oc6ccc7ccccc7c65)c5ccccc5cc43)cc2c1 ; c1ccc2cc3c(ccc4c(-c5cc6c(oc7ccc8ccccc8c76)c6ccccc56)c5ccccc5cc43)cc2c1]

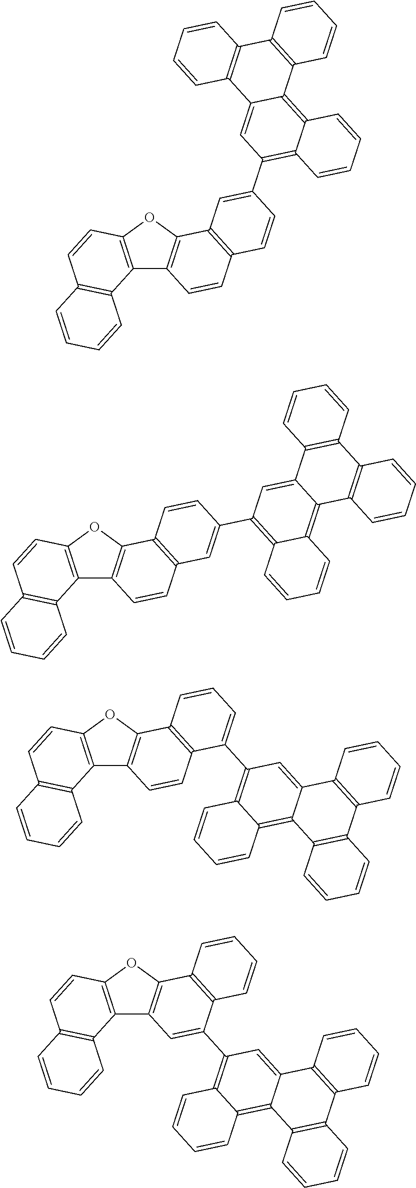 [SMILES: c1ccc2c(c1)ccc1oc3c4cc(-c5cc6c7ccccc7c7ccccc7c6c6ccccc56)ccc4ccc3c12 ; c1ccc2c(c1)ccc1oc3c4ccc(-c5cc6c7ccccc7c7ccccc7c6c6ccccc56)cc4ccc3c12 ; c1ccc2c(c1)ccc1oc3c4cccc(-c5cc6c7ccccc7c7ccccc7c6c6ccccc56)c4ccc3c12 ; c1ccc2c(c1)ccc1oc3c4ccccc4c(-c4cc5c6ccccc6c6ccccc6c5c5ccccc45)cc3c12]

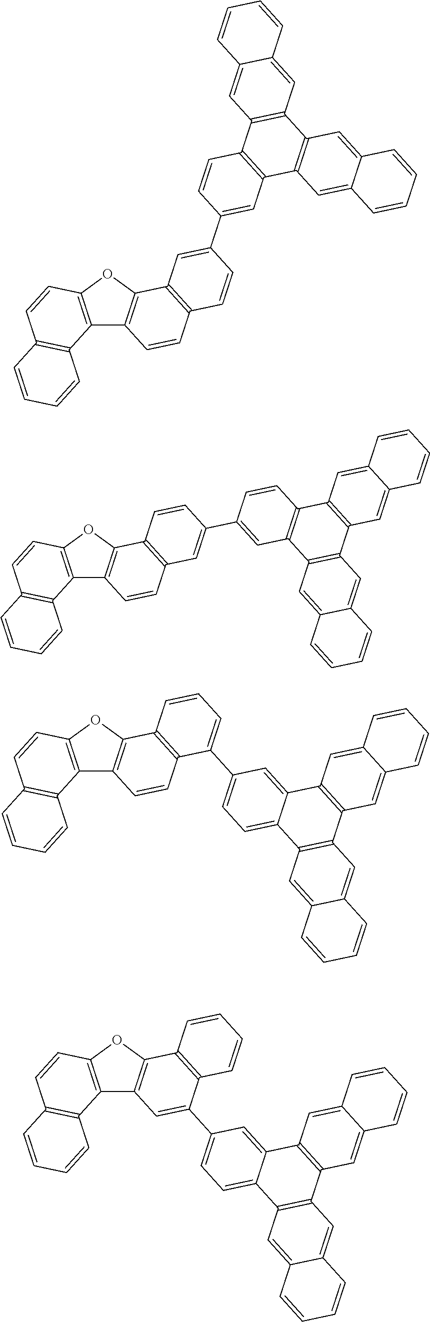 [SMILES: c1ccc2cc3c(cc2c1)c1ccc(-c2ccc4ccc5c(oc6ccc7ccccc7c65)c4c2)cc1c1cc2ccccc2cc13 ; c1ccc2cc3c(cc2c1)c1ccc(-c2ccc4c(ccc5c4oc4ccc6ccccc6c45)c2)cc1c1cc2ccccc2cc13 ; c1ccc2cc3c(cc2c1)c1ccc(-c2cccc4c2ccc2c4oc4ccc5ccccc5c42)cc1c1cc2ccccc2cc13 ; c1ccc2cc3c(cc2c1)c1ccc(-c2cc4c(oc5ccc6ccccc6c54)c4ccccc24)cc1c1cc2ccccc2cc13]

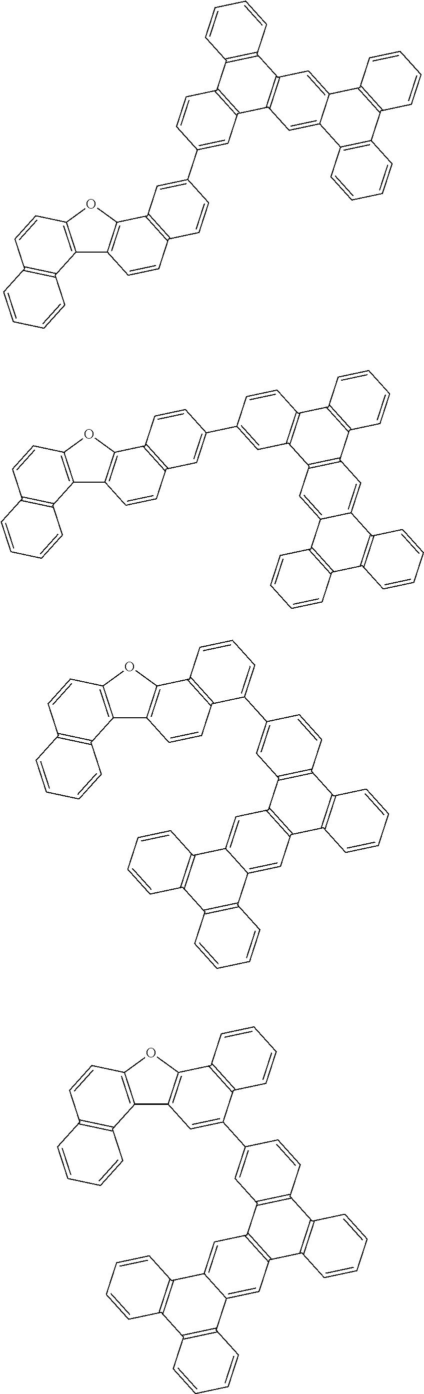 [SMILES: c1ccc2c(c1)ccc1oc3c4cc(-c5ccc6c7ccccc7c7cc8c9ccccc9c9ccccc9c8cc7c6c5)ccc4ccc3c12 ; c1ccc2c(c1)ccc1oc3c4ccc(-c5ccc6c7ccccc7c7cc8c9ccccc9c9ccccc9c8cc7c6c5)cc4ccc3c12 ; c1ccc2c(c1)ccc1oc3c4cccc(-c5ccc6c7ccccc7c7cc8c9ccccc9c9ccccc9c8cc7c6c5)c4ccc3c12 ; c1ccc2c(c1)ccc1oc3c4ccccc4c(-c4ccc5c6ccccc6c6cc7c8ccccc8c8ccccc8c7cc6c5c4)cc3c12]

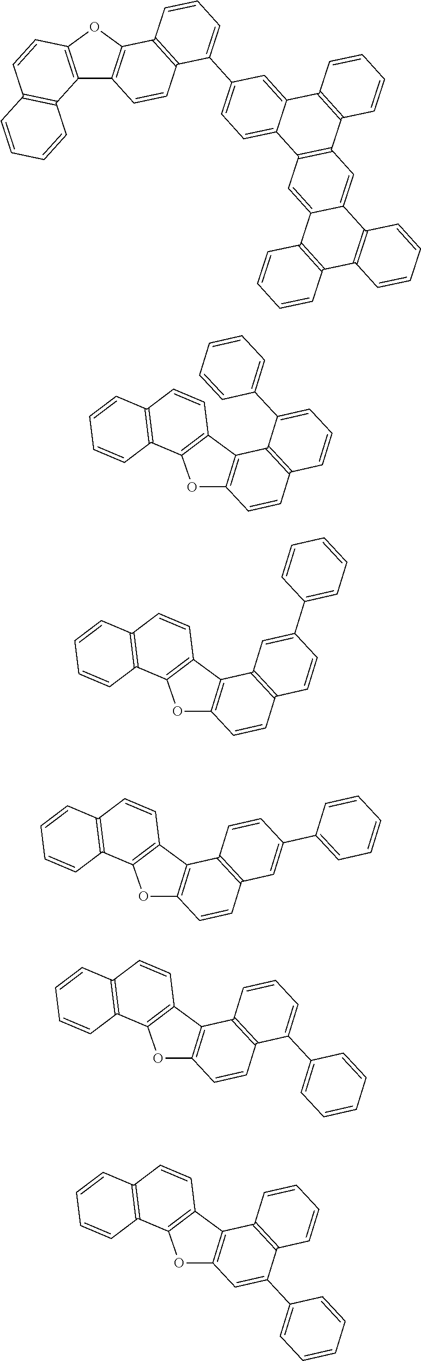

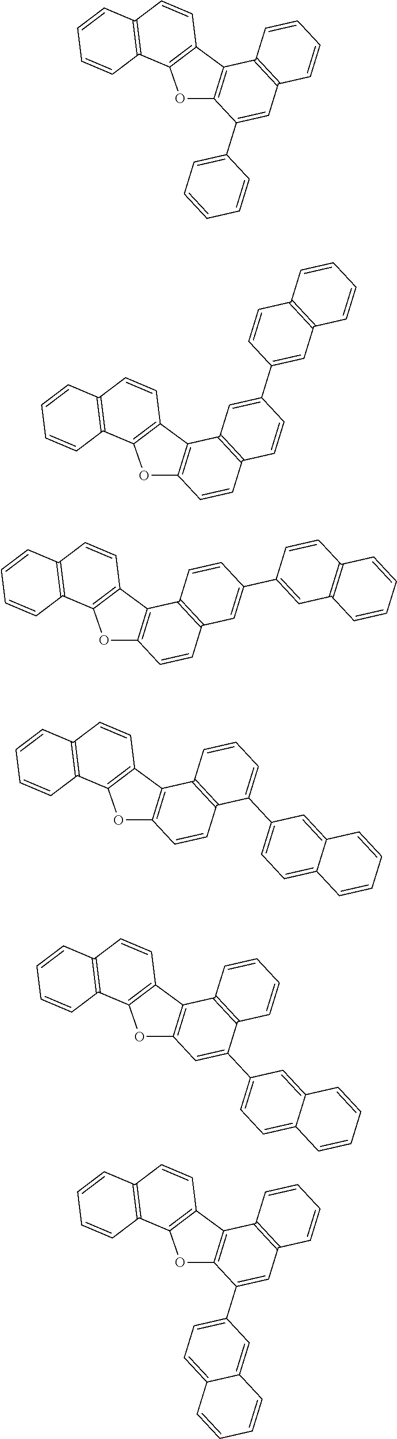

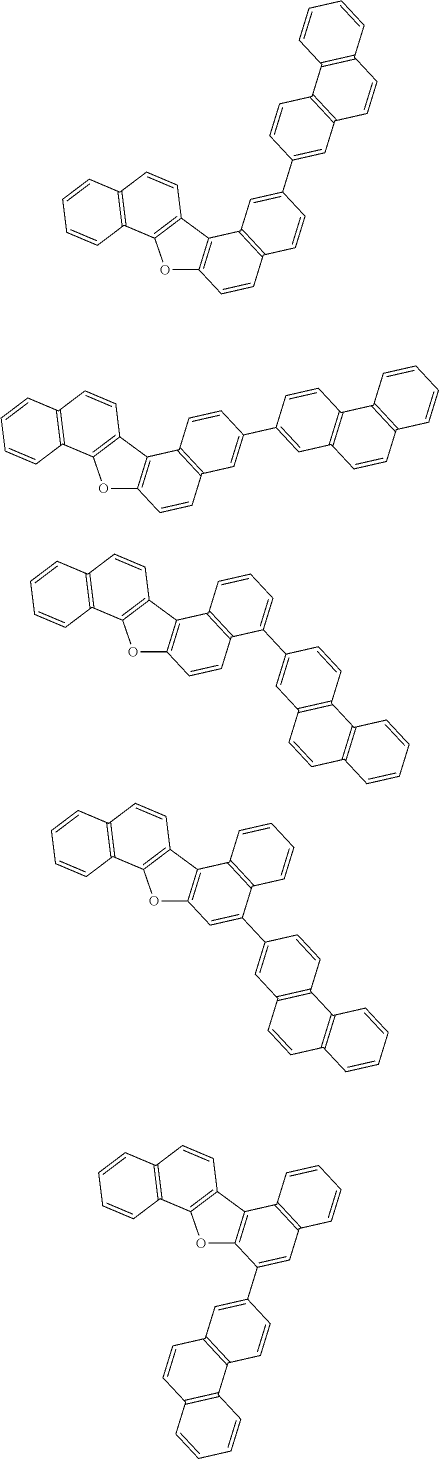 [SMILES: c1ccc2c(c1)ccc1cc(-c3ccc4ccc5oc6c7ccccc7ccc6c5c4c3)ccc12 ; c1ccc2c(c1)ccc1cc(-c3ccc4c(ccc5oc6c7ccccc7ccc6c54)c3)ccc12 ; c1ccc2c(c1)ccc1cc(-c3cccc4c3ccc3oc5c6ccccc6ccc5c34)ccc12 ; c1ccc2c(c1)ccc1cc(-c3cc4oc5c6ccccc6ccc5c4c4ccccc34)ccc12 ; c1ccc2c(c1)ccc1cc(-c3cc4ccccc4c4c3oc3c5ccccc5ccc34)ccc12]

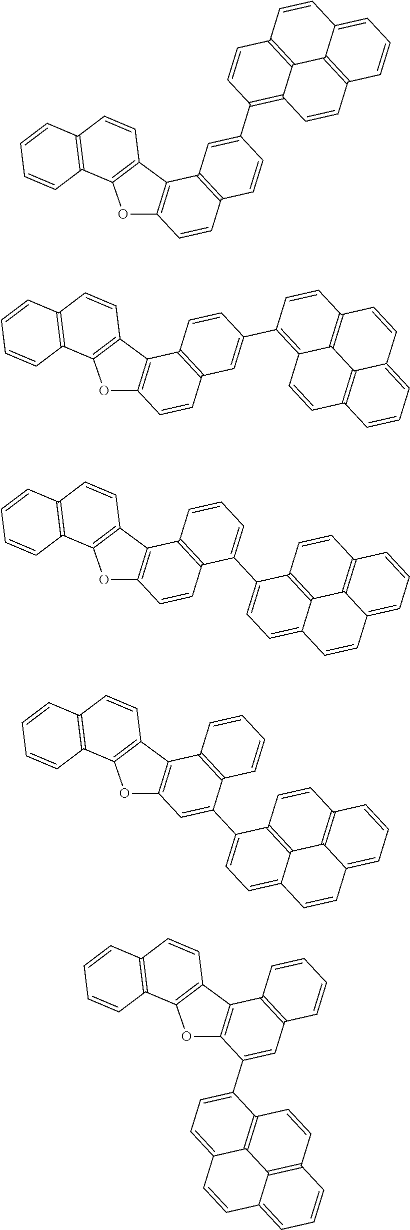 [SMILES: c1ccc2c(c1)ccc1c2oc2ccc3ccc(-c4ccc5ccc6cccc7ccc4c5c67)cc3c21 ; c1ccc2c(c1)ccc1c2oc2ccc3cc(-c4ccc5ccc6cccc7ccc4c5c67)ccc3c21 ; c1ccc2c(c1)ccc1c2oc2ccc3c(-c4ccc5ccc6cccc7ccc4c5c67)cccc3c21 ; c1ccc2c(c1)ccc1c2oc2cc(-c3ccc4ccc5cccc6ccc3c4c56)c3ccccc3c21 ; c1ccc2c(c1)ccc1c2oc2c(-c3ccc4ccc5cccc6ccc3c4c56)cc3ccccc3c21]

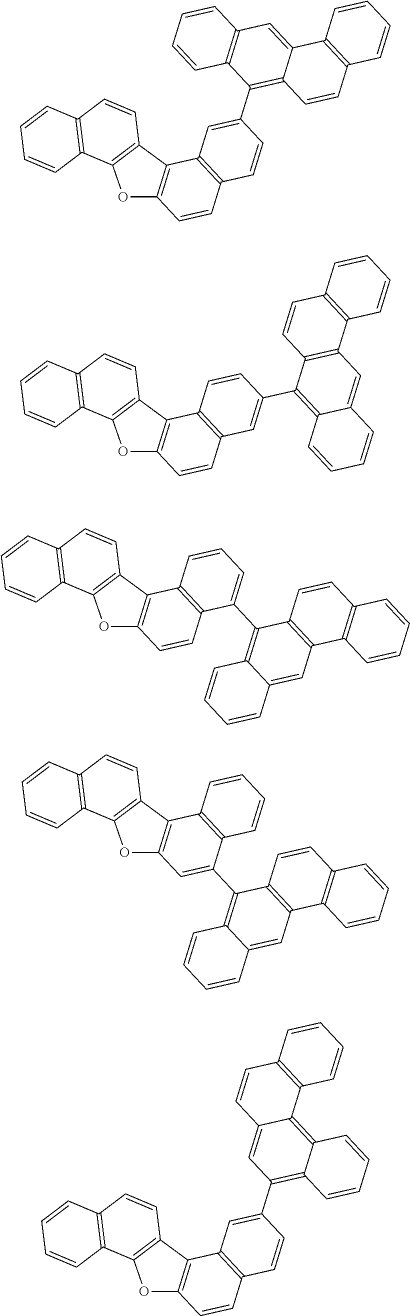 [SMILES: c1ccc2c(-c3ccc4ccc5oc6c7ccccc7ccc6c5c4c3)c3ccc4ccccc4c3cc2c1 ; c1ccc2c(-c3ccc4c(ccc5oc6c7ccccc7ccc6c54)c3)c3ccc4ccccc4c3cc2c1 ; c1ccc2c(-c3cccc4c3ccc3oc5c6ccccc6ccc5c34)c3ccc4ccccc4c3cc2c1 ; c1ccc2c(-c3cc4oc5c6ccccc6ccc5c4c4ccccc34)c3ccc4ccccc4c3cc2c1 ; c1ccc2c(c1)ccc1c2oc2ccc3ccc(-c4cc5ccc6ccccc6c5c5ccccc45)cc3c21]

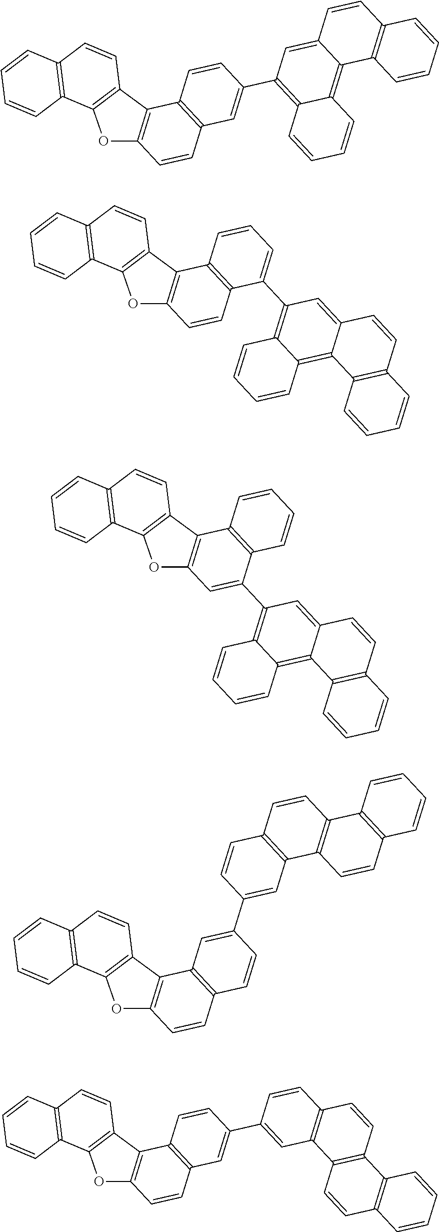 [SMILES: c1ccc2c(c1)ccc1c2oc2ccc3cc(-c4cc5ccc6ccccc6c5c5ccccc45)ccc3c21 ; c1ccc2c(c1)ccc1c2oc2ccc3c(-c4cc5ccc6ccccc6c5c5ccccc45)cccc3c21 ; c1ccc2c(c1)ccc1c2oc2cc(-c3cc4ccc5ccccc5c4c4ccccc34)c3ccccc3c21 ; c1ccc2c(c1)ccc1c3cc(-c4ccc5ccc6oc7c8ccccc8ccc7c6c5c4)ccc3ccc21 ; c1ccc2c(c1)ccc1c3cc(-c4ccc5c(ccc6oc7c8ccccc8ccc7c65)c4)ccc3ccc21]

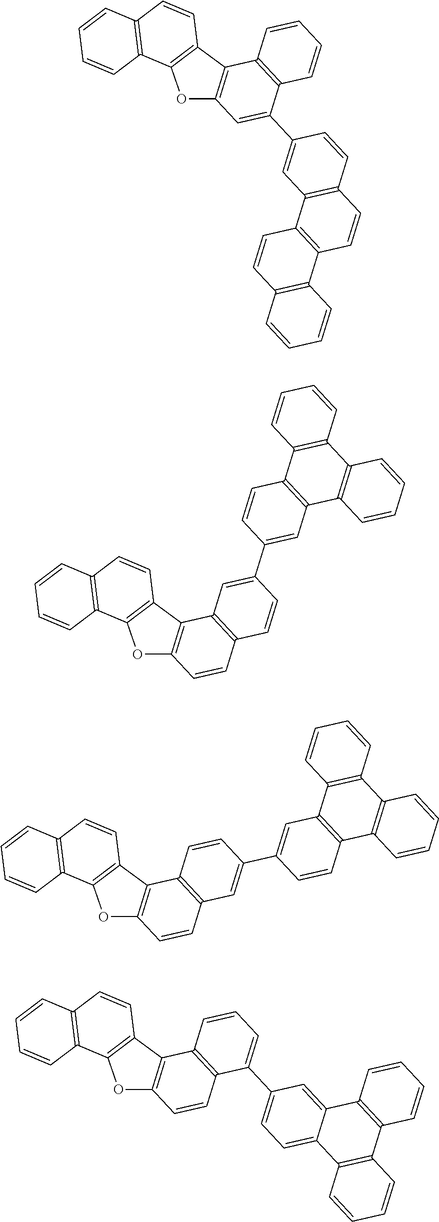

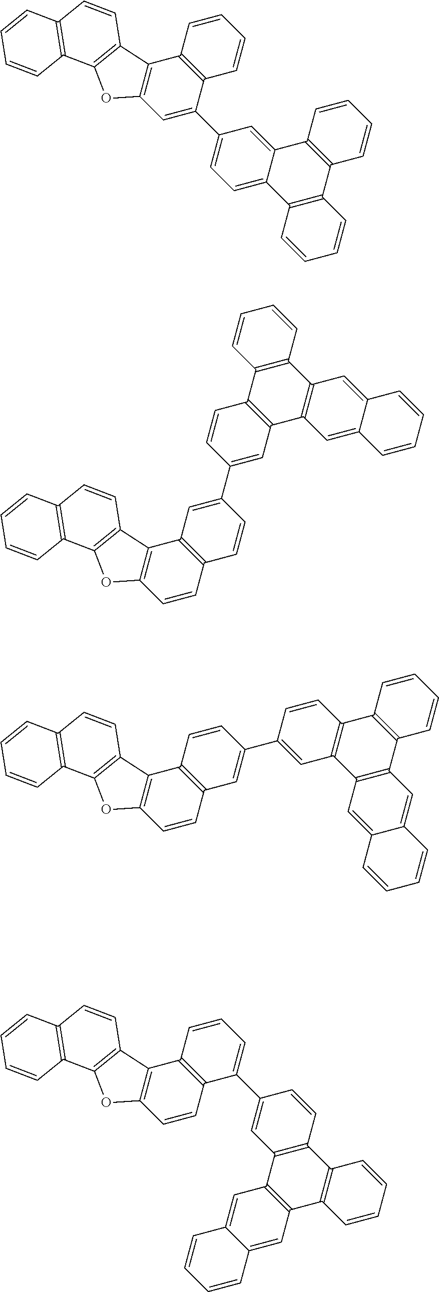 [SMILES: c1ccc2c(c1)ccc1c2oc2cc(-c3ccc4c5ccccc5c5ccccc5c4c3)c3ccccc3c21 ; c1ccc2cc3c4cc(-c5ccc6ccc7oc8c9ccccc9ccc8c7c6c5)ccc4c4ccccc4c3cc2c1 ; c1ccc2cc3c4cc(-c5ccc6c(ccc7oc8c9ccccc9ccc8c76)c5)ccc4c4ccccc4c3cc2c1 ; c1ccc2cc3c4cc(-c5cccc6c5ccc5oc7c8ccccc8ccc7c56)ccc4c4ccccc4c3cc2c1]

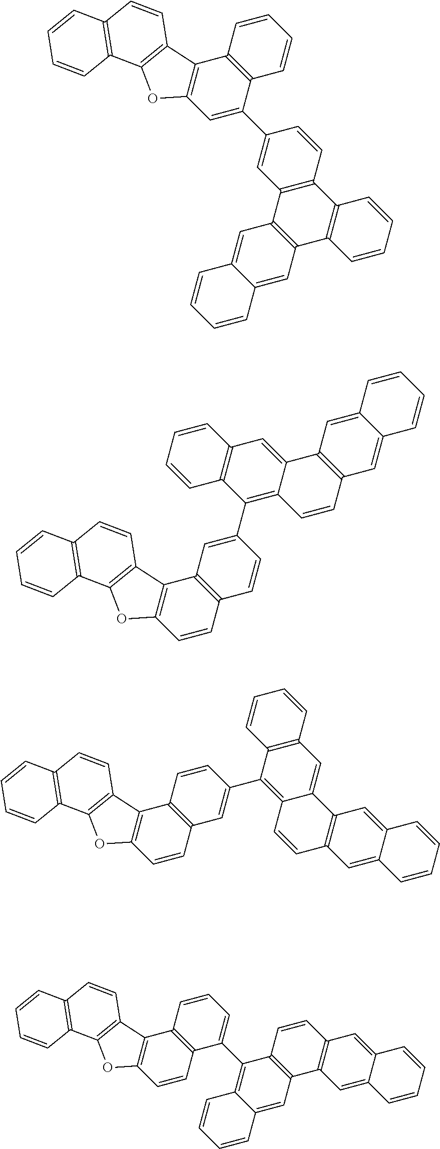 [SMILES: c1ccc2cc3c4cc(-c5cc6oc7c8ccccc8ccc7c6c6ccccc56)ccc4c4ccccc4c3cc2c1 ; c1ccc2cc3c(ccc4c(-c5ccc6ccc7oc8c9ccccc9ccc8c7c6c5)c5ccccc5cc43)cc2c1 ; c1ccc2cc3c(ccc4c(-c5ccc6c(ccc7oc8c9ccccc9ccc8c76)c5)c5ccccc5cc43)cc2c1 ; c1ccc2cc3c(ccc4c(-c5cccc6c5ccc5oc7c8ccccc8ccc7c56)c5ccccc5cc43)cc2c1]

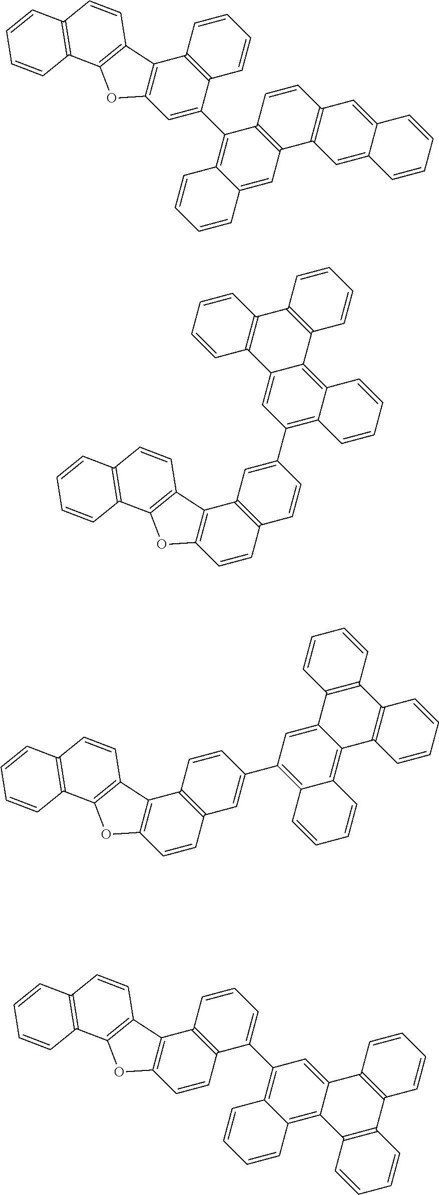 [SMILES: c1ccc2cc3c(ccc4c(-c5cc6oc7c8ccccc8ccc7c6c6ccccc56)c5ccccc5cc43)cc2c1 ; c1ccc2c(c1)ccc1c2oc2ccc3ccc(-c4cc5c6ccccc6c6ccccc6c5c5ccccc45)cc3c21 ; c1ccc2c(c1)ccc1c2oc2ccc3cc(-c4cc5c6ccccc6c6ccccc6c5c5ccccc45)ccc3c21 ; c1ccc2c(c1)ccc1c2oc2ccc3c(-c4cc5c6ccccc6c6ccccc6c5c5ccccc45)cccc3c21]

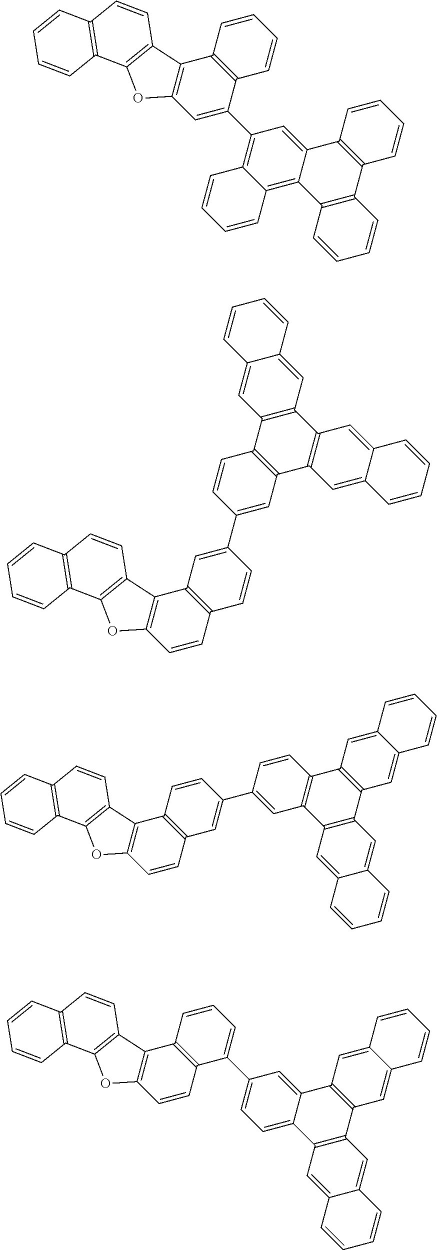 [SMILES: c1ccc2c(c1)ccc1c2oc2cc(-c3cc4c5ccccc5c5ccccc5c4c4ccccc34)c3ccccc3c21 ; c1ccc2cc3c(cc2c1)c1ccc(-c2ccc4ccc5oc6c7ccccc7ccc6c5c4c2)cc1c1cc2ccccc2cc13 ; c1ccc2cc3c(cc2c1)c1ccc(-c2ccc4c(ccc5oc6c7ccccc7ccc6c54)c2)cc1c1cc2ccccc2cc13 ; c1ccc2cc3c(cc2c1)c1ccc(-c2cccc4c2ccc2oc5c6ccccc6ccc5c24)cc1c1cc2ccccc2cc13]

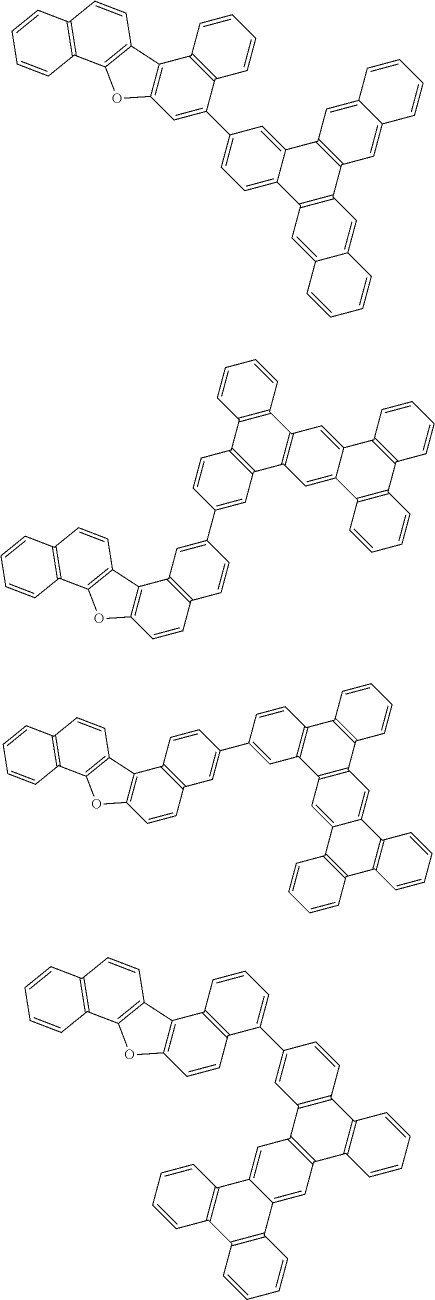 [SMILES: c1ccc2cc3c(cc2c1)c1ccc(-c2cc4oc5c6ccccc6ccc5c4c4ccccc24)cc1c1cc2ccccc2cc13 ; c1ccc2c(c1)ccc1c2oc2ccc3ccc(-c4ccc5c6ccccc6c6cc7c8ccccc8c8ccccc8c7cc6c5c4)cc3c21 ; c1ccc2c(c1)ccc1c2oc2ccc3cc(-c4ccc5c6ccccc6c6cc7c8ccccc8c8ccccc8c7cc6c5c4)ccc3c21 ; c1ccc2c(c1)ccc1c2oc2ccc3c(-c4ccc5c6ccccc6c6cc7c8ccccc8c8ccccc8c7cc6c5c4)cccc3c21]

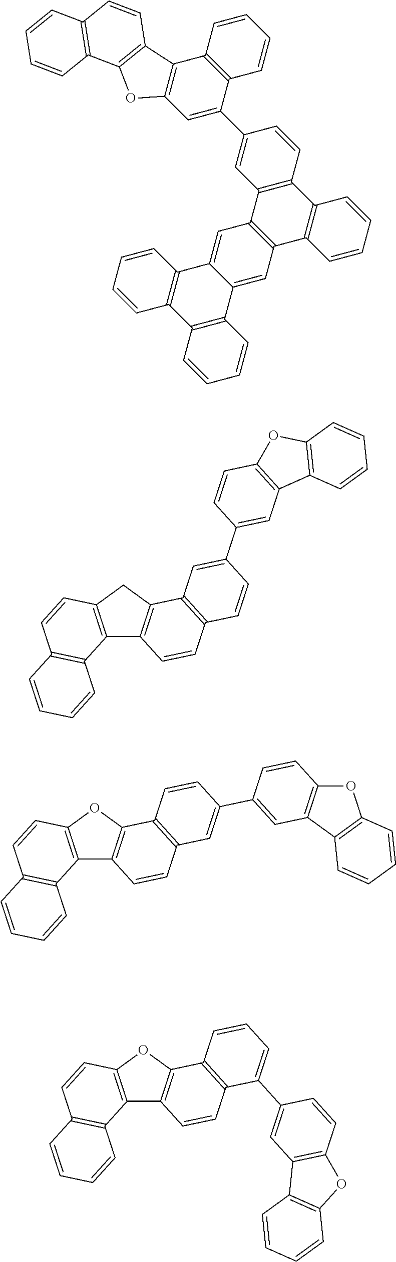 [SMILES: c1ccc2c(c1)ccc1c2oc2cc(-c3ccc4c5ccccc5c5cc6c7ccccc7c7ccccc7c6cc5c4c3)c3ccccc3c21 ; c1ccc2c3c(ccc2c1)Cc1c-3ccc2ccc(-c3ccc4oc5ccccc5c4c3)cc12 ; c1ccc2c(c1)ccc1oc3c4ccc(-c5ccc6oc7ccccc7c6c5)cc4ccc3c12 ; c1ccc2c(c1)ccc1oc3c4cccc(-c5ccc6oc7ccccc7c6c5)c4ccc3c12]

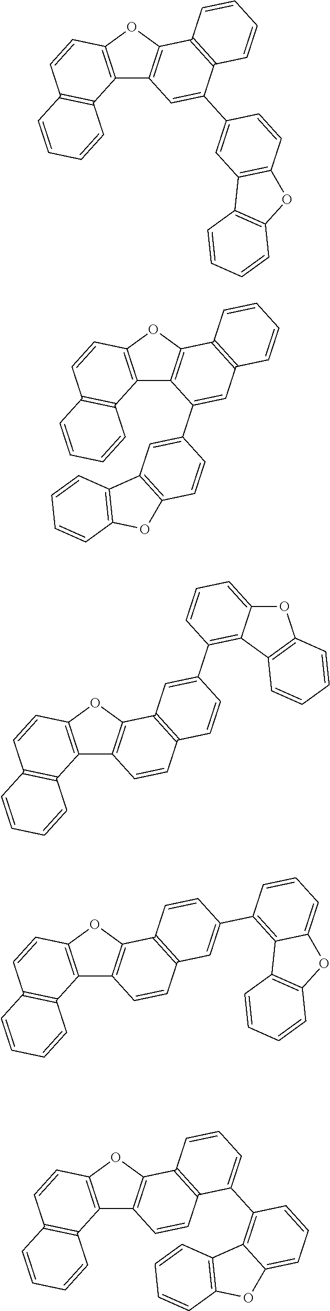

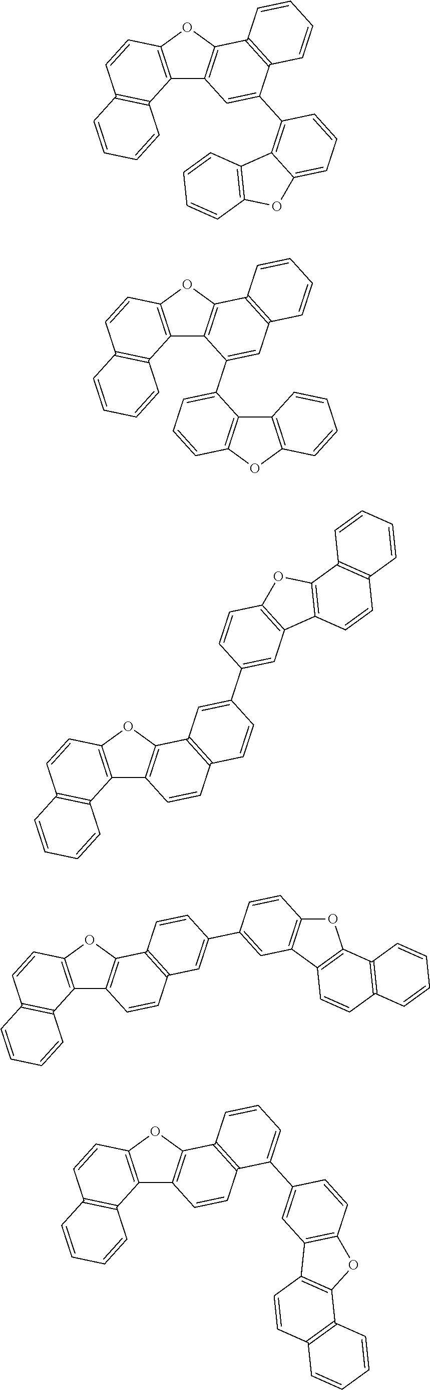 [SMILES: c1ccc2c(c1)ccc1oc3c4ccccc4c(-c4cccc5oc6ccccc6c45)cc3c12 ; c1ccc2c(c1)cc(-c1cccc3oc4ccccc4c13)c1c2oc2ccc3ccccc3c21 ; c1ccc2c(c1)ccc1c3cc(-c4ccc5ccc6c(oc7ccc8ccccc8c76)c5c4)ccc3oc21 ; c1ccc2c(c1)ccc1c3cc(-c4ccc5c(ccc6c5oc5ccc7ccccc7c56)c4)ccc3oc21 ; c1ccc2c(c1)ccc1c3cc(-c4cccc5c4ccc4c5oc5ccc6ccccc6c54)ccc3oc21]

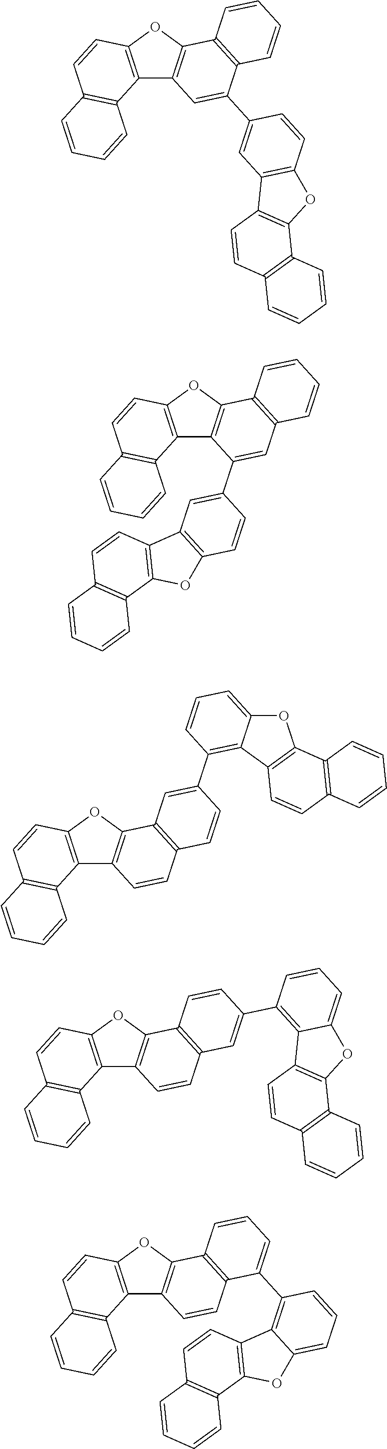

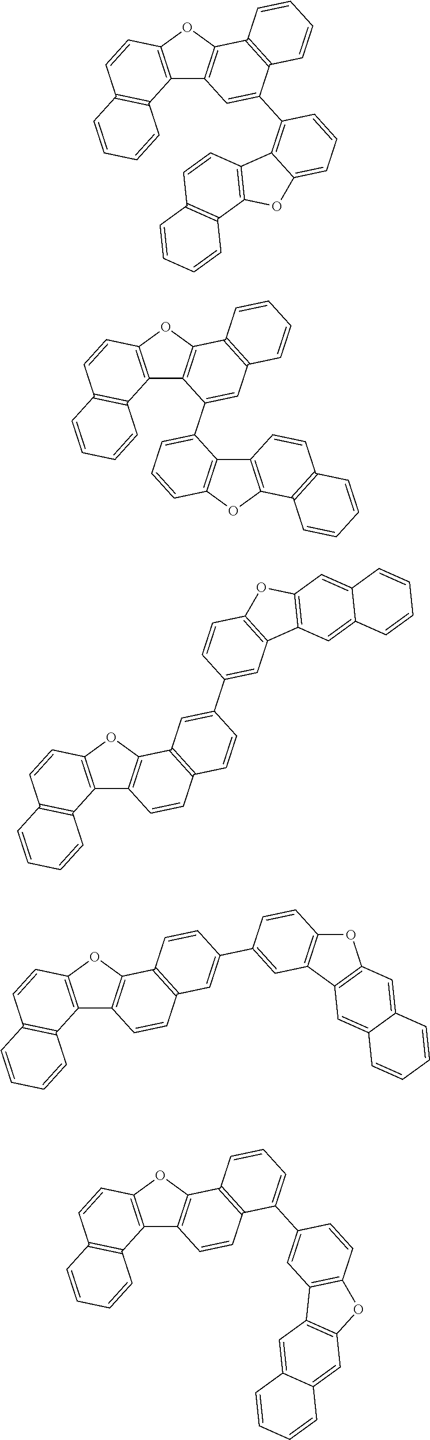

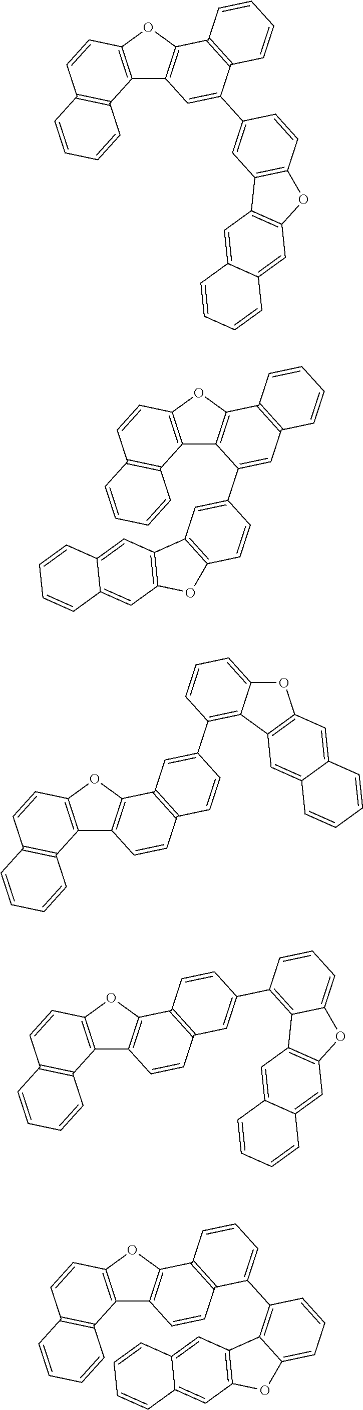 [SMILES: c1ccc2cc3c(cc2c1)oc1ccc(-c2cc4c(oc5ccc6ccccc6c54)c4ccccc24)cc13 ; c1ccc2cc3c(cc2c1)oc1ccc(-c2cc4ccccc4c4oc5ccc6ccccc6c5c24)cc13 ; c1ccc2cc3c(cc2c1)oc1cccc(-c2ccc4ccc5c(oc6ccc7ccccc7c65)c4c2)c13 ; c1ccc2cc3c(cc2c1)oc1cccc(-c2ccc4c(ccc5c4oc4ccc6ccccc6c45)c2)c13 ; c1ccc2cc3c(cc2c1)oc1cccc(-c2cccc4c2ccc2c4oc4ccc5ccccc5c42)c13]

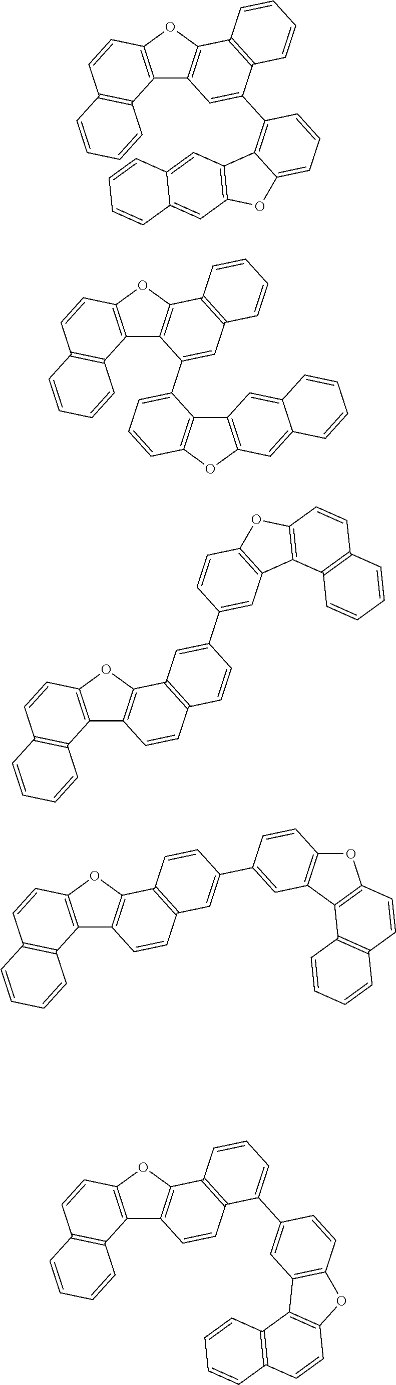 [SMILES: c1ccc2cc3c(cc2c1)oc1cccc(-c2cc4c(oc5ccc6ccccc6c54)c4ccccc24)c13 ; c1ccc2cc3c(cc2c1)oc1cccc(-c2cc4ccccc4c4oc5ccc6ccccc6c5c24)c13 ; c1ccc2c(c1)ccc1oc3ccc(-c4ccc5ccc6c(oc7ccc8ccccc8c76)c5c4)cc3c12 ; c1ccc2c(c1)ccc1oc3ccc(-c4ccc5c(ccc6c5oc5ccc7ccccc7c56)c4)cc3c12 ; c1ccc2c(c1)ccc1oc3ccc(-c4cccc5c4ccc4c5oc5ccc6ccccc6c54)cc3c12]

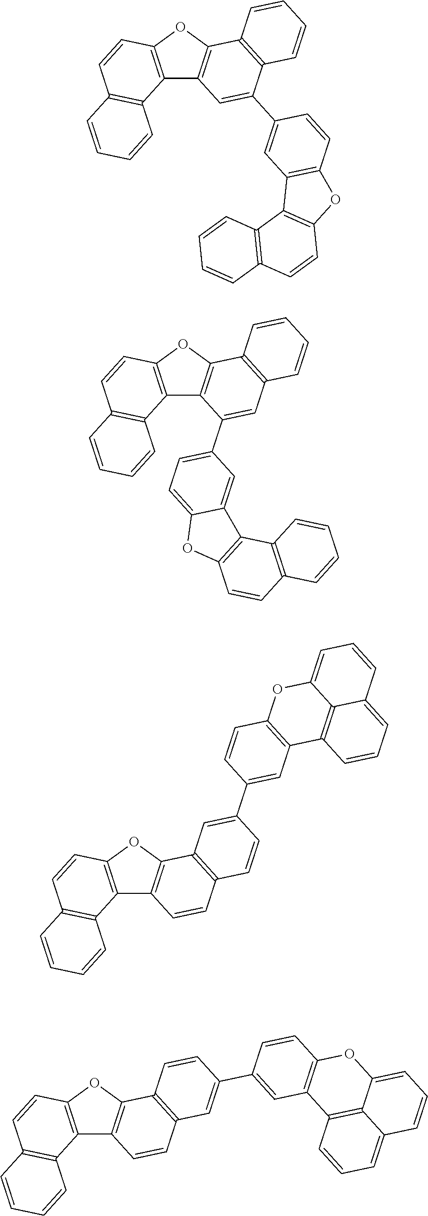

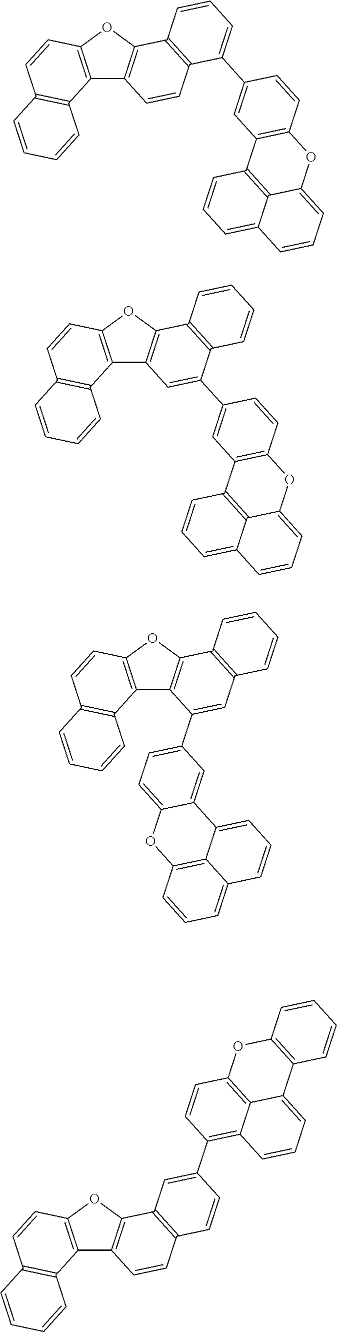

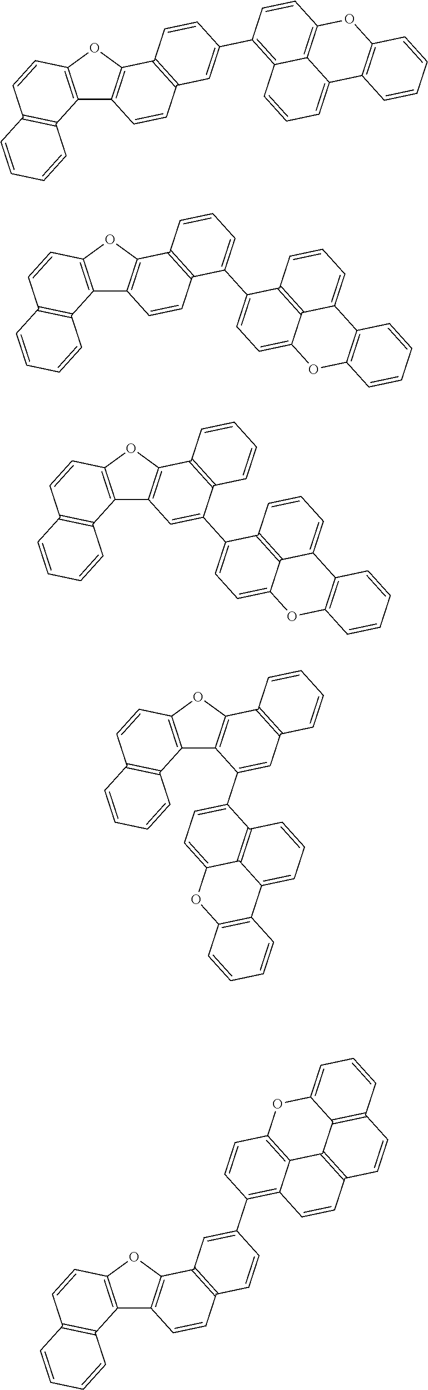 [SMILES: c1ccc2c(c1)Oc1ccc(-c3ccc4c(ccc5c4oc4ccc6ccccc6c45)c3)c3cccc-2c13 ; c1ccc2c(c1)Oc1ccc(-c3cccc4c3ccc3c4oc4ccc5ccccc5c43)c3cccc-2c13 ; c1ccc2c(c1)Oc1ccc(-c3cc4c(oc5ccc6ccccc6c54)c4ccccc34)c3cccc-2c13 ; c1ccc2c(c1)Oc1ccc(-c3cc4ccccc4c4oc5ccc6ccccc6c5c34)c3cccc-2c13 ; c1ccc2c(c1)ccc1oc3c4cc(-c5ccc6c7c5ccc5ccc8cccc(c8c57)O6)ccc4ccc3c12]

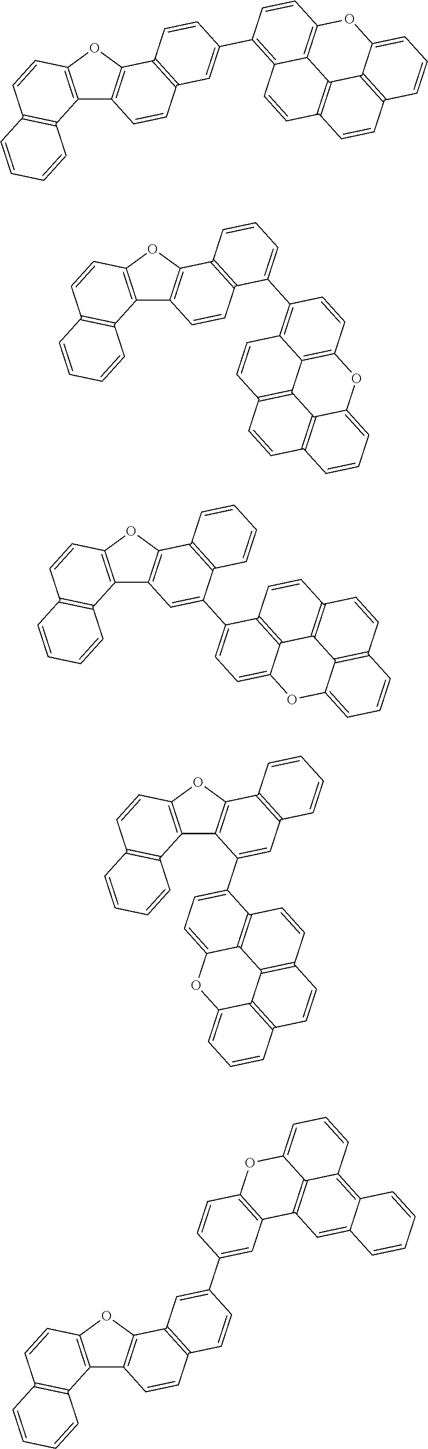 [SMILES: c1ccc2c(c1)ccc1oc3c4ccc(-c5ccc6c7c5ccc5ccc8cccc(c8c57)O6)cc4ccc3c12 ; c1ccc2c(c1)ccc1oc3c4cccc(-c5ccc6c7c5ccc5ccc8cccc(c8c57)O6)c4ccc3c12 ; c1ccc2c(c1)ccc1oc3c4ccccc4c(-c4ccc5c6c4ccc4ccc7cccc(c7c46)O5)cc3c12 ; c1ccc2c(c1)cc(-c1ccc3c4c1ccc1ccc5cccc(c5c14)O3)c1c2oc2ccc3ccccc3c21 ; c1ccc2c(c1)cc1c3c(cccc32)Oc2ccc(-c3ccc4ccc5c(oc6ccc7ccccc7c65)c4c3)cc2-1]

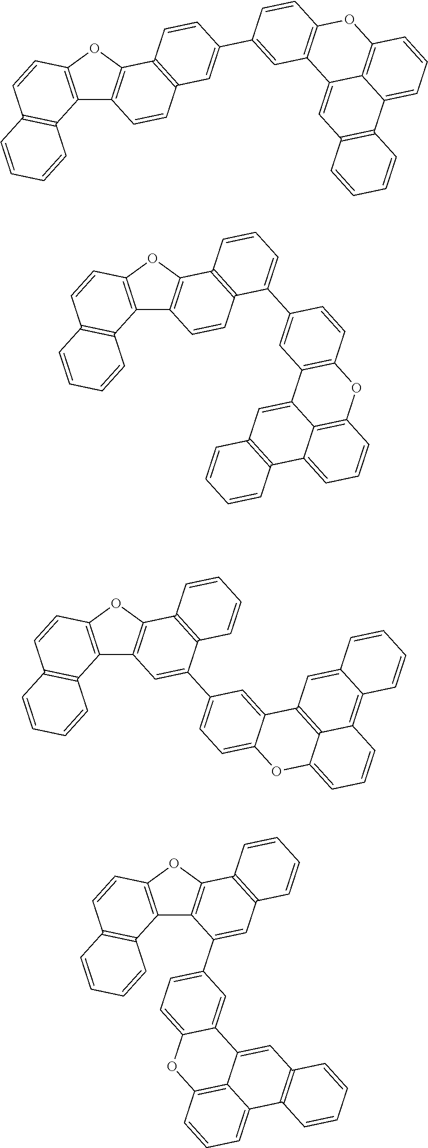 [SMILES: c1ccc2c(c1)cc1c3c(cccc32)Oc2ccc(-c3ccc4c(ccc5c4oc4ccc6ccccc6c45)c3)cc2-1 ; c1ccc2c(c1)cc1c3c(cccc32)Oc2ccc(-c3cccc4c3ccc3c4oc4ccc5ccccc5c43)cc2-1 ; c1ccc2c(c1)cc1c3c(cccc32)Oc2ccc(-c3cc4c(oc5ccc6ccccc6c54)c4ccccc34)cc2-1 ; c1ccc2c(c1)cc1c3c(cccc32)Oc2ccc(-c3cc4ccccc4c4oc5ccc6ccccc6c5c34)cc2-1]

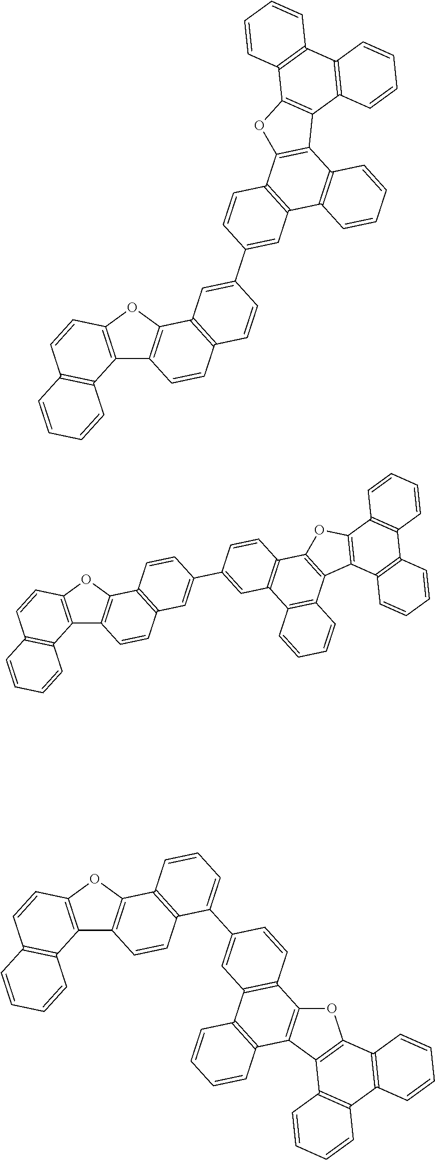 [SMILES: c1ccc2c(c1)ccc1oc3c4cc(-c5ccc6c(c5)c5ccccc5c5c6oc6c7ccccc7c7ccccc7c65)ccc4ccc3c12 ; c1ccc2c(c1)ccc1oc3c4ccc(-c5ccc6c(c5)c5ccccc5c5c6oc6c7ccccc7c7ccccc7c65)cc4ccc3c12 ; c1ccc2c(c1)ccc1oc3c4cccc(-c5ccc6c(c5)c5ccccc5c5c6oc6c7ccccc7c7ccccc7c65)c4ccc3c12]

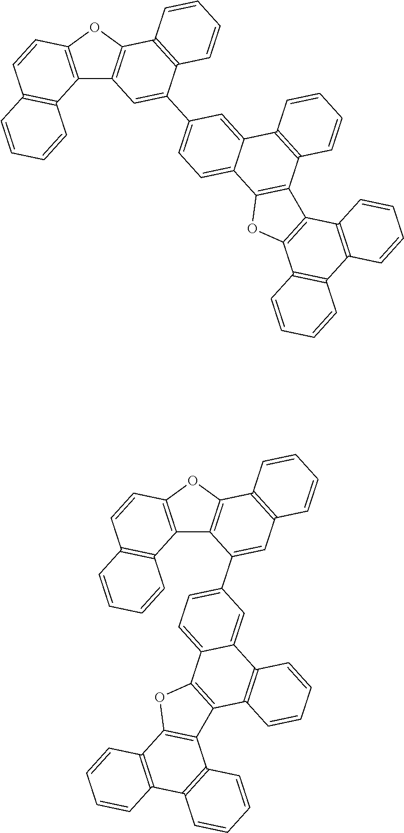 [SMILES: c1ccc2c(c1)ccc1oc3c4ccccc4c(-c4ccc5c(c4)c4ccccc4c4c5oc5c6ccccc6c6ccccc6c54)cc3c12 ; c1ccc2c(c1)cc(-c1ccc3c(c1)c1ccccc1c1c3oc3c4ccccc4c4ccccc4c31)c1c2oc2ccc3ccccc3c21]

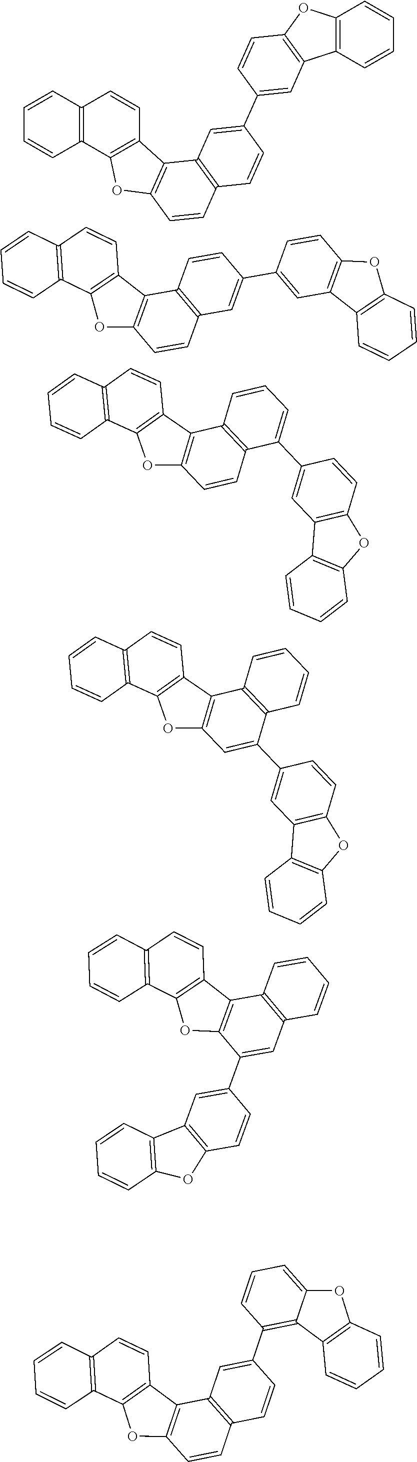

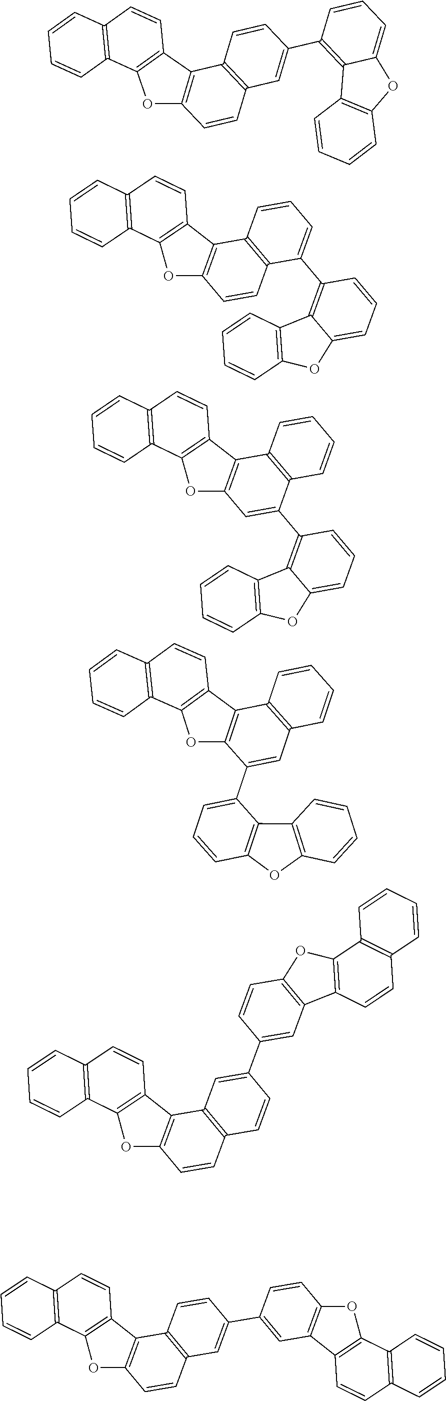

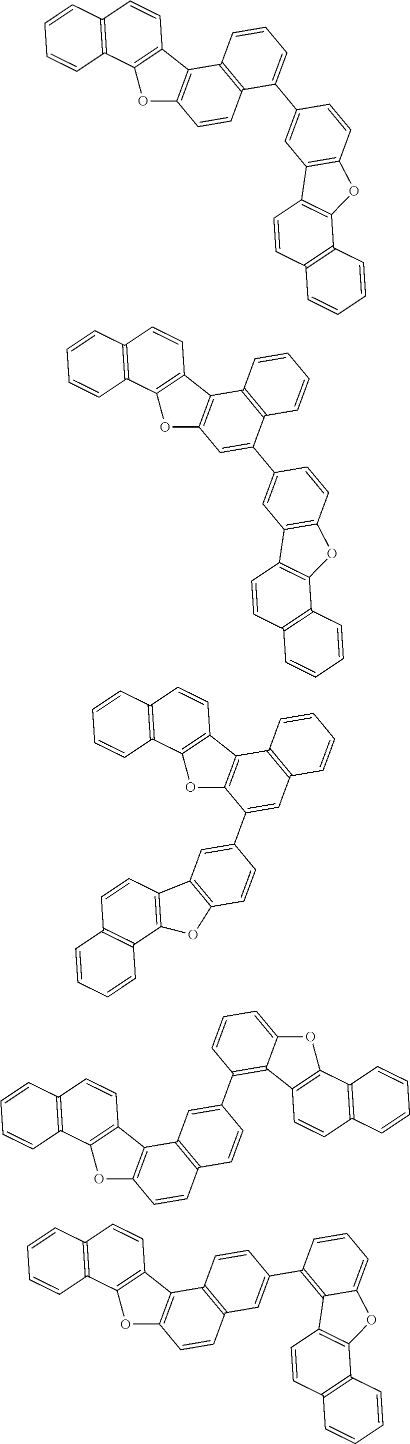

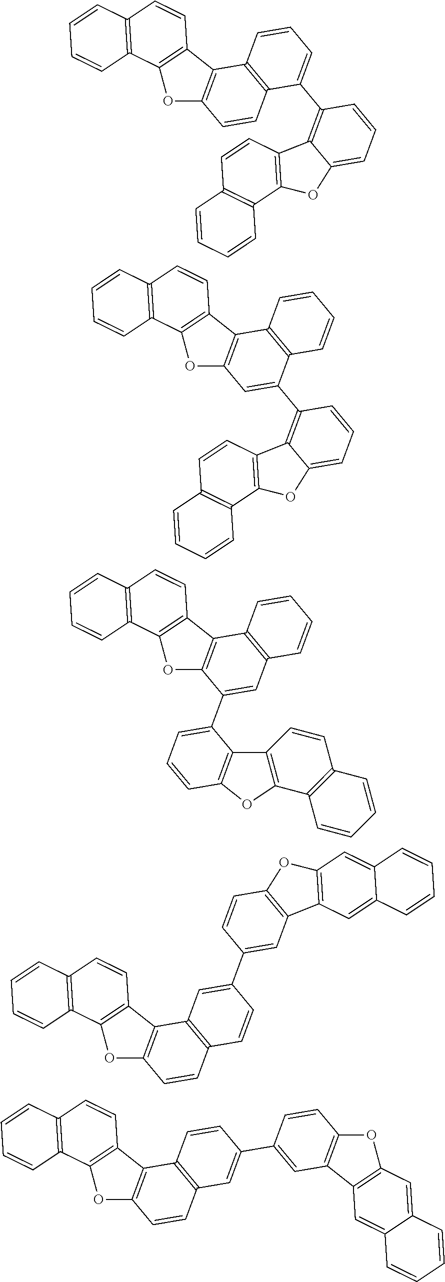

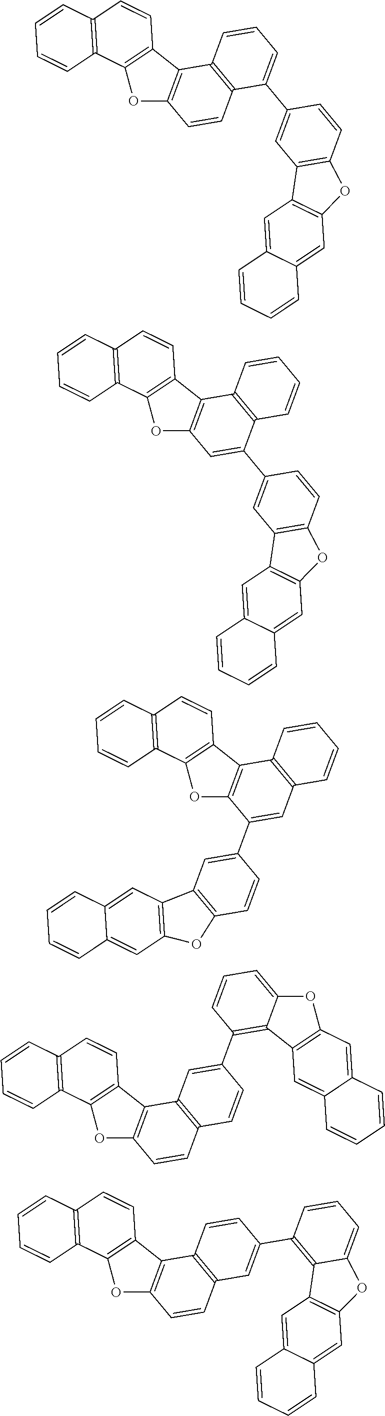

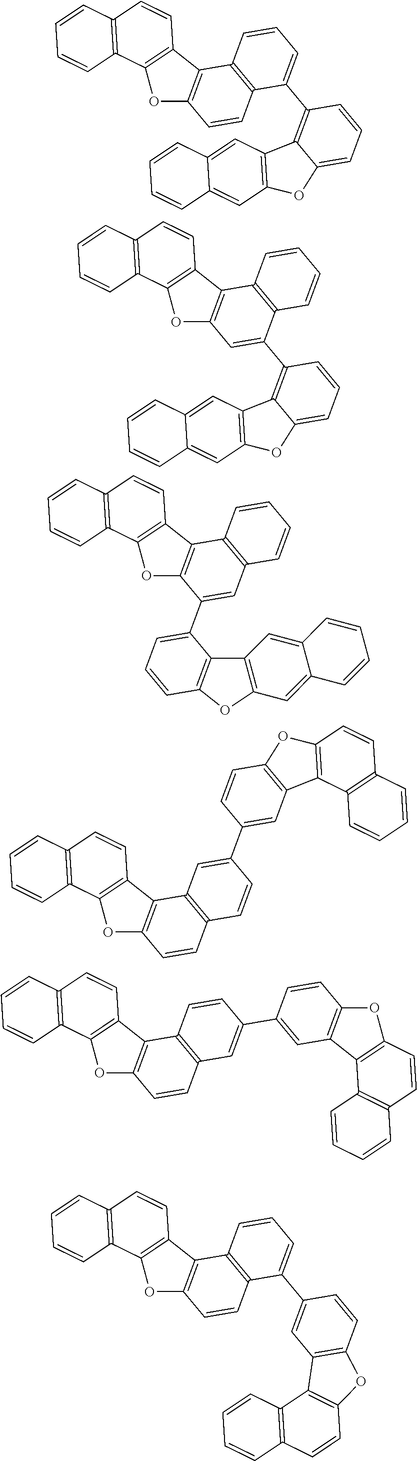

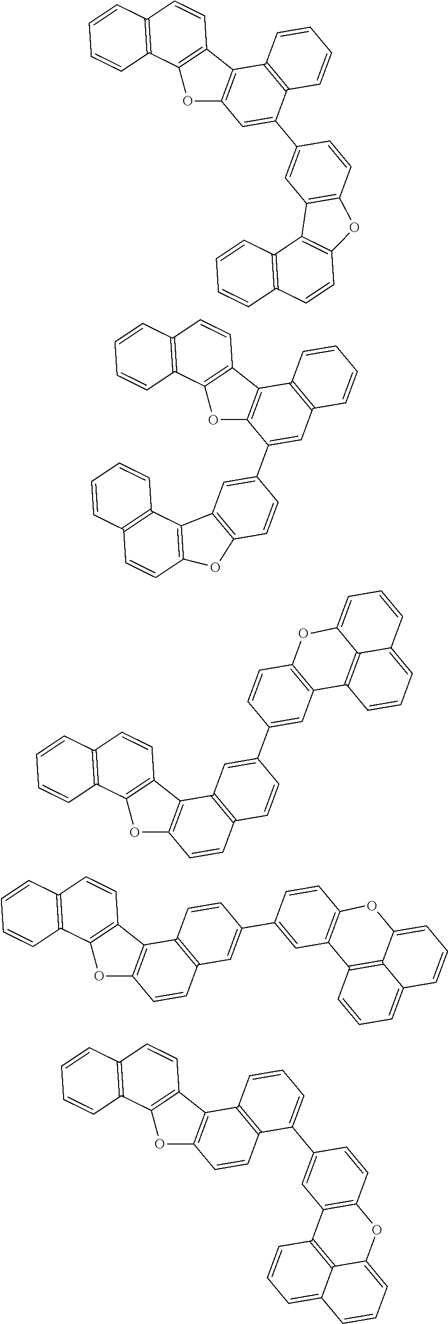

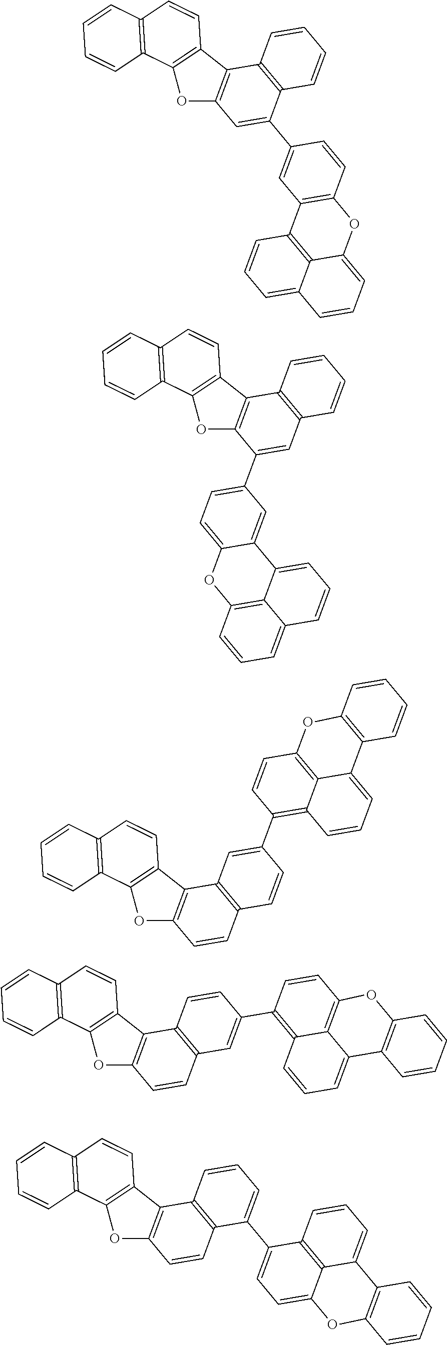

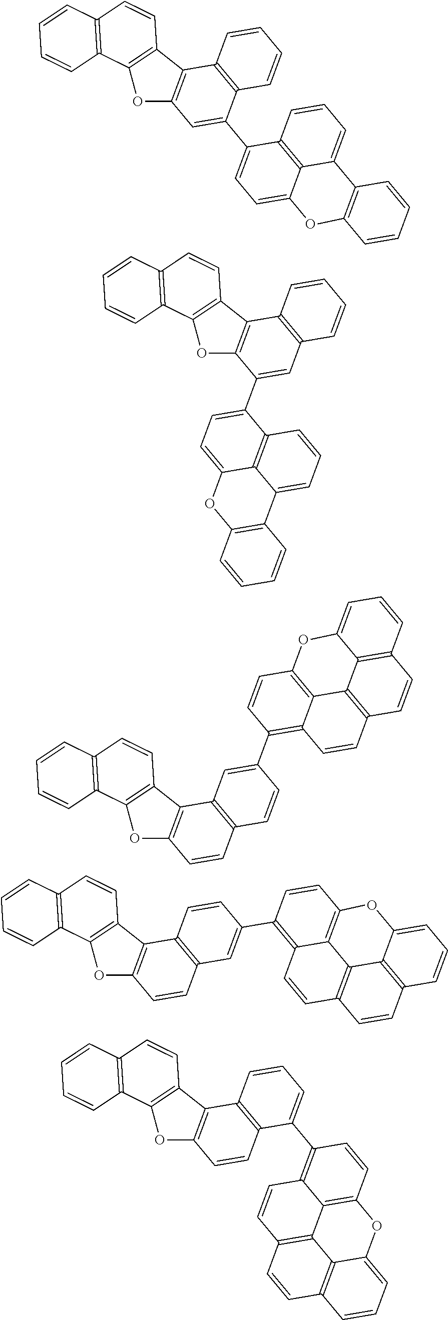

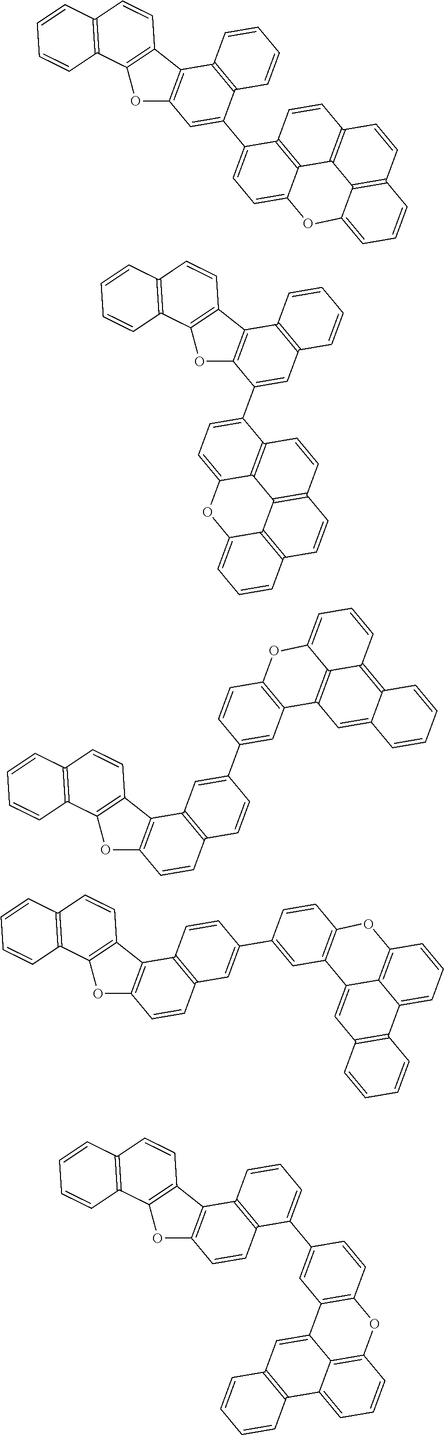 [SMILES: c1ccc2c(c1)ccc1c2oc2cc(-c3ccc4c5c3ccc3ccc6cccc(c6c35)O4)c3ccccc3c21 ; c1ccc2c(c1)ccc1c2oc2c(-c3ccc4c5c3ccc3ccc6cccc(c6c35)O4)cc3ccccc3c21 ; c1ccc2c(c1)cc1c3c(cccc32)Oc2ccc(-c3ccc4ccc5oc6c7ccccc7ccc6c5c4c3)cc2-1 ; c1ccc2c(c1)cc1c3c(cccc32)Oc2ccc(-c3ccc4c(ccc5oc6c7ccccc7ccc6c54)c3)cc2-1 ; c1ccc2c(c1)cc1c3c(cccc32)Oc2ccc(-c3cccc4c3ccc3oc5c6ccccc6ccc5c34)cc2-1]

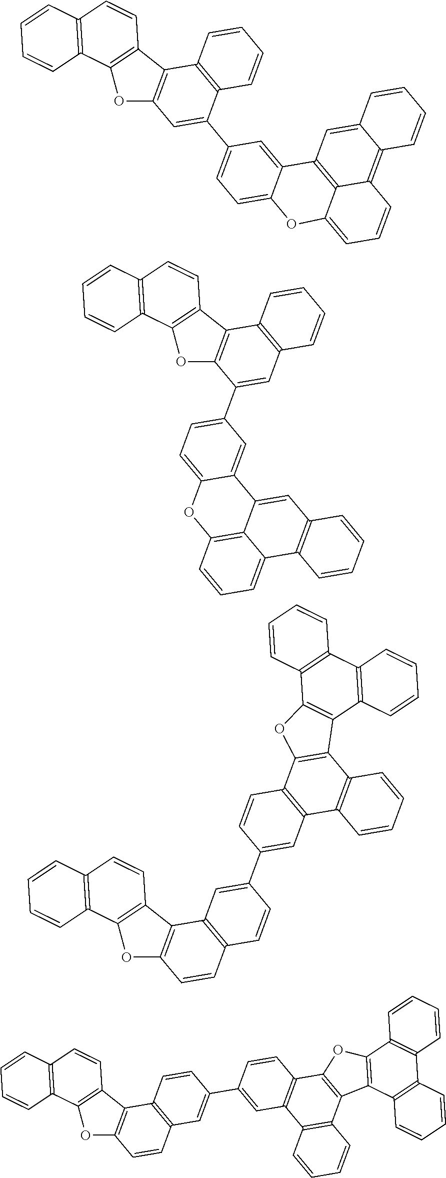

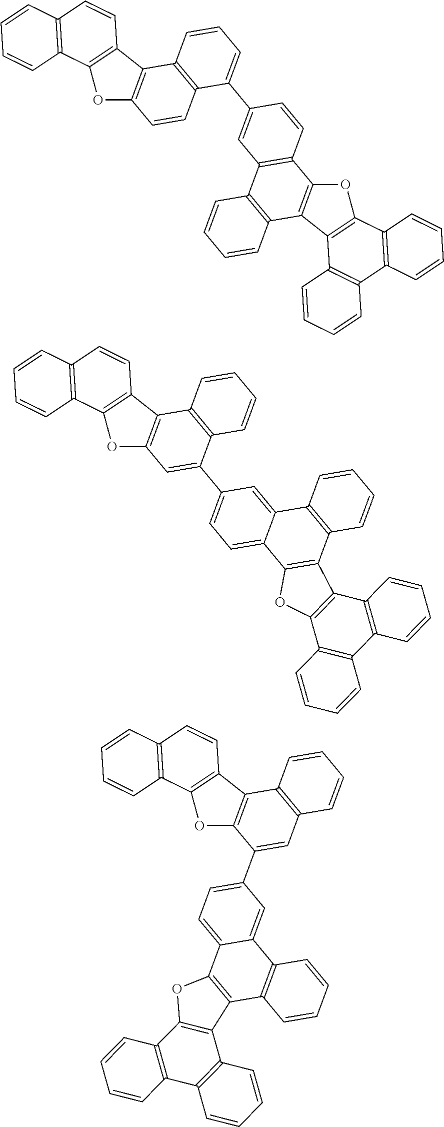

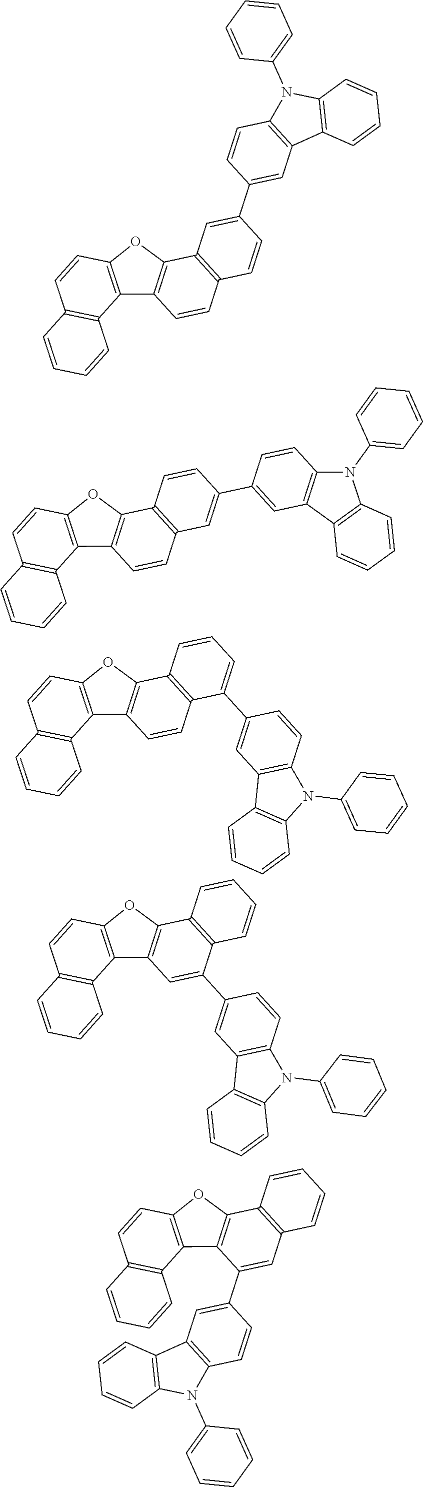

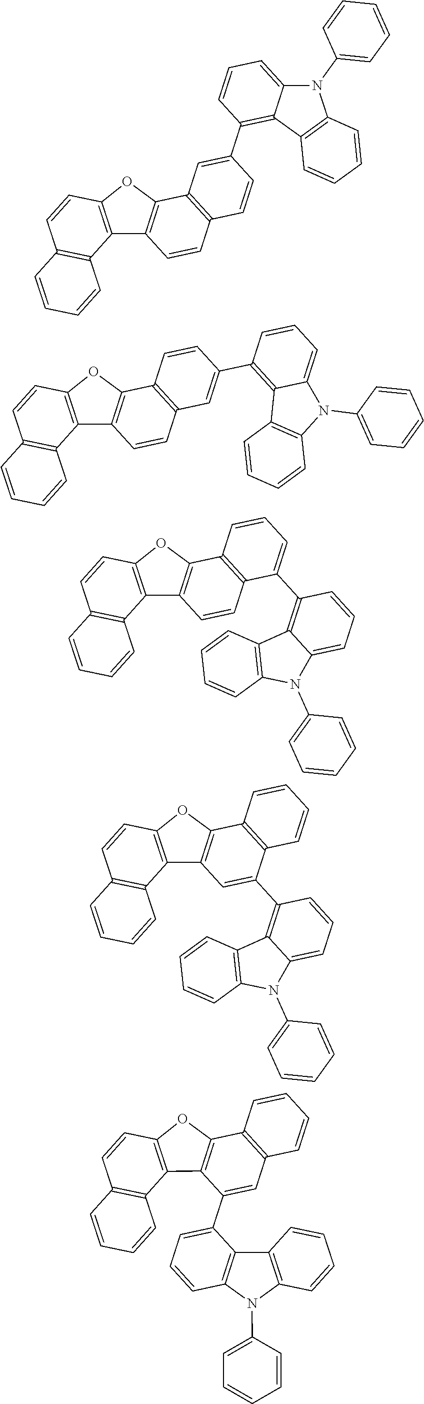

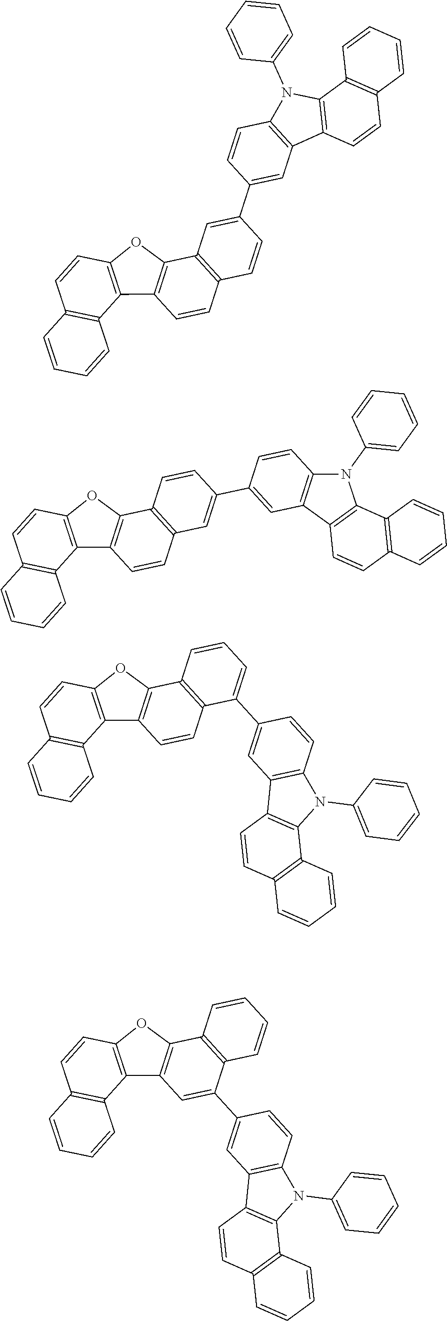 [SMILES: c1ccc(-n2c3ccc(-c4ccc5ccc6c(oc7ccc8ccccc8c76)c5c4)cc3c3ccc4ccccc4c32)cc1 ; c1ccc(-n2c3ccc(-c4ccc5c(ccc6c5oc5ccc7ccccc7c56)c4)cc3c3ccc4ccccc4c32)cc1 ; c1ccc(-n2c3ccc(-c4cccc5c4ccc4c5oc5ccc6ccccc6c54)cc3c3ccc4ccccc4c32)cc1 ; c1ccc(-n2c3ccc(-c4cc5c(oc6ccc7ccccc7c65)c5ccccc45)cc3c3ccc4ccccc4c32)cc1]

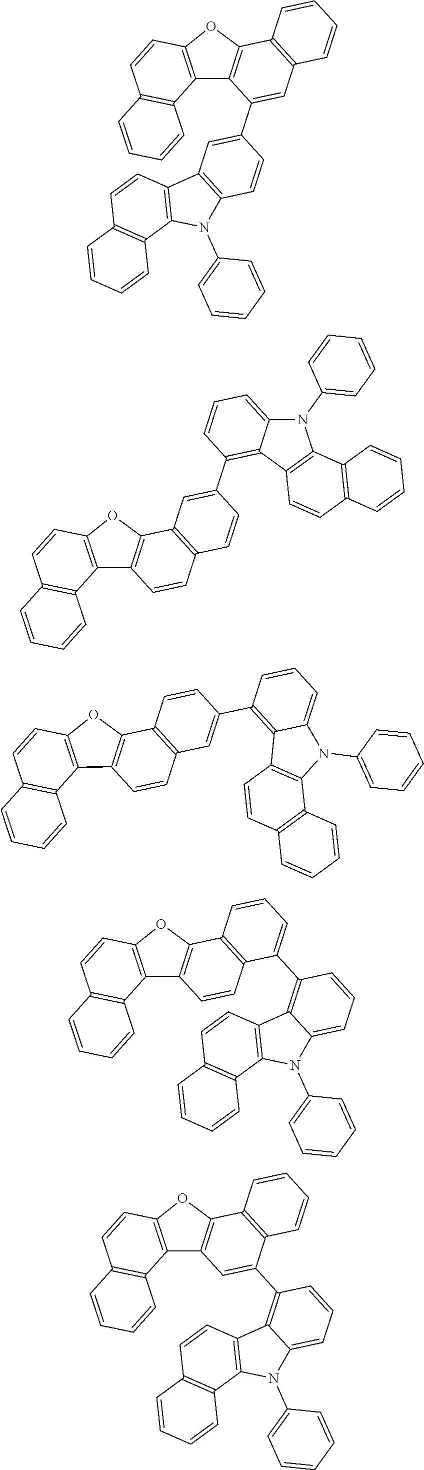

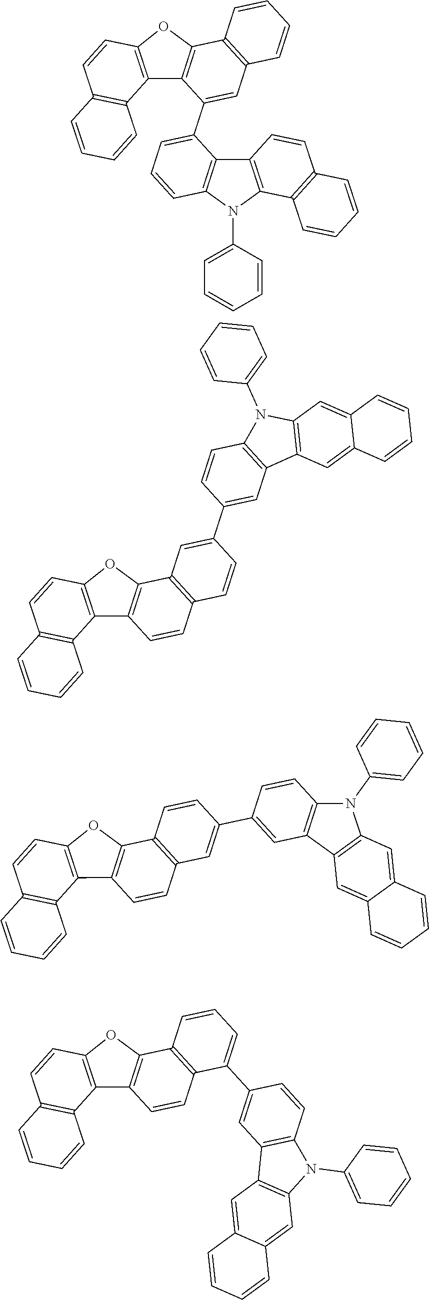

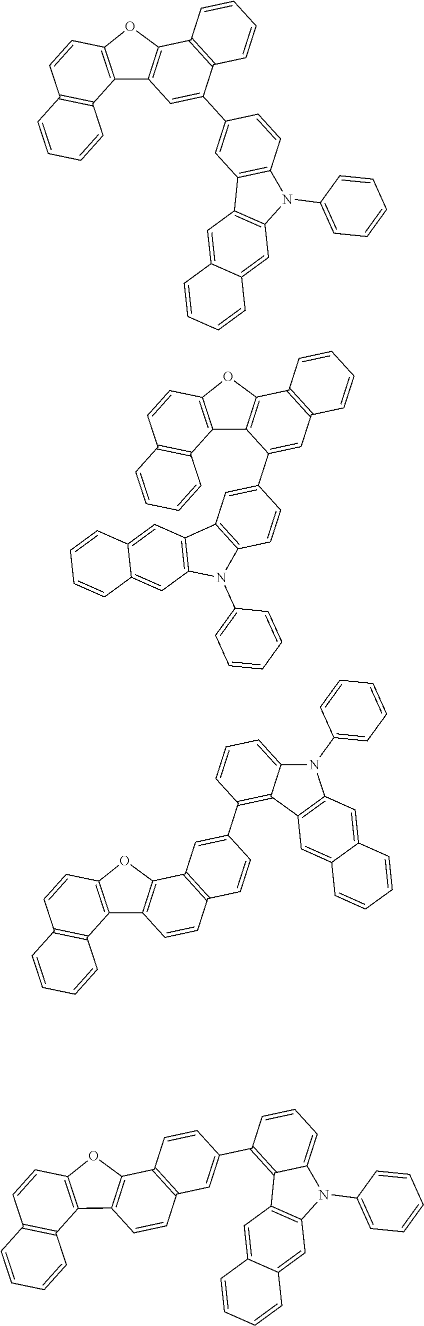 [SMILES: c1ccc(-n2c3ccc(-c4cc5c(oc6ccc7ccccc7c65)c5ccccc45)cc3c3cc4ccccc4cc32)cc1 ; c1ccc(-n2c3ccc(-c4cc5ccccc5c5oc6ccc7ccccc7c6c45)cc3c3cc4ccccc4cc32)cc1 ; c1ccc(-n2c3cc4ccccc4cc3c3c(-c4ccc5ccc6c(oc7ccc8ccccc8c76)c5c4)cccc32)cc1 ; c1ccc(-n2c3cc4ccccc4cc3c3c(-c4ccc5c(ccc6c5oc5ccc7ccccc7c56)c4)cccc32)cc1]

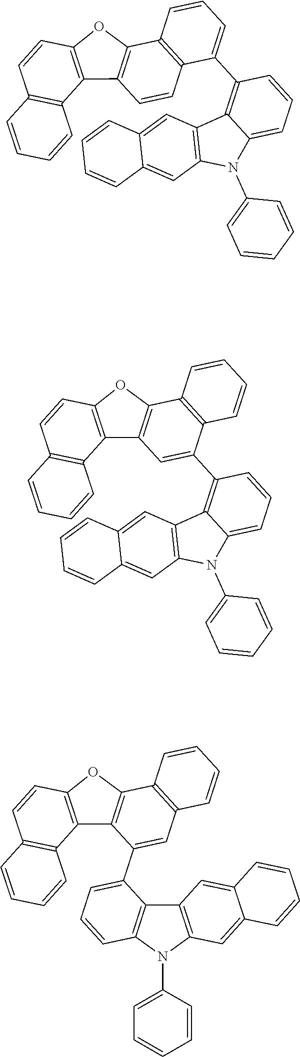 [SMILES: c1ccc(-n2c3cc4ccccc4cc3c3c(-c4cccc5c4ccc4c5oc5ccc6ccccc6c54)cccc32)cc1 ; c1ccc(-n2c3cc4ccccc4cc3c3c(-c4cc5c(oc6ccc7ccccc7c65)c5ccccc45)cccc32)cc1 ; c1ccc(-n2c3cc4ccccc4cc3c3c(-c4cc5ccccc5c5oc6ccc7ccccc7c6c45)cccc32)cc1]

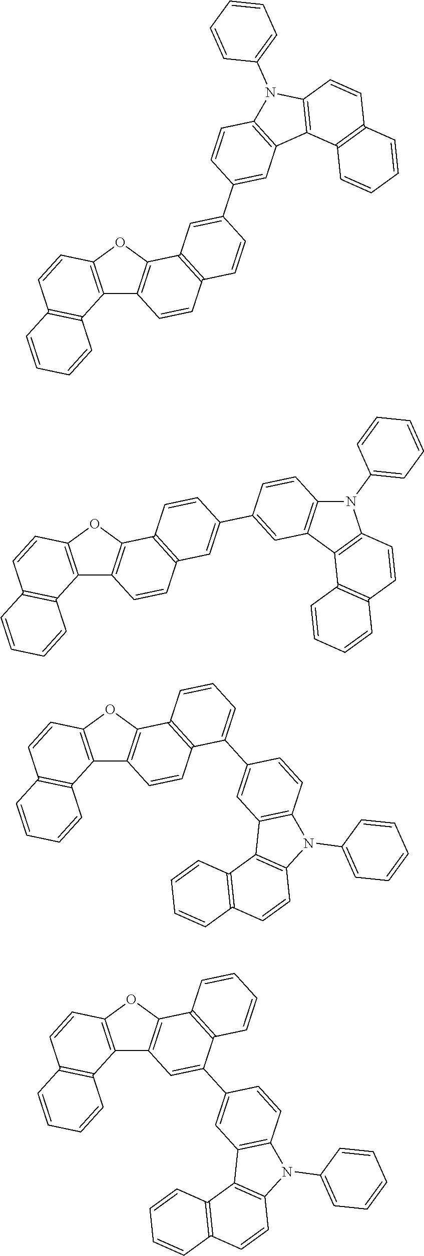 [SMILES: c1ccc(-n2c3ccc(-c4ccc5ccc6c(oc7ccc8ccccc8c76)c5c4)cc3c3c4ccccc4ccc32)cc1 ; c1ccc(-n2c3ccc(-c4ccc5c(ccc6c5oc5ccc7ccccc7c56)c4)cc3c3c4ccccc4ccc32)cc1 ; c1ccc(-n2c3ccc(-c4cccc5c4ccc4c5oc5ccc6ccccc6c54)cc3c3c4ccccc4ccc32)cc1 ; c1ccc(-n2c3ccc(-c4cc5c(oc6ccc7ccccc7c65)c5ccccc45)cc3c3c4ccccc4ccc32)cc1]

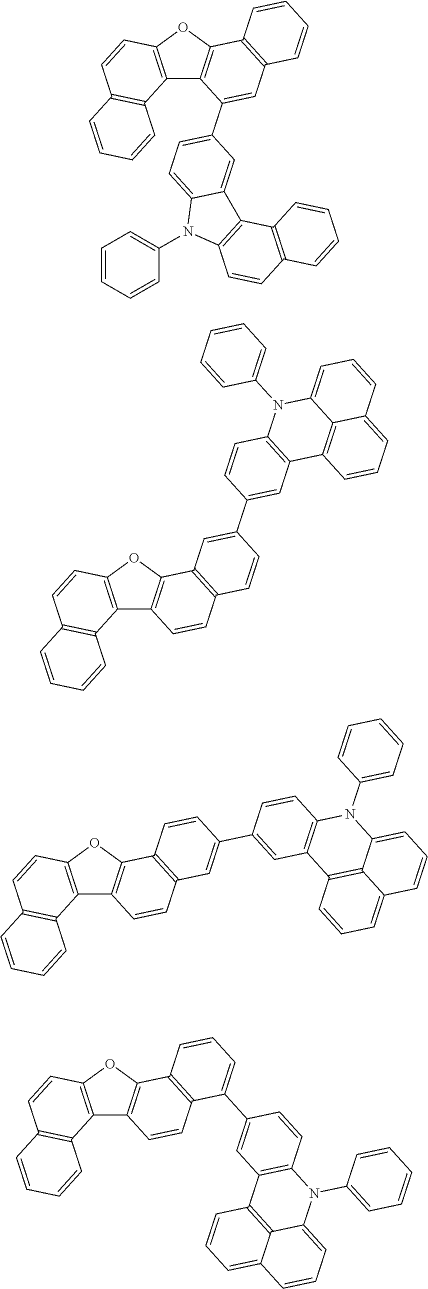

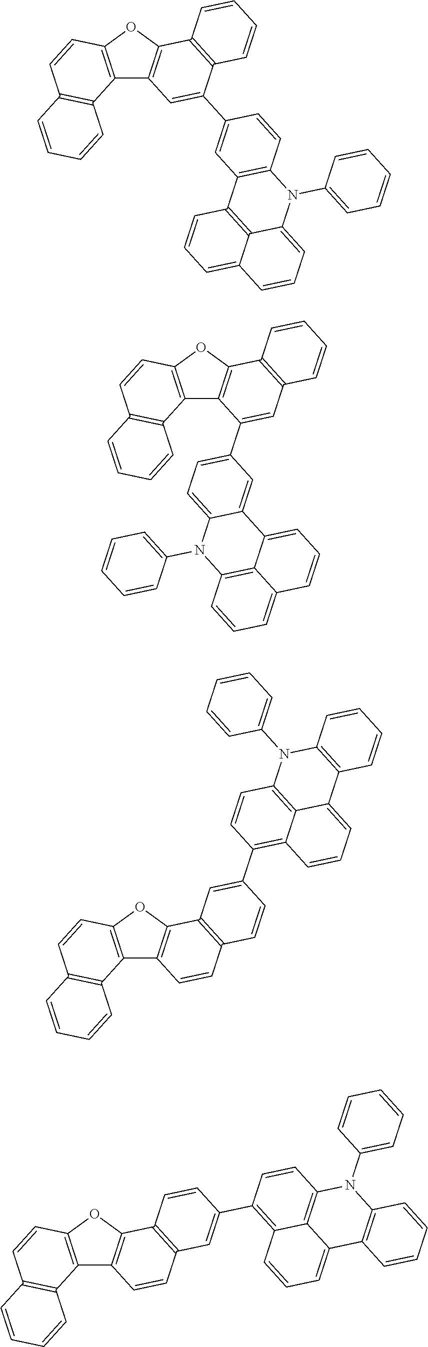

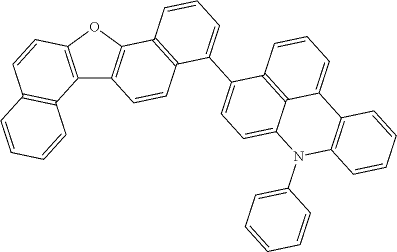 [SMILES: c1ccc(N2c3ccccc3-c3cccc4c(-c5cccc6c5ccc5c6oc6ccc7ccccc7c65)ccc2c34)cc1]

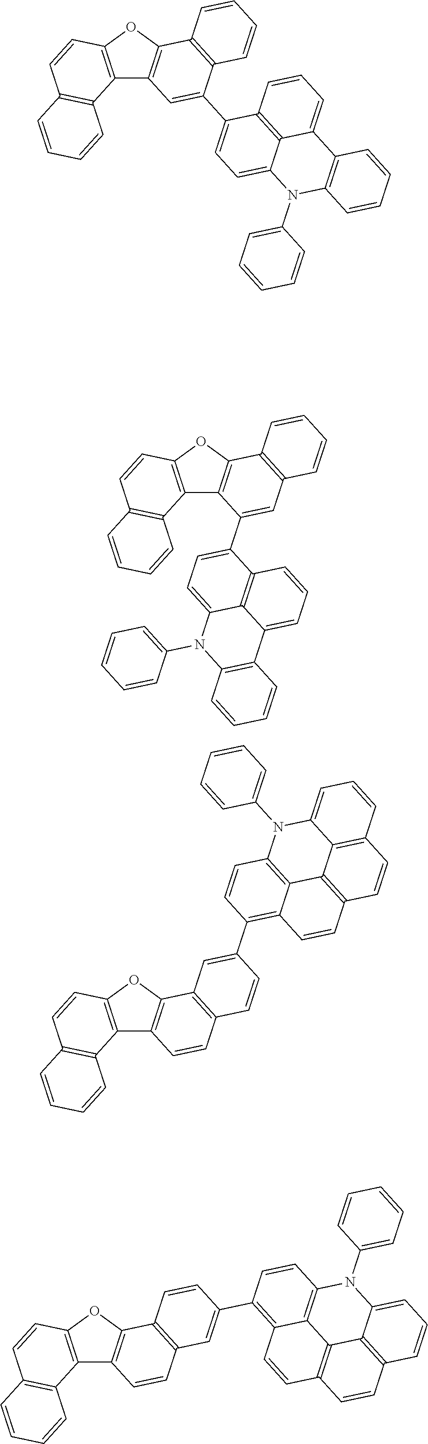

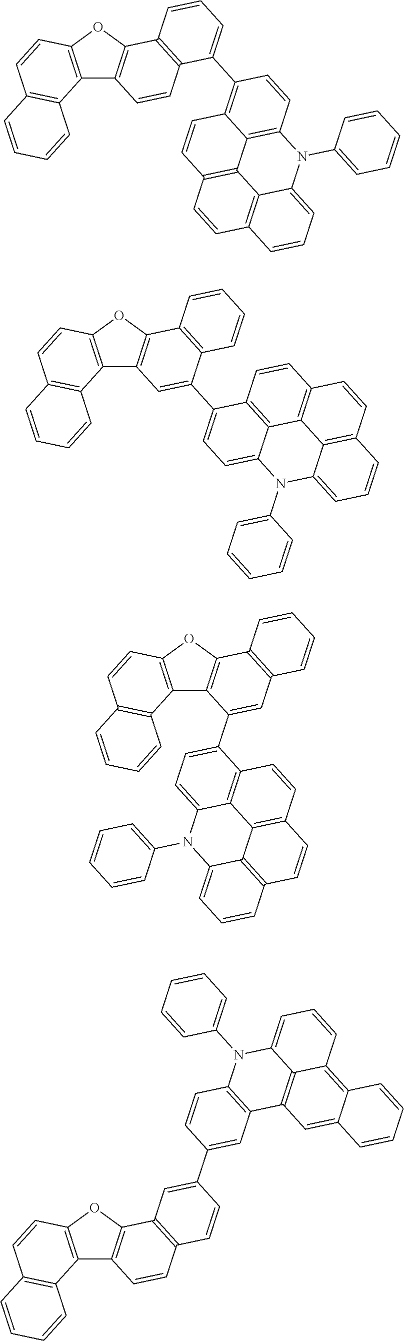

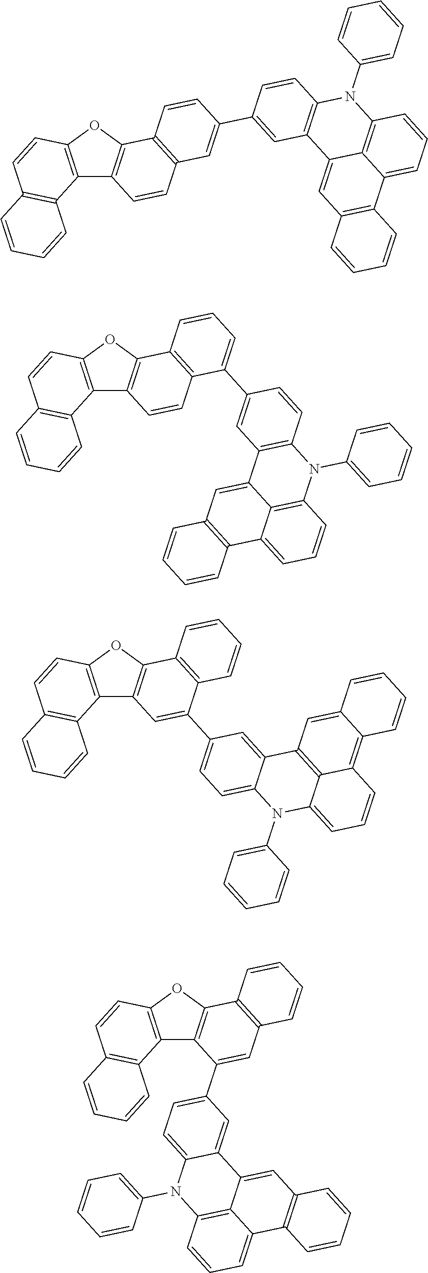

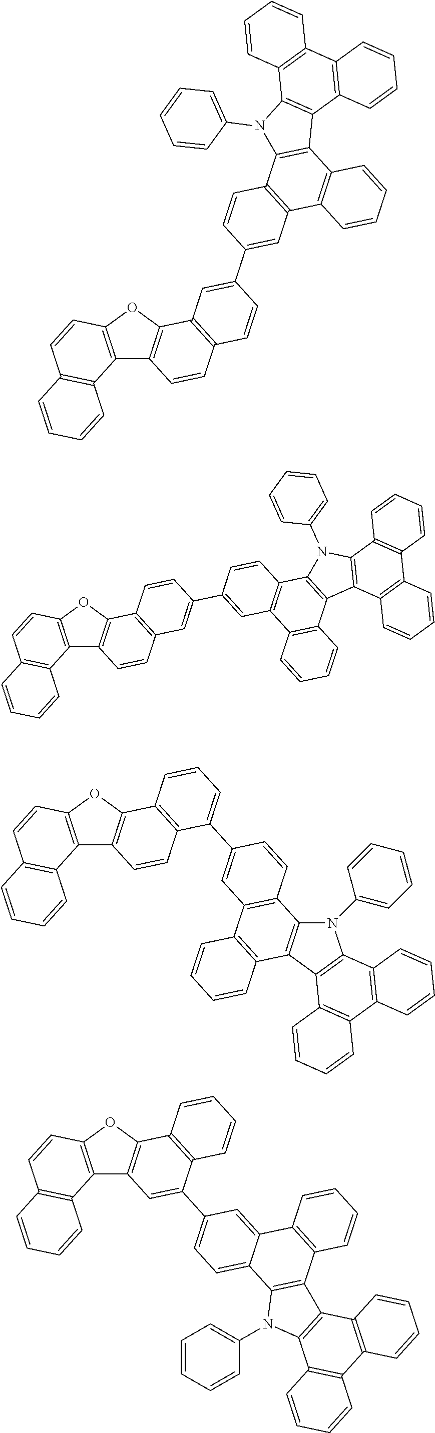 [SMILES: c1ccc(-n2c3c4ccccc4c4ccccc4c3c3c4ccccc4c4cc(-c5ccc6ccc7c(oc8ccc9ccccc9c87)c6c5)ccc4c32)cc1 ; c1ccc(-n2c3c4ccccc4c4ccccc4c3c3c4ccccc4c4cc(-c5ccc6c(ccc7c6oc6ccc8ccccc8c67)c5)ccc4c32)cc1 ; c1ccc(-n2c3c4ccccc4c4ccccc4c3c3c4ccccc4c4cc(-c5cccc6c5ccc5c6oc6ccc7ccccc7c65)ccc4c32)cc1 ; c1ccc(-n2c3c4ccccc4c4ccccc4c3c3c4ccccc4c4cc(-c5cc6c(oc7ccc8ccccc8c76)c6ccccc56)ccc4c32)cc1]

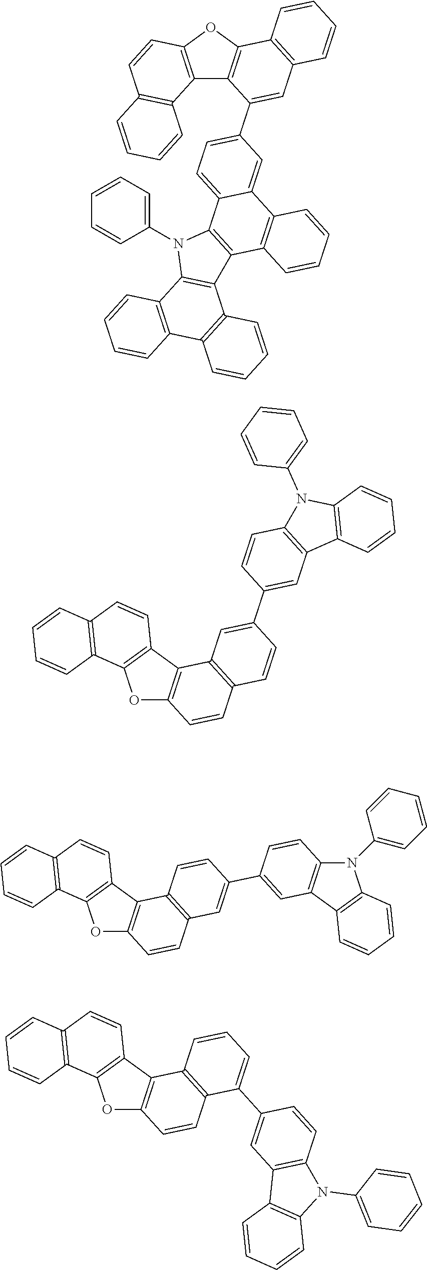

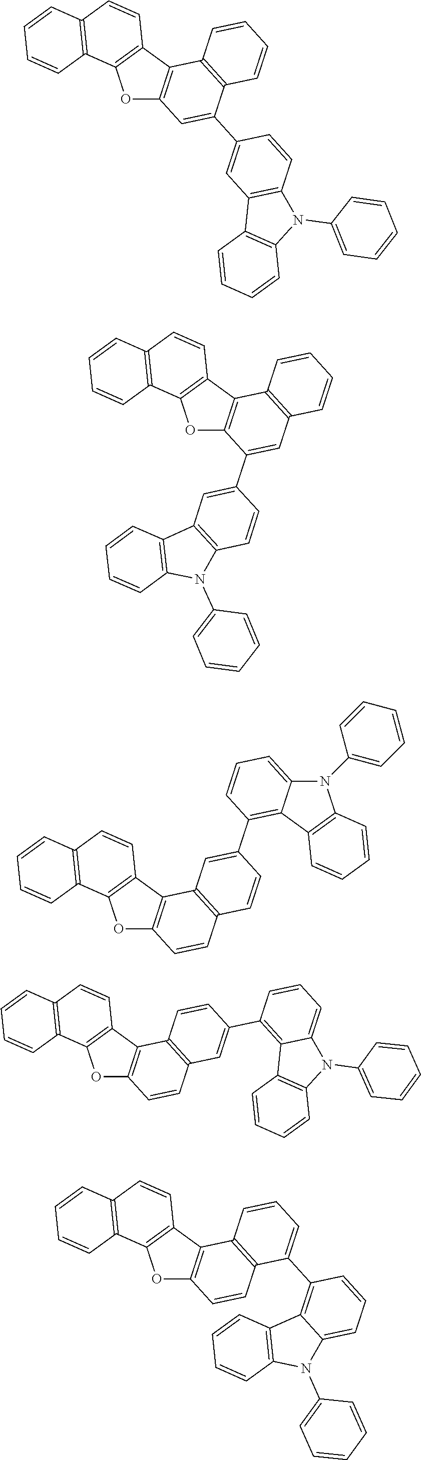 [SMILES: c1ccc(-n2c3ccccc3c3cc(-c4cc5oc6c7ccccc7ccc6c5c5ccccc45)ccc32)cc1 ; c1ccc(-n2c3ccccc3c3cc(-c4cc5ccccc5c5c4oc4c6ccccc6ccc45)ccc32)cc1 ; c1ccc(-n2c3ccccc3c3c(-c4ccc5ccc6oc7c8ccccc8ccc7c6c5c4)cccc32)cc1 ; c1ccc(-n2c3ccccc3c3c(-c4ccc5c(ccc6oc7c8ccccc8ccc7c65)c4)cccc32)cc1 ; c1ccc(-n2c3ccccc3c3c(-c4cccc5c4ccc4oc6c7ccccc7ccc6c45)cccc32)cc1]

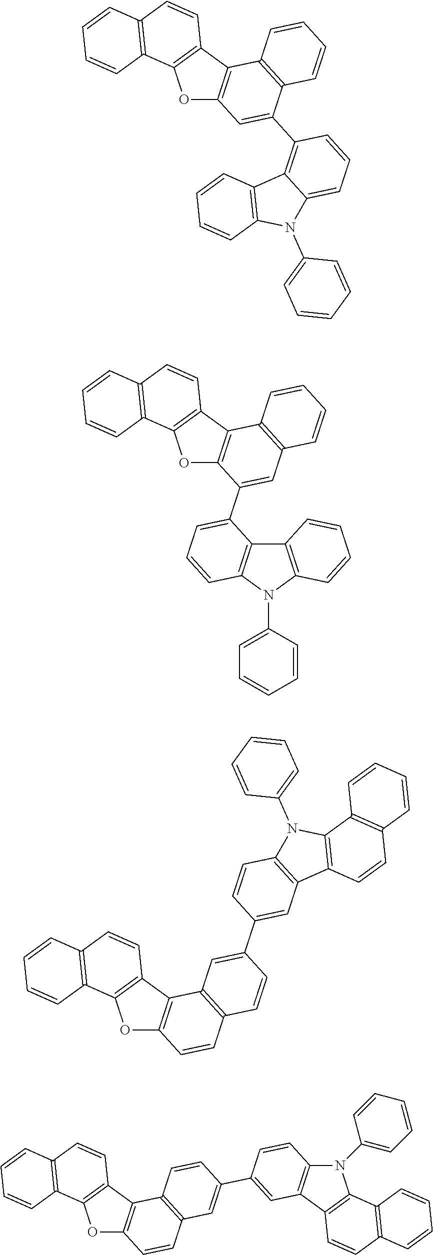

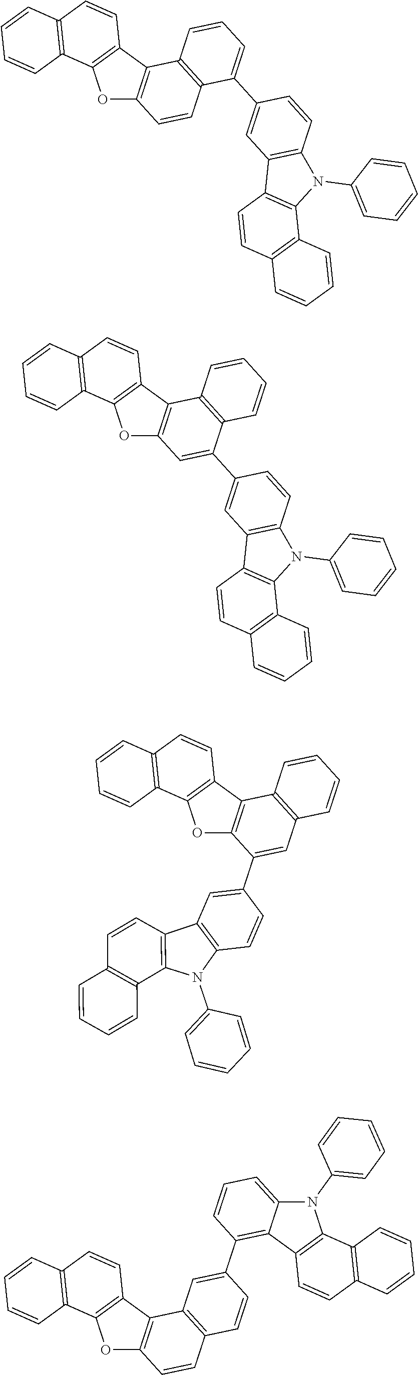 [SMILES: c1ccc(-n2c3ccc(-c4cccc5c4ccc4oc6c7ccccc7ccc6c45)cc3c3ccc4ccccc4c32)cc1 ; c1ccc(-n2c3ccc(-c4cc5oc6c7ccccc7ccc6c5c5ccccc45)cc3c3ccc4ccccc4c32)cc1 ; c1ccc(-n2c3ccc(-c4cc5ccccc5c5c4oc4c6ccccc6ccc45)cc3c3ccc4ccccc4c32)cc1 ; c1ccc(-n2c3cccc(-c4ccc5ccc6oc7c8ccccc8ccc7c6c5c4)c3c3ccc4ccccc4c32)cc1]

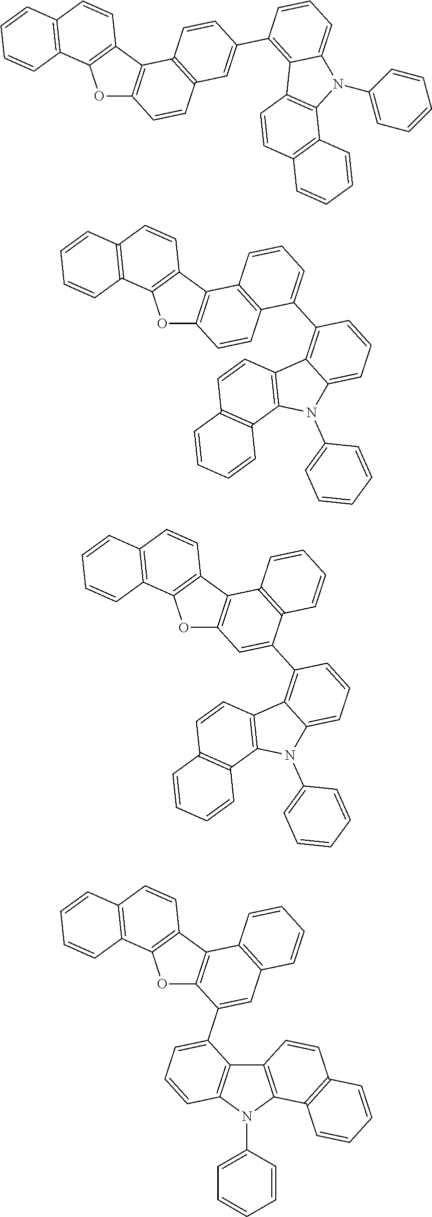 [SMILES: c1ccc(-n2c3cccc(-c4ccc5c(ccc6oc7c8ccccc8ccc7c65)c4)c3c3ccc4ccccc4c32)cc1 ; c1ccc(-n2c3cccc(-c4cccc5c4ccc4oc6c7ccccc7ccc6c45)c3c3ccc4ccccc4c32)cc1 ; c1ccc(-n2c3cccc(-c4cc5oc6c7ccccc7ccc6c5c5ccccc45)c3c3ccc4ccccc4c32)cc1 ; c1ccc(-n2c3cccc(-c4cc5ccccc5c5c4oc4c6ccccc6ccc45)c3c3ccc4ccccc4c32)cc1]

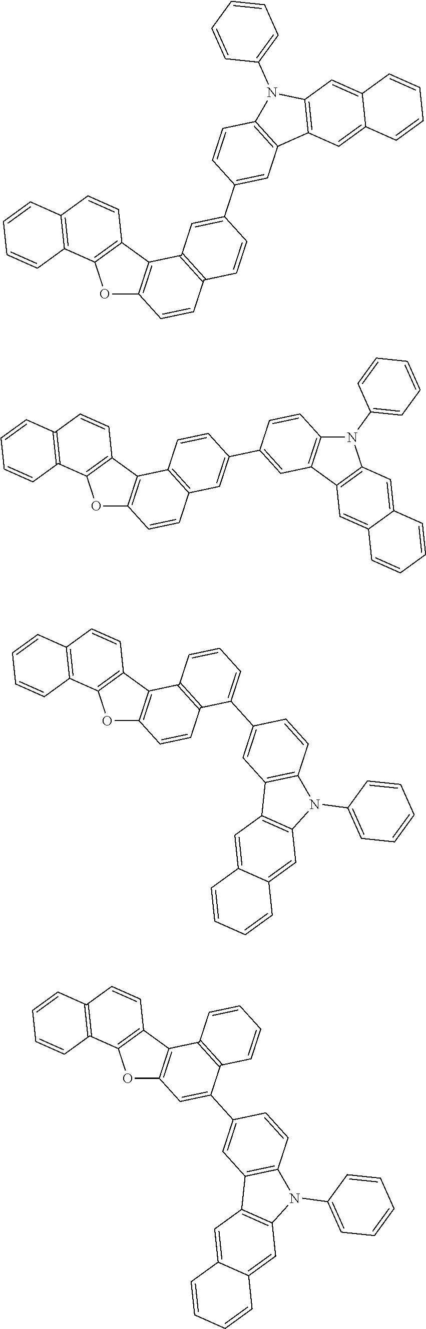 [SMILES: c1ccc(-n2c3ccc(-c4ccc5ccc6oc7c8ccccc8ccc7c6c5c4)cc3c3cc4ccccc4cc32)cc1 ; c1ccc(-n2c3ccc(-c4ccc5c(ccc6oc7c8ccccc8ccc7c65)c4)cc3c3cc4ccccc4cc32)cc1 ; c1ccc(-n2c3ccc(-c4cccc5c4ccc4oc6c7ccccc7ccc6c45)cc3c3cc4ccccc4cc32)cc1 ; c1ccc(-n2c3ccc(-c4cc5oc6c7ccccc7ccc6c5c5ccccc45)cc3c3cc4ccccc4cc32)cc1]

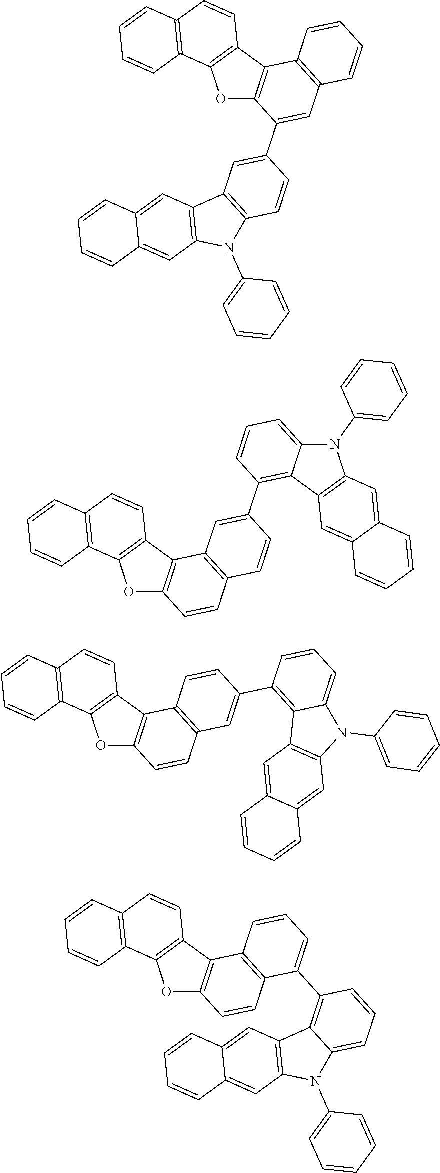 [SMILES: c1ccc(-n2c3ccc(-c4cc5ccccc5c5c4oc4c6ccccc6ccc45)cc3c3cc4ccccc4cc32)cc1 ; c1ccc(-n2c3cc4ccccc4cc3c3c(-c4ccc5ccc6oc7c8ccccc8ccc7c6c5c4)cccc32)cc1 ; c1ccc(-n2c3cc4ccccc4cc3c3c(-c4ccc5c(ccc6oc7c8ccccc8ccc7c65)c4)cccc32)cc1 ; c1ccc(-n2c3cc4ccccc4cc3c3c(-c4cccc5c4ccc4oc6c7ccccc7ccc6c45)cccc32)cc1]

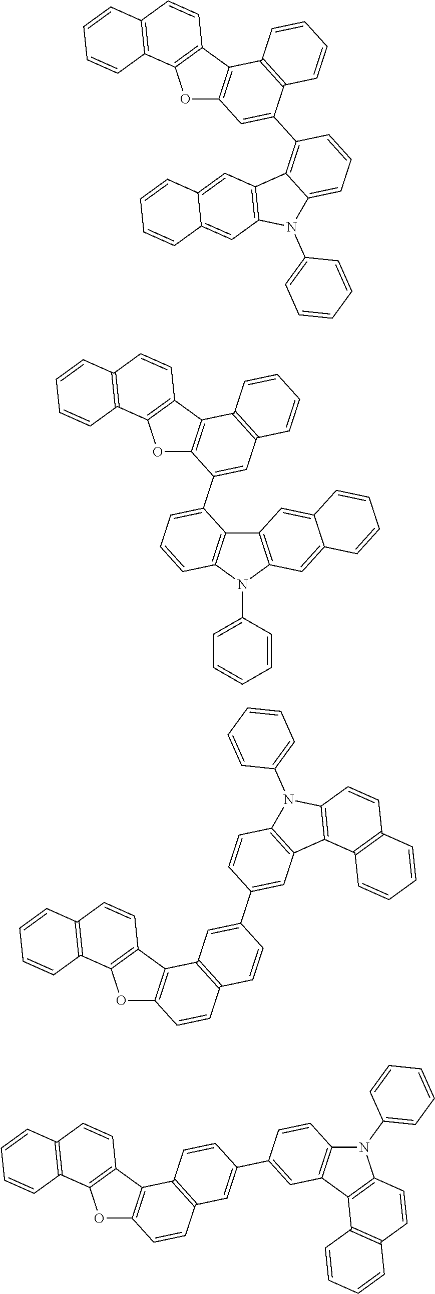

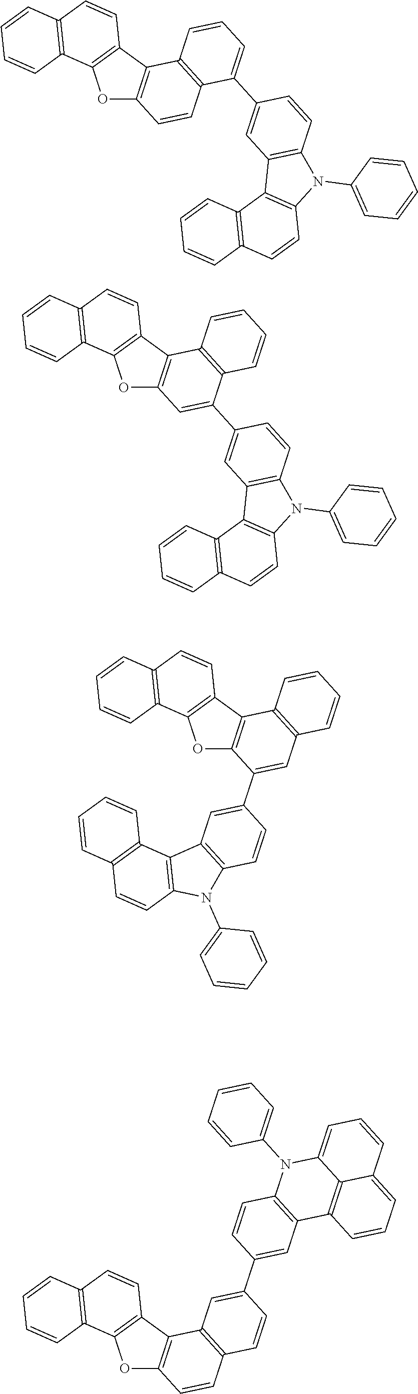 [SMILES: c1ccc(-n2c3ccc(-c4cccc5c4ccc4oc6c7ccccc7ccc6c45)cc3c3c4ccccc4ccc32)cc1 ; c1ccc(-n2c3ccc(-c4cc5oc6c7ccccc7ccc6c5c5ccccc45)cc3c3c4ccccc4ccc32)cc1 ; c1ccc(-n2c3ccc(-c4cc5ccccc5c5c4oc4c6ccccc6ccc45)cc3c3c4ccccc4ccc32)cc1 ; c1ccc(N2c3ccc(-c4ccc5ccc6oc7c8ccccc8ccc7c6c5c4)cc3-c3cccc4cccc2c34)cc1]

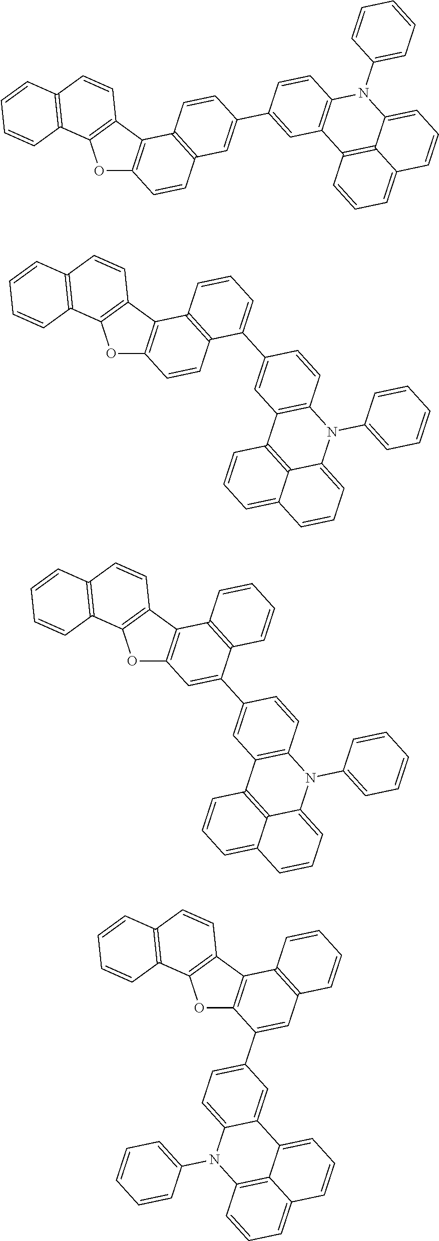 [SMILES: c1ccc(N2c3ccc(-c4ccc5c(ccc6oc7c8ccccc8ccc7c65)c4)cc3-c3cccc4cccc2c34)cc1 ; c1ccc(N2c3ccc(-c4cccc5c4ccc4oc6c7ccccc7ccc6c45)cc3-c3cccc4cccc2c34)cc1 ; c1ccc(N2c3ccc(-c4cc5oc6c7ccccc7ccc6c5c5ccccc45)cc3-c3cccc4cccc2c34)cc1 ; c1ccc(N2c3ccc(-c4cc5ccccc5c5c4oc4c6ccccc6ccc45)cc3-c3cccc4cccc2c34)cc1]

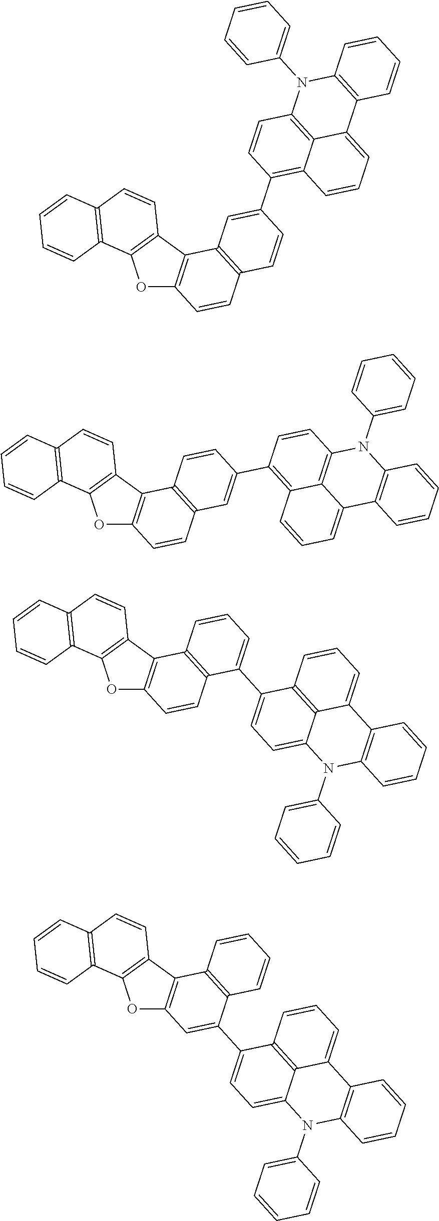 [SMILES: c1ccc(N2c3ccccc3-c3cccc4c(-c5ccc6ccc7oc8c9ccccc9ccc8c7c6c5)ccc2c34)cc1 ; c1ccc(N2c3ccccc3-c3cccc4c(-c5ccc6c(ccc7oc8c9ccccc9ccc8c76)c5)ccc2c34)cc1 ; c1ccc(N2c3ccccc3-c3cccc4c(-c5cccc6c5ccc5oc7c8ccccc8ccc7c56)ccc2c34)cc1 ; c1ccc(N2c3ccccc3-c3cccc4c(-c5cc6oc7c8ccccc8ccc7c6c6ccccc56)ccc2c34)cc1]

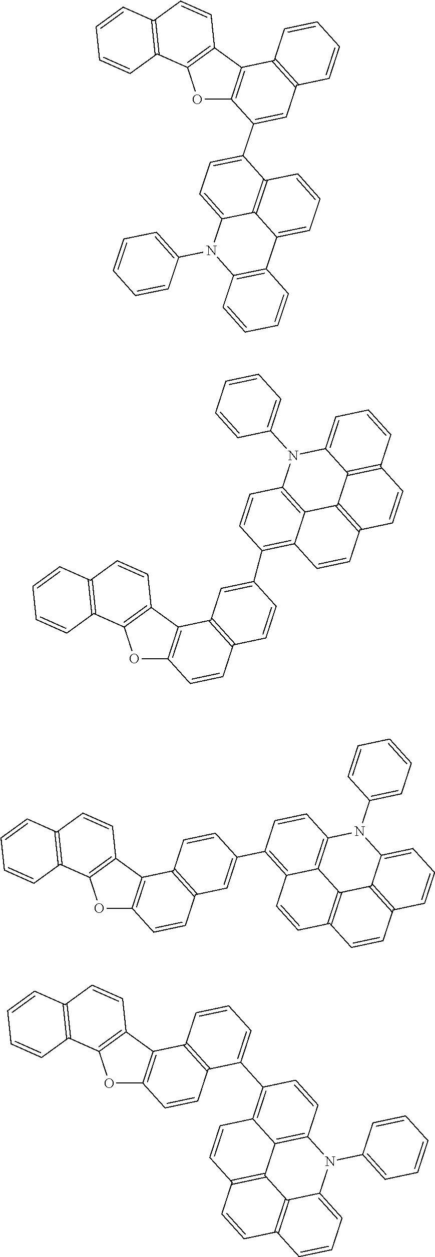

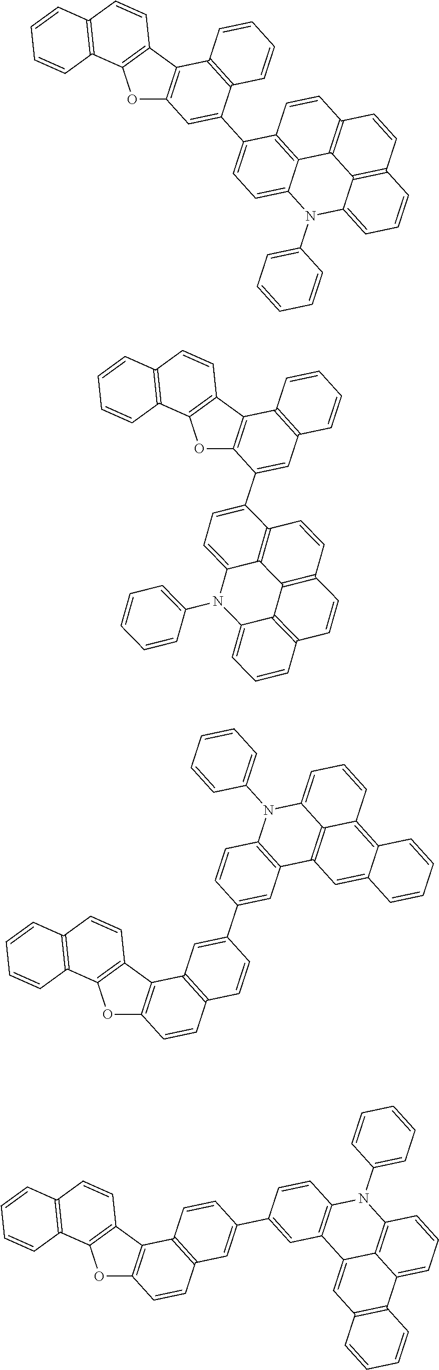 [SMILES: c1ccc(N2c3cccc4ccc5ccc6c(-c7cc8oc9c%10ccccc%10ccc9c8c8ccccc78)ccc2c6c5c34)cc1 ; c1ccc(N2c3cccc4ccc5ccc6c(-c7cc8ccccc8c8c7oc7c9ccccc9ccc78)ccc2c6c5c34)cc1 ; c1ccc(N2c3ccc(-c4ccc5ccc6oc7c8ccccc8ccc7c6c5c4)cc3-c3cc4ccccc4c4cccc2c34)cc1 ; c1ccc(N2c3ccc(-c4ccc5c(ccc6oc7c8ccccc8ccc7c65)c4)cc3-c3cc4ccccc4c4cccc2c34)cc1]

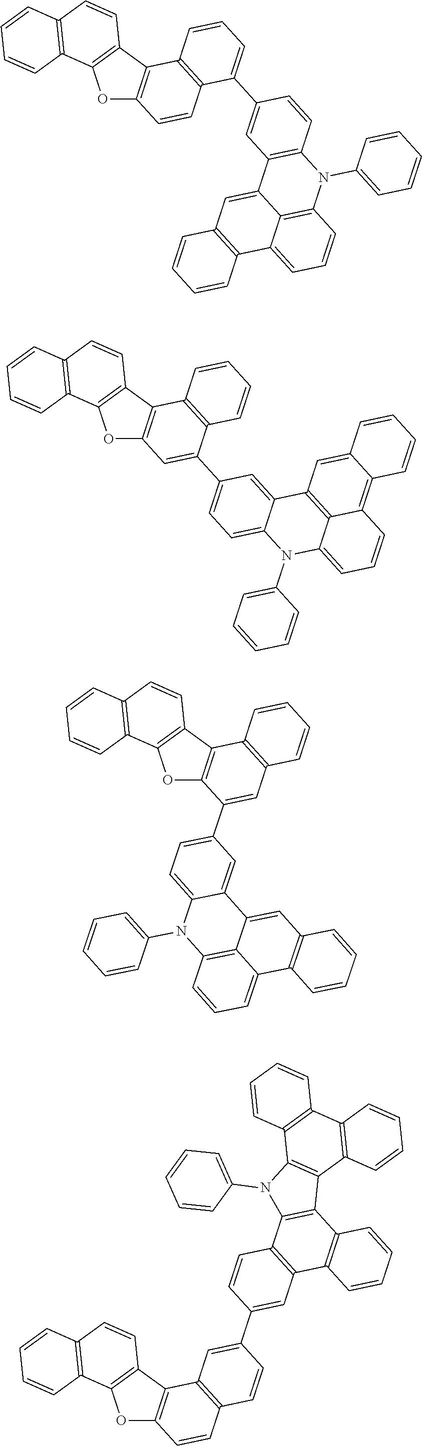 [SMILES: c1ccc(N2c3ccc(-c4cccc5c4ccc4oc6c7ccccc7ccc6c45)cc3-c3cc4ccccc4c4cccc2c34)cc1 ; c1ccc(N2c3ccc(-c4cc5oc6c7ccccc7ccc6c5c5ccccc45)cc3-c3cc4ccccc4c4cccc2c34)cc1 ; c1ccc(N2c3ccc(-c4cc5ccccc5c5c4oc4c6ccccc6ccc45)cc3-c3cc4ccccc4c4cccc2c34)cc1 ; c1ccc(-n2c3c4ccccc4c4ccccc4c3c3c4ccccc4c4cc(-c5ccc6ccc7oc8c9ccccc9ccc8c7c6c5)ccc4c32)cc1]

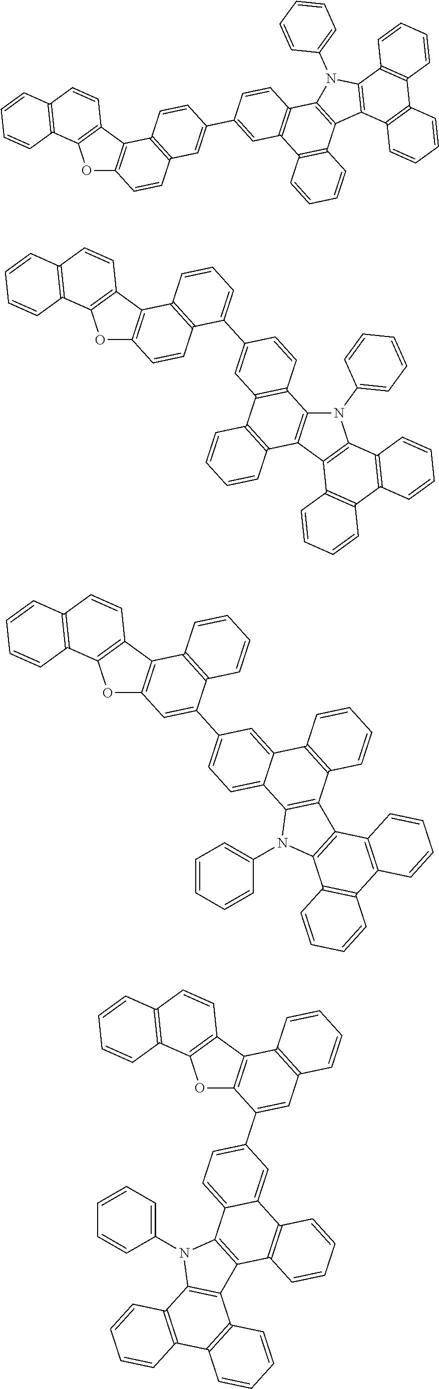 [SMILES: c1ccc(-n2c3c4ccccc4c4ccccc4c3c3c4ccccc4c4cc(-c5ccc6c(ccc7oc8c9ccccc9ccc8c76)c5)ccc4c32)cc1 ; c1ccc(-n2c3c4ccccc4c4ccccc4c3c3c4ccccc4c4cc(-c5cccc6c5ccc5oc7c8ccccc8ccc7c56)ccc4c32)cc1 ; c1ccc(-n2c3c4ccccc4c4ccccc4c3c3c4ccccc4c4cc(-c5cc6oc7c8ccccc8ccc7c6c6ccccc56)ccc4c32)cc1 ; c1ccc(-n2c3c4ccccc4c4ccccc4c3c3c4ccccc4c4cc(-c5cc6ccccc6c6c5oc5c7ccccc7ccc56)ccc4c32)cc1]

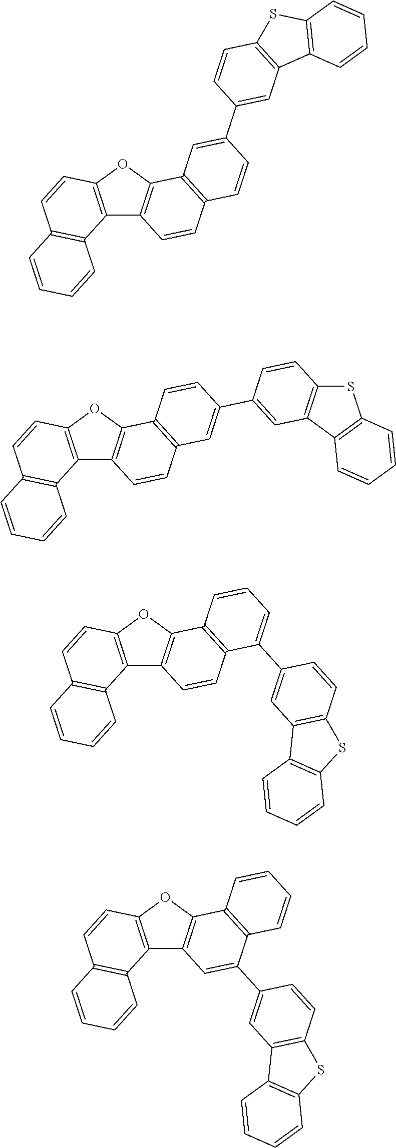 [SMILES: c1ccc2c(c1)ccc1oc3c4cc(-c5ccc6sc7ccccc7c6c5)ccc4ccc3c12 ; c1ccc2c(c1)ccc1oc3c4ccc(-c5ccc6sc7ccccc7c6c5)cc4ccc3c12 ; c1ccc2c(c1)ccc1oc3c4cccc(-c5ccc6sc7ccccc7c6c5)c4ccc3c12 ; c1ccc2c(c1)ccc1oc3c4ccccc4c(-c4ccc5sc6ccccc6c5c4)cc3c12]

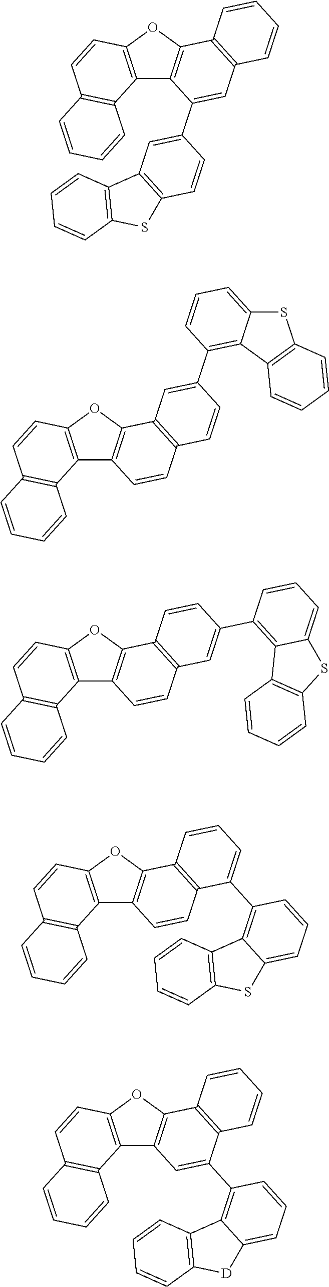

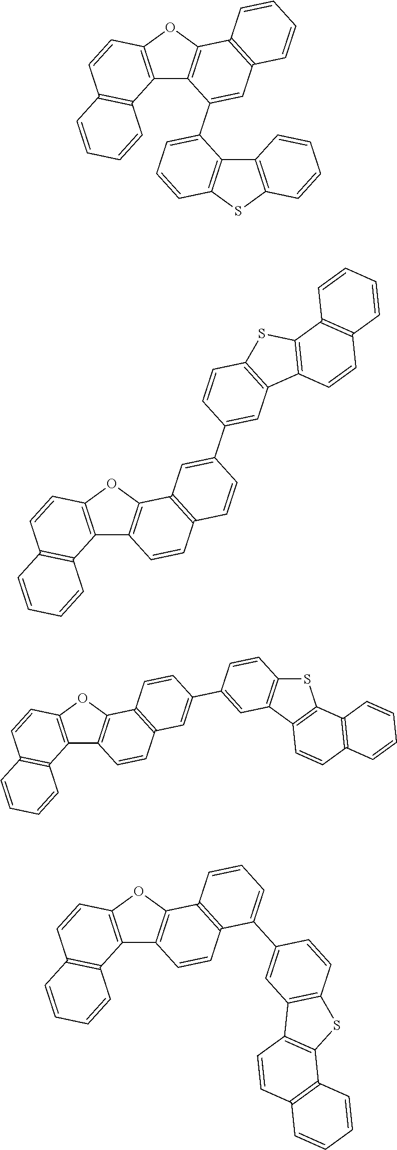 [SMILES: c1ccc2c(c1)cc(-c1cccc3sc4ccccc4c13)c1c2oc2ccc3ccccc3c21 ; c1ccc2c(c1)ccc1c3cc(-c4ccc5ccc6c(oc7ccc8ccccc8c76)c5c4)ccc3sc21 ; c1ccc2c(c1)ccc1c3cc(-c4ccc5c(ccc6c5oc5ccc7ccccc7c56)c4)ccc3sc21 ; c1ccc2c(c1)ccc1c3cc(-c4cccc5c4ccc4c5oc5ccc6ccccc6c54)ccc3sc21]

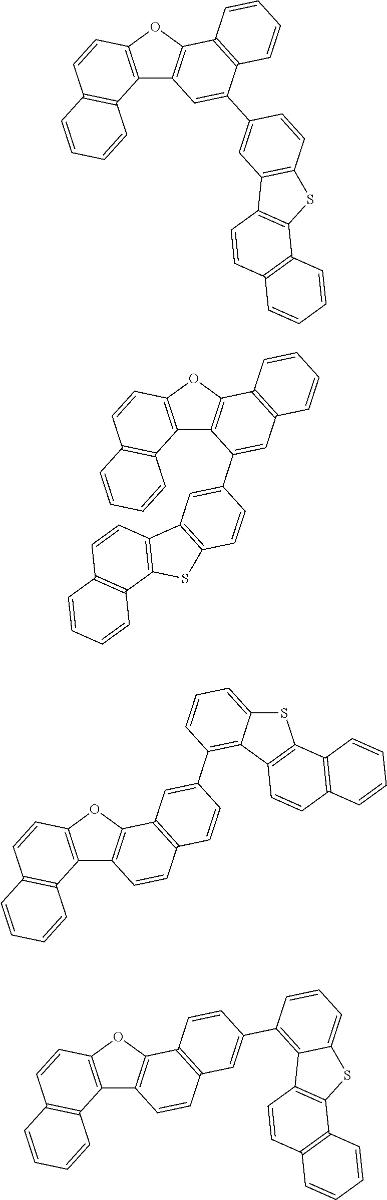

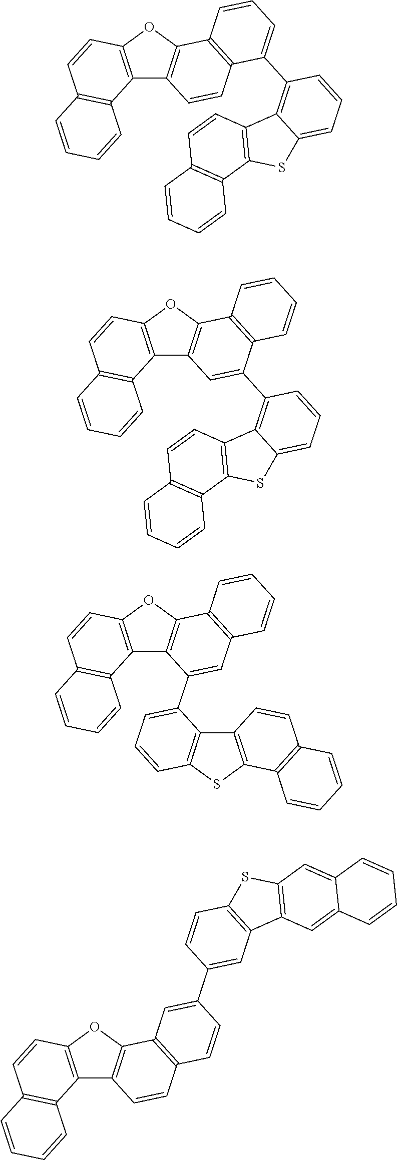 [SMILES: c1ccc2c(c1)ccc1c2sc2cccc(-c3cccc4c3ccc3c4oc4ccc5ccccc5c43)c21 ; c1ccc2c(c1)ccc1c2sc2cccc(-c3cc4c(oc5ccc6ccccc6c54)c4ccccc34)c21 ; c1ccc2c(c1)cc(-c1cccc3sc4c5ccccc5ccc4c13)c1c2oc2ccc3ccccc3c21 ; c1ccc2cc3c(cc2c1)sc1ccc(-c2ccc4ccc5c(oc6ccc7ccccc7c65)c4c2)cc13]

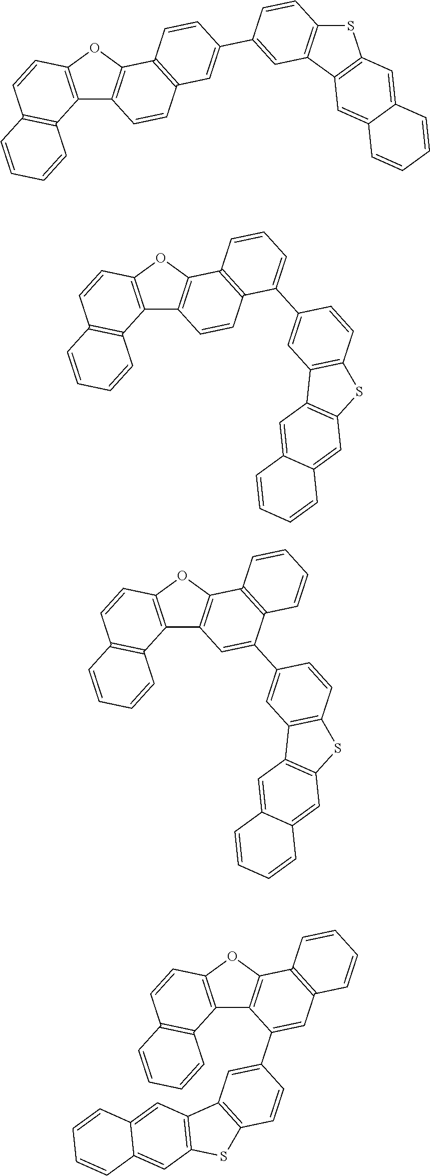

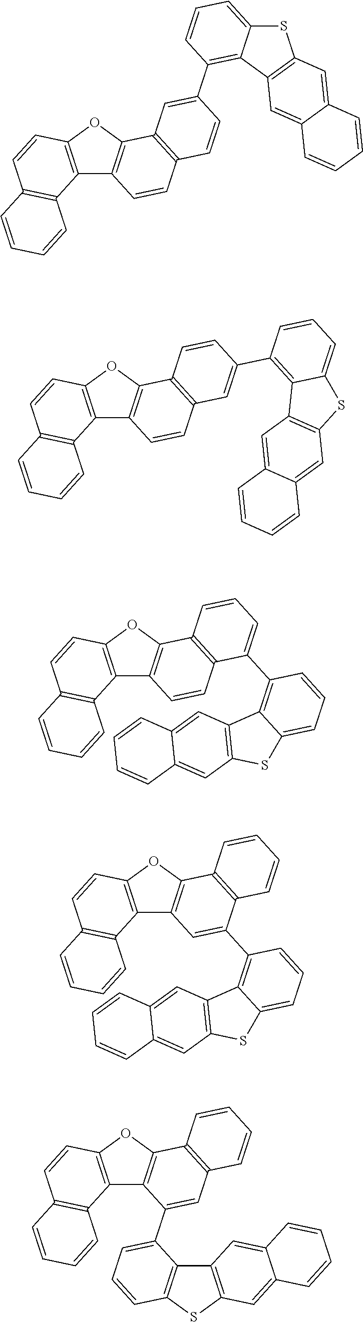 [SMILES: c1ccc2cc3c(cc2c1)sc1cccc(-c2ccc4ccc5c(oc6ccc7ccccc7c65)c4c2)c13 ; c1ccc2cc3c(cc2c1)sc1cccc(-c2ccc4c(ccc5c4oc4ccc6ccccc6c45)c2)c13 ; c1ccc2cc3c(cc2c1)sc1cccc(-c2cccc4c2ccc2c4oc4ccc5ccccc5c42)c13 ; c1ccc2cc3c(cc2c1)sc1cccc(-c2cc4c(oc5ccc6ccccc6c54)c4ccccc24)c13 ; c1ccc2cc3c(cc2c1)sc1cccc(-c2cc4ccccc4c4oc5ccc6ccccc6c5c24)c13]

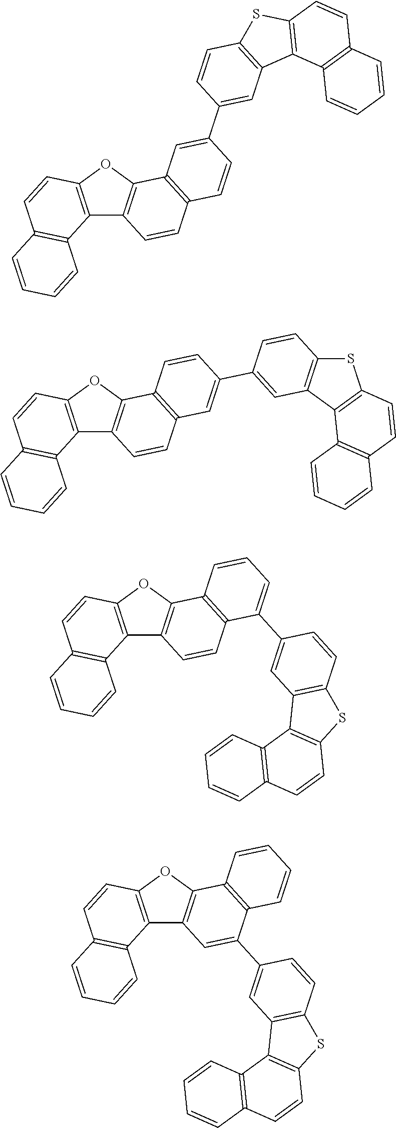 [SMILES: c1ccc2c(c1)ccc1oc3c4cc(-c5ccc6sc7ccc8ccccc8c7c6c5)ccc4ccc3c12 ; c1ccc2c(c1)ccc1oc3c4ccc(-c5ccc6sc7ccc8ccccc8c7c6c5)cc4ccc3c12 ; c1ccc2c(c1)ccc1oc3c4cccc(-c5ccc6sc7ccc8ccccc8c7c6c5)c4ccc3c12 ; c1ccc2c(c1)ccc1oc3c4ccccc4c(-c4ccc5sc6ccc7ccccc7c6c5c4)cc3c12]

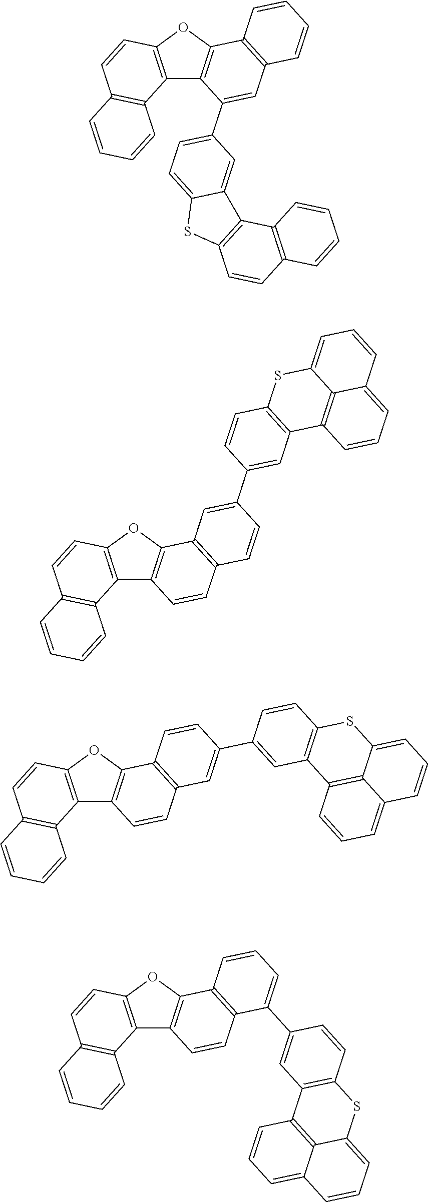 [SMILES: c1ccc2c(c1)cc(-c1ccc3sc4ccc5ccccc5c4c3c1)c1c2oc2ccc3ccccc3c21 ; c1cc2c3c(cccc3c1)-c1cc(-c3ccc4ccc5c(oc6ccc7ccccc7c65)c4c3)ccc1S2 ; c1cc2c3c(cccc3c1)-c1cc(-c3ccc4c(ccc5c4oc4ccc6ccccc6c45)c3)ccc1S2 ; c1cc2c3c(cccc3c1)-c1cc(-c3cccc4c3ccc3c4oc4ccc5ccccc5c43)ccc1S2]

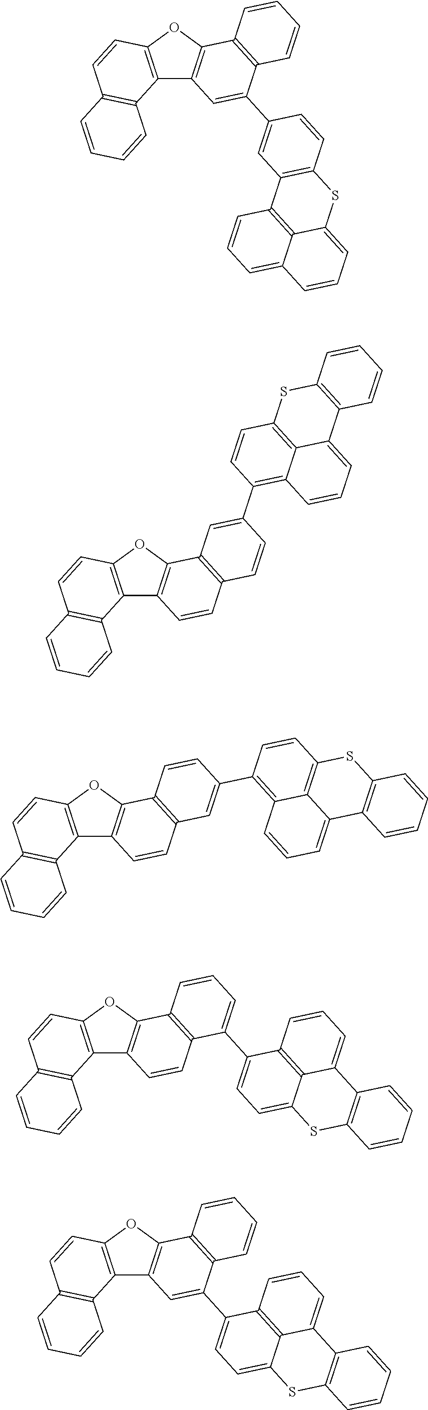 [SMILES: c1cc2c3c(cccc3c1)-c1cc(-c3cc4c(oc5ccc6ccccc6c54)c4ccccc34)ccc1S2 ; c1ccc2c(c1)Sc1ccc(-c3ccc4ccc5c(oc6ccc7ccccc7c65)c4c3)c3cccc-2c13 ; c1ccc2c(c1)Sc1ccc(-c3ccc4c(ccc5c4oc4ccc6ccccc6c45)c3)c3cccc-2c13 ; c1ccc2c(c1)Sc1ccc(-c3cccc4c3ccc3c4oc4ccc5ccccc5c43)c3cccc-2c13 ; c1ccc2c(c1)Sc1ccc(-c3cc4c(oc5ccc6ccccc6c54)c4ccccc34)c3cccc-2c13]

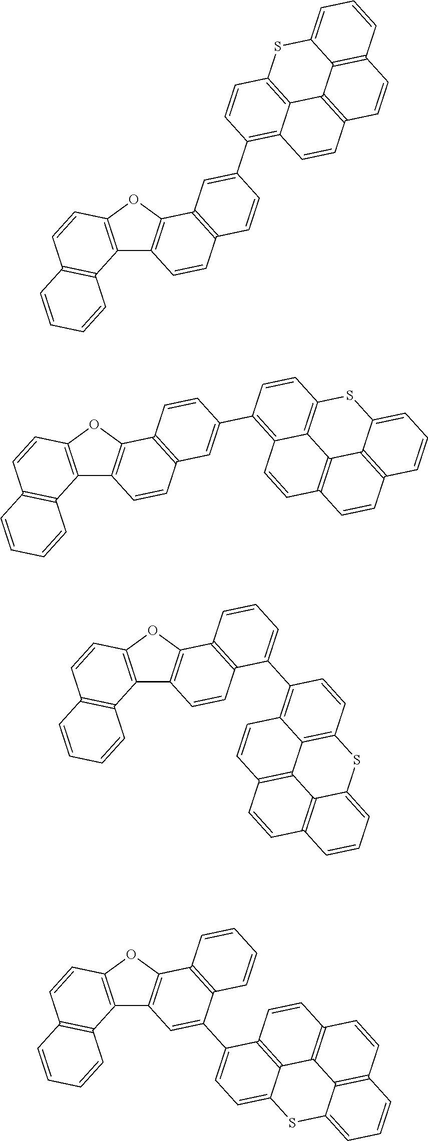 [SMILES: c1ccc2c(c1)ccc1oc3c4cc(-c5ccc6c7c5ccc5ccc8cccc(c8c57)S6)ccc4ccc3c12 ; c1ccc2c(c1)ccc1oc3c4ccc(-c5ccc6c7c5ccc5ccc8cccc(c8c57)S6)cc4ccc3c12 ; c1ccc2c(c1)ccc1oc3c4cccc(-c5ccc6c7c5ccc5ccc8cccc(c8c57)S6)c4ccc3c12 ; c1ccc2c(c1)ccc1oc3c4ccccc4c(-c4ccc5c6c4ccc4ccc7cccc(c7c46)S5)cc3c12]

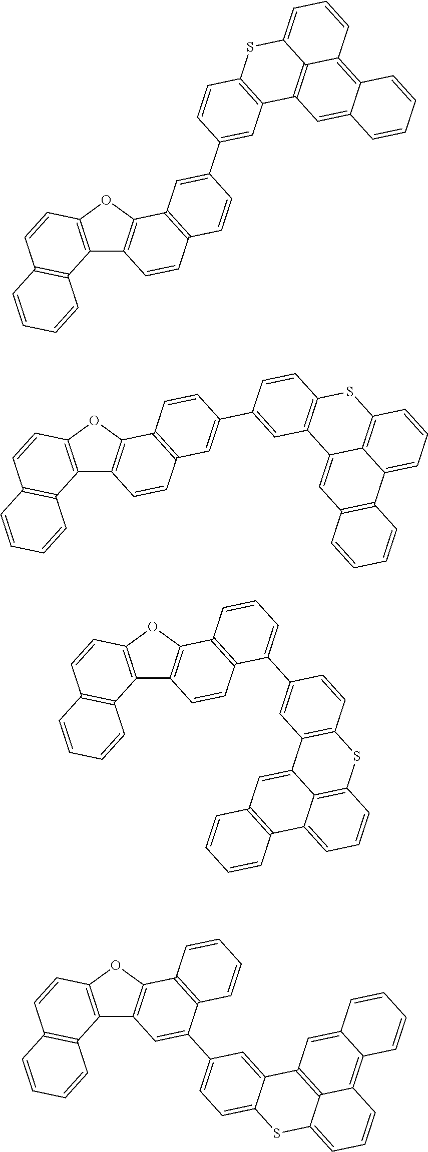 [SMILES: c1ccc2c(c1)cc1c3c(cccc32)Sc2ccc(-c3ccc4ccc5c(oc6ccc7ccccc7c65)c4c3)cc2-1 ; c1ccc2c(c1)cc1c3c(cccc32)Sc2ccc(-c3ccc4c(ccc5c4oc4ccc6ccccc6c45)c3)cc2-1 ; c1ccc2c(c1)cc1c3c(cccc32)Sc2ccc(-c3cccc4c3ccc3c4oc4ccc5ccccc5c43)cc2-1 ; c1ccc2c(c1)cc1c3c(cccc32)Sc2ccc(-c3cc4c(oc5ccc6ccccc6c54)c4ccccc34)cc2-1]

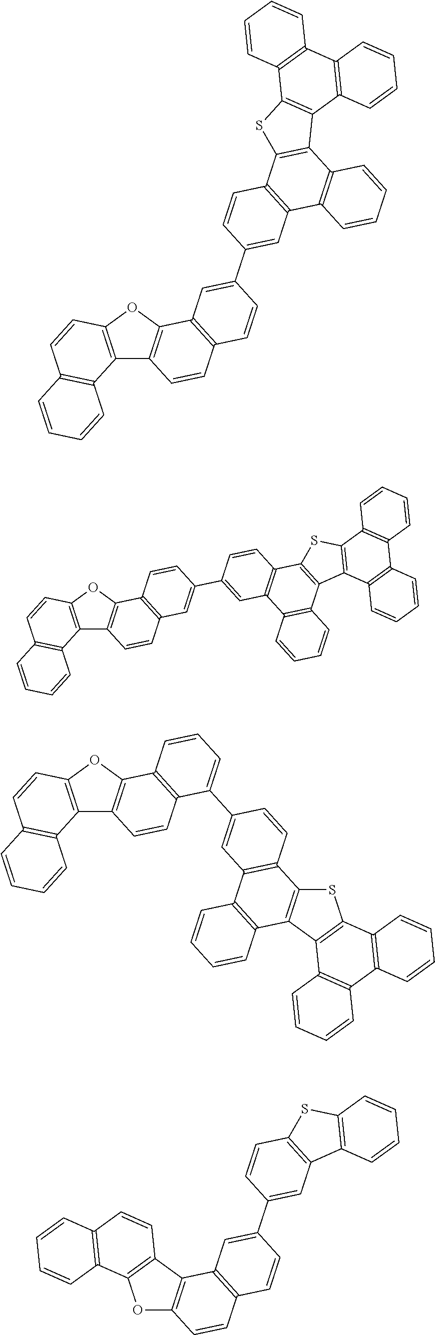 [SMILES: c1ccc2c(c1)ccc1oc3c4cc(-c5ccc6c(c5)c5ccccc5c5c6sc6c7ccccc7c7ccccc7c65)ccc4ccc3c12 ; c1ccc2c(c1)ccc1oc3c4ccc(-c5ccc6c(c5)c5ccccc5c5c6sc6c7ccccc7c7ccccc7c65)cc4ccc3c12 ; c1ccc2c(c1)ccc1oc3c4cccc(-c5ccc6c(c5)c5ccccc5c5c6sc6c7ccccc7c7ccccc7c65)c4ccc3c12 ; c1ccc2c(c1)ccc1c2oc2ccc3ccc(-c4ccc5sc6ccccc6c5c4)cc3c21]

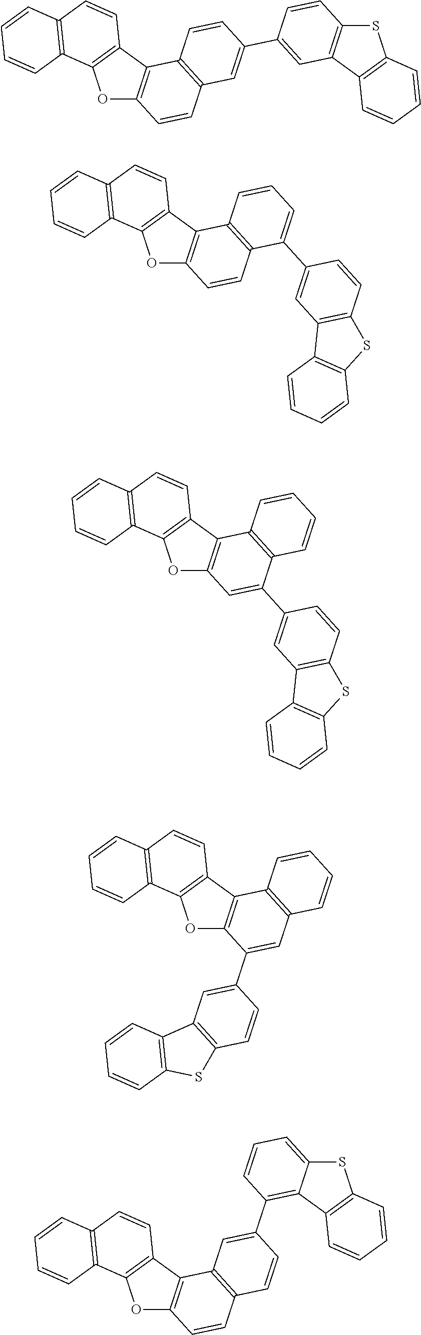 [SMILES: c1ccc2c(c1)ccc1c2oc2ccc3cc(-c4ccc5sc6ccccc6c5c4)ccc3c21 ; c1ccc2c(c1)ccc1c2oc2ccc3c(-c4ccc5sc6ccccc6c5c4)cccc3c21 ; c1ccc2c(c1)ccc1c2oc2cc(-c3ccc4sc5ccccc5c4c3)c3ccccc3c21 ; c1ccc2c(c1)ccc1c2oc2c(-c3ccc4sc5ccccc5c4c3)cc3ccccc3c21 ; c1ccc2c(c1)ccc1c2oc2ccc3ccc(-c4cccc5sc6ccccc6c45)cc3c21]

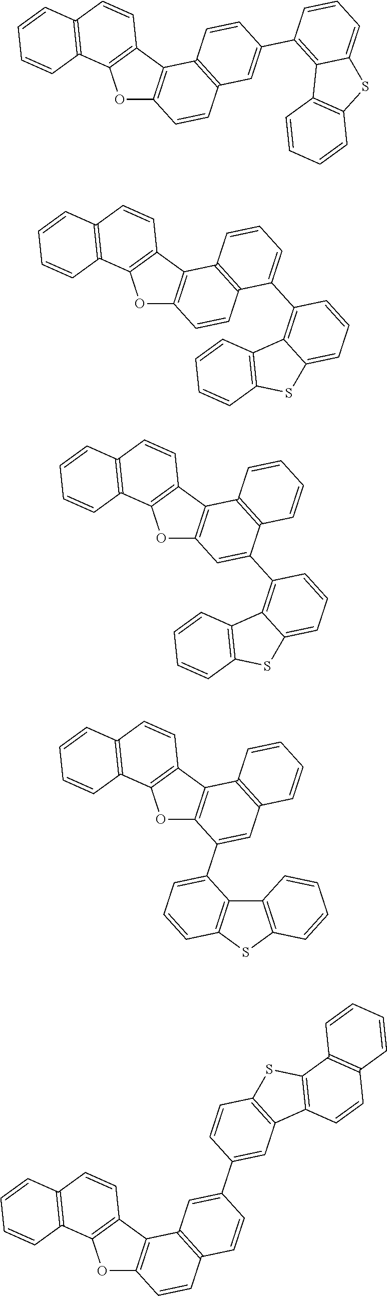 [SMILES: c1ccc2c(c1)ccc1c2oc2ccc3cc(-c4cccc5sc6ccccc6c45)ccc3c21 ; c1ccc2c(c1)ccc1c2oc2ccc3c(-c4cccc5sc6ccccc6c45)cccc3c21 ; c1ccc2c(c1)ccc1c2oc2cc(-c3cccc4sc5ccccc5c34)c3ccccc3c21 ; c1ccc2c(c1)ccc1c2oc2c(-c3cccc4sc5ccccc5c34)cc3ccccc3c21 ; c1ccc2c(c1)ccc1c2oc2ccc3ccc(-c4ccc5sc6c7ccccc7ccc6c5c4)cc3c21]

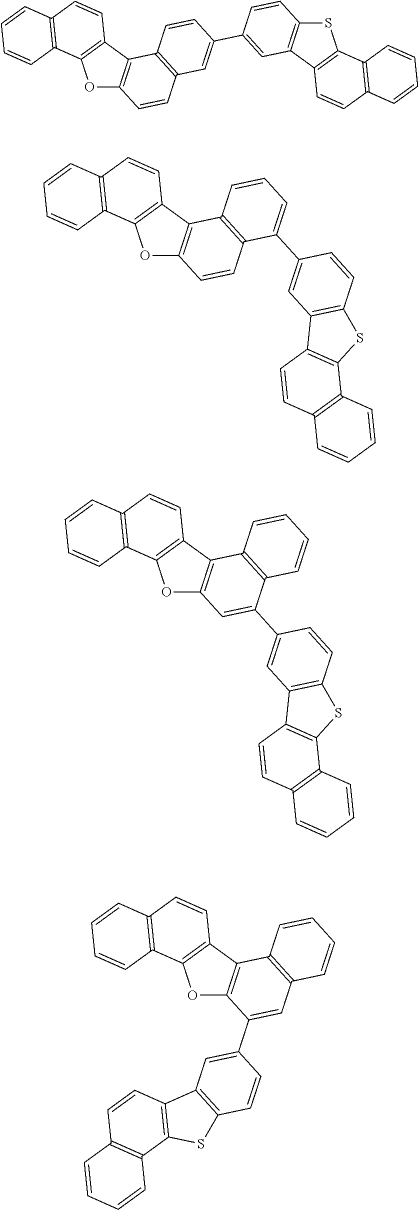 [SMILES: c1ccc2c(c1)ccc1c2oc2ccc3cc(-c4ccc5sc6c7ccccc7ccc6c5c4)ccc3c21 ; c1ccc2c(c1)ccc1c2oc2ccc3c(-c4ccc5sc6c7ccccc7ccc6c5c4)cccc3c21 ; c1ccc2c(c1)ccc1c2oc2cc(-c3ccc4sc5c6ccccc6ccc5c4c3)c3ccccc3c21 ; c1ccc2c(c1)ccc1c2oc2c(-c3ccc4sc5c6ccccc6ccc5c4c3)cc3ccccc3c21]

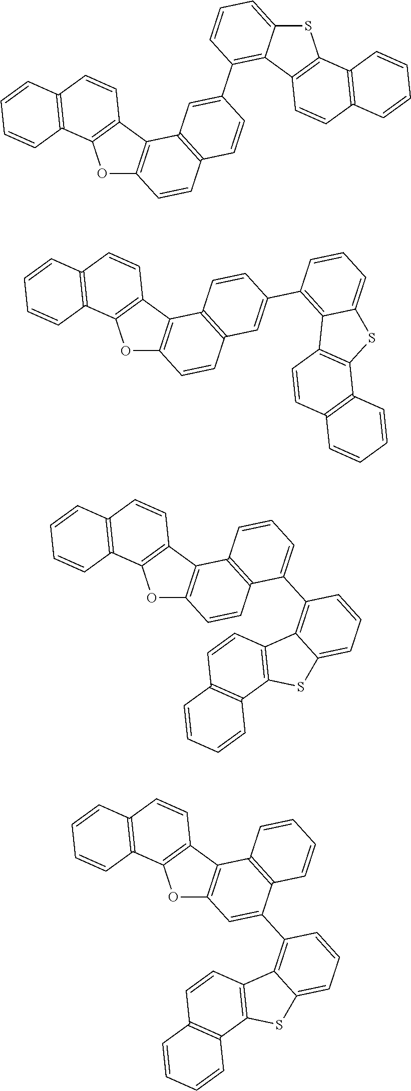 [SMILES: c1ccc2c(c1)ccc1c2oc2ccc3ccc(-c4cccc5sc6c7ccccc7ccc6c45)cc3c21 ; c1ccc2c(c1)ccc1c2oc2ccc3cc(-c4cccc5sc6c7ccccc7ccc6c45)ccc3c21 ; c1ccc2c(c1)ccc1c2oc2ccc3c(-c4cccc5sc6c7ccccc7ccc6c45)cccc3c21 ; c1ccc2c(c1)ccc1c2oc2cc(-c3cccc4sc5c6ccccc6ccc5c34)c3ccccc3c21]

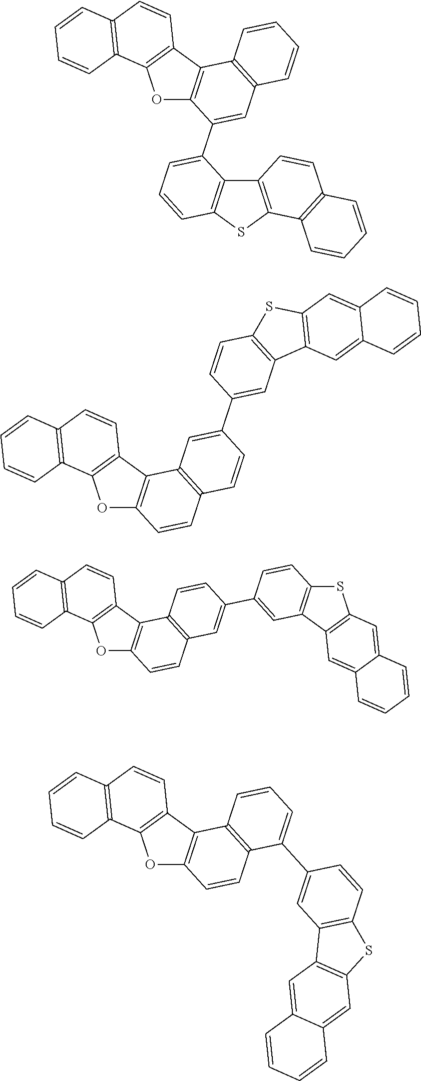

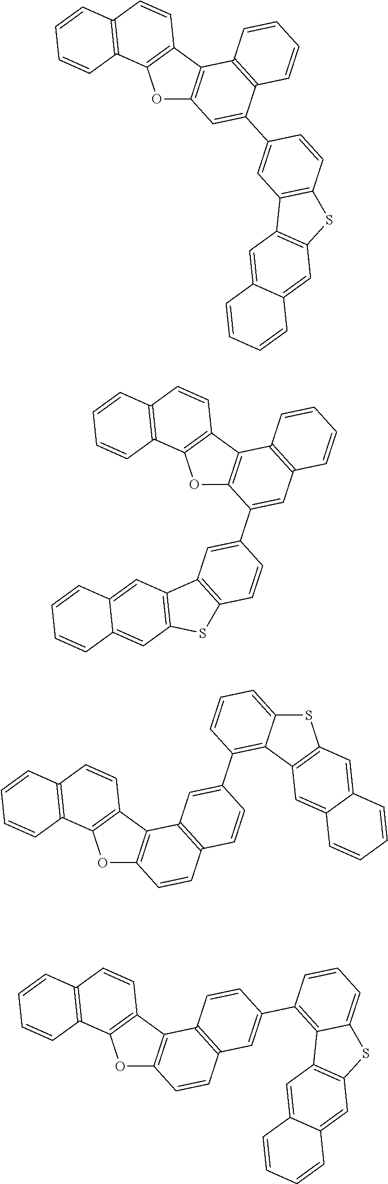 [SMILES: c1ccc2cc3c(cc2c1)sc1ccc(-c2cc4oc5c6ccccc6ccc5c4c4ccccc24)cc13 ; c1ccc2cc3c(cc2c1)sc1ccc(-c2cc4ccccc4c4c2oc2c5ccccc5ccc24)cc13 ; c1ccc2cc3c(cc2c1)sc1cccc(-c2ccc4ccc5oc6c7ccccc7ccc6c5c4c2)c13 ; c1ccc2cc3c(cc2c1)sc1cccc(-c2ccc4c(ccc5oc6c7ccccc7ccc6c54)c2)c13]

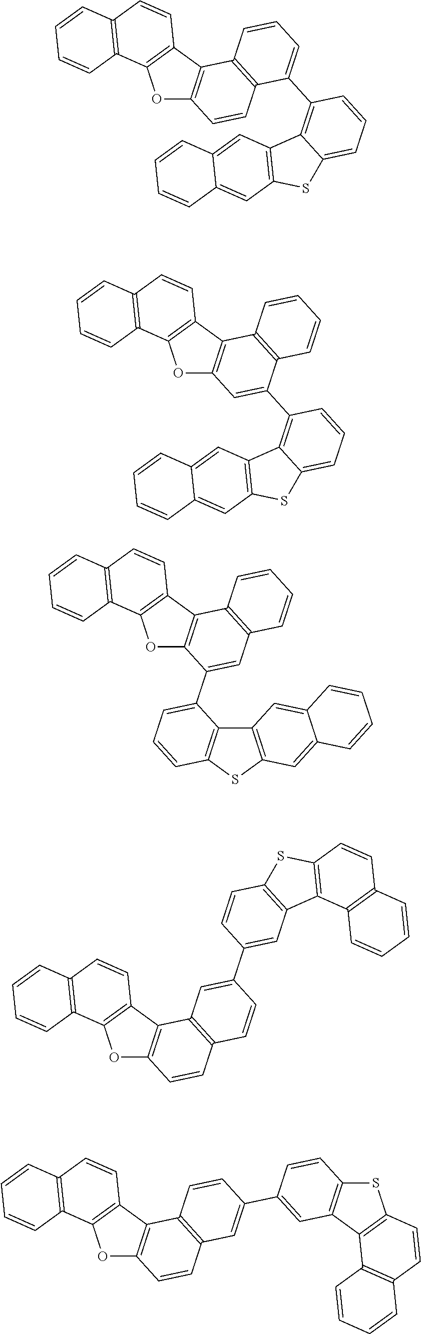

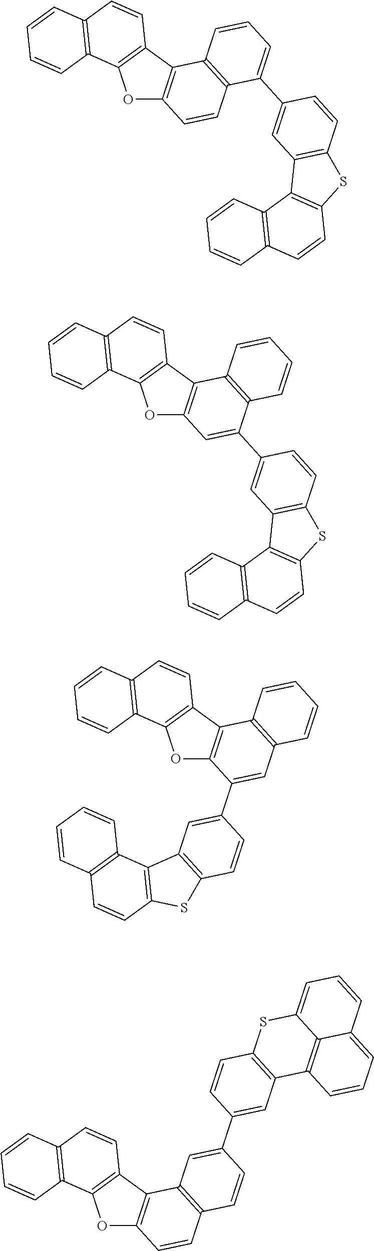 [SMILES: c1ccc2c(c1)ccc1c2oc2ccc3c(-c4ccc5sc6ccc7ccccc7c6c5c4)cccc3c21 ; c1ccc2c(c1)ccc1c2oc2cc(-c3ccc4sc5ccc6ccccc6c5c4c3)c3ccccc3c21 ; c1ccc2c(c1)ccc1c2oc2c(-c3ccc4sc5ccc6ccccc6c5c4c3)cc3ccccc3c21 ; c1cc2c3c(cccc3c1)-c1cc(-c3ccc4ccc5oc6c7ccccc7ccc6c5c4c3)ccc1S2]

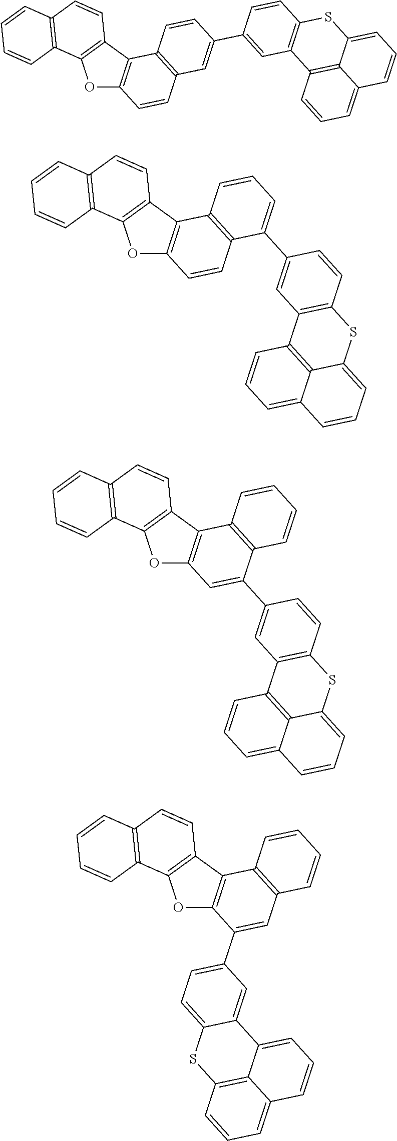 [SMILES: c1cc2c3c(cccc3c1)-c1cc(-c3ccc4c(ccc5oc6c7ccccc7ccc6c54)c3)ccc1S2 ; c1cc2c3c(cccc3c1)-c1cc(-c3cccc4c3ccc3oc5c6ccccc6ccc5c34)ccc1S2 ; c1cc2c3c(cccc3c1)-c1cc(-c3cc4oc5c6ccccc6ccc5c4c4ccccc34)ccc1S2 ; c1cc2c3c(cccc3c1)-c1cc(-c3cc4ccccc4c4c3oc3c5ccccc5ccc34)ccc1S2]

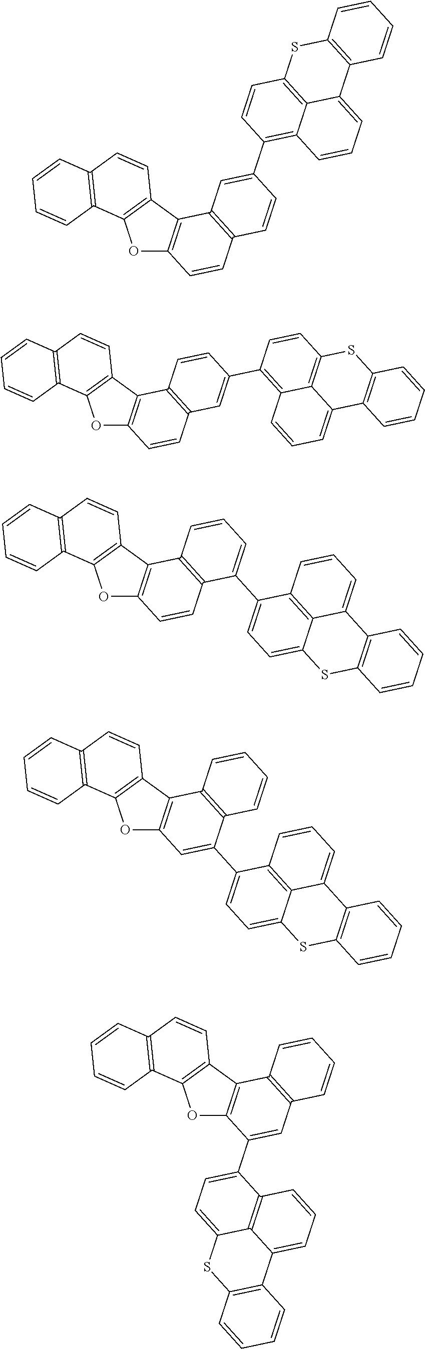 [SMILES: c1ccc2c(c1)Sc1ccc(-c3ccc4ccc5oc6c7ccccc7ccc6c5c4c3)c3cccc-2c13 ; c1ccc2c(c1)Sc1ccc(-c3ccc4c(ccc5oc6c7ccccc7ccc6c54)c3)c3cccc-2c13 ; c1ccc2c(c1)Sc1ccc(-c3cccc4c3ccc3oc5c6ccccc6ccc5c34)c3cccc-2c13 ; c1ccc2c(c1)Sc1ccc(-c3cc4oc5c6ccccc6ccc5c4c4ccccc34)c3cccc-2c13 ; c1ccc2c(c1)Sc1ccc(-c3cc4ccccc4c4c3oc3c5ccccc5ccc34)c3cccc-2c13]

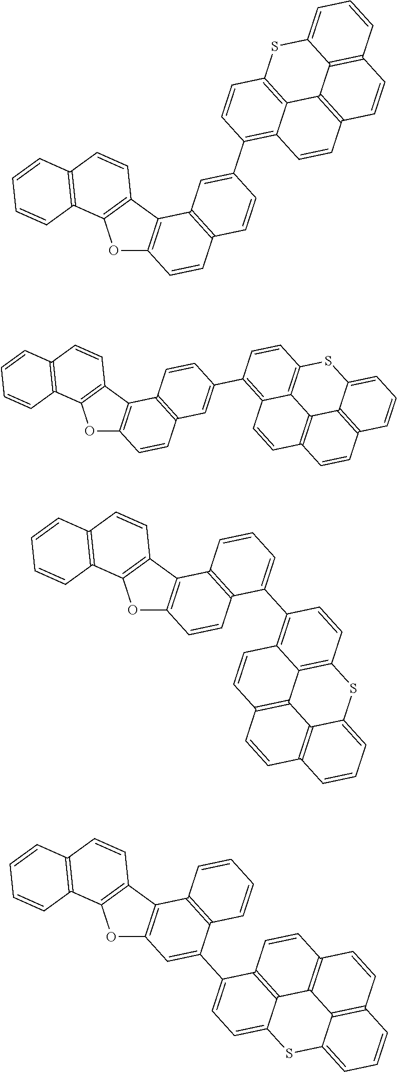 [SMILES: c1ccc2c(c1)ccc1c2oc2ccc3ccc(-c4ccc5c6c4ccc4ccc7cccc(c7c46)S5)cc3c21 ; c1ccc2c(c1)ccc1c2oc2ccc3cc(-c4ccc5c6c4ccc4ccc7cccc(c7c46)S5)ccc3c21 ; c1ccc2c(c1)ccc1c2oc2ccc3c(-c4ccc5c6c4ccc4ccc7cccc(c7c46)S5)cccc3c21 ; c1ccc2c(c1)ccc1c2oc2cc(-c3ccc4c5c3ccc3ccc6cccc(c6c35)S4)c3ccccc3c21]

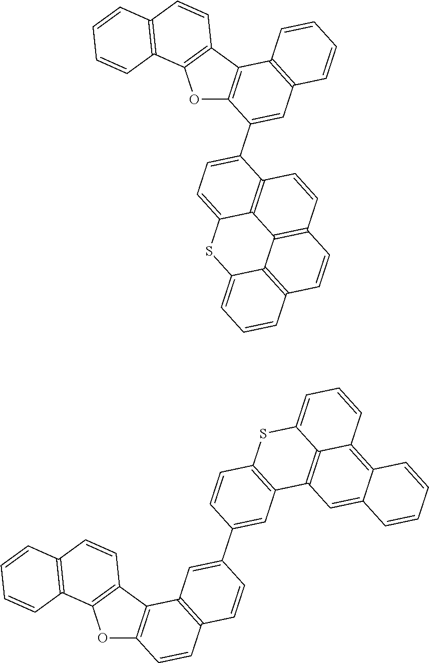 [SMILES: c1ccc2c(c1)ccc1c2oc2c(-c3ccc4c5c3ccc3ccc6cccc(c6c35)S4)cc3ccccc3c21 ; c1ccc2c(c1)cc1c3c(cccc32)Sc2ccc(-c3ccc4ccc5oc6c7ccccc7ccc6c5c4c3)cc2-1]

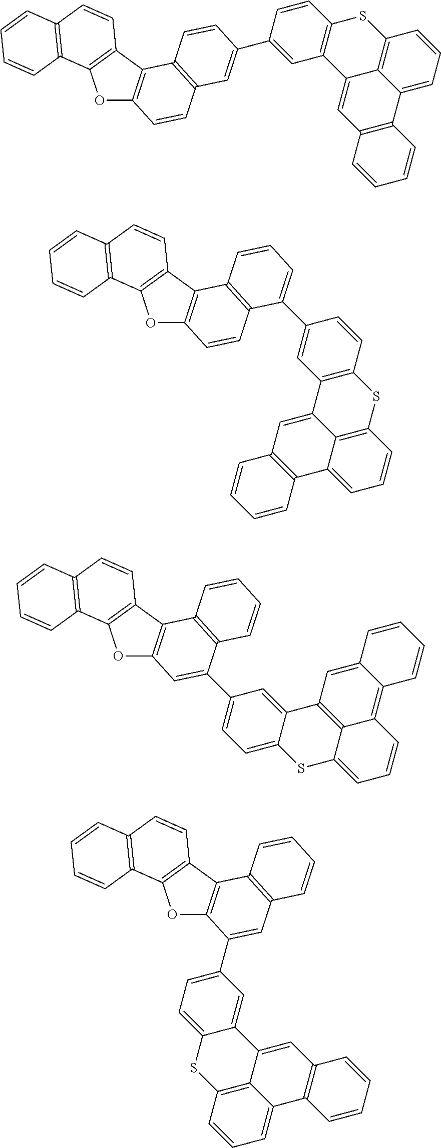 [SMILES: c1ccc2c(c1)cc1c3c(cccc32)Sc2ccc(-c3ccc4c(ccc5oc6c7ccccc7ccc6c54)c3)cc2-1 ; c1ccc2c(c1)cc1c3c(cccc32)Sc2ccc(-c3cccc4c3ccc3oc5c6ccccc6ccc5c34)cc2-1 ; c1ccc2c(c1)cc1c3c(cccc32)Sc2ccc(-c3cc4oc5c6ccccc6ccc5c4c4ccccc34)cc2-1 ; c1ccc2c(c1)cc1c3c(cccc32)Sc2ccc(-c3cc4ccccc4c4c3oc3c5ccccc5ccc34)cc2-1]

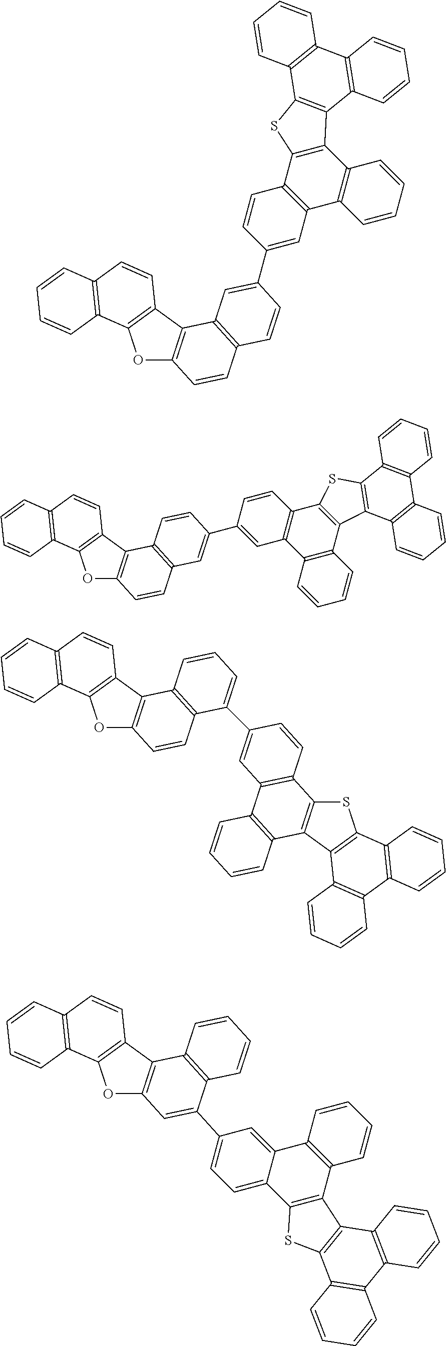 [SMILES: c1ccc2c(c1)ccc1c2oc2ccc3ccc(-c4ccc5c(c4)c4ccccc4c4c5sc5c6ccccc6c6ccccc6c54)cc3c21 ; c1ccc2c(c1)ccc1c2oc2ccc3cc(-c4ccc5c(c4)c4ccccc4c4c5sc5c6ccccc6c6ccccc6c54)ccc3c21 ; c1ccc2c(c1)ccc1c2oc2ccc3c(-c4ccc5c(c4)c4ccccc4c4c5sc5c6ccccc6c6ccccc6c54)cccc3c21 ; c1ccc2c(c1)ccc1c2oc2cc(-c3ccc4c(c3)c3ccccc3c3c4sc4c5ccccc5c5ccccc5c43)c3ccccc3c21]

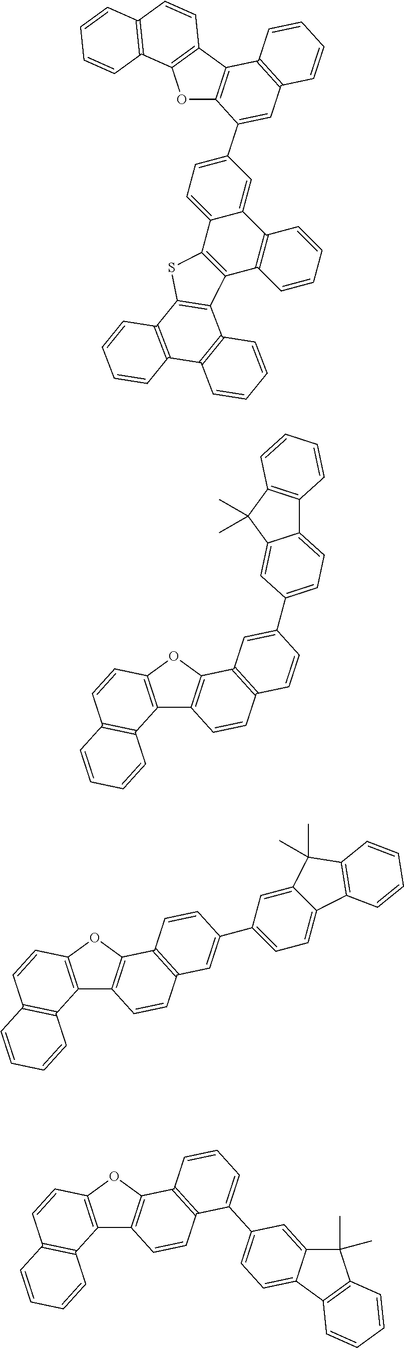 [SMILES: c1ccc2c(c1)ccc1c2oc2c(-c3ccc4c(c3)c3ccccc3c3c4sc4c5ccccc5c5ccccc5c43)cc3ccccc3c21 ; CC1(C)c2ccccc2-c2ccc(-c3ccc4ccc5c(oc6ccc7ccccc7c65)c4c3)cc21 ; CC1(C)c2ccccc2-c2ccc(-c3ccc4c(ccc5c4oc4ccc6ccccc6c45)c3)cc21 ; CC1(C)c2ccccc2-c2ccc(-c3cccc4c3ccc3c4oc4ccc5ccccc5c43)cc21]

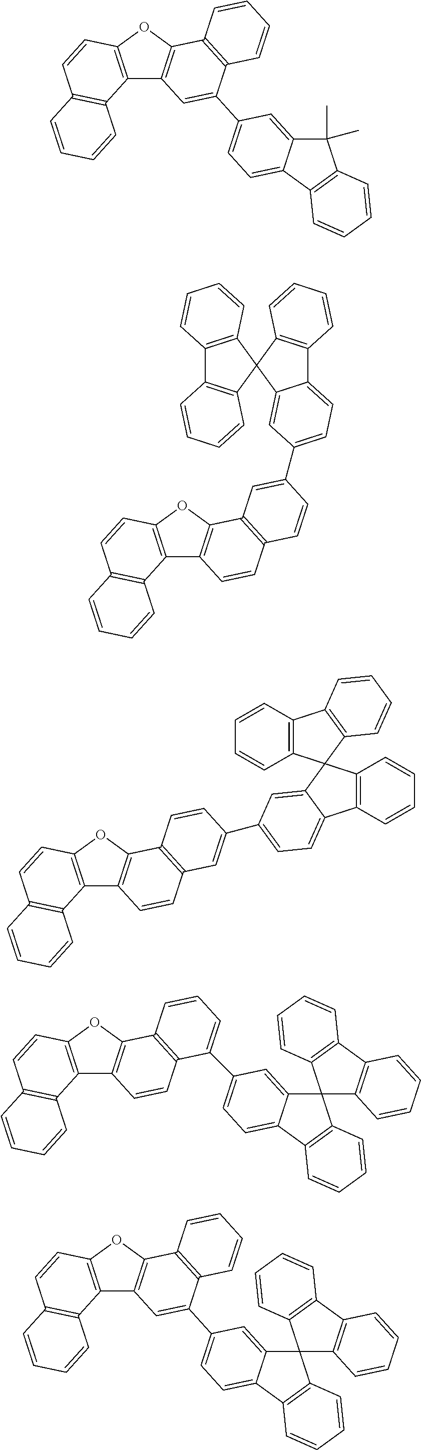 [SMILES: CC1(C)c2ccccc2-c2ccc(-c3cc4c(oc5ccc6ccccc6c54)c4ccccc34)cc21 ; c1ccc2c(c1)-c1ccccc1C21c2ccccc2-c2ccc(-c3ccc4ccc5c(oc6ccc7ccccc7c65)c4c3)cc21 ; c1ccc2c(c1)-c1ccccc1C21c2ccccc2-c2ccc(-c3ccc4c(ccc5c4oc4ccc6ccccc6c45)c3)cc21 ; c1ccc2c(c1)-c1ccccc1C21c2ccccc2-c2ccc(-c3cccc4c3ccc3c4oc4ccc5ccccc5c43)cc21 ; c1ccc2c(c1)-c1ccccc1C21c2ccccc2-c2ccc(-c3cc4c(oc5ccc6ccccc6c54)c4ccccc34)cc21]

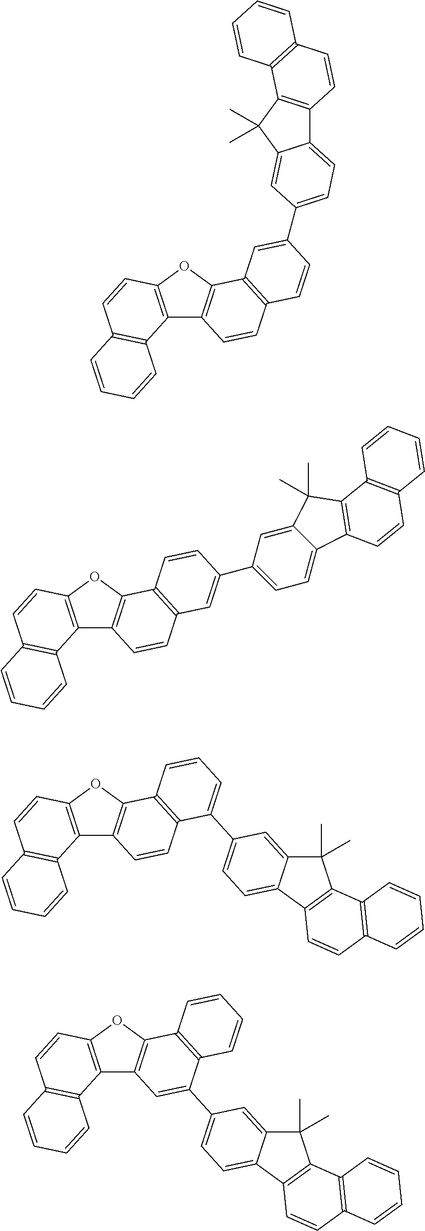 [SMILES: CC1(C)c2cc(-c3ccc4ccc5c(oc6ccc7ccccc7c65)c4c3)ccc2-c2ccc3ccccc3c21 ; CC1(C)c2cc(-c3ccc4c(ccc5c4oc4ccc6ccccc6c45)c3)ccc2-c2ccc3ccccc3c21 ; CC1(C)c2cc(-c3cccc4c3ccc3c4oc4ccc5ccccc5c43)ccc2-c2ccc3ccccc3c21 ; CC1(C)c2cc(-c3cc4c(oc5ccc6ccccc6c54)c4ccccc34)ccc2-c2ccc3ccccc3c21]

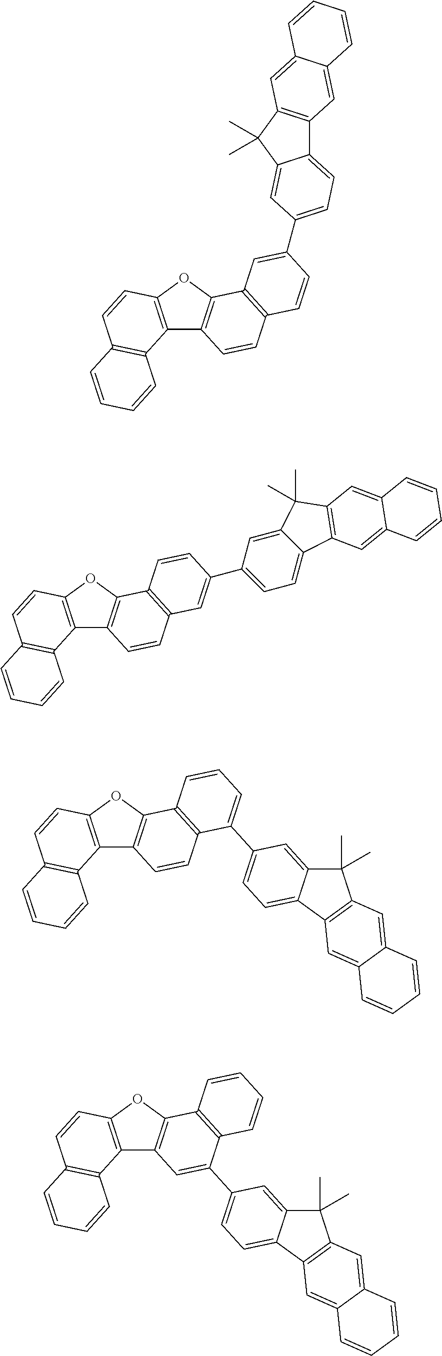 [SMILES: CC1(C)c2cc(-c3ccc4ccc5c(oc6ccc7ccccc7c65)c4c3)ccc2-c2cc3ccccc3cc21 ; CC1(C)c2cc(-c3ccc4c(ccc5c4oc4ccc6ccccc6c45)c3)ccc2-c2cc3ccccc3cc21 ; CC1(C)c2cc(-c3cccc4c3ccc3c4oc4ccc5ccccc5c43)ccc2-c2cc3ccccc3cc21 ; CC1(C)c2cc(-c3cc4c(oc5ccc6ccccc6c54)c4ccccc34)ccc2-c2cc3ccccc3cc21]

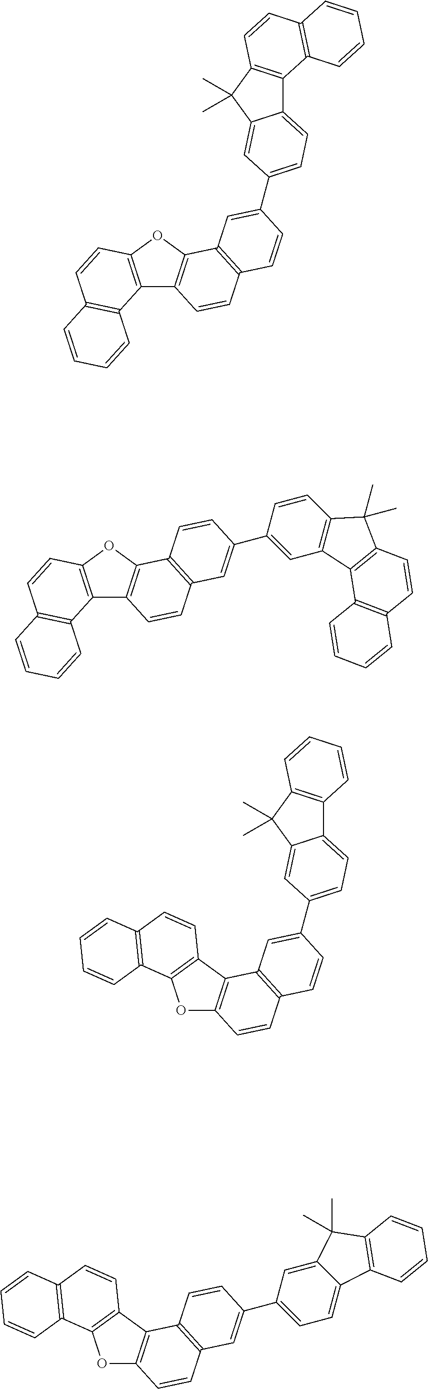 [SMILES: CC1(C)c2cc(-c3ccc4ccc5c(oc6ccc7ccccc7c65)c4c3)ccc2-c2c1ccc1ccccc21 ; CC1(C)c2ccc(-c3ccc4c(ccc5c4oc4ccc6ccccc6c45)c3)cc2-c2c1ccc1ccccc21 ; CC1(C)c2ccccc2-c2ccc(-c3ccc4ccc5oc6c7ccccc7ccc6c5c4c3)cc21 ; CC1(C)c2ccccc2-c2ccc(-c3ccc4c(ccc5oc6c7ccccc7ccc6c54)c3)cc21]

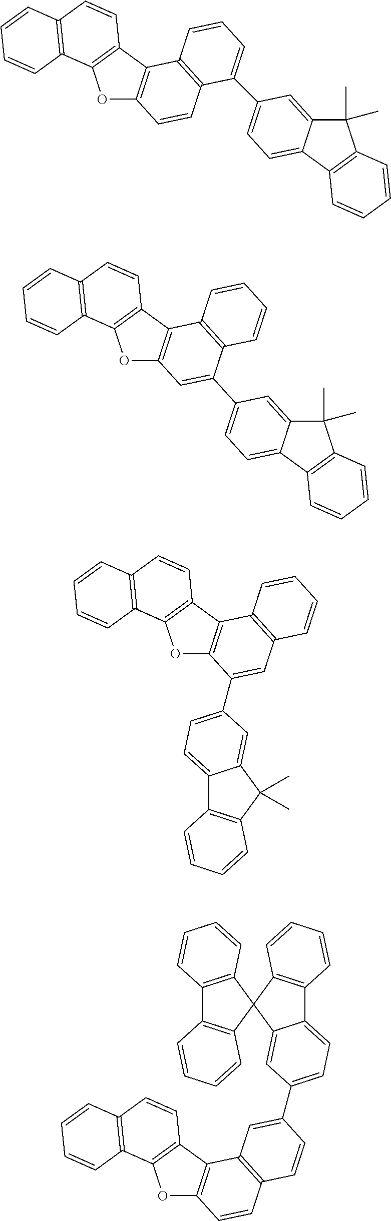 [SMILES: CC1(C)c2ccccc2-c2ccc(-c3cccc4c3ccc3oc5c6ccccc6ccc5c34)cc21 ; CC1(C)c2ccccc2-c2ccc(-c3cc4oc5c6ccccc6ccc5c4c4ccccc34)cc21 ; CC1(C)c2ccccc2-c2ccc(-c3cc4ccccc4c4c3oc3c5ccccc5ccc34)cc21 ; c1ccc2c(c1)-c1ccccc1C21c2ccccc2-c2ccc(-c3ccc4ccc5oc6c7ccccc7ccc6c5c4c3)cc21]

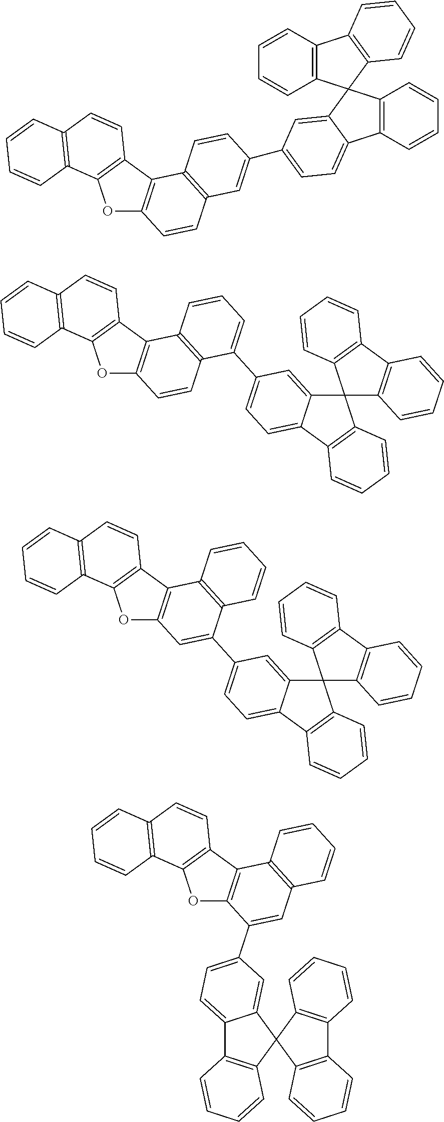 [SMILES: c1ccc2c(c1)-c1ccccc1C21c2ccccc2-c2ccc(-c3ccc4c(ccc5oc6c7ccccc7ccc6c54)c3)cc21 ; c1ccc2c(c1)-c1ccccc1C21c2ccccc2-c2ccc(-c3cccc4c3ccc3oc5c6ccccc6ccc5c34)cc21 ; c1ccc2c(c1)-c1ccccc1C21c2ccccc2-c2ccc(-c3cc4oc5c6ccccc6ccc5c4c4ccccc34)cc21 ; c1ccc2c(c1)-c1ccccc1C21c2ccccc2-c2ccc(-c3cc4ccccc4c4c3oc3c5ccccc5ccc34)cc21]

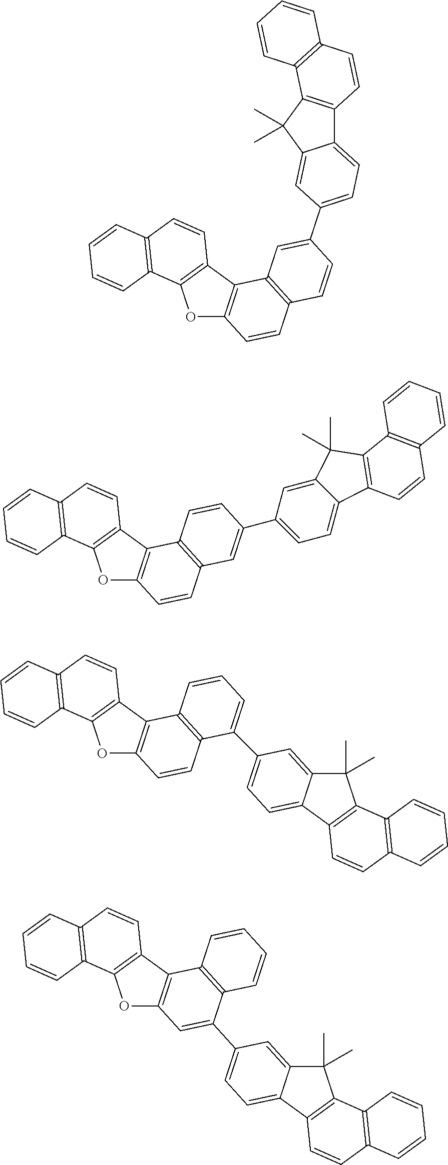 [SMILES: CC1(C)c2cc(-c3ccc4ccc5oc6c7ccccc7ccc6c5c4c3)ccc2-c2ccc3ccccc3c21 ; CC1(C)c2cc(-c3ccc4c(ccc5oc6c7ccccc7ccc6c54)c3)ccc2-c2ccc3ccccc3c21 ; CC1(C)c2cc(-c3cccc4c3ccc3oc5c6ccccc6ccc5c34)ccc2-c2ccc3ccccc3c21 ; CC1(C)c2cc(-c3cc4oc5c6ccccc6ccc5c4c4ccccc34)ccc2-c2ccc3ccccc3c21]

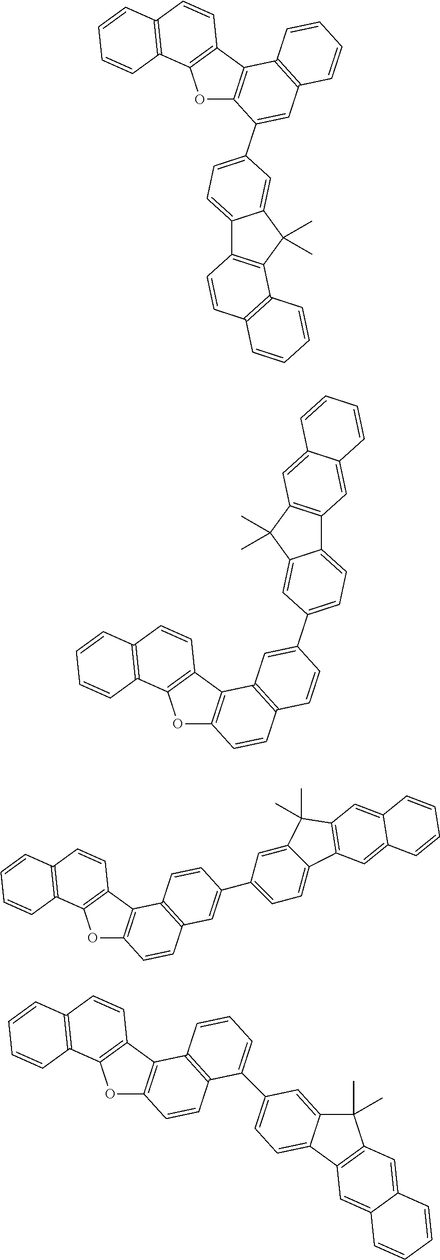 [SMILES: CC1(C)c2cc(-c3cc4ccccc4c4c3oc3c5ccccc5ccc34)ccc2-c2ccc3ccccc3c21 ; CC1(C)c2cc(-c3ccc4ccc5oc6c7ccccc7ccc6c5c4c3)ccc2-c2cc3ccccc3cc21 ; CC1(C)c2cc(-c3ccc4c(ccc5oc6c7ccccc7ccc6c54)c3)ccc2-c2cc3ccccc3cc21 ; CC1(C)c2cc(-c3cccc4c3ccc3oc5c6ccccc6ccc5c34)ccc2-c2cc3ccccc3cc21]

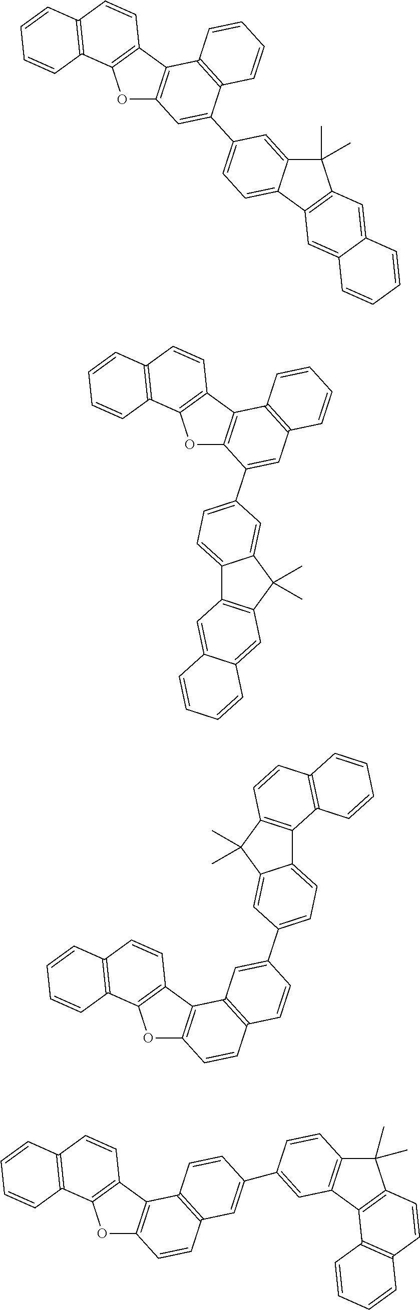 [SMILES: CC1(C)c2cc(-c3cc4oc5c6ccccc6ccc5c4c4ccccc34)ccc2-c2cc3ccccc3cc21 ; CC1(C)c2cc(-c3cc4ccccc4c4c3oc3c5ccccc5ccc34)ccc2-c2cc3ccccc3cc21 ; CC1(C)c2cc(-c3ccc4ccc5oc6c7ccccc7ccc6c5c4c3)ccc2-c2c1ccc1ccccc21 ; CC1(C)c2ccc(-c3ccc4c(ccc5oc6c7ccccc7ccc6c54)c3)cc2-c2c1ccc1ccccc21]

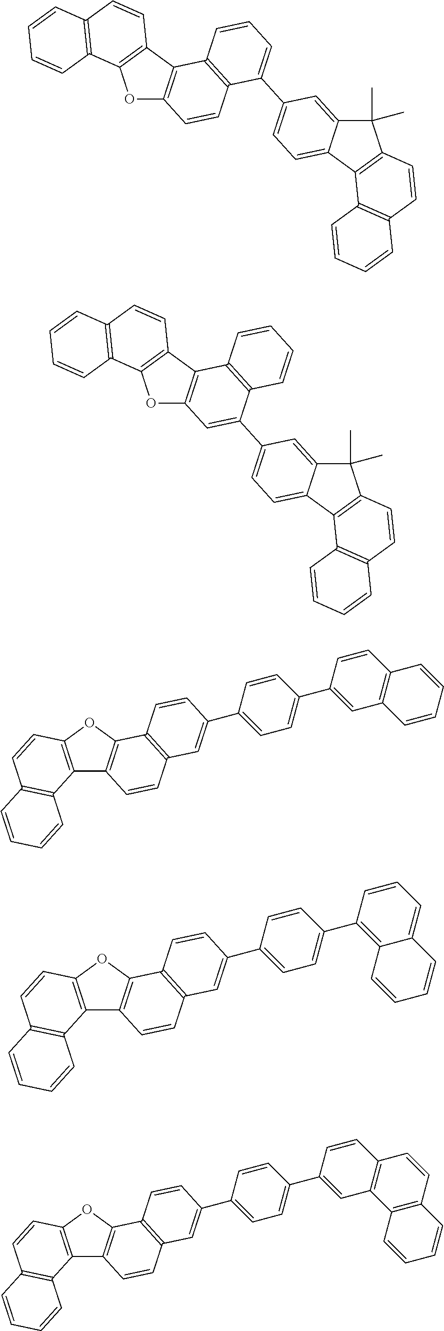

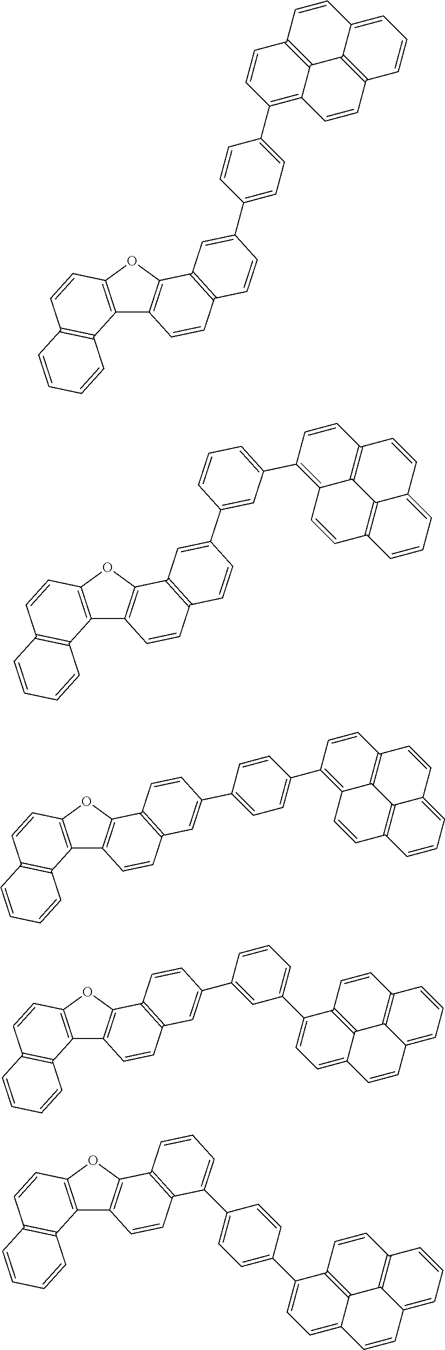 [SMILES: c1ccc2c(c1)ccc1oc3c4cc(-c5ccc(-c6ccc7ccc8cccc9ccc6c7c89)cc5)ccc4ccc3c12 ; c1cc(-c2ccc3ccc4c(oc5ccc6ccccc6c54)c3c2)cc(-c2ccc3ccc4cccc5ccc2c3c45)c1 ; c1ccc2c(c1)ccc1oc3c4ccc(-c5ccc(-c6ccc7ccc8cccc9ccc6c7c89)cc5)cc4ccc3c12 ; c1cc(-c2ccc3c(ccc4c3oc3ccc5ccccc5c34)c2)cc(-c2ccc3ccc4cccc5ccc2c3c45)c1 ; c1ccc2c(c1)ccc1oc3c4cccc(-c5ccc(-c6ccc7ccc8cccc9ccc6c7c89)cc5)c4ccc3c12]

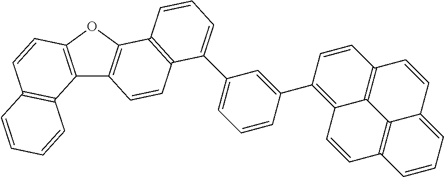 [SMILES: c1cc(-c2cccc3c2ccc2c3oc3ccc4ccccc4c32)cc(-c2ccc3ccc4cccc5ccc2c3c45)c1]

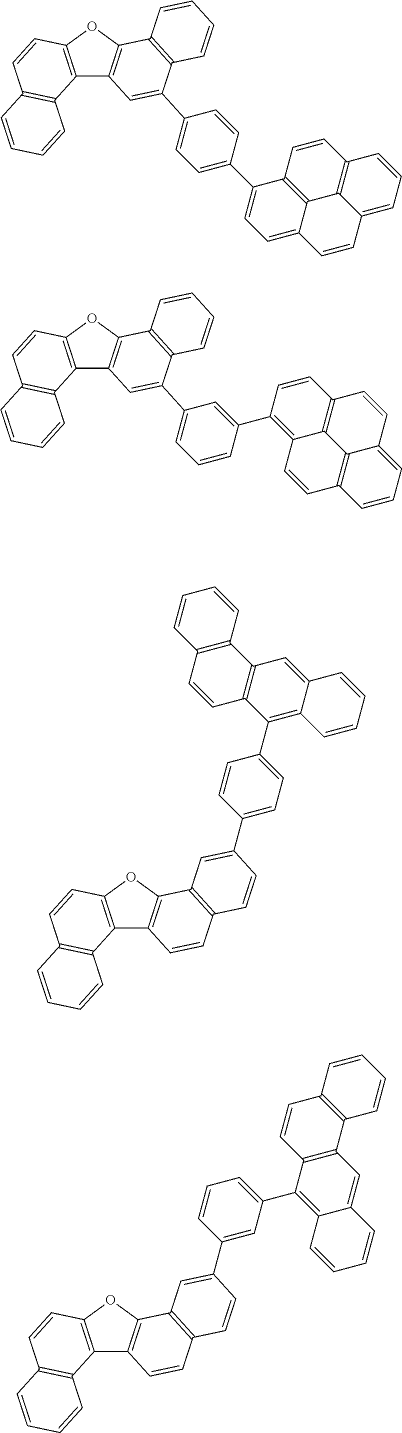 [SMILES: c1ccc2c(c1)ccc1oc3c4ccccc4c(-c4ccc(-c5ccc6ccc7cccc8ccc5c6c78)cc4)cc3c12 ; c1cc(-c2cc3c(oc4ccc5ccccc5c43)c3ccccc23)cc(-c2ccc3ccc4cccc5ccc2c3c45)c1 ; c1ccc2c(-c3ccc(-c4ccc5ccc6c(oc7ccc8ccccc8c76)c5c4)cc3)c3ccc4ccccc4c3cc2c1 ; c1cc(-c2ccc3ccc4c(oc5ccc6ccccc6c54)c3c2)cc(-c2c3ccccc3cc3c2ccc2ccccc23)c1]

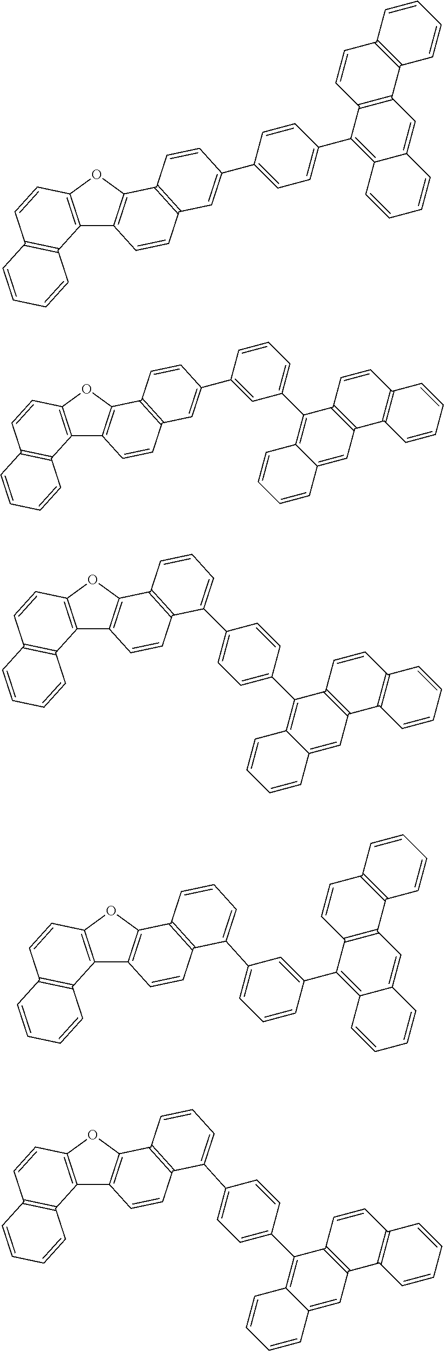 [SMILES: c1ccc2c(-c3ccc(-c4ccc5c(ccc6c5oc5ccc7ccccc7c56)c4)cc3)c3ccc4ccccc4c3cc2c1 ; c1cc(-c2ccc3c(ccc4c3oc3ccc5ccccc5c34)c2)cc(-c2c3ccccc3cc3c2ccc2ccccc23)c1 ; c1ccc2c(-c3ccc(-c4cccc5c4ccc4c5oc5ccc6ccccc6c54)cc3)c3ccc4ccccc4c3cc2c1 ; c1cc(-c2c3ccccc3cc3c2ccc2ccccc23)cc(-c2cccc3c2ccc2c3oc3ccc4ccccc4c32)c1 ; c1ccc2c(-c3ccc(-c4cccc5c4ccc4c5oc5ccc6ccccc6c54)cc3)c3ccc4ccccc4c3cc2c1]

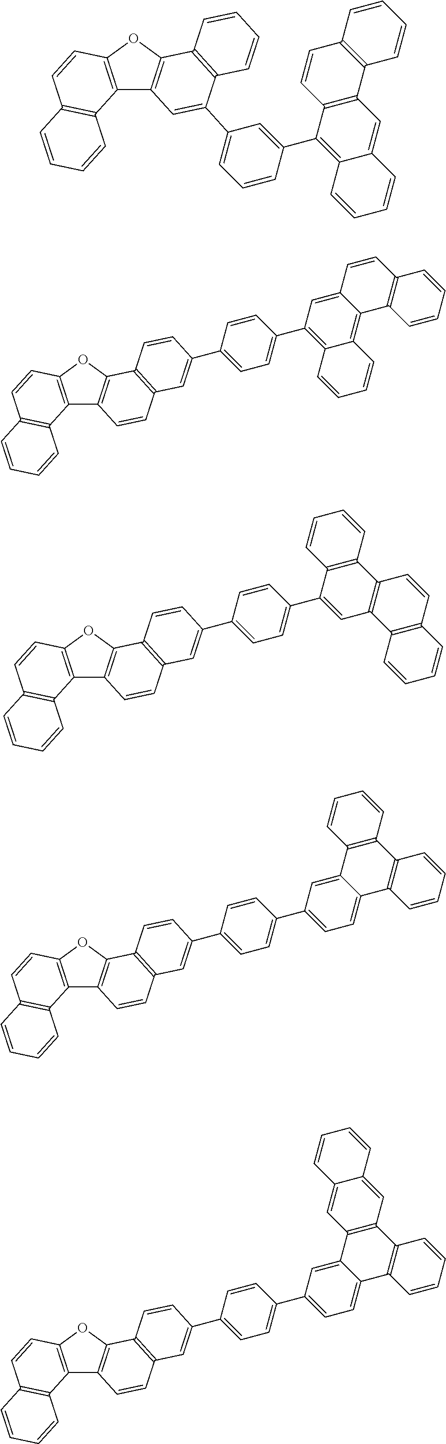 [SMILES: c1cc(-c2c3ccccc3cc3c2ccc2ccccc23)cc(-c2cc3c(oc4ccc5ccccc5c43)c3ccccc23)c1 ; c1ccc2c(c1)ccc1cc(-c3ccc(-c4ccc5c(ccc6c5oc5ccc7ccccc7c56)c4)cc3)c3ccccc3c12 ; c1ccc2c(c1)ccc1c3ccccc3c(-c3ccc(-c4ccc5c(ccc6c5oc5ccc7ccccc7c56)c4)cc3)cc21 ; c1ccc2c(c1)ccc1oc3c4ccc(-c5ccc(-c6ccc7c8ccccc8c8ccccc8c7c6)cc5)cc4ccc3c12 ; c1ccc2cc3c4cc(-c5ccc(-c6ccc7c(ccc8c7oc7ccc9ccccc9c78)c6)cc5)ccc4c4ccccc4c3cc2c1]

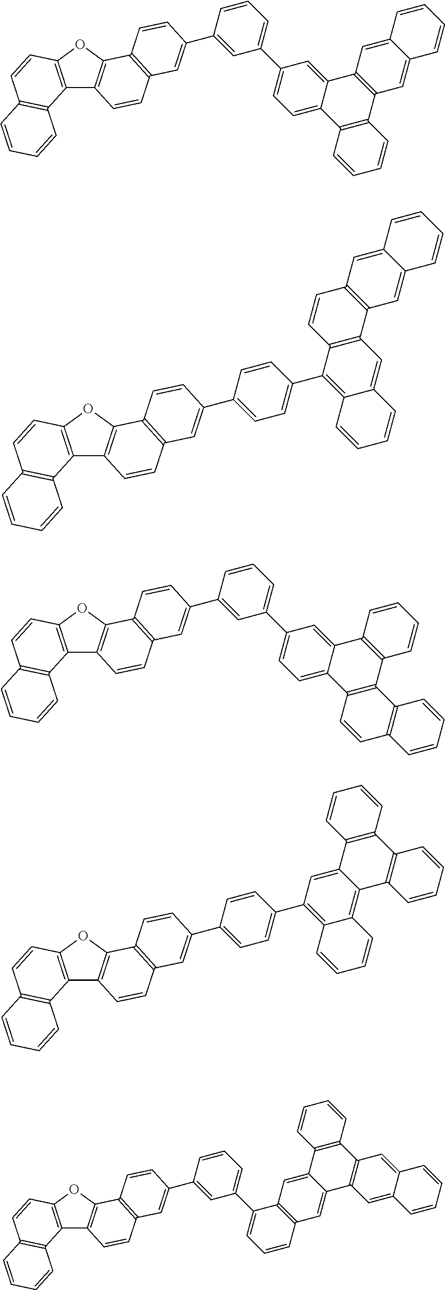 [SMILES: c1cc(-c2ccc3c(ccc4c3oc3ccc5ccccc5c34)c2)cc(-c2ccc3c4ccccc4c4cc5ccccc5cc4c3c2)c1 ; c1ccc2cc3c(ccc4c(-c5ccc(-c6ccc7c(ccc8c7oc7ccc9ccccc9c78)c6)cc5)c5ccccc5cc43)cc2c1 ; c1cc(-c2ccc3c(ccc4c3oc3ccc5ccccc5c34)c2)cc(-c2ccc3c(c2)c2ccccc2c2c4ccccc4ccc32)c1 ; c1ccc2c(c1)ccc1oc3c4ccc(-c5ccc(-c6cc7c8ccccc8c8ccccc8c7c7ccccc67)cc5)cc4ccc3c12 ; c1cc(-c2ccc3c(ccc4c3oc3ccc5ccccc5c34)c2)cc(-c2cccc3cc4c5cc6ccccc6cc5c5ccccc5c4cc23)c1]

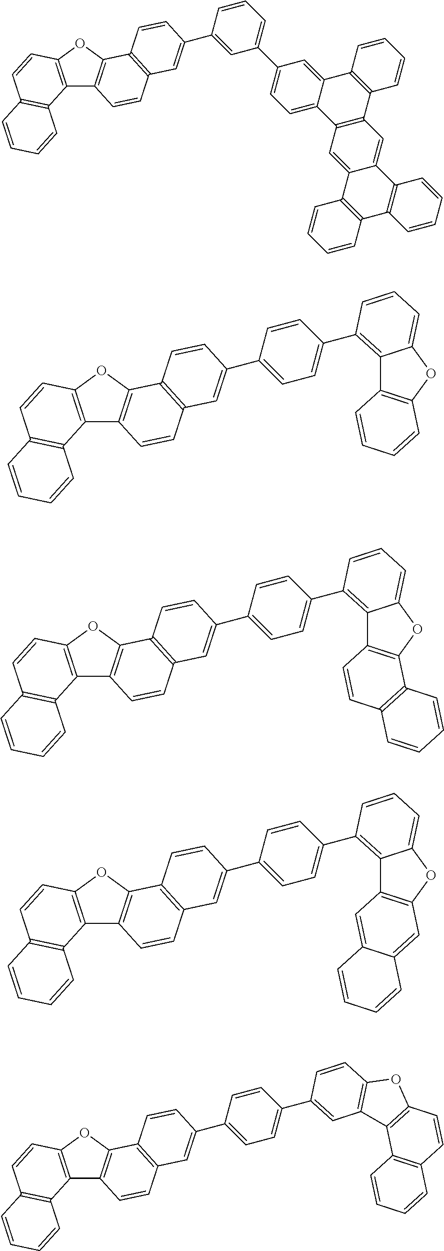 [SMILES: c1cc(-c2ccc3c(ccc4c3oc3ccc5ccccc5c34)c2)cc(-c2ccc3c(c2)c2ccccc2c2cc4c5ccccc5c5ccccc5c4cc32)c1 ; c1ccc2c(c1)ccc1oc3c4ccc(-c5ccc(-c6cccc7oc8ccccc8c67)cc5)cc4ccc3c12 ; c1ccc2c(c1)ccc1c2oc2cccc(-c3ccc(-c4ccc5c(ccc6c5oc5ccc7ccccc7c56)c4)cc3)c21 ; c1ccc2cc3c(cc2c1)oc1cccc(-c2ccc(-c4ccc5c(ccc6c5oc5ccc7ccccc7c56)c4)cc2)c13 ; c1ccc2c(c1)ccc1oc3ccc(-c4ccc(-c5ccc6c(ccc7c6oc6ccc8ccccc8c67)c5)cc4)cc3c12]

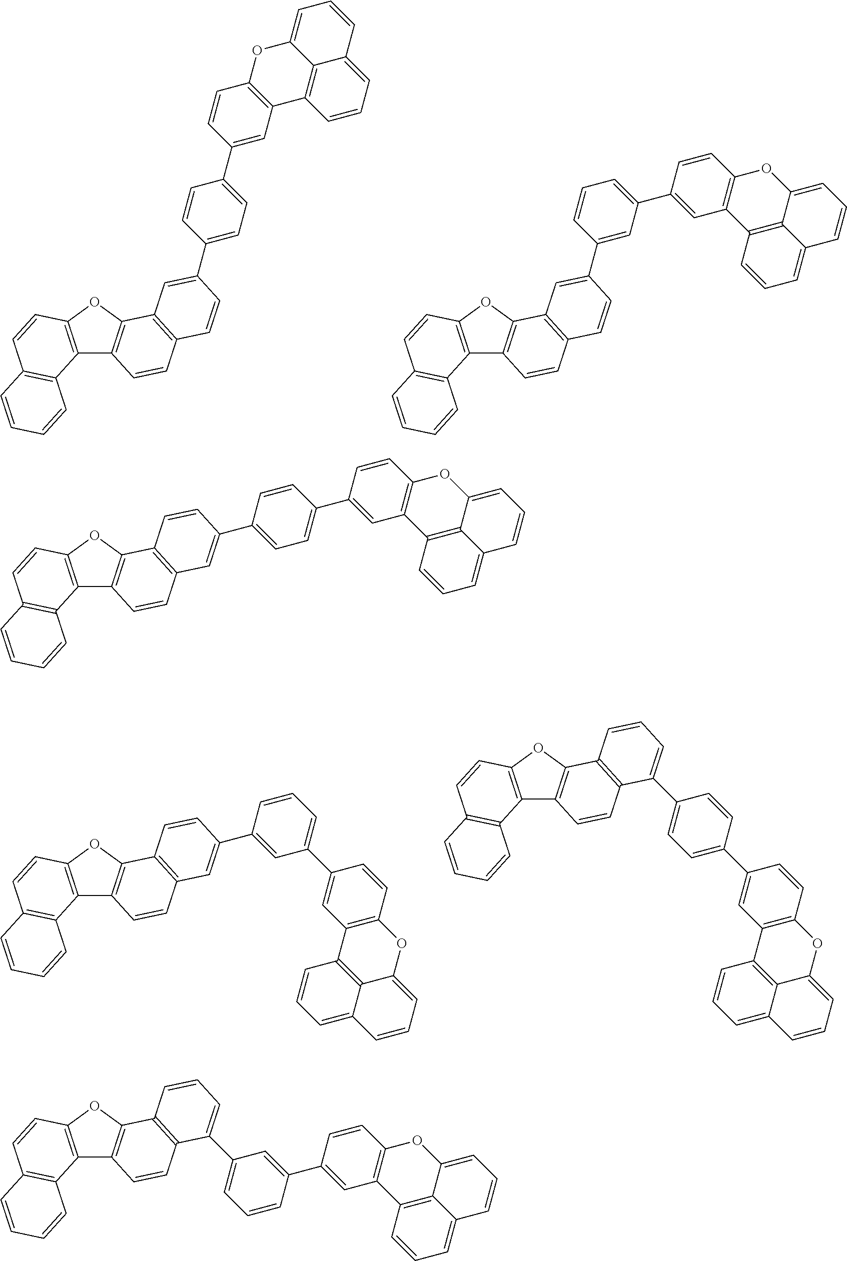

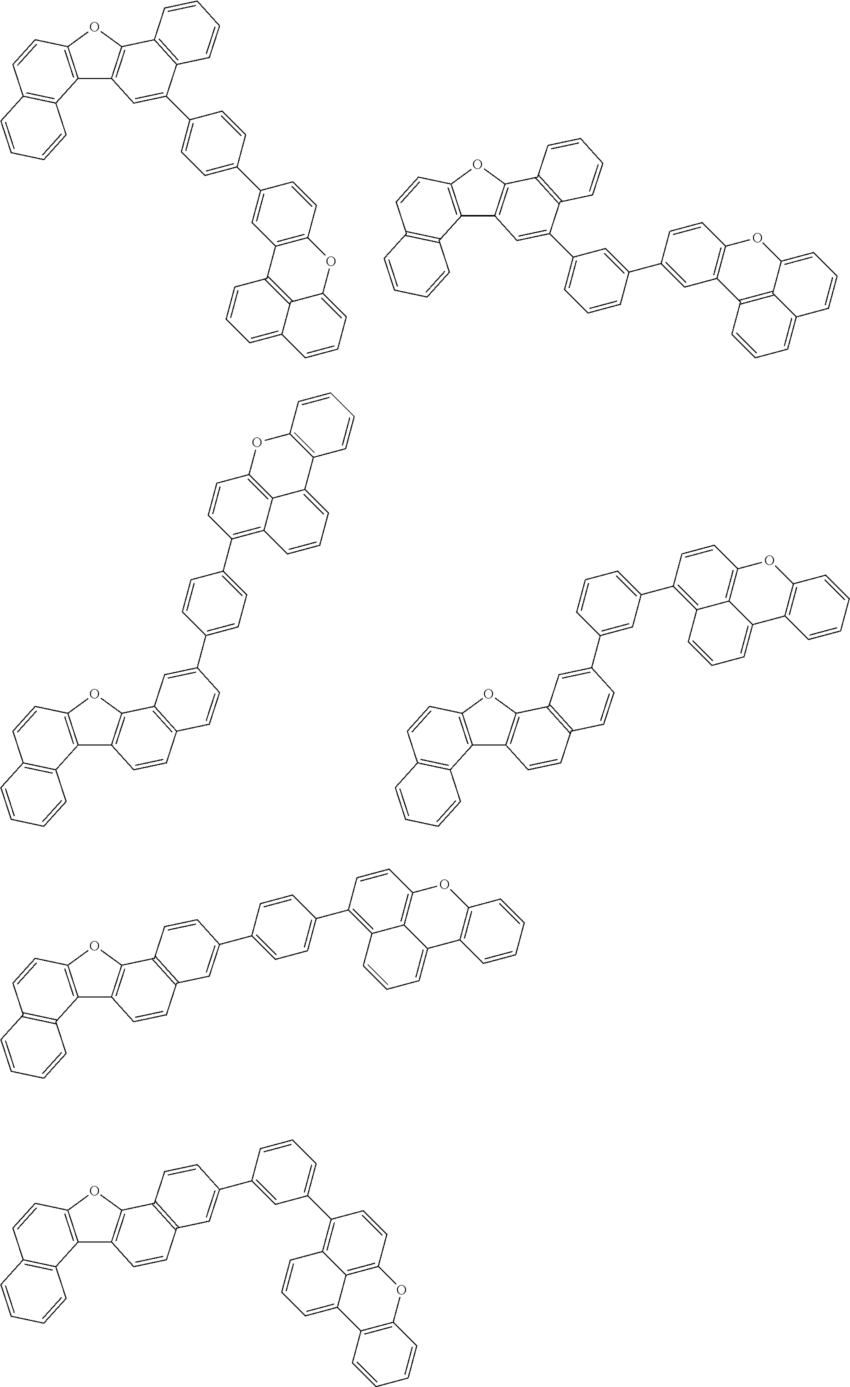

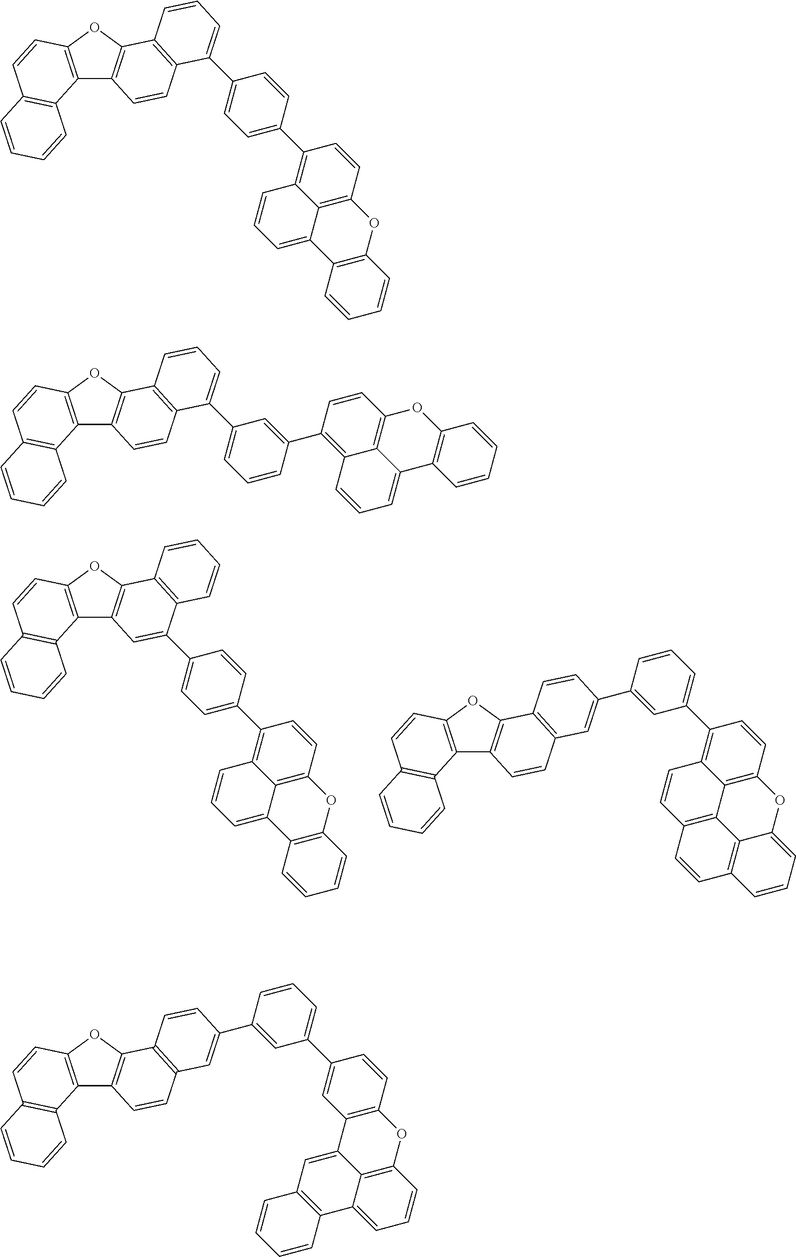 [SMILES: c1ccc2c(c1)Oc1ccc(-c3ccc(-c4cccc5c4ccc4c5oc5ccc6ccccc6c54)cc3)c3cccc-2c13 ; c1cc(-c2ccc3c4c(cccc24)-c2ccccc2O3)cc(-c2cccc3c2ccc2c3oc3ccc4ccccc4c32)c1 ; c1ccc2c(c1)Oc1ccc(-c3ccc(-c4cc5c(oc6ccc7ccccc7c65)c5ccccc45)cc3)c3cccc-2c13 ; c1cc(-c2ccc3c(ccc4c3oc3ccc5ccccc5c34)c2)cc(-c2ccc3c4c2ccc2ccc5cccc(c5c24)O3)c1 ; c1cc(-c2ccc3c(c2)-c2cc4ccccc4c4cccc(c24)O3)cc(-c2ccc3c(ccc4c3oc3ccc5ccccc5c34)c2)c1]

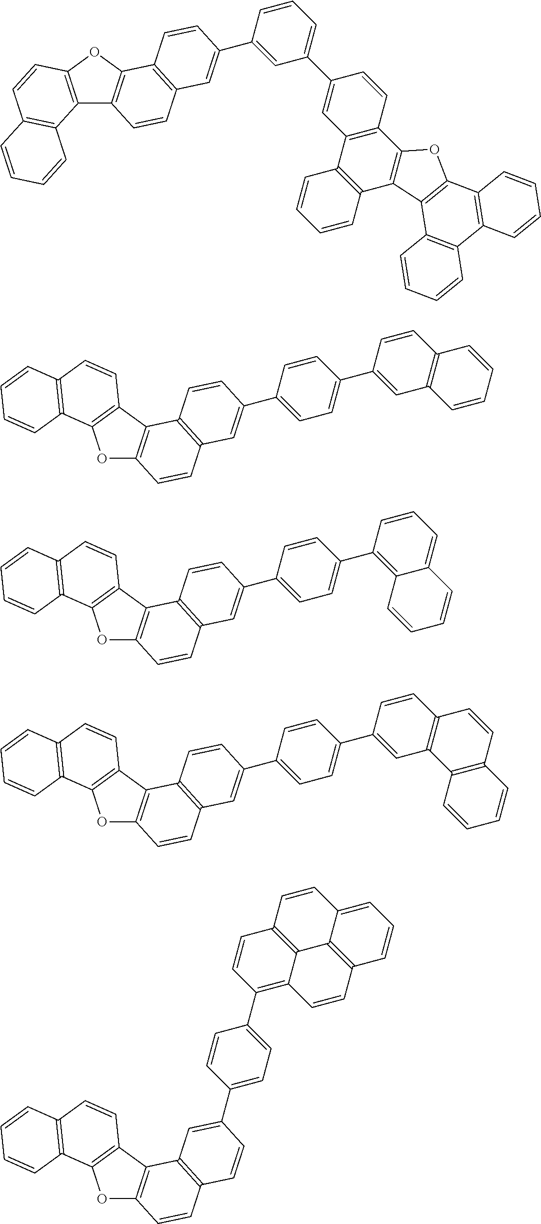

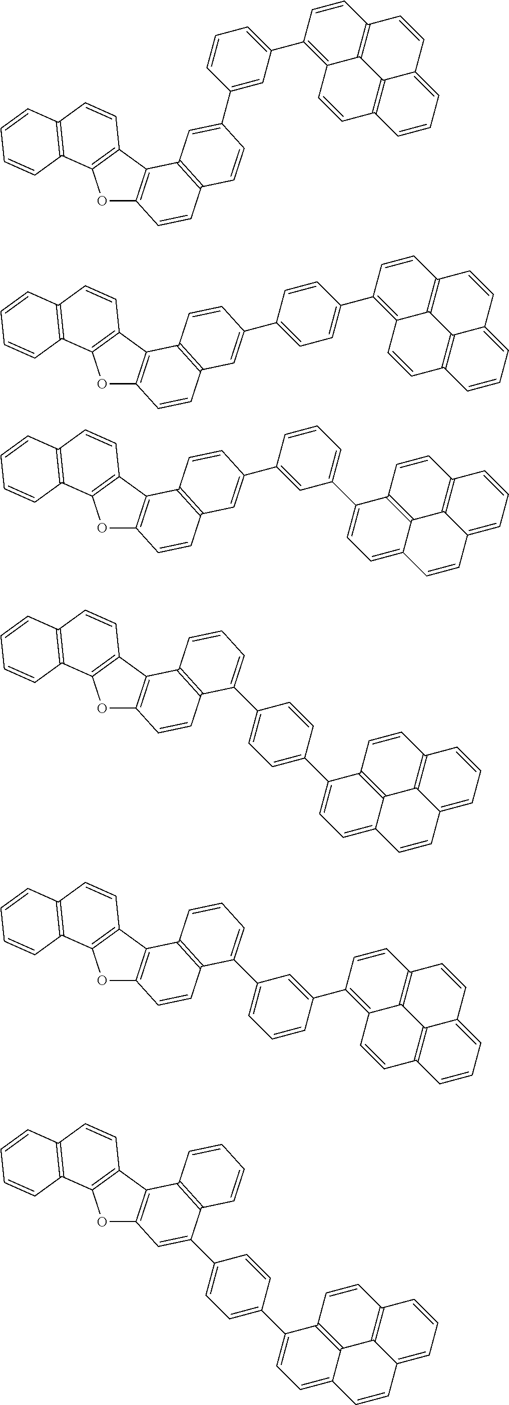 [SMILES: c1cc(-c2ccc3ccc4oc5c6ccccc6ccc5c4c3c2)cc(-c2ccc3ccc4cccc5ccc2c3c45)c1 ; c1ccc2c(c1)ccc1c2oc2ccc3cc(-c4ccc(-c5ccc6ccc7cccc8ccc5c6c78)cc4)ccc3c21 ; c1cc(-c2ccc3c(ccc4oc5c6ccccc6ccc5c43)c2)cc(-c2ccc3ccc4cccc5ccc2c3c45)c1 ; c1ccc2c(c1)ccc1c2oc2ccc3c(-c4ccc(-c5ccc6ccc7cccc8ccc5c6c78)cc4)cccc3c21 ; c1cc(-c2cccc3c2ccc2oc4c5ccccc5ccc4c23)cc(-c2ccc3ccc4cccc5ccc2c3c45)c1 ; c1ccc2c(c1)ccc1c2oc2cc(-c3ccc(-c4ccc5ccc6cccc7ccc4c5c67)cc3)c3ccccc3c21]

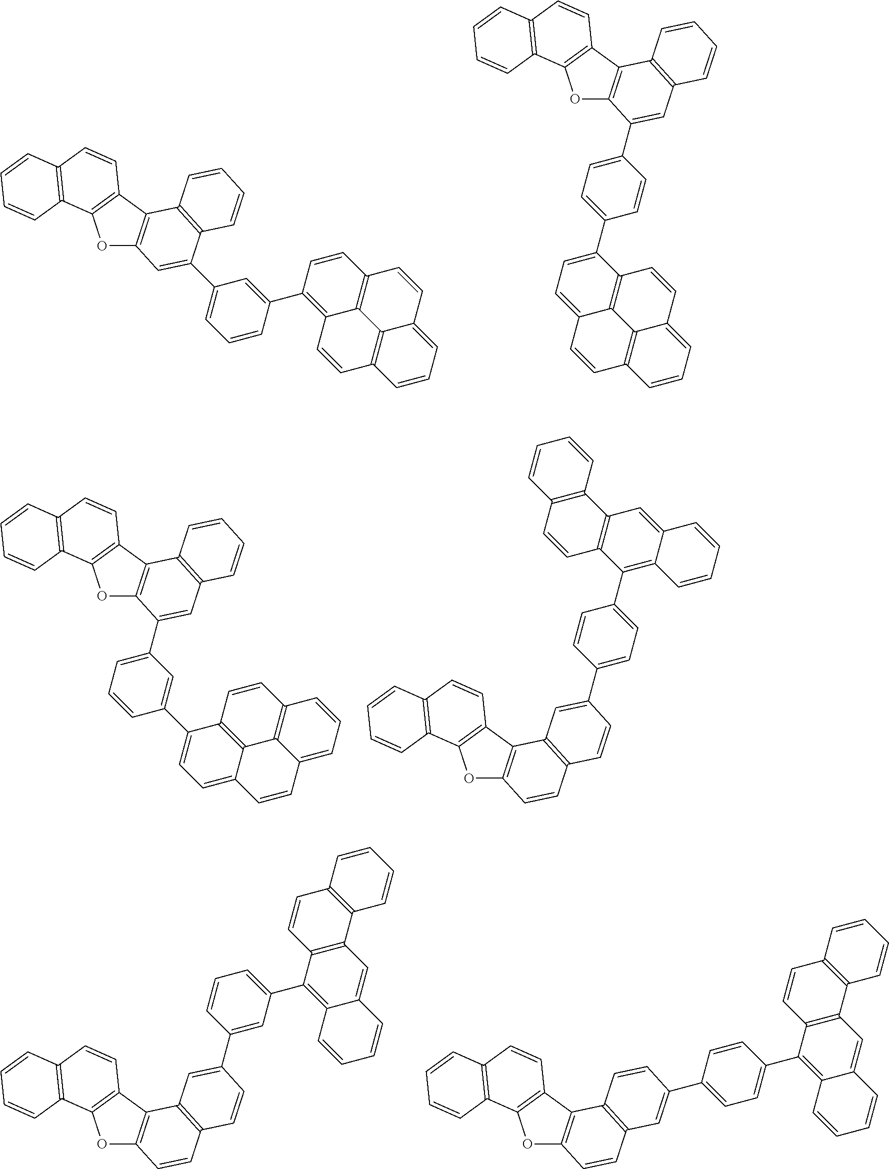

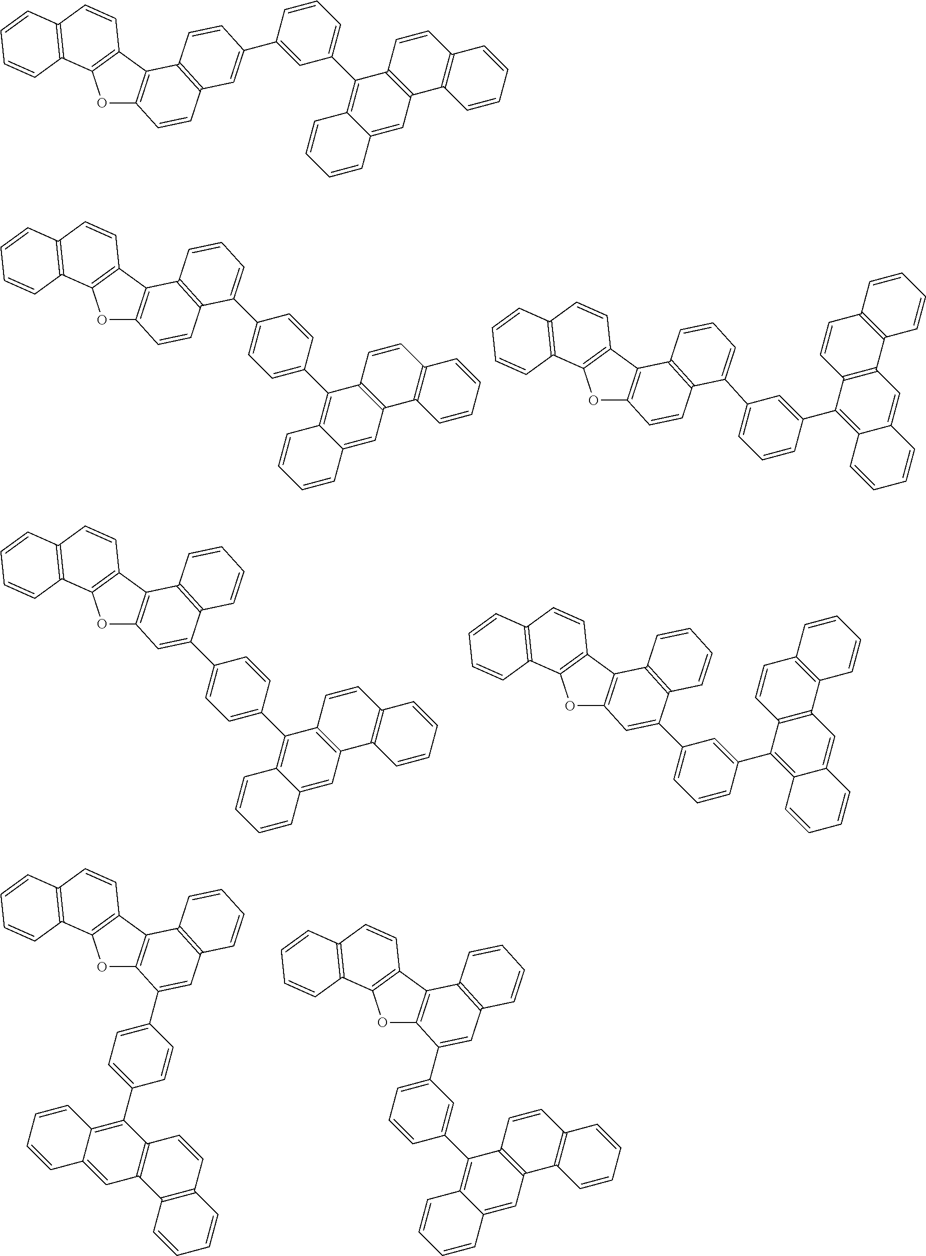

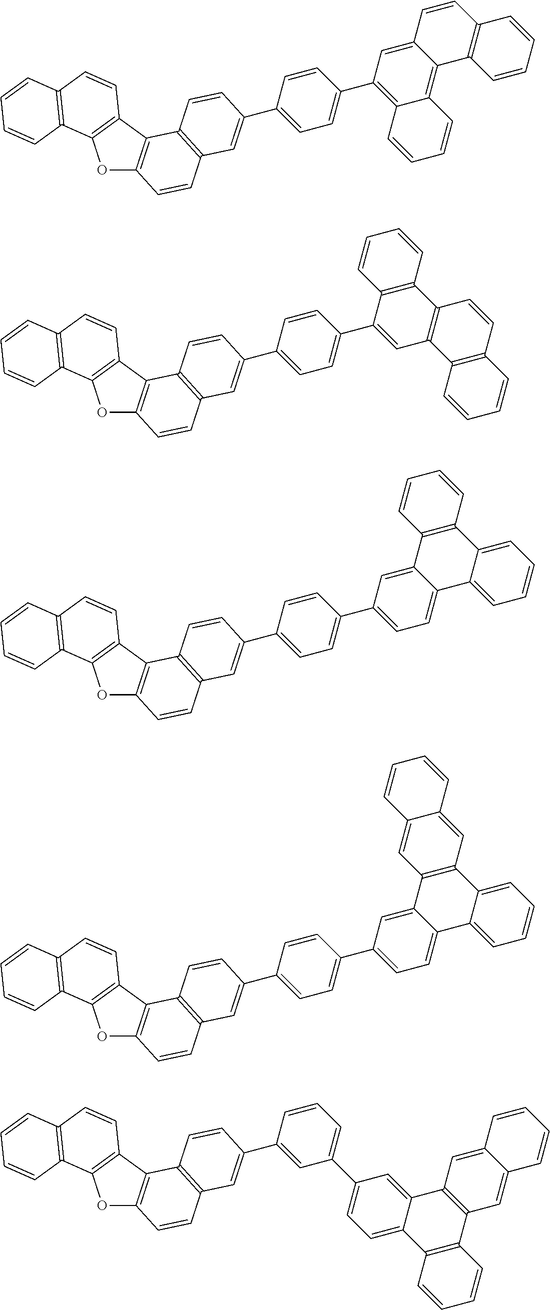 [SMILES: c1ccc2c(c1)ccc1c2oc2ccc3cc(-c4ccc(-c5cc6ccc7ccccc7c6c6ccccc56)cc4)ccc3c21 ; c1ccc2c(c1)ccc1c3ccccc3c(-c3ccc(-c4ccc5c(ccc6oc7c8ccccc8ccc7c65)c4)cc3)cc21 ; c1ccc2c(c1)ccc1c2oc2ccc3cc(-c4ccc(-c5ccc6c7ccccc7c7ccccc7c6c5)cc4)ccc3c21 ; c1ccc2cc3c4cc(-c5ccc(-c6ccc7c(ccc8oc9c%10ccccc%10ccc9c87)c6)cc5)ccc4c4ccccc4c3cc2c1 ; c1cc(-c2ccc3c(ccc4oc5c6ccccc6ccc5c43)c2)cc(-c2ccc3c4ccccc4c4cc5ccccc5cc4c3c2)c1]

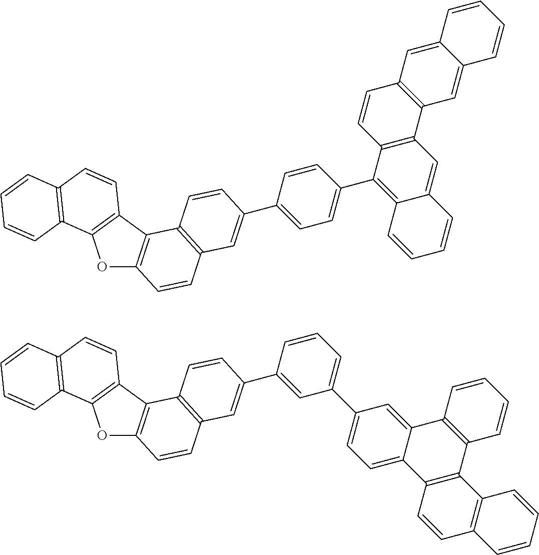 [SMILES: c1ccc2cc3c(ccc4c(-c5ccc(-c6ccc7c(ccc8oc9c%10ccccc%10ccc9c87)c6)cc5)c5ccccc5cc43)cc2c1 ; c1cc(-c2ccc3c(ccc4oc5c6ccccc6ccc5c43)c2)cc(-c2ccc3c(c2)c2ccccc2c2c4ccccc4ccc32)c1]

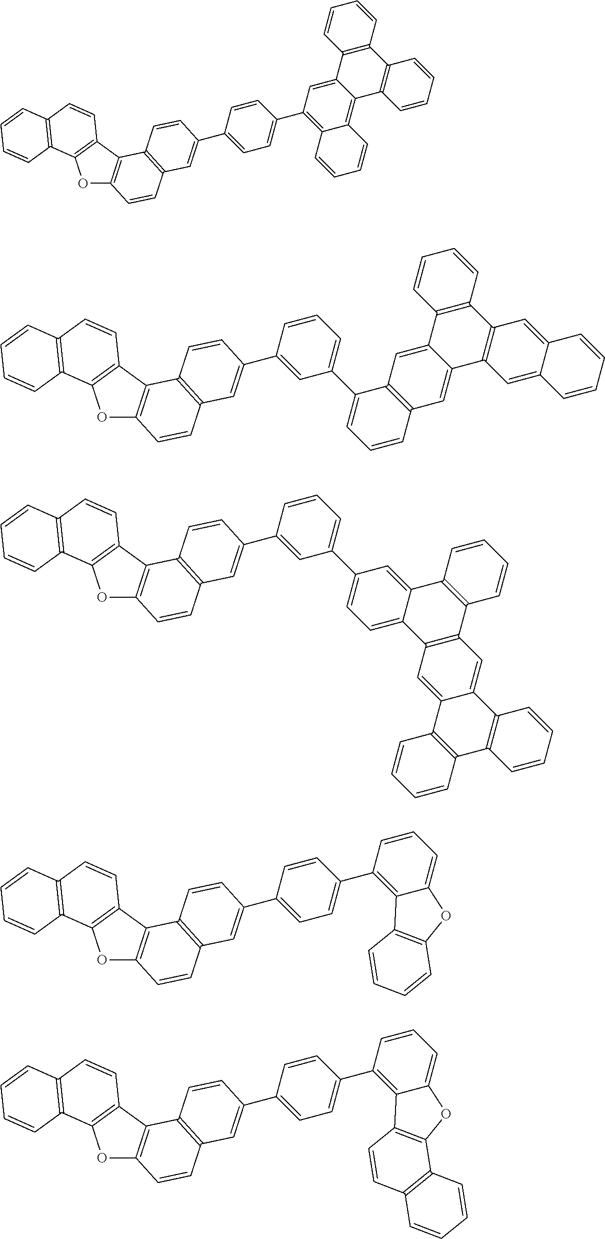

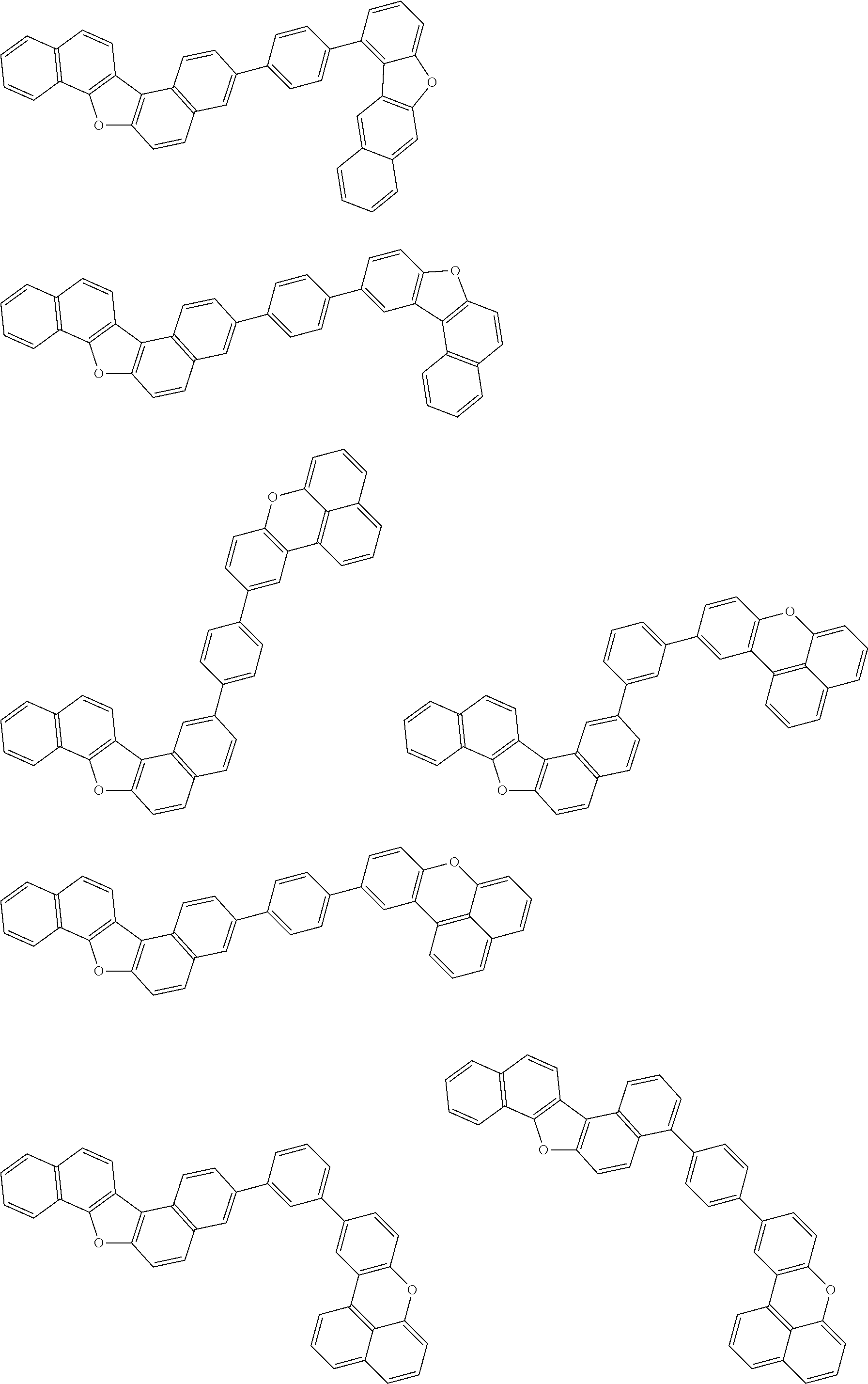

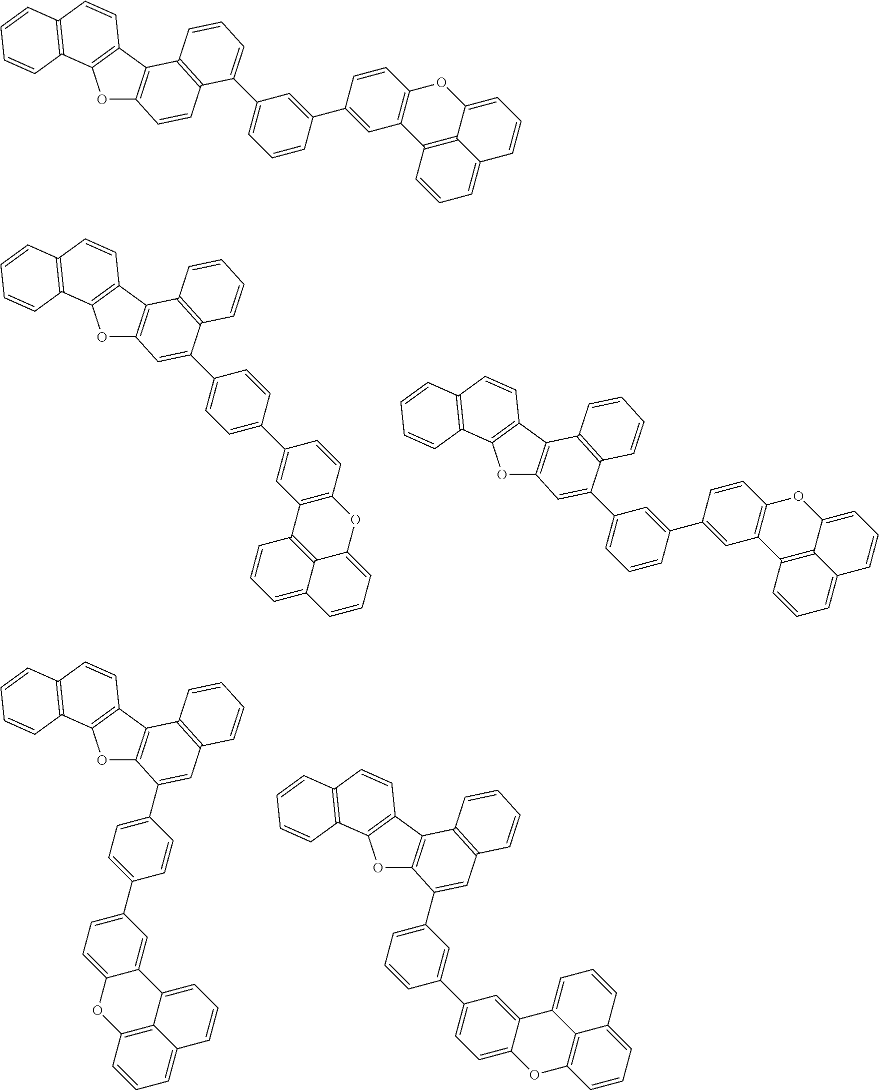 [SMILES: c1cc(-c2ccc3c(c2)-c2cccc4cccc(c24)O3)cc(-c2cccc3c2ccc2oc4c5ccccc5ccc4c23)c1 ; c1cc2c3c(cccc3c1)-c1cc(-c3ccc(-c4cc5oc6c7ccccc7ccc6c5c5ccccc45)cc3)ccc1O2 ; c1cc(-c2ccc3c(c2)-c2cccc4cccc(c24)O3)cc(-c2cc3oc4c5ccccc5ccc4c3c3ccccc23)c1 ; c1cc2c3c(cccc3c1)-c1cc(-c3ccc(-c4cc5ccccc5c5c4oc4c6ccccc6ccc45)cc3)ccc1O2 ; c1cc(-c2ccc3c(c2)-c2cccc4cccc(c24)O3)cc(-c2cc3ccccc3c3c2oc2c4ccccc4ccc23)c1]

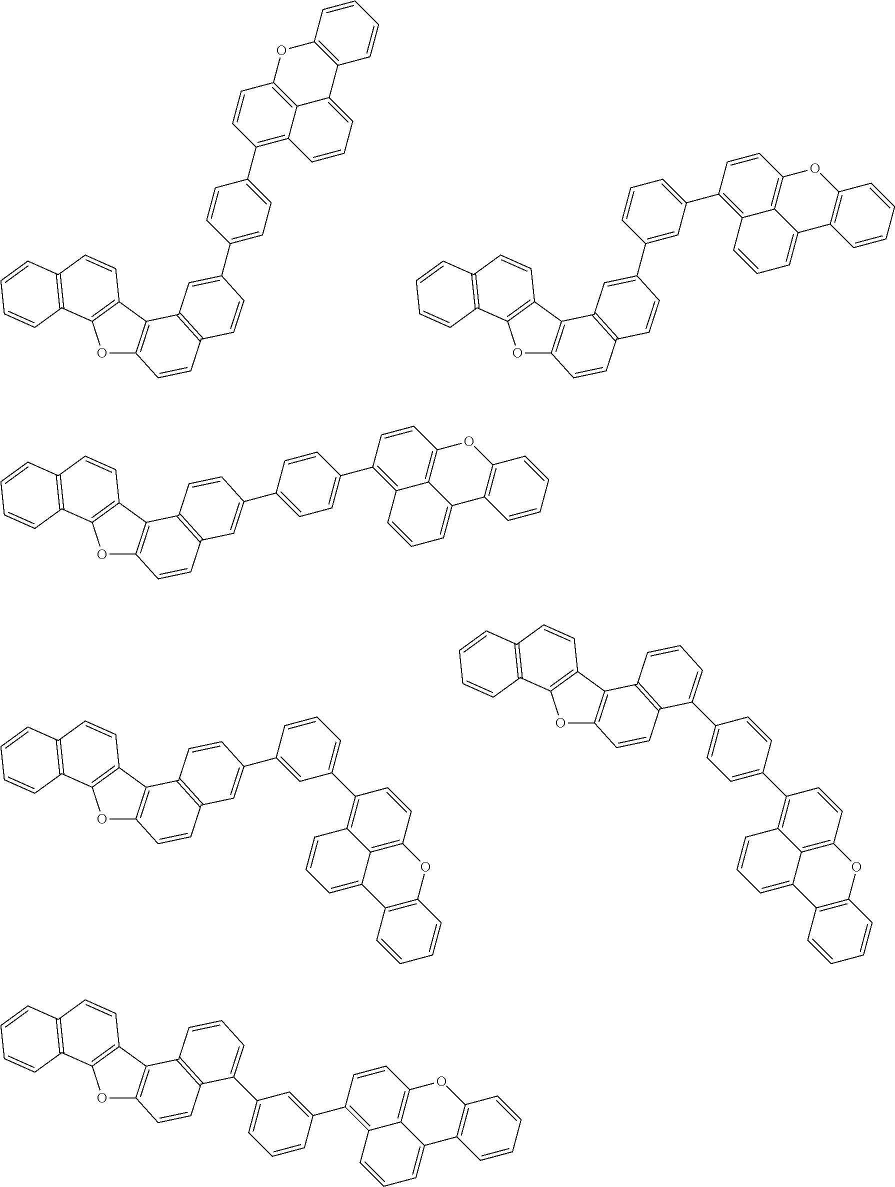 [SMILES: c1ccc2c(c1)Oc1ccc(-c3ccc(-c4ccc5ccc6oc7c8ccccc8ccc7c6c5c4)cc3)c3cccc-2c13 ; c1cc(-c2ccc3ccc4oc5c6ccccc6ccc5c4c3c2)cc(-c2ccc3c4c(cccc24)-c2ccccc2O3)c1 ; c1ccc2c(c1)Oc1ccc(-c3ccc(-c4ccc5c(ccc6oc7c8ccccc8ccc7c65)c4)cc3)c3cccc-2c13 ; c1cc(-c2ccc3c(ccc4oc5c6ccccc6ccc5c43)c2)cc(-c2ccc3c4c(cccc24)-c2ccccc2O3)c1 ; c1ccc2c(c1)Oc1ccc(-c3ccc(-c4cccc5c4ccc4oc6c7ccccc7ccc6c45)cc3)c3cccc-2c13 ; c1cc(-c2ccc3c4c(cccc24)-c2ccccc2O3)cc(-c2cccc3c2ccc2oc4c5ccccc5ccc4c23)c1]

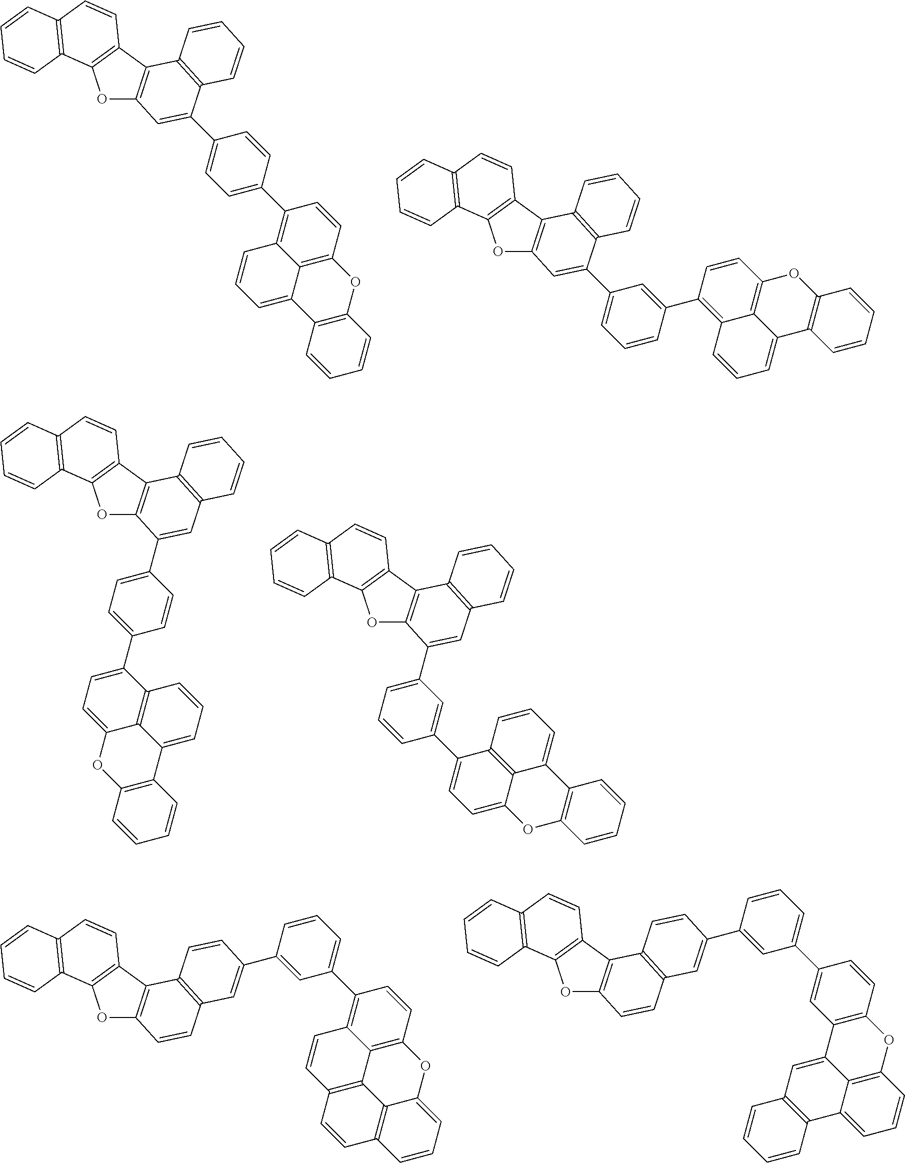 [SMILES: c1ccc2c(c1)Oc1ccc(-c3ccc(-c4cc5oc6c7ccccc7ccc6c5c5ccccc45)cc3)c3cccc-2c13 ; c1cc(-c2ccc3c4c(cccc24)-c2ccccc2O3)cc(-c2cc3oc4c5ccccc5ccc4c3c3ccccc23)c1 ; c1ccc2c(c1)Oc1ccc(-c3ccc(-c4cc5ccccc5c5c4oc4c6ccccc6ccc45)cc3)c3cccc-2c13 ; c1cc(-c2ccc3c4c(cccc24)-c2ccccc2O3)cc(-c2cc3ccccc3c3c2oc2c4ccccc4ccc23)c1 ; c1cc(-c2ccc3c(ccc4oc5c6ccccc6ccc5c43)c2)cc(-c2ccc3c4c2ccc2ccc5cccc(c5c24)O3)c1 ; c1cc(-c2ccc3c(c2)-c2cc4ccccc4c4cccc(c24)O3)cc(-c2ccc3c(ccc4oc5c6ccccc6ccc5c43)c2)c1]

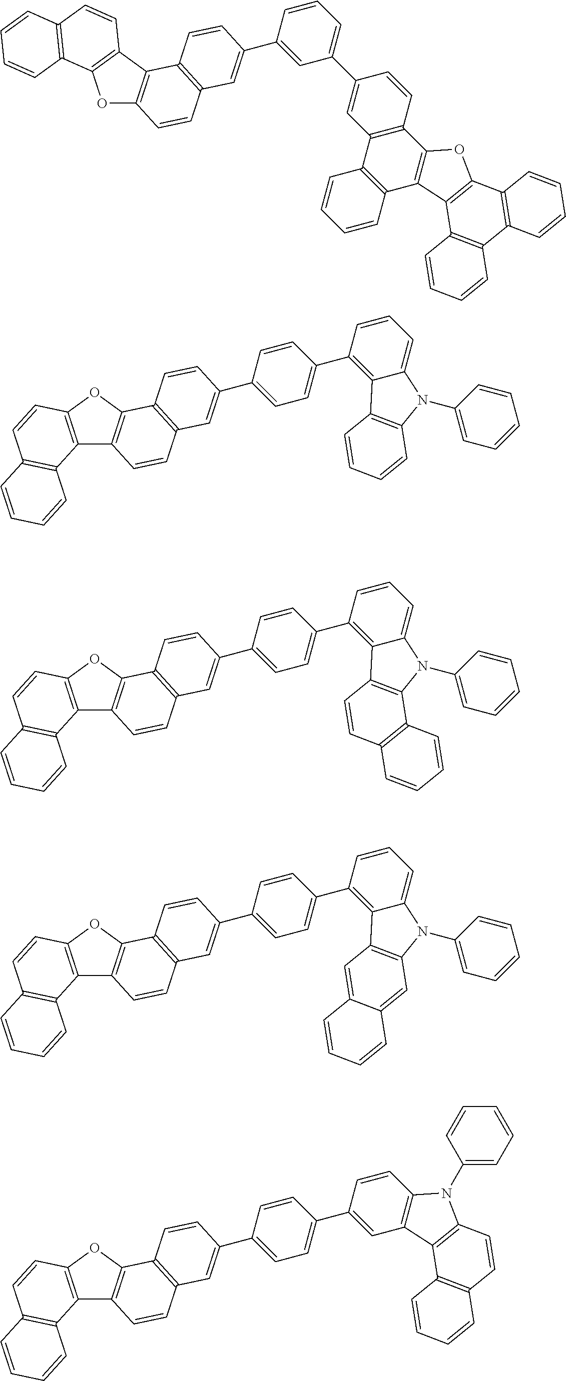 [SMILES: c1cc(-c2ccc3c(ccc4oc5c6ccccc6ccc5c43)c2)cc(-c2ccc3c(c2)c2ccccc2c2c3oc3c4ccccc4c4ccccc4c32)c1 ; c1ccc(-n2c3ccccc3c3c(-c4ccc(-c5ccc6c(ccc7c6oc6ccc8ccccc8c67)c5)cc4)cccc32)cc1 ; c1ccc(-n2c3cccc(-c4ccc(-c5ccc6c(ccc7c6oc6ccc8ccccc8c67)c5)cc4)c3c3ccc4ccccc4c32)cc1 ; c1ccc(-n2c3cc4ccccc4cc3c3c(-c4ccc(-c5ccc6c(ccc7c6oc6ccc8ccccc8c67)c5)cc4)cccc32)cc1 ; c1ccc(-n2c3ccc(-c4ccc(-c5ccc6c(ccc7c6oc6ccc8ccccc8c67)c5)cc4)cc3c3c4ccccc4ccc32)cc1]

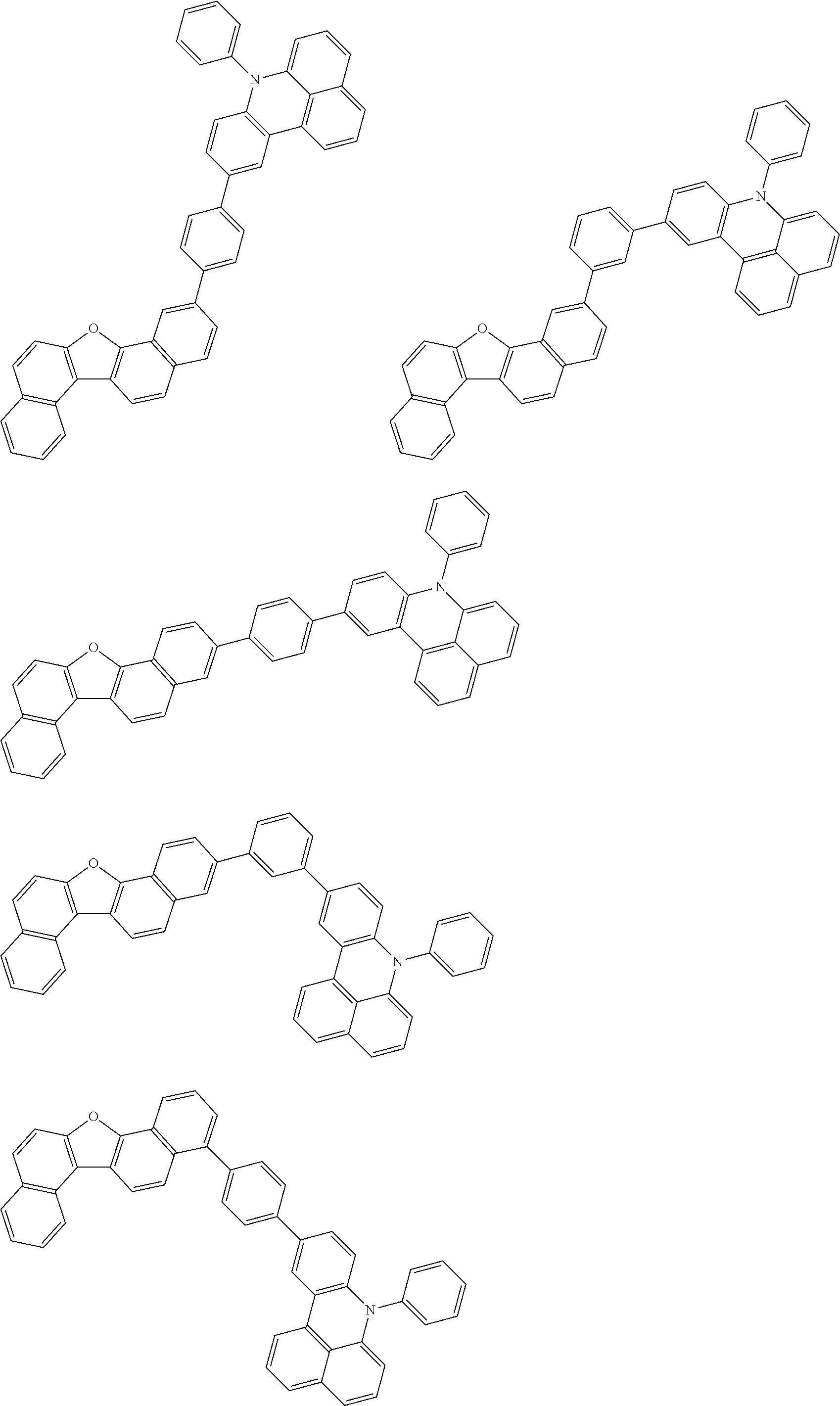

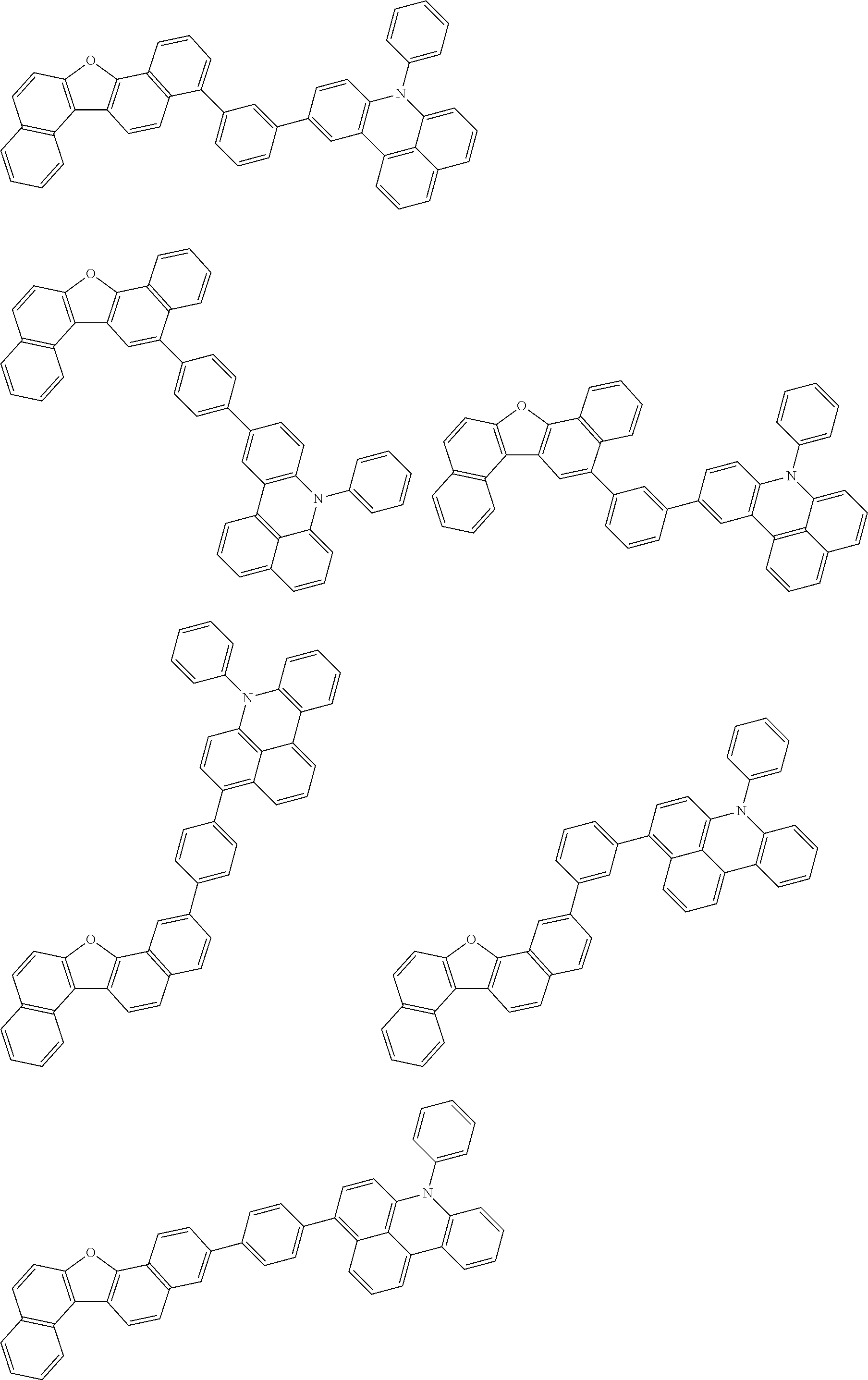

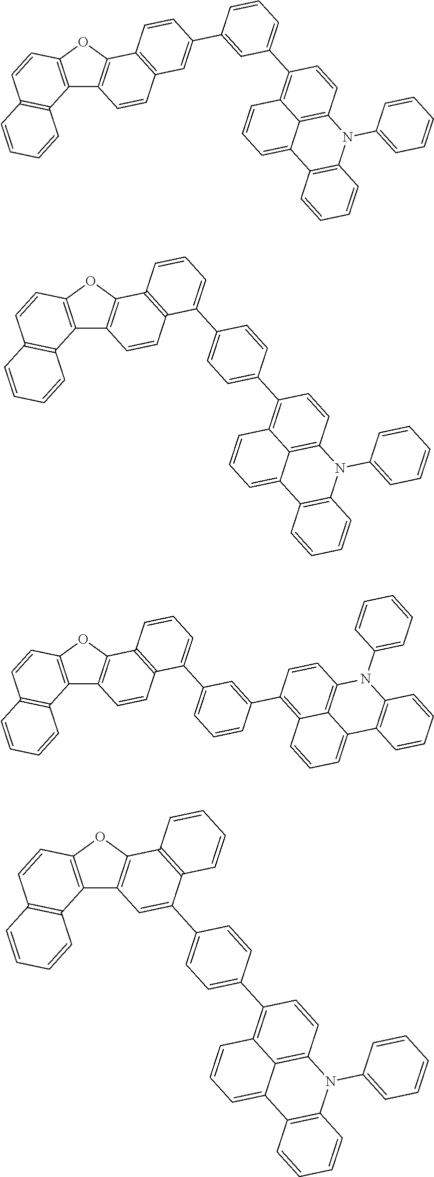 [SMILES: c1ccc(N2c3ccccc3-c3cccc4c(-c5cccc(-c6ccc7c(ccc8c7oc7ccc9ccccc9c78)c6)c5)ccc2c34)cc1 ; c1ccc(N2c3ccccc3-c3cccc4c(-c5ccc(-c6cccc7c6ccc6c7oc7ccc8ccccc8c76)cc5)ccc2c34)cc1 ; c1ccc(N2c3ccccc3-c3cccc4c(-c5cccc(-c6cccc7c6ccc6c7oc7ccc8ccccc8c76)c5)ccc2c34)cc1 ; c1ccc(N2c3ccccc3-c3cccc4c(-c5ccc(-c6cc7c(oc8ccc9ccccc9c87)c7ccccc67)cc5)ccc2c34)cc1]

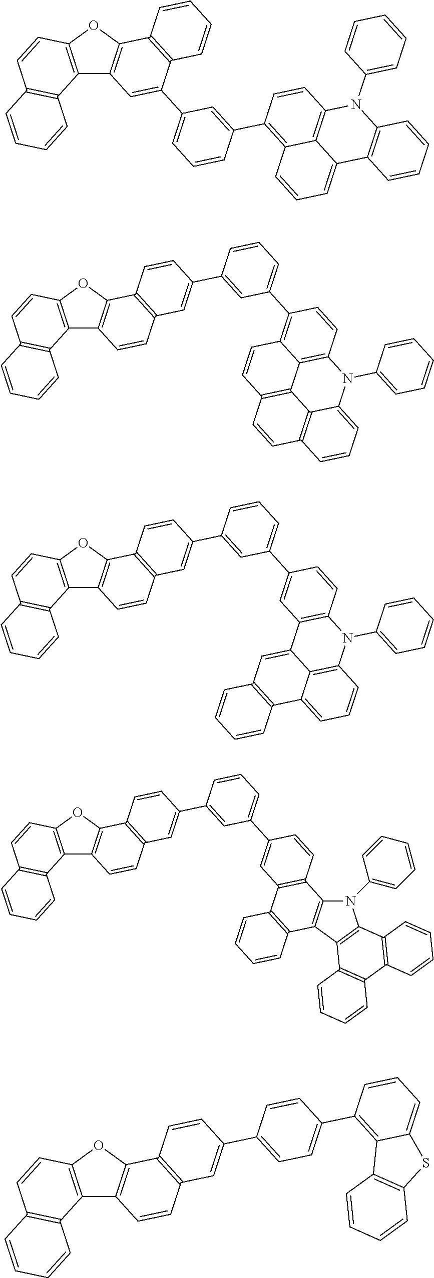

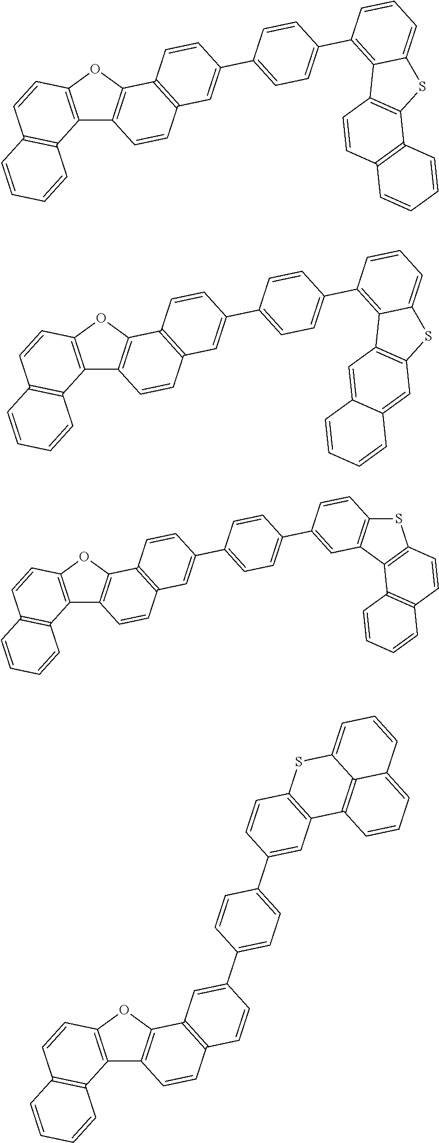

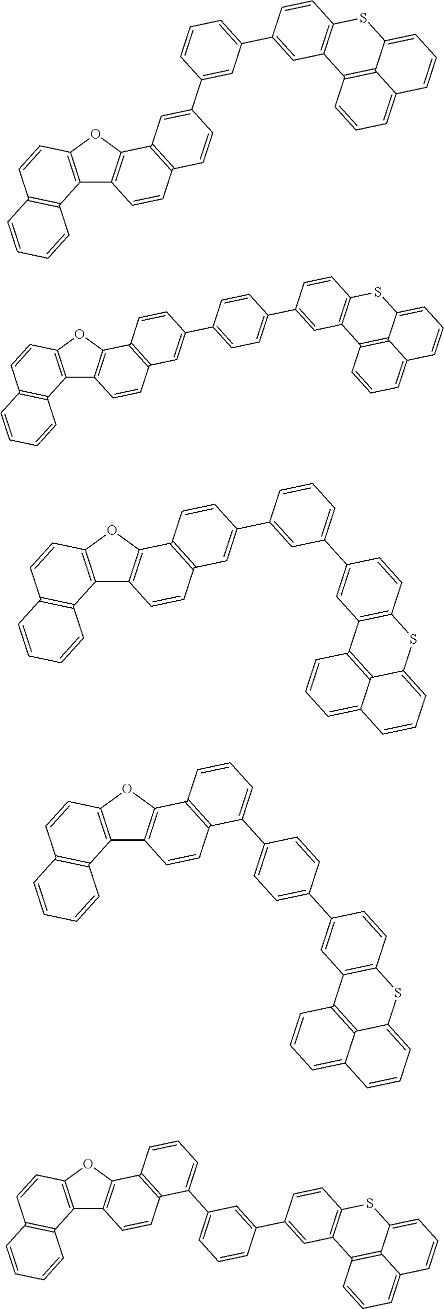 [SMILES: c1cc(-c2ccc3c(c2)-c2cccc4cccc(c24)S3)cc(-c2ccc3ccc4c(oc5ccc6ccccc6c54)c3c2)c1 ; c1cc2c3c(cccc3c1)-c1cc(-c3ccc(-c4ccc5c(ccc6c5oc5ccc7ccccc7c56)c4)cc3)ccc1S2 ; c1cc(-c2ccc3c(c2)-c2cccc4cccc(c24)S3)cc(-c2ccc3c(ccc4c3oc3ccc5ccccc5c34)c2)c1 ; c1cc2c3c(cccc3c1)-c1cc(-c3ccc(-c4cccc5c4ccc4c5oc5ccc6ccccc6c54)cc3)ccc1S2 ; c1cc(-c2ccc3c(c2)-c2cccc4cccc(c24)S3)cc(-c2cccc3c2ccc2c3oc3ccc4ccccc4c32)c1]

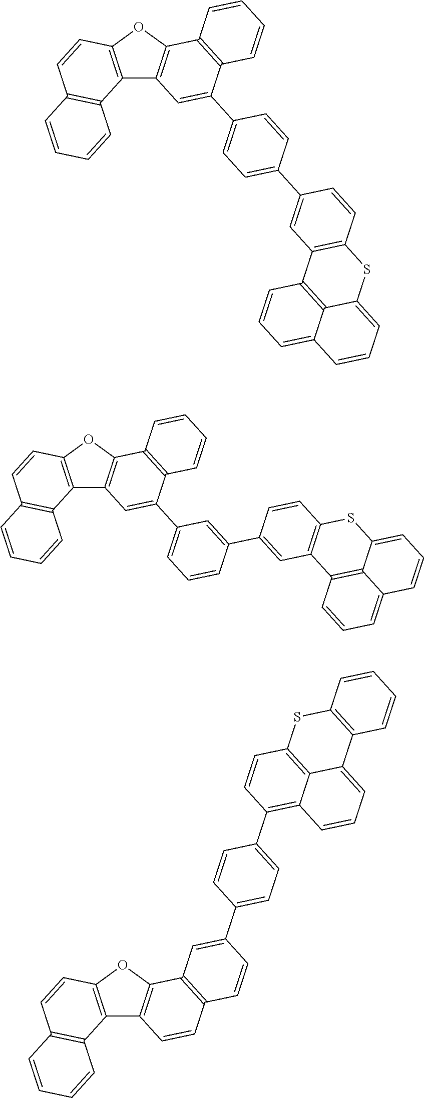 [SMILES: c1cc2c3c(cccc3c1)-c1cc(-c3ccc(-c4cc5c(oc6ccc7ccccc7c65)c5ccccc45)cc3)ccc1S2 ; c1cc(-c2ccc3c(c2)-c2cccc4cccc(c24)S3)cc(-c2cc3c(oc4ccc5ccccc5c43)c3ccccc23)c1 ; c1ccc2c(c1)Sc1ccc(-c3ccc(-c4ccc5ccc6c(oc7ccc8ccccc8c76)c5c4)cc3)c3cccc-2c13]

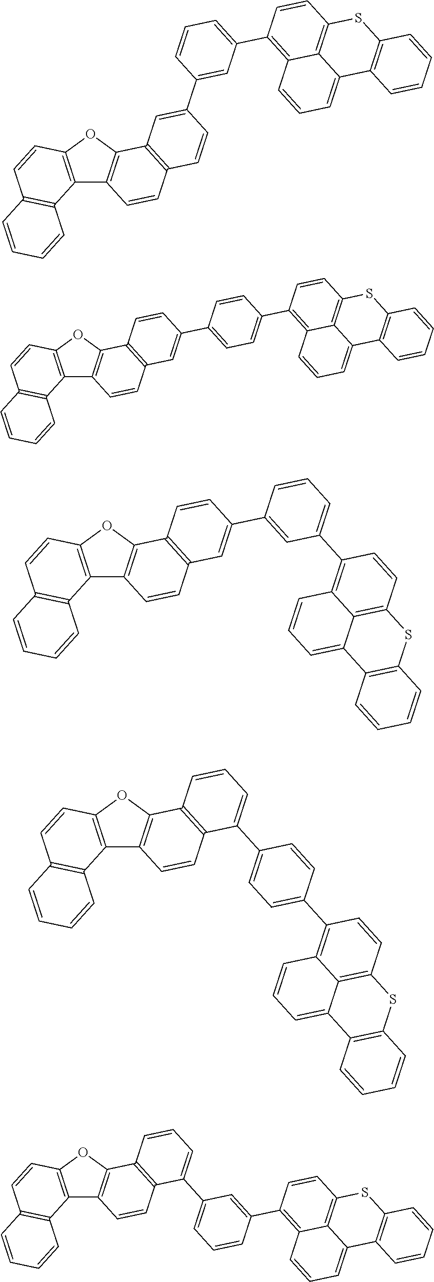 [SMILES: c1cc(-c2ccc3ccc4c(oc5ccc6ccccc6c54)c3c2)cc(-c2ccc3c4c(cccc24)-c2ccccc2S3)c1 ; c1ccc2c(c1)Sc1ccc(-c3ccc(-c4ccc5c(ccc6c5oc5ccc7ccccc7c56)c4)cc3)c3cccc-2c13 ; c1cc(-c2ccc3c(ccc4c3oc3ccc5ccccc5c34)c2)cc(-c2ccc3c4c(cccc24)-c2ccccc2S3)c1 ; c1ccc2c(c1)Sc1ccc(-c3ccc(-c4cccc5c4ccc4c5oc5ccc6ccccc6c54)cc3)c3cccc-2c13 ; c1cc(-c2ccc3c4c(cccc24)-c2ccccc2S3)cc(-c2cccc3c2ccc2c3oc3ccc4ccccc4c32)c1]

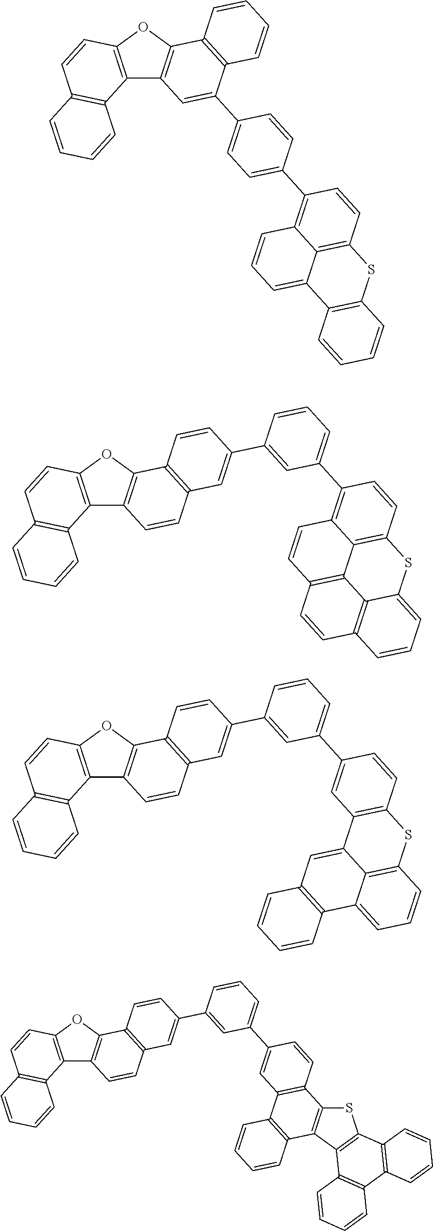

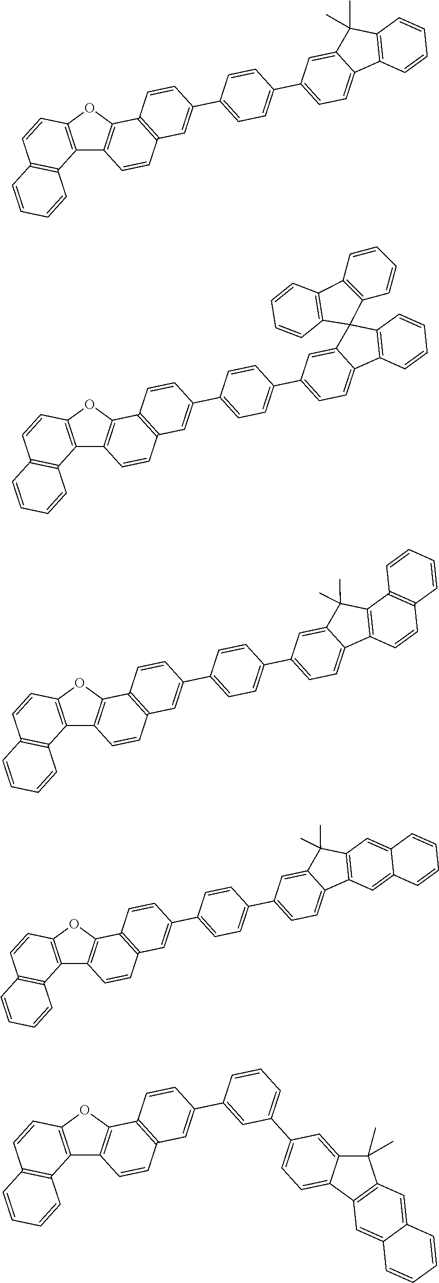 [SMILES: CC1(C)c2ccccc2-c2ccc(-c3ccc(-c4ccc5c(ccc6c5oc5ccc7ccccc7c56)c4)cc3)cc21 ; c1ccc2c(c1)-c1ccccc1C21c2ccccc2-c2ccc(-c3ccc(-c4ccc5c(ccc6c5oc5ccc7ccccc7c56)c4)cc3)cc21 ; CC1(C)c2cc(-c3ccc(-c4ccc5c(ccc6c5oc5ccc7ccccc7c56)c4)cc3)ccc2-c2ccc3ccccc3c21 ; CC1(C)c2cc(-c3ccc(-c4ccc5c(ccc6c5oc5ccc7ccccc7c56)c4)cc3)ccc2-c2cc3ccccc3cc21 ; CC1(C)c2cc(-c3cccc(-c4ccc5c(ccc6c5oc5ccc7ccccc7c56)c4)c3)ccc2-c2cc3ccccc3cc21]

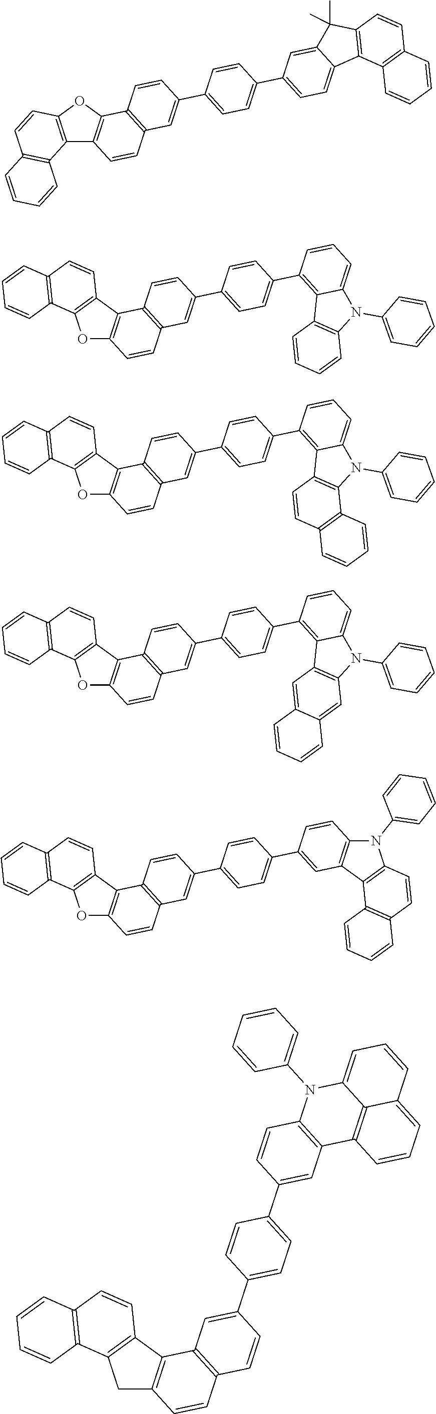

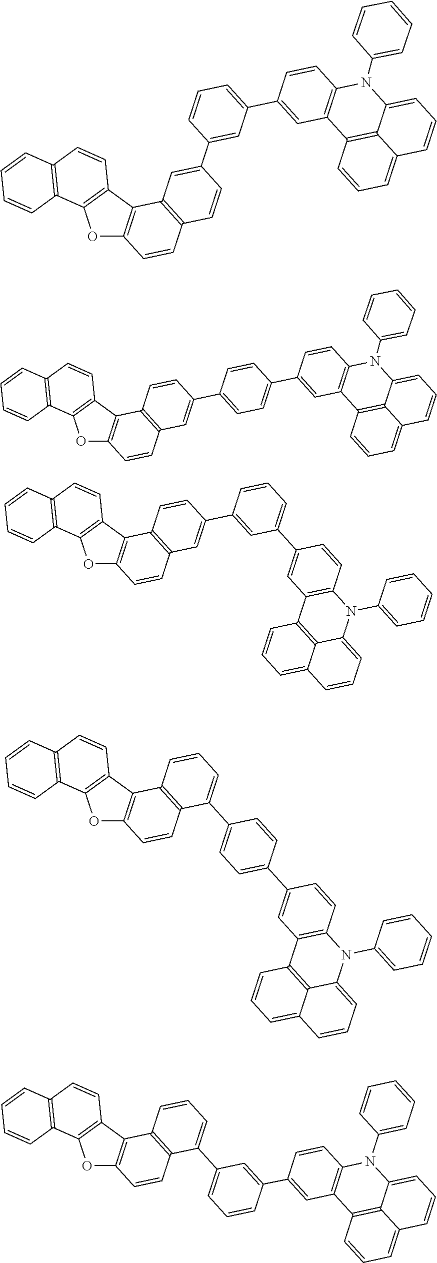 [SMILES: c1ccc(N2c3ccc(-c4cccc(-c5ccc6ccc7oc8c9ccccc9ccc8c7c6c5)c4)cc3-c3cccc4cccc2c34)cc1 ; c1ccc(N2c3ccc(-c4ccc(-c5ccc6c(ccc7oc8c9ccccc9ccc8c76)c5)cc4)cc3-c3cccc4cccc2c34)cc1 ; c1ccc(N2c3ccc(-c4cccc(-c5ccc6c(ccc7oc8c9ccccc9ccc8c76)c5)c4)cc3-c3cccc4cccc2c34)cc1 ; c1ccc(N2c3ccc(-c4ccc(-c5cccc6c5ccc5oc7c8ccccc8ccc7c56)cc4)cc3-c3cccc4cccc2c34)cc1 ; c1ccc(N2c3ccc(-c4cccc(-c5cccc6c5ccc5oc7c8ccccc8ccc7c56)c4)cc3-c3cccc4cccc2c34)cc1]

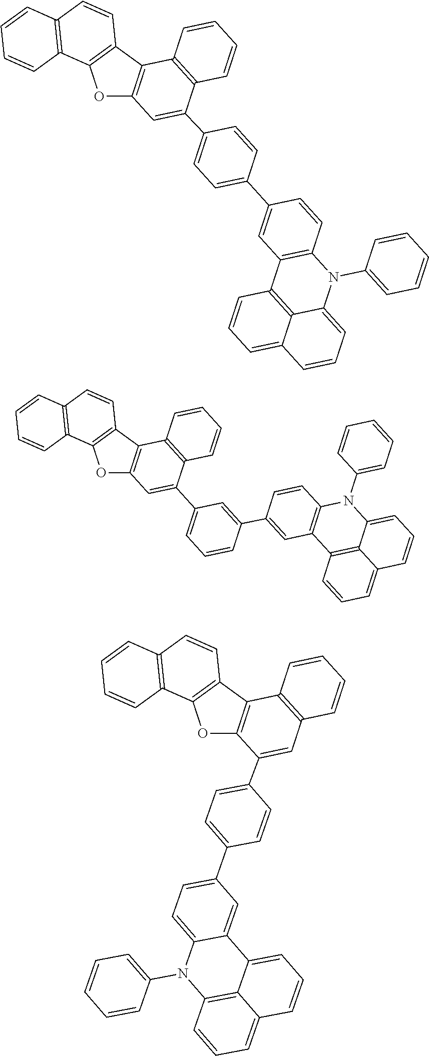 [SMILES: c1ccc(N2c3ccc(-c4ccc(-c5cc6oc7c8ccccc8ccc7c6c6ccccc56)cc4)cc3-c3cccc4cccc2c34)cc1 ; c1ccc(N2c3ccc(-c4cccc(-c5cc6oc7c8ccccc8ccc7c6c6ccccc56)c4)cc3-c3cccc4cccc2c34)cc1 ; c1ccc(N2c3ccc(-c4ccc(-c5cc6ccccc6c6c5oc5c7ccccc7ccc56)cc4)cc3-c3cccc4cccc2c34)cc1]

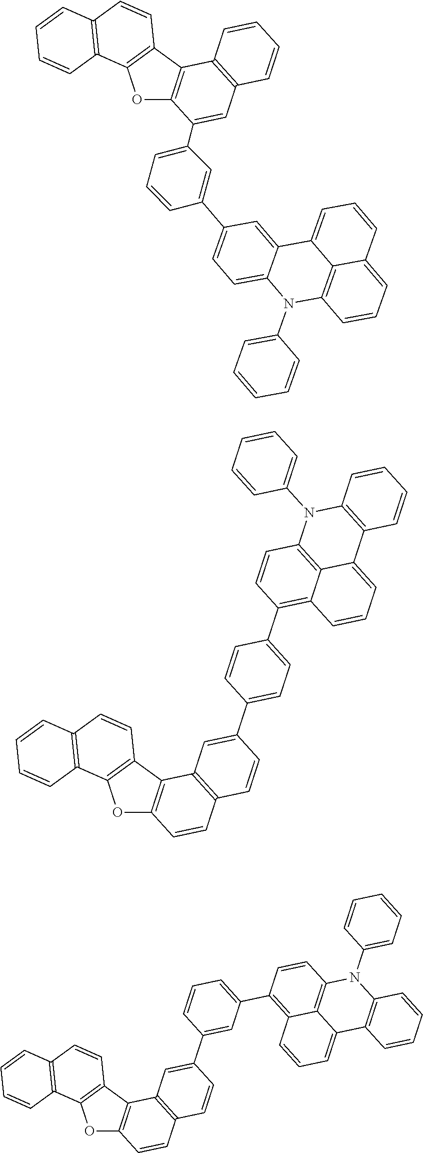

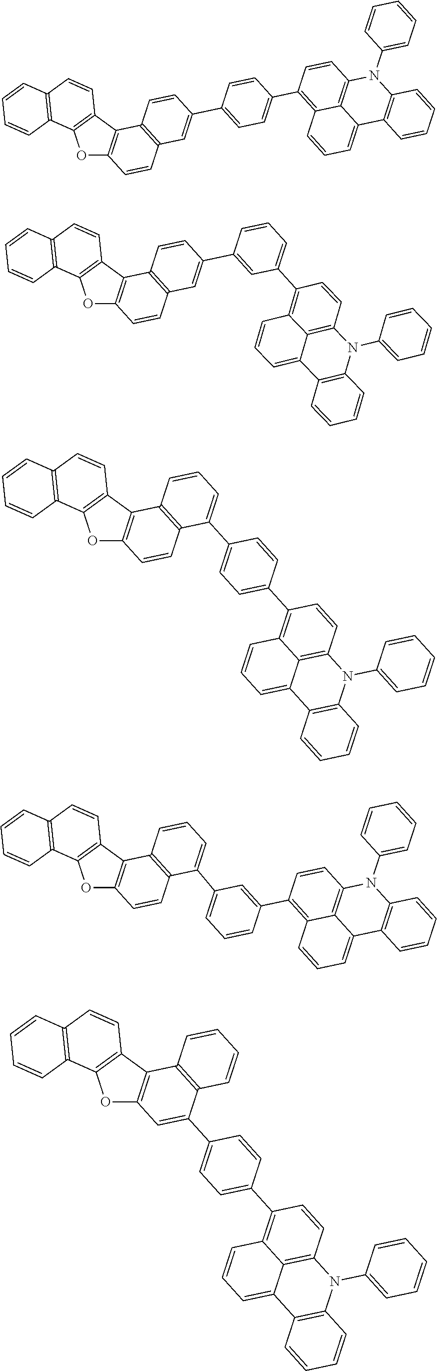 [SMILES: c1ccc(N2c3ccccc3-c3cccc4c(-c5ccc(-c6ccc7c(ccc8oc9c%10ccccc%10ccc9c87)c6)cc5)ccc2c34)cc1 ; c1ccc(N2c3ccccc3-c3cccc4c(-c5cccc(-c6ccc7c(ccc8oc9c%10ccccc%10ccc9c87)c6)c5)ccc2c34)cc1 ; c1ccc(N2c3ccccc3-c3cccc4c(-c5ccc(-c6cccc7c6ccc6oc8c9ccccc9ccc8c67)cc5)ccc2c34)cc1 ; c1ccc(N2c3ccccc3-c3cccc4c(-c5cccc(-c6cccc7c6ccc6oc8c9ccccc9ccc8c67)c5)ccc2c34)cc1 ; c1ccc(N2c3ccccc3-c3cccc4c(-c5ccc(-c6cc7oc8c9ccccc9ccc8c7c7ccccc67)cc5)ccc2c34)cc1]

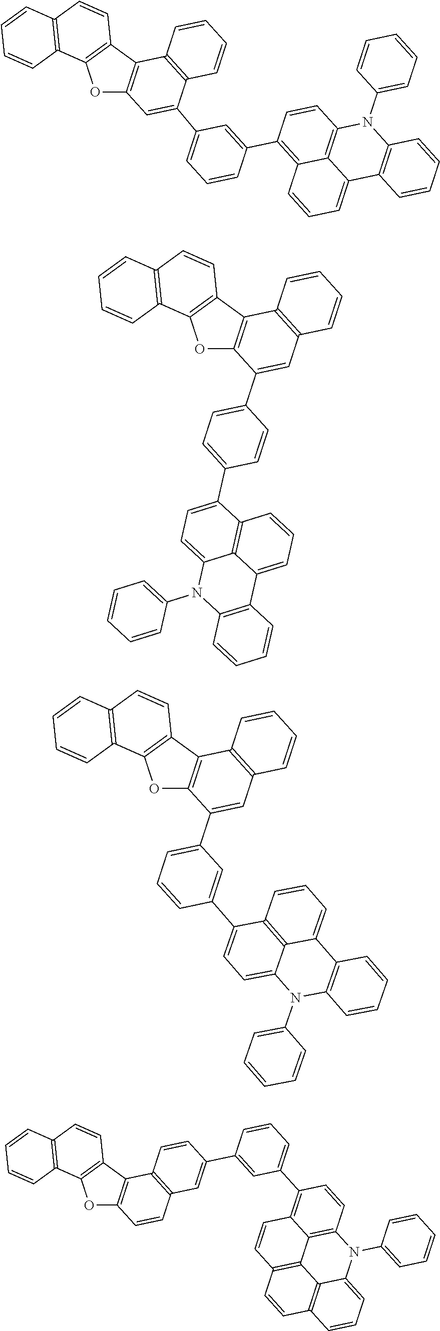

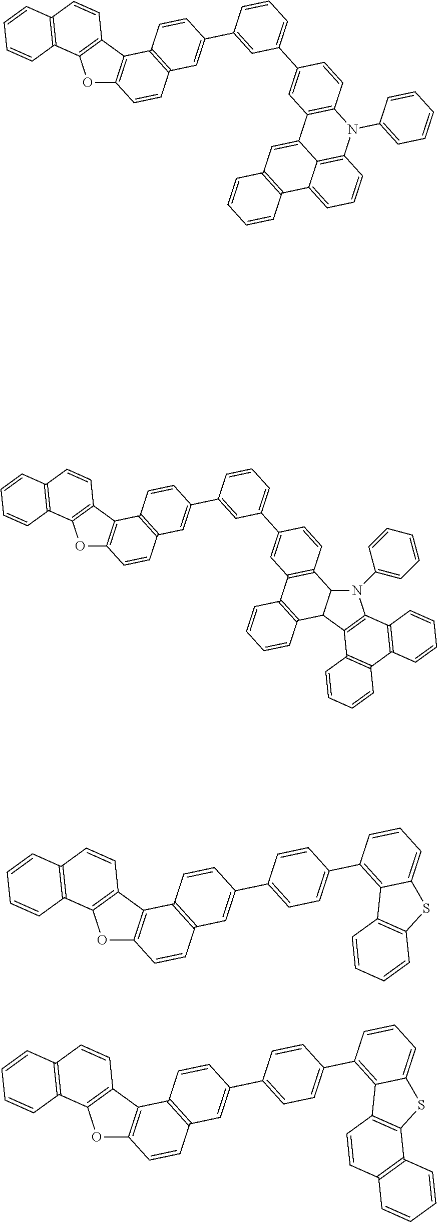 [SMILES: c1ccc(N2c3ccc(-c4cccc(-c5ccc6c(ccc7oc8c9ccccc9ccc8c76)c5)c4)cc3-c3cc4ccccc4c4cccc2c34)cc1 ; c1ccc(N2c3c(c4ccccc4c4ccccc34)C3c4ccccc4-c4cc(-c5cccc(-c6ccc7c(ccc8oc9c%10ccccc%10ccc9c87)c6)c5)ccc4C32)cc1 ; c1ccc2c(c1)ccc1c2oc2ccc3cc(-c4ccc(-c5cccc6sc7ccccc7c56)cc4)ccc3c21 ; c1ccc2c(c1)ccc1c2oc2ccc3cc(-c4ccc(-c5cccc6sc7c8ccccc8ccc7c56)cc4)ccc3c21]

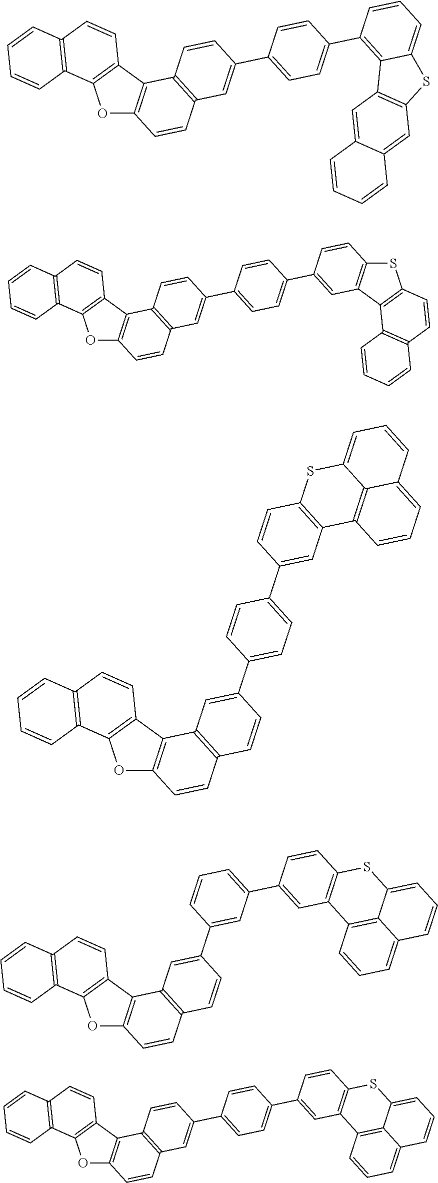

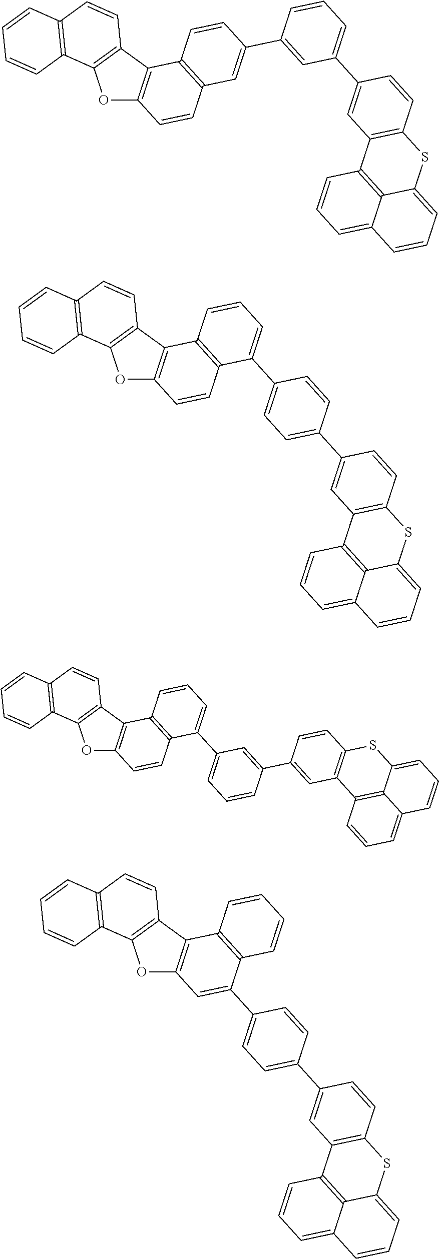 [SMILES: c1cc(-c2ccc3c(c2)-c2cccc4cccc(c24)S3)cc(-c2ccc3c(ccc4oc5c6ccccc6ccc5c43)c2)c1 ; c1cc2c3c(cccc3c1)-c1cc(-c3ccc(-c4cccc5c4ccc4oc6c7ccccc7ccc6c45)cc3)ccc1S2 ; c1cc(-c2ccc3c(c2)-c2cccc4cccc(c24)S3)cc(-c2cccc3c2ccc2oc4c5ccccc5ccc4c23)c1 ; c1cc2c3c(cccc3c1)-c1cc(-c3ccc(-c4cc5oc6c7ccccc7ccc6c5c5ccccc45)cc3)ccc1S2]

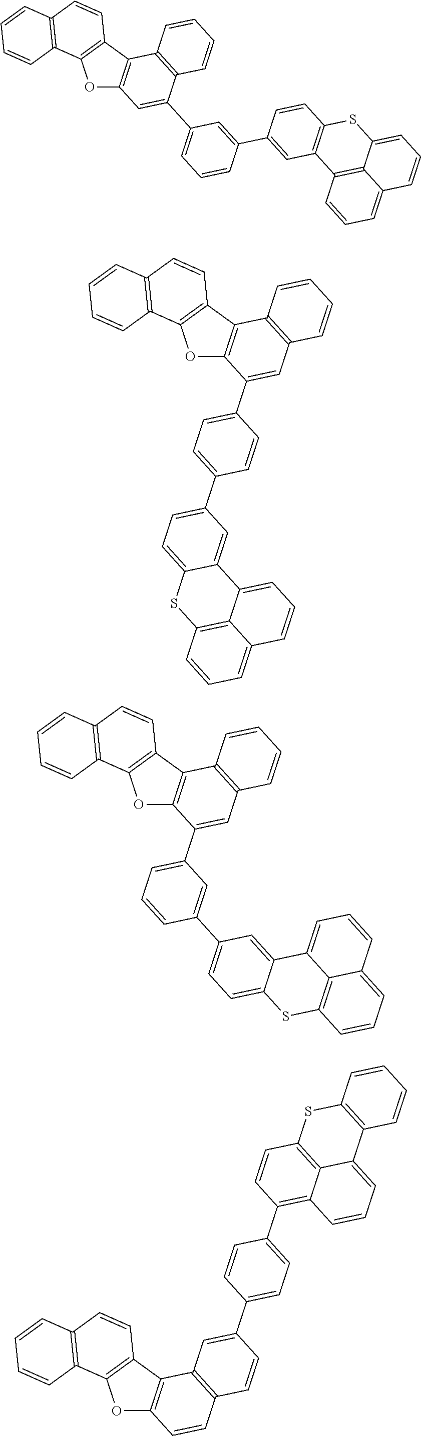

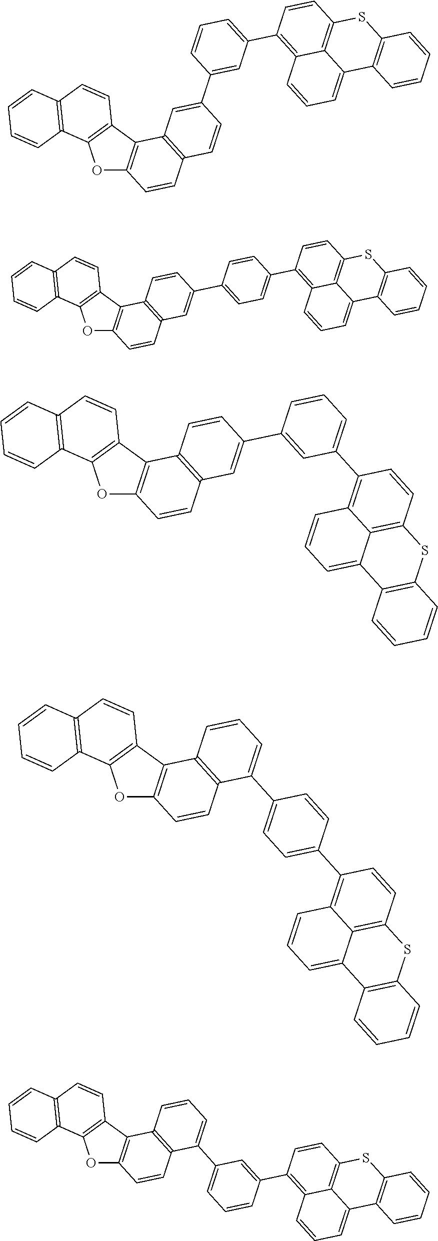 [SMILES: c1cc(-c2ccc3ccc4oc5c6ccccc6ccc5c4c3c2)cc(-c2ccc3c4c(cccc24)-c2ccccc2S3)c1 ; c1ccc2c(c1)Sc1ccc(-c3ccc(-c4ccc5c(ccc6oc7c8ccccc8ccc7c65)c4)cc3)c3cccc-2c13 ; c1cc(-c2ccc3c(ccc4oc5c6ccccc6ccc5c43)c2)cc(-c2ccc3c4c(cccc24)-c2ccccc2S3)c1 ; c1ccc2c(c1)Sc1ccc(-c3ccc(-c4cccc5c4ccc4oc6c7ccccc7ccc6c45)cc3)c3cccc-2c13 ; c1cc(-c2ccc3c4c(cccc24)-c2ccccc2S3)cc(-c2cccc3c2ccc2oc4c5ccccc5ccc4c23)c1]

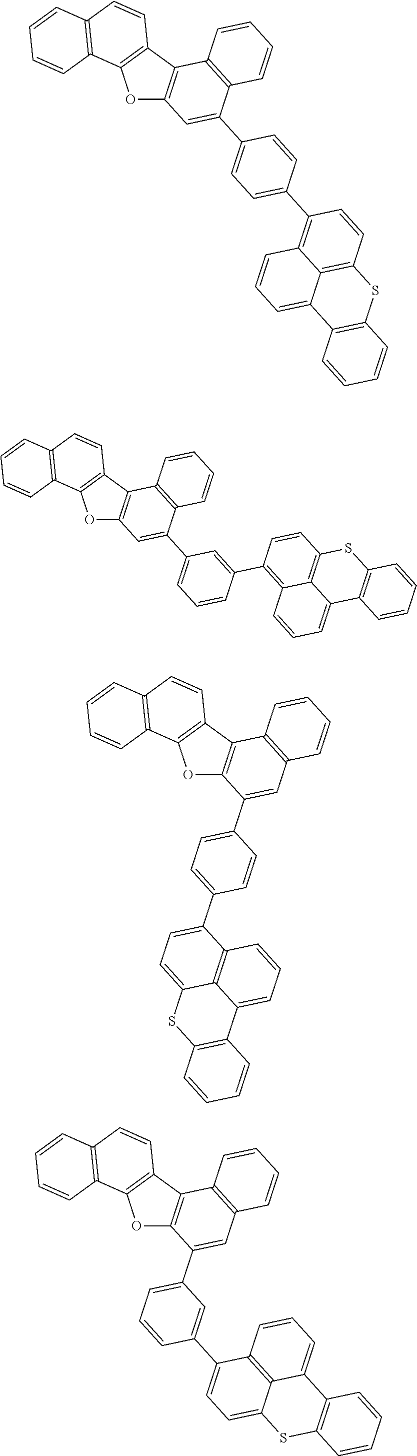 [SMILES: c1ccc2c(c1)Sc1ccc(-c3ccc(-c4cc5oc6c7ccccc7ccc6c5c5ccccc45)cc3)c3cccc-2c13 ; c1cc(-c2ccc3c4c(cccc24)-c2ccccc2S3)cc(-c2cc3oc4c5ccccc5ccc4c3c3ccccc23)c1 ; c1ccc2c(c1)Sc1ccc(-c3ccc(-c4cc5ccccc5c5c4oc4c6ccccc6ccc45)cc3)c3cccc-2c13 ; c1cc(-c2ccc3c4c(cccc24)-c2ccccc2S3)cc(-c2cc3ccccc3c3c2oc2c4ccccc4ccc23)c1]

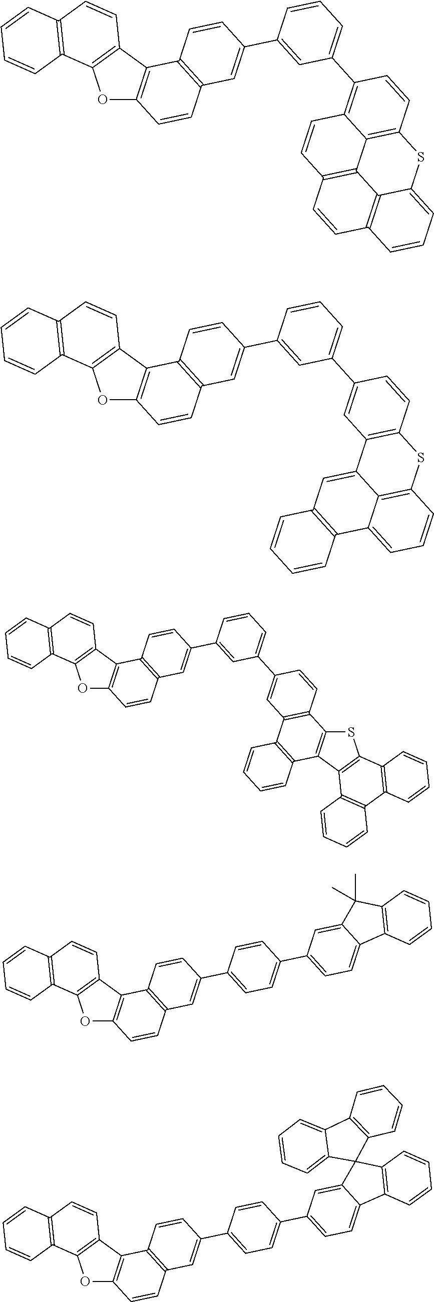

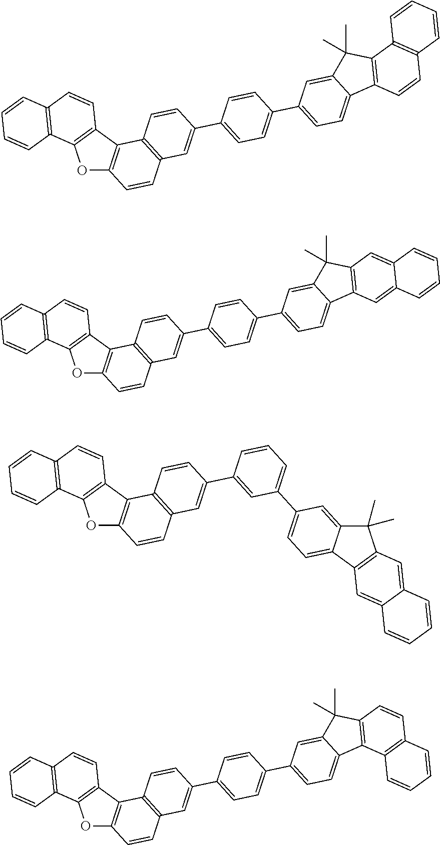 [SMILES: CC1(C)c2cc(-c3ccc(-c4ccc5c(ccc6oc7c8ccccc8ccc7c65)c4)cc3)ccc2-c2ccc3ccccc3c21 ; CC1(C)c2cc(-c3ccc(-c4ccc5c(ccc6oc7c8ccccc8ccc7c65)c4)cc3)ccc2-c2cc3ccccc3cc21 ; CC1(C)c2cc(-c3cccc(-c4ccc5c(ccc6oc7c8ccccc8ccc7c65)c4)c3)ccc2-c2cc3ccccc3cc21 ; CC1(C)c2cc(-c3ccc(-c4ccc5c(ccc6oc7c8ccccc8ccc7c65)c4)cc3)ccc2-c2c1ccc1ccccc21]

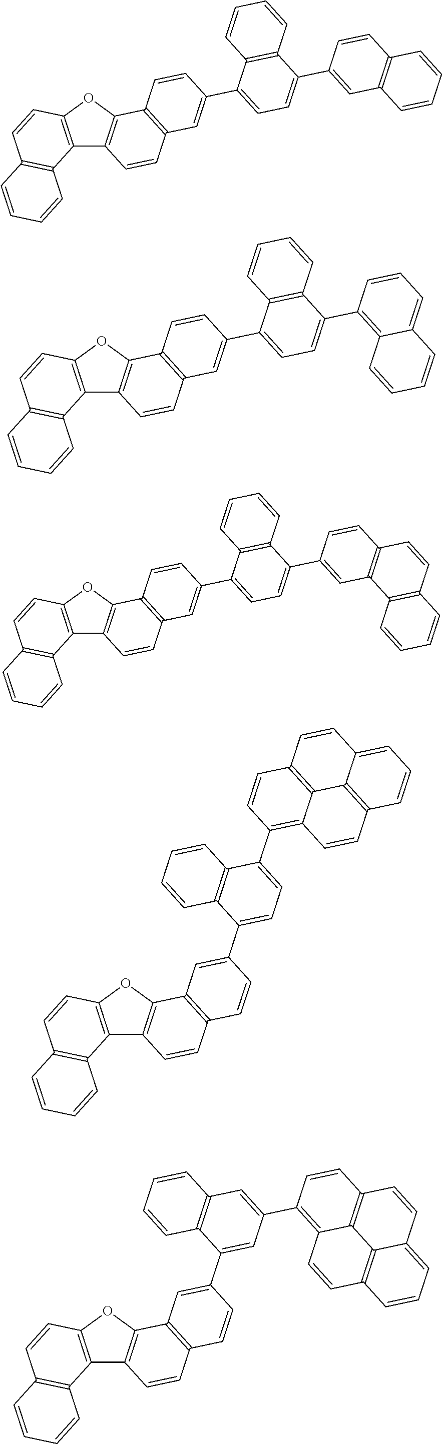 [SMILES: c1ccc2cc(-c3ccc(-c4ccc5c(ccc6c5oc5ccc7ccccc7c56)c4)c4ccccc34)ccc2c1 ; c1ccc2c(-c3ccc(-c4ccc5c(ccc6c5oc5ccc7ccccc7c56)c4)c4ccccc34)cccc2c1 ; c1ccc2c(c1)ccc1ccc(-c3ccc(-c4ccc5c(ccc6c5oc5ccc7ccccc7c56)c4)c4ccccc34)cc12 ; c1ccc2c(c1)ccc1oc3c4cc(-c5ccc(-c6ccc7ccc8cccc9ccc6c7c89)c6ccccc56)ccc4ccc3c12 ; c1ccc2c(-c3ccc4ccc5c(oc6ccc7ccccc7c65)c4c3)cc(-c3ccc4ccc5cccc6ccc3c4c56)cc2c1]

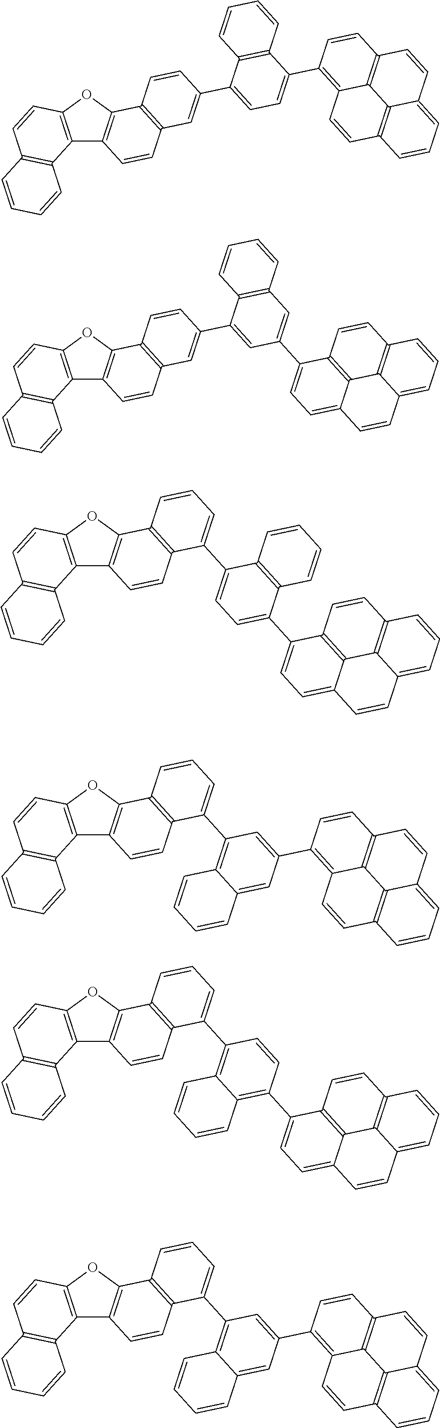

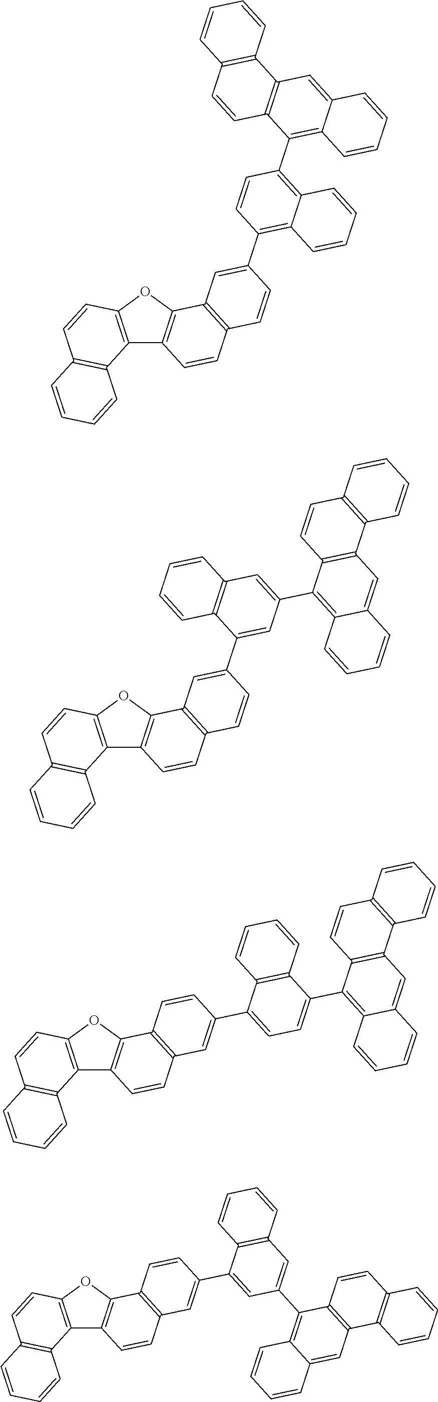 [SMILES: c1ccc2c(-c3ccc(-c4ccc5ccc6c(oc7ccc8ccccc8c76)c5c4)c4ccccc34)c3ccc4ccccc4c3cc2c1 ; c1ccc2c(-c3ccc4ccc5c(oc6ccc7ccccc7c65)c4c3)cc(-c3c4ccccc4cc4c3ccc3ccccc34)cc2c1 ; c1ccc2c(-c3ccc(-c4ccc5c(ccc6c5oc5ccc7ccccc7c56)c4)c4ccccc34)c3ccc4ccccc4c3cc2c1 ; c1ccc2c(-c3ccc4c(ccc5c4oc4ccc6ccccc6c45)c3)cc(-c3c4ccccc4cc4c3ccc3ccccc34)cc2c1]

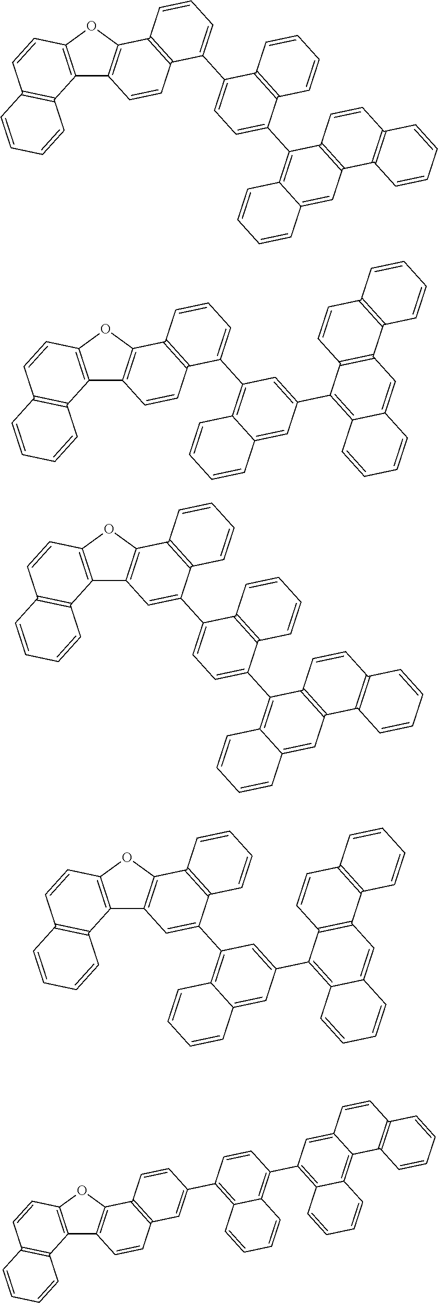

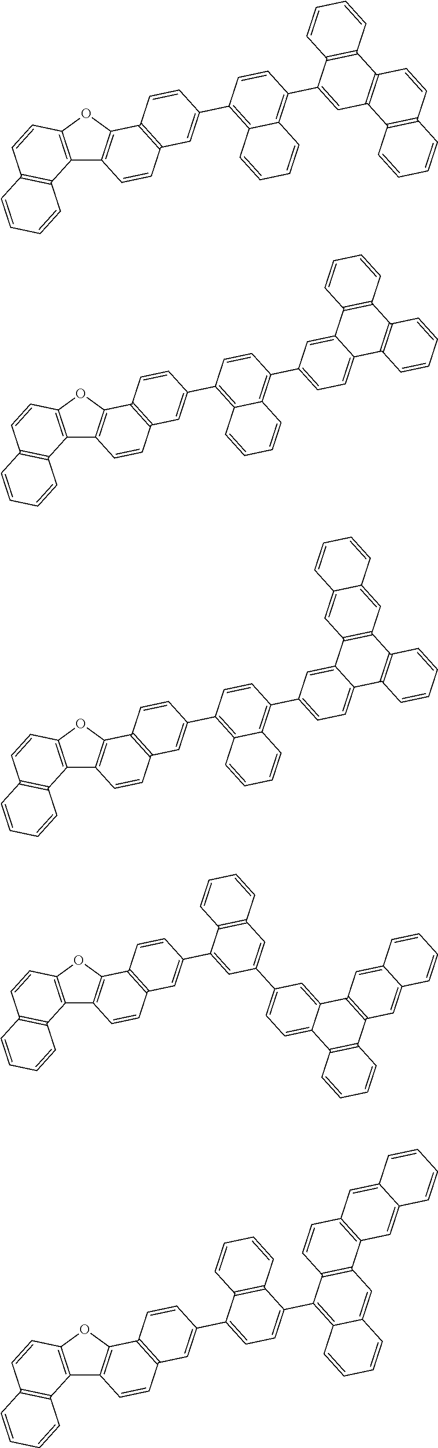 [SMILES: c1ccc2c(c1)ccc1c3ccccc3c(-c3ccc(-c4ccc5c(ccc6c5oc5ccc7ccccc7c56)c4)c4ccccc34)cc21 ; c1ccc2c(c1)ccc1oc3c4ccc(-c5ccc(-c6ccc7c8ccccc8c8ccccc8c7c6)c6ccccc56)cc4ccc3c12 ; c1ccc2cc3c4cc(-c5ccc(-c6ccc7c(ccc8c7oc7ccc9ccccc9c78)c6)c6ccccc56)ccc4c4ccccc4c3cc2c1 ; c1ccc2cc3c4cc(-c5cc(-c6ccc7c(ccc8c7oc7ccc9ccccc9c78)c6)c6ccccc6c5)ccc4c4ccccc4c3cc2c1 ; c1ccc2cc3c(ccc4c(-c5ccc(-c6ccc7c(ccc8c7oc7ccc9ccccc9c78)c6)c6ccccc56)c5ccccc5cc43)cc2c1]

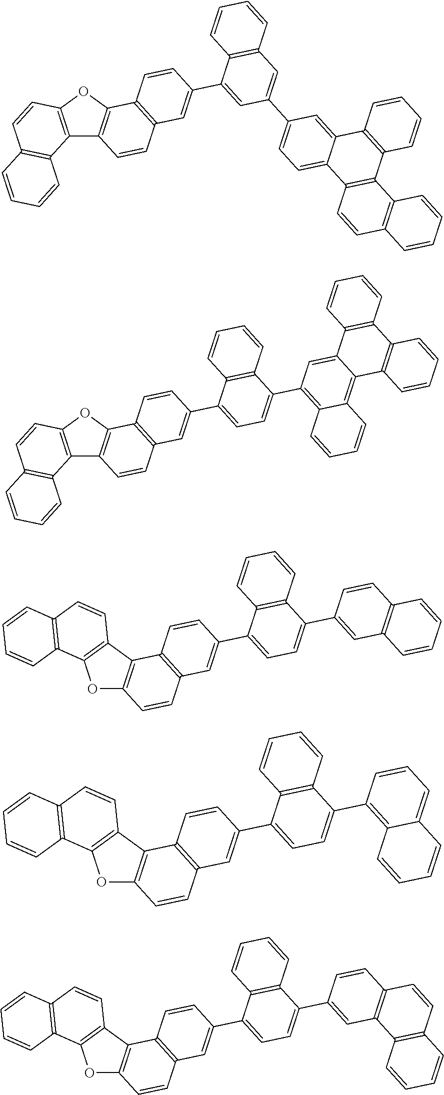 [SMILES: c1ccc2c(-c3ccc4c(ccc5c4oc4ccc6ccccc6c45)c3)cc(-c3ccc4c(c3)c3ccccc3c3c5ccccc5ccc43)cc2c1 ; c1ccc2c(c1)ccc1oc3c4ccc(-c5ccc(-c6cc7c8ccccc8c8ccccc8c7c7ccccc67)c6ccccc56)cc4ccc3c12 ; c1ccc2cc(-c3ccc(-c4ccc5c(ccc6oc7c8ccccc8ccc7c65)c4)c4ccccc34)ccc2c1 ; c1ccc2c(-c3ccc(-c4ccc5c(ccc6oc7c8ccccc8ccc7c65)c4)c4ccccc34)cccc2c1 ; c1ccc2c(c1)ccc1ccc(-c3ccc(-c4ccc5c(ccc6oc7c8ccccc8ccc7c65)c4)c4ccccc34)cc12]

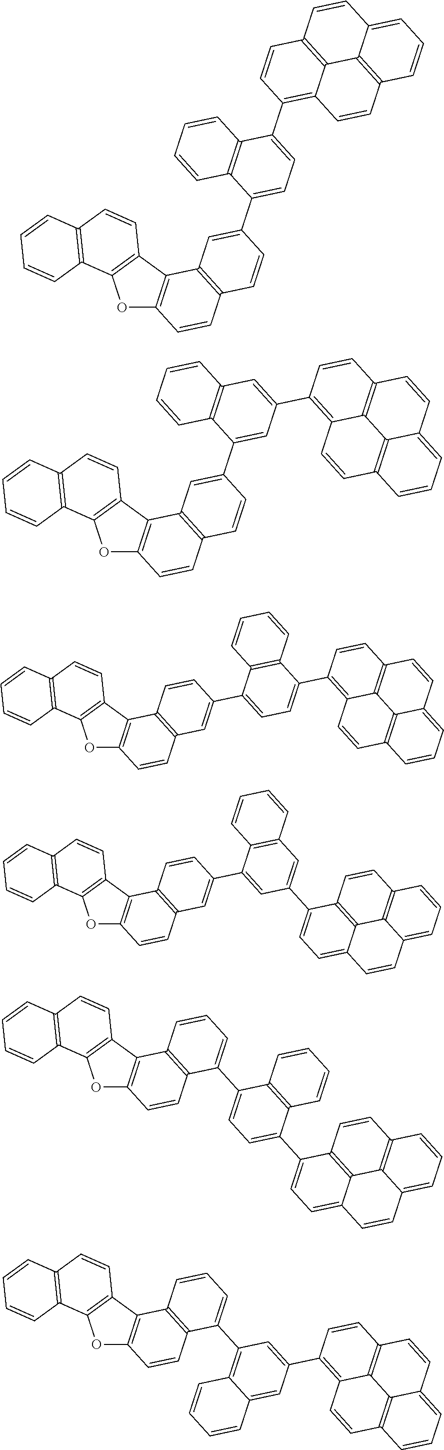

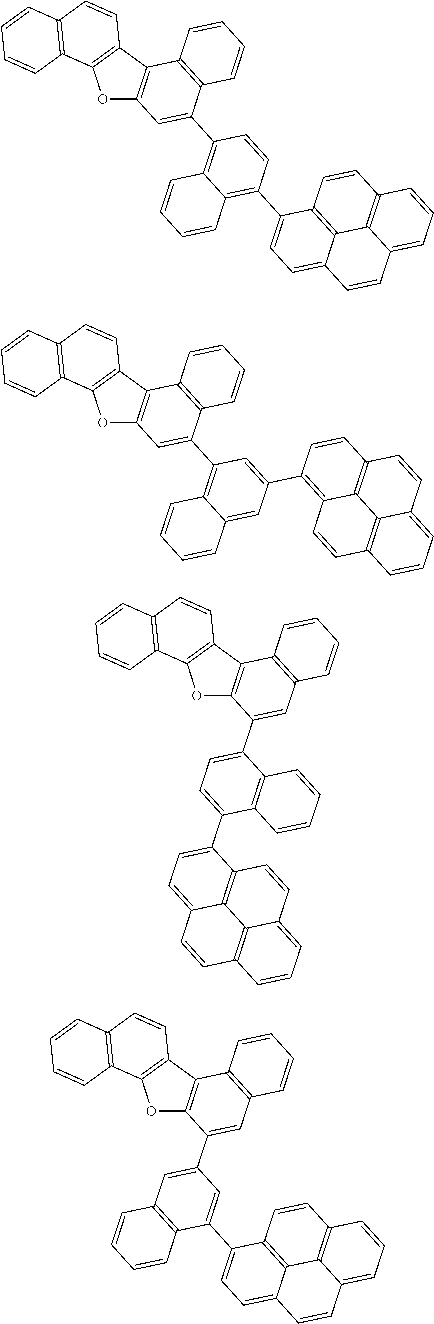

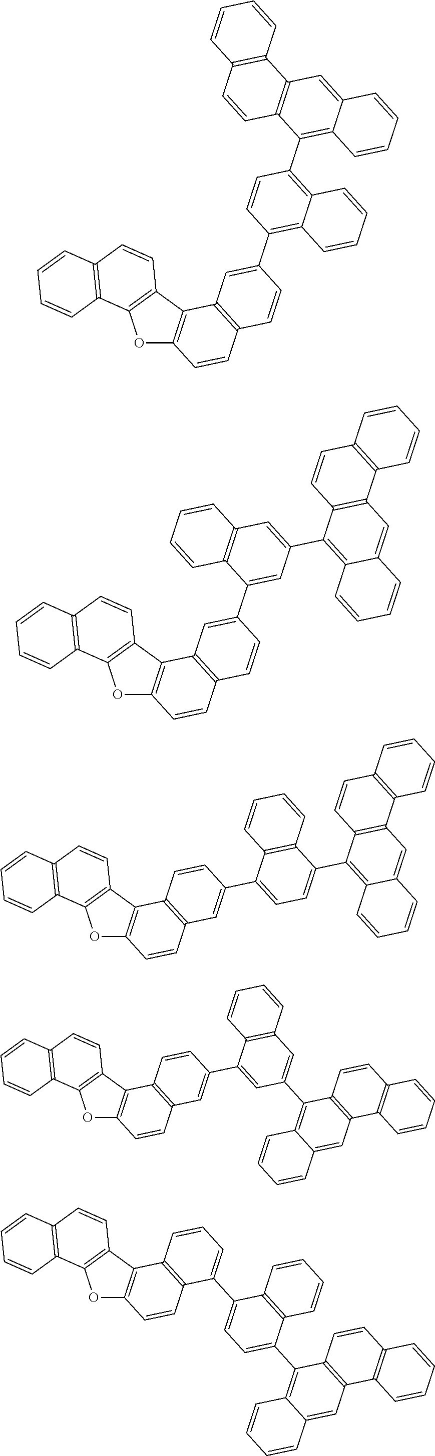 [SMILES: c1ccc2c(-c3ccc(-c4ccc5ccc6oc7c8ccccc8ccc7c6c5c4)c4ccccc34)c3ccc4ccccc4c3cc2c1 ; c1ccc2c(-c3ccc4ccc5oc6c7ccccc7ccc6c5c4c3)cc(-c3c4ccccc4cc4c3ccc3ccccc34)cc2c1 ; c1ccc2c(-c3ccc(-c4ccc5c(ccc6oc7c8ccccc8ccc7c65)c4)c4ccccc34)c3ccc4ccccc4c3cc2c1 ; c1ccc2c(-c3ccc4c(ccc5oc6c7ccccc7ccc6c54)c3)cc(-c3c4ccccc4cc4c3ccc3ccccc34)cc2c1 ; c1ccc2c(-c3ccc(-c4cccc5c4ccc4oc6c7ccccc7ccc6c45)c4ccccc34)c3ccc4ccccc4c3cc2c1]

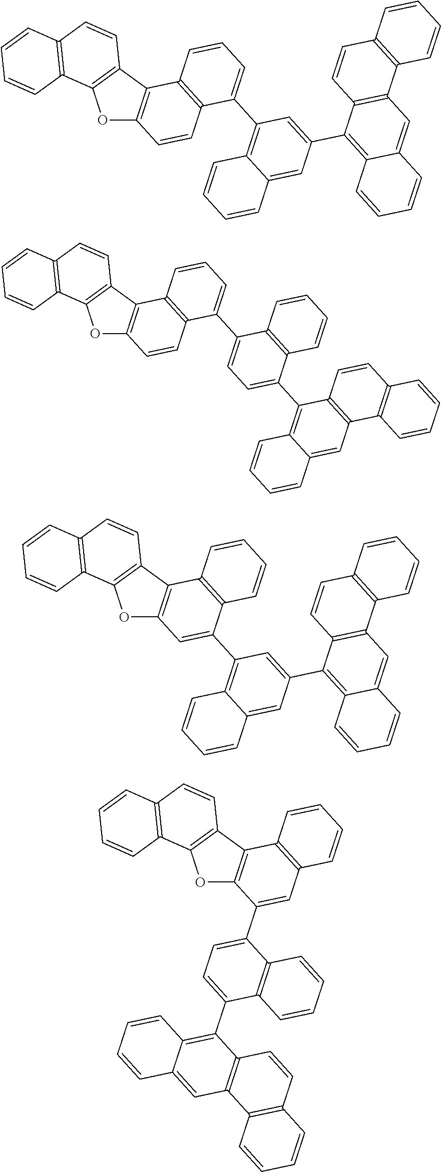

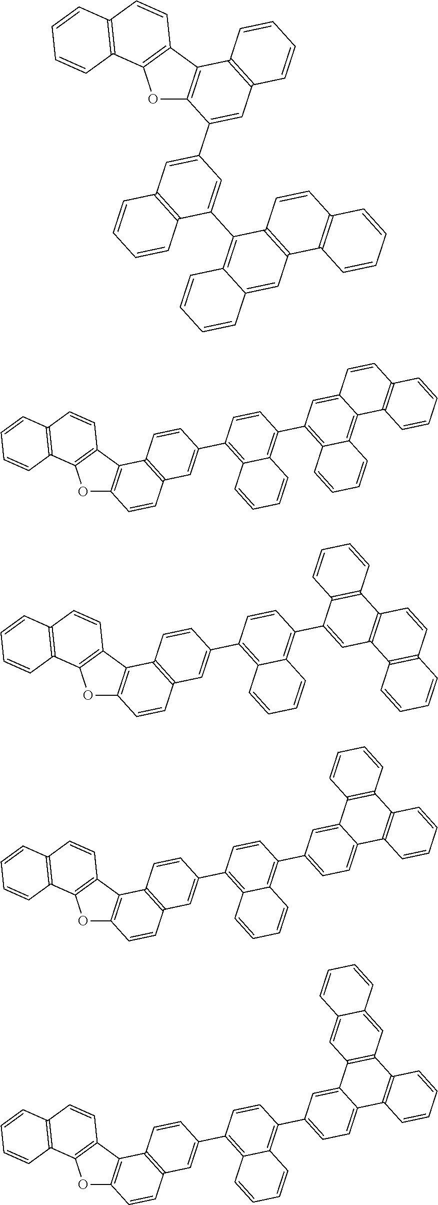 [SMILES: c1ccc2c(-c3c4ccccc4cc4c3ccc3ccccc34)cc(-c3cc4ccccc4c4c3oc3c5ccccc5ccc34)cc2c1 ; c1ccc2c(c1)ccc1c2oc2ccc3cc(-c4ccc(-c5cc6ccc7ccccc7c6c6ccccc56)c5ccccc45)ccc3c21 ; c1ccc2c(c1)ccc1c3ccccc3c(-c3ccc(-c4ccc5c(ccc6oc7c8ccccc8ccc7c65)c4)c4ccccc34)cc21 ; c1ccc2c(c1)ccc1c2oc2ccc3cc(-c4ccc(-c5ccc6c7ccccc7c7ccccc7c6c5)c5ccccc45)ccc3c21 ; c1ccc2cc3c4cc(-c5ccc(-c6ccc7c(ccc8oc9c%10ccccc%10ccc9c87)c6)c6ccccc56)ccc4c4ccccc4c3cc2c1]

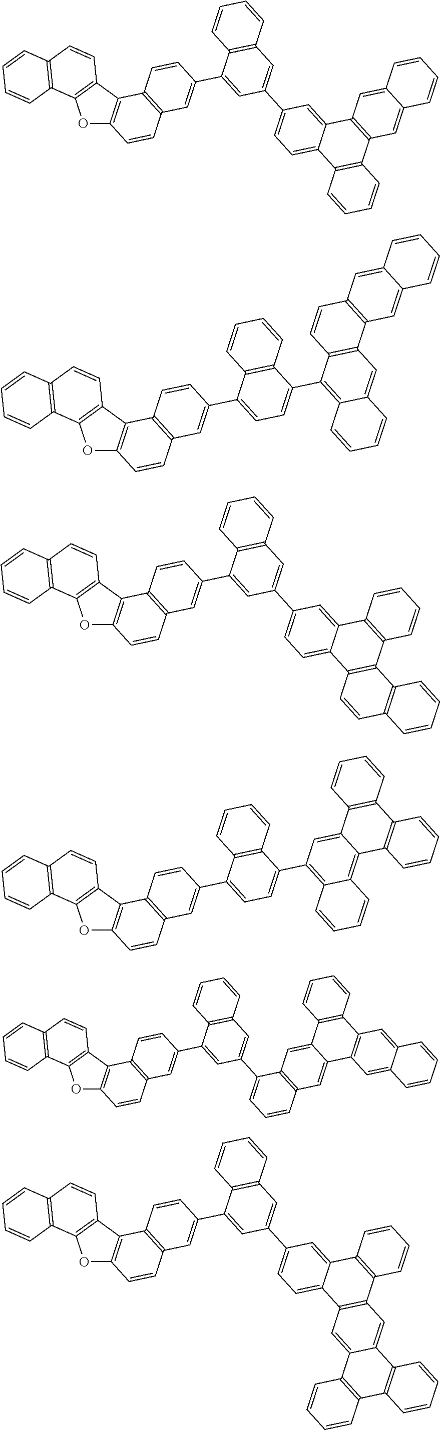

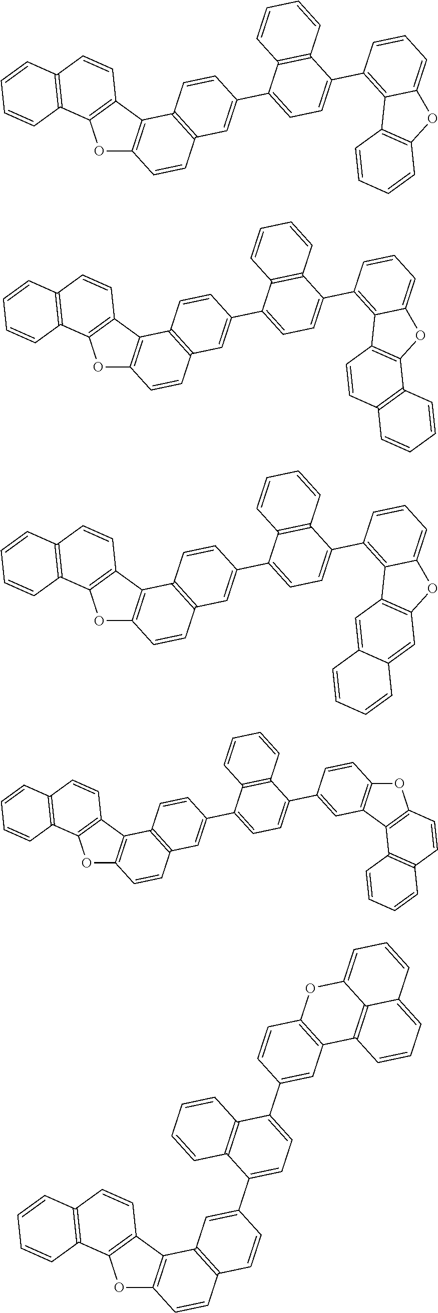

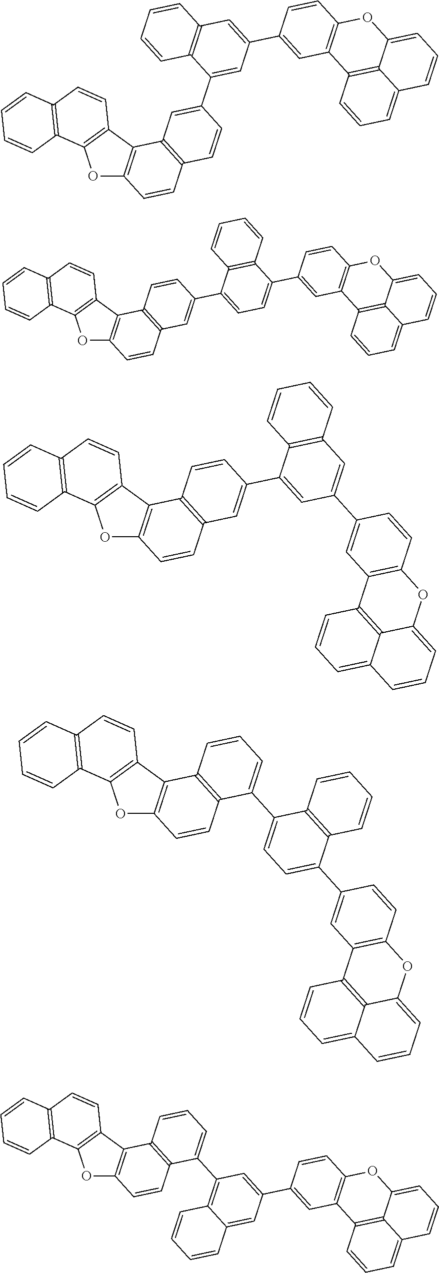 [SMILES: c1ccc2c(-c3ccc4ccc5oc6c7ccccc7ccc6c5c4c3)cc(-c3ccc4c(c3)-c3cccc5cccc(c35)O4)cc2c1 ; c1cc2c3c(cccc3c1)-c1cc(-c3ccc(-c4ccc5c(ccc6oc7c8ccccc8ccc7c65)c4)c4ccccc34)ccc1O2 ; c1ccc2c(-c3ccc4c(ccc5oc6c7ccccc7ccc6c54)c3)cc(-c3ccc4c(c3)-c3cccc5cccc(c35)O4)cc2c1 ; c1cc2c3c(cccc3c1)-c1cc(-c3ccc(-c4cccc5c4ccc4oc6c7ccccc7ccc6c45)c4ccccc34)ccc1O2 ; c1ccc2c(-c3cccc4c3ccc3oc5c6ccccc6ccc5c34)cc(-c3ccc4c(c3)-c3cccc5cccc(c35)O4)cc2c1]

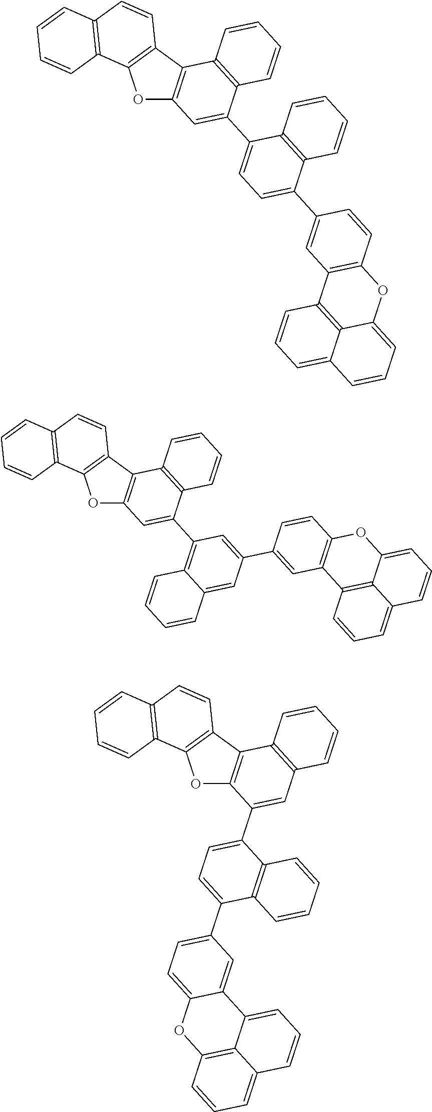 [SMILES: c1cc2c3c(cccc3c1)-c1cc(-c3ccc(-c4cc5oc6c7ccccc7ccc6c5c5ccccc45)c4ccccc34)ccc1O2 ; c1ccc2c(-c3cc4oc5c6ccccc6ccc5c4c4ccccc34)cc(-c3ccc4c(c3)-c3cccc5cccc(c35)O4)cc2c1 ; c1cc2c3c(cccc3c1)-c1cc(-c3ccc(-c4cc5ccccc5c5c4oc4c6ccccc6ccc45)c4ccccc34)ccc1O2]

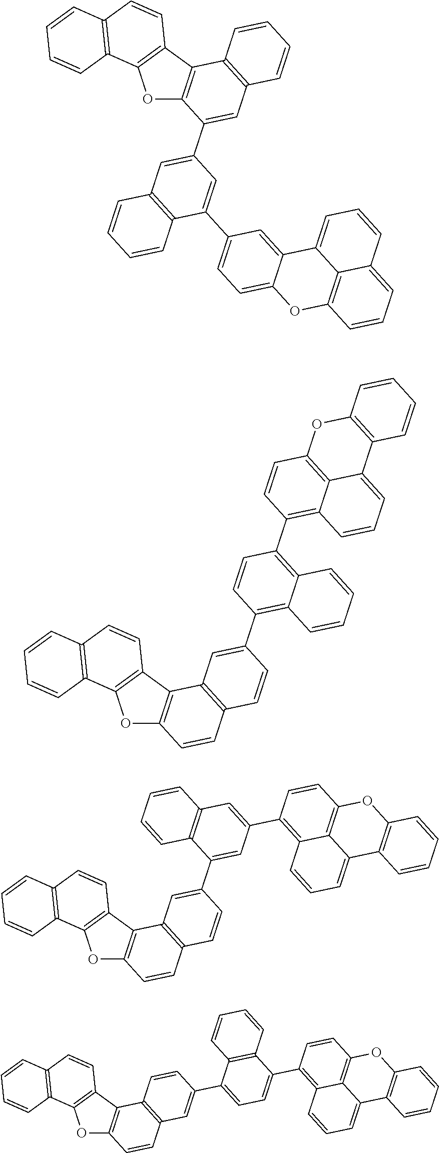

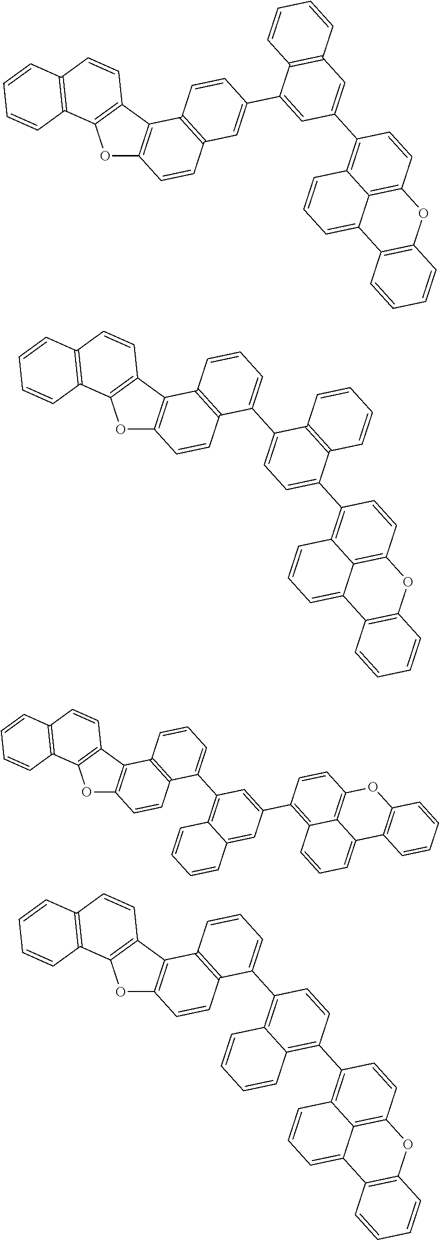 [SMILES: c1ccc2c(c1)Oc1ccc(-c3cc(-c4ccc5c(ccc6oc7c8ccccc8ccc7c65)c4)c4ccccc4c3)c3cccc-2c13 ; c1ccc2c(c1)Oc1ccc(-c3ccc(-c4cccc5c4ccc4oc6c7ccccc7ccc6c45)c4ccccc34)c3cccc-2c13 ; c1ccc2c(c1)Oc1ccc(-c3cc(-c4cccc5c4ccc4oc6c7ccccc7ccc6c45)c4ccccc4c3)c3cccc-2c13 ; c1ccc2c(c1)Oc1ccc(-c3ccc(-c4cccc5c4ccc4oc6c7ccccc7ccc6c45)c4ccccc34)c3cccc-2c13]

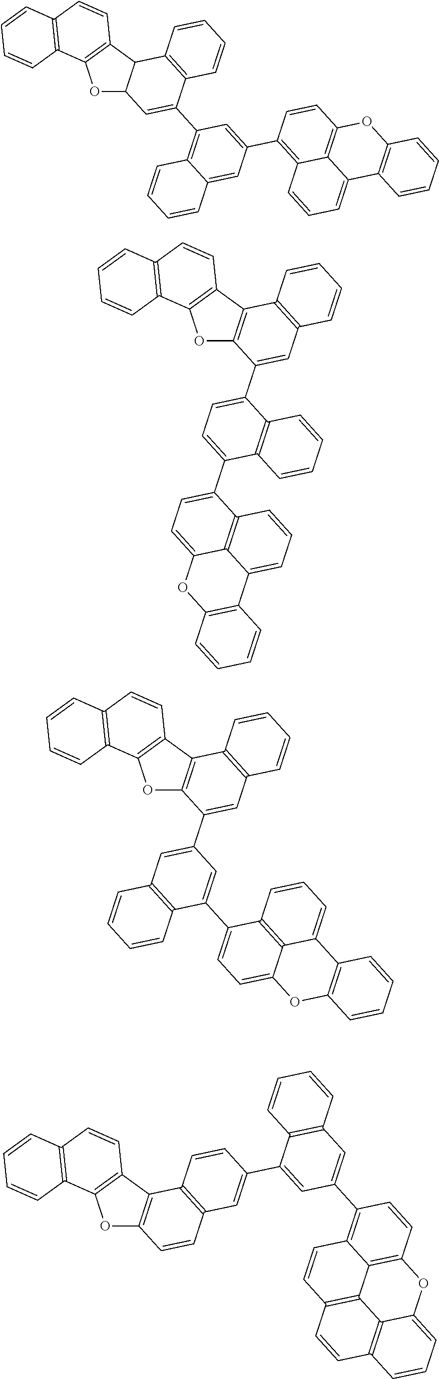

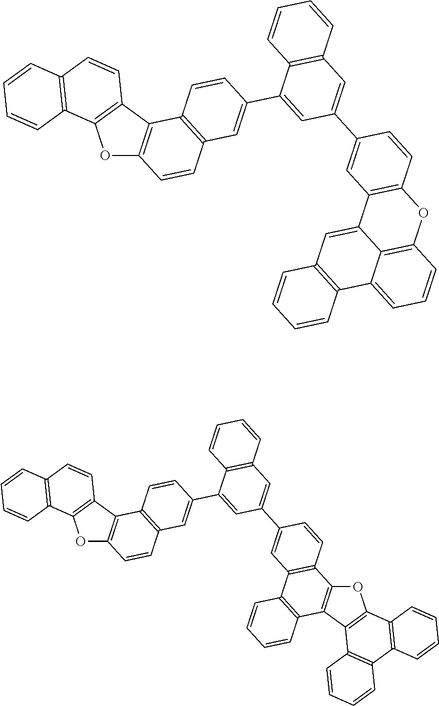 [SMILES: c1ccc2c(-c3ccc4c(ccc5oc6c7ccccc7ccc6c54)c3)cc(-c3ccc4c(c3)-c3cc5ccccc5c5cccc(c35)O4)cc2c1 ; c1ccc2c(-c3ccc4c(ccc5oc6c7ccccc7ccc6c54)c3)cc(-c3ccc4c(c3)c3ccccc3c3c4oc4c5ccccc5c5ccccc5c43)cc2c1]

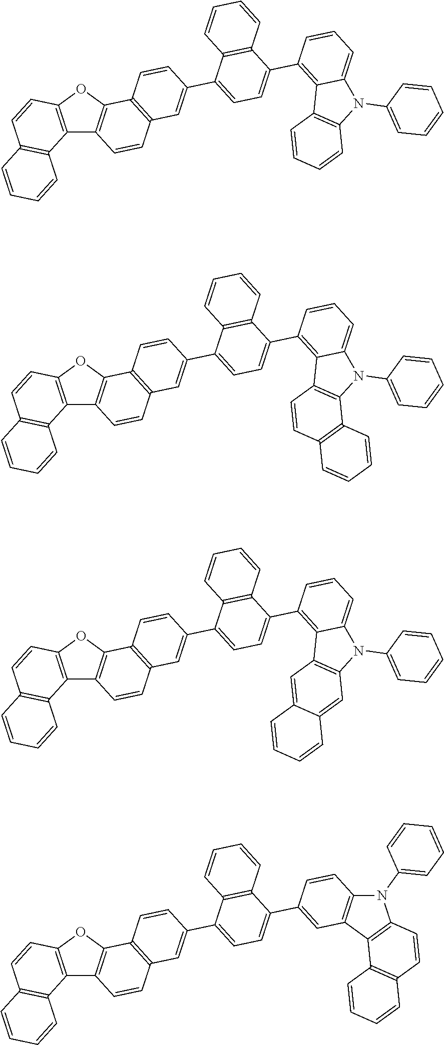 [SMILES: c1ccc(-n2c3ccccc3c3c(-c4ccc(-c5ccc6c(ccc7c6oc6ccc8ccccc8c67)c5)c5ccccc45)cccc32)cc1 ; c1ccc(-n2c3cccc(-c4ccc(-c5ccc6c(ccc7c6oc6ccc8ccccc8c67)c5)c5ccccc45)c3c3ccc4ccccc4c32)cc1 ; c1ccc(-n2c3cc4ccccc4cc3c3c(-c4ccc(-c5ccc6c(ccc7c6oc6ccc8ccccc8c67)c5)c5ccccc45)cccc32)cc1 ; c1ccc(-n2c3ccc(-c4ccc(-c5ccc6c(ccc7c6oc6ccc8ccccc8c67)c5)c5ccccc45)cc3c3c4ccccc4ccc32)cc1]

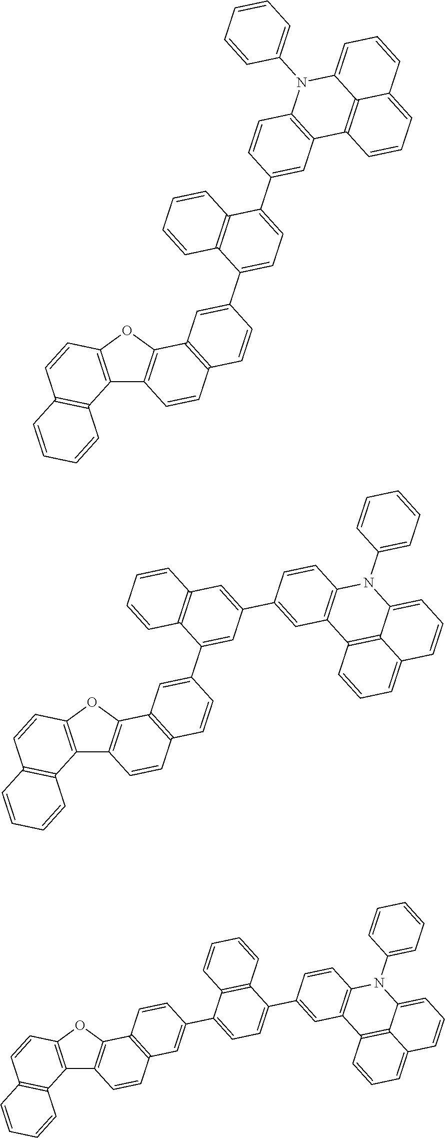 [SMILES: c1ccc(N2c3ccc(-c4ccc(-c5ccc6ccc7c(oc8ccc9ccccc9c87)c6c5)c5ccccc45)cc3-c3cccc4cccc2c34)cc1 ; c1ccc(N2c3ccc(-c4cc(-c5ccc6ccc7c(oc8ccc9ccccc9c87)c6c5)c5ccccc5c4)cc3-c3cccc4cccc2c34)cc1 ; c1ccc(N2c3ccc(-c4ccc(-c5ccc6c(ccc7c6oc6ccc8ccccc8c67)c5)c5ccccc45)cc3-c3cccc4cccc2c34)cc1]

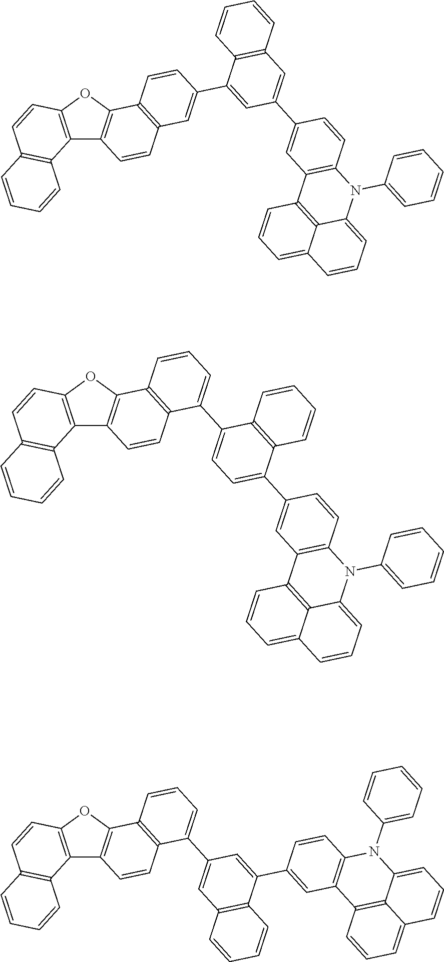 [SMILES: c1ccc(N2c3ccc(-c4cc(-c5ccc6c(ccc7c6oc6ccc8ccccc8c67)c5)c5ccccc5c4)cc3-c3cccc4cccc2c34)cc1 ; c1ccc(N2c3ccc(-c4ccc(-c5cccc6c5ccc5c6oc6ccc7ccccc7c65)c5ccccc45)cc3-c3cccc4cccc2c34)cc1 ; c1ccc(N2c3ccc(-c4cc(-c5cccc6c5ccc5c6oc6ccc7ccccc7c65)cc5ccccc45)cc3-c3cccc4cccc2c34)cc1]

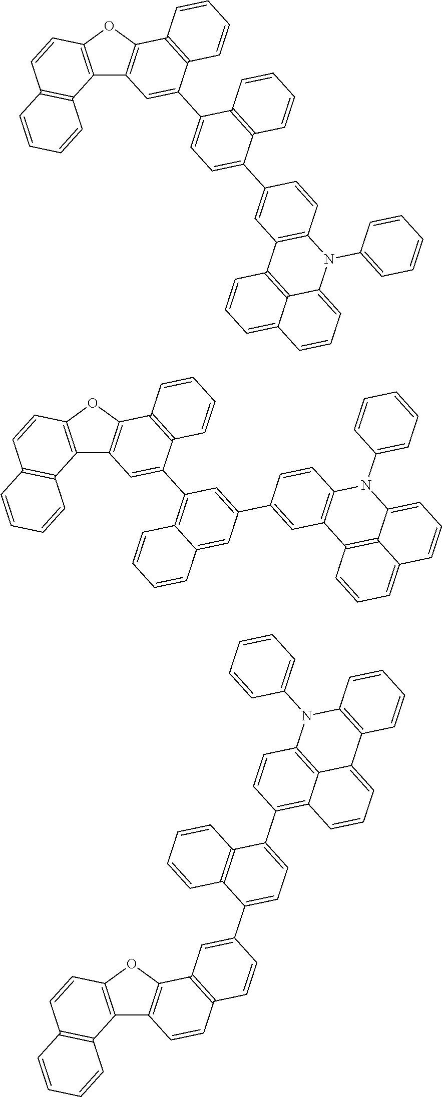 [SMILES: c1ccc(N2c3ccc(-c4ccc(-c5cc6c(oc7ccc8ccccc8c76)c6ccccc56)c5ccccc45)cc3-c3cccc4cccc2c34)cc1 ; c1ccc(N2c3ccc(-c4cc(-c5cc6c(oc7ccc8ccccc8c76)c6ccccc56)c5ccccc5c4)cc3-c3cccc4cccc2c34)cc1 ; c1ccc(N2c3ccccc3-c3cccc4c(-c5ccc(-c6ccc7ccc8c(oc9ccc%10ccccc%10c98)c7c6)c6ccccc56)ccc2c34)cc1]

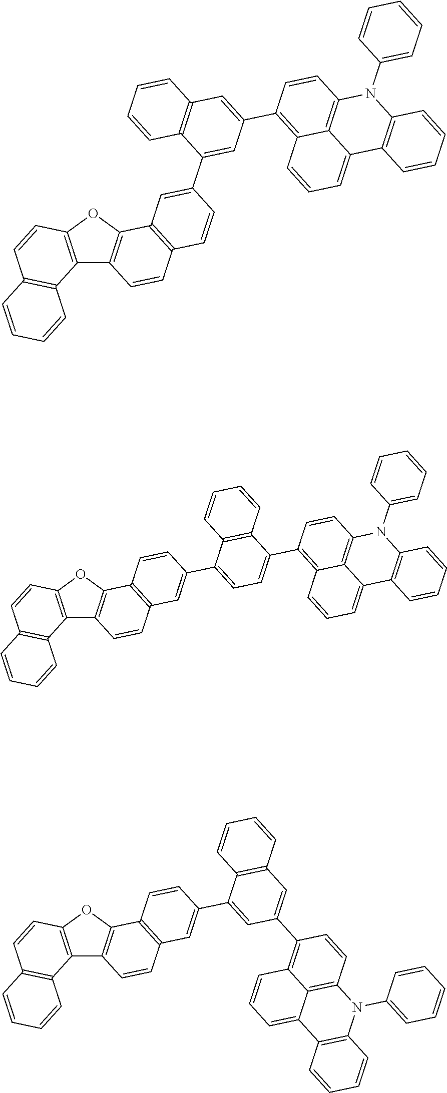 [SMILES: c1ccc(N2c3ccccc3-c3cccc4c(-c5cc(-c6ccc7ccc8c(oc9ccc%10ccccc%10c98)c7c6)c6ccccc6c5)ccc2c34)cc1 ; c1ccc(N2c3ccccc3-c3cccc4c(-c5ccc(-c6ccc7c(ccc8c7oc7ccc9ccccc9c78)c6)c6ccccc56)ccc2c34)cc1 ; c1ccc(N2c3ccccc3-c3cccc4c(-c5cc(-c6ccc7c(ccc8c7oc7ccc9ccccc9c78)c6)c6ccccc6c5)ccc2c34)cc1]

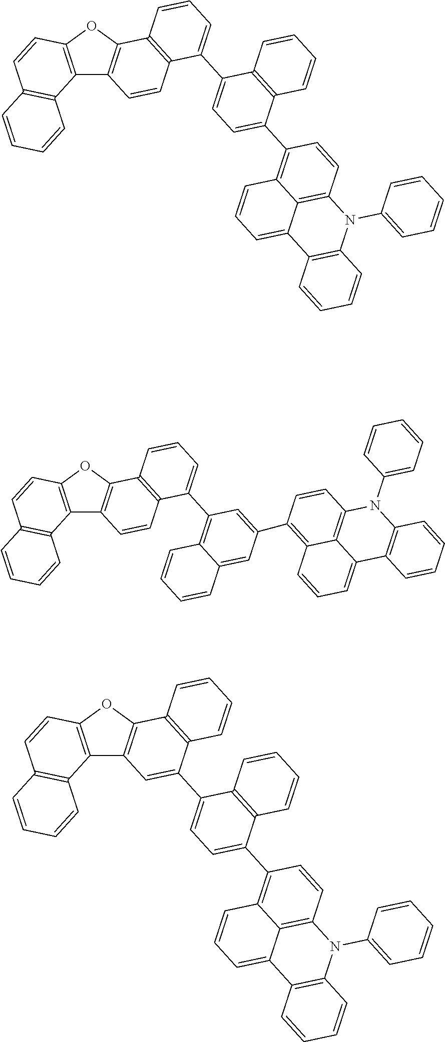 [SMILES: c1ccc(N2c3ccccc3-c3cccc4c(-c5ccc(-c6cccc7c6ccc6c7oc7ccc8ccccc8c76)c6ccccc56)ccc2c34)cc1 ; c1ccc(N2c3ccccc3-c3cccc4c(-c5cc(-c6cccc7c6ccc6c7oc7ccc8ccccc8c76)c6ccccc6c5)ccc2c34)cc1 ; c1ccc(N2c3ccccc3-c3cccc4c(-c5ccc(-c6cc7c(oc8ccc9ccccc9c87)c7ccccc67)c6ccccc56)ccc2c34)cc1]

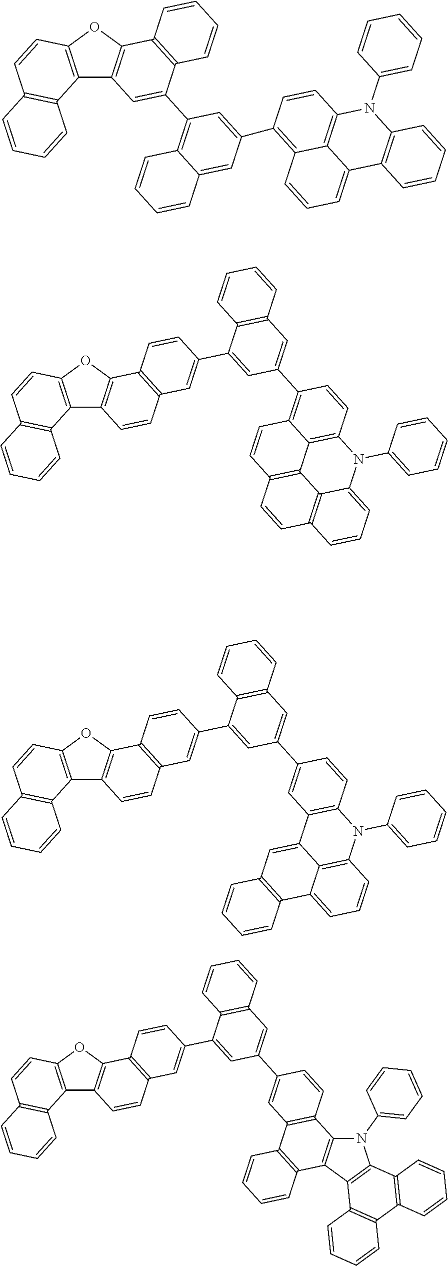

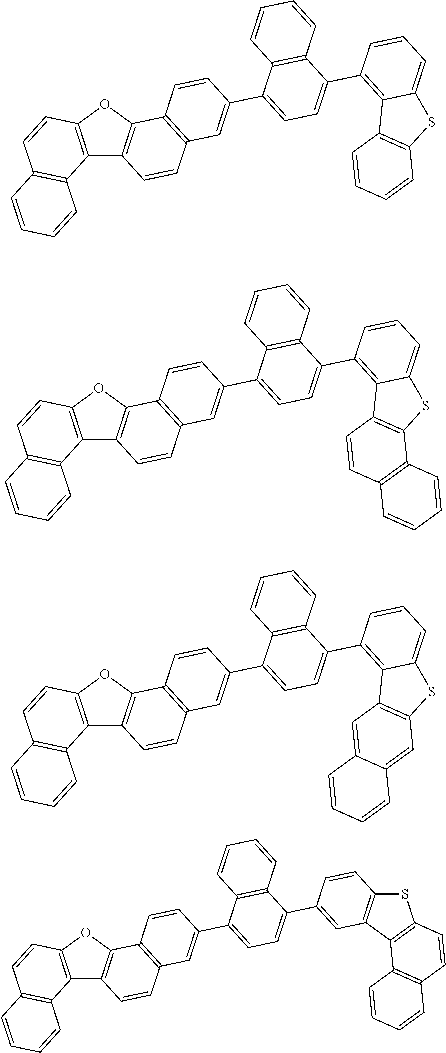 [SMILES: c1ccc2c(c1)ccc1oc3c4ccc(-c5ccc(-c6cccc7sc8ccccc8c67)c6ccccc56)cc4ccc3c12 ; c1ccc2c(c1)ccc1c2sc2cccc(-c3ccc(-c4ccc5c(ccc6c5oc5ccc7ccccc7c56)c4)c4ccccc34)c21 ; c1ccc2cc3c(cc2c1)sc1cccc(-c2ccc(-c4ccc5c(ccc6c5oc5ccc7ccccc7c56)c4)c4ccccc24)c13 ; c1ccc2c(c1)ccc1oc3c4ccc(-c5ccc(-c6ccc7sc8ccc9ccccc9c8c7c6)c6ccccc56)cc4ccc3c12]

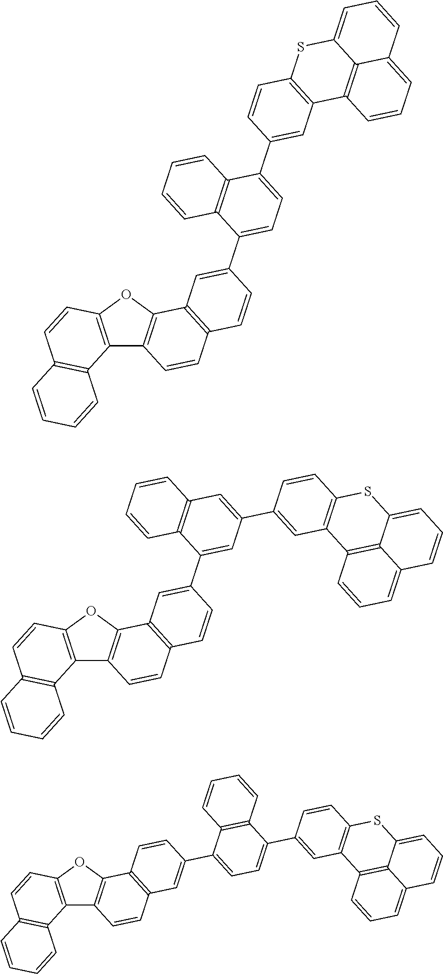 [SMILES: c1cc2c3c(cccc3c1)-c1cc(-c3ccc(-c4ccc5ccc6c(oc7ccc8ccccc8c76)c5c4)c4ccccc34)ccc1S2 ; c1ccc2c(-c3ccc4ccc5c(oc6ccc7ccccc7c65)c4c3)cc(-c3ccc4c(c3)-c3cccc5cccc(c35)S4)cc2c1 ; c1cc2c3c(cccc3c1)-c1cc(-c3ccc(-c4ccc5c(ccc6c5oc5ccc7ccccc7c56)c4)c4ccccc34)ccc1S2]

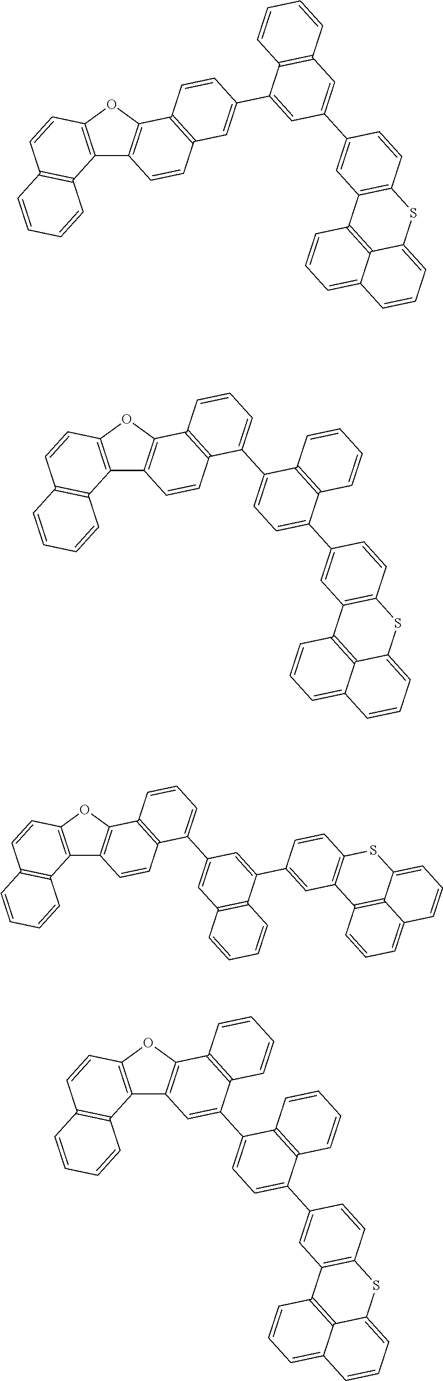 [SMILES: c1ccc2c(-c3ccc4c(ccc5c4oc4ccc6ccccc6c45)c3)cc(-c3ccc4c(c3)-c3cccc5cccc(c35)S4)cc2c1 ; c1cc2c3c(cccc3c1)-c1cc(-c3ccc(-c4cccc5c4ccc4c5oc5ccc6ccccc6c54)c4ccccc34)ccc1S2 ; c1ccc2c(-c3ccc4c(c3)-c3cccc5cccc(c35)S4)cc(-c3cccc4c3ccc3c4oc4ccc5ccccc5c43)cc2c1 ; c1cc2c3c(cccc3c1)-c1cc(-c3ccc(-c4cc5c(oc6ccc7ccccc7c65)c5ccccc45)c4ccccc34)ccc1S2]

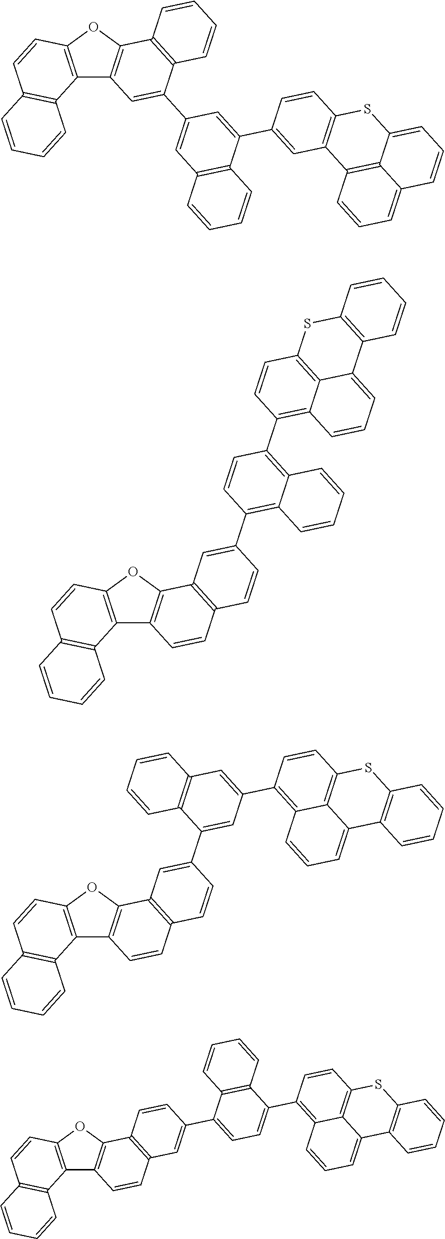 [SMILES: c1ccc2c(-c3ccc4c(c3)-c3cccc5cccc(c35)S4)cc(-c3cc4c(oc5ccc6ccccc6c54)c4ccccc34)cc2c1 ; c1ccc2c(c1)Sc1ccc(-c3ccc(-c4ccc5ccc6c(oc7ccc8ccccc8c76)c5c4)c4ccccc34)c3cccc-2c13 ; c1ccc2c(c1)Sc1ccc(-c3cc(-c4ccc5ccc6c(oc7ccc8ccccc8c76)c5c4)c4ccccc4c3)c3cccc-2c13 ; c1ccc2c(c1)Sc1ccc(-c3ccc(-c4ccc5c(ccc6c5oc5ccc7ccccc7c56)c4)c4ccccc34)c3cccc-2c13]

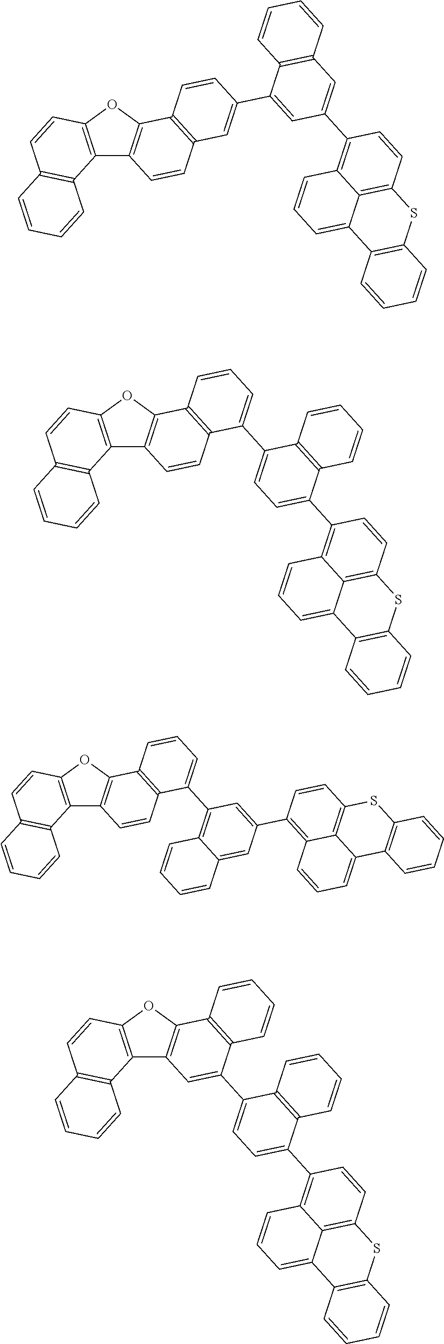 [SMILES: c1ccc2c(c1)Sc1ccc(-c3cc(-c4ccc5c(ccc6c5oc5ccc7ccccc7c56)c4)c4ccccc4c3)c3cccc-2c13 ; c1ccc2c(c1)Sc1ccc(-c3ccc(-c4cccc5c4ccc4c5oc5ccc6ccccc6c54)c4ccccc34)c3cccc-2c13 ; c1ccc2c(c1)Sc1ccc(-c3cc(-c4cccc5c4ccc4c5oc5ccc6ccccc6c54)c4ccccc4c3)c3cccc-2c13 ; c1ccc2c(c1)Sc1ccc(-c3ccc(-c4cc5c(oc6ccc7ccccc7c65)c5ccccc45)c4ccccc34)c3cccc-2c13]

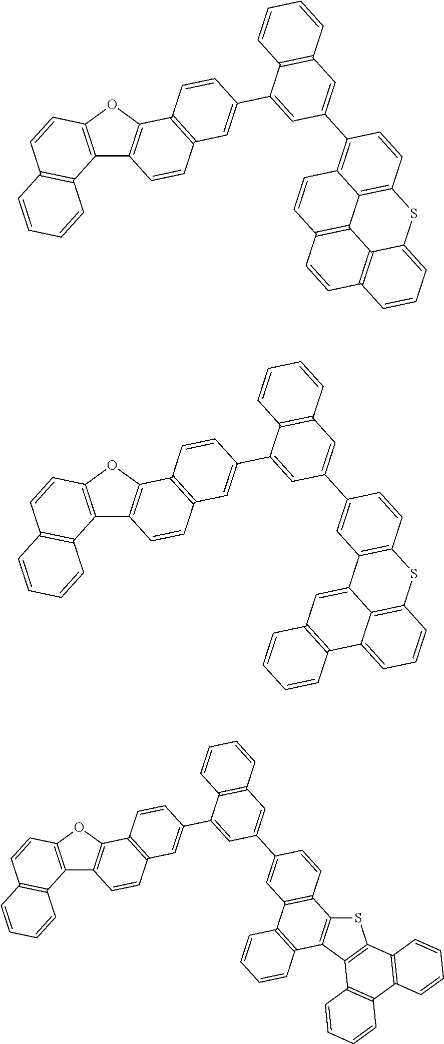 [SMILES: c1ccc2c(-c3ccc4c(ccc5c4oc4ccc6ccccc6c45)c3)cc(-c3ccc4c5c3ccc3ccc6cccc(c6c35)S4)cc2c1 ; c1ccc2c(-c3ccc4c(ccc5c4oc4ccc6ccccc6c45)c3)cc(-c3ccc4c(c3)-c3cc5ccccc5c5cccc(c35)S4)cc2c1 ; c1ccc2c(-c3ccc4c(ccc5c4oc4ccc6ccccc6c45)c3)cc(-c3ccc4c(c3)c3ccccc3c3c4sc4c5ccccc5c5ccccc5c43)cc2c1]

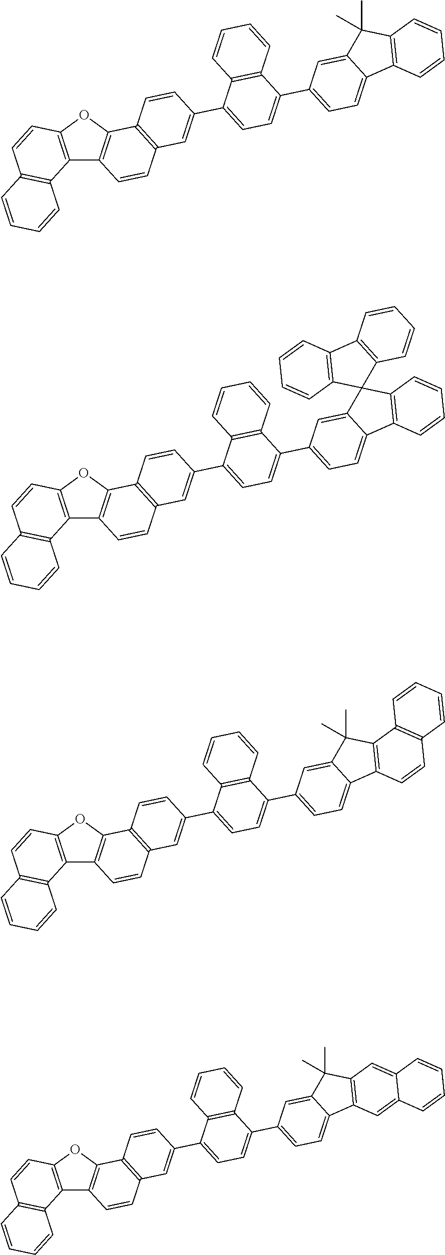 [SMILES: CC1(C)c2ccccc2-c2ccc(-c3ccc(-c4ccc5c(ccc6c5oc5ccc7ccccc7c56)c4)c4ccccc34)cc21 ; c1ccc2c(c1)-c1ccccc1C21c2ccccc2-c2ccc(-c3ccc(-c4ccc5c(ccc6c5oc5ccc7ccccc7c56)c4)c4ccccc34)cc21 ; CC1(C)c2cc(-c3ccc(-c4ccc5c(ccc6c5oc5ccc7ccccc7c56)c4)c4ccccc34)ccc2-c2ccc3ccccc3c21 ; CC1(C)c2cc(-c3ccc(-c4ccc5c(ccc6c5oc5ccc7ccccc7c56)c4)c4ccccc34)ccc2-c2cc3ccccc3cc21]

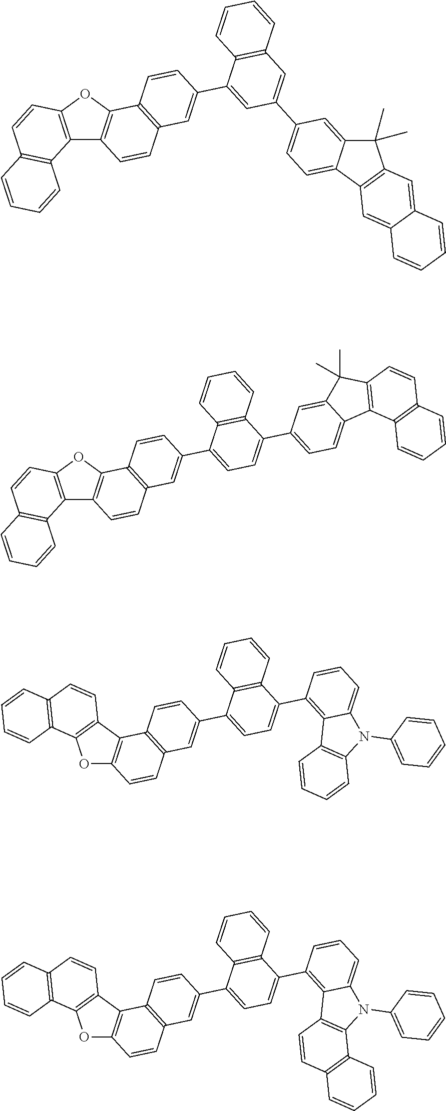 [SMILES: CC1(C)c2cc(-c3cc(-c4ccc5c(ccc6c5oc5ccc7ccccc7c56)c4)c4ccccc4c3)ccc2-c2cc3ccccc3cc21 ; CC1(C)c2cc(-c3ccc(-c4ccc5c(ccc6c5oc5ccc7ccccc7c56)c4)c4ccccc34)ccc2-c2c1ccc1ccccc21 ; c1ccc(-n2c3ccccc3c3c(-c4ccc(-c5ccc6c(ccc7oc8c9ccccc9ccc8c76)c5)c5ccccc45)cccc32)cc1 ; c1ccc(-n2c3cccc(-c4ccc(-c5ccc6c(ccc7oc8c9ccccc9ccc8c76)c5)c5ccccc45)c3c3ccc4ccccc4c32)cc1]

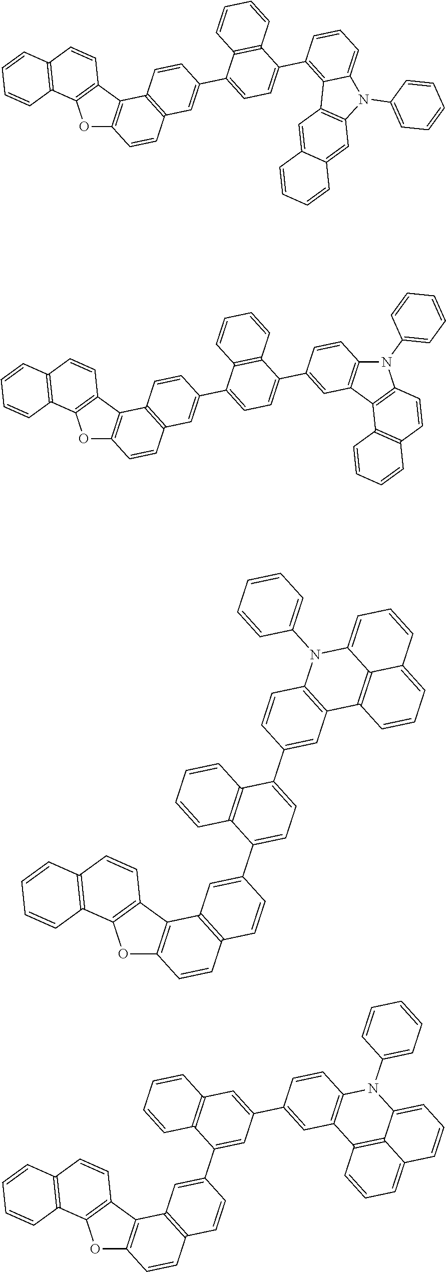 [SMILES: c1ccc(-n2c3cc4ccccc4cc3c3c(-c4ccc(-c5ccc6c(ccc7oc8c9ccccc9ccc8c76)c5)c5ccccc45)cccc32)cc1 ; c1ccc(-n2c3ccc(-c4ccc(-c5ccc6c(ccc7oc8c9ccccc9ccc8c76)c5)c5ccccc45)cc3c3c4ccccc4ccc32)cc1 ; c1ccc(N2c3ccc(-c4ccc(-c5ccc6ccc7oc8c9ccccc9ccc8c7c6c5)c5ccccc45)cc3-c3cccc4cccc2c34)cc1 ; c1ccc(N2c3ccc(-c4cc(-c5ccc6ccc7oc8c9ccccc9ccc8c7c6c5)c5ccccc5c4)cc3-c3cccc4cccc2c34)cc1]

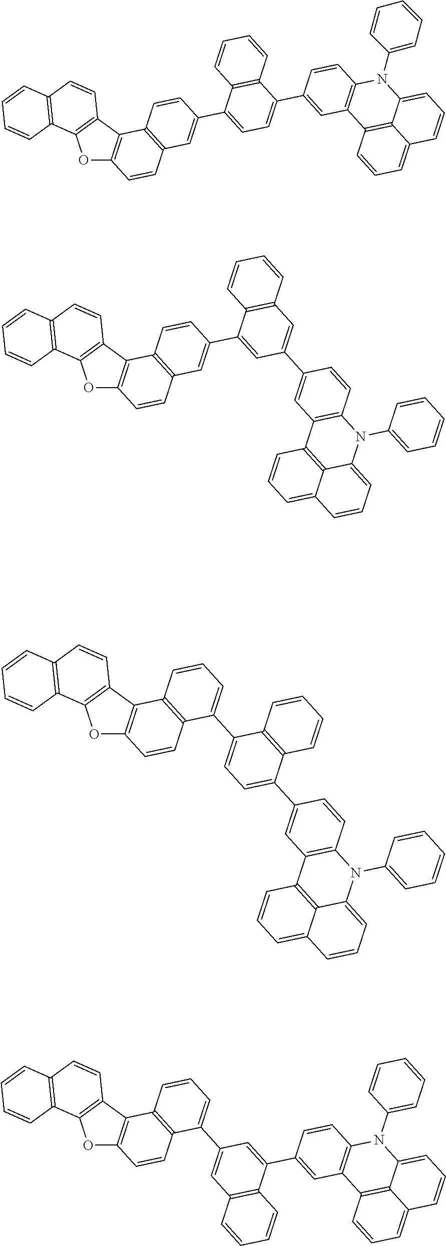 [SMILES: c1ccc(N2c3ccc(-c4ccc(-c5ccc6c(ccc7oc8c9ccccc9ccc8c76)c5)c5ccccc45)cc3-c3cccc4cccc2c34)cc1 ; c1ccc(N2c3ccc(-c4cc(-c5ccc6c(ccc7oc8c9ccccc9ccc8c76)c5)c5ccccc5c4)cc3-c3cccc4cccc2c34)cc1 ; c1ccc(N2c3ccc(-c4ccc(-c5cccc6c5ccc5oc7c8ccccc8ccc7c56)c5ccccc45)cc3-c3cccc4cccc2c34)cc1 ; c1ccc(N2c3ccc(-c4cc(-c5cccc6c5ccc5oc7c8ccccc8ccc7c56)cc5ccccc45)cc3-c3cccc4cccc2c34)cc1]

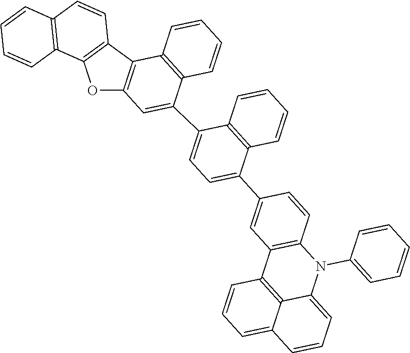 [SMILES: c1ccc(N2c3ccc(-c4ccc(-c5cc6oc7c8ccccc8ccc7c6c6ccccc56)c5ccccc45)cc3-c3cccc4cccc2c34)cc1]

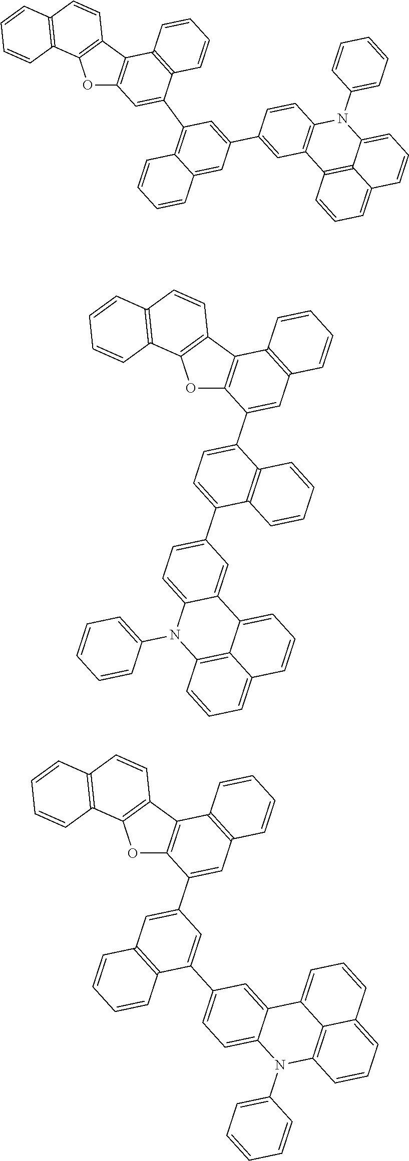 [SMILES: c1ccc(N2c3ccc(-c4cc(-c5cc6oc7c8ccccc8ccc7c6c6ccccc56)c5ccccc5c4)cc3-c3cccc4cccc2c34)cc1 ; c1ccc(N2c3ccc(-c4ccc(-c5cc6ccccc6c6c5oc5c7ccccc7ccc56)c5ccccc45)cc3-c3cccc4cccc2c34)cc1 ; c1ccc(N2c3ccc(-c4cc(-c5cc6ccccc6c6c5oc5c7ccccc7ccc56)cc5ccccc45)cc3-c3cccc4cccc2c34)cc1]

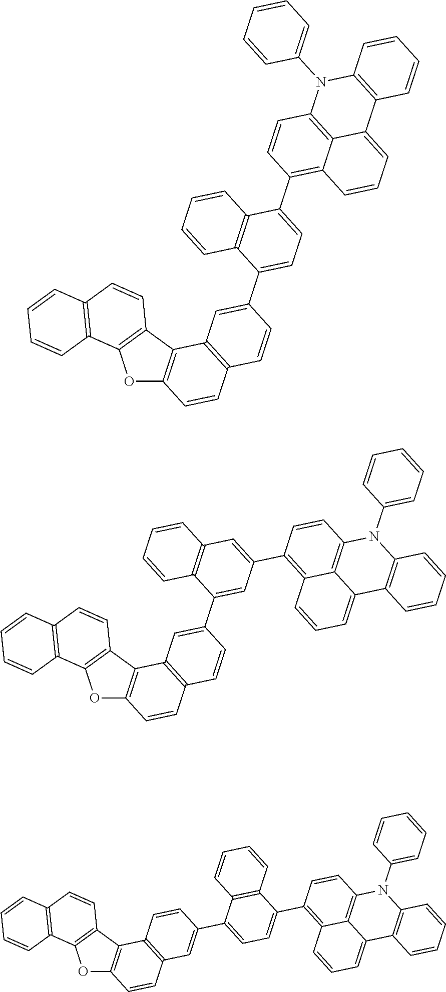 [SMILES: c1ccc(N2c3ccccc3-c3cccc4c(-c5ccc(-c6ccc7ccc8oc9c%10ccccc%10ccc9c8c7c6)c6ccccc56)ccc2c34)cc1 ; c1ccc(N2c3ccccc3-c3cccc4c(-c5cc(-c6ccc7ccc8oc9c%10ccccc%10ccc9c8c7c6)c6ccccc6c5)ccc2c34)cc1 ; c1ccc(N2c3ccccc3-c3cccc4c(-c5ccc(-c6ccc7c(ccc8oc9c%10ccccc%10ccc9c87)c6)c6ccccc56)ccc2c34)cc1]

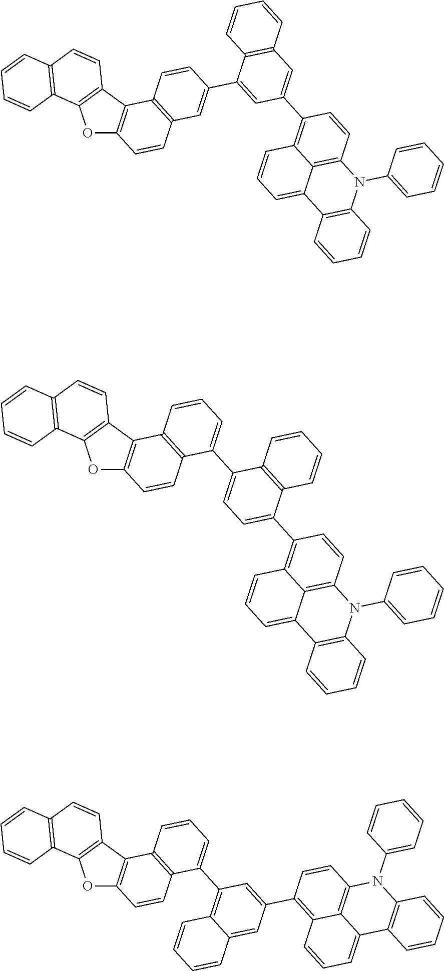 [SMILES: c1ccc(N2c3ccccc3-c3cccc4c(-c5cc(-c6ccc7c(ccc8oc9c%10ccccc%10ccc9c87)c6)c6ccccc6c5)ccc2c34)cc1 ; c1ccc(N2c3ccccc3-c3cccc4c(-c5ccc(-c6cccc7c6ccc6oc8c9ccccc9ccc8c67)c6ccccc56)ccc2c34)cc1 ; c1ccc(N2c3ccccc3-c3cccc4c(-c5cc(-c6cccc7c6ccc6oc8c9ccccc9ccc8c67)c6ccccc6c5)ccc2c34)cc1]

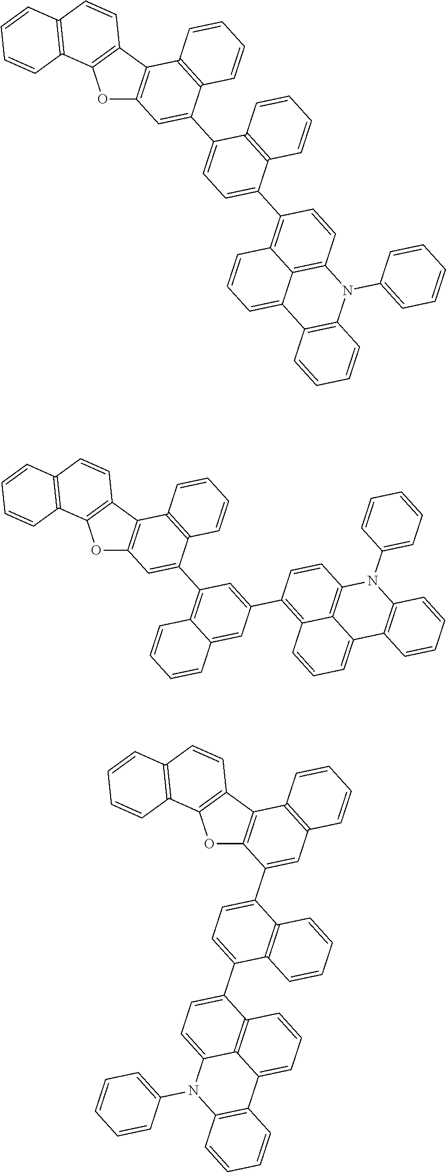 [SMILES: c1ccc(N2c3ccccc3-c3cccc4c(-c5ccc(-c6cc7oc8c9ccccc9ccc8c7c7ccccc67)c6ccccc56)ccc2c34)cc1 ; c1ccc(N2c3ccccc3-c3cccc4c(-c5cc(-c6cc7oc8c9ccccc9ccc8c7c7ccccc67)c6ccccc6c5)ccc2c34)cc1 ; c1ccc(N2c3ccccc3-c3cccc4c(-c5ccc(-c6cc7ccccc7c7c6oc6c8ccccc8ccc67)c6ccccc56)ccc2c34)cc1]

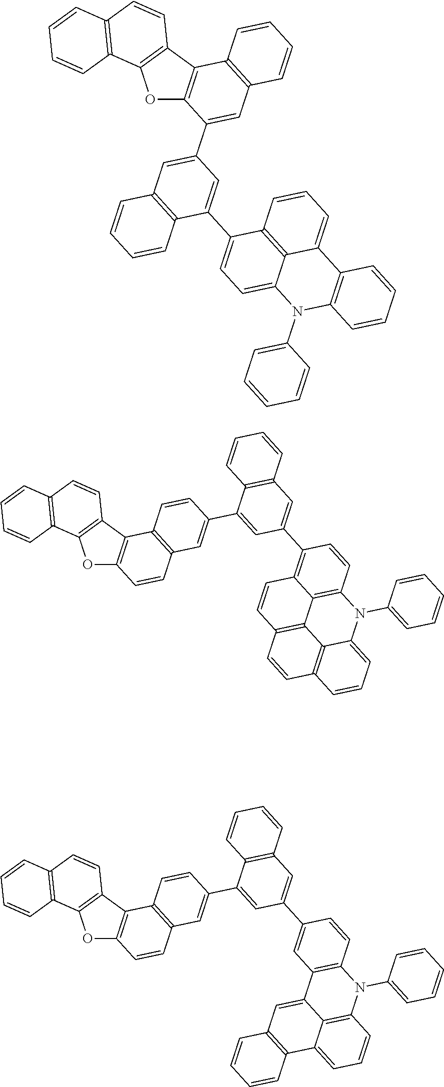

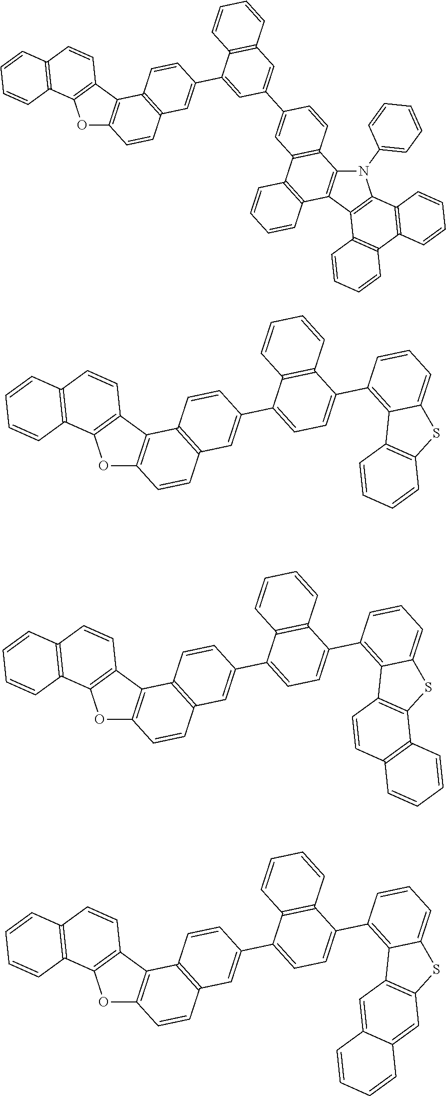 [SMILES: c1ccc(-n2c3c4ccccc4c4ccccc4c3c3c4ccccc4c4cc(-c5cc(-c6ccc7c(ccc8oc9c%10ccccc%10ccc9c87)c6)c6ccccc6c5)ccc4c32)cc1 ; c1ccc2c(c1)ccc1c2oc2ccc3cc(-c4ccc(-c5cccc6sc7ccccc7c56)c5ccccc45)ccc3c21 ; c1ccc2c(c1)ccc1c2oc2ccc3cc(-c4ccc(-c5cccc6sc7c8ccccc8ccc7c56)c5ccccc45)ccc3c21 ; c1ccc2cc3c(cc2c1)sc1cccc(-c2ccc(-c4ccc5c(ccc6oc7c8ccccc8ccc7c65)c4)c4ccccc24)c13]

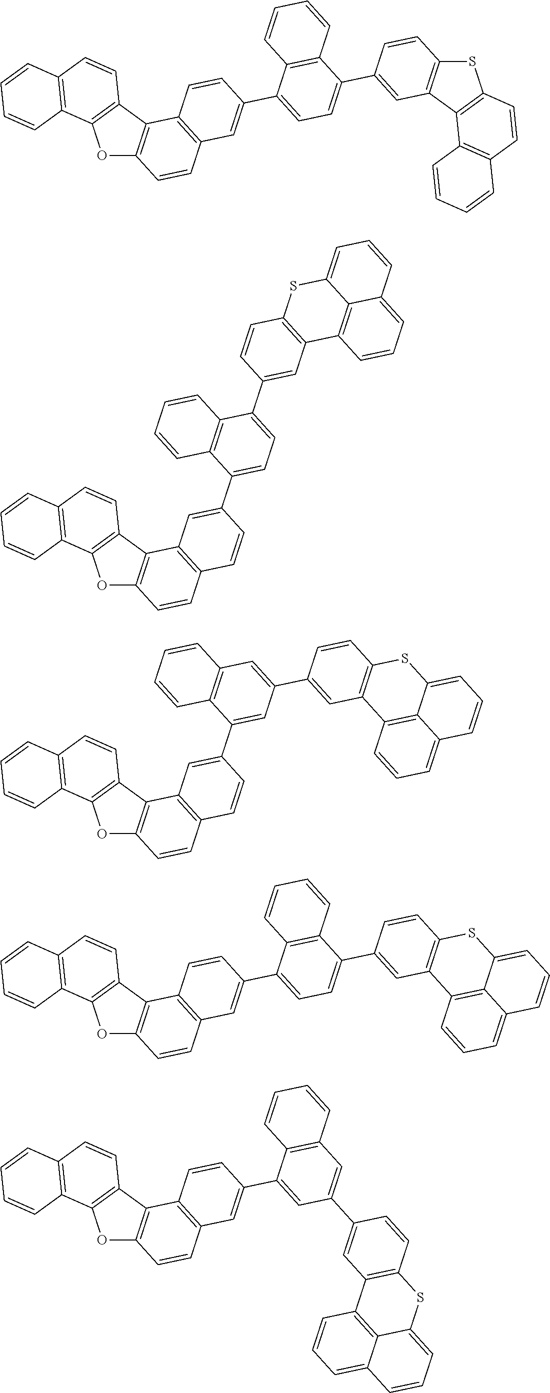

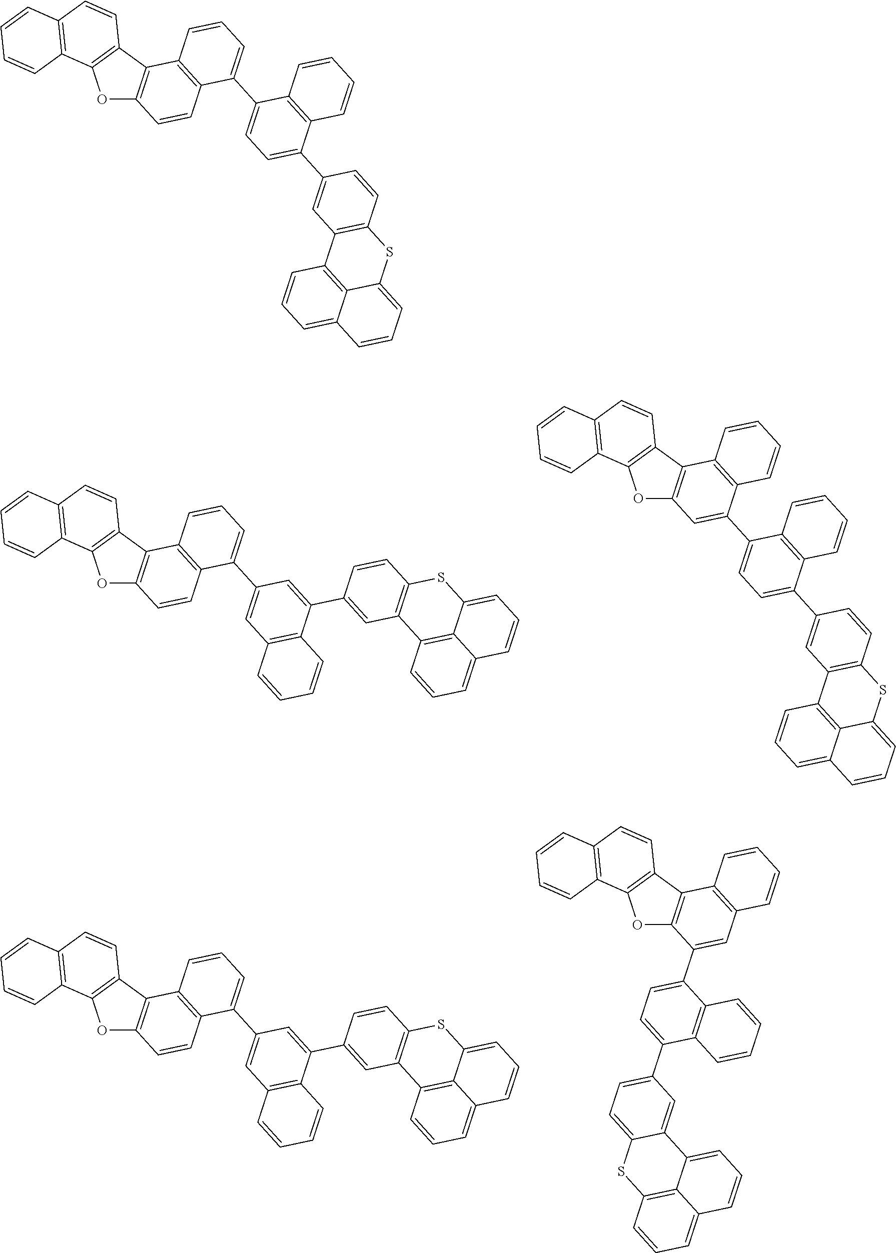 [SMILES: c1cc2c3c(cccc3c1)-c1cc(-c3ccc(-c4cccc5c4ccc4oc6c7ccccc7ccc6c45)c4ccccc34)ccc1S2 ; c1ccc2c(-c3ccc4c(c3)-c3cccc5cccc(c35)S4)cc(-c3cccc4c3ccc3oc5c6ccccc6ccc5c34)cc2c1 ; c1cc2c3c(cccc3c1)-c1cc(-c3ccc(-c4cc5oc6c7ccccc7ccc6c5c5ccccc45)c4ccccc34)ccc1S2 ; c1ccc2c(-c3ccc4c(c3)-c3cccc5cccc(c35)S4)cc(-c3cccc4c3ccc3oc5c6ccccc6ccc5c34)cc2c1 ; c1cc2c3c(cccc3c1)-c1cc(-c3ccc(-c4cc5ccccc5c5c4oc4c6ccccc6ccc45)c4ccccc34)ccc1S2]

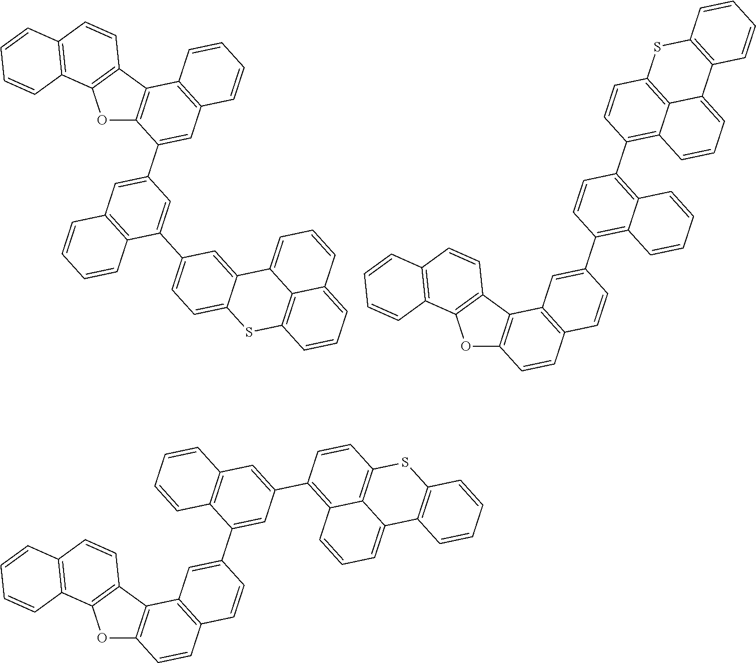

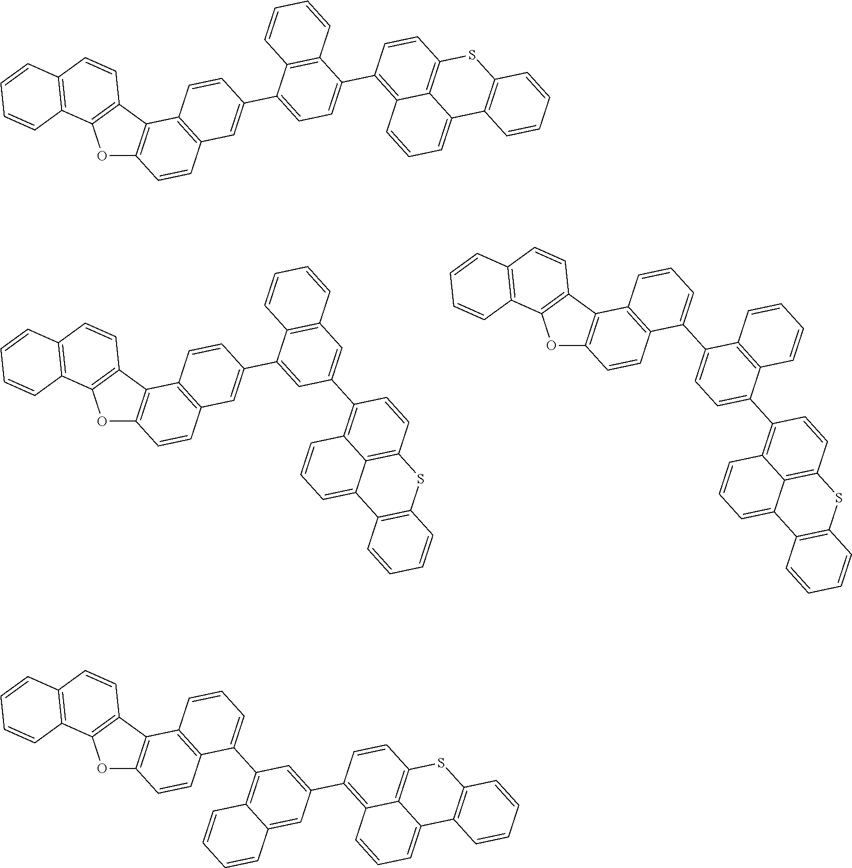 [SMILES: c1ccc2c(c1)Sc1ccc(-c3ccc(-c4ccc5c(ccc6oc7c8ccccc8ccc7c65)c4)c4ccccc34)c3cccc-2c13 ; c1ccc2c(c1)Sc1ccc(-c3cc(-c4ccc5c(ccc6oc7c8ccccc8ccc7c65)c4)c4ccccc4c3)c3cccc-2c13 ; c1ccc2c(c1)Sc1ccc(-c3ccc(-c4cccc5c4ccc4oc6c7ccccc7ccc6c45)c4ccccc34)c3cccc-2c13 ; c1ccc2c(c1)Sc1ccc(-c3cc(-c4cccc5c4ccc4oc6c7ccccc7ccc6c45)c4ccccc4c3)c3cccc-2c13]

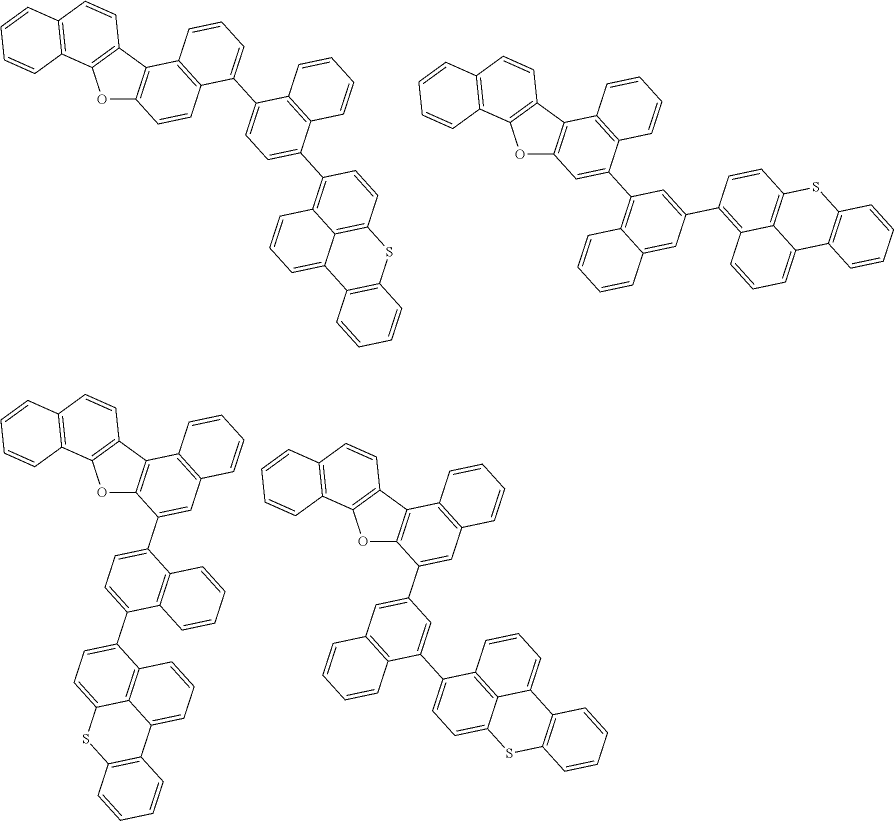

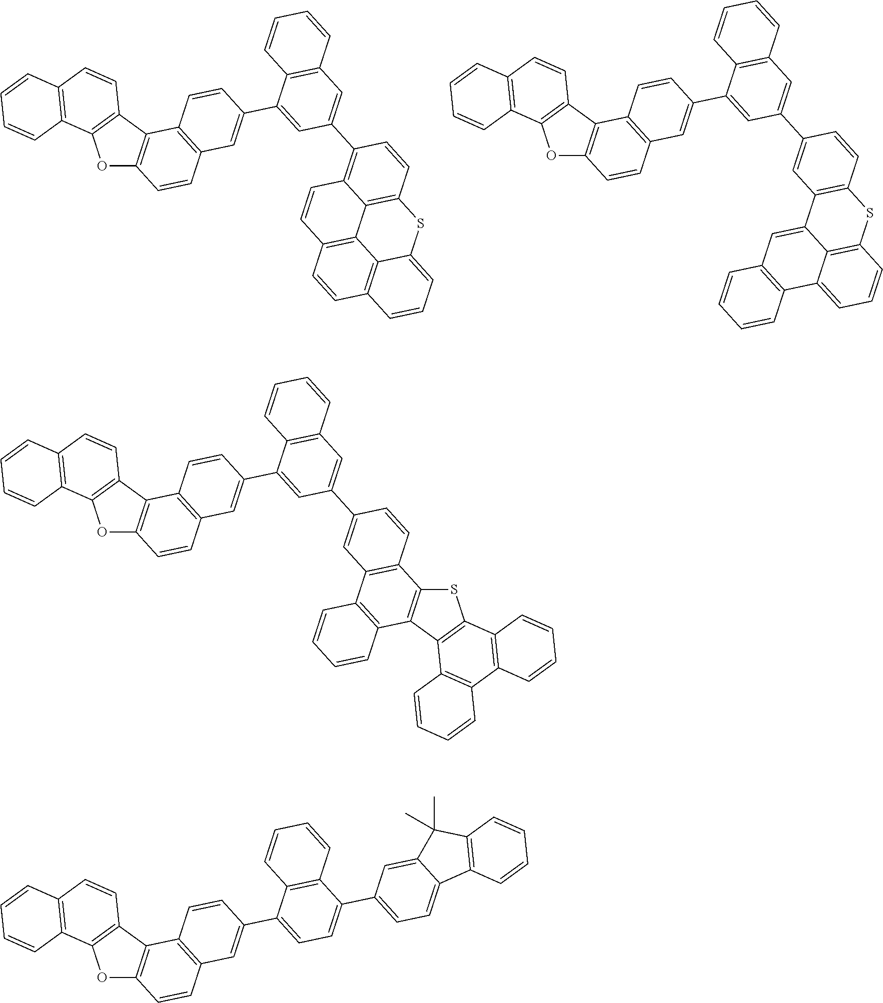 [SMILES: c1ccc2c(-c3ccc4c(ccc5oc6c7ccccc7ccc6c54)c3)cc(-c3ccc4c5c3ccc3ccc6cccc(c6c35)S4)cc2c1 ; c1ccc2c(-c3ccc4c(ccc5oc6c7ccccc7ccc6c54)c3)cc(-c3ccc4c(c3)-c3cc5ccccc5c5cccc(c35)S4)cc2c1 ; c1ccc2c(-c3ccc4c(ccc5oc6c7ccccc7ccc6c54)c3)cc(-c3ccc4c(c3)c3ccccc3c3c4sc4c5ccccc5c5ccccc5c43)cc2c1 ; CC1(C)c2ccccc2-c2ccc(-c3ccc(-c4ccc5c(ccc6oc7c8ccccc8ccc7c65)c4)c4ccccc34)cc21]

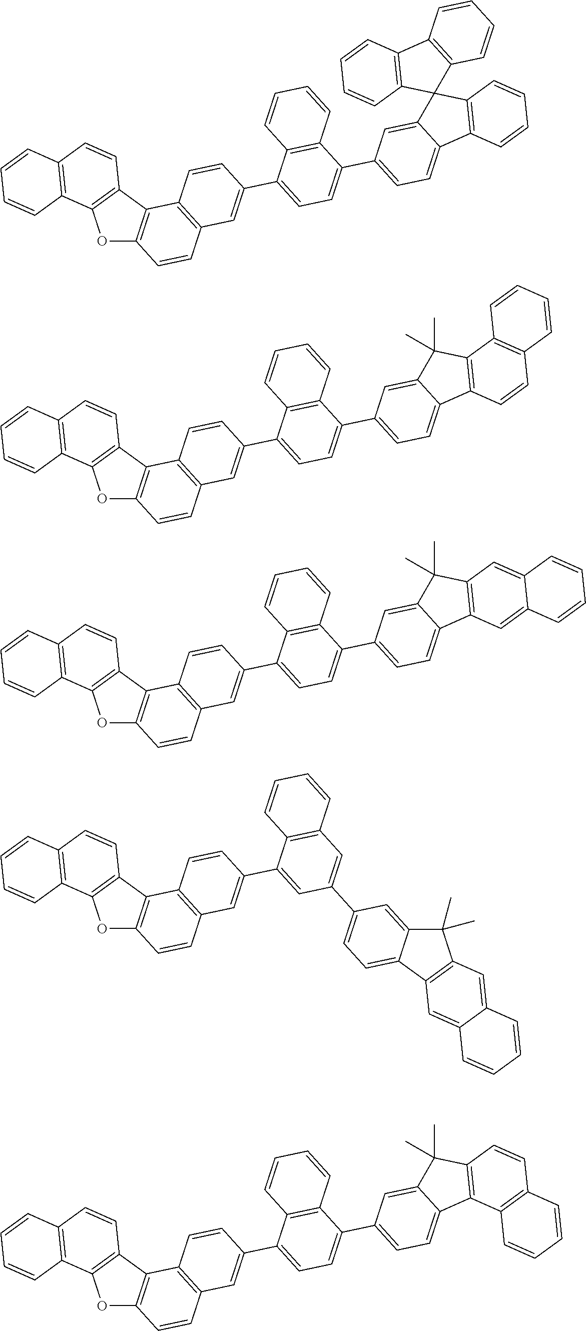 [SMILES: c1ccc2c(c1)-c1ccccc1C21c2ccccc2-c2ccc(-c3ccc(-c4ccc5c(ccc6oc7c8ccccc8ccc7c65)c4)c4ccccc34)cc21 ; CC1(C)c2cc(-c3ccc(-c4ccc5c(ccc6oc7c8ccccc8ccc7c65)c4)c4ccccc34)ccc2-c2ccc3ccccc3c21 ; CC1(C)c2cc(-c3ccc(-c4ccc5c(ccc6oc7c8ccccc8ccc7c65)c4)c4ccccc34)ccc2-c2cc3ccccc3cc21 ; CC1(C)c2cc(-c3cc(-c4ccc5c(ccc6oc7c8ccccc8ccc7c65)c4)c4ccccc4c3)ccc2-c2cc3ccccc3cc21 ; CC1(C)c2cc(-c3ccc(-c4ccc5c(ccc6oc7c8ccccc8ccc7c65)c4)c4ccccc34)ccc2-c2c1ccc1ccccc21]

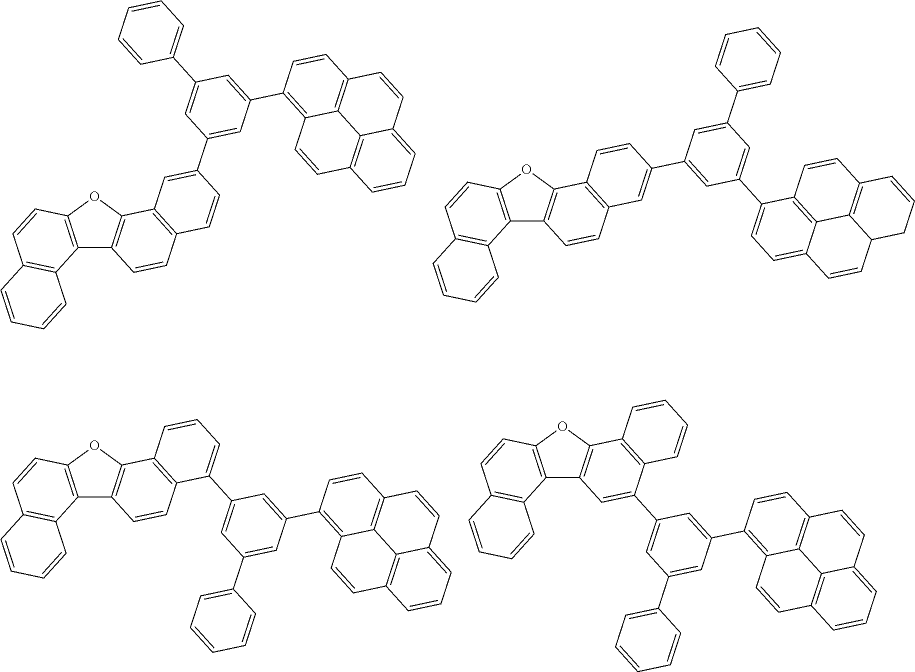

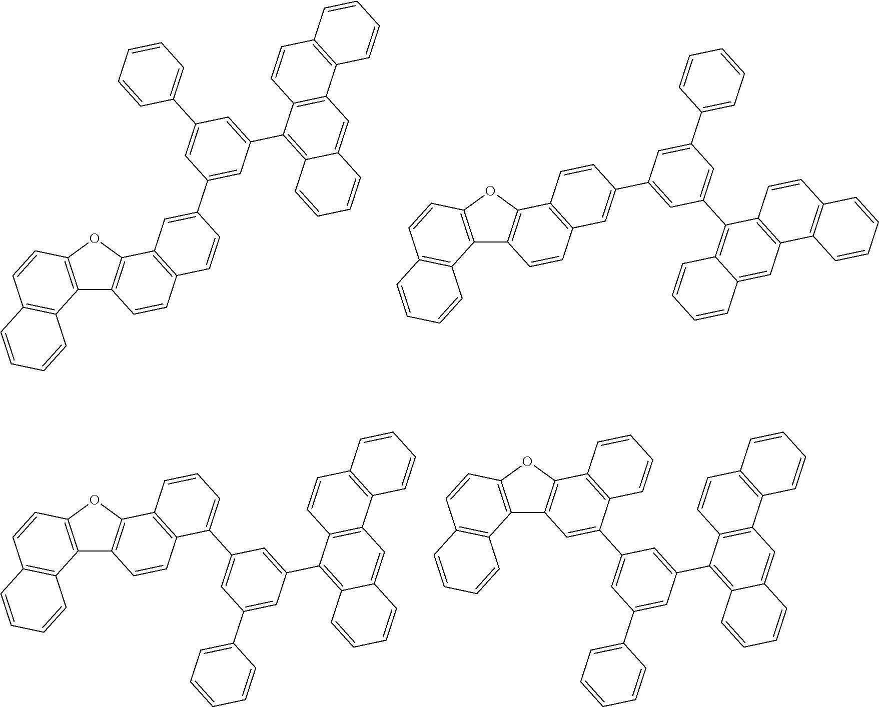

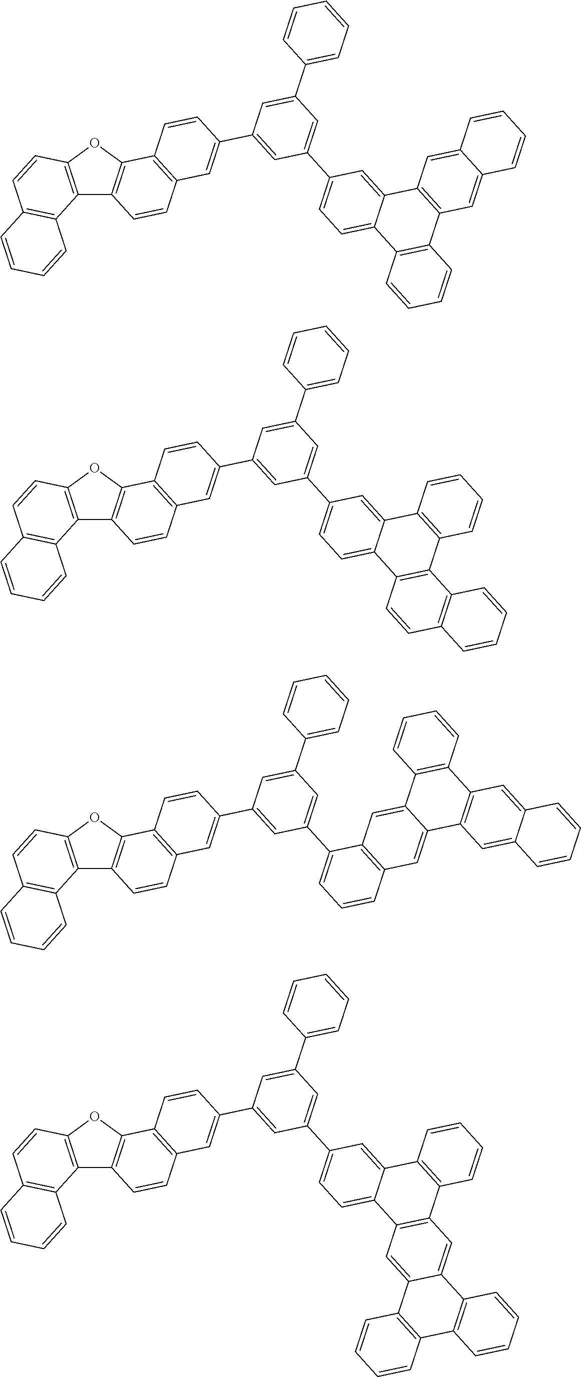 [SMILES: c1ccc(-c2cc(-c3ccc4c(ccc5c4oc4ccc6ccccc6c45)c3)cc(-c3ccc4c5ccccc5c5cc6ccccc6cc5c4c3)c2)cc1 ; c1ccc(-c2cc(-c3ccc4c(ccc5c4oc4ccc6ccccc6c45)c3)cc(-c3ccc4c(c3)c3ccccc3c3c5ccccc5ccc43)c2)cc1 ; c1ccc(-c2cc(-c3ccc4c(ccc5c4oc4ccc6ccccc6c45)c3)cc(-c3cccc4cc5c6cc7ccccc7cc6c6ccccc6c5cc34)c2)cc1 ; c1ccc(-c2cc(-c3ccc4c(ccc5c4oc4ccc6ccccc6c45)c3)cc(-c3ccc4c(c3)c3ccccc3c3cc5c6ccccc6c6ccccc6c5cc43)c2)cc1]

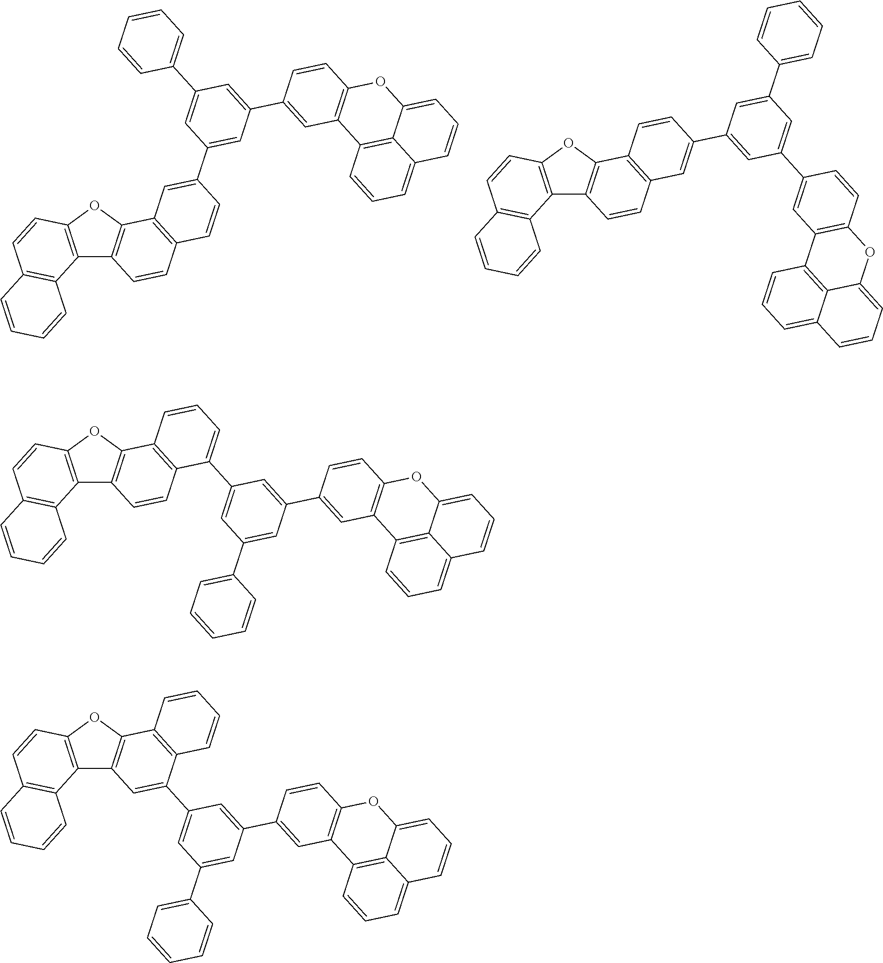

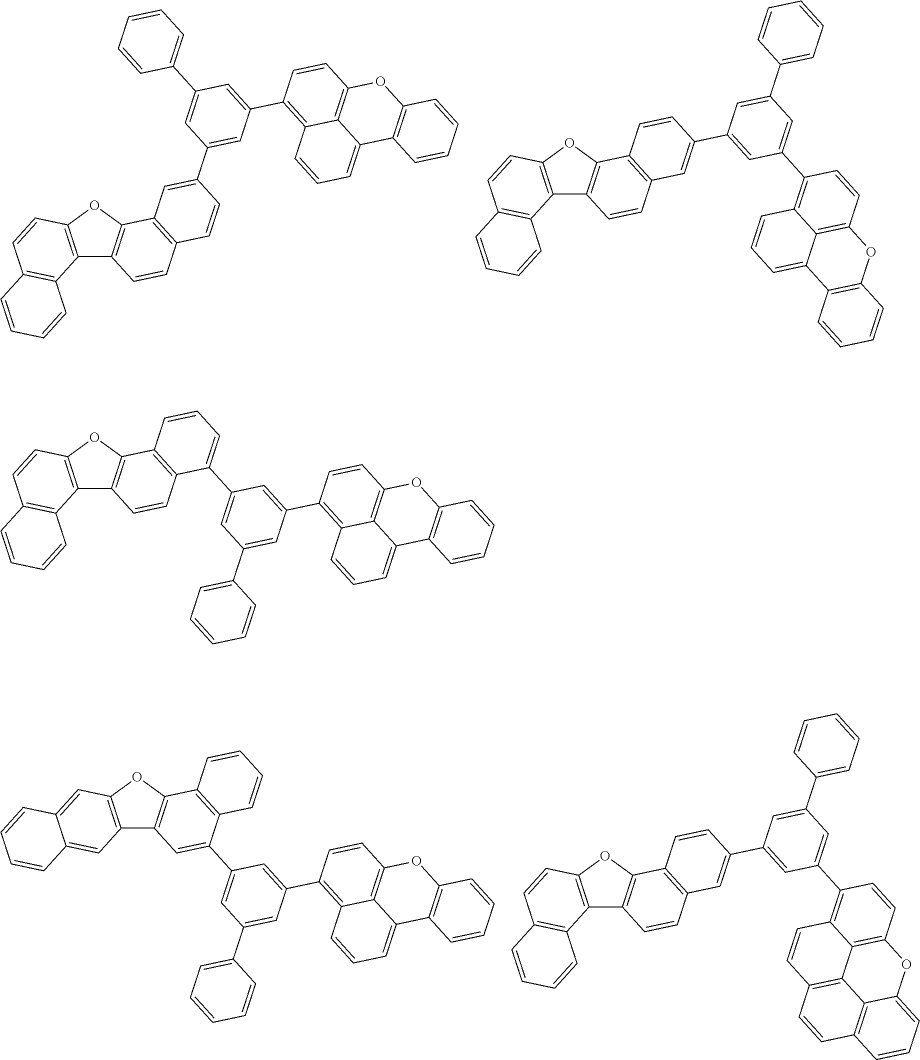

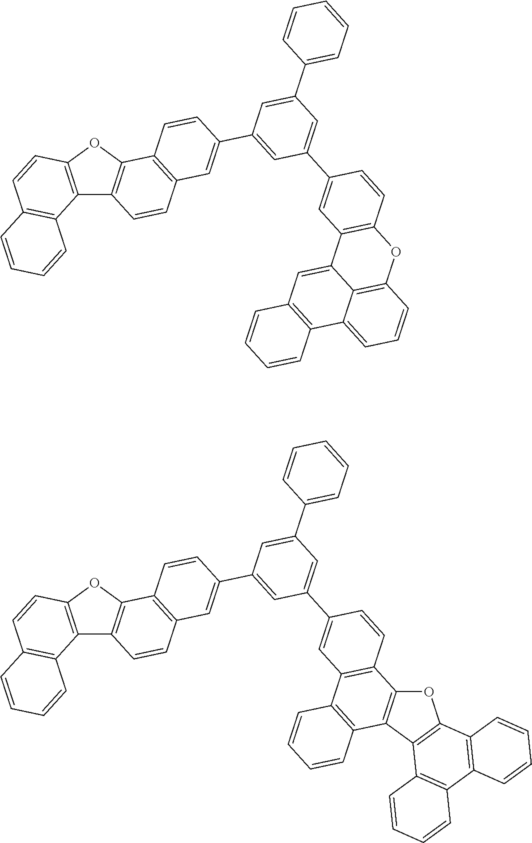 [SMILES: c1ccc(-c2cc(-c3ccc4c(c3)-c3cc5ccccc5c5cccc(c35)O4)cc(-c3ccc4c(ccc5c4oc4ccc6ccccc6c45)c3)c2)cc1 ; c1ccc(-c2cc(-c3ccc4c(ccc5c4oc4ccc6ccccc6c45)c3)cc(-c3ccc4c(c3)c3ccccc3c3c4oc4c5ccccc5c5ccccc5c43)c2)cc1]

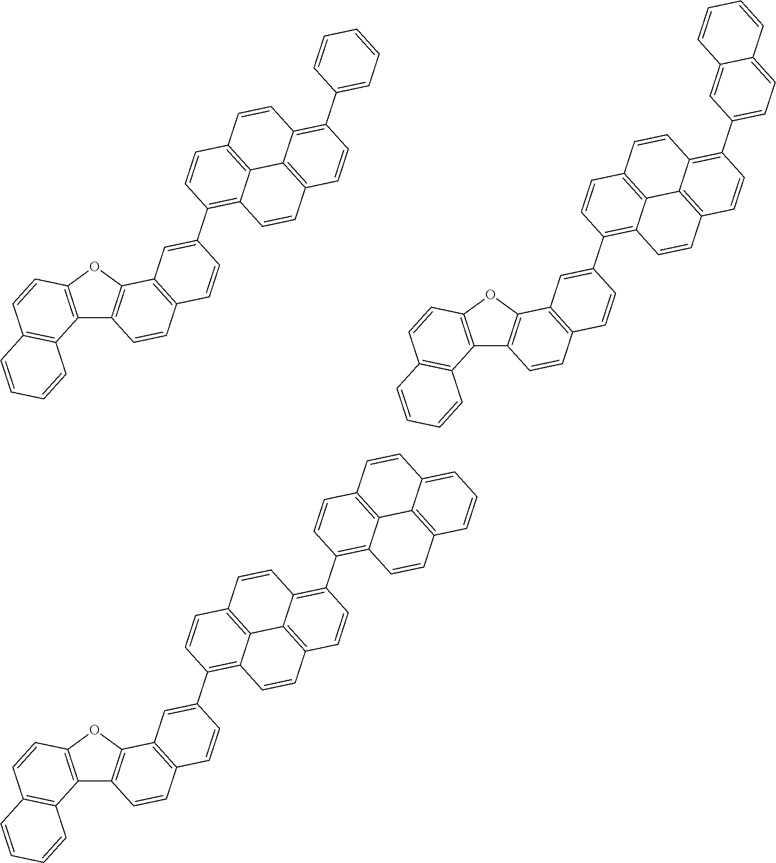

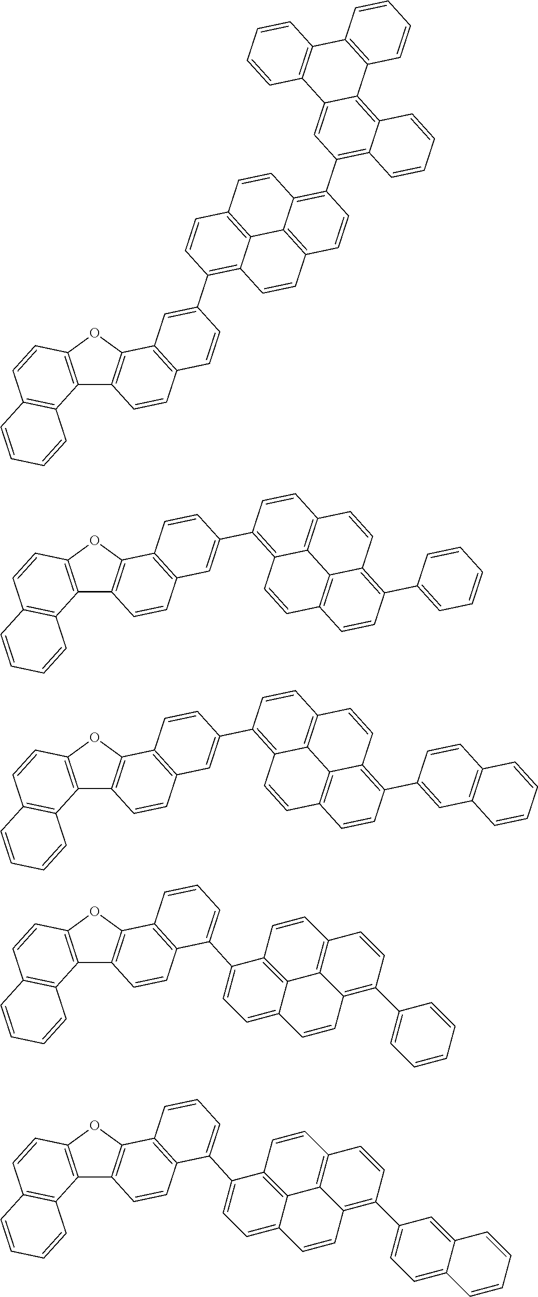 [SMILES: c1ccc2c(c1)ccc1oc3c4cc(-c5ccc6ccc7c(-c8cc9c%10ccccc%10c%10ccccc%10c9c9ccccc89)ccc8ccc5c6c87)ccc4ccc3c12 ; c1ccc(-c2ccc3ccc4c(-c5ccc6c(ccc7c6oc6ccc8ccccc8c67)c5)ccc5ccc2c3c54)cc1 ; c1ccc2cc(-c3ccc4ccc5c(-c6ccc7c(ccc8c7oc7ccc9ccccc9c78)c6)ccc6ccc3c4c65)ccc2c1 ; c1ccc(-c2ccc3ccc4c(-c5cccc6c5ccc5c6oc6ccc7ccccc7c65)ccc5ccc2c3c54)cc1 ; c1ccc2cc(-c3ccc4ccc5c(-c6cccc7c6ccc6c7oc7ccc8ccccc8c76)ccc6ccc3c4c65)ccc2c1]

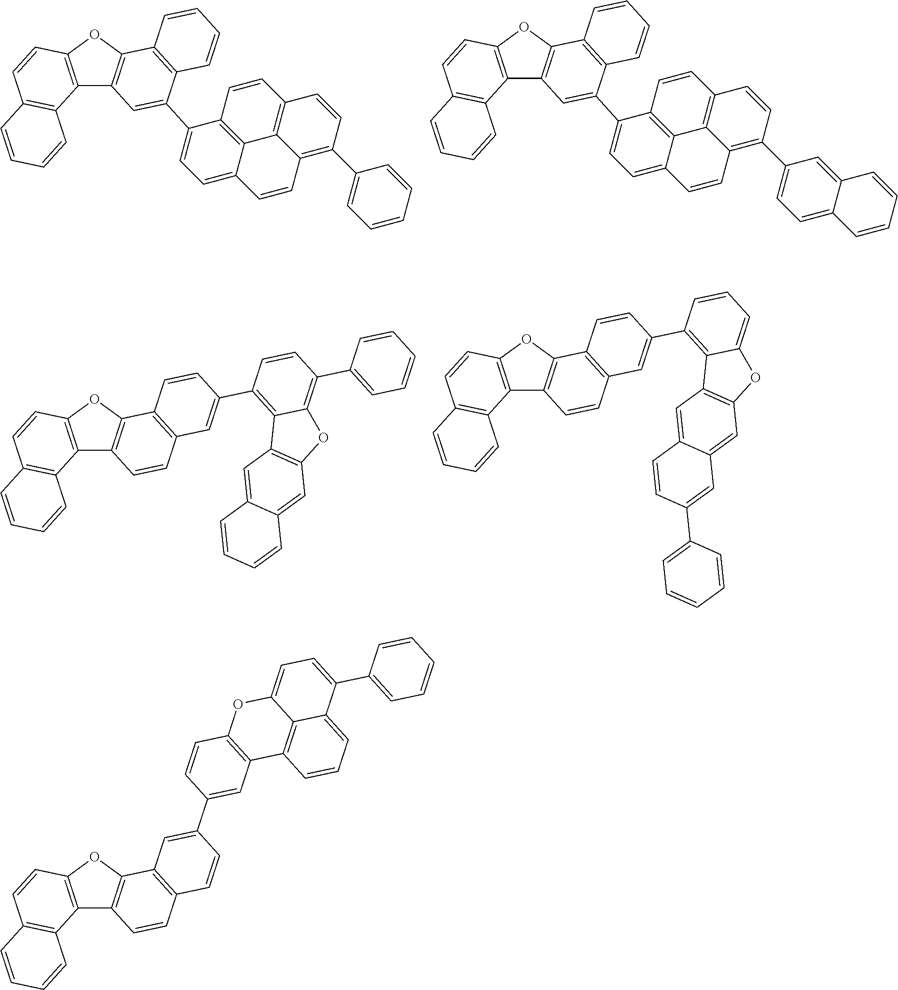

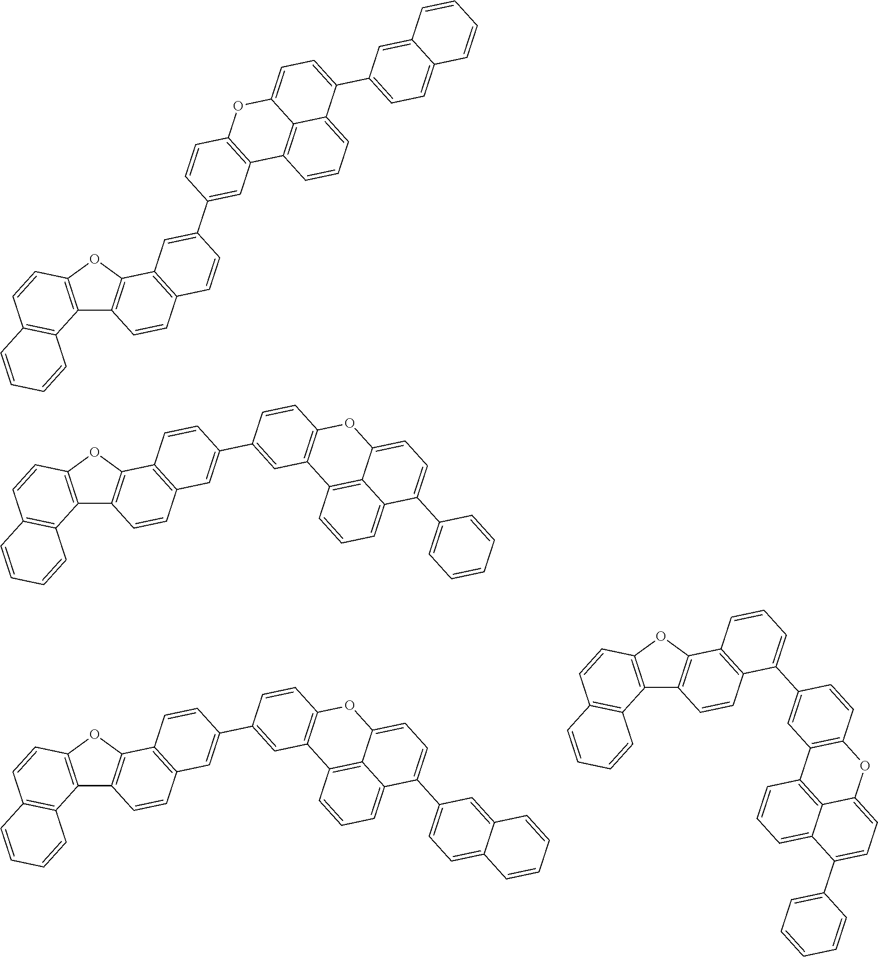 [SMILES: c1ccc2cc(-c3ccc4c5c(cccc35)-c3cc(-c5ccc6ccc7c(oc8ccc9ccccc9c87)c6c5)ccc3O4)ccc2c1 ; c1ccc(-c2ccc3c4c(cccc24)-c2cc(-c4ccc5c(ccc6c5oc5ccc7ccccc7c56)c4)ccc2O3)cc1 ; c1ccc2cc(-c3ccc4c5c(cccc35)-c3cc(-c5ccc6c(ccc7c6oc6ccc8ccccc8c67)c5)ccc3O4)ccc2c1 ; c1ccc(-c2ccc3c4c(cccc24)-c2cc(-c4cccc5c4ccc4c5oc5ccc6ccccc6c54)ccc2O3)cc1]

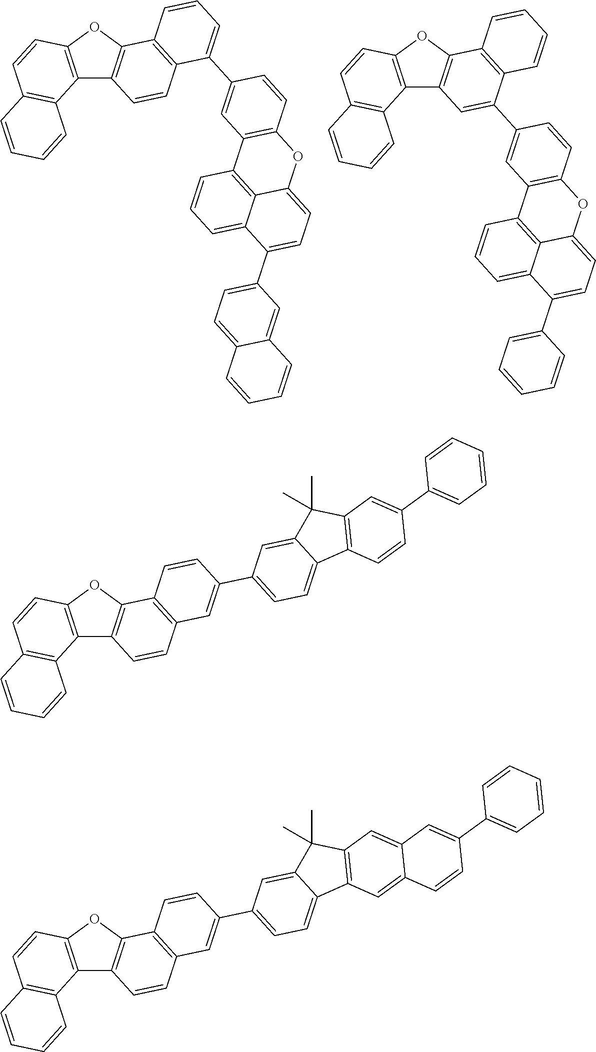

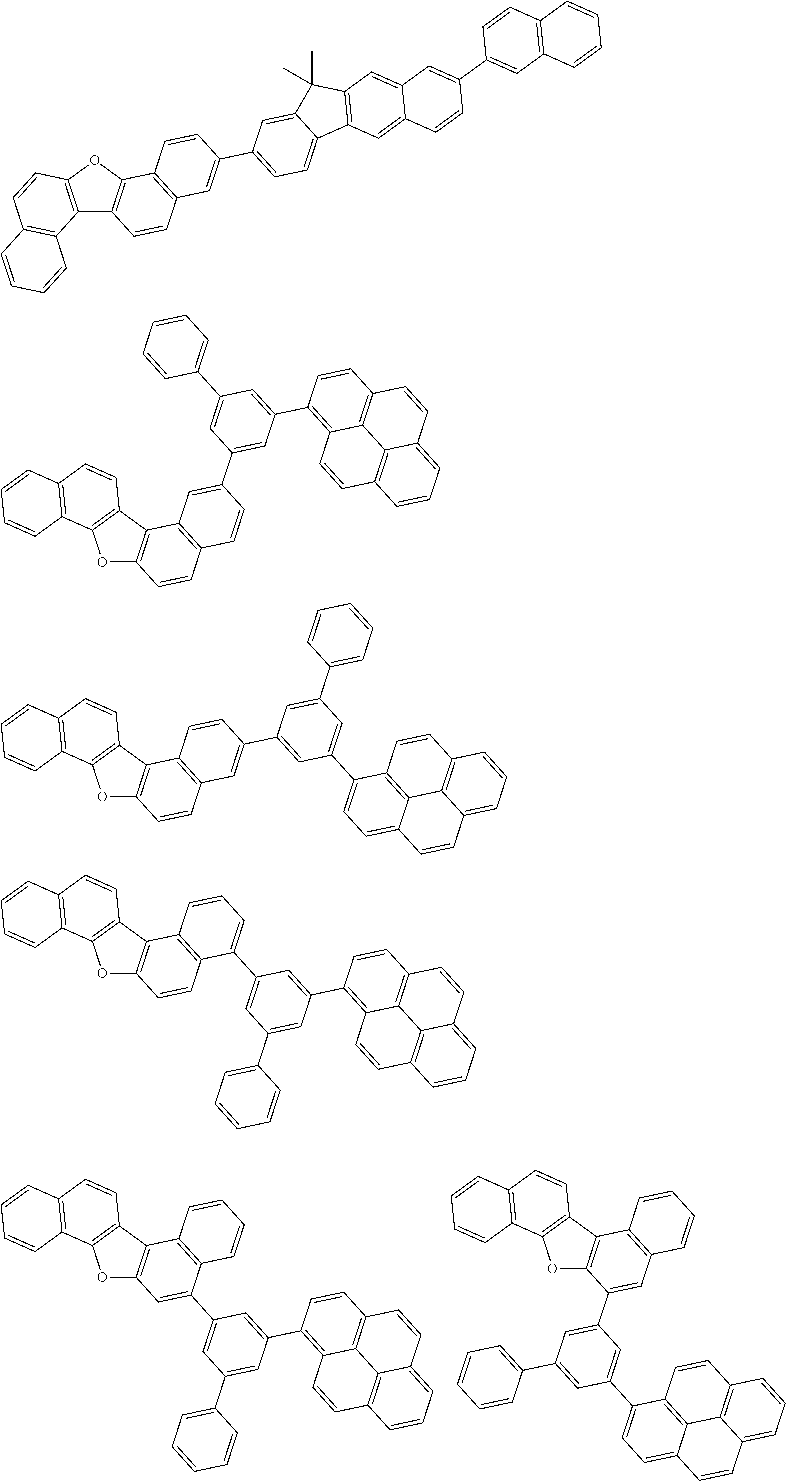

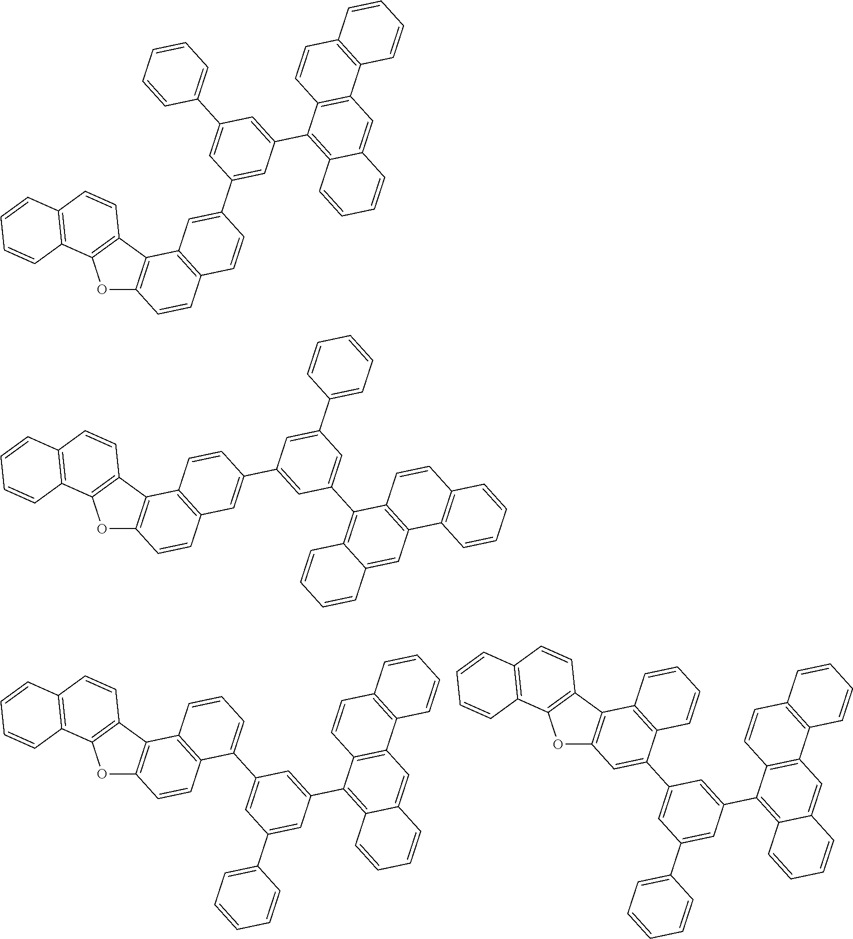

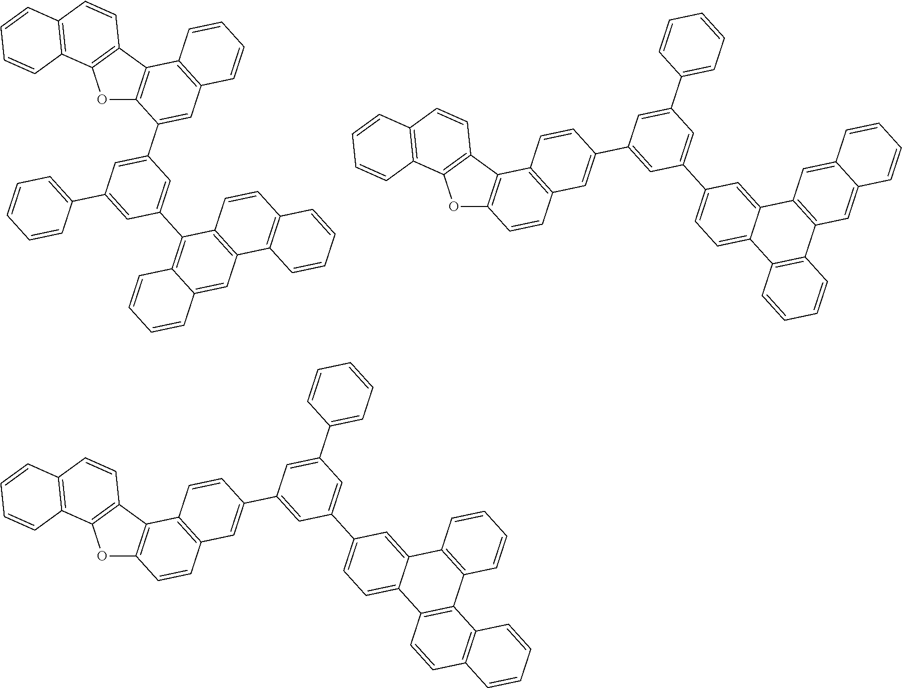 [SMILES: c1ccc(-c2cc(-c3c4ccccc4cc4c3ccc3ccccc34)cc(-c3cc4ccccc4c4c3oc3c5ccccc5ccc34)c2)cc1 ; c1ccc(-c2cc(-c3ccc4c(ccc5oc6c7ccccc7ccc6c54)c3)cc(-c3ccc4c5ccccc5c5cc6ccccc6cc5c4c3)c2)cc1 ; c1ccc(-c2cc(-c3ccc4c(ccc5oc6c7ccccc7ccc6c54)c3)cc(-c3ccc4c(c3)c3ccccc3c3c5ccccc5ccc43)c2)cc1]

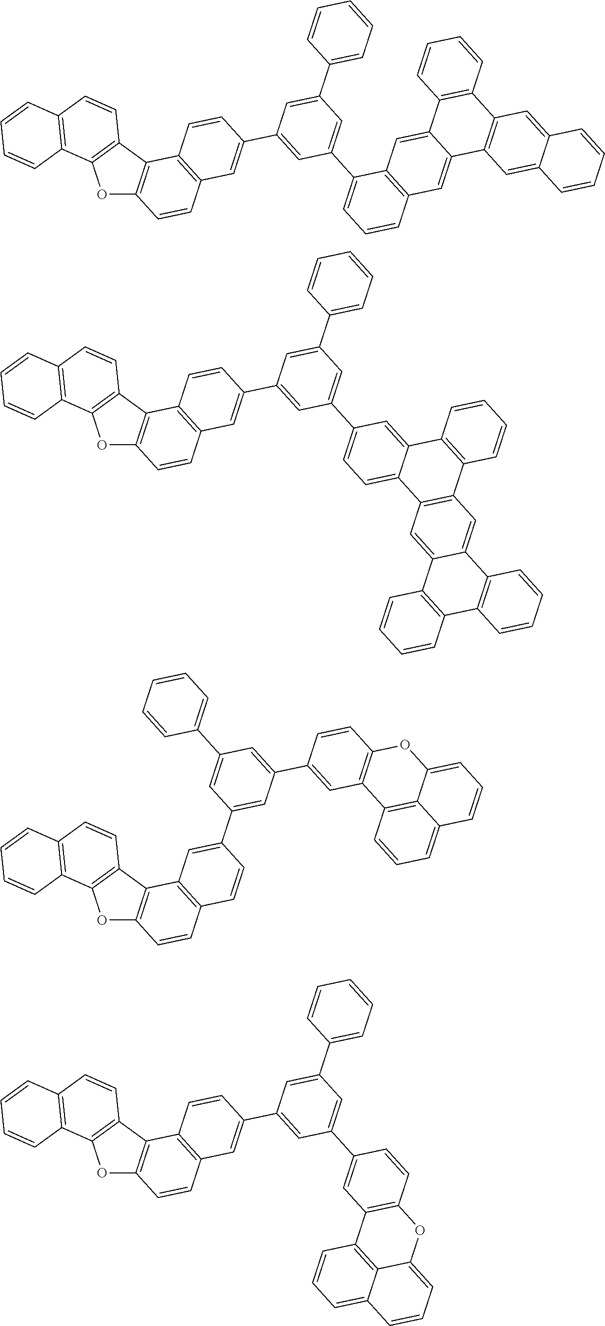

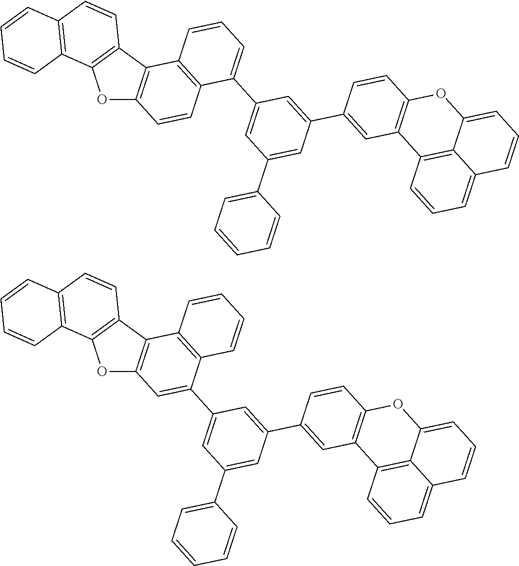

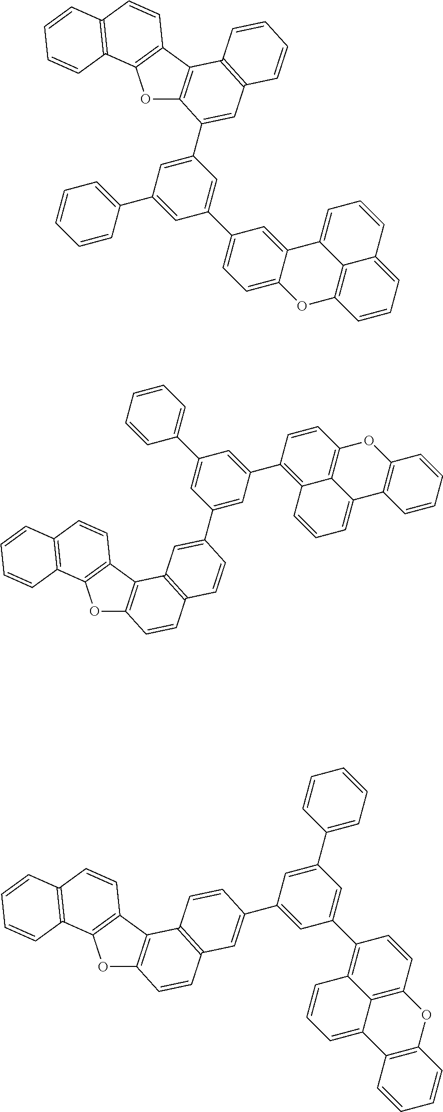 [SMILES: c1ccc(-c2cc(-c3ccc4c(c3)-c3cccc5cccc(c35)O4)cc(-c3cc4ccccc4c4c3oc3c5ccccc5ccc34)c2)cc1 ; c1ccc(-c2cc(-c3ccc4ccc5oc6c7ccccc7ccc6c5c4c3)cc(-c3ccc4c5c(cccc35)-c3ccccc3O4)c2)cc1 ; c1ccc(-c2cc(-c3ccc4c(ccc5oc6c7ccccc7ccc6c54)c3)cc(-c3ccc4c5c(cccc35)-c3ccccc3O4)c2)cc1]

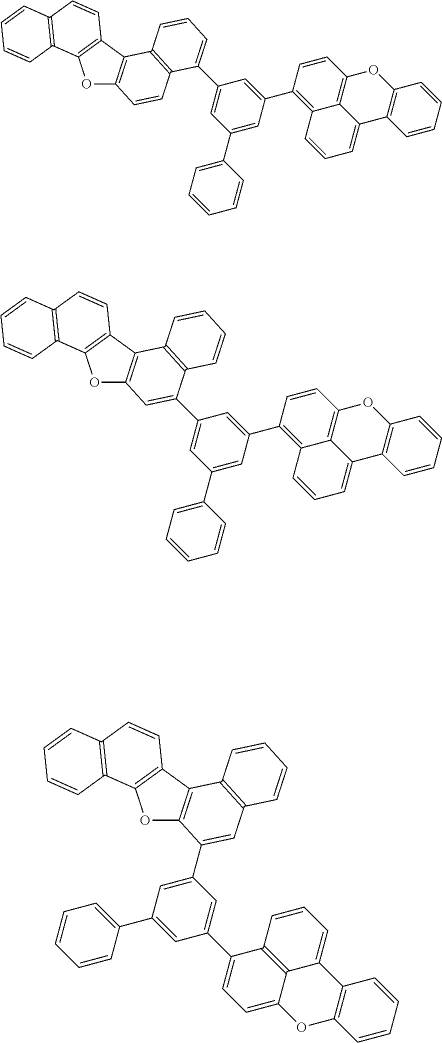 [SMILES: c1ccc(-c2cc(-c3ccc4c5c(cccc35)-c3ccccc3O4)cc(-c3cccc4c3ccc3oc5c6ccccc6ccc5c34)c2)cc1 ; c1ccc(-c2cc(-c3ccc4c5c(cccc35)-c3ccccc3O4)cc(-c3cc4oc5c6ccccc6ccc5c4c4ccccc34)c2)cc1 ; c1ccc(-c2cc(-c3ccc4c5c(cccc35)-c3ccccc3O4)cc(-c3cc4ccccc4c4c3oc3c5ccccc5ccc34)c2)cc1]

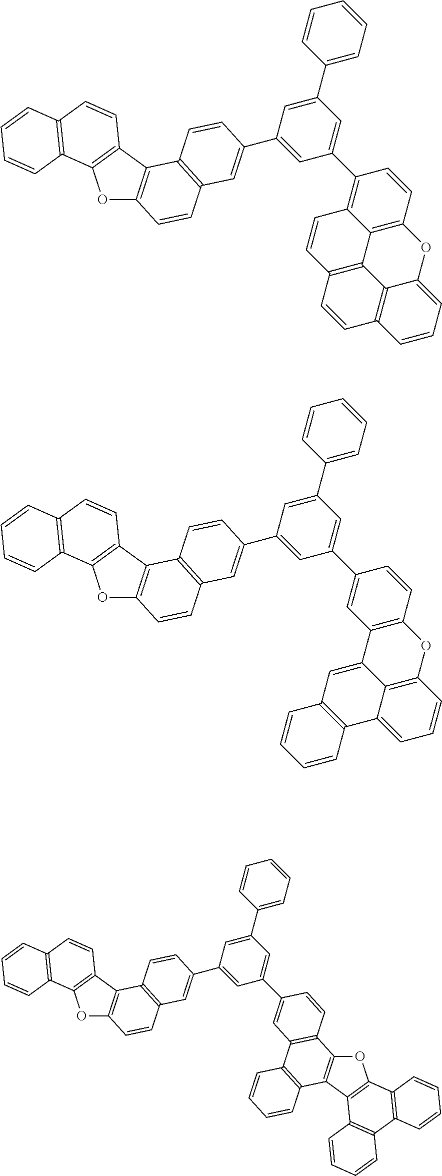 [SMILES: c1ccc(-c2cc(-c3ccc4c(ccc5oc6c7ccccc7ccc6c54)c3)cc(-c3ccc4c5c3ccc3ccc6cccc(c6c35)O4)c2)cc1 ; c1ccc(-c2cc(-c3ccc4c(c3)-c3cc5ccccc5c5cccc(c35)O4)cc(-c3ccc4c(ccc5oc6c7ccccc7ccc6c54)c3)c2)cc1 ; c1ccc(-c2cc(-c3ccc4c(ccc5oc6c7ccccc7ccc6c54)c3)cc(-c3ccc4c(c3)c3ccccc3c3c4oc4c5ccccc5c5ccccc5c43)c2)cc1]

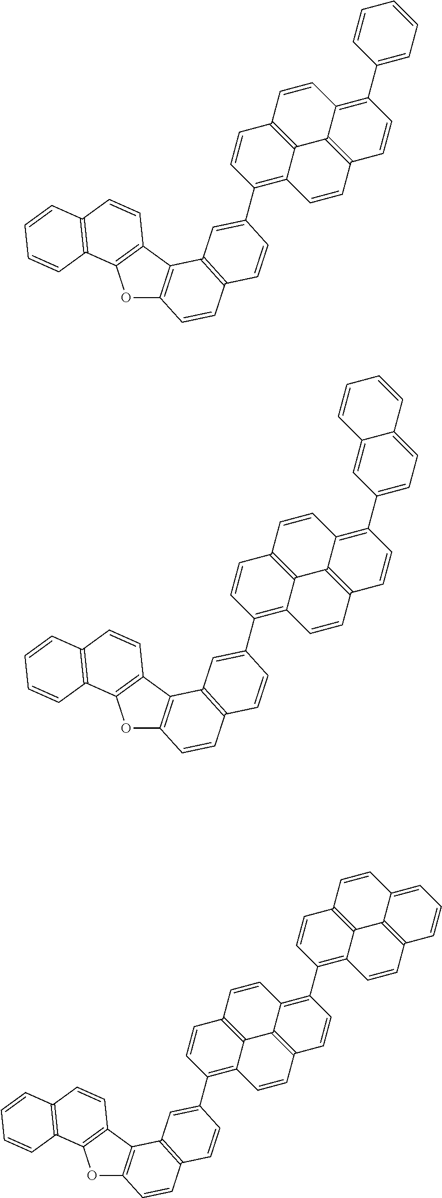 [SMILES: c1ccc(-c2ccc3ccc4c(-c5ccc6ccc7oc8c9ccccc9ccc8c7c6c5)ccc5ccc2c3c54)cc1 ; c1ccc2cc(-c3ccc4ccc5c(-c6ccc7ccc8oc9c%10ccccc%10ccc9c8c7c6)ccc6ccc3c4c65)ccc2c1 ; c1ccc2c(c1)ccc1c2oc2ccc3ccc(-c4ccc5ccc6c(-c7ccc8ccc9cccc%10ccc7c8c9%10)ccc7ccc4c5c76)cc3c21]

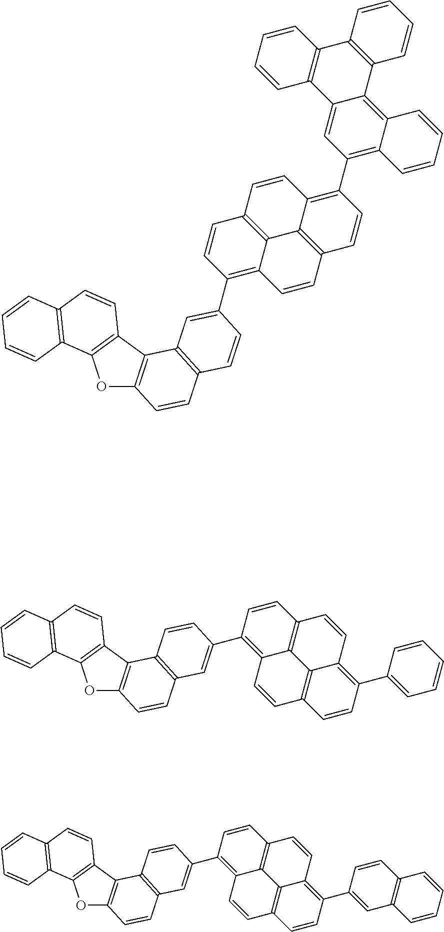 [SMILES: c1ccc2c(c1)ccc1c2oc2ccc3ccc(-c4ccc5ccc6c(-c7cc8c9ccccc9c9ccccc9c8c8ccccc78)ccc7ccc4c5c76)cc3c21 ; c1ccc(-c2ccc3ccc4c(-c5ccc6c(ccc7oc8c9ccccc9ccc8c76)c5)ccc5ccc2c3c54)cc1 ; c1ccc2cc(-c3ccc4ccc5c(-c6ccc7c(ccc8oc9c%10ccccc%10ccc9c87)c6)ccc6ccc3c4c65)ccc2c1]

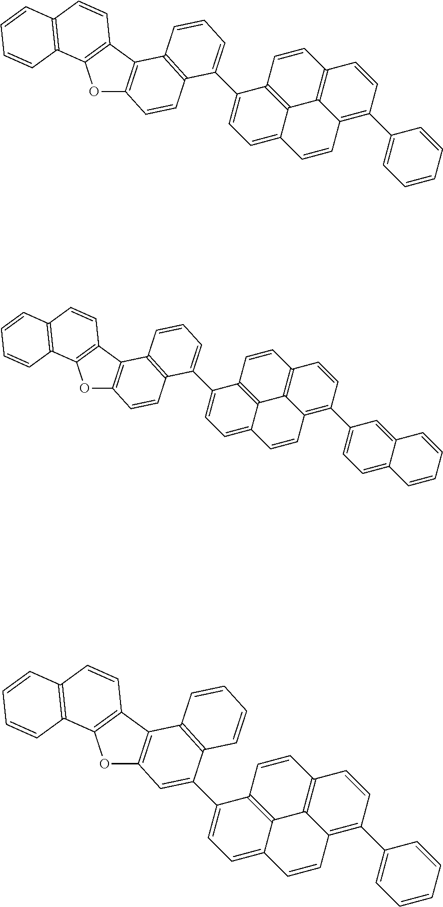 [SMILES: c1ccc(-c2ccc3ccc4c(-c5cccc6c5ccc5oc7c8ccccc8ccc7c56)ccc5ccc2c3c54)cc1 ; c1ccc2cc(-c3ccc4ccc5c(-c6cccc7c6ccc6oc8c9ccccc9ccc8c67)ccc6ccc3c4c65)ccc2c1 ; c1ccc(-c2ccc3ccc4c(-c5cc6oc7c8ccccc8ccc7c6c6ccccc56)ccc5ccc2c3c54)cc1]

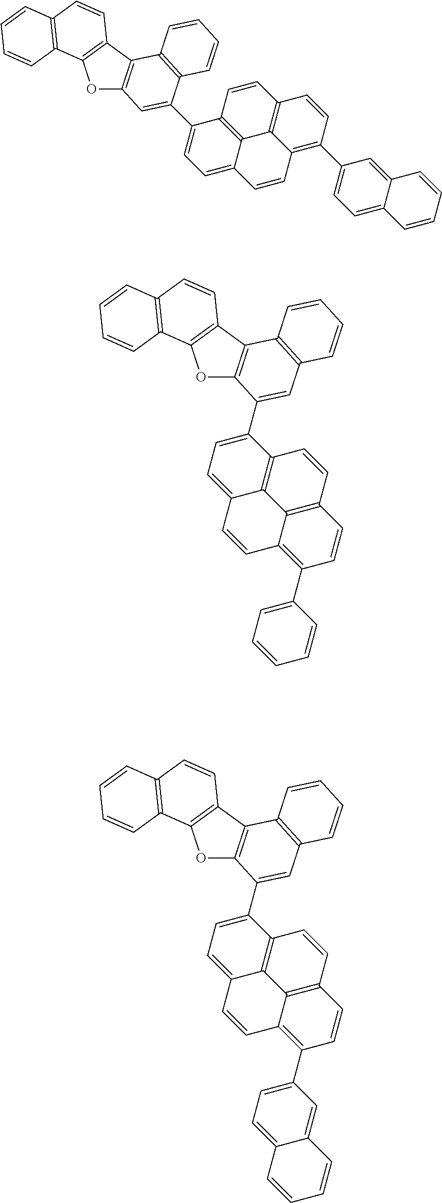 [SMILES: c1ccc2cc(-c3ccc4ccc5c(-c6cc7oc8c9ccccc9ccc8c7c7ccccc67)ccc6ccc3c4c65)ccc2c1 ; c1ccc(-c2ccc3ccc4c(-c5cc6ccccc6c6c5oc5c7ccccc7ccc56)ccc5ccc2c3c54)cc1 ; c1ccc2cc(-c3ccc4ccc5c(-c6cc7ccccc7c7c6oc6c8ccccc8ccc67)ccc6ccc3c4c65)ccc2c1]

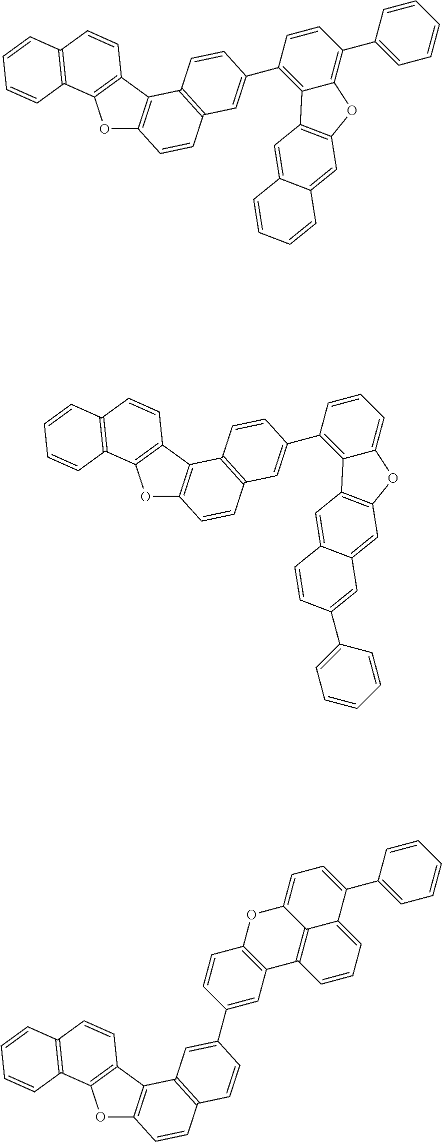 [SMILES: c1ccc(-c2ccc(-c3ccc4c(ccc5oc6c7ccccc7ccc6c54)c3)c3c2oc2cc4ccccc4cc23)cc1 ; c1ccc(-c2ccc3cc4c(cc3c2)oc2cccc(-c3ccc5c(ccc6oc7c8ccccc8ccc7c65)c3)c24)cc1 ; c1ccc(-c2ccc3c4c(cccc24)-c2cc(-c4ccc5ccc6oc7c8ccccc8ccc7c6c5c4)ccc2O3)cc1]

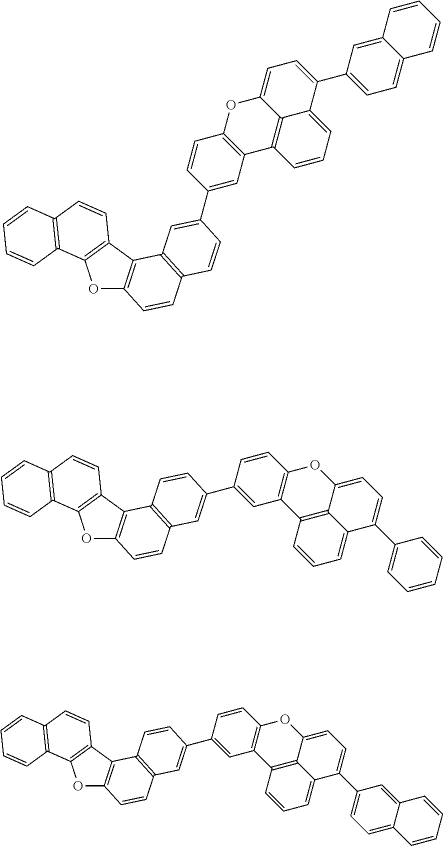 [SMILES: c1ccc2cc(-c3ccc4c5c(cccc35)-c3cc(-c5ccc6ccc7oc8c9ccccc9ccc8c7c6c5)ccc3O4)ccc2c1 ; c1ccc(-c2ccc3c4c(cccc24)-c2cc(-c4ccc5c(ccc6oc7c8ccccc8ccc7c65)c4)ccc2O3)cc1 ; c1ccc2cc(-c3ccc4c5c(cccc35)-c3cc(-c5ccc6c(ccc7oc8c9ccccc9ccc8c76)c5)ccc3O4)ccc2c1]

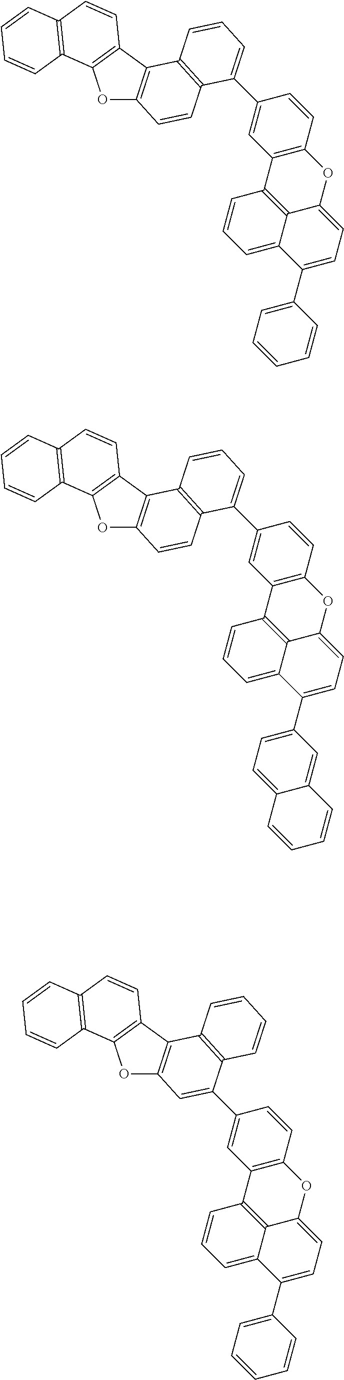 [SMILES: c1ccc(-c2ccc3c4c(cccc24)-c2cc(-c4cccc5c4ccc4oc6c7ccccc7ccc6c45)ccc2O3)cc1 ; c1ccc2cc(-c3ccc4c5c(cccc35)-c3cc(-c5cccc6c5ccc5oc7c8ccccc8ccc7c56)ccc3O4)ccc2c1 ; c1ccc(-c2ccc3c4c(cccc24)-c2cc(-c4cc5oc6c7ccccc7ccc6c5c5ccccc45)ccc2O3)cc1]

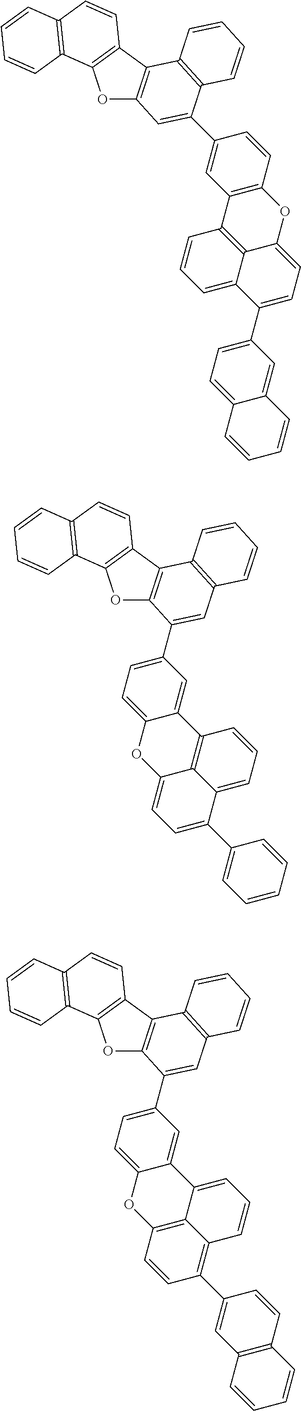 [SMILES: c1ccc2cc(-c3ccc4c5c(cccc35)-c3cc(-c5cc6oc7c8ccccc8ccc7c6c6ccccc56)ccc3O4)ccc2c1 ; c1ccc(-c2ccc3c4c(cccc24)-c2cc(-c4cc5ccccc5c5c4oc4c6ccccc6ccc45)ccc2O3)cc1 ; c1ccc2cc(-c3ccc4c5c(cccc35)-c3cc(-c5cc6ccccc6c6c5oc5c7ccccc7ccc56)ccc3O4)ccc2c1]

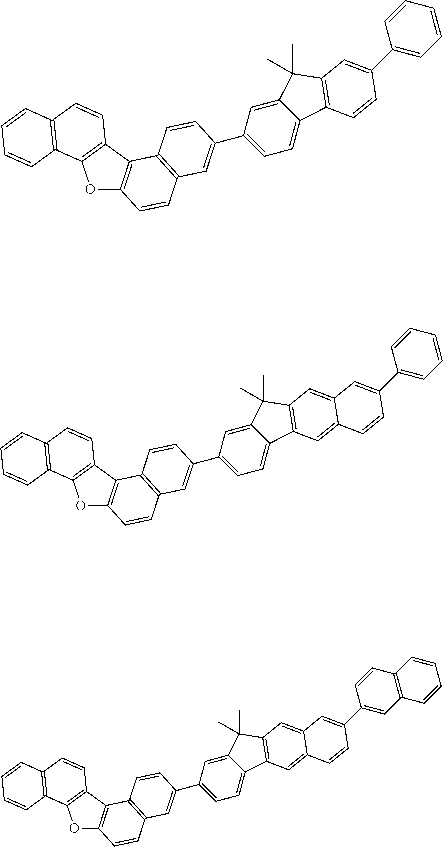 [SMILES: CC1(C)c2cc(-c3ccccc3)ccc2-c2ccc(-c3ccc4c(ccc5oc6c7ccccc7ccc6c54)c3)cc21 ; CC1(C)c2cc(-c3ccc4c(ccc5oc6c7ccccc7ccc6c54)c3)ccc2-c2cc3ccc(-c4ccccc4)cc3cc21 ; CC1(C)c2cc(-c3ccc4c(ccc5oc6c7ccccc7ccc6c54)c3)ccc2-c2cc3ccc(-c4ccc5ccccc5c4)cc3cc21]

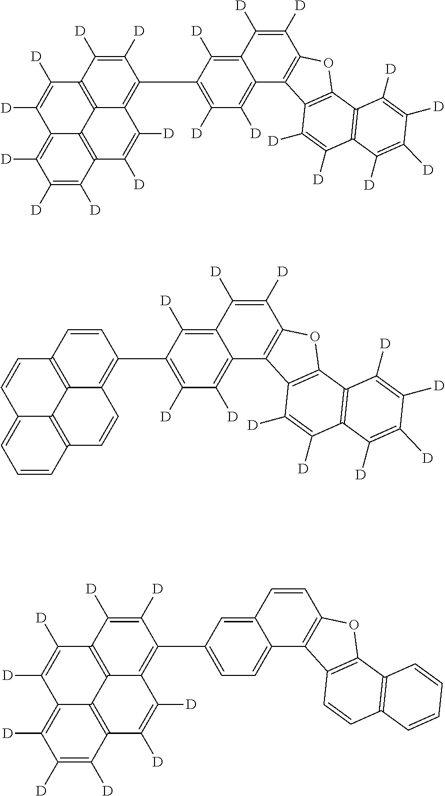 [SMILES: [2H]c1c([2H])c([2H])c2c(c1[2H])c([2H])c([2H])c1c2oc2c([2H])c([2H])c3c([2H])c(-c4c([2H])c([2H])c5c([2H])c([2H])c6c([2H])c([2H])c([2H])c7c([2H])c([2H])c4c5c67)c([2H])c([2H])c3c21 ; [2H]c1c([2H])c([2H])c2c(c1[2H])c([2H])c([2H])c1c2oc2c([2H])c([2H])c3c([2H])c(-c4ccc5ccc6cccc7ccc4c5c67)c([2H])c([2H])c3c21 ; [2H]c1c([2H])c2c([2H])c([2H])c3c([2H])c([2H])c(-c4ccc5c(ccc6oc7c8ccccc8ccc7c65)c4)c4c([2H])c([2H])c(c1[2H])c2c34]

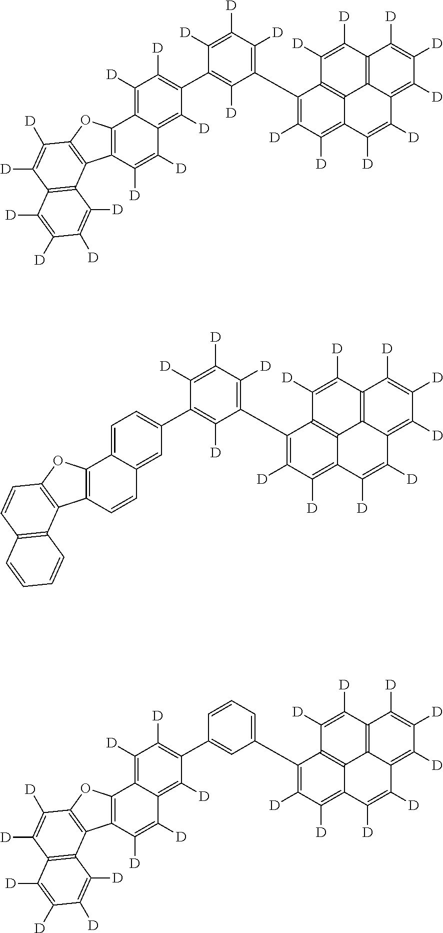

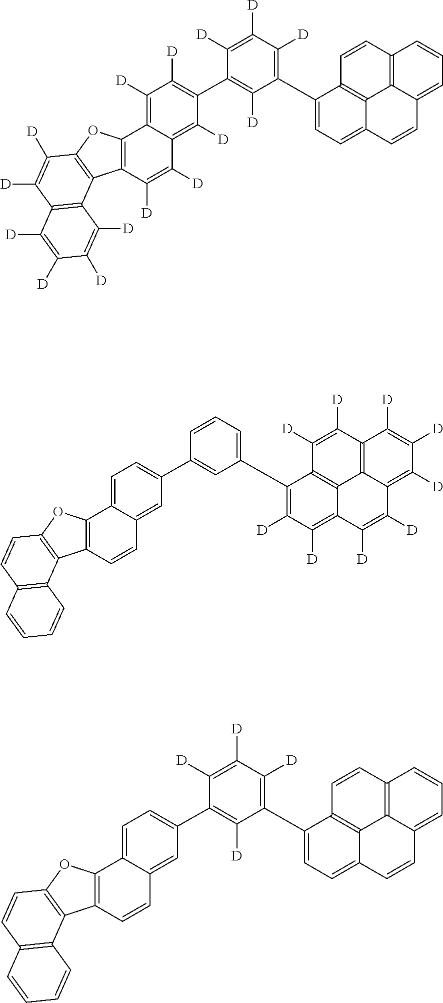 [SMILES: [2H]c1c([2H])c(-c2c([2H])c([2H])c3c(c2[2H])c([2H])c([2H])c2c3oc3c([2H])c([2H])c4c([2H])c([2H])c([2H])c([2H])c4c32)c([2H])c(-c2ccc3ccc4cccc5ccc2c3c45)c1[2H] ; [2H]c1c([2H])c2c([2H])c([2H])c3c([2H])c([2H])c(-c4cccc(-c5ccc6c(ccc7c6oc6ccc8ccccc8c67)c5)c4)c4c([2H])c([2H])c(c1[2H])c2c34 ; [2H]c1c([2H])c(-c2ccc3c(ccc4c3oc3ccc5ccccc5c34)c2)c([2H])c(-c2ccc3ccc4cccc5ccc2c3c45)c1[2H]]

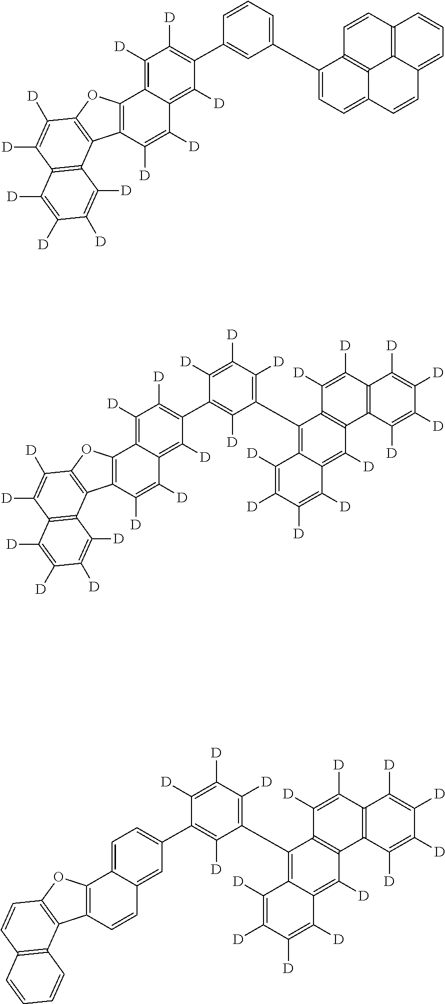

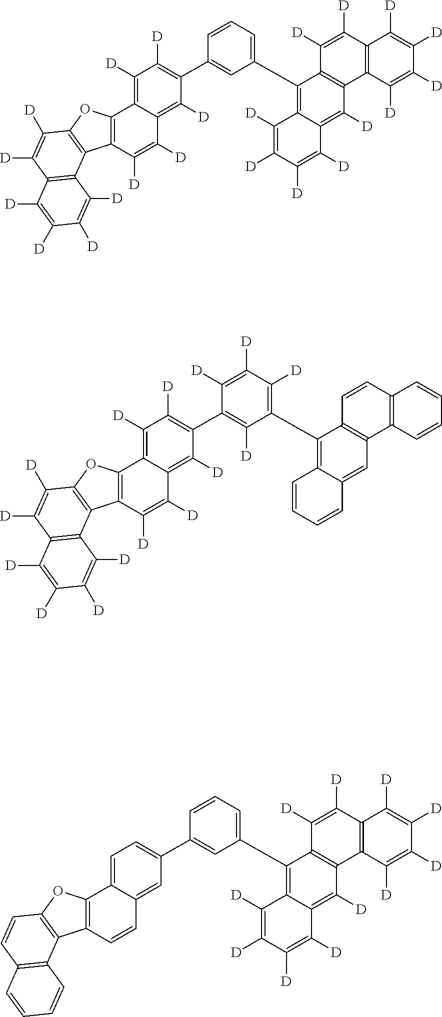

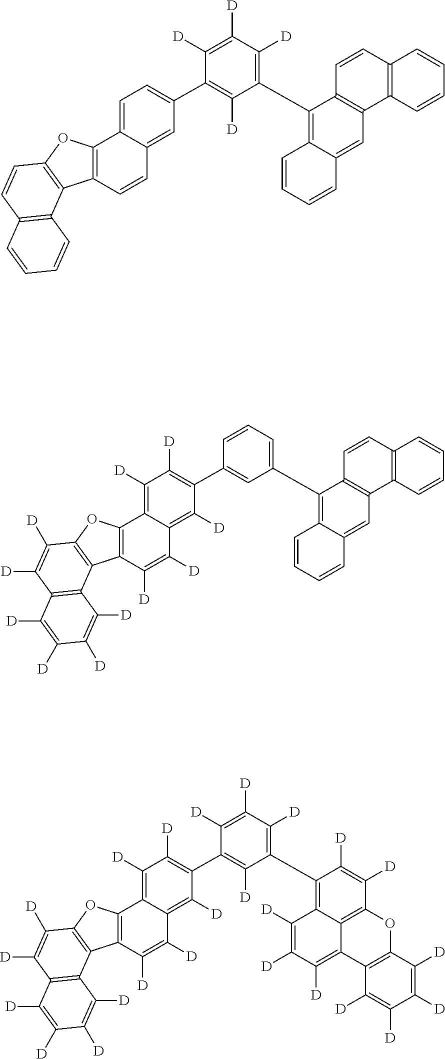 [SMILES: [2H]c1c([2H])c(-c2ccc3c(ccc4c3oc3ccc5ccccc5c34)c2)c([2H])c(-c2c3ccccc3cc3c2ccc2ccccc23)c1[2H] ; [2H]c1c([2H])c([2H])c2c(c1[2H])c([2H])c([2H])c1oc3c4c([2H])c([2H])c(-c5cccc(-c6c7ccccc7cc7c6ccc6ccccc67)c5)c([2H])c4c([2H])c([2H])c3c12 ; [2H]c1c([2H])c([2H])c2c(c1[2H])Oc1c([2H])c([2H])c(-c3c([2H])c([2H])c([2H])c(-c4c([2H])c([2H])c5c(c4[2H])c([2H])c([2H])c4c5oc5c([2H])c([2H])c6c([2H])c([2H])c([2H])c([2H])c6c54)c3[2H])c3c([2H])c([2H])c([2H])c-2c13]

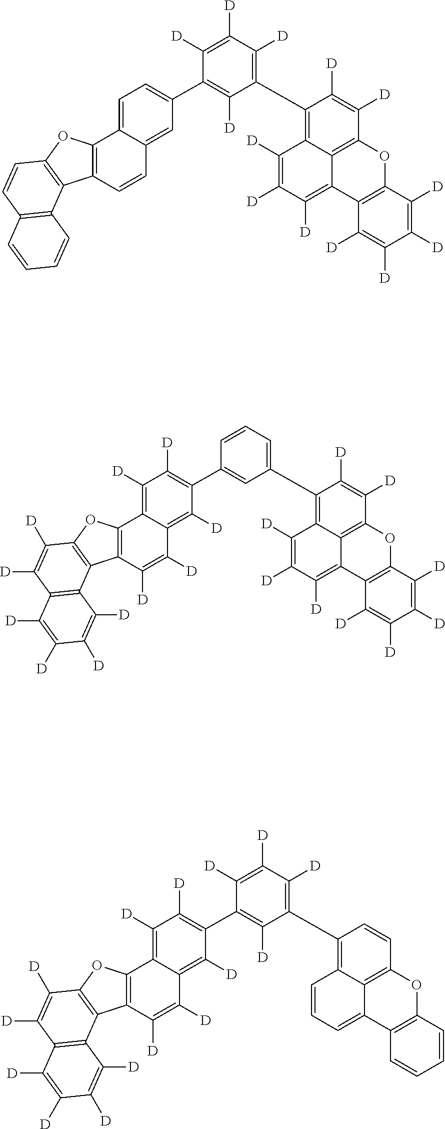

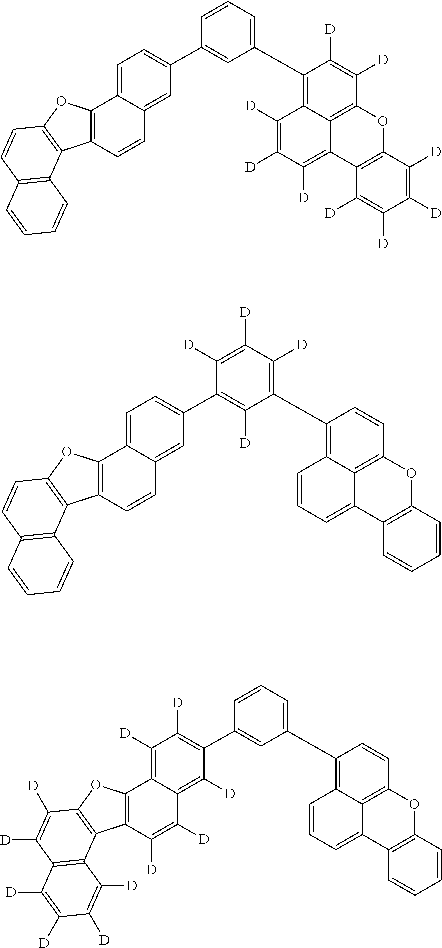 [SMILES: [2H]c1c([2H])c([2H])c2c(c1[2H])Oc1c([2H])c([2H])c(-c3cccc(-c4ccc5c(ccc6c5oc5ccc7ccccc7c56)c4)c3)c3c([2H])c([2H])c([2H])c-2c13 ; [2H]c1c([2H])c(-c2ccc3c(ccc4c3oc3ccc5ccccc5c34)c2)c([2H])c(-c2ccc3c4c(cccc24)-c2ccccc2O3)c1[2H] ; [2H]c1c([2H])c([2H])c2c(c1[2H])c([2H])c([2H])c1oc3c4c([2H])c([2H])c(-c5cccc(-c6ccc7c8c(cccc68)-c6ccccc6O7)c5)c([2H])c4c([2H])c([2H])c3c12]

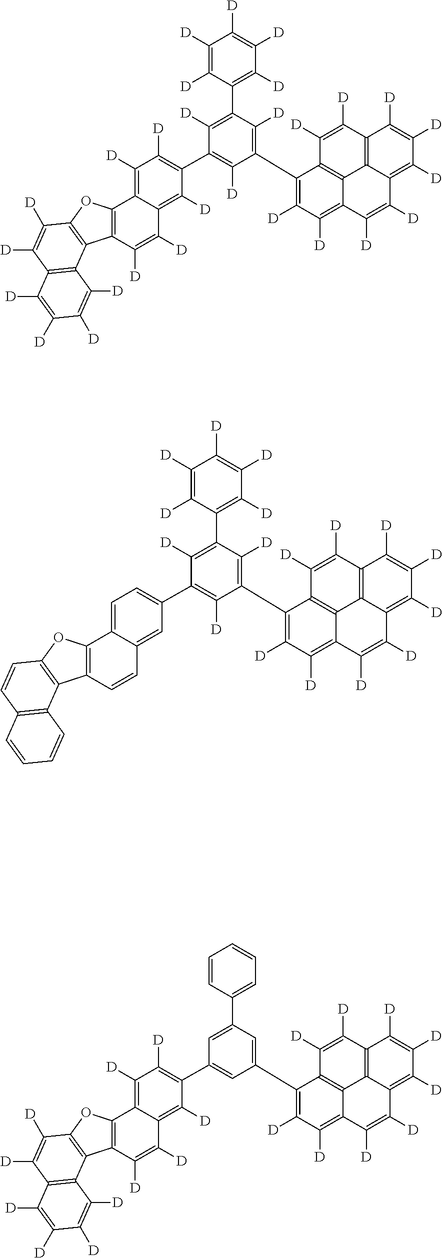

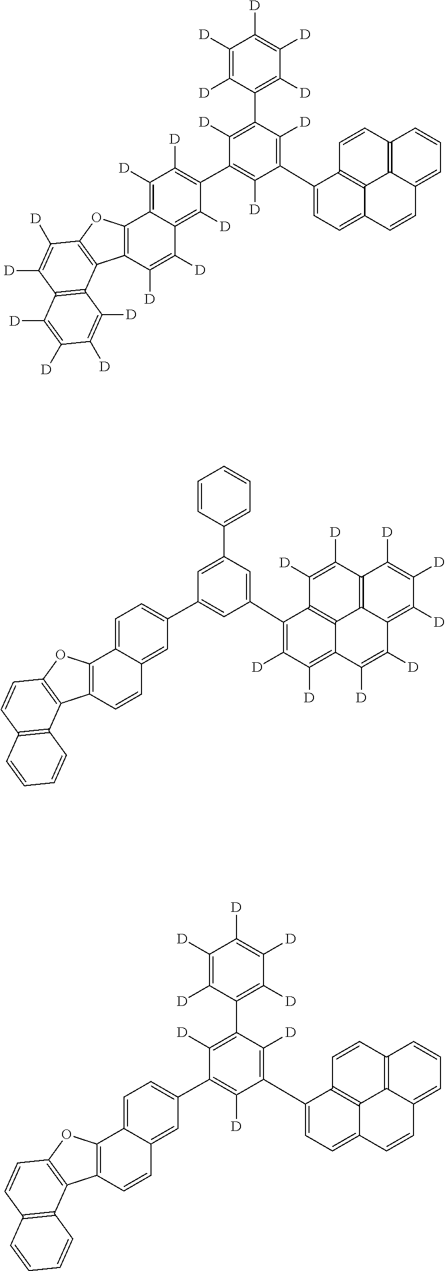 [SMILES: [2H]c1c([2H])c([2H])c(-c2c([2H])c(-c3c([2H])c([2H])c4c(c3[2H])c([2H])c([2H])c3c4oc4c([2H])c([2H])c5c([2H])c([2H])c([2H])c([2H])c5c43)c([2H])c(-c3ccc4ccc5cccc6ccc3c4c56)c2[2H])c([2H])c1[2H] ; [2H]c1c([2H])c2c([2H])c([2H])c3c([2H])c([2H])c(-c4cc(-c5ccccc5)cc(-c5ccc6c(ccc7c6oc6ccc8ccccc8c67)c5)c4)c4c([2H])c([2H])c(c1[2H])c2c34 ; [2H]c1c([2H])c([2H])c(-c2c([2H])c(-c3ccc4c(ccc5c4oc4ccc6ccccc6c45)c3)c([2H])c(-c3ccc4ccc5cccc6ccc3c4c56)c2[2H])c([2H])c1[2H]]

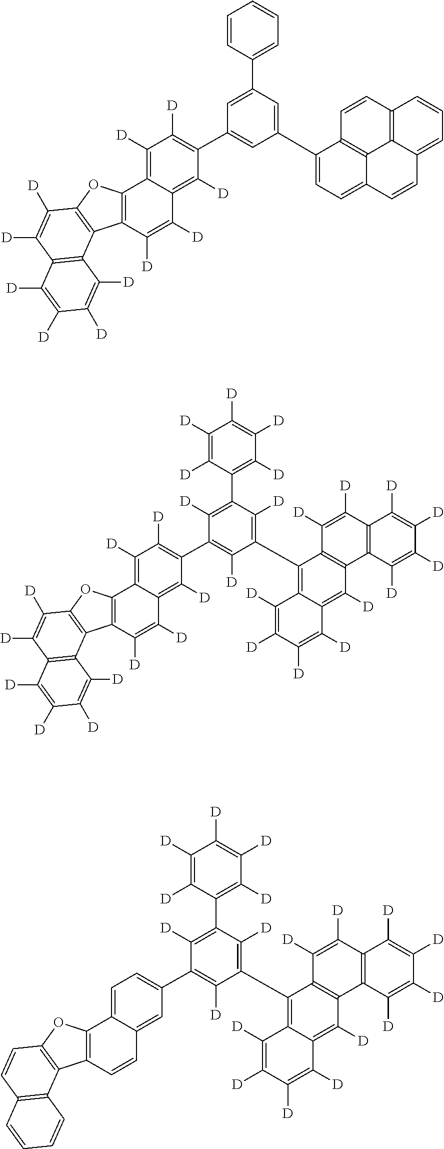

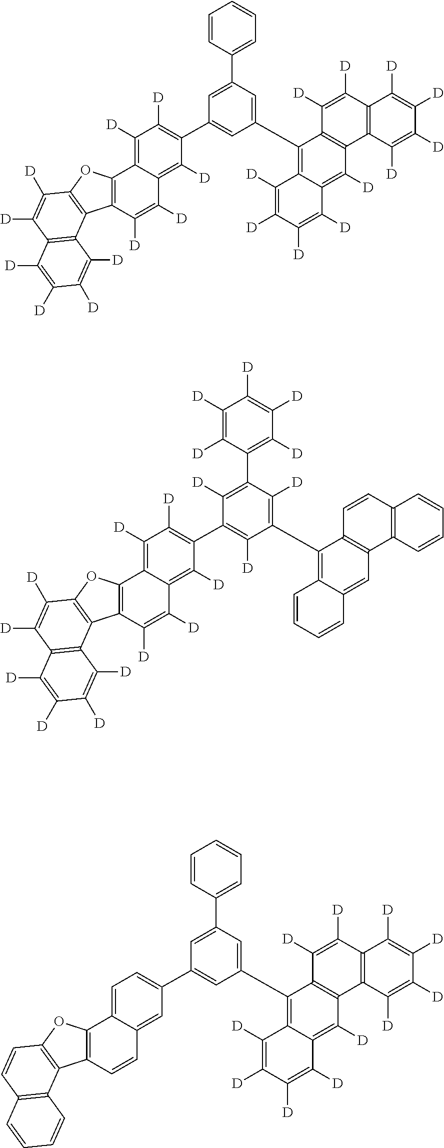

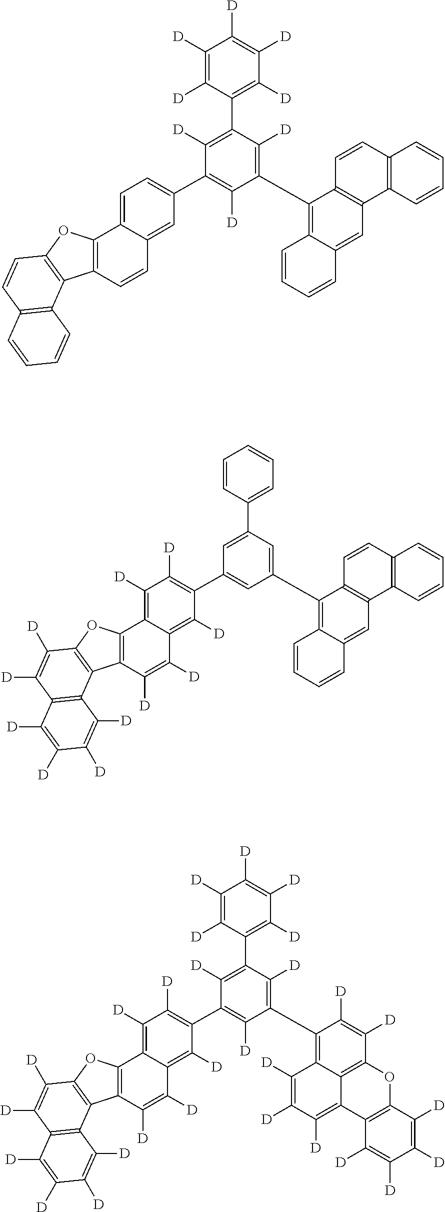

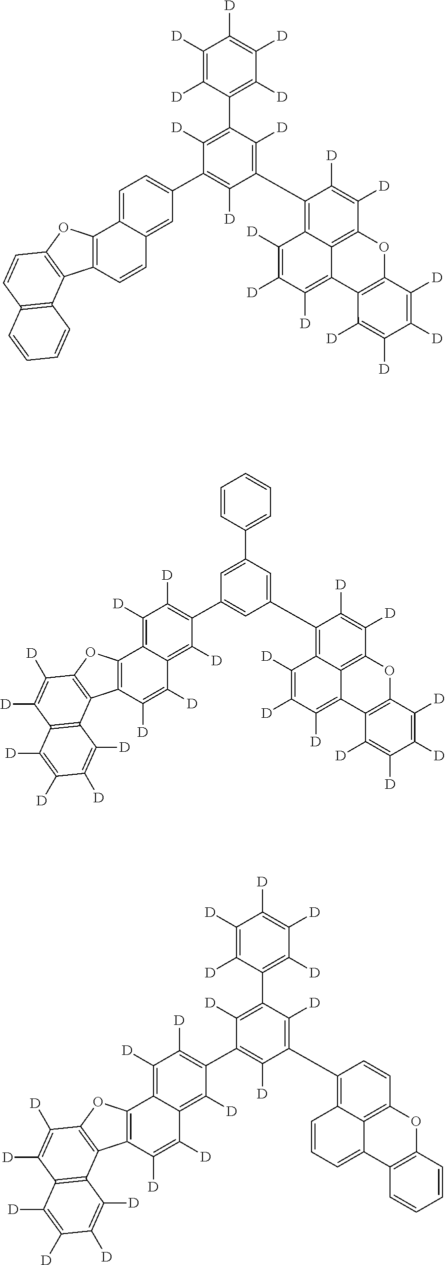

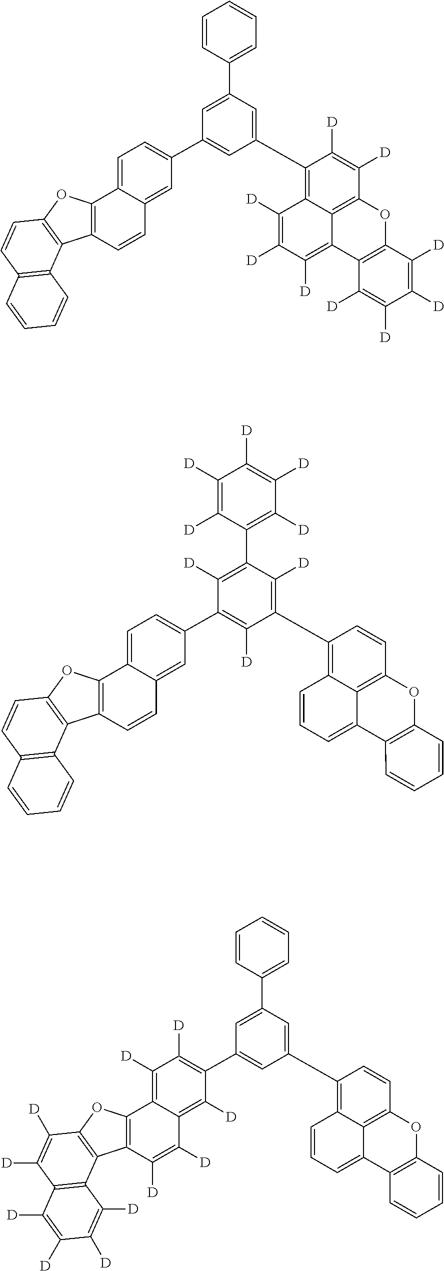 [SMILES: [2H]c1c([2H])c([2H])c2c(c1[2H])Oc1c([2H])c([2H])c(-c3cc(-c4ccccc4)cc(-c4ccc5c(ccc6c5oc5ccc7ccccc7c56)c4)c3)c3c([2H])c([2H])c([2H])c-2c13 ; [2H]c1c([2H])c([2H])c(-c2c([2H])c(-c3ccc4c(ccc5c4oc4ccc6ccccc6c45)c3)c([2H])c(-c3ccc4c5c(cccc35)-c3ccccc3O4)c2[2H])c([2H])c1[2H] ; [2H]c1c([2H])c([2H])c2c(c1[2H])c([2H])c([2H])c1oc3c4c([2H])c([2H])c(-c5cc(-c6ccccc6)cc(-c6ccc7c8c(cccc68)-c6ccccc6O7)c5)c([2H])c4c([2H])c([2H])c3c12]

### [Compound Represented by Formula (4)]

The compound represented by the formula (4) is as follows:

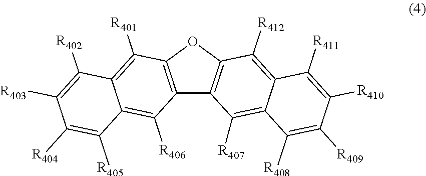

wherein in the formula (4),
at least one of R₄₀₁ to R₄₁₂ is a single bond bonded to a group represented by the following formula (A1):

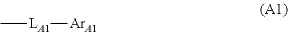

those in the formula (A1) are the same as those defined in the above formula (1), and
R₄₀₁ to R₄₁₂ which are not a single bond bonded to the group represented by the formula (A1) are independently
a hydrogen atom,
a substituted or unsubstituted aryl group having 6 to 20 ring carbon atoms, or
a substituted or unsubstituted monovalent heterocyclic group having 5 to 19 ring atoms.

In the formula (4), when L_{A1} of the formula (A1) is a single bond, Ar_{A1} is directly bonded to the dinaphthofuran skeleton.

The matter described for the formula (A1) in the compound represented by the formula (1) can also be applied to the compound represented by the formula (4).

In one embodiment, the compound represented by the formula (4) is a compound represented by the following formula (41):

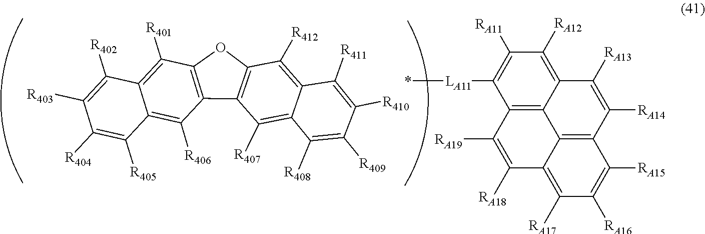

wherein in the formula (41),
at least one of R₄₀₁ to R₄₁₂ is a single bond bonded to L_{A11},
R₄₀₁ to R₄₁₂ which are not a single bond bonded to L_{A11} are independently
a hydrogen atom,
a substituted or unsubstituted aryl group having 6 to 20 ring carbon atoms, or
a substituted or unsubstituted monovalent heterocyclic group having 5 to 19 ring atoms,
L_{A11} is
a single bond, or
a substituted or unsubstituted arylene group having 6 to 20 ring carbon atoms,
R_{A11} to R_{A19} are independently a hydrogen atom or a substituent R, and
the substituent R is as defined in the above formula (11).

In the formula (41), when L_{A11} is a single bond, the pyrene skeleton is directly bonded to the dinaphthofuran skeleton.

In one embodiment, R_{A11} to R_{A19} are a hydrogen atom.

In one embodiment, at least one of R_{A11} to R_{A19} which are a hydrogen atom is a deuterium atom.

In one embodiment, the compound represented by the formula (4) is a compound represented by the following formula (42):

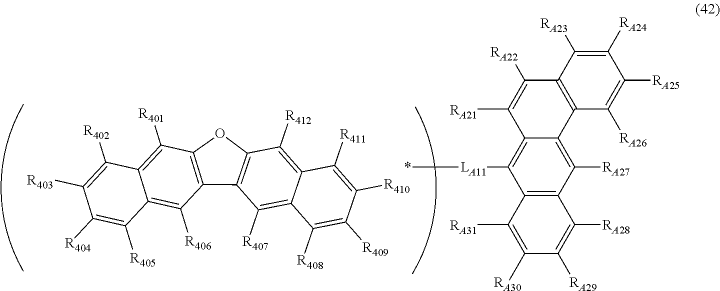

wherein in the formula (42),
at least one of R₄₀₁ to R₄₁₂ is a single bond bonded to L_{A11},
R₄₀₁ to R₄₁₂ which are not a single bond bonded to L_{A11} are independently
a hydrogen atom,
a substituted or unsubstituted aryl group having 6 to 20 ring carbon atoms, or
a substituted or unsubstituted monovalent heterocyclic group having 5 to 19 ring atoms,
L_{A11} is
a single bond, or
a substituted or unsubstituted arylene group having 6 to 20 ring carbon atoms,
R_{A21} to R_{A31} are independently a hydrogen atom or a substituent R,
the substituent R is selected from the group consisting of
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,

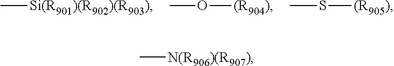

a halogen atom, a cyano group, a nitro group,
a substituted or unsubstituted aryl group having 6 to 50 ring carbon atoms, and
a substituted or unsubstituted monovalent heterocyclic group having 5 to 50 ring atoms,
when two or more substituents R are present, the two or more substituents R may be the same as or different from each other,
R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms, and
when two or more of each of R₉₀₁ to R₉₀₇ are present, the two or more of each of R₉₀₁ to R₉₀₇ may be the same as or different from each other.

In one embodiment, R_{A21} to R_{A31} are a hydrogen atom.

In one embodiment, at least one of R_{A21} to R_{A31} which are a hydrogen atom is a deuterium atom.

In one embodiment, R₄₀₁ to R₄₁₂ which are not a single bond bonded to L_{A11} are a hydrogen atom.

For the deuterium atom, the matter described in the compound represented by the formula (1) can be applied.

In one embodiment, a substituent in the case of “substituted or unsubstituted” in the above formula (4) is selected from the group consisting of
an alkyl group having 1 to 50 carbon atoms,
a haloalkyl group having 1 to 50 carbon atoms,
an alkenyl group having 2 to 50 carbon atoms,
an alkynyl group having 2 to 50 carbon atoms,
a cycloalkyl group having 3 to 50 ring carbon atoms,
an alkoxy group having 1 to 50 carbon atoms,
an alkylthio group having 1 to 50 carbon atoms,
an aryloxy group having 6 to 50 ring carbon atoms,
an arylthio group having 6 to 50 ring carbon atoms,
an aralkyl group having 7 to 50 carbon atoms,

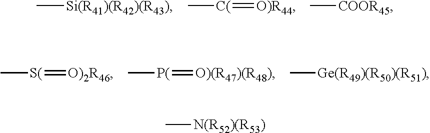

(wherein R₄₁ to R₅₃ are independently a hydrogen atom, an alkyl group having 1 to 50 carbon atoms, an aryl group having 6 to 50 ring carbon atoms, or a monovalent heterocyclic group having 5 to 50 ring atoms; when two or more of each of R₄₁ to R₅₃ are present, the two or more of each of R₄₁ to R₅₃ may be the same as or different from each other),
a hydroxy group,
a halogen atom,
a cyano group,
a nitro group,
an aryl group having 6 to 50 ring carbon atoms, and
a monovalent heterocyclic group having 5 to 50 ring atoms.

In one embodiment, a substituent in the case of “substituted or unsubstituted” in the above formula (4) is selected from the group consisting of
an alkyl group having 1 to 50 carbon atoms,
an aryl group having 6 to 50 ring carbon atoms, and
a monovalent heterocyclic group having 5 to 50 ring atoms.

In one embodiment, a substituent in the case of “substituted or unsubstituted” in the above formula (4) is
an unsubstituted aryl group having 6 to 20 ring carbon atoms, or
an unsubstituted monovalent heterocyclic group having 5 to 19 ring atoms.

The compound represented by the formula (4) can be synthesized by following Examples and using a known alternative reaction or raw material suited for an intended product.

Specific examples of the compound represented by the formula (4) will be described below, but these are merely examples, and the compound represented by the formula (4) is not limited to the following specific examples.

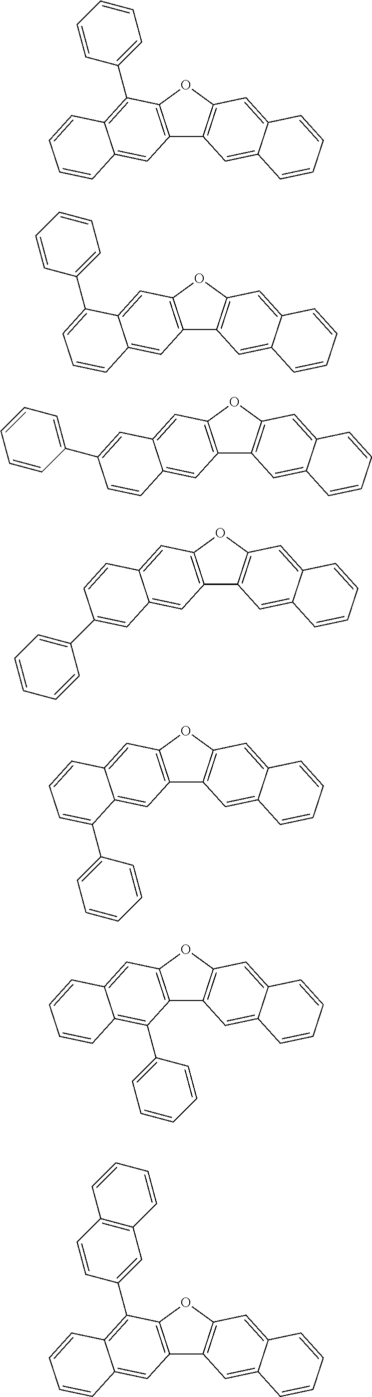

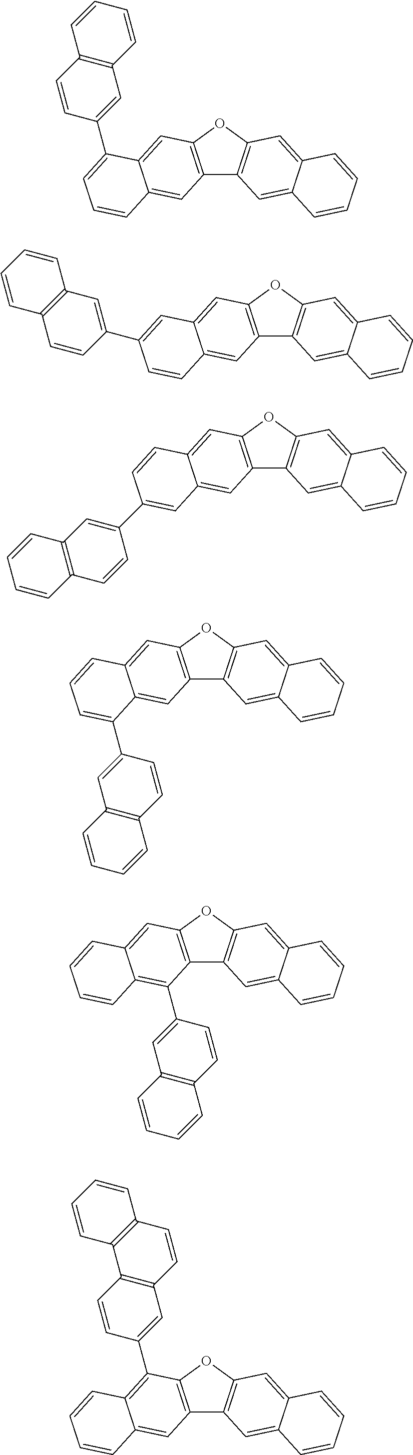 [SMILES: c1ccc2cc(-c3cccc4cc5c(cc34)oc3cc4ccccc4cc35)ccc2c1 ; c1ccc2cc(-c3ccc4cc5c(cc4c3)oc3cc4ccccc4cc35)ccc2c1 ; c1ccc2cc(-c3ccc4cc5oc6cc7ccccc7cc6c5cc4c3)ccc2c1 ; c1ccc2cc(-c3cccc4cc5oc6cc7ccccc7cc6c5cc34)ccc2c1 ; c1ccc2cc(-c3c4ccccc4cc4oc5cc6ccccc6cc5c34)ccc2c1 ; c1ccc2cc3c(cc2c1)oc1c(-c2ccc4c(ccc5ccccc54)c2)c2ccccc2cc13]

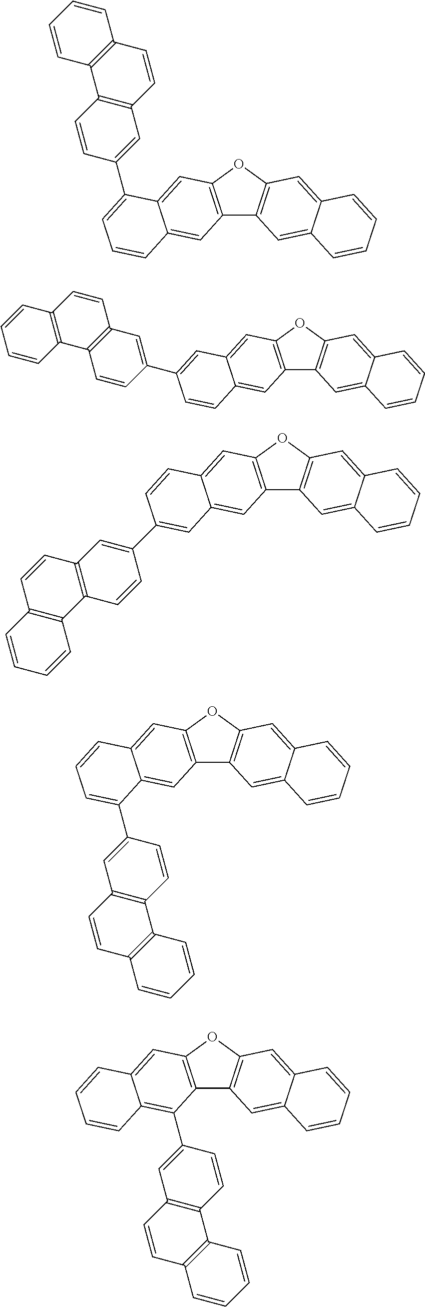

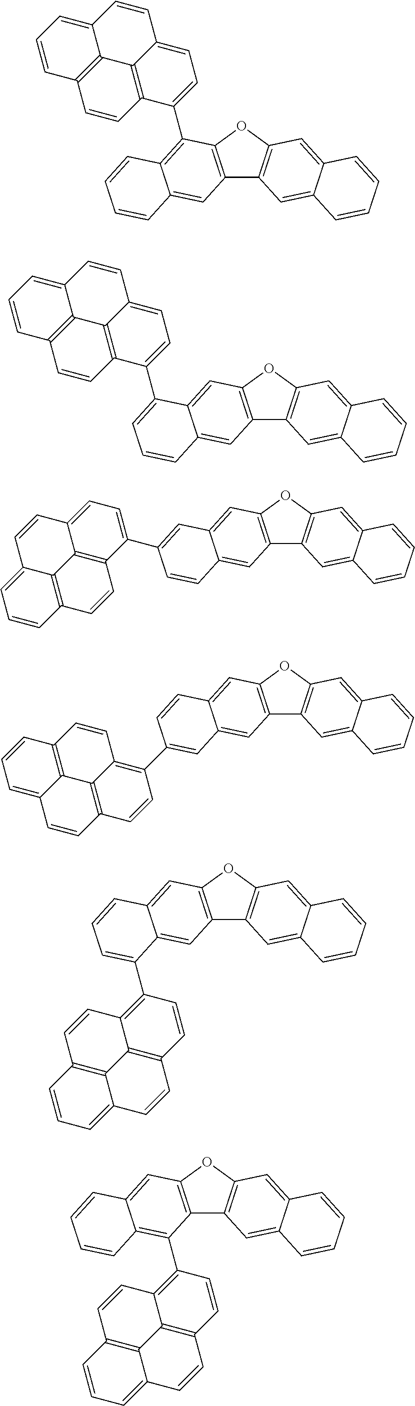 [SMILES: c1ccc2cc3c(cc2c1)oc1c(-c2ccc4ccc5cccc6ccc2c4c56)c2ccccc2cc13 ; c1ccc2cc3c(cc2c1)oc1cc2c(-c4ccc5ccc6cccc7ccc4c5c67)cccc2cc13 ; c1ccc2cc3c(cc2c1)oc1cc2cc(-c4ccc5ccc6cccc7ccc4c5c67)ccc2cc13 ; c1ccc2cc3c(cc2c1)oc1cc2ccc(-c4ccc5ccc6cccc7ccc4c5c67)cc2cc13 ; c1ccc2cc3c(cc2c1)oc1cc2cccc(-c4ccc5ccc6cccc7ccc4c5c67)c2cc13 ; c1ccc2cc3c(cc2c1)oc1cc2ccccc2c(-c2ccc4ccc5cccc6ccc2c4c56)c13]

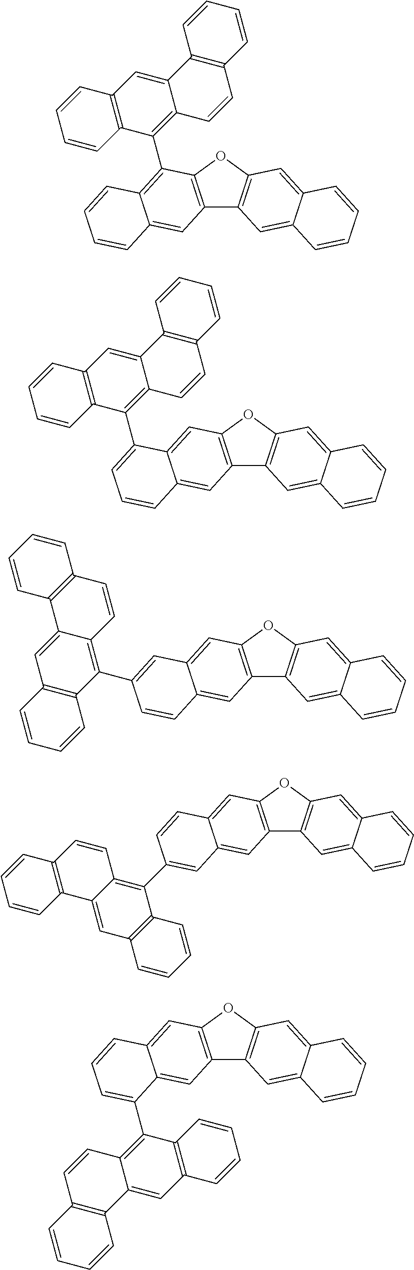

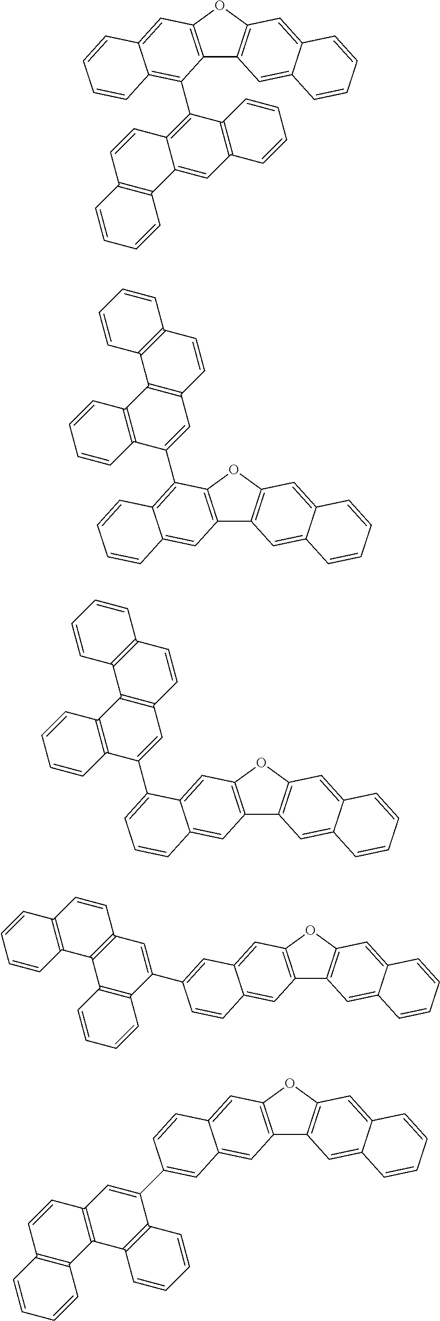

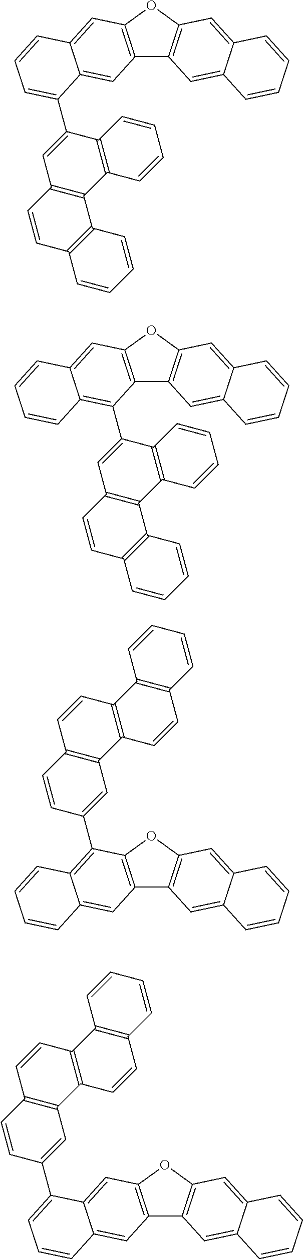

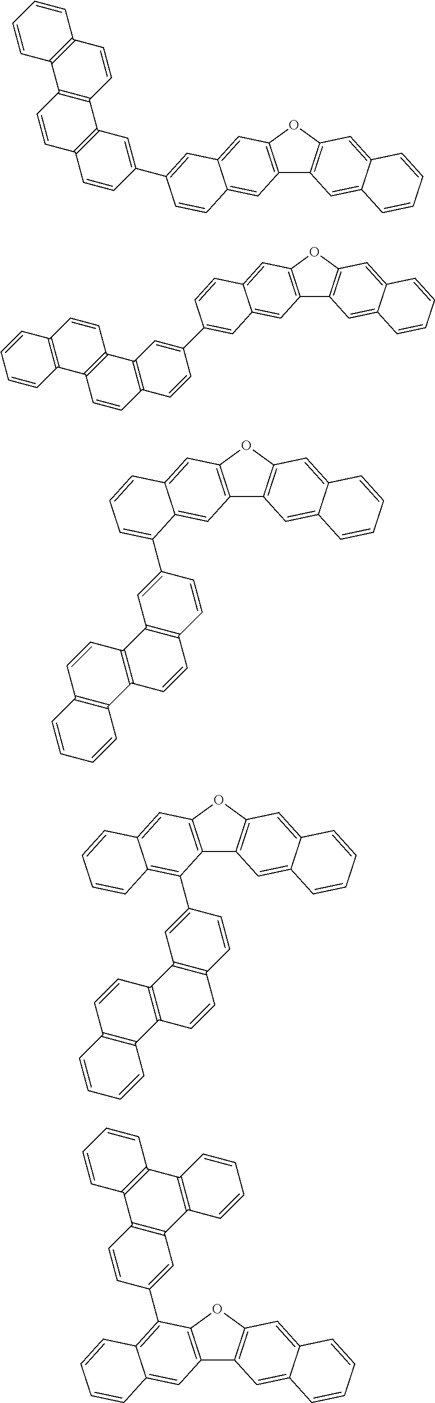

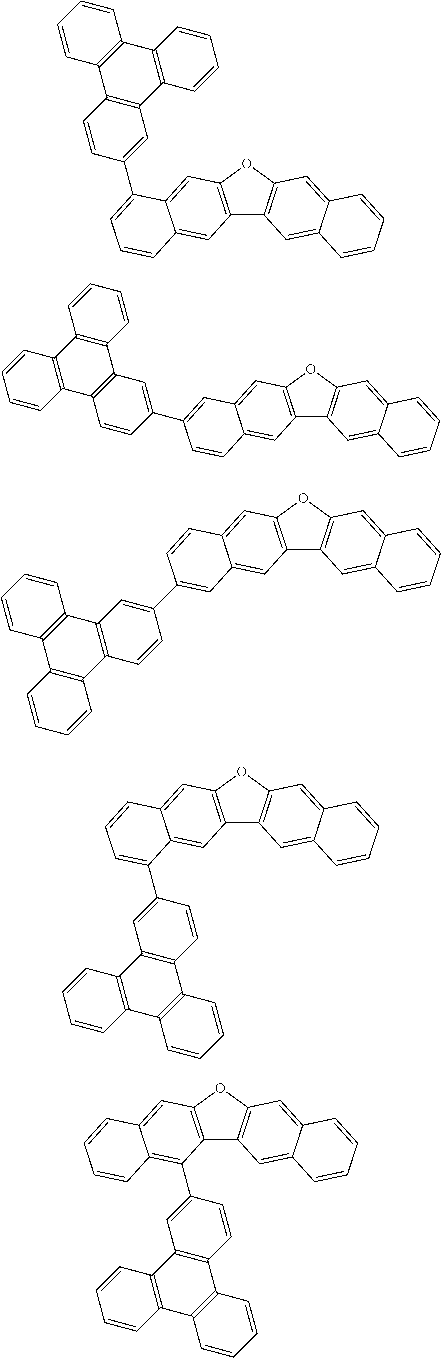

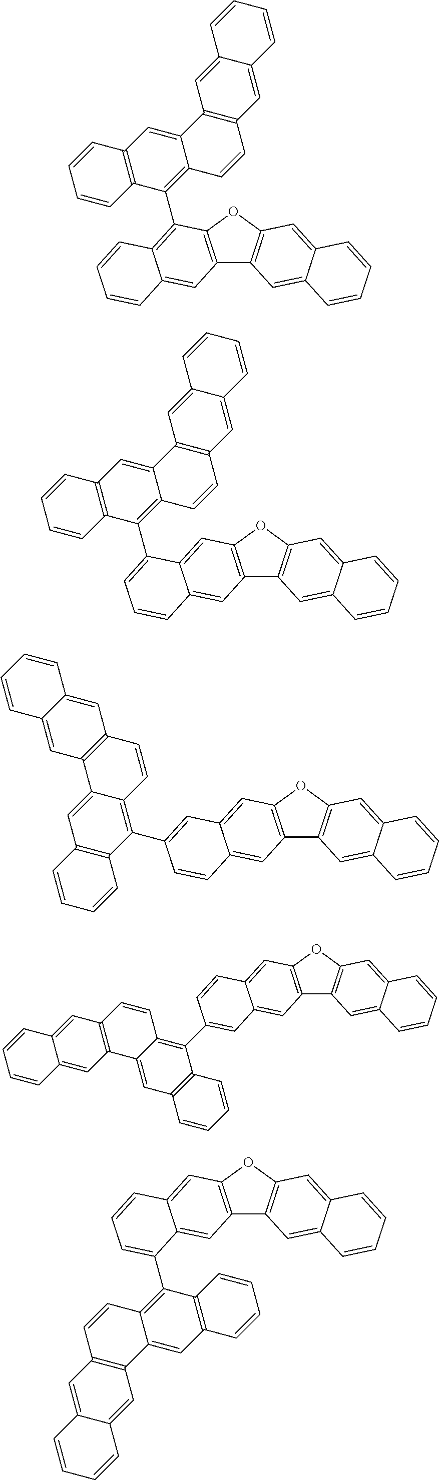 [SMILES: c1ccc2cc3c(ccc4c(-c5c6ccccc6cc6c5oc5cc7ccccc7cc56)c5ccccc5cc43)cc2c1 ; c1ccc2cc3c(ccc4c(-c5cccc6cc7c(cc56)oc5cc6ccccc6cc57)c5ccccc5cc43)cc2c1 ; c1ccc2cc3c(ccc4c(-c5ccc6cc7c(cc6c5)oc5cc6ccccc6cc57)c5ccccc5cc43)cc2c1 ; c1ccc2cc3c(ccc4c(-c5ccc6cc7oc8cc9ccccc9cc8c7cc6c5)c5ccccc5cc43)cc2c1 ; c1ccc2cc3c(ccc4c(-c5cccc6cc7oc8cc9ccccc9cc8c7cc56)c5ccccc5cc43)cc2c1]

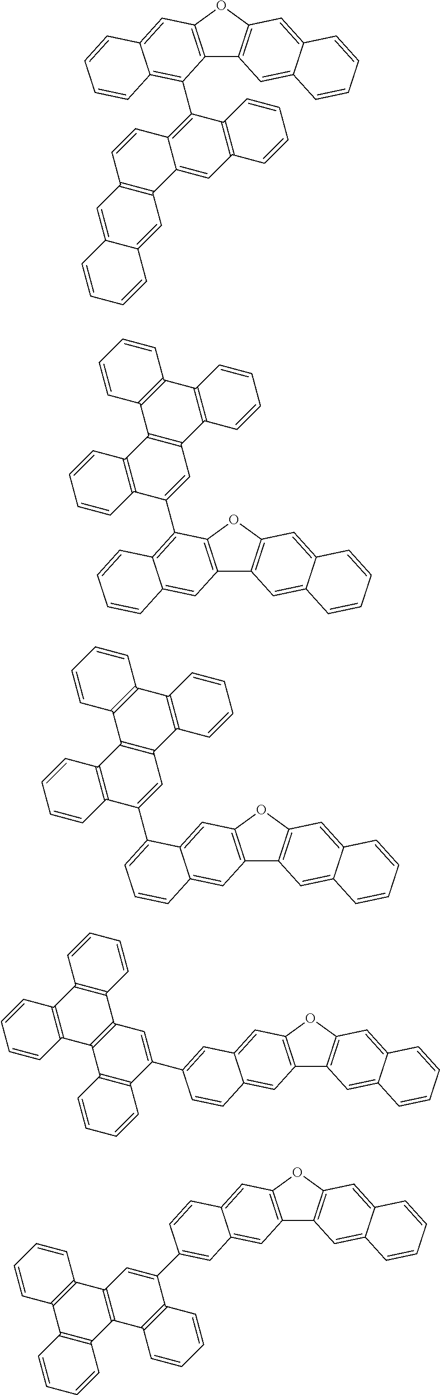

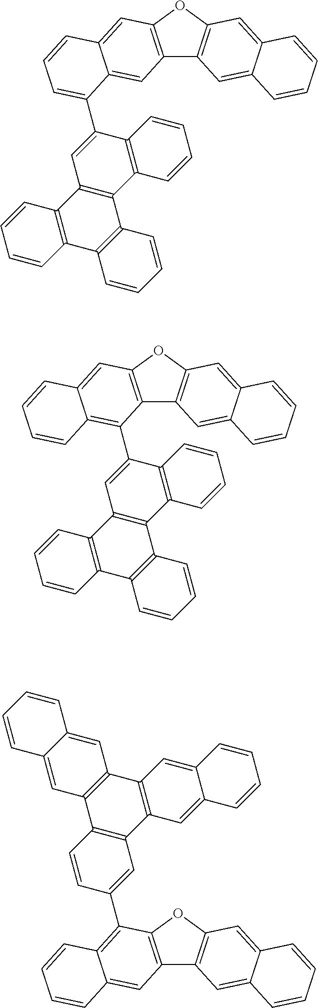 [SMILES: c1ccc2cc3c(cc2c1)oc1cc2cccc(-c4cc5c6ccccc6c6ccccc6c5c5ccccc45)c2cc13 ; c1ccc2cc3c(cc2c1)oc1cc2ccccc2c(-c2cc4c5ccccc5c5ccccc5c4c4ccccc24)c13 ; c1ccc2cc3c(cc2c1)oc1c(-c2ccc4c(c2)c2cc5ccccc5cc2c2cc5ccccc5cc42)c2ccccc2cc13]

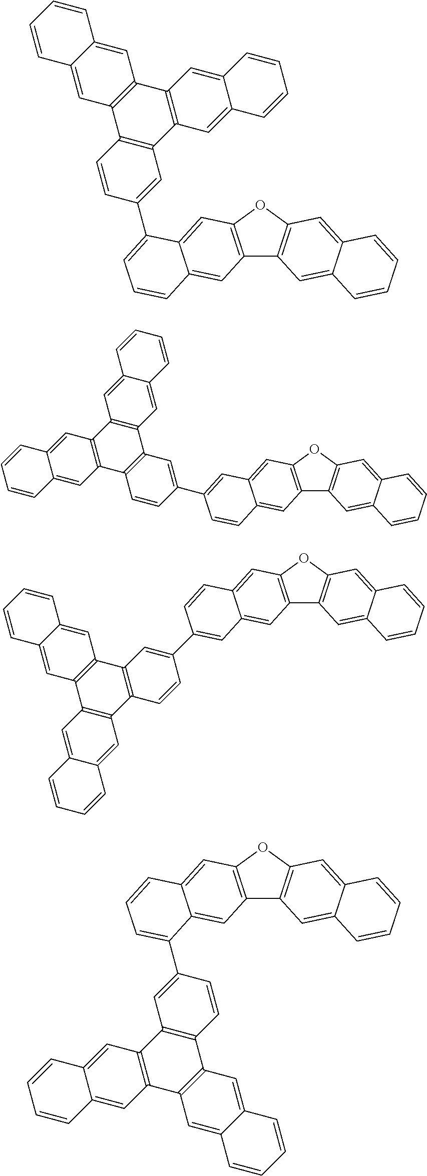

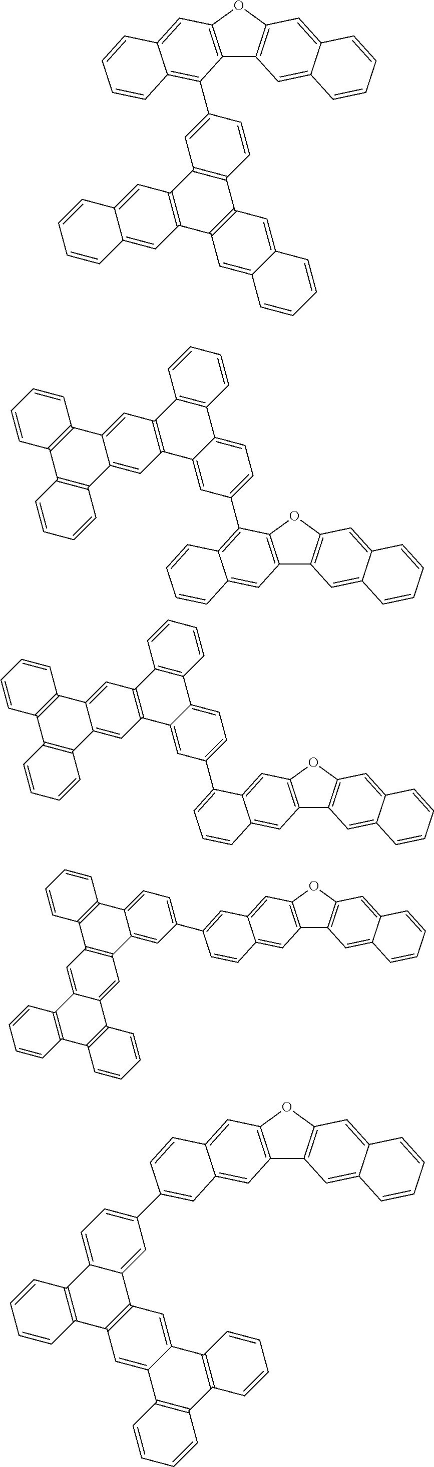

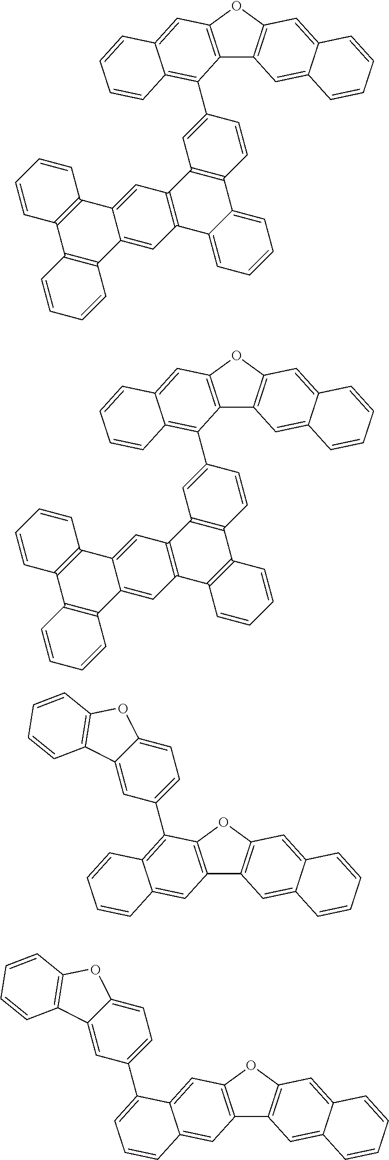

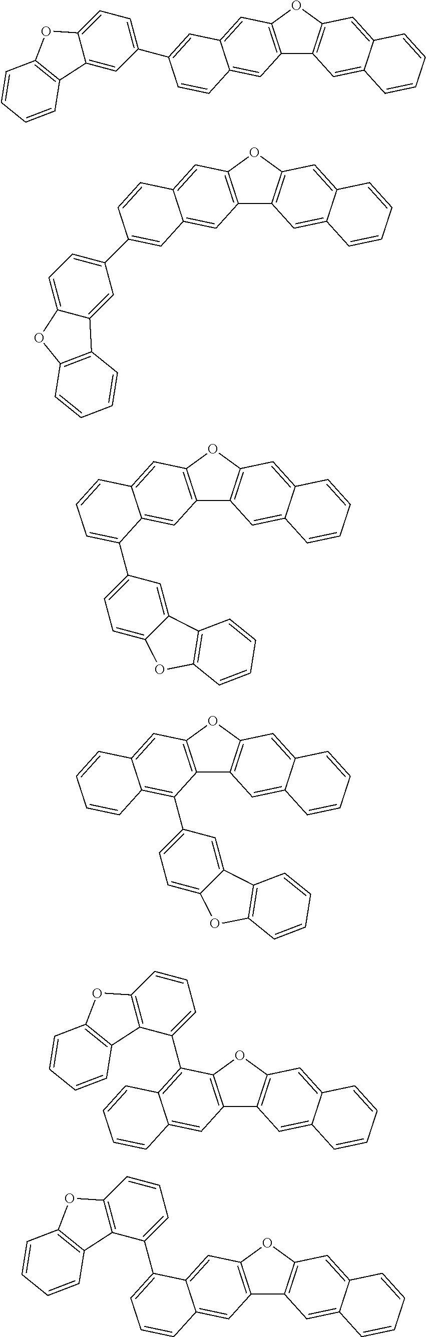

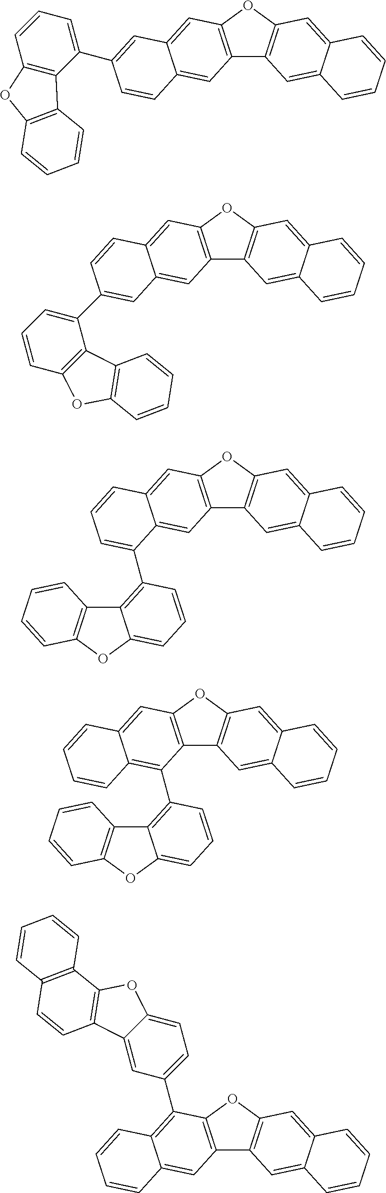 [SMILES: c1ccc2cc3c(cc2c1)oc1cc2cc(-c4cccc5oc6ccccc6c45)ccc2cc13 ; c1ccc2cc3c(cc2c1)oc1cc2ccc(-c4cccc5oc6ccccc6c45)cc2cc13 ; c1ccc2cc3c(cc2c1)oc1cc2cccc(-c4cccc5oc6ccccc6c45)c2cc13 ; c1ccc2cc3c(cc2c1)oc1cc2ccccc2c(-c2cccc4oc5ccccc5c24)c13 ; c1ccc2cc3c(cc2c1)oc1c(-c2ccc4oc5c6ccccc6ccc5c4c2)c2ccccc2cc13]

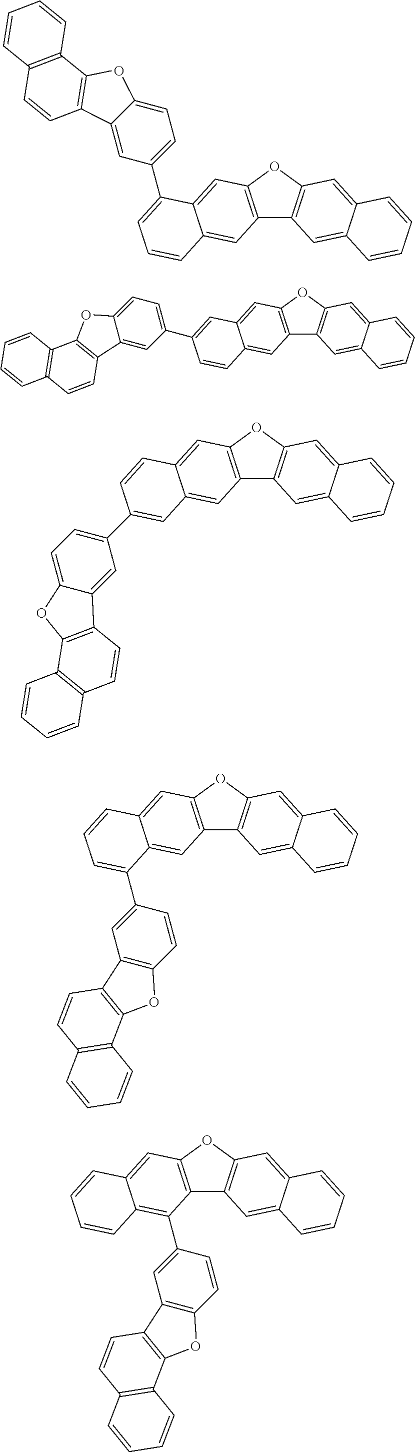

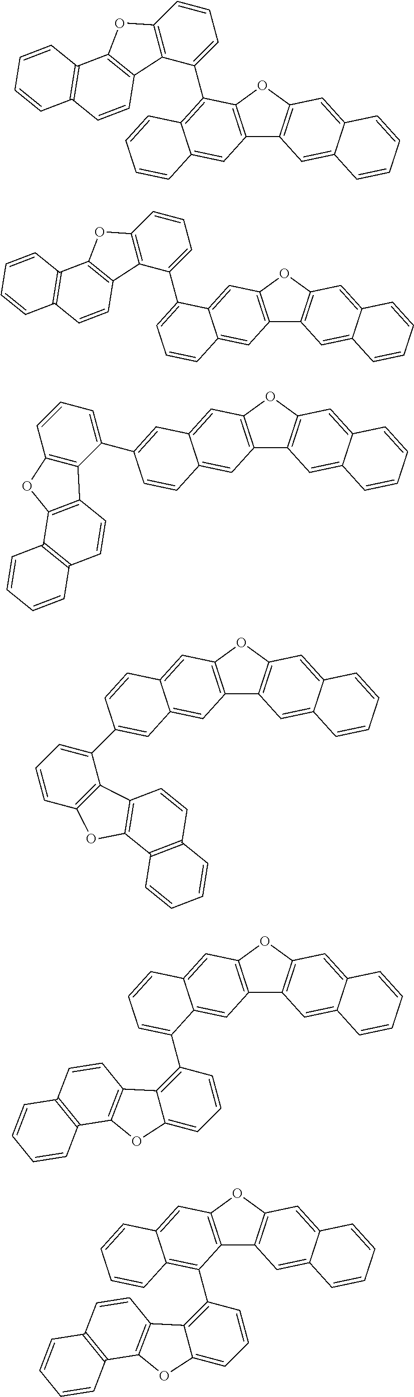

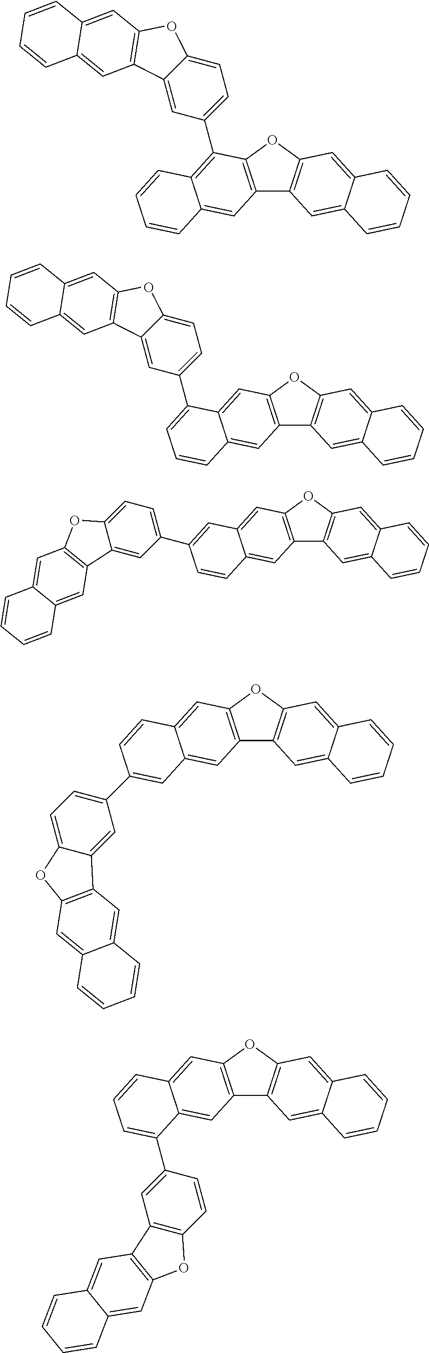 [SMILES: c1ccc2cc3c(cc2c1)oc1ccc(-c2c4ccccc4cc4c2oc2cc5ccccc5cc24)cc13 ; c1ccc2cc3c(cc2c1)oc1ccc(-c2cccc4cc5c(cc24)oc2cc4ccccc4cc25)cc13 ; c1ccc2cc3c(cc2c1)oc1ccc(-c2ccc4cc5c(cc4c2)oc2cc4ccccc4cc25)cc13 ; c1ccc2cc3c(cc2c1)oc1ccc(-c2ccc4cc5oc6cc7ccccc7cc6c5cc4c2)cc13 ; c1ccc2cc3c(cc2c1)oc1ccc(-c2cccc4cc5oc6cc7ccccc7cc6c5cc24)cc13]

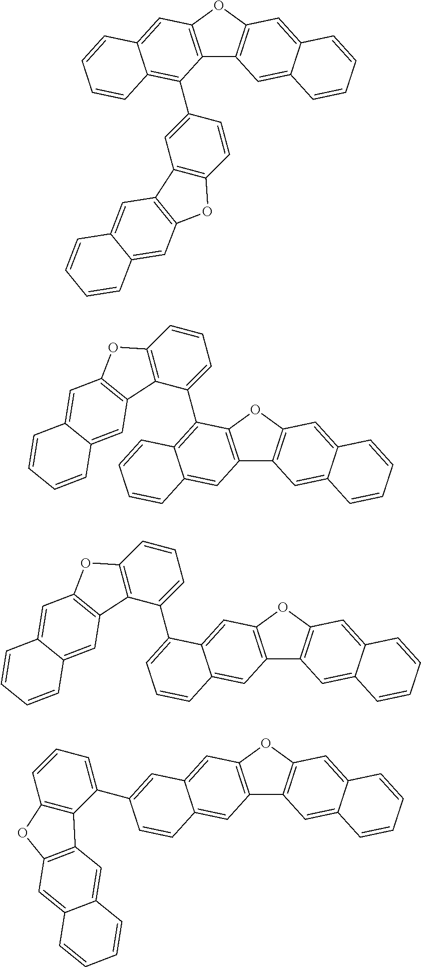

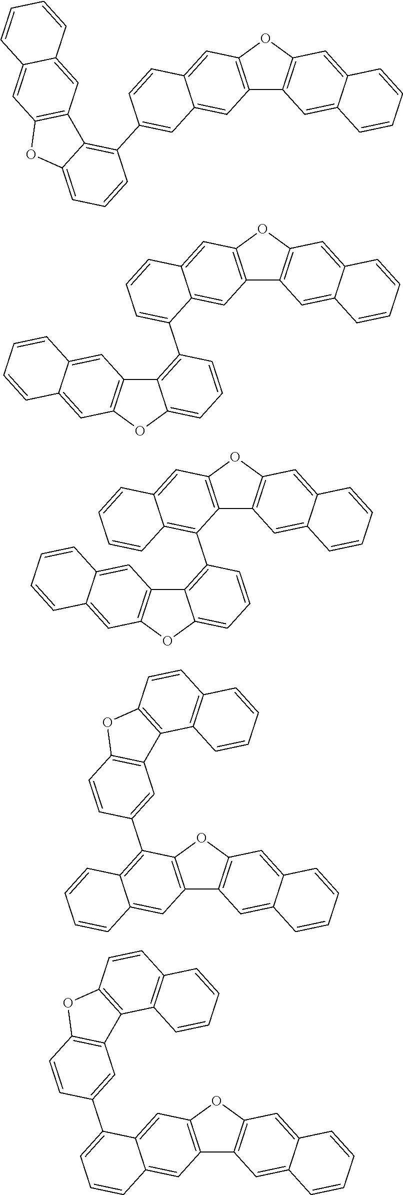

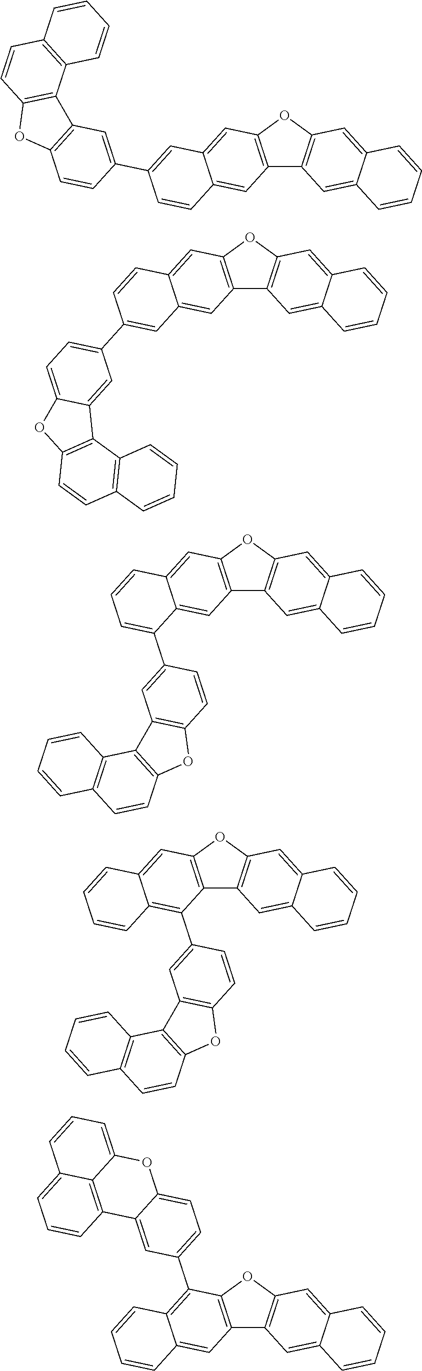

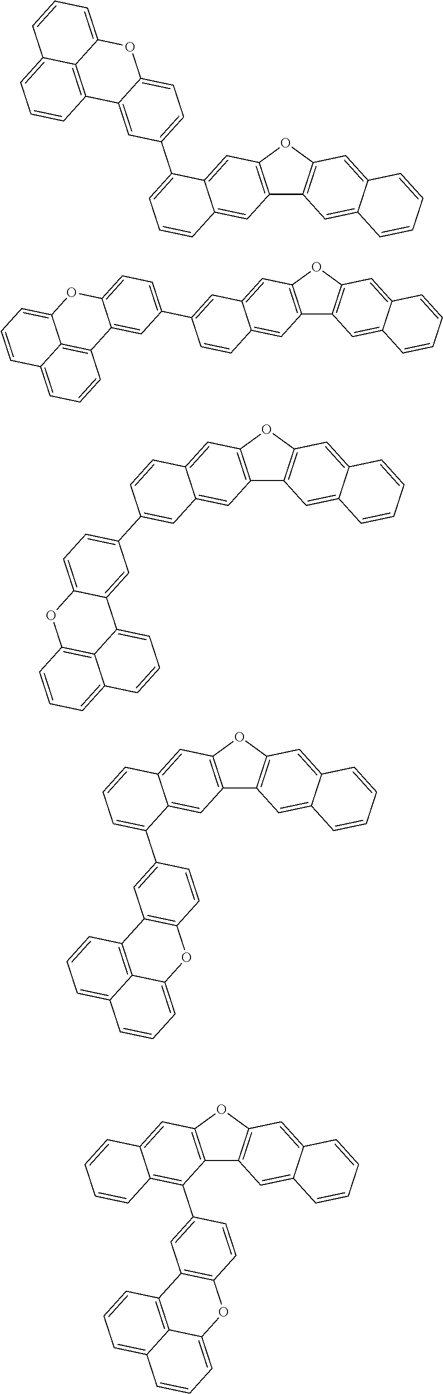

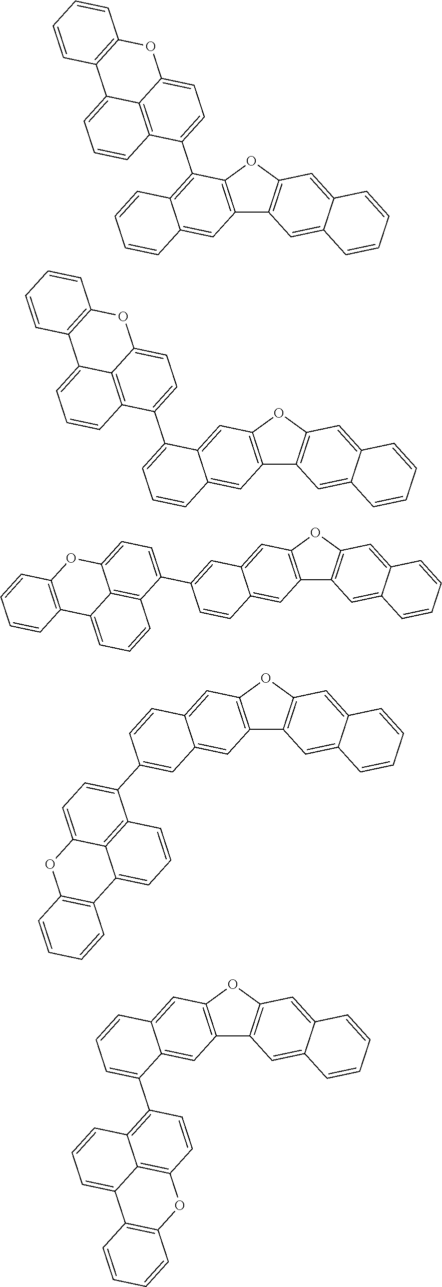

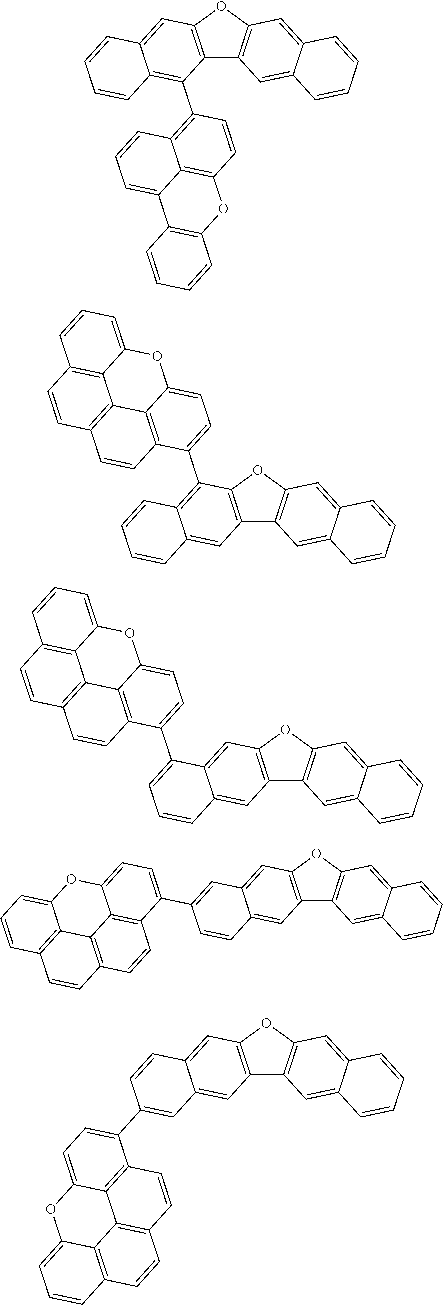

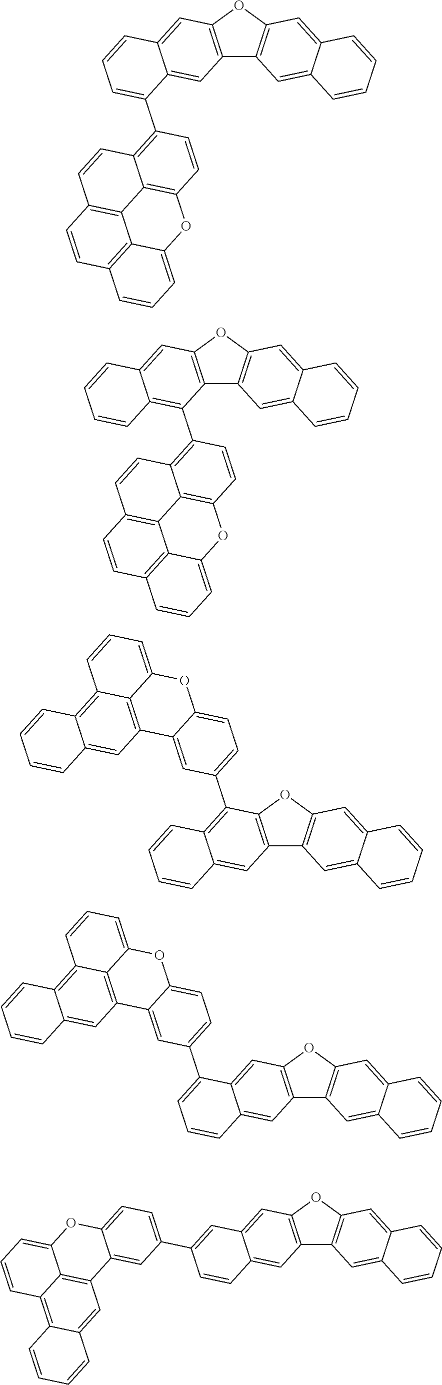

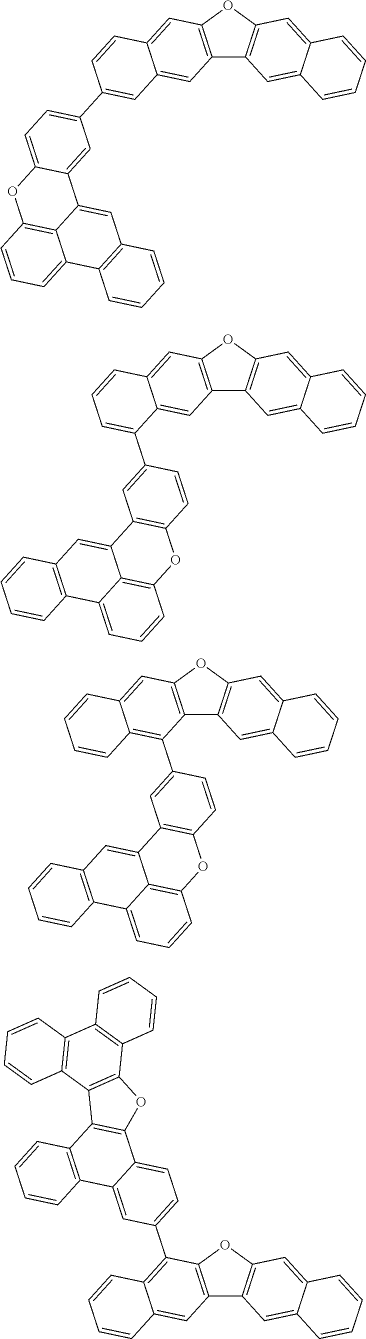

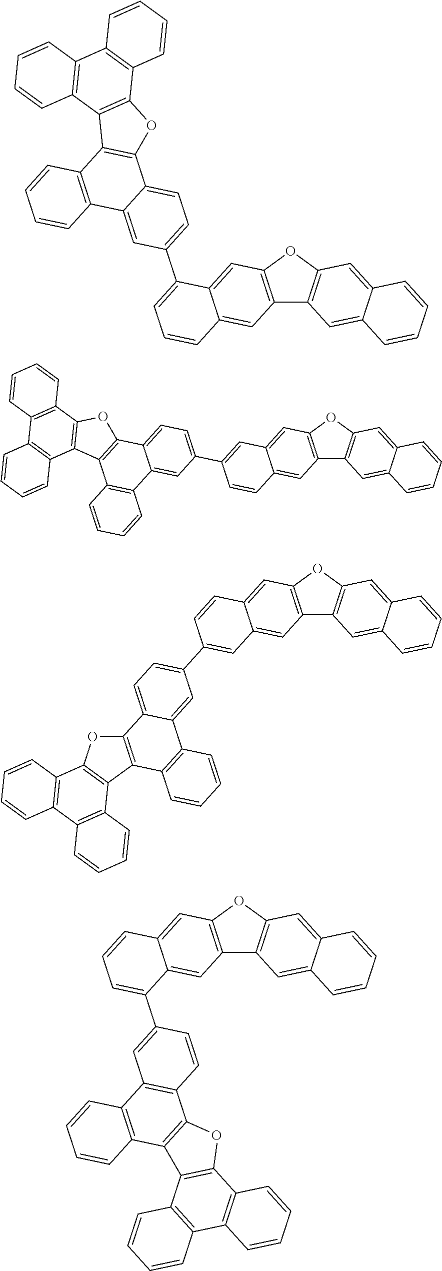 [SMILES: c1ccc2cc3c(cc2c1)oc1cc2c(-c4ccc5c(c4)c4ccccc4c4c5oc5c6ccccc6c6ccccc6c54)cccc2cc13 ; c1ccc2cc3c(cc2c1)oc1cc2cc(-c4ccc5c(c4)c4ccccc4c4c5oc5c6ccccc6c6ccccc6c54)ccc2cc13 ; c1ccc2cc3c(cc2c1)oc1cc2ccc(-c4ccc5c(c4)c4ccccc4c4c5oc5c6ccccc6c6ccccc6c54)cc2cc13 ; c1ccc2cc3c(cc2c1)oc1cc2cccc(-c4ccc5c(c4)c4ccccc4c4c5oc5c6ccccc6c6ccccc6c54)c2cc13]

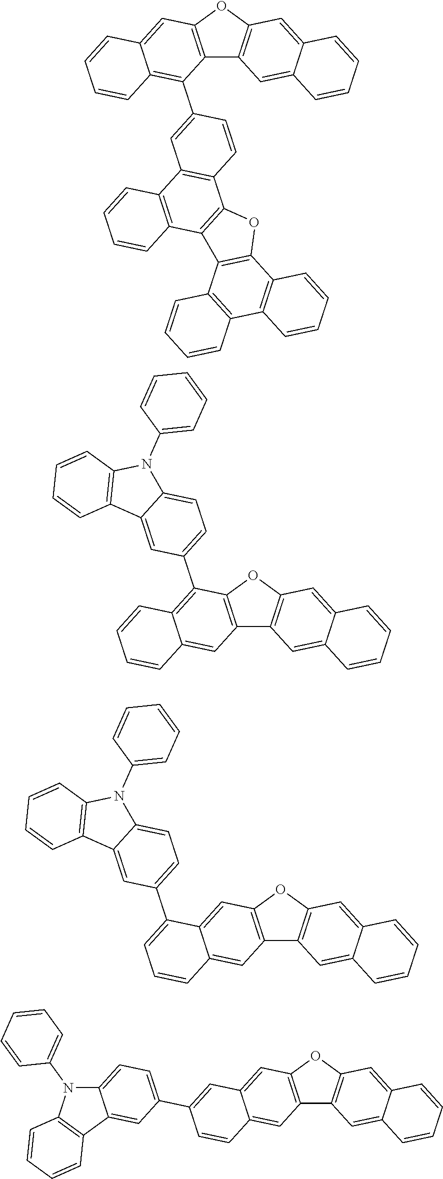

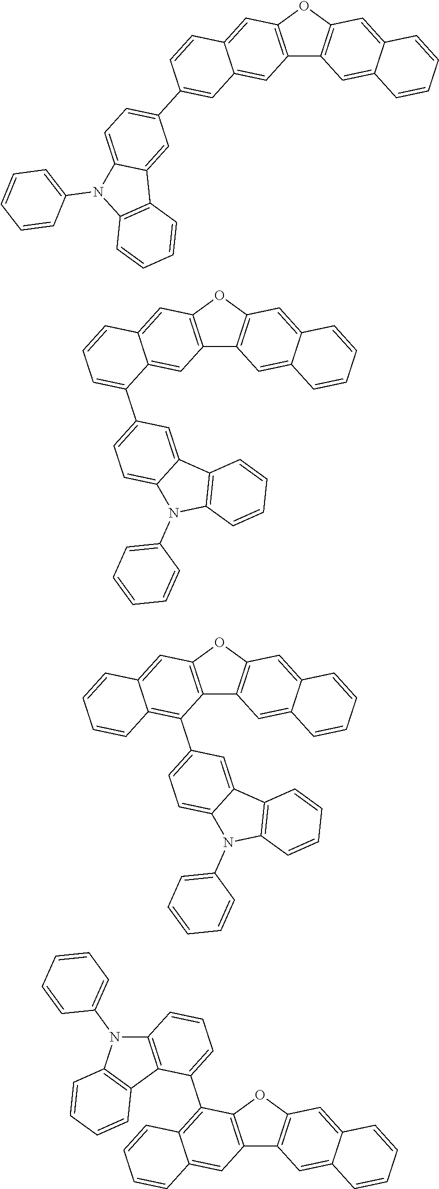

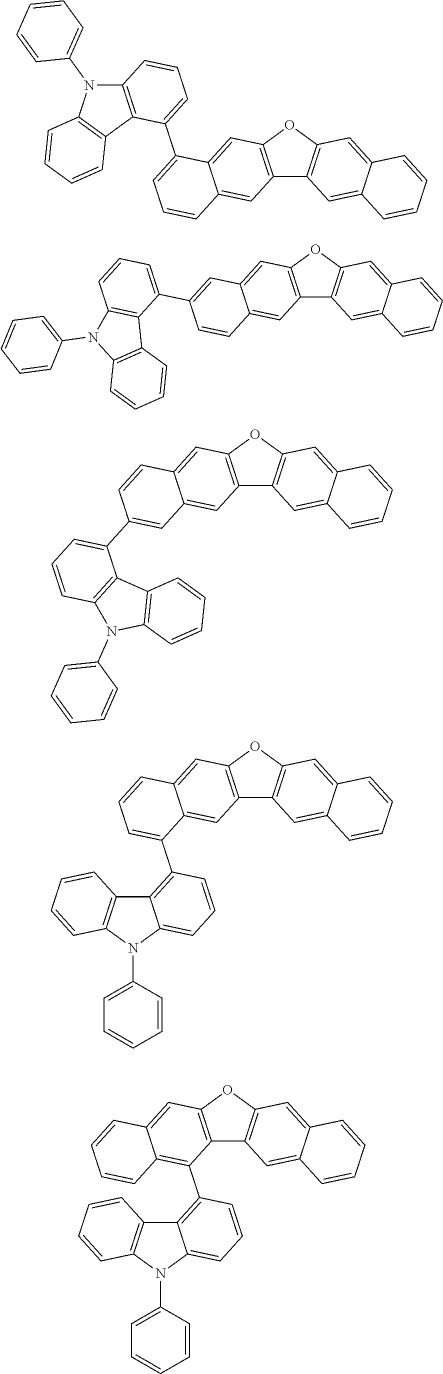

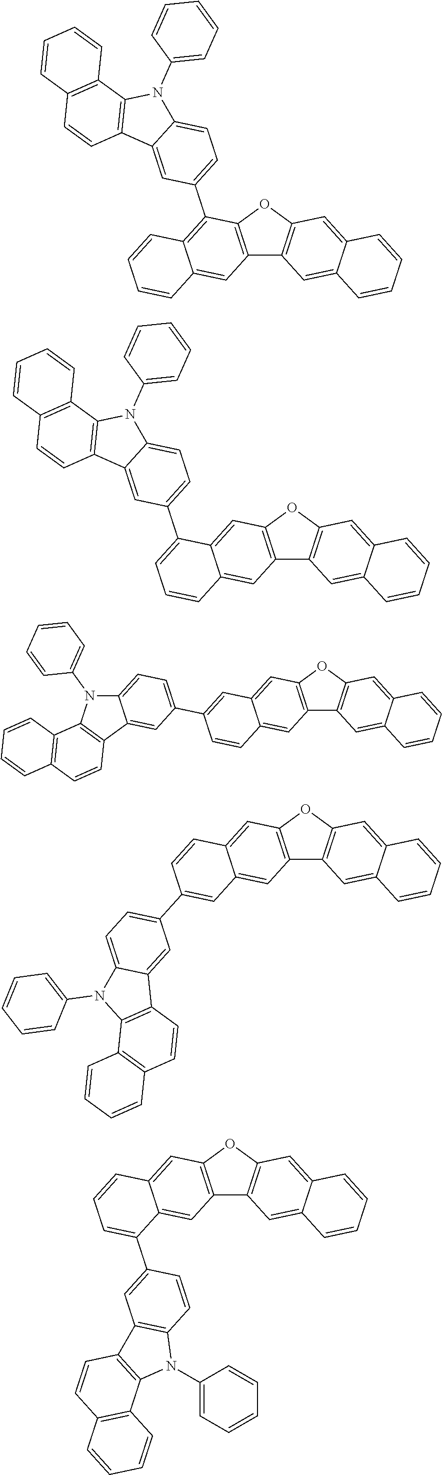

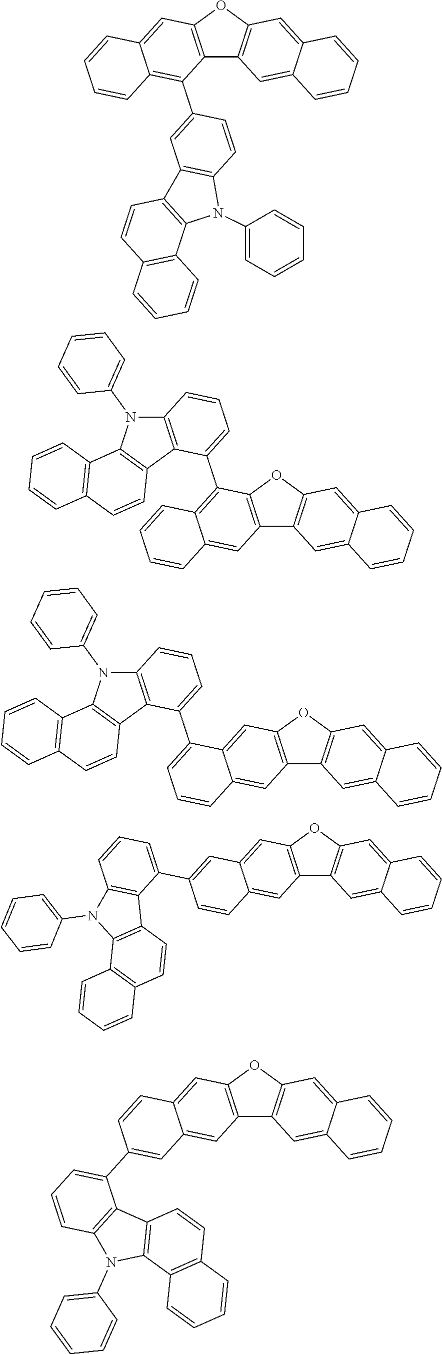

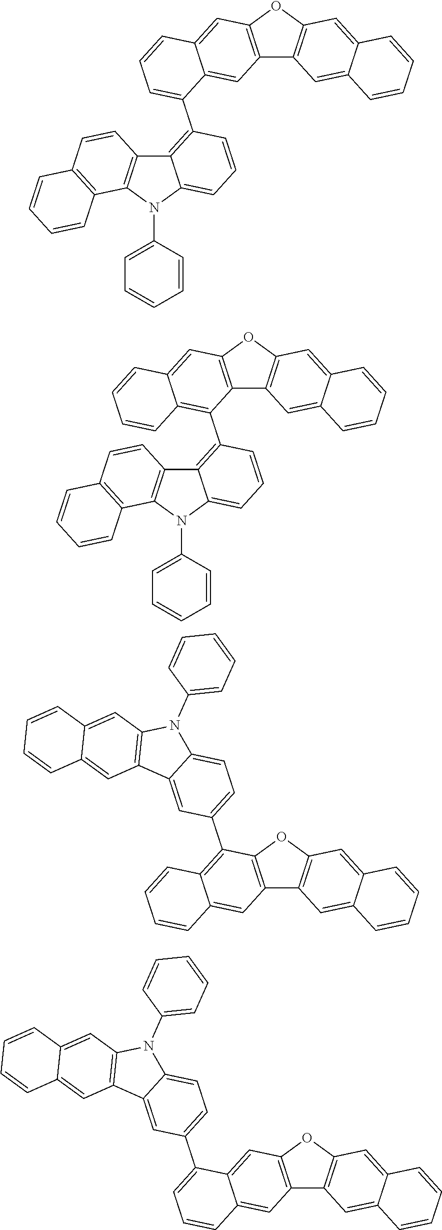

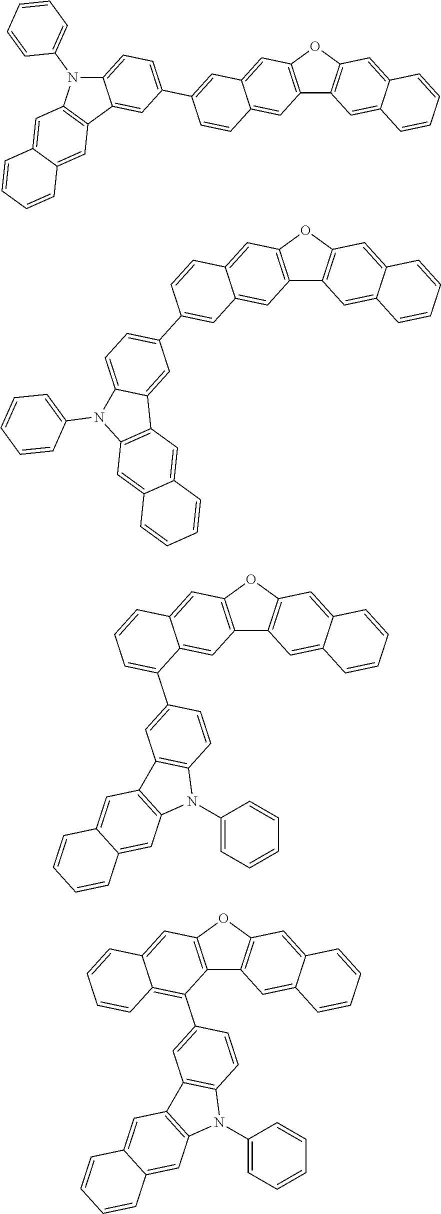 [SMILES: c1ccc(-n2c3ccc(-c4ccc5cc6c(cc5c4)oc4cc5ccccc5cc46)cc3c3cc4ccccc4cc32)cc1 ; c1ccc(-n2c3ccc(-c4ccc5cc6oc7cc8ccccc8cc7c6cc5c4)cc3c3cc4ccccc4cc32)cc1 ; c1ccc(-n2c3ccc(-c4cccc5cc6oc7cc8ccccc8cc7c6cc45)cc3c3cc4ccccc4cc32)cc1 ; c1ccc(-n2c3ccc(-c4c5ccccc5cc5oc6cc7ccccc7cc6c45)cc3c3cc4ccccc4cc32)cc1]

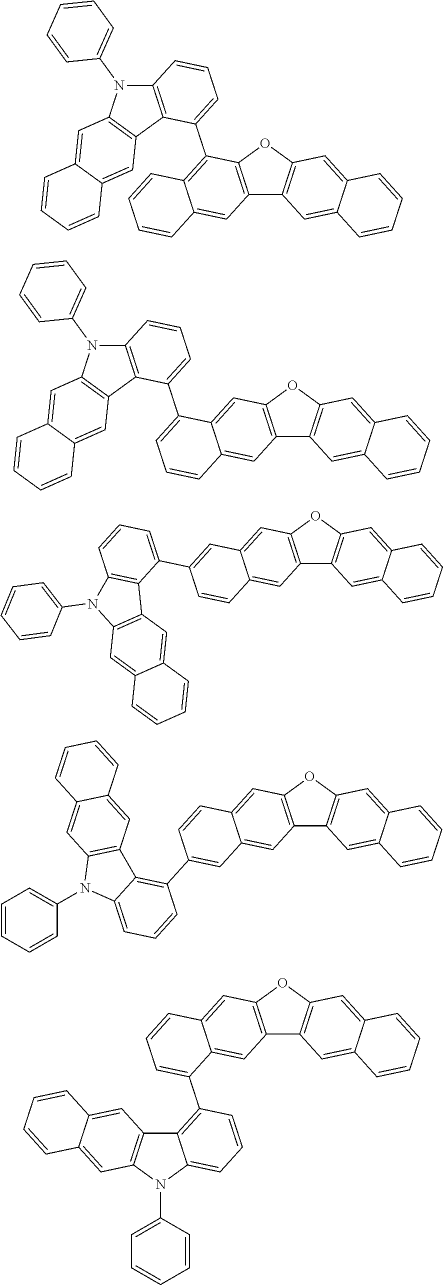

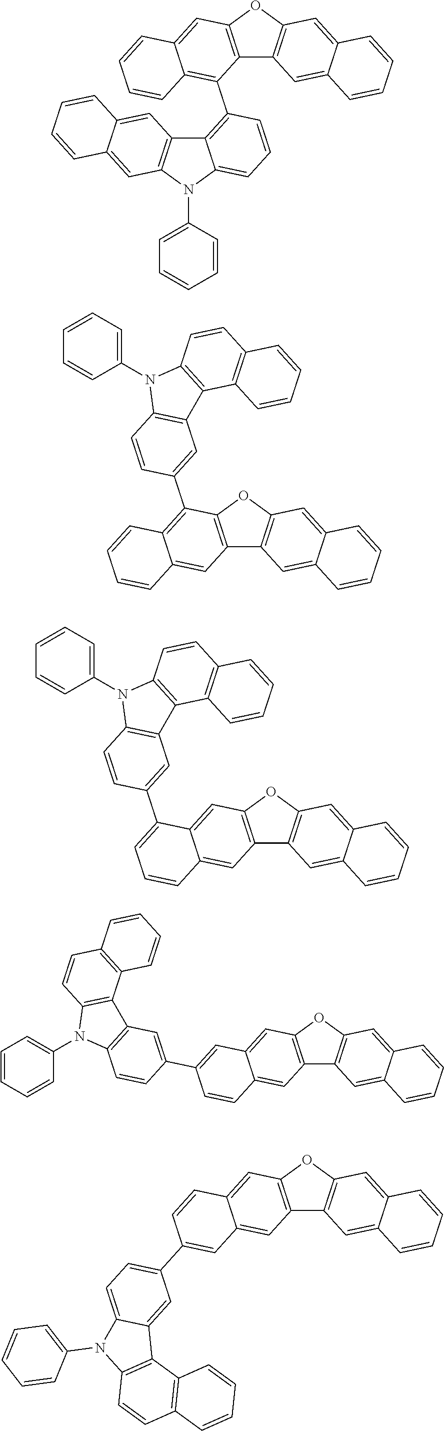

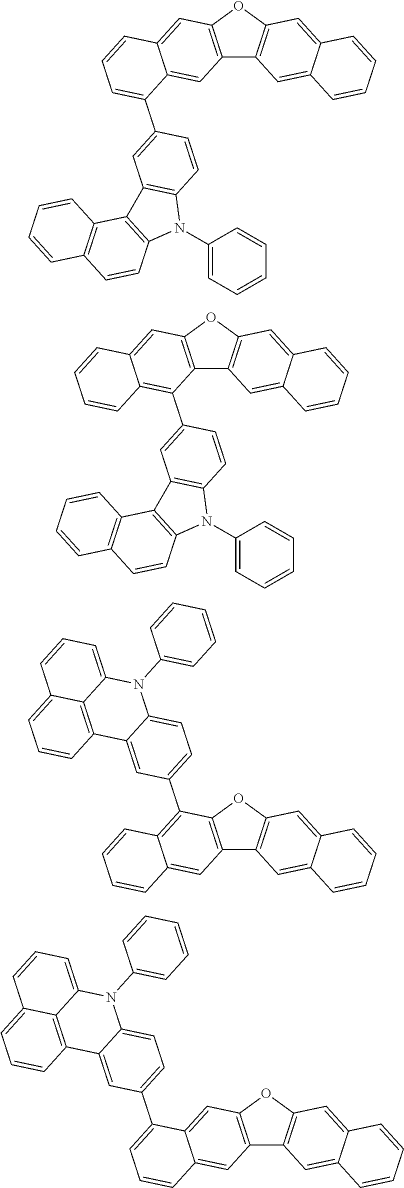

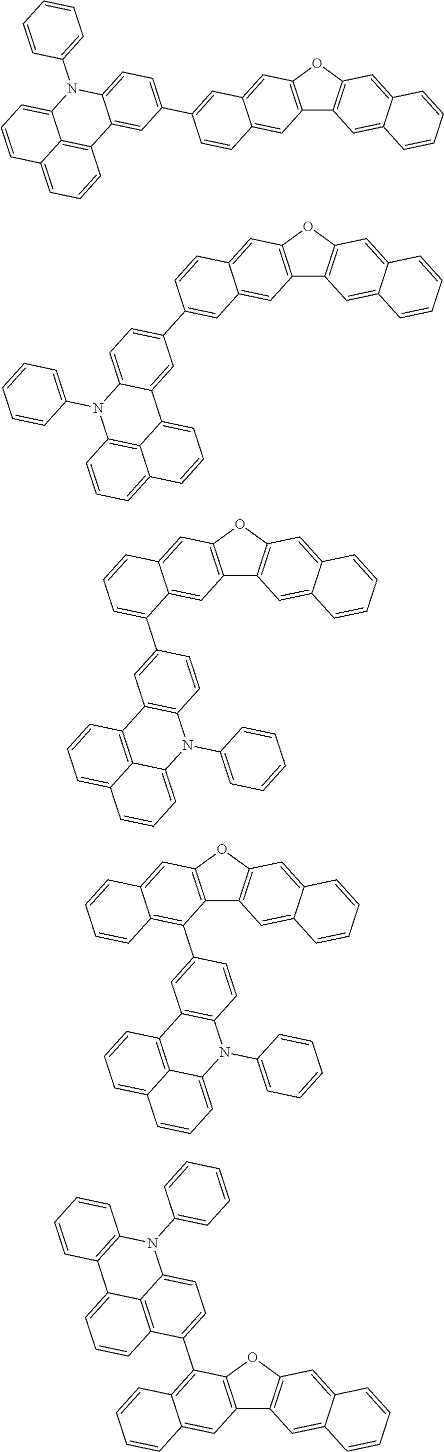

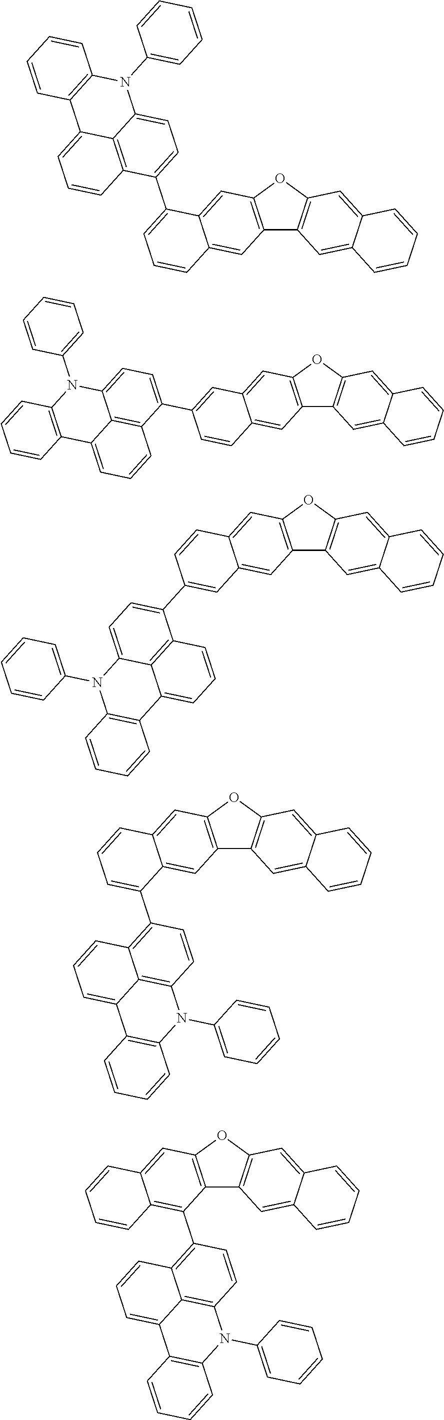 [SMILES: c1ccc(N2c3ccccc3-c3cccc4c(-c5cccc6cc7c(cc56)oc5cc6ccccc6cc57)ccc2c34)cc1 ; c1ccc(N2c3ccccc3-c3cccc4c(-c5ccc6cc7c(cc6c5)oc5cc6ccccc6cc57)ccc2c34)cc1 ; c1ccc(N2c3ccccc3-c3cccc4c(-c5ccc6cc7oc8cc9ccccc9cc8c7cc6c5)ccc2c34)cc1 ; c1ccc(N2c3ccccc3-c3cccc4c(-c5cccc6cc7oc8cc9ccccc9cc8c7cc56)ccc2c34)cc1 ; c1ccc(N2c3ccccc3-c3cccc4c(-c5c6ccccc6cc6oc7cc8ccccc8cc7c56)ccc2c34)cc1]

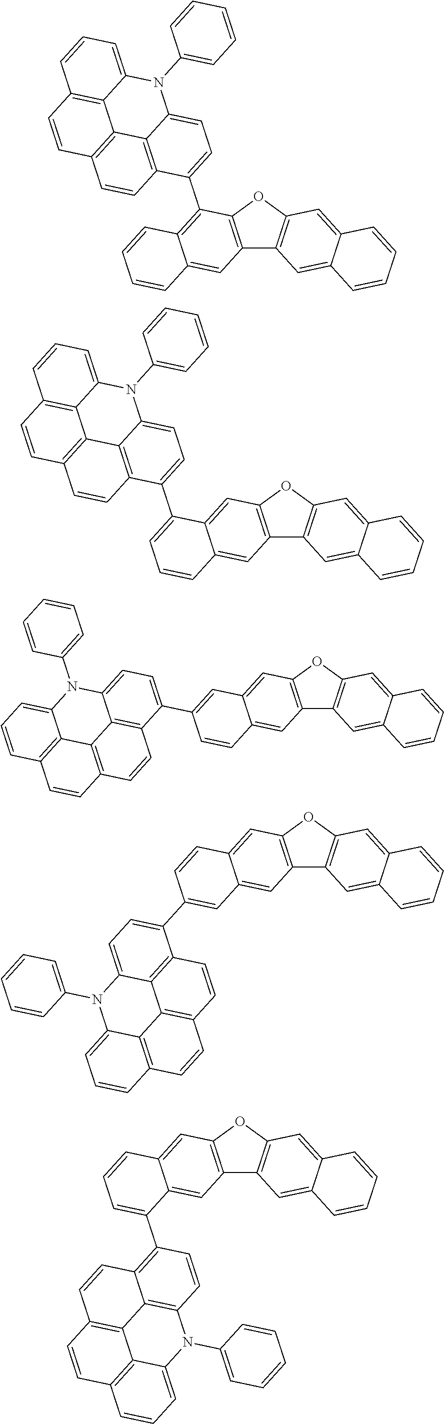

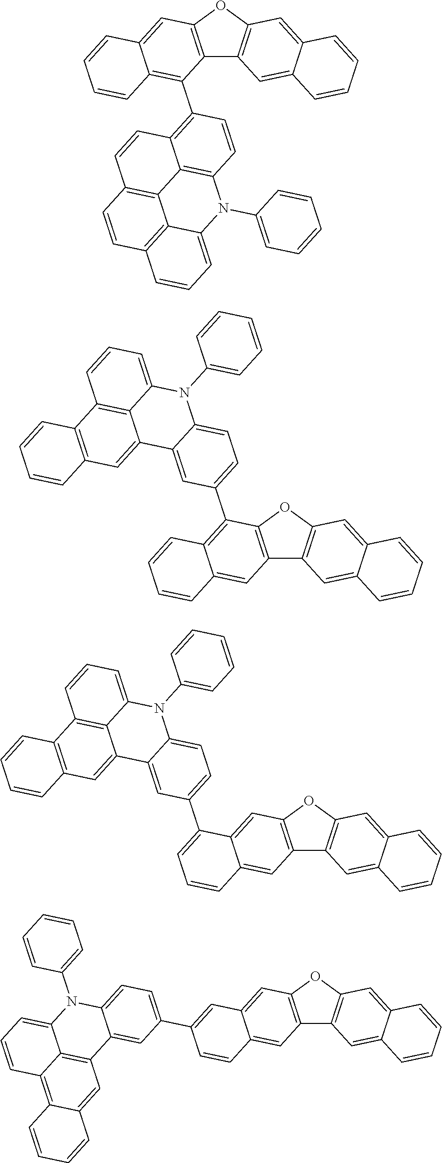

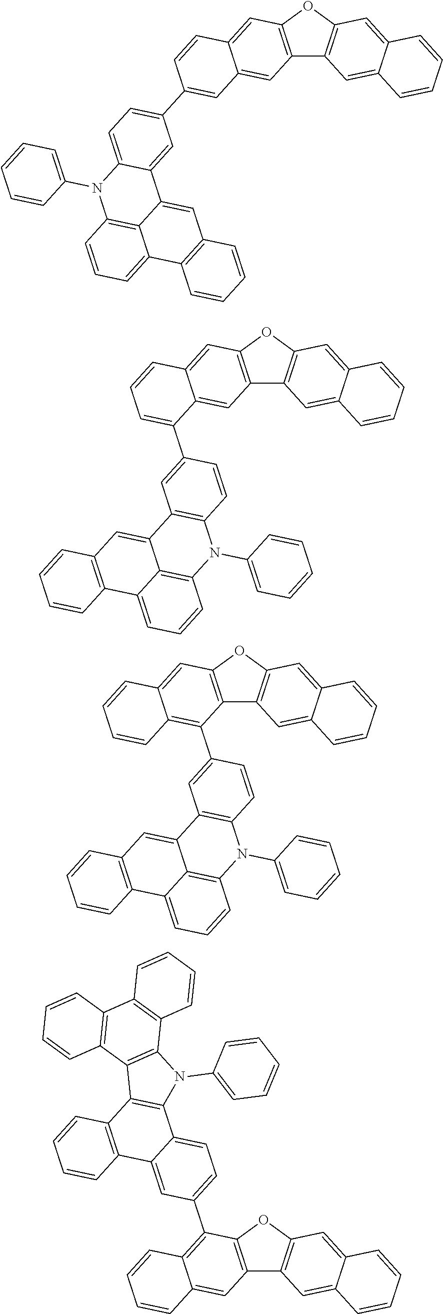

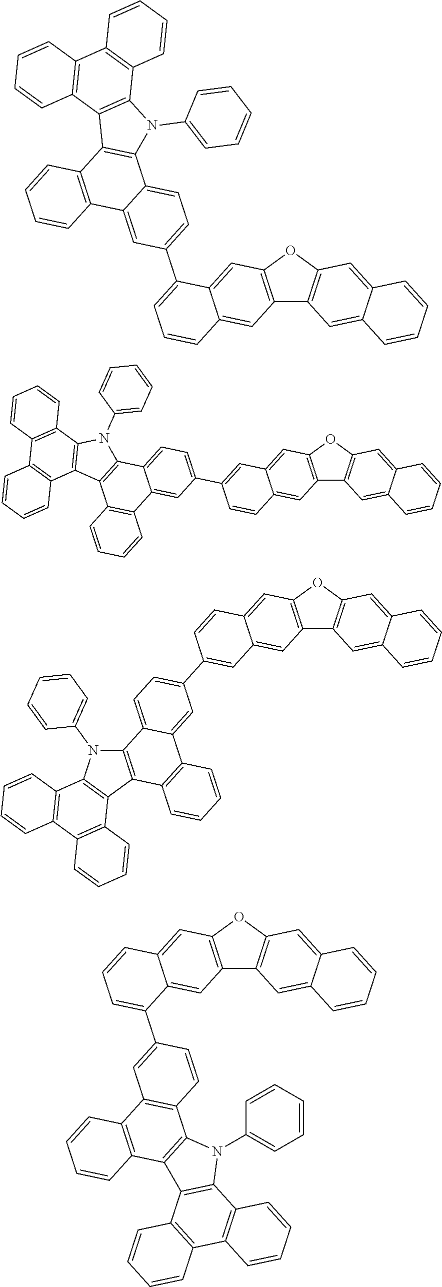

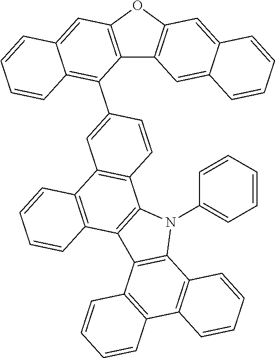 [SMILES: c1ccc(-n2c3c4ccccc4c4ccccc4c3c3c4ccccc4c4cc(-c5c6ccccc6cc6oc7cc8ccccc8cc7c56)ccc4c32)cc1]

[chemical structure]

[chemical structure]

[chemical structure]

[chemical structure]

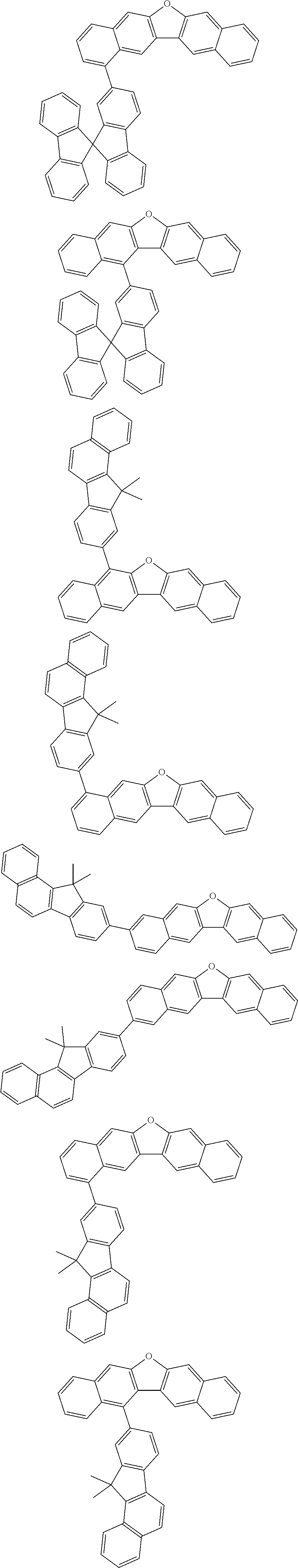

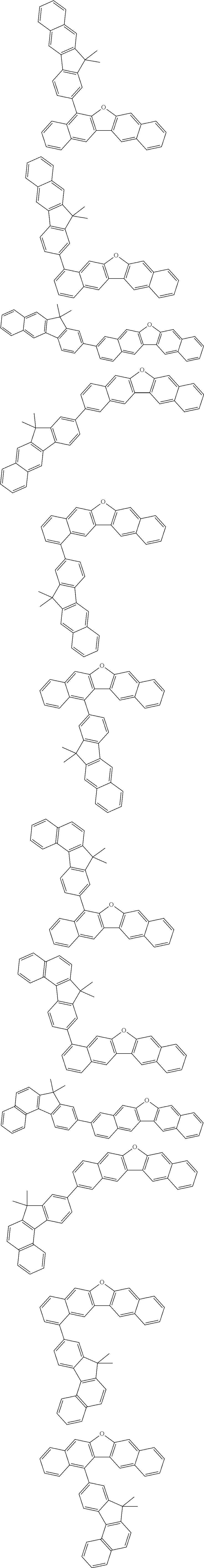

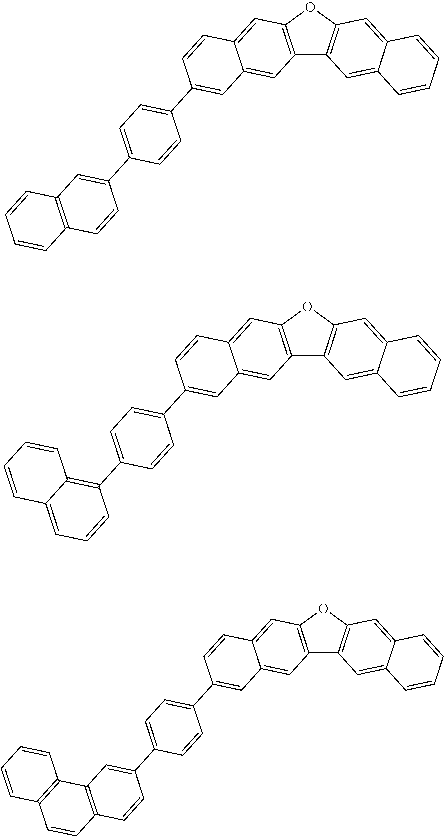 [SMILES: c1ccc2cc(-c3ccc(-c4ccc5cc6oc7cc8ccccc8cc7c6cc5c4)cc3)ccc2c1 ; c1ccc2cc3c(cc2c1)oc1cc2ccc(-c4ccc(-c5cccc6ccccc56)cc4)cc2cc13 ; c1ccc2cc3c(cc2c1)oc1cc2ccc(-c4ccc(-c5ccc6ccc7ccccc7c6c5)cc4)cc2cc13]

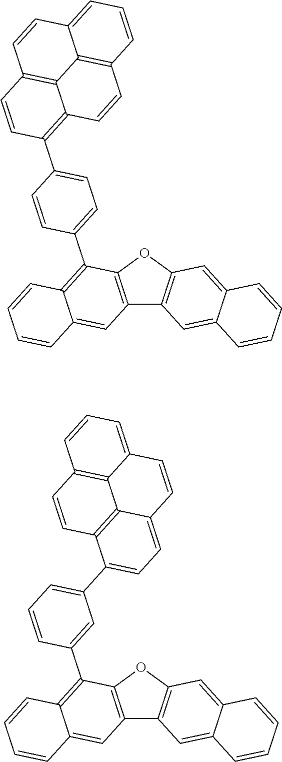 [SMILES: c1ccc2cc3c(cc2c1)oc1c(-c2ccc(-c4ccc5ccc6cccc7ccc4c5c67)cc2)c2ccccc2cc13 ; c1cc(-c2ccc3ccc4cccc5ccc2c3c45)cc(-c2c3ccccc3cc3c2oc2cc4ccccc4cc23)c1]

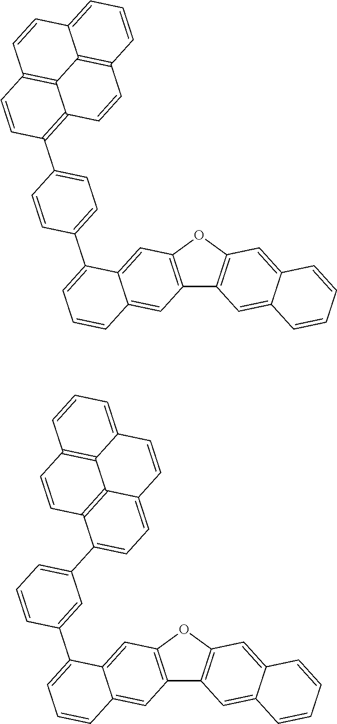 [SMILES: c1ccc2cc3c(cc2c1)oc1cc2c(-c4ccc(-c5ccc6ccc7cccc8ccc5c6c78)cc4)cccc2cc13 ; c1cc(-c2cccc3cc4c(cc23)oc2cc3ccccc3cc24)cc(-c2ccc3ccc4cccc5ccc2c3c45)c1]

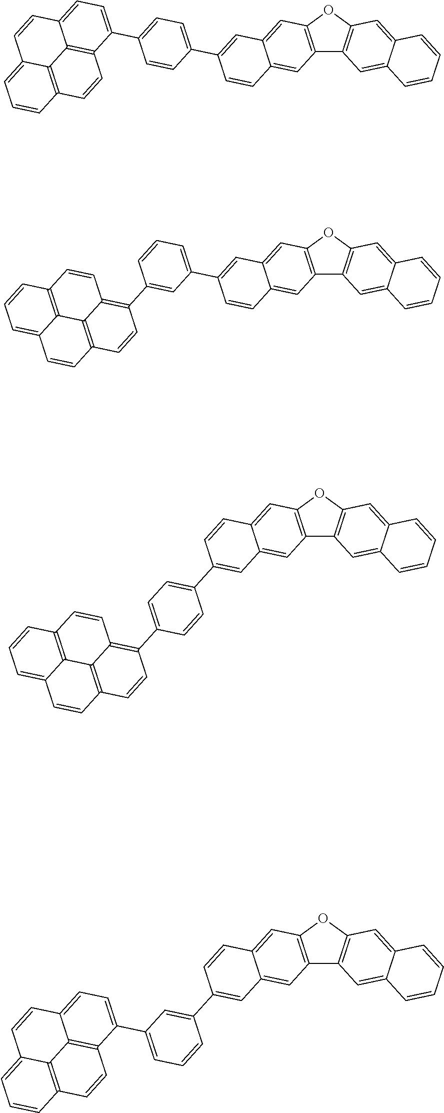 [SMILES: c1ccc2cc3c(cc2c1)oc1cc2cc(-c4ccc(-c5ccc6ccc7cccc8ccc5c6c78)cc4)ccc2cc13 ; c1cc(-c2ccc3cc4c(cc3c2)oc2cc3ccccc3cc24)cc(-c2ccc3ccc4cccc5ccc2c3c45)c1 ; c1ccc2cc3c(cc2c1)oc1cc2ccc(-c4ccc(-c5ccc6ccc7cccc8ccc5c6c78)cc4)cc2cc13 ; c1cc(-c2ccc3cc4oc5cc6ccccc6cc5c4cc3c2)cc(-c2ccc3ccc4cccc5ccc2c3c45)c1]

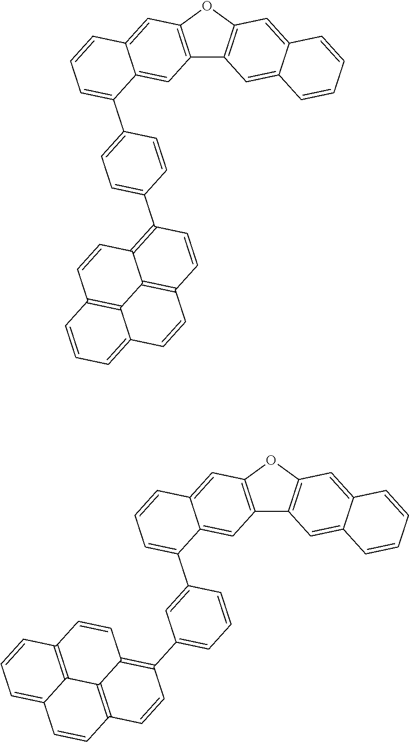 [SMILES: c1ccc2cc3c(cc2c1)oc1cc2cccc(-c4ccc(-c5ccc6ccc7cccc8ccc5c6c78)cc4)c2cc13 ; c1cc(-c2cccc3cc4oc5cc6ccccc6cc5c4cc23)cc(-c2ccc3ccc4cccc5ccc2c3c45)c1]

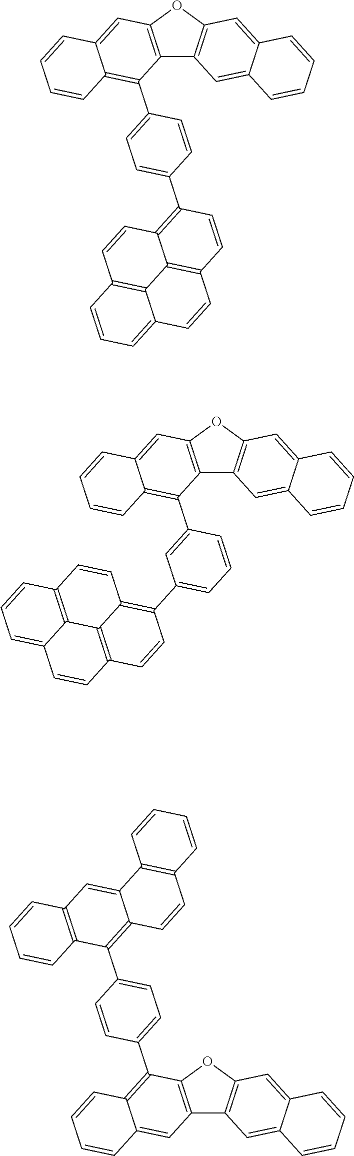 [SMILES: c1ccc2cc3c(cc2c1)oc1cc2ccccc2c(-c2ccc(-c4ccc5ccc6cccc7ccc4c5c67)cc2)c13 ; c1cc(-c2ccc3ccc4cccc5ccc2c3c45)cc(-c2c3ccccc3cc3oc4cc5ccccc5cc4c23)c1 ; c1ccc2cc3c(cc2c1)oc1c(-c2ccc(-c4c5ccccc5cc5c4ccc4ccccc45)cc2)c2ccccc2cc13]

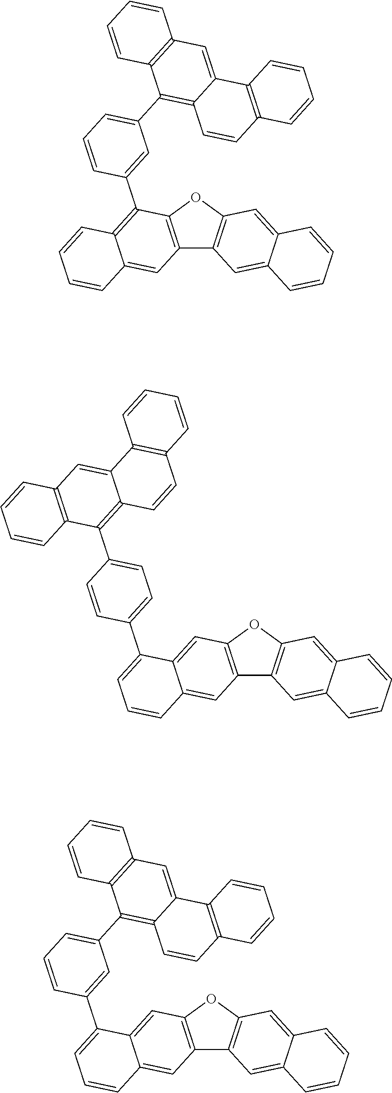 [SMILES: c1cc(-c2c3ccccc3cc3c2ccc2ccccc23)cc(-c2c3ccccc3cc3c2oc2cc4ccccc4cc23)c1 ; c1ccc2cc3c(cc2c1)oc1cc2c(-c4ccc(-c5c6ccccc6cc6c5ccc5ccccc56)cc4)cccc2cc13 ; c1cc(-c2cccc3cc4c(cc23)oc2cc3ccccc3cc24)cc(-c2c3ccccc3cc3c2ccc2ccccc23)c1]

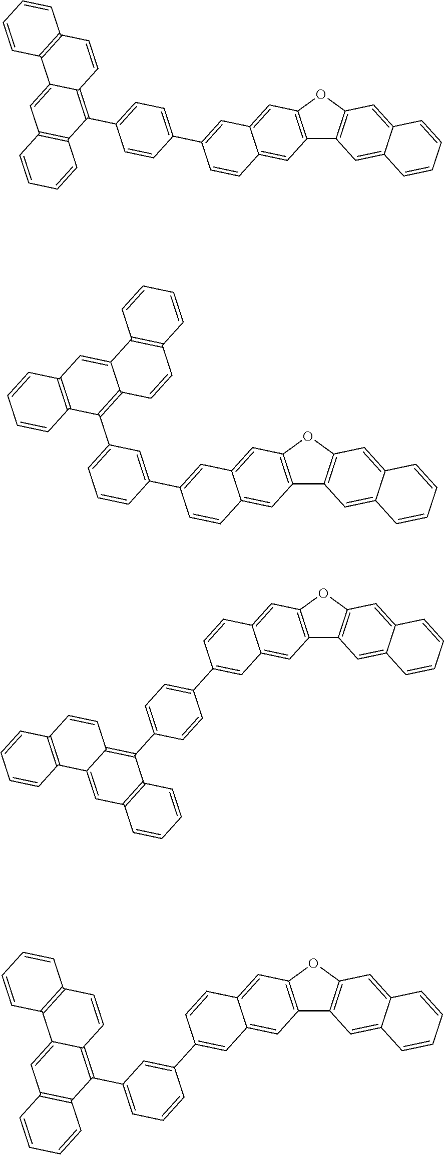 [SMILES: c1ccc2cc3c(cc2c1)oc1cc2cc(-c4ccc(-c5c6ccccc6cc6c5ccc5ccccc56)cc4)ccc2cc13 ; c1cc(-c2ccc3cc4c(cc3c2)oc2cc3ccccc3cc24)cc(-c2c3ccccc3cc3c2ccc2ccccc23)c1 ; c1ccc2cc3c(cc2c1)oc1cc2ccc(-c4ccc(-c5c6ccccc6cc6c5ccc5ccccc56)cc4)cc2cc13 ; c1cc(-c2ccc3cc4oc5cc6ccccc6cc5c4cc3c2)cc(-c2c3ccccc3cc3c2ccc2ccccc23)c1]

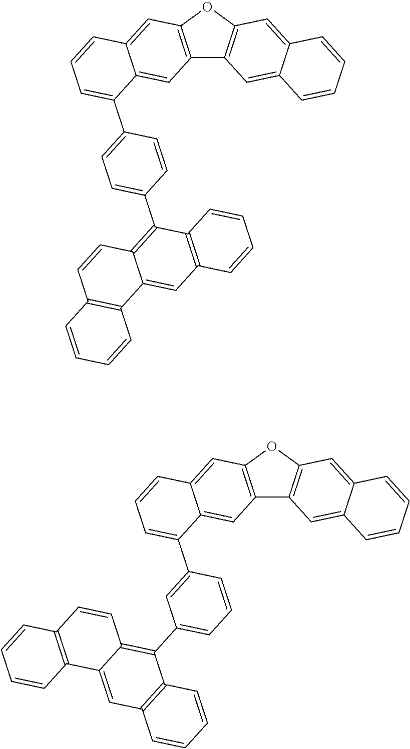 [SMILES: c1ccc2cc3c(cc2c1)oc1cc2cccc(-c4ccc(-c5c6ccccc6cc6c5ccc5ccccc56)cc4)c2cc13 ; c1cc(-c2cccc3cc4oc5cc6ccccc6cc5c4cc23)cc(-c2c3ccccc3cc3c2ccc2ccccc23)c1]

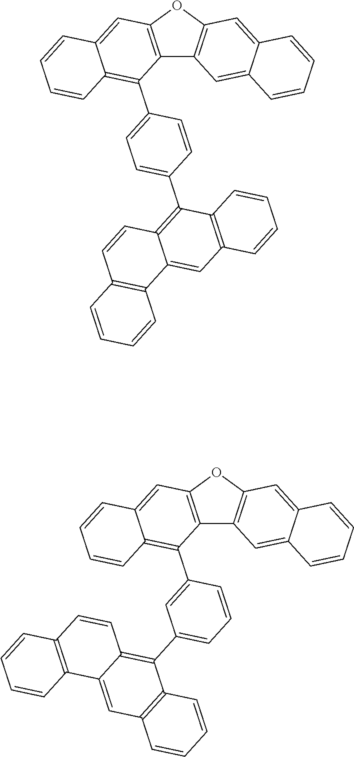 [SMILES: c1ccc2cc3c(cc2c1)oc1cc2ccccc2c(-c2ccc(-c4c5ccccc5cc5c4ccc4ccccc45)cc2)c13 ; c1cc(-c2c3ccccc3cc3c2ccc2ccccc23)cc(-c2c3ccccc3cc3oc4cc5ccccc5cc4c23)c1]

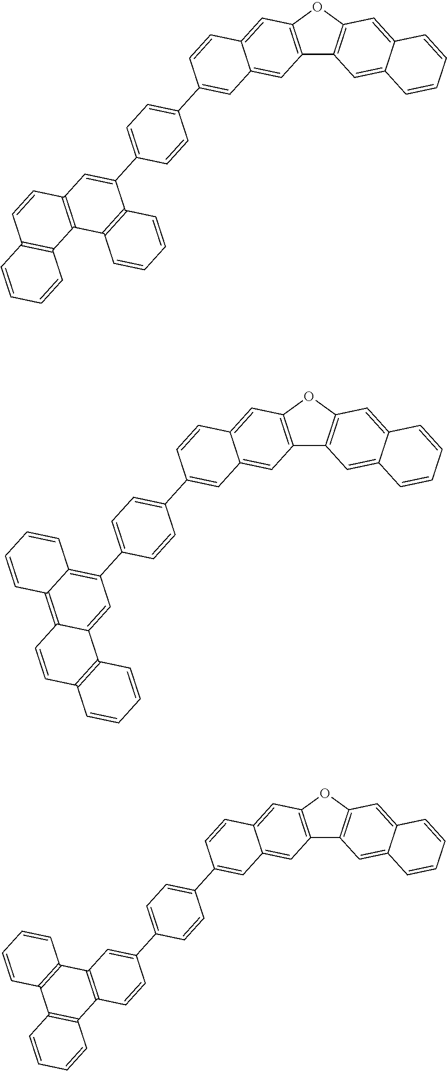 [SMILES: c1ccc2cc3c(cc2c1)oc1cc2ccc(-c4ccc(-c5cc6ccc7ccccc7c6c6ccccc56)cc4)cc2cc13 ; c1ccc2cc3c(cc2c1)oc1cc2ccc(-c4ccc(-c5cc6c7ccccc7ccc6c6ccccc56)cc4)cc2cc13 ; c1ccc2cc3c(cc2c1)oc1cc2ccc(-c4ccc(-c5ccc6c7ccccc7c7ccccc7c6c5)cc4)cc2cc13]

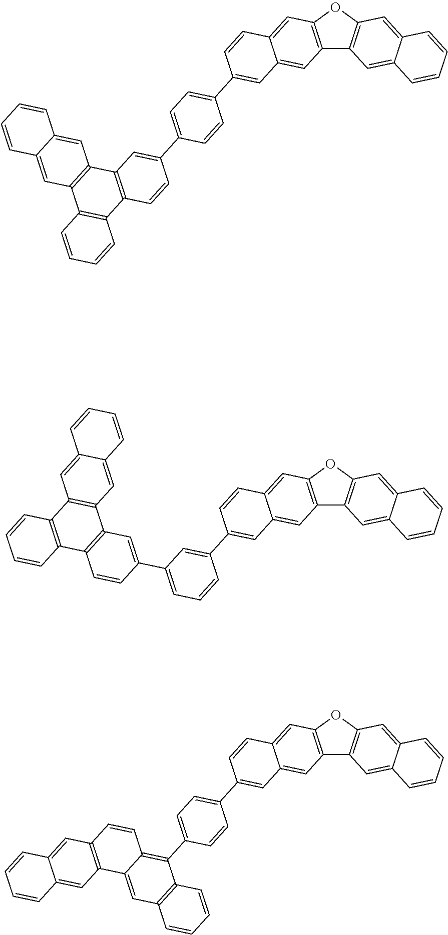 [SMILES: c1ccc2cc3c(cc2c1)oc1cc2ccc(-c4ccc(-c5ccc6c7ccccc7c7cc8ccccc8cc7c6c5)cc4)cc2cc13 ; c1cc(-c2ccc3cc4oc5cc6ccccc6cc5c4cc3c2)cc(-c2ccc3c4ccccc4c4cc5ccccc5cc4c3c2)c1 ; c1ccc2cc3c(ccc4c(-c5ccc(-c6ccc7cc8oc9cc%10ccccc%10cc9c8cc7c6)cc5)c5ccccc5cc43)cc2c1]

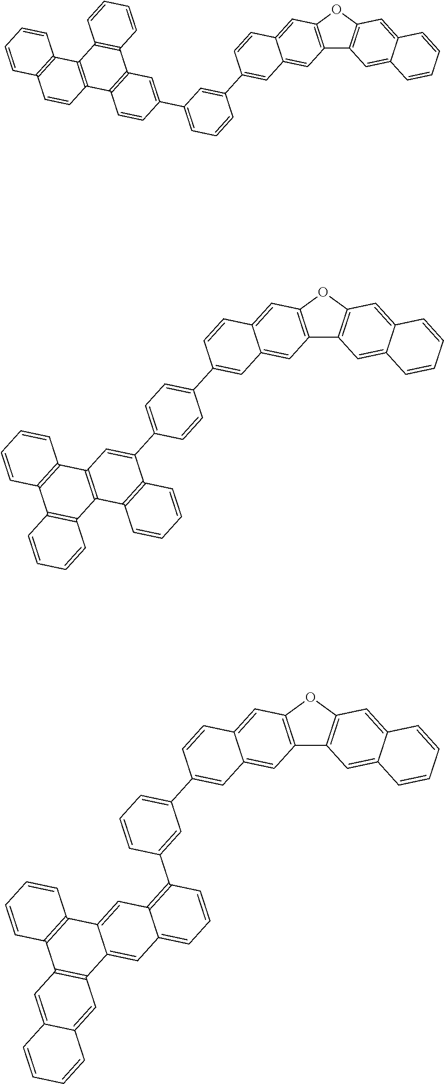 [SMILES: c1cc(-c2ccc3cc4oc5cc6ccccc6cc5c4cc3c2)cc(-c2ccc3c(c2)c2ccccc2c2c4ccccc4ccc32)c1 ; c1ccc2cc3c(cc2c1)oc1cc2ccc(-c4ccc(-c5cc6c7ccccc7c7ccccc7c6c6ccccc56)cc4)cc2cc13 ; c1cc(-c2ccc3cc4oc5cc6ccccc6cc5c4cc3c2)cc(-c2cccc3cc4c5cc6ccccc6cc5c5ccccc5c4cc23)c1]

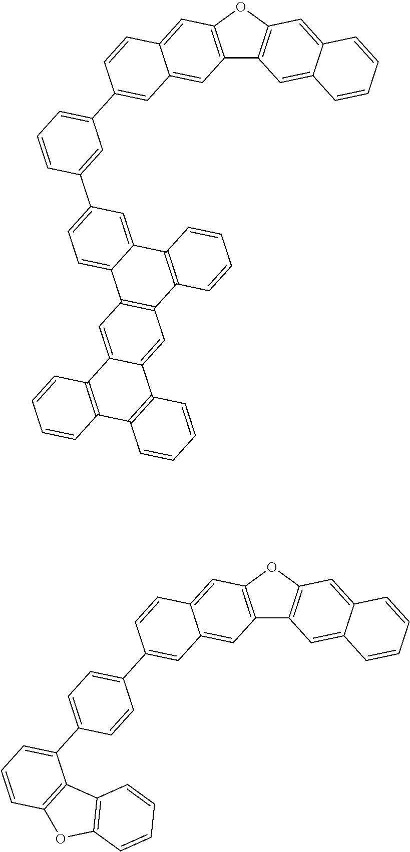 [SMILES: c1cc(-c2ccc3cc4oc5cc6ccccc6cc5c4cc3c2)cc(-c2ccc3c(c2)c2ccccc2c2cc4c5ccccc5c5ccccc5c4cc32)c1 ; c1ccc2cc3c(cc2c1)oc1cc2ccc(-c4ccc(-c5cccc6oc7ccccc7c56)cc4)cc2cc13]

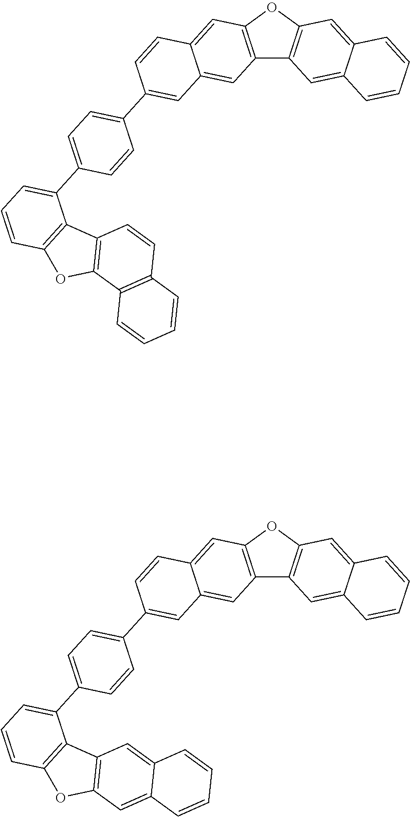 [SMILES: c1ccc2cc3c(cc2c1)oc1cc2ccc(-c4ccc(-c5cccc6oc7c8ccccc8ccc7c56)cc4)cc2cc13 ; c1ccc2cc3c(cc2c1)oc1cc2ccc(-c4ccc(-c5cccc6oc7cc8ccccc8cc7c56)cc4)cc2cc13]

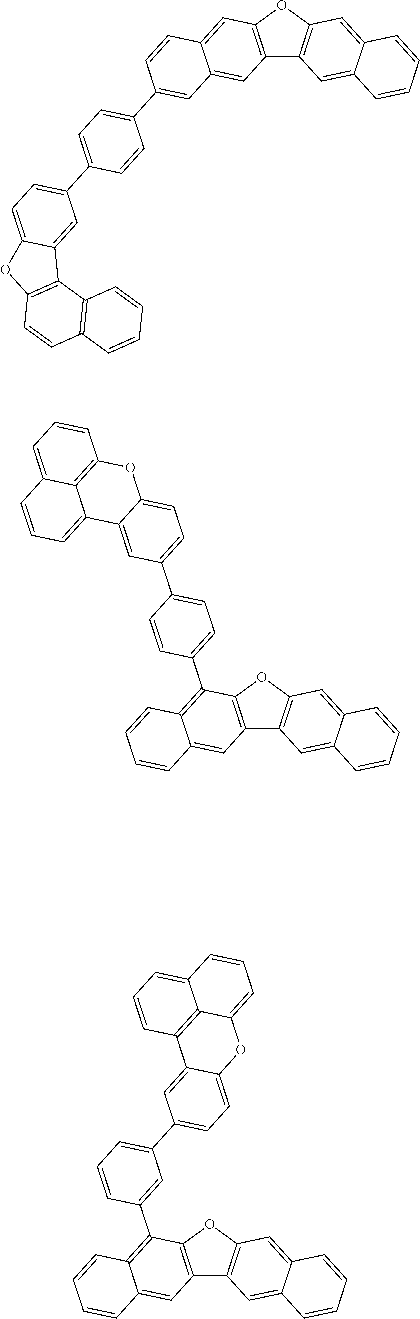 [SMILES: c1ccc2cc3c(cc2c1)oc1cc2ccc(-c4ccc(-c5ccc6oc7ccc8ccccc8c7c6c5)cc4)cc2cc13 ; c1ccc2cc3c(cc2c1)oc1c(-c2ccc(-c4ccc5c(c4)-c4cccc6cccc(c46)O5)cc2)c2ccccc2cc13 ; c1cc(-c2ccc3c(c2)-c2cccc4cccc(c24)O3)cc(-c2c3ccccc3cc3c2oc2cc4ccccc4cc23)c1]

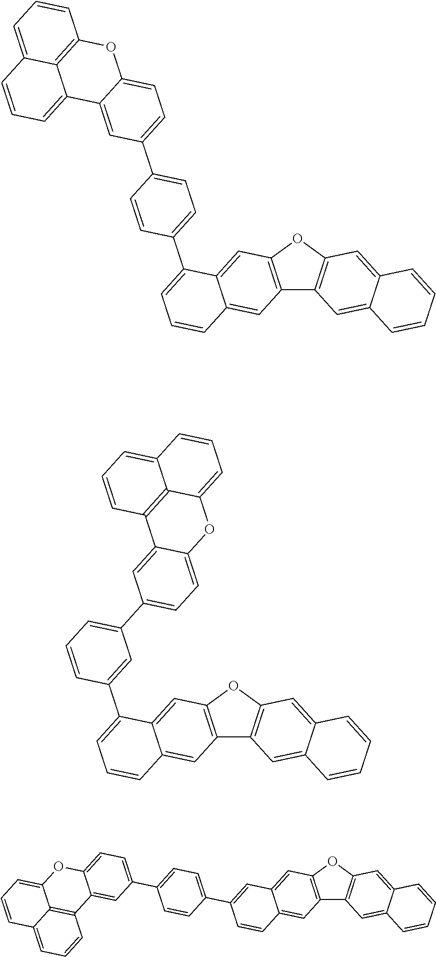 [SMILES: c1ccc2cc3c(cc2c1)oc1cc2c(-c4ccc(-c5ccc6c(c5)-c5cccc7cccc(c57)O6)cc4)cccc2cc13 ; c1cc(-c2ccc3c(c2)-c2cccc4cccc(c24)O3)cc(-c2cccc3cc4c(cc23)oc2cc3ccccc3cc24)c1 ; c1ccc2cc3c(cc2c1)oc1cc2cc(-c4ccc(-c5ccc6c(c5)-c5cccc7cccc(c57)O6)cc4)ccc2cc13]

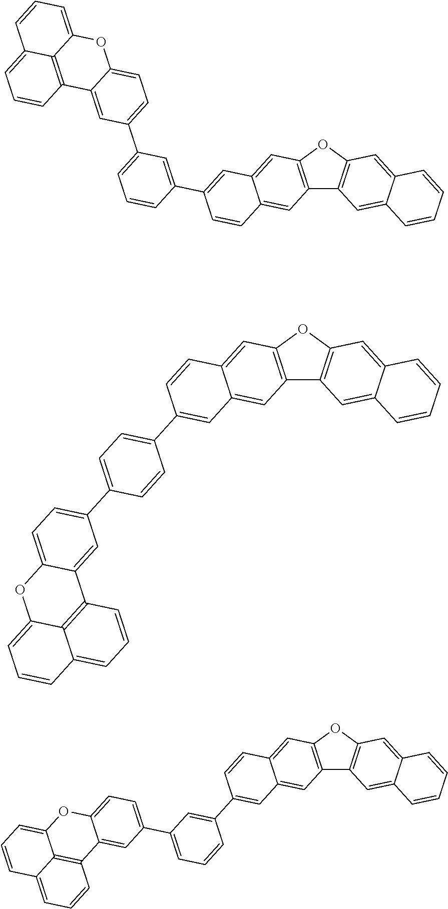 [SMILES: c1cc(-c2ccc3c(c2)-c2cccc4cccc(c24)O3)cc(-c2ccc3cc4c(cc3c2)oc2cc3ccccc3cc24)c1 ; c1ccc2cc3c(cc2c1)oc1cc2ccc(-c4ccc(-c5ccc6c(c5)-c5cccc7cccc(c57)O6)cc4)cc2cc13 ; c1cc(-c2ccc3c(c2)-c2cccc4cccc(c24)O3)cc(-c2ccc3cc4oc5cc6ccccc6cc5c4cc3c2)c1]

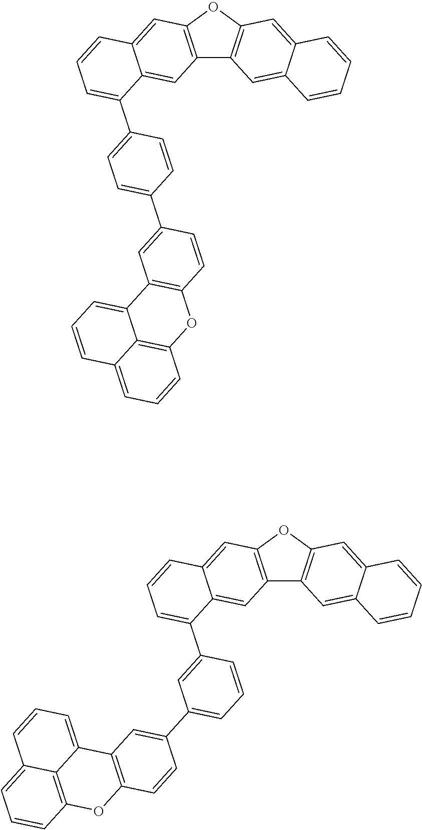

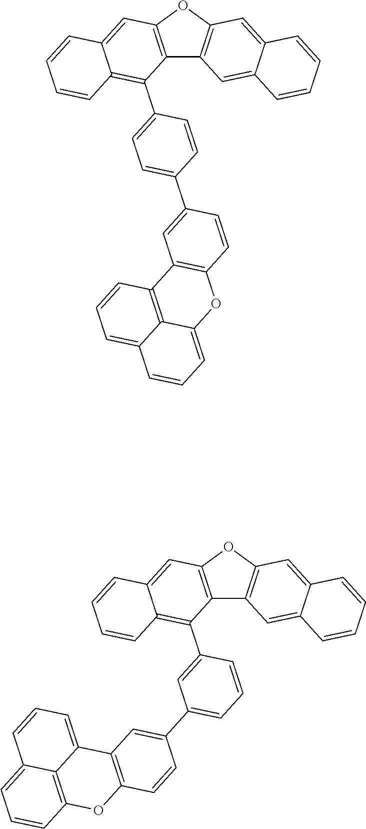

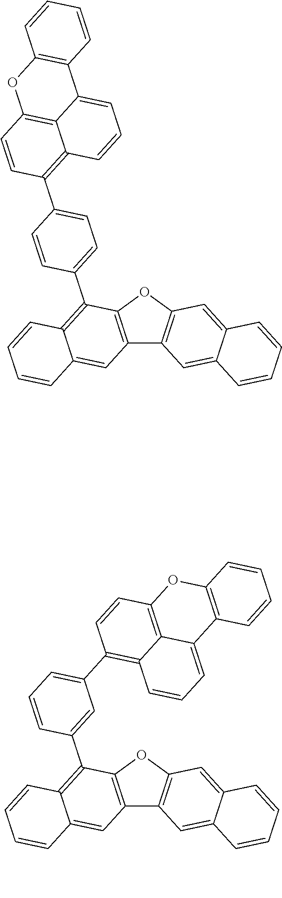

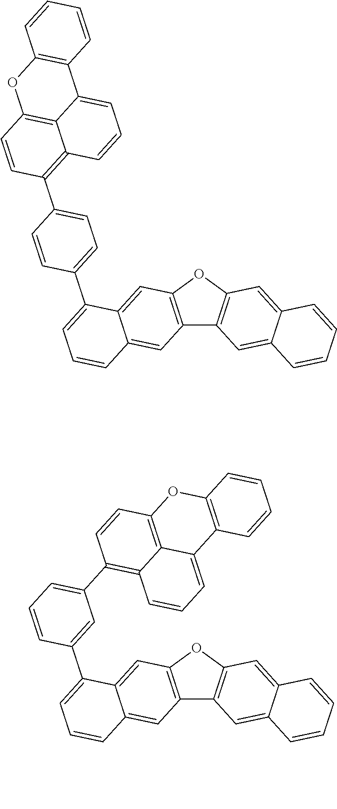

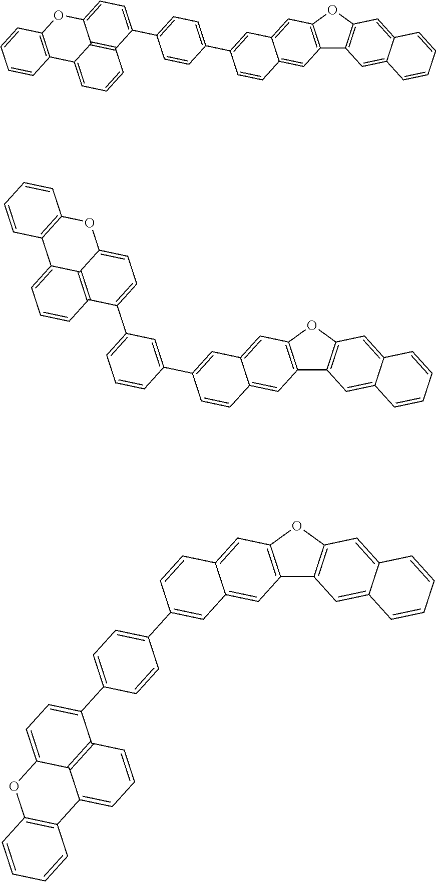 [SMILES: c1ccc2c(c1)Oc1ccc(-c3ccc(-c4ccc5cc6c(cc5c4)oc4cc5ccccc5cc46)cc3)c3cccc-2c13 ; c1cc(-c2ccc3cc4c(cc3c2)oc2cc3ccccc3cc24)cc(-c2ccc3c4c(cccc24)-c2ccccc2O3)c1 ; c1ccc2c(c1)Oc1ccc(-c3ccc(-c4ccc5cc6oc7cc8ccccc8cc7c6cc5c4)cc3)c3cccc-2c13]

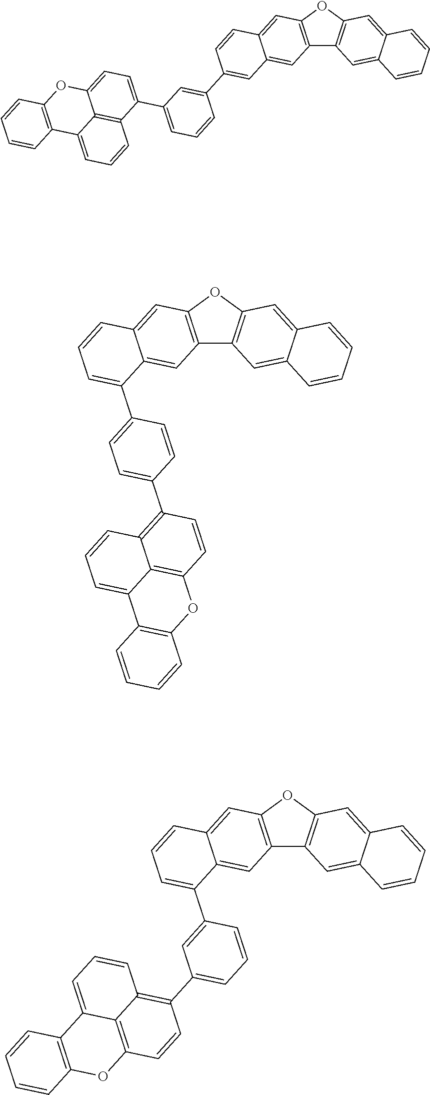 [SMILES: c1cc(-c2ccc3cc4oc5cc6ccccc6cc5c4cc3c2)cc(-c2ccc3c4c(cccc24)-c2ccccc2O3)c1 ; c1ccc2c(c1)Oc1ccc(-c3ccc(-c4cccc5cc6oc7cc8ccccc8cc7c6cc45)cc3)c3cccc-2c13 ; c1cc(-c2cccc3cc4oc5cc6ccccc6cc5c4cc23)cc(-c2ccc3c4c(cccc24)-c2ccccc2O3)c1]

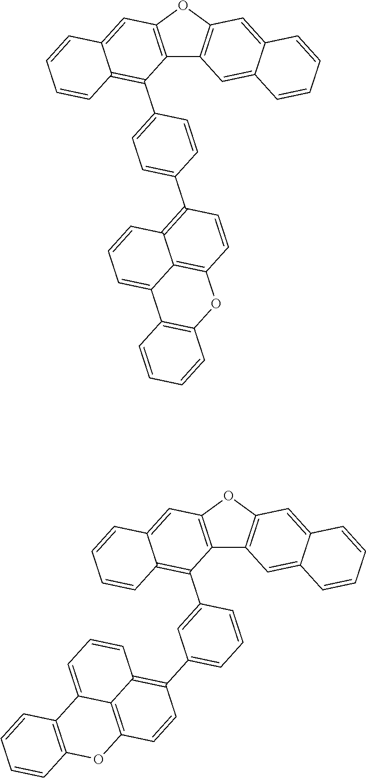 [SMILES: c1ccc2c(c1)Oc1ccc(-c3ccc(-c4c5ccccc5cc5oc6cc7ccccc7cc6c45)cc3)c3cccc-2c13 ; c1cc(-c2ccc3c4c(cccc24)-c2ccccc2O3)cc(-c2c3ccccc3cc3oc4cc5ccccc5cc4c23)c1]

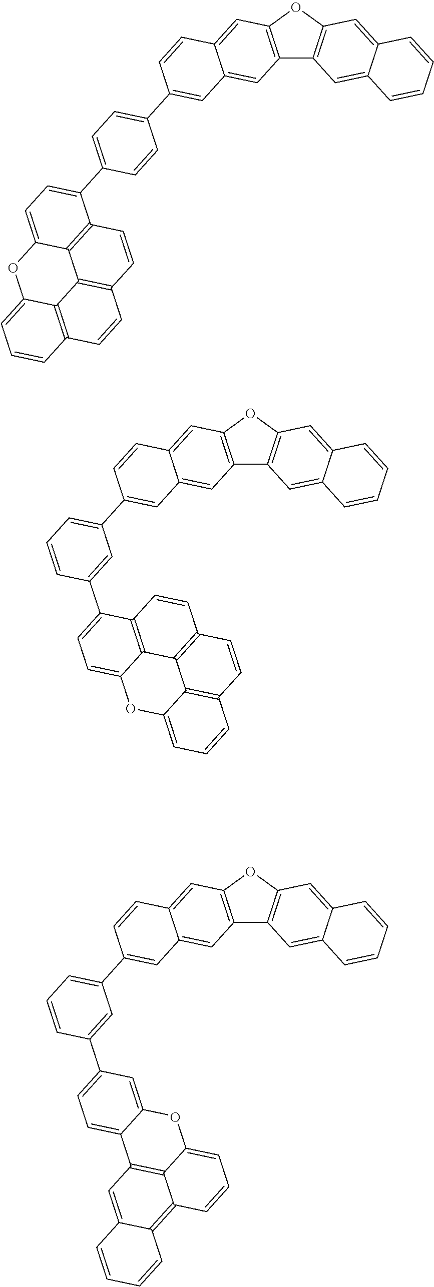 [SMILES: c1ccc2cc3c(cc2c1)oc1cc2ccc(-c4ccc(-c5ccc6c7c5ccc5ccc8cccc(c8c57)O6)cc4)cc2cc13 ; c1cc(-c2ccc3cc4oc5cc6ccccc6cc5c4cc3c2)cc(-c2ccc3c4c2ccc2ccc5cccc(c5c24)O3)c1 ; c1cc(-c2ccc3c(c2)Oc2cccc4c2c-3cc2ccccc24)cc(-c2ccc3cc4oc5cc6ccccc6cc5c4cc3c2)c1]

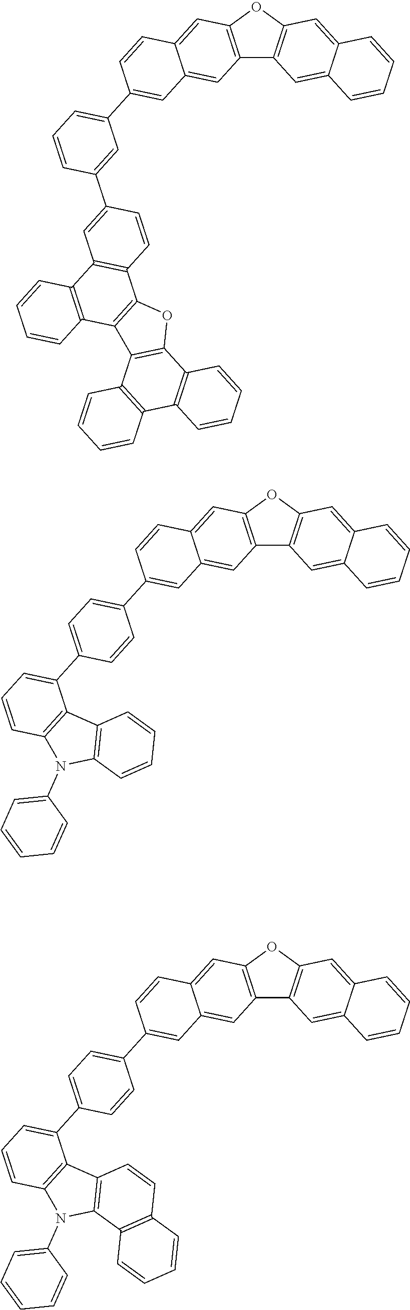 [SMILES: c1cc(-c2ccc3cc4oc5cc6ccccc6cc5c4cc3c2)cc(-c2ccc3c(c2)c2ccccc2c2c3oc3c4ccccc4c4ccccc4c32)c1 ; c1ccc(-n2c3ccccc3c3c(-c4ccc(-c5ccc6cc7oc8cc9ccccc9cc8c7cc6c5)cc4)cccc32)cc1 ; c1ccc(-n2c3cccc(-c4ccc(-c5ccc6cc7oc8cc9ccccc9cc8c7cc6c5)cc4)c3c3ccc4ccccc4c32)cc1]

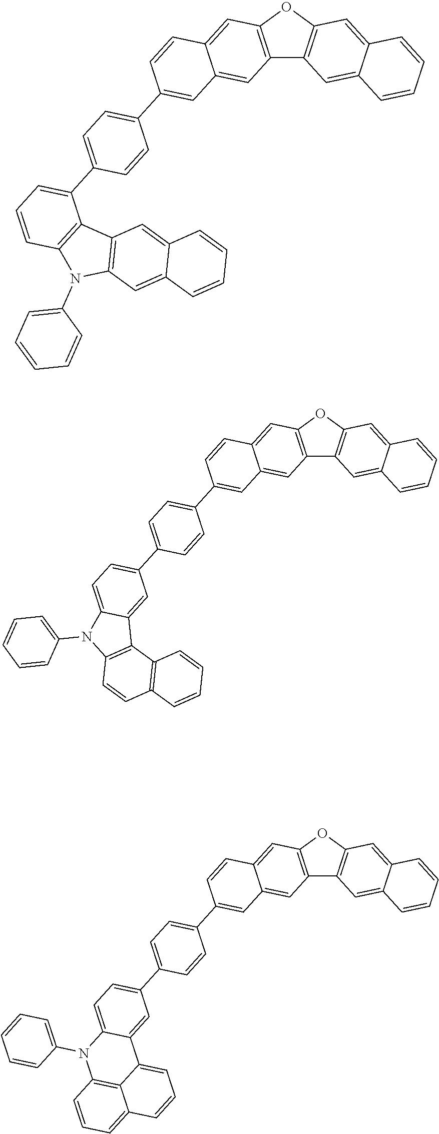 [SMILES: c1ccc(-n2c3cc4ccccc4cc3c3c(-c4ccc(-c5ccc6cc7oc8cc9ccccc9cc8c7cc6c5)cc4)cccc32)cc1 ; c1ccc(-n2c3ccc(-c4ccc(-c5ccc6cc7oc8cc9ccccc9cc8c7cc6c5)cc4)cc3c3c4ccccc4ccc32)cc1 ; c1ccc(N2c3ccc(-c4ccc(-c5ccc6cc7oc8cc9ccccc9cc8c7cc6c5)cc4)cc3-c3cccc4cccc2c34)cc1]

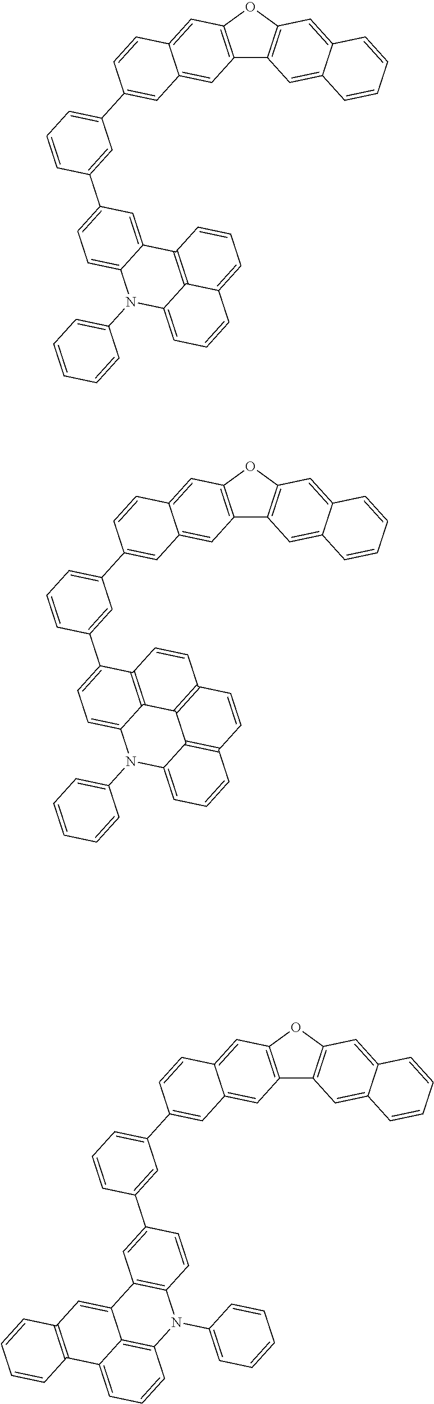 [SMILES: c1ccc(N2c3ccc(-c4cccc(-c5ccc6cc7oc8cc9ccccc9cc8c7cc6c5)c4)cc3-c3cccc4cccc2c34)cc1 ; c1ccc(N2c3cccc4ccc5ccc6c(-c7cccc(-c8ccc9cc%10oc%11cc%12ccccc%12cc%11c%10cc9c8)c7)ccc2c6c5c34)cc1 ; c1ccc(N2c3ccc(-c4cccc(-c5ccc6cc7oc8cc9ccccc9cc8c7cc6c5)c4)cc3-c3cc4ccccc4c4cccc2c34)cc1]

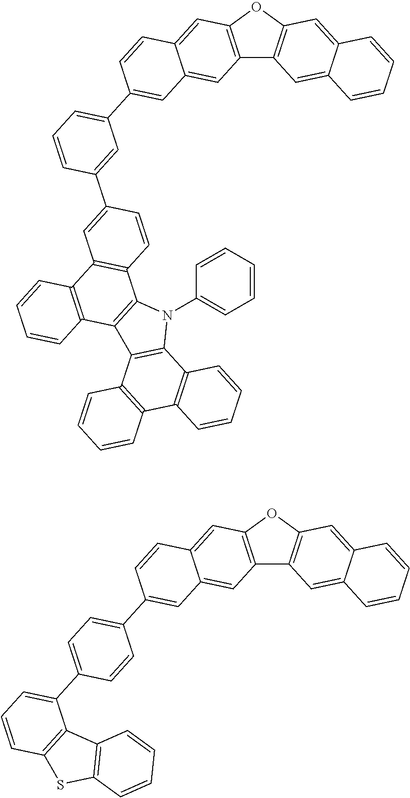 [SMILES: c1ccc(-n2c3c4ccccc4c4ccccc4c3c3c4ccccc4c4cc(-c5cccc(-c6ccc7cc8oc9cc%10ccccc%10cc9c8cc7c6)c5)ccc4c32)cc1 ; c1ccc2cc3c(cc2c1)oc1cc2ccc(-c4ccc(-c5cccc6sc7ccccc7c56)cc4)cc2cc13]

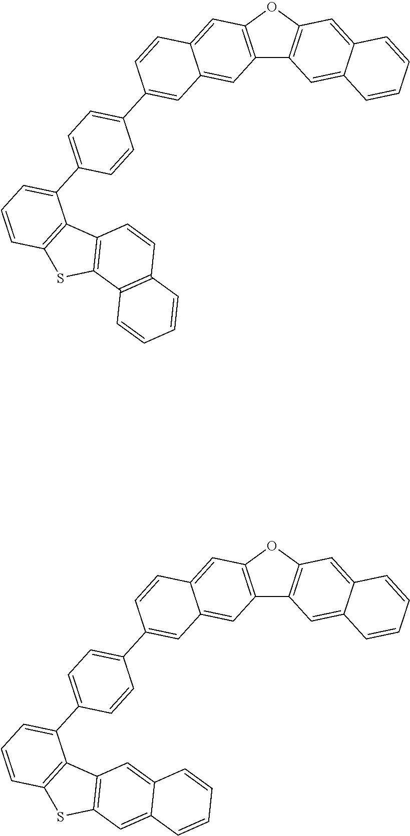 [SMILES: c1ccc2cc3c(cc2c1)oc1cc2ccc(-c4ccc(-c5cccc6sc7c8ccccc8ccc7c56)cc4)cc2cc13 ; c1ccc2cc3c(cc2c1)oc1cc2ccc(-c4ccc(-c5cccc6sc7cc8ccccc8cc7c56)cc4)cc2cc13]

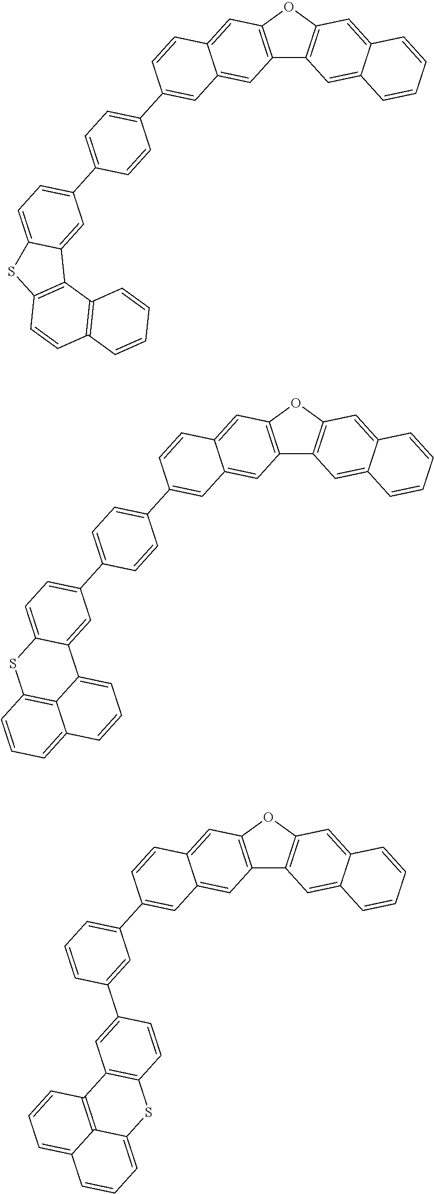 [SMILES: c1ccc2cc3c(cc2c1)oc1cc2ccc(-c4ccc(-c5ccc6sc7ccc8ccccc8c7c6c5)cc4)cc2cc13 ; c1ccc2cc3c(cc2c1)oc1cc2ccc(-c4ccc(-c5ccc6c(c5)-c5cccc7cccc(c57)S6)cc4)cc2cc13 ; c1cc(-c2ccc3c(c2)-c2cccc4cccc(c24)S3)cc(-c2ccc3cc4oc5cc6ccccc6cc5c4cc3c2)c1]

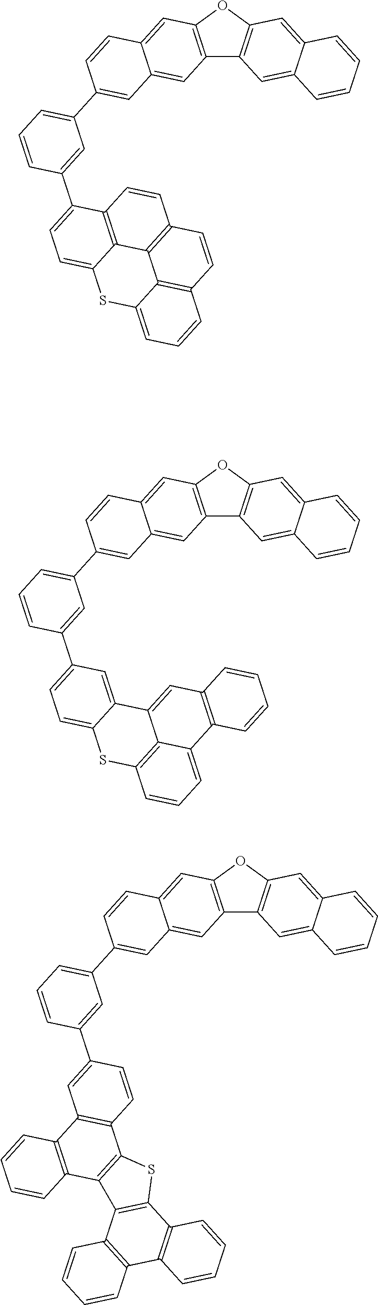 [SMILES: c1cc(-c2ccc3cc4oc5cc6ccccc6cc5c4cc3c2)cc(-c2ccc3c4c2ccc2ccc5cccc(c5c24)S3)c1 ; c1cc(-c2ccc3c(c2)-c2cc4ccccc4c4cccc(c24)S3)cc(-c2ccc3cc4oc5cc6ccccc6cc5c4cc3c2)c1 ; c1cc(-c2ccc3cc4oc5cc6ccccc6cc5c4cc3c2)cc(-c2ccc3c(c2)c2ccccc2c2c3sc3c4ccccc4c4ccccc4c32)c1]

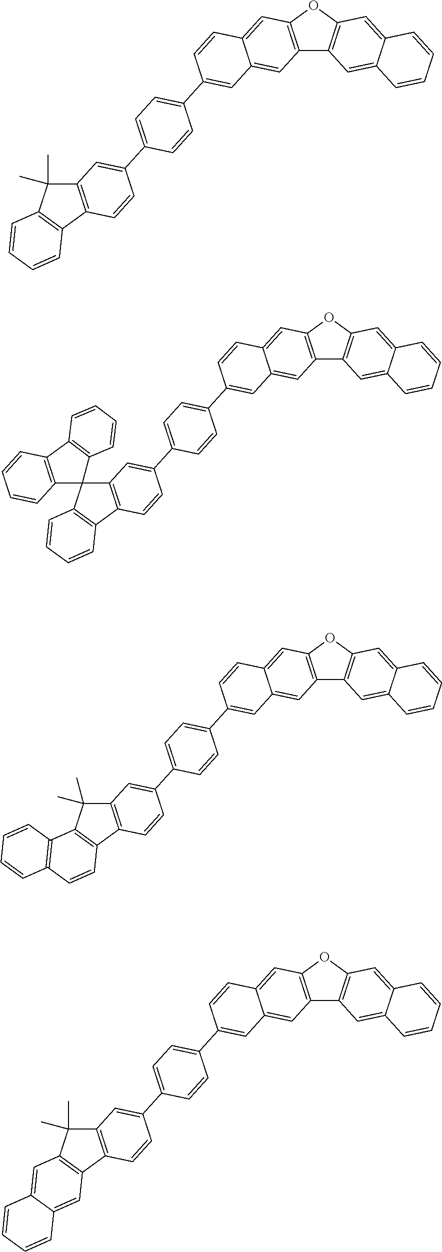 [SMILES: CC1(C)c2ccccc2-c2ccc(-c3ccc(-c4ccc5cc6oc7cc8ccccc8cc7c6cc5c4)cc3)cc21 ; c1ccc2c(c1)-c1ccccc1C21c2ccccc2-c2ccc(-c3ccc(-c4ccc5cc6oc7cc8ccccc8cc7c6cc5c4)cc3)cc21 ; CC1(C)c2cc(-c3ccc(-c4ccc5cc6oc7cc8ccccc8cc7c6cc5c4)cc3)ccc2-c2ccc3ccccc3c21 ; CC1(C)c2cc(-c3ccc(-c4ccc5cc6oc7cc8ccccc8cc7c6cc5c4)cc3)ccc2-c2cc3ccccc3cc21]

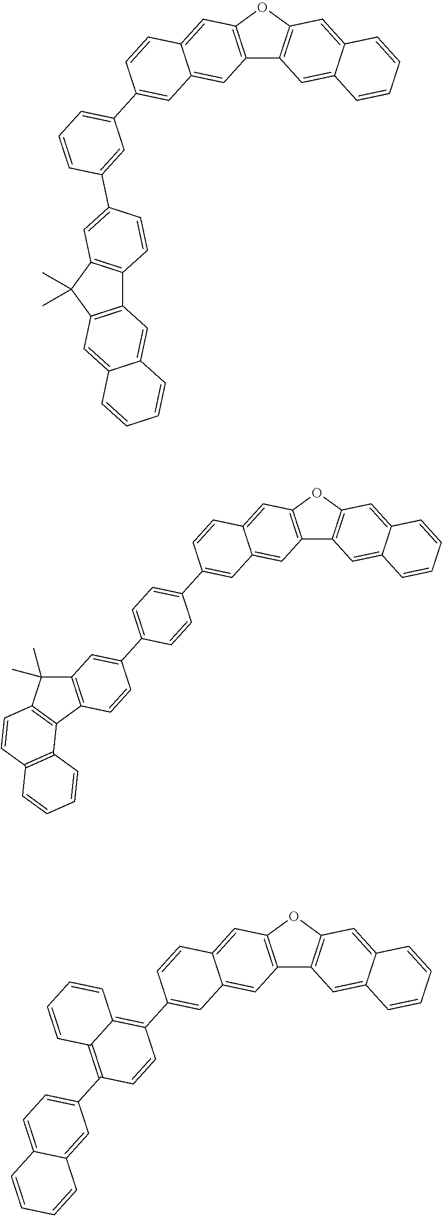 [SMILES: CC1(C)c2cc(-c3cccc(-c4ccc5cc6oc7cc8ccccc8cc7c6cc5c4)c3)ccc2-c2cc3ccccc3cc21 ; CC1(C)c2cc(-c3ccc(-c4ccc5cc6oc7cc8ccccc8cc7c6cc5c4)cc3)ccc2-c2c1ccc1ccccc21 ; c1ccc2cc(-c3ccc(-c4ccc5cc6oc7cc8ccccc8cc7c6cc5c4)c4ccccc34)ccc2c1]

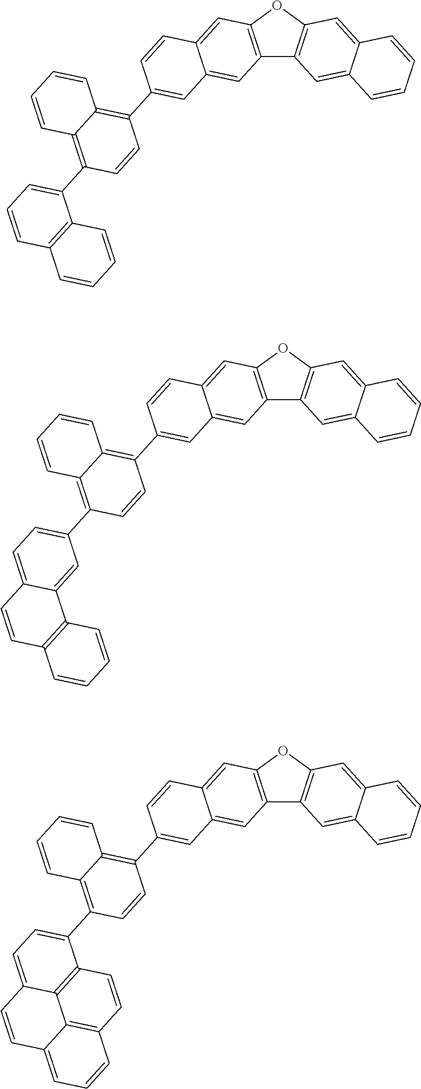 [SMILES: c1ccc2cc3c(cc2c1)oc1cc2ccc(-c4ccc(-c5cccc6ccccc56)c5ccccc45)cc2cc13 ; c1ccc2cc3c(cc2c1)oc1cc2ccc(-c4ccc(-c5ccc6ccc7ccccc7c6c5)c5ccccc45)cc2cc13 ; c1ccc2cc3c(cc2c1)oc1cc2ccc(-c4ccc(-c5ccc6ccc7cccc8ccc5c6c78)c5ccccc45)cc2cc13]

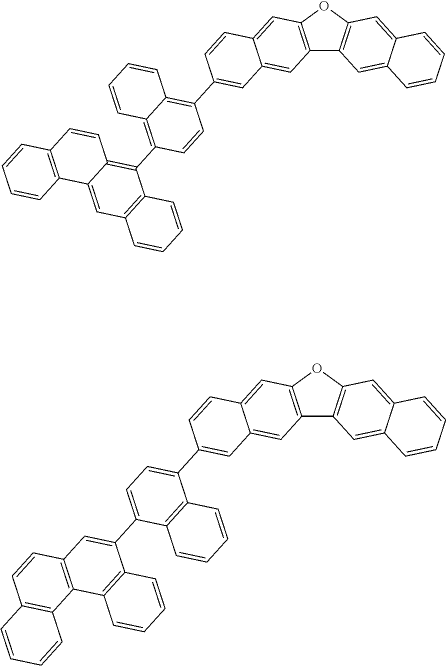 [SMILES: c1ccc2cc3c(cc2c1)oc1cc2ccc(-c4ccc(-c5c6ccccc6cc6c5ccc5ccccc56)c5ccccc45)cc2cc13 ; c1ccc2cc3c(cc2c1)oc1cc2ccc(-c4ccc(-c5cc6ccc7ccccc7c6c6ccccc56)c5ccccc45)cc2cc13]

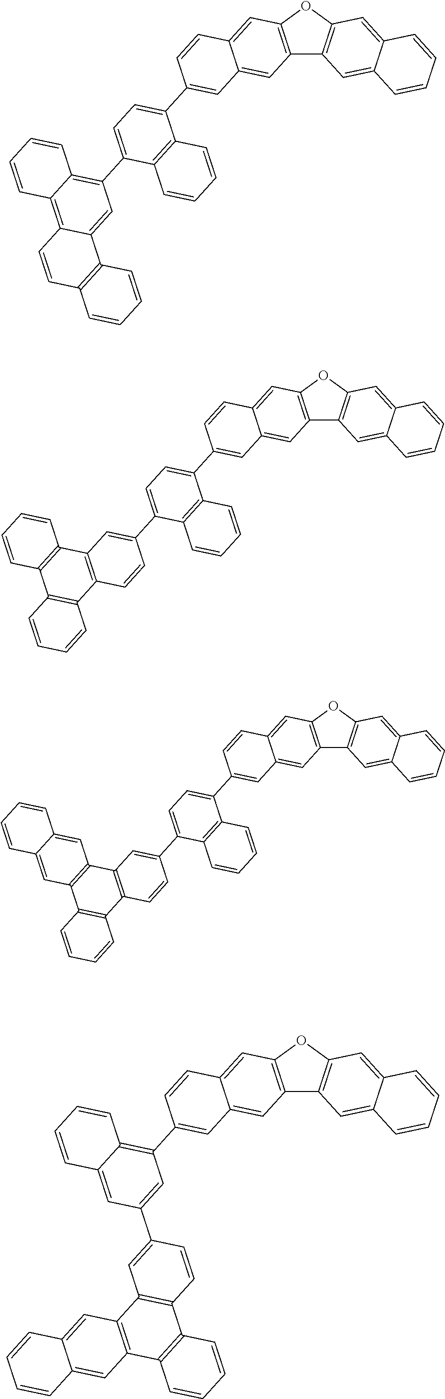 [SMILES: c1ccc2cc3c(cc2c1)oc1cc2ccc(-c4ccc(-c5cc6c7ccccc7ccc6c6ccccc56)c5ccccc45)cc2cc13 ; c1ccc2cc3c(cc2c1)oc1cc2ccc(-c4ccc(-c5ccc6c7ccccc7c7ccccc7c6c5)c5ccccc45)cc2cc13 ; c1ccc2cc3c(cc2c1)oc1cc2ccc(-c4ccc(-c5ccc6c7ccccc7c7cc8ccccc8cc7c6c5)c5ccccc45)cc2cc13 ; c1ccc2cc3c(cc2c1)oc1cc2ccc(-c4cc(-c5ccc6c7ccccc7c7cc8ccccc8cc7c6c5)cc5ccccc45)cc2cc13]

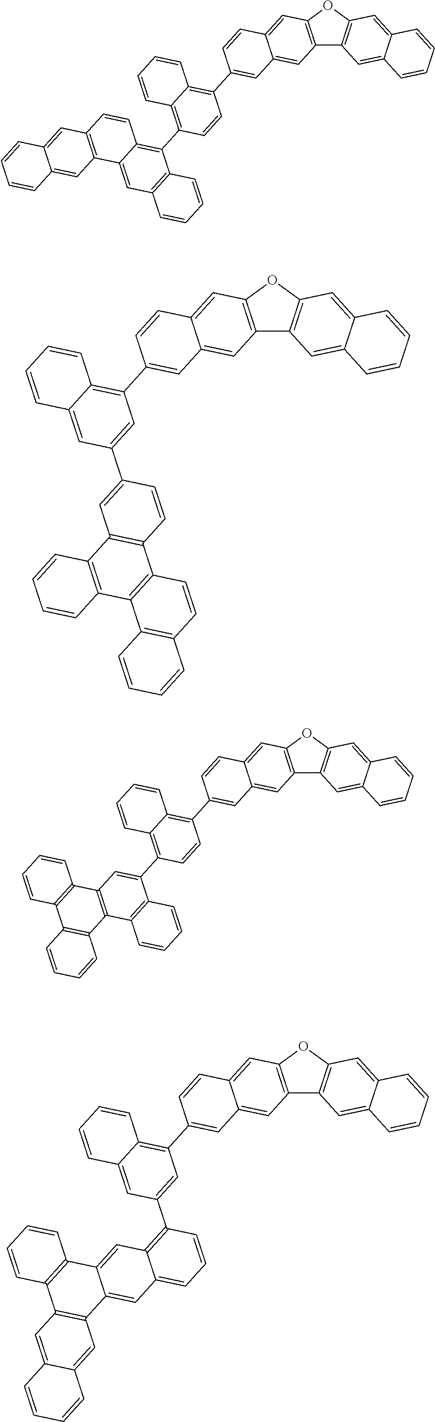 [SMILES: c1ccc2cc3c(ccc4c(-c5ccc(-c6ccc7cc8oc9cc%10ccccc%10cc9c8cc7c6)c6ccccc56)c5ccccc5cc43)cc2c1 ; c1ccc2cc3c(cc2c1)oc1cc2ccc(-c4cc(-c5ccc6c(c5)c5ccccc5c5c7ccccc7ccc65)cc5ccccc45)cc2cc13 ; c1ccc2cc3c(cc2c1)oc1cc2ccc(-c4ccc(-c5cc6c7ccccc7c7ccccc7c6c6ccccc56)c5ccccc45)cc2cc13 ; c1ccc2cc3c(cc2c1)oc1cc2ccc(-c4cc(-c5cccc6cc7c8cc9ccccc9cc8c8ccccc8c7cc56)cc5ccccc45)cc2cc13]

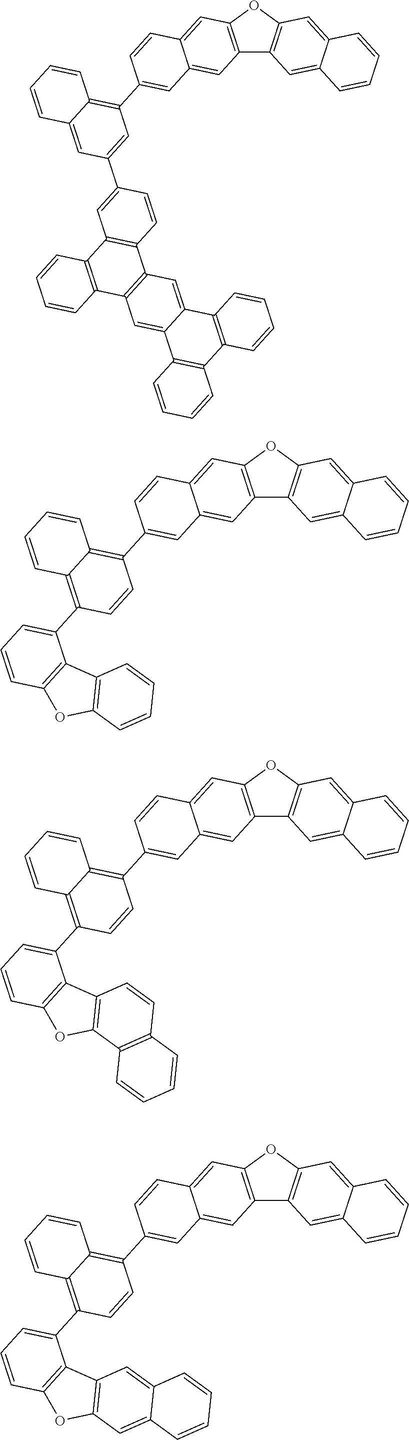

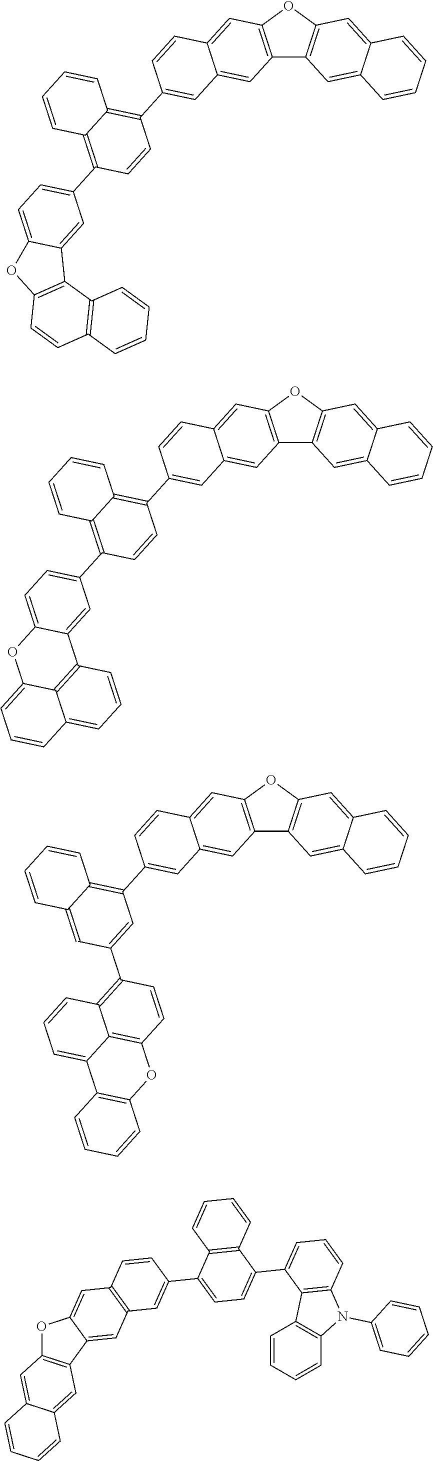 [SMILES: c1ccc2cc3c(cc2c1)oc1cc2ccc(-c4ccc(-c5ccc6oc7ccc8ccccc8c7c6c5)c5ccccc45)cc2cc13 ; c1ccc2cc3c(cc2c1)oc1cc2ccc(-c4ccc(-c5ccc6c(c5)-c5cccc7cccc(c57)O6)c5ccccc45)cc2cc13 ; c1ccc2c(c1)Oc1ccc(-c3cc(-c4ccc5cc6oc7cc8ccccc8cc7c6cc5c4)c4ccccc4c3)c3cccc-2c13 ; c1ccc(-n2c3ccccc3c3c(-c4ccc(-c5ccc6cc7oc8cc9ccccc9cc8c7cc6c5)c5ccccc45)cccc32)cc1]

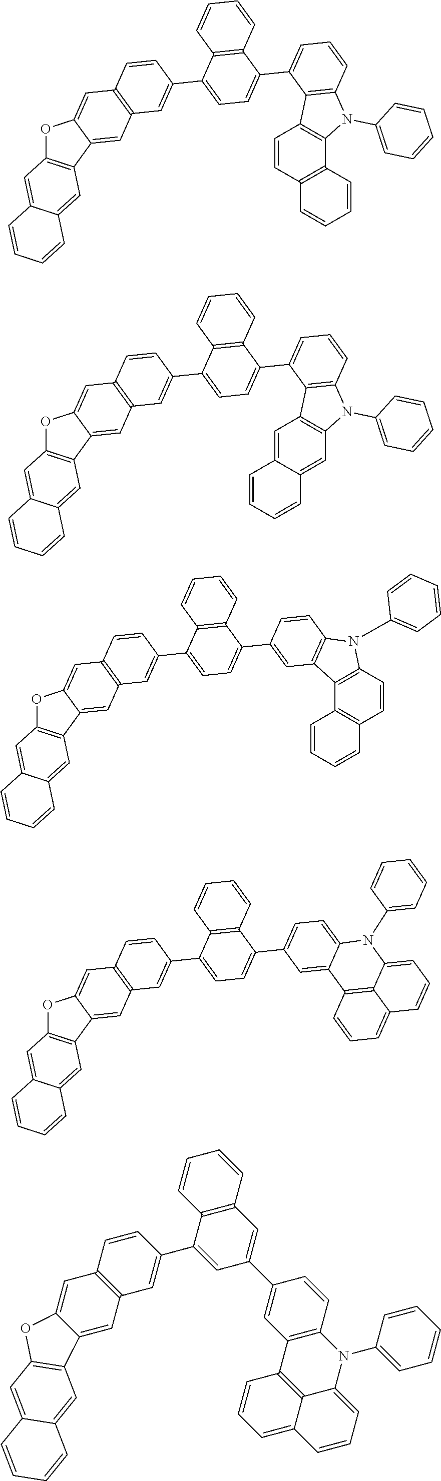 [SMILES: c1ccc(-n2c3cccc(-c4ccc(-c5ccc6cc7oc8cc9ccccc9cc8c7cc6c5)c5ccccc45)c3c3ccc4ccccc4c32)cc1 ; c1ccc(-n2c3cc4ccccc4cc3c3c(-c4ccc(-c5ccc6cc7oc8cc9ccccc9cc8c7cc6c5)c5ccccc45)cccc32)cc1 ; c1ccc(-n2c3ccc(-c4ccc(-c5ccc6cc7oc8cc9ccccc9cc8c7cc6c5)c5ccccc45)cc3c3c4ccccc4ccc32)cc1 ; c1ccc(N2c3ccc(-c4ccc(-c5ccc6cc7oc8cc9ccccc9cc8c7cc6c5)c5ccccc45)cc3-c3cccc4cccc2c34)cc1 ; c1ccc(N2c3ccc(-c4cc(-c5ccc6cc7oc8cc9ccccc9cc8c7cc6c5)c5ccccc5c4)cc3-c3cccc4cccc2c34)cc1]

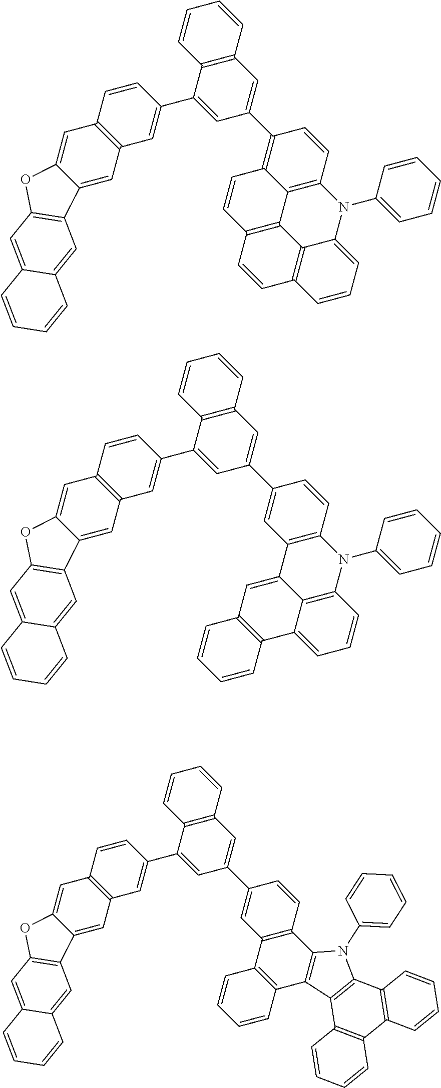 [SMILES: c1ccc(N2c3cccc4ccc5ccc6c(-c7cc(-c8ccc9cc%10oc%11cc%12ccccc%12cc%11c%10cc9c8)c8ccccc8c7)ccc2c6c5c34)cc1 ; c1ccc(N2c3ccc(-c4cc(-c5ccc6cc7oc8cc9ccccc9cc8c7cc6c5)c5ccccc5c4)cc3-c3cc4ccccc4c4cccc2c34)cc1 ; c1ccc(-n2c3c4ccccc4c4ccccc4c3c3c4ccccc4c4cc(-c5cc(-c6ccc7cc8oc9cc%10ccccc%10cc9c8cc7c6)c6ccccc6c5)ccc4c32)cc1]

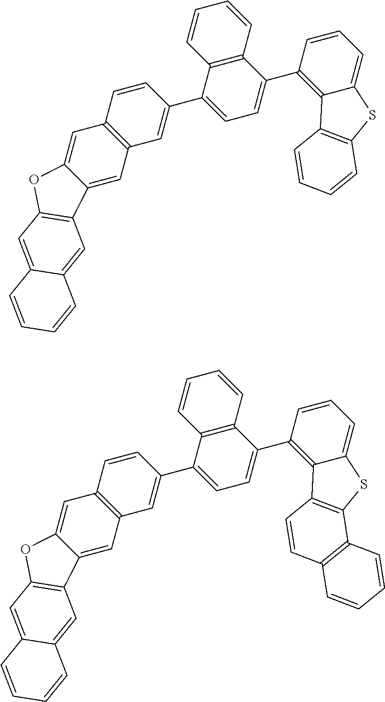 [SMILES: c1ccc2cc3c(cc2c1)oc1cc2ccc(-c4ccc(-c5cccc6sc7ccccc7c56)c5ccccc45)cc2cc13 ; c1ccc2cc3c(cc2c1)oc1cc2ccc(-c4ccc(-c5cccc6sc7c8ccccc8ccc7c56)c5ccccc45)cc2cc13]

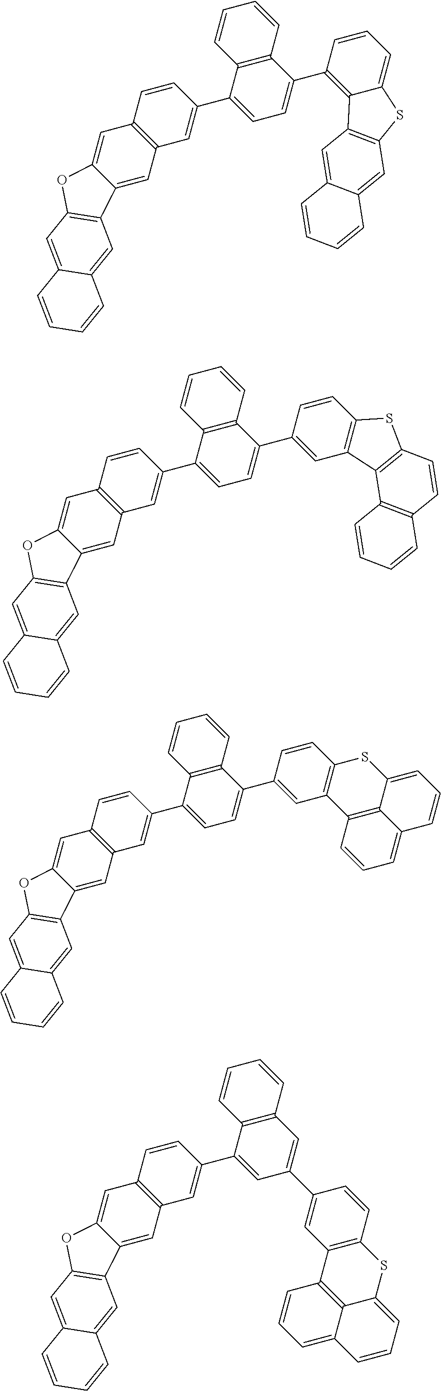 [SMILES: c1ccc2cc3c(cc2c1)oc1cc2ccc(-c4ccc(-c5cccc6sc7cc8ccccc8cc7c56)c5ccccc45)cc2cc13 ; c1ccc2cc3c(cc2c1)oc1cc2ccc(-c4ccc(-c5ccc6sc7ccc8ccccc8c7c6c5)c5ccccc45)cc2cc13 ; c1ccc2cc3c(cc2c1)oc1cc2ccc(-c4ccc(-c5ccc6c(c5)-c5cccc7cccc(c57)S6)c5ccccc45)cc2cc13 ; c1ccc2cc3c(cc2c1)oc1cc2ccc(-c4cc(-c5ccc6c(c5)-c5cccc7cccc(c57)S6)cc5ccccc45)cc2cc13]

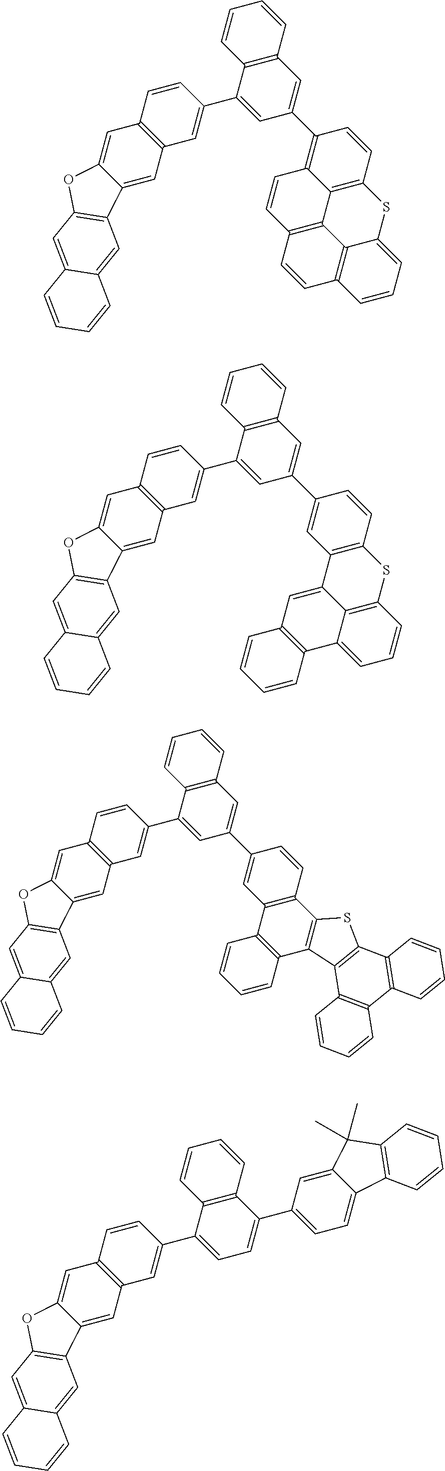 [SMILES: c1ccc2cc3c(cc2c1)oc1cc2ccc(-c4cc(-c5ccc6c7c5ccc5ccc8cccc(c8c57)S6)cc5ccccc45)cc2cc13 ; c1ccc2cc3c(cc2c1)oc1cc2ccc(-c4cc(-c5ccc6c(c5)-c5cc7ccccc7c7cccc(c57)S6)cc5ccccc45)cc2cc13 ; c1ccc2cc3c(cc2c1)oc1cc2ccc(-c4cc(-c5ccc6c(c5)c5ccccc5c5c6sc6c7ccccc7c7ccccc7c65)cc5ccccc45)cc2cc13 ; CC1(C)c2ccccc2-c2ccc(-c3ccc(-c4ccc5cc6oc7cc8ccccc8cc7c6cc5c4)c4ccccc34)cc21]

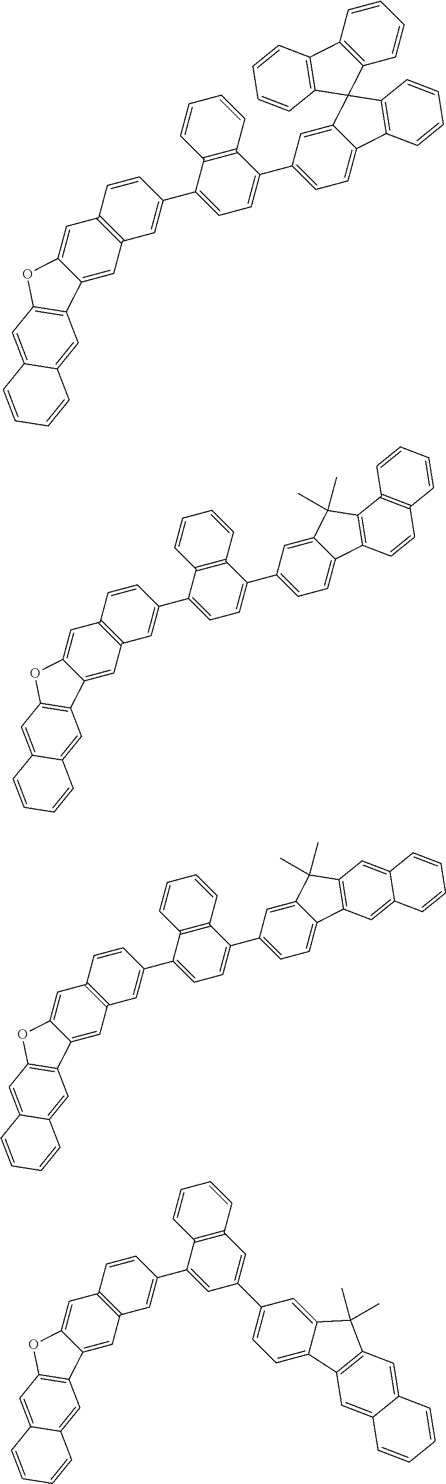 [SMILES: c1ccc2c(c1)-c1ccccc1C21c2ccccc2-c2ccc(-c3ccc(-c4ccc5cc6oc7cc8ccccc8cc7c6cc5c4)c4ccccc34)cc21 ; CC1(C)c2cc(-c3ccc(-c4ccc5cc6oc7cc8ccccc8cc7c6cc5c4)c4ccccc34)ccc2-c2ccc3ccccc3c21 ; CC1(C)c2cc(-c3ccc(-c4ccc5cc6oc7cc8ccccc8cc7c6cc5c4)c4ccccc34)ccc2-c2cc3ccccc3cc21 ; CC1(C)c2cc(-c3cc(-c4ccc5cc6oc7cc8ccccc8cc7c6cc5c4)c4ccccc4c3)ccc2-c2cc3ccccc3cc21]

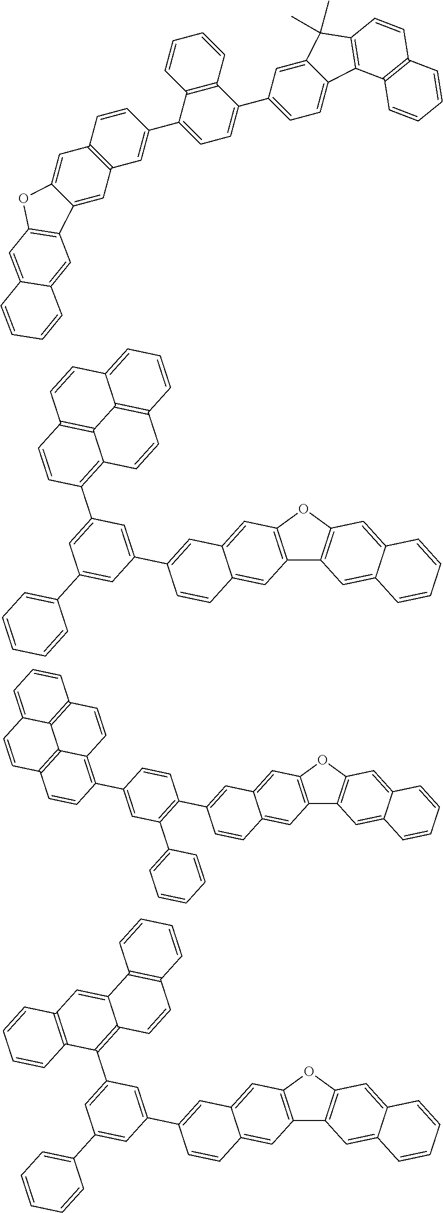

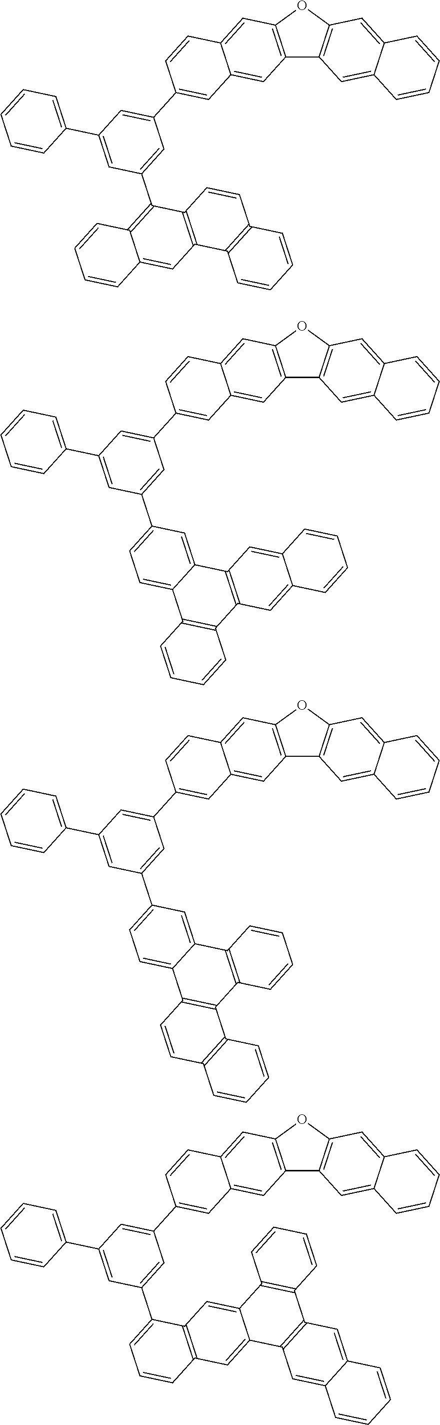

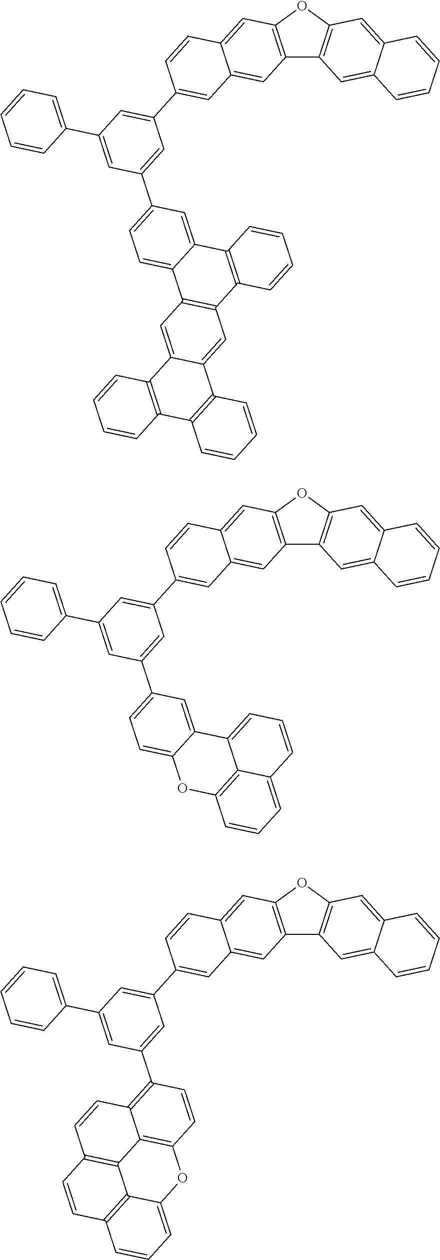 [SMILES: c1ccc(-c2cc(-c3ccc4cc5oc6cc7ccccc7cc6c5cc4c3)cc(-c3ccc4c(c3)c3ccccc3c3cc5c6ccccc6c6ccccc6c5cc43)c2)cc1 ; c1ccc(-c2cc(-c3ccc4c(c3)-c3cccc5cccc(c35)O4)cc(-c3ccc4cc5oc6cc7ccccc7cc6c5cc4c3)c2)cc1 ; c1ccc(-c2cc(-c3ccc4cc5oc6cc7ccccc7cc6c5cc4c3)cc(-c3ccc4c5c3ccc3ccc6cccc(c6c35)O4)c2)cc1]

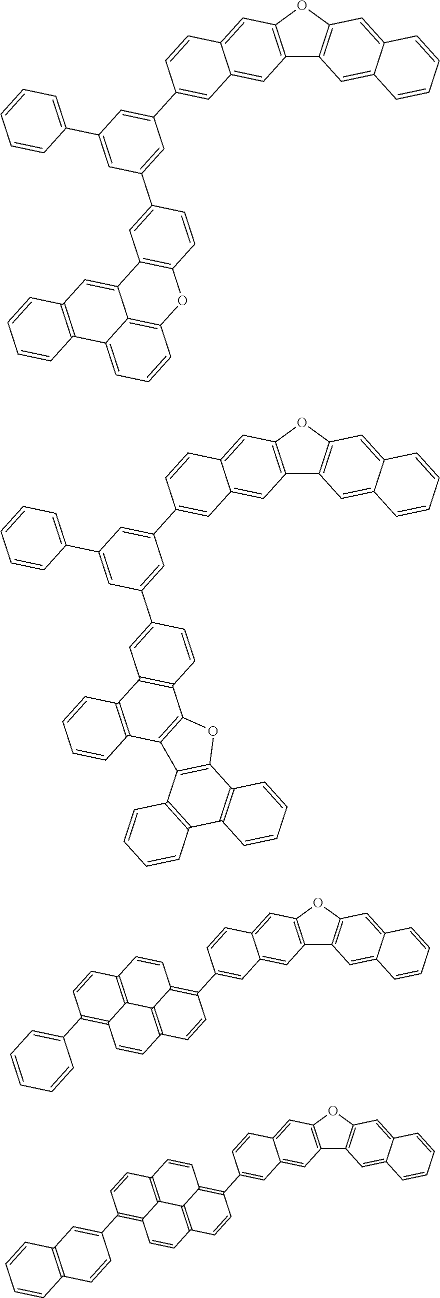 [SMILES: c1ccc(-c2cc(-c3ccc4c(c3)-c3cc5ccccc5c5cccc(c35)O4)cc(-c3ccc4cc5oc6cc7ccccc7cc6c5cc4c3)c2)cc1 ; c1ccc(-c2cc(-c3ccc4cc5oc6cc7ccccc7cc6c5cc4c3)cc(-c3ccc4c(c3)c3ccccc3c3c4oc4c5ccccc5c5ccccc5c43)c2)cc1 ; c1ccc(-c2ccc3ccc4c(-c5ccc6cc7oc8cc9ccccc9cc8c7cc6c5)ccc5ccc2c3c54)cc1 ; c1ccc2cc(-c3ccc4ccc5c(-c6ccc7cc8oc9cc%10ccccc%10cc9c8cc7c6)ccc6ccc3c4c65)ccc2c1]

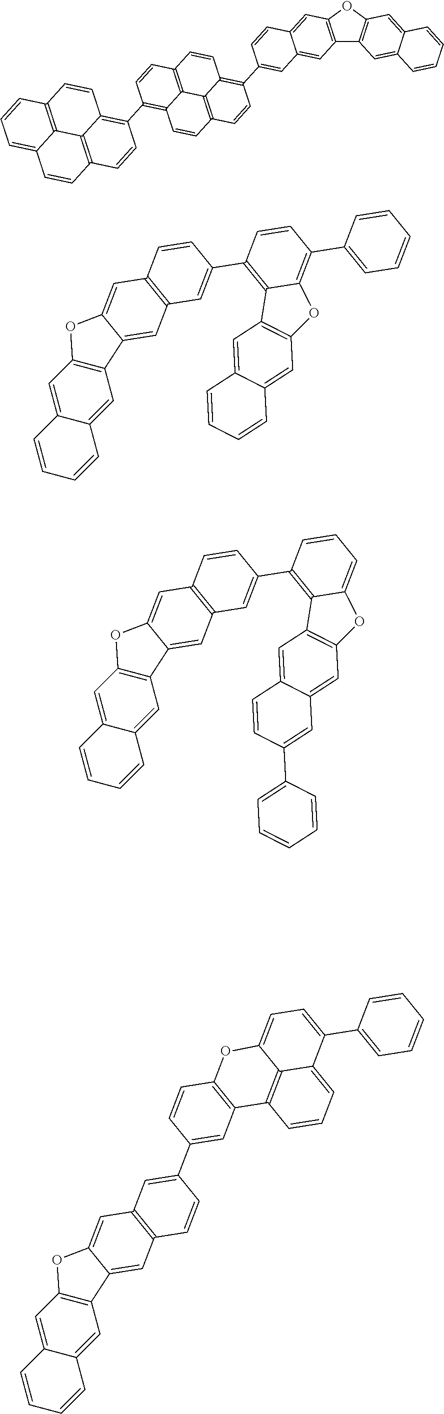 [SMILES: c1ccc2cc3c(cc2c1)oc1cc2ccc(-c4ccc5ccc6c(-c7ccc8ccc9cccc%10ccc7c8c9%10)ccc7ccc4c5c76)cc2cc13 ; c1ccc(-c2ccc(-c3ccc4cc5oc6cc7ccccc7cc6c5cc4c3)c3c2oc2cc4ccccc4cc23)cc1 ; c1ccc(-c2ccc3cc4c(cc3c2)oc2cccc(-c3ccc5cc6oc7cc8ccccc8cc7c6cc5c3)c24)cc1 ; c1ccc(-c2ccc3c4c(cccc24)-c2cc(-c4ccc5cc6c(cc5c4)oc4cc5ccccc5cc46)ccc2O3)cc1]

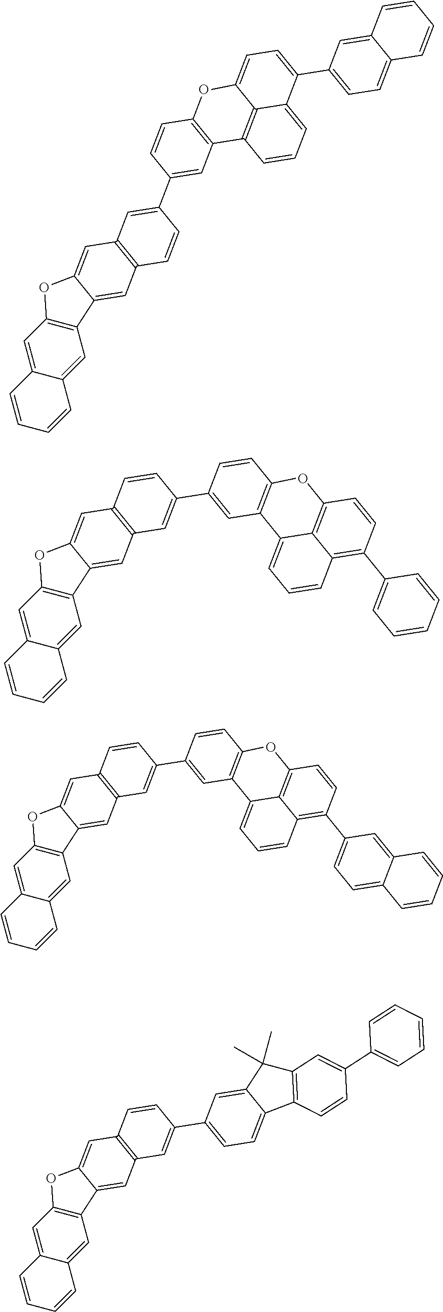 [SMILES: c1ccc2cc(-c3ccc4c5c(cccc35)-c3cc(-c5ccc6cc7c(cc6c5)oc5cc6ccccc6cc57)ccc3O4)ccc2c1 ; c1ccc(-c2ccc3c4c(cccc24)-c2cc(-c4ccc5cc6oc7cc8ccccc8cc7c6cc5c4)ccc2O3)cc1 ; c1ccc2cc(-c3ccc4c5c(cccc35)-c3cc(-c5ccc6cc7oc8cc9ccccc9cc8c7cc6c5)ccc3O4)ccc2c1 ; CC1(C)c2cc(-c3ccccc3)ccc2-c2ccc(-c3ccc4cc5oc6cc7ccccc7cc6c5cc4c3)cc21]

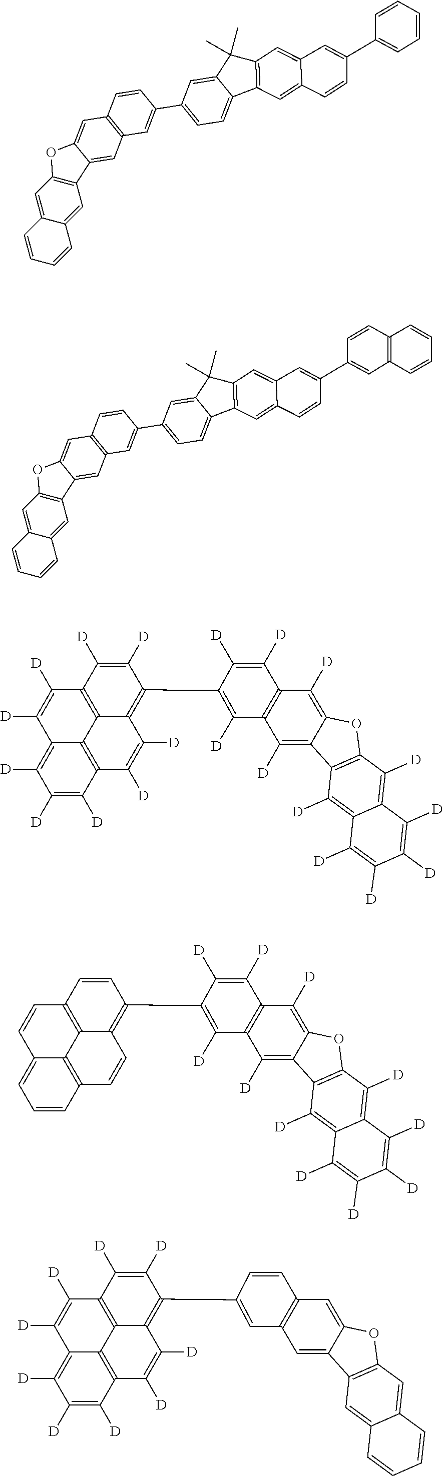

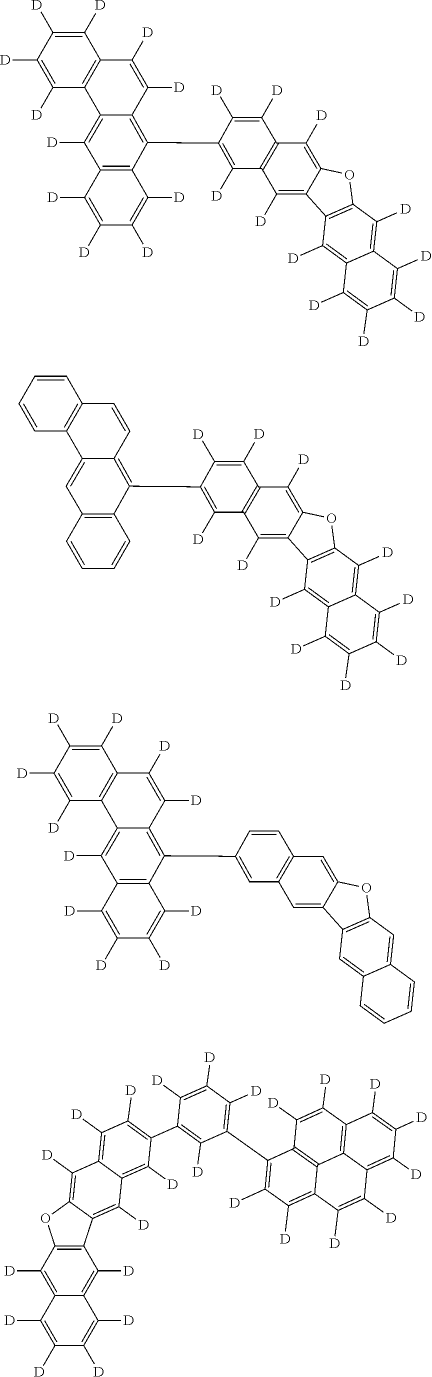

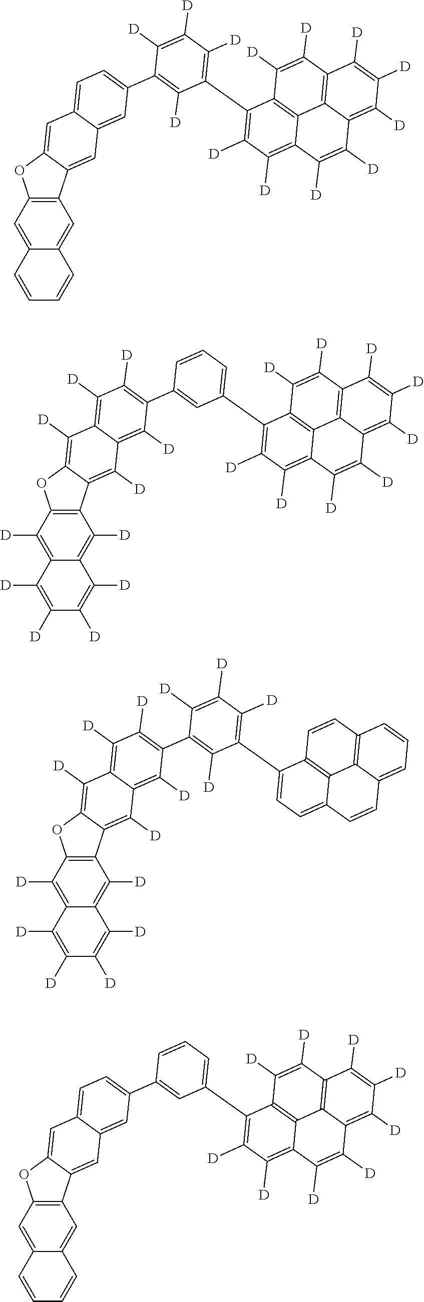

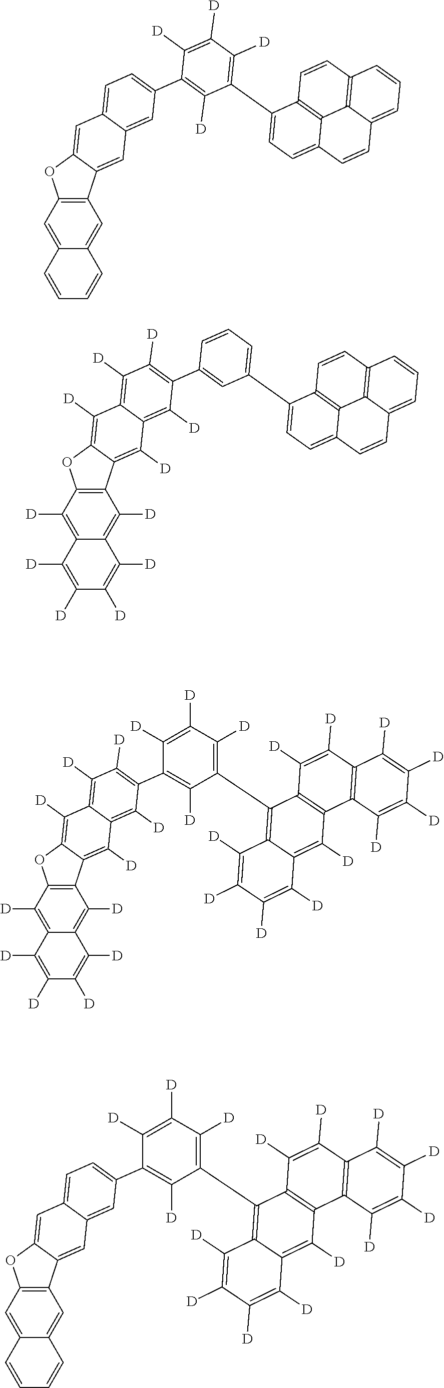

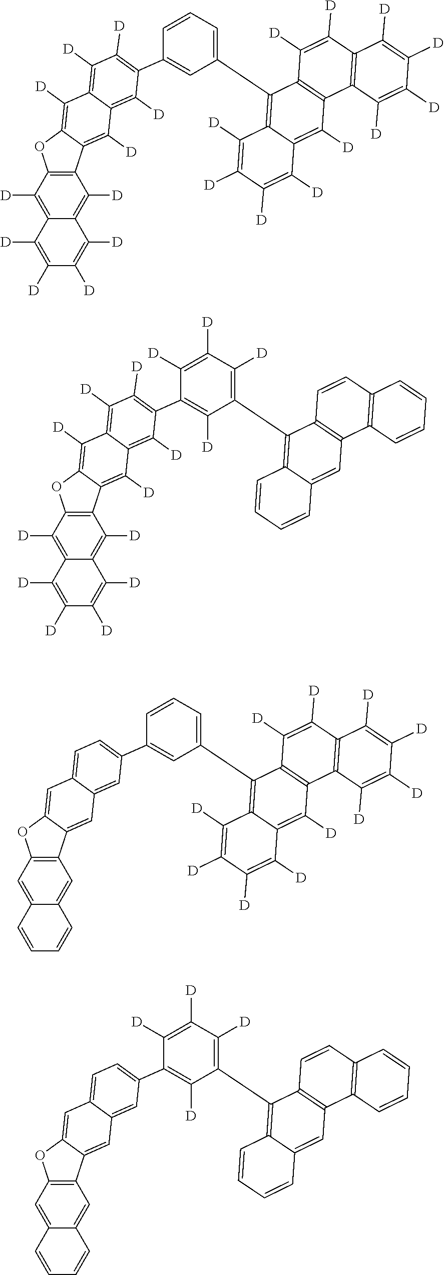

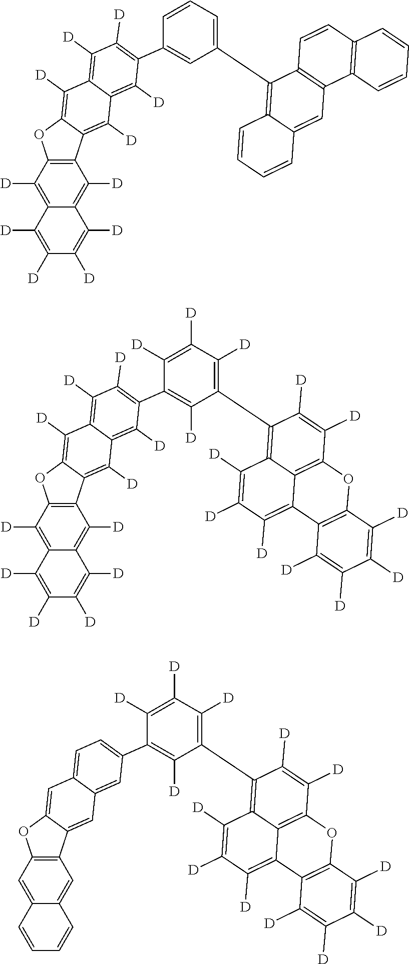 [SMILES: [2H]c1c([2H])c([2H])c2c([2H])c3c(oc4c([2H])c5c([2H])c([2H])c(-c6cccc(-c7c8ccccc8cc8c7ccc7ccccc78)c6)c([2H])c5c([2H])c43)c([2H])c2c1[2H] ; [2H]c1c([2H])c([2H])c2c(c1[2H])Oc1c([2H])c([2H])c(-c3c([2H])c([2H])c([2H])c(-c4c([2H])c([2H])c5c([2H])c6oc7c([2H])c8c([2H])c([2H])c([2H])c([2H])c8c([2H])c7c6c([2H])c5c4[2H])c3[2H])c3c([2H])c([2H])c([2H])c-2c13 ; [2H]c1c([2H])c([2H])c2c(c1[2H])Oc1c([2H])c([2H])c(-c3c([2H])c([2H])c([2H])c(-c4ccc5cc6oc7cc8ccccc8cc7c6cc5c4)c3[2H])c3c([2H])c([2H])c([2H])c-2c13]

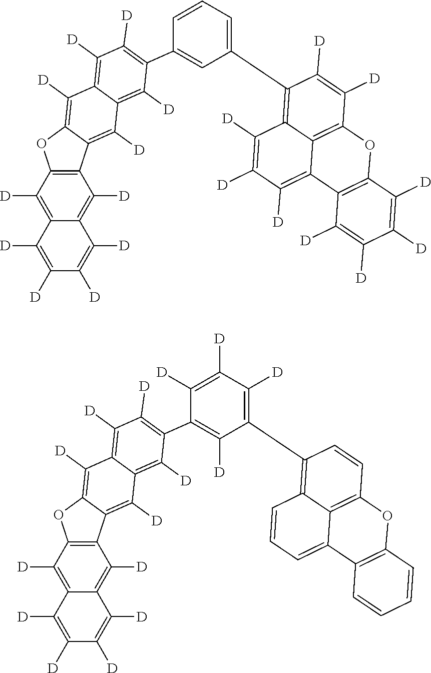 [SMILES: [2H]c1c([2H])c([2H])c2c(c1[2H])Oc1c([2H])c([2H])c(-c3cccc(-c4c([2H])c([2H])c5c([2H])c6oc7c([2H])c8c([2H])c([2H])c([2H])c([2H])c8c([2H])c7c6c([2H])c5c4[2H])c3)c3c([2H])c([2H])c([2H])c-2c13 ; [2H]c1c([2H])c(-c2c([2H])c([2H])c3c([2H])c4oc5c([2H])c6c([2H])c([2H])c([2H])c([2H])c6c([2H])c5c4c([2H])c3c2[2H])c([2H])c(-c2ccc3c4c(cccc24)-c2ccccc2O3)c1[2H]]

[chemical structure]

[chemical structure]

In one embodiment, the first emitting layer contains one or more selected from the group consisting of the compounds represented by the formulas (1) to (4), and a second compound.

One or more selected from the group consisting of the compounds represented by the formulas (1) to (4) and the second compound are different from each other.

### (Second Compound)

In one embodiment, the second compound is an emitting material.

In one embodiment, the second compound is a fluorescent compound.

In one embodiment, the second compound is a compound emitting fluorescence having a fluorescence emission maximum peak wavelength of 430 nm or more and 480 nm or less. In the present specification, the maximum peak wavelength of fluorescence emission may be referred to as a fluorescence emission maximum peak wavelength.

In the present specification, the fluorescence emission maximum peak wavelength refers to the maximum peak wavelength of a fluorescence spectrum at which the emission intensity in the measured fluorescence spectrum is maximized for a toluene solution in which a compound to be measured is dissolved at a concentration of 10⁻⁶ mol/L or more and 10⁻⁵ mol/L or less. As a measurement apparatus, a fluorescence spectrum measuring apparatus (apparatus name: FP-8300, manufactured by JASCO Corporation) can be used. The fluorescence spectrum measuring apparatus is not limited to the apparatus exemplified here.

Examples of the second compound include a bisarylaminonaphthalene derivative, an aryl-substituted naphthalene derivative, a bisarylaminoanthracene derivative, an aryl-substituted anthracene derivative, a bisarylaminopyrene derivative, an aryl-substituted pyrene derivative, a bisarylaminochrysene derivative, an aryl-substituted chrysene derivative, a bisarylaminofluoranthene derivative, an aryl-substituted fluoranthene derivative, an indenoperylene derivative, an acenaphthofluoranthene derivative, a compound containing a boron atom, a pyrromethene boron complex compound, a compound having a pyrromethene skeleton, a metal complex of a compound having a pyrromethene skeleton, a diketopyrrolopyrrole derivative, a perylene derivative, a naphthacene derivative, and the like.

Examples of the second compound include one or more compounds selected from the group consisting of a compound represented by the following formula (D1), a compound represented by the following formula (D2), a compound represented by the following formula (D3), and a compound represented by the following formula (D4).

### (Compound Represented by Formula (D1))

The compound represented by the formula (D1) will be described.

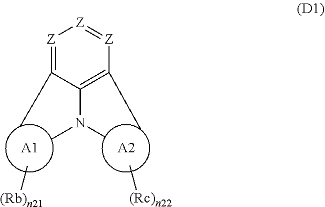

In the formula (D1),
Z's are independently CRa or a nitrogen atom,
A1 ring and A2 ring are independently
a substituted or unsubstituted aromatic hydrocarbon ring having 6 to 50 ring carbon atoms, or
a substituted or unsubstituted heterocyclic ring having 5 to 50 ring atoms,
when a plurality of Ra's is present, one or more sets of the adjacent two or more of the plurality of Ra's form a substituted or unsubstituted monocyclic ring by bonding with each other, form a substituted or unsubstituted fused ring by bonding with each other, or do not bond with each other,
n21 and n22 are independently 0, 1, 2, 3, or 4,
when a plurality of Rb's is present, one or more sets of the adjacent two or more of the plurality of Rb's form a substituted or unsubstituted monocyclic ring by bonding with each other, form a substituted or unsubstituted fused ring by bonding with each other, or do not bond with each other,
when a plurality of Rc's is present, one or more sets of the adjacent two or more of the plurality of Rc's form a substituted or unsubstituted monocyclic ring by bonding with each other, form a substituted or unsubstituted fused ring by bonding with each other, or do not bond with each other,
Ra, Rb, and Rc which do not bond with each other are independently
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,

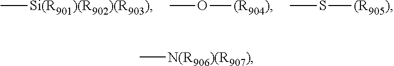

a halogen atom, a cyano group, a nitro group,
a substituted or unsubstituted aryl group having 6 to 50 ring carbon atoms, or
a substituted or unsubstituted monovalent heterocyclic group having 5 to 50 ring atoms,
R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms, and
when two or more of each of R₉₀₁ to R₉₀₇ are present, the two or more of each of R₉₀₁ to R₉₀₇ may be the same as or different from each other.

Examples of the “aromatic hydrocarbon ring” for the A1 ring and the A2 ring include the same structure as the compound formed by introducing a hydrogen atom to the “aryl group having 6 to 50 ring carbon atoms” described above.

The “aromatic hydrocarbon ring” for the A1 ring and the A2 ring contains two carbon atoms on a fused bicyclic structure at the center of the above formula (D1).

Specific examples of the “substituted or unsubstituted aromatic hydrocarbon ring having 6 to 50 ring carbon atoms” include a compound formed by introducing a hydrogen atom to the “substituted or unsubstituted aryl group” described in the specific example group G1, and the like.

Examples of the “heterocyclic ring” for the A1 ring and the A2 ring include the same structure as the compound formed by introducing a hydrogen atom to the “heterocyclic group having 5 to 50 ring atoms” described above.

The “heterocyclic ring” for the A1 ring and the A2 ring contains two carbon atoms on a fused bicyclic structure at the center of the above formula (D1).

Specific examples of the “substituted or unsubstituted heterocyclic ring having 5 to 50 ring atoms” include a compound formed by introducing a hydrogen atom to the “substituted or unsubstituted heterocyclic group” described in the specific example group G2, and the like.

Rb is bonded to any one of the carbon atoms forming the aromatic hydrocarbon ring as the A1 ring, or any one of atoms forming the heterocyclic ring as the A1 ring.

Rc is bonded to any one of the carbon atoms forming the aromatic hydrocarbon ring as the A2 ring, or any one of atoms forming the heterocyclic ring as the A2 ring.

In one embodiment, at least one of Ra, Rb, and Rc is a group represented by the following formula (D1a).

In one embodiment, at least two of Ra, Rb, and Rc are a group represented by the following formula (D1a).

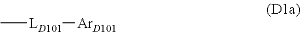

In the formula (D1a),
L_{D101} is
a single bond,
a substituted or unsubstituted arylene group having 6 to 30 ring carbon atoms, or
a substituted or unsubstituted divalent heterocyclic group having 5 to 30 ring atoms, and Ar_{D101} is
a substituted or unsubstituted aryl group having 6 to 50 ring carbon atoms,
a substituted or unsubstituted monovalent heterocyclic group having 5 to 50 ring atoms, or
a group represented by the following formula (D1 b):

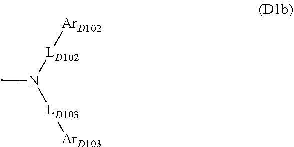

in the formula (D1 b),
L_{D102} and L_{D103} are independently
a single bond,
a substituted or unsubstituted arylene group having 6 to 30 ring carbon atoms, or
a substituted or unsubstituted divalent heterocyclic group having 5 to 30 ring atoms,
a set of Ar_{D102} and Ar_{D103} forms a substituted or unsubstituted monocyclic ring by bonding with each other, forms a substituted or unsubstituted fused ring by bonding with each other, or does not bond with each other, and
Ar_{D102} and Ar_{D103} which do not bond with each other are independently
a substituted or unsubstituted aryl group having 6 to 50 ring carbon atoms, or
a substituted or unsubstituted monovalent heterocyclic group having 5 to 50 ring atoms.

In one embodiment, R₉₀₁ to R₉₀₇ are independently
a substituted or unsubstituted alkyl group having 1 to 50 carbon atoms, or
a substituted or unsubstituted aryl group having 6 to 50 ring carbon atoms.

The compound represented by the formula (D1) can be synthesized by using a known reaction or raw material suited for an intended product.

Specific examples of the compound represented by the formula (D1) include the following compounds. These are merely examples, and the compound represented by the formula (D1) is not limited to the following specific examples.

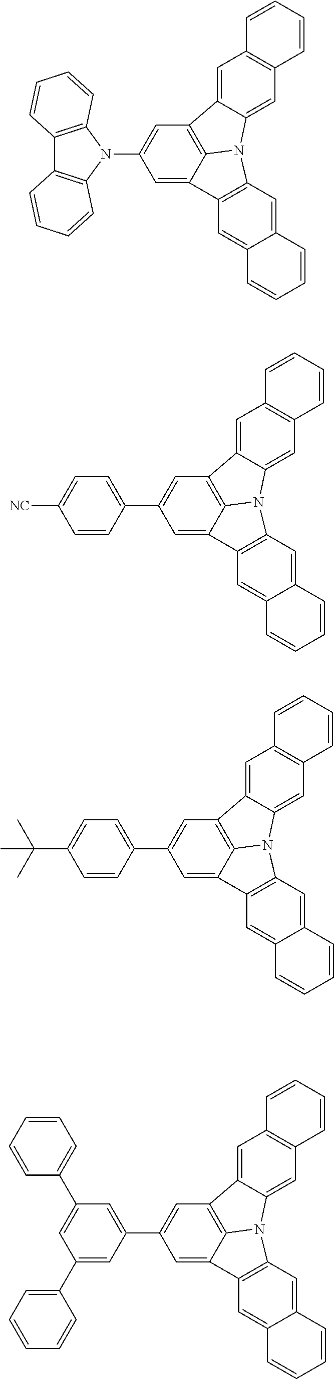

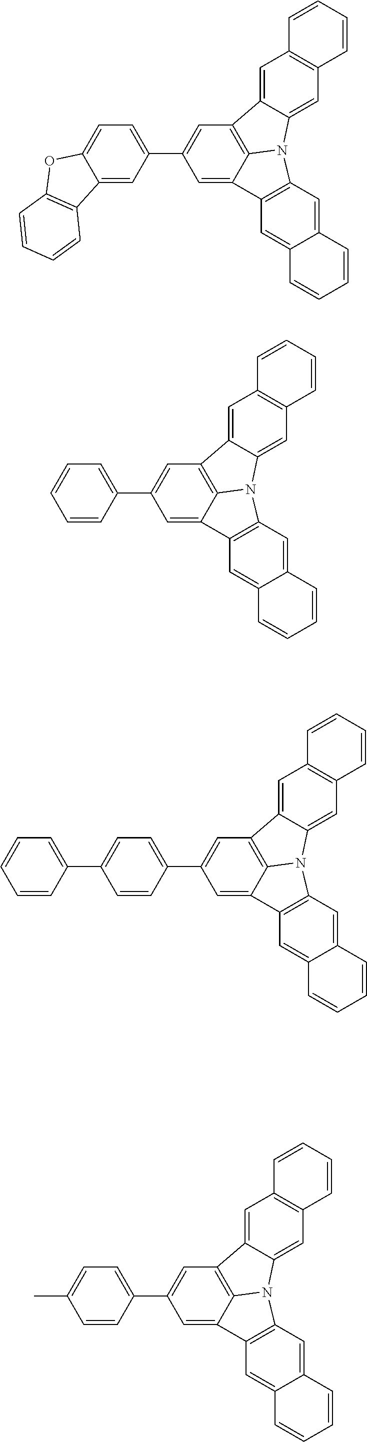 [SMILES: c1ccc2cc3c(cc2c1)c1cc(-c2ccc4oc5ccccc5c4c2)cc2c4cc5ccccc5cc4n3c12 ; c1ccc(-c2cc3c4cc5ccccc5cc4n4c5cc6ccccc6cc5c(c2)c34)cc1 ; c1ccc(-c2ccc(-c3cc4c5cc6ccccc6cc5n5c6cc7ccccc7cc6c(c3)c45)cc2)cc1 ; Cc1ccc(-c2cc3c4cc5ccccc5cc4n4c5cc6ccccc6cc5c(c2)c34)cc1]

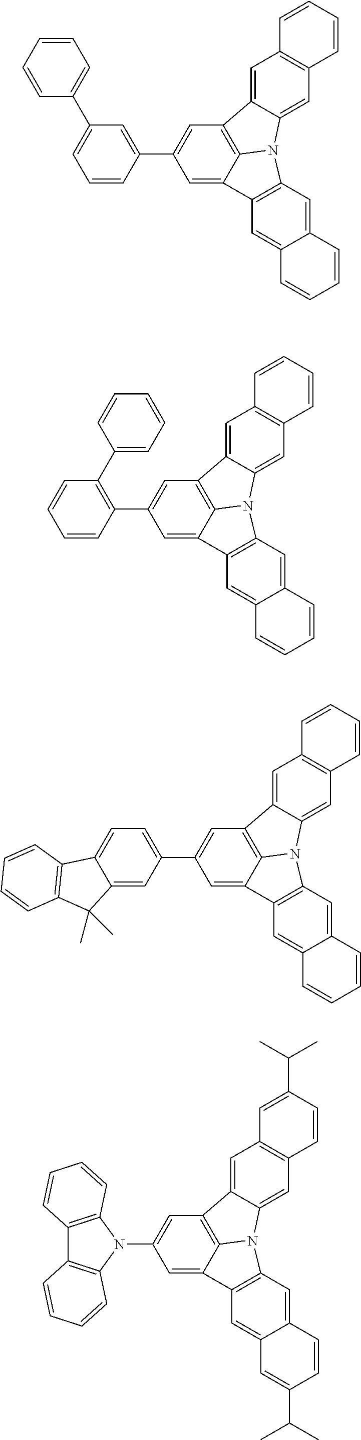

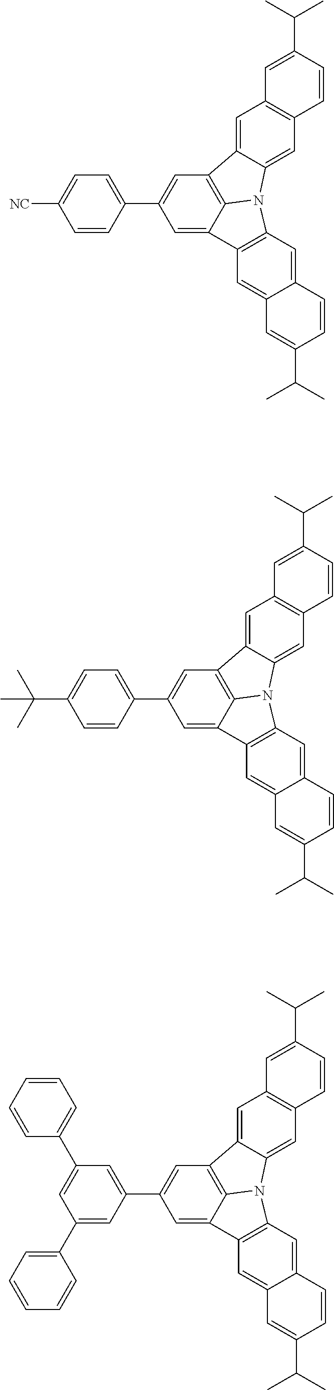

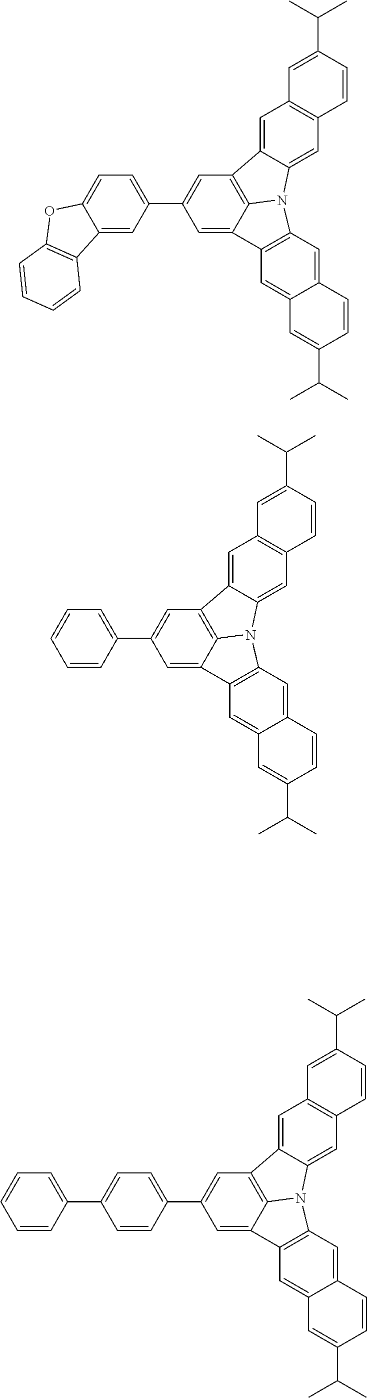

### (Compound Represented by Formula (02))

The compound represented by the formula (02) will be described.

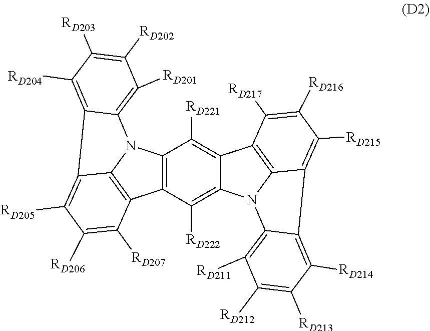

In the formula (D2),
one or more sets of the adjacent two or more of R_{D201} to R_{D207} and R_{D211} to R_{D217} form a substituted or unsubstituted monocyclic ring by bonding with each other, form a substituted or unsubstituted fused ring by bonding with each other, or do not bond with each other,
R_{D201} to R_{D207} and R_{D211} to R_{D217} which do not bond with each other are independently
a hydrogen atom,
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,

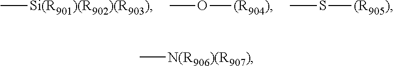

a halogen atom, a cyano group, a nitro group,
a substituted or unsubstituted aryl group having 6 to 50 ring carbon atoms, or
a substituted or unsubstituted monovalent heterocyclic group having 5 to 50 ring atoms, R_{D221} and R_{D222} are independently
a hydrogen atom,
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms, a substituted or unsubstituted cycloalkyl group having 3 to 50 ring carbon atoms,

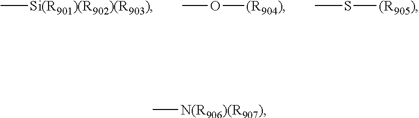

a halogen atom, a cyano group, a nitro group,
a substituted or unsubstituted aryl group having 6 to 50 ring carbon atoms, or
a substituted or unsubstituted monovalent heterocyclic group having 5 to 50 ring atoms, and
R₉₀₁ to R₉₀₇ are as defined in the above formula (D1).

The “one sets of the adjacent two or more of R_{D201} to R_{D207} and R_{D211} to R_{D217}” is, for example, a combination of a set of R_{D201} and R_{D202}, a set of R_{D202} and R_{D203}, a set of R_{D203} and R_{D204}, a set of R_{D205} and R_{D206}, a set of R_{D206} and R_{D207}, a set of R_{D201}, R_{D202} and R_{D203}, and the like.

In one embodiment, at least one of R_{D201} to R_{D207} and R_{D211} to R_{D217} is —N(R₉₀₆)(R₉₀₇).

In one embodiment, at least two of R_{D201} to R_{D207} and R_{D211} to R_{D217} is —N(R₉₀₆)(R₉₀₇).

In one embodiment, at least one of R_{D201} to R_{D207} is —N(R₉₀₆)(R₉₀₇).

In one embodiment, at least one of R_{D211} to R_{D217} is —N(R₉₀₆)(R₉₀₇).

In one embodiment, at least one of R_{D201} to R_{D207}, and at least one of R_{D211} to R_{D217} are independently —N(R₉₀₆)(R₉₀₇).

In one embodiment, R_{D201} to R_{D207} and R_{D211} to R_{D217} which are not —N(R₉₀₆)(R₉₀₇) are independently
a hydrogen atom,
a substituted or unsubstituted aryl group having 6 to 50 ring carbon atoms, or
a substituted or unsubstituted monovalent heterocyclic group having 5 to 50 ring atoms.

The compound represented by the formula (D2) can be synthesized by using a known reaction or raw material suited for an intended product.

Specific examples of the compound represented by the formula (D2) include the following compounds. These are merely examples, and the compound represented by the formula (D2) is not limited to the following specific examples.

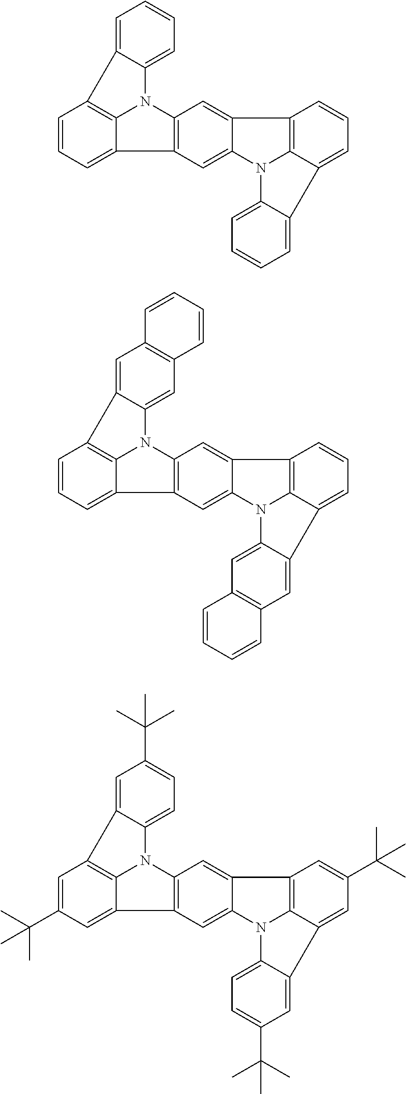 [SMILES: c1ccc2c(c1)c1cccc3c4cc5c(cc4n2c13)c1cccc2c3ccccc3n5c21 ; c1ccc2cc3c(cc2c1)c1cccc2c4cc5c(cc4n3c12)c1cccc2c3cc4ccccc4cc3n5c21 ; CC(C)(C)c1ccc2c(c1)c1cc(C(C)(C)C)cc3c4cc5c(cc4n2c13)c1cc(C(C)(C)C)cc2c3cc(C(C)(C)C)ccc3n5c21]

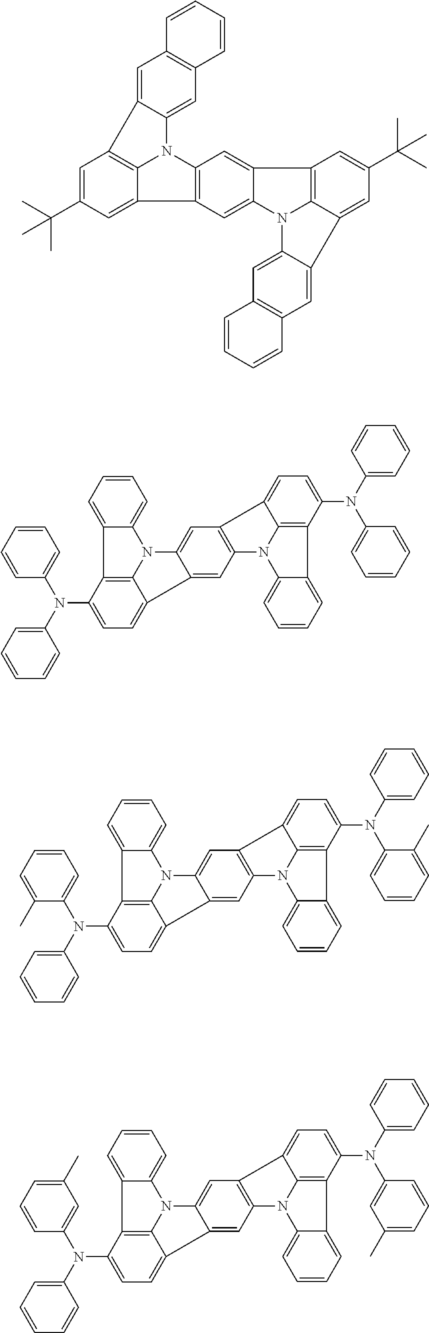

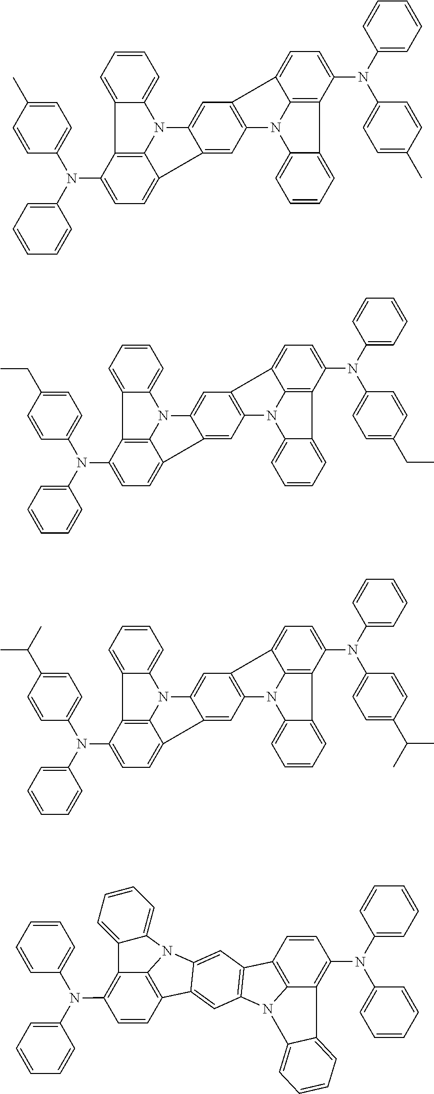

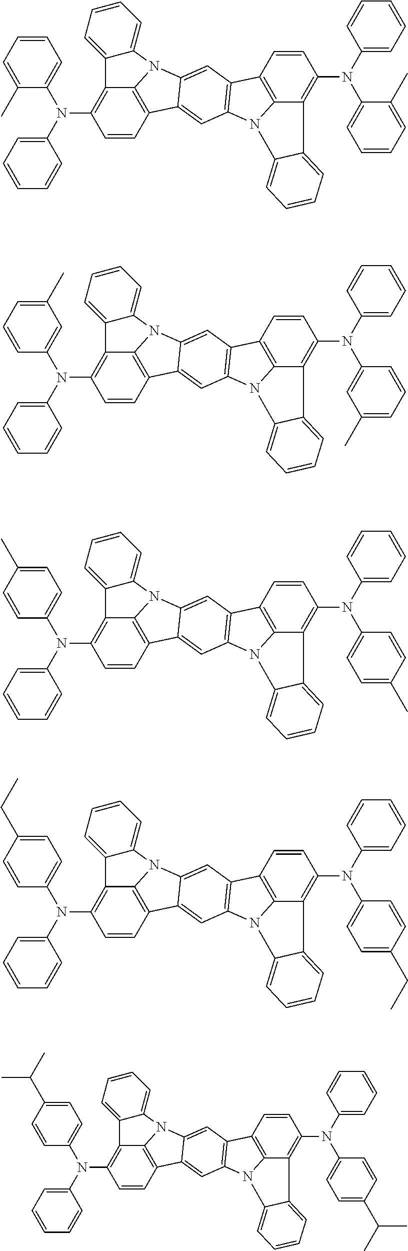

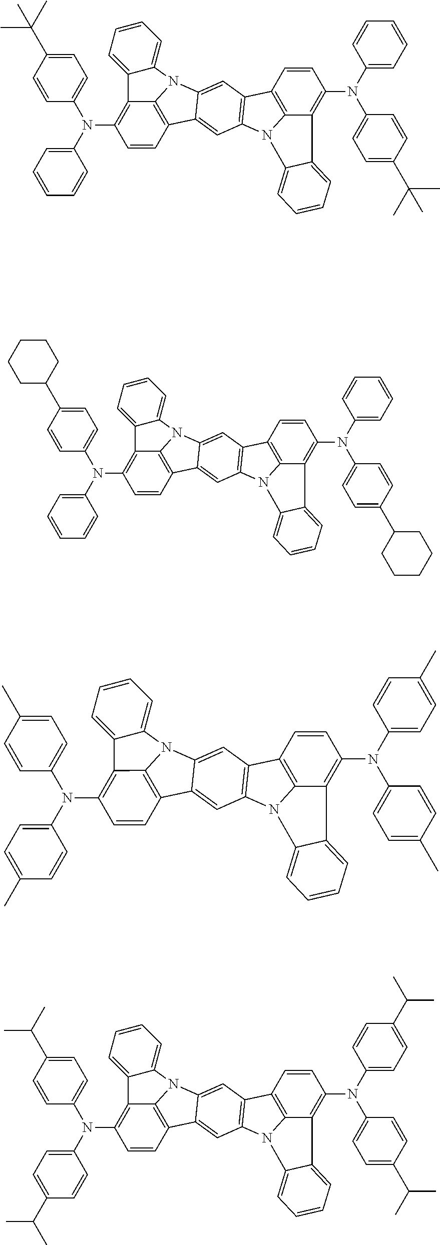

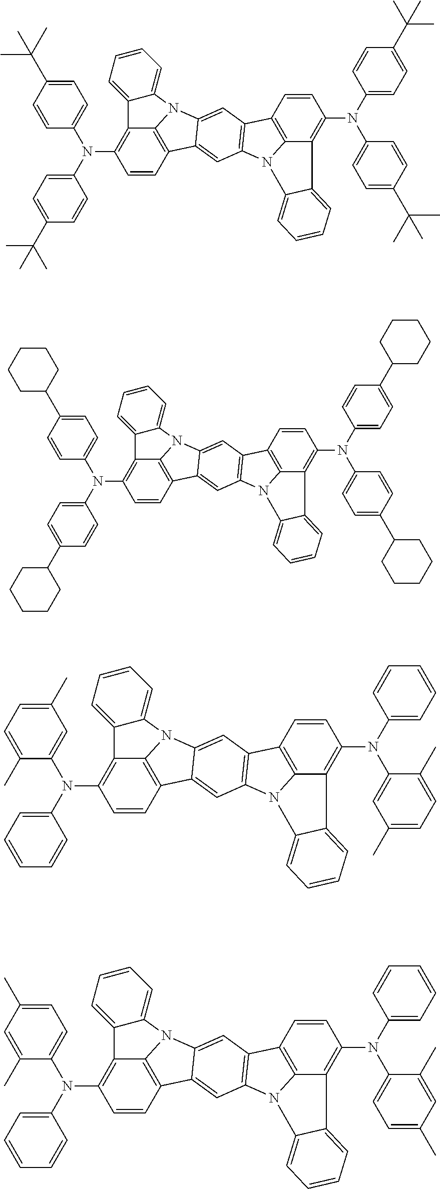

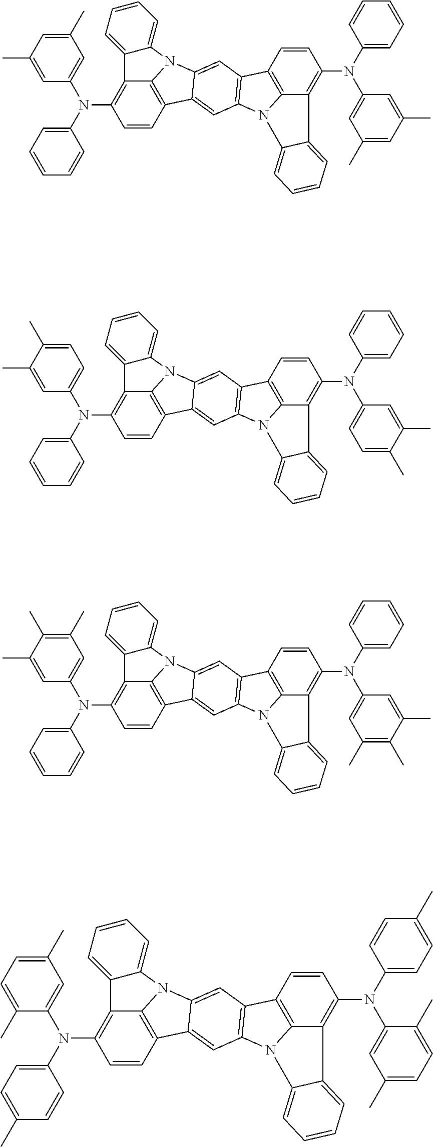

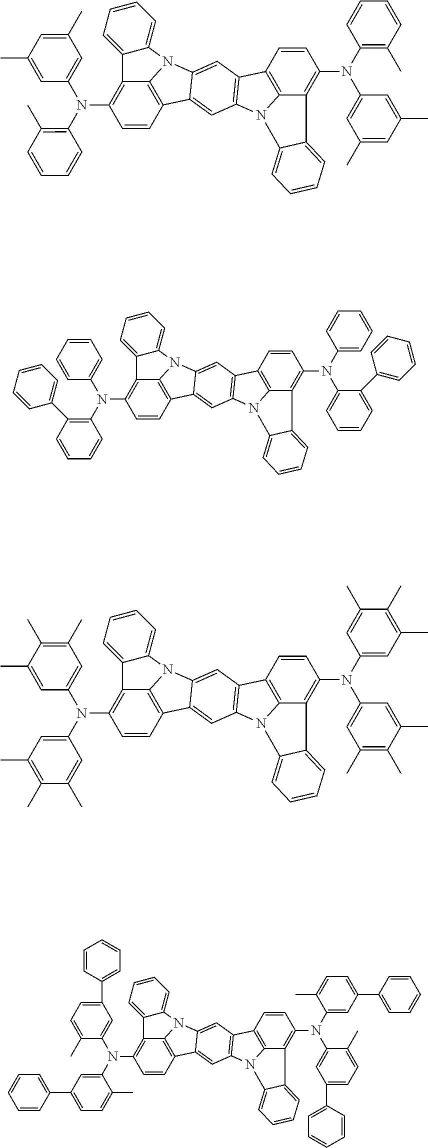

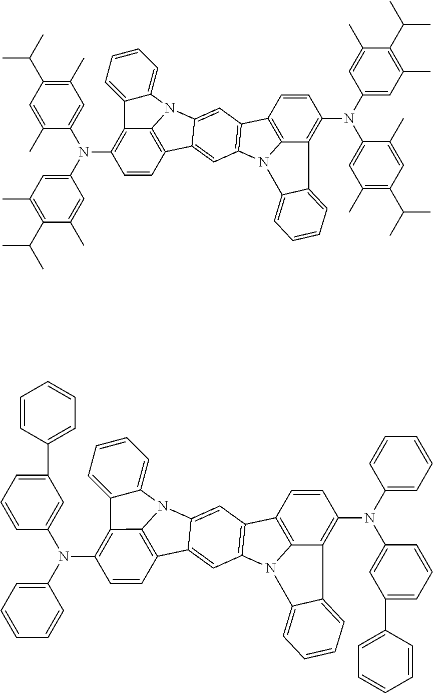 [SMILES: Cc1cc(N(c2cc(C)c(C(C)C)c(C)c2)c2ccc3c4cc5c(cc4n4c6ccccc6c2c34)c2ccc(N(c3cc(C)c(C(C)C)c(C)c3)c3cc(C)c(C(C)C)cc3C)c3c4ccccc4n5c23)c(C)cc1C(C)C ; c1ccc(-c2cccc(N(c3ccccc3)c3ccc4c5cc6c(cc5n5c7ccccc7c3c45)c3ccc(N(c4ccccc4)c4cccc(-c5ccccc5)c4)c4c5ccccc5n6c34)c2)cc1]

### (Compound Represented by Formula (D3))

The compound represented by the formula (D3) will be described.

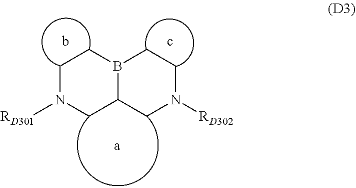

In the formula (D3),
a ring, b ring, and c ring are independently
a substituted or unsubstituted aromatic hydrocarbon ring having 6 to 50 ring carbon atoms, or
a substituted or unsubstituted heterocyclic ring having 5 to 50 ring atoms,
R_{D301} and R_{D302} are independently bonded to the a ring, the b ring, or the c ring to form a substituted or unsubstituted heterocyclic ring, or do not form the substituted or unsubstituted heterocyclic ring, and
R_{D301} and R_{D302} which do not form the substituted or unsubstituted heterocyclic ring are independently
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms.

The a ring, the b ring, and the c ring are fused to the fused bicyclic structure at the center of the above formula (D3), which is composed of a boron atom, two nitrogen atoms, and seven carbon atoms.

The “aromatic hydrocarbon ring” for the a ring, the b ring, and the c ring has the same structure as the compound formed by introducing a hydrogen atom to the “aryl group having 6 to 50 ring carbon atoms” described above.

The “aromatic hydrocarbon ring” for the a ring contains three carbon atoms on a fused bicyclic structure at the center of the above formula (D3).

The “aromatic hydrocarbon ring” for the b ring and the c ring contains two carbon atoms on a fused bicyclic structure at the center of the above formula (D3).

Specific examples of the “substituted or unsubstituted aromatic hydrocarbon ring having 6 to 50 ring carbon atoms” include a compound formed by introducing a hydrogen atom to the “substituted or unsubstituted aryl group” described in the specific example group G1, and the like.

Examples of the “heterocyclic ring” for the a ring, the b ring, and the c ring include the same structure as the compound formed by introducing a hydrogen atom to the “heterocyclic group having 5 to 50 ring atoms” described above.

The “heterocyclic ring” for the a ring contains three carbon atoms on a fused bicyclic structure at the center of the above formula (D3). The “heterocyclic ring” for the b ring and the c ring contains two carbon atoms on a fused bicyclic structure at the center of the above formula (D3). Specific examples of the “substituted or unsubstituted heterocyclic ring having 5 to 50 ring atoms” include a compound formed by introducing a hydrogen atom to the “substituted or unsubstituted heterocyclic group” described in the specific example group G2, and the like.

R_{D301} and R_{D302} may be independently bonded to the a ring, the b ring, or the c ring to form a substituted or unsubstituted heterocyclic ring. The heterocyclic ring in this case contains a nitrogen atom on a fused bicyclic structure at the center of the above formula (D3). The heterocyclic ring in this case may contain a hetero atom other than the nitrogen atom. The fact that R_{D301} or R_{D302} is bonded to the a ring, the b ring, or the c ring specifically means that an atom constituting the a ring, the b ring, or the c ring is bonded to an atom constituting R_{D301} or R_{D302}. For example, R_{D301} may be bonded to the a ring to form a bicyclic fused, tricyclic fused, tetracyclic fused, or pentacyclic or higher fused nitrogen-containing heterocyclic ring in which the ring including R_{D301} and the a ring are fused. Specific examples of the nitrogen-containing heterocyclic ring include a compound corresponding to the bicyclic or higher fused heterocyclic group containing nitrogen, and the like in the specific example group G2. The same applies to a case where R_{D301} is bonded to the b ring, R_{D302} is bonded to the a ring, and a case where R_{D302} is bonded to the c ring.

In one embodiment, the a ring, the b ring, and the c ring in the formula (D3) are independently a substituted or unsubstituted aromatic hydrocarbon ring having 6 to 50 ring carbon atoms.

In one embodiment, the a ring, the b ring, and the c ring in the formula (D3) are independently a substituted or unsubstituted benzene ring or naphthalene ring.

In one embodiment, R_{D301} and R_{D302} in the formula (D3) are independently
a substituted or unsubstituted aryl group having 6 to 50 ring carbon atoms, or
a substituted or unsubstituted monovalent heterocyclic group having 5 to 50 ring atoms.

In one embodiment, R_{D301} and R_{D302} in the formula (D3) are independently a substituted or unsubstituted aryl group having 6 to 50 ring carbon atoms.

In one embodiment, the compound represented by the formula (D3) is a compound represented by the following formula (D32):

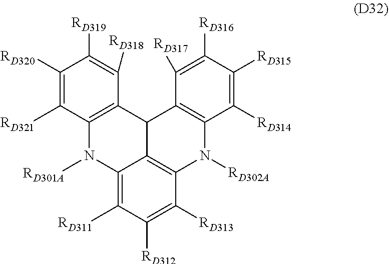

wherein in the formula (D32),
R_{D301A} is bonded to one or more selected from the group consisting of R_{D311} and R_{D321} to form a substituted or unsubstituted heterocyclic ring, or does not form the substituted or unsubstituted heterocyclic ring,
R_{D302A} is bonded to one or more selected from the group consisting of R_{D313} and R_{D314} to form a substituted or unsubstituted heterocyclic ring, or does not form the substituted or unsubstituted heterocyclic ring,
R_{D301A} and R_{D302A} which do not form the substituted or unsubstituted heterocyclic ring are independently
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms,
one or more sets of the adjacent two or more of R_{D311} to R_{D321} form a substituted or unsubstituted monocyclic ring by bonding with each other, form a substituted or unsubstituted fused ring by bonding with each other, or do not bond with each other,
R_{D311} to R_{D321} which do not form the substituted or unsubstituted heterocyclic ring, which do not form the monocyclic ring, and which do not form the fused ring are independently
a hydrogen atom,
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,

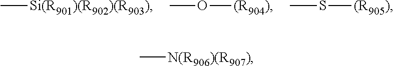

a halogen atom, a cyano group, a nitro group,
a substituted or unsubstituted aryl group having 6 to 50 ring carbon atoms, or
a substituted or unsubstituted monovalent heterocyclic group having 5 to 50 ring atoms, and
R₉₀₁ to R₉₀₇ are as defined in the above formula (D1).

R_{D301A} and R_{D302A} of the above formula (D32) each correspond to R_{D301} and R_{D302} of the above formula (D3).

For example, R_{D301A} and R_{D311} may be bonded to each other to form a bicyclic fused, tricyclic fused, tetracyclic fused, or pentacyclic or higher fused nitrogen-containing heterocyclic ring in which the ring including them and a benzene ring corresponding to the a ring are fused. Specific examples of the nitrogen-containing heterocyclic ring include a compound corresponding to the bicyclic or higher fused heterocyclic group containing nitrogen, and the like in the specific example group G2. The same applies to a case where R_{D301A} and R_{D321} are bonded, R_{D302A} and R_{D313} are bonded, and R_{D302A} and R_{D314} are bonded.

In one embodiment, one or more sets of the adjacent two or more of R_{D311} to R_{D321}
form a substituted or unsubstituted monocyclic ring by bonding with each other, or
form a substituted or unsubstituted fused ring by bonding with each other.

For example, R_{D311} and R_{D312} may be bonded to each other to form a structure in which a benzene ring, an indole ring, a pyrrole ring, a benzofuran ring, a benzothiophene ring, or the like is fused to the 6-membered ring to which they are bonded. The formed fused rings each form a naphthalene ring, a carbazole ring, an indole ring, a benzofuran ring, a dibenzofuran ring, or a dibenzothiophene ring.

In one embodiment, R_{D311} to R_{D321} which do not contribute to ring formation are independently
a hydrogen atom,
a substituted or unsubstituted alkyl group having 1 to 50 carbon atoms,
a substituted or unsubstituted aryl group having 6 to 50 ring carbon atoms, or
a substituted or unsubstituted monovalent heterocyclic group having 5 to 50 ring atoms.

In one embodiment, R_{D311} to R_{D321} which do not contribute to ring formation are independently
a hydrogen atom,
a substituted or unsubstituted aryl group having 6 to 50 ring carbon atoms, or
a substituted or unsubstituted monovalent heterocyclic group having 5 to 50 ring atoms.

In one embodiment, R_{D311} to R_{D321} which do not contribute to ring formation are independently

a hydrogen atom, or
a substituted or unsubstituted alkyl group having 1 to 50 carbon atoms.

In one embodiment, R_{D311} to R_{D321} which do not contribute to ring formation are independently
a hydrogen atom, or
a substituted or unsubstituted alkyl group having 1 to 50 carbon atoms, and
at least one of R_{D311} to R_{D321} is a substituted or unsubstituted alkyl group having 1 to 50 carbon atoms.

In one embodiment, the compound represented by the formula (D32) is a compound represented by the following formula (D33):

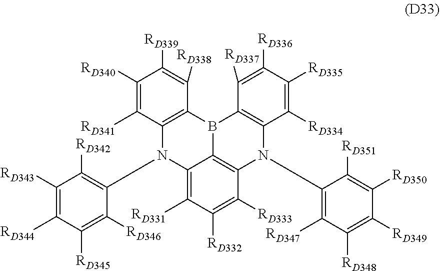

wherein in the formula (D33),
R_{D331} is bonded to R_{D346} to form a substituted or unsubstituted heterocyclic ring, or does not form the substituted or unsubstituted heterocyclic ring,
R_{D333} is bonded to R_{D347} to form a substituted or unsubstituted heterocyclic ring, or does not form the substituted or unsubstituted heterocyclic ring,
R_{D334} is bonded to R_{D351} to form a substituted or unsubstituted heterocyclic ring, or does not form the substituted or unsubstituted heterocyclic ring,
R_{D341} is bonded to R_{D342} to form a substituted or unsubstituted heterocyclic ring, or does not form the substituted or unsubstituted heterocyclic ring,
one or more sets of the adjacent two or more of R_{D331} to R_{D351} form a substituted or unsubstituted monocyclic ring by bonding with each other, form a substituted or unsubstituted fused ring by bonding with each other, or do not bond with each other,
R_{D331} to R_{D351} which do not bond with each other are independently
a hydrogen atom,
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,

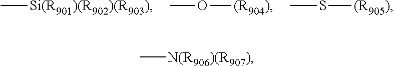

a halogen atom, a cyano group, a nitro group,
a substituted or unsubstituted aryl group having 6 to 50 ring carbon atoms, or
a substituted or unsubstituted monovalent heterocyclic group having 5 to 50 ring atoms, and
R₉₀₁ to R₉₀₇ are as defined in the above formula (D1).

R_{D331} may be bonded to R_{D346} to form a substituted or unsubstituted heterocyclic ring. For example, R_{D331} and R_{D346} may be bonded to each other to form a tricyclic or higher nitrogen-containing heterocyclic ring in which a benzene ring to which R_{D346} is bonded, a ring including N, and a benzene ring corresponding to the a ring are fused. Specific examples of the nitrogen-containing heterocyclic ring include a compound corresponding to the tricyclic or higher fused heterocyclic group containing nitrogen, and the like in the specific example group G2. The same applies to a case where R_{D333} and R_{D347} are bonded, R_{D334} and R_{D351} are bonded, and R_{D341} and R_{D342} are bonded.

In one embodiment, R_{D331} to R_{D351} which do not contribute to ring formation are independently
a hydrogen atom,
a substituted or unsubstituted alkyl group having 1 to 50 carbon atoms,
a substituted or unsubstituted aryl group having 6 to 50 ring carbon atoms, or
a substituted or unsubstituted monovalent heterocyclic group having 5 to 50 ring atoms.

In one embodiment, R_{D331} to R_{D351} which do not contribute to ring formation are independently
a hydrogen atom,
a substituted or unsubstituted aryl group having 6 to 50 ring carbon atoms, or
a substituted or unsubstituted monovalent heterocyclic group having 5 to 50 ring atoms.

In one embodiment, R_{D331} to R_{D351} which do not contribute to ring formation are independently
a hydrogen atom, or
a substituted or unsubstituted alkyl group having 1 to 50 carbon atoms.

In one embodiment, R_{D331} to R_{D351} which do not contribute to ring formation are independently
a hydrogen atom, or
a substituted or unsubstituted alkyl group having 1 to 50 carbon atoms, and
at least one of R_{D331} to R_{D351} is a substituted or unsubstituted alkyl group having 1 to 50 carbon atoms.

In one embodiment, the compound represented by the formula (D33) is a compound represented by the following formula (D33A).

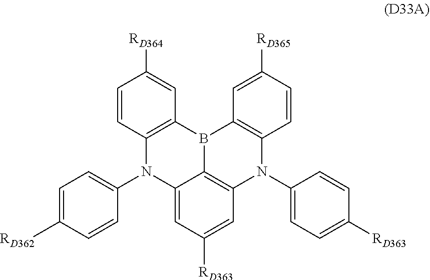

In the formula (D33A),
R_{D361} is
a hydrogen atom,
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms, or
a substituted or unsubstituted aryl group having 6 to 50 ring carbon atoms, and
R_{D362} to R_{D365} are independently
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms, or
a substituted or unsubstituted aryl group having 6 to 50 ring carbon atoms.

In one embodiment, R_{D361} to R_{D365} are independently
a substituted or unsubstituted alkyl group having 1 to 50 carbon atoms, or
a substituted or unsubstituted aryl group having 6 to 50 ring carbon atoms.

In one embodiment, R_{D361} to R_{D365} are independently a substituted or unsubstituted alkyl group having 1 to 50 carbon atoms.

In one embodiment, the compound represented by the formula (D33) is a compound represented by the following formula (D33B).

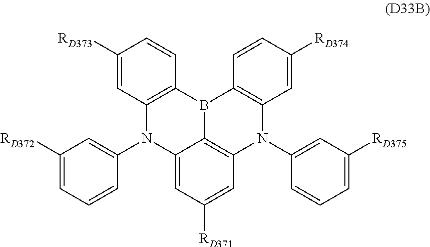

In the formula (D33B),
R_{D371} and R_{D372} are independently
a hydrogen atom,
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms, or

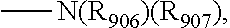

a substituted or unsubstituted aryl group having 6 to 50 ring carbon atoms,
R_{D373} to R_{D375} are independently
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,

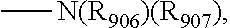

or
a substituted or unsubstituted aryl group having 6 to 50 ring carbon atoms, and
R₉₀₆ and R₉₀₇ are as defined in the above formula (D1).

In one embodiment, the compound represented by the formula (D33) is a compound represented by the following formula (D33B′).

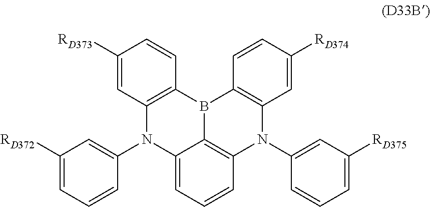

In the formula (D33B′), R_{D372} to R_{D375} are as defined in the above formula (D33B).

In one embodiment, at least one of R_{D371} to R_{D375} is
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,

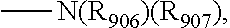

or
a substituted or unsubstituted aryl group having 6 to 50 ring carbon atoms.

In one embodiment, R_{D372} is
a hydrogen atom,
a substituted or unsubstituted alkyl group having 1 to 50 carbon atoms,

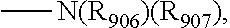

or
a substituted or unsubstituted aryl group having 6 to 50 ring carbon atoms, and
R_{D371} and R_{D373} to R_{D375} are independently
a substituted or unsubstituted alkyl group having 1 to 50 carbon atoms, —N(R₉₀₆)(R₉₀₇), or

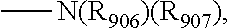

or
a substituted or unsubstituted aryl group having 6 to 50 ring carbon atoms.

In one embodiment, the compound represented by the formula (D33) is a compound represented by the following formula (D33C).

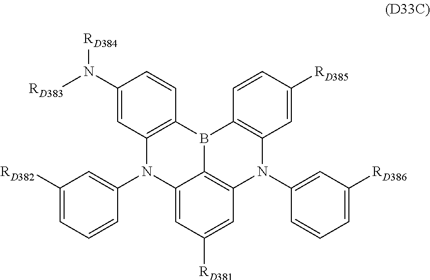

In the formula (D33C),
R_{D381} and R_{D382} are independently
a hydrogen atom,
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms, or
a substituted or unsubstituted aryl group having 6 to 50 ring carbon atoms, and
R_{D383} to R_{D386} are independently
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms, or
a substituted or unsubstituted aryl group having 6 to 50 ring carbon atoms.

In one embodiment, the compound represented by the formula (D33) is a compound represented by the following formula (D33C′).

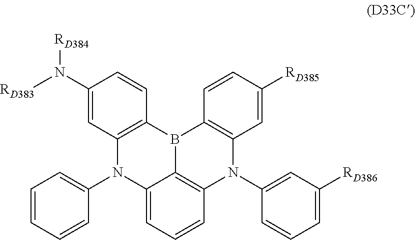

In the formula (D33C′), R_{D383} to R_{D386} are as defined in the above formula (D33C).

In one embodiment, R_{D381} to R_{D386} are independently
a substituted or unsubstituted alkyl group having 1 to 50 carbon atoms, or
a substituted or unsubstituted aryl group having 6 to 50 ring carbon atoms.

In one embodiment, R_{D381} to R_{D386} are independently a substituted or unsubstituted aryl group having 6 to 50 ring carbon atoms.

The compound represented by the formula (D3) can produced, first, by producing an intermediate by bonding the a ring, the b ring, and the c ring with first linking groups (a group including N—R_{D301} and a group including N—R_{D302}) (first reaction), and subsequently by producing a final product by bonding the a ring, the b ring, and the c ring with a second linking group (a group containing a boron atom) (second reaction). In the first reaction, an amination reaction such as Buchwald-Hartwig reaction can be applied. In the second reaction, Tandem Hetero-Friedel-Crafts Reactions or the like can be applied.

The compound represented by the formula (D3) can be synthesized by using a known reaction or raw material suited for an intended product.

Specific examples of the compound represented by the formula (D3) include the following compounds. These are merely examples, and the compound represented by the formula (D3) is not limited to the following specific examples.

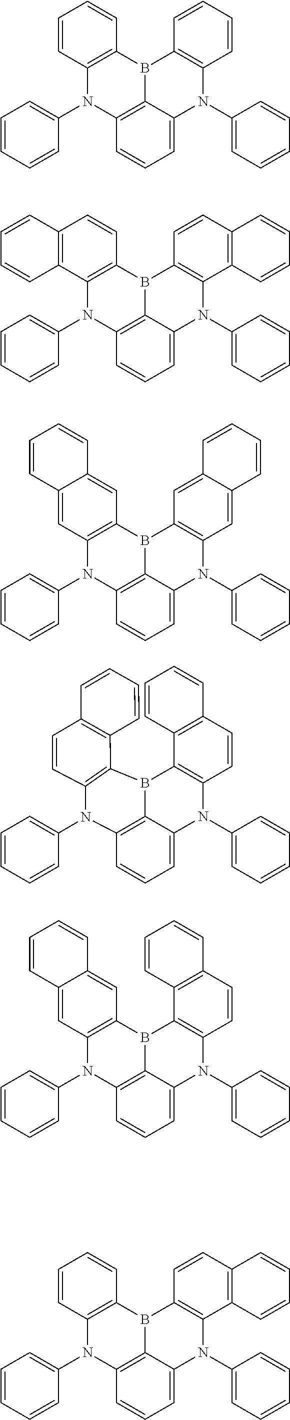

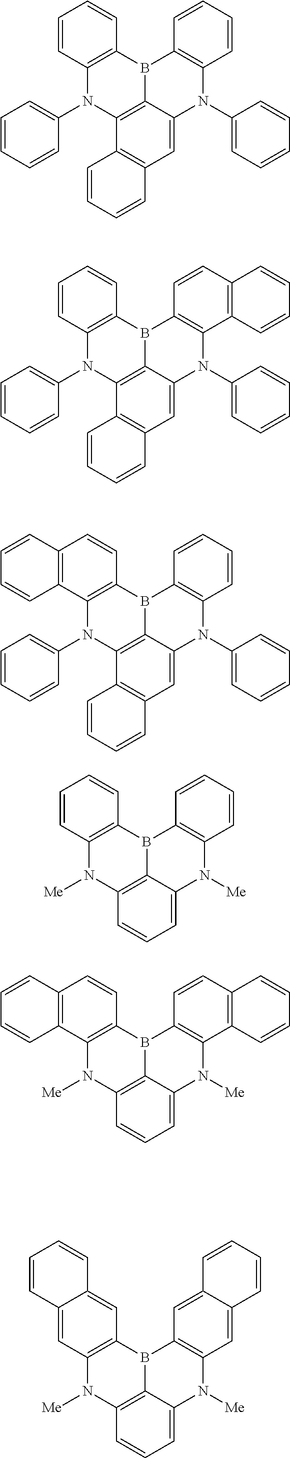

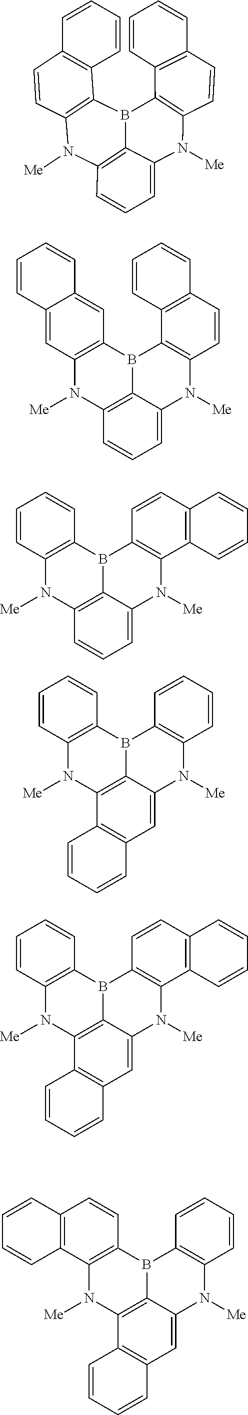

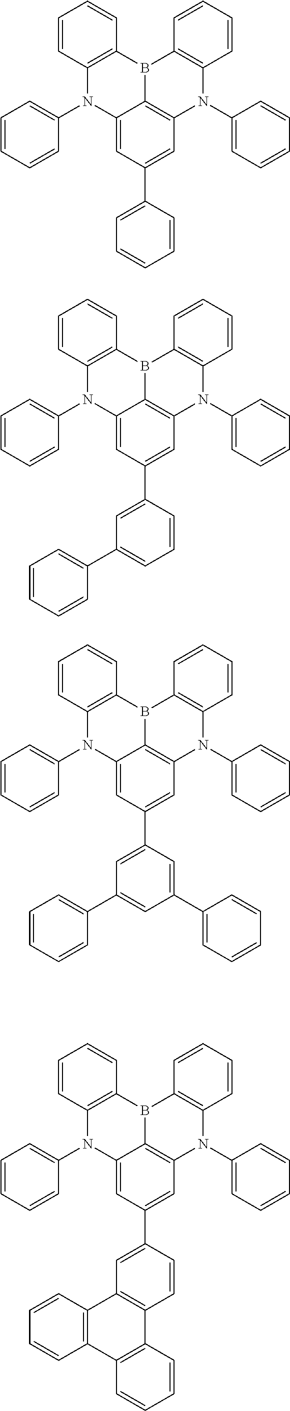

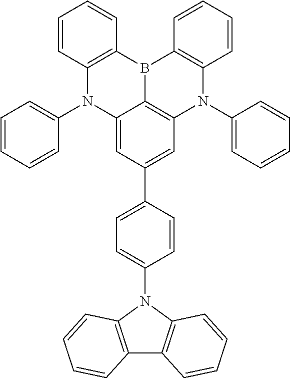 [SMILES: c1ccc(N2c3ccccc3B3c4ccccc4N(c4ccccc4)c4cc(-c5ccc(-n6c7ccccc7c7ccccc76)cc5)cc2c43)cc1]

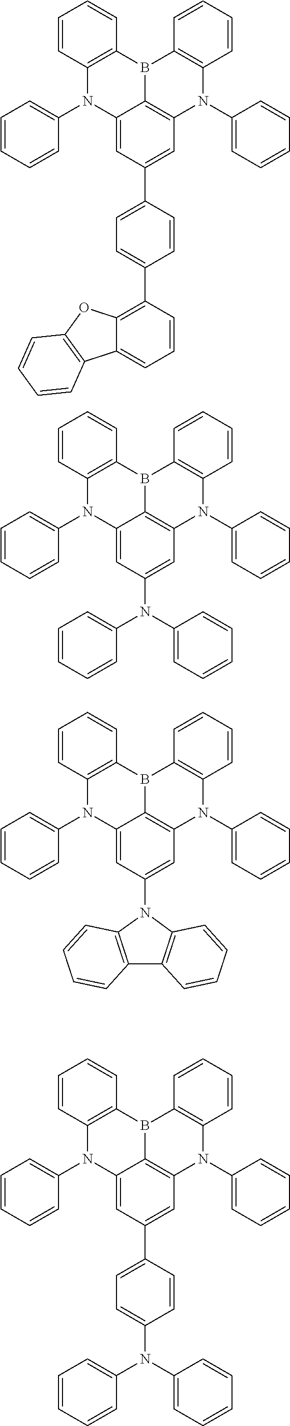

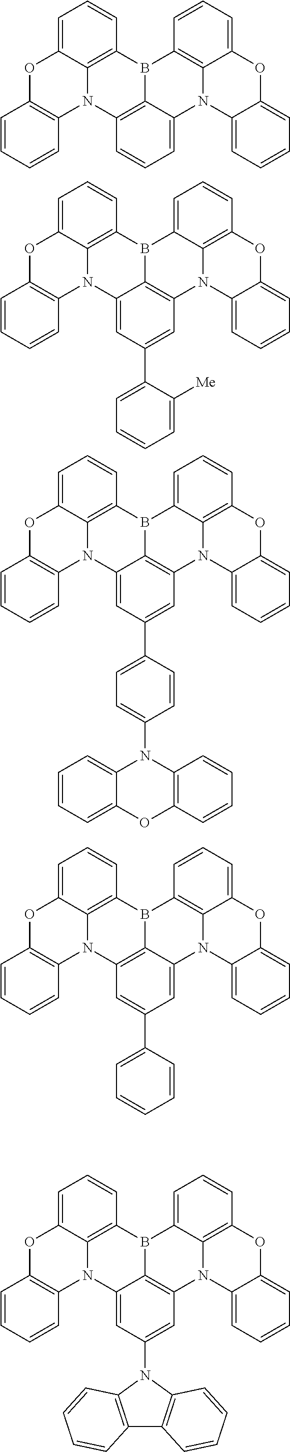

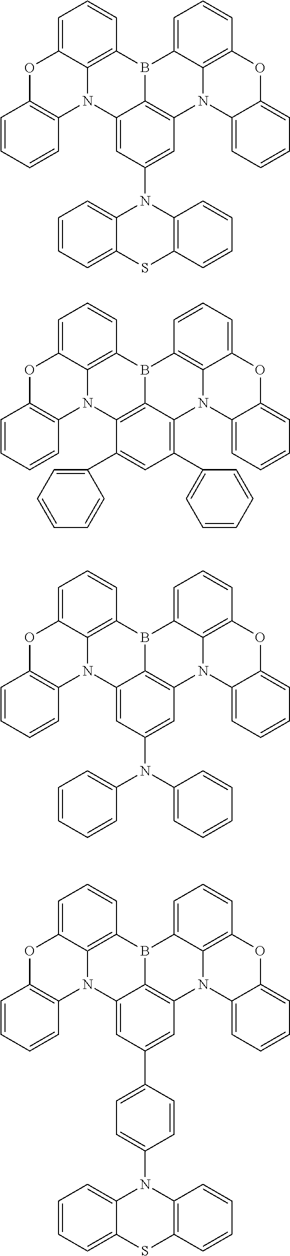

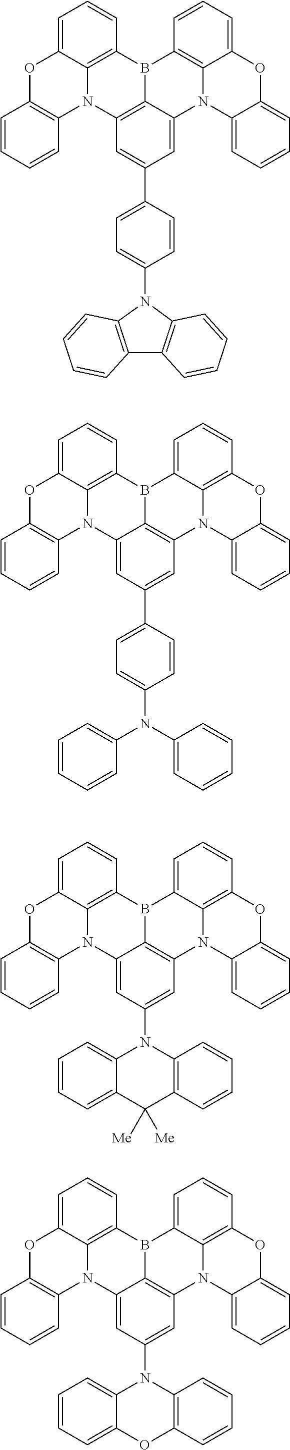 [SMILES: c1ccc2c(c1)Oc1cccc3c1N2c1cc(-c2ccc(-n4c5ccccc5c5ccccc54)cc2)cc2c1B3c1cccc3c1N2c1ccccc1O3 ; c1ccc(N(c2ccccc2)c2ccc(-c3cc4c5c(c3)N3c6ccccc6Oc6cccc(c63)B5c3cccc5c3N4c3ccccc3O5)cc2)cc1 ; CC1(C)c2ccccc2N(c2cc3c4c(c2)N2c5ccccc5Oc5cccc(c52)B4c2cccc4c2N3c2ccccc2O4)c2ccccc21 ; c1ccc2c(c1)Oc1ccccc1N2c1cc2c3c(c1)N1c4ccccc4Oc4cccc(c41)B3c1cccc3c1N2c1ccccc1O3]

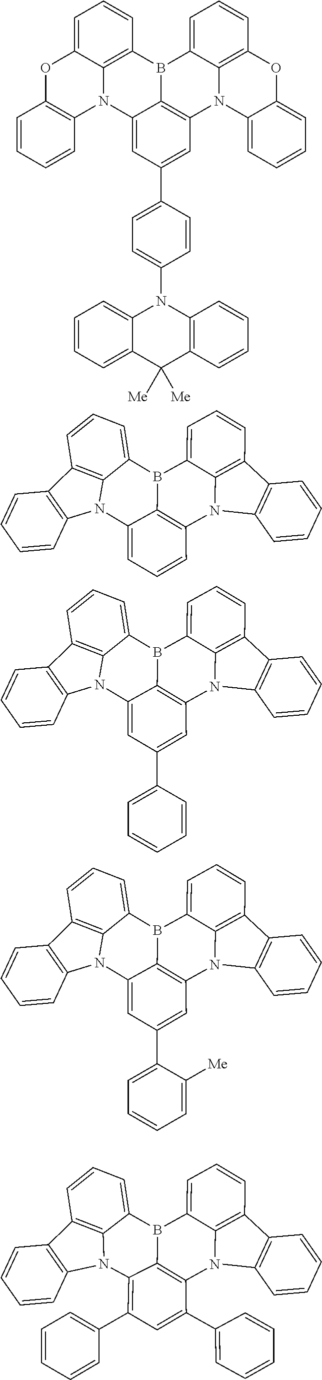

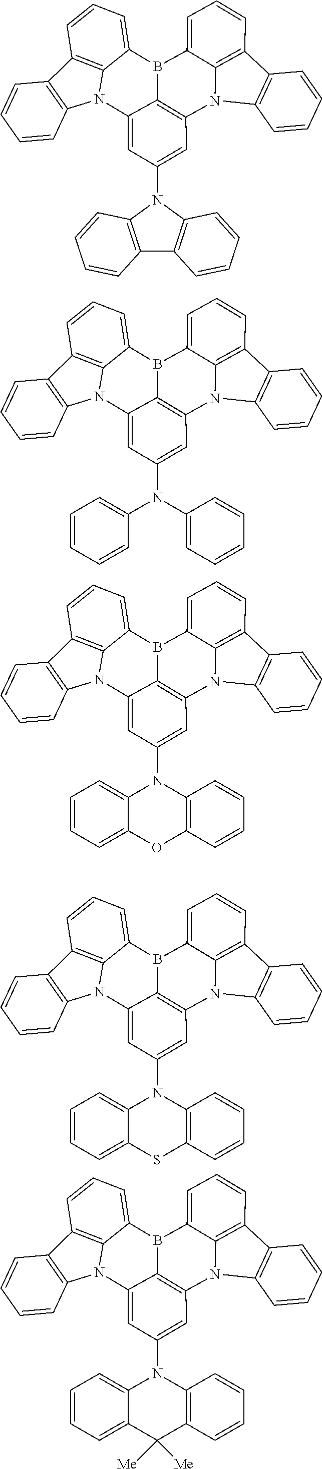

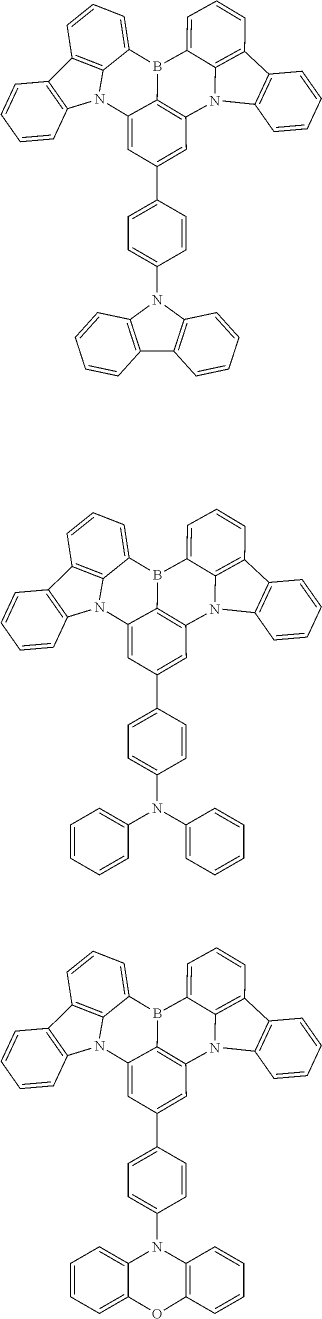 [SMILES: c1ccc2c(c1)c1ccccc1n2-c1ccc(-c2cc3c4c(c2)-n2c5ccccc5c5cccc(c52)B4c2cccc4c5ccccc5n-3c24)cc1 ; c1ccc(N(c2ccccc2)c2ccc(-c3cc4c5c(c3)-n3c6ccccc6c6cccc(c63)B5c3cccc5c6ccccc6n-4c35)cc2)cc1 ; c1ccc2c(c1)Oc1ccccc1N2c1ccc(-c2cc3c4c(c2)-n2c5ccccc5c5cccc(c52)B4c2cccc4c5ccccc5n-3c24)cc1]

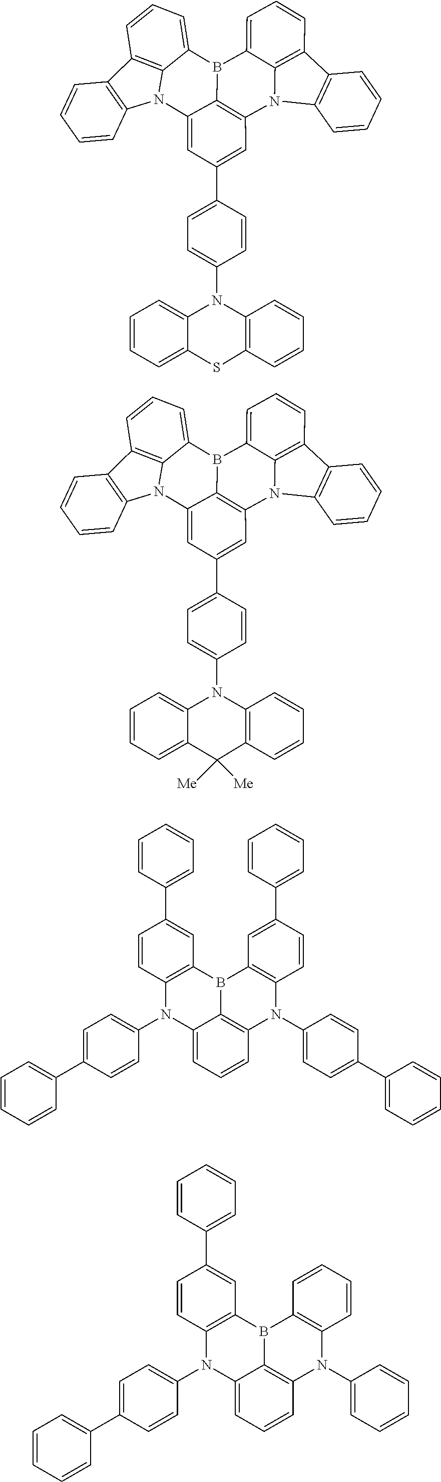

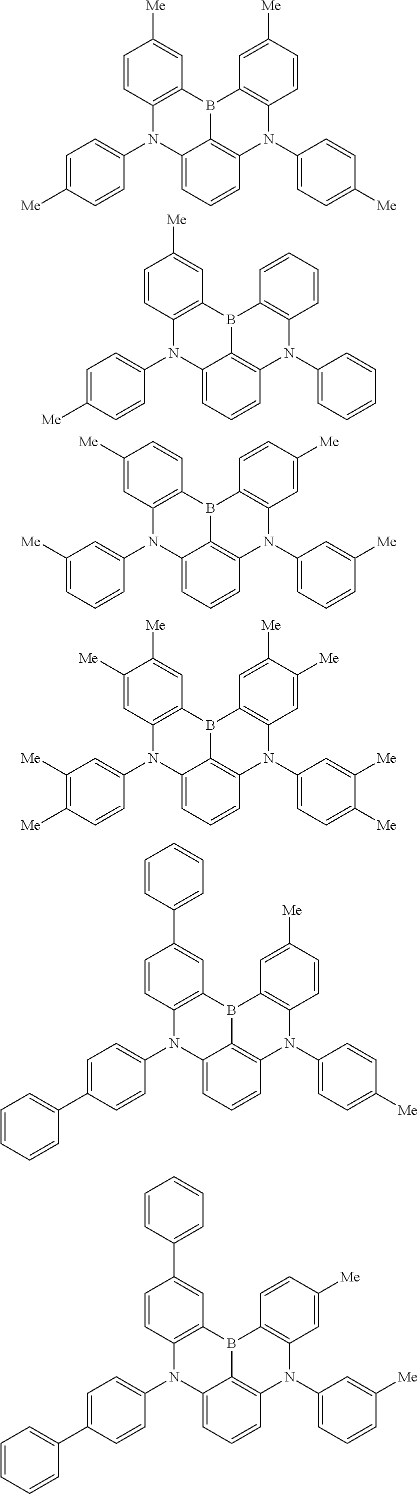

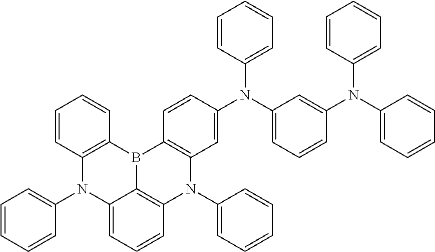 [SMILES: c1ccc(N(c2ccccc2)c2cccc(N(c3ccccc3)c3ccc4c(c3)N(c3ccccc3)c3cccc5c3B4c3ccccc3N5c3ccccc3)c2)cc1]

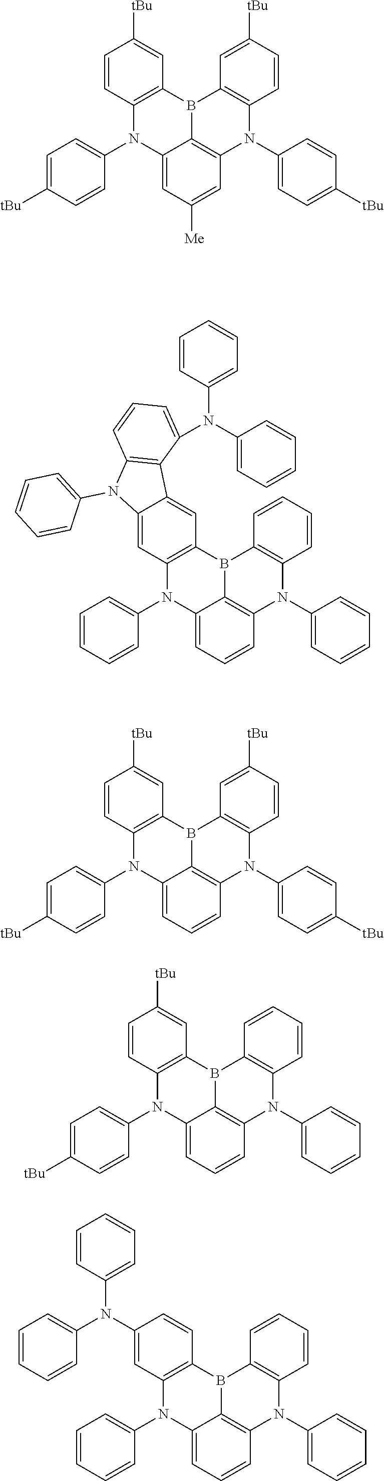

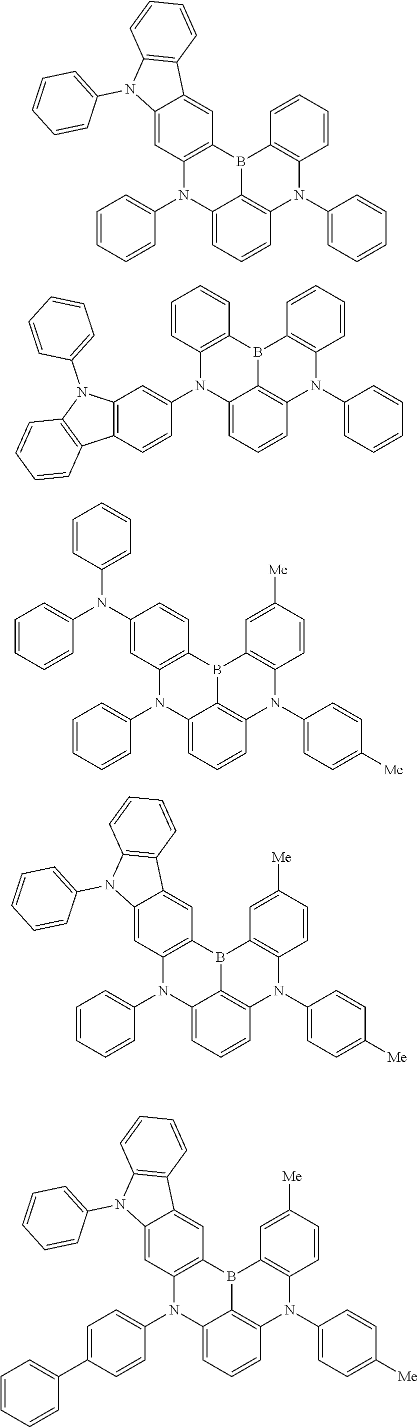

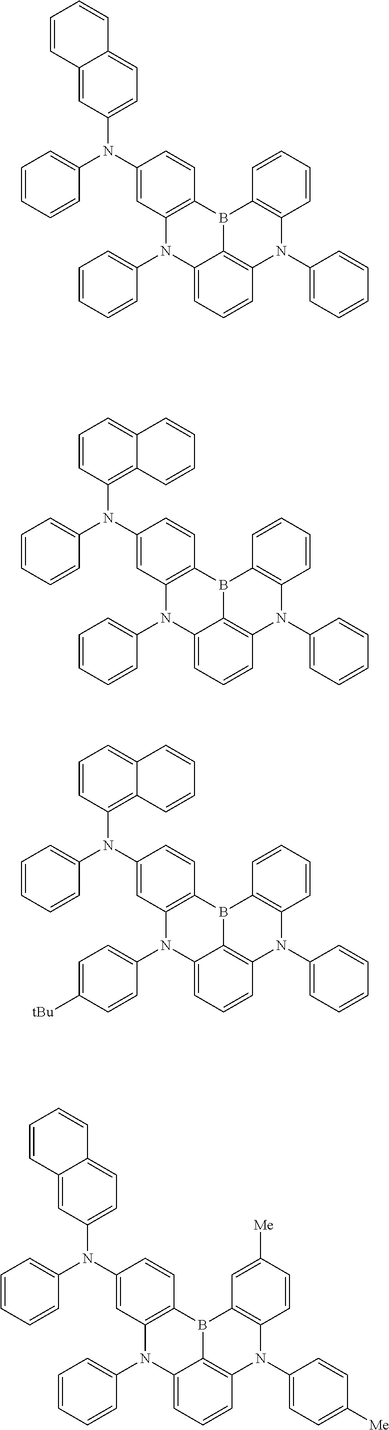 [SMILES: c1ccc(N(c2ccc3c(c2)N(c2ccccc2)c2cccc4c2B3c2ccccc2N4c2ccccc2)c2ccc3ccccc3c2)cc1 ; c1ccc(N2c3ccccc3B3c4ccc(N(c5ccccc5)c5cccc6ccccc56)cc4N(c4ccccc4)c4cccc2c43)cc1 ; CC(C)(C)c1ccc(N2c3cc(N(c4ccccc4)c4cccc5ccccc45)ccc3B3c4ccccc4N(c4ccccc4)c4cccc2c43)cc1 ; Cc1ccc(N2c3ccc(C)cc3B3c4ccc(N(c5ccccc5)c5ccc6ccccc6c5)cc4N(c4ccccc4)c4cccc2c43)cc1]

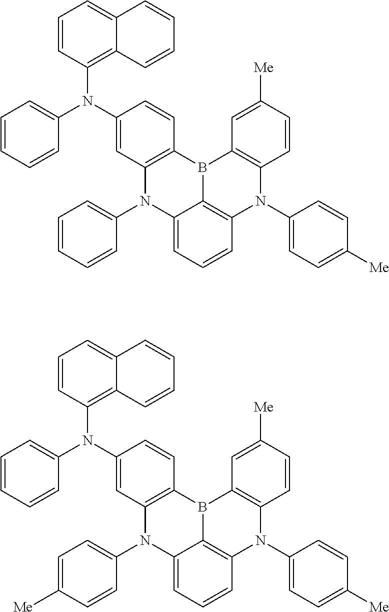 [SMILES: Cc1ccc(N2c3ccc(C)cc3B3c4ccc(N(c5ccccc5)c5cccc6ccccc56)cc4N(c4ccccc4)c4cccc2c43)cc1 ; Cc1ccc(N2c3ccc(C)cc3B3c4ccc(N(c5ccccc5)c5cccc6ccccc56)cc4N(c4ccc(C)cc4)c4cccc2c43)cc1]

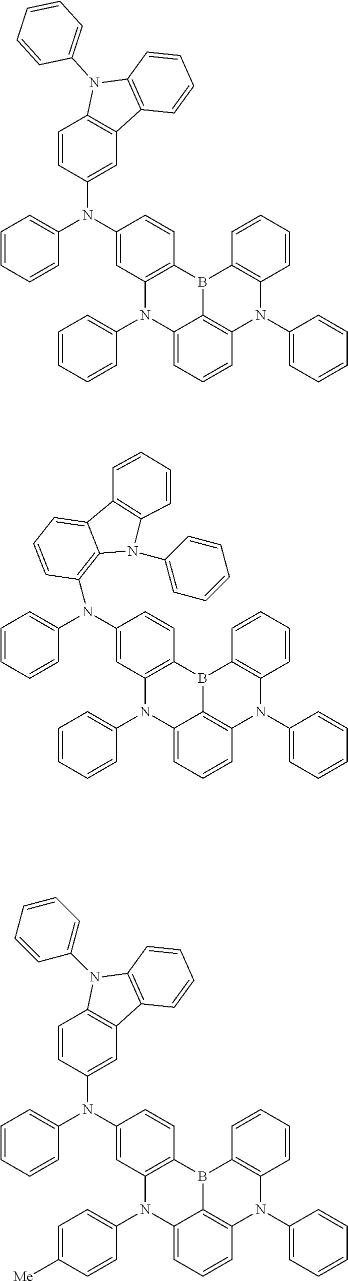 [SMILES: c1ccc(N(c2ccc3c(c2)N(c2ccccc2)c2cccc4c2B3c2ccccc2N4c2ccccc2)c2ccc3c(c2)c2ccccc2n3-c2ccccc2)cc1 ; c1ccc(N2c3ccccc3B3c4ccc(N(c5ccccc5)c5cccc6c7ccccc7n(-c7ccccc7)c56)cc4N(c4ccccc4)c4cccc2c43)cc1 ; Cc1ccc(N2c3cc(N(c4ccccc4)c4ccc5c(c4)c4ccccc4n5-c4ccccc4)ccc3B3c4ccccc4N(c4ccccc4)c4cccc2c43)cc1]

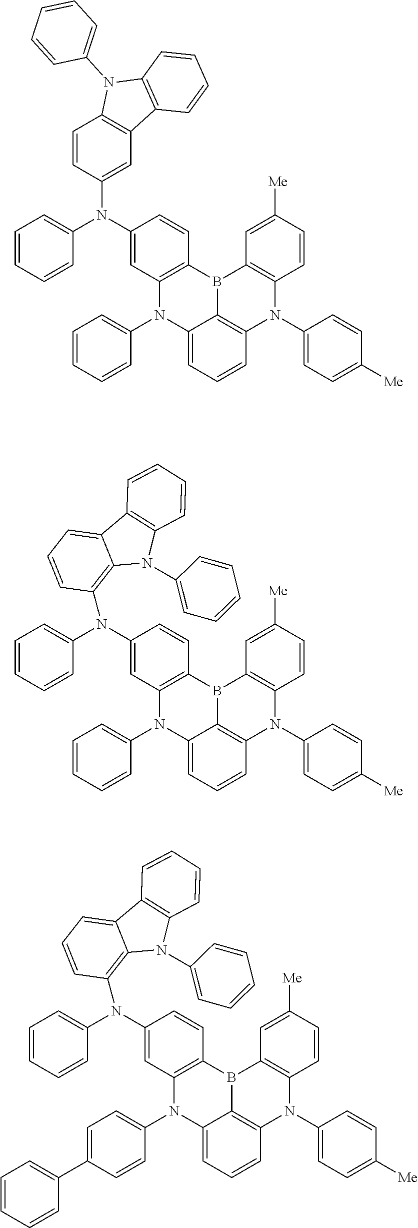 [SMILES: Cc1ccc(N2c3ccc(C)cc3B3c4ccc(N(c5ccccc5)c5ccc6c(c5)c5ccccc5n6-c5ccccc5)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccc(-c5ccccc5)cc4)c4cccc2c43)cc1]

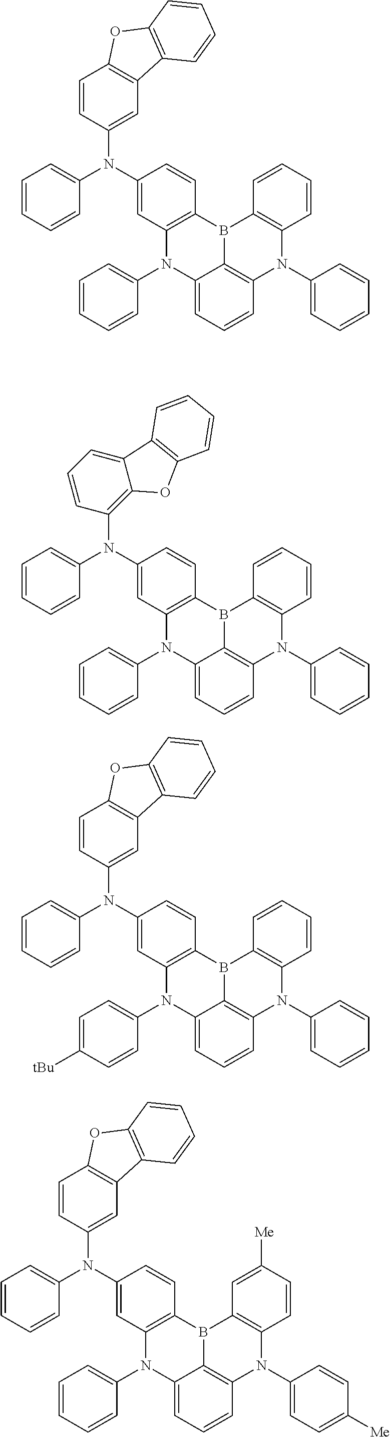

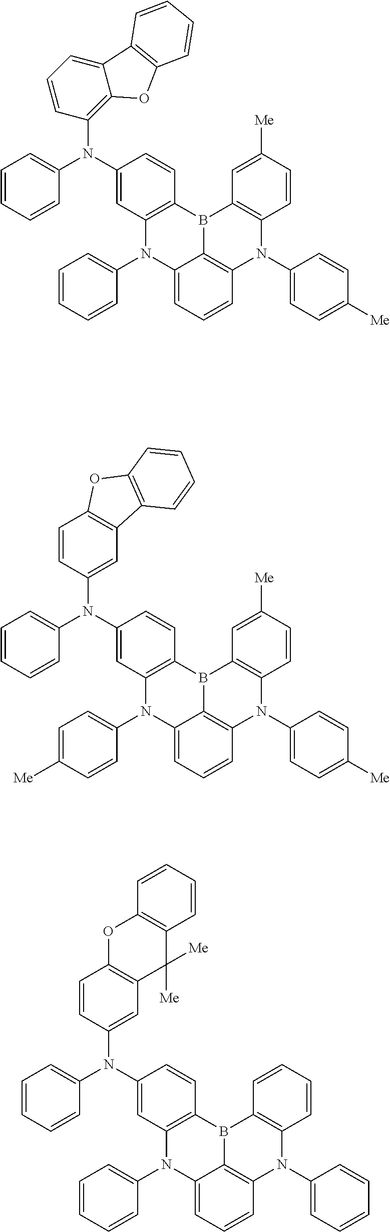 [SMILES: Cc1ccc(N2c3ccc(C)cc3B3c4ccc(N(c5ccccc5)c5cccc6c5oc5ccccc56)cc4N(c4ccccc4)c4cccc2c43)cc1 ; Cc1ccc(N2c3ccc(C)cc3B3c4ccc(N(c5ccccc5)c5ccc6oc7ccccc7c6c5)cc4N(c4ccc(C)cc4)c4cccc2c43)cc1 ; CC1(C)c2ccccc2Oc2ccc(N(c3ccccc3)c3ccc4c(c3)N(c3ccccc3)c3cccc5c3B4c3ccccc3N5c3ccccc3)cc21]

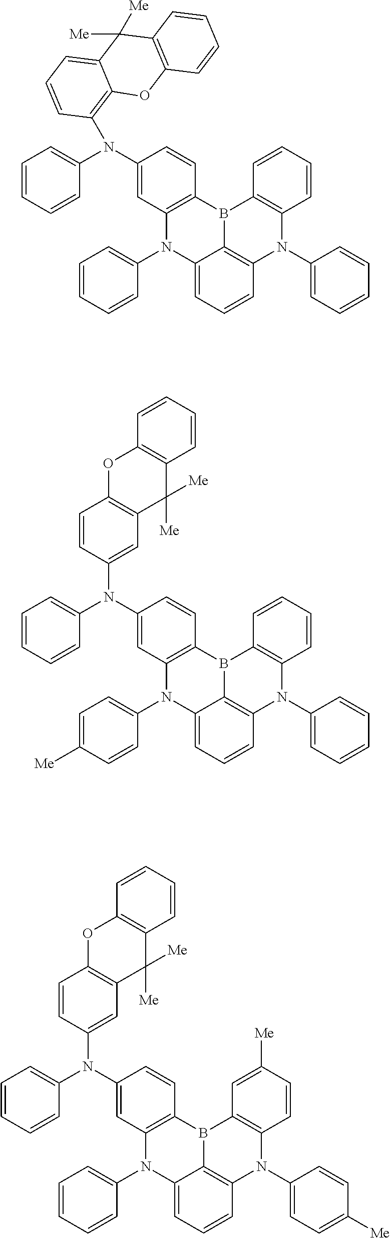 [SMILES: CC1(C)c2ccccc2Oc2c(N(c3ccccc3)c3ccc4c(c3)N(c3ccccc3)c3cccc5c3B4c3ccccc3N5c3ccccc3)cccc21 ; Cc1ccc(N2c3cc(N(c4ccccc4)c4ccc5c(c4)C(C)(C)c4ccccc4O5)ccc3B3c4ccccc4N(c4ccccc4)c4cccc2c43)cc1 ; Cc1ccc(N2c3ccc(C)cc3B3c4ccc(N(c5ccccc5)c5ccc6c(c5)C(C)(C)c5ccccc5O6)cc4N(c4ccccc4)c4cccc2c43)cc1]

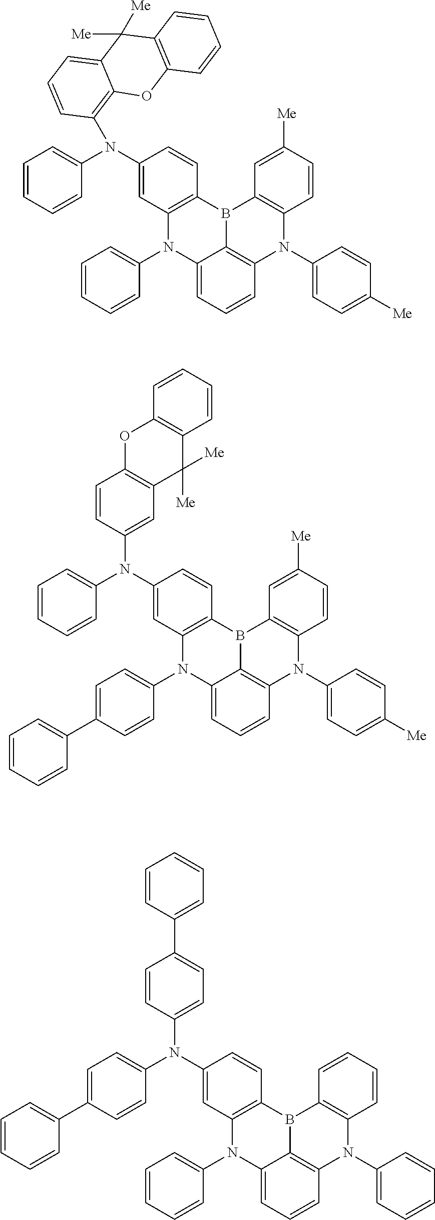 [SMILES: Cc1ccc(N2c3ccc(C)cc3B3c4ccc(N(c5ccccc5)c5cccc6c5Oc5ccccc5C6(C)C)cc4N(c4ccccc4)c4cccc2c43)cc1 ; Cc1ccc(N2c3ccc(C)cc3B3c4ccc(N(c5ccccc5)c5ccc6c(c5)C(C)(C)c5ccccc5O6)cc4N(c4ccc(-c5ccccc5)cc4)c4cccc2c43)cc1 ; c1ccc(-c2ccc(N(c3ccc(-c4ccccc4)cc3)c3ccc4c(c3)N(c3ccccc3)c3cccc5c3B4c3ccccc3N5c3ccccc3)cc2)cc1]

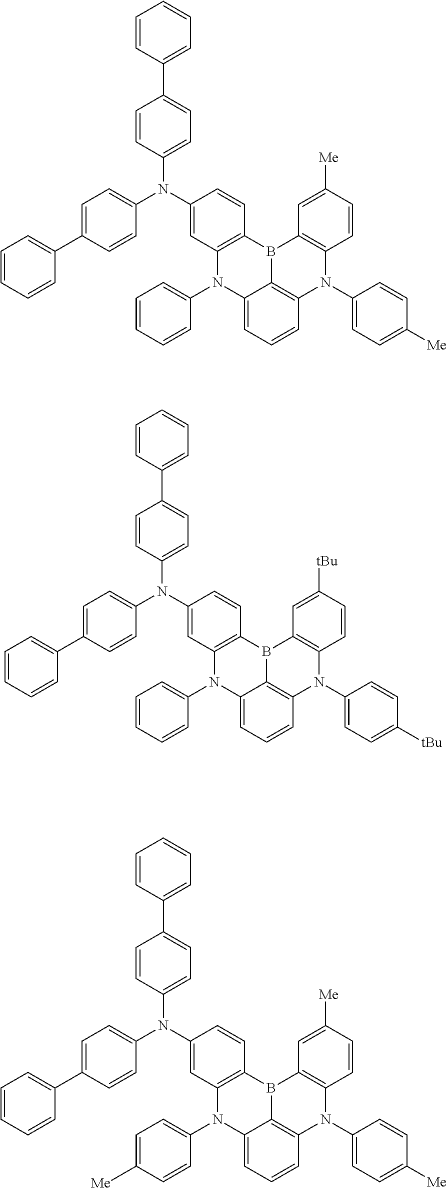 [SMILES: Cc1ccc(N2c3ccc(C)cc3B3c4ccc(N(c5ccc(-c6ccccc6)cc5)c5ccc(-c6ccccc6)cc5)cc4N(c4ccccc4)c4cccc2c43)cc1 ; CC(C)(C)c1ccc(N2c3ccc(C(C)(C)C)cc3B3c4ccc(N(c5ccc(-c6ccccc6)cc5)c5ccc(-c6ccccc6)cc5)cc4N(c4ccccc4)c4cccc2c43)cc1 ; Cc1ccc(N2c3ccc(C)cc3B3c4ccc(N(c5ccc(-c6ccccc6)cc5)c5ccc(-c6ccccc6)cc5)cc4N(c4ccc(C)cc4)c4cccc2c43)cc1]

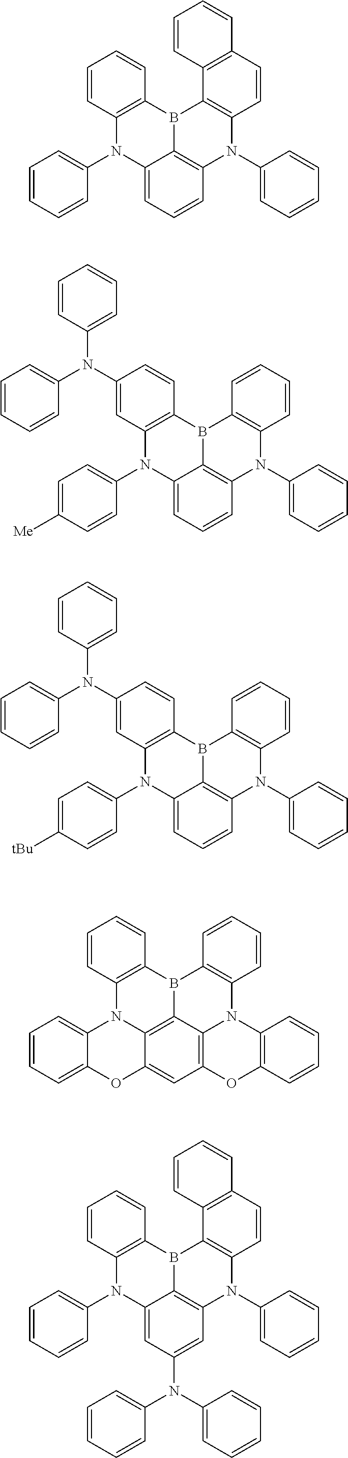 [SMILES: c1ccc(N2c3ccccc3B3c4c2cccc4N(c2ccccc2)c2ccc4ccccc4c23)cc1 ; Cc1ccc(N2c3cc(N(c4ccccc4)c4ccccc4)ccc3B3c4ccccc4N(c4ccccc4)c4cccc2c43)cc1 ; CC(C)(C)c1ccc(N2c3cc(N(c4ccccc4)c4ccccc4)ccc3B3c4ccccc4N(c4ccccc4)c4cccc2c43)cc1 ; c1ccc2c(c1)B1c3ccccc3-n3c4ccccc4oc4cc5oc6ccccc6n-2c5c1c43 ; c1ccc(N(c2ccccc2)c2cc3c4c(c2)N(c2ccccc2)c2ccc5ccccc5c2B4c2ccccc2N3c2ccccc2)cc1]

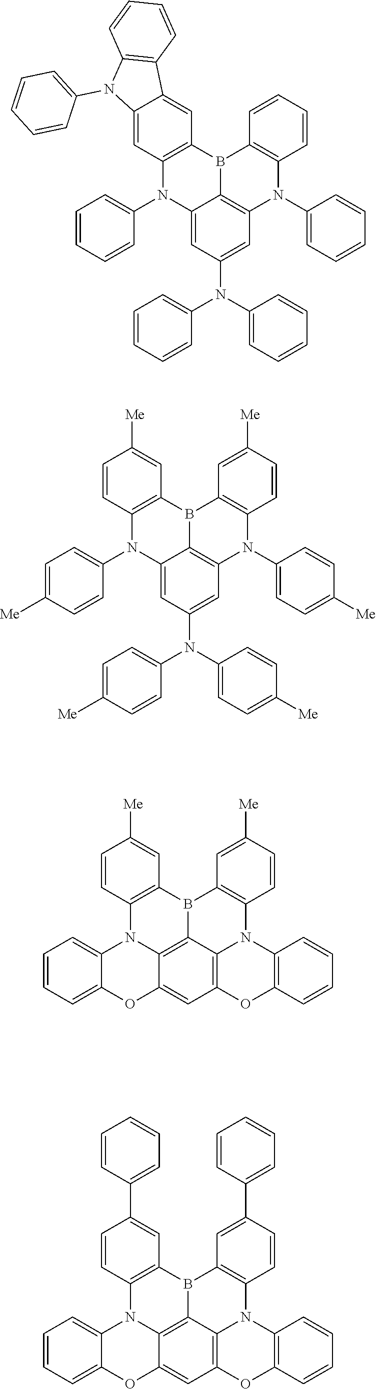 [SMILES: c1ccc(N(c2ccccc2)c2cc3c4c(c2)N(c2ccccc2)c2cc5c(cc2B4c2ccccc2N3c2ccccc2)c2ccccc2n5-c2ccccc2)cc1 ; Cc1ccc(N(c2ccc(C)cc2)c2cc3c4c(c2)N(c2ccc(C)cc2)c2ccc(C)cc2B4c2cc(C)ccc2N3c2ccc(C)cc2)cc1 ; Cc1ccc2c(c1)B1c3cc(C)ccc3-n3c4ccccc4oc4cc5oc6ccccc6n-2c5c1c43 ; c1ccc(-c2ccc3c(c2)B2c4cc(-c5ccccc5)ccc4-n4c5ccccc5oc5cc6oc7ccccc7n-3c6c2c54)cc1]

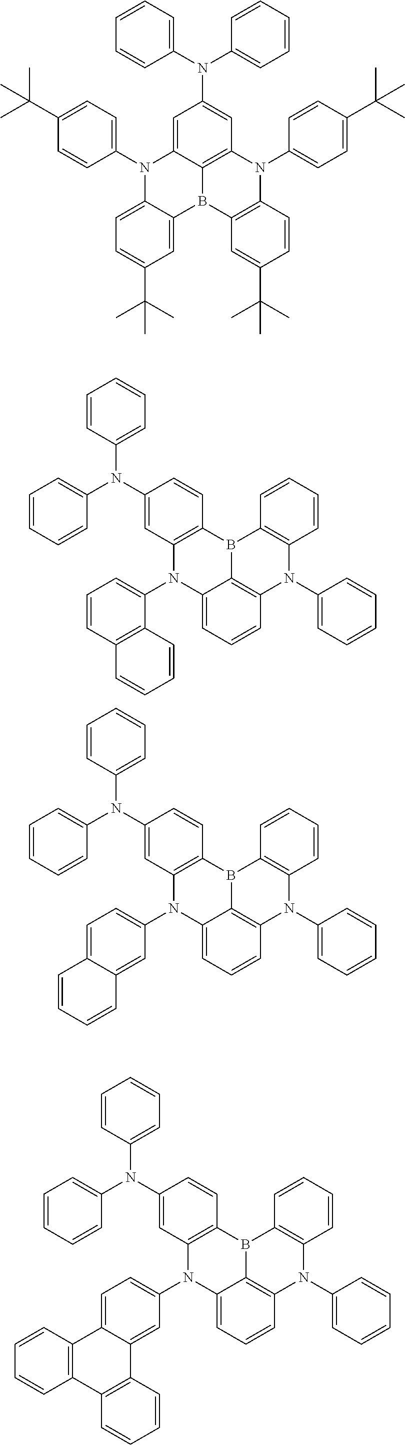

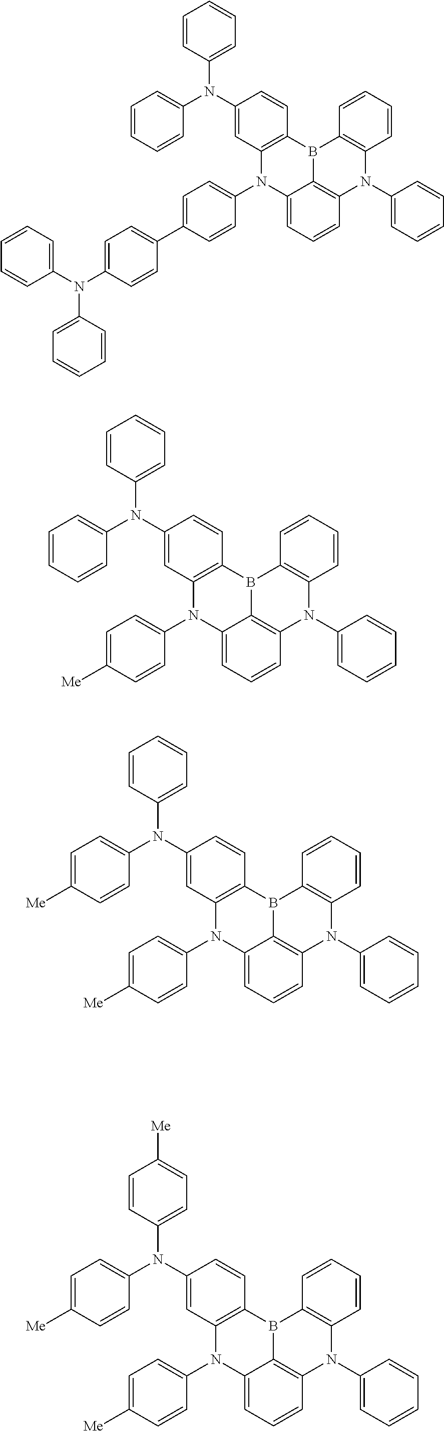 [SMILES: c1ccc(N(c2ccccc2)c2ccc(-c3ccc(N4c5cc(N(c6ccccc6)c6ccccc6)ccc5B5c6ccccc6N(c6ccccc6)c6cccc4c65)cc3)cc2)cc1 ; Cc1ccc(N2c3cc(N(c4ccccc4)c4ccccc4)ccc3B3c4ccccc4N(c4ccccc4)c4cccc2c43)cc1 ; Cc1ccc(N(c2ccccc2)c2ccc3c(c2)N(c2ccc(C)cc2)c2cccc4c2B3c2ccccc2N4c2ccccc2)cc1 ; Cc1ccc(N(c2ccc(C)cc2)c2ccc3c(c2)N(c2ccc(C)cc2)c2cccc4c2B3c2ccccc2N4c2ccccc2)cc1]

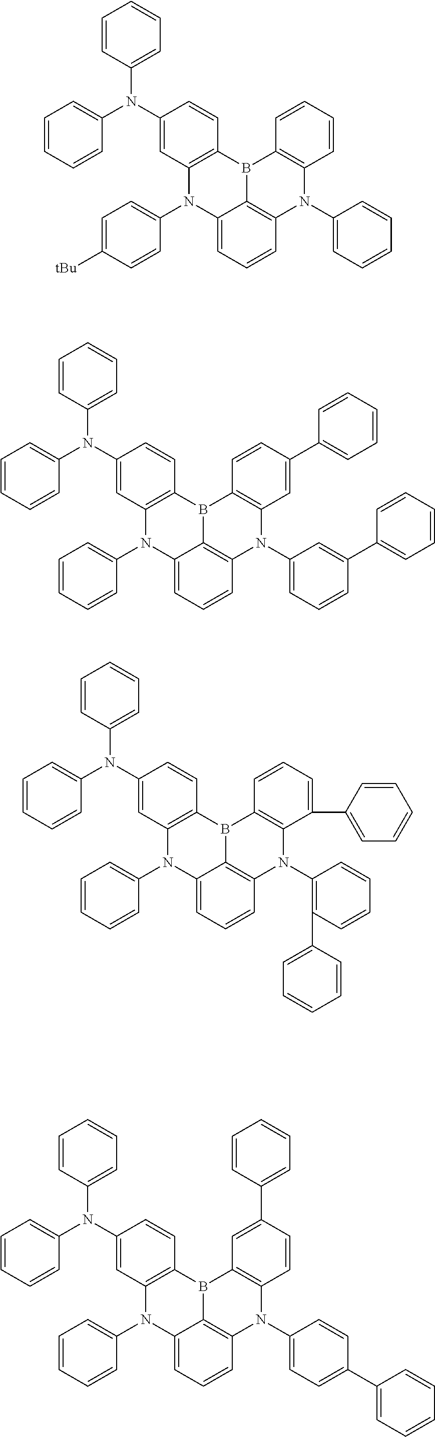 [SMILES: CC(C)(C)c1ccc(N2c3cc(N(c4ccccc4)c4ccccc4)ccc3B3c4ccccc4N(c4ccccc4)c4cccc2c43)cc1 ; c1ccc(-c2cccc(N3c4cc(-c5ccccc5)ccc4B4c5ccc(N(c6ccccc6)c6ccccc6)cc5N(c5ccccc5)c5cccc3c54)c2)cc1 ; c1ccc(-c2ccccc2N2c3cccc4c3B(c3ccc(N(c5ccccc5)c5ccccc5)cc3N4c3ccccc3)c3cccc(-c4ccccc4)c32)cc1 ; c1ccc(-c2ccc(N3c4ccc(-c5ccccc5)cc4B4c5ccc(N(c6ccccc6)c6ccccc6)cc5N(c5ccccc5)c5cccc3c54)cc2)cc1]

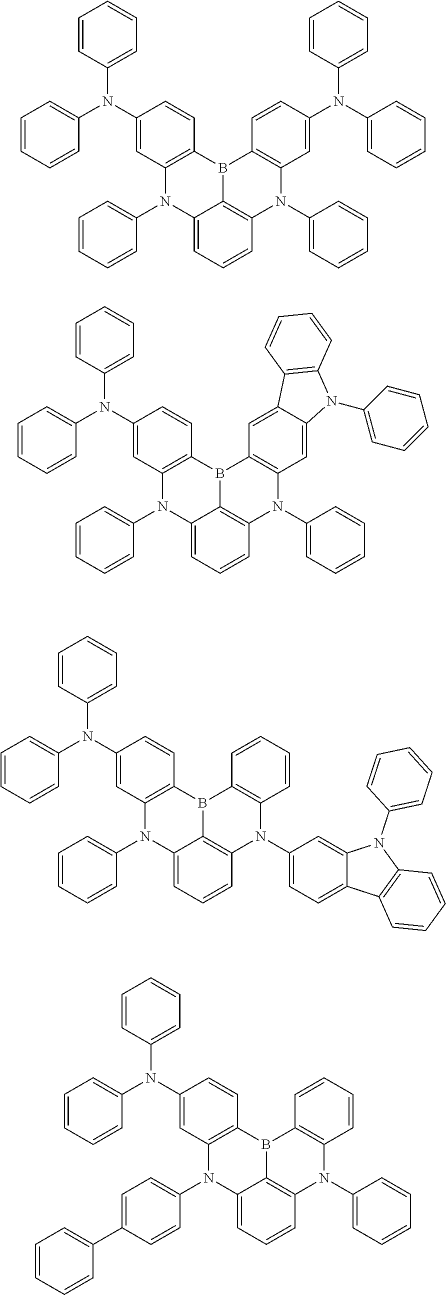

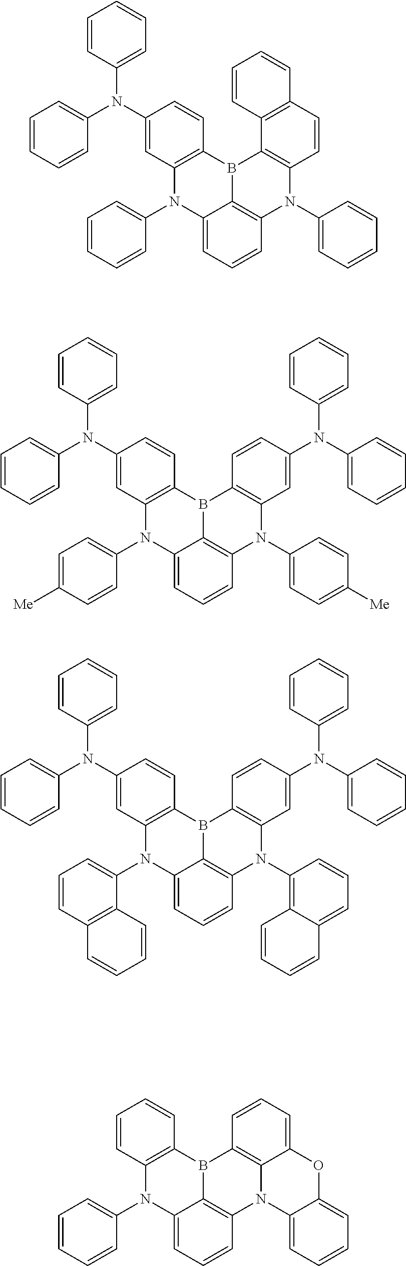 [SMILES: c1ccc(N(c2ccccc2)c2ccc3c(c2)N(c2ccccc2)c2cccc4c2B3c2c(ccc3ccccc23)N4c2ccccc2)cc1 ; Cc1ccc(N2c3cc(N(c4ccccc4)c4ccccc4)ccc3B3c4ccc(N(c5ccccc5)c5ccccc5)cc4N(c4ccc(C)cc4)c4cccc2c43)cc1 ; c1ccc(N(c2ccccc2)c2ccc3c(c2)N(c2cccc4ccccc24)c2cccc4c2B3c2ccc(N(c3ccccc3)c3ccccc3)cc2N4c2cccc3ccccc23)cc1 ; c1ccc(N2c3ccccc3B3c4cccc5c4N(c4ccccc4O5)c4cccc2c43)cc1]

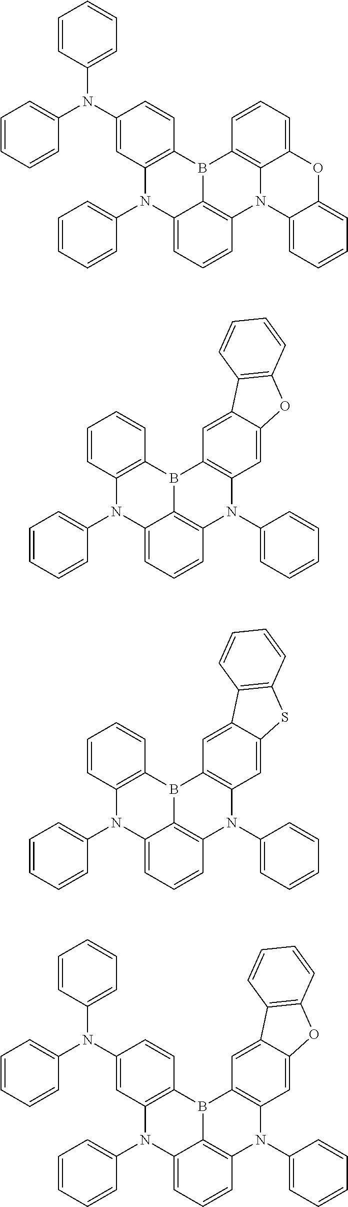 [SMILES: c1ccc(N(c2ccccc2)c2ccc3c(c2)N(c2ccccc2)c2cccc4c2B3c2cccc3c2N4c2ccccc2O3)cc1 ; c1ccc(N2c3ccccc3B3c4cc5c(cc4N(c4ccccc4)c4cccc2c43)oc2ccccc25)cc1 ; c1ccc(N2c3ccccc3B3c4cc5c(cc4N(c4ccccc4)c4cccc2c43)sc2ccccc25)cc1 ; c1ccc(N(c2ccccc2)c2ccc3c(c2)N(c2ccccc2)c2cccc4c2B3c2cc3c(cc2N4c2ccccc2)oc2ccccc23)cc1]

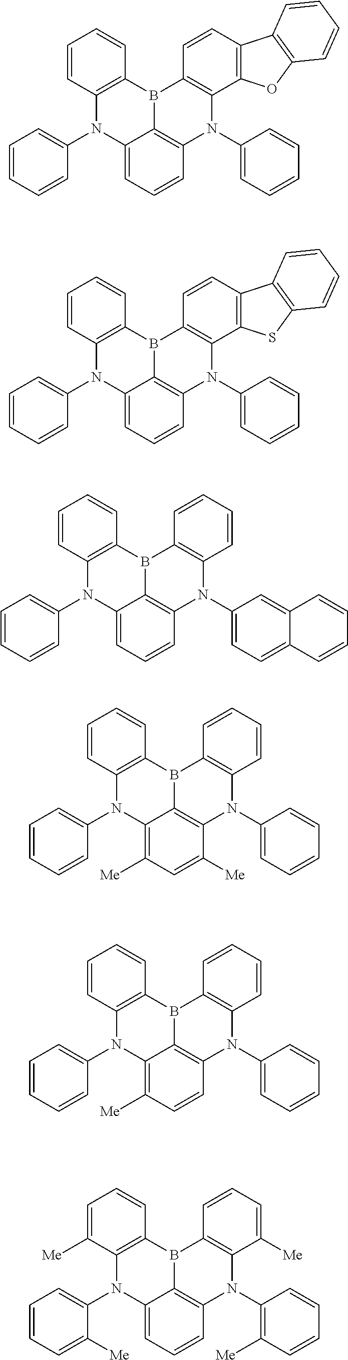 [SMILES: c1ccc(N2c3ccccc3B3c4ccc5c(oc6ccccc65)c4N(c4ccccc4)c4cccc2c43)cc1 ; c1ccc(N2c3ccccc3B3c4ccc5c(sc6ccccc65)c4N(c4ccccc4)c4cccc2c43)cc1 ; c1ccc(N2c3ccccc3B3c4ccccc4N(c4ccc5ccccc5c4)c4cccc2c43)cc1 ; Cc1cc(C)c2c3c1N(c1ccccc1)c1ccccc1B3c1ccccc1N2c1ccccc1 ; Cc1ccc2c3c1N(c1ccccc1)c1ccccc1B3c1ccccc1N2c1ccccc1 ; Cc1ccccc1N1c2cccc3c2B(c2cccc(C)c21)c1cccc(C)c1N3c1ccccc1C]

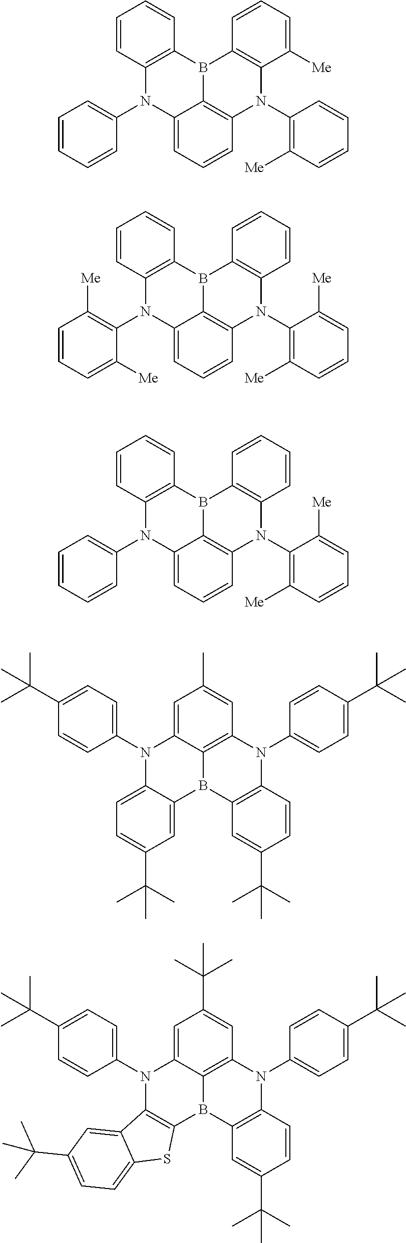

### (Compound Represented by Formula (D4))

The compound represented by the formula (D4) will be described.

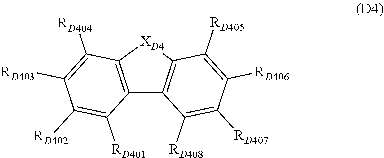

In the formula (D4),
at least one set of a set of R_{D401} and R_{D402}, a set of R_{D402} and R_{D403}, and a set of R_{D403} and R_{D404} forms a divalent group represented by the following formula (D42) by bonding with each other, and
at least one set of a set of R_{D405} and R_{D406}, a set of R_{D406} and R_{D407}, and a set of R_{D407} and R_{D408} forms a divalent group represented by the following formula (D43) by bonding with each other:

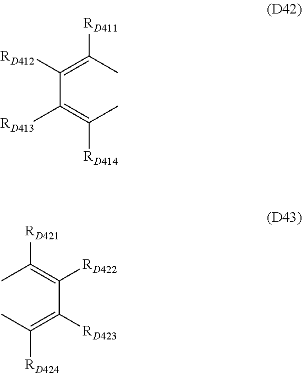

wherein at least one of R_{D401} to R_{D404} which do not form the divalent group represented by the formula (D42), and R_{D411} to R_{D414} is a monovalent group represented by the following formula (D44),
at least one of R_{D405} to R_{D408} which do not form the divalent group represented by the formula (D43), and R_{D421} to R_{D424} is a monovalent group represented by the following formula (D44),
X_{D4} is an oxygen atom, a sulfur atom, or NR_{D409}, and
R_{D401} to R_{D408} which do not form the divalent groups represented by the formula (D42) and the formula (D43) and which are not the monovalent group represented by the formula (D44), R_{D411} to R_{D414} and R_{D421} to R_{D424} which are not the monovalent group represented by the formula (D44), and R_{D409} are independently
a hydrogen atom,
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,

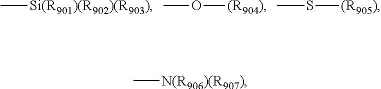

a halogen atom, a cyano group, a nitro group,
a substituted or unsubstituted aryl group having 6 to 50 ring carbon atoms, or
a substituted or unsubstituted heterocyclic group having 5 to 50 ring atoms:

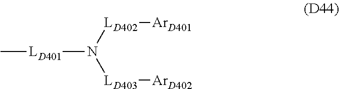

in the formula (D44),
Ar_{D401} and Ar_{D402} are independently
a substituted or unsubstituted aryl group having 6 to 50 ring carbon atoms, or
a substituted or unsubstituted monovalent heterocyclic group having 5 to 50 ring atoms,
L_{D401} to L_{D403} are independently
a single bond,
a substituted or unsubstituted arylene group having 6 to 30 ring carbon atoms,
a substituted or unsubstituted divalent heterocyclic group having 5 to 30 ring atoms, or
a divalent linking group formed by bonding two to four groups selected from the group consisting of a substituted or unsubstituted arylene group having 6 to 30 ring carbon atoms and a substituted or unsubstituted divalent heterocyclic group having 5 to 30 ring atoms, and
L_{D401} is bonded to the ring structure represented by the formula (D4), the group represented by the formula (D42), or the group represented by the formula (D43).

In the above formula (D4), the positions at which the divalent group represented by the formula (D42) and the divalent group represented by the formula (D43) are formed are not particularly limited, and the groups can be formed at any possible positions on R_{D401} to R_{D408}.

The compound represented by the formula (D4) can be synthesized by using a known reaction or raw material suited for an intended product.

Specific examples of the compound represented by the formula (D4) include, in addition to the compound described in WO 2014/104144 A1, the following compounds. These are merely examples, and the compound represented by the formula (D4) is not limited to the following specific examples.

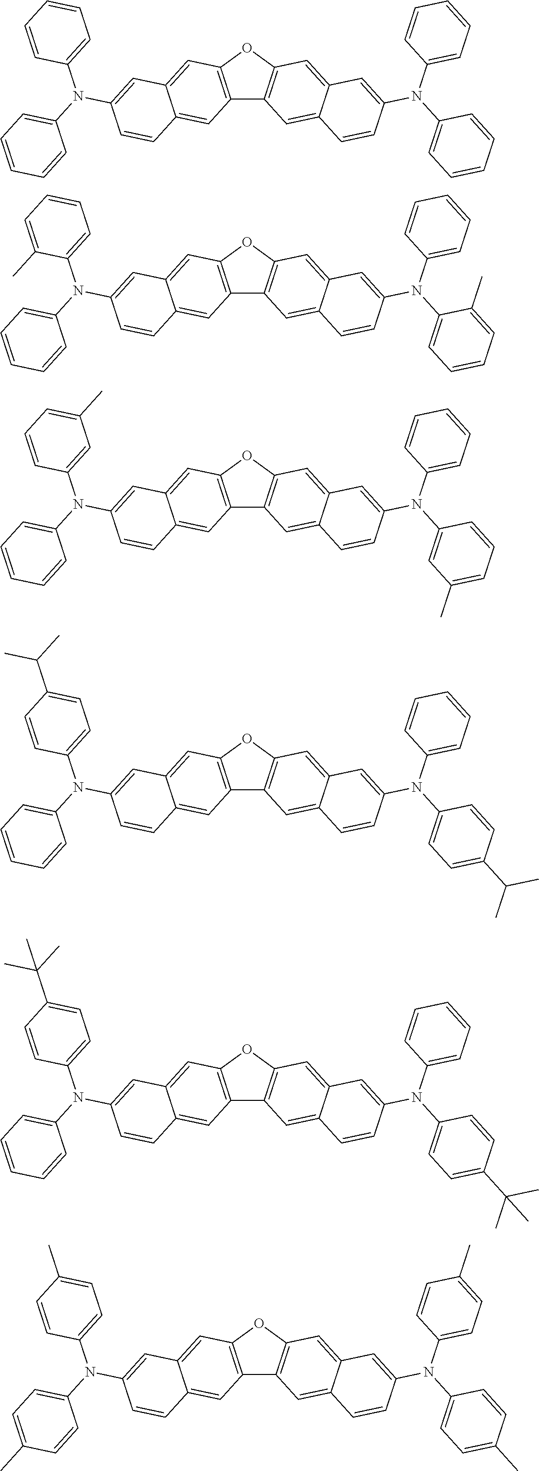

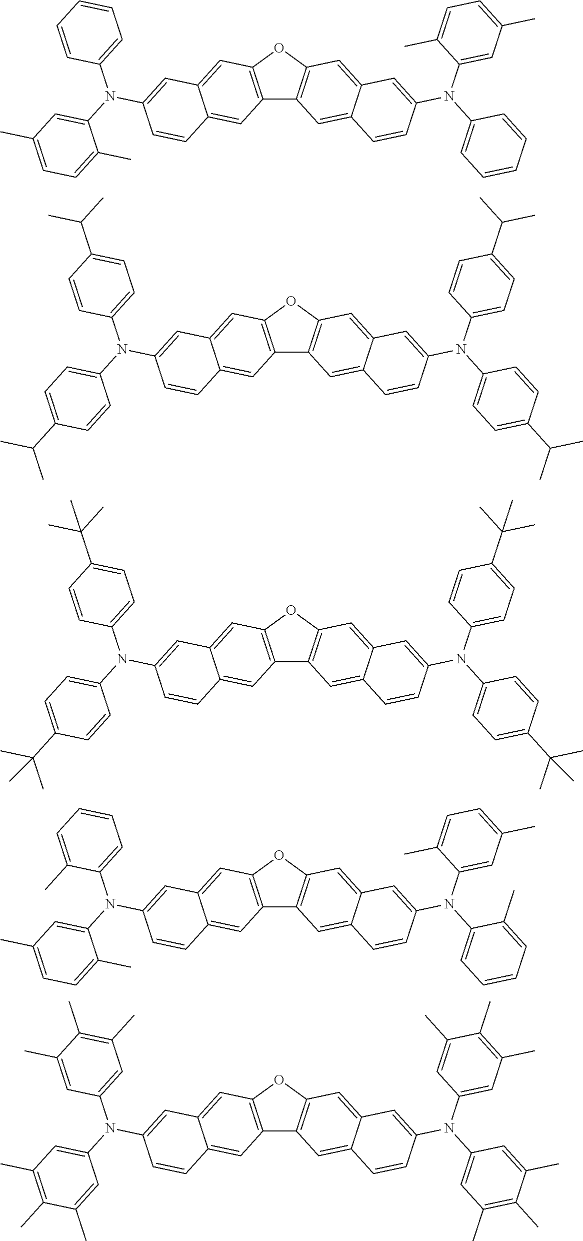

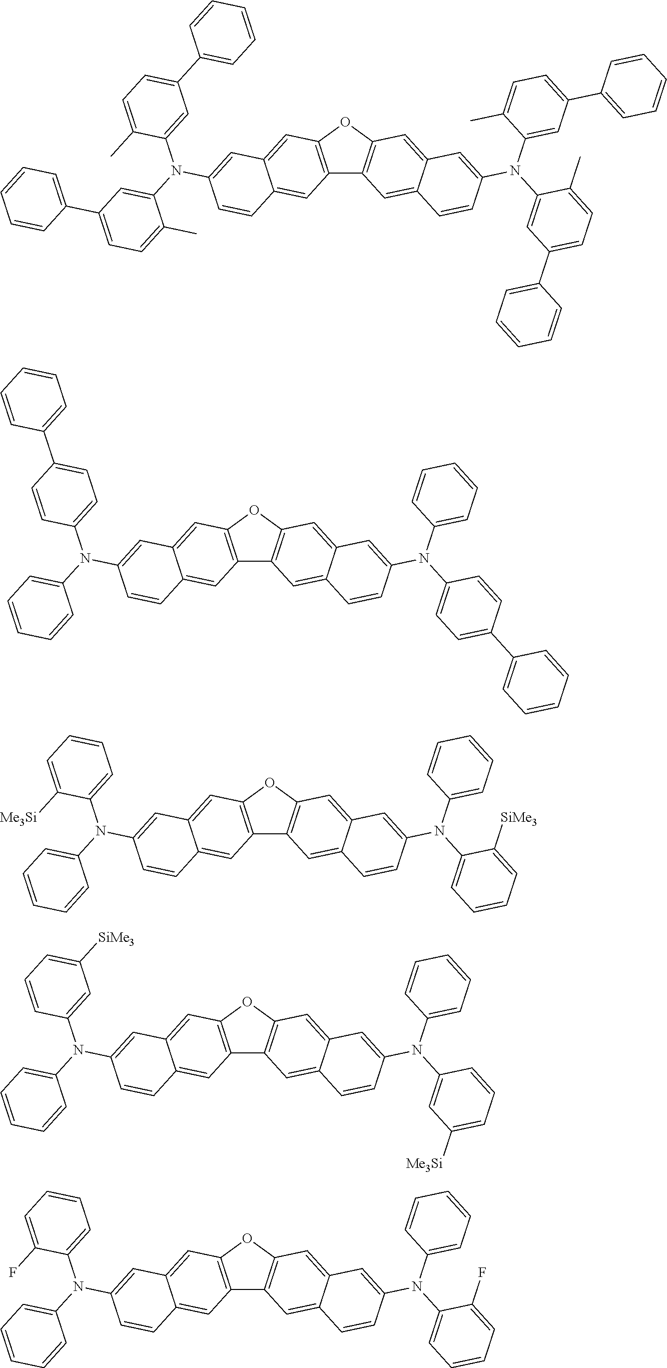

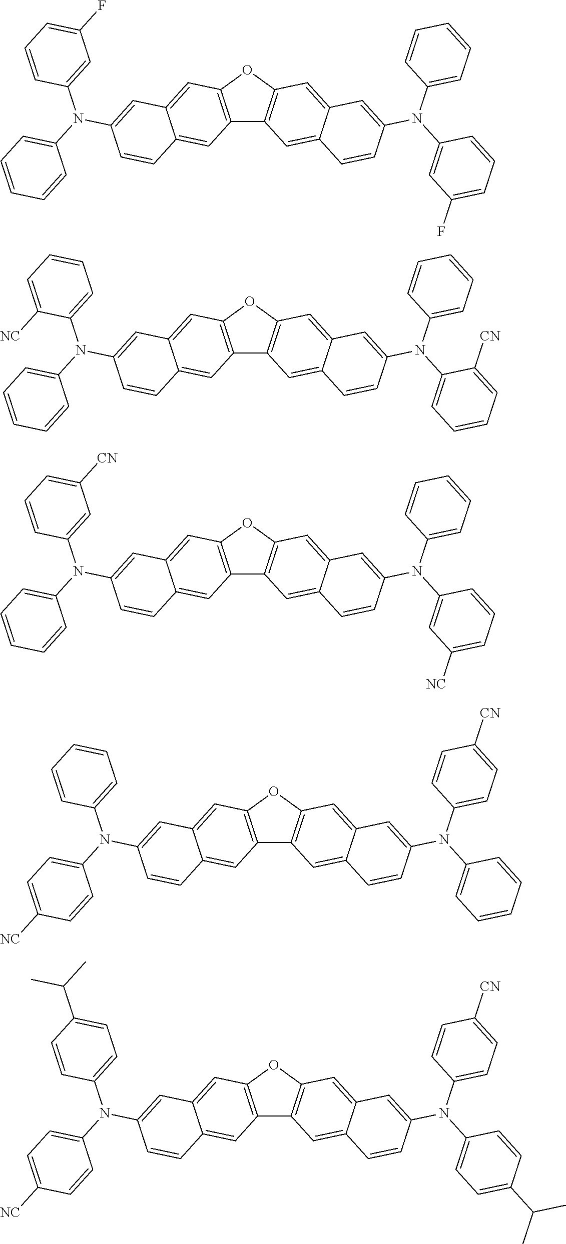

In addition to the compounds represented by the formula (D1), formula (D2), formula (D3), and formula (D4) described above, for example, the following compounds can be used as the second compound.

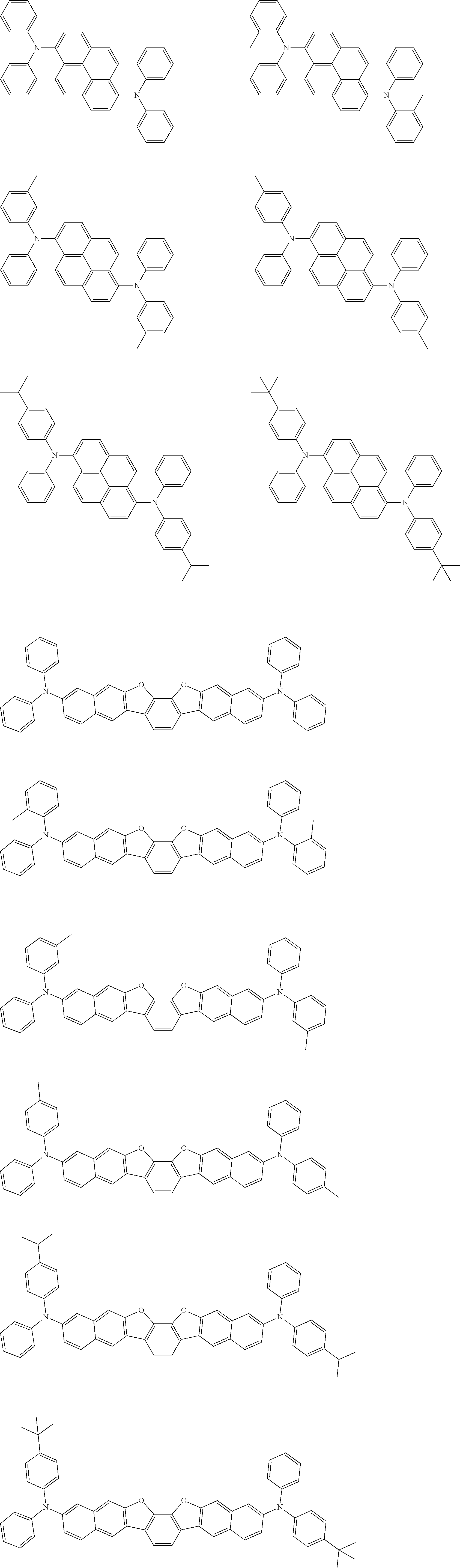

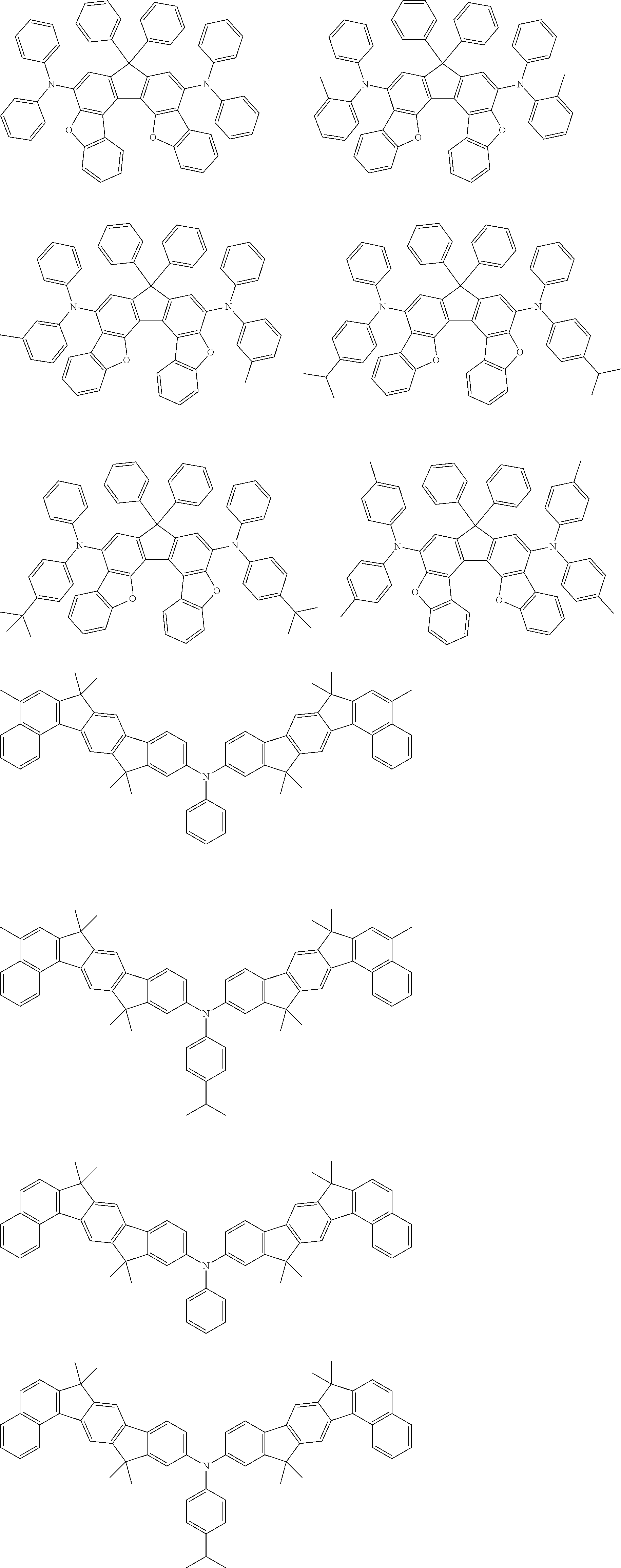

In one embodiment, the first emitting layer contains one or more compounds selected from the group consisting of the compounds represented by the formulas (1) to (4) as a host material (also referred to as a matrix material in some cases).

In one embodiment, the first emitting layer further contains a dopant material.

In one embodiment, the first emitting layer contains the second compound as a dopant material (also referred to as a guest material, an emitter, or an emitting material in some cases).

In one embodiment, the first emitting layer contains the dopant material in an amount of more than 1.1% by mass, 1.2% by mass or more, or 1.5% by mass or more of the total mass of the first emitting layer.

In one embodiment, the first emitting layer contains the dopant material in an amount of 10% by mass or less, 7% by mass or less, or 5% by mass or less of the total mass of the first emitting layer.

In one embodiment, the first emitting layer contains the host material in an amount of 60% by mass or more, 70% by mass or more, 80% by mass or more, 90% by mass or more, or 95% by mass or more of the total mass of the first emitting layer.

In one embodiment, the first emitting layer contains the host material in an amount of 99% by mass or less of the total mass of the first emitting layer.

The first emitting layer may contain a material other than the host material and the dopant material.

The first emitting layer may include one kind of the host material alone, or it may include two or more kinds thereof. The first emitting layer may include one kind of the dopant material alone, or it may include two or more kinds thereof.

In one embodiment, the film thickness of the first emitting layer is 3 nm or more or 5 nm or more. When the film thickness of the first emitting layer is 3 nm or more, the film thickness is sufficient to cause recombination of holes and electrons in the first emitting layer.

In one embodiment, the film thickness of the first emitting layer is 15 nm or less or 10 nm or less. When the film thickness of the first emitting layer is 15 nm or less, the film thickness is sufficiently thin so that triplet excitons transfer to the second emitting layer.

In one embodiment, the film thickness of the first emitting layer is 3 nm or more and 15 nm or less.

### (Second Emitting Layer)

The second emitting layer contains at least one compound different from that of the above-described first emitting layer. In one embodiment, the second emitting layer contains a host material. As the host material, in addition to the compounds represented by the formulas (1) to (4) described above, for example, 1) a metal complex such as an aluminum complex, a beryllium complex and a zinc complex, 2) a heterocyclic compound such as an oxadiazole derivative, a benzimidazole derivative and a phenanthroline derivative, 3) a fused aromatic compound such as a carbazole derivative, an anthracene derivative, a phenanthrene derivative, a pyrene derivative and a chrysene derivative, and 4) an aromatic amine compound such as a triarylamine derivative and a fused polycyclic aromatic amine derivative can be used.

In one embodiment, a second host material is a compound different from a first host material contained in the first emitting layer.

In one embodiment, the second emitting layer further contains a dopant material. As the dopant material, for example, the second compound described above can be used. A known phosphorescent material can also be used as the dopant material.

The dopant material of the second emitting layer may be a compound that is same as or different from the dopant material of the first emitting layer.

In one embodiment, the dopant material of the second emitting layer is a compound different from the dopant material of the first emitting layer.

In one embodiment, the dopant material of the second emitting layer is a compound same as the dopant material of the first emitting layer.

In one embodiment, the second emitting layer contains the dopant material in an amount of more than 1.1% by mass, 1.2% by mass or more, or 1.5% by mass or more of the total mass of the second emitting layer.

In one embodiment, the second emitting layer contains the dopant material in an amount of 10% by mass or less, 7% by mass or less, or 5% by mass or less of the total mass of the second emitting layer.

In one embodiment, the second emitting layer contains the host material in an amount of 60% by mass or more, 70% by mass or more, 80% by mass or more, 90% by mass or more, or 95% by mass or more of the total mass of the second emitting layer.

In one embodiment, the second emitting layer contains the host material in an amount of 99% by mass or less of the total mass of the second emitting layer.

The second emitting layer may contain a material other than the host material and the dopant material.

The second emitting layer may include one kind of the host material alone, or it may include two or more kinds thereof. The second emitting layer may include one kind of the dopant material alone, or it may include two or more kinds thereof.

The second emitting layer may be a fluorescent emitting layer, or it may be a phosphorescent emitting layer.

In one embodiment, the second emitting layer is a fluorescent emitting layer.

In one embodiment, the film thickness of the second emitting layer is 5 nm or more, 10 nm or more, or 15 nm or more. When the film thickness of the first emitting layer is 5 nm or more, triplet excitons can be sufficiently separated from a recombination portion in the first emitting layer.

In one embodiment, the film thickness of the second emitting layer is 20 nm or less. When the film thickness of the second emitting layer is 20 nm or less, the density of the triplet excitons in the second emitting layer is improved to cause the TTF phenomenon more easily.

In one embodiment, the film thickness of the second emitting layer is 5 nm or more and 20 nm or less.

### (Relationship Between First Emitting Layer and Second Emitting Layer)

In one embodiment, a triplet energy T₁ (H1) of the host material of the first emitting layer (hereinafter, also referred to as “first host material”) and a triplet energy T₁ (H2) of the host material of the second emitting layer (hereinafter, also referred to as “second host material”) satisfy the relationship of the following mathematical formula (Math. 1).

$${T}_{1} ( H 1 ) > {T}_{1} ( H 2 ) \qquad ( Math . 1 )$$

By providing the first emitting layer and the second emitting layer so as to satisfy the relationship of the mathematical formula (Math. 1), the triplet excitons generated in the first emitting layer can transfer to the second emitting layer without being quenched by excessive carriers and can suppressed from back-transferring from the second emitting layer to the first emitting layer. As a result, in the second emitting layer, a TTF mechanism is developed, singlet excitons are efficiently generated, and luminous efficiency is improved.

As described above, the organic EL device includes, as different regions, the first emitting layer mainly generating triplet excitons and the second emitting layer mainly exhibiting the TTF mechanism by utilizing the triplet excitons having transferred from the first emitting layer, and a difference in triplet energy is provided by using a compound having a smaller triplet energy than that of the first host material in the first emitting layer as the second host material in the second emitting layer, thereby improving luminous efficiency.

### Triplet Energy T₁

Examples of a method for measuring the triplet energy T₁ include the following methods.

A compound to be measured is dissolved in EPA (diethyl ether:isopentane:ethanol=5:5 2 (volume ratio)) so as to be 10⁻⁵ mol/L or more and 10⁻⁴ mol/L or less, and this solution is placed in a quartz cell and used as a measurement sample. For this measurement sample, a phosphorescence spectrum (ordinate axis: phosphorescence emission intensity, abscissa axis: wavelength) is measured at a low temperature (77 [K]), a tangent is drawn to the rise of the phosphorescence spectrum on the short wavelength side, and an energy amount is calculated from the following Conversion Equation (F1) based on a wavelength value λ_{edge} [nm] at ab intersection of the tangent and the abscissa axis and is defined as the triplet energy T₁.

$$Conversion equation ( F 1 ) : {T}_{1} [ eV ] = 1239.85 / {λ}_{edge}$$

The tangent to the rise of the phosphorescence spectrum on the short wavelength side is drawn as follows. While transferring on a curve of the phosphorescence spectrum from the short wavelength side to the local maximum value closest to the short wavelength side among the local maximum values of the spectrum, a tangent at each point on the curve is considered toward the long wavelength side. An inclination of the tangent is increased along the rise of the curve (that is, a value of the ordinate axis is increased). A tangent drawn at a point of the local maximum inclination (that is, a tangent at an inflection point) is defined as the tangent to the rise of the phosphorescence spectrum on the short wavelength side.

The local maximum point where a peak intensity is 15% or less of the maximum peak intensity of the spectrum is not counted as the above-mentioned local maximum intensity closest to the short wavelength side, and a tangent drawn at a point that is closest to the local maximum intensity closest to the short wavelength side and where the inclination of the curve is the local maximum is defined as a tangent to the rise of the phosphorescence spectrum on the short wavelength side. For the measurement of phosphorescence, a spectrophotofluorometer body F-7100 manufactured by Hitachi High-Technologies Corporation can be used. The measurement apparatus is not limited thereto, and the measurement may be performed by combining a cooling apparatus, a low-temperature container, an excitation light source, and a light-receiving apparatus.

In one embodiment, a triplet energy T₁ (H1) of the first host material and a triplet energy T₁ (D1) of a dopant material of the first emitting layer (hereinafter, also referred to as “first dopant material”) satisfy the relationship of the following mathematical formula (Math. 2).

$${T}_{1} ( D 1 ) > {T}_{1} ( H 1 ) \qquad ( Math . 2 )$$

When the first host material and the first dopant material satisfy the relationship of the mathematical formula (Math. 2), triplet excitons generated in the first emitting layer transfer not on the first dopant material having a higher triplet energy but on the first host material, and thus easily transfer to the second emitting layer.

In one embodiment, the triplet energy T₁ (H1) of the first host material, the triplet energy T₁ (D1) of the first dopant material, and the triplet energy T₁ (H2) of the second host material satisfy the relationship of the following mathematical formula (Math. 3).

$${T}_{1} ( D 1 ) > {T}_{1} ( H 1 ) > {T}_{1} ( H 2 ) \qquad ( Math . 3 )$$

In one embodiment, a triplet energy T₁ (D2) of a dopant material of the second emitting layer (hereinafter, also referred to as “second dopant material”) and the triplet energy T₁ (H2) of the second host material satisfy the relationship of the following mathematical formula (Math. 4).

$${T}_{1} ( D 2 ) > {T}_{1} ( H 2 ) \qquad ( Math . 4 )$$

When the second dopant material and the second host material satisfy the relationship of the mathematical formula (Math. 4), triplet excitons generated in the first emitting layer energy-transfer not to the second dopant material having a higher triplet energy but to molecules of the second host material in the case where they transfer to the second emitting layer. Triplet excitons generated by recombination of holes and electrons on the second host material do not transfer to the second dopant material having a higher triplet energy. Triplet excitons generated by recombination on the molecules of the second dopant material rapidly energy-transfer to the molecules of the second host material.

Triplet excitons of the second host material efficiently collide with each other on the second host material due to the TTF phenomenon without transferring the triplet excitons thereof to the second dopant material, thereby generating singlet excitons.

In the organic EL device according to an aspect of the present invention, conventionally known materials and device configurations can be applied as long as the effects of the present invention are not impaired, except that the first emitting layer contains one or more compounds selected from the group consisting of a compound represented by each of the formulas (1) to (4).

### (Substrate)

The substrate is used as a support of an emitting device. As the substrate, for example, glass, quartz, plastic, or the like can be used. A flexible substrate may be used. The flexible substrate is a bendable (flexible) substrate, and examples thereof include plastic substrates made of polycarbonate or polyvinyl chloride, and the like.

### (Anode)

For the anode formed on the substrate, a metal, an alloy, an electrically conductive compound, a mixture thereof, and the like having a large work function (specifically, 4.0 eV or more) is preferably used. Specific examples thereof include indium oxide-tin oxide (ITO: Indium Tin Oxide), indium oxide-tin oxide containing silicon or silicon oxide, indium oxide-zinc oxide, indium oxide containing tungsten oxide and zinc oxide, graphene, and the like. In addition thereto, gold (Au), platinum (Pt), a nitride of a metal material (for example, titanium nitride), and the like can be used.

### (Hole-Injecting Layer)

The hole-injecting layer is a layer containing a substance having a high hole injectability. As the substance having a high hole injectability, molybdenum oxide, titanium oxide, vanadium oxide, rhenium oxide, ruthenium oxide, chromium oxide, zirconium oxide, hafnium oxide, tantalum oxide, silver oxide, tungsten oxide, manganese oxide, an aromatic amine compound, a polymer compound (such as an oligomer, a dendrimer and a polymer), or the like can also be used.

### (Hole-Transporting Layer)

The hole-transporting layer is a layer containing a substance having a high hole transportability. For the hole-transporting layer, an aromatic amine compound, a carbazole derivative, an anthracene derivative, or the like can be used. A polymer compound such as poly(N-vinylcarbazole) (abbreviation: PVK) and poly(4-vinyltriphenylamine) (abbreviation: PVTPA) can also be used. However, a substance other than these substances may be used as long as the substance has a higher hole transportability than an electron transportability. The layer containing a substance having a high hole transportability may be not only a single layer but also layers in which two or more layers formed of the above substances are stacked.

### (Guest (Dopant) Material of Emitting Layer)

The emitting layer is a layer containing a substance having high luminous property, and various materials can be used. For example, as the substance having high luminous property, in addition to the compound represented by the formula (D1), the compound represented by the formula (D2), the compound represented by the formula (D3), and the compound represented by the formula(D4), a fluorescent compound emitting fluorescence or a phosphorescent compound emitting phosphorescence can be used. The fluorescent compound is a compound capable of emitting light from a singlet excited state, and the phosphorescent compound is a compound capable of emitting light from a triplet excited state.

As a blue fluorescent emitting material that can be used for the emitting layer, a pyrene derivative, a styrylamine derivative, a chrysene derivative, a fluoranthene derivative, a fluorene derivative, a diamine derivative, a triarylamine derivative, or the like can be used. As a green fluorescent emitting material that can be used for the emitting layer, an aromatic amine derivative or the like can be used. As a red fluorescent emitting material that can be used for the emitting layer, a tetracene derivative, a diamine derivative, or the like can be used.

As a blue phosphorescent emitting material that can be used for the emitting layer, a metal complex such as an iridium complex, an osmium complex and a platinum complex is used. As a green phosphorescent emitting material that can be used for the emitting layer, an iridium complex or the like is used. As a red phosphorescent emitting material that can be used for the emitting layer, a metal complex such as an iridium complex, a platinum complex, a terbium complex and a europium complex is used.

### (Host Material of Emitting Layer)

The emitting layer may have a configuration in which the above-described substance having high luminous property (guest material) is dispersed in another substance (host material). As a substance for dispersing a substance having high luminous property, in addition to the material used in the present invention described above (the compound represented by the formula (1), the compound represented by the formula (2), the compound represented by the formula (3), and the compound represented by the formula (4)), various substances can be used, and it is preferable to use a substance having a lowest unoccupied molecular orbital level (LUMO level) higher than that of the substance having high luminous property and a highest occupied molecular orbital level (HOMO level) lower than that of the substance having high luminous property.

As a substance (host material) for dispersing the substance having high luminous property, 1) a metal complex such as an aluminum complex, a beryllium complex and a zinc complex, 2) a heterocyclic compound such as an oxadiazole derivative, a benzimidazole derivative and a phenanthroline derivative, 3) a fused aromatic compound such as a carbazole derivative, an anthracene derivative, a phenanthrene derivative, a pyrene derivative and a chrysene derivative, and 4) an aromatic amine compound such as a triarylamine derivative and a fused polycyclic aromatic amine derivative are used.

A compound having delayed fluorescence (thermally activated delayed fluorescence) can also be used as the host material. It is also preferable that the emitting layer contains the materials used in the present invention described above and a host compound having delayed fluorescence.

The emitting layer may or may not contain the other substances described above in addition to the materials used in the present invention described above.

### (Electron-Transporting Layer)

The electron-transporting layer is a layer containing a substance having a high electron transportability. For the electron-transporting layer, 1) a metal complex such as an aluminum complex, a beryllium complex and a zinc complex, 2) a heteroaromatic compound such as an imidazole derivative, a benzimidazole derivative, an azine derivative, a carbazole derivative and a phenanthroline derivative, and 3) a polymer compound can be used.

### (Electron-Injecting Layer)

The electron-injecting layer is a layer containing a substance having a high electron injectability. For the electron-injecting layer, a metal complex compound such as lithium (Li), ytterbium (Yb), lithium fluoride (LiF), cesium fluoride (CsF), calcium fluoride (CaF₂) and 8-hydroxyquinolinolato-lithium (Liq), an alkali metal such as lithium oxide (LiOₓ), an alkaline earth metal, or a compound thereof can be used.

### (Cathode)

For the cathode, a metal, an alloy, an electrically conductive compound, a mixture thereof, and the like having a small work function (specifically, 3.8 eV or less) is preferably used. Specific examples of such a cathode material include elements belonging to Group 1 or Group 2 of the Periodic Table of the Elements, that is, alkali metals such as lithium (Li) and cesium(Cs), alkaline earth metals such as magnesium (Mg), calcium (Ca) and strontium (Sr), alloys containing these metals (for example, MgAg and AILi), rare earth metals such as europium (Eu) and ytterbium (Yb), alloys containing these metals, and the like.

The cathode is usually formed by a vacuum deposition method or a sputtering method. In the case of using silver paste or the like, a coating method, an inkjet method, or the like can be used.

In the case of providing the electron-injecting layer, the cathode can be formed using various conductive materials such as aluminum, silver, ITO, graphene, and indium oxide-tin oxide containing silicon or silicon oxide, regardless of the magnitude of the work function.

### (Electron-Blocking Layer, Hole-Blocking Layer, and Exciton-Blocking Layer)

An electron-blocking layer, a hole-blocking layer, an exciton (triplet)-blocking layer, or the like may be provided in adjacent to the emitting layer.

The electron-blocking layer is a layer having a function of preventing leakage of electrons from the emitting layer to the hole-transporting layer. The hole-blocking layer is a layer having a function of preventing leakage of holes from the emitting layer to the electron-transporting layer. The exciton-blocking layer is a layer having a function of preventing diffusion of excitons generated in the emitting layer to the adjacent layers and confining the excitons within the emitting layer.

In the organic EL device according to an aspect of the present invention, the film thickness of each layer is not particularly limited, but is generally preferably in a range of several nm to 1 μm in order to suppress defects such as pinholes, suppress the applied voltage to be low, and improve luminous efficiency.

In the organic EL device according to an aspect of the present invention, a method for forming each layer is not particularly limited. A conventionally known method for forming each layer by a vacuum deposition method, a spin coating method, or the like can be used. Each layer such as the emitting layer can be formed by a known method such as a vacuum deposition method, a molecular beam deposition method (MBE method), or a coating method such as a dipping method, a spin coating method, a casting method, a bar coating method and a roll coating method using a solution prepared by dissolving the material in a solvent.

### [Electronic Apparatus]

An electronic apparatus according to an aspect of the present invention includes the organic EL device according to an aspect of the present invention.

Specific examples of the electronic apparatus include display components such as an organic EL panel module, display devices for a television, a mobile phone, a personal computer and the like, emitting devices such as a light and a vehicular lamp, and the like.

### EXAMPLES

### <Compound>

The compound represented by the formula (1) or (2) used in the fabrication of the organic EL device of Examples is shown below.

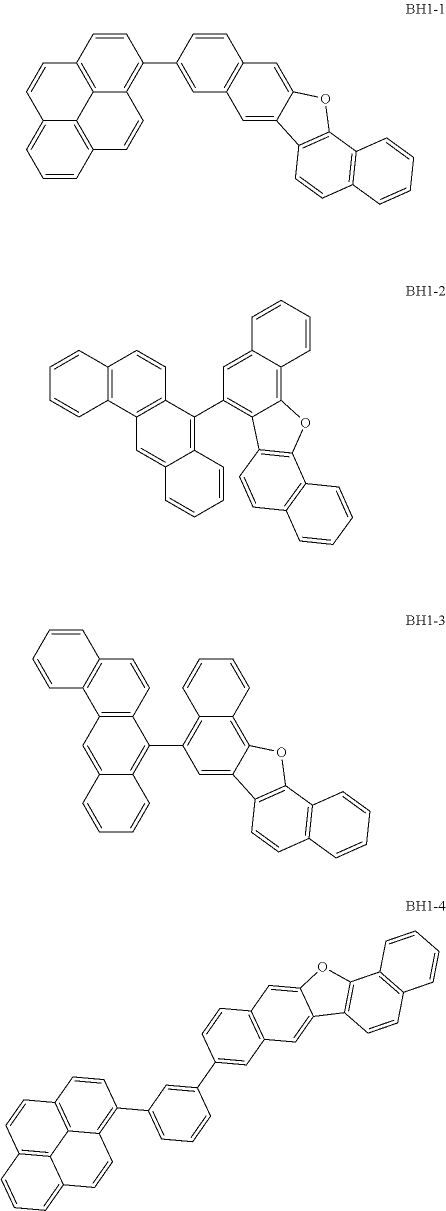 [SMILES: c1ccc2c(c1)ccc1c3cc4cc(-c5ccc6ccc7cccc8ccc5c6c78)ccc4cc3oc21 ; c1ccc2c(-c3cc4ccccc4c4oc5c6ccccc6ccc5c34)c3ccc4ccccc4c3cc2c1 ; c1ccc2c(-c3cc4c5ccc6ccccc6c5oc4c4ccccc34)c3ccc4ccccc4c3cc2c1 ; c1cc(-c2ccc3cc4oc5c6ccccc6ccc5c4cc3c2)cc(-c2ccc3ccc4cccc5ccc2c3c45)c1]

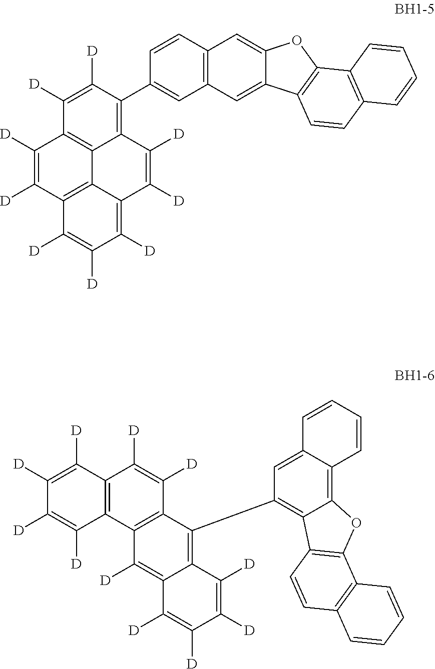 [SMILES: [2H]c1c([2H])c2c([2H])c([2H])c3c([2H])c([2H])c(-c4ccc5cc6oc7c8ccccc8ccc7c6cc5c4)c4c([2H])c([2H])c(c1[2H])c2c34 ; [2H]c1c([2H])c([2H])c2c([2H])c3c(c([2H])c([2H])c4c([2H])c([2H])c([2H])c([2H])c43)c(-c3cc4ccccc4c4oc5c6ccccc6ccc5c34)c2c1[2H]]

The compound used in the fabrication of the organic EL device of Comparative Example is shown below.

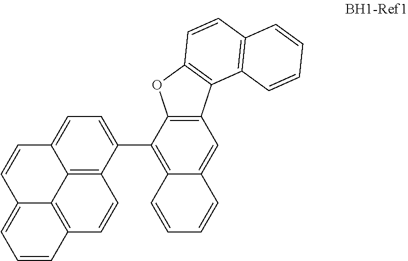 [SMILES: c1ccc2c(-c3ccc4ccc5cccc6ccc3c4c56)c3oc4ccc5ccccc5c4c3cc2c1]

The structures of other compounds used in the fabrication of the organic EL device of Examples and Comparative Example are shown below.

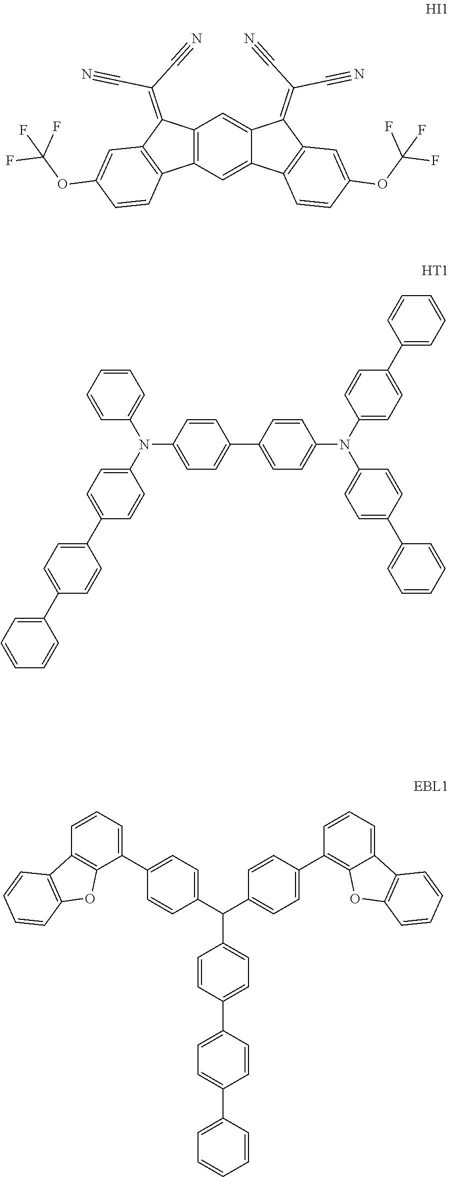 [SMILES: N#CC(C#N)=C1c2cc(OC(F)(F)F)ccc2-c2cc3c(cc21)C(=C(C#N)C#N)c1cc(OC(F)(F)F)ccc1-3 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(-c3ccc(C(c4ccc(-c5cccc6c5oc5ccccc56)cc4)c4ccc(-c5cccc6c5oc5ccccc56)cc4)cc3)cc2)cc1]

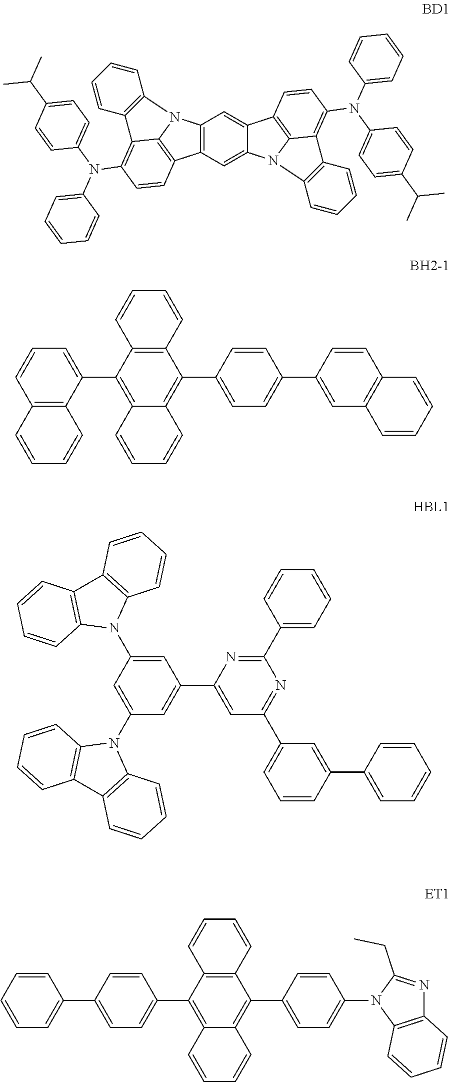

The triplet energy (T₁) of a compound used as a host material or a dopant material in the fabrication of the organic EL devices of Examples and Comparative Example was measured as follows. The results are shown in Table 1.

### Measurement of Triplet Energy (T₁)

A compound to be measured was dissolved in EPA (diethyl ether:isopentane:ethanol=5 5:2 (volume ratio)) so as to be 10⁻⁵ mol/L or more and 10⁻⁴ mol/L or less, and this solution was placed in a quartz cell and used as a measurement sample. For this measurement sample, a phosphorescence spectrum (ordinate axis: phosphorescence emission intensity, abscissa axis: wavelength) was measured at a low temperature (77 [K]), a tangent was drawn to the rise of the phosphorescence spectrum on the short wavelength side, and an energy amount was calculated from the following Conversion Equation (F1) based on a wavelength value λ_{edge} [nm] at ab intersection of the tangent and the abscissa axis and was defined as the triplet energy T₁.

$${T}_{1} [ eV ] = 1239 \text{.85} / {λ}_{edge} \qquad Conversation Equation ( F1 )$$

The tangent to the rise of the phosphorescence spectrum on the short wavelength side was drawn as follows. While transferring on a curve of the phosphorescence spectrum from the short wavelength side to the local maximum value closest to the short wavelength side among the local maximum values of the spectrum, a tangent at each point on the curve is considered toward the long wavelength side. An inclination of the tangent is increased along the rise of the curve (that is, a value of the ordinate axis is increased). A tangent drawn at a point of the local maximum inclination (that is, a tangent at an inflection point) was defined as the tangent to the rise of the phosphorescence spectrum on the short wavelength side.

The local maximum point where a peak intensity is 15% or less of the maximum peak intensity of the spectrum was not counted as the above-mentioned local maximum intensity closest to the short wavelength side, and a tangent drawn at a point that is closest to the local maximum intensity closest to the short wavelength side and where the inclination of the curve is the local maximum was defined as a tangent to the rise of the phosphorescence spectrum on the short wavelength side.

For the measurement of phosphorescence, a spectrophotofluorometer body F-7100 manufactured by Hitachi High-Technologies Corporation was used.

TABLE 1

| Compound | T₁ (eV) |
|---|---|
| BH1-1 | 2.08 |
| BH1-2 | 2.07 |
| BH1-3 | 2.07 |
| BH1-4 | 2.09 |
| BH1-5 | 2.08 |
| BH1-6 | 2.07 |
| BH1-Ref1 | 2.10 |
| BH2-1 | 1.86 |
| BD | 2.29 |

### Example 1

### <Fabrication of Organic EL Device>

An organic EL device was fabricated as follows.

A glass substrate of 25 mm×75 mm×1.1 mm thick with an ITO transparent electrode (anode) (manufactured by GEOMATEC Co., Ltd.) was subjected to ultrasonic cleaning with isopropyl alcohol for 5 minutes, and then subjected to UV ozone cleaning for 30 minutes. The film thickness of ITO was 130 nm.

The cleaned glass substrate with a transparent electrode was mounted on a substrate holder in a vacuum deposition apparatus, and first, a compound H11 was vapor-deposited on the surface on the side on which the transparent electrode was formed so as to cover the transparent electrode, thereby forming a first hole-transporting layer having a film thickness of 5 nm.

A compound HT1 was vapor-deposited on the first hole-transporting layer to form a second hole-transporting layer having a film thickness of 80 nm.

A compound EBL1 was vapor-deposited on the second hole-transporting layer to form a third hole-transporting layer having a film thickness of 10 nm.

A compound BH1-1 (host material) and a compound BD1 (dopant material) were co-deposited on the third hole-transporting layer so that the ratio of the compound BD1 was 2% by mass, thereby forming a first emitting layer having a film thickness of 5 nm.

A compound BH2-1 (host material) and a compound BD1 (dopant material) were co-deposited on the first emitting layer so that the ratio of the compound BD1 was 2% by mass, thereby forming a second emitting layer having a film thickness of 20 nm.

A compound HBL1 was vapor-deposited on the second emitting layer to form a first electron-transporting layer having a film thickness of 10 nm.

A compound ET1 was vapor-deposited on the first electron-transporting layer to form a second electron-transporting layer having a film thickness of 15 nm.

LiF was vapor-deposited on the second electron-transporting layer to form an electron-injecting layer having a film thickness of 1 nm.

Metal A1 was vapor-deposited on the electron-injecting layer to form a cathode having a film thickness of 80 nm.

The device configuration of the organic EL device of Example 1 is schematically shown as follows.

ITO (130)/HI1 (5)/HT1 (80)/EBL1 (10)/BH1-1:BD1 (5:2%)/BH2-1:BD1 (20:2%)/HBL1 (10)/ET1 (15)/LiF (1)/Al (80)

The number in parentheses represents the film thickness (unit: nm).

The number expressed in percent in parentheses indicates the ratio (% by mass) of the latter compound in the layer.

### <Evaluation of Organic EL Device>

The fabricated organic EL device was evaluated as follows. The results are shown in Table 2.

### External Quantum Efficiency

A voltage was applied to the organic EL device so that the current density was 10 mA/cm², and the EL emission spectrum was measured with a spectroradiometer CS-2000 (manufactured by Konica Minolta, Inc.). An external quantum efficiency EQE (%) was calculated from the obtained spectral-radiance spectrum.

### Device Lifetime

A voltage was applied to the organic EL device at room temperature so that the current density was 50 mA/cm², and the time (LT95 (unit: h)) until the luminance reached 95% with respect to the initial luminance was measured.

### Examples 2 to 6

An organic EL device was fabricated and evaluated in the same manner as in Example 1, except that the compound described in Table 2 was used instead of the compound BH1-1 in formation of the first emitting layer. The results are shown in Table 2.

### Comparative Example 1

An organic EL device was fabricated and evaluated in the same manner as in Example 1, except that a compound BH1-Ref1 was used instead of the compound BH1-1 in formation of the first emitting layer. The results are shown in Table 2.

TABLE 2

| | First emitting layer | EQE (%) | LT95 (h) |
|---|---|---|---|
| Example 1 | BH1-1 | 10.5 | 152 |
| Example 2 | BH1-2 | 11.3 | 125 |
| Example 3 | BH1-3 | 11.2 | 128 |
| Example 4 | BH1-4 | 10.9 | 139 |
| Example 5 | BH1-5 | 10.5 | 201 |
| Example 6 | BH1-6 | 11.3 | 183 |
| Comparative | BH1-Ref1 | 10.1 | 102 |
| Example 1 | | | |

### <Synthesis of Compounds>

### (Synthesis Example 1) Synthesis of BH1-1

BH1-1 was synthesized by the following synthesis route.

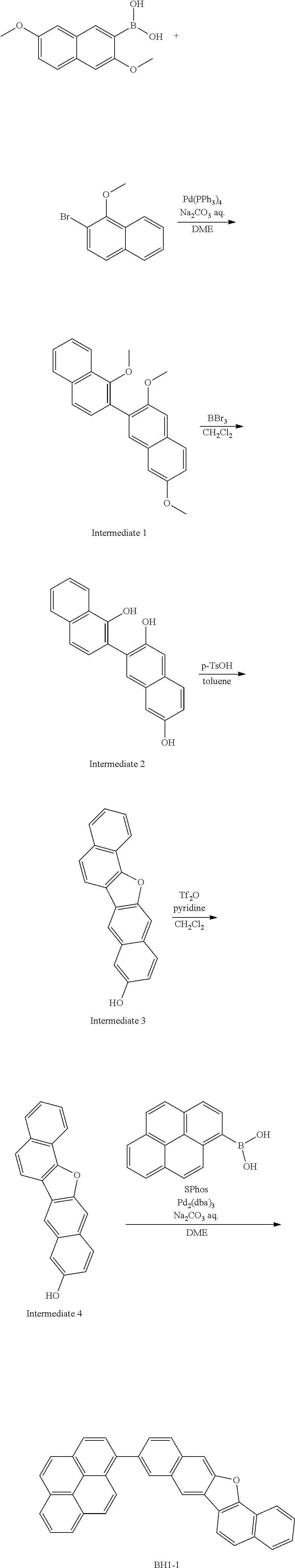

### (1) Synthesis of 1,37′-trimethoxy-2,2′binaphthalene (Intermediate 1)

(3,7-Dimethoxynaphthalene-2-yl)boronic acid (6.8 g), 2-bromo-1-methoxynaphthalene (6.92 g), tetrakis(triphenylphosphine)palladium(0) (1.00 g), and 1,2-dimethoxyethane (150 mL) were put in a flask and refluxed under an argon atmosphere under heating and stirring for 30 minutes. A 2 mol/L aqueous sodium carbonate solution (30 mL) was added dropwise over 15 minutes, and the reaction solution was refluxed under heating and stirring for 8 hours. After completion of the reaction, the solution was allowed to cool to room temperature, and a sufficient amount of water was added. The solid was collected by filtration and washed with methanol. The solid was purified by silica gel column chromatography to obtain a white solid of 1,3′,7′-trimethoxy-2,2′binaphthalene (6.9 g, yield: 68%).

### (2) Synthesis of [2,2′-binaphthalene]-1,3′,7′-triol (Intermediate 2)

1,3′,7′-Trimethoxy-2,2′-binaphthalene (Intermediate 1) (6.9 g) was dissolved in dehydrated dichloromethane (60 mL) in a flask, a 1 mol/L boron tribromide dichloromethane solution (6.3 mL) was added dropwise under ice cooling, and the mixture was stirred in an ice bath overnight. After completion of the reaction, the reaction solution was ice-cooled, and ice water was added thereto. The precipitated solid was collected by filtration to obtain a white solid of [2,2′-binaphthalene]-1,3′,7′-triol (6.0 g, yield: 97%).

### (3) Synthesis of dinaphtho[1,2-b:2′,3′-d]furan-9-ol (Intermediate 3)

[2,2′-Binaphthalene]-1,3′,7′-triol (Intermediate 2) (6.0 g), p-toluenesulfonic acid monohydrate (1.2 g), and toluene (60 mL) were put in a flask and refluxed under an argon atmosphere under heating and stirring for 2 hours. After completion of the reaction, the reaction solution was allowed to cool, 30 mL of methanol was added, the mixture was stirred, and the precipitated solid was collected by filtration. The obtained solid was recrystallized with toluene to obtain a white solid of dinaphtho[1,2-b:2′,3′-d]furan-9-ol (4.2 g, yield: 74%).

### (4) Synthesis of dinaphtho[1,2-b:2′,3′-d]furan-9-yl trifluoromethanesulfonate (Intermediate 4)

Dinaphtho[1,2-b:2′,3′-d]furan-9-ol (Intermediate 3) (4.2 g) and dichloromethane (120 mL) were put in a flask, pyridine (3.6 mL) was added thereto, trifluoromethanesulfonic anhydride (3.6 mL) was added dropwise thereto under ice cooling, and the mixture was stirred while raising the temperature to room temperature. After completion of the reaction, water was added under ice cooling. The solution was extracted with dichloromethane, the organic phase was dried over anhydrous sodium sulfate, the solvent was then distilled off, and the residue was purified by silica gel column chromatography to obtain a white solid of dinaphtho[1,2-b:2′,3′-d]furan-9-yl trifluoromethanesulfonate (3.8 g, yield: 62%).

### (5) Synthesis of 9-(pyrene-1-yl)dinaphtho[1,2-b:2′,3′-d]furan (BH1-1)

Dinaphtho[1,2-b:2′,3′-d]furan-9-yl trifluoromethanesulfonate (Intermediate 4) (6.6 g), pyrene-1-yl boronic acid (3.7 g), 2-dicyclohexylphosphino-2′,6′-dimethoxybiphenyl (0.5 g), and tris(dibenzylideneacetone)dipalladium(0) (0.28 g) were added, and the mixture was refluxed under an argon atmosphere under heating and stirring for 30 minutes. A 2 mol/L aqueous sodium carbonate solution (19 mL) was added dropwise over 15 minutes, and the reaction solution was refluxed under heating and stirring for 4 hours. After completion of the reaction, the solution was allowed to cool to room temperature, and a sufficient amount of water was added. The solid was collected by filtration and washed with methanol. The solid was heated and dissolved in toluene and passed through a silica gel short column. The solution was distilled off and the obtained solid was recrystallized with toluene to obtain a white solid of 9-(pyrene-1-yl)dinaphtho[1,2-b:2′,3′-d]furan (BH1-1) (4.7 g, yield: 67%). The result of mass spectrometric analysis was m/e=469 to the molecular weight 468.56, and the compound was identified as an intended product.

### (Synthesis Example 2) Synthesis of BH1-2

BH1-2 was synthesized by the following synthesis route.

### (1) Synthesis of Intermediate 5

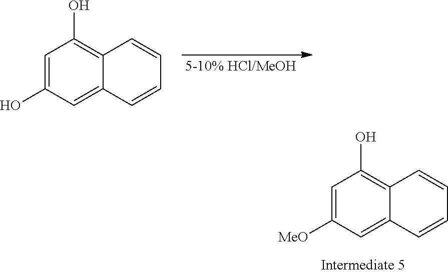 [SMILES: Oc1cc(O)c2ccccc2c1 ; COc1cc(O)c2ccccc2c1]

To 100 mL of a 5 to 10% hydrochloric acid/methanol solution, 1,3-dihydroxynaphthalene (10 g) was added, and the mixture was stirred at room temperature for 30 hours. Sodium hydroxide was added to the reaction solution, the organic phase was separated, and the mixture was concentrated under a reduced pressure. The obtained residue was purified by silica gel column chromatography to obtain Intermediate 5 as a light red solid (9.6 g, yield: 88%).

### (2) Synthesis of Intermediate 6

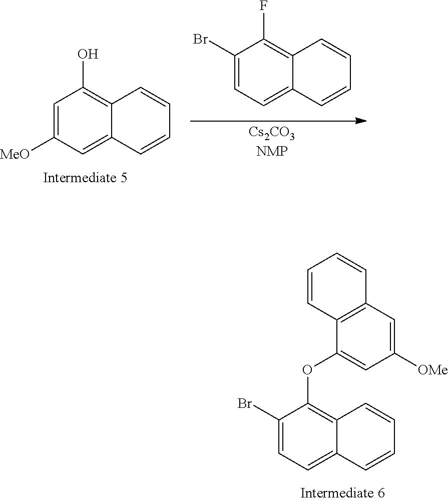 [SMILES: COc1cc(O)c2ccccc2c1 ; Fc1c(Br)ccc2ccccc12 ; COc1cc(Oc2c(Br)ccc3ccccc23)c2ccccc2c1]

Intermediate 5 (8.3 g), 2-bromo-1-fluoronaphthalene (10.7 g), and cesium carbonate (31 g) were added to 240 mL of NMP (N-methylpyrrolidone), and the mixture was stirred under heating at 130° C. for 7 hours under an argon atmosphere. The reaction solution was concentrated, and the obtained residue was purified by silica gel column chromatography to obtain Intermediate 6 as a white solid (12.8 g, yield: 70%).

### (3) Synthesis of Intermediate 7

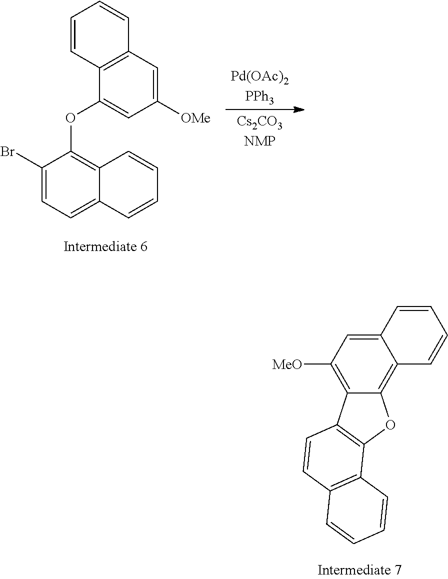 [SMILES: COc1cc(Oc2c(Br)ccc3ccccc23)c2ccccc2c1 ; COc1cc2ccccc2c2oc3c4ccccc4ccc3c12]

Intermediate 6 (12.8 g), palladium acetate (0.8 g), triphenylphosphine (1.8 g), and cesium carbonate (22.1 g) were added to 340 mL of NMP, and the mixture was stirred under heating at 170° C. for 6 hours under an argon atmosphere. The reaction solution was concentrated, and the obtained residue was purified by silica gel column chromatography to obtain Intermediate 7 as a white solid (6.0 g, yield: 59%).

### (4) Synthesis of Intermediate 8

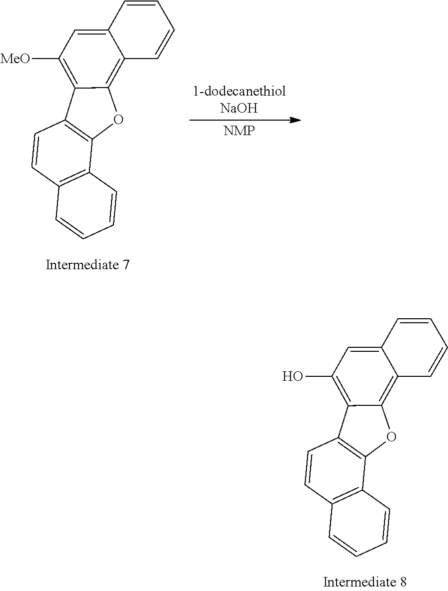 [SMILES: COc1cc2ccccc2c2oc3c4ccccc4ccc3c12 ; Oc1cc2ccccc2c2oc3c4ccccc4ccc3c12]

Intermediate 7 (5 g) and sodium hydroxide (2.0 g) were added to 67 mL of NMP, and 1-dodecanethiol (5.1 g) was added thereto under an argon atmosphere. After stirring under heating at 140° C. for 6 hours, 1 N hydrochloric acid was added to make the solution acidic. The organic phase was collected by extraction with a hexane-ethyl acetate mixed solvent, and concentrated under a reduced pressure to obtain Intermediate 8 as a yellow oily product (4.6 g, yield: 97%).

### (5) Synthesis of Intermediate 9

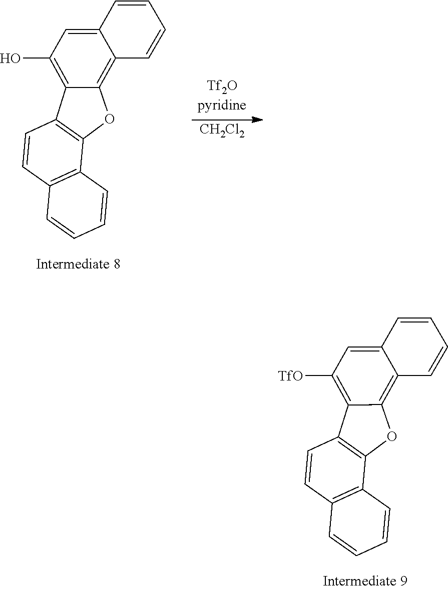 [SMILES: Oc1cc2ccccc2c2oc3c4ccccc4ccc3c12 ; "CH2Cl2" ; O=S(=O)(Oc1cc2ccccc2c2oc3c4ccccc4ccc3c12)C(F)(F)F]

Intermediate 8 (4.4 g) and pyridine (3.7 g) were added to 160 mL of dichloromethane, and the mixture was stirred at 0° C. under an argon atmosphere. Trifluoromethanesulfonic anhydride (Tf₂O, 6.6 g) was added dropwise thereto, and then the mixture was stirred at room temperature for 2 hours. The reaction solution was concentrated under a reduced pressure, and the obtained residue was purified by silica gel column chromatography to obtain Intermediate 9 as a white solid (1.9 g, yield: 29%).

### (6) Synthesis of BH1-2

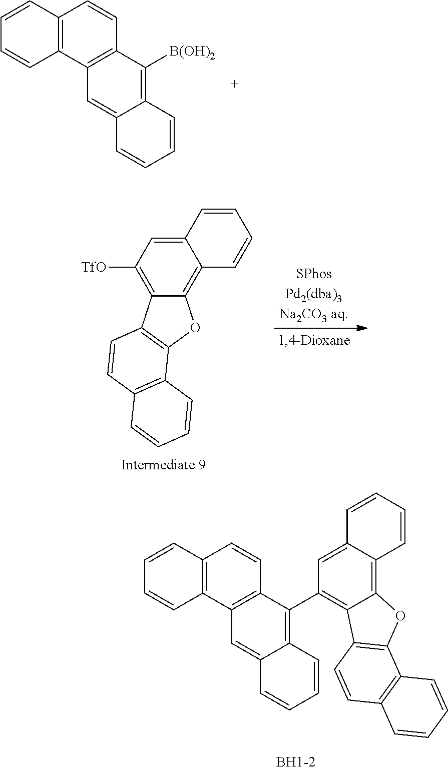 [SMILES: OB(O)c1c2ccccc2cc2c1ccc1ccccc12 ; O=S(=O)(Oc1cc2ccccc2c2oc3c4ccccc4ccc3c12)C(F)(F)F ; c1ccc2c(-c3cc4ccccc4c4oc5c6ccccc6ccc5c34)c3ccc4ccccc4c3cc2c1]

Intermediate 9 (8.0 g), tetraphene-7-yl boronic acid (6.3 g), 2-dicyclohexylphosphino-2′,6′-dimethoxybiphenyl (SPhos, 0.63 g), and tris(dibenzylideneacetone)dipalladium(0) (0.35 g) were added to 165 mL of 1,4-dioxane, and the mixture was refluxed under an argon atmosphere under heating and stirring for 30 minutes. A 2 mol/L aqueous sodium carbonate solution (19 mL) was added dropwise over 15 minutes, and the reaction solution was refluxed under heating and stirring for 4 hours. After completion of the reaction, the solution was allowed to cool to room temperature, and a sufficient amount of water was added. The solid was collected by filtration and washed with methanol. The solid was heated and dissolved in toluene and passed through a silica gel short column. The solution was distilled off and the obtained solid was recrystallized with toluene to obtain a white solid of BH1-2 (3.8 g, yield: 40%). The result of mass spectrometric analysis was m/e=495 to the molecular weight 494.59, and the compound was identified as an intended product.

### (Synthesis Example 3) Synthesis of BH1-3

BH1-3 was synthesized by the following synthesis route.

### (1) Synthesis of Intermediate 10

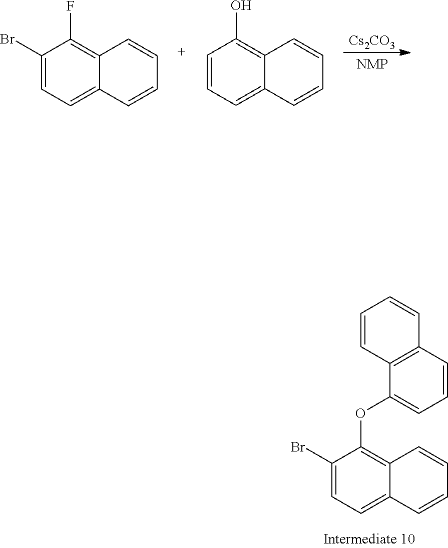

2-Bromo-1-fluoronaphthalene (21.4 g), naphthalene-1-ol (14.4 g), and cesium carbonate (68 g) were added to 300 mL of NMP, and the mixture was heated and stirred at 130° C. for 24 hours under an argon atmosphere. The organic phase was separated by addition of t-butyl methyl ether and water, concentration under a reduced pressure was performed, and the obtained residue was purified by silica gel chromatography to obtain Intermediate 10 as a light yellow oily product (25.2 g, yield: 76%).

### (2) Synthesis of Intermediate 11

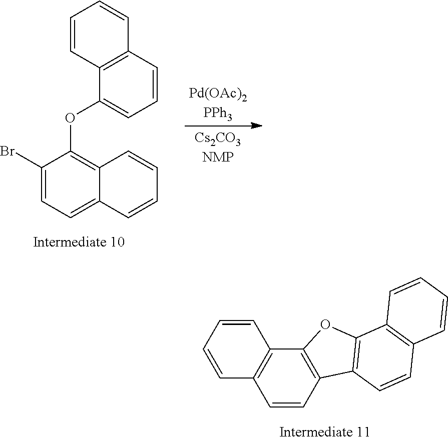 [SMILES: Brc1ccc2ccccc2c1Oc1cccc2ccccc12 ; c1ccc2c(c1)ccc1c3ccc4ccccc4c3oc21]

Intermediate 10 (26.5 g), cesium carbonate (49.5 g), palladium acetate (0.85 g), and triphenylphosphine (2.0 g) were added to 300 mL of NMP, and the mixture was stirred under heating at 160° C. for 24 hours under an argon atmosphere. The temperature was returned to room temperature, and the precipitated solid was collected by filtration, washed with dichloromethane and methanol, and then recrystallized with tetrahydrofuran for purification. Intermediate 11 was obtained as a white solid (17.7 g, yield: 87%).

### (3) Synthesis of Intermediate 12

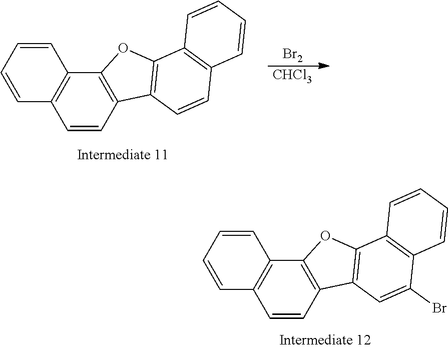

Intermediate 11 (13.3 g) was dissolved in 450 mL of chloroform, cooled to 0° C., and stirred. Then, bromine (7.1 g) dissolved in 50 mL of chloroform was added dropwise. The mixture was stirred at 0° C. for two hours, then returned to room temperature, an aqueous sodium hydroxide solution was added to make the reaction solution alkaline, and then the chloroform phase was separated. The chloroform phase was concentrated under a reduced pressure, and the obtained residue was purified by silica gel chromatography to obtain Intermediate 11 as a white solid (15.1 g, yield: 88%).

### (4) Synthesis of BH1-3

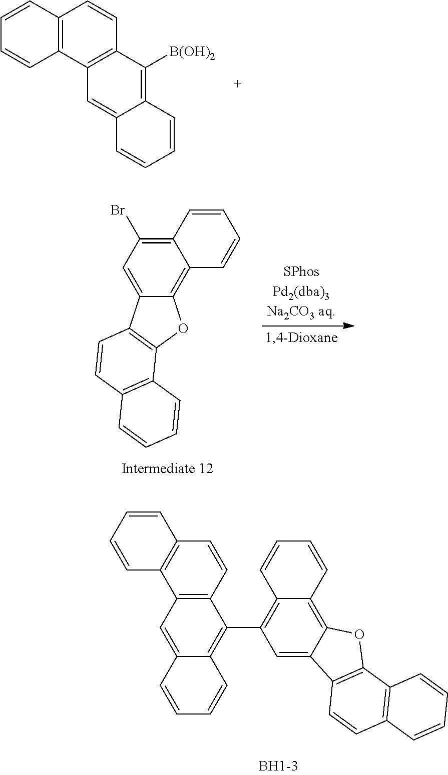 [SMILES: OB(O)c1c2ccccc2cc2c1ccc1ccccc12 ; Brc1cc2c3ccc4ccccc4c3oc2c2ccccc12 ; c1ccc2c(-c3cc4c5ccc6ccccc6c5oc4c4ccccc34)c3ccc4ccccc4c3cc2c1]

Intermediate 12 (5.0 g), tetraphene-7-yl boronic acid (4.7 g), 2-dicyclohexylphosphino-2′,6′-dimethoxybiphenyl (SPhos, 0.47 g), and tris(dibenzylideneacetone)dipalladium(0) (0.26 g) were added to 120 mL of 1,4-dioxane, and the mixture was refluxed under an argon atmosphere under heating and stirring for 30 minutes. A 2 mol/L aqueous sodium carbonate solution (14 mL) was added dropwise over 15 minutes, and the reaction solution was refluxed under heating and stirring for 4 hours. After completion of the reaction, the solution was allowed to cool to room temperature, and a sufficient amount of water was added. The solid was collected by filtration and washed with methanol. The solid was heated and dissolved in toluene and passed through a silica gel short column. The solution was distilled off and the obtained solid was recrystallized with toluene to obtain a white solid of BH1-3 (3.5 g, yield: 49%). The result of mass spectrometric analysis was m/e=495 to the molecular weight 494.59, and the compound was identified as an intended product.

### (Synthesis Example 4) Synthesis of BH1-4

BH1-4 was synthesized by the following synthesis route.

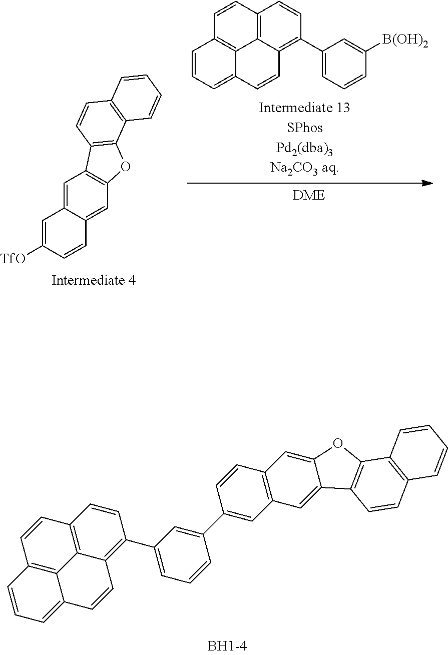 [SMILES: O=S(=O)(Oc1ccc2cc3oc4c5ccccc5ccc4c3cc2c1)C(F)(F)F ; OB(O)c1cccc(-c2ccc3ccc4cccc5ccc2c3c45)c1 ; c1cc(-c2ccc3cc4oc5c6ccccc6ccc5c4cc3c2)cc(-c2ccc3ccc4cccc5ccc2c3c45)c1]

A white solid of BH1-4 (2.7 g, yield: 69%) was obtained by the method described in (5) of Synthesis Example 1 using Intermediate 4 (3.0 g) and Intermediate 13 (2.3 g). The result of mass spectrometric analysis was m/e=545 to the molecular weight 544.65, and the compound was identified as an intended product.

### (Synthesis Example 5) Synthesis of BH1-5

BH1-5 was synthesized by the following synthesis route.

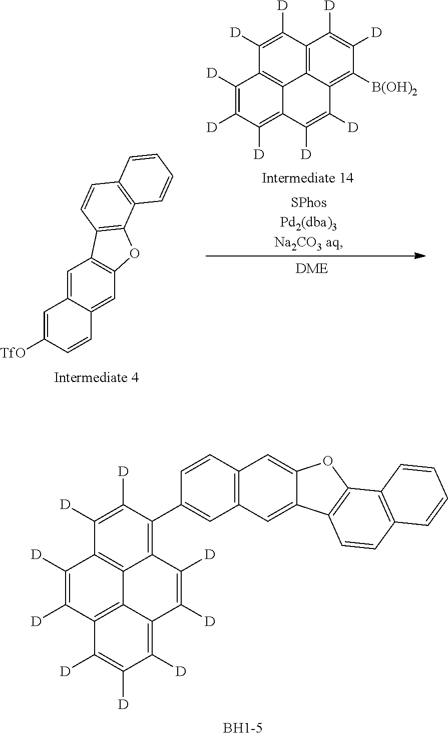 [SMILES: O=S(=O)(Oc1ccc2cc3oc4c5ccccc5ccc4c3cc2c1)C(F)(F)F ; [2H]c1c([2H])c2c([2H])c([2H])c3c([2H])c([2H])c(B(O)O)c4c([2H])c([2H])c(c1[2H])c2c34 ; [2H]c1c([2H])c2c([2H])c([2H])c3c([2H])c([2H])c(-c4ccc5cc6oc7c8ccccc8ccc7c6cc5c4)c4c([2H])c([2H])c(c1[2H])c2c34 ; "BH1-5"]

A white solid of BH1-5 (1.5 g, yield: 65%) was obtained by the method described in (5) of Synthesis Example 1 using Intermediate 4 (2.0 g) and Intermediate 14 (1.3 g). The result of mass spectrometric analysis was m/e=478 to the molecular weight 477.61, and the compound was identified as an intended product.

### (Synthesis Example 6) Synthesis of BH1-6

BH1-6 was synthesized by the following synthesis route.

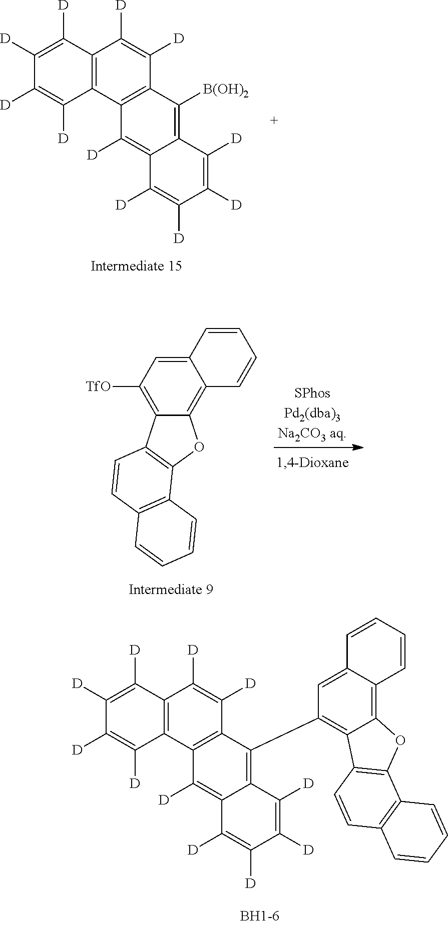 [SMILES: [2H]c1c([2H])c([2H])c2c([2H])c3c(c([2H])c([2H])c4c([2H])c([2H])c([2H])c([2H])c43)c(B(O)O)c2c1[2H] ; O=S(=O)(Oc1cc2ccccc2c2oc3c4ccccc4ccc3c12)C(F)(F)F ; [2H]c1c([2H])c([2H])c2c([2H])c3c(c([2H])c([2H])c4c([2H])c([2H])c([2H])c([2H])c43)c(-c3cc4ccccc4c4oc5c6ccccc6ccc5c34)c2c1[2H]]

A white solid of BH1-6 (3.4 g, yield: 56%) was obtained by the method described in (6) of Synthesis Example 2 using Intermediate 15 (4.1 g) and Intermediate 9 (5.0 g). The result of mass spectrometric analysis was m/e=506 to the molecular weight 505.66, and the compound was identified as an intended product.

Although several embodiments and/or examples of the present invention have been described in detail above, those skilled in the art will readily understand that numerous modifications can be made to these exemplary embodiments and/or examples without substantially departing from the novel teachings and effects of the present invention. Therefore, many of these modifications fall within the scope of the present invention.

All literature cited in this specification, as well as the contents of the applications on which the priority claim under the Paris Convention is based, are incorporated herein by reference in their entirety.

1. An organic electroluminescence device comprising
a cathode,
an anode, and
an emitting layer disposed between the cathode and the anode,
wherein the emitting layer comprises a first emitting layer and a second emitting layer, and
the first emitting layer contains one or more compounds selected from the group consisting of a compound represented by each of the following formulas (1) to (4): 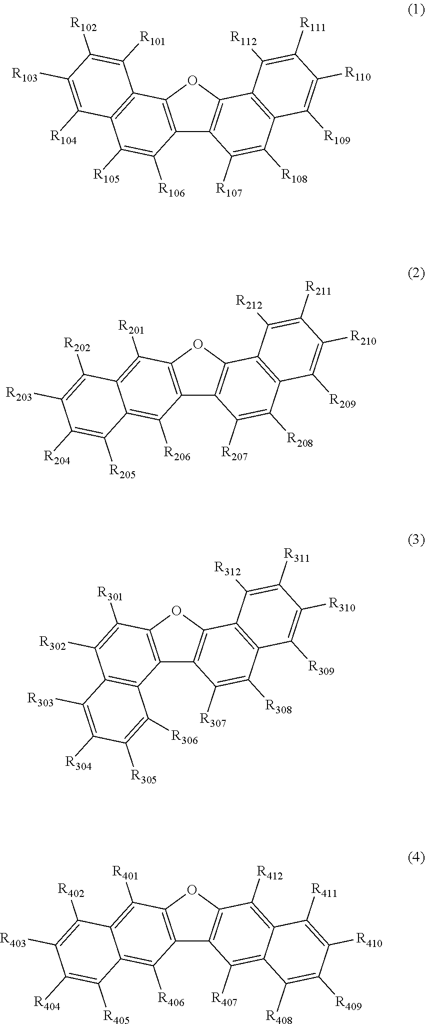
wherein in the formulas (1) to (4),
at least one of R₁₀₁ to R₁₁₂, at least one of R₂₀₁ to R₂₁₂, at least one of R₃₀₁ to R₃₁₂, and at least one of R₄₀₁ to R₄₁₂ are a single bond bonded to a group represented by the following formula (A1): 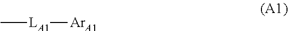
in the formula (A1),
L_{A1} is
a single bond,
a substituted or unsubstituted arylene group having 6 to 20 ring carbon atoms, or
a substituted or unsubstituted divalent heterocyclic group having 5 to 19 ring atoms,
Ar_{A1} is
a substituted or unsubstituted aryl group having 6 to 30 ring carbon atoms, or
a substituted or unsubstituted monovalent heterocyclic group having 5 to 30 ring atoms,
R₁₀₁ to R₁₁₂, R₂₀₁ to R₂₁₂, R₃₀₁ to R₃₁₂, and R₄₀₁ to R₄₁₂ which are not a single bond bonded to the group represented by the formula (A1) are independently
a hydrogen atom,
a substituted or unsubstituted aryl group having 6 to 20 ring carbon atoms, or
a substituted or unsubstituted monovalent heterocyclic group having 5 to 19 ring atoms, and
when two or more groups represented by the formula (A1) are present, the two or more groups represented by the formula (A1) may be the same as or different from each other.

2. The organic electroluminescence device according to claim 1, wherein Ar_{A1} is a substituted or unsubstituted aryl group having 6 to 30 ring carbon atoms.

3. The organic electroluminescence device according to claim 1, wherein Ar_{A1} is
a substituted or unsubstituted phenyl group,
a substituted or unsubstituted naphthyl group, or
a substituted or unsubstituted pyrenyl group.

4. The organic electroluminescence device according to claim 1, wherein Ar_{A1} is a substituted or unsubstituted monovalent heterocyclic group having 5 to 30 ring atoms.

5. The organic electroluminescence device according to claim 1, wherein Ar_{A1} is
a substituted or unsubstituted pyrenyl group,
a substituted or unsubstituted benzanthryl group, or
a substituted or unsubstituted benzoxanthenyl group.

6. The organic electroluminescence device according to claim 1, wherein L_{A1} is
a single bond, or
a substituted or unsubstituted arylene group having 6 to 20 ring carbon atoms.

7. The organic electroluminescence device according to claim 1, wherein the compound represented by each of the formulas (1) to (4) is a compound represented by each of the following formulas (11) to (41): 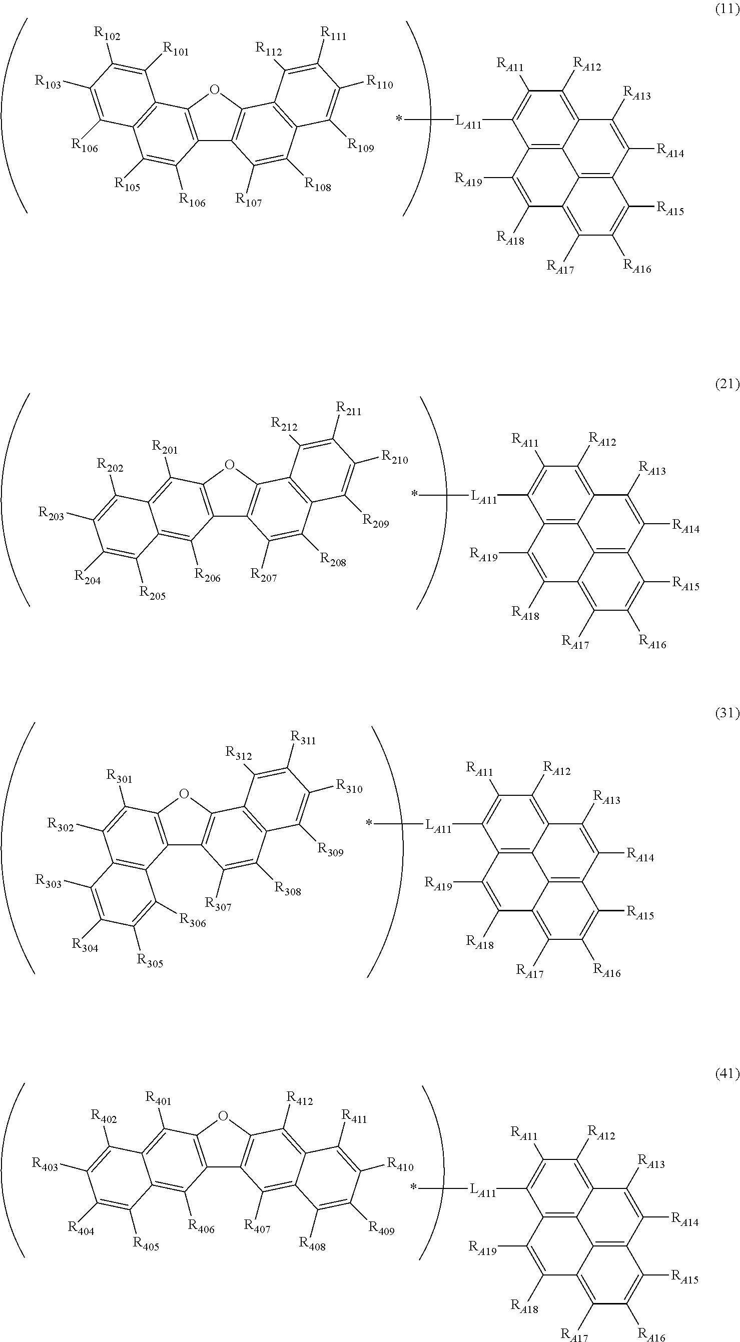
wherein in the formulas (11) to (41),
at least one of R₁₀₁ to R₁₁₂, at least one of R₂₀₁ to R₂₁₂, at least one of R₃₀₁ to R₃₁₂, and at least one of R₄₀₁ to R₄₁₂ are a single bond bonded to L_{A11},
R₁₀₁ to R₁₁₂, R₂₀₁ to R₂₁₂, R₃₀₁ to R₃₁₂, and R₄₀₁ to R₄₁₂ which are not a single bond bonded to L_{A11} are independently
a hydrogen atom,
a substituted or unsubstituted aryl group having 6 to 20 ring carbon atoms, or
a substituted or unsubstituted monovalent heterocyclic group having 5 to 19 ring atoms,
L_{A11} is
a single bond, or
a substituted or unsubstituted arylene group having 6 to 20 ring carbon atoms,
R_{A11} to R_{A19} are independently a hydrogen atom or a substituent R,
the substituent R is selected from the group consisting of
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms, 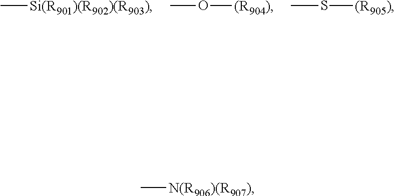
a halogen atom, a cyano group, a nitro group,
a substituted or unsubstituted aryl group having 6 to 50 ring carbon atoms, and
a substituted or unsubstituted monovalent heterocyclic group having 5 to 50 ring atoms,
when two or more substituents R are present, the two or more substituents R may be the same as or different from each other,
R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms, and
when two or more of each of R₉₀₁ to R₉₀₇ are present, the two or more of each of R₉₀₁ to R₉₀₇ may be the same as or different from each other.

8. The organic electroluminescence device according to claim 7, wherein the compound represented by the formula (21) is a compound represented by the following formula (211): 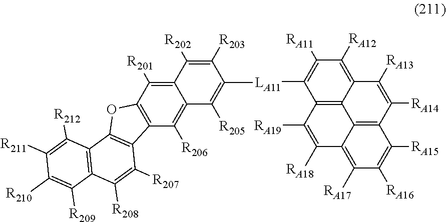
wherein in the formula (211),
L_{A11}, R_{A11} to R_{A19}, R₂₀₁ to R₂₀₃, and R₂₀₅ to R₂₁₂ are as defined in the above formula (21).

9. The organic electroluminescence device according to claim 7, wherein R_{A11} to R_{A19} are a hydrogen atom.

10. The organic electroluminescence device according to claim 7, wherein at least one of R_{A11} to R_{A19} which are a hydrogen atom is a deuterium atom.

11. The organic electroluminescence device according to claim 1, wherein the compound represented by each of the formulas (1) to (4) is a compound represented by each of the following formulas (12) to (42): 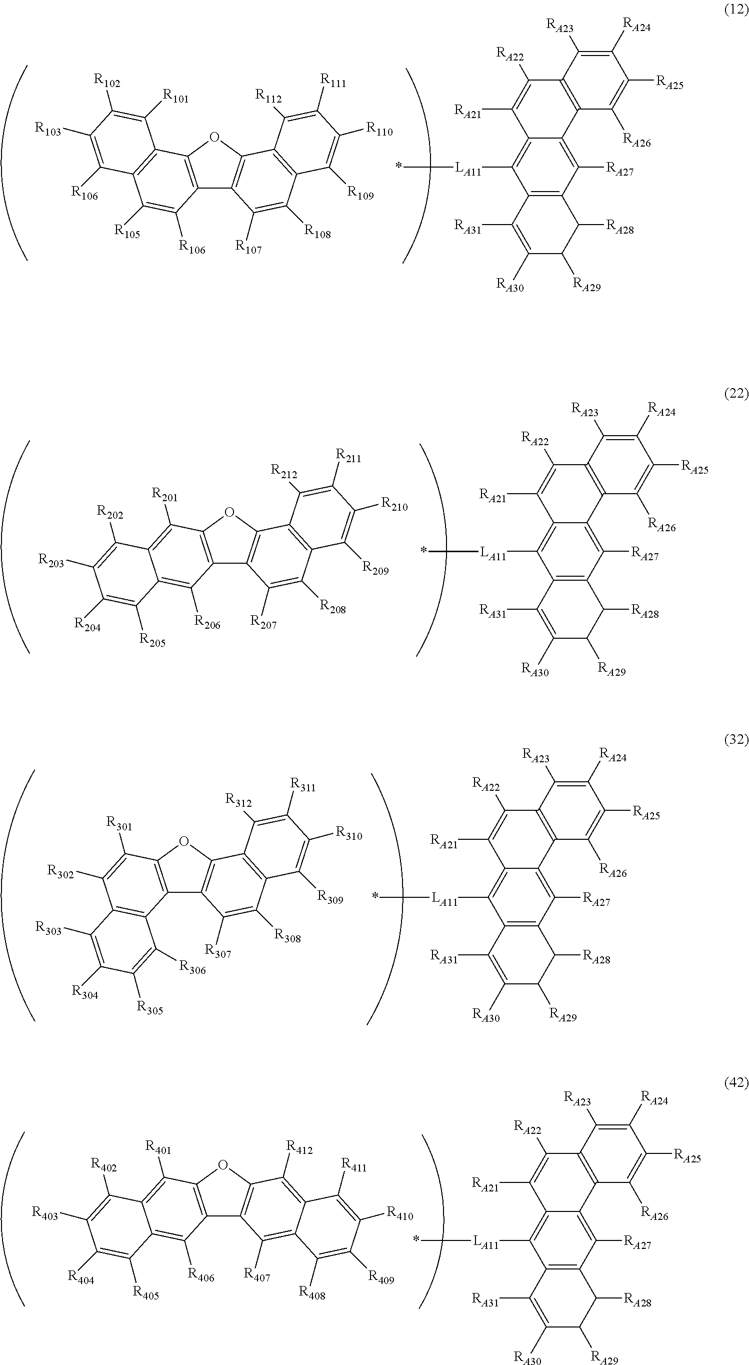
wherein in the formulas (12) to (42),
at least one of R₁₀₁ to R₁₁₂, at least one of R₂₀₁ to R₂₁₂, at least one of R₃₀₁ to R₃₁₂, and at least one of R₄₀₁ to R₄₁₂ are a single bond bonded to L_{A11},
R₁₀₁ to R₁₁₂, R₂₀₁ to R₂₁₂, R₃₀₁ to R₃₁₂, and R₄₀₁ to R₄₁₂ which are not a single bond bonded to L_{A11} are independently
a hydrogen atom,
a substituted or unsubstituted aryl group having 6 to 20 ring carbon atoms, or
a substituted or unsubstituted monovalent heterocyclic group having 5 to 19 ring atoms,
L_{A11} is
a single bond, or
a substituted or unsubstituted arylene group having 6 to 20 ring carbon atoms,
R_{A21} to R_{A31} are independently a hydrogen atom or a substituent R,
the substituent R is selected from the group consisting of
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms, 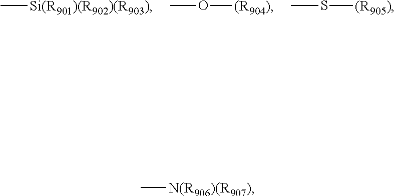
a halogen atom, a cyano group, a nitro group,
a substituted or unsubstituted aryl group having 6 to 50 ring carbon atoms, and
a substituted or unsubstituted monovalent heterocyclic group having 5 to 50 ring atoms,
when two or more substituents R are present, the two or more substituents R may be the same as or different from each other,
R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms, and
when two or more of each of R₉₀₁ to R₉₀₇ are present, the two or more of each of R₉₀₁ to R₉₀₇ may be the same as or different from each other.

12. The organic electroluminescence device according to claim 10, wherein the compound represented by the formula (12) is a compound represented by the following formula (121) or (122): 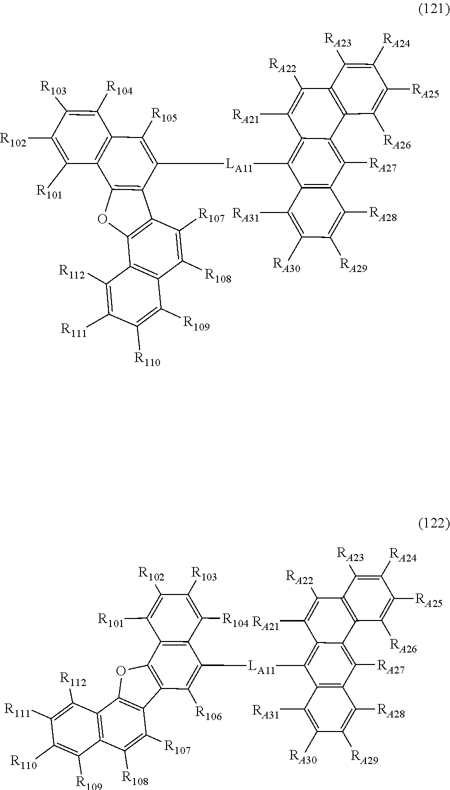
wherein in the formulas (121) and (122),
L_{A11}, R_{A21} to R_{A31}, and R₁₀₁ to R₁₁₂ are as defined in the above formula (12).

13. The organic electroluminescence device according to claim 11, wherein R_{A21} to R_{A31} are a hydrogen atom.

14. The organic electroluminescence device according to claim 11, wherein at least one of R_{A21} to R_{A31} which are a hydrogen atom is a deuterium atom.

15. The organic electroluminescence device according to claim 7, wherein R₁₀₁ to R₁₀₂, R₂₀₁ to R₂₁₂, R₃₀₁ to R₃₁₂, and R₄₀₁ to R₄₁₂ which are not a single bond bonded to L_{A11} are a hydrogen atom.

16. The organic electroluminescence device according to claim 1, wherein a substituent in the case of “substituted or unsubstituted” is
an unsubstituted aryl group having 6 to 20 ring carbon atoms, or
an unsubstituted monovalent heterocyclic group having 5 to 19 ring atoms.

17. The organic electroluminescence device according to claim 1, wherein the emitting layer includes the first emitting layer and the second emitting layer in this order from the anode side.

18. The organic electroluminescence device according to claim 17, wherein the first emitting layer and the second emitting layer are directly adjacent to each other.

19. The organic electroluminescence device according to claim 1, which comprises a hole-transporting layer between the anode and the emitting layer.

20. The organic electroluminescence device according to claim 1, which comprises an electron-transporting layer between the cathode and the emitting layer.

21. An electronic apparatus comprising the organic electroluminescence device according to claim 1.
